(19) United States
(12) Patent Application Publication
(10) Pub. No.: US 2025/0031570 A1
(43) Pub. Date: Jan. 23, 2025

(54) ORGANIC ELECTROLUMINESCENT MATERIAL COMPOSITION AND APPLICATION THEREOF

(71) Applicant: NINGBO LUMILAN ADVANCED MATERIALS CO., LTD., Ningbo, (CN)

(72) Inventors: Ting-Wei WEI, Ningbo (CN); Fengjiao LIU, Ningbo (CN); Qinghua ZOU, Ningbo (CN); Cong TANG, Ningbo (CN); Xiaoxin RAN, Ningbo (CN); Binyu XU, Ningbo (CN); Xiaoyun XU, Ningbo (CN); Renzhou WANG, Ningbo (CN); Qixiang SONG, Ningbo (CN); Huanda DING, Ningbo (CN)

(73) Assignee: NINGBO LUMILAN ADVANCED MATERIALS CO., LTD., Ningbo (CN)

(21) Appl. No.: 18/587,881

(22) Filed: Feb. 26, 2024

(30) Foreign Application Priority Data
Jun. 30, 2023 (CN) 202310803157.7
Dec. 29, 2023 (CN) 202311873192.2

(51) Int. Cl. H10K 85/60; C09K 11/06; H10K 50/11

(52) U.S. Cl. CPC H10K 85/654; C09K 11/06; H10K 50/11; H10K 85/6572; H10K 85/6574; H10K 85/6576; C09K 2211/1018

(57) ABSTRACT

The present application relates to the technical field of display, in particular to an organic electroluminescent material composition and an application thereof. The organic electroluminescent material composition of the present application comprise compound N and compound M, compound N and compound M cooperate with each other, resulting in an organic electroluminescent device comprising this material with better lifespan, lower driving voltage and higher efficiency at the same time.

### TECHNICAL FIELD

The present application relates to the technical field of display, in particular to an organic electroluminescent material composition and an application thereof.

### BACKGROUND

An organic light emitting device (OLED) converts electrical energy into light by applying electricity to an organic electroluminescent material, and typically includes an anode, a cathode, and an organic layer formed between these two electrodes. The organic layer of the organic EL device may contain a hole injection layer, a hole transport layer, a hole auxiliary layer, a light emitting auxiliary layer, an electron blocking layer, a light emitting layer (containing a host material and a dopant material), an electron buffer layer, a hole blocking layer, an electron transport layer, an electron injection layer, etc. The materials used in the organic layer can be divided into hole injection materials, hole transport materials, hole auxiliary materials, light emitting auxiliary materials, electron blocking materials, light emitting materials, electron buffer materials, hole blocking materials, electron transport materials, electron injection materials, etc. depending on their functions. In the organic EL device, holes from the anode and electrons from the cathode are injected into the light emitting layer by applying voltages, and high-energy excitons are produced by the recombination of the holes and the electrons. Organic light emitting compounds move to an excited state through energy and the organic light emitting compounds emit light through energy when the organic light emitting compounds return to a ground state from the excited state.

At present, due to the low stability and unbalanced carrier mobility of organic functional materials, etc., resulting in problems such as high driving voltage, and short lifespan of organic light-emitting diodes, thereby severely limiting the application of organic light-emitting diodes.

### SUMMARY OF THE INVENTION

The purpose of the present application is to overcome the defects of high driving voltage and short lifespan of organic light-emitting diodes caused by low stability and unbalanced carrier mobility of organic electroluminescent materials, and then provide an organic electroluminescent material composition and an application thereof.

In the present application, the definitions of substituent terms are as follows.

As used in the present application, the term “halogen” may include fluorine, chlorine, bromine or iodine.

As used in the present application, the term “C1-C30 alkyl” refers to a univalent substituent derived from linear or branched saturated hydrocarbon with 1 to 30 carbon atoms, and its examples include but are not limited to methyl, ethyl, propyl, isobutyl, sec-butyl, tert-butyl, pentyl, isopentyl and hexyl.

As used in the present application, the term “C3-C30 cycloalkyl” refers to monocyclic hydrocarbon or polycyclic hydrocarbon with 1 to 30 cycle main chain carbon atoms, and the C3-C30 cycloalkyl may include cyclopropyl, cyclobutyl, adamantyl, etc.

The aryl and arylenyl in the present application include monocyclic, polycyclic or fused-ring aryls, and rings may be separated by short non-aromatic units and may contain spiro structures, the aryl includes but not limited to phenyl, biphenyl, triphenyl, naphthyl, phenanthryl, anthryl, fluorenyl, spirodifluorenyl, etc. The arylenyl includes but not limited to phenylenyl, biphenylidenyl, tribiphenylidenyl, naphthenyl, phenanthrylenyl, anthrylenyl, fluorenylidenyl, spirodifluorenylidenyl, etc.

The heteroaryl and heteroarylenyl in the present application include monocyclic, polycyclic or fused-ring heteroaryls, rings may be separated by short non-aromatic units, and heteroatoms include nitrogen, oxygen and sulfur. The heteroaryl include but are not limited to furyl, thienyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, benzofuryl, benzothienyl, isobenzofuryl, dibenzofuryl, dibenzothienyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenothiazinyl, phenanthridinyl, benzodioxolyl, dihydroacridinyl, and derivatives thereof, etc. The heteroarylenyl includes but are not limited to furylenyl, thienylenyl, pyrrolylenyl, imidazolylenyl, pyrazolylenyl, thiazolylenyl, thiadiazolylenyl, isothiazolylenyl, isoxazolylenyl, oxazolylenyl, oxadiazolylenyl, triazinylenyl, tetrazinylenyl, triazolylenyl, tetrazolylenyl, furazanylenyl, pyridylenyl, pyrazinylenyl, pyrimidinylenyl, pyridazinylenyl, benzofurylenyl, benzothienylenyl, isobenzofurylenyl, dibenzofurylenyl, dibenzothienylenyl, benzimidazolylenyl, benzothiazolylenyl, benzoisothiazolylenyl, benzoisoxazolylenyl, benzoxazolylenyl, isoindolylenyl, indolylenyl, indazolylenyl, benzothiadiazolylenyl, quinolylenyl, isoquinolylenyl, cinnolinylenyl, quinazolinylenyl, quinoxalinylenyl, carbazolylenyl, phenoxazinylenyl, phenothiazinylenyl, phenanthridinylenyl, benzodioxolylenyl, dihydroacridinylenyl, and derivatives thereof.

As used in the present application, the term “substituted” refers to the substitution of a hydrogen atom in a compound by another substituent. The position is not limited to a specific position, as long as hydrogen(s) at that position can be substituted by substituent(s). When two or more substituents appear, they can be the same or different.

As used in the present application, unless otherwise specified, hydrogen atoms include protium, deuterium, and tritium.

In the present application, in the limitation of the groups, the range of carbon atom number is limited, which is any integer within the limited range, for example, C6-C30 aryl represents that the carbon atom number of aryl may be any integer within the range of 6-30, such as 6, 8, 10, 13, 15, 17, 20, 22, 25, or 30, etc.

The solution adopted by the present application is as follows:

The present application provides an organic electroluminescent material composition, wherein the organic electroluminescent material composition comprise compound N and compound M, compound N and compound M are compounds represented by Formula (1):

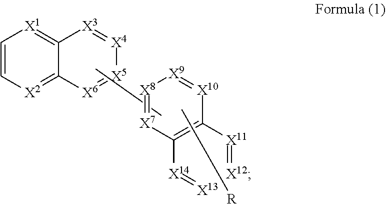

wherein in compound N, R is selected from the following structure:

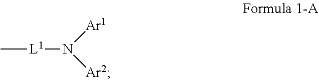

wherein in compound M, R is selected from the following structure:

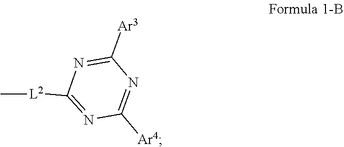

wherein, X¹-X¹⁴ are each independently selected from N or CR⁸, and R⁸ is selected from hydrogen or deuterium;
L¹ and L² are selected from a connecting bond, a substituted or unsubstituted C6-C30 arylenyl, and a substituted or unsubstituted C3-C30 heteroarylenyl;
Ar¹ to Ar⁴ are each independently selected from a substituted or unsubstituted C6-C30 aryl, a substituted or unsubstituted C3-C30 heteroaryl, a substituted or unsubstituted C6-C60 arylamine group, and a substituted or unsubstituted C3-C60 heteroarylamine group; the substituent in the substituted C6-C30 arylenyl, the substituted C3-C30 heteroarylenyl,
the substituted C6-C30 aryl, the substituted C3-C30 heteroaryl, the substituted C6-C60 arylamine group, and the substituted C3-C60 heteroarylamine group is selected from one of or a combination of two of deuterium, halogen, cyano, C1-C6 alkyl, C3-C30 cycloalkyl, C6-C30 aryl, C3-C30 heteroaryl, C6-C60 arylamine group and C3-C60 heteroarylamine group.

It can be understood that compound N has the following structure:

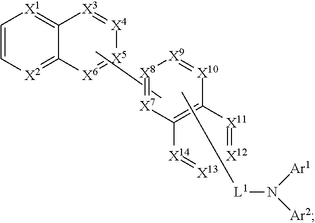

wherein, X¹-X¹⁴, L¹, Ar¹ and Ar² have the same definitions as above.

It can be understood that compound M has the following structure:

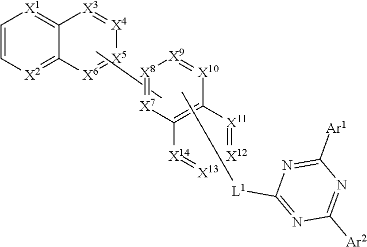

wherein, X¹-X¹⁴, L¹, Ar¹ and Ar² have the same definitions as above.

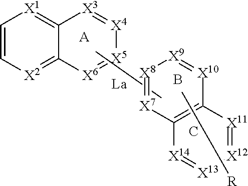

It can be understood, in the present application, R can be substituted on ring B or on ring C; ring A and ring B are connected through La.

Preferably, in formula (1). X¹-X¹⁴ are all selected from CR⁸, R⁸ is selected from hydrogen or deuterium;
preferably, X¹-X¹⁴ are all selected from CR⁸, wherein R⁸ is hydrogen;
preferably, any one of X¹-X⁶ is selected from N, and the remaining is CR⁸;
preferably, any one of X¹-X⁶ is selected from N, and the remaining is CR⁸; any one of X⁷-X¹⁴ is selected from N, and the remaining is CR⁸;
wherein, R⁸ is each present independently, and can be the same or different; R⁸ is selected from hydrogen or deuterium;
preferably, Ar¹-Ar⁴ are each independently selected from a substituted or unsubstituted A group;
the A group comprises: phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, benzofuryl, dibenzofuryl, naphthobenzofuryl, dinaphthalofuryl, benzothienyl, dibenzothienyl, naphthobenzothienyl, carbazolyl, phenylcarbazolyl, benzomethylcarbazolyl, dibenzocarbazolyl, biphenylcarbazolyl, phenanthrobenzofuryl, dibenzofuranofuryl, and phenylcarbazolobenzofuryl;
wherein, the substituent of the substituted A group is selected from one of or a combination of two of deuterium, halogen, cyano, C1-C6 alkyl, C3-C30 cycloalkyl, C6-C30 aryl, C3-C30 heteroaryl, C6-C60 arylamine group, and C3-C60 heteroarylamine group;
preferably, Ar¹-Ar² are each independently selected from phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, dibenzofuryl, naphthobenzofuryl, dibenzothienyl, naphthobenzothienyl, phenylcarbazolyl, benzophenylcarbazolyl, dibenzophenylcarbazolyl, or a group with the following structure:

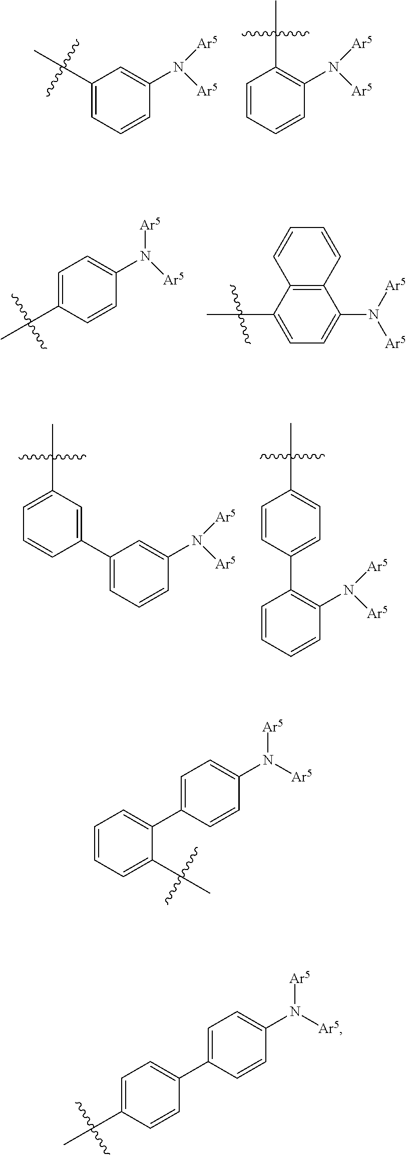

[symbol] represents a single bond connected to adjacent atoms, a plurality of Ar⁵ are each present independently, and the plurality of Ar⁵ can be the same or different;
wherein, Ar⁵ is each independently selected from substituted or unsubstituted B group, and the B group comprises: phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, benzofuryl, dibenzofuryl, naphthobenzofuryl, benzothienyl, dibenzothienyl, naphthobenzothienyl, carbazolyl, phenylcarbazolyl, benzophenylcarbazolyl, and dibenzophenylcarbazolyl;
preferably, the substituent of the substituted B group is selected from one of or a combination of two of deuterium, halogen, cyano, C1-C6 alkyl, C3-C30 cycloalkyl, C6-C30 aryl, C3-C30 heteroaryl, C6-C60 arylamine group, and C3-C60 heteroarylamine group;
preferably, Ar³-Ar⁴ are each independently selected from phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, dibenzofuryl, naphthobenzofuryl, dibenzothienyl, naphthobenzothienyl, carbazolyl, phenylcarbazolyl, benzocarbazolyl, and dibenzocarbazolyl;
preferably, L¹ and L² are each independently selected from a connecting bond, and a substituted or unsubstituted C6-C18 arylenyl;
preferably, L¹ is selected from a connecting bond, phenylenyl and naphthenyl; and
preferably, L² is selected from a connecting bond and phenylenyl.

Preferably, the compound N has a structure as shown in any one of Formula 1-1 to Formula 1-64:

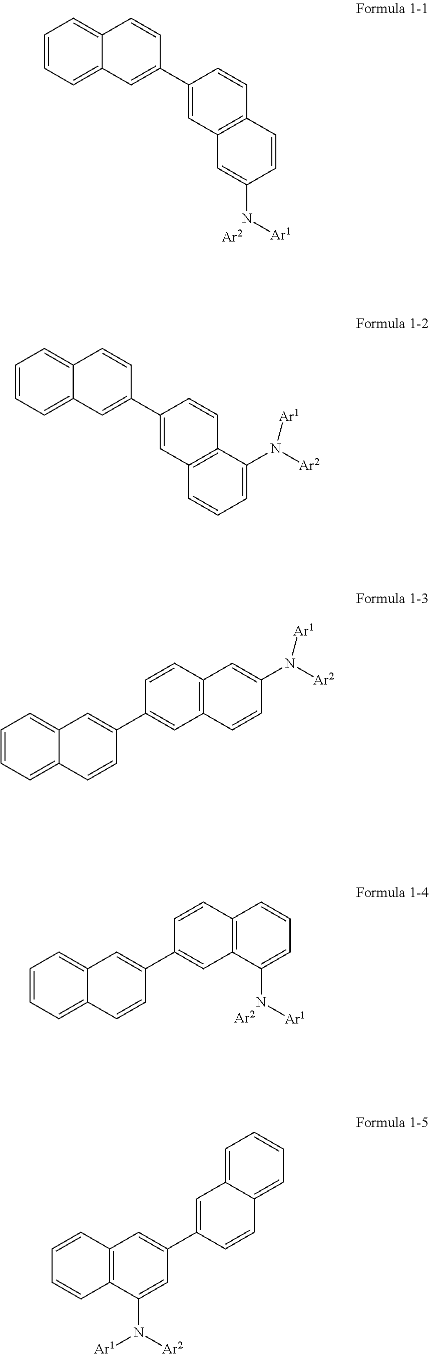

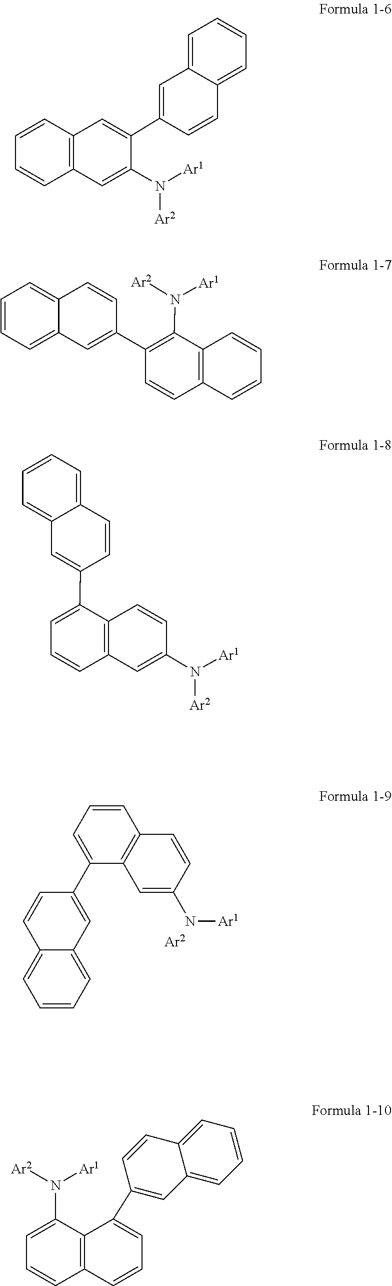

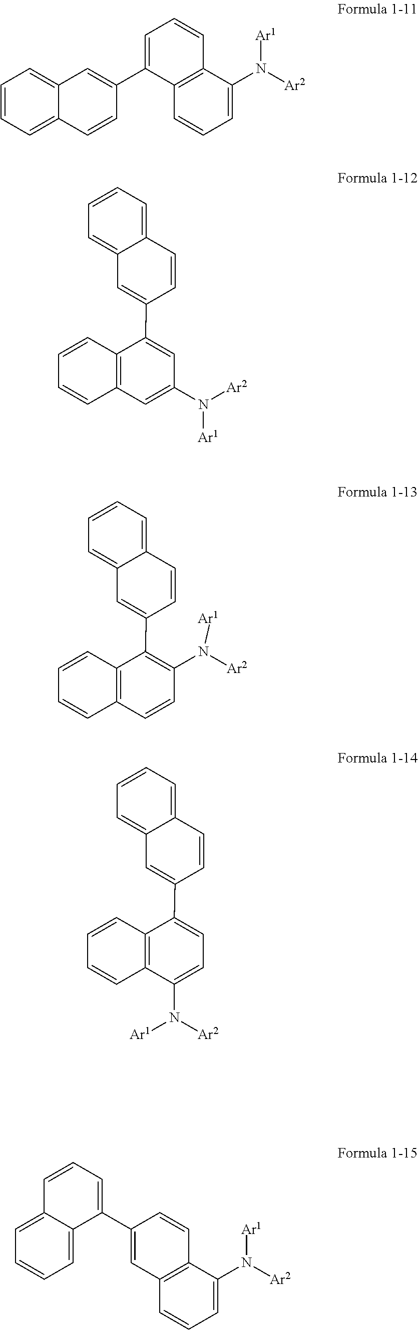

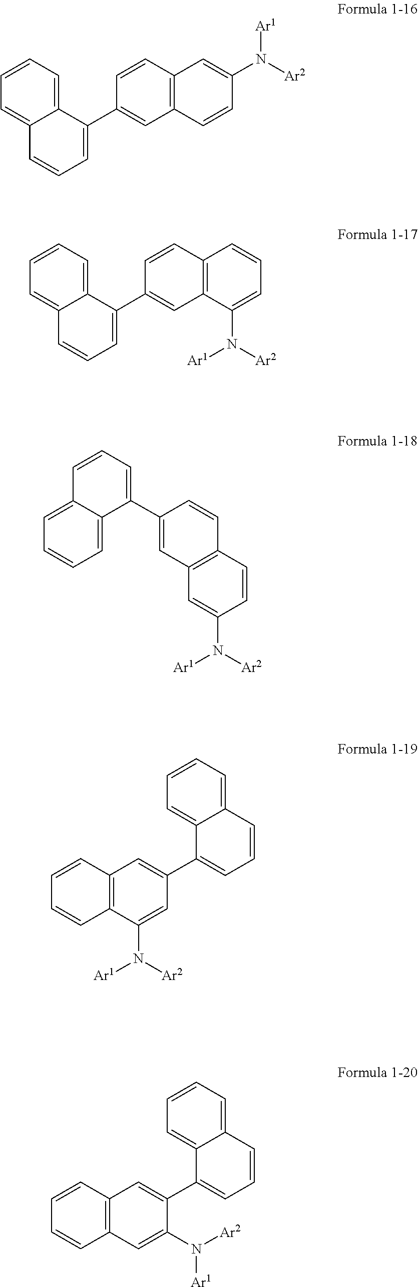

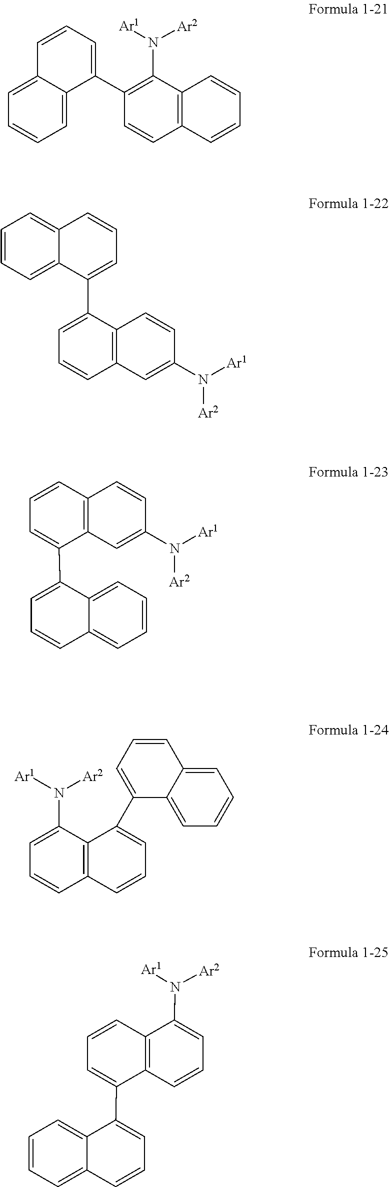

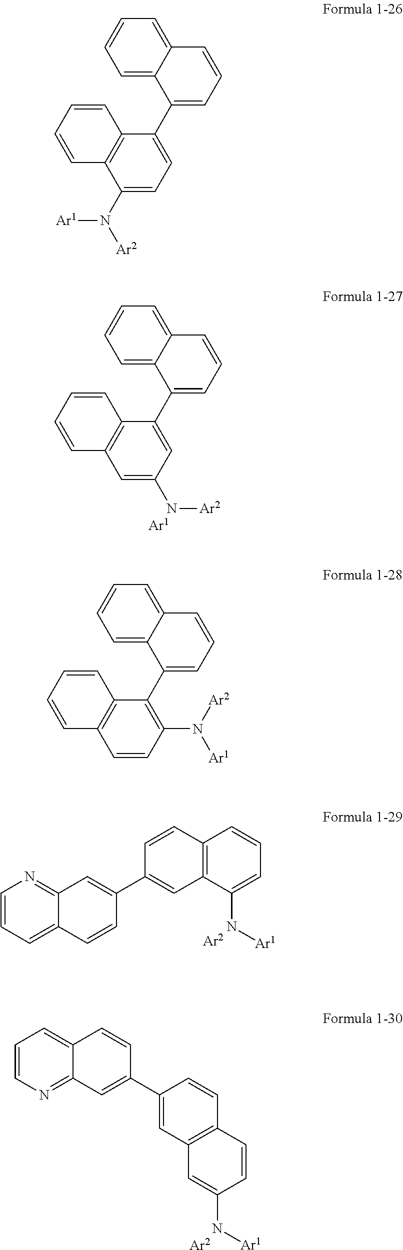

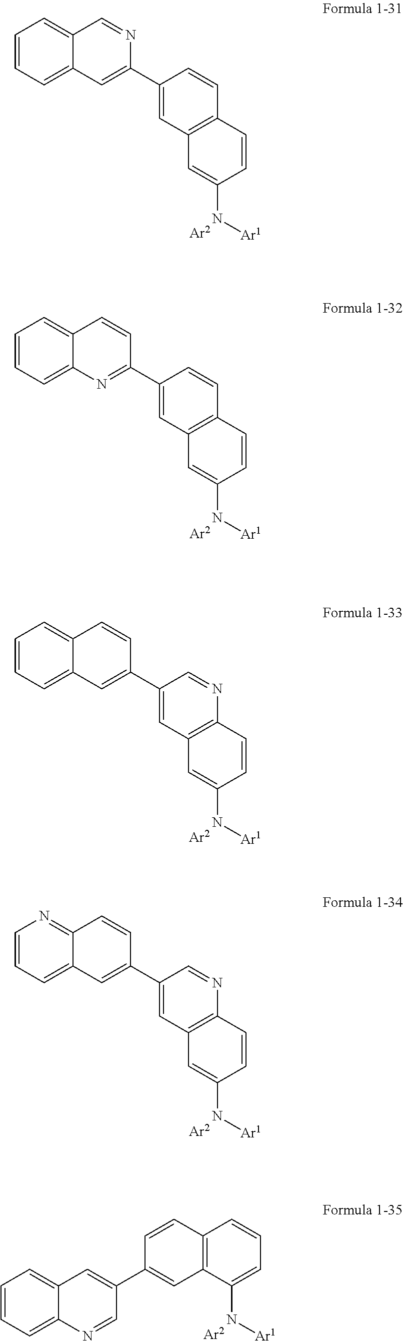

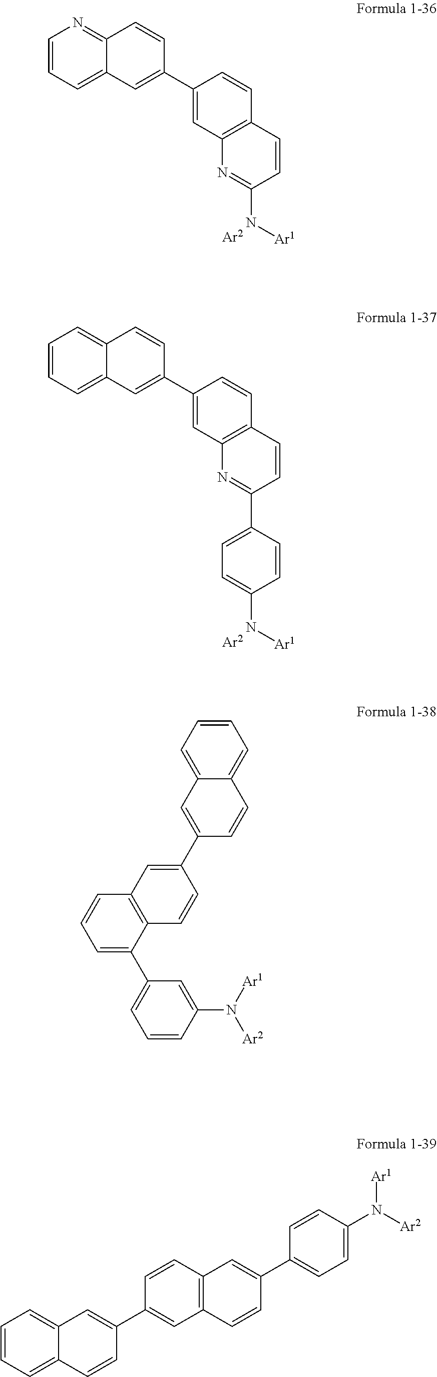

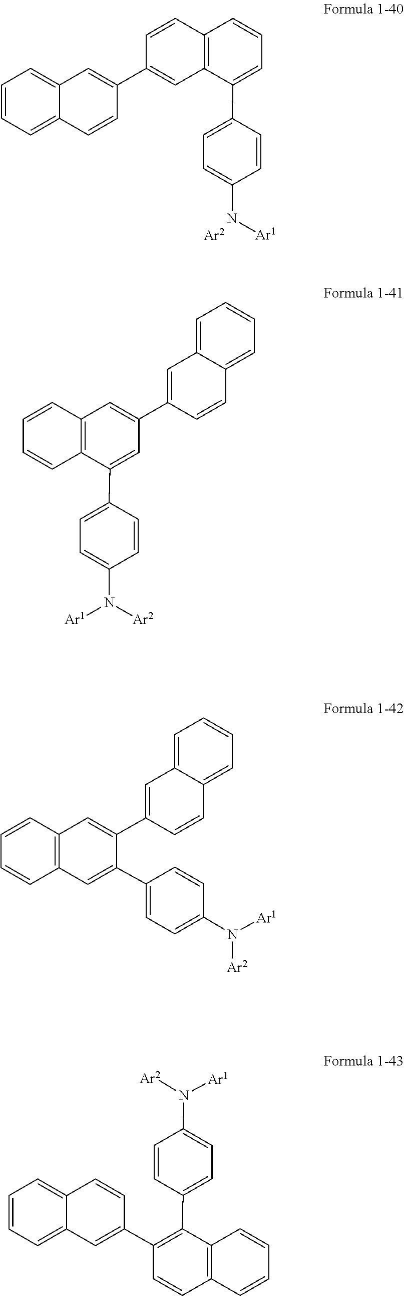

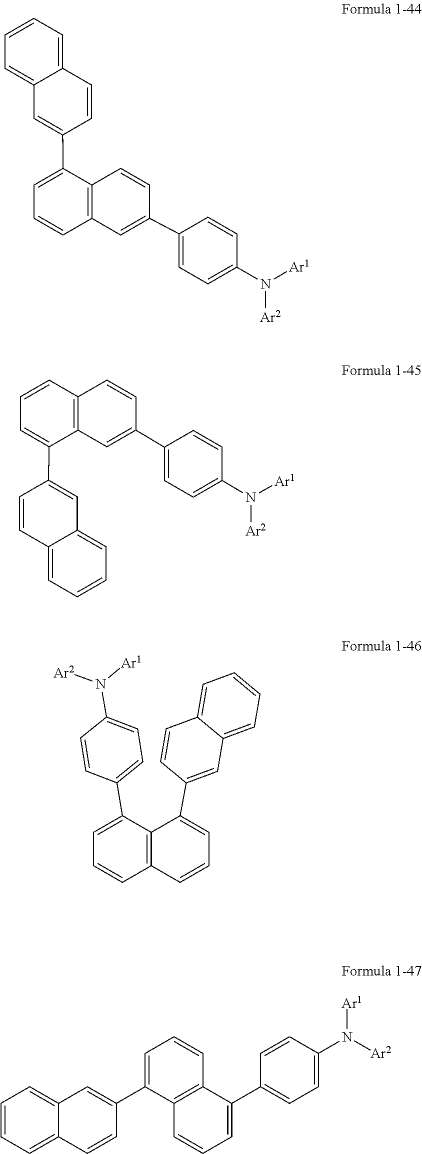

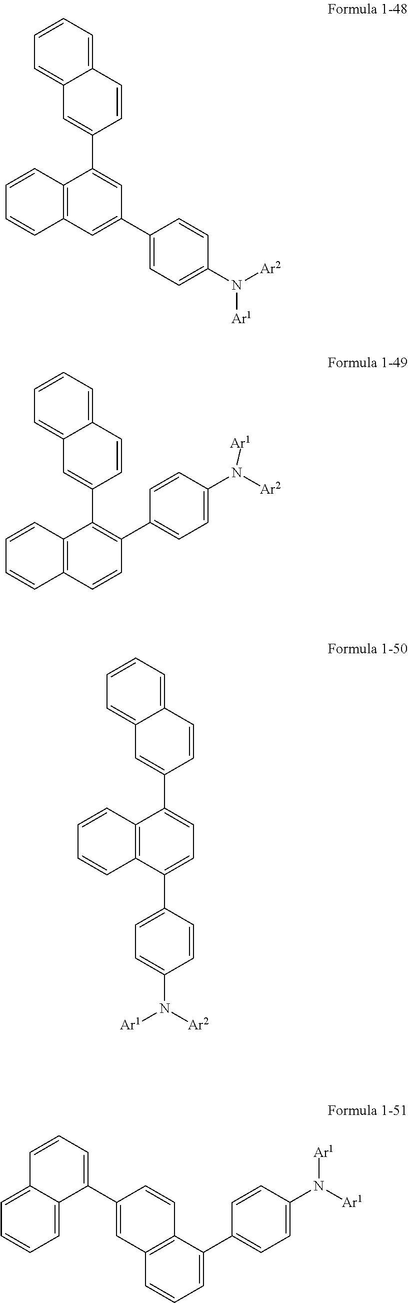

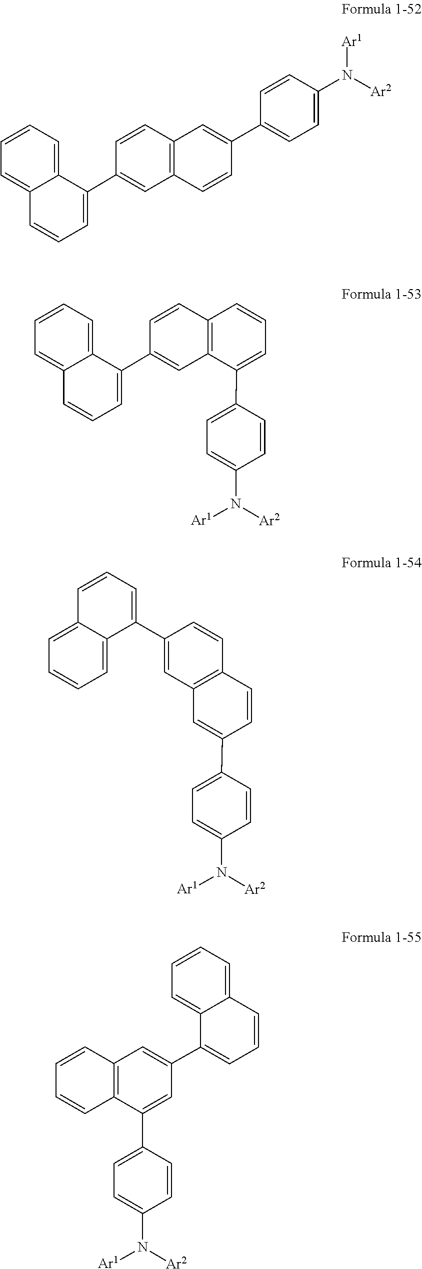

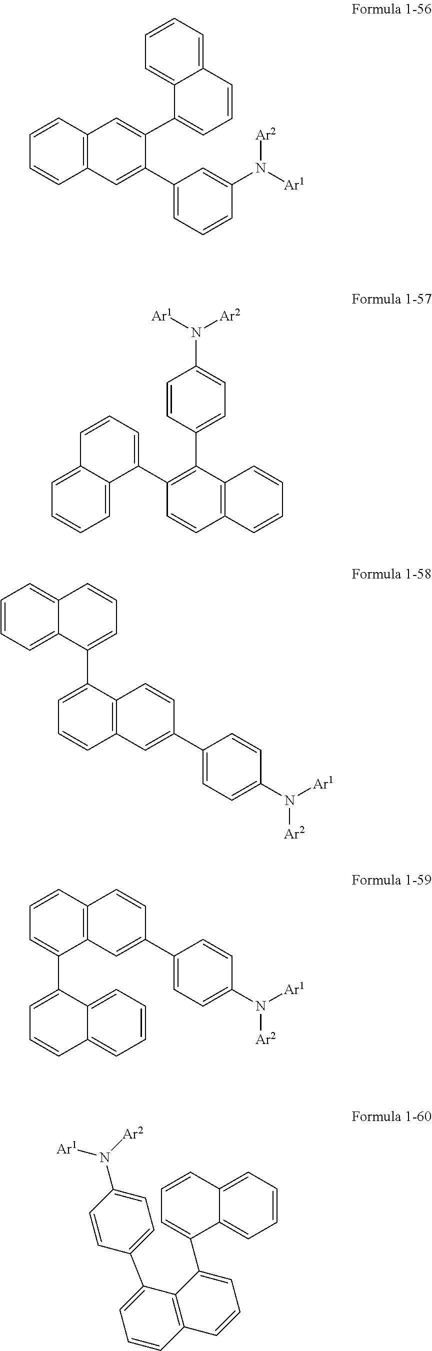

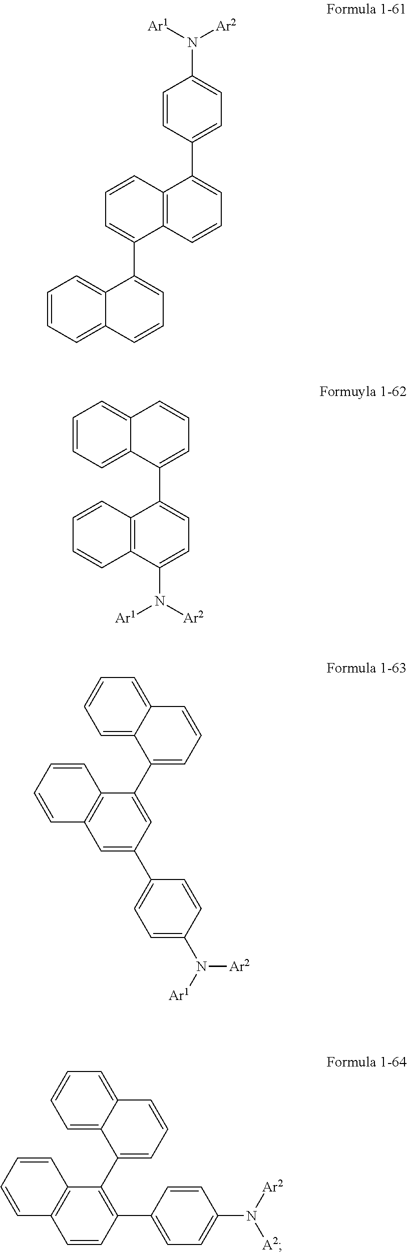

wherein Ar¹-Ar² are defined the same as above.

Preferably, in Formula 1-A, Ar² is selected from the following groups:

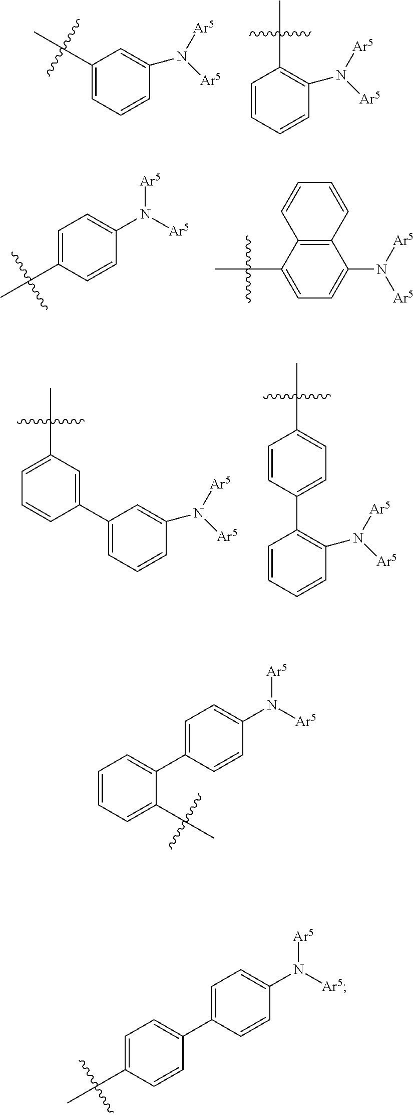

Wherein, Ar⁵ is defined the same as above.

Preferably, the compound N has a structure as shown in any one of Formula 1-a to Formula 1-h:

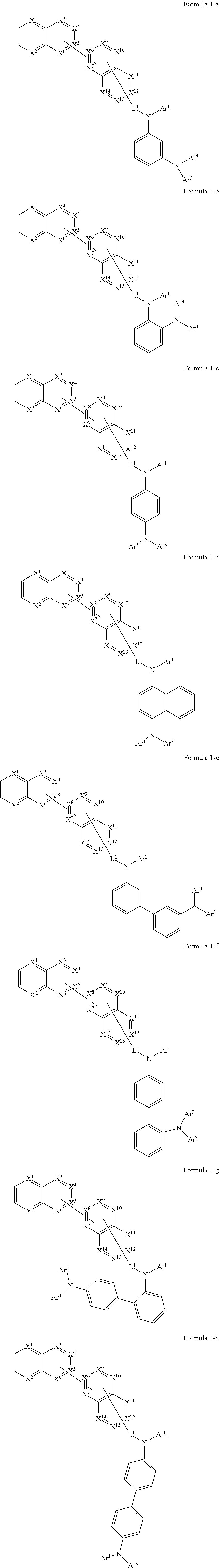

Preferably, the compound N has a structure as shown in any one of Formula 1-i to Formula 1-ii:

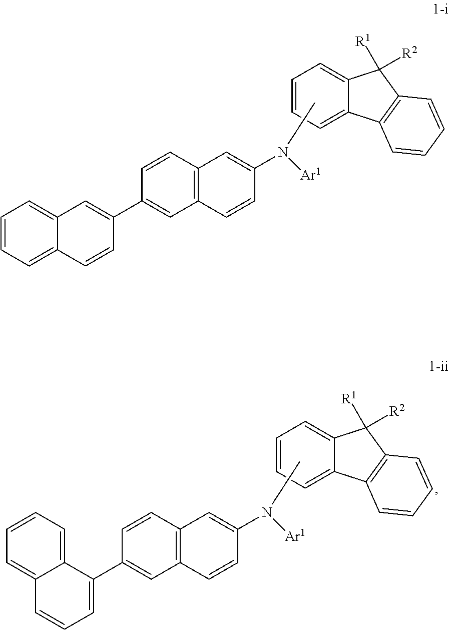

wherein, Ar¹ is defined the same as above; R¹-R² are each independently selected from one of or a combination of two of hydrogen, deuterium, a substituted or unsubstituted C1-C6 alkyl, a substituted or unsubstituted C3-C30 cycloalkyl, a substituted or unsubstituted C6-C30 aryl, and a substituted or unsubstituted C3-C30 heteroaryl;
the substituent of the substituted C1-C6 alkyl, the substituted C3-C30 cycloalkyl, the substituted C6-C30 aryl, the substituted C3-C30 heteroaryl is selected from one of or a combination of two of deuterium, halogen, cyano, a C1-C6 alkyl, a C3-C30 cycloalkyl, a C6-C30 aryl, a C3-C30 heteroaryl, a C6-C60 arylamine group, and a C3-C60 heteroarylamine group.

Preferably, in Formula 1-i or Formula 1-ii, R¹-R² are each independently selected from a C3-C15 cycloalkyl and a C6-C15 aryl;
preferably, R¹ and R² are each independently selected from methyl, phenyl, and fluorenyl;
preferably, Ar¹ is selected from a substituted or unsubstituted C6-C15 aryl and a substituted or unsubstituted C3-C15 heteroaryl; wherein, the substituent of the substituted C6-C15 aryl and the substituted C3-C15 heteroaryl is selected from deuterium, C1-C3 alkyl, C3-C10 cycloalkyl, and C6-C12 aryl;
preferably, Ar¹ is selected from tolyl, phenyl, biphenyl, and dibenzofuryl.

Preferably, the compound N has a structure as shown in any one of the following Formula N-i-1 to Formula N-i-72:

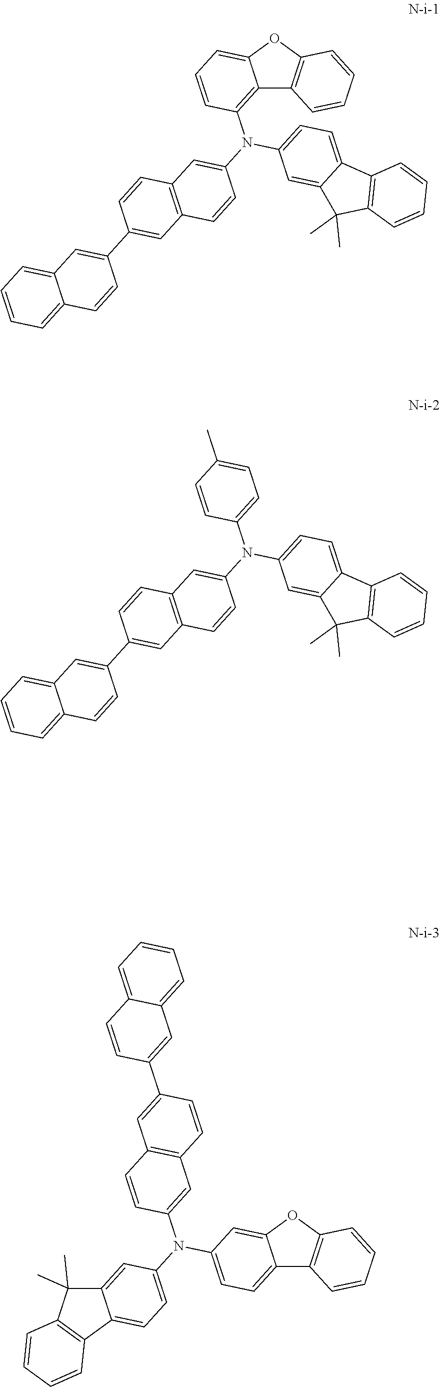 [SMILES: CC1(C)c2ccccc2-c2ccc(N(c3ccc4cc(-c5ccc6ccccc6c5)ccc4c3)c3cccc4oc5ccccc5c34)cc21 ; Cc1ccc(N(c2ccc3c(c2)C(C)(C)c2ccccc2-3)c2ccc3cc(-c4ccc5ccccc5c4)ccc3c2)cc1 ; CC1(C)c2ccccc2-c2ccc(N(c3ccc4cc(-c5ccc6ccccc6c5)ccc4c3)c3ccc4c(c3)oc3ccccc34)cc21]

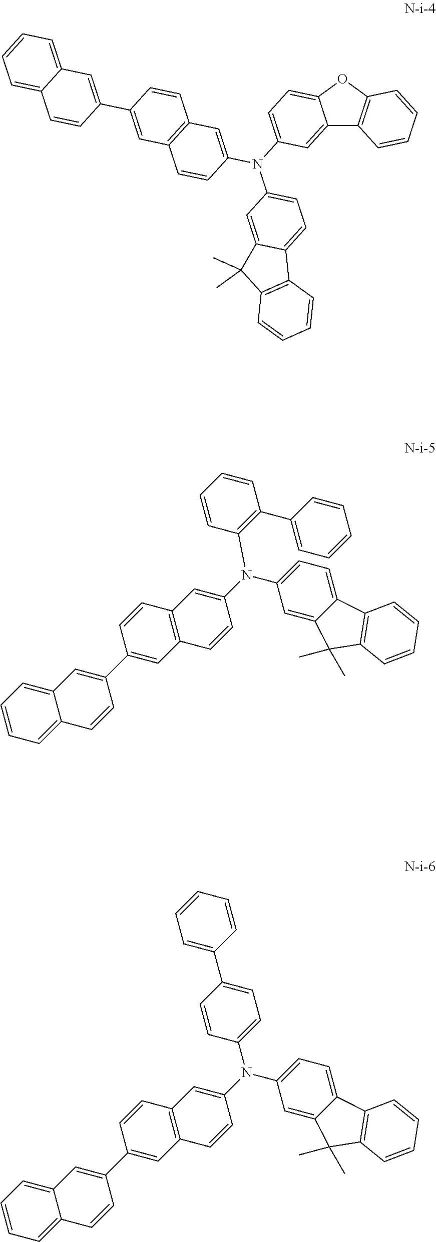 [SMILES: CC1(C)c2ccccc2-c2ccc(N(c3ccc4cc(-c5ccc6ccccc6c5)ccc4c3)c3ccc4oc5ccccc5c4c3)cc21 ; CC1(C)c2ccccc2-c2ccc(N(c3ccc4cc(-c5ccc6ccccc6c5)ccc4c3)c3ccccc3-c3ccccc3)cc21 ; CC1(C)c2ccccc2-c2ccc(N(c3ccc(-c4ccccc4)cc3)c3ccc4cc(-c5ccc6ccccc6c5)ccc4c3)cc21]

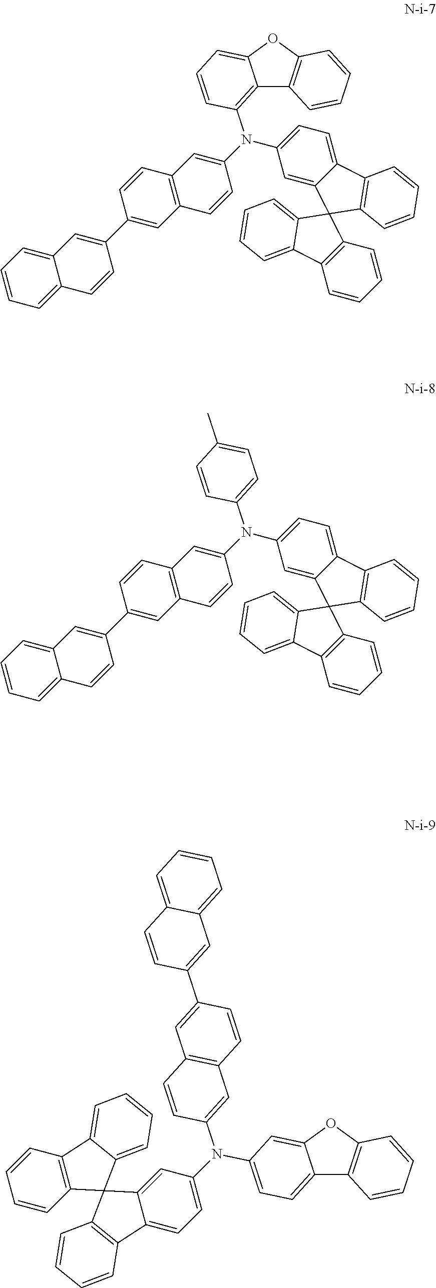 [SMILES: c1ccc2c(c1)-c1ccccc1C21c2ccccc2-c2ccc(N(c3ccc4cc(-c5ccc6ccccc6c5)ccc4c3)c3cccc4oc5ccccc5c34)cc21 ; Cc1ccc(N(c2ccc3c(c2)C2(c4ccccc4-c4ccccc42)c2ccccc2-3)c2ccc3cc(-c4ccc5ccccc5c4)ccc3c2)cc1 ; c1ccc2c(c1)-c1ccccc1C21c2ccccc2-c2ccc(N(c3ccc4cc(-c5ccc6ccccc6c5)ccc4c3)c3ccc4c(c3)oc3ccccc34)cc21]

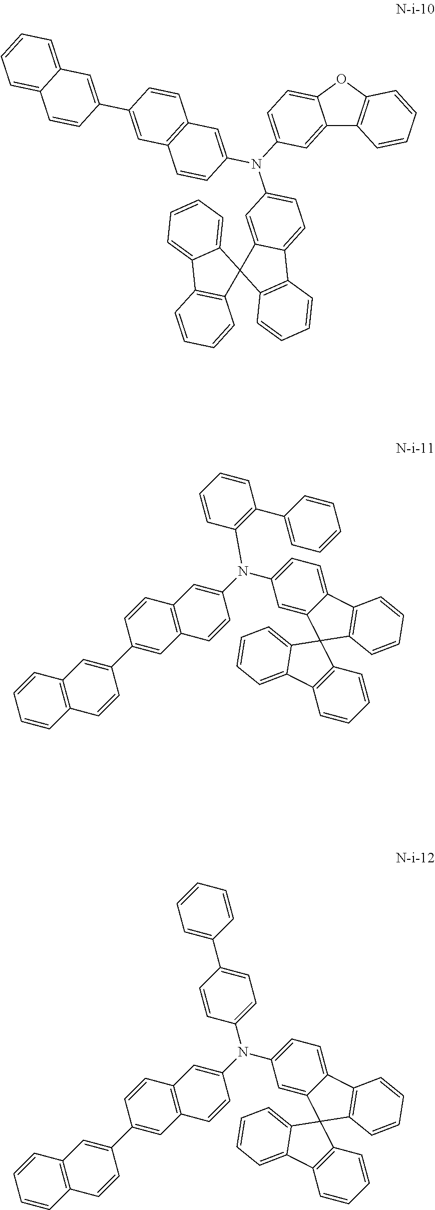 [SMILES: c1ccc2c(c1)-c1ccccc1C21c2ccccc2-c2ccc(N(c3ccc4cc(-c5ccc6ccccc6c5)ccc4c3)c3ccc4oc5ccccc5c4c3)cc21 ; c1ccc(-c2ccccc2N(c2ccc3c(c2)C2(c4ccccc4-c4ccccc42)c2ccccc2-3)c2ccc3cc(-c4ccc5ccccc5c4)ccc3c2)cc1 ; c1ccc(-c2ccc(N(c3ccc4c(c3)C3(c5ccccc5-c5ccccc53)c3ccccc3-4)c3ccc4cc(-c5ccc6ccccc6c5)ccc4c3)cc2)cc1]

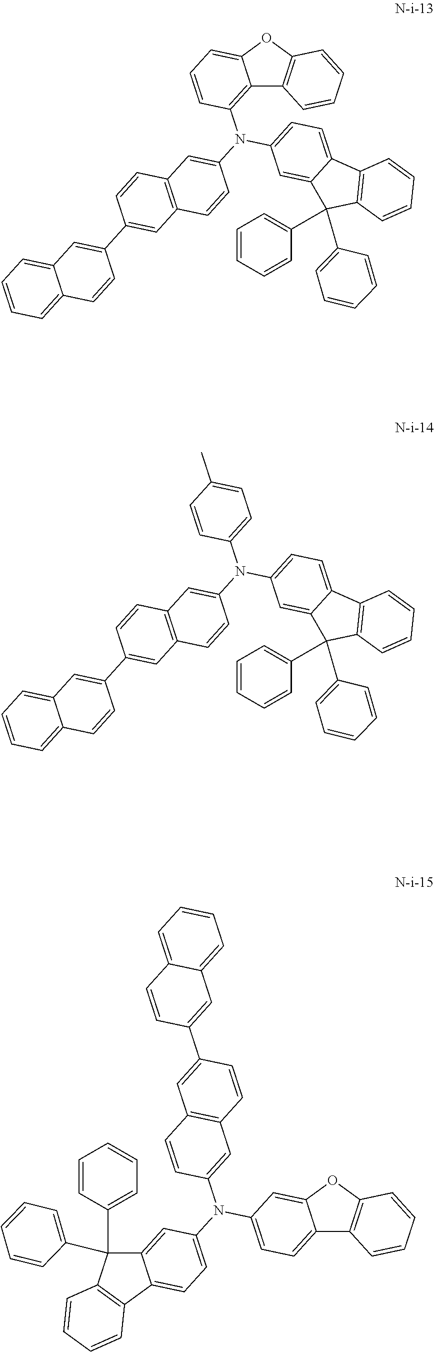 [SMILES: c1ccc(C2(c3ccccc3)c3ccccc3-c3ccc(N(c4ccc5cc(-c6ccc7ccccc7c6)ccc5c4)c4cccc5oc6ccccc6c45)cc32)cc1 ; Cc1ccc(N(c2ccc3c(c2)C(c2ccccc2)(c2ccccc2)c2ccccc2-3)c2ccc3cc(-c4ccc5ccccc5c4)ccc3c2)cc1 ; c1ccc(C2(c3ccccc3)c3ccccc3-c3ccc(N(c4ccc5cc(-c6ccc7ccccc7c6)ccc5c4)c4ccc5c(c4)oc4ccccc45)cc32)cc1]

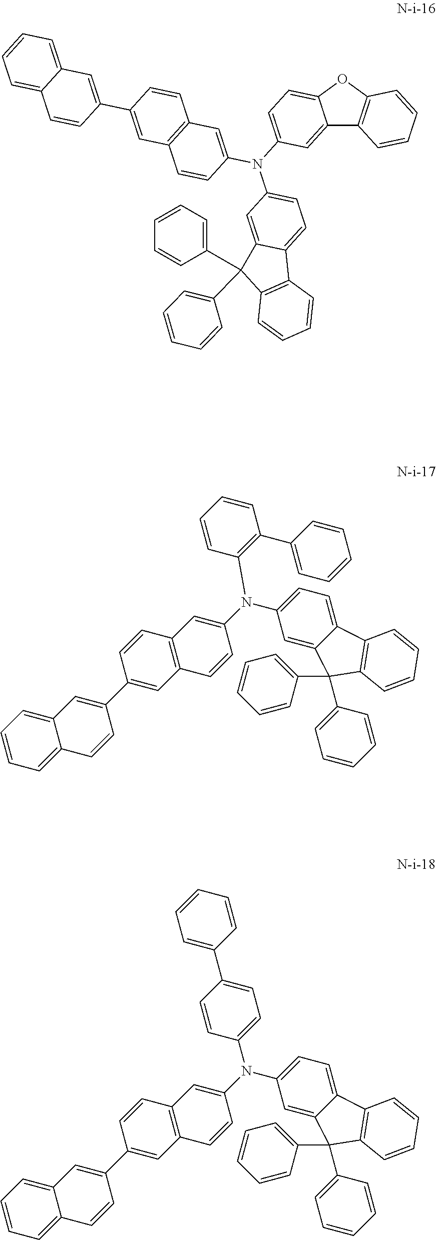 [SMILES: c1ccc(C2(c3ccccc3)c3ccccc3-c3ccc(N(c4ccc5cc(-c6ccc7ccccc7c6)ccc5c4)c4ccc5oc6ccccc6c5c4)cc32)cc1 ; c1ccc(-c2ccccc2N(c2ccc3c(c2)C(c2ccccc2)(c2ccccc2)c2ccccc2-3)c2ccc3cc(-c4ccc5ccccc5c4)ccc3c2)cc1 ; c1ccc(-c2ccc(N(c3ccc4c(c3)C(c3ccccc3)(c3ccccc3)c3ccccc3-4)c3ccc4cc(-c5ccc6ccccc6c5)ccc4c3)cc2)cc1]

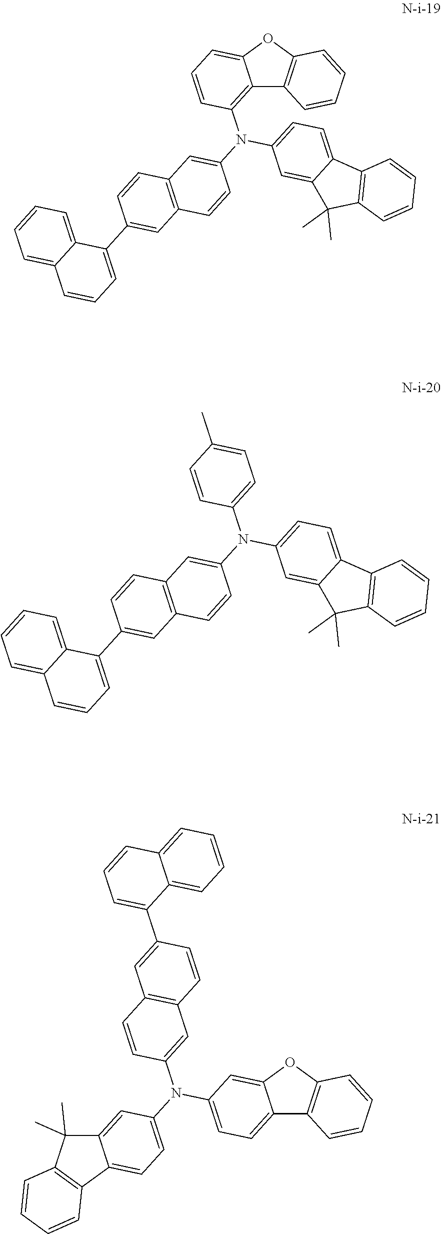 [SMILES: CC1(C)c2ccccc2-c2ccc(N(c3ccc4cc(-c5cccc6ccccc56)ccc4c3)c3cccc4oc5ccccc5c34)cc21 ; Cc1ccc(N(c2ccc3c(c2)C(C)(C)c2ccccc2-3)c2ccc3cc(-c4cccc5ccccc45)ccc3c2)cc1 ; CC1(C)c2ccccc2-c2ccc(N(c3ccc4cc(-c5cccc6ccccc56)ccc4c3)c3ccc4c(c3)oc3ccccc34)cc21]

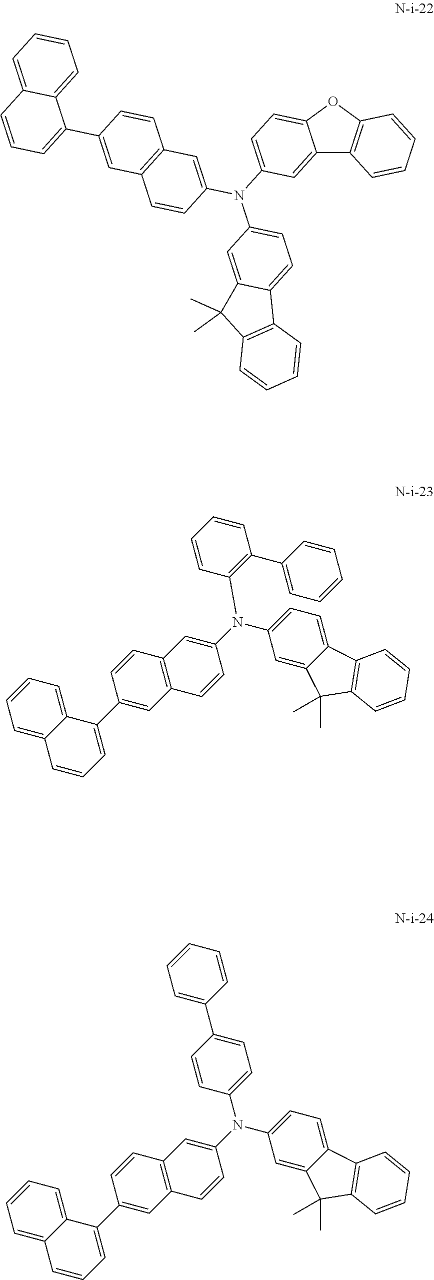 [SMILES: CC1(C)c2ccccc2-c2ccc(N(c3ccc4cc(-c5cccc6ccccc56)ccc4c3)c3ccc4oc5ccccc5c4c3)cc21 ; CC1(C)c2ccccc2-c2ccc(N(c3ccc4cc(-c5cccc6ccccc56)ccc4c3)c3ccccc3-c3ccccc3)cc21 ; CC1(C)c2ccccc2-c2ccc(N(c3ccc(-c4ccccc4)cc3)c3ccc4cc(-c5cccc6ccccc56)ccc4c3)cc21]

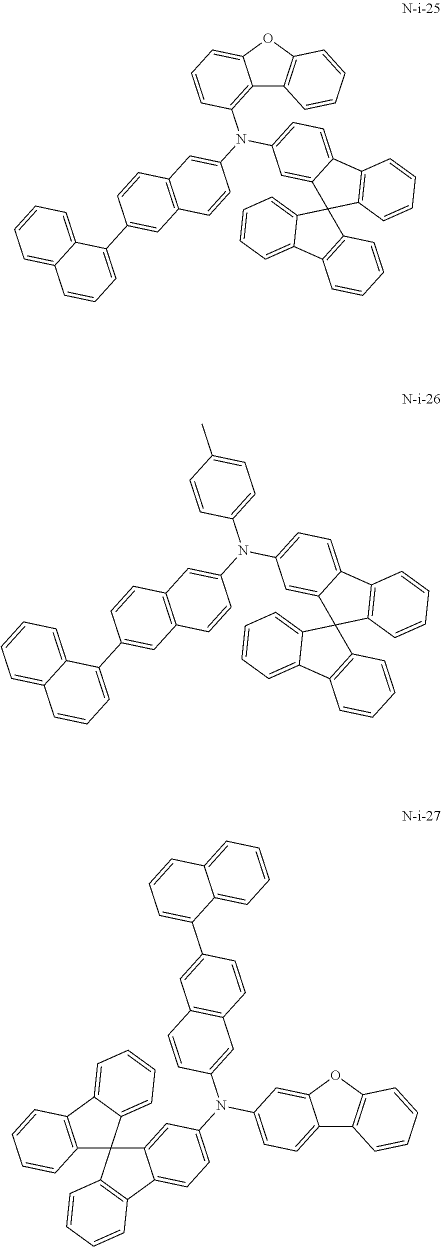 [SMILES: c1ccc2c(c1)-c1ccccc1C21c2ccccc2-c2ccc(N(c3ccc4cc(-c5cccc6ccccc56)ccc4c3)c3cccc4oc5ccccc5c34)cc21 ; Cc1ccc(N(c2ccc3c(c2)C2(c4ccccc4-c4ccccc42)c2ccccc2-3)c2ccc3cc(-c4cccc5ccccc45)ccc3c2)cc1 ; c1ccc2c(c1)-c1ccccc1C21c2ccccc2-c2ccc(N(c3ccc4cc(-c5cccc6ccccc56)ccc4c3)c3ccc4c(c3)oc3ccccc34)cc21]

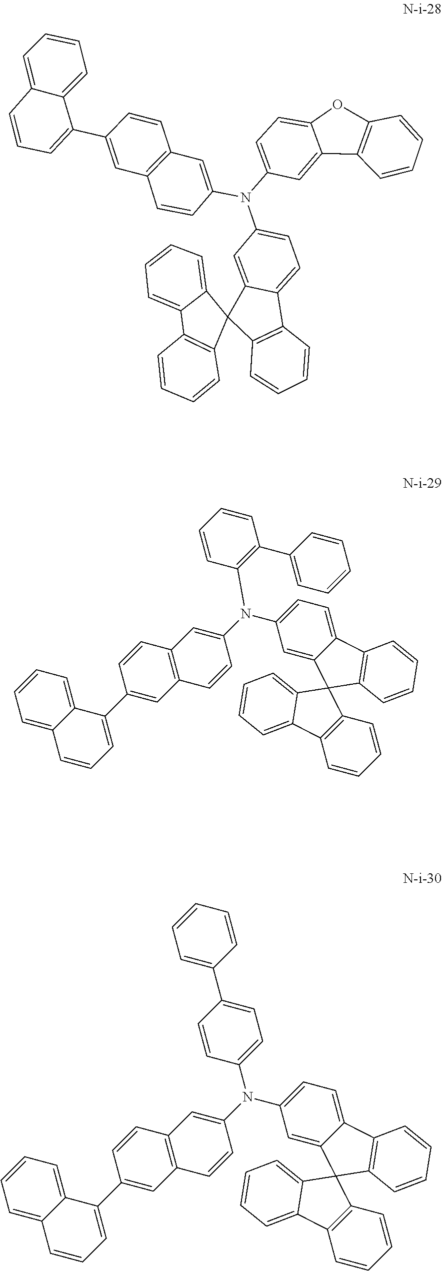 [SMILES: c1ccc2c(c1)-c1ccccc1C21c2ccccc2-c2ccc(N(c3ccc4cc(-c5cccc6ccccc56)ccc4c3)c3ccc4oc5ccccc5c4c3)cc21 ; c1ccc(-c2ccccc2N(c2ccc3c(c2)C2(c4ccccc4-c4ccccc42)c2ccccc2-3)c2ccc3cc(-c4cccc5ccccc45)ccc3c2)cc1 ; c1ccc(-c2ccc(N(c3ccc4c(c3)C3(c5ccccc5-c5ccccc53)c3ccccc3-4)c3ccc4cc(-c5cccc6ccccc56)ccc4c3)cc2)cc1]

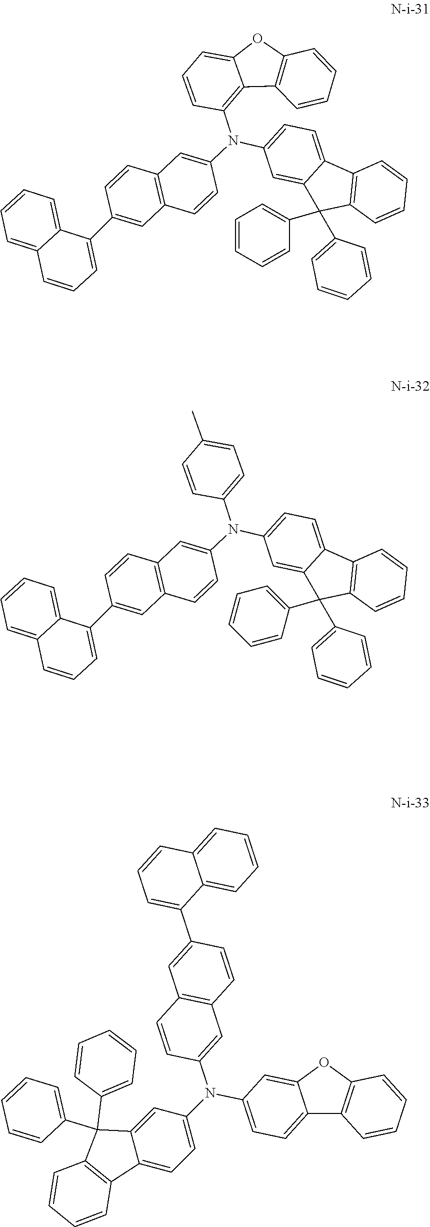 [SMILES: c1ccc(C2(c3ccccc3)c3ccccc3-c3ccc(N(c4ccc5cc(-c6cccc7ccccc67)ccc5c4)c4cccc5oc6ccccc6c45)cc32)cc1 ; Cc1ccc(N(c2ccc3c(c2)C(c2ccccc2)(c2ccccc2)c2ccccc2-3)c2ccc3cc(-c4cccc5ccccc45)ccc3c2)cc1 ; c1ccc(C2(c3ccccc3)c3ccccc3-c3ccc(N(c4ccc5cc(-c6cccc7ccccc67)ccc5c4)c4ccc5c(c4)oc4ccccc45)cc32)cc1]

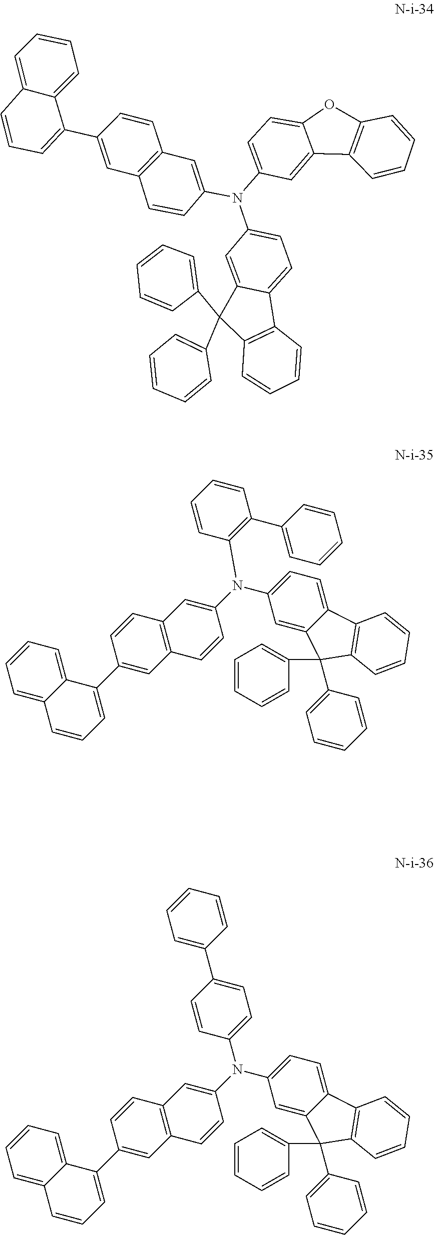 [SMILES: c1ccc(C2(c3ccccc3)c3ccccc3-c3ccc(N(c4ccc5cc(-c6cccc7ccccc67)ccc5c4)c4ccc5oc6ccccc6c5c4)cc32)cc1 ; c1ccc(-c2ccccc2N(c2ccc3c(c2)C(c2ccccc2)(c2ccccc2)c2ccccc2-3)c2ccc3cc(-c4cccc5ccccc45)ccc3c2)cc1 ; c1ccc(-c2ccc(N(c3ccc4c(c3)C(c3ccccc3)(c3ccccc3)c3ccccc3-4)c3ccc4cc(-c5cccc6ccccc56)ccc4c3)cc2)cc1]

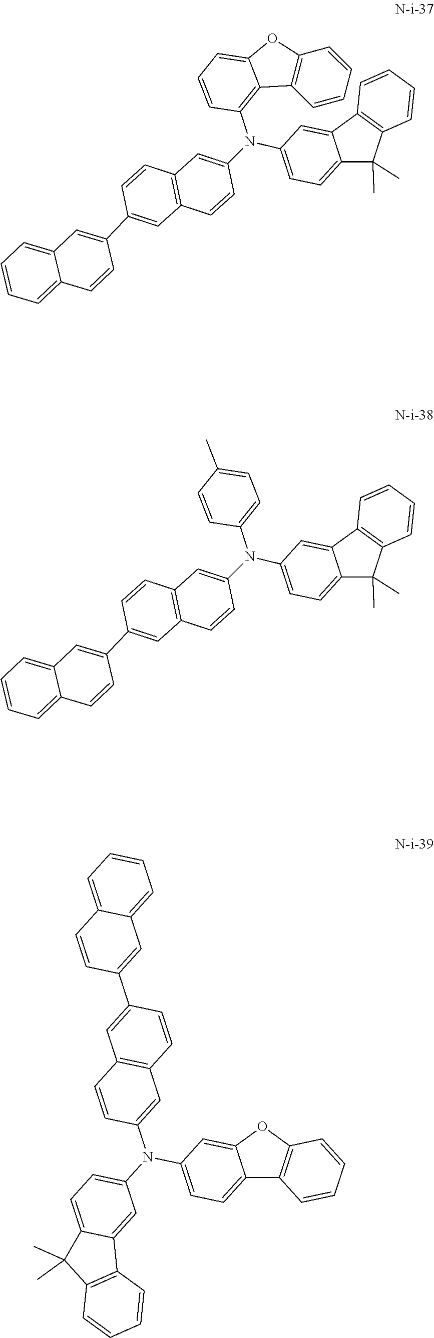 [SMILES: CC1(C)c2ccccc2-c2cc(N(c3ccc4cc(-c5ccc6ccccc6c5)ccc4c3)c3cccc4oc5ccccc5c34)ccc21 ; Cc1ccc(N(c2ccc3c(c2)-c2ccccc2C3(C)C)c2ccc3cc(-c4ccc5ccccc5c4)ccc3c2)cc1 ; CC1(C)c2ccccc2-c2cc(N(c3ccc4cc(-c5ccc6ccccc6c5)ccc4c3)c3ccc4c(c3)oc3ccccc34)ccc21]

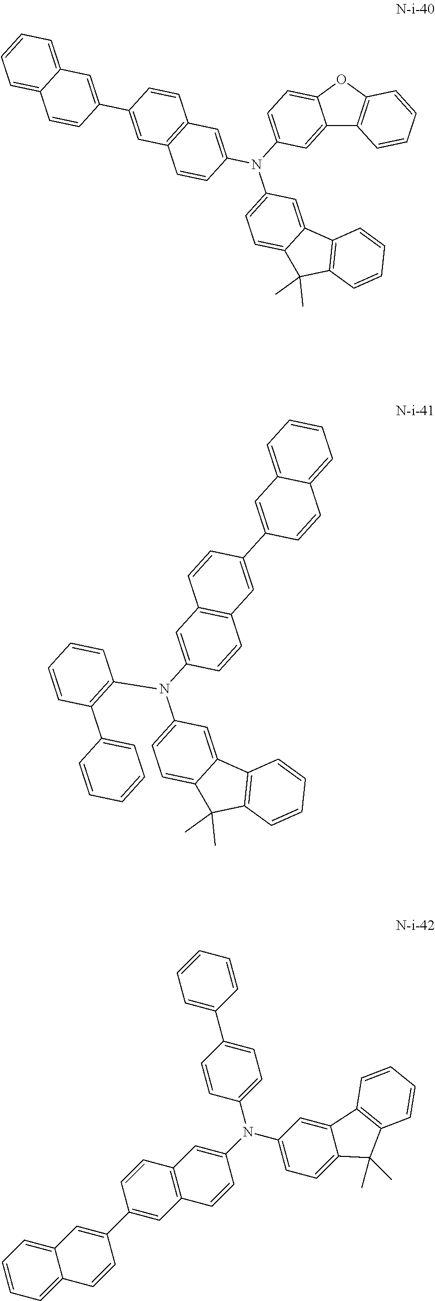 [SMILES: CC1(C)c2ccccc2-c2cc(N(c3ccc4cc(-c5ccc6ccccc6c5)ccc4c3)c3ccc4oc5ccccc5c4c3)ccc21 ; CC1(C)c2ccccc2-c2cc(N(c3ccc4cc(-c5ccc6ccccc6c5)ccc4c3)c3ccccc3-c3ccccc3)ccc21 ; CC1(C)c2ccccc2-c2cc(N(c3ccc(-c4ccccc4)cc3)c3ccc4cc(-c5ccc6ccccc6c5)ccc4c3)ccc21]

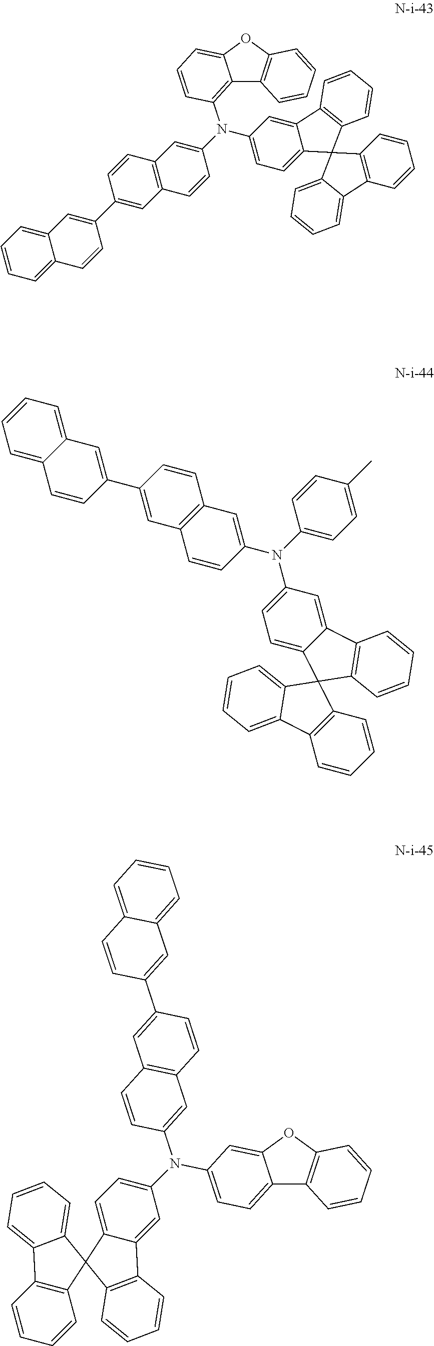 [SMILES: c1ccc2c(c1)-c1ccccc1C21c2ccccc2-c2cc(N(c3ccc4cc(-c5ccc6ccccc6c5)ccc4c3)c3cccc4oc5ccccc5c34)ccc21 ; Cc1ccc(N(c2ccc3c(c2)-c2ccccc2C32c3ccccc3-c3ccccc32)c2ccc3cc(-c4ccc5ccccc5c4)ccc3c2)cc1 ; c1ccc2c(c1)-c1ccccc1C21c2ccccc2-c2cc(N(c3ccc4cc(-c5ccc6ccccc6c5)ccc4c3)c3ccc4c(c3)oc3ccccc34)ccc21]

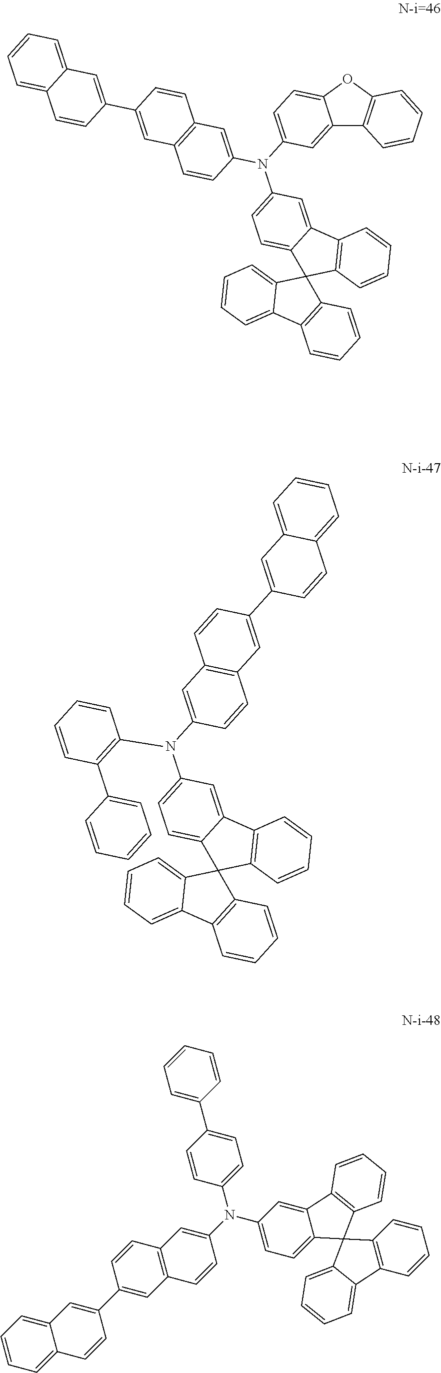 [SMILES: c1ccc2c(c1)-c1ccccc1C21c2ccccc2-c2cc(N(c3ccc4cc(-c5ccc6ccccc6c5)ccc4c3)c3ccc4oc5ccccc5c4c3)ccc21 ; c1ccc(-c2ccccc2N(c2ccc3c(c2)-c2ccccc2C32c3ccccc3-c3ccccc32)c2ccc3cc(-c4ccc5ccccc5c4)ccc3c2)cc1 ; c1ccc(-c2ccc(N(c3ccc4c(c3)-c3ccccc3C43c4ccccc4-c4ccccc43)c3ccc4cc(-c5ccc6ccccc6c5)ccc4c3)cc2)cc1]

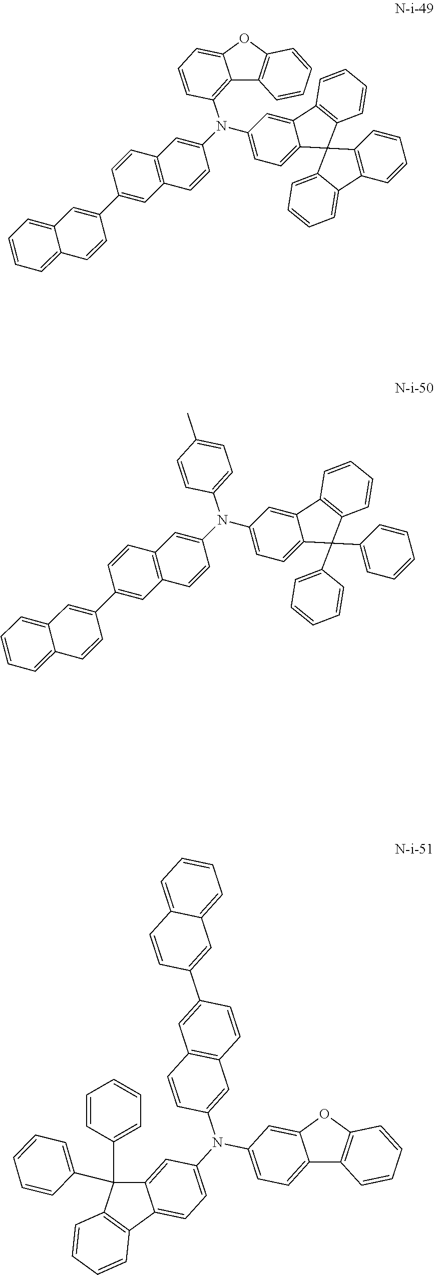 [SMILES: c1ccc2c(c1)-c1ccccc1C21c2ccccc2-c2cc(N(c3ccc4cc(-c5ccc6ccccc6c5)ccc4c3)c3cccc4oc5ccccc5c34)ccc21 ; Cc1ccc(N(c2ccc3c(c2)-c2ccccc2C3(c2ccccc2)c2ccccc2)c2ccc3cc(-c4ccc5ccccc5c4)ccc3c2)cc1 ; c1ccc(C2(c3ccccc3)c3ccccc3-c3ccc(N(c4ccc5cc(-c6ccc7ccccc7c6)ccc5c4)c4ccc5c(c4)oc4ccccc45)cc32)cc1]

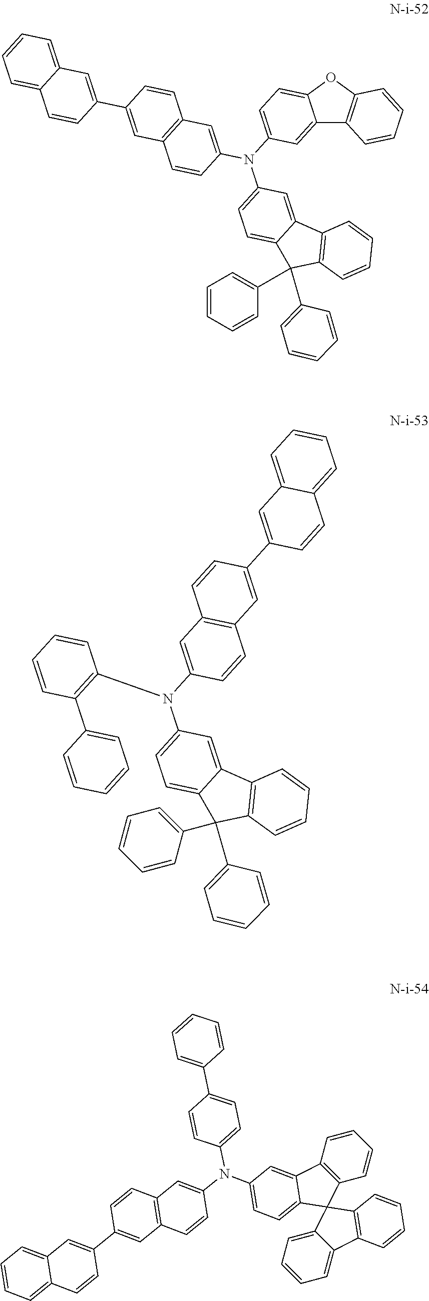 [SMILES: c1ccc(C2(c3ccccc3)c3ccccc3-c3cc(N(c4ccc5cc(-c6ccc7ccccc7c6)ccc5c4)c4ccc5oc6ccccc6c5c4)ccc32)cc1 ; c1ccc(-c2ccccc2N(c2ccc3c(c2)-c2ccccc2C3(c2ccccc2)c2ccccc2)c2ccc3cc(-c4ccc5ccccc5c4)ccc3c2)cc1 ; c1ccc(-c2ccc(N(c3ccc4c(c3)-c3ccccc3C43c4ccccc4-c4ccccc43)c3ccc4cc(-c5ccc6ccccc6c5)ccc4c3)cc2)cc1]

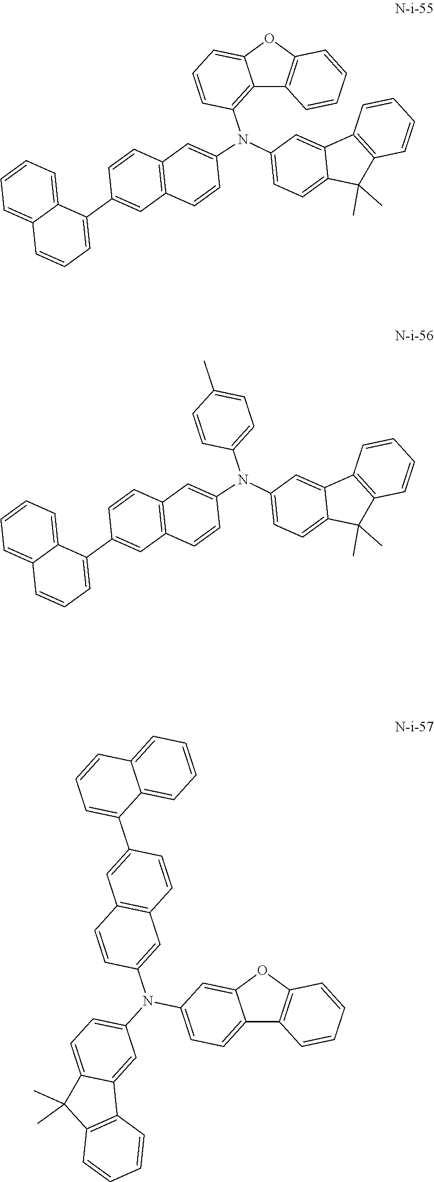 [SMILES: CC1(C)c2ccccc2-c2cc(N(c3ccc4cc(-c5cccc6ccccc56)ccc4c3)c3cccc4oc5ccccc5c34)ccc21 ; Cc1ccc(N(c2ccc3c(c2)-c2ccccc2C3(C)C)c2ccc3cc(-c4cccc5ccccc45)ccc3c2)cc1 ; CC1(C)c2ccccc2-c2cc(N(c3ccc4cc(-c5cccc6ccccc56)ccc4c3)c3ccc4c(c3)oc3ccccc34)ccc21]

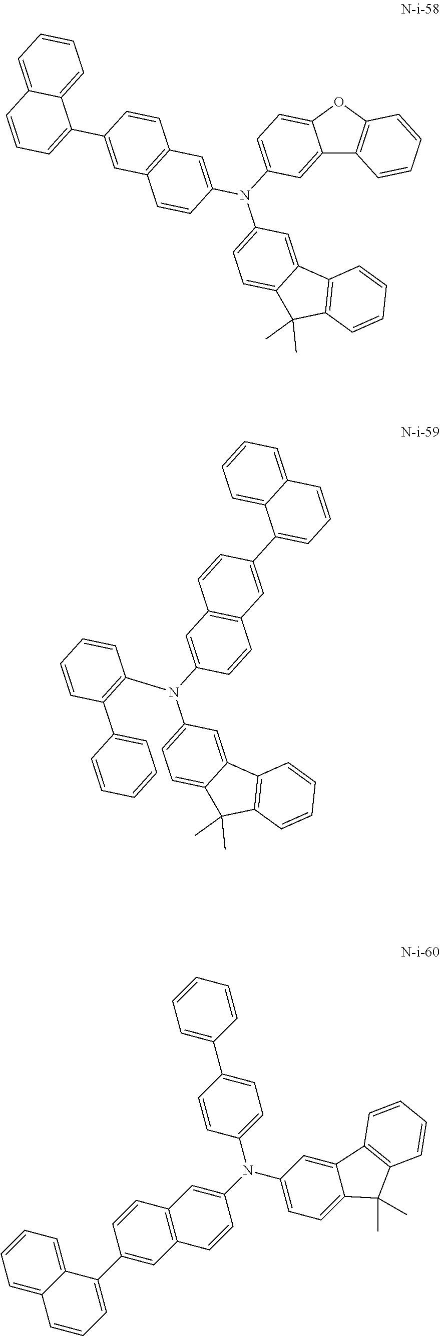 [SMILES: CC1(C)c2ccccc2-c2cc(N(c3ccc4cc(-c5cccc6ccccc56)ccc4c3)c3ccc4oc5ccccc5c4c3)ccc21 ; CC1(C)c2ccccc2-c2cc(N(c3ccc4cc(-c5cccc6ccccc56)ccc4c3)c3ccccc3-c3ccccc3)ccc21 ; CC1(C)c2ccccc2-c2cc(N(c3ccc(-c4ccccc4)cc3)c3ccc4cc(-c5cccc6ccccc56)ccc4c3)ccc21]

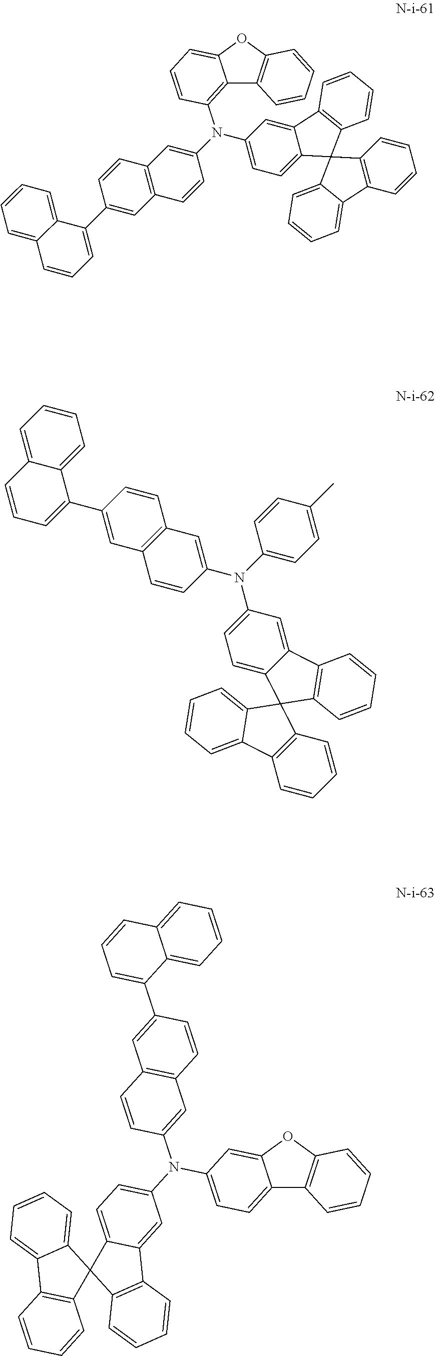 [SMILES: c1ccc2c(c1)-c1ccccc1C21c2ccccc2-c2cc(N(c3ccc4cc(-c5cccc6ccccc56)ccc4c3)c3cccc4oc5ccccc5c34)ccc21 ; Cc1ccc(N(c2ccc3c(c2)-c2ccccc2C32c3ccccc3-c3ccccc32)c2ccc3cc(-c4cccc5ccccc45)ccc3c2)cc1 ; c1ccc2c(c1)-c1ccccc1C21c2ccccc2-c2cc(N(c3ccc4cc(-c5cccc6ccccc56)ccc4c3)c3ccc4c(c3)oc3ccccc34)ccc21]

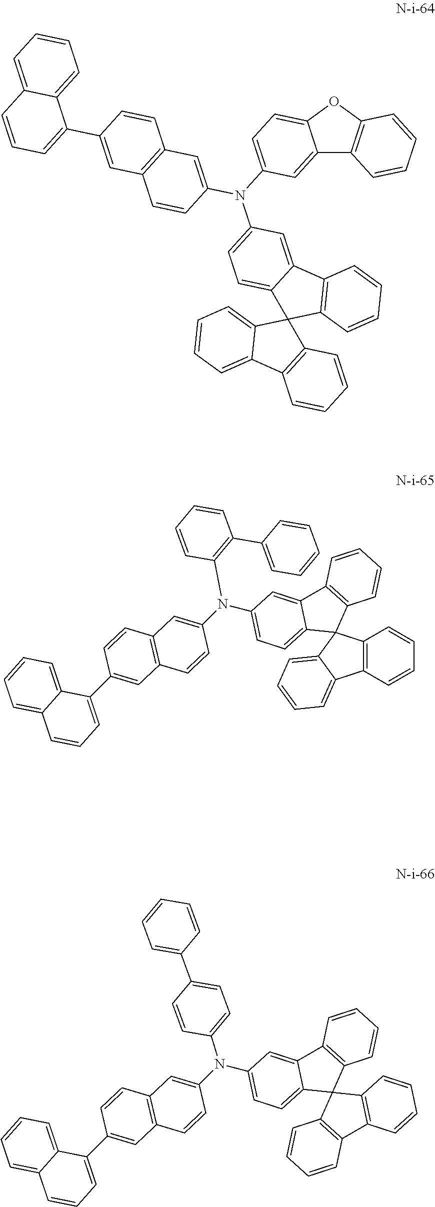 [SMILES: c1ccc2c(c1)-c1ccccc1C21c2ccccc2-c2cc(N(c3ccc4cc(-c5cccc6ccccc56)ccc4c3)c3ccc4oc5ccccc5c4c3)ccc21 ; c1ccc(-c2ccccc2N(c2ccc3c(c2)-c2ccccc2C32c3ccccc3-c3ccccc32)c2ccc3cc(-c4cccc5ccccc45)ccc3c2)cc1 ; c1ccc(-c2ccc(N(c3ccc4c(c3)-c3ccccc3C43c4ccccc4-c4ccccc43)c3ccc4cc(-c5cccc6ccccc56)ccc4c3)cc2)cc1]

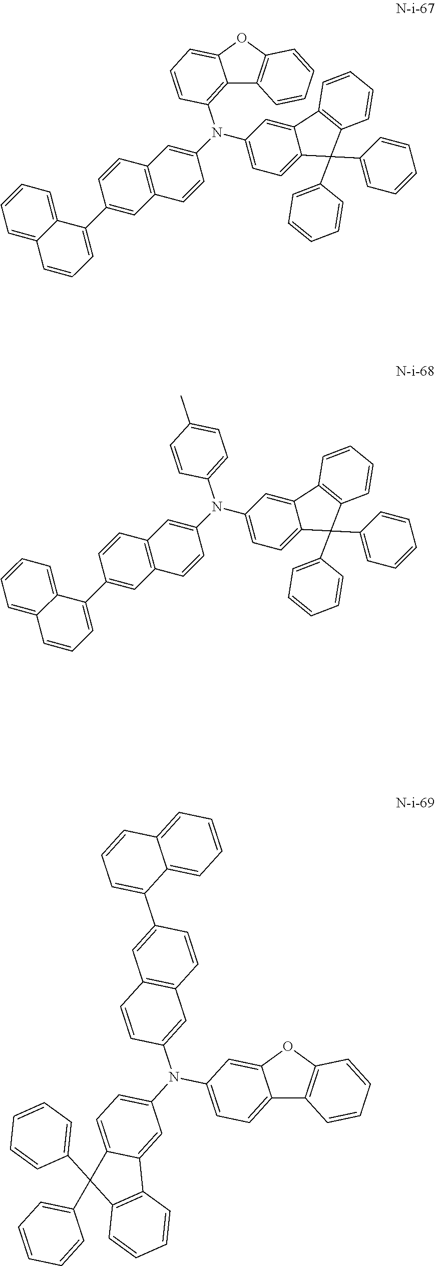 [SMILES: c1ccc(C2(c3ccccc3)c3ccccc3-c3cc(N(c4ccc5cc(-c6cccc7ccccc67)ccc5c4)c4cccc5oc6ccccc6c45)ccc32)cc1 ; Cc1ccc(N(c2ccc3c(c2)-c2ccccc2C3(c2ccccc2)c2ccccc2)c2ccc3cc(-c4cccc5ccccc45)ccc3c2)cc1 ; c1ccc(C2(c3ccccc3)c3ccccc3-c3cc(N(c4ccc5cc(-c6cccc7ccccc67)ccc5c4)c4ccc5c(c4)oc4ccccc45)ccc32)cc1]

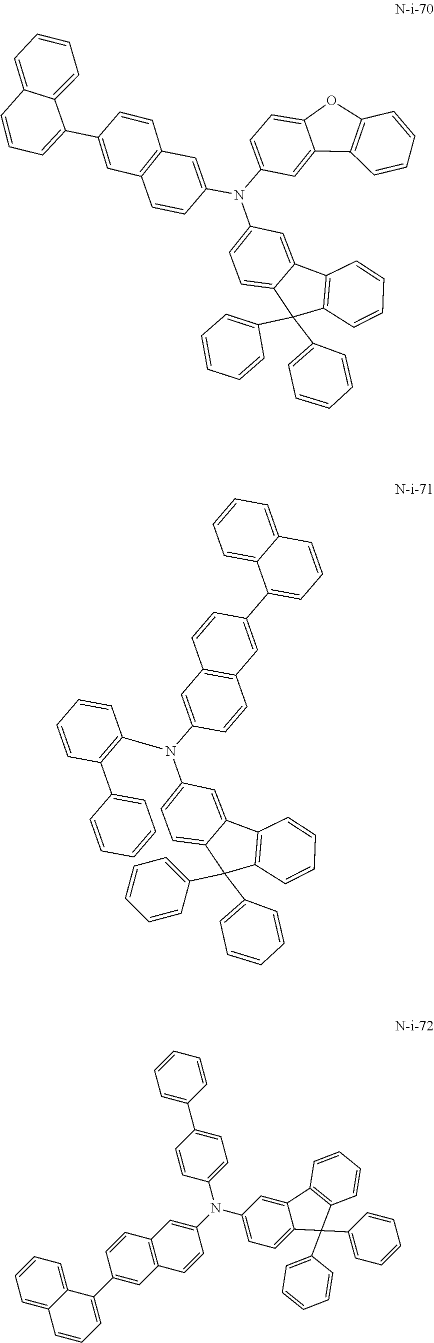 [SMILES: c1ccc(C2(c3ccccc3)c3ccccc3-c3cc(N(c4ccc5cc(-c6cccc7ccccc67)ccc5c4)c4ccc5oc6ccccc6c5c4)ccc32)cc1 ; c1ccc(-c2ccccc2N(c2ccc3c(c2)-c2ccccc2C3(c2ccccc2)c2ccccc2)c2ccc3cc(-c4cccc5ccccc45)ccc3c2)cc1 ; c1ccc(-c2ccc(N(c3ccc4c(c3)-c3ccccc3C4(c3ccccc3)c3ccccc3)c3ccc4cc(-c5cccc6ccccc56)ccc4c3)cc2)cc1]

Preferably, the compound N has the structure as shown in any one of the following N-1 to N-549:

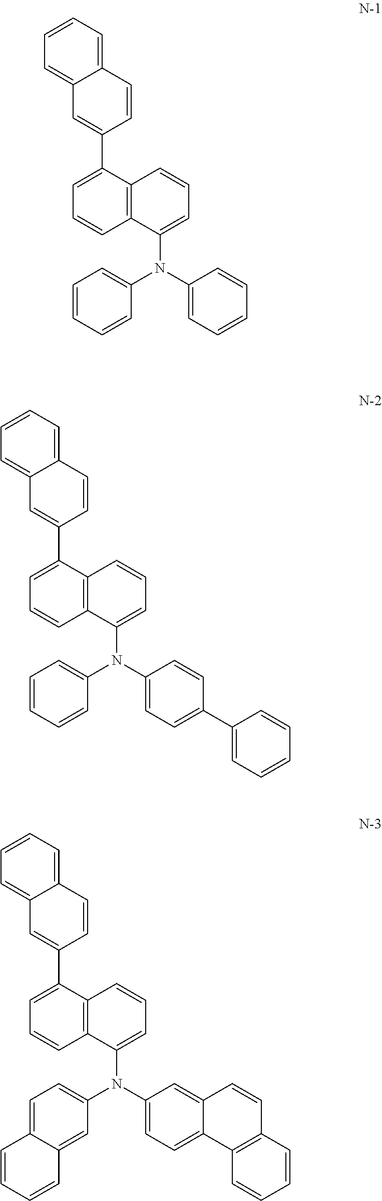 [SMILES: c1ccc(N(c2ccccc2)c2cccc3c(-c4ccc5ccccc5c4)cccc23)cc1 ; c1ccc(-c2ccc(N(c3ccccc3)c3cccc4c(-c5ccc6ccccc6c5)cccc34)cc2)cc1 ; c1ccc2cc(-c3cccc4c(N(c5ccc6ccccc6c5)c5ccc6c(ccc7ccccc76)c5)cccc34)ccc2c1]

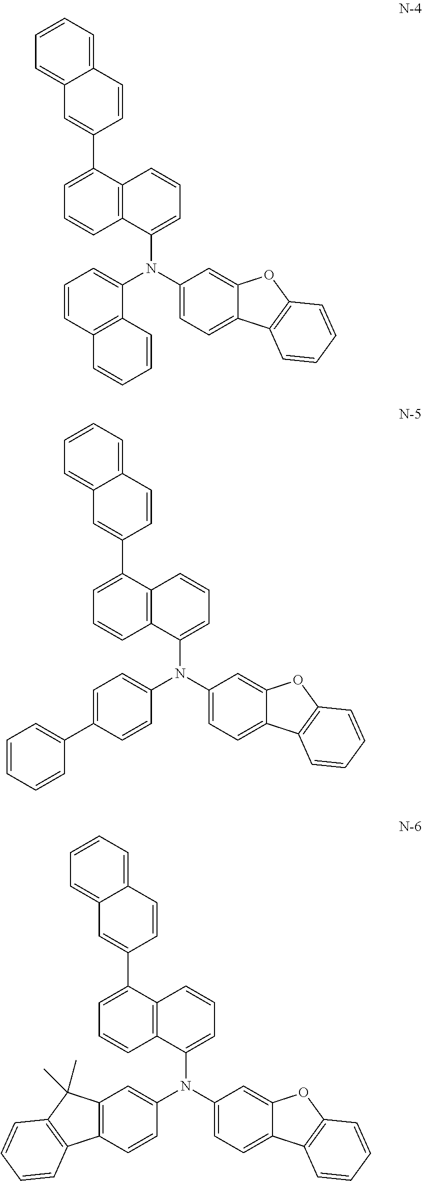 [SMILES: c1ccc2cc(-c3cccc4c(N(c5ccc6c(c5)oc5ccccc56)c5cccc6ccccc56)cccc34)ccc2c1 ; c1ccc(-c2ccc(N(c3ccc4c(c3)oc3ccccc34)c3cccc4c(-c5ccc6ccccc6c5)cccc34)cc2)cc1 ; CC1(C)c2ccccc2-c2ccc(N(c3ccc4c(c3)oc3ccccc34)c3cccc4c(-c5ccc6ccccc6c5)cccc34)cc21]

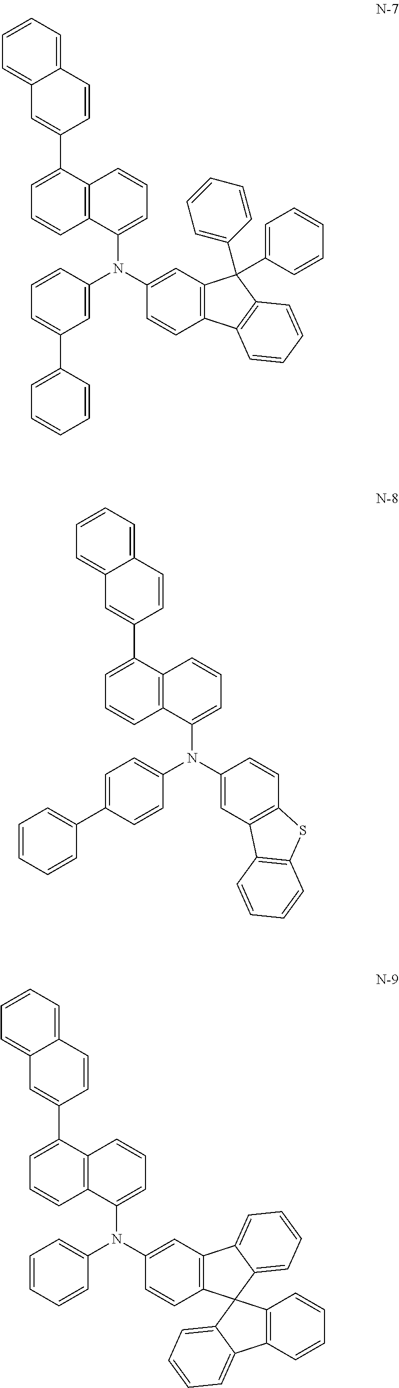 [SMILES: c1ccc(-c2cccc(N(c3ccc4c(c3)C(c3ccccc3)(c3ccccc3)c3ccccc3-4)c3cccc4c(-c5ccc6ccccc6c5)cccc34)c2)cc1 ; c1ccc(-c2ccc(N(c3ccc4sc5ccccc5c4c3)c3cccc4c(-c5ccc6ccccc6c5)cccc34)cc2)cc1 ; c1ccc(N(c2ccc3c(c2)-c2ccccc2C32c3ccccc3-c3ccccc32)c2cccc3c(-c4ccc5ccccc5c4)cccc23)cc1]

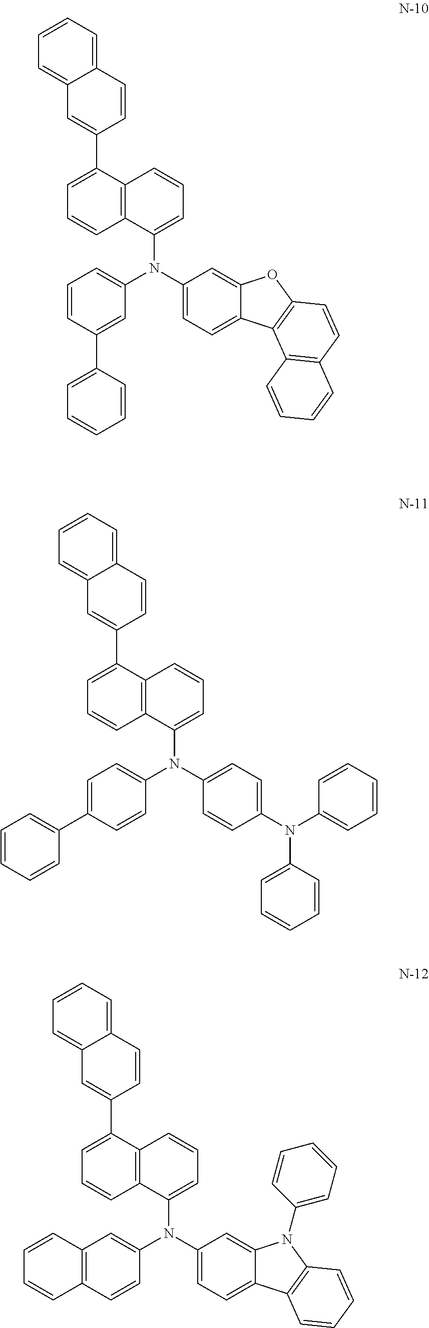 [SMILES: c1ccc(-c2cccc(N(c3ccc4c(c3)oc3ccc5ccccc5c34)c3cccc4c(-c5ccc6ccccc6c5)cccc34)c2)cc1 ; c1ccc(-c2ccc(N(c3ccc(N(c4ccccc4)c4ccccc4)cc3)c3cccc4c(-c5ccc6ccccc6c5)cccc34)cc2)cc1 ; c1ccc(-n2c3ccccc3c3ccc(N(c4ccc5ccccc5c4)c4cccc5c(-c6ccc7ccccc7c6)cccc45)cc32)cc1]

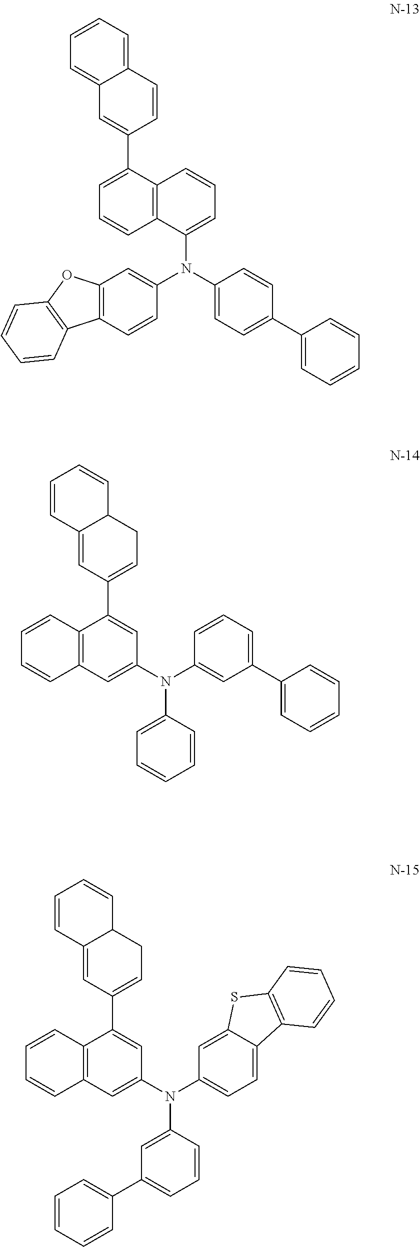 [SMILES: c1ccc(-c2ccc(N(c3ccc4c(c3)oc3ccccc34)c3cccc4c(-c5ccc6ccccc6c5)cccc34)cc2)cc1 ; C1=CC2=CC(c3cc(N(c4ccccc4)c4cccc(-c5ccccc5)c4)cc4ccccc34)=CCC2C=C1 ; C1=CC2=CC(c3cc(N(c4cccc(-c5ccccc5)c4)c4ccc5c(c4)sc4ccccc45)cc4ccccc34)=CCC2C=C1]

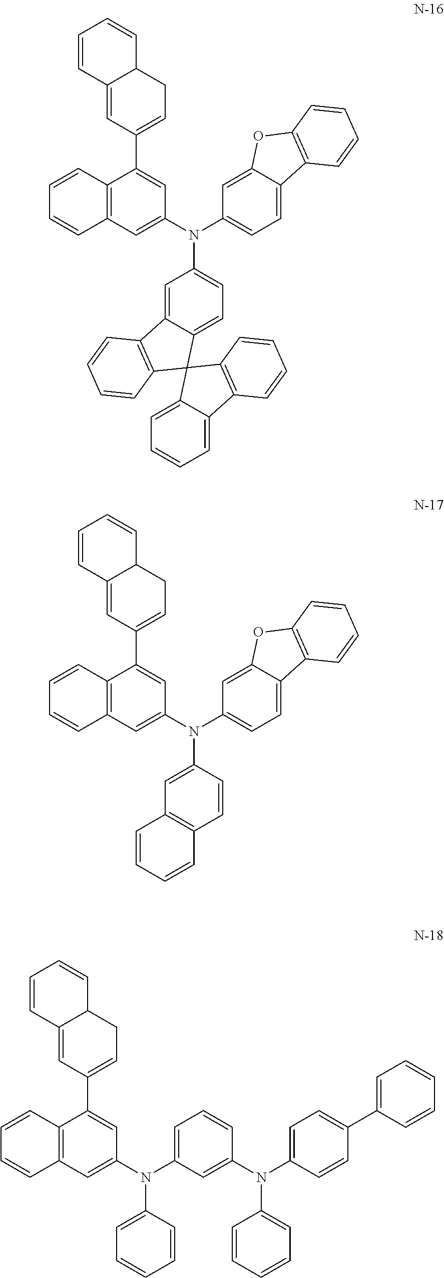 [SMILES: C1=CC2=CC(c3cc(N(c4ccc5c(c4)-c4ccccc4C54c5ccccc5-c5ccccc54)c4ccc5c(c4)oc4ccccc45)cc4ccccc34)=CCC2C=C1 ; C1=CC2=CC(c3cc(N(c4ccc5ccccc5c4)c4ccc5c(c4)oc4ccccc45)cc4ccccc34)=CCC2C=C1 ; C1=CC2=CC(c3cc(N(c4ccccc4)c4cccc(N(c5ccccc5)c5ccc(-c6ccccc6)cc5)c4)cc4ccccc34)=CCC2C=C1]

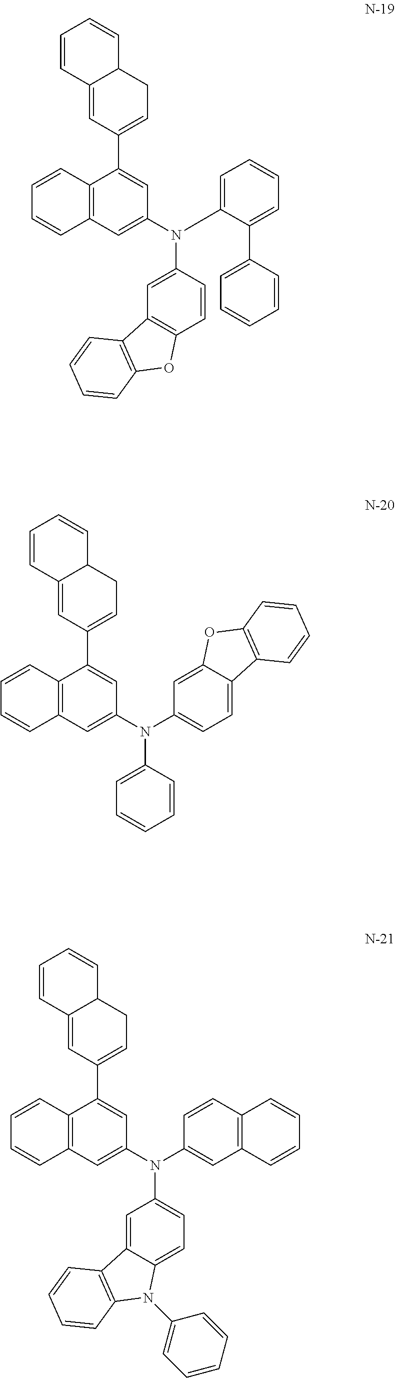 [SMILES: C1=CC2=CC(c3cc(N(c4ccc5oc6ccccc6c5c4)c4ccccc4-c4ccccc4)cc4ccccc34)=CCC2C=C1 ; C1=CC2=CC(c3cc(N(c4ccccc4)c4ccc5c(c4)oc4ccccc45)cc4ccccc34)=CCC2C=C1 ; C1=CC2=CC(c3cc(N(c4ccc5ccccc5c4)c4ccc5c(c4)c4ccccc4n5-c4ccccc4)cc4ccccc34)=CCC2C=C1]

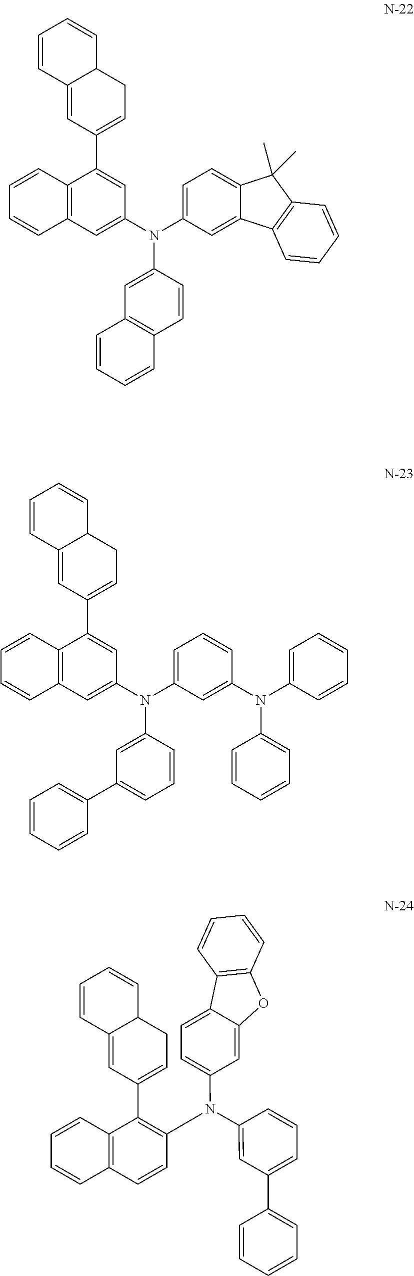 [SMILES: CC1(C)c2ccccc2-c2cc(N(c3ccc4ccccc4c3)c3cc(C4=CCC5C=CC=CC5=C4)c4ccccc4c3)ccc21 ; C1=CC2=CC(c3cc(N(c4cccc(-c5ccccc5)c4)c4cccc(N(c5ccccc5)c5ccccc5)c4)cc4ccccc34)=CCC2C=C1 ; C1=CC2=CC(c3c(N(c4cccc(-c5ccccc5)c4)c4ccc5c(c4)oc4ccccc45)ccc4ccccc34)=CCC2C=C1]

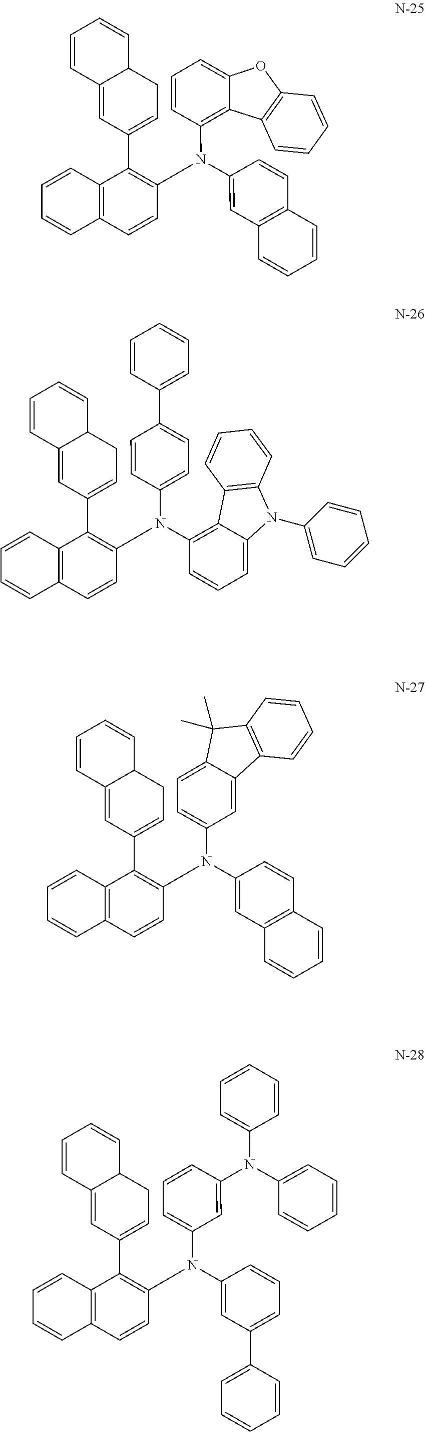 [SMILES: C1=CC2=CC(c3c(N(c4ccc5ccccc5c4)c4cccc5oc6ccccc6c45)ccc4ccccc34)=CCC2C=C1 ; C1=CC2=CC(c3c(N(c4ccc(-c5ccccc5)cc4)c4cccc5c4c4ccccc4n5-c4ccccc4)ccc4ccccc34)=CCC2C=C1 ; CC1(C)c2ccccc2-c2cc(N(c3ccc4ccccc4c3)c3ccc4ccccc4c3C3=CCC4C=CC=CC4=C3)ccc21 ; C1=CC2=CC(c3c(N(c4cccc(-c5ccccc5)c4)c4cccc(N(c5ccccc5)c5ccccc5)c4)ccc4ccccc34)=CCC2C=C1]

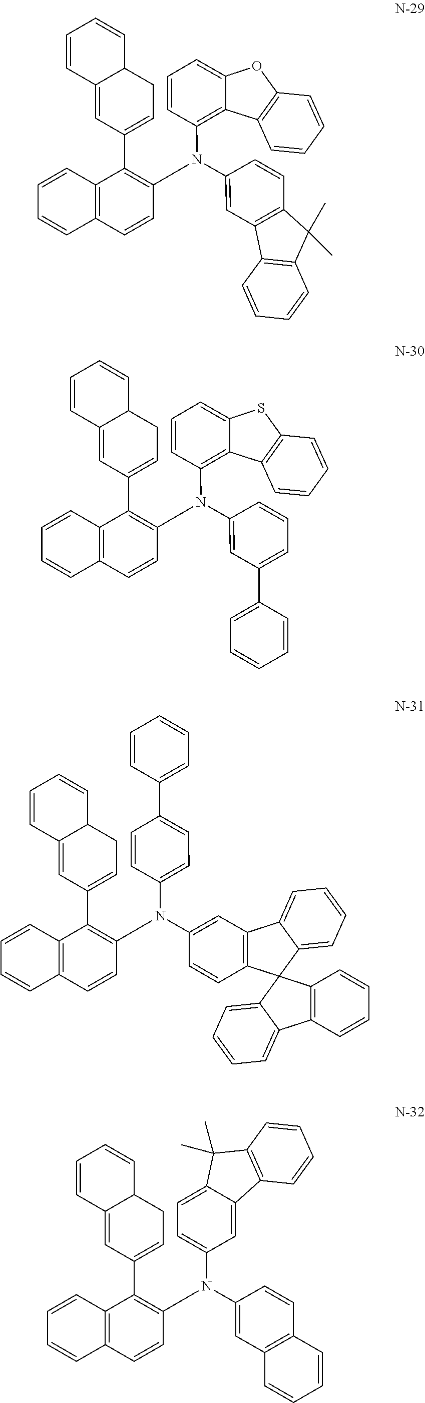 [SMILES: CC1(C)c2ccccc2-c2cc(N(c3ccc4ccccc4c3C3=CCC4C=CC=CC4=C3)c3cccc4oc5ccccc5c34)ccc21 ; C1=CC2=CC(c3c(N(c4cccc(-c5ccccc5)c4)c4cccc5sc6ccccc6c45)ccc4ccccc34)=CCC2C=C1 ; C1=CC2=CC(c3c(N(c4ccc(-c5ccccc5)cc4)c4ccc5c(c4)-c4ccccc4C54c5ccccc5-c5ccccc54)ccc4ccccc34)=CCC2C=C1 ; CC1(C)c2ccccc2-c2cc(N(c3ccc4ccccc4c3)c3ccc4ccccc4c3C3=CCC4C=CC=CC4=C3)ccc21]

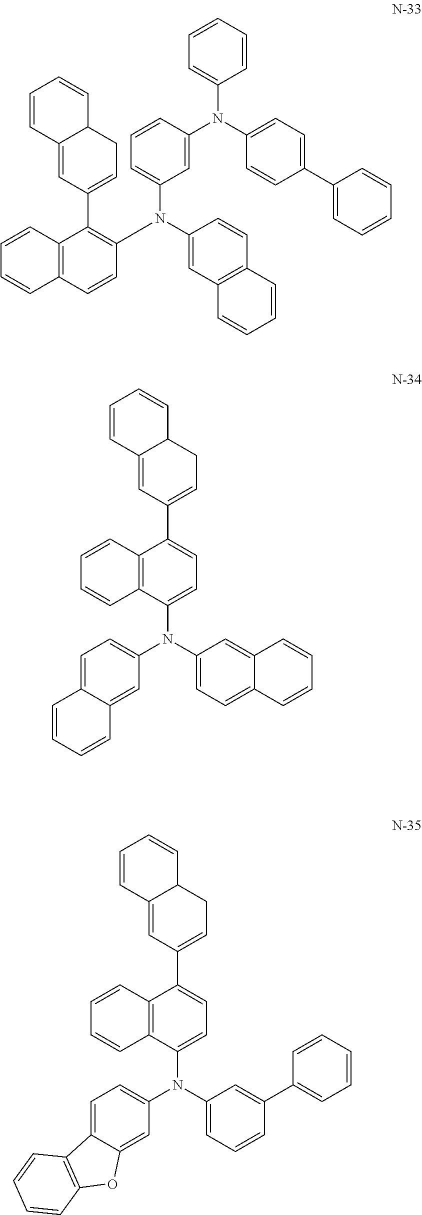 [SMILES: C1=CC2=CC(c3c(N(c4cccc(N(c5ccccc5)c5ccc(-c6ccccc6)cc5)c4)c4ccc5ccccc5c4)ccc4ccccc34)=CCC2C=C1 ; C1=CC2=CC(c3ccc(N(c4ccc5ccccc5c4)c4ccc5ccccc5c4)c4ccccc34)=CCC2C=C1 ; C1=CC2=CC(c3ccc(N(c4cccc(-c5ccccc5)c4)c4ccc5c(c4)oc4ccccc45)c4ccccc34)=CCC2C=C1]

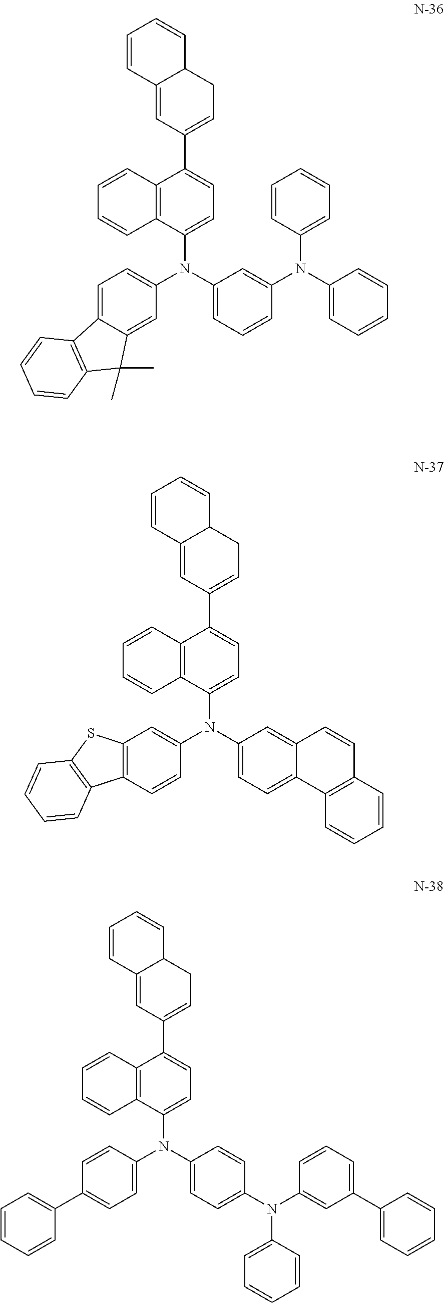 [SMILES: CC1(C)c2ccccc2-c2ccc(N(c3cccc(N(c4ccccc4)c4ccccc4)c3)c3ccc(C4=CCC5C=CC=CC5=C4)c4ccccc34)cc21 ; C1=CC2=CC(c3ccc(N(c4ccc5c(ccc6ccccc65)c4)c4ccc5c(c4)sc4ccccc45)c4ccccc34)=CCC2C=C1 ; C1=CC2=CC(c3ccc(N(c4ccc(-c5ccccc5)cc4)c4ccc(N(c5ccccc5)c5cccc(-c6ccccc6)c5)cc4)c4ccccc34)=CCC2C=C1]

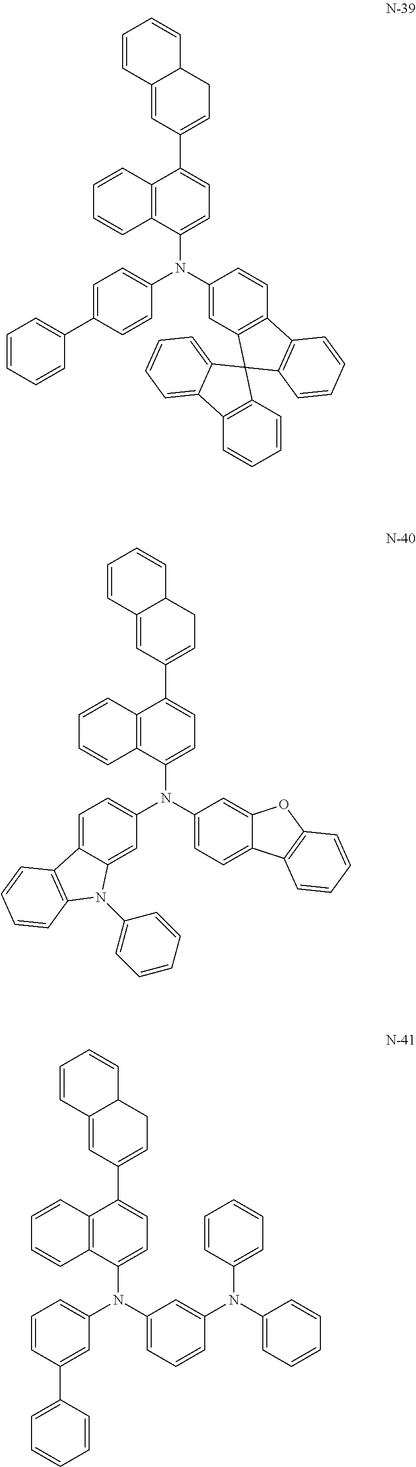 [SMILES: C1=CC2=CC(c3ccc(N(c4ccc(-c5ccccc5)cc4)c4ccc5c(c4)C4(c6ccccc6-c6ccccc64)c4ccccc4-5)c4ccccc34)=CCC2C=C1 ; C1=CC2=CC(c3ccc(N(c4ccc5c(c4)oc4ccccc45)c4ccc5c6ccccc6n(-c6ccccc6)c5c4)c4ccccc34)=CCC2C=C1 ; C1=CC2=CC(c3ccc(N(c4cccc(-c5ccccc5)c4)c4cccc(N(c5ccccc5)c5ccccc5)c4)c4ccccc34)=CCC2C=C1]

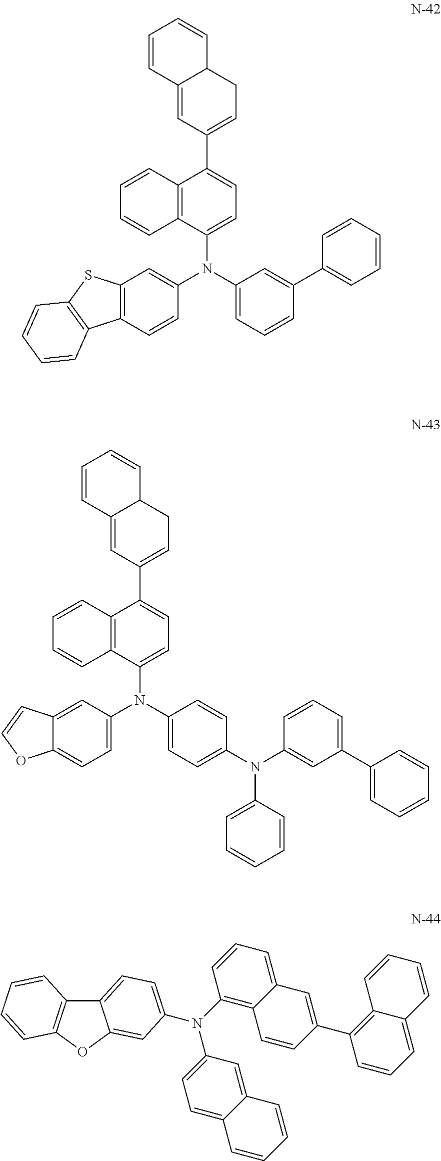 [SMILES: C1=CC2=CC(c3ccc(N(c4cccc(-c5ccccc5)c4)c4ccc5c(c4)sc4ccccc45)c4ccccc34)=CCC2C=C1 ; C1=CC2=CC(c3ccc(N(c4ccc(N(c5ccccc5)c5cccc(-c6ccccc6)c5)cc4)c4ccc5occc5c4)c4ccccc34)=CCC2C=C1 ; c1ccc2cc(N(c3ccc4c(c3)oc3ccccc34)c3cccc4cc(-c5cccc6ccccc56)ccc34)ccc2c1]

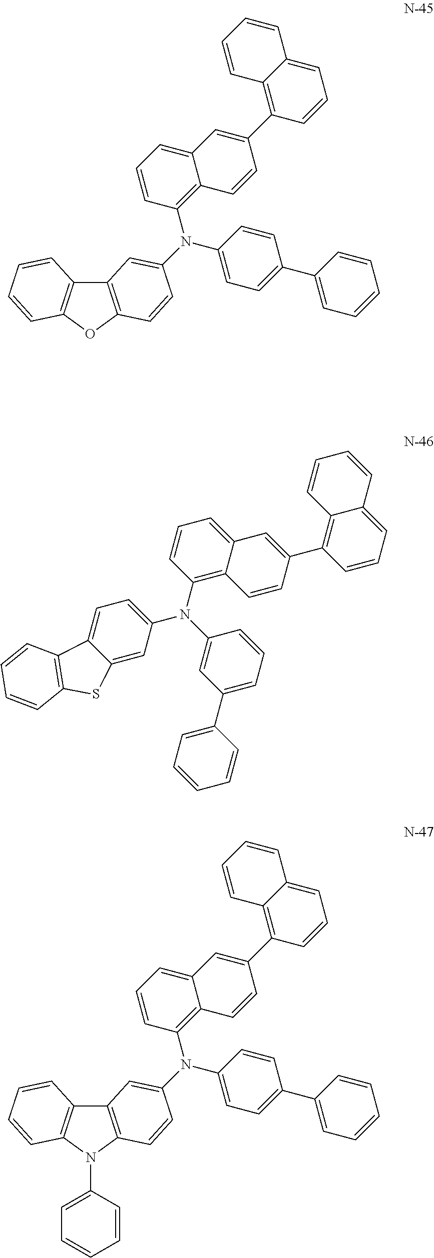 [SMILES: c1ccc(-c2ccc(N(c3ccc4oc5ccccc5c4c3)c3cccc4cc(-c5cccc6ccccc56)ccc34)cc2)cc1 ; c1ccc(-c2cccc(N(c3ccc4c(c3)sc3ccccc34)c3cccc4cc(-c5cccc6ccccc56)ccc34)c2)cc1 ; c1ccc(-c2ccc(N(c3ccc4c(c3)c3ccccc3n4-c3ccccc3)c3cccc4cc(-c5cccc6ccccc56)ccc34)cc2)cc1]

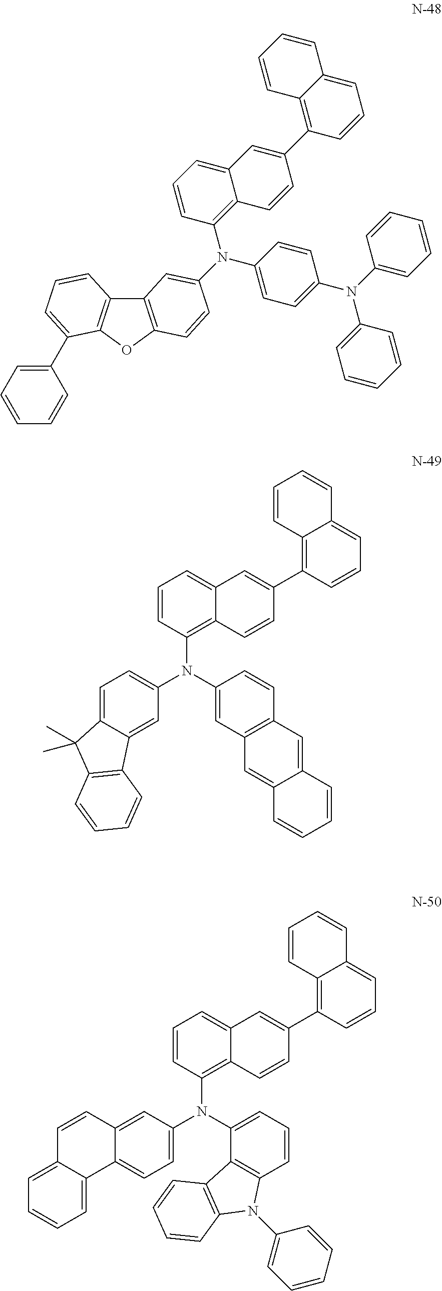 [SMILES: c1ccc(-c2cccc3c2oc2ccc(N(c4ccc(N(c5ccccc5)c5ccccc5)cc4)c4cccc5cc(-c6cccc7ccccc67)ccc45)cc23)cc1 ; CC1(C)c2ccccc2-c2cc(N(c3ccc4cc5ccccc5cc4c3)c3cccc4cc(-c5cccc6ccccc56)ccc34)ccc21 ; c1ccc(-n2c3ccccc3c3c(N(c4ccc5c(ccc6ccccc65)c4)c4cccc5cc(-c6cccc7ccccc67)ccc45)cccc32)cc1]

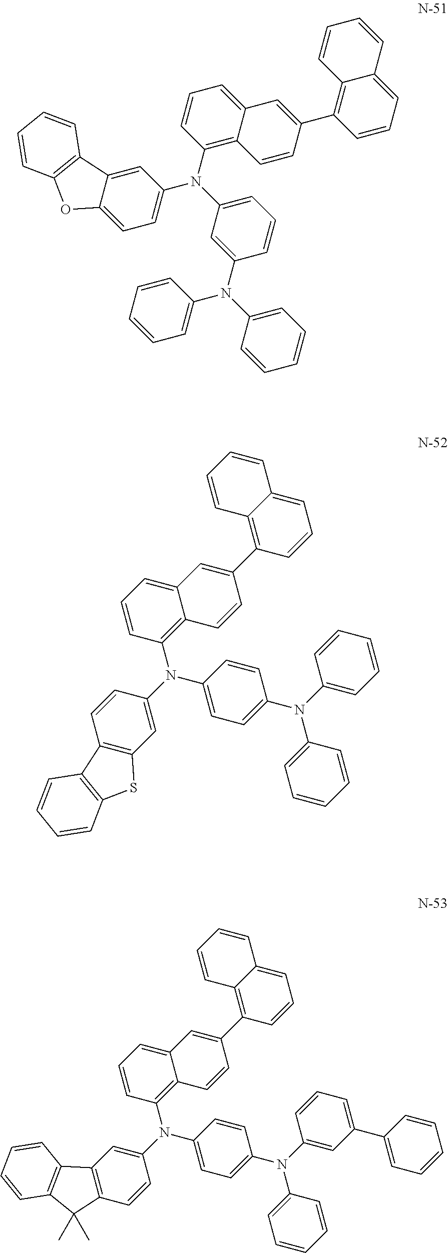 [SMILES: c1ccc(N(c2ccccc2)c2cccc(N(c3ccc4oc5ccccc5c4c3)c3cccc4cc(-c5cccc6ccccc56)ccc34)c2)cc1 ; c1ccc(N(c2ccccc2)c2ccc(N(c3ccc4c(c3)sc3ccccc34)c3cccc4cc(-c5cccc6ccccc56)ccc34)cc2)cc1 ; CC1(C)c2ccccc2-c2cc(N(c3ccc(N(c4ccccc4)c4cccc(-c5ccccc5)c4)cc3)c3cccc4cc(-c5cccc6ccccc56)ccc34)ccc21]

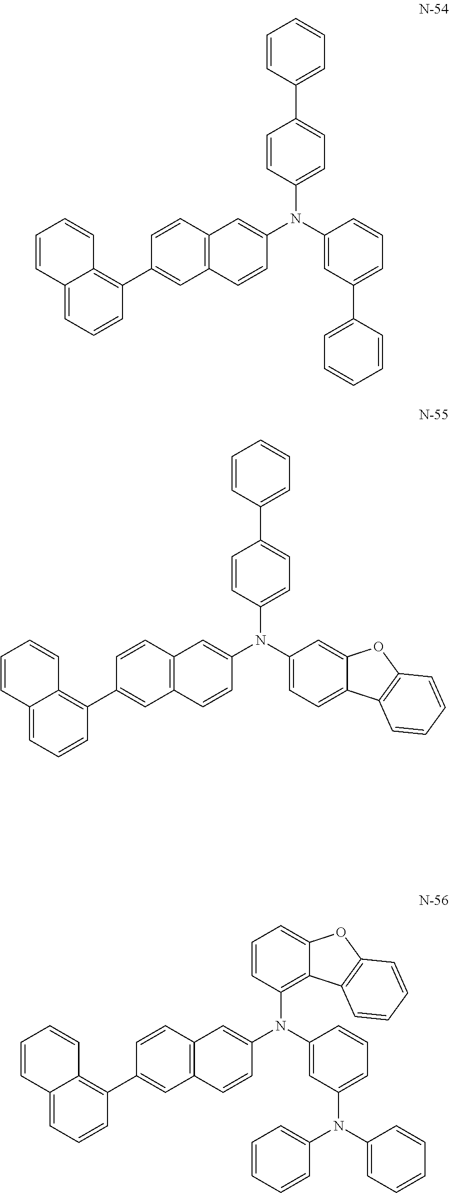 [SMILES: c1ccc(-c2ccc(N(c3cccc(-c4ccccc4)c3)c3ccc4cc(-c5cccc6ccccc56)ccc4c3)cc2)cc1 ; c1ccc(-c2ccc(N(c3ccc4cc(-c5cccc6ccccc56)ccc4c3)c3ccc4c(c3)oc3ccccc34)cc2)cc1 ; c1ccc(N(c2ccccc2)c2cccc(N(c3ccc4cc(-c5cccc6ccccc56)ccc4c3)c3cccc4oc5ccccc5c34)c2)cc1]

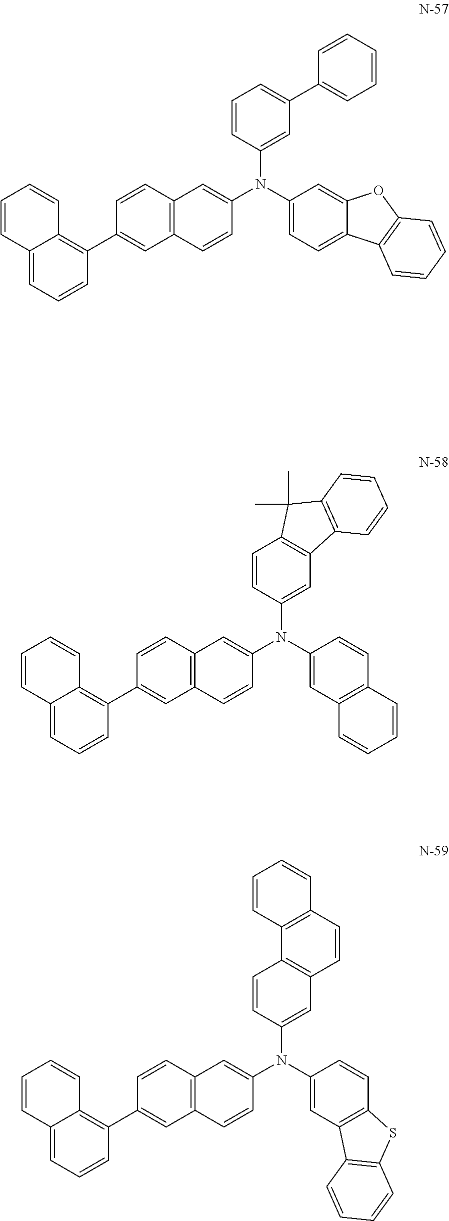 [SMILES: c1ccc(-c2cccc(N(c3ccc4cc(-c5cccc6ccccc56)ccc4c3)c3ccc4c(c3)oc3ccccc34)c2)cc1 ; CC1(C)c2ccccc2-c2cc(N(c3ccc4ccccc4c3)c3ccc4cc(-c5cccc6ccccc56)ccc4c3)ccc21 ; c1ccc2c(-c3ccc4cc(N(c5ccc6c(ccc7ccccc76)c5)c5ccc6sc7ccccc7c6c5)ccc4c3)cccc2c1]

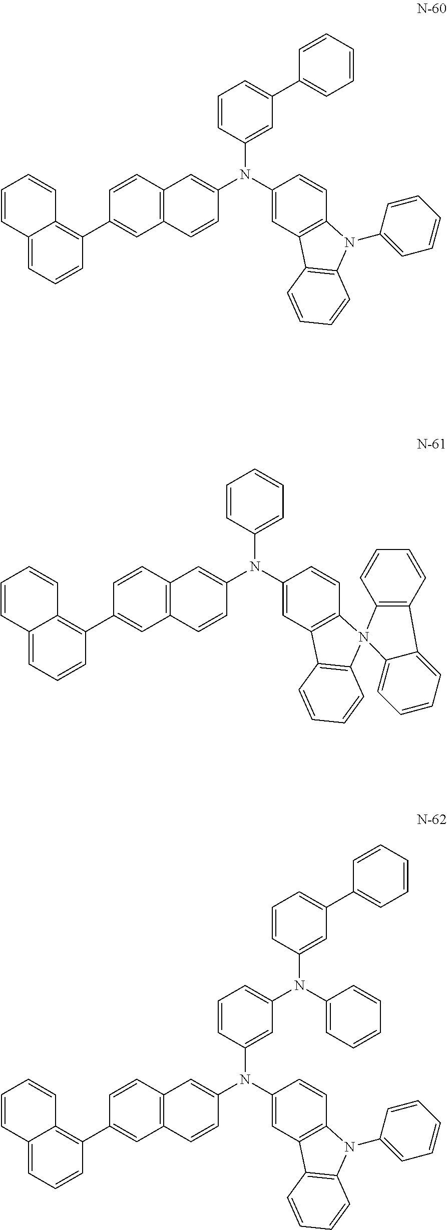

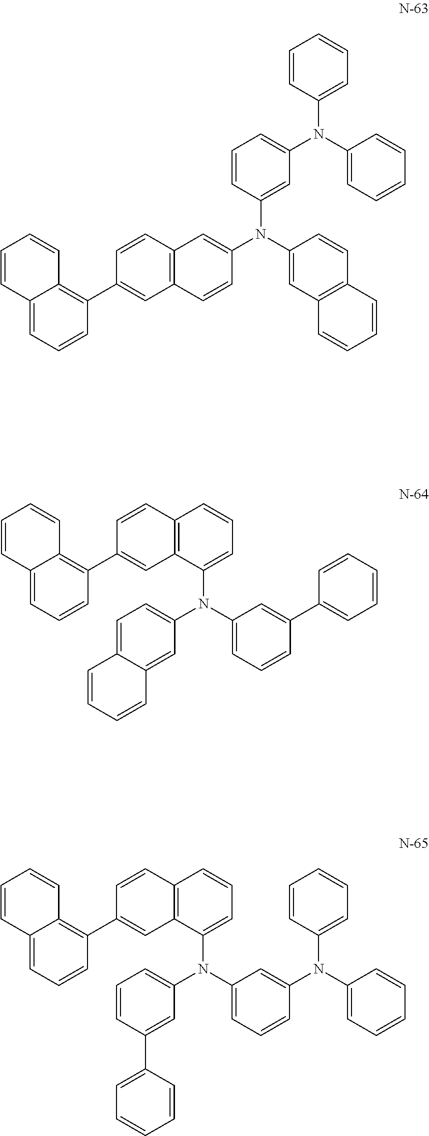 [SMILES: c1ccc(N(c2ccccc2)c2cccc(N(c3ccc4ccccc4c3)c3ccc4cc(-c5cccc6ccccc56)ccc4c3)c2)cc1 ; c1ccc(-c2cccc(N(c3ccc4ccccc4c3)c3cccc4ccc(-c5cccc6ccccc56)cc34)c2)cc1 ; c1ccc(-c2cccc(N(c3cccc(N(c4ccccc4)c4ccccc4)c3)c3cccc4ccc(-c5cccc6ccccc56)cc34)c2)cc1]

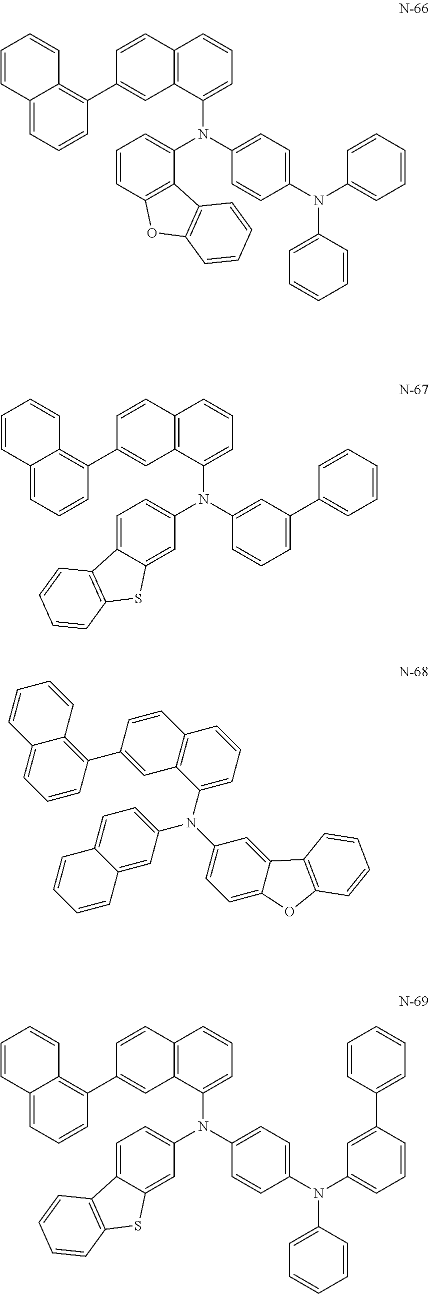 [SMILES: c1ccc(N(c2ccccc2)c2ccc(N(c3cccc4ccc(-c5cccc6ccccc56)cc34)c3cccc4oc5ccccc5c34)cc2)cc1 ; c1ccc(-c2cccc(N(c3ccc4c(c3)sc3ccccc34)c3cccc4ccc(-c5cccc6ccccc56)cc34)c2)cc1 ; c1ccc2cc(N(c3ccc4oc5ccccc5c4c3)c3cccc4ccc(-c5cccc6ccccc56)cc34)ccc2c1 ; c1ccc(-c2cccc(N(c3ccccc3)c3ccc(N(c4ccc5c(c4)sc4ccccc45)c4cccc5ccc(-c6cccc7ccccc67)cc45)cc3)c2)cc1]

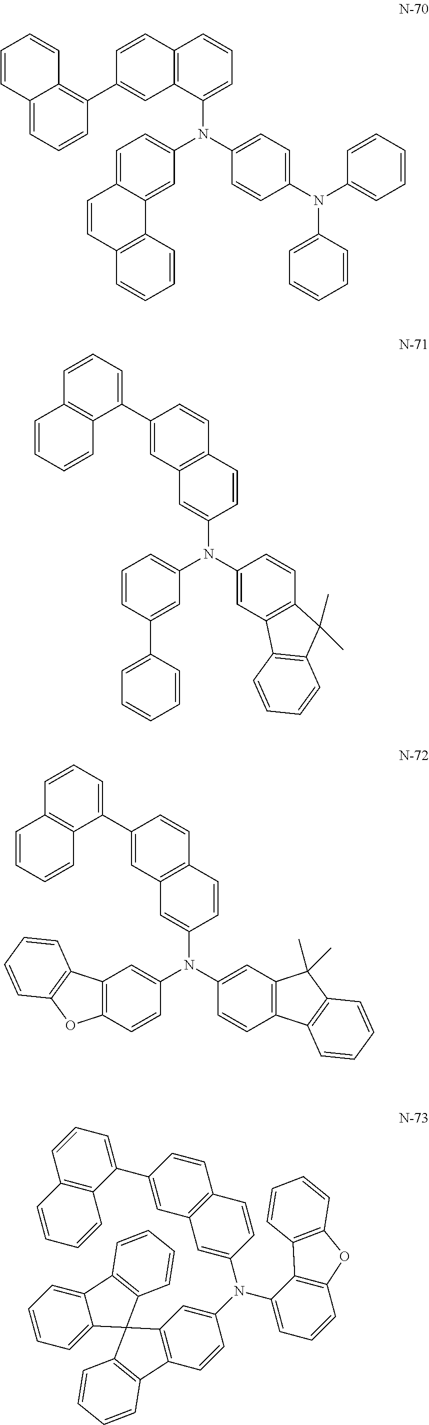 [SMILES: c1ccc(N(c2ccccc2)c2ccc(N(c3ccc4ccc5ccccc5c4c3)c3cccc4ccc(-c5cccc6ccccc56)cc34)cc2)cc1 ; CC1(C)c2ccccc2-c2cc(N(c3cccc(-c4ccccc4)c3)c3ccc4ccc(-c5cccc6ccccc56)cc4c3)ccc21 ; CC1(C)c2ccccc2-c2ccc(N(c3ccc4ccc(-c5cccc6ccccc56)cc4c3)c3ccc4oc5ccccc5c4c3)cc21 ; c1ccc2c(c1)-c1ccccc1C21c2ccccc2-c2ccc(N(c3ccc4ccc(-c5cccc6ccccc56)cc4c3)c3cccc4oc5ccccc5c34)cc21]

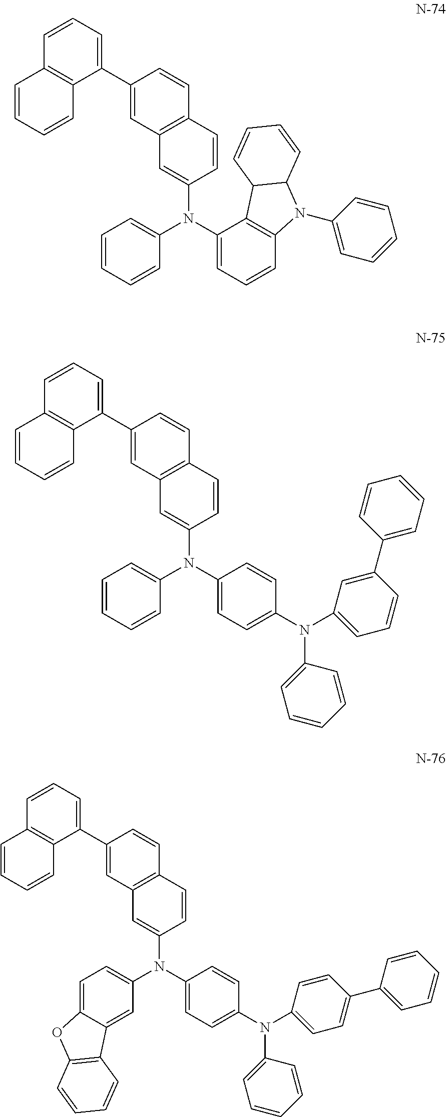 [SMILES: C1=CC2c3c(N(c4ccccc4)c4ccc5ccc(-c6cccc7ccccc67)cc5c4)cccc3N(c3ccccc3)C2C=C1 ; c1ccc(-c2cccc(N(c3ccccc3)c3ccc(N(c4ccccc4)c4ccc5ccc(-c6cccc7ccccc67)cc5c4)cc3)c2)cc1 ; c1ccc(-c2ccc(N(c3ccccc3)c3ccc(N(c4ccc5ccc(-c6cccc7ccccc67)cc5c4)c4ccc5oc6ccccc6c5c4)cc3)cc2)cc1]

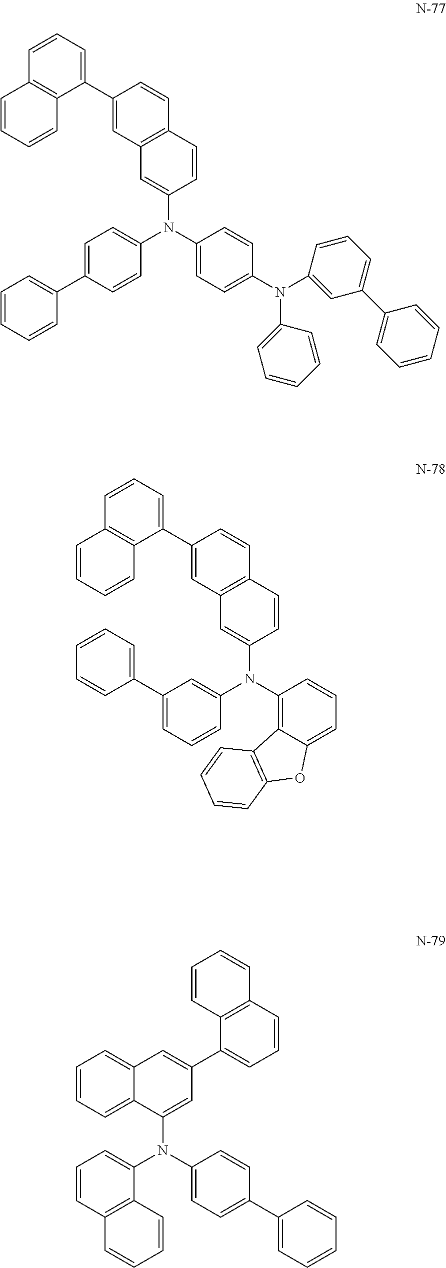 [SMILES: c1ccc(-c2ccc(N(c3ccc(N(c4ccccc4)c4cccc(-c5ccccc5)c4)cc3)c3ccc4ccc(-c5cccc6ccccc56)cc4c3)cc2)cc1 ; c1ccc(-c2cccc(N(c3ccc4ccc(-c5cccc6ccccc56)cc4c3)c3cccc4oc5ccccc5c34)c2)cc1 ; c1ccc(-c2ccc(N(c3cccc4ccccc34)c3cc(-c4cccc5ccccc45)cc4ccccc34)cc2)cc1]

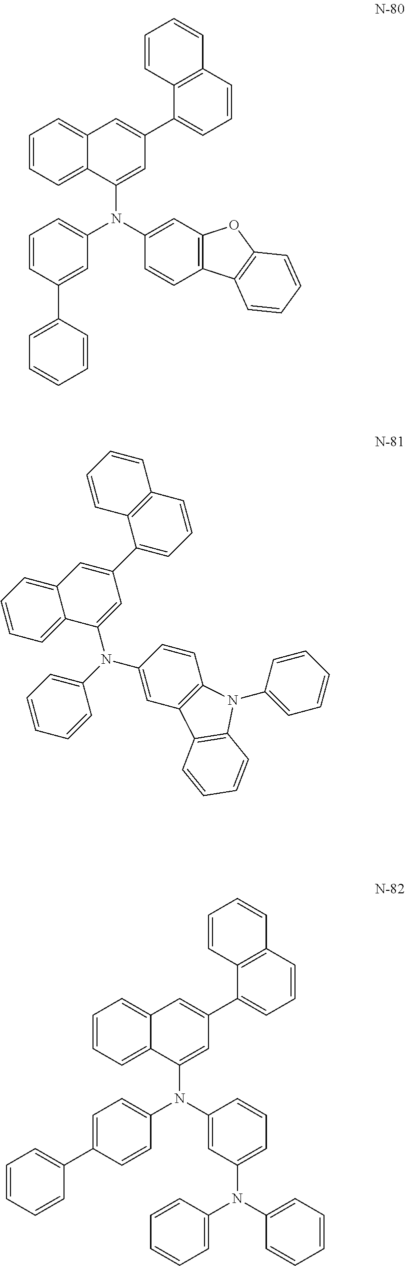 [SMILES: c1ccc(-c2cccc(N(c3ccc4c(c3)oc3ccccc34)c3cc(-c4cccc5ccccc45)cc4ccccc34)c2)cc1 ; c1ccc(N(c2ccc3c(c2)c2ccccc2n3-c2ccccc2)c2cc(-c3cccc4ccccc34)cc3ccccc23)cc1 ; c1ccc(-c2ccc(N(c3cccc(N(c4ccccc4)c4ccccc4)c3)c3cc(-c4cccc5ccccc45)cc4ccccc34)cc2)cc1]

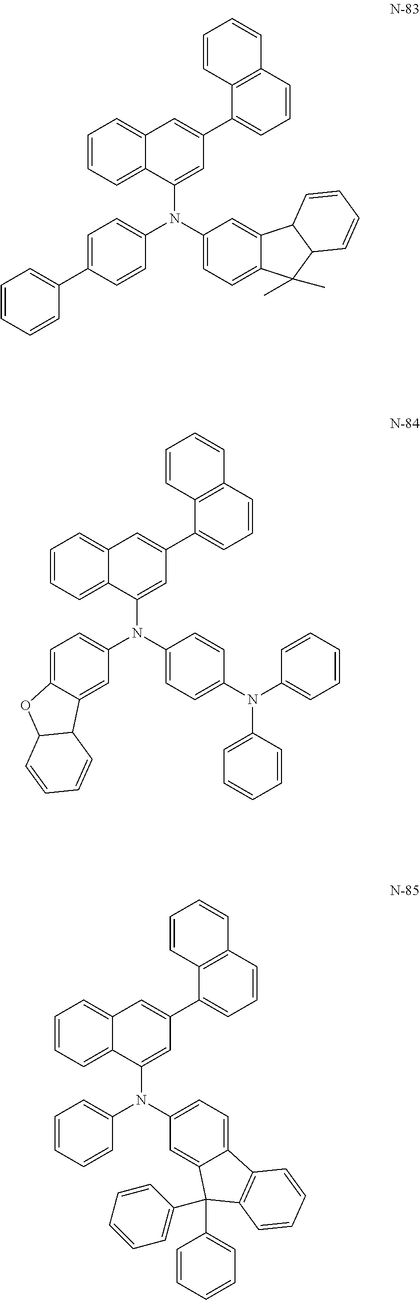 [SMILES: CC1(C)c2ccc(N(c3ccc(-c4ccccc4)cc3)c3cc(-c4cccc5ccccc45)cc4ccccc34)cc2C2C=CC=CC21 ; C1=CC2Oc3ccc(N(c4ccc(N(c5ccccc5)c5ccccc5)cc4)c4cc(-c5cccc6ccccc56)cc5ccccc45)cc3C2C=C1 ; c1ccc(N(c2ccc3c(c2)C(c2ccccc2)(c2ccccc2)c2ccccc2-3)c2cc(-c3cccc4ccccc34)cc3ccccc23)cc1]

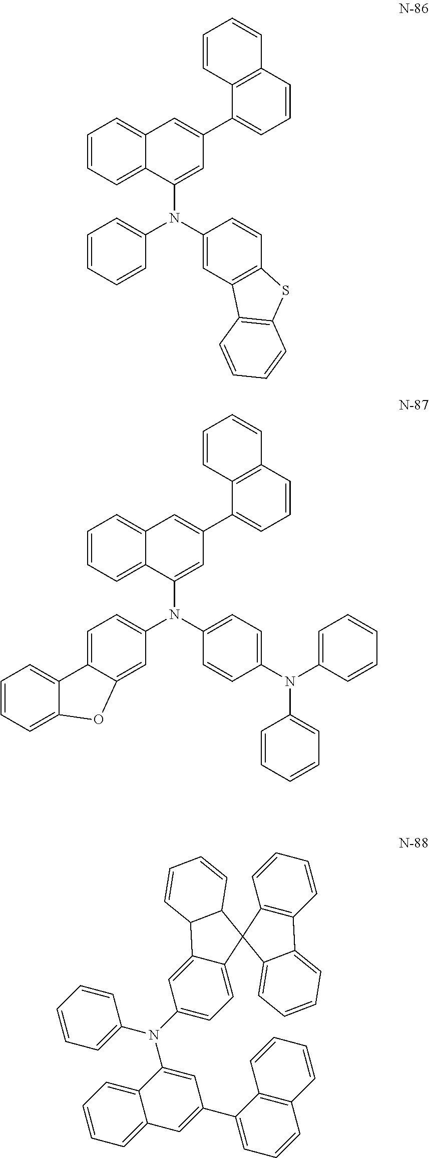

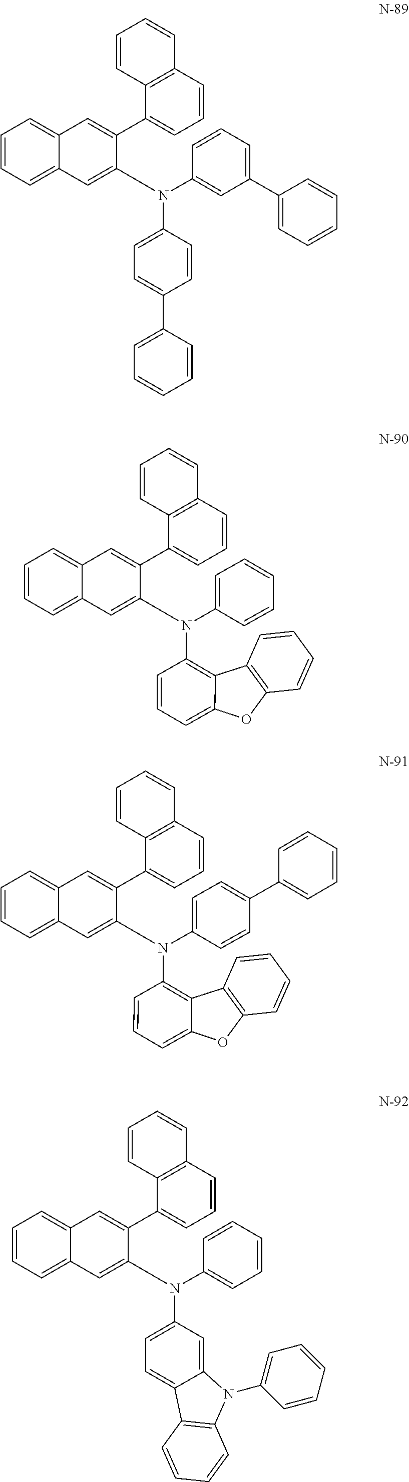 [SMILES: c1ccc(-c2ccc(N(c3cccc(-c4ccccc4)c3)c3cc4ccccc4cc3-c3cccc4ccccc34)cc2)cc1 ; c1ccc(N(c2cc3ccccc3cc2-c2cccc3ccccc23)c2cccc3oc4ccccc4c23)cc1 ; c1ccc(-c2ccc(N(c3cc4ccccc4cc3-c3cccc4ccccc34)c3cccc4oc5ccccc5c34)cc2)cc1 ; c1ccc(N(c2ccc3c4ccccc4n(-c4ccccc4)c3c2)c2cc3ccccc3cc2-c2cccc3ccccc23)cc1]

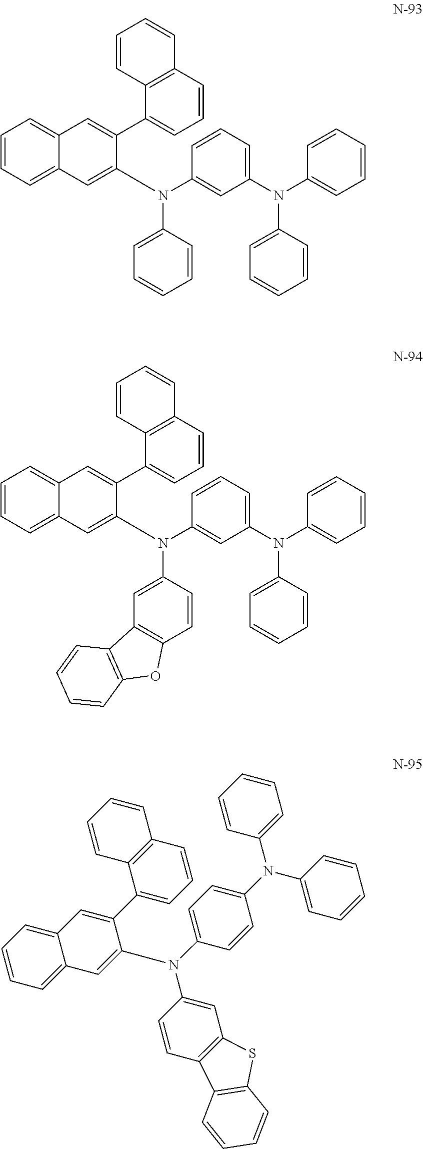 [SMILES: c1ccc(N(c2ccccc2)c2cccc(N(c3ccccc3)c3cc4ccccc4cc3-c3cccc4ccccc34)c2)cc1 ; c1ccc(N(c2ccccc2)c2cccc(N(c3ccc4oc5ccccc5c4c3)c3cc4ccccc4cc3-c3cccc4ccccc34)c2)cc1 ; c1ccc(N(c2ccccc2)c2ccc(N(c3ccc4c(c3)sc3ccccc34)c3cc4ccccc4cc3-c3cccc4ccccc34)cc2)cc1]

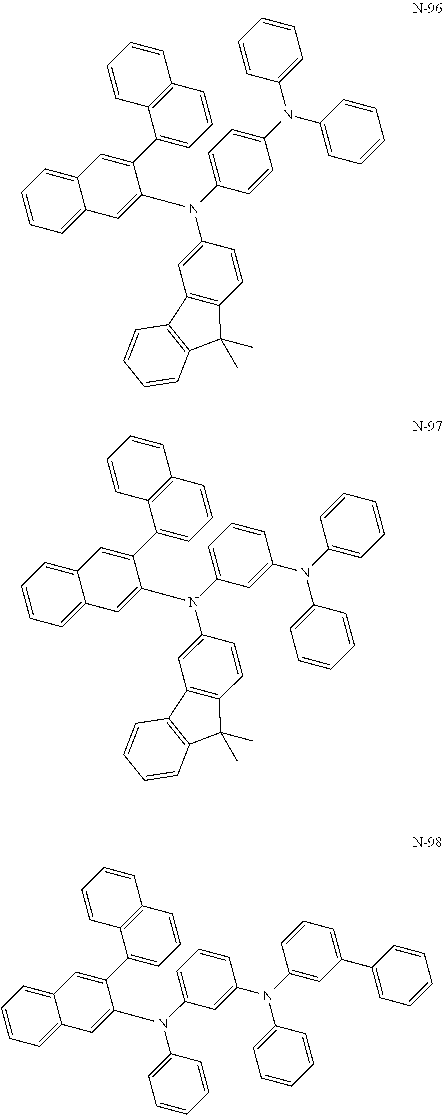 [SMILES: CC1(C)c2ccccc2-c2cc(N(c3ccc(N(c4ccccc4)c4ccccc4)cc3)c3cc4ccccc4cc3-c3cccc4ccccc34)ccc21 ; CC1(C)c2ccccc2-c2cc(N(c3cccc(N(c4ccccc4)c4ccccc4)c3)c3cc4ccccc4cc3-c3cccc4ccccc34)ccc21 ; c1ccc(-c2cccc(N(c3ccccc3)c3cccc(N(c4ccccc4)c4cc5ccccc5cc4-c4cccc5ccccc45)c3)c2)cc1]

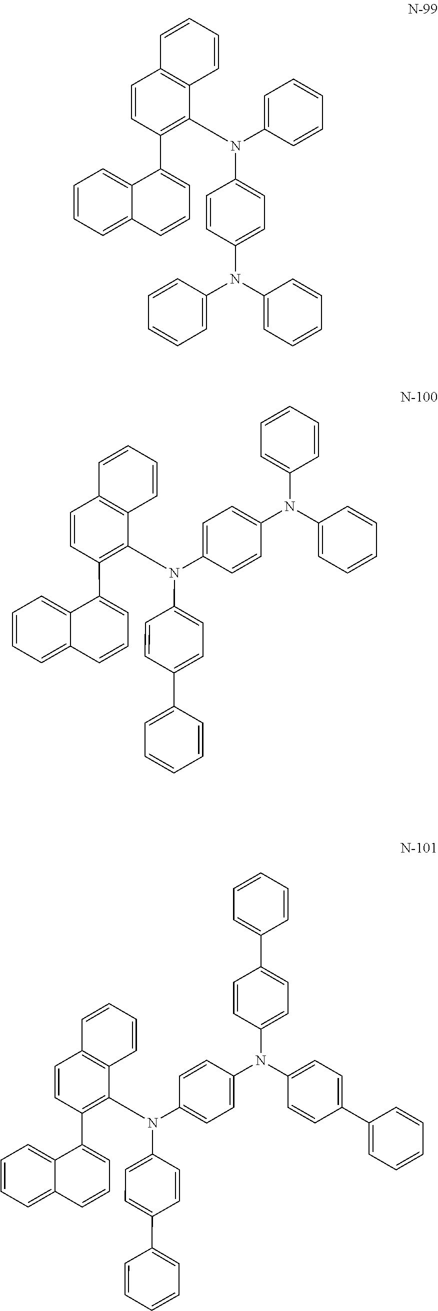 [SMILES: c1ccc(N(c2ccccc2)c2ccc(N(c3ccccc3)c3c(-c4cccc5ccccc45)ccc4ccccc34)cc2)cc1 ; c1ccc(-c2ccc(N(c3ccc(N(c4ccccc4)c4ccccc4)cc3)c3c(-c4cccc5ccccc45)ccc4ccccc34)cc2)cc1 ; c1ccc(-c2ccc(N(c3ccc(-c4ccccc4)cc3)c3ccc(N(c4ccc(-c5ccccc5)cc4)c4c(-c5cccc6ccccc56)ccc5ccccc45)cc3)cc2)cc1]

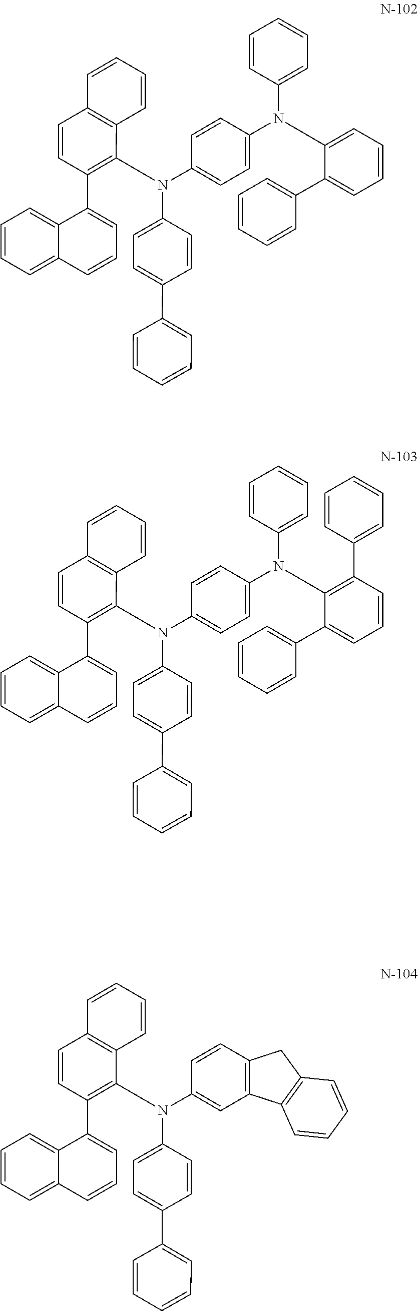 [SMILES: c1ccc(-c2ccc(N(c3ccc(N(c4ccccc4)c4ccccc4-c4ccccc4)cc3)c3c(-c4cccc5ccccc45)ccc4ccccc34)cc2)cc1 ; c1ccc(-c2ccc(N(c3ccc(N(c4ccccc4)c4c(-c5ccccc5)cccc4-c4ccccc4)cc3)c3c(-c4cccc5ccccc45)ccc4ccccc34)cc2)cc1 ; c1ccc(-c2ccc(N(c3ccc4c(c3)-c3ccccc3C4)c3c(-c4cccc5ccccc45)ccc4ccccc34)cc2)cc1]

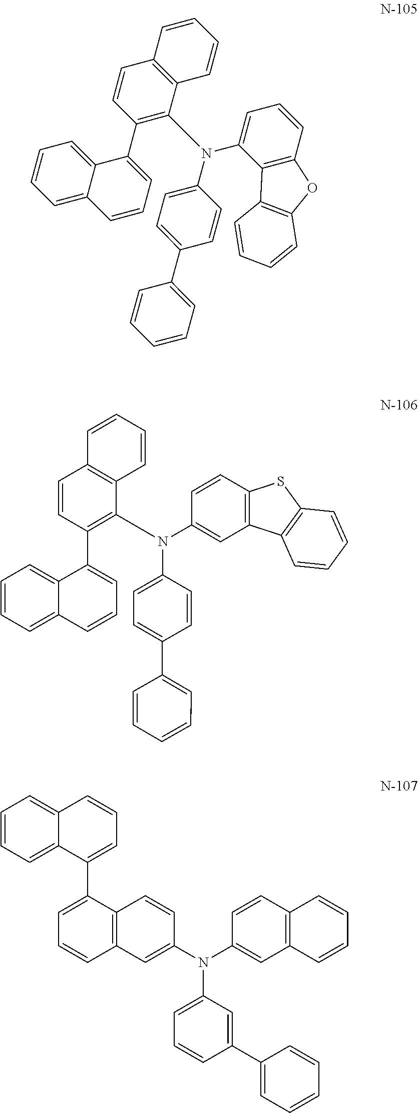 [SMILES: c1ccc(-c2ccc(N(c3c(-c4cccc5ccccc45)ccc4ccccc34)c3cccc4oc5ccccc5c34)cc2)cc1 ; c1ccc(-c2ccc(N(c3ccc4sc5ccccc5c4c3)c3c(-c4cccc5ccccc45)ccc4ccccc34)cc2)cc1 ; c1ccc(-c2cccc(N(c3ccc4ccccc4c3)c3ccc4c(-c5cccc6ccccc56)cccc4c3)c2)cc1]

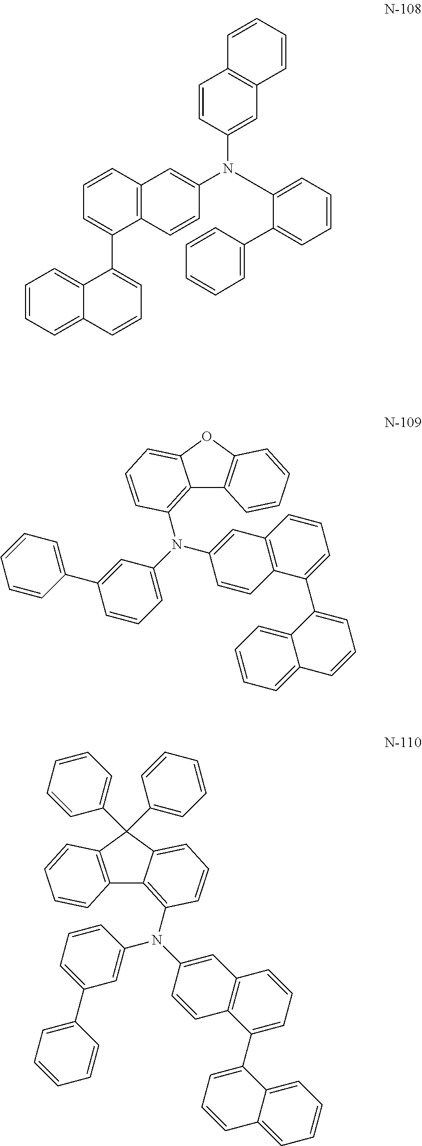 [SMILES: c1ccc(-c2ccccc2N(c2ccc3ccccc3c2)c2ccc3c(-c4cccc5ccccc45)cccc3c2)cc1 ; c1ccc(-c2cccc(N(c3ccc4c(-c5cccc6ccccc56)cccc4c3)c3cccc4oc5ccccc5c34)c2)cc1 ; c1ccc(-c2cccc(N(c3ccc4c(-c5cccc6ccccc56)cccc4c3)c3cccc4c3-c3ccccc3C4(c3ccccc3)c3ccccc3)c2)cc1]

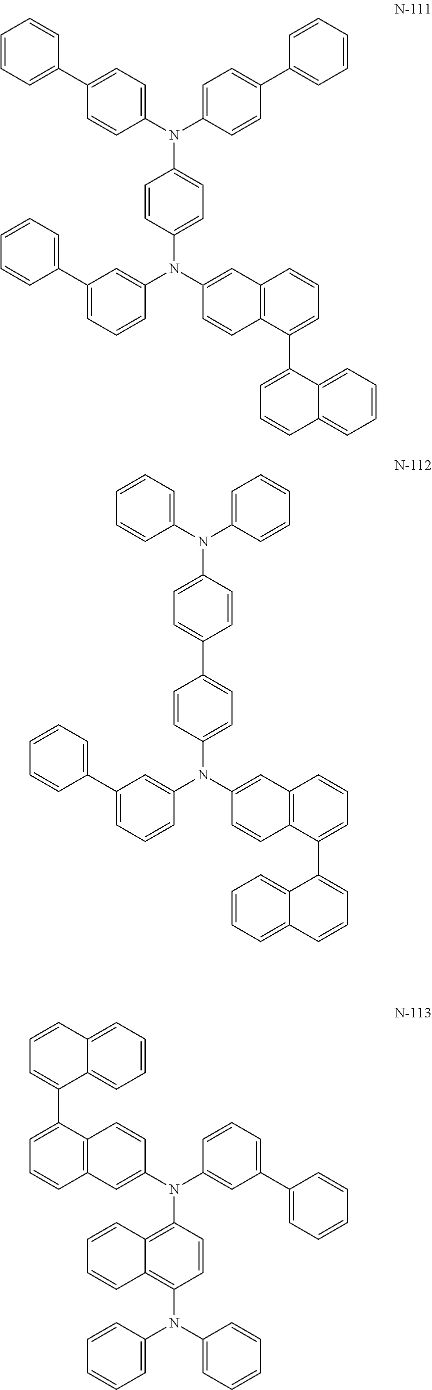 [SMILES: c1ccc(-c2ccc(N(c3ccc(-c4ccccc4)cc3)c3ccc(N(c4cccc(-c5ccccc5)c4)c4ccc5c(-c6cccc7ccccc67)cccc5c4)cc3)cc2)cc1 ; c1ccc(-c2cccc(N(c3ccc(-c4ccc(N(c5ccccc5)c5ccccc5)cc4)cc3)c3ccc4c(-c5cccc6ccccc56)cccc4c3)c2)cc1 ; c1ccc(-c2cccc(N(c3ccc4c(-c5cccc6ccccc56)cccc4c3)c3ccc(N(c4ccccc4)c4ccccc4)c4ccccc34)c2)cc1]

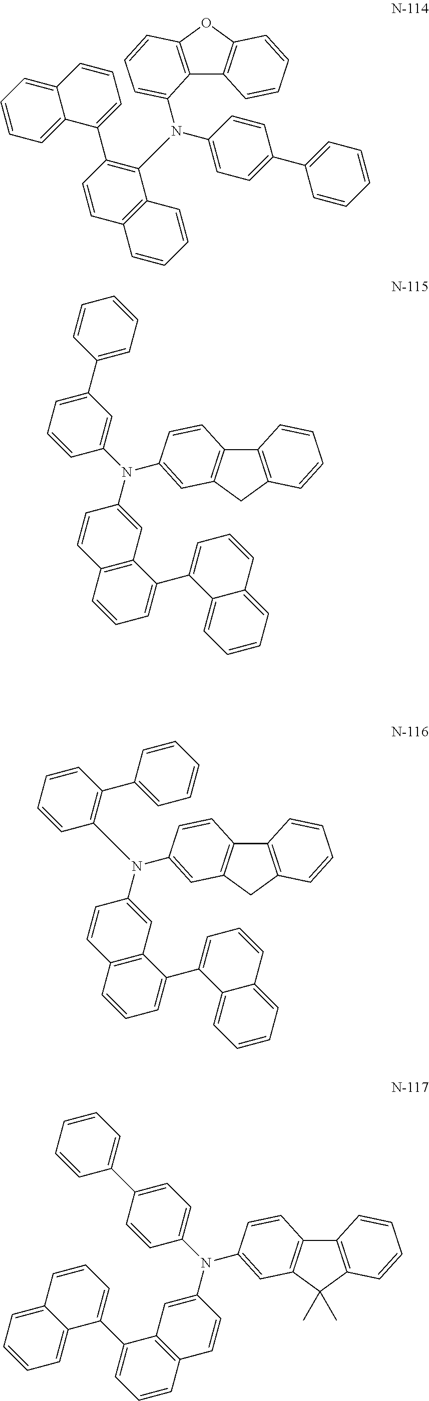

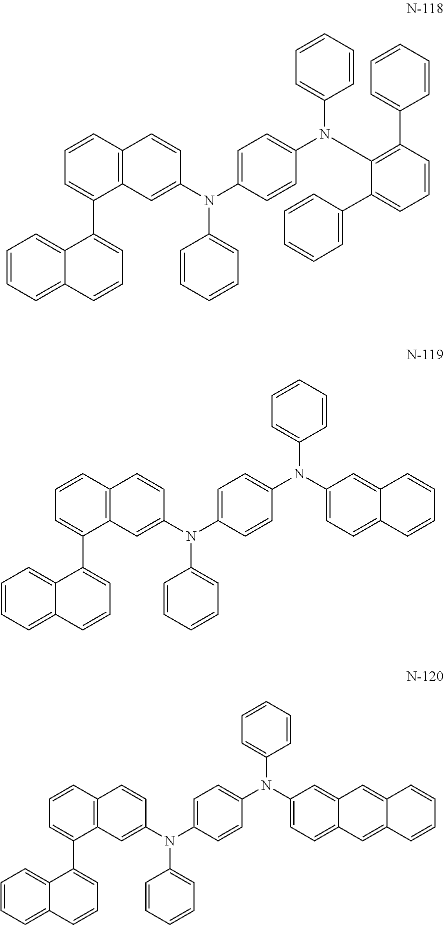 [SMILES: c1ccc(-c2cccc(-c3ccccc3)c2N(c2ccccc2)c2ccc(N(c3ccccc3)c3ccc4cccc(-c5cccc6ccccc56)c4c3)cc2)cc1 ; c1ccc(N(c2ccc(N(c3ccccc3)c3ccc4cccc(-c5cccc6ccccc56)c4c3)cc2)c2ccc3ccccc3c2)cc1 ; c1ccc(N(c2ccc(N(c3ccccc3)c3ccc4cccc(-c5cccc6ccccc56)c4c3)cc2)c2ccc3cc4ccccc4cc3c2)cc1]

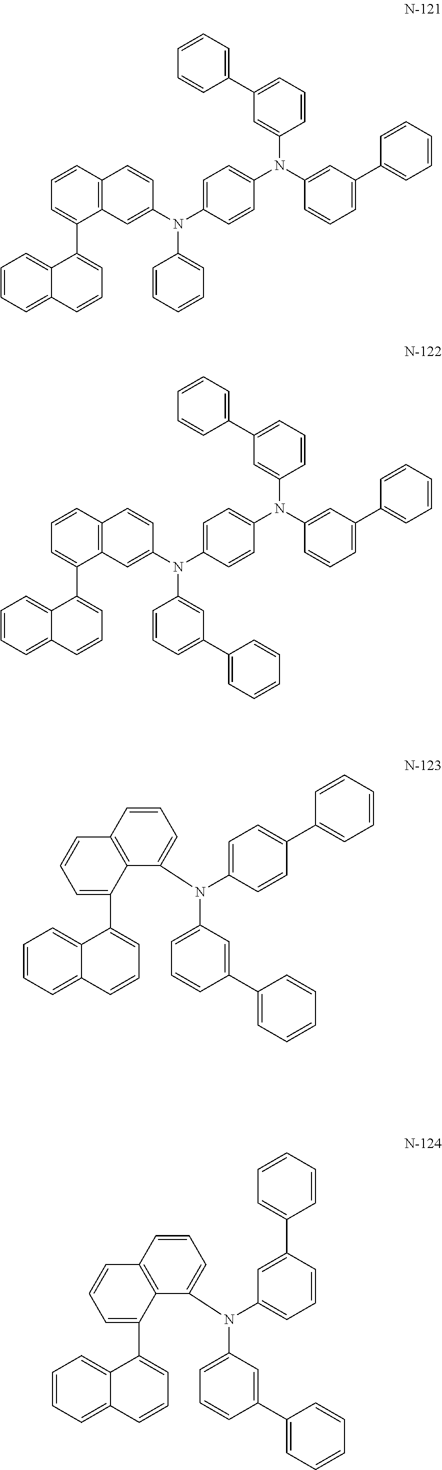 [SMILES: c1ccc(-c2cccc(N(c3ccc(N(c4ccccc4)c4ccc5cccc(-c6cccc7ccccc67)c5c4)cc3)c3cccc(-c4ccccc4)c3)c2)cc1 ; c1ccc(-c2cccc(N(c3ccc(N(c4cccc(-c5ccccc5)c4)c4ccc5cccc(-c6cccc7ccccc67)c5c4)cc3)c3cccc(-c4ccccc4)c3)c2)cc1 ; c1ccc(-c2ccc(N(c3cccc(-c4ccccc4)c3)c3cccc4cccc(-c5cccc6ccccc56)c34)cc2)cc1 ; c1ccc(-c2cccc(N(c3cccc(-c4ccccc4)c3)c3cccc4cccc(-c5cccc6ccccc56)c34)c2)cc1]

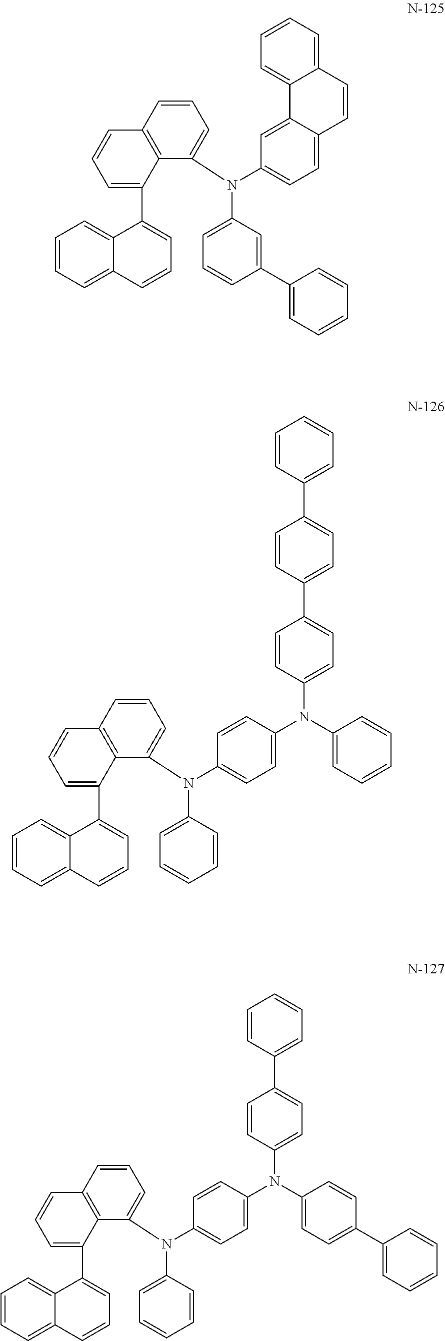 [SMILES: c1ccc(-c2cccc(N(c3ccc4ccc5ccccc5c4c3)c3cccc4cccc(-c5cccc6ccccc56)c34)c2)cc1 ; c1ccc(-c2ccc(-c3ccc(N(c4ccccc4)c4ccc(N(c5ccccc5)c5cccc6cccc(-c7cccc8ccccc78)c56)cc4)cc3)cc2)cc1 ; c1ccc(-c2ccc(N(c3ccc(-c4ccccc4)cc3)c3ccc(N(c4ccccc4)c4cccc5cccc(-c6cccc7ccccc67)c45)cc3)cc2)cc1]

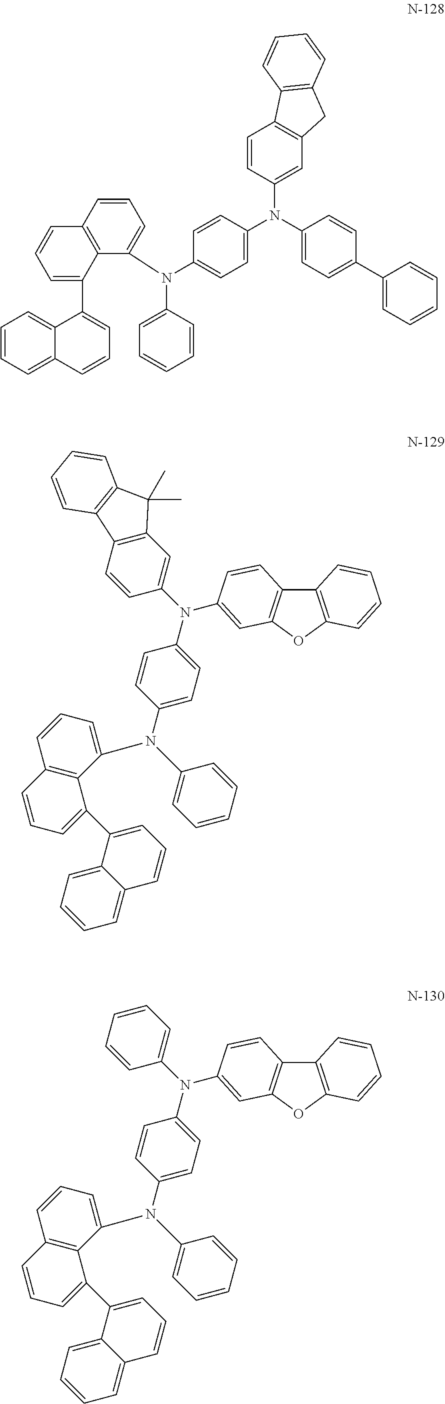 [SMILES: c1ccc(-c2ccc(N(c3ccc(N(c4ccccc4)c4cccc5cccc(-c6cccc7ccccc67)c45)cc3)c3ccc4c(c3)Cc3ccccc3-4)cc2)cc1 ; CC1(C)c2ccccc2-c2ccc(N(c3ccc(N(c4ccccc4)c4cccc5cccc(-c6cccc7ccccc67)c45)cc3)c3ccc4c(c3)oc3ccccc34)cc21 ; c1ccc(N(c2ccc(N(c3ccccc3)c3cccc4cccc(-c5cccc6ccccc56)c34)cc2)c2ccc3c(c2)oc2ccccc23)cc1]

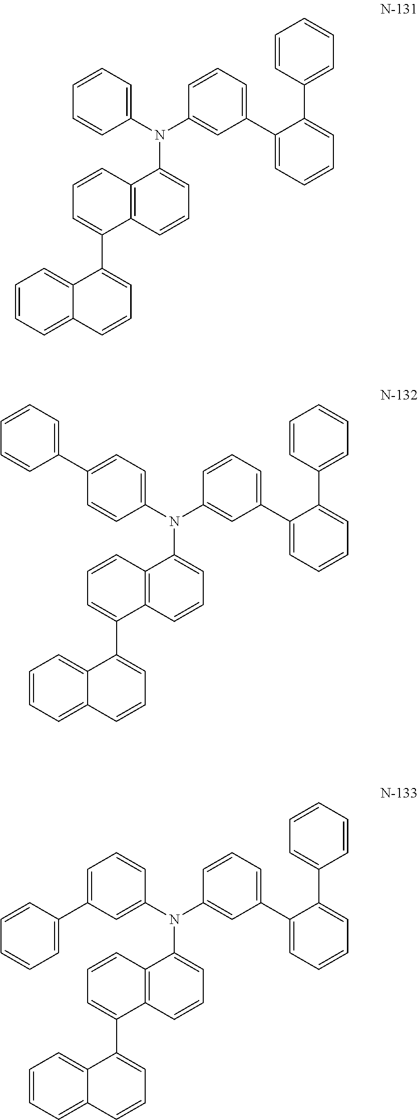 [SMILES: c1ccc(-c2ccccc2-c2cccc(N(c3ccccc3)c3cccc4c(-c5cccc6ccccc56)cccc34)c2)cc1 ; c1ccc(-c2ccc(N(c3cccc(-c4ccccc4-c4ccccc4)c3)c3cccc4c(-c5cccc6ccccc56)cccc34)cc2)cc1 ; c1ccc(-c2cccc(N(c3cccc(-c4ccccc4-c4ccccc4)c3)c3cccc4c(-c5cccc6ccccc56)cccc34)c2)cc1]

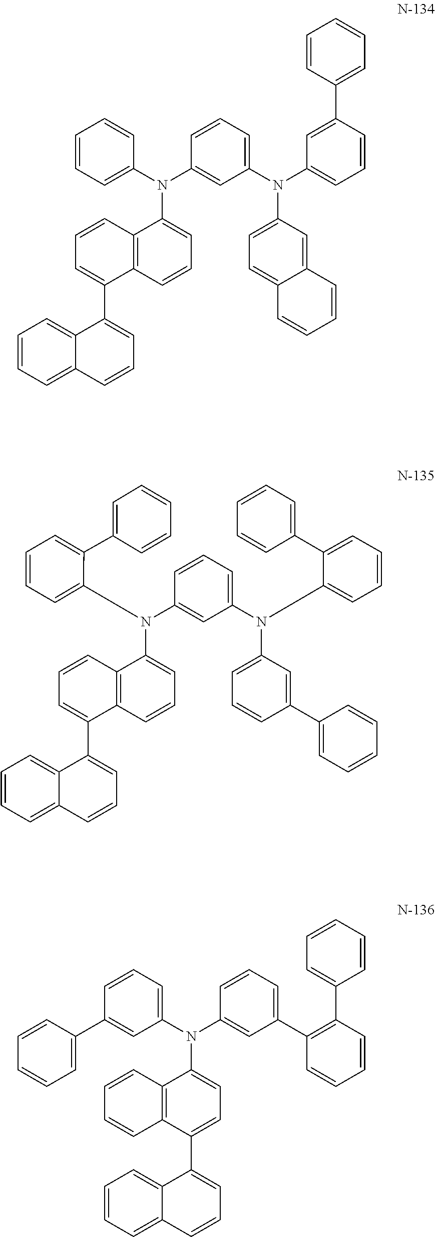 [SMILES: c1ccc(-c2cccc(N(c3cccc(N(c4ccccc4)c4cccc5c(-c6cccc7ccccc67)cccc45)c3)c3ccc4ccccc4c3)c2)cc1 ; c1ccc(-c2cccc(N(c3cccc(N(c4ccccc4-c4ccccc4)c4cccc5c(-c6cccc7ccccc67)cccc45)c3)c3ccccc3-c3ccccc3)c2)cc1 ; c1ccc(-c2cccc(N(c3cccc(-c4ccccc4-c4ccccc4)c3)c3ccc(-c4cccc5ccccc45)c4ccccc34)c2)cc1]

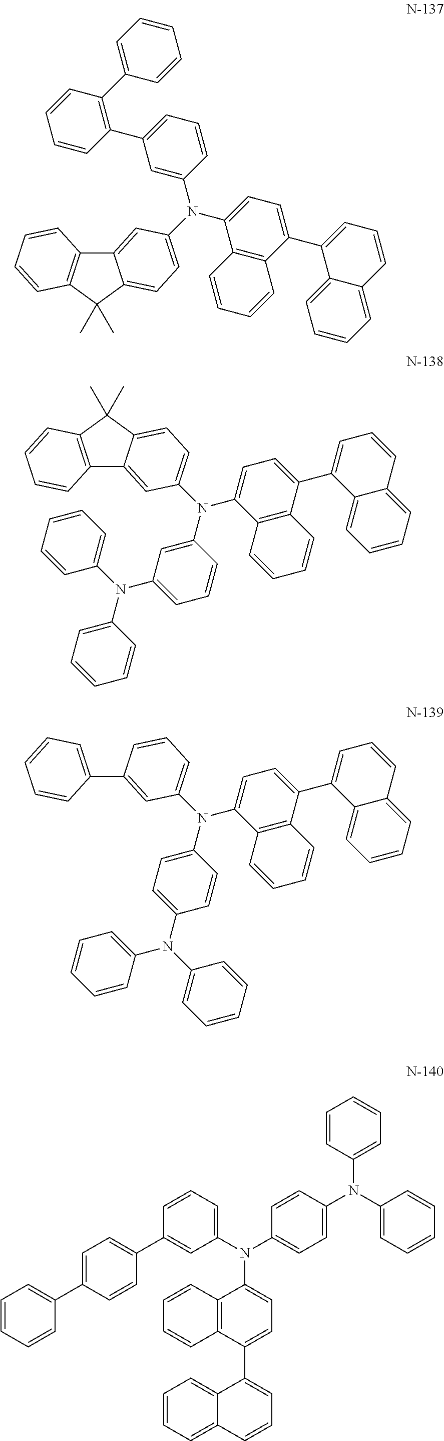 [SMILES: CC1(C)c2ccccc2-c2cc(N(c3cccc(-c4ccccc4-c4ccccc4)c3)c3ccc(-c4cccc5ccccc45)c4ccccc34)ccc21 ; CC1(C)c2ccccc2-c2cc(N(c3cccc(N(c4ccccc4)c4ccccc4)c3)c3ccc(-c4cccc5ccccc45)c4ccccc34)ccc21 ; c1ccc(-c2cccc(N(c3ccc(N(c4ccccc4)c4ccccc4)cc3)c3ccc(-c4cccc5ccccc45)c4ccccc34)c2)cc1 ; c1ccc(-c2ccc(-c3cccc(N(c4ccc(N(c5ccccc5)c5ccccc5)cc4)c4ccc(-c5cccc6ccccc56)c5ccccc45)c3)cc2)cc1]

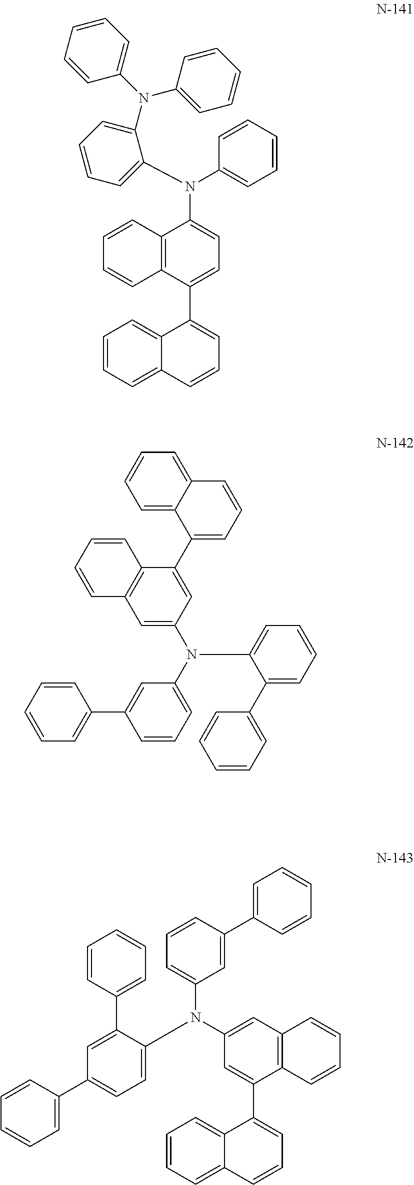 [SMILES: c1ccc(N(c2ccccc2)c2ccccc2N(c2ccccc2)c2ccc(-c3cccc4ccccc34)c3ccccc23)cc1 ; c1ccc(-c2cccc(N(c3cc(-c4cccc5ccccc45)c4ccccc4c3)c3ccccc3-c3ccccc3)c2)cc1 ; c1ccc(-c2cccc(N(c3cc(-c4cccc5ccccc45)c4ccccc4c3)c3ccc(-c4ccccc4)cc3-c3ccccc3)c2)cc1]

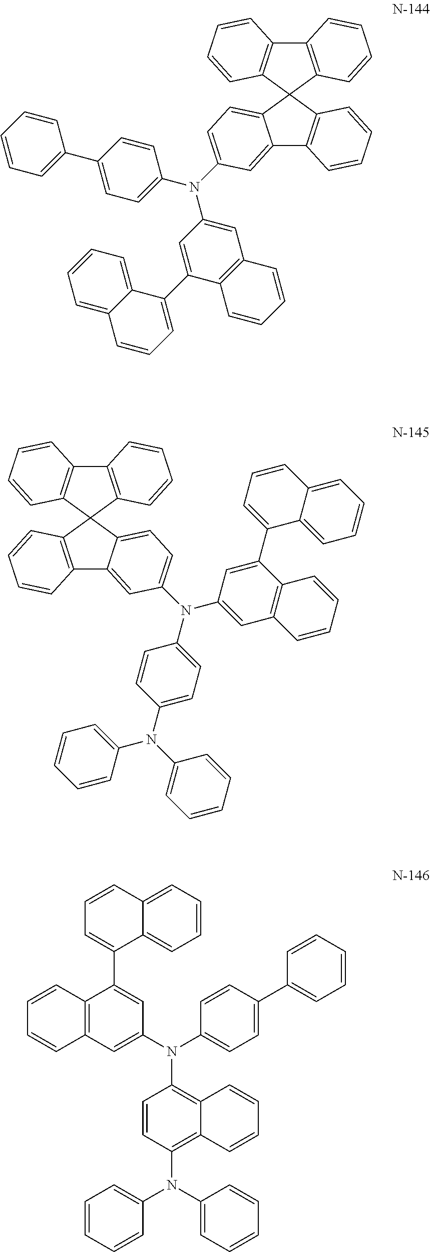 [SMILES: c1ccc(-c2ccc(N(c3ccc4c(c3)-c3ccccc3C43c4ccccc4-c4ccccc43)c3cc(-c4cccc5ccccc45)c4ccccc4c3)cc2)cc1 ; c1ccc(N(c2ccccc2)c2ccc(N(c3ccc4c(c3)-c3ccccc3C43c4ccccc4-c4ccccc43)c3cc(-c4cccc5ccccc45)c4ccccc4c3)cc2)cc1 ; c1ccc(-c2ccc(N(c3cc(-c4cccc5ccccc45)c4ccccc4c3)c3ccc(N(c4ccccc4)c4ccccc4)c4ccccc34)cc2)cc1]

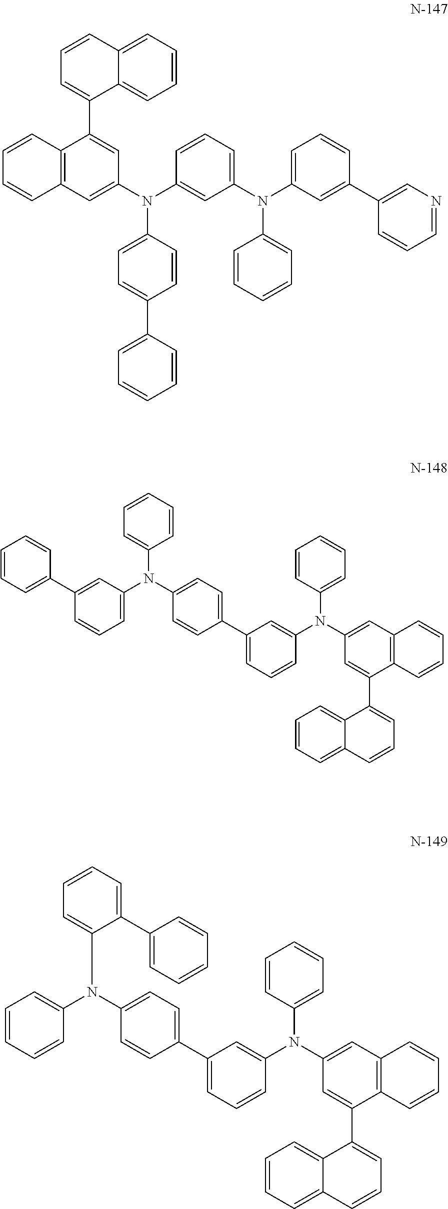 [SMILES: c1ccc(-c2ccc(N(c3cccc(N(c4ccccc4)c4cccc(-c5cccnc5)c4)c3)c3cc(-c4cccc5ccccc45)c4ccccc4c3)cc2)cc1 ; c1ccc(-c2cccc(N(c3ccccc3)c3ccc(-c4cccc(N(c5ccccc5)c5cc(-c6cccc7ccccc67)c6ccccc6c5)c4)cc3)c2)cc1 ; c1ccc(-c2ccccc2N(c2ccccc2)c2ccc(-c3cccc(N(c4ccccc4)c4cc(-c5cccc6ccccc56)c5ccccc5c4)c3)cc2)cc1]

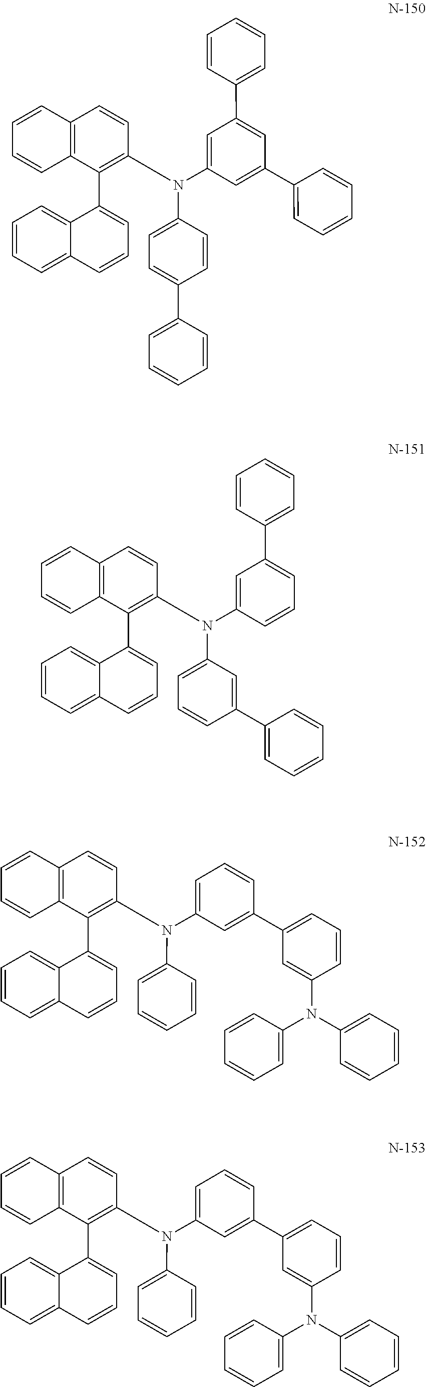 [SMILES: c1ccc(-c2ccc(N(c3cc(-c4ccccc4)cc(-c4ccccc4)c3)c3ccc4ccccc4c3-c3cccc4ccccc34)cc2)cc1 ; c1ccc(-c2cccc(N(c3cccc(-c4ccccc4)c3)c3ccc4ccccc4c3-c3cccc4ccccc34)c2)cc1 ; c1ccc(N(c2ccccc2)c2cccc(-c3cccc(N(c4ccccc4)c4ccc5ccccc5c4-c4cccc5ccccc45)c3)c2)cc1 ; c1ccc(N(c2ccccc2)c2cccc(-c3cccc(N(c4ccccc4)c4ccc5ccccc5c4-c4cccc5ccccc45)c3)c2)cc1]

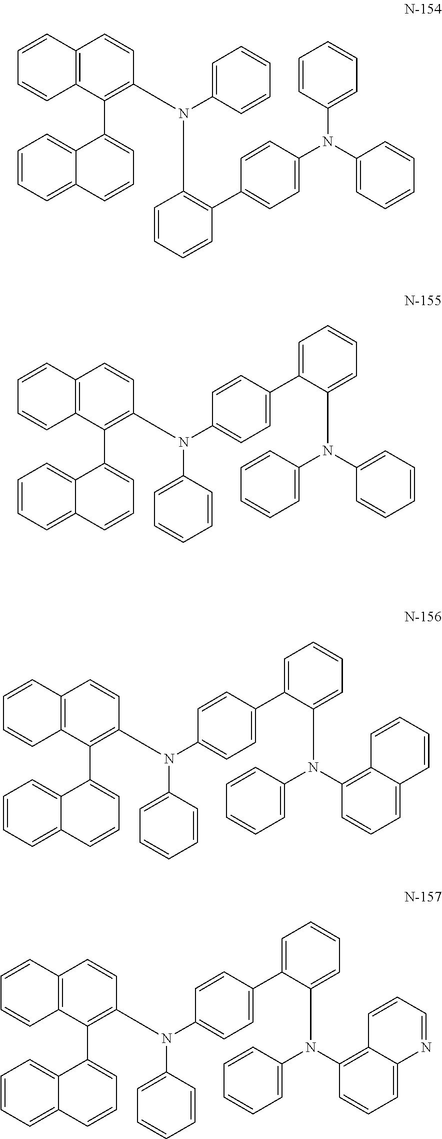 [SMILES: c1ccc(N(c2ccccc2)c2ccc(-c3ccccc3N(c3ccccc3)c3ccc4ccccc4c3-c3cccc4ccccc34)cc2)cc1 ; c1ccc(N(c2ccccc2)c2ccccc2-c2ccc(N(c3ccccc3)c3ccc4ccccc4c3-c3cccc4ccccc34)cc2)cc1 ; c1ccc(N(c2ccc(-c3ccccc3N(c3ccccc3)c3cccc4ccccc34)cc2)c2ccc3ccccc3c2-c2cccc3ccccc23)cc1 ; c1ccc(N(c2ccc(-c3ccccc3N(c3ccccc3)c3cccc4ncccc34)cc2)c2ccc3ccccc3c2-c2cccc3ccccc23)cc1]

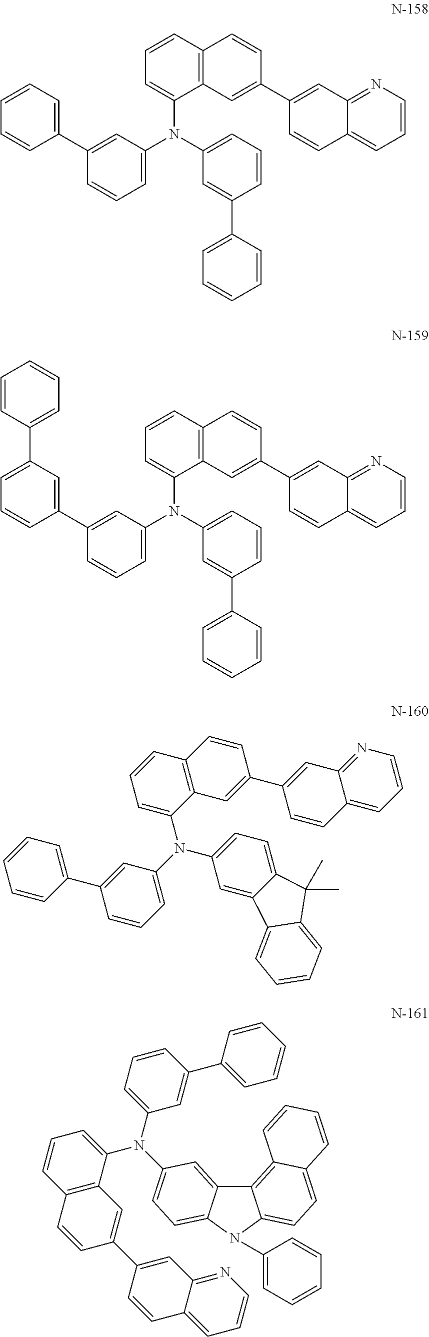

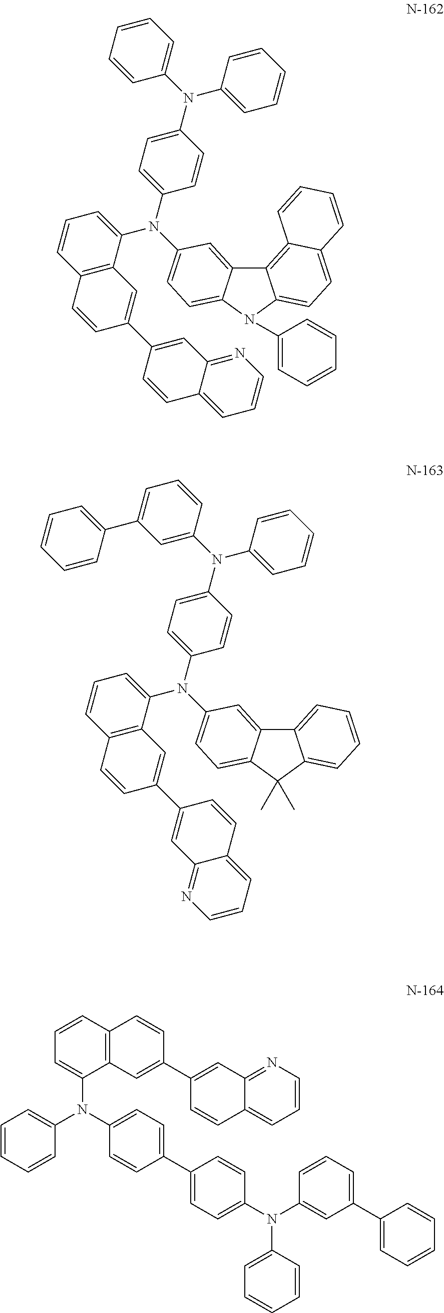 [SMILES: c1ccc(N(c2ccccc2)c2ccc(N(c3ccc4c(c3)c3c5ccccc5ccc3n4-c3ccccc3)c3cccc4ccc(-c5ccc6cccnc6c5)cc34)cc2)cc1 ; CC1(C)c2ccccc2-c2cc(N(c3ccc(N(c4ccccc4)c4cccc(-c5ccccc5)c4)cc3)c3cccc4ccc(-c5ccc6cccnc6c5)cc34)ccc21 ; c1ccc(-c2cccc(N(c3ccccc3)c3ccc(-c4ccc(N(c5ccccc5)c5cccc6ccc(-c7ccc8cccnc8c7)cc56)cc4)cc3)c2)cc1]

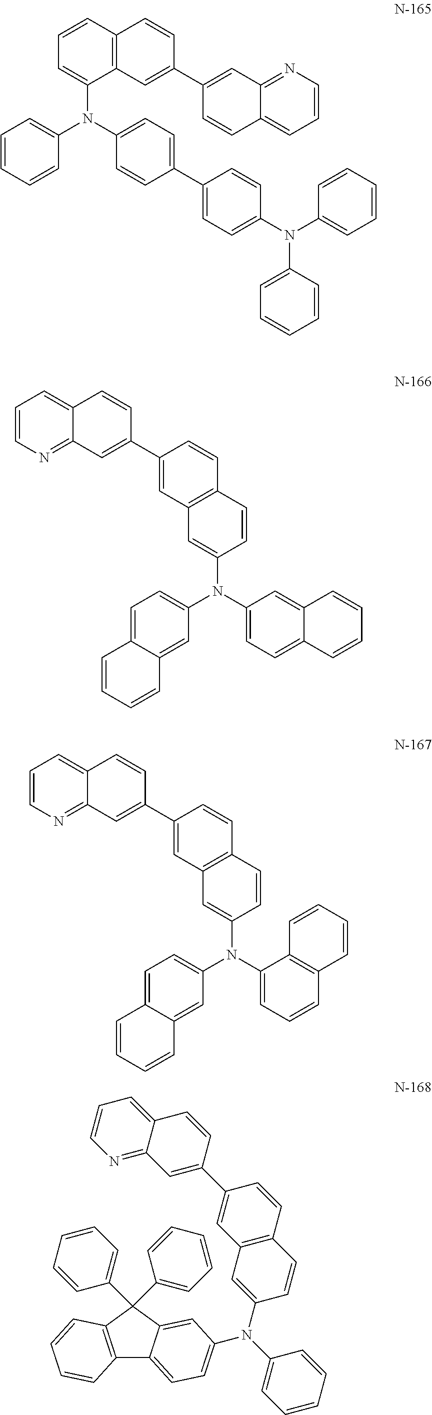

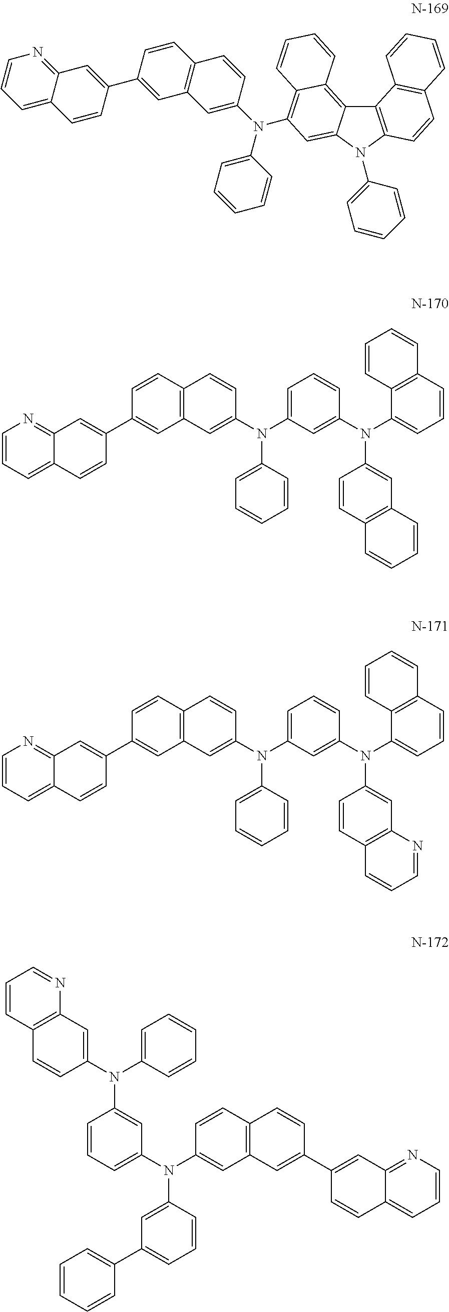 [SMILES: c1ccc(N(c2ccc3ccc(-c4ccc5cccnc5c4)cc3c2)c2cc3c(c4ccccc24)c2c4ccccc4ccc2n3-c2ccccc2)cc1 ; c1ccc(N(c2cccc(N(c3ccc4ccccc4c3)c3cccc4ccccc34)c2)c2ccc3ccc(-c4ccc5cccnc5c4)cc3c2)cc1 ; c1ccc(N(c2cccc(N(c3ccc4cccnc4c3)c3cccc4ccccc34)c2)c2ccc3ccc(-c4ccc5cccnc5c4)cc3c2)cc1 ; c1ccc(-c2cccc(N(c3cccc(N(c4ccccc4)c4ccc5cccnc5c4)c3)c3ccc4ccc(-c5ccc6cccnc6c5)cc4c3)c2)cc1]

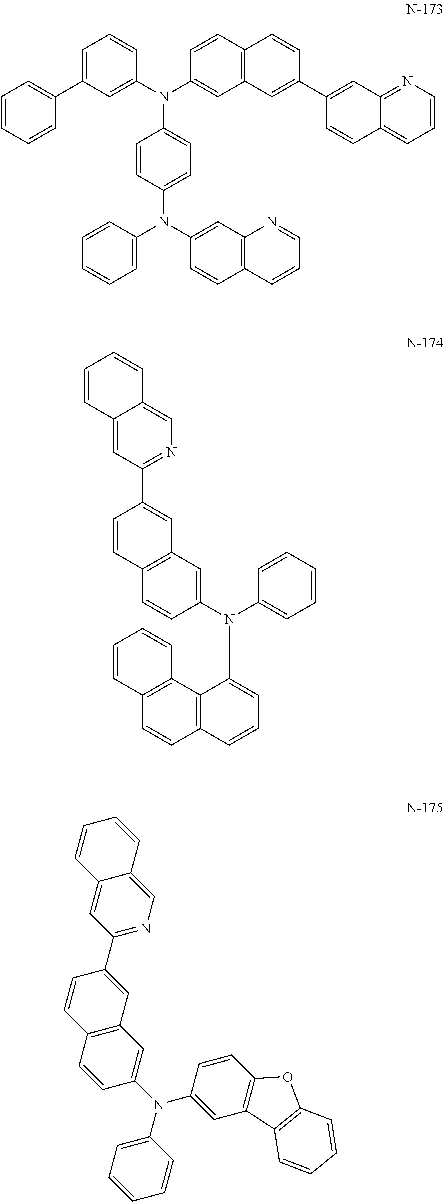 [SMILES: c1ccc(-c2cccc(N(c3ccc(N(c4ccccc4)c4ccc5cccnc5c4)cc3)c3ccc4ccc(-c5ccc6cccnc6c5)cc4c3)c2)cc1 ; c1ccc(N(c2ccc3ccc(-c4cc5ccccc5cn4)cc3c2)c2cccc3ccc4ccccc4c23)cc1 ; c1ccc(N(c2ccc3ccc(-c4cc5ccccc5cn4)cc3c2)c2ccc3oc4ccccc4c3c2)cc1]

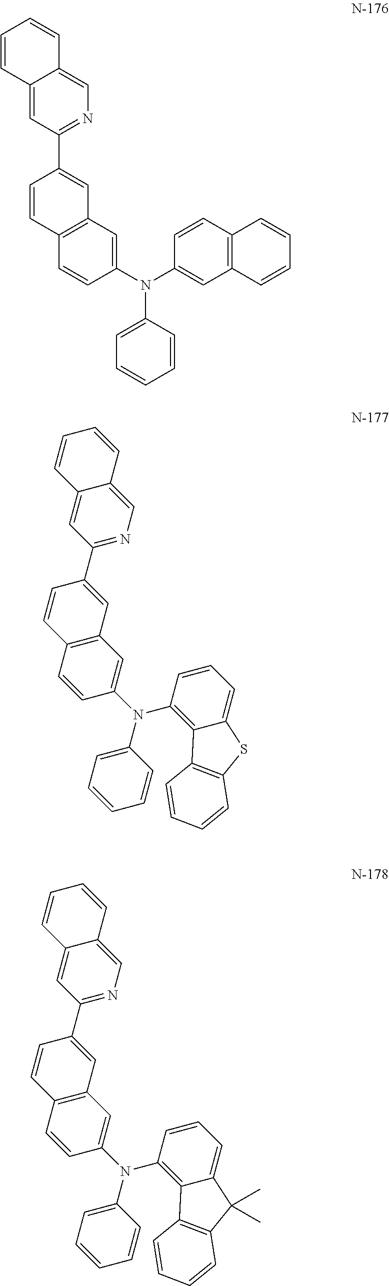 [SMILES: c1ccc(N(c2ccc3ccccc3c2)c2ccc3ccc(-c4cc5ccccc5cn4)cc3c2)cc1 ; c1ccc(N(c2ccc3ccc(-c4cc5ccccc5cn4)cc3c2)c2cccc3sc4ccccc4c23)cc1 ; CC1(C)c2ccccc2-c2c(N(c3ccccc3)c3ccc4ccc(-c5cc6ccccc6cn5)cc4c3)cccc21]

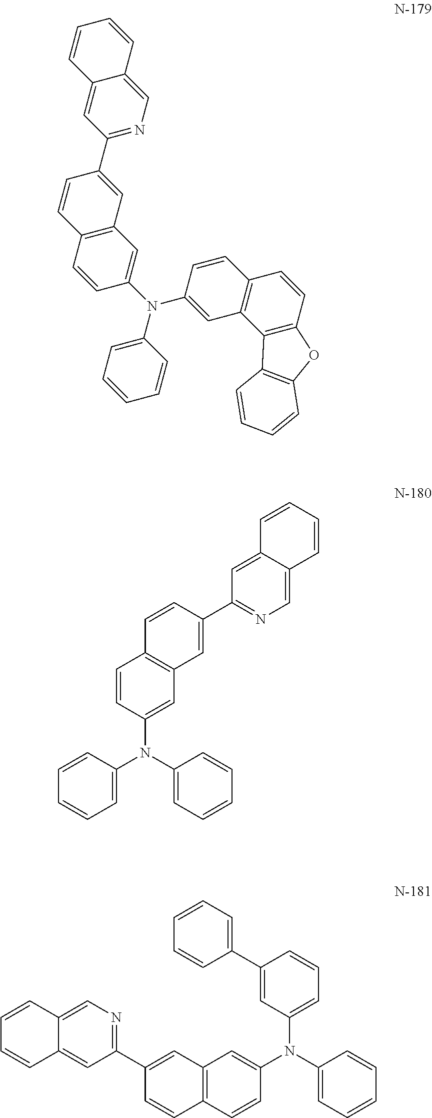 [SMILES: c1ccc(N(c2ccc3ccc(-c4cc5ccccc5cn4)cc3c2)c2ccc3ccc4oc5ccccc5c4c3c2)cc1 ; c1ccc(N(c2ccccc2)c2ccc3ccc(-c4cc5ccccc5cn4)cc3c2)cc1 ; c1ccc(-c2cccc(N(c3ccccc3)c3ccc4ccc(-c5cc6ccccc6cn5)cc4c3)c2)cc1]

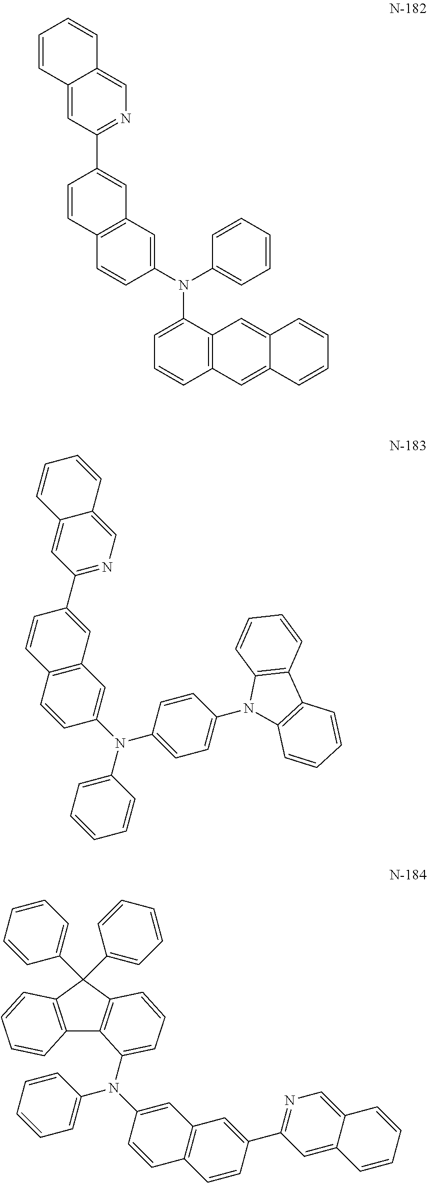 [SMILES: c1ccc(N(c2ccc3ccc(-c4cc5ccccc5cn4)cc3c2)c2cccc3cc4ccccc4cc23)cc1 ; c1ccc(N(c2ccc(-n3c4ccccc4c4ccccc43)cc2)c2ccc3ccc(-c4cc5ccccc5cn4)cc3c2)cc1 ; c1ccc(N(c2ccc3ccc(-c4cc5ccccc5cn4)cc3c2)c2cccc3c2-c2ccccc2C3(c2ccccc2)c2ccccc2)cc1]

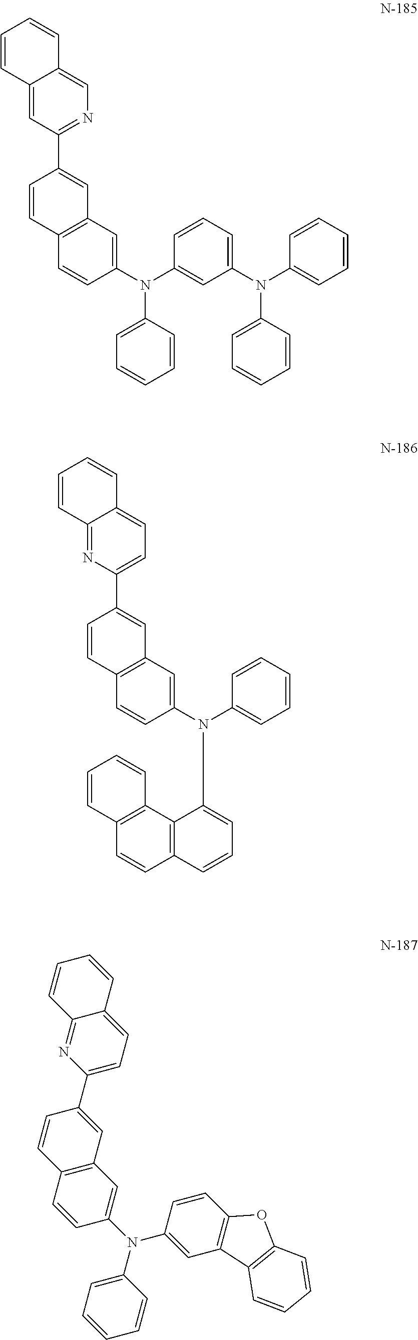 [SMILES: c1ccc(N(c2ccccc2)c2cccc(N(c3ccccc3)c3ccc4ccc(-c5cc6ccccc6cn5)cc4c3)c2)cc1 ; c1ccc(N(c2ccc3ccc(-c4ccc5ccccc5n4)cc3c2)c2cccc3ccc4ccccc4c23)cc1 ; c1ccc(N(c2ccc3ccc(-c4ccc5ccccc5n4)cc3c2)c2ccc3oc4ccccc4c3c2)cc1]

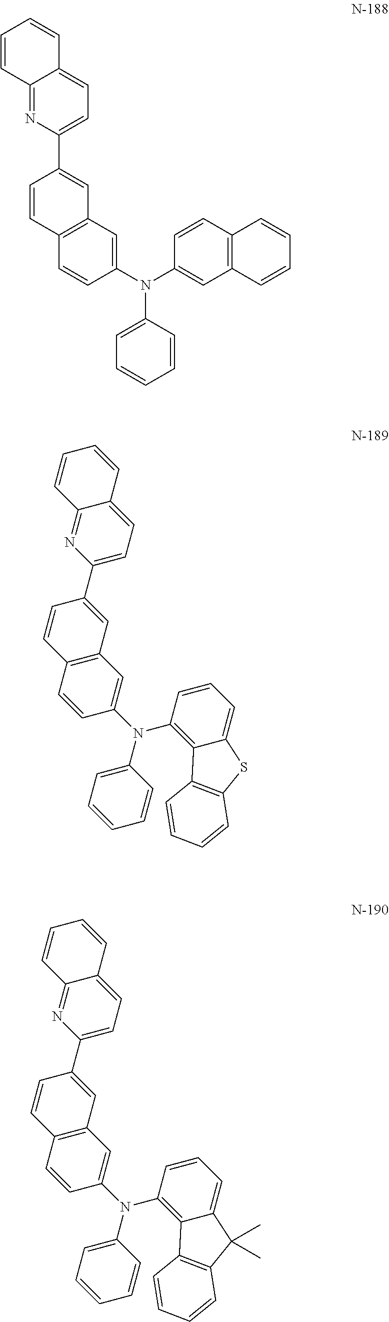 [SMILES: c1ccc(N(c2ccc3ccccc3c2)c2ccc3ccc(-c4ccc5ccccc5n4)cc3c2)cc1 ; c1ccc(N(c2ccc3ccc(-c4ccc5ccccc5n4)cc3c2)c2cccc3sc4ccccc4c23)cc1 ; CC1(C)c2ccccc2-c2c(N(c3ccccc3)c3ccc4ccc(-c5ccc6ccccc6n5)cc4c3)cccc21]

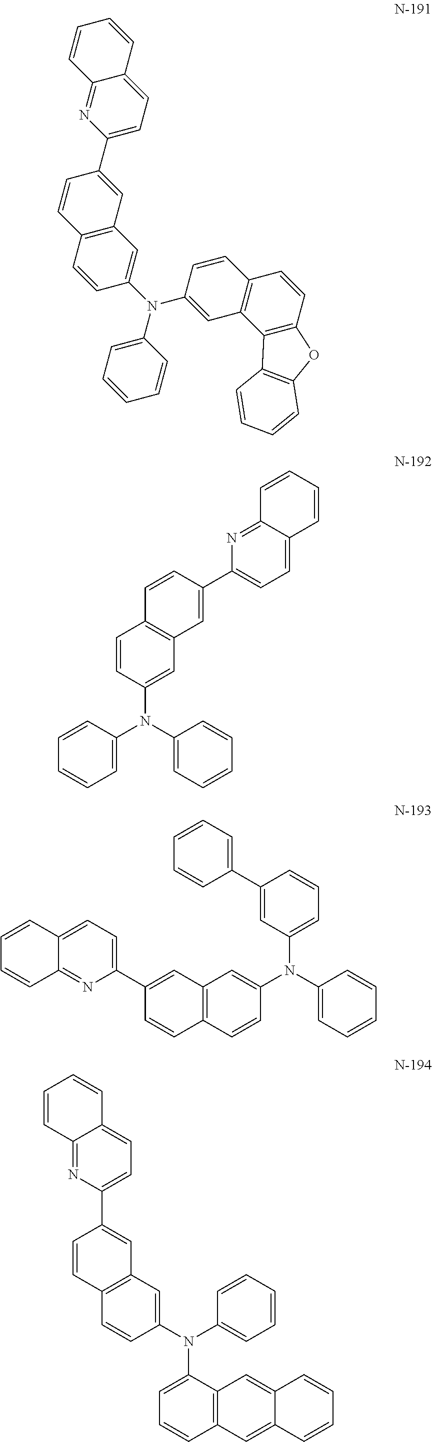

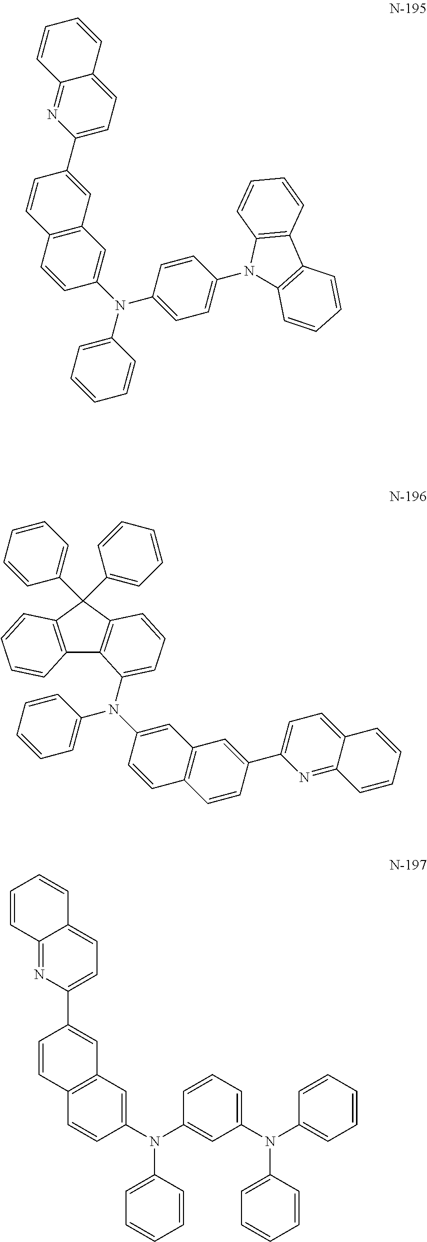 [SMILES: c1ccc(N(c2ccc(-n3c4ccccc4c4ccccc43)cc2)c2ccc3ccc(-c4ccc5ccccc5n4)cc3c2)cc1 ; c1ccc(N(c2ccc3ccc(-c4ccc5ccccc5n4)cc3c2)c2cccc3c2-c2ccccc2C3(c2ccccc2)c2ccccc2)cc1 ; c1ccc(N(c2ccccc2)c2cccc(N(c3ccccc3)c3ccc4ccc(-c5ccc6ccccc6n5)cc4c3)c2)cc1]

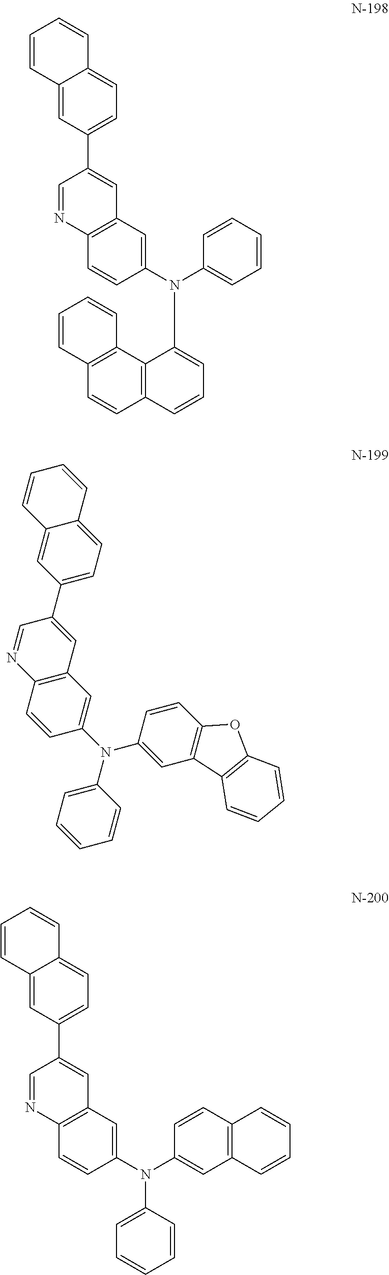 [SMILES: c1ccc(N(c2ccc3ncc(-c4ccc5ccccc5c4)cc3c2)c2cccc3ccc4ccccc4c23)cc1 ; c1ccc(N(c2ccc3ncc(-c4ccc5ccccc5c4)cc3c2)c2ccc3oc4ccccc4c3c2)cc1 ; c1ccc(N(c2ccc3ccccc3c2)c2ccc3ncc(-c4ccc5ccccc5c4)cc3c2)cc1]

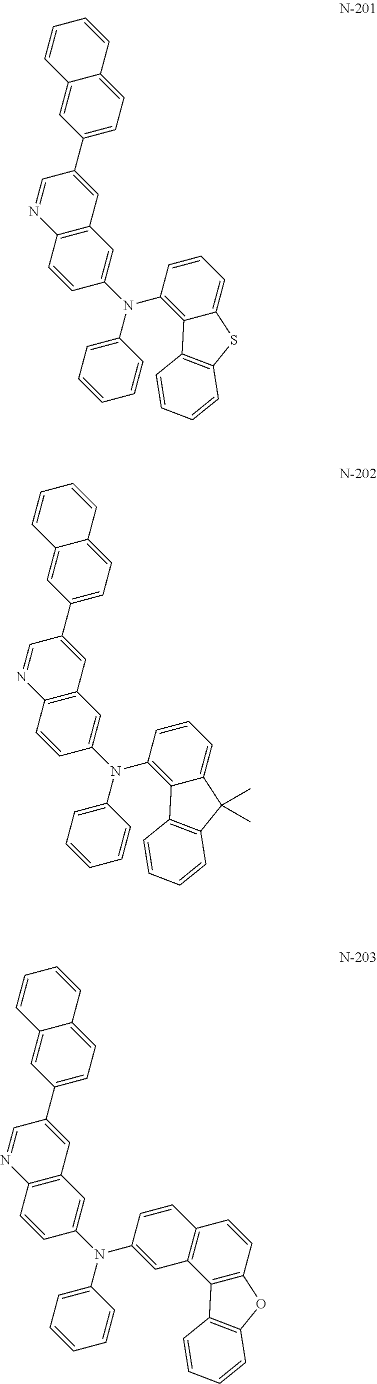 [SMILES: c1ccc(N(c2ccc3ncc(-c4ccc5ccccc5c4)cc3c2)c2cccc3sc4ccccc4c23)cc1 ; CC1(C)c2ccccc2-c2c(N(c3ccccc3)c3ccc4ncc(-c5ccc6ccccc6c5)cc4c3)cccc21 ; c1ccc(N(c2ccc3ncc(-c4ccc5ccccc5c4)cc3c2)c2ccc3ccc4oc5ccccc5c4c3c2)cc1]

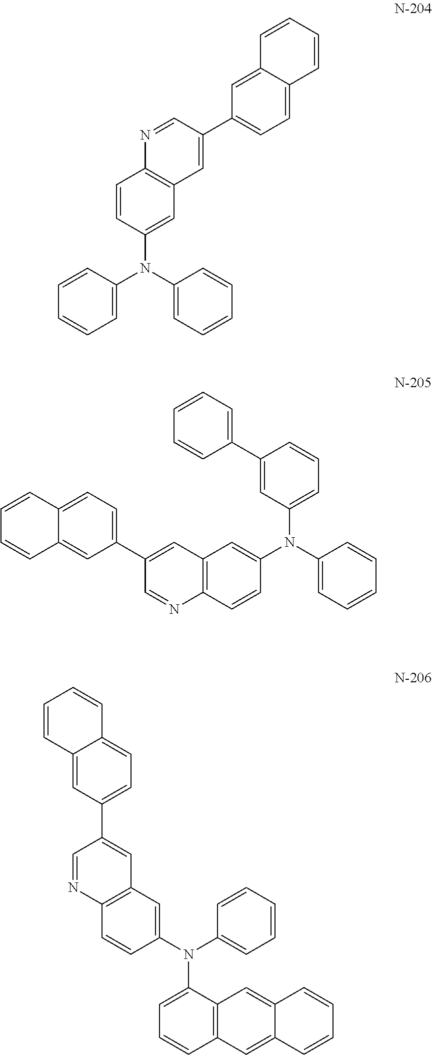 [SMILES: c1ccc(N(c2ccccc2)c2ccc3ncc(-c4ccc5ccccc5c4)cc3c2)cc1 ; c1ccc(-c2cccc(N(c3ccccc3)c3ccc4ncc(-c5ccc6ccccc6c5)cc4c3)c2)cc1 ; c1ccc(N(c2ccc3ncc(-c4ccc5ccccc5c4)cc3c2)c2cccc3cc4ccccc4cc23)cc1]

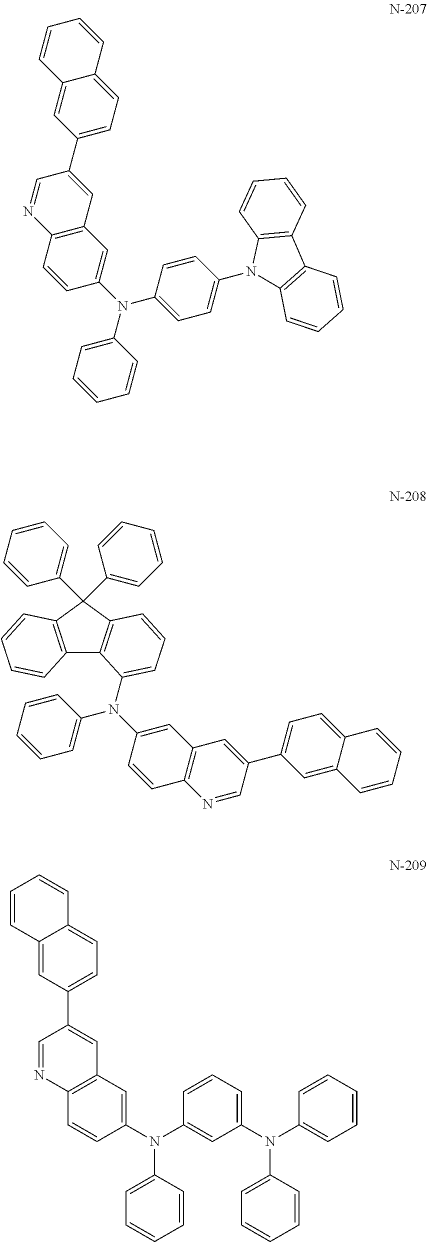 [SMILES: c1ccc(N(c2ccc(-n3c4ccccc4c4ccccc43)cc2)c2ccc3ncc(-c4ccc5ccccc5c4)cc3c2)cc1 ; c1ccc(N(c2ccc3ncc(-c4ccc5ccccc5c4)cc3c2)c2cccc3c2-c2ccccc2C3(c2ccccc2)c2ccccc2)cc1 ; c1ccc(N(c2ccccc2)c2cccc(N(c3ccccc3)c3ccc4ncc(-c5ccc6ccccc6c5)cc4c3)c2)cc1]

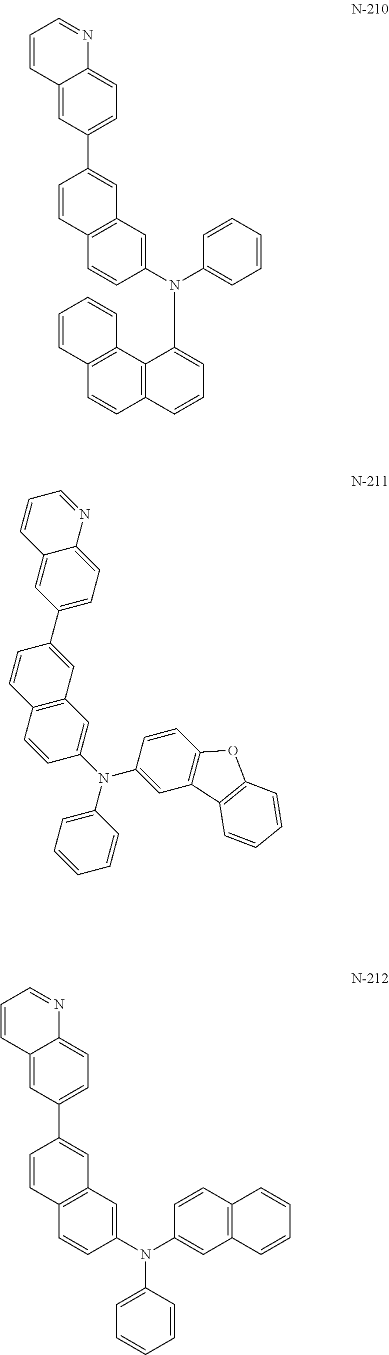 [SMILES: c1ccc(N(c2ccc3ccc(-c4ccc5ncccc5c4)cc3c2)c2cccc3ccc4ccccc4c23)cc1 ; c1ccc(N(c2ccc3ccc(-c4ccc5ncccc5c4)cc3c2)c2ccc3oc4ccccc4c3c2)cc1 ; c1ccc(N(c2ccc3ccccc3c2)c2ccc3ccc(-c4ccc5ncccc5c4)cc3c2)cc1]

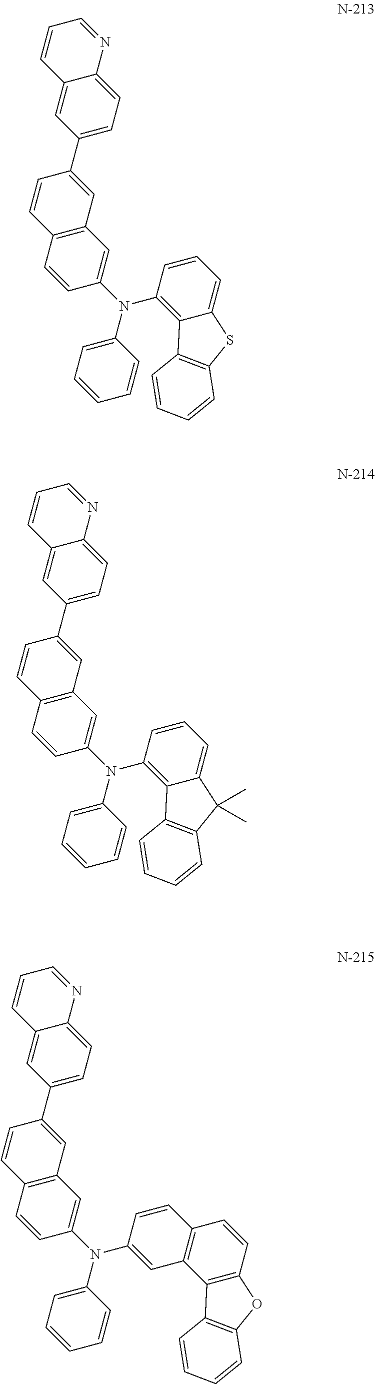 [SMILES: c1ccc(N(c2ccc3ccc(-c4ccc5ncccc5c4)cc3c2)c2cccc3sc4ccccc4c23)cc1 ; CC1(C)c2ccccc2-c2c(N(c3ccccc3)c3ccc4ccc(-c5ccc6ncccc6c5)cc4c3)cccc21 ; c1ccc(N(c2ccc3ccc(-c4ccc5ncccc5c4)cc3c2)c2ccc3ccc4oc5ccccc5c4c3c2)cc1]

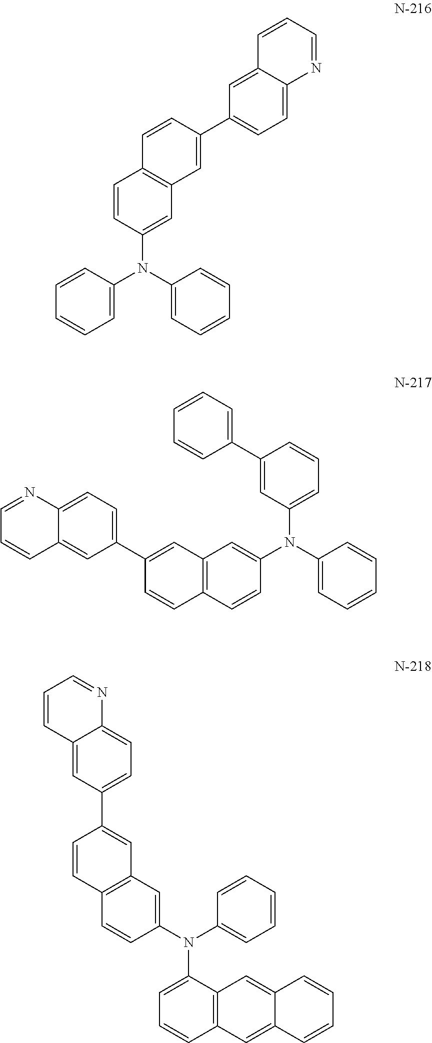 [SMILES: c1ccc(N(c2ccccc2)c2ccc3ccc(-c4ccc5ncccc5c4)cc3c2)cc1 ; c1ccc(-c2cccc(N(c3ccccc3)c3ccc4ccc(-c5ccc6ncccc6c5)cc4c3)c2)cc1 ; c1ccc(N(c2ccc3ccc(-c4ccc5ncccc5c4)cc3c2)c2cccc3cc4ccccc4cc23)cc1]

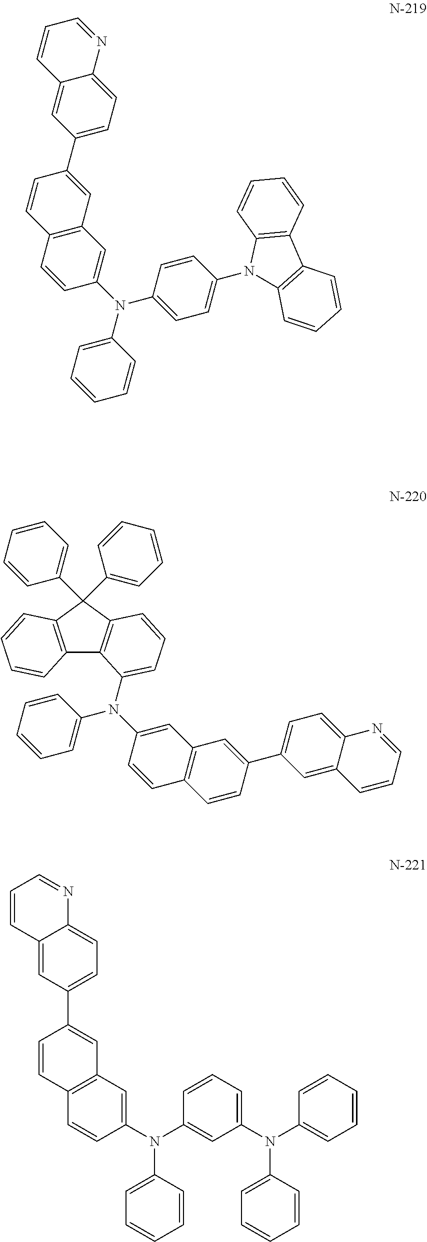 [SMILES: c1ccc(N(c2ccc(-n3c4ccccc4c4ccccc43)cc2)c2ccc3ccc(-c4ccc5ncccc5c4)cc3c2)cc1 ; c1ccc(N(c2ccc3ccc(-c4ccc5ncccc5c4)cc3c2)c2cccc3c2-c2ccccc2C3(c2ccccc2)c2ccccc2)cc1 ; c1ccc(N(c2ccccc2)c2cccc(N(c3ccccc3)c3ccc4ccc(-c5ccc6ncccc6c5)cc4c3)c2)cc1]

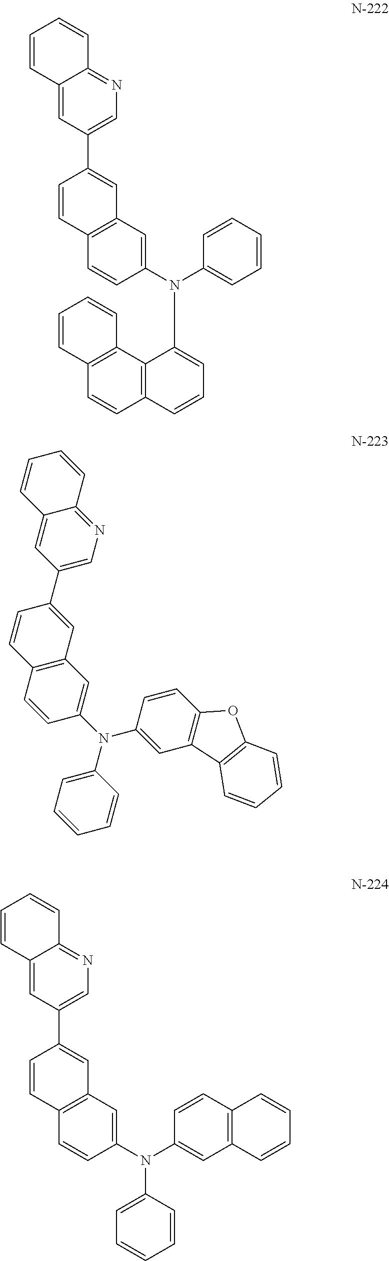 [SMILES: c1ccc(N(c2ccc3ccc(-c4cnc5ccccc5c4)cc3c2)c2cccc3ccc4ccccc4c23)cc1 ; c1ccc(N(c2ccc3ccc(-c4cnc5ccccc5c4)cc3c2)c2ccc3oc4ccccc4c3c2)cc1 ; c1ccc(N(c2ccc3ccccc3c2)c2ccc3ccc(-c4cnc5ccccc5c4)cc3c2)cc1]

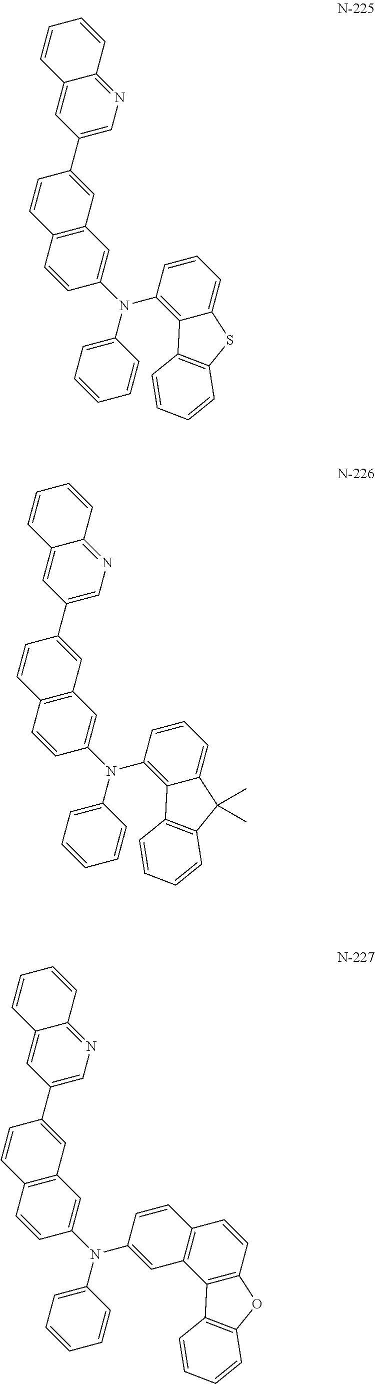 [SMILES: c1ccc(N(c2ccc3ccc(-c4cnc5ccccc5c4)cc3c2)c2cccc3sc4ccccc4c23)cc1 ; CC1(C)c2ccccc2-c2c(N(c3ccccc3)c3ccc4ccc(-c5cnc6ccccc6c5)cc4c3)cccc21 ; c1ccc(N(c2ccc3ccc(-c4cnc5ccccc5c4)cc3c2)c2ccc3ccc4oc5ccccc5c4c3c2)cc1]

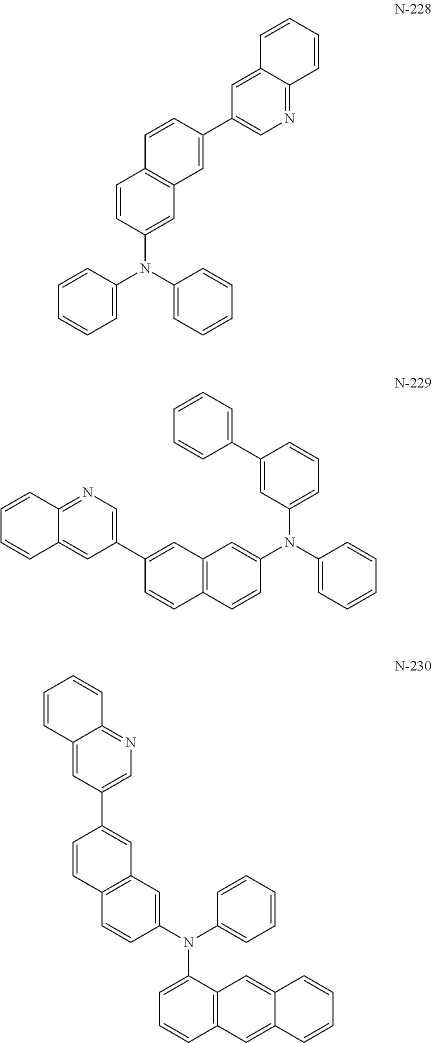 [SMILES: c1ccc(N(c2ccccc2)c2ccc3ccc(-c4cnc5ccccc5c4)cc3c2)cc1 ; c1ccc(-c2cccc(N(c3ccccc3)c3ccc4ccc(-c5cnc6ccccc6c5)cc4c3)c2)cc1 ; c1ccc(N(c2ccc3ccc(-c4cnc5ccccc5c4)cc3c2)c2cccc3cc4ccccc4cc23)cc1]

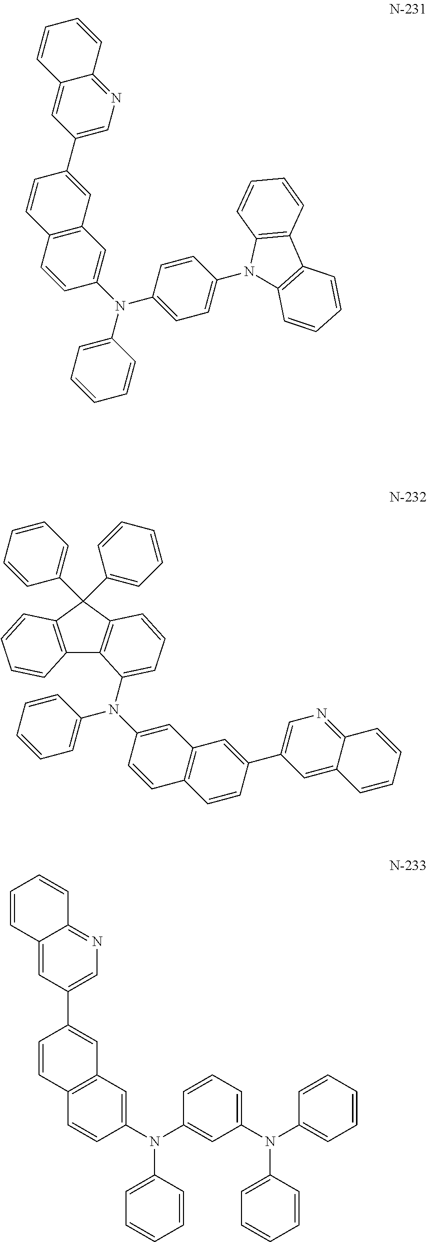 [SMILES: c1ccc(N(c2ccc(-n3c4ccccc4c4ccccc43)cc2)c2ccc3ccc(-c4cnc5ccccc5c4)cc3c2)cc1 ; c1ccc(N(c2ccc3ccc(-c4cnc5ccccc5c4)cc3c2)c2cccc3c2-c2ccccc2C3(c2ccccc2)c2ccccc2)cc1 ; c1ccc(N(c2ccccc2)c2cccc(N(c3ccccc3)c3ccc4ccc(-c5cnc6ccccc6c5)cc4c3)c2)cc1]

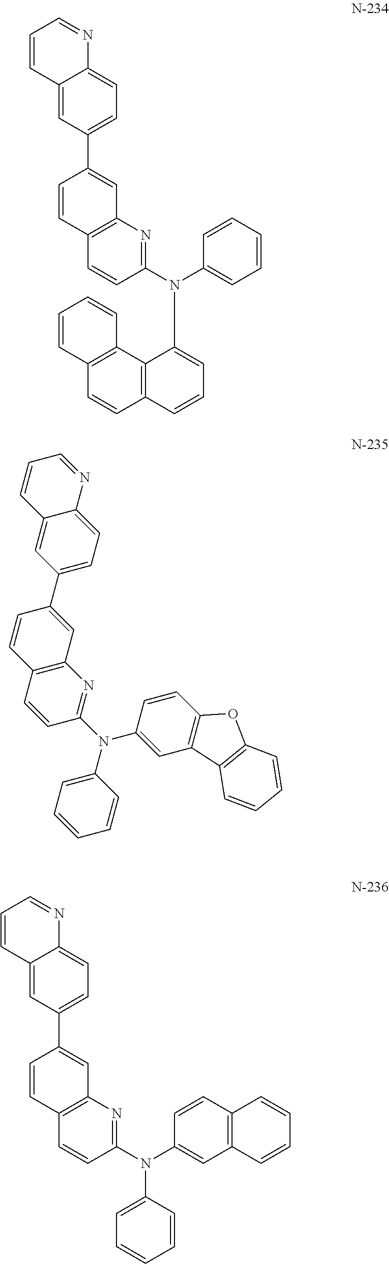 [SMILES: c1ccc(N(c2ccc3ccc(-c4ccc5ncccc5c4)cc3n2)c2cccc3ccc4ccccc4c23)cc1 ; c1ccc(N(c2ccc3oc4ccccc4c3c2)c2ccc3ccc(-c4ccc5ncccc5c4)cc3n2)cc1 ; c1ccc(N(c2ccc3ccccc3c2)c2ccc3ccc(-c4ccc5ncccc5c4)cc3n2)cc1]

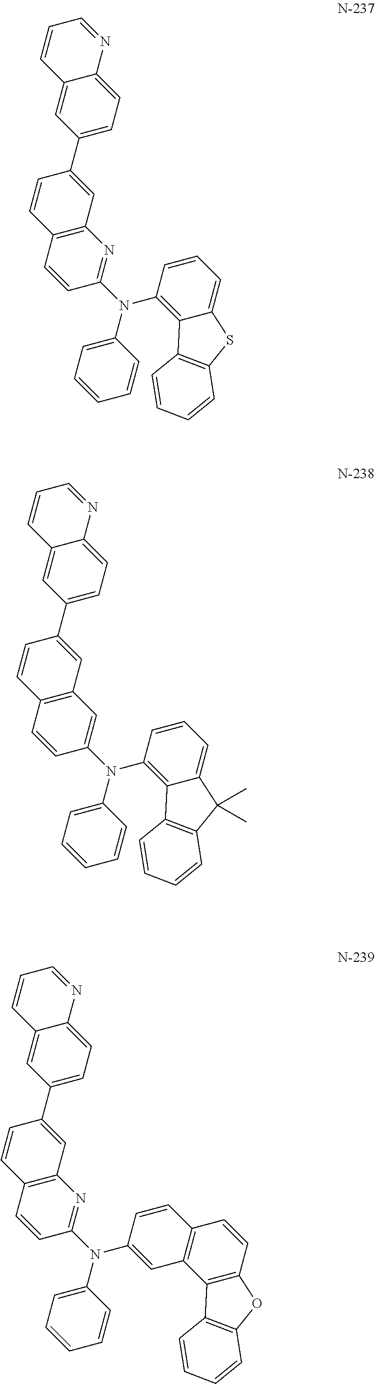 [SMILES: c1ccc(N(c2ccc3ccc(-c4ccc5ncccc5c4)cc3n2)c2cccc3sc4ccccc4c23)cc1 ; CC1(C)c2ccccc2-c2c(N(c3ccccc3)c3ccc4ccc(-c5ccc6ncccc6c5)cc4c3)cccc21 ; c1ccc(N(c2ccc3ccc4oc5ccccc5c4c3c2)c2ccc3ccc(-c4ccc5ncccc5c4)cc3n2)cc1]

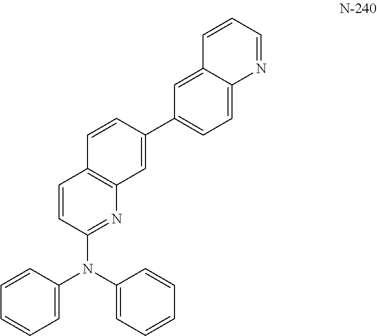 [SMILES: c1ccc(N(c2ccccc2)c2ccc3ccc(-c4ccc5ncccc5c4)cc3n2)cc1]

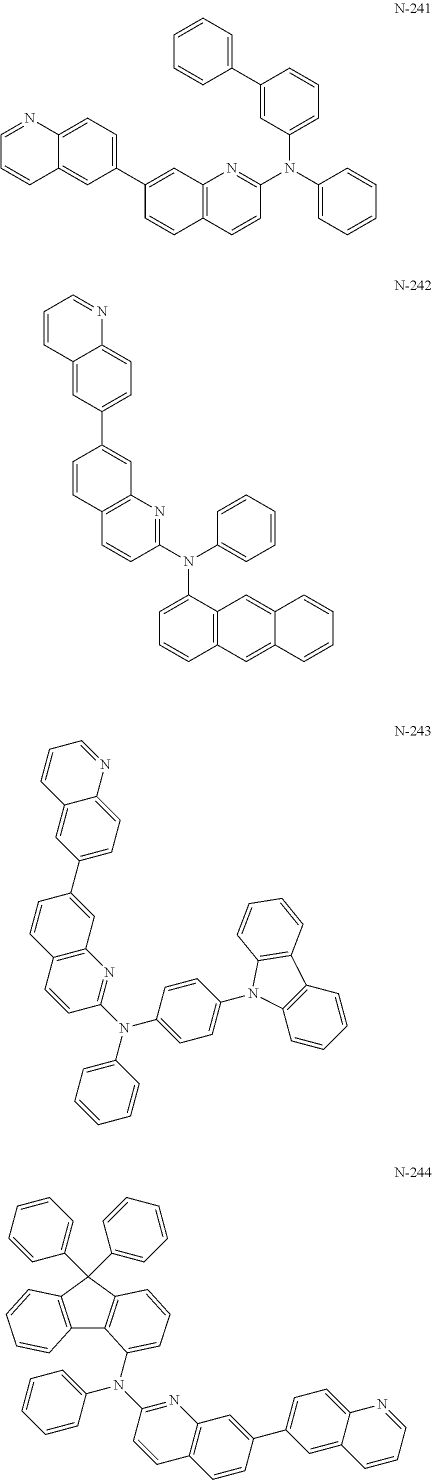 [SMILES: c1ccc(-c2cccc(N(c3ccccc3)c3ccc4ccc(-c5ccc6ncccc6c5)cc4n3)c2)cc1 ; c1ccc(N(c2ccc3ccc(-c4ccc5ncccc5c4)cc3n2)c2cccc3cc4ccccc4cc23)cc1 ; c1ccc(N(c2ccc(-n3c4ccccc4c4ccccc43)cc2)c2ccc3ccc(-c4ccc5ncccc5c4)cc3n2)cc1 ; c1ccc(N(c2ccc3ccc(-c4ccc5ncccc5c4)cc3n2)c2cccc3c2-c2ccccc2C3(c2ccccc2)c2ccccc2)cc1]

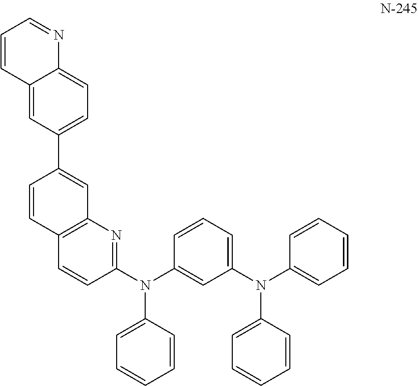 [SMILES: c1ccc(N(c2ccccc2)c2cccc(N(c3ccccc3)c3ccc4ccc(-c5ccc6ncccc6c5)cc4n3)c2)cc1]

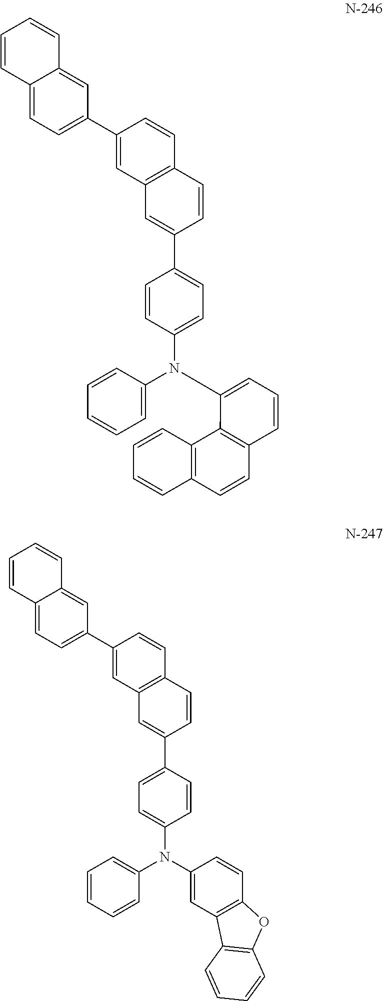 [SMILES: c1ccc(N(c2ccc(-c3ccc4ccc(-c5ccc6ccccc6c5)cc4c3)cc2)c2cccc3ccc4ccccc4c23)cc1 ; c1ccc(N(c2ccc(-c3ccc4ccc(-c5ccc6ccccc6c5)cc4c3)cc2)c2ccc3oc4ccccc4c3c2)cc1]

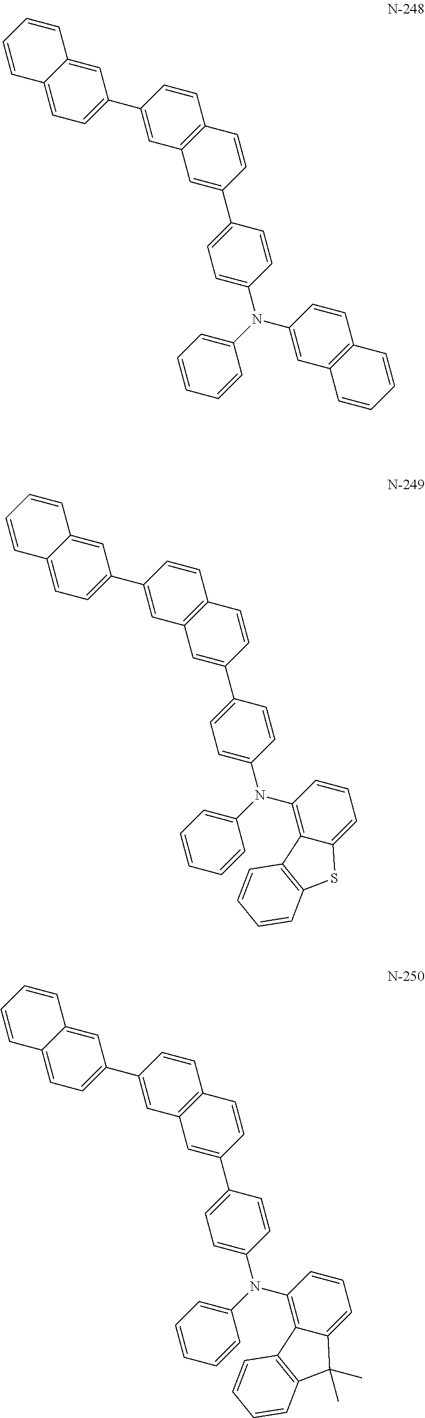 [SMILES: c1ccc(N(c2ccc(-c3ccc4ccc(-c5ccc6ccccc6c5)cc4c3)cc2)c2ccc3ccccc3c2)cc1 ; c1ccc(N(c2ccc(-c3ccc4ccc(-c5ccc6ccccc6c5)cc4c3)cc2)c2cccc3sc4ccccc4c23)cc1 ; CC1(C)c2ccccc2-c2c(N(c3ccccc3)c3ccc(-c4ccc5ccc(-c6ccc7ccccc7c6)cc5c4)cc3)cccc21]

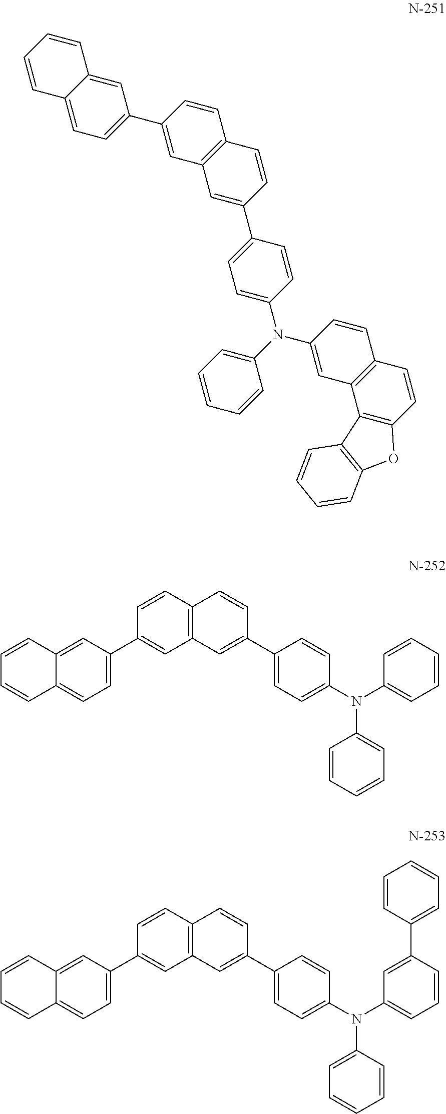 [SMILES: c1ccc(N(c2ccc(-c3ccc4ccc(-c5ccc6ccccc6c5)cc4c3)cc2)c2ccc3ccc4oc5ccccc5c4c3c2)cc1 ; c1ccc(N(c2ccccc2)c2ccc(-c3ccc4ccc(-c5ccc6ccccc6c5)cc4c3)cc2)cc1 ; c1ccc(-c2cccc(N(c3ccccc3)c3ccc(-c4ccc5ccc(-c6ccc7ccccc7c6)cc5c4)cc3)c2)cc1]

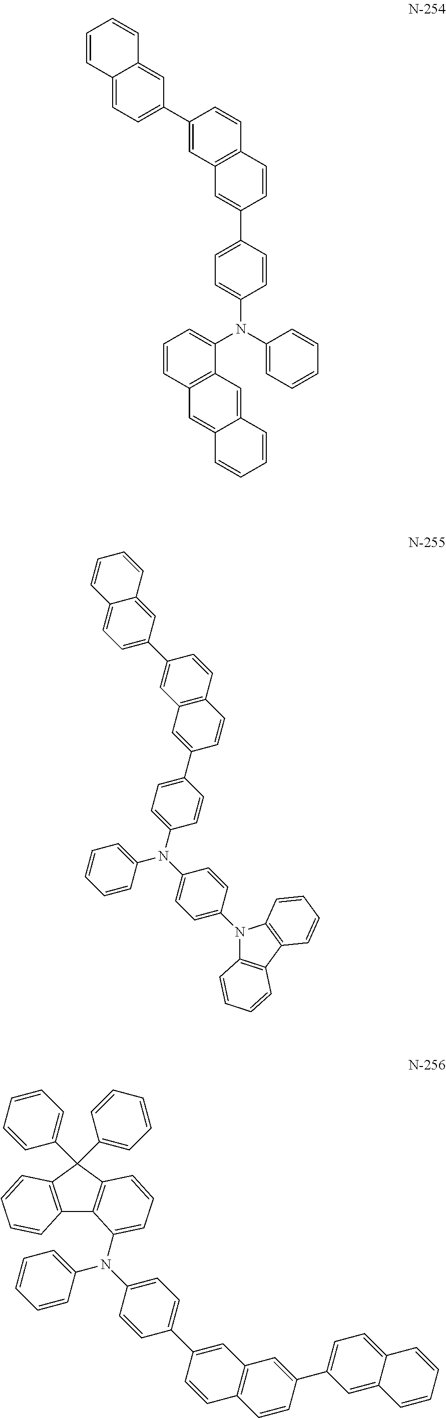 [SMILES: c1ccc(N(c2ccc(-c3ccc4ccc(-c5ccc6ccccc6c5)cc4c3)cc2)c2cccc3cc4ccccc4cc23)cc1 ; c1ccc(N(c2ccc(-c3ccc4ccc(-c5ccc6ccccc6c5)cc4c3)cc2)c2ccc(-n3c4ccccc4c4ccccc43)cc2)cc1 ; c1ccc(N(c2ccc(-c3ccc4ccc(-c5ccc6ccccc6c5)cc4c3)cc2)c2cccc3c2-c2ccccc2C3(c2ccccc2)c2ccccc2)cc1]

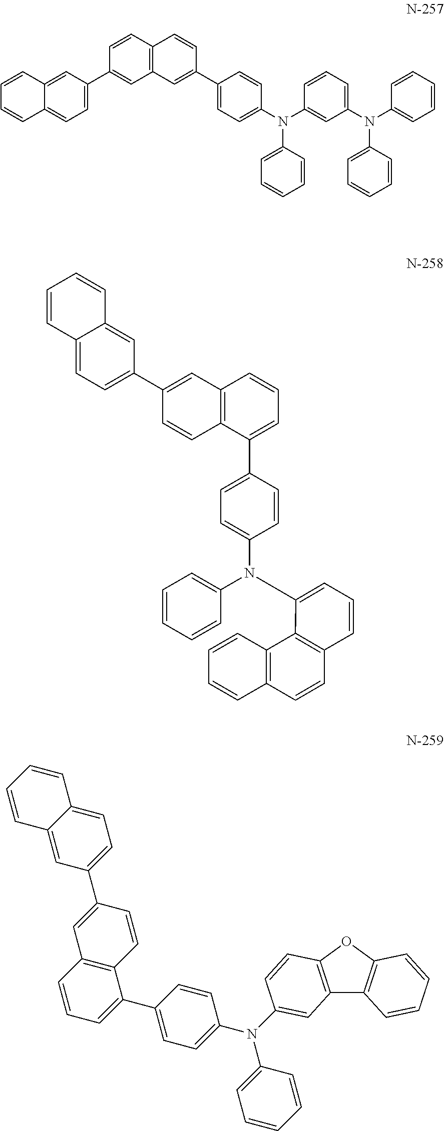 [SMILES: c1ccc(N(c2ccccc2)c2cccc(N(c3ccccc3)c3ccc(-c4ccc5ccc(-c6ccc7ccccc7c6)cc5c4)cc3)c2)cc1 ; c1ccc(N(c2ccc(-c3cccc4cc(-c5ccc6ccccc6c5)ccc34)cc2)c2cccc3ccc4ccccc4c23)cc1 ; c1ccc(N(c2ccc(-c3cccc4cc(-c5ccc6ccccc6c5)ccc34)cc2)c2ccc3oc4ccccc4c3c2)cc1]

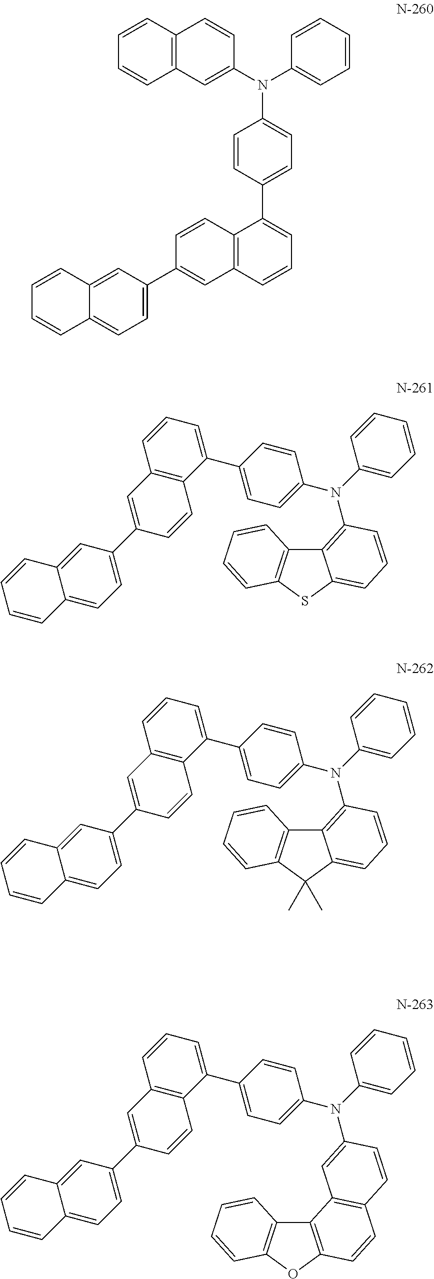 [SMILES: c1ccc(N(c2ccc(-c3cccc4cc(-c5ccc6ccccc6c5)ccc34)cc2)c2ccc3ccccc3c2)cc1 ; c1ccc(N(c2ccc(-c3cccc4cc(-c5ccc6ccccc6c5)ccc34)cc2)c2cccc3sc4ccccc4c23)cc1 ; CC1(C)c2ccccc2-c2c(N(c3ccccc3)c3ccc(-c4cccc5cc(-c6ccc7ccccc7c6)ccc45)cc3)cccc21 ; c1ccc(N(c2ccc(-c3cccc4cc(-c5ccc6ccccc6c5)ccc34)cc2)c2ccc3ccc4oc5ccccc5c4c3c2)cc1]

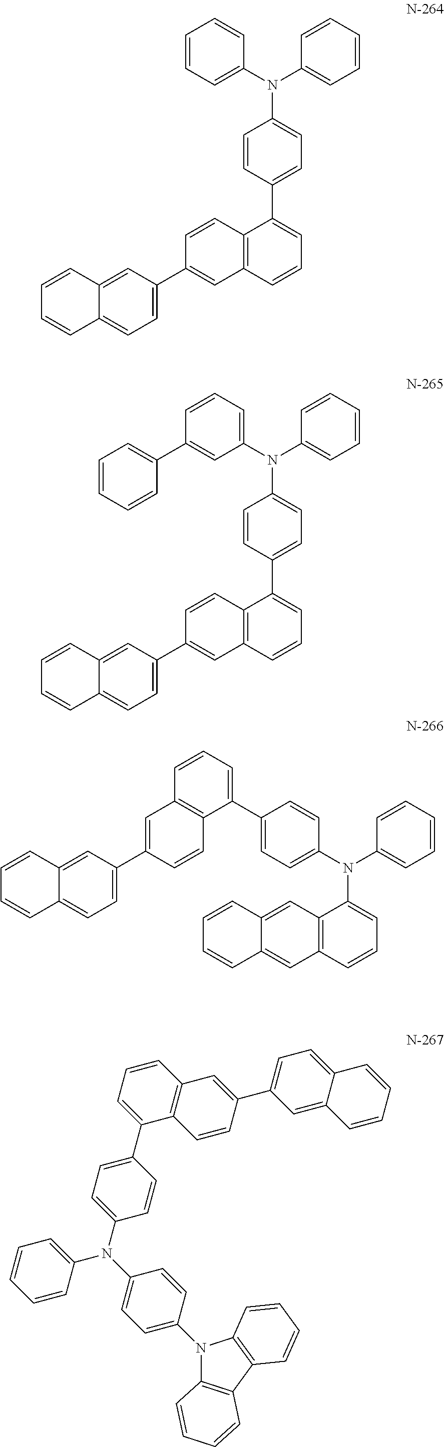 [SMILES: c1ccc(N(c2ccccc2)c2ccc(-c3cccc4cc(-c5ccc6ccccc6c5)ccc34)cc2)cc1 ; c1ccc(-c2cccc(N(c3ccccc3)c3ccc(-c4cccc5cc(-c6ccc7ccccc7c6)ccc45)cc3)c2)cc1 ; c1ccc(N(c2ccc(-c3cccc4cc(-c5ccc6ccccc6c5)ccc34)cc2)c2cccc3cc4ccccc4cc23)cc1 ; c1ccc(N(c2ccc(-c3cccc4cc(-c5ccc6ccccc6c5)ccc34)cc2)c2ccc(-n3c4ccccc4c4ccccc43)cc2)cc1]

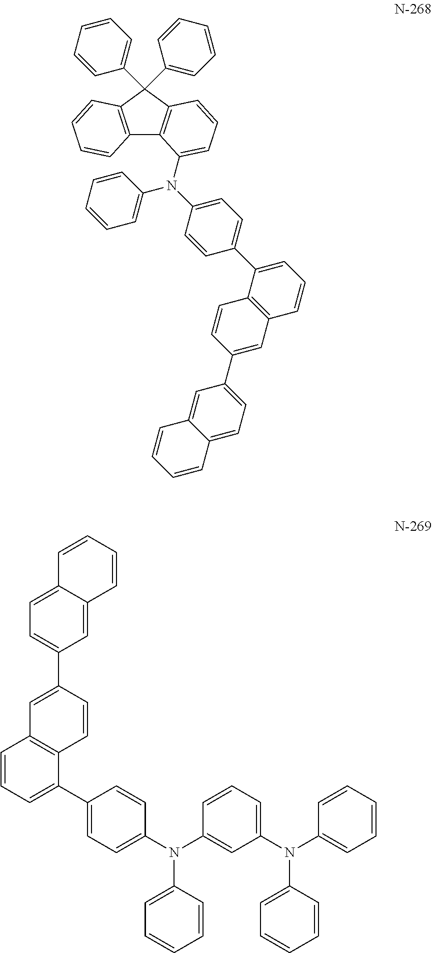 [SMILES: c1ccc(N(c2ccc(-c3cccc4cc(-c5ccc6ccccc6c5)ccc34)cc2)c2cccc3c2-c2ccccc2C3(c2ccccc2)c2ccccc2)cc1 ; c1ccc(N(c2ccccc2)c2cccc(N(c3ccccc3)c3ccc(-c4cccc5cc(-c6ccc7ccccc7c6)ccc45)cc3)c2)cc1]

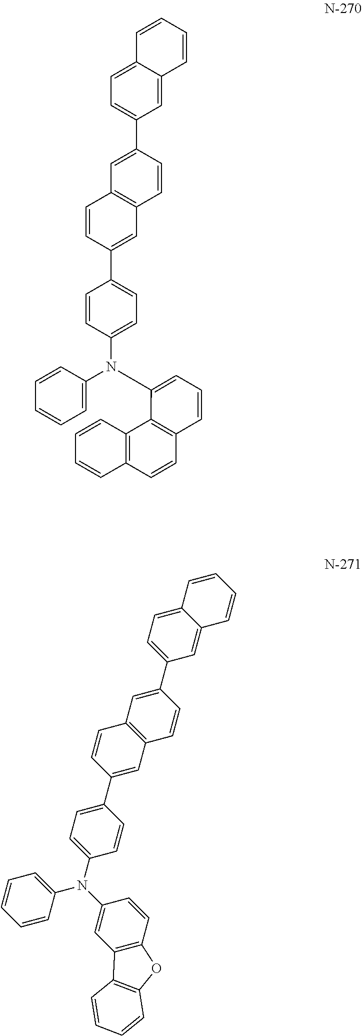 [SMILES: c1ccc(N(c2ccc(-c3ccc4cc(-c5ccc6ccccc6c5)ccc4c3)cc2)c2cccc3ccc4ccccc4c23)cc1 ; c1ccc(N(c2ccc(-c3ccc4cc(-c5ccc6ccccc6c5)ccc4c3)cc2)c2ccc3oc4ccccc4c3c2)cc1]

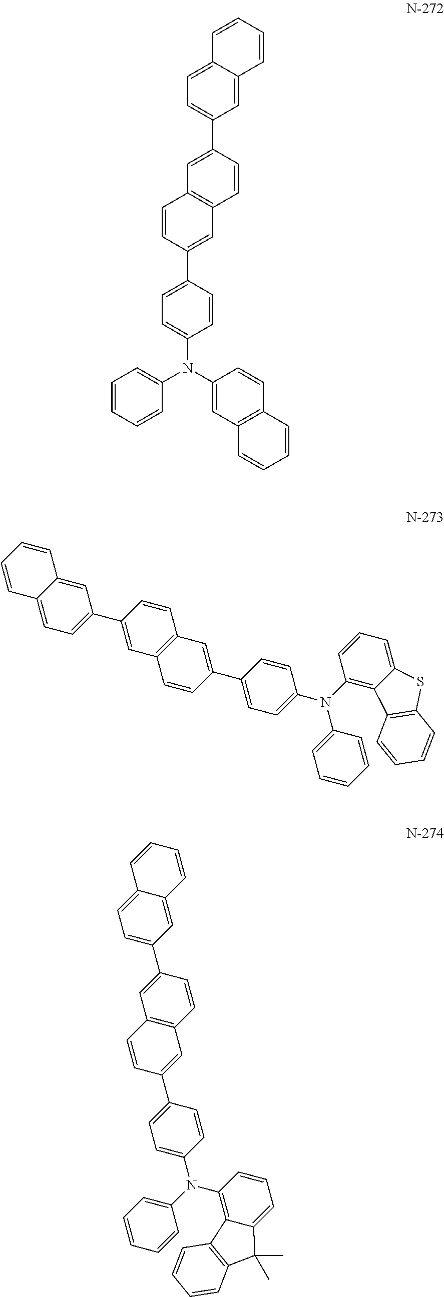 [SMILES: c1ccc(N(c2ccc(-c3ccc4cc(-c5ccc6ccccc6c5)ccc4c3)cc2)c2ccc3ccccc3c2)cc1 ; c1ccc(N(c2ccc(-c3ccc4cc(-c5ccc6ccccc6c5)ccc4c3)cc2)c2cccc3sc4ccccc4c23)cc1 ; CC1(C)c2ccccc2-c2c(N(c3ccccc3)c3ccc(-c4ccc5cc(-c6ccc7ccccc7c6)ccc5c4)cc3)cccc21]

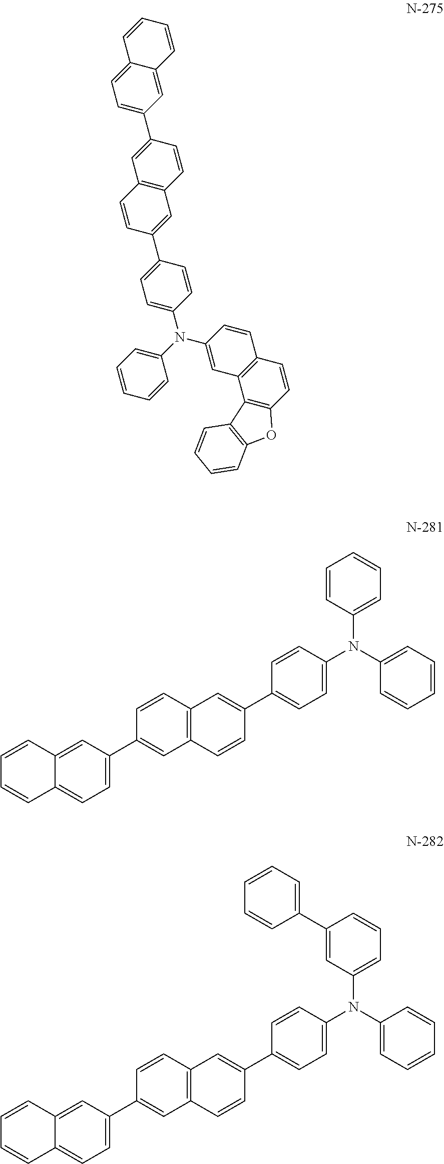 [SMILES: c1ccc(N(c2ccc(-c3ccc4cc(-c5ccc6ccccc6c5)ccc4c3)cc2)c2ccc3ccc4oc5ccccc5c4c3c2)cc1 ; c1ccc(N(c2ccccc2)c2ccc(-c3ccc4cc(-c5ccc6ccccc6c5)ccc4c3)cc2)cc1 ; c1ccc(-c2cccc(N(c3ccccc3)c3ccc(-c4ccc5cc(-c6ccc7ccccc7c6)ccc5c4)cc3)c2)cc1]

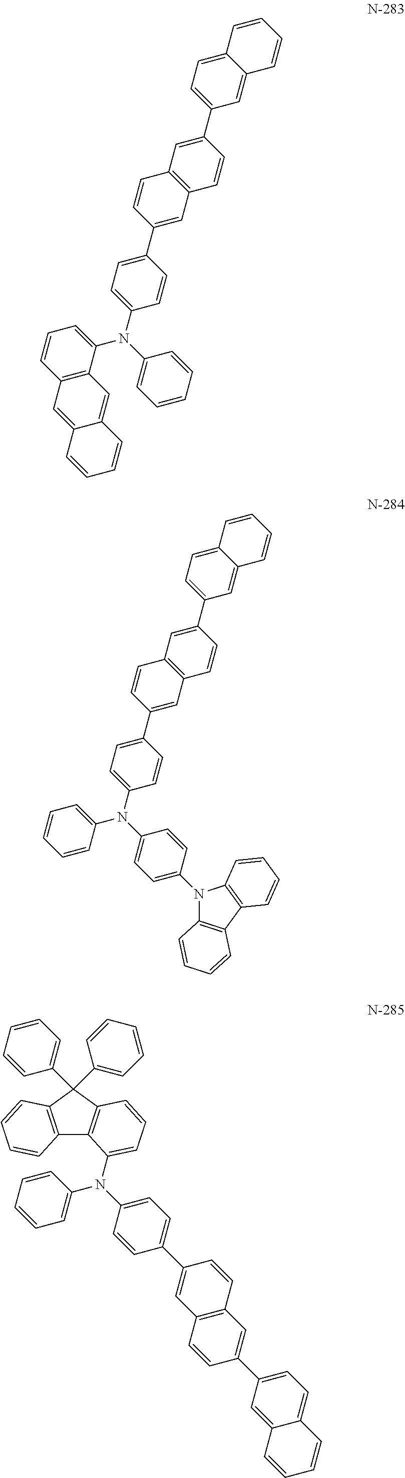 [SMILES: c1ccc(N(c2ccc(-c3ccc4cc(-c5ccc6ccccc6c5)ccc4c3)cc2)c2cccc3cc4ccccc4cc23)cc1 ; c1ccc(N(c2ccc(-c3ccc4cc(-c5ccc6ccccc6c5)ccc4c3)cc2)c2ccc(-n3c4ccccc4c4ccccc43)cc2)cc1 ; c1ccc(N(c2ccc(-c3ccc4cc(-c5ccc6ccccc6c5)ccc4c3)cc2)c2cccc3c2-c2ccccc2C3(c2ccccc2)c2ccccc2)cc1]

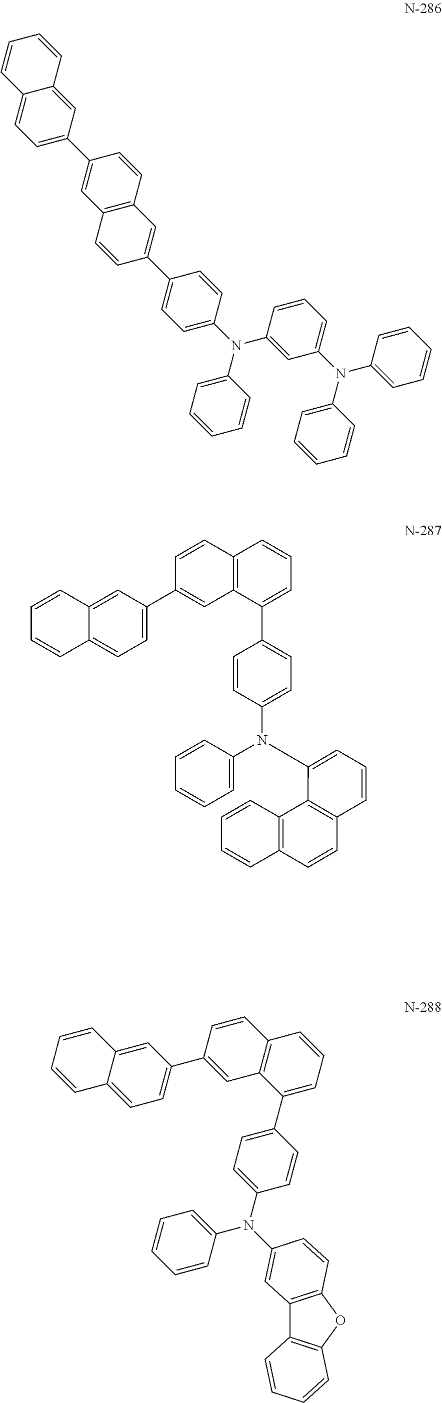 [SMILES: c1ccc(N(c2ccccc2)c2cccc(N(c3ccccc3)c3ccc(-c4ccc5cc(-c6ccc7ccccc7c6)ccc5c4)cc3)c2)cc1 ; c1ccc(N(c2ccc(-c3cccc4ccc(-c5ccc6ccccc6c5)cc34)cc2)c2cccc3ccc4ccccc4c23)cc1 ; c1ccc(N(c2ccc(-c3cccc4ccc(-c5ccc6ccccc6c5)cc34)cc2)c2ccc3oc4ccccc4c3c2)cc1]

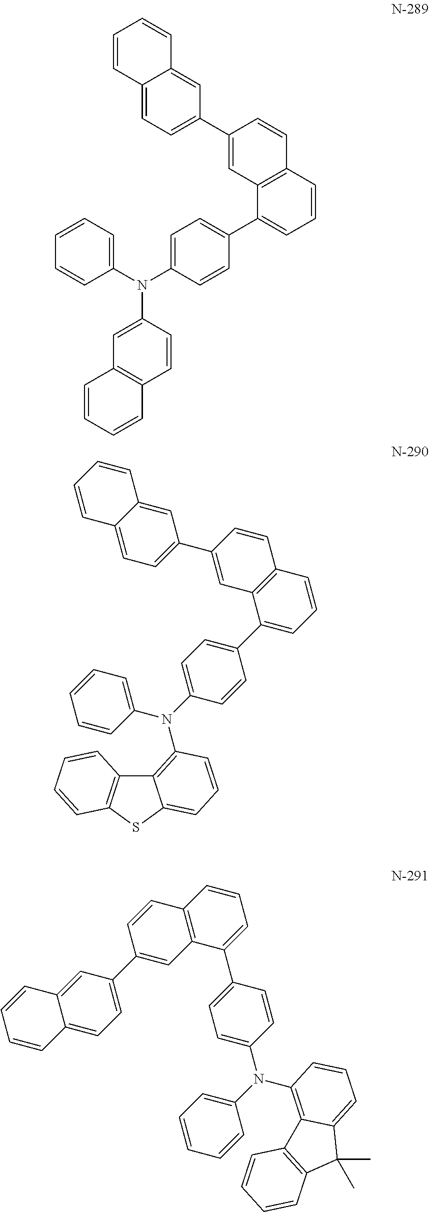

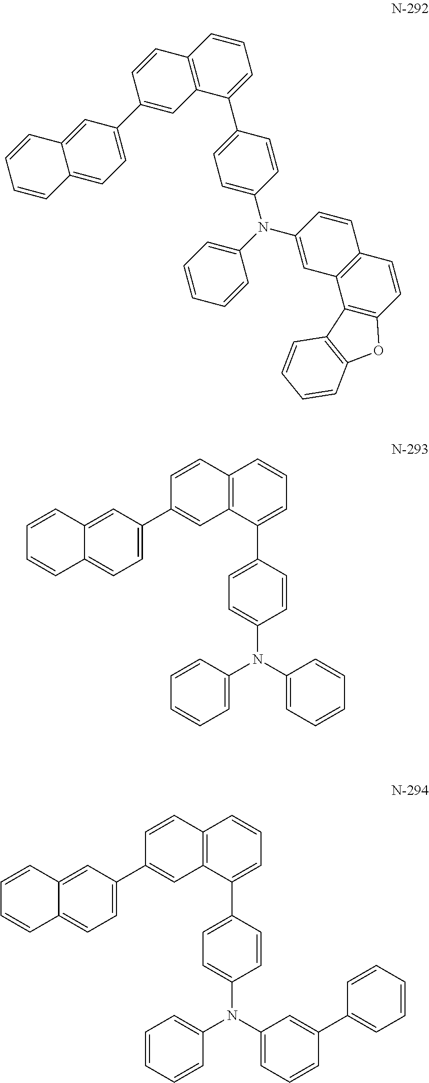 [SMILES: c1ccc(N(c2ccc(-c3cccc4ccc(-c5ccc6ccccc6c5)cc34)cc2)c2ccc3ccc4oc5ccccc5c4c3c2)cc1 ; c1ccc(N(c2ccccc2)c2ccc(-c3cccc4ccc(-c5ccc6ccccc6c5)cc34)cc2)cc1 ; c1ccc(-c2cccc(N(c3ccccc3)c3ccc(-c4cccc5ccc(-c6ccc7ccccc7c6)cc45)cc3)c2)cc1]

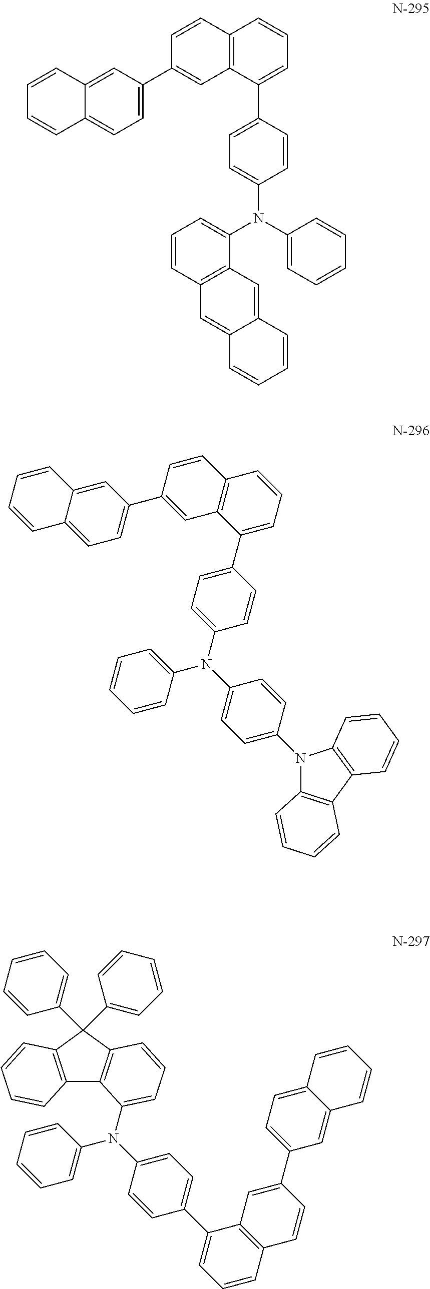 [SMILES: c1ccc(N(c2ccc(-c3cccc4ccc(-c5ccc6ccccc6c5)cc34)cc2)c2cccc3cc4ccccc4cc23)cc1 ; c1ccc(N(c2ccc(-c3cccc4ccc(-c5ccc6ccccc6c5)cc34)cc2)c2ccc(-n3c4ccccc4c4ccccc43)cc2)cc1 ; c1ccc(N(c2ccc(-c3cccc4ccc(-c5ccc6ccccc6c5)cc34)cc2)c2cccc3c2-c2ccccc2C3(c2ccccc2)c2ccccc2)cc1]

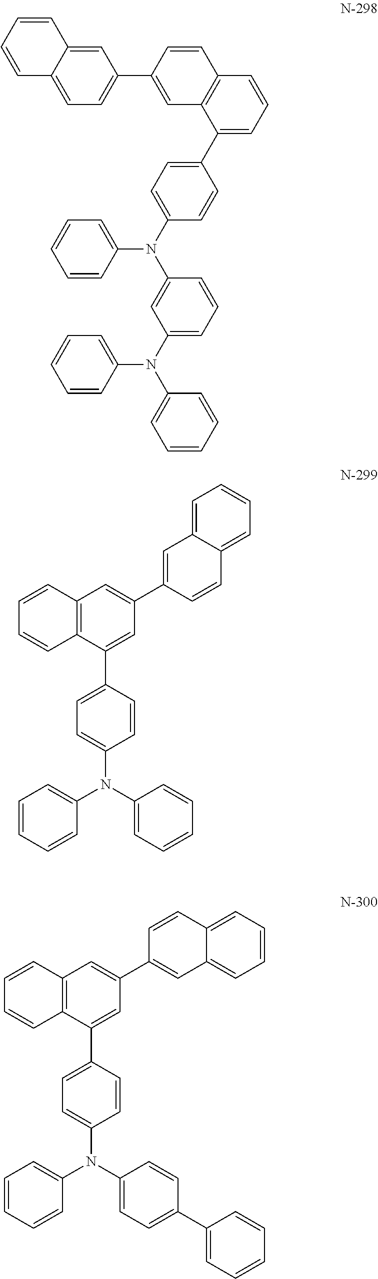

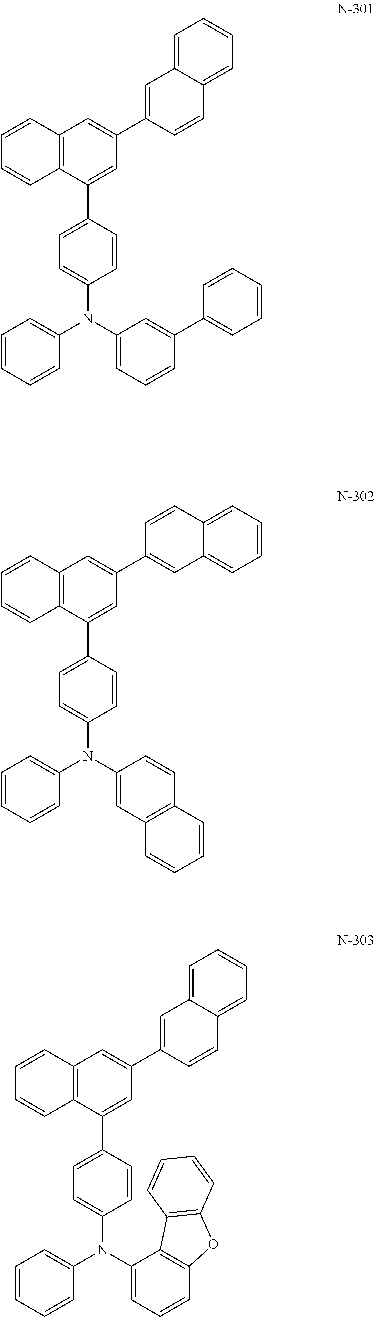 [SMILES: c1ccc(-c2cccc(N(c3ccccc3)c3ccc(-c4cc(-c5ccc6ccccc6c5)cc5ccccc45)cc3)c2)cc1 ; c1ccc(N(c2ccc(-c3cc(-c4ccc5ccccc5c4)cc4ccccc34)cc2)c2ccc3ccccc3c2)cc1 ; c1ccc(N(c2ccc(-c3cc(-c4ccc5ccccc5c4)cc4ccccc34)cc2)c2cccc3oc4ccccc4c23)cc1]

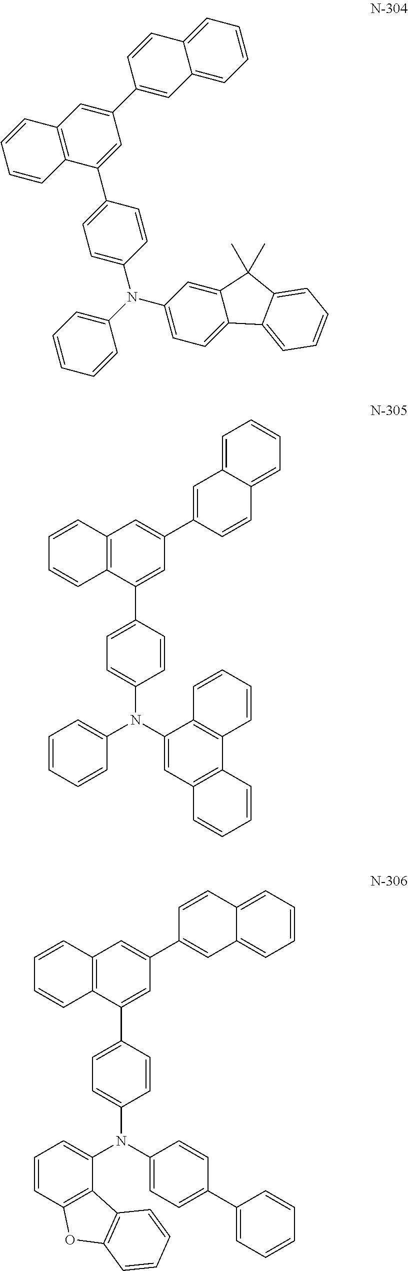 [SMILES: CC1(C)c2ccccc2-c2ccc(N(c3ccccc3)c3ccc(-c4cc(-c5ccc6ccccc6c5)cc5ccccc45)cc3)cc21 ; c1ccc(N(c2ccc(-c3cc(-c4ccc5ccccc5c4)cc4ccccc34)cc2)c2cc3ccccc3c3ccccc23)cc1 ; c1ccc(-c2ccc(N(c3ccc(-c4cc(-c5ccc6ccccc6c5)cc5ccccc45)cc3)c3cccc4oc5ccccc5c34)cc2)cc1]

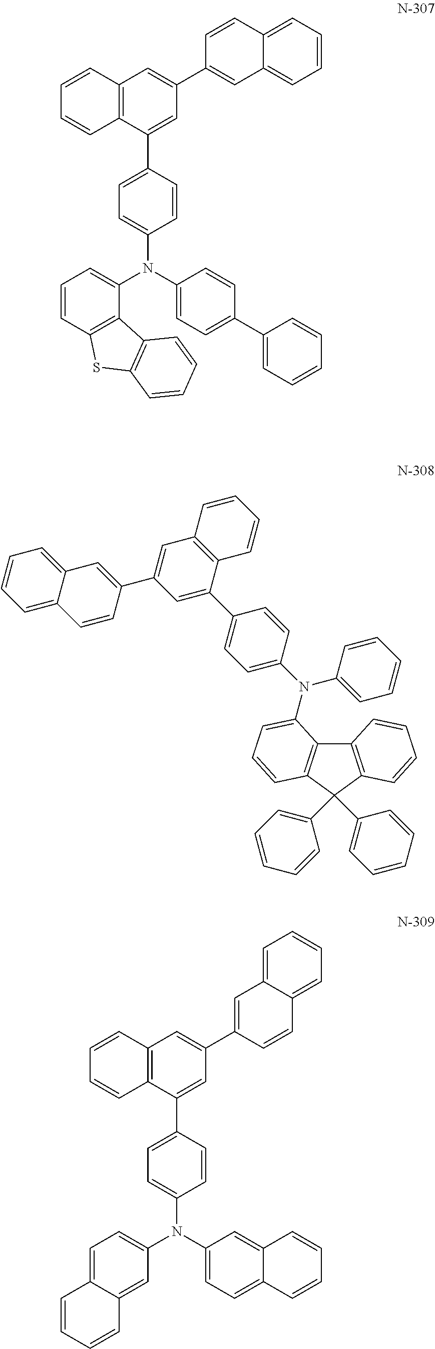 [SMILES: c1ccc(-c2ccc(N(c3ccc(-c4cc(-c5ccc6ccccc6c5)cc5ccccc45)cc3)c3cccc4sc5ccccc5c34)cc2)cc1 ; c1ccc(N(c2ccc(-c3cc(-c4ccc5ccccc5c4)cc4ccccc34)cc2)c2cccc3c2-c2ccccc2C3(c2ccccc2)c2ccccc2)cc1 ; c1ccc2cc(-c3cc(-c4ccc(N(c5ccc6ccccc6c5)c5ccc6ccccc6c5)cc4)c4ccccc4c3)ccc2c1]

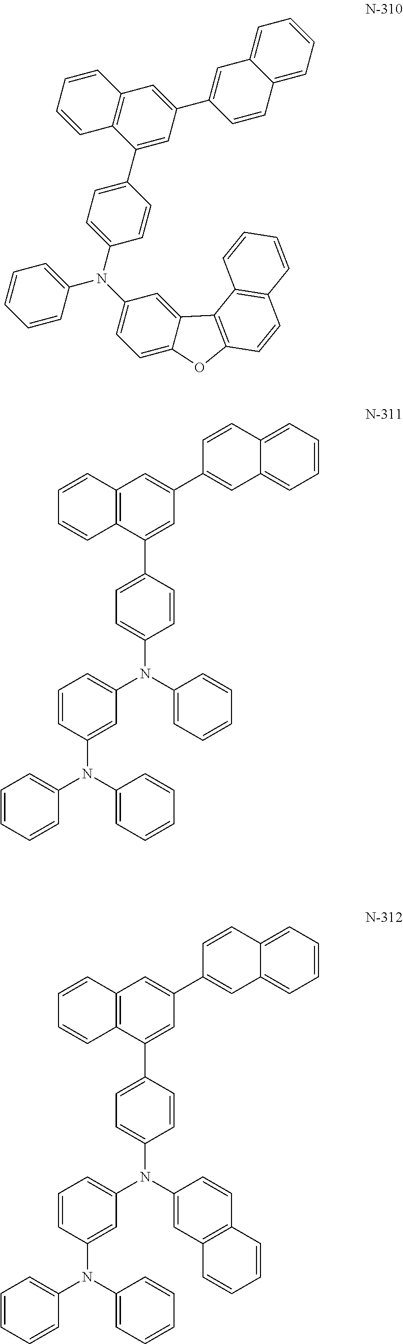 [SMILES: c1ccc(N(c2ccc(-c3cc(-c4ccc5ccccc5c4)cc4ccccc34)cc2)c2ccc3oc4ccc5ccccc5c4c3c2)cc1 ; c1ccc(N(c2ccccc2)c2cccc(N(c3ccccc3)c3ccc(-c4cc(-c5ccc6ccccc6c5)cc5ccccc45)cc3)c2)cc1 ; c1ccc(N(c2ccccc2)c2cccc(N(c3ccc(-c4cc(-c5ccc6ccccc6c5)cc5ccccc45)cc3)c3ccc4ccccc4c3)c2)cc1]

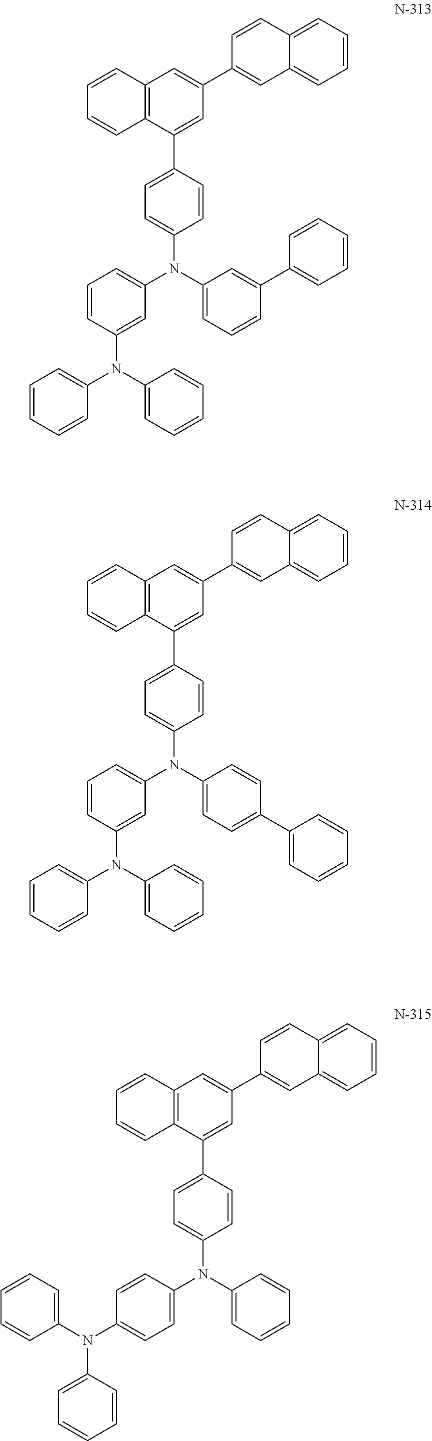 [SMILES: c1ccc(-c2cccc(N(c3ccc(-c4cc(-c5ccc6ccccc6c5)cc5ccccc45)cc3)c3cccc(N(c4ccccc4)c4ccccc4)c3)c2)cc1 ; c1ccc(-c2ccc(N(c3ccc(-c4cc(-c5ccc6ccccc6c5)cc5ccccc45)cc3)c3cccc(N(c4ccccc4)c4ccccc4)c3)cc2)cc1 ; c1ccc(N(c2ccccc2)c2ccc(N(c3ccccc3)c3ccc(-c4cc(-c5ccc6ccccc6c5)cc5ccccc45)cc3)cc2)cc1]

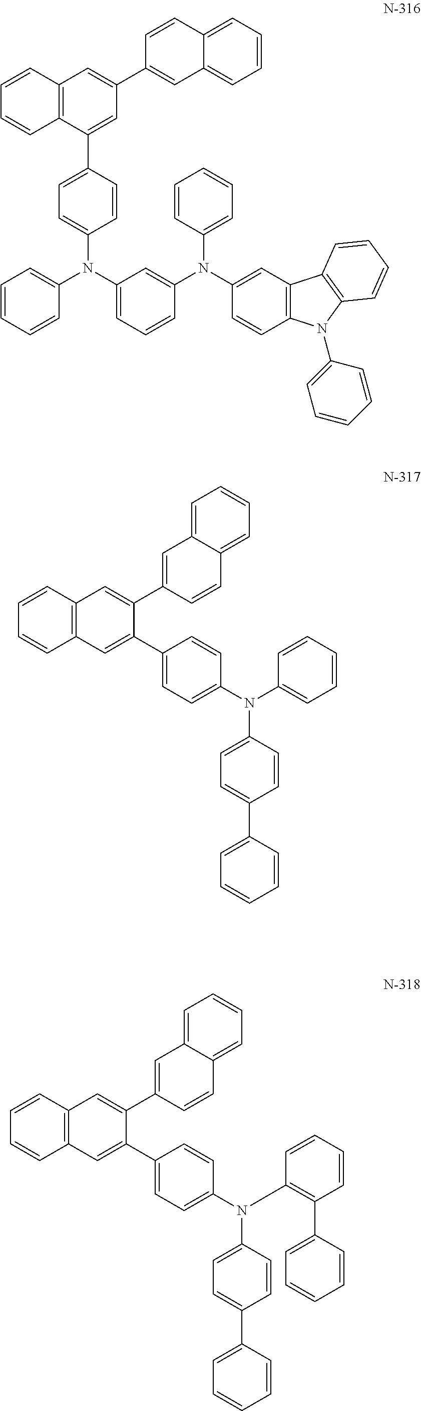 [SMILES: c1ccc(N(c2ccc(-c3cc(-c4ccc5ccccc5c4)cc4ccccc34)cc2)c2cccc(N(c3ccccc3)c3ccc4c(c3)c3ccccc3n4-c3ccccc3)c2)cc1 ; c1ccc(-c2ccc(N(c3ccccc3)c3ccc(-c4cc5ccccc5cc4-c4ccc5ccccc5c4)cc3)cc2)cc1 ; c1ccc(-c2ccc(N(c3ccc(-c4cc5ccccc5cc4-c4ccc5ccccc5c4)cc3)c3ccccc3-c3ccccc3)cc2)cc1]

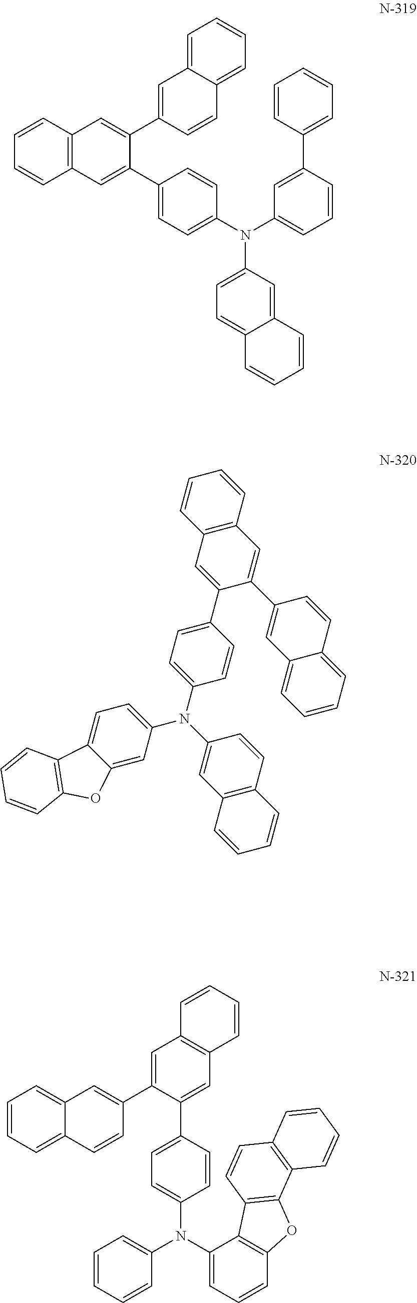 [SMILES: c1ccc(-c2cccc(N(c3ccc(-c4cc5ccccc5cc4-c4ccc5ccccc5c4)cc3)c3ccc4ccccc4c3)c2)cc1 ; c1ccc2cc(-c3cc4ccccc4cc3-c3ccc(N(c4ccc5ccccc5c4)c4ccc5c(c4)oc4ccccc45)cc3)ccc2c1 ; c1ccc(N(c2ccc(-c3cc4ccccc4cc3-c3ccc4ccccc4c3)cc2)c2cccc3oc4c5ccccc5ccc4c23)cc1]

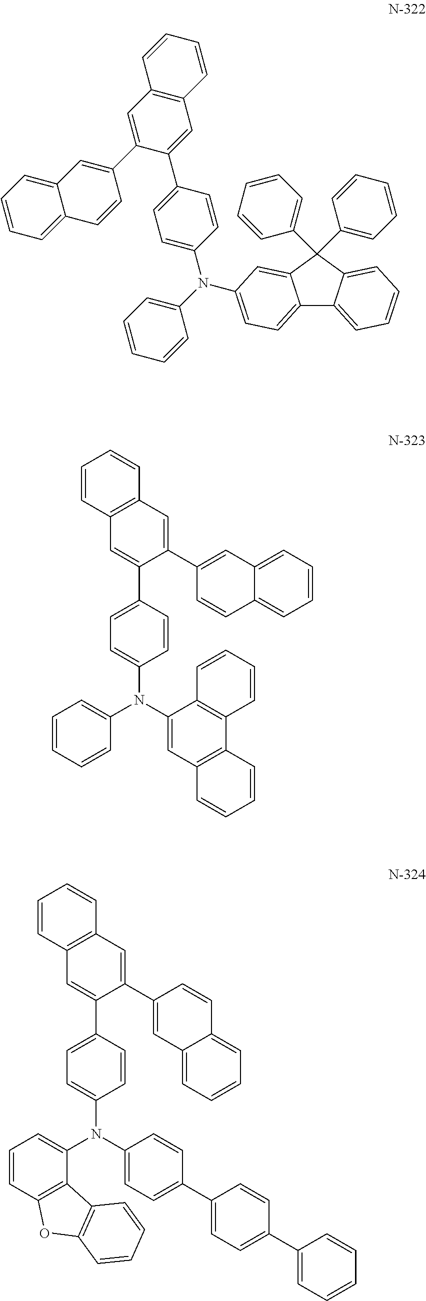 [SMILES: c1ccc(N(c2ccc(-c3cc4ccccc4cc3-c3ccc4ccccc4c3)cc2)c2ccc3c(c2)C(c2ccccc2)(c2ccccc2)c2ccccc2-3)cc1 ; c1ccc(N(c2ccc(-c3cc4ccccc4cc3-c3ccc4ccccc4c3)cc2)c2cc3ccccc3c3ccccc23)cc1 ; c1ccc(-c2ccc(-c3ccc(N(c4ccc(-c5cc6ccccc6cc5-c5ccc6ccccc6c5)cc4)c4cccc5oc6ccccc6c45)cc3)cc2)cc1]

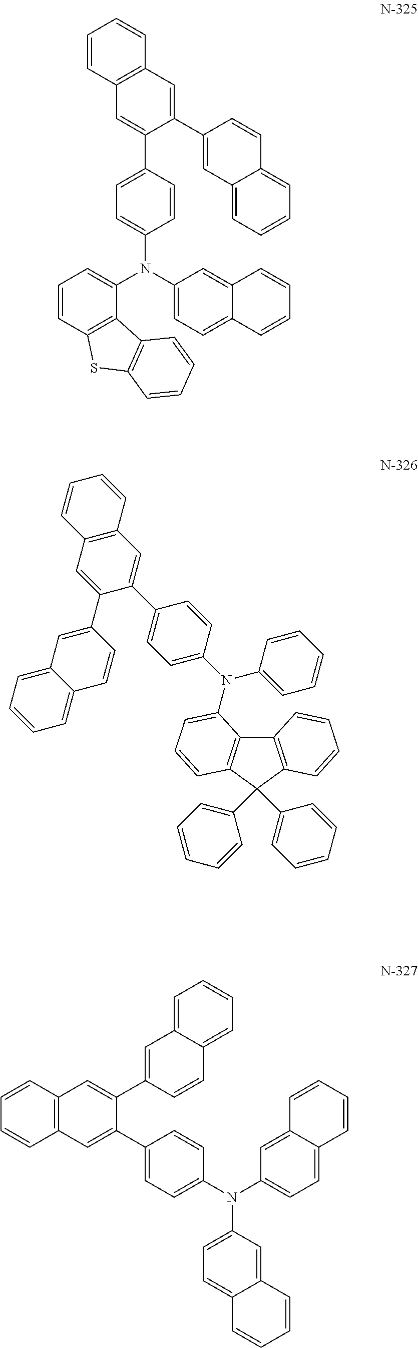 [SMILES: c1ccc2cc(-c3cc4ccccc4cc3-c3ccc(N(c4ccc5ccccc5c4)c4cccc5sc6ccccc6c45)cc3)ccc2c1 ; c1ccc(N(c2ccc(-c3cc4ccccc4cc3-c3ccc4ccccc4c3)cc2)c2cccc3c2-c2ccccc2C3(c2ccccc2)c2ccccc2)cc1 ; c1ccc2cc(-c3cc4ccccc4cc3-c3ccc(N(c4ccc5ccccc5c4)c4ccc5ccccc5c4)cc3)ccc2c1]

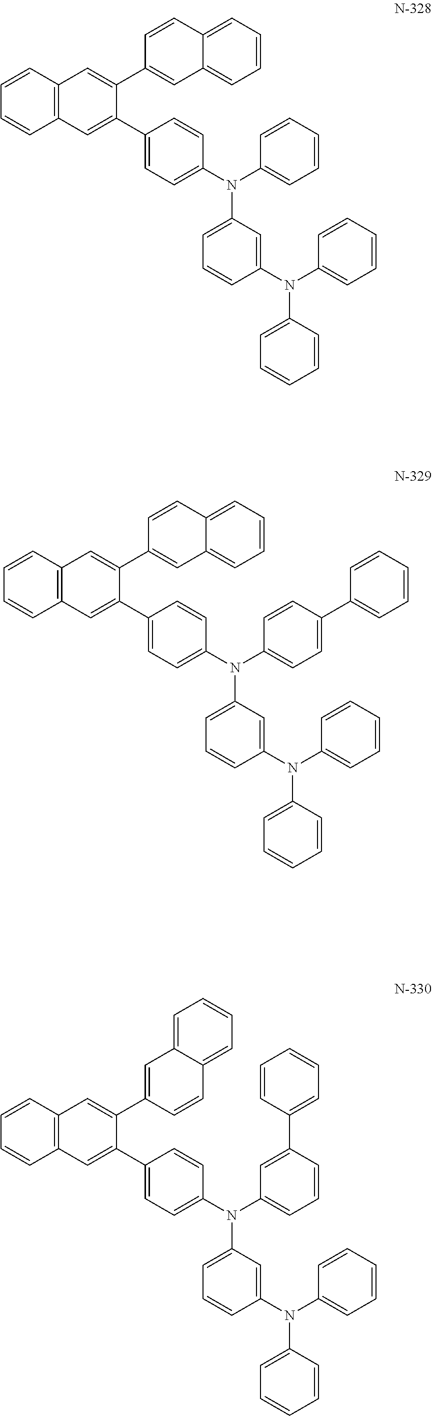 [SMILES: c1ccc(N(c2ccccc2)c2cccc(N(c3ccccc3)c3ccc(-c4cc5ccccc5cc4-c4ccc5ccccc5c4)cc3)c2)cc1 ; c1ccc(-c2ccc(N(c3ccc(-c4cc5ccccc5cc4-c4ccc5ccccc5c4)cc3)c3cccc(N(c4ccccc4)c4ccccc4)c3)cc2)cc1 ; c1ccc(-c2cccc(N(c3ccc(-c4cc5ccccc5cc4-c4ccc5ccccc5c4)cc3)c3cccc(N(c4ccccc4)c4ccccc4)c3)c2)cc1]

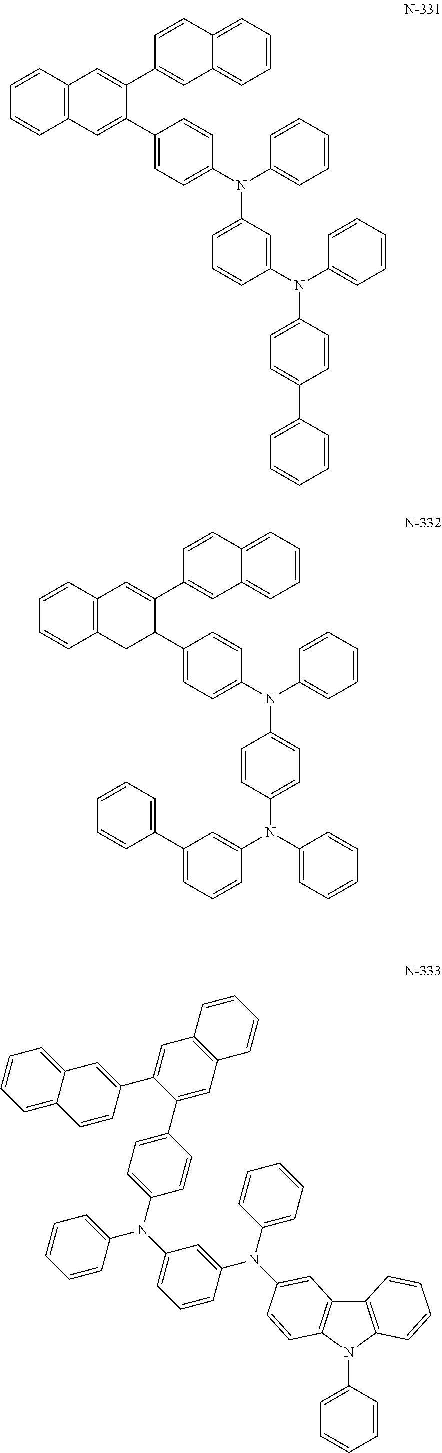 [SMILES: c1ccc(-c2ccc(N(c3ccccc3)c3cccc(N(c4ccccc4)c4ccc(-c5cc6ccccc6cc5-c5ccc6ccccc6c5)cc4)c3)cc2)cc1 ; C1=C(c2ccc3ccccc3c2)C(c2ccc(N(c3ccccc3)c3ccc(N(c4ccccc4)c4cccc(-c5ccccc5)c4)cc3)cc2)Cc2ccccc21 ; c1ccc(N(c2ccc(-c3cc4ccccc4cc3-c3ccc4ccccc4c3)cc2)c2cccc(N(c3ccccc3)c3ccc4c(c3)c3ccccc3n4-c3ccccc3)c2)cc1]

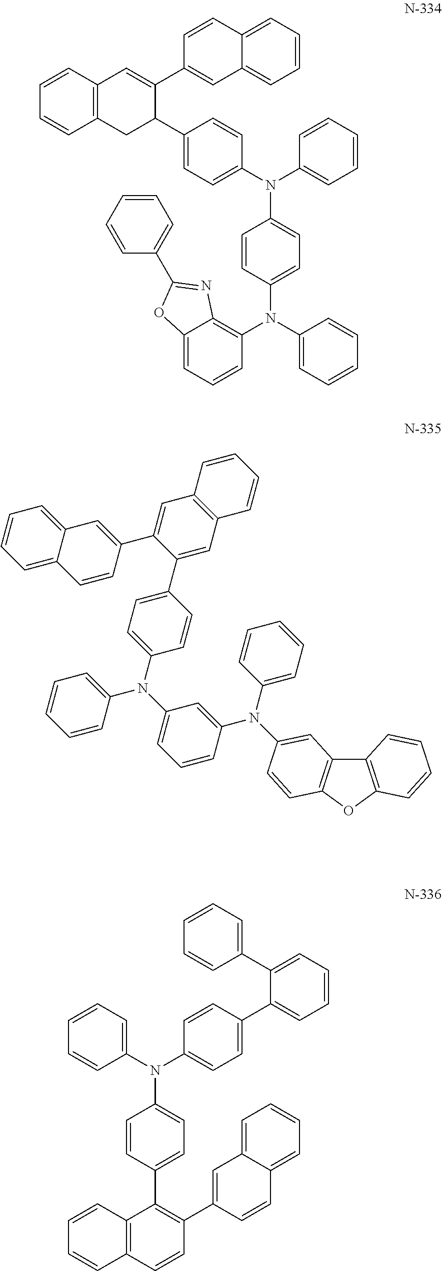 [SMILES: C1=C(c2ccc3ccccc3c2)C(c2ccc(N(c3ccccc3)c3ccc(N(c4ccccc4)c4cccc5oc(-c6ccccc6)nc45)cc3)cc2)Cc2ccccc21 ; c1ccc(N(c2ccc(-c3cc4ccccc4cc3-c3ccc4ccccc4c3)cc2)c2cccc(N(c3ccccc3)c3ccc4oc5ccccc5c4c3)c2)cc1 ; c1ccc(-c2ccccc2-c2ccc(N(c3ccccc3)c3ccc(-c4c(-c5ccc6ccccc6c5)ccc5ccccc45)cc3)cc2)cc1]

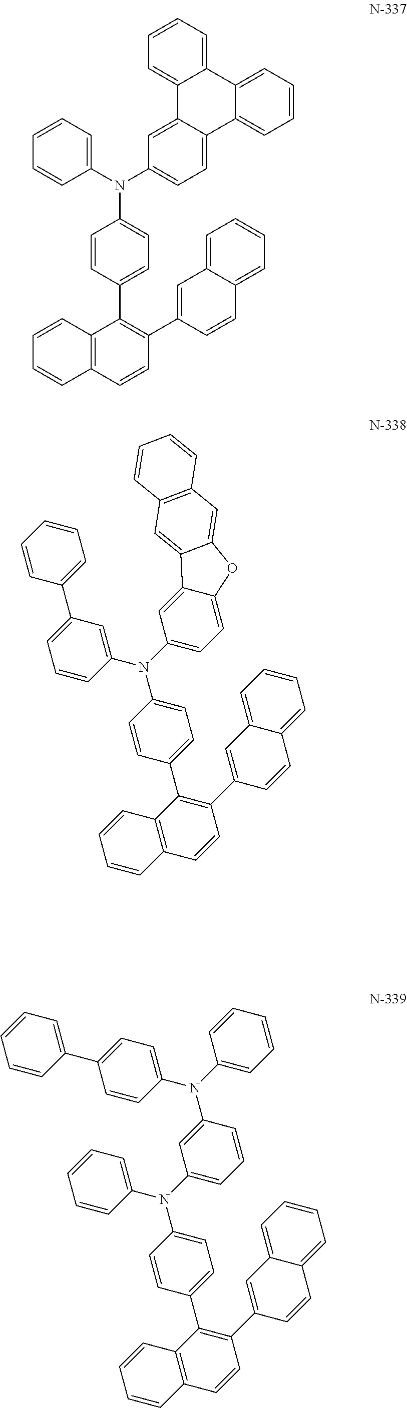 [SMILES: c1ccc(N(c2ccc(-c3c(-c4ccc5ccccc5c4)ccc4ccccc34)cc2)c2ccc3c4ccccc4c4ccccc4c3c2)cc1 ; c1ccc(-c2cccc(N(c3ccc(-c4c(-c5ccc6ccccc6c5)ccc5ccccc45)cc3)c3ccc4oc5cc6ccccc6cc5c4c3)c2)cc1 ; c1ccc(-c2ccc(N(c3ccccc3)c3cccc(N(c4ccccc4)c4ccc(-c5c(-c6ccc7ccccc7c6)ccc6ccccc56)cc4)c3)cc2)cc1]

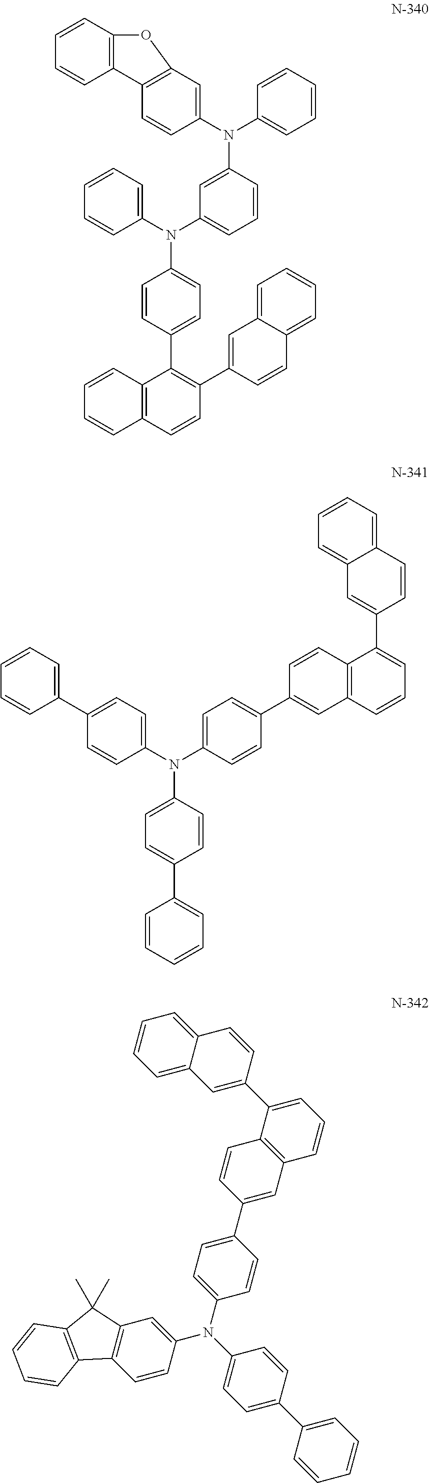 [SMILES: c1ccc(N(c2ccc(-c3c(-c4ccc5ccccc5c4)ccc4ccccc34)cc2)c2cccc(N(c3ccccc3)c3ccc4c(c3)oc3ccccc34)c2)cc1 ; c1ccc(-c2ccc(N(c3ccc(-c4ccccc4)cc3)c3ccc(-c4ccc5c(-c6ccc7ccccc7c6)cccc5c4)cc3)cc2)cc1 ; CC1(C)c2ccccc2-c2ccc(N(c3ccc(-c4ccccc4)cc3)c3ccc(-c4ccc5c(-c6ccc7ccccc7c6)cccc5c4)cc3)cc21]

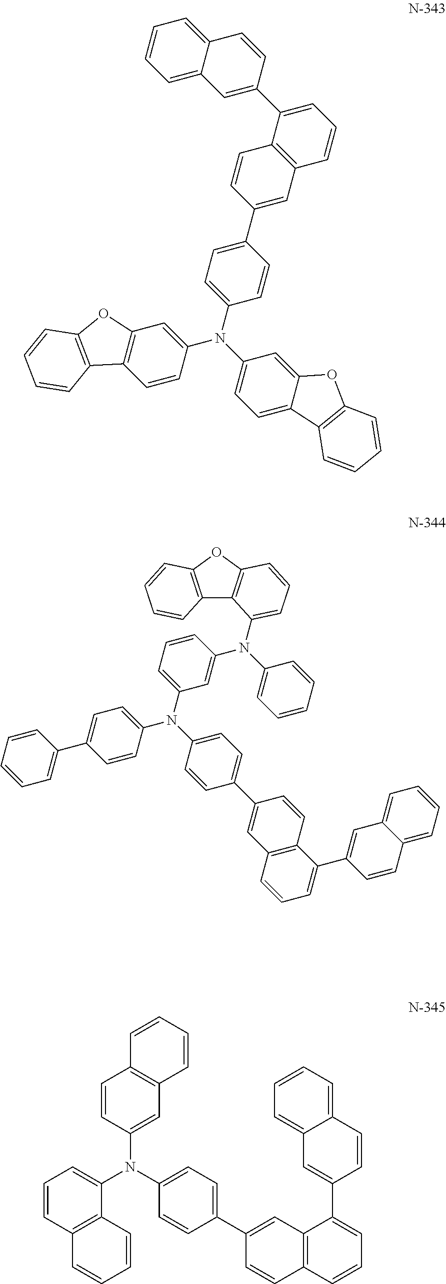 [SMILES: c1ccc2cc(-c3cccc4cc(-c5ccc(N(c6ccc7c(c6)oc6ccccc67)c6ccc7c(c6)oc6ccccc67)cc5)ccc34)ccc2c1 ; c1ccc(-c2ccc(N(c3ccc(-c4ccc5c(-c6ccc7ccccc7c6)cccc5c4)cc3)c3cccc(N(c4ccccc4)c4cccc5oc6ccccc6c45)c3)cc2)cc1 ; c1ccc2cc(-c3cccc4ccc(-c5ccc(N(c6ccc7ccccc7c6)c6cccc7ccccc67)cc5)cc34)ccc2c1]

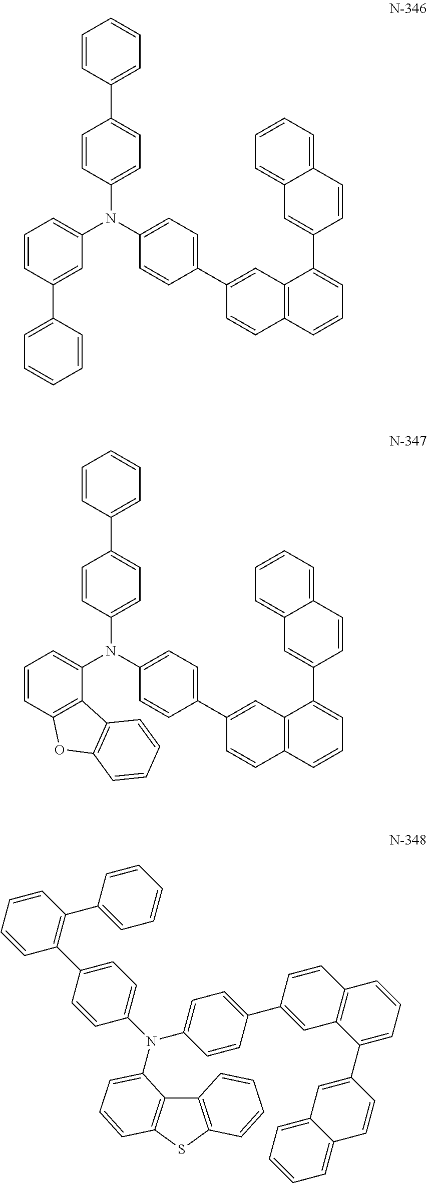 [SMILES: c1ccc(-c2ccc(N(c3ccc(-c4ccc5cccc(-c6ccc7ccccc7c6)c5c4)cc3)c3cccc(-c4ccccc4)c3)cc2)cc1 ; c1ccc(-c2ccc(N(c3ccc(-c4ccc5cccc(-c6ccc7ccccc7c6)c5c4)cc3)c3cccc4oc5ccccc5c34)cc2)cc1 ; c1ccc(-c2ccccc2-c2ccc(N(c3ccc(-c4ccc5cccc(-c6ccc7ccccc7c6)c5c4)cc3)c3cccc4sc5ccccc5c34)cc2)cc1]

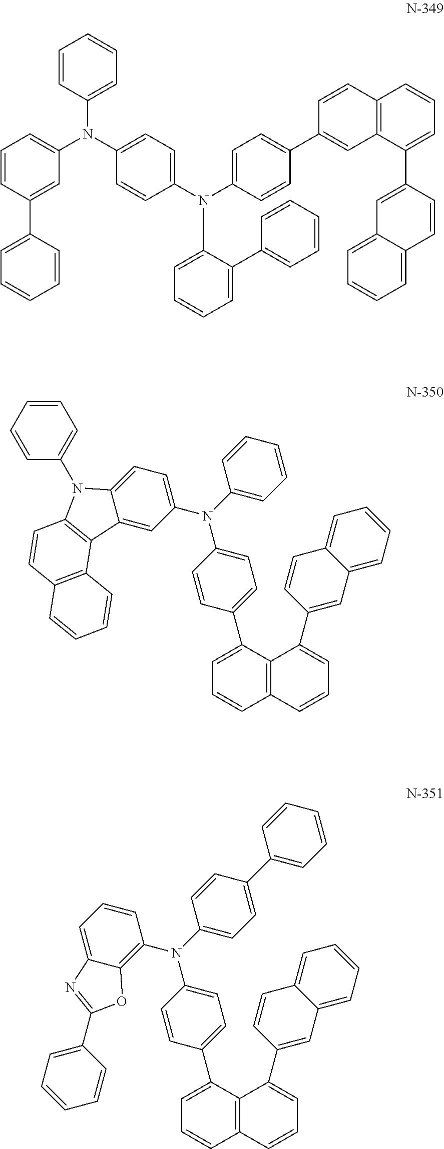 [SMILES: c1ccc(-c2cccc(N(c3ccccc3)c3ccc(N(c4ccc(-c5ccc6cccc(-c7ccc8ccccc8c7)c6c5)cc4)c4ccccc4-c4ccccc4)cc3)c2)cc1 ; c1ccc(N(c2ccc(-c3cccc4cccc(-c5ccc6ccccc6c5)c34)cc2)c2ccc3c(c2)c2c4ccccc4ccc2n3-c2ccccc2)cc1 ; c1ccc(-c2ccc(N(c3ccc(-c4cccc5cccc(-c6ccc7ccccc7c6)c45)cc3)c3cccc4nc(-c5ccccc5)oc34)cc2)cc1]

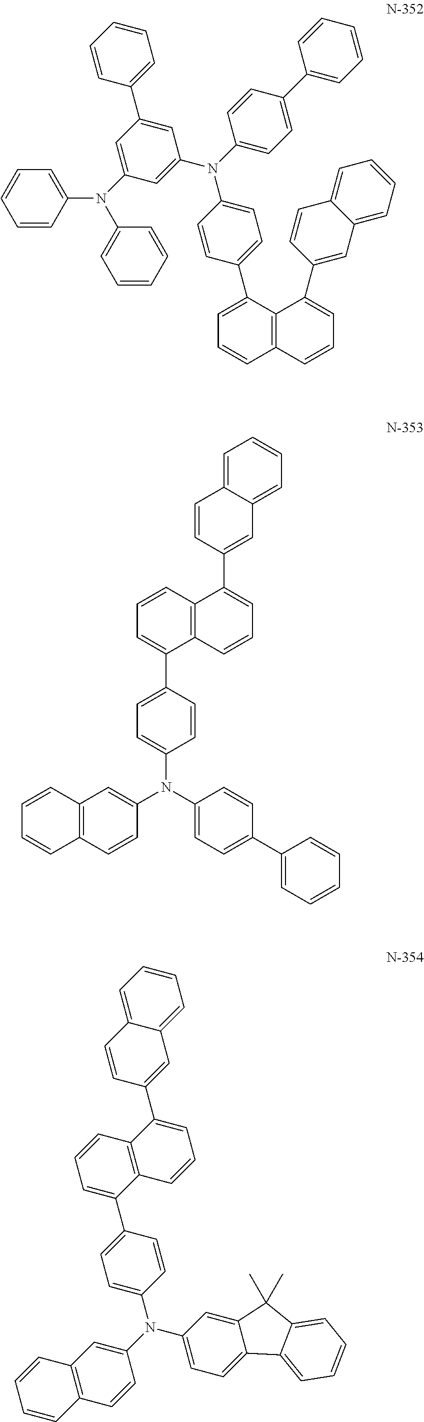 [SMILES: c1ccc(-c2ccc(N(c3ccc(-c4cccc5cccc(-c6ccc7ccccc7c6)c45)cc3)c3cc(-c4ccccc4)cc(N(c4ccccc4)c4ccccc4)c3)cc2)cc1 ; c1ccc(-c2ccc(N(c3ccc(-c4cccc5c(-c6ccc7ccccc7c6)cccc45)cc3)c3ccc4ccccc4c3)cc2)cc1 ; CC1(C)c2ccccc2-c2ccc(N(c3ccc(-c4cccc5c(-c6ccc7ccccc7c6)cccc45)cc3)c3ccc4ccccc4c3)cc21]

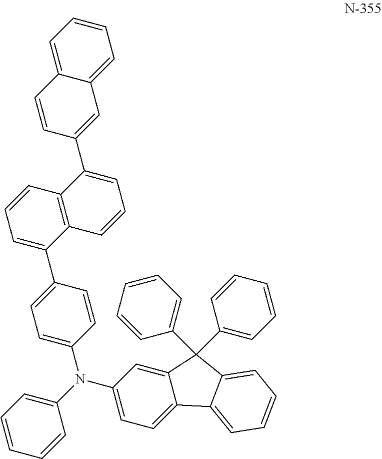 [SMILES: c1ccc(N(c2ccc(-c3cccc4c(-c5ccc6ccccc6c5)cccc34)cc2)c2ccc3c(c2)C(c2ccccc2)(c2ccccc2)c2ccccc2-3)cc1]

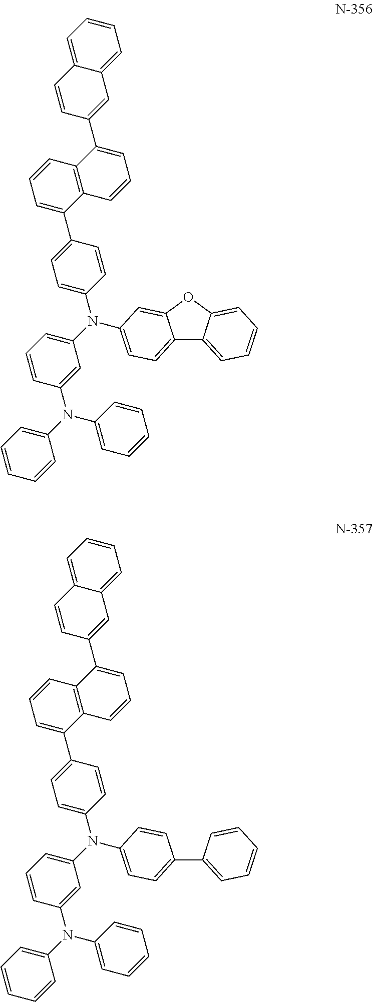 [SMILES: c1ccc(N(c2ccccc2)c2cccc(N(c3ccc(-c4cccc5c(-c6ccc7ccccc7c6)cccc45)cc3)c3ccc4c(c3)oc3ccccc34)c2)cc1 ; c1ccc(-c2ccc(N(c3ccc(-c4cccc5c(-c6ccc7ccccc7c6)cccc45)cc3)c3cccc(N(c4ccccc4)c4ccccc4)c3)cc2)cc1]

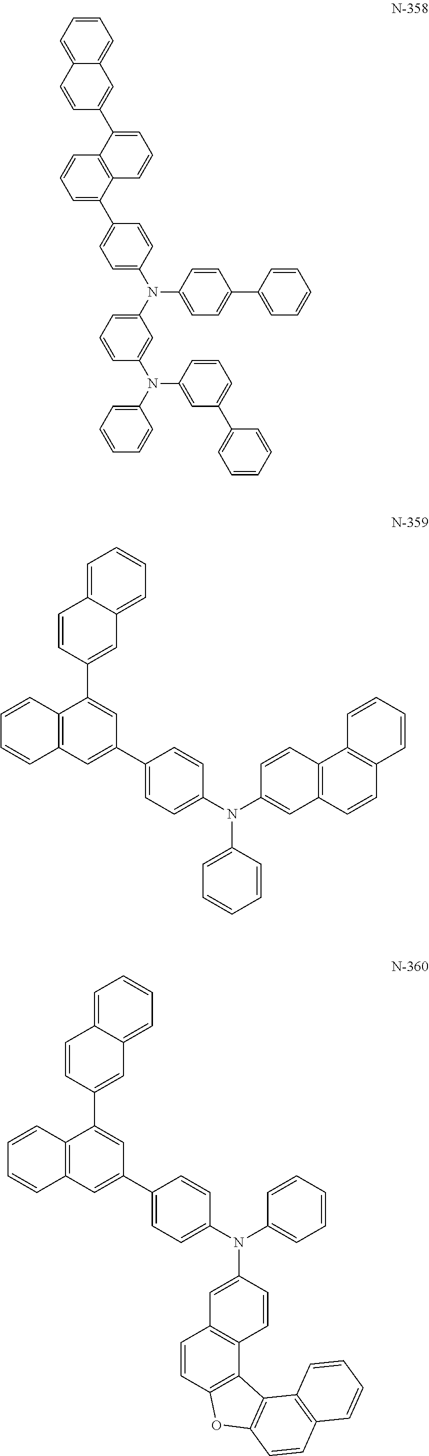 [SMILES: c1ccc(-c2ccc(N(c3ccc(-c4cccc5c(-c6ccc7ccccc7c6)cccc45)cc3)c3cccc(N(c4ccccc4)c4cccc(-c5ccccc5)c4)c3)cc2)cc1 ; c1ccc(N(c2ccc(-c3cc(-c4ccc5ccccc5c4)c4ccccc4c3)cc2)c2ccc3c(ccc4ccccc43)c2)cc1 ; c1ccc(N(c2ccc(-c3cc(-c4ccc5ccccc5c4)c4ccccc4c3)cc2)c2ccc3c(ccc4oc5ccc6ccccc6c5c43)c2)cc1]

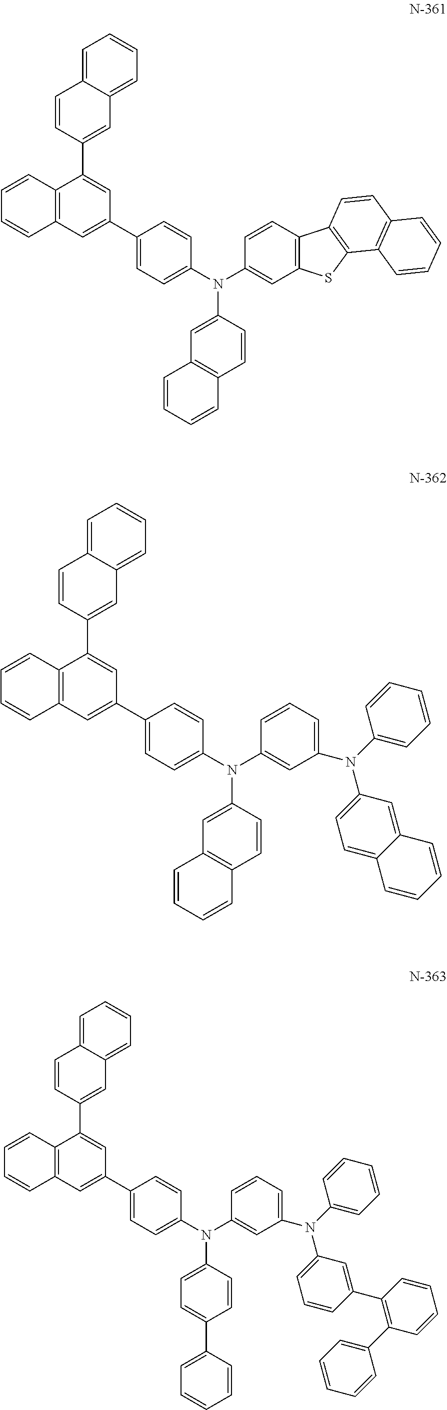 [SMILES: c1ccc2cc(-c3cc(-c4ccc(N(c5ccc6ccccc6c5)c5ccc6c(c5)sc5c7ccccc7ccc65)cc4)cc4ccccc34)ccc2c1 ; c1ccc(N(c2cccc(N(c3ccc(-c4cc(-c5ccc6ccccc6c5)c5ccccc5c4)cc3)c3ccc4ccccc4c3)c2)c2ccc3ccccc3c2)cc1 ; c1ccc(-c2ccc(N(c3ccc(-c4cc(-c5ccc6ccccc6c5)c5ccccc5c4)cc3)c3cccc(N(c4ccccc4)c4cccc(-c5ccccc5-c5ccccc5)c4)c3)cc2)cc1]

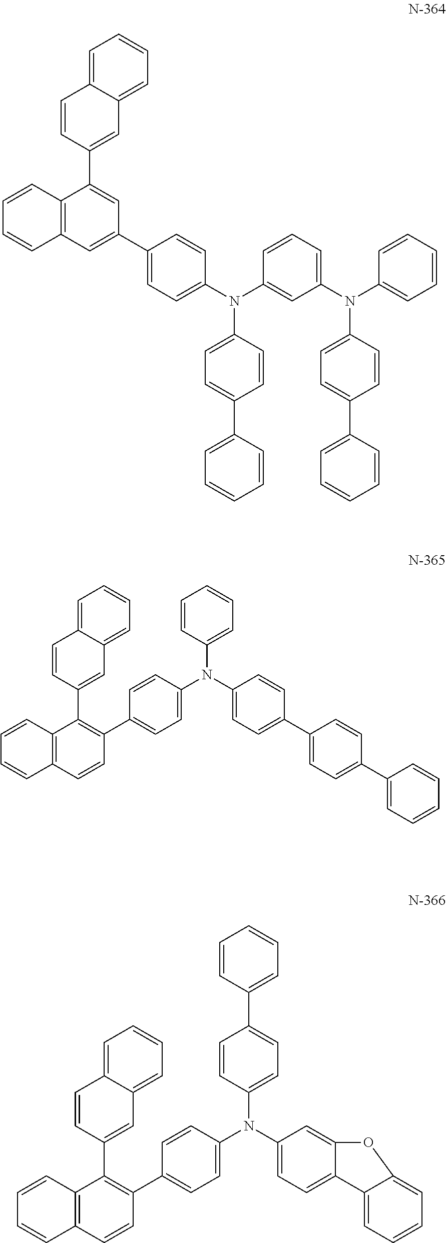 [SMILES: c1ccc(-c2ccc(N(c3ccccc3)c3cccc(N(c4ccc(-c5ccccc5)cc4)c4ccc(-c5cc(-c6ccc7ccccc7c6)c6ccccc6c5)cc4)c3)cc2)cc1 ; c1ccc(-c2ccc(-c3ccc(N(c4ccccc4)c4ccc(-c5ccc6ccccc6c5-c5ccc6ccccc6c5)cc4)cc3)cc2)cc1 ; c1ccc(-c2ccc(N(c3ccc(-c4ccc5ccccc5c4-c4ccc5ccccc5c4)cc3)c3ccc4c(c3)oc3ccccc34)cc2)cc1]

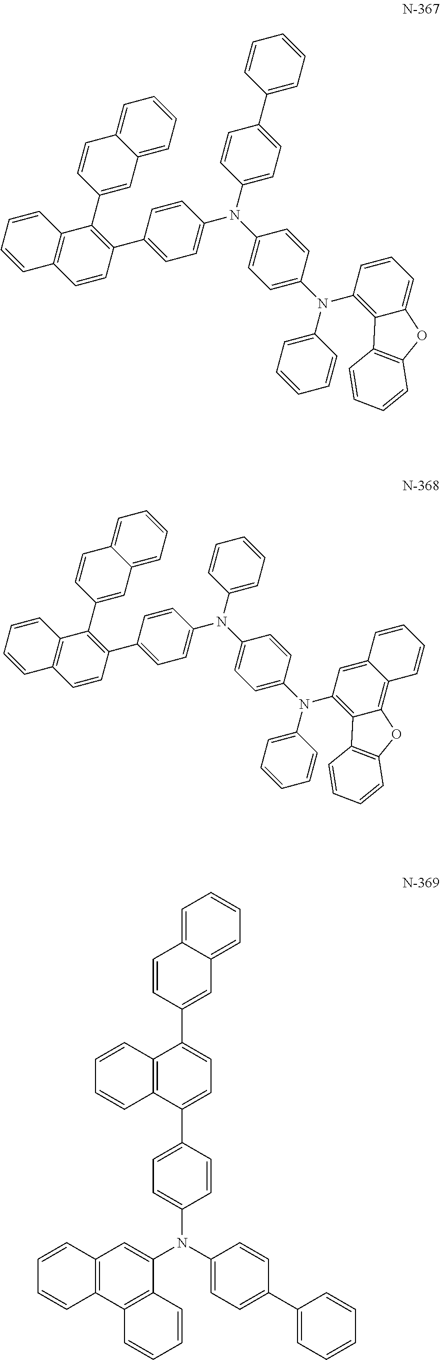 [SMILES: c1ccc(-c2ccc(N(c3ccc(-c4ccc5ccccc5c4-c4ccc5ccccc5c4)cc3)c3ccc(N(c4ccccc4)c4cccc5oc6ccccc6c45)cc3)cc2)cc1 ; c1ccc(N(c2ccc(-c3ccc4ccccc4c3-c3ccc4ccccc4c3)cc2)c2ccc(N(c3ccccc3)c3cc4ccccc4c4oc5ccccc5c34)cc2)cc1 ; c1ccc(-c2ccc(N(c3ccc(-c4ccc(-c5ccc6ccccc6c5)c5ccccc45)cc3)c3cc4ccccc4c4ccccc34)cc2)cc1]

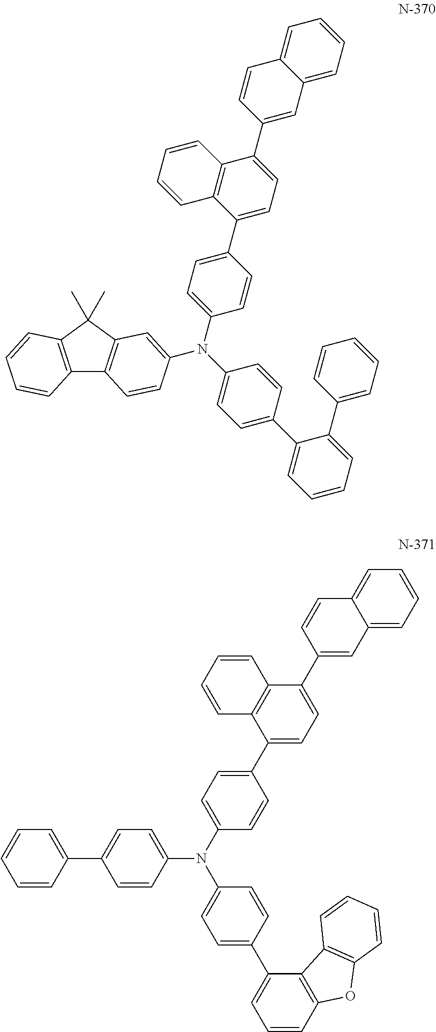 [SMILES: CC1(C)c2ccccc2-c2ccc(N(c3ccc(-c4ccccc4-c4ccccc4)cc3)c3ccc(-c4ccc(-c5ccc6ccccc6c5)c5ccccc45)cc3)cc21 ; c1ccc(-c2ccc(N(c3ccc(-c4ccc(-c5ccc6ccccc6c5)c5ccccc45)cc3)c3ccc(-c4cccc5oc6ccccc6c45)cc3)cc2)cc1]

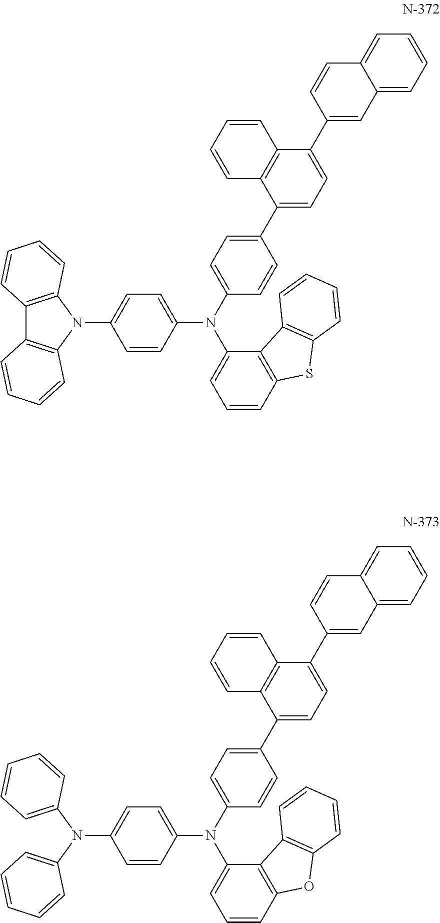 [SMILES: c1ccc2cc(-c3ccc(-c4ccc(N(c5ccc(-n6c7ccccc7c7ccccc76)cc5)c5cccc6sc7ccccc7c56)cc4)c4ccccc34)ccc2c1 ; c1ccc(N(c2ccccc2)c2ccc(N(c3ccc(-c4ccc(-c5ccc6ccccc6c5)c5ccccc45)cc3)c3cccc4oc5ccccc5c34)cc2)cc1]

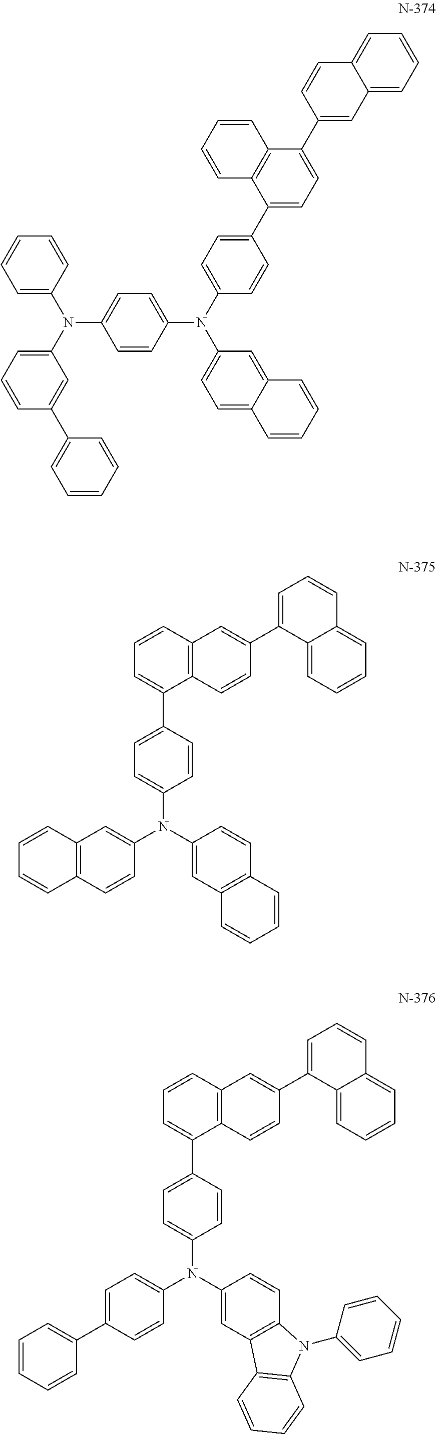 [SMILES: c1ccc(-c2cccc(N(c3ccccc3)c3ccc(N(c4ccc(-c5ccc(-c6ccc7ccccc7c6)c6ccccc56)cc4)c4ccc5ccccc5c4)cc3)c2)cc1 ; c1ccc2cc(N(c3ccc(-c4cccc5cc(-c6cccc7ccccc67)ccc45)cc3)c3ccc4ccccc4c3)ccc2c1 ; c1ccc(-c2ccc(N(c3ccc(-c4cccc5cc(-c6cccc7ccccc67)ccc45)cc3)c3ccc4c(c3)c3ccccc3n4-c3ccccc3)cc2)cc1]

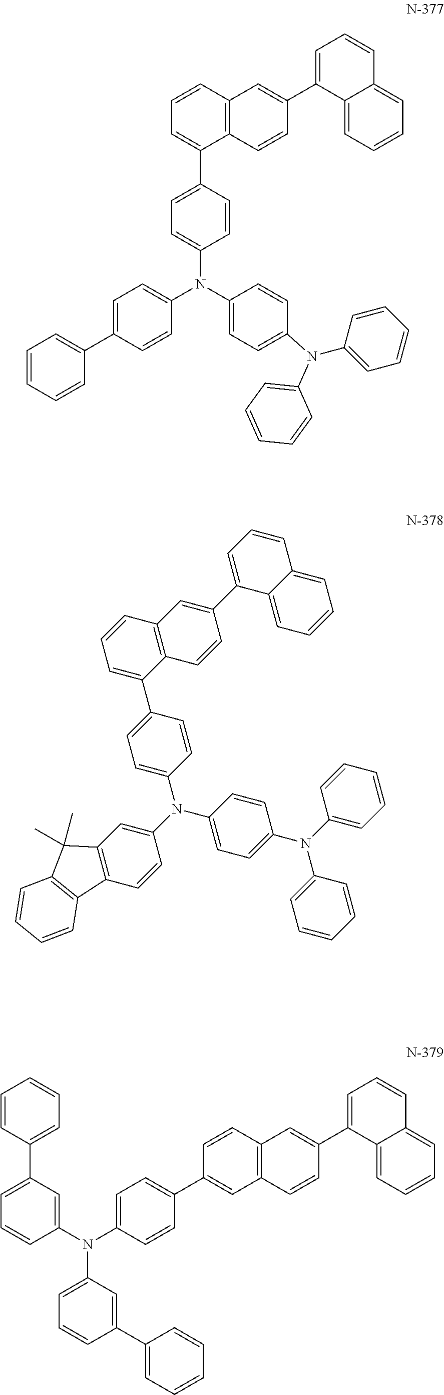 [SMILES: c1ccc(-c2ccc(N(c3ccc(-c4cccc5cc(-c6cccc7ccccc67)ccc45)cc3)c3ccc(N(c4ccccc4)c4ccccc4)cc3)cc2)cc1 ; CC1(C)c2ccccc2-c2ccc(N(c3ccc(-c4cccc5cc(-c6cccc7ccccc67)ccc45)cc3)c3ccc(N(c4ccccc4)c4ccccc4)cc3)cc21 ; c1ccc(-c2cccc(N(c3ccc(-c4ccc5cc(-c6cccc7ccccc67)ccc5c4)cc3)c3cccc(-c4ccccc4)c3)c2)cc1]

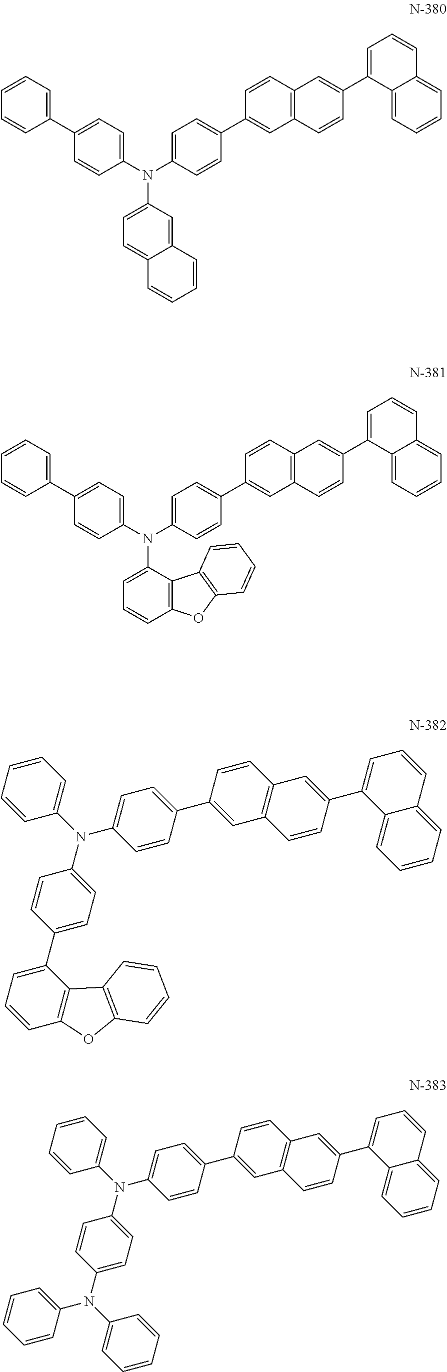 [SMILES: c1ccc(-c2ccc(N(c3ccc(-c4ccc5cc(-c6cccc7ccccc67)ccc5c4)cc3)c3ccc4ccccc4c3)cc2)cc1 ; c1ccc(-c2ccc(N(c3ccc(-c4ccc5cc(-c6cccc7ccccc67)ccc5c4)cc3)c3cccc4oc5ccccc5c34)cc2)cc1 ; c1ccc(N(c2ccc(-c3ccc4cc(-c5cccc6ccccc56)ccc4c3)cc2)c2ccc(-c3cccc4oc5ccccc5c34)cc2)cc1 ; c1ccc(N(c2ccccc2)c2ccc(N(c3ccccc3)c3ccc(-c4ccc5cc(-c6cccc7ccccc67)ccc5c4)cc3)cc2)cc1]

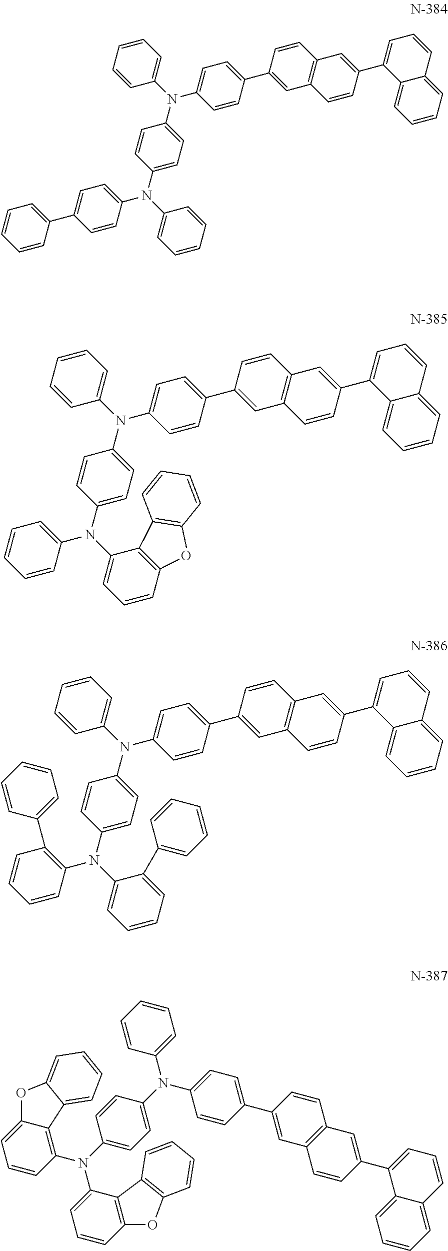 [SMILES: c1ccc(-c2ccc(N(c3ccccc3)c3ccc(N(c4ccccc4)c4ccc(-c5ccc6cc(-c7cccc8ccccc78)ccc6c5)cc4)cc3)cc2)cc1 ; c1ccc(N(c2ccc(-c3ccc4cc(-c5cccc6ccccc56)ccc4c3)cc2)c2ccc(N(c3ccccc3)c3cccc4oc5ccccc5c34)cc2)cc1 ; c1ccc(-c2ccccc2N(c2ccc(N(c3ccccc3)c3ccc(-c4ccc5cc(-c6cccc7ccccc67)ccc5c4)cc3)cc2)c2ccccc2-c2ccccc2)cc1 ; c1ccc(N(c2ccc(-c3ccc4cc(-c5cccc6ccccc56)ccc4c3)cc2)c2ccc(N(c3cccc4oc5ccccc5c34)c3cccc4oc5ccccc5c34)cc2)cc1]

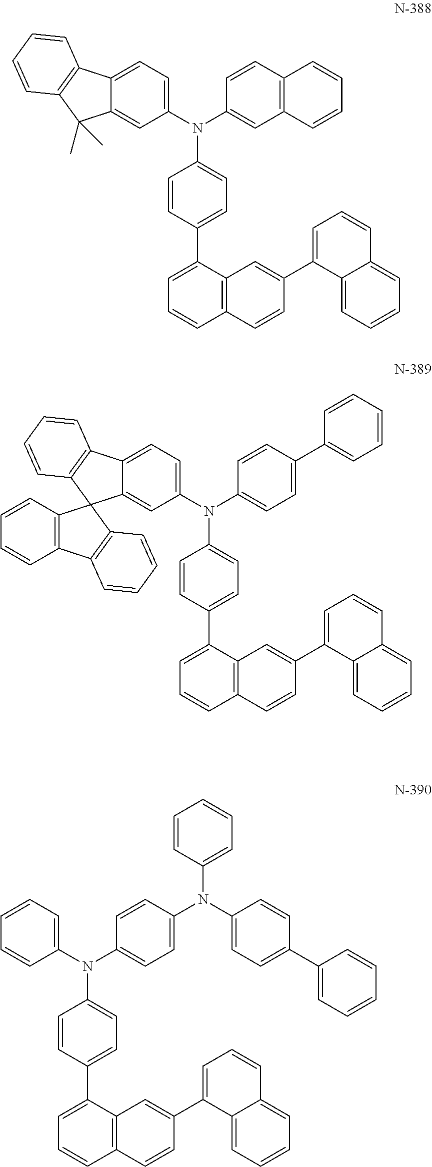 [SMILES: CC1(C)c2ccccc2-c2ccc(N(c3ccc(-c4cccc5ccc(-c6cccc7ccccc67)cc45)cc3)c3ccc4ccccc4c3)cc21 ; c1ccc(-c2ccc(N(c3ccc(-c4cccc5ccc(-c6cccc7ccccc67)cc45)cc3)c3ccc4c(c3)C3(c5ccccc5-c5ccccc53)c3ccccc3-4)cc2)cc1 ; c1ccc(-c2ccc(N(c3ccccc3)c3ccc(N(c4ccccc4)c4ccc(-c5cccc6ccc(-c7cccc8ccccc78)cc56)cc4)cc3)cc2)cc1]

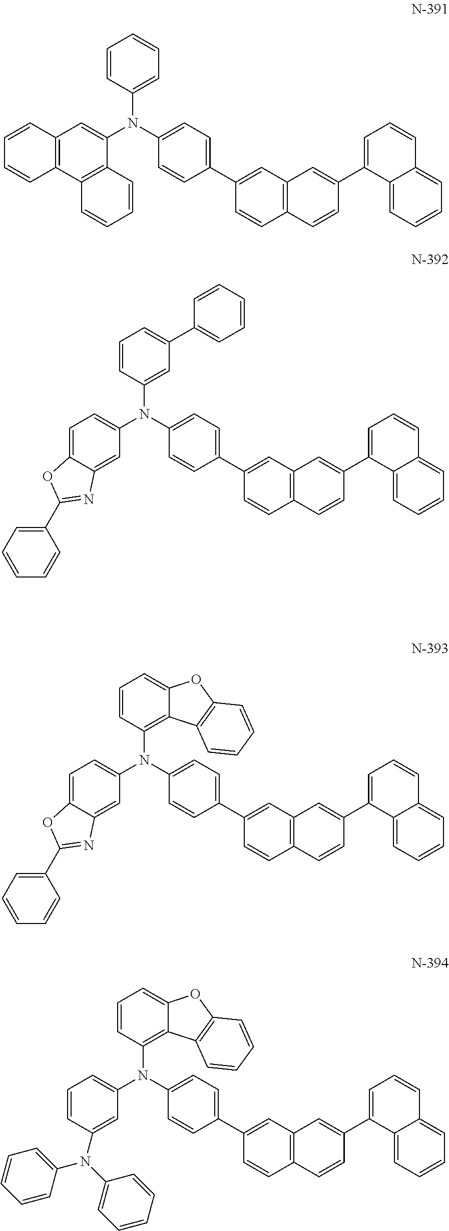 [SMILES: c1ccc(N(c2ccc(-c3ccc4ccc(-c5cccc6ccccc56)cc4c3)cc2)c2cc3ccccc3c3ccccc23)cc1 ; c1ccc(-c2cccc(N(c3ccc(-c4ccc5ccc(-c6cccc7ccccc67)cc5c4)cc3)c3ccc4oc(-c5ccccc5)nc4c3)c2)cc1 ; c1ccc(-c2nc3cc(N(c4ccc(-c5ccc6ccc(-c7cccc8ccccc78)cc6c5)cc4)c4cccc5oc6ccccc6c45)ccc3o2)cc1 ; c1ccc(N(c2ccccc2)c2cccc(N(c3ccc(-c4ccc5ccc(-c6cccc7ccccc67)cc5c4)cc3)c3cccc4oc5ccccc5c34)c2)cc1]

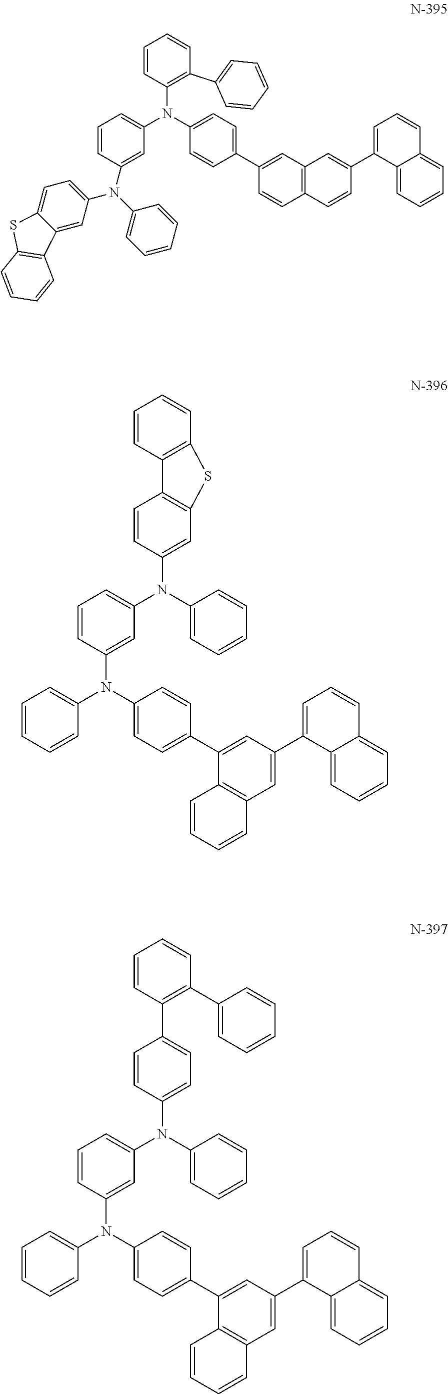 [SMILES: c1ccc(-c2ccccc2N(c2ccc(-c3ccc4ccc(-c5cccc6ccccc56)cc4c3)cc2)c2cccc(N(c3ccccc3)c3ccc4sc5ccccc5c4c3)c2)cc1 ; c1ccc(N(c2ccc(-c3cc(-c4cccc5ccccc45)cc4ccccc34)cc2)c2cccc(N(c3ccccc3)c3ccc4c(c3)sc3ccccc34)c2)cc1 ; c1ccc(-c2ccccc2-c2ccc(N(c3ccccc3)c3cccc(N(c4ccccc4)c4ccc(-c5cc(-c6cccc7ccccc67)cc6ccccc56)cc4)c3)cc2)cc1]

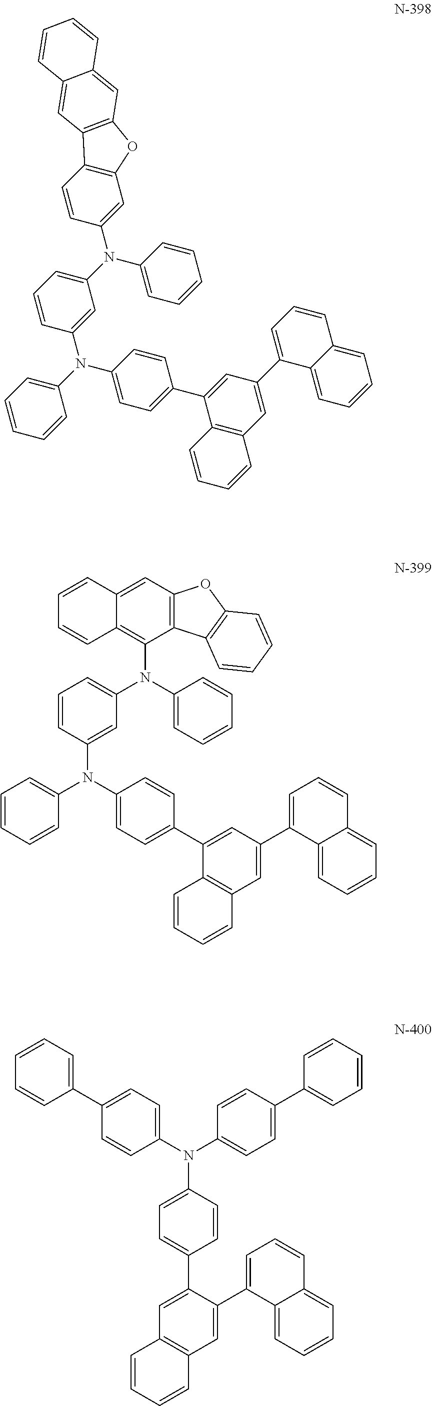 [SMILES: c1ccc(N(c2ccc(-c3cc(-c4cccc5ccccc45)cc4ccccc34)cc2)c2cccc(N(c3ccccc3)c3ccc4c(c3)oc3cc5ccccc5cc34)c2)cc1 ; c1ccc(N(c2ccc(-c3cc(-c4cccc5ccccc45)cc4ccccc34)cc2)c2cccc(N(c3ccccc3)c3c4ccccc4cc4oc5ccccc5c34)c2)cc1 ; c1ccc(-c2ccc(N(c3ccc(-c4ccccc4)cc3)c3ccc(-c4cc5ccccc5cc4-c4cccc5ccccc45)cc3)cc2)cc1]

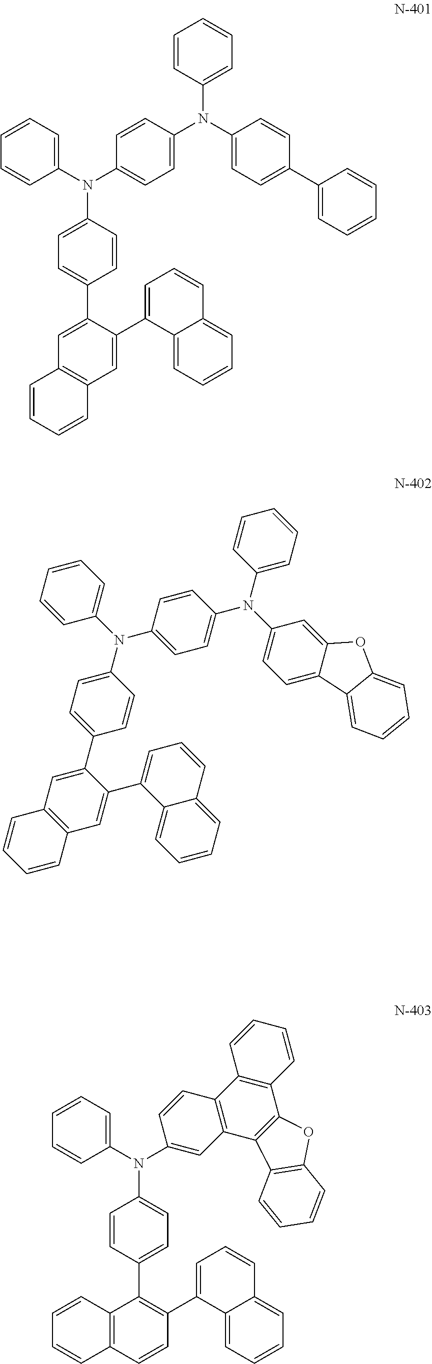 [SMILES: c1ccc(-c2ccc(N(c3ccccc3)c3ccc(N(c4ccccc4)c4ccc(-c5cc6ccccc6cc5-c5cccc6ccccc56)cc4)cc3)cc2)cc1 ; c1ccc(N(c2ccc(-c3cc4ccccc4cc3-c3cccc4ccccc34)cc2)c2ccc(N(c3ccccc3)c3ccc4c(c3)oc3ccccc34)cc2)cc1 ; c1ccc(N(c2ccc(-c3c(-c4cccc5ccccc45)ccc4ccccc34)cc2)c2ccc3c4ccccc4c4oc5ccccc5c4c3c2)cc1]

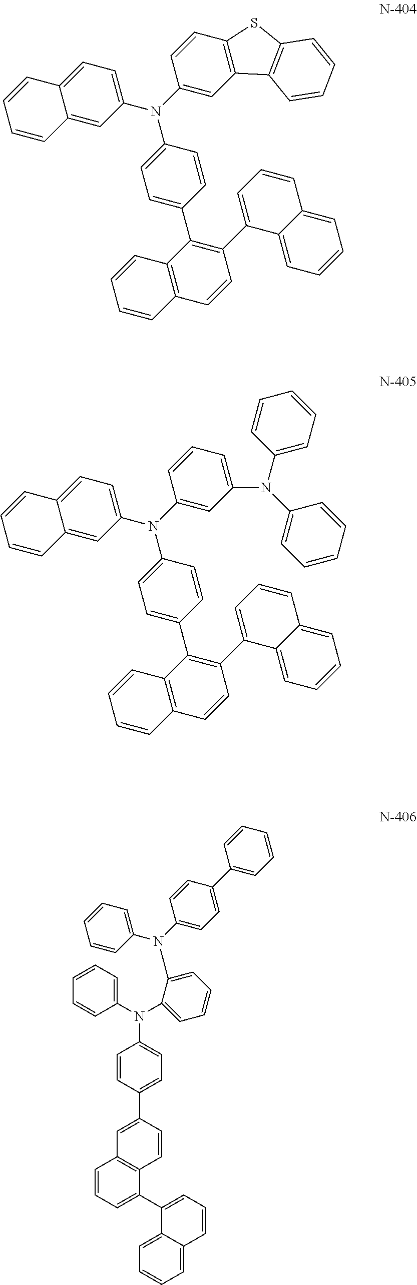 [SMILES: c1ccc2cc(N(c3ccc(-c4c(-c5cccc6ccccc56)ccc5ccccc45)cc3)c3ccc4sc5ccccc5c4c3)ccc2c1 ; c1ccc(N(c2ccccc2)c2cccc(N(c3ccc(-c4c(-c5cccc6ccccc56)ccc5ccccc45)cc3)c3ccc4ccccc4c3)c2)cc1 ; c1ccc(-c2ccc(N(c3ccccc3)c3ccccc3N(c3ccccc3)c3ccc(-c4ccc5c(-c6cccc7ccccc67)cccc5c4)cc3)cc2)cc1]

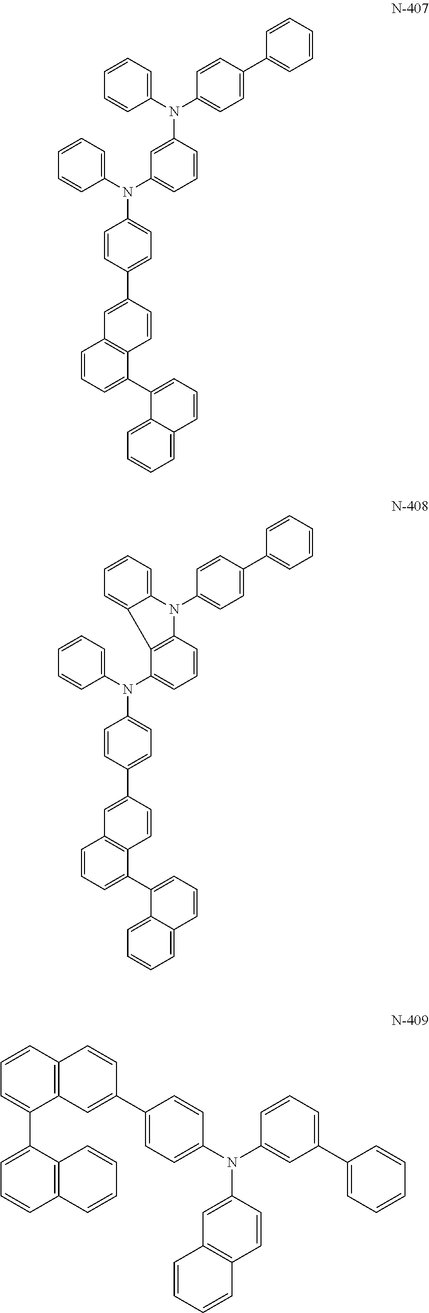 [SMILES: c1ccc(-c2ccc(N(c3ccccc3)c3cccc(N(c4ccccc4)c4ccc(-c5ccc6c(-c7cccc8ccccc78)cccc6c5)cc4)c3)cc2)cc1 ; c1ccc(-c2ccc(-n3c4ccccc4c4c(N(c5ccccc5)c5ccc(-c6ccc7c(-c8cccc9ccccc89)cccc7c6)cc5)cccc43)cc2)cc1 ; c1ccc(-c2cccc(N(c3ccc(-c4ccc5cccc(-c6cccc7ccccc67)c5c4)cc3)c3ccc4ccccc4c3)c2)cc1]

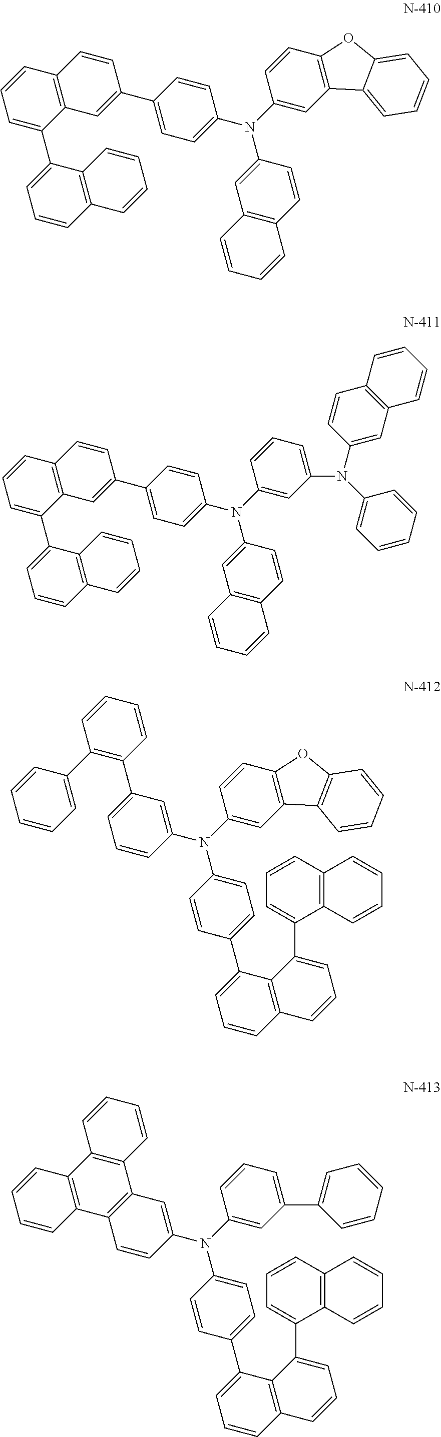 [SMILES: c1ccc2cc(N(c3ccc(-c4ccc5cccc(-c6cccc7ccccc67)c5c4)cc3)c3ccc4oc5ccccc5c4c3)ccc2c1 ; c1ccc(N(c2cccc(N(c3ccc(-c4ccc5cccc(-c6cccc7ccccc67)c5c4)cc3)c3ccc4ccccc4c3)c2)c2ccc3ccccc3c2)cc1 ; c1ccc(-c2ccccc2-c2cccc(N(c3ccc(-c4cccc5cccc(-c6cccc7ccccc67)c45)cc3)c3ccc4oc5ccccc5c4c3)c2)cc1 ; c1ccc(-c2cccc(N(c3ccc(-c4cccc5cccc(-c6cccc7ccccc67)c45)cc3)c3ccc4c5ccccc5c5ccccc5c4c3)c2)cc1]

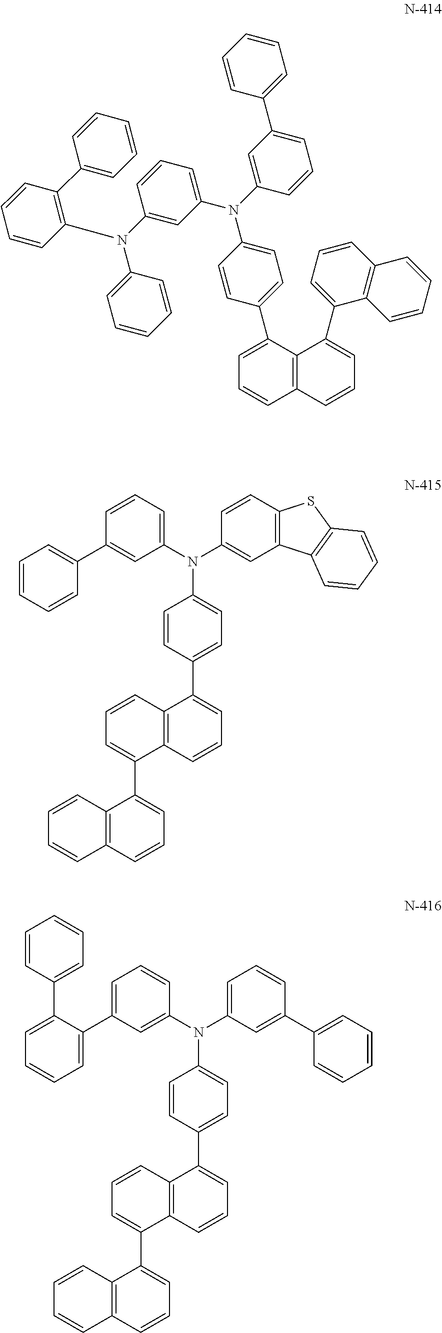 [SMILES: c1ccc(-c2cccc(N(c3ccc(-c4cccc5cccc(-c6cccc7ccccc67)c45)cc3)c3cccc(N(c4ccccc4)c4ccccc4-c4ccccc4)c3)c2)cc1 ; c1ccc(-c2cccc(N(c3ccc(-c4cccc5c(-c6cccc7ccccc67)cccc45)cc3)c3ccc4sc5ccccc5c4c3)c2)cc1 ; c1ccc(-c2cccc(N(c3ccc(-c4cccc5c(-c6cccc7ccccc67)cccc45)cc3)c3cccc(-c4ccccc4-c4ccccc4)c3)c2)cc1]

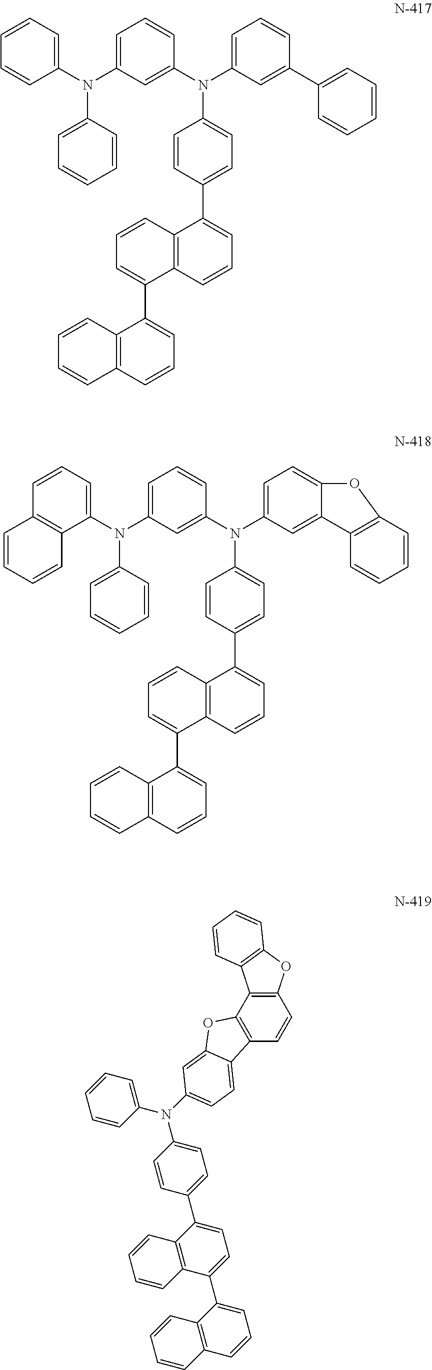 [SMILES: c1ccc(-c2cccc(N(c3ccc(-c4cccc5c(-c6cccc7ccccc67)cccc45)cc3)c3cccc(N(c4ccccc4)c4ccccc4)c3)c2)cc1 ; c1ccc(N(c2cccc(N(c3ccc(-c4cccc5c(-c6cccc7ccccc67)cccc45)cc3)c3ccc4oc5ccccc5c4c3)c2)c2cccc3ccccc23)cc1 ; c1ccc(N(c2ccc(-c3ccc(-c4cccc5ccccc45)c4ccccc34)cc2)c2ccc3c(c2)oc2c3ccc3oc4ccccc4c32)cc1]

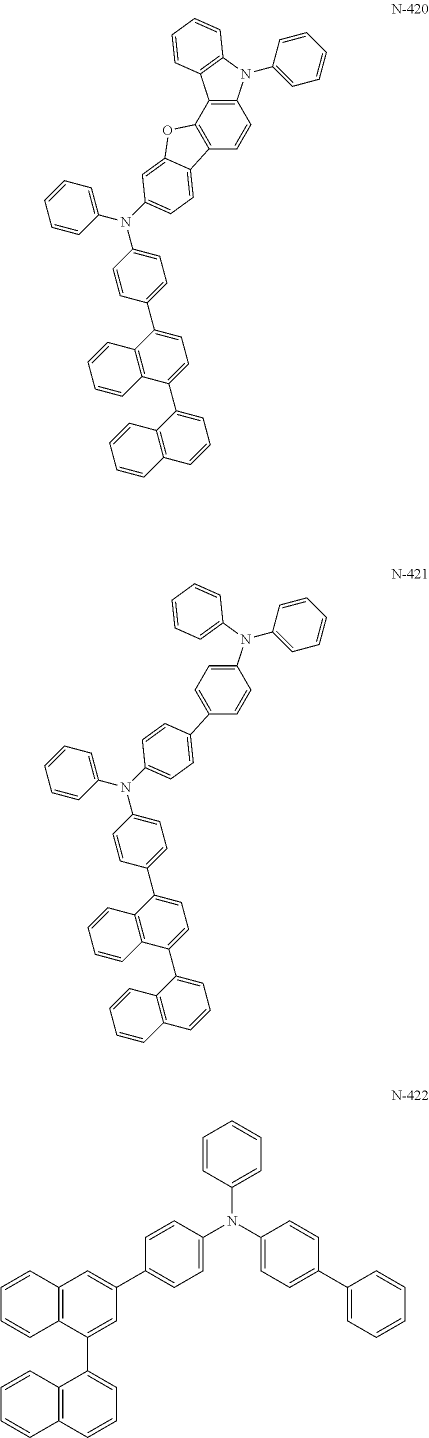 [SMILES: c1ccc(N(c2ccc(-c3ccc(-c4cccc5ccccc45)c4ccccc34)cc2)c2ccc3c(c2)oc2c3ccc3c2c2ccccc2n3-c2ccccc2)cc1 ; c1ccc(N(c2ccccc2)c2ccc(-c3ccc(N(c4ccccc4)c4ccc(-c5ccc(-c6cccc7ccccc67)c6ccccc56)cc4)cc3)cc2)cc1 ; c1ccc(-c2ccc(N(c3ccccc3)c3ccc(-c4cc(-c5cccc6ccccc56)c5ccccc5c4)cc3)cc2)cc1]

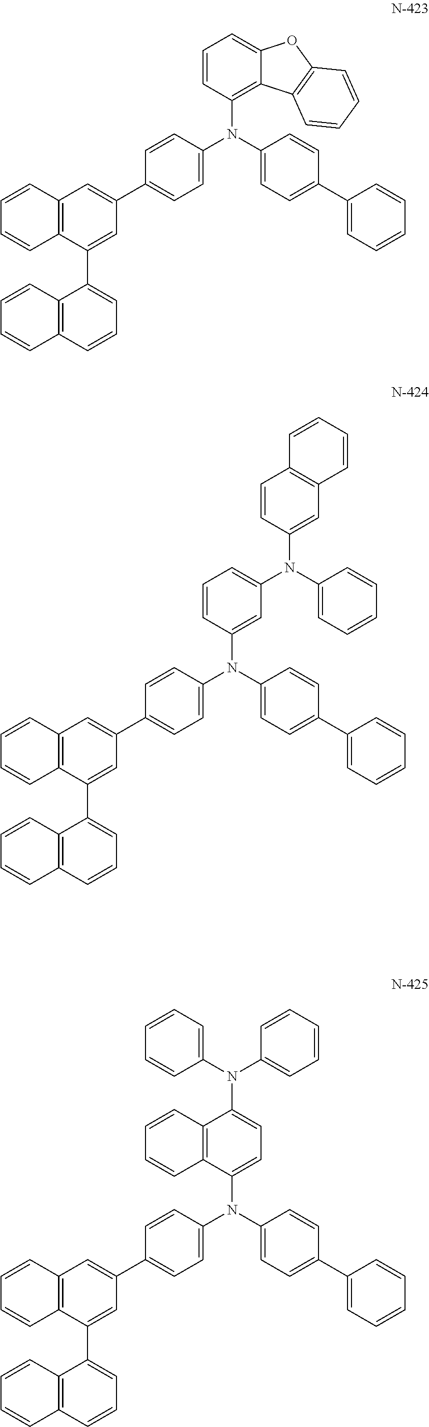 [SMILES: c1ccc(-c2ccc(N(c3ccc(-c4cc(-c5cccc6ccccc56)c5ccccc5c4)cc3)c3cccc4oc5ccccc5c34)cc2)cc1 ; c1ccc(-c2ccc(N(c3ccc(-c4cc(-c5cccc6ccccc56)c5ccccc5c4)cc3)c3cccc(N(c4ccccc4)c4ccc5ccccc5c4)c3)cc2)cc1 ; c1ccc(-c2ccc(N(c3ccc(-c4cc(-c5cccc6ccccc56)c5ccccc5c4)cc3)c3ccc(N(c4ccccc4)c4ccccc4)c4ccccc34)cc2)cc1]

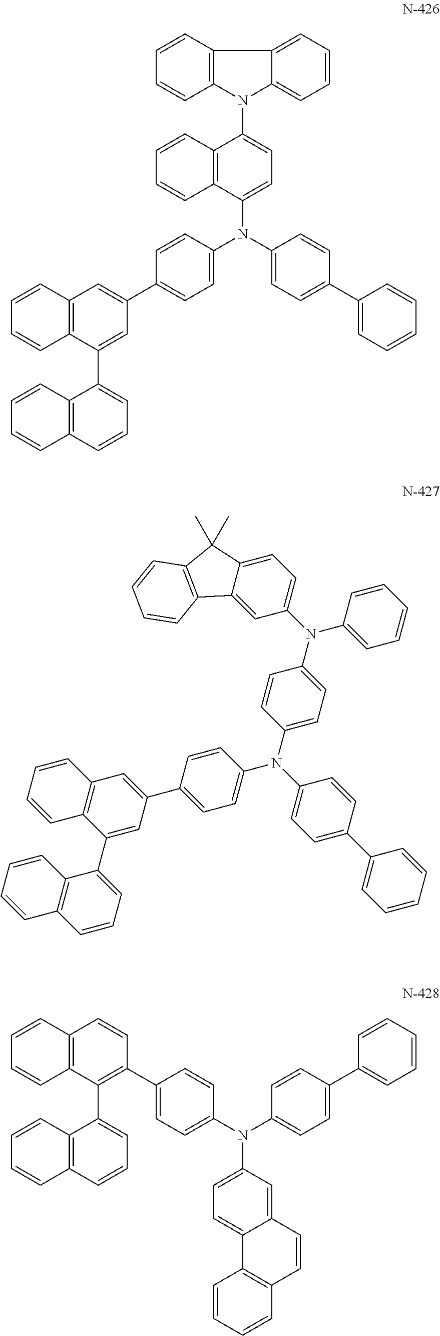 [SMILES: c1ccc(-c2ccc(N(c3ccc(-c4cc(-c5cccc6ccccc56)c5ccccc5c4)cc3)c3ccc(-n4c5ccccc5c5ccccc54)c4ccccc34)cc2)cc1 ; CC1(C)c2ccccc2-c2cc(N(c3ccccc3)c3ccc(N(c4ccc(-c5ccccc5)cc4)c4ccc(-c5cc(-c6cccc7ccccc67)c6ccccc6c5)cc4)cc3)ccc21 ; c1ccc(-c2ccc(N(c3ccc(-c4ccc5ccccc5c4-c4cccc5ccccc45)cc3)c3ccc4c(ccc5ccccc54)c3)cc2)cc1]

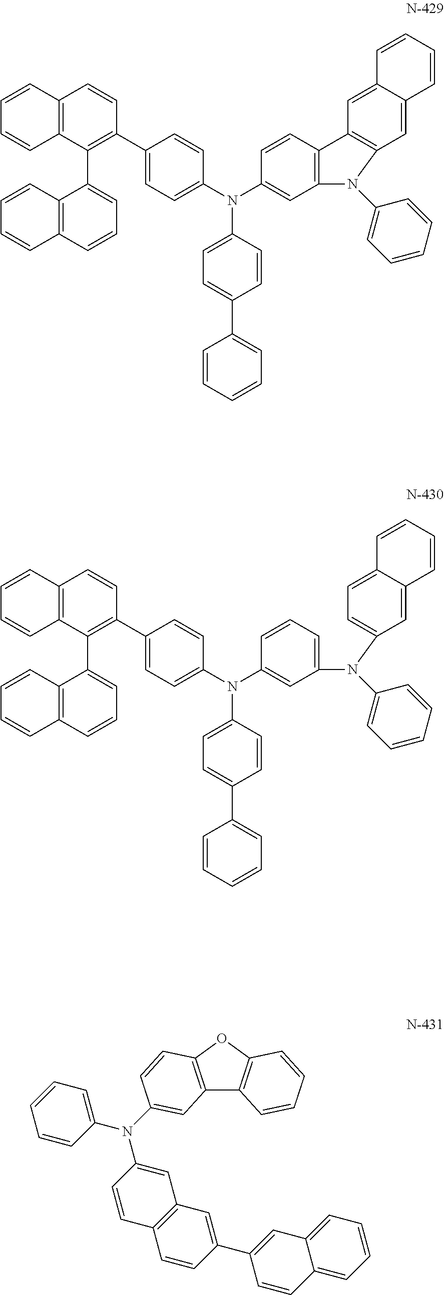 [SMILES: c1ccc(-c2ccc(N(c3ccc(-c4ccc5ccccc5c4-c4cccc5ccccc45)cc3)c3ccc4c5cc6ccccc6cc5n(-c5ccccc5)c4c3)cc2)cc1 ; c1ccc(-c2ccc(N(c3ccc(-c4ccc5ccccc5c4-c4cccc5ccccc45)cc3)c3cccc(N(c4ccccc4)c4ccc5ccccc5c4)c3)cc2)cc1 ; c1ccc(N(c2ccc3ccc(-c4ccc5ccccc5c4)cc3c2)c2ccc3oc4ccccc4c3c2)cc1]

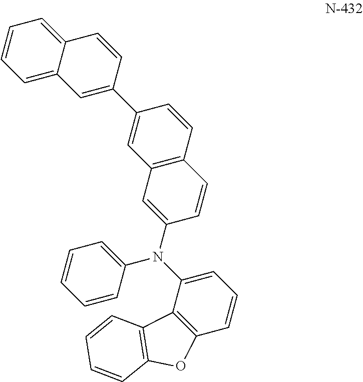 [SMILES: c1ccc(N(c2ccc3ccc(-c4ccc5ccccc5c4)cc3c2)c2cccc3oc4ccccc4c23)cc1]

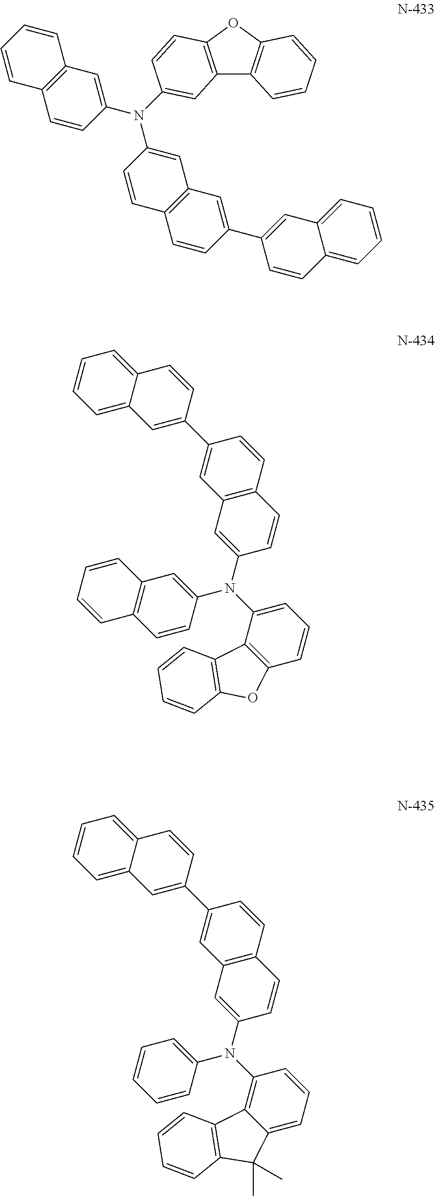 [SMILES: c1ccc2cc(-c3ccc4ccc(N(c5ccc6ccccc6c5)c5ccc6oc7ccccc7c6c5)cc4c3)ccc2c1 ; c1ccc2cc(-c3ccc4ccc(N(c5ccc6ccccc6c5)c5cccc6oc7ccccc7c56)cc4c3)ccc2c1 ; CC1(C)c2ccccc2-c2c(N(c3ccccc3)c3ccc4ccc(-c5ccc6ccccc6c5)cc4c3)cccc21]

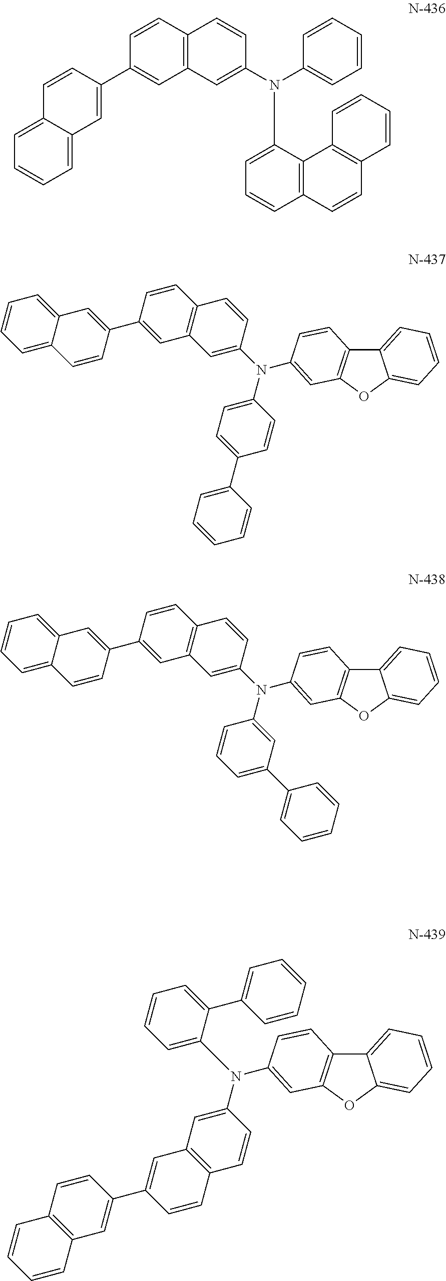 [SMILES: c1ccc(N(c2ccc3ccc(-c4ccc5ccccc5c4)cc3c2)c2cccc3ccc4ccccc4c23)cc1 ; c1ccc(-c2ccc(N(c3ccc4ccc(-c5ccc6ccccc6c5)cc4c3)c3ccc4c(c3)oc3ccccc34)cc2)cc1 ; c1ccc(-c2cccc(N(c3ccc4ccc(-c5ccc6ccccc6c5)cc4c3)c3ccc4c(c3)oc3ccccc34)c2)cc1 ; c1ccc(-c2ccccc2N(c2ccc3ccc(-c4ccc5ccccc5c4)cc3c2)c2ccc3c(c2)oc2ccccc23)cc1]

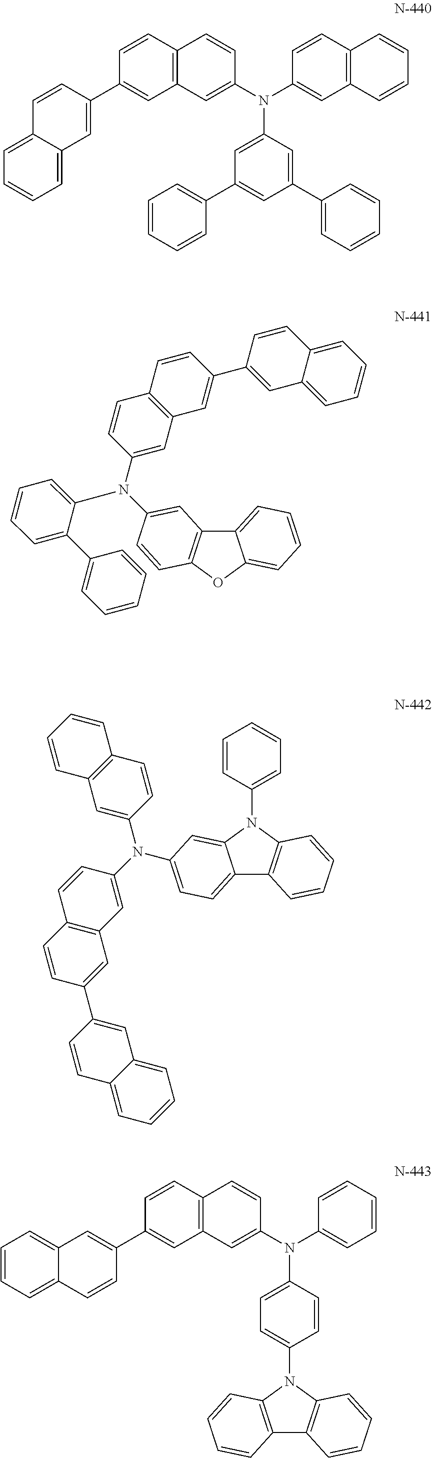 [SMILES: c1ccc(-c2cc(-c3ccccc3)cc(N(c3ccc4ccccc4c3)c3ccc4ccc(-c5ccc6ccccc6c5)cc4c3)c2)cc1 ; c1ccc(-c2ccccc2N(c2ccc3ccc(-c4ccc5ccccc5c4)cc3c2)c2ccc3oc4ccccc4c3c2)cc1 ; c1ccc(-n2c3ccccc3c3ccc(N(c4ccc5ccccc5c4)c4ccc5ccc(-c6ccc7ccccc7c6)cc5c4)cc32)cc1 ; c1ccc(N(c2ccc(-n3c4ccccc4c4ccccc43)cc2)c2ccc3ccc(-c4ccc5ccccc5c4)cc3c2)cc1]

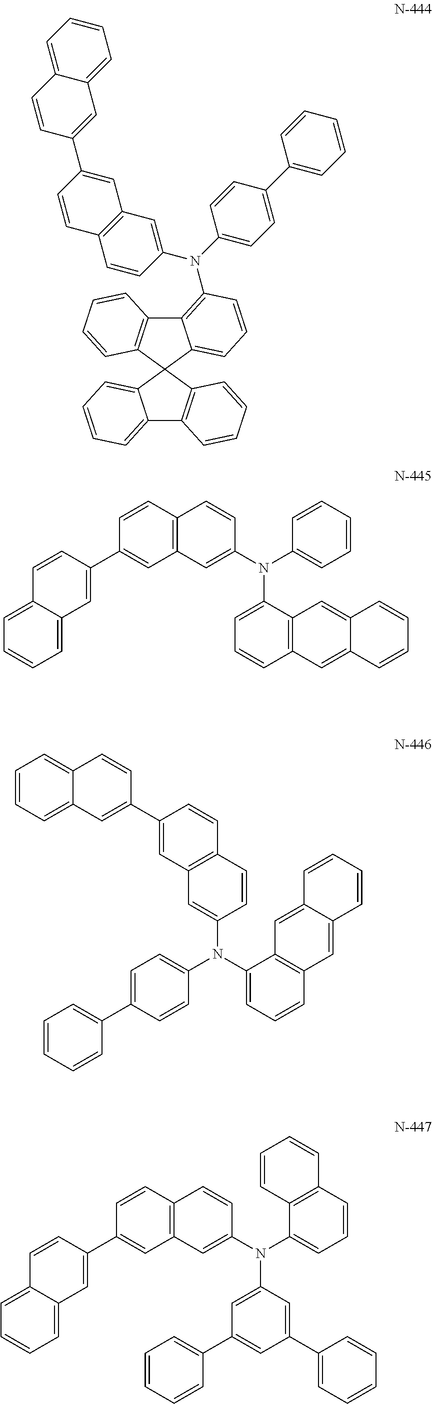 [SMILES: c1ccc(-c2ccc(N(c3ccc4ccc(-c5ccc6ccccc6c5)cc4c3)c3cccc4c3-c3ccccc3C43c4ccccc4-c4ccccc43)cc2)cc1 ; c1ccc(N(c2ccc3ccc(-c4ccc5ccccc5c4)cc3c2)c2cccc3cc4ccccc4cc23)cc1 ; c1ccc(-c2ccc(N(c3ccc4ccc(-c5ccc6ccccc6c5)cc4c3)c3cccc4cc5ccccc5cc34)cc2)cc1 ; c1ccc(-c2cc(-c3ccccc3)cc(N(c3ccc4ccc(-c5ccc6ccccc6c5)cc4c3)c3cccc4ccccc34)c2)cc1]

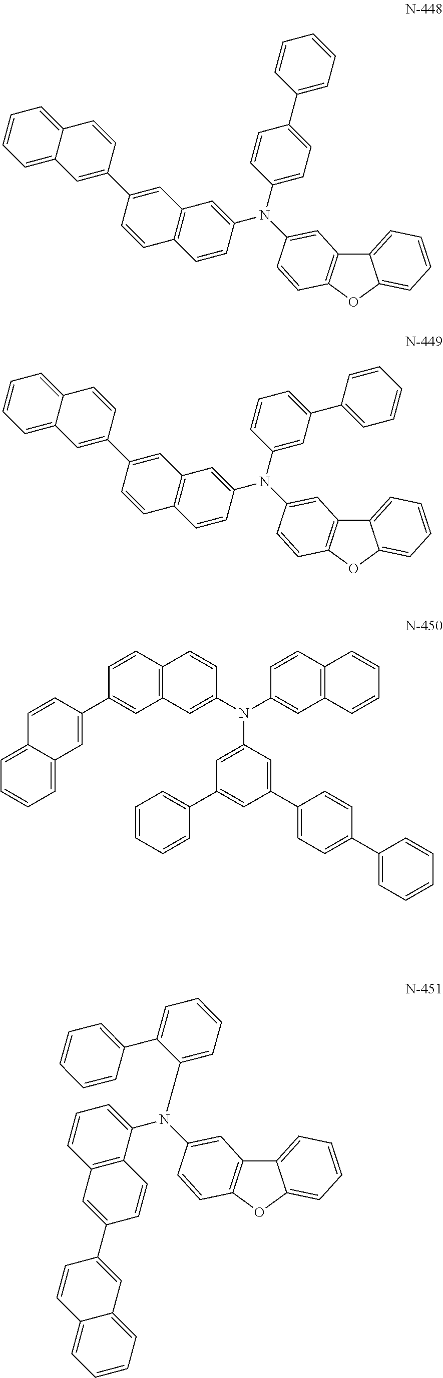 [SMILES: c1ccc(-c2ccc(N(c3ccc4ccc(-c5ccc6ccccc6c5)cc4c3)c3ccc4oc5ccccc5c4c3)cc2)cc1 ; c1ccc(-c2cccc(N(c3ccc4ccc(-c5ccc6ccccc6c5)cc4c3)c3ccc4oc5ccccc5c4c3)c2)cc1 ; c1ccc(-c2ccc(-c3cc(-c4ccccc4)cc(N(c4ccc5ccccc5c4)c4ccc5ccc(-c6ccc7ccccc7c6)cc5c4)c3)cc2)cc1 ; c1ccc(-c2ccccc2N(c2ccc3oc4ccccc4c3c2)c2cccc3cc(-c4ccc5ccccc5c4)ccc23)cc1]

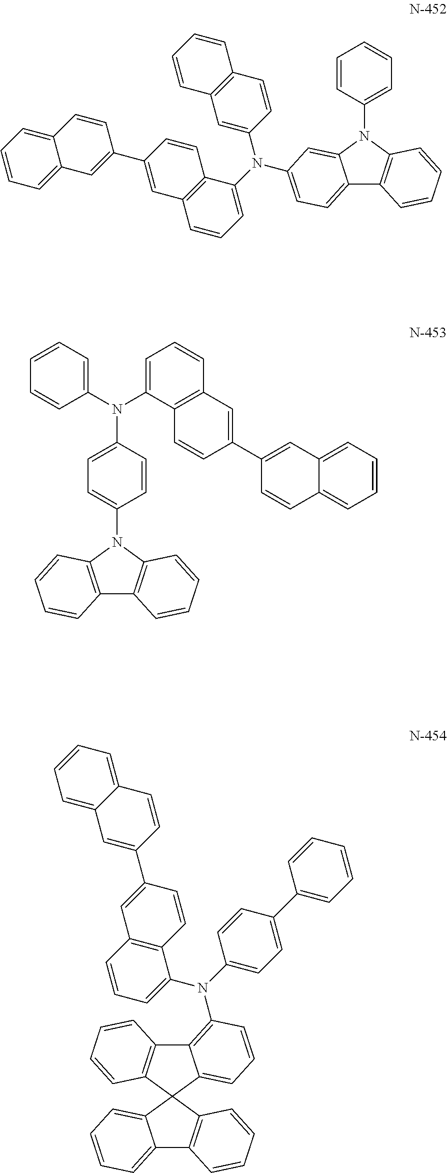 [SMILES: c1ccc(-n2c3ccccc3c3ccc(N(c4ccc5ccccc5c4)c4cccc5cc(-c6ccc7ccccc7c6)ccc45)cc32)cc1 ; c1ccc(N(c2ccc(-n3c4ccccc4c4ccccc43)cc2)c2cccc3cc(-c4ccc5ccccc5c4)ccc23)cc1 ; c1ccc(-c2ccc(N(c3cccc4c3-c3ccccc3C43c4ccccc4-c4ccccc43)c3cccc4cc(-c5ccc6ccccc6c5)ccc34)cc2)cc1]

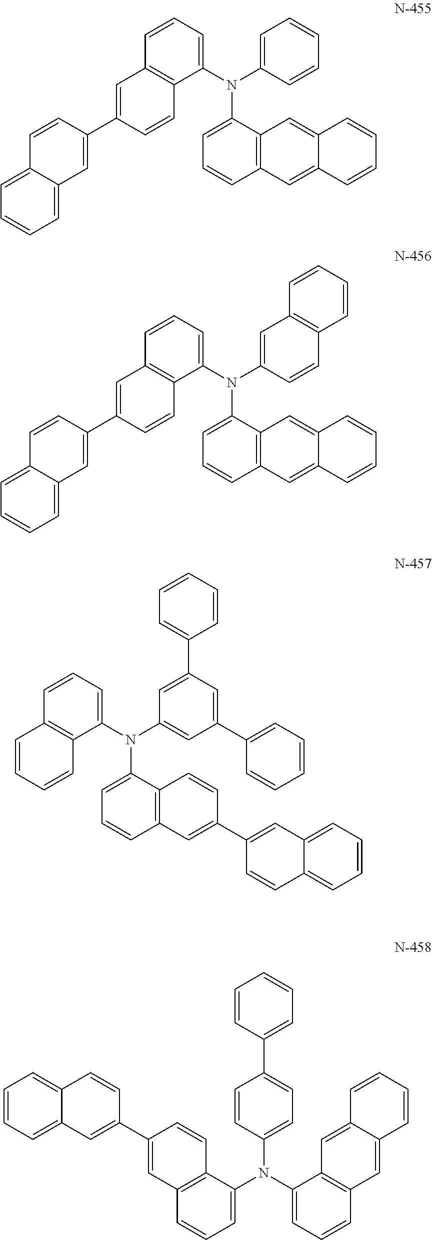 [SMILES: c1ccc(N(c2cccc3cc(-c4ccc5ccccc5c4)ccc23)c2cccc3cc4ccccc4cc23)cc1 ; c1ccc2cc(-c3ccc4c(N(c5ccc6ccccc6c5)c5cccc6cc7ccccc7cc56)cccc4c3)ccc2c1 ; c1ccc(-c2cc(-c3ccccc3)cc(N(c3cccc4ccccc34)c3cccc4cc(-c5ccc6ccccc6c5)ccc34)c2)cc1 ; c1ccc(-c2ccc(N(c3cccc4cc(-c5ccc6ccccc6c5)ccc34)c3cccc4cc5ccccc5cc34)cc2)cc1]

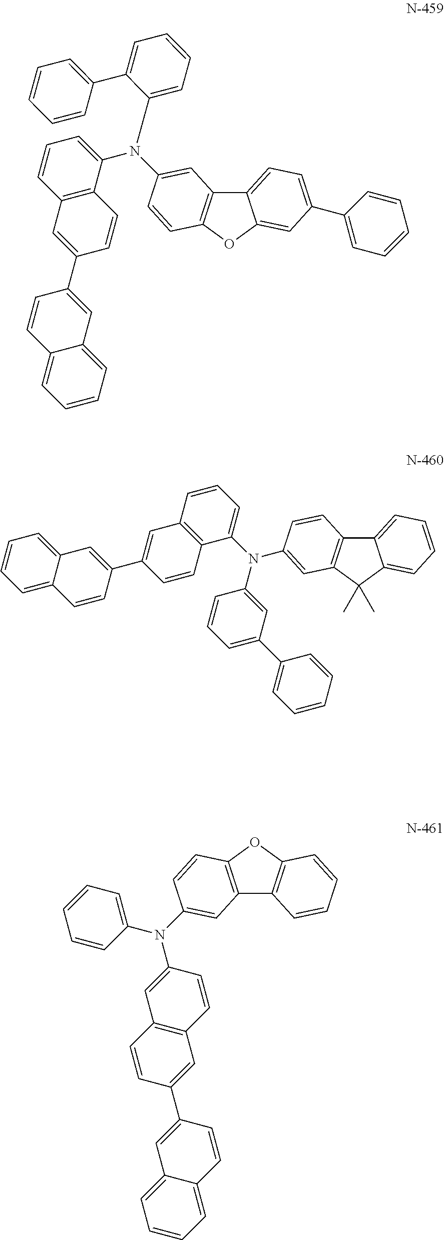 [SMILES: c1ccc(-c2ccc3c(c2)oc2ccc(N(c4ccccc4-c4ccccc4)c4cccc5cc(-c6ccc7ccccc7c6)ccc45)cc23)cc1 ; CC1(C)c2ccccc2-c2ccc(N(c3cccc(-c4ccccc4)c3)c3cccc4cc(-c5ccc6ccccc6c5)ccc34)cc21 ; c1ccc(N(c2ccc3cc(-c4ccc5ccccc5c4)ccc3c2)c2ccc3oc4ccccc4c3c2)cc1]

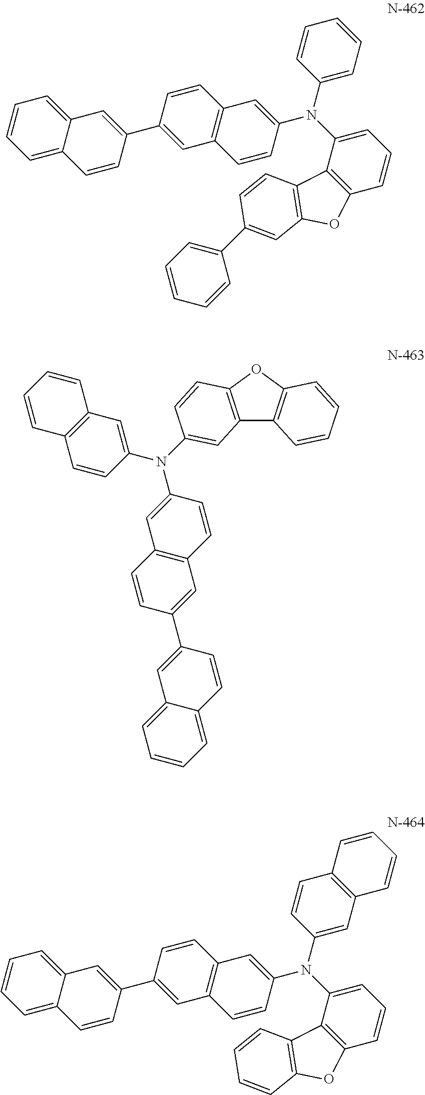 [SMILES: c1ccc(-c2ccc3c(c2)oc2cccc(N(c4ccccc4)c4ccc5cc(-c6ccc7ccccc7c6)ccc5c4)c23)cc1 ; c1ccc2cc(-c3ccc4cc(N(c5ccc6ccccc6c5)c5ccc6oc7ccccc7c6c5)ccc4c3)ccc2c1 ; c1ccc2cc(-c3ccc4cc(N(c5ccc6ccccc6c5)c5cccc6oc7ccccc7c56)ccc4c3)ccc2c1]

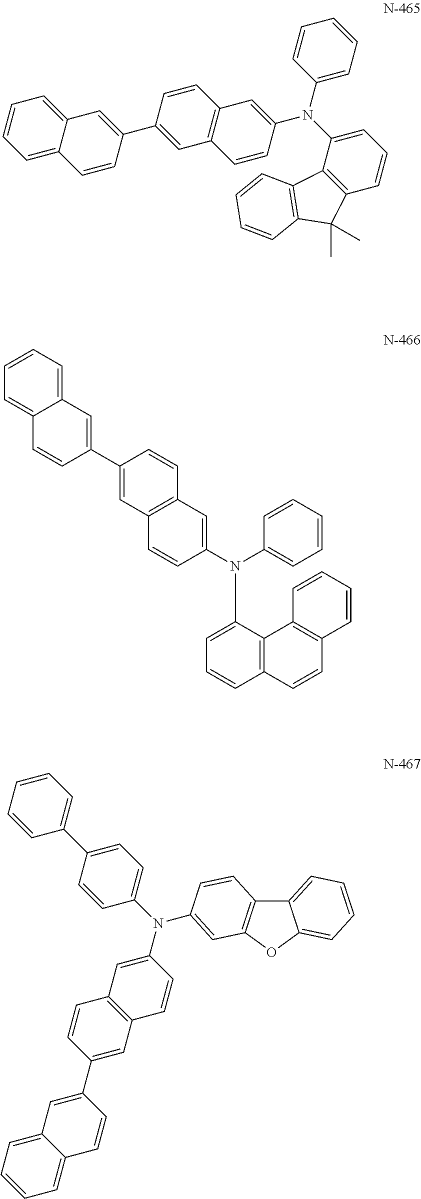 [SMILES: CC1(C)c2ccccc2-c2c(N(c3ccccc3)c3ccc4cc(-c5ccc6ccccc6c5)ccc4c3)cccc21 ; c1ccc(N(c2ccc3cc(-c4ccc5ccccc5c4)ccc3c2)c2cccc3ccc4ccccc4c23)cc1 ; c1ccc(-c2ccc(N(c3ccc4cc(-c5ccc6ccccc6c5)ccc4c3)c3ccc4c(c3)oc3ccccc34)cc2)cc1]

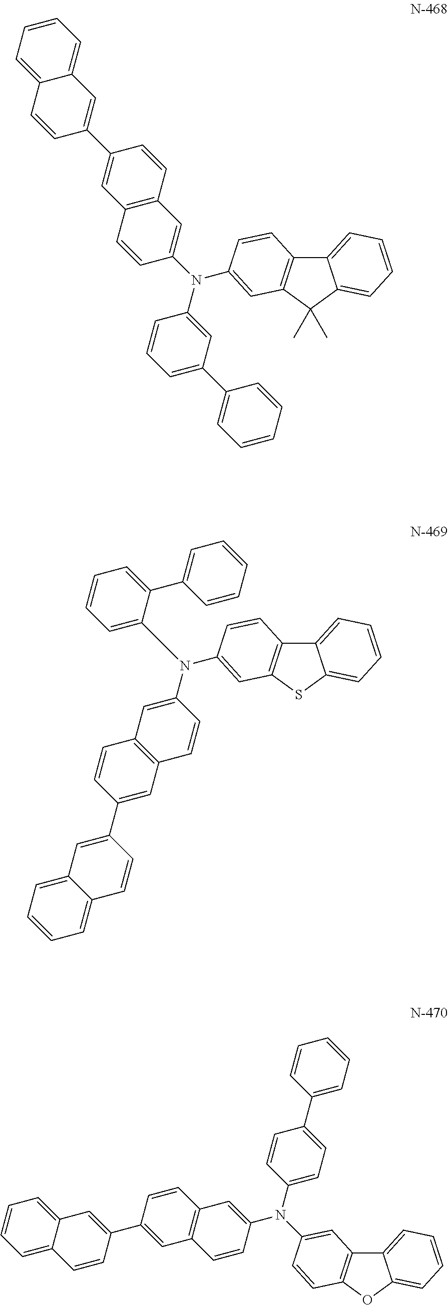 [SMILES: CC1(C)c2ccccc2-c2ccc(N(c3cccc(-c4ccccc4)c3)c3ccc4cc(-c5ccc6ccccc6c5)ccc4c3)cc21 ; c1ccc(-c2ccccc2N(c2ccc3cc(-c4ccc5ccccc5c4)ccc3c2)c2ccc3c(c2)sc2ccccc23)cc1 ; c1ccc(-c2ccc(N(c3ccc4cc(-c5ccc6ccccc6c5)ccc4c3)c3ccc4oc5ccccc5c4c3)cc2)cc1]

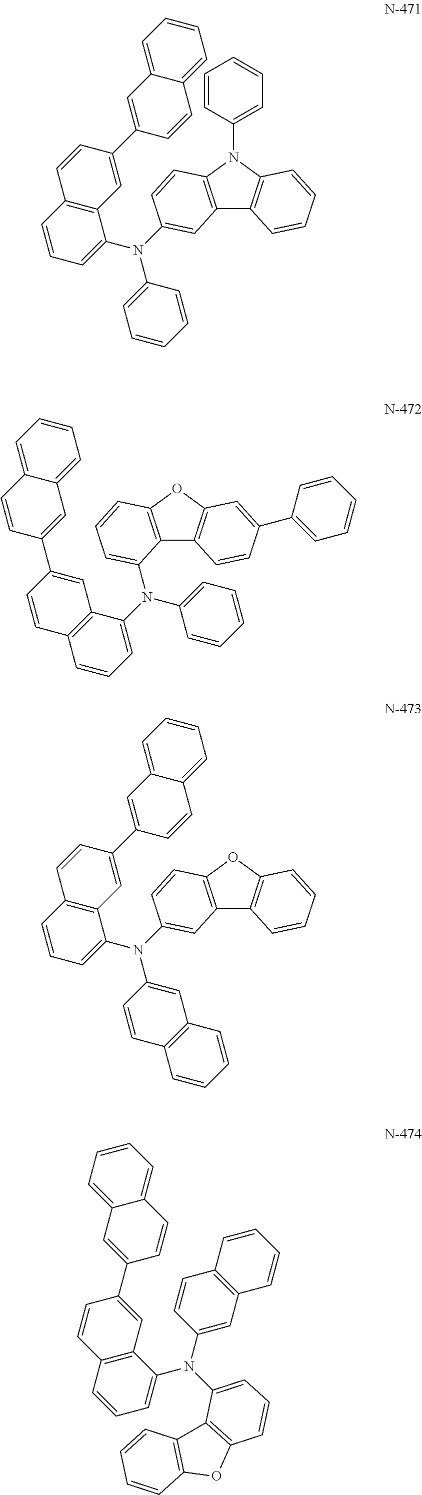 [SMILES: c1ccc(N(c2ccc3c(c2)c2ccccc2n3-c2ccccc2)c2cccc3ccc(-c4ccc5ccccc5c4)cc23)cc1 ; c1ccc(-c2ccc3c(c2)oc2cccc(N(c4ccccc4)c4cccc5ccc(-c6ccc7ccccc7c6)cc45)c23)cc1 ; c1ccc2cc(-c3ccc4cccc(N(c5ccc6ccccc6c5)c5ccc6oc7ccccc7c6c5)c4c3)ccc2c1 ; c1ccc2cc(-c3ccc4cccc(N(c5ccc6ccccc6c5)c5cccc6oc7ccccc7c56)c4c3)ccc2c1]

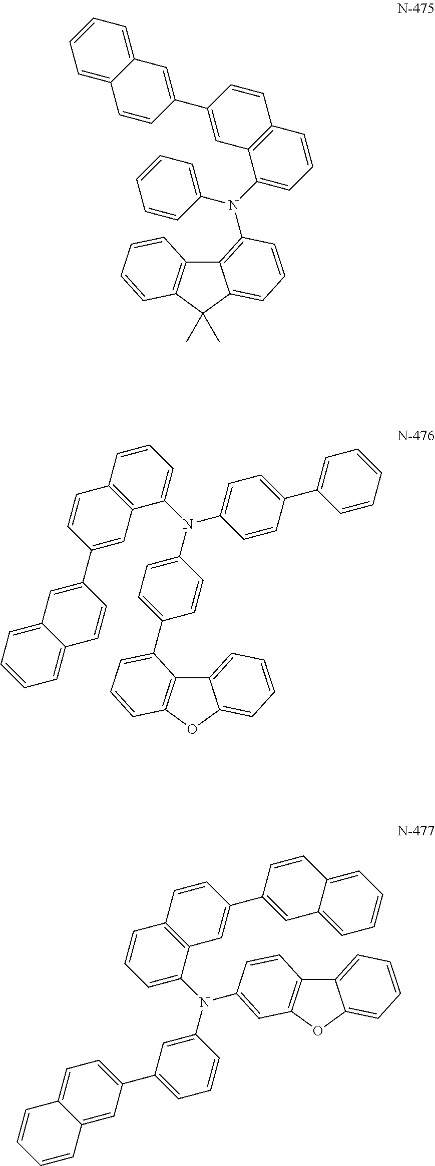 [SMILES: CC1(C)c2ccccc2-c2c(N(c3ccccc3)c3cccc4ccc(-c5ccc6ccccc6c5)cc34)cccc21 ; c1ccc(-c2ccc(N(c3ccc(-c4cccc5oc6ccccc6c45)cc3)c3cccc4ccc(-c5ccc6ccccc6c5)cc34)cc2)cc1 ; c1cc(-c2ccc3ccccc3c2)cc(N(c2ccc3c(c2)oc2ccccc23)c2cccc3ccc(-c4ccc5ccccc5c4)cc23)c1]

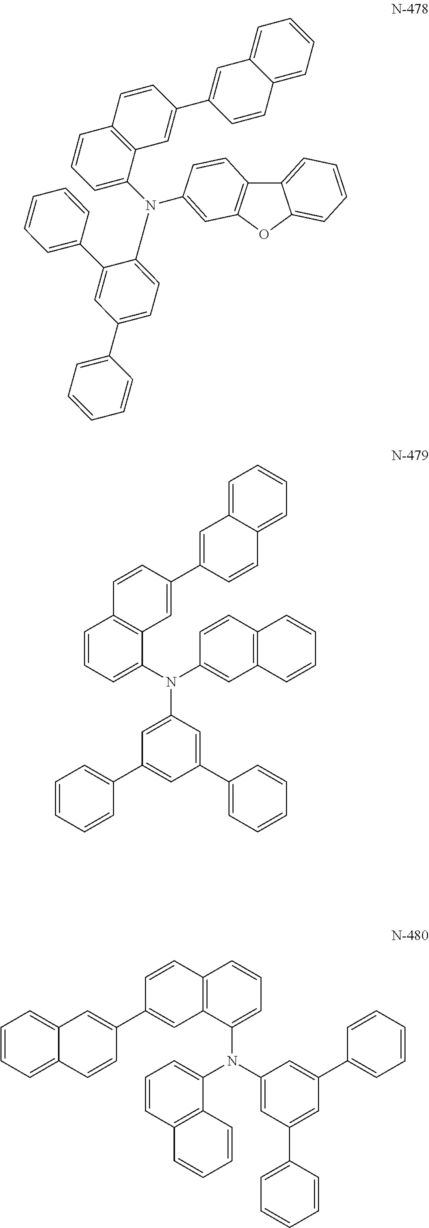 [SMILES: c1ccc(-c2ccc(N(c3ccc4c(c3)oc3ccccc34)c3cccc4ccc(-c5ccc6ccccc6c5)cc34)c(-c3ccccc3)c2)cc1 ; c1ccc(-c2cc(-c3ccccc3)cc(N(c3ccc4ccccc4c3)c3cccc4ccc(-c5ccc6ccccc6c5)cc34)c2)cc1 ; c1ccc(-c2cc(-c3ccccc3)cc(N(c3cccc4ccccc34)c3cccc4ccc(-c5ccc6ccccc6c5)cc34)c2)cc1]

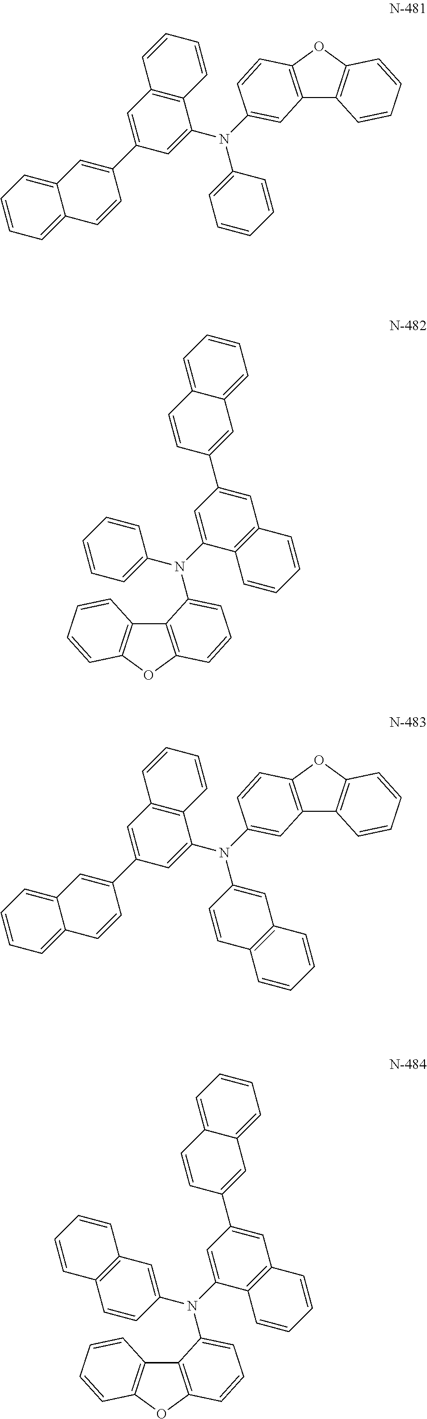 [SMILES: c1ccc(N(c2ccc3oc4ccccc4c3c2)c2cc(-c3ccc4ccccc4c3)cc3ccccc23)cc1 ; c1ccc(N(c2cc(-c3ccc4ccccc4c3)cc3ccccc23)c2cccc3oc4ccccc4c23)cc1 ; c1ccc2cc(-c3cc(N(c4ccc5ccccc5c4)c4ccc5oc6ccccc6c5c4)c4ccccc4c3)ccc2c1 ; c1ccc2cc(-c3cc(N(c4ccc5ccccc5c4)c4cccc5oc6ccccc6c45)c4ccccc4c3)ccc2c1]

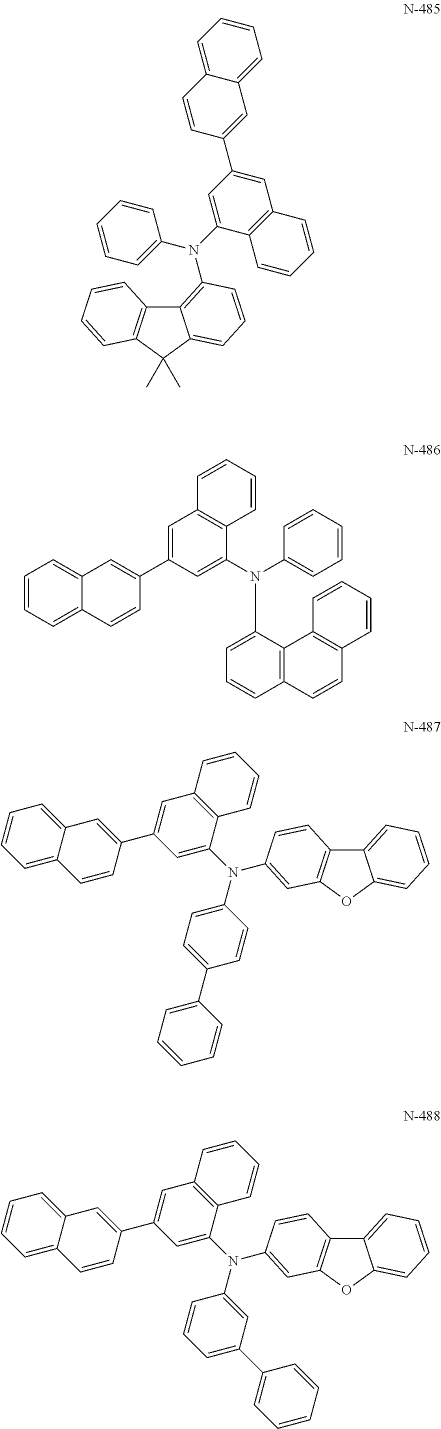 [SMILES: CC1(C)c2ccccc2-c2c(N(c3ccccc3)c3cc(-c4ccc5ccccc5c4)cc4ccccc34)cccc21 ; c1ccc(N(c2cc(-c3ccc4ccccc4c3)cc3ccccc23)c2cccc3ccc4ccccc4c23)cc1 ; c1ccc(-c2ccc(N(c3ccc4c(c3)oc3ccccc34)c3cc(-c4ccc5ccccc5c4)cc4ccccc34)cc2)cc1 ; c1ccc(-c2cccc(N(c3ccc4c(c3)oc3ccccc34)c3cc(-c4ccc5ccccc5c4)cc4ccccc34)c2)cc1]

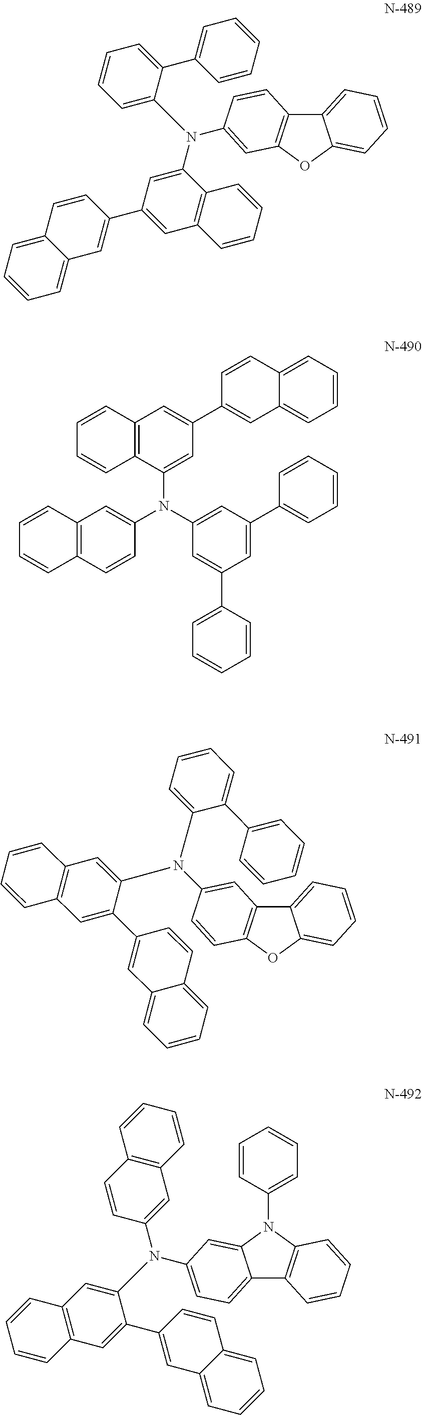 [SMILES: c1ccc(-c2ccccc2N(c2ccc3c(c2)oc2ccccc23)c2cc(-c3ccc4ccccc4c3)cc3ccccc23)cc1 ; c1ccc(-c2cc(-c3ccccc3)cc(N(c3ccc4ccccc4c3)c3cc(-c4ccc5ccccc5c4)cc4ccccc34)c2)cc1 ; c1ccc(-c2ccccc2N(c2ccc3oc4ccccc4c3c2)c2cc3ccccc3cc2-c2ccc3ccccc3c2)cc1 ; c1ccc(-n2c3ccccc3c3ccc(N(c4ccc5ccccc5c4)c4cc5ccccc5cc4-c4ccc5ccccc5c4)cc32)cc1]

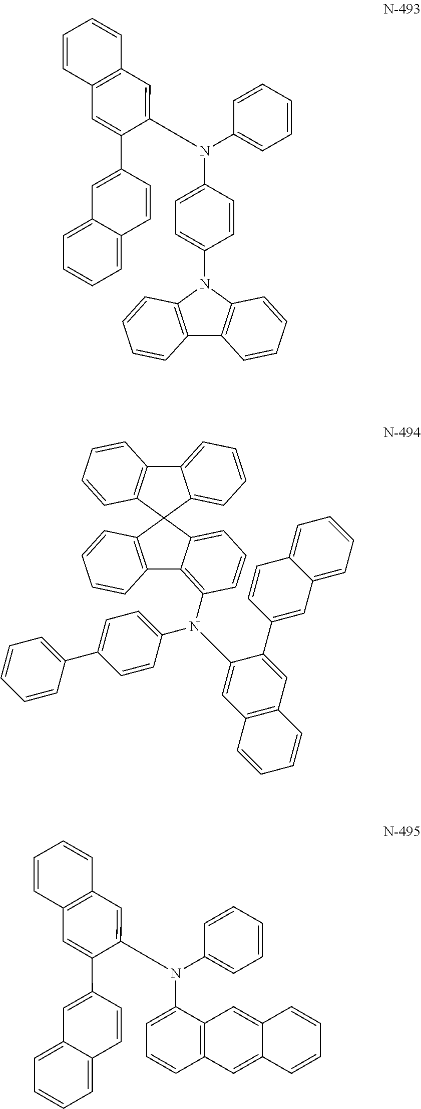 [SMILES: c1ccc(N(c2ccc(-n3c4ccccc4c4ccccc43)cc2)c2cc3ccccc3cc2-c2ccc3ccccc3c2)cc1 ; c1ccc(-c2ccc(N(c3cc4ccccc4cc3-c3ccc4ccccc4c3)c3cccc4c3-c3ccccc3C43c4ccccc4-c4ccccc43)cc2)cc1 ; c1ccc(N(c2cc3ccccc3cc2-c2ccc3ccccc3c2)c2cccc3cc4ccccc4cc23)cc1]

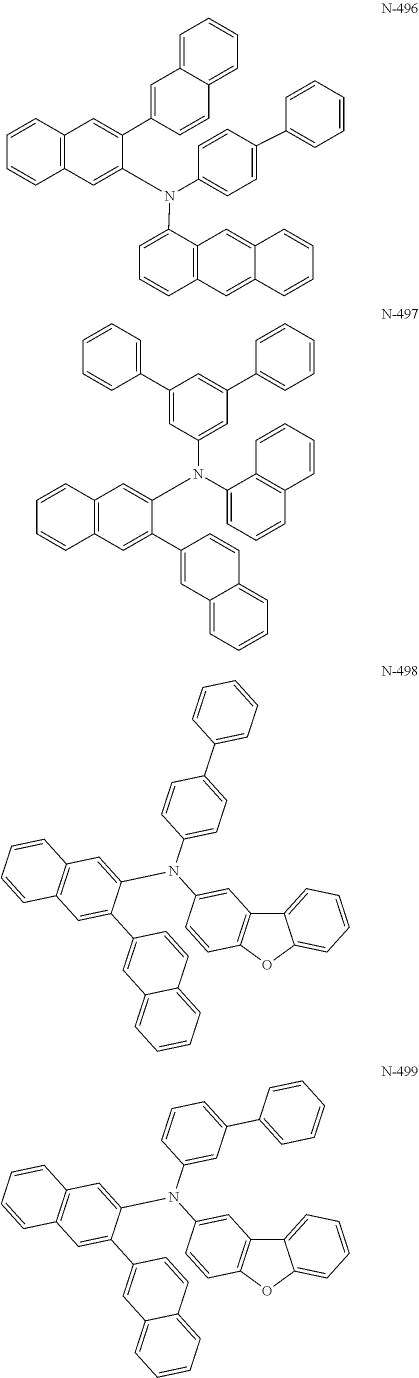

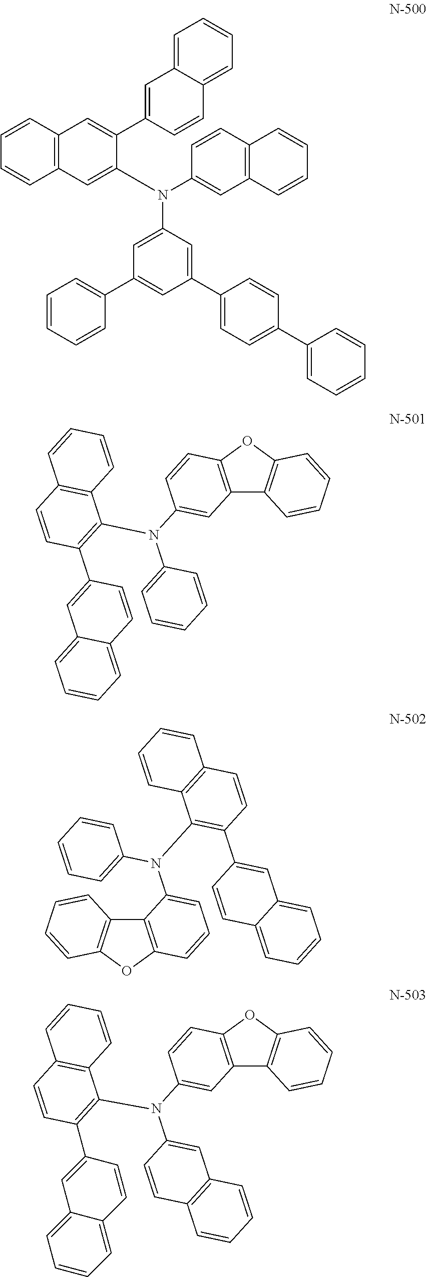

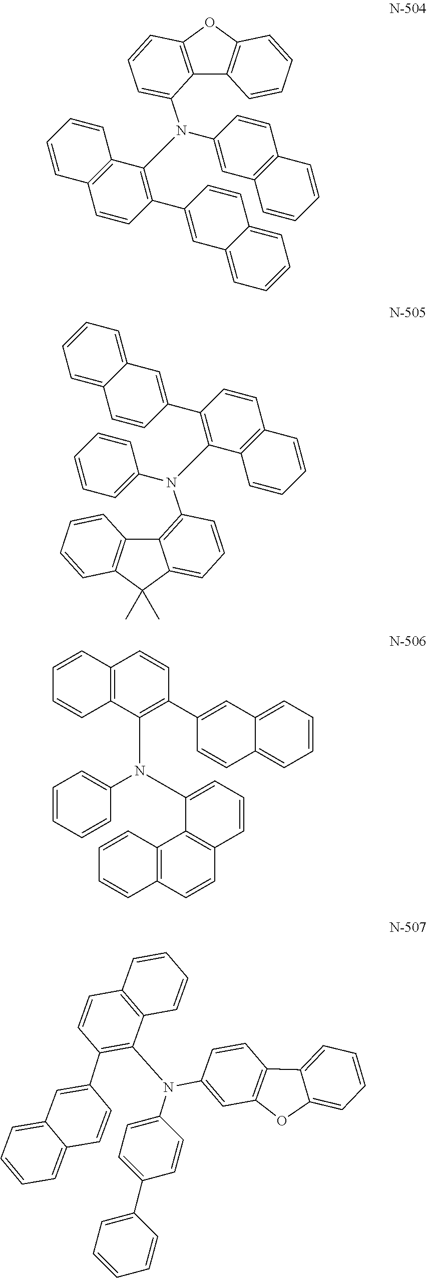

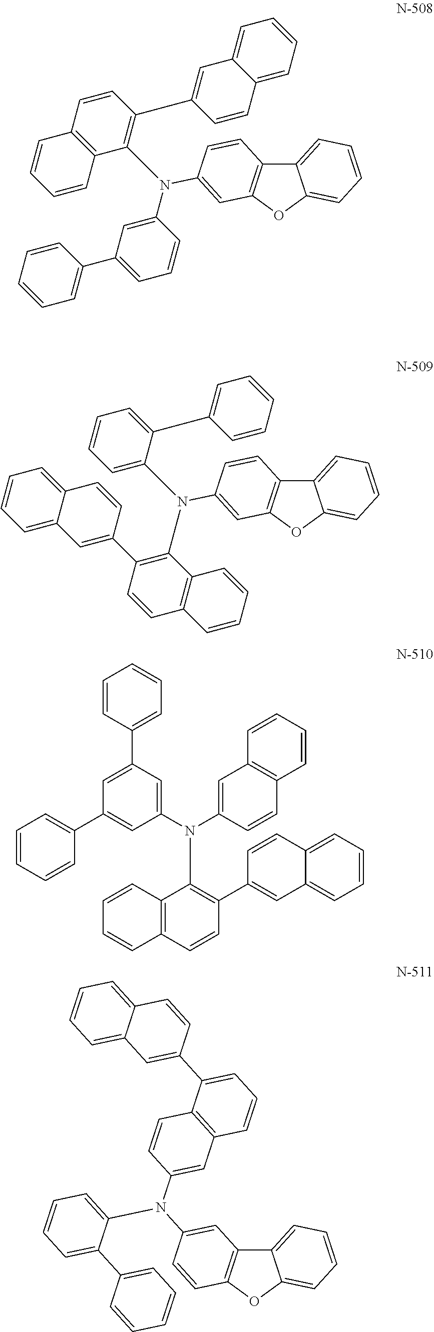

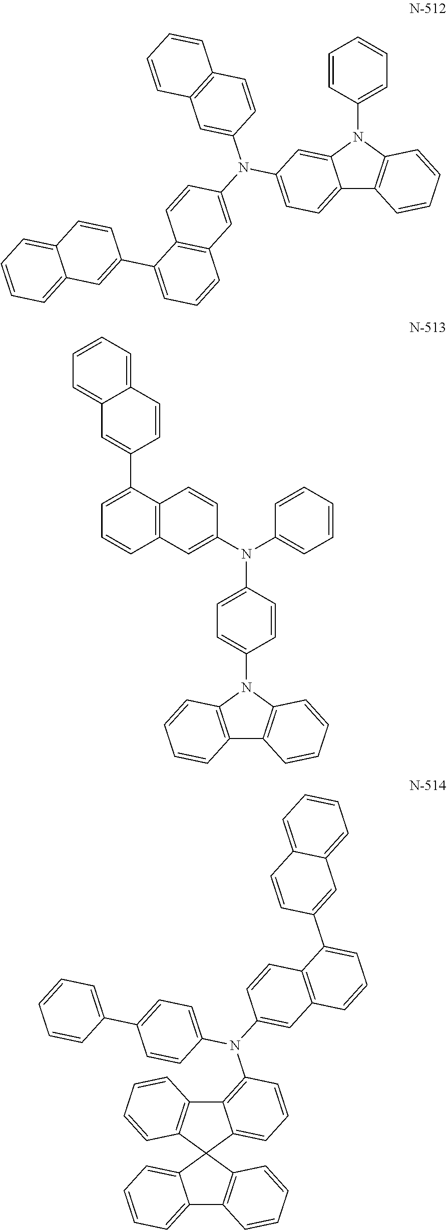

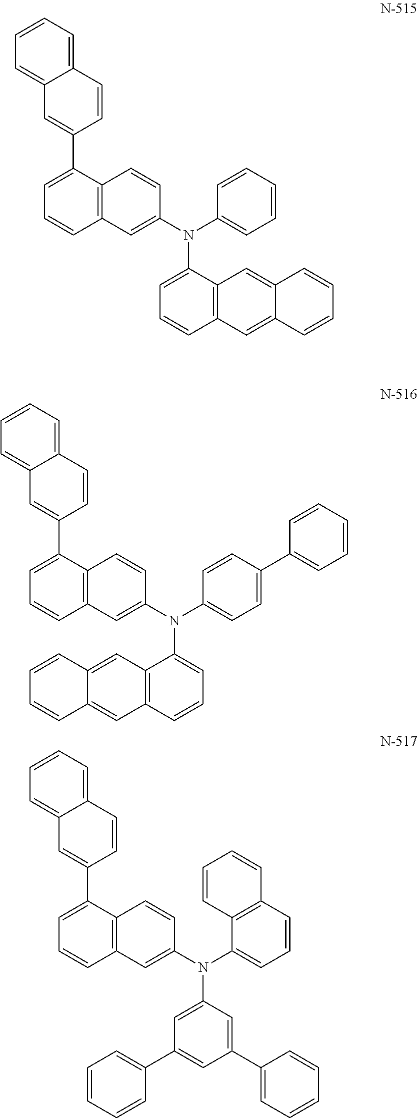

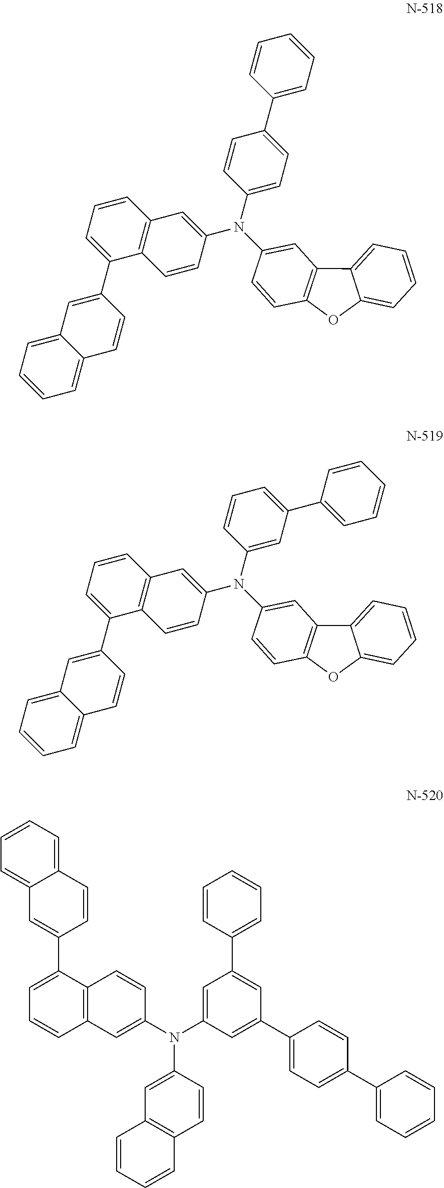 [SMILES: c1ccc(-c2ccc(N(c3ccc4c(-c5ccc6ccccc6c5)cccc4c3)c3ccc4oc5ccccc5c4c3)cc2)cc1 ; c1ccc(-c2cccc(N(c3ccc4c(-c5ccc6ccccc6c5)cccc4c3)c3ccc4oc5ccccc5c4c3)c2)cc1 ; c1ccc(-c2ccc(-c3cc(-c4ccccc4)cc(N(c4ccc5ccccc5c4)c4ccc5c(-c6ccc7ccccc7c6)cccc5c4)c3)cc2)cc1]

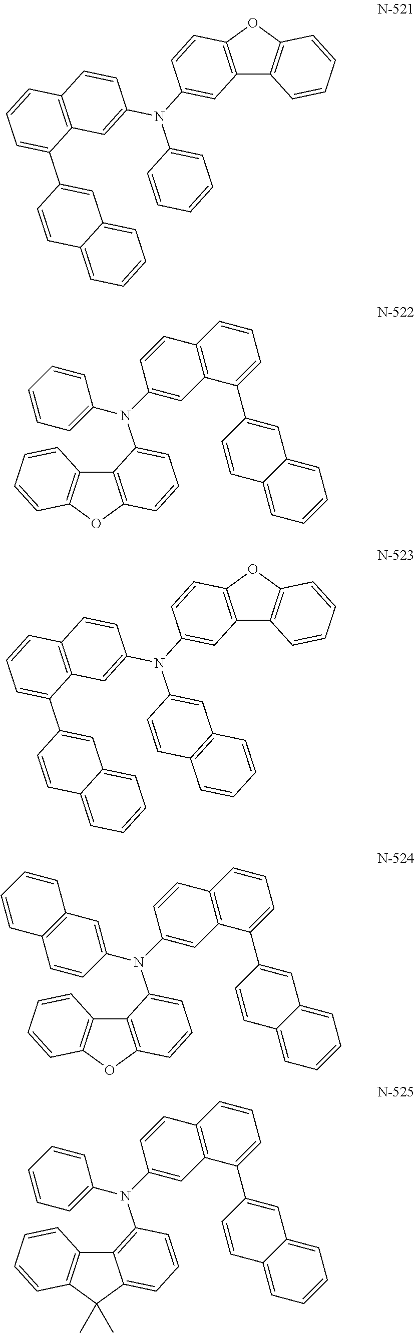 [SMILES: c1ccc(N(c2ccc3cccc(-c4ccc5ccccc5c4)c3c2)c2ccc3oc4ccccc4c3c2)cc1 ; c1ccc(N(c2ccc3cccc(-c4ccc5ccccc5c4)c3c2)c2cccc3oc4ccccc4c23)cc1 ; c1ccc2cc(-c3cccc4ccc(N(c5ccc6ccccc6c5)c5ccc6oc7ccccc7c6c5)cc34)ccc2c1 ; c1ccc2cc(-c3cccc4ccc(N(c5ccc6ccccc6c5)c5cccc6oc7ccccc7c56)cc34)ccc2c1 ; CC1(C)c2ccccc2-c2c(N(c3ccccc3)c3ccc4cccc(-c5ccc6ccccc6c5)c4c3)cccc21]

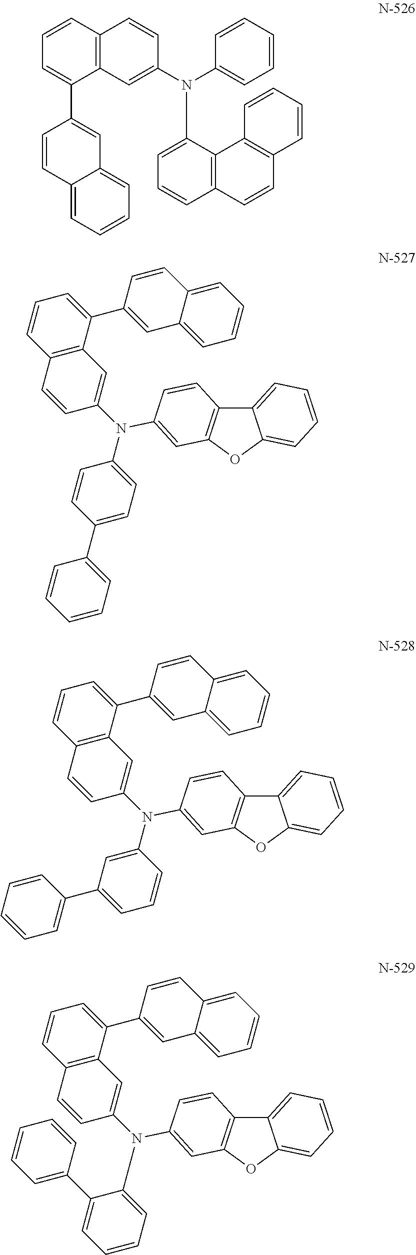 [SMILES: c1ccc(N(c2ccc3cccc(-c4ccc5ccccc5c4)c3c2)c2cccc3ccc4ccccc4c23)cc1 ; c1ccc(-c2ccc(N(c3ccc4c(c3)oc3ccccc34)c3ccc4cccc(-c5ccc6ccccc6c5)c4c3)cc2)cc1 ; c1ccc(-c2cccc(N(c3ccc4c(c3)oc3ccccc34)c3ccc4cccc(-c5ccc6ccccc6c5)c4c3)c2)cc1 ; c1ccc(-c2ccccc2N(c2ccc3c(c2)oc2ccccc23)c2ccc3cccc(-c4ccc5ccccc5c4)c3c2)cc1]

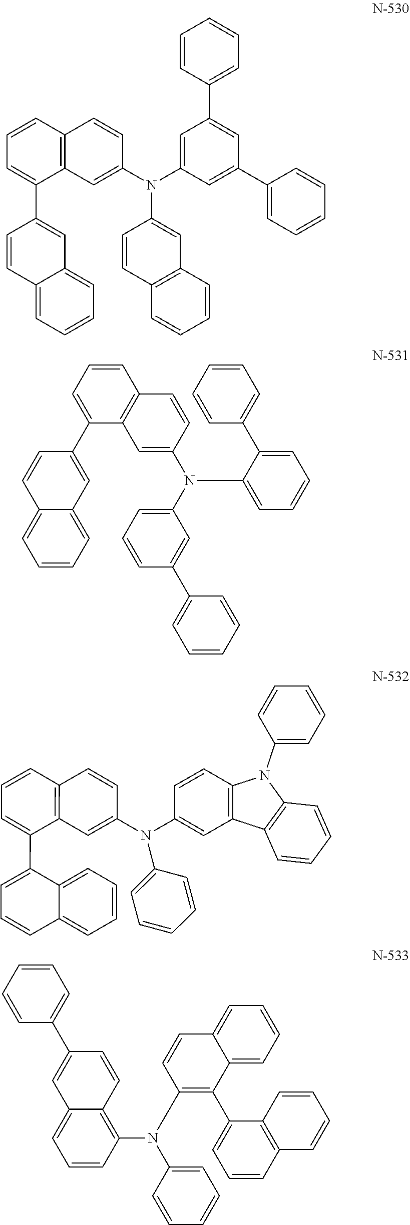

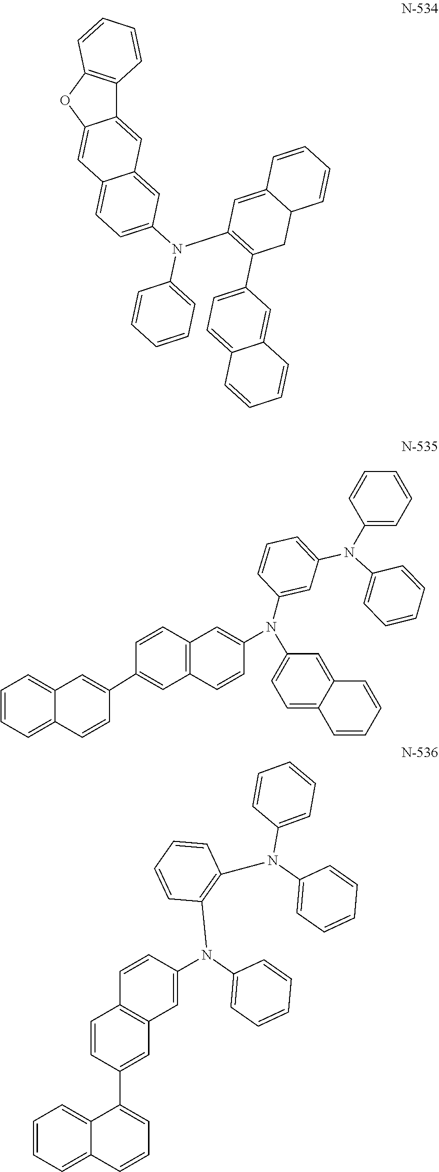 [SMILES: C1=CC2=CC(N(c3ccccc3)c3ccc4cc5oc6ccccc6c5cc4c3)=C(c3ccc4ccccc4c3)CC2C=C1 ; c1ccc(N(c2ccccc2)c2cccc(N(c3ccc4ccccc4c3)c3ccc4cc(-c5ccc6ccccc6c5)ccc4c3)c2)cc1 ; c1ccc(N(c2ccccc2)c2ccccc2N(c2ccccc2)c2ccc3ccc(-c4cccc5ccccc45)cc3c2)cc1]

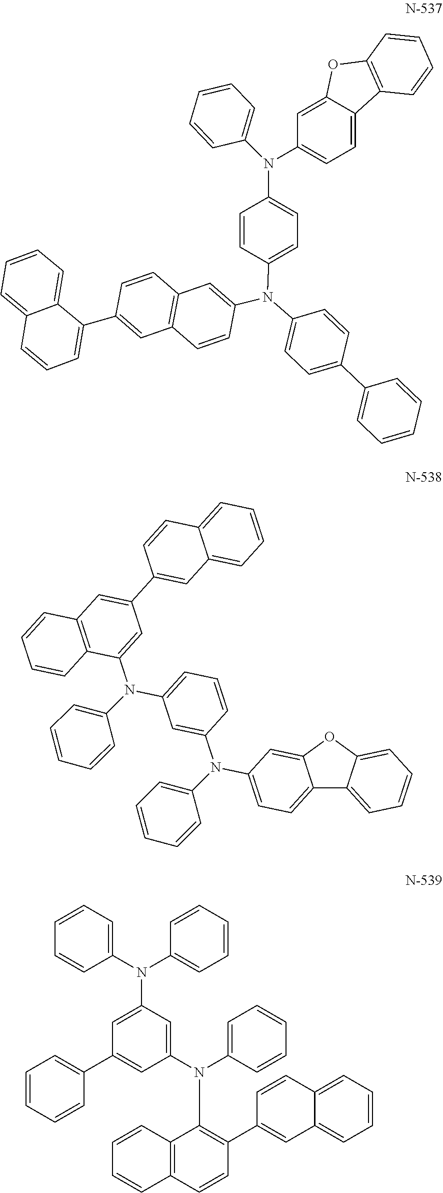 [SMILES: c1ccc(-c2ccc(N(c3ccc(N(c4ccccc4)c4ccc5c(c4)oc4ccccc45)cc3)c3ccc4cc(-c5cccc6ccccc56)ccc4c3)cc2)cc1 ; c1ccc(N(c2cccc(N(c3ccccc3)c3cc(-c4ccc5ccccc5c4)cc4ccccc34)c2)c2ccc3c(c2)oc2ccccc23)cc1 ; c1ccc(-c2cc(N(c3ccccc3)c3ccccc3)cc(N(c3ccccc3)c3c(-c4ccc5ccccc5c4)ccc4ccccc34)c2)cc1]

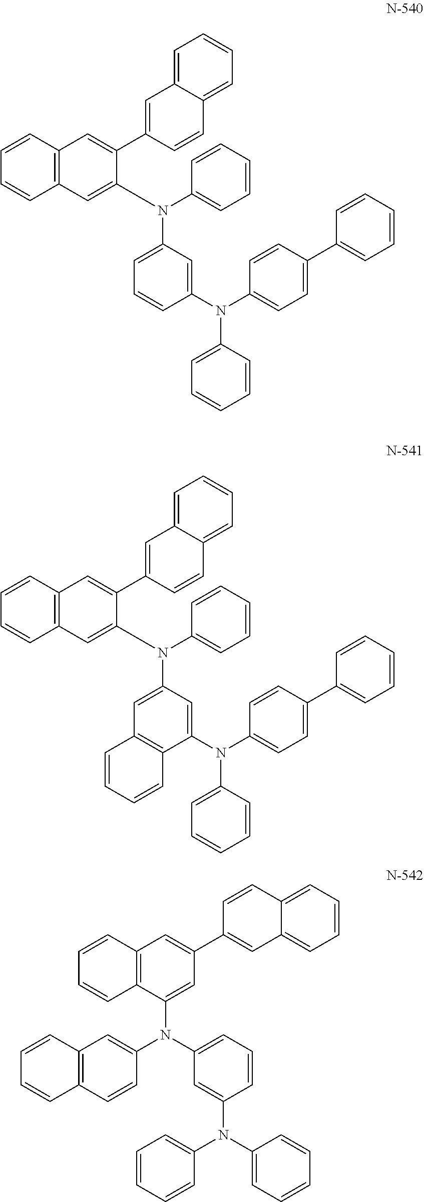

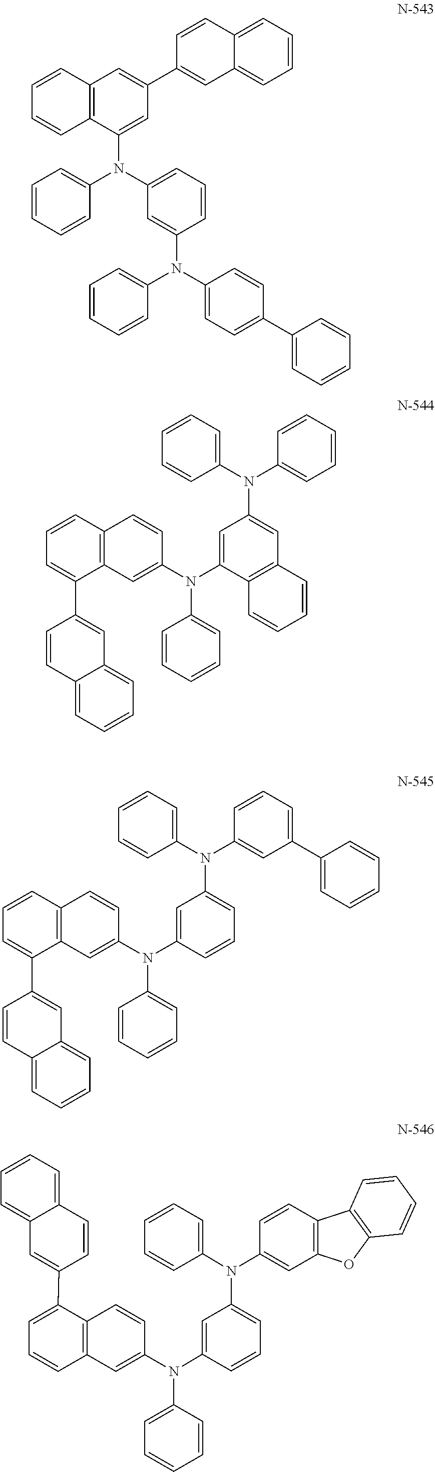

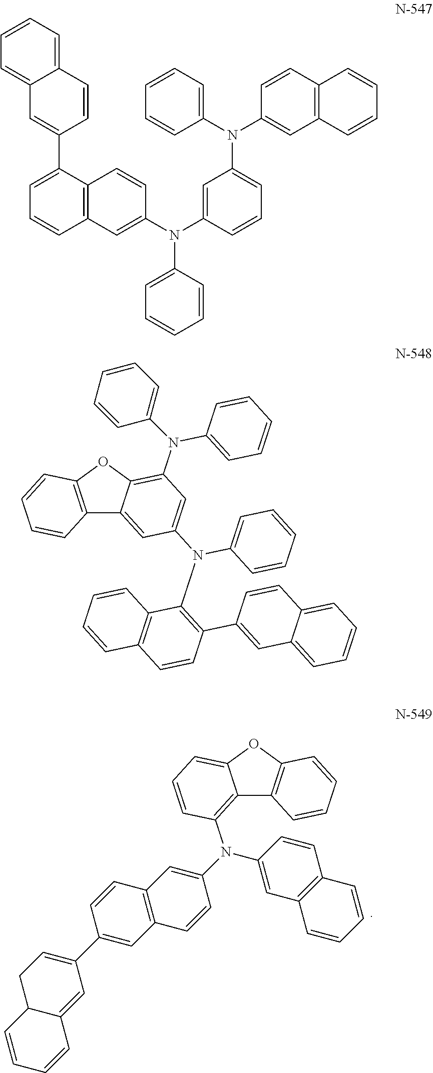

Preferably, the compound M has the structure as shown in any one of Formula 2-1 to Formula 2-28:

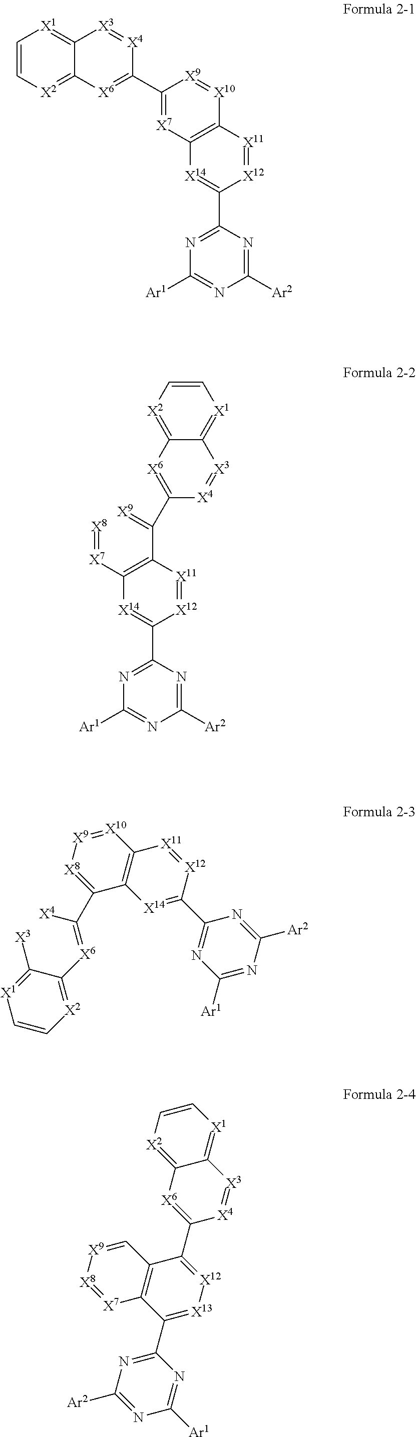

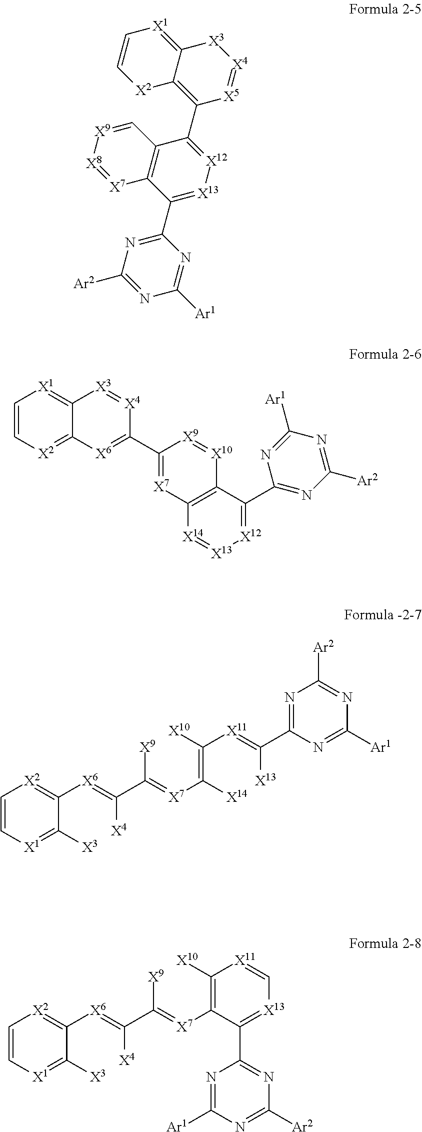

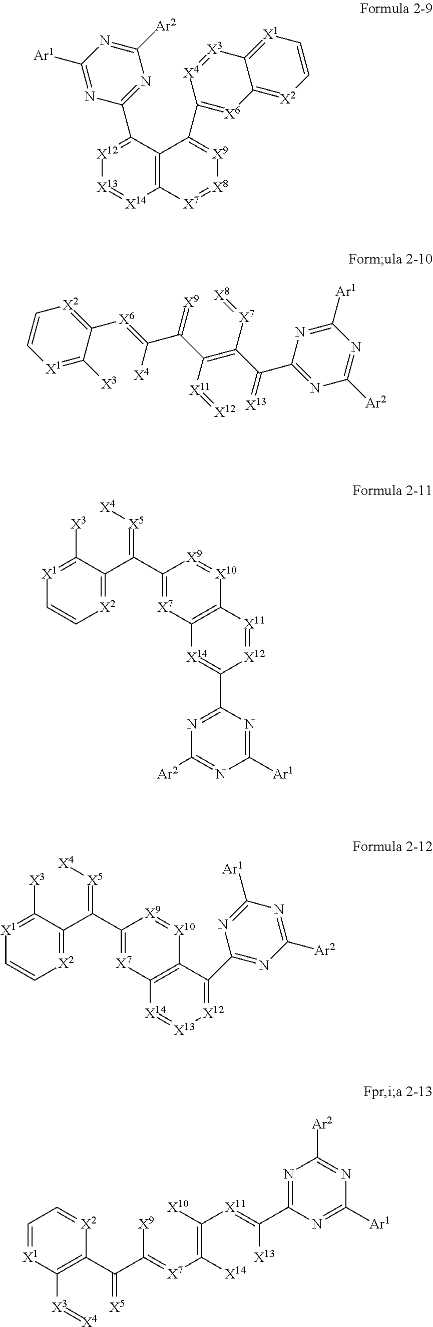

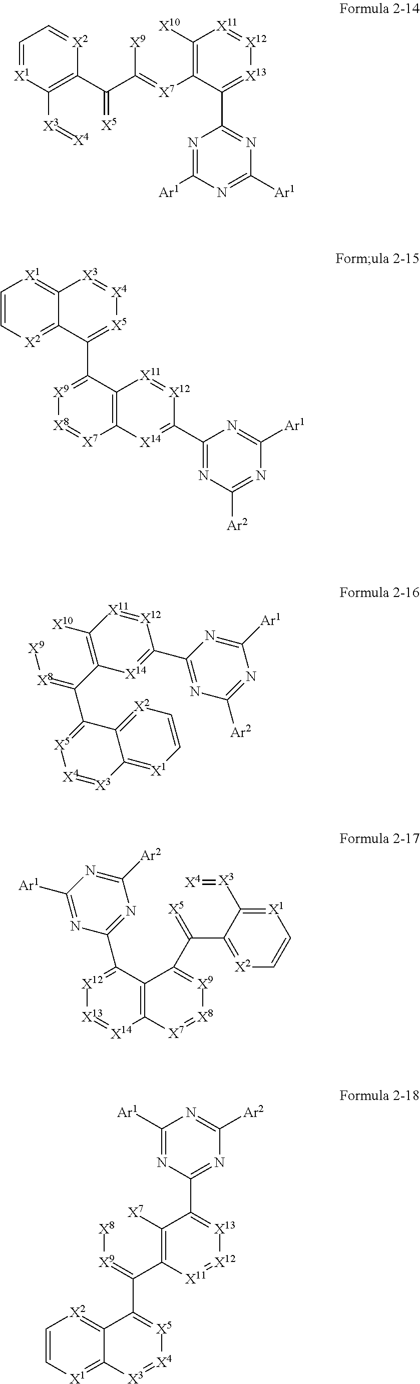

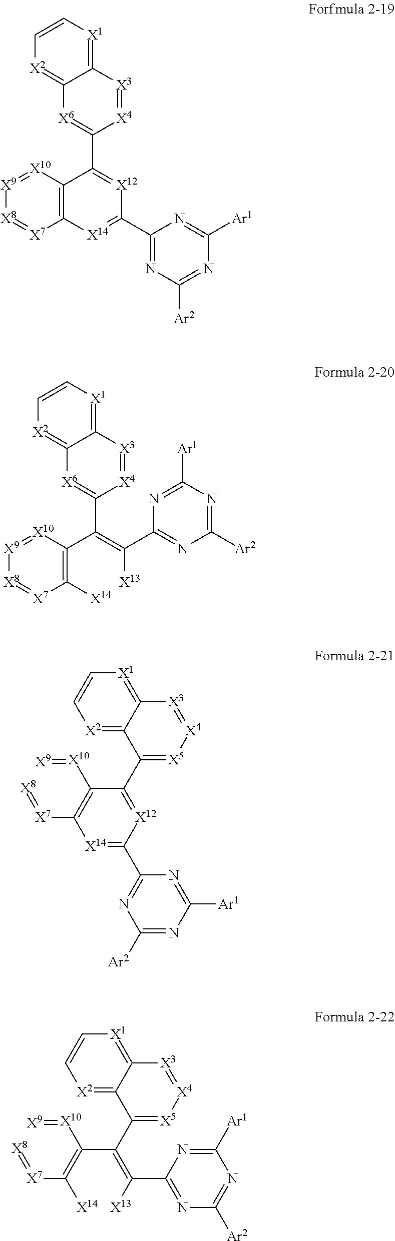

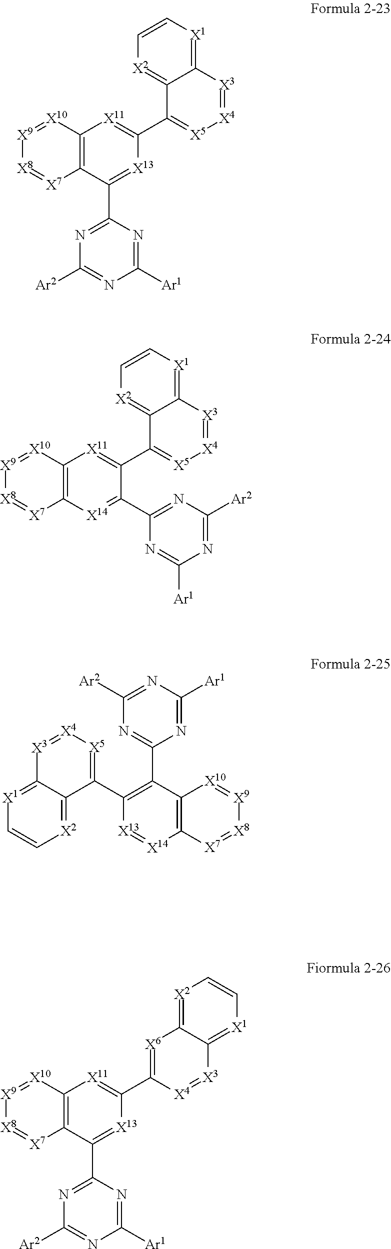

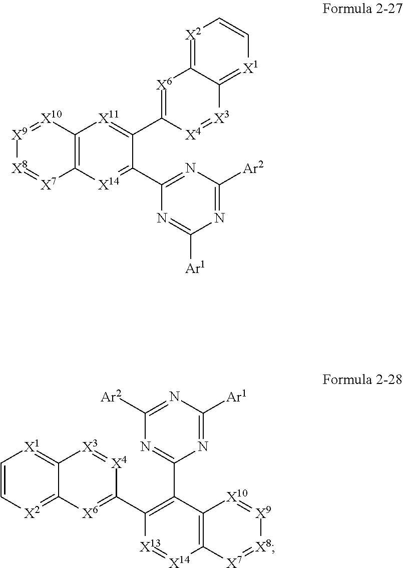

wherein Ar³-Ar⁴ are defined the same as above.

Preferably, the structure of compound M is shown in any one of M-1 to M-619:

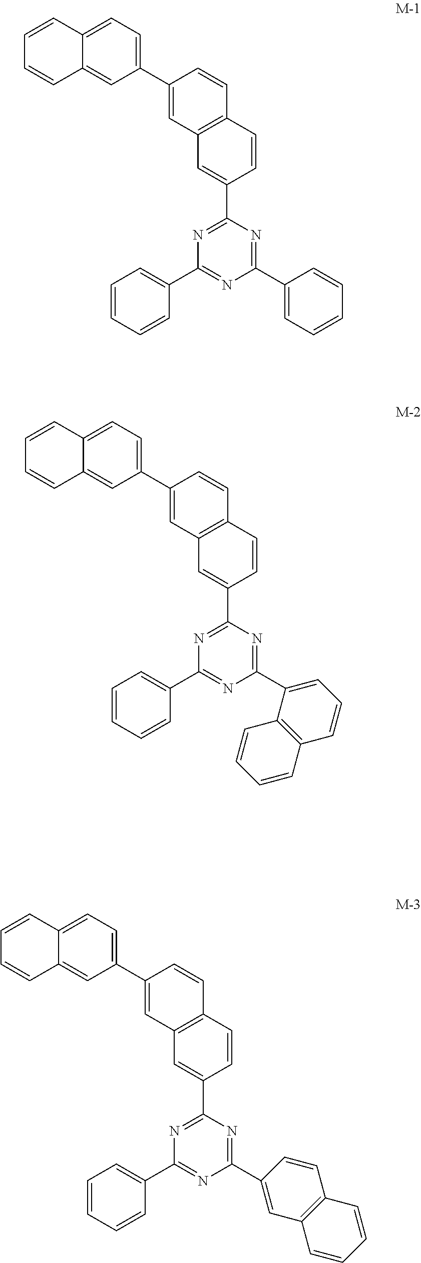 [SMILES: c1ccc(-c2nc(-c3ccccc3)nc(-c3ccc4ccc(-c5ccc6ccccc6c5)cc4c3)n2)cc1 ; c1ccc(-c2nc(-c3ccc4ccc(-c5ccc6ccccc6c5)cc4c3)nc(-c3cccc4ccccc34)n2)cc1 ; c1ccc(-c2nc(-c3ccc4ccccc4c3)nc(-c3ccc4ccc(-c5ccc6ccccc6c5)cc4c3)n2)cc1]

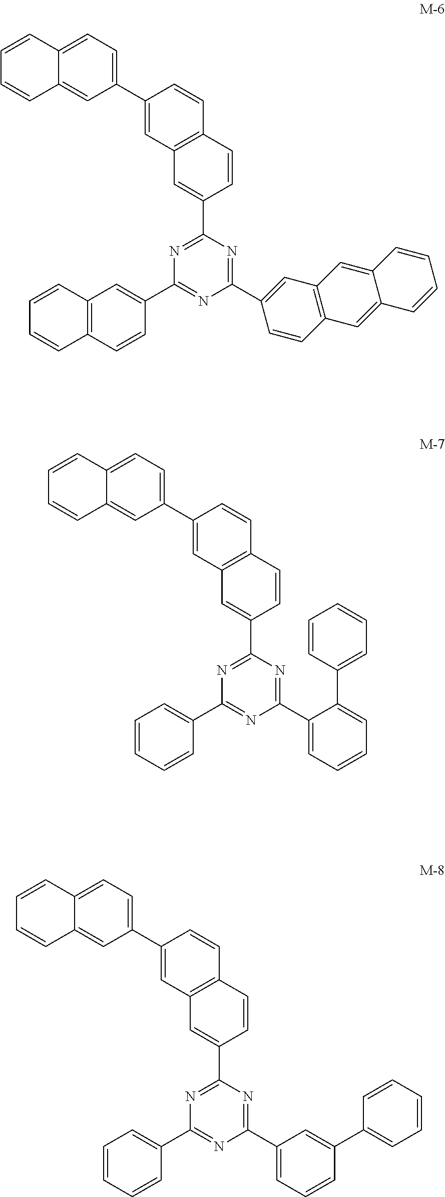 [SMILES: c1ccc2cc(-c3ccc4ccc(-c5nc(-c6ccc7ccccc7c6)nc(-c6ccc7cc8ccccc8cc7c6)n5)cc4c3)ccc2c1 ; c1ccc(-c2nc(-c3ccc4ccc(-c5ccc6ccccc6c5)cc4c3)nc(-c3ccccc3-c3ccccc3)n2)cc1 ; c1ccc(-c2cccc(-c3nc(-c4ccccc4)nc(-c4ccc5ccc(-c6ccc7ccccc7c6)cc5c4)n3)c2)cc1]

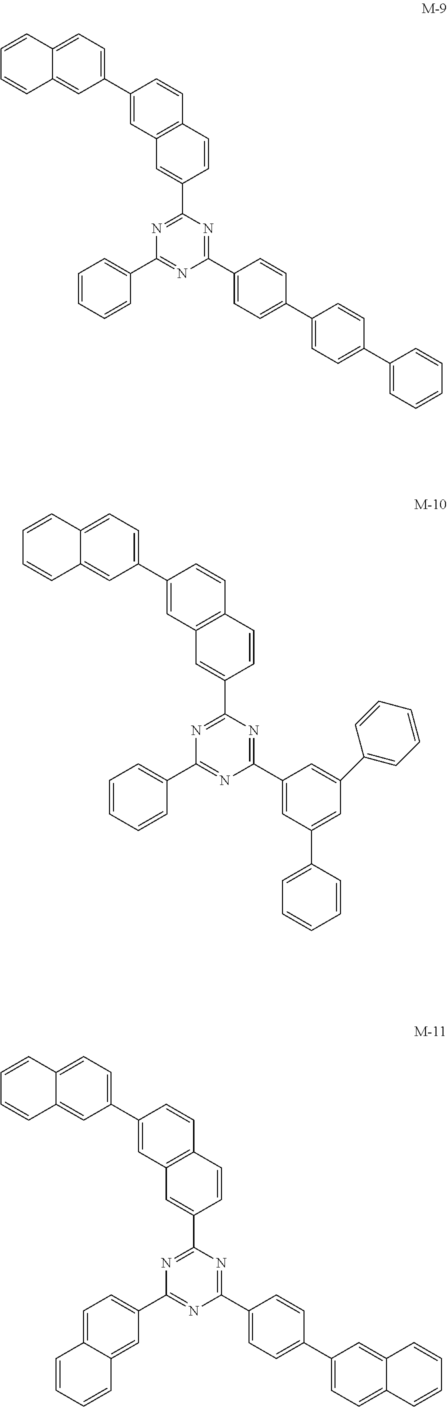 [SMILES: c1ccc(-c2ccc(-c3ccc(-c4nc(-c5ccccc5)nc(-c5ccc6ccc(-c7ccc8ccccc8c7)cc6c5)n4)cc3)cc2)cc1 ; c1ccc(-c2cc(-c3ccccc3)cc(-c3nc(-c4ccccc4)nc(-c4ccc5ccc(-c6ccc7ccccc7c6)cc5c4)n3)c2)cc1 ; c1ccc2cc(-c3ccc(-c4nc(-c5ccc6ccccc6c5)nc(-c5ccc6ccc(-c7ccc8ccccc8c7)cc6c5)n4)cc3)ccc2c1]

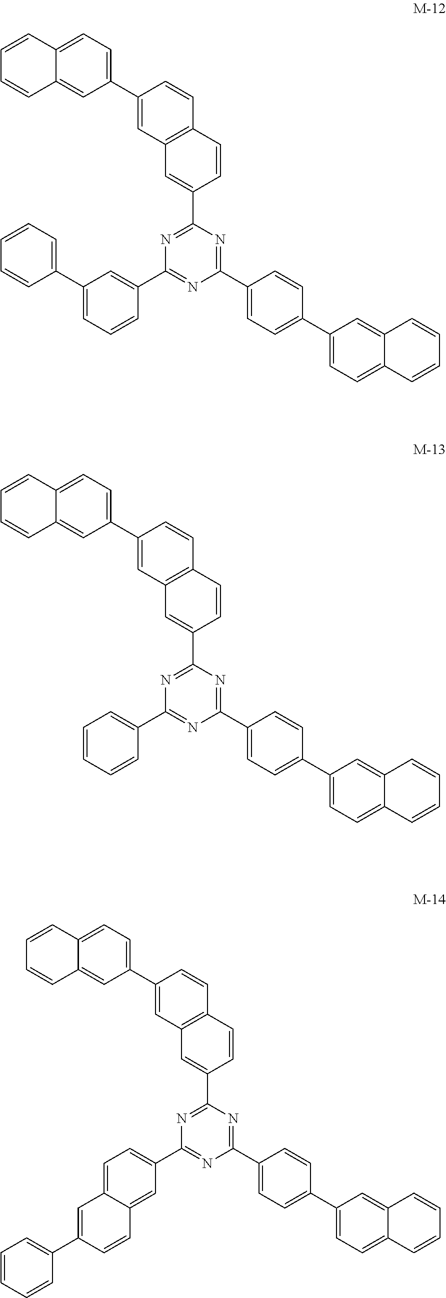 [SMILES: c1ccc(-c2cccc(-c3nc(-c4ccc(-c5ccc6ccccc6c5)cc4)nc(-c4ccc5ccc(-c6ccc7ccccc7c6)cc5c4)n3)c2)cc1 ; c1ccc(-c2nc(-c3ccc(-c4ccc5ccccc5c4)cc3)nc(-c3ccc4ccc(-c5ccc6ccccc6c5)cc4c3)n2)cc1 ; c1ccc(-c2ccc3cc(-c4nc(-c5ccc(-c6ccc7ccccc7c6)cc5)nc(-c5ccc6ccc(-c7ccc8ccccc8c7)cc6c5)n4)ccc3c2)cc1]

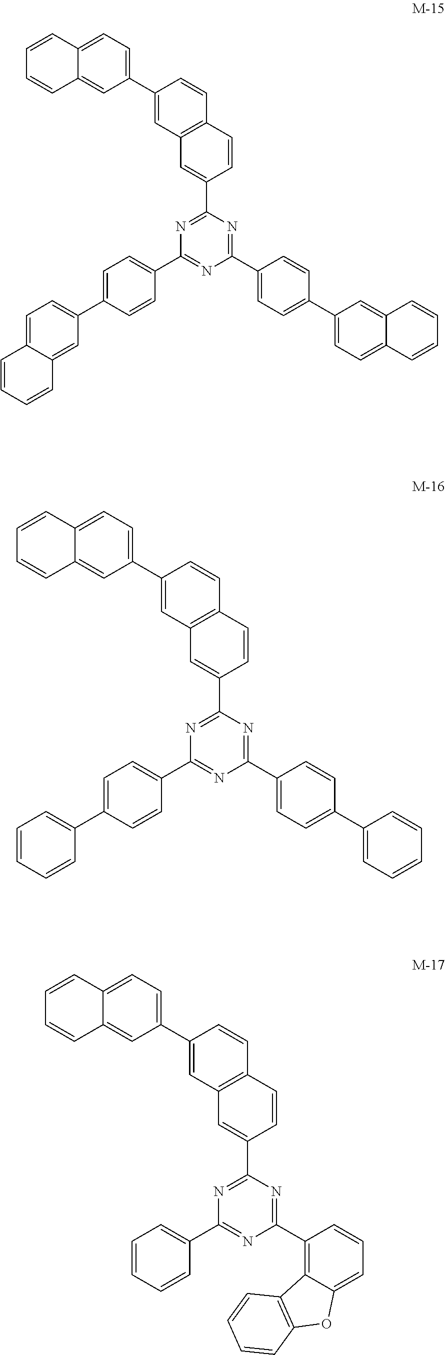 [SMILES: c1ccc2cc(-c3ccc(-c4nc(-c5ccc(-c6ccc7ccccc7c6)cc5)nc(-c5ccc6ccc(-c7ccc8ccccc8c7)cc6c5)n4)cc3)ccc2c1 ; c1ccc(-c2ccc(-c3nc(-c4ccc(-c5ccccc5)cc4)nc(-c4ccc5ccc(-c6ccc7ccccc7c6)cc5c4)n3)cc2)cc1 ; c1ccc(-c2nc(-c3ccc4ccc(-c5ccc6ccccc6c5)cc4c3)nc(-c3cccc4oc5ccccc5c34)n2)cc1]

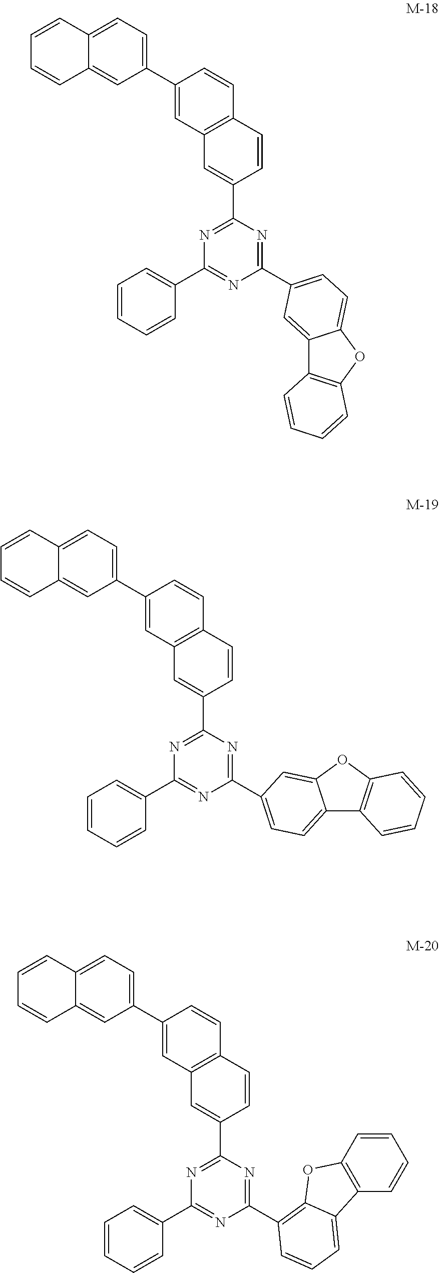 [SMILES: c1ccc(-c2nc(-c3ccc4ccc(-c5ccc6ccccc6c5)cc4c3)nc(-c3ccc4oc5ccccc5c4c3)n2)cc1 ; c1ccc(-c2nc(-c3ccc4ccc(-c5ccc6ccccc6c5)cc4c3)nc(-c3ccc4c(c3)oc3ccccc34)n2)cc1 ; c1ccc(-c2nc(-c3ccc4ccc(-c5ccc6ccccc6c5)cc4c3)nc(-c3cccc4c3oc3ccccc34)n2)cc1]

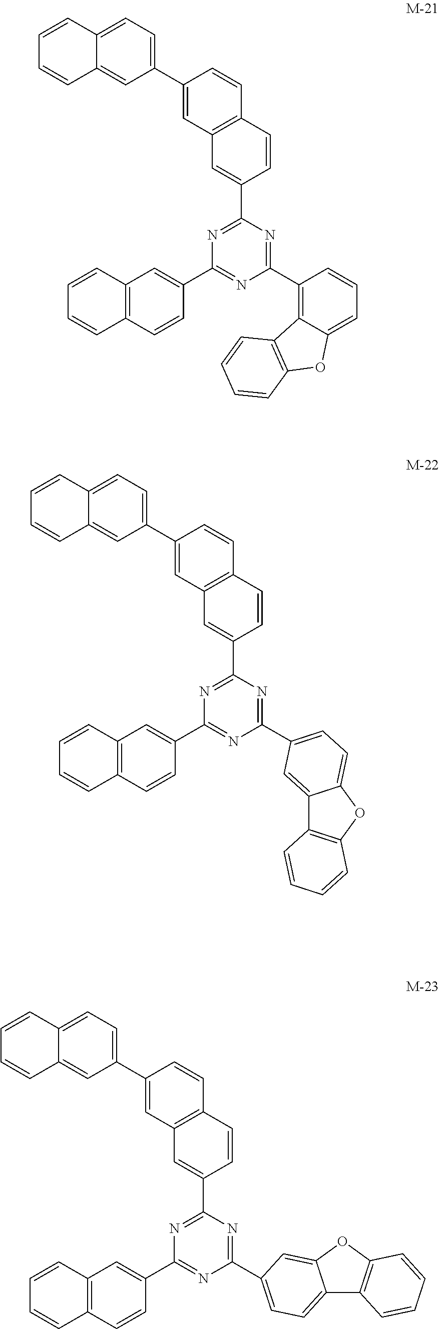 [SMILES: c1ccc2cc(-c3ccc4ccc(-c5nc(-c6ccc7ccccc7c6)nc(-c6cccc7oc8ccccc8c67)n5)cc4c3)ccc2c1 ; c1ccc2cc(-c3ccc4ccc(-c5nc(-c6ccc7ccccc7c6)nc(-c6ccc7oc8ccccc8c7c6)n5)cc4c3)ccc2c1 ; c1ccc2cc(-c3ccc4ccc(-c5nc(-c6ccc7ccccc7c6)nc(-c6ccc7c(c6)oc6ccccc67)n5)cc4c3)ccc2c1]

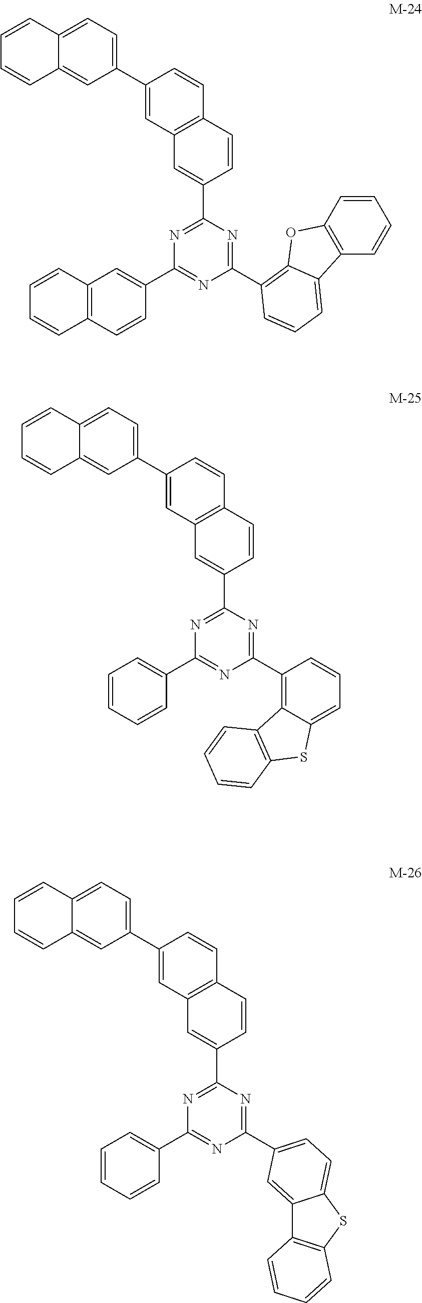 [SMILES: c1ccc2cc(-c3ccc4ccc(-c5nc(-c6ccc7ccccc7c6)nc(-c6cccc7c6oc6ccccc67)n5)cc4c3)ccc2c1 ; c1ccc(-c2nc(-c3ccc4ccc(-c5ccc6ccccc6c5)cc4c3)nc(-c3cccc4sc5ccccc5c34)n2)cc1 ; c1ccc(-c2nc(-c3ccc4ccc(-c5ccc6ccccc6c5)cc4c3)nc(-c3ccc4sc5ccccc5c4c3)n2)cc1]

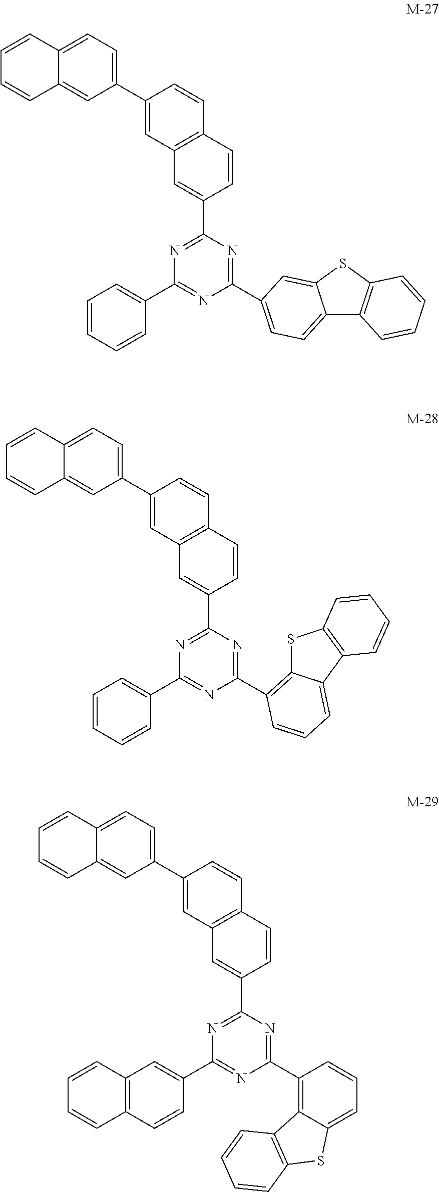 [SMILES: c1ccc(-c2nc(-c3ccc4ccc(-c5ccc6ccccc6c5)cc4c3)nc(-c3ccc4c(c3)sc3ccccc34)n2)cc1 ; c1ccc(-c2nc(-c3ccc4ccc(-c5ccc6ccccc6c5)cc4c3)nc(-c3cccc4c3sc3ccccc34)n2)cc1 ; c1ccc2cc(-c3ccc4ccc(-c5nc(-c6ccc7ccccc7c6)nc(-c6cccc7sc8ccccc8c67)n5)cc4c3)ccc2c1]

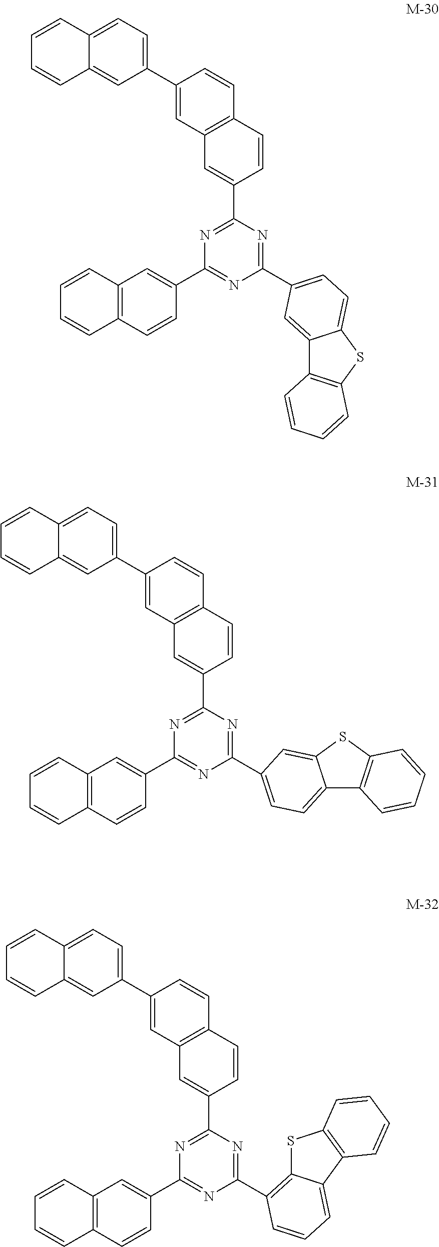 [SMILES: c1ccc2cc(-c3ccc4ccc(-c5nc(-c6ccc7ccccc7c6)nc(-c6ccc7sc8ccccc8c7c6)n5)cc4c3)ccc2c1 ; c1ccc2cc(-c3ccc4ccc(-c5nc(-c6ccc7ccccc7c6)nc(-c6ccc7c(c6)sc6ccccc67)n5)cc4c3)ccc2c1 ; c1ccc2cc(-c3ccc4ccc(-c5nc(-c6ccc7ccccc7c6)nc(-c6cccc7c6sc6ccccc67)n5)cc4c3)ccc2c1]

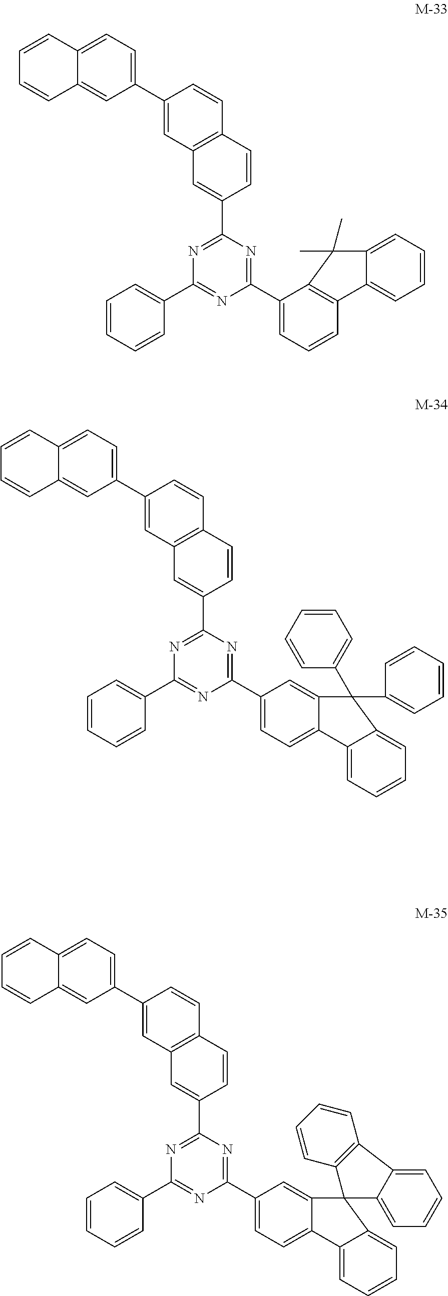 [SMILES: CC1(C)c2ccccc2-c2cccc(-c3nc(-c4ccccc4)nc(-c4ccc5ccc(-c6ccc7ccccc7c6)cc5c4)n3)c21 ; c1ccc(-c2nc(-c3ccc4c(c3)C(c3ccccc3)(c3ccccc3)c3ccccc3-4)nc(-c3ccc4ccc(-c5ccc6ccccc6c5)cc4c3)n2)cc1 ; c1ccc(-c2nc(-c3ccc4c(c3)C3(c5ccccc5-c5ccccc53)c3ccccc3-4)nc(-c3ccc4ccc(-c5ccc6ccccc6c5)cc4c3)n2)cc1]

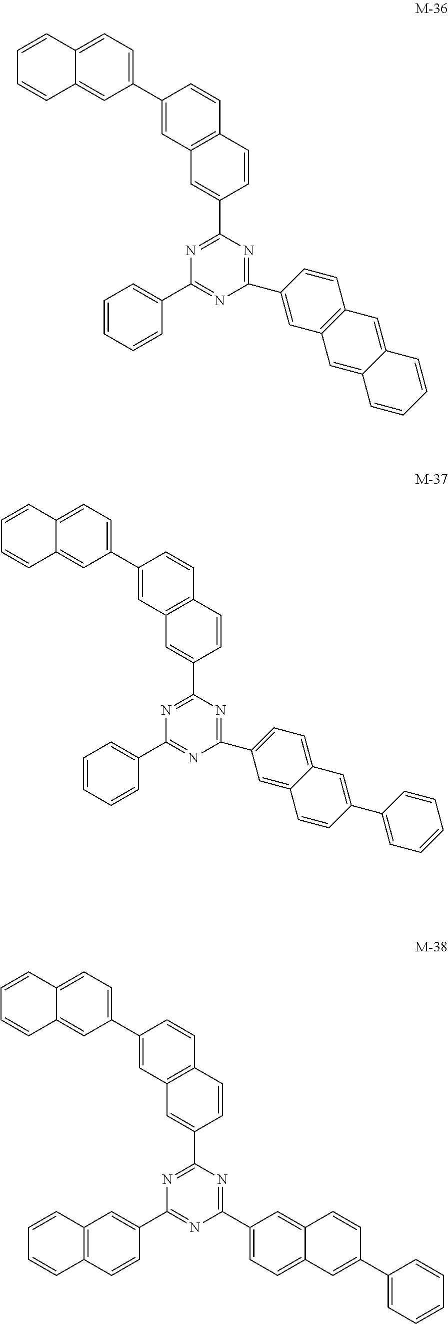 [SMILES: c1ccc(-c2nc(-c3ccc4ccc(-c5ccc6ccccc6c5)cc4c3)nc(-c3ccc4cc5ccccc5cc4c3)n2)cc1 ; c1ccc(-c2ccc3cc(-c4nc(-c5ccccc5)nc(-c5ccc6ccc(-c7ccc8ccccc8c7)cc6c5)n4)ccc3c2)cc1 ; c1ccc(-c2ccc3cc(-c4nc(-c5ccc6ccccc6c5)nc(-c5ccc6ccc(-c7ccc8ccccc8c7)cc6c5)n4)ccc3c2)cc1]

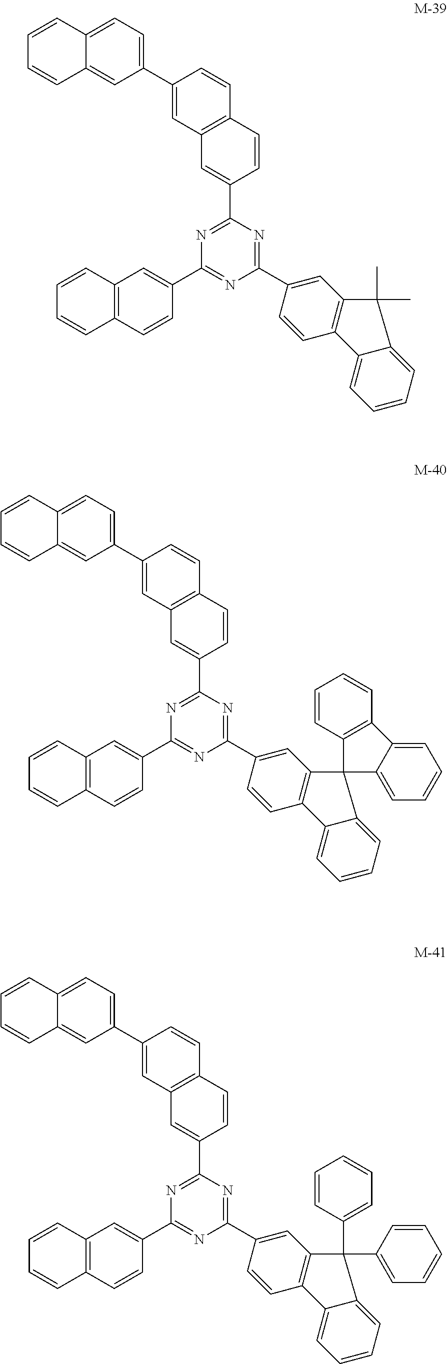 [SMILES: CC1(C)c2ccccc2-c2ccc(-c3nc(-c4ccc5ccccc5c4)nc(-c4ccc5ccc(-c6ccc7ccccc7c6)cc5c4)n3)cc21 ; c1ccc2c(c1)-c1ccccc1C21c2ccccc2-c2ccc(-c3nc(-c4ccc5ccccc5c4)nc(-c4ccc5ccc(-c6ccc7ccccc7c6)cc5c4)n3)cc21 ; c1ccc(C2(c3ccccc3)c3ccccc3-c3ccc(-c4nc(-c5ccc6ccccc6c5)nc(-c5ccc6ccc(-c7ccc8ccccc8c7)cc6c5)n4)cc32)cc1]

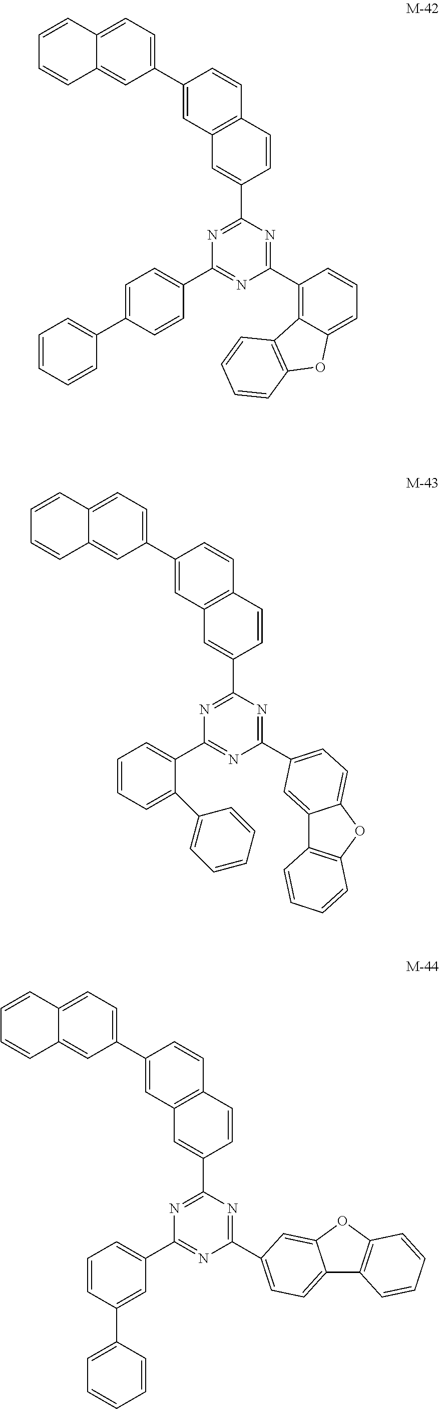 [SMILES: c1ccc(-c2ccc(-c3nc(-c4ccc5ccc(-c6ccc7ccccc7c6)cc5c4)nc(-c4cccc5oc6ccccc6c45)n3)cc2)cc1 ; c1ccc(-c2ccccc2-c2nc(-c3ccc4ccc(-c5ccc6ccccc6c5)cc4c3)nc(-c3ccc4oc5ccccc5c4c3)n2)cc1 ; c1ccc(-c2cccc(-c3nc(-c4ccc5ccc(-c6ccc7ccccc7c6)cc5c4)nc(-c4ccc5c(c4)oc4ccccc45)n3)c2)cc1]

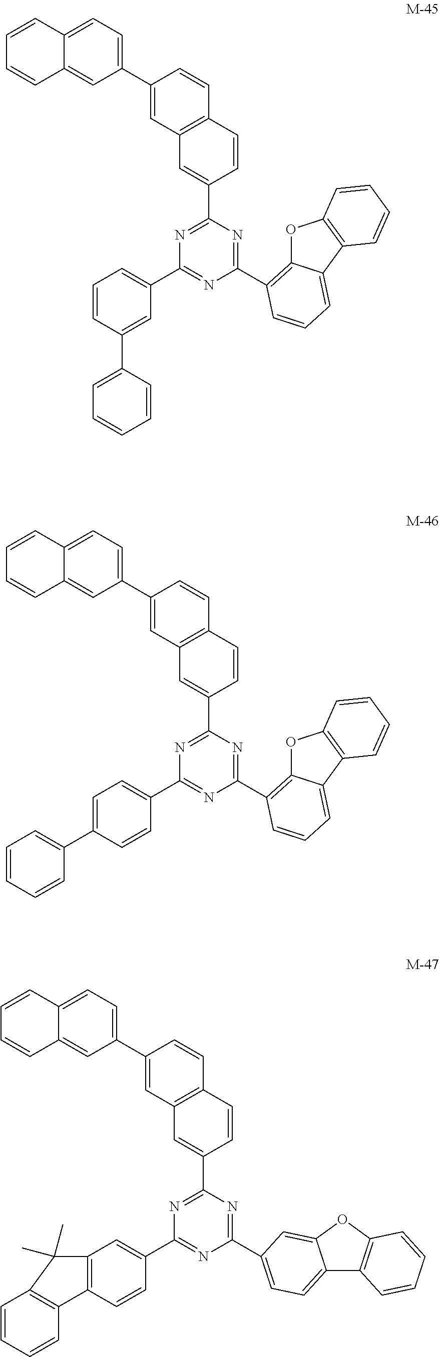 [SMILES: c1ccc(-c2cccc(-c3nc(-c4ccc5ccc(-c6ccc7ccccc7c6)cc5c4)nc(-c4cccc5c4oc4ccccc45)n3)c2)cc1 ; c1ccc(-c2ccc(-c3nc(-c4ccc5ccc(-c6ccc7ccccc7c6)cc5c4)nc(-c4cccc5c4oc4ccccc45)n3)cc2)cc1 ; CC1(C)c2ccccc2-c2ccc(-c3nc(-c4ccc5ccc(-c6ccc7ccccc7c6)cc5c4)nc(-c4ccc5c(c4)oc4ccccc45)n3)cc21]

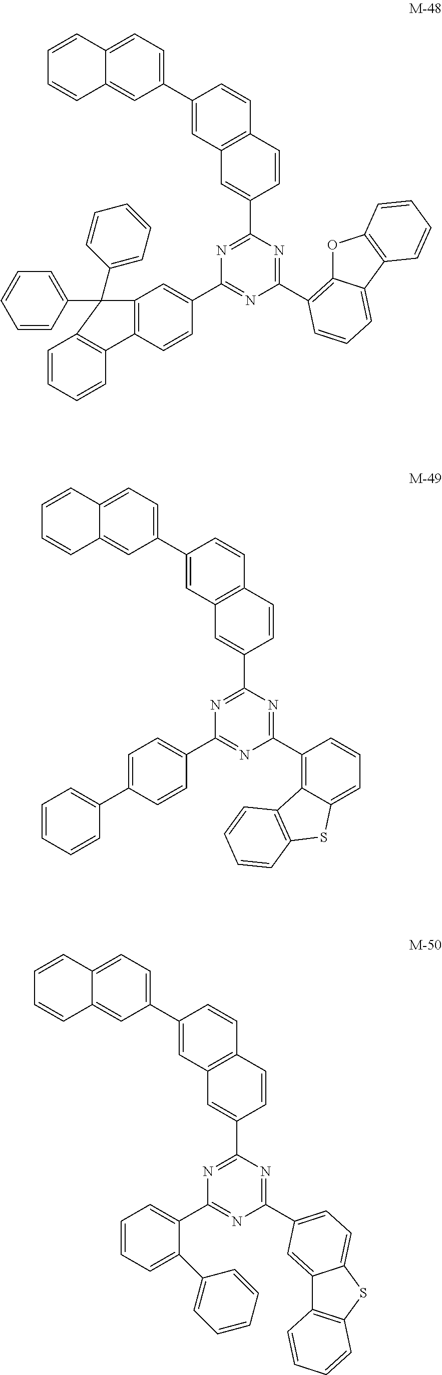 [SMILES: c1ccc(C2(c3ccccc3)c3ccccc3-c3ccc(-c4nc(-c5ccc6ccc(-c7ccc8ccccc8c7)cc6c5)nc(-c5cccc6c5oc5ccccc56)n4)cc32)cc1 ; c1ccc(-c2ccc(-c3nc(-c4ccc5ccc(-c6ccc7ccccc7c6)cc5c4)nc(-c4cccc5sc6ccccc6c45)n3)cc2)cc1 ; c1ccc(-c2ccccc2-c2nc(-c3ccc4ccc(-c5ccc6ccccc6c5)cc4c3)nc(-c3ccc4sc5ccccc5c4c3)n2)cc1]

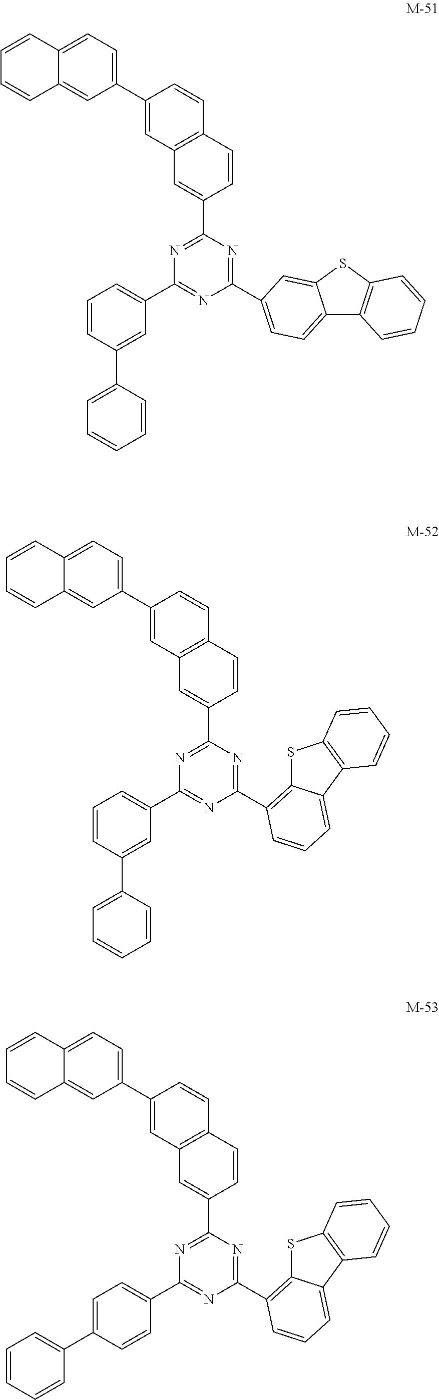 [SMILES: c1ccc(-c2cccc(-c3nc(-c4ccc5ccc(-c6ccc7ccccc7c6)cc5c4)nc(-c4ccc5c(c4)sc4ccccc45)n3)c2)cc1 ; c1ccc(-c2cccc(-c3nc(-c4ccc5ccc(-c6ccc7ccccc7c6)cc5c4)nc(-c4cccc5c4sc4ccccc45)n3)c2)cc1 ; c1ccc(-c2ccc(-c3nc(-c4ccc5ccc(-c6ccc7ccccc7c6)cc5c4)nc(-c4cccc5c4sc4ccccc45)n3)cc2)cc1]

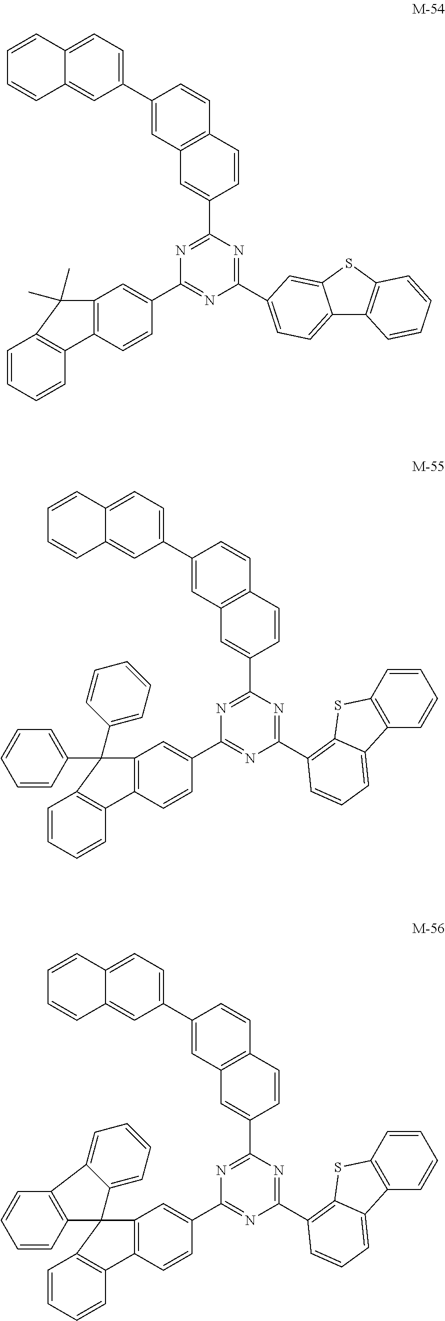 [SMILES: CC1(C)c2ccccc2-c2ccc(-c3nc(-c4ccc5ccc(-c6ccc7ccccc7c6)cc5c4)nc(-c4ccc5c(c4)sc4ccccc45)n3)cc21 ; c1ccc(C2(c3ccccc3)c3ccccc3-c3ccc(-c4nc(-c5ccc6ccc(-c7ccc8ccccc8c7)cc6c5)nc(-c5cccc6c5sc5ccccc56)n4)cc32)cc1 ; c1ccc2c(c1)-c1ccccc1C21c2ccccc2-c2ccc(-c3nc(-c4ccc5ccc(-c6ccc7ccccc7c6)cc5c4)nc(-c4cccc5c4sc4ccccc45)n3)cc21]

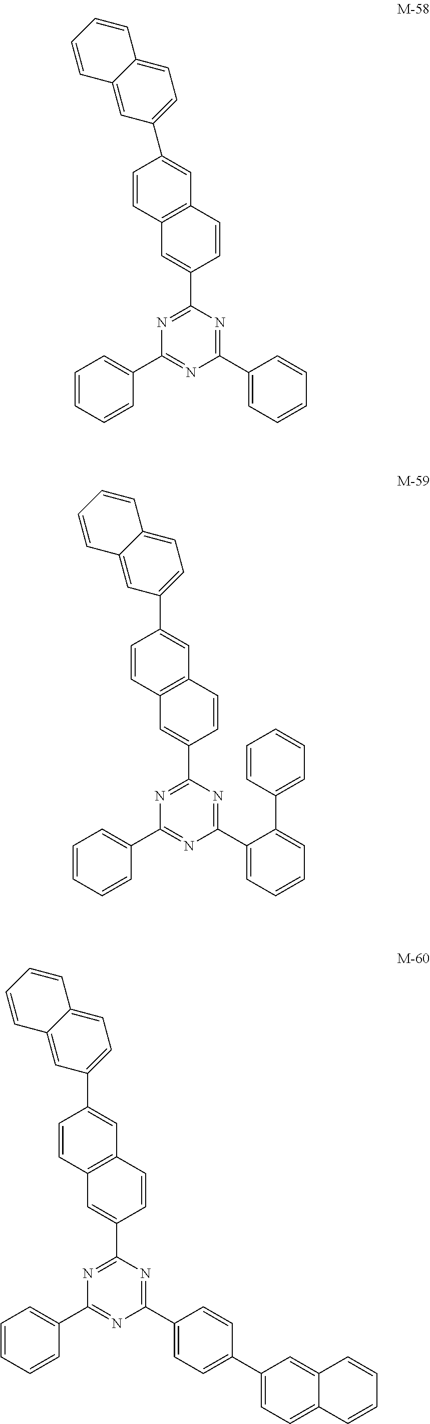 [SMILES: c1ccc(-c2nc(-c3ccccc3)nc(-c3ccc4cc(-c5ccc6ccccc6c5)ccc4c3)n2)cc1 ; c1ccc(-c2nc(-c3ccc4cc(-c5ccc6ccccc6c5)ccc4c3)nc(-c3ccccc3-c3ccccc3)n2)cc1 ; c1ccc(-c2nc(-c3ccc(-c4ccc5ccccc5c4)cc3)nc(-c3ccc4cc(-c5ccc6ccccc6c5)ccc4c3)n2)cc1]

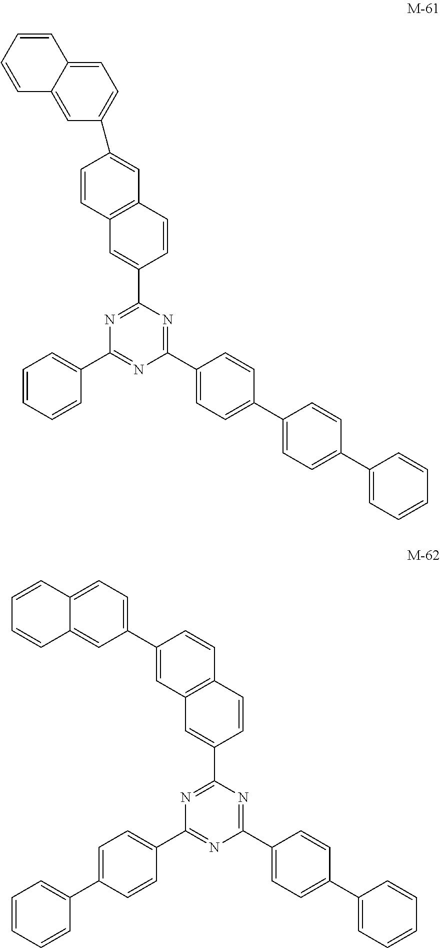 [SMILES: c1ccc(-c2ccc(-c3ccc(-c4nc(-c5ccccc5)nc(-c5ccc6cc(-c7ccc8ccccc8c7)ccc6c5)n4)cc3)cc2)cc1 ; c1ccc(-c2ccc(-c3nc(-c4ccc(-c5ccccc5)cc4)nc(-c4ccc5ccc(-c6ccc7ccccc7c6)cc5c4)n3)cc2)cc1]

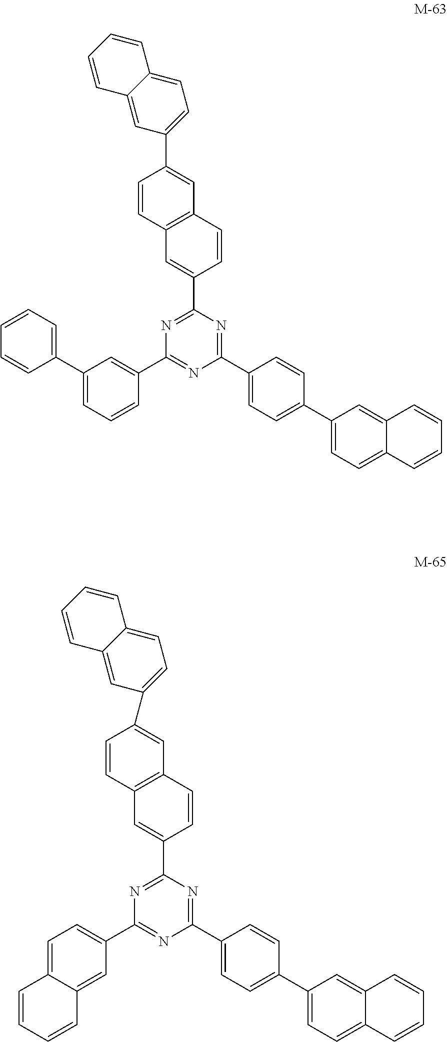 [SMILES: c1ccc(-c2cccc(-c3nc(-c4ccc(-c5ccc6ccccc6c5)cc4)nc(-c4ccc5cc(-c6ccc7ccccc7c6)ccc5c4)n3)c2)cc1 ; c1ccc2cc(-c3ccc(-c4nc(-c5ccc6ccccc6c5)nc(-c5ccc6cc(-c7ccc8ccccc8c7)ccc6c5)n4)cc3)ccc2c1]

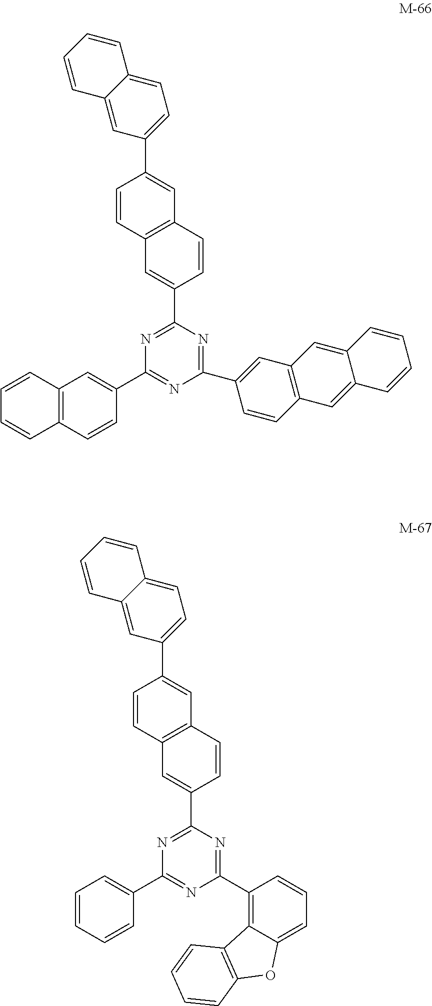 [SMILES: c1ccc2cc(-c3ccc4cc(-c5nc(-c6ccc7ccccc7c6)nc(-c6ccc7cc8ccccc8cc7c6)n5)ccc4c3)ccc2c1 ; c1ccc(-c2nc(-c3ccc4cc(-c5ccc6ccccc6c5)ccc4c3)nc(-c3cccc4oc5ccccc5c34)n2)cc1]

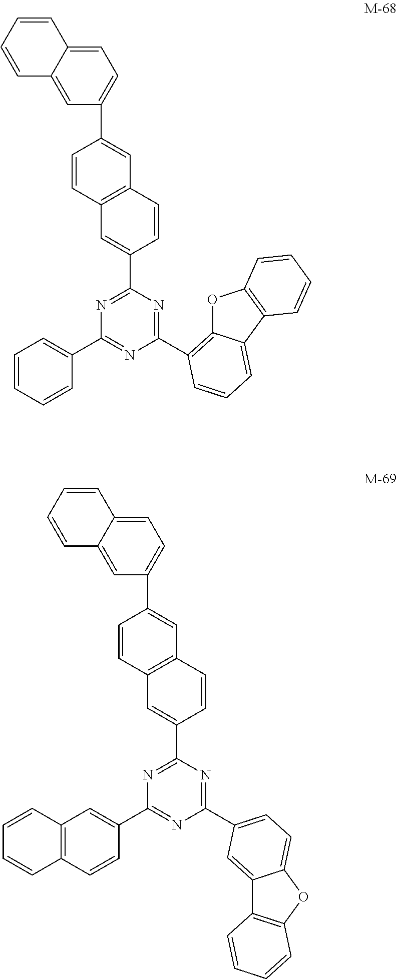 [SMILES: c1ccc(-c2nc(-c3ccc4cc(-c5ccc6ccccc6c5)ccc4c3)nc(-c3cccc4c3oc3ccccc34)n2)cc1 ; c1ccc2cc(-c3ccc4cc(-c5nc(-c6ccc7ccccc7c6)nc(-c6ccc7oc8ccccc8c7c6)n5)ccc4c3)ccc2c1]

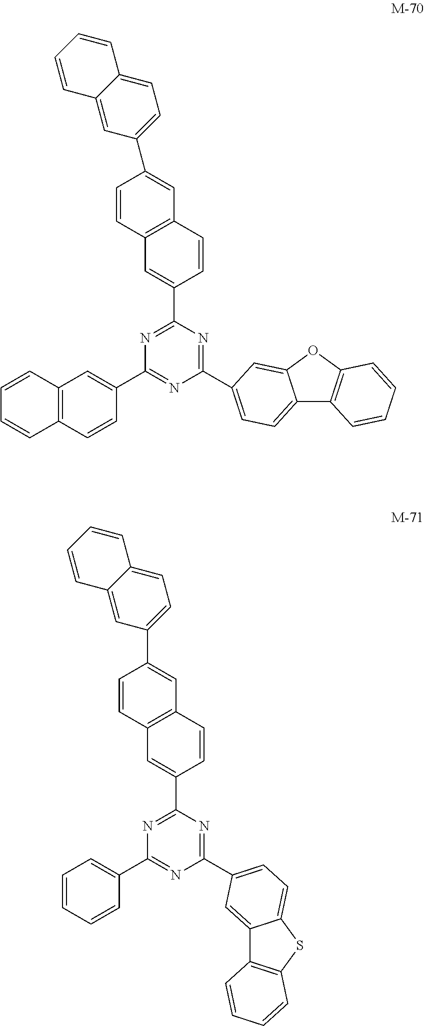 [SMILES: c1ccc2cc(-c3ccc4cc(-c5nc(-c6ccc7ccccc7c6)nc(-c6ccc7c(c6)oc6ccccc67)n5)ccc4c3)ccc2c1 ; c1ccc(-c2nc(-c3ccc4cc(-c5ccc6ccccc6c5)ccc4c3)nc(-c3ccc4sc5ccccc5c4c3)n2)cc1]

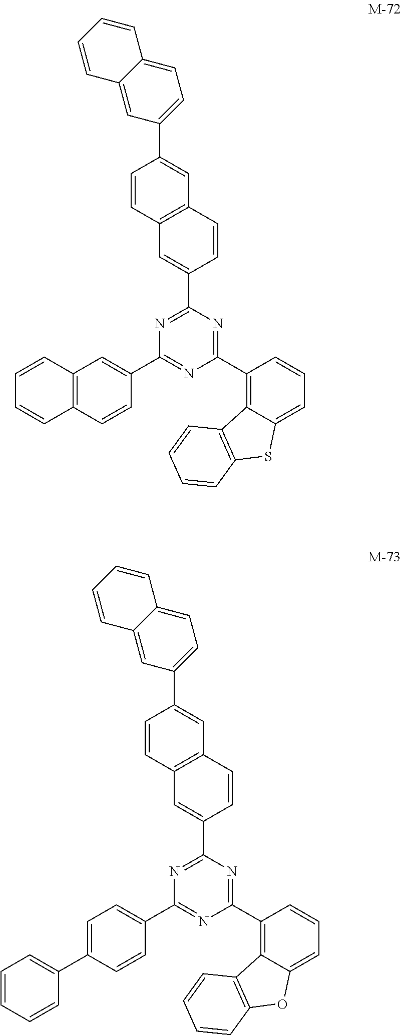 [SMILES: c1ccc2cc(-c3ccc4cc(-c5nc(-c6ccc7ccccc7c6)nc(-c6cccc7sc8ccccc8c67)n5)ccc4c3)ccc2c1 ; c1ccc(-c2ccc(-c3nc(-c4ccc5cc(-c6ccc7ccccc7c6)ccc5c4)nc(-c4cccc5oc6ccccc6c45)n3)cc2)cc1]

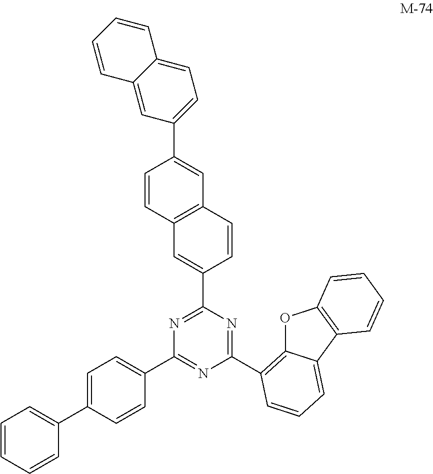 [SMILES: c1ccc(-c2ccc(-c3nc(-c4ccc5cc(-c6ccc7ccccc7c6)ccc5c4)nc(-c4cccc5c4oc4ccccc45)n3)cc2)cc1]

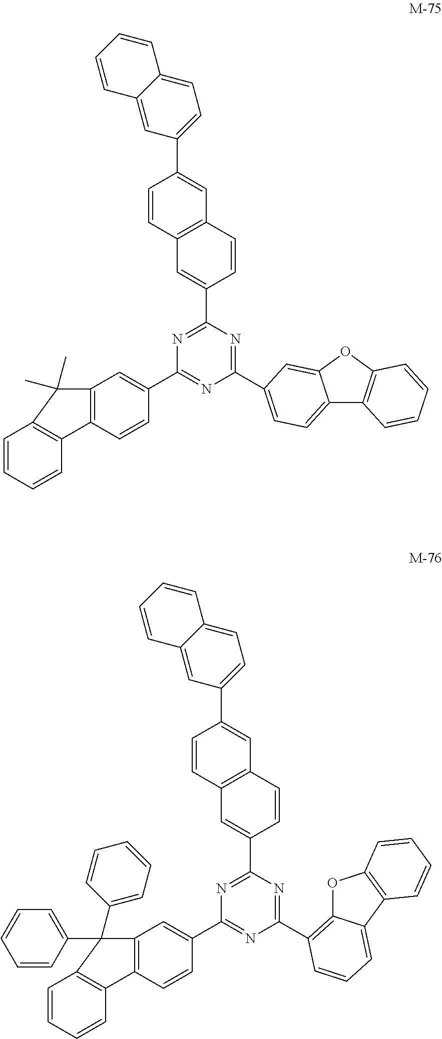 [SMILES: CC1(C)c2ccccc2-c2ccc(-c3nc(-c4ccc5cc(-c6ccc7ccccc7c6)ccc5c4)nc(-c4ccc5c(c4)oc4ccccc45)n3)cc21 ; c1ccc(C2(c3ccccc3)c3ccccc3-c3ccc(-c4nc(-c5ccc6cc(-c7ccc8ccccc8c7)ccc6c5)nc(-c5cccc6c5oc5ccccc56)n4)cc32)cc1]

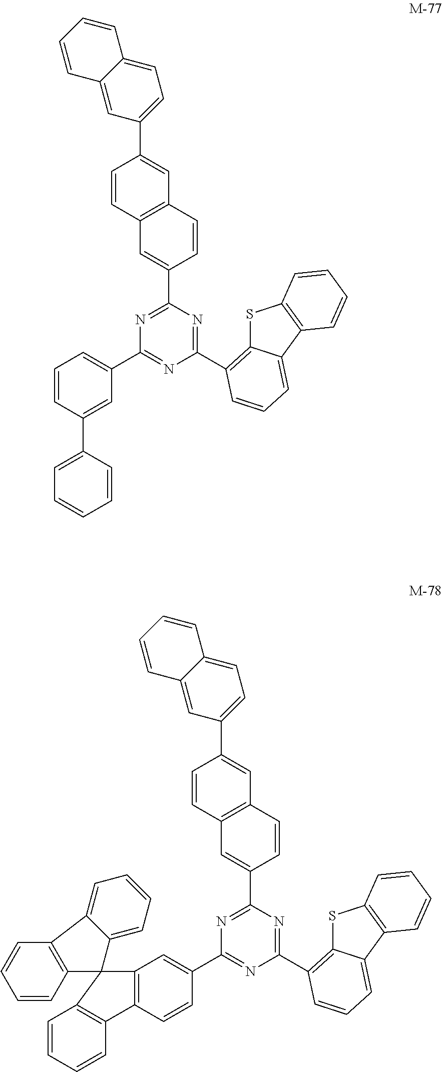 [SMILES: c1ccc(-c2cccc(-c3nc(-c4ccc5cc(-c6ccc7ccccc7c6)ccc5c4)nc(-c4cccc5c4sc4ccccc45)n3)c2)cc1 ; c1ccc2c(c1)-c1ccccc1C21c2ccccc2-c2ccc(-c3nc(-c4ccc5cc(-c6ccc7ccccc7c6)ccc5c4)nc(-c4cccc5c4sc4ccccc45)n3)cc21]

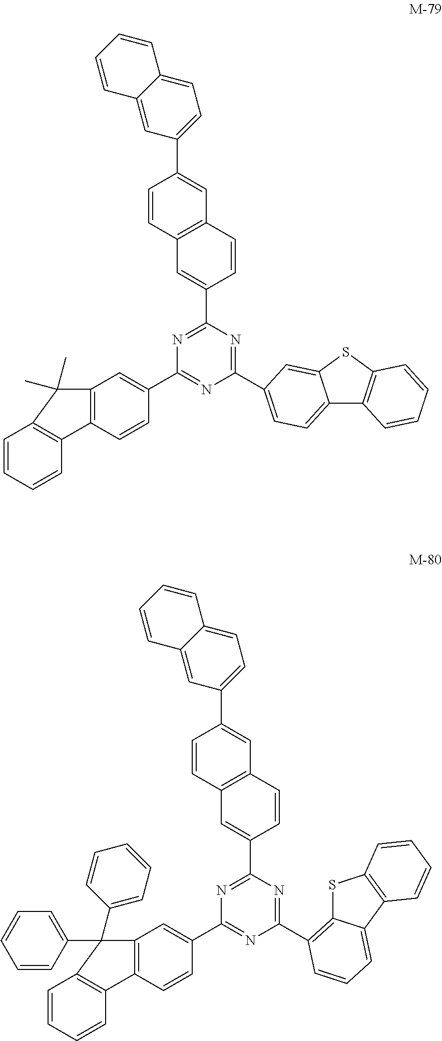 [SMILES: CC1(C)c2ccccc2-c2ccc(-c3nc(-c4ccc5cc(-c6ccc7ccccc7c6)ccc5c4)nc(-c4ccc5c(c4)sc4ccccc45)n3)cc21 ; c1ccc(C2(c3ccccc3)c3ccccc3-c3ccc(-c4nc(-c5ccc6cc(-c7ccc8ccccc8c7)ccc6c5)nc(-c5cccc6c5sc5ccccc56)n4)cc32)cc1]

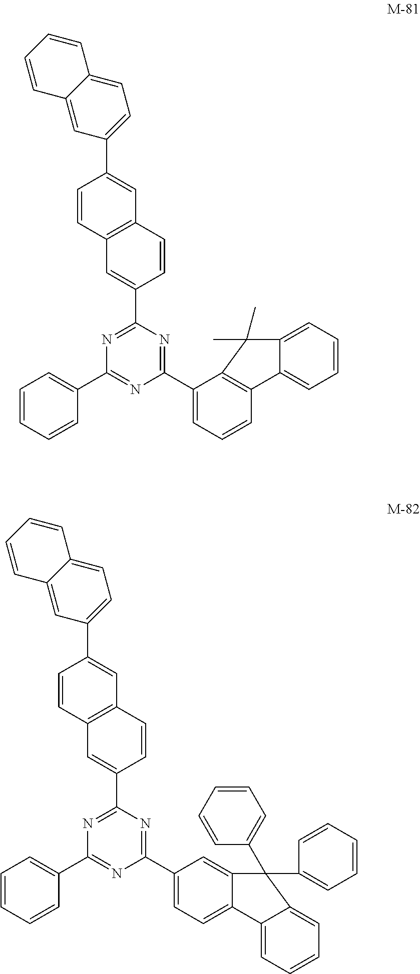 [SMILES: CC1(C)c2ccccc2-c2cccc(-c3nc(-c4ccccc4)nc(-c4ccc5cc(-c6ccc7ccccc7c6)ccc5c4)n3)c21 ; c1ccc(-c2nc(-c3ccc4c(c3)C(c3ccccc3)(c3ccccc3)c3ccccc3-4)nc(-c3ccc4cc(-c5ccc6ccccc6c5)ccc4c3)n2)cc1]

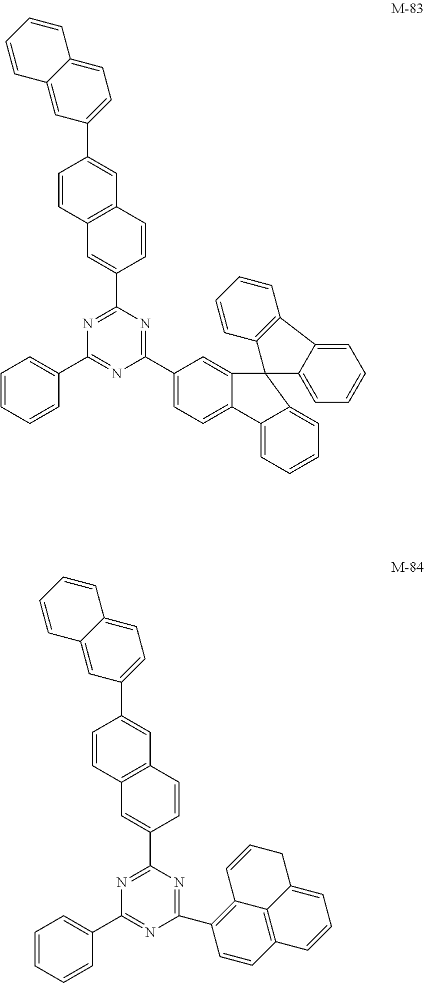 [SMILES: c1ccc(-c2nc(-c3ccc4c(c3)C3(c5ccccc5-c5ccccc53)c3ccccc3-4)nc(-c3ccc4cc(-c5ccc6ccccc6c5)ccc4c3)n2)cc1 ; C1=Cc2c(-c3nc(-c4ccccc4)nc(-c4ccc5cc(-c6ccc7ccccc7c6)ccc5c4)n3)ccc3cccc(c23)C1]

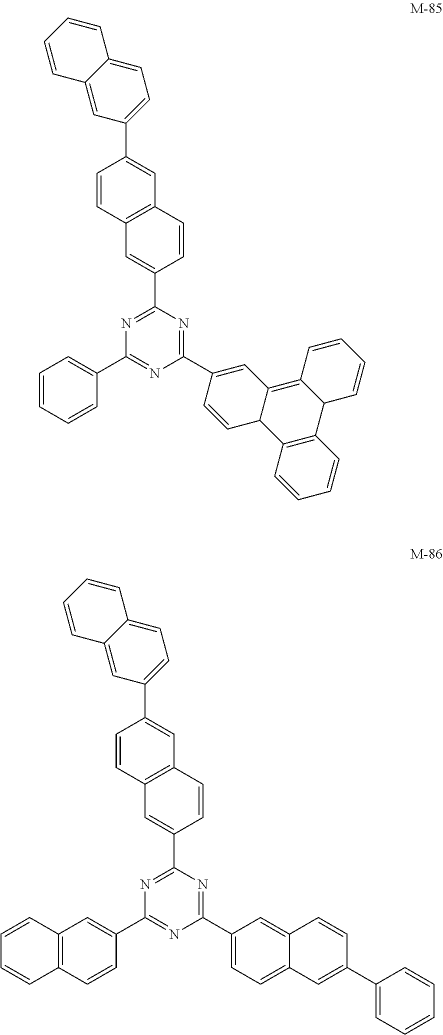 [SMILES: C1=CC2=C3C=C(c4nc(-c5ccccc5)nc(-c5ccc6cc(-c7ccc8ccccc8c7)ccc6c5)n4)C=CC3c3ccccc3C2C=C1 ; c1ccc(-c2ccc3cc(-c4nc(-c5ccc6ccccc6c5)nc(-c5ccc6cc(-c7ccc8ccccc8c7)ccc6c5)n4)ccc3c2)cc1]

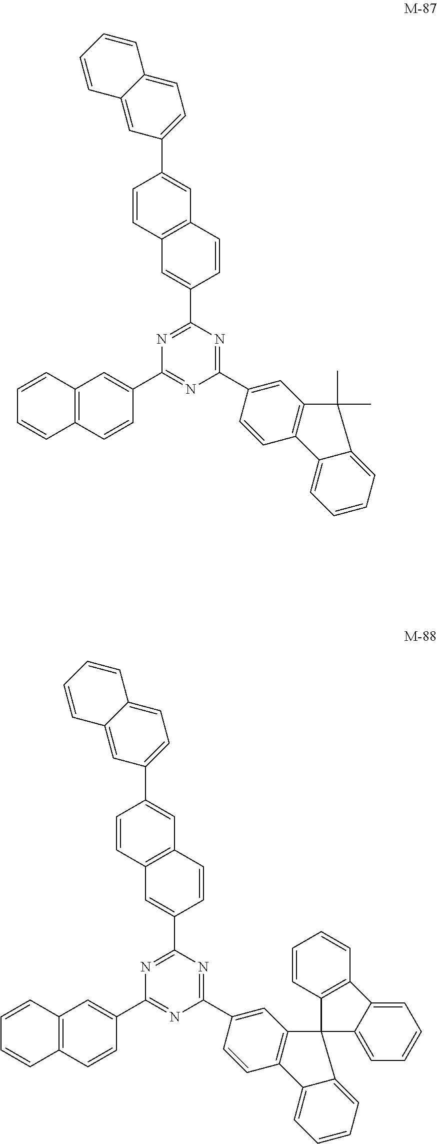 [SMILES: CC1(C)c2ccccc2-c2ccc(-c3nc(-c4ccc5ccccc5c4)nc(-c4ccc5cc(-c6ccc7ccccc7c6)ccc5c4)n3)cc21 ; c1ccc2c(c1)-c1ccccc1C21c2ccccc2-c2ccc(-c3nc(-c4ccc5ccccc5c4)nc(-c4ccc5cc(-c6ccc7ccccc7c6)ccc5c4)n3)cc21]

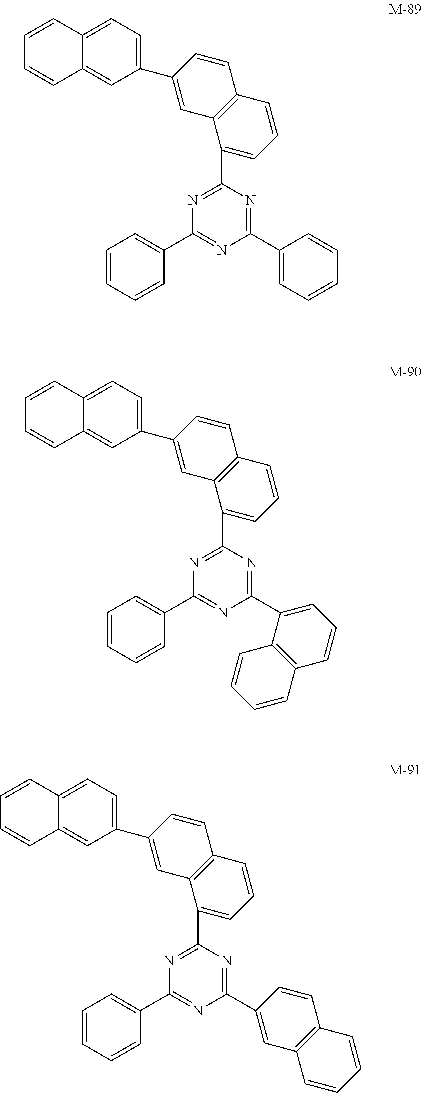 [SMILES: c1ccc(-c2nc(-c3ccccc3)nc(-c3cccc4ccc(-c5ccc6ccccc6c5)cc34)n2)cc1 ; c1ccc(-c2nc(-c3cccc4ccccc34)nc(-c3cccc4ccc(-c5ccc6ccccc6c5)cc34)n2)cc1 ; c1ccc(-c2nc(-c3ccc4ccccc4c3)nc(-c3cccc4ccc(-c5ccc6ccccc6c5)cc34)n2)cc1]

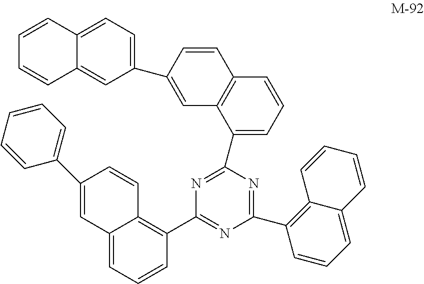 [SMILES: c1ccc(-c2ccc3c(-c4nc(-c5cccc6ccccc56)nc(-c5cccc6ccc(-c7ccc8ccccc8c7)cc56)n4)cccc3c2)cc1]

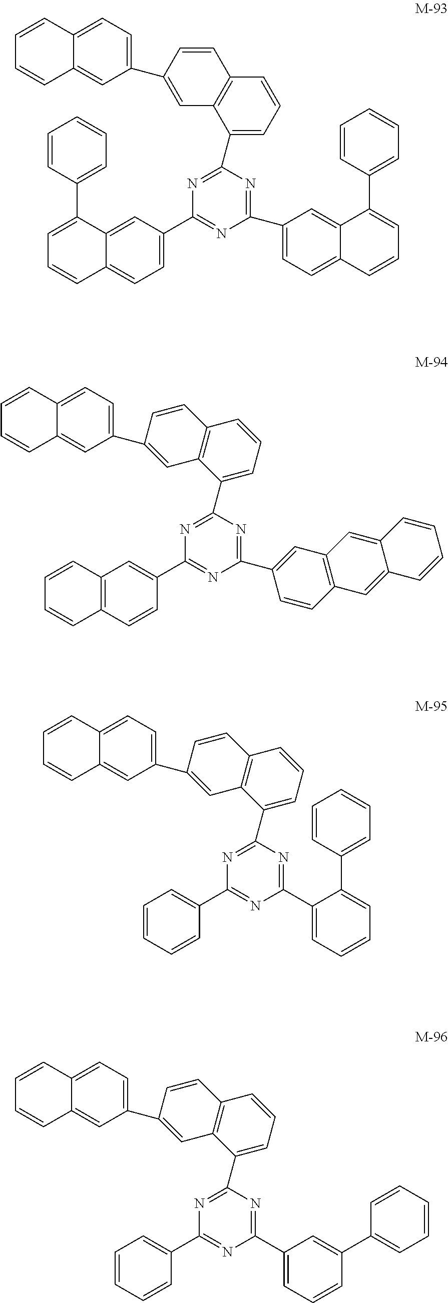 [SMILES: c1ccc(-c2cccc3ccc(-c4nc(-c5ccc6cccc(-c7ccccc7)c6c5)nc(-c5cccc6ccc(-c7ccc8ccccc8c7)cc56)n4)cc23)cc1 ; c1ccc2cc(-c3ccc4cccc(-c5nc(-c6ccc7ccccc7c6)nc(-c6ccc7cc8ccccc8cc7c6)n5)c4c3)ccc2c1 ; c1ccc(-c2nc(-c3ccccc3-c3ccccc3)nc(-c3cccc4ccc(-c5ccc6ccccc6c5)cc34)n2)cc1 ; c1ccc(-c2cccc(-c3nc(-c4ccccc4)nc(-c4cccc5ccc(-c6ccc7ccccc7c6)cc45)n3)c2)cc1]

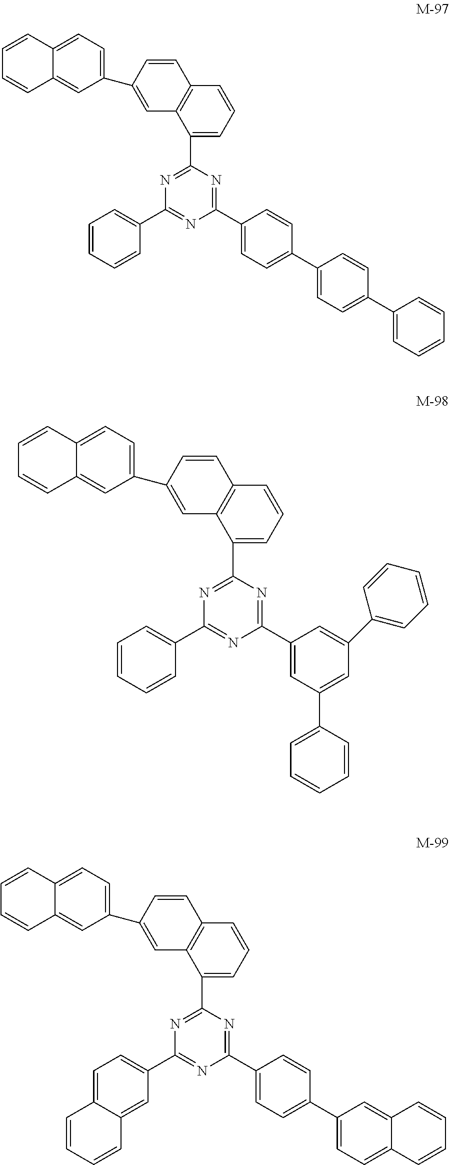 [SMILES: c1ccc(-c2ccc(-c3ccc(-c4nc(-c5ccccc5)nc(-c5cccc6ccc(-c7ccc8ccccc8c7)cc56)n4)cc3)cc2)cc1 ; c1ccc(-c2cc(-c3ccccc3)cc(-c3nc(-c4ccccc4)nc(-c4cccc5ccc(-c6ccc7ccccc7c6)cc45)n3)c2)cc1 ; c1ccc2cc(-c3ccc(-c4nc(-c5ccc6ccccc6c5)nc(-c5cccc6ccc(-c7ccc8ccccc8c7)cc56)n4)cc3)ccc2c1]

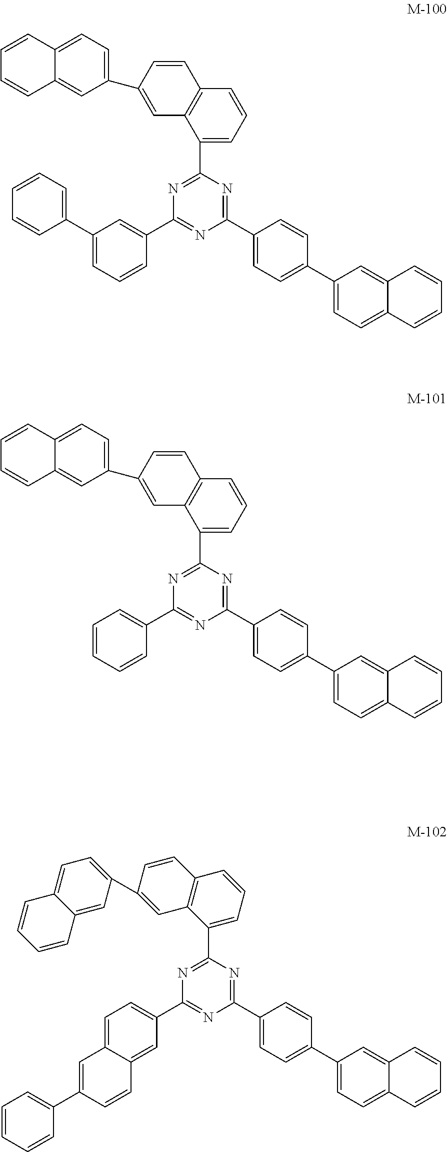 [SMILES: c1ccc(-c2cccc(-c3nc(-c4ccc(-c5ccc6ccccc6c5)cc4)nc(-c4cccc5ccc(-c6ccc7ccccc7c6)cc45)n3)c2)cc1 ; c1ccc(-c2nc(-c3ccc(-c4ccc5ccccc5c4)cc3)nc(-c3cccc4ccc(-c5ccc6ccccc6c5)cc34)n2)cc1 ; c1ccc(-c2ccc3cc(-c4nc(-c5ccc(-c6ccc7ccccc7c6)cc5)nc(-c5cccc6ccc(-c7ccc8ccccc8c7)cc56)n4)ccc3c2)cc1]

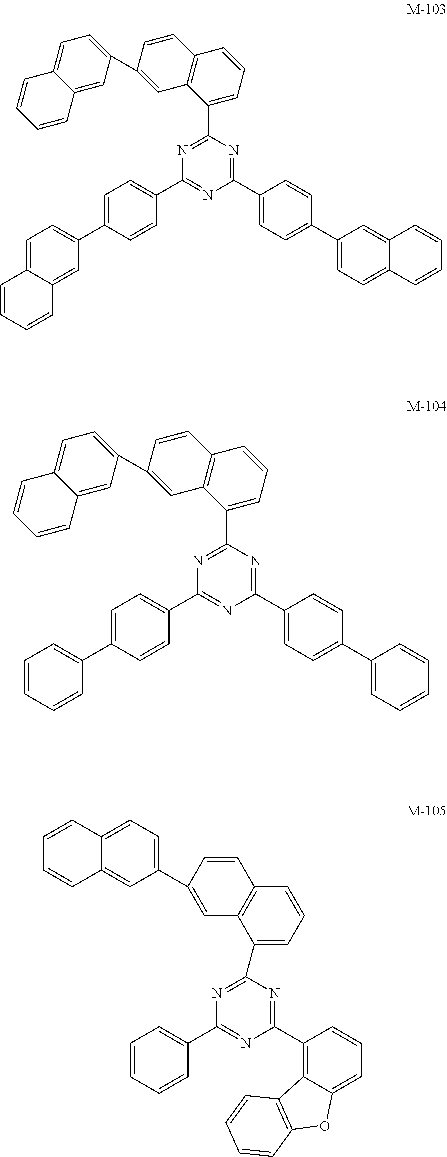 [SMILES: c1ccc2cc(-c3ccc(-c4nc(-c5ccc(-c6ccc7ccccc7c6)cc5)nc(-c5cccc6ccc(-c7ccc8ccccc8c7)cc56)n4)cc3)ccc2c1 ; c1ccc(-c2ccc(-c3nc(-c4ccc(-c5ccccc5)cc4)nc(-c4cccc5ccc(-c6ccc7ccccc7c6)cc45)n3)cc2)cc1 ; c1ccc(-c2nc(-c3cccc4ccc(-c5ccc6ccccc6c5)cc34)nc(-c3cccc4oc5ccccc5c34)n2)cc1]

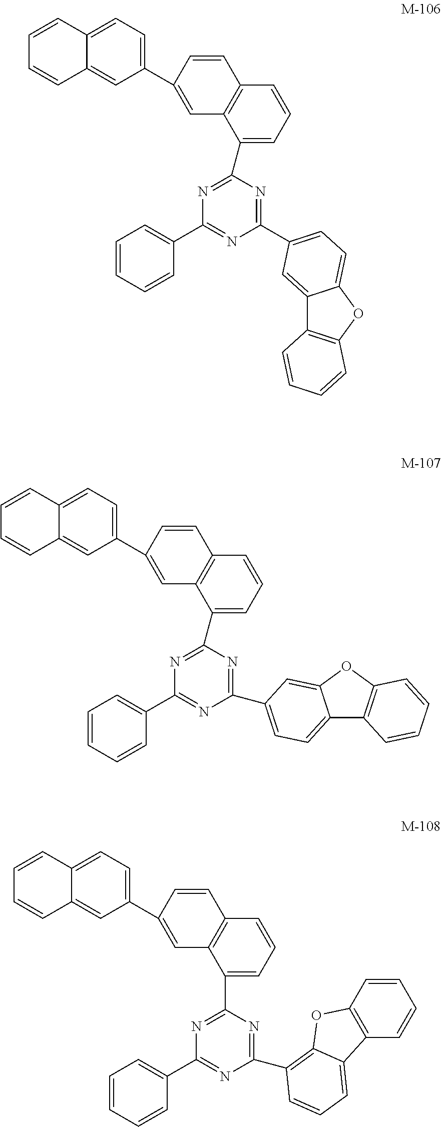 [SMILES: c1ccc(-c2nc(-c3ccc4oc5ccccc5c4c3)nc(-c3cccc4ccc(-c5ccc6ccccc6c5)cc34)n2)cc1 ; c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3cccc4ccc(-c5ccc6ccccc6c5)cc34)nc(-c3cccc4c3oc3ccccc34)n2)cc1]

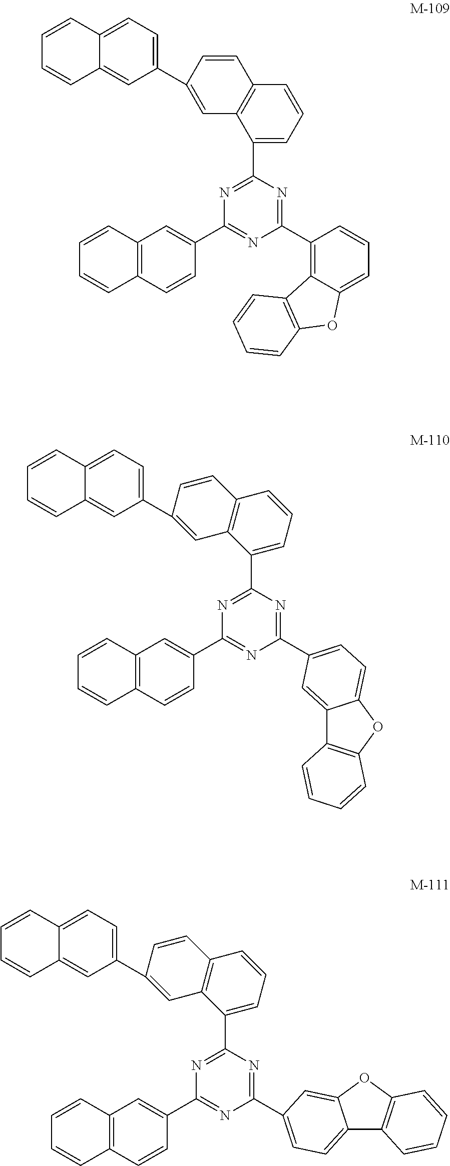 [SMILES: c1ccc2cc(-c3ccc4cccc(-c5nc(-c6ccc7ccccc7c6)nc(-c6cccc7oc8ccccc8c67)n5)c4c3)ccc2c1 ; c1ccc2cc(-c3ccc4cccc(-c5nc(-c6ccc7ccccc7c6)nc(-c6ccc7oc8ccccc8c7c6)n5)c4c3)ccc2c1 ; c1ccc2cc(-c3ccc4cccc(-c5nc(-c6ccc7ccccc7c6)nc(-c6ccc7c(c6)oc6ccccc67)n5)c4c3)ccc2c1]

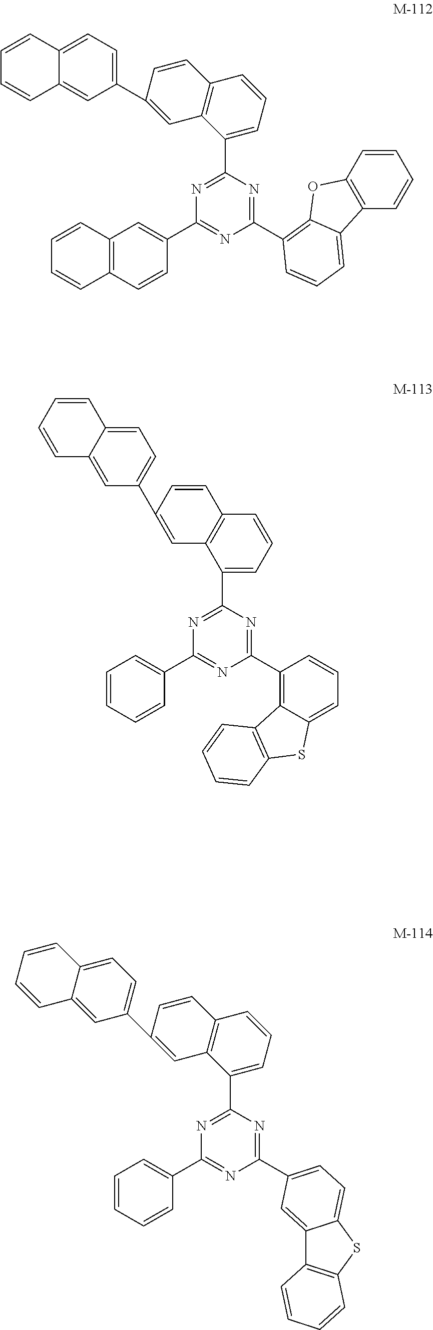 [SMILES: c1ccc2cc(-c3ccc4cccc(-c5nc(-c6ccc7ccccc7c6)nc(-c6cccc7c6oc6ccccc67)n5)c4c3)ccc2c1 ; c1ccc(-c2nc(-c3cccc4ccc(-c5ccc6ccccc6c5)cc34)nc(-c3cccc4sc5ccccc5c34)n2)cc1 ; c1ccc(-c2nc(-c3ccc4sc5ccccc5c4c3)nc(-c3cccc4ccc(-c5ccc6ccccc6c5)cc34)n2)cc1]

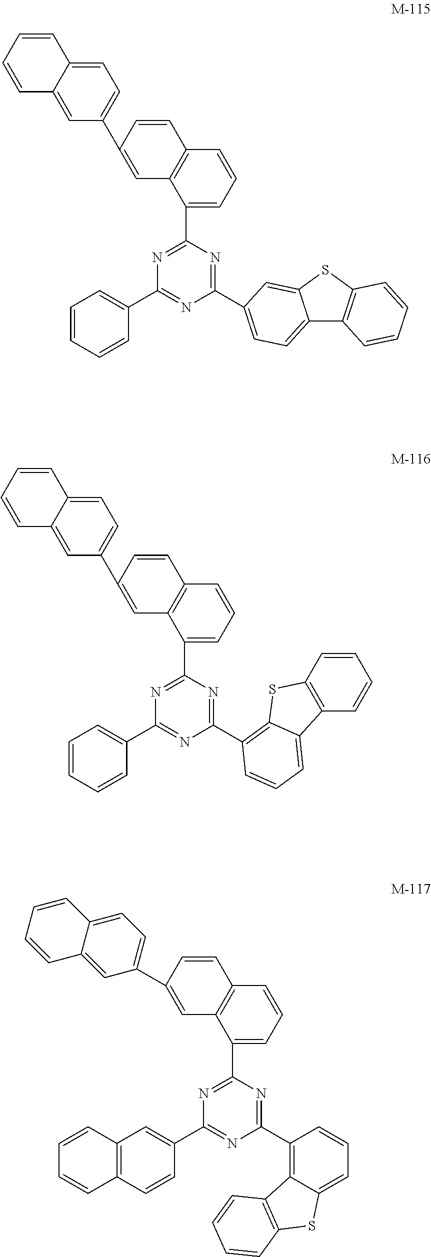 [SMILES: c1ccc(-c2nc(-c3ccc4c(c3)sc3ccccc34)nc(-c3cccc4ccc(-c5ccc6ccccc6c5)cc34)n2)cc1 ; c1ccc(-c2nc(-c3cccc4ccc(-c5ccc6ccccc6c5)cc34)nc(-c3cccc4c3sc3ccccc34)n2)cc1 ; c1ccc2cc(-c3ccc4cccc(-c5nc(-c6ccc7ccccc7c6)nc(-c6cccc7sc8ccccc8c67)n5)c4c3)ccc2c1]

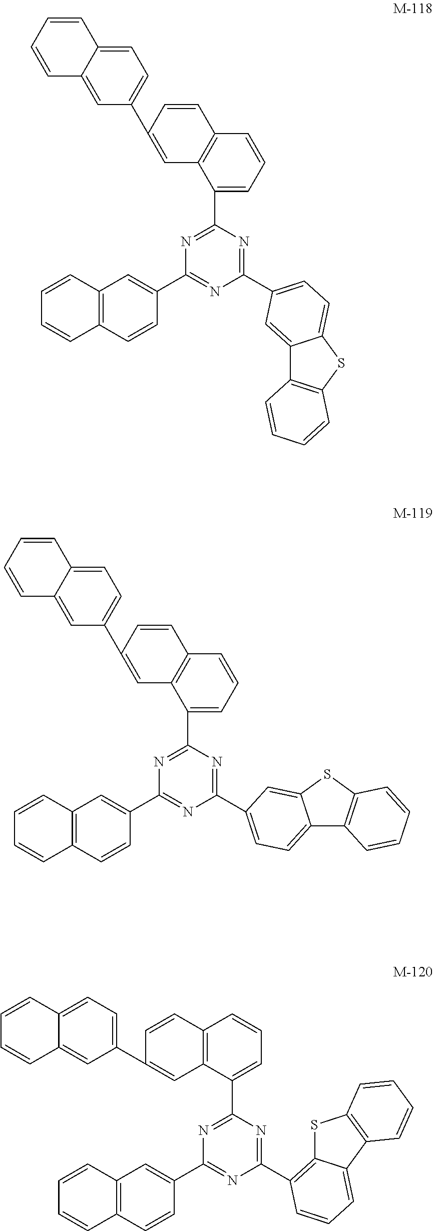 [SMILES: c1ccc2cc(-c3ccc4cccc(-c5nc(-c6ccc7ccccc7c6)nc(-c6ccc7sc8ccccc8c7c6)n5)c4c3)ccc2c1 ; c1ccc2cc(-c3ccc4cccc(-c5nc(-c6ccc7ccccc7c6)nc(-c6ccc7c(c6)sc6ccccc67)n5)c4c3)ccc2c1 ; c1ccc2cc(-c3ccc4cccc(-c5nc(-c6ccc7ccccc7c6)nc(-c6cccc7c6sc6ccccc67)n5)c4c3)ccc2c1]

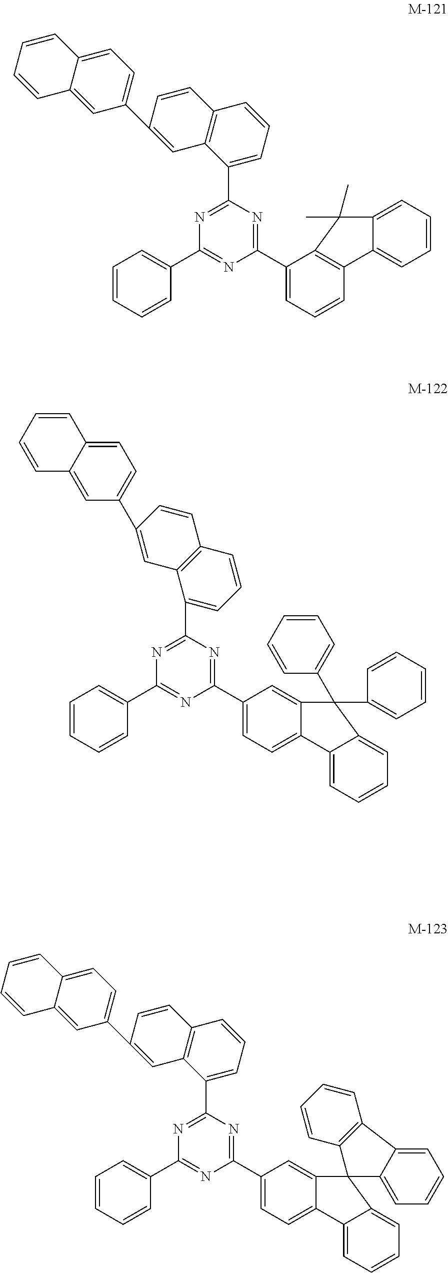 [SMILES: CC1(C)c2ccccc2-c2cccc(-c3nc(-c4ccccc4)nc(-c4cccc5ccc(-c6ccc7ccccc7c6)cc45)n3)c21 ; c1ccc(-c2nc(-c3ccc4c(c3)C(c3ccccc3)(c3ccccc3)c3ccccc3-4)nc(-c3cccc4ccc(-c5ccc6ccccc6c5)cc34)n2)cc1 ; c1ccc(-c2nc(-c3ccc4c(c3)C3(c5ccccc5-c5ccccc53)c3ccccc3-4)nc(-c3cccc4ccc(-c5ccc6ccccc6c5)cc34)n2)cc1]

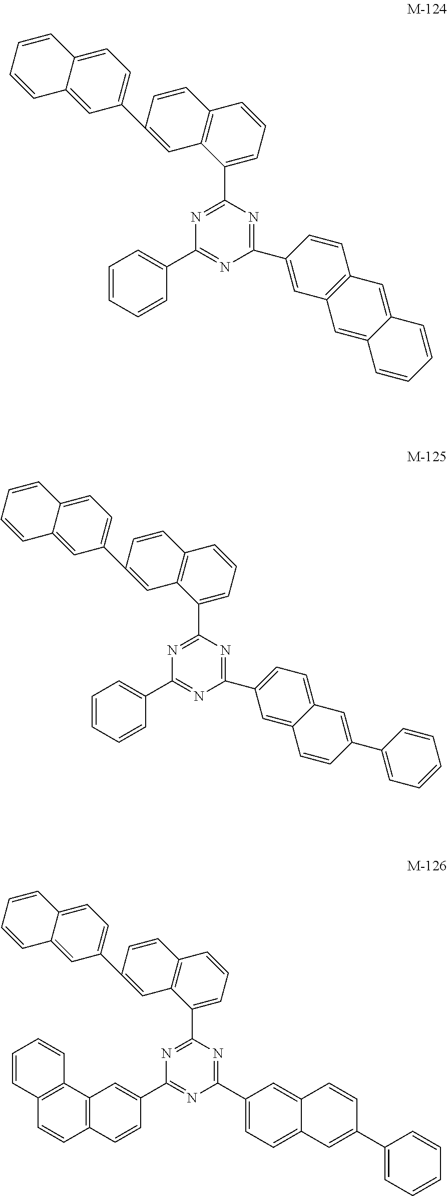 [SMILES: c1ccc(-c2nc(-c3ccc4cc5ccccc5cc4c3)nc(-c3cccc4ccc(-c5ccc6ccccc6c5)cc34)n2)cc1 ; c1ccc(-c2ccc3cc(-c4nc(-c5ccccc5)nc(-c5cccc6ccc(-c7ccc8ccccc8c7)cc56)n4)ccc3c2)cc1 ; c1ccc(-c2ccc3cc(-c4nc(-c5ccc6ccc7ccccc7c6c5)nc(-c5cccc6ccc(-c7ccc8ccccc8c7)cc56)n4)ccc3c2)cc1]

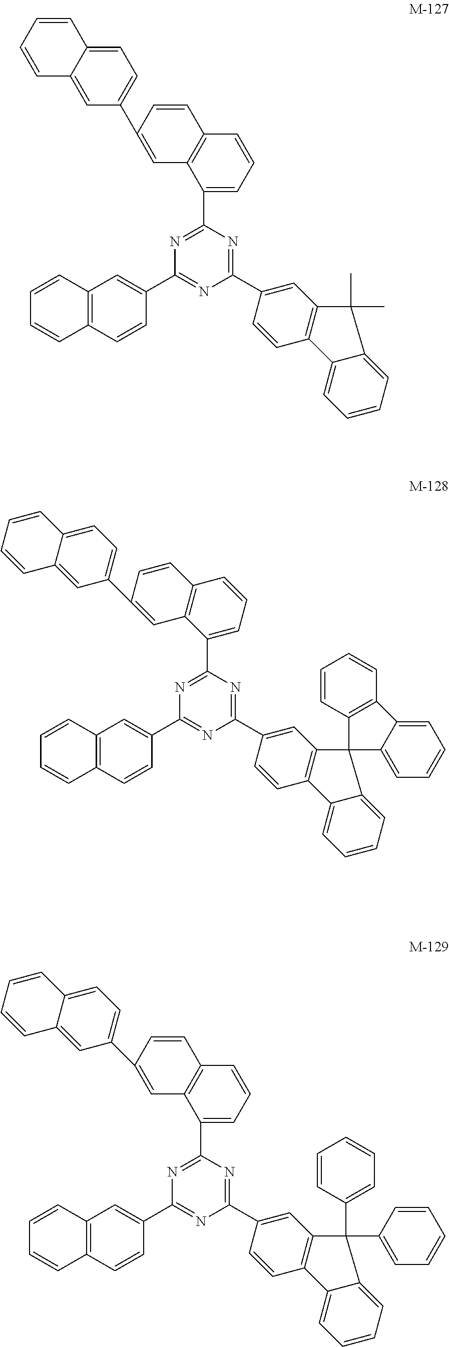 [SMILES: CC1(C)c2ccccc2-c2ccc(-c3nc(-c4ccc5ccccc5c4)nc(-c4cccc5ccc(-c6ccc7ccccc7c6)cc45)n3)cc21 ; c1ccc2c(c1)-c1ccccc1C21c2ccccc2-c2ccc(-c3nc(-c4ccc5ccccc5c4)nc(-c4cccc5ccc(-c6ccc7ccccc7c6)cc45)n3)cc21 ; c1ccc(C2(c3ccccc3)c3ccccc3-c3ccc(-c4nc(-c5ccc6ccccc6c5)nc(-c5cccc6ccc(-c7ccc8ccccc8c7)cc56)n4)cc32)cc1]

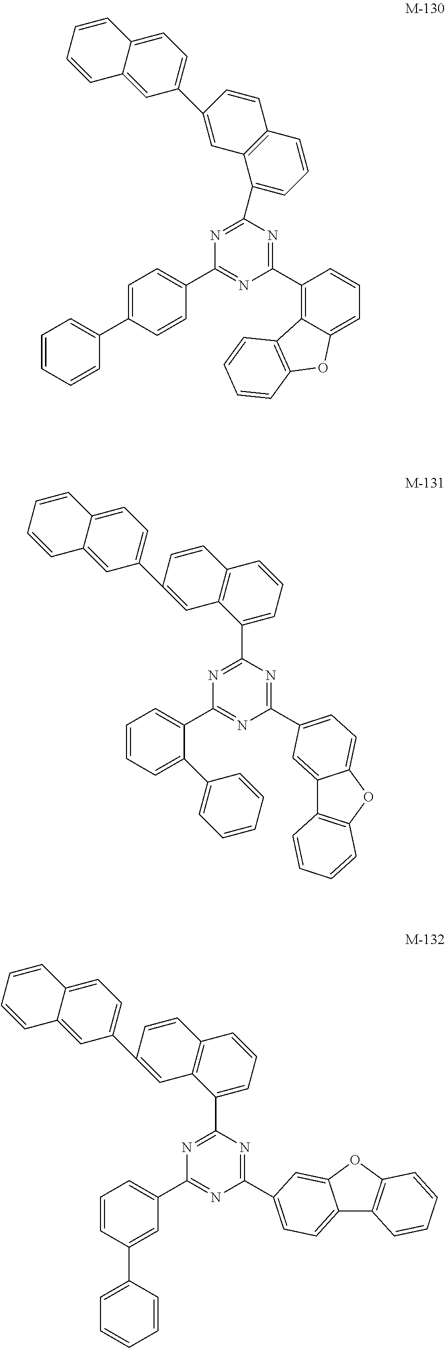 [SMILES: c1ccc(-c2ccc(-c3nc(-c4cccc5ccc(-c6ccc7ccccc7c6)cc45)nc(-c4cccc5oc6ccccc6c45)n3)cc2)cc1 ; c1ccc(-c2ccccc2-c2nc(-c3ccc4oc5ccccc5c4c3)nc(-c3cccc4ccc(-c5ccc6ccccc6c5)cc34)n2)cc1 ; c1ccc(-c2cccc(-c3nc(-c4ccc5c(c4)oc4ccccc45)nc(-c4cccc5ccc(-c6ccc7ccccc7c6)cc45)n3)c2)cc1]

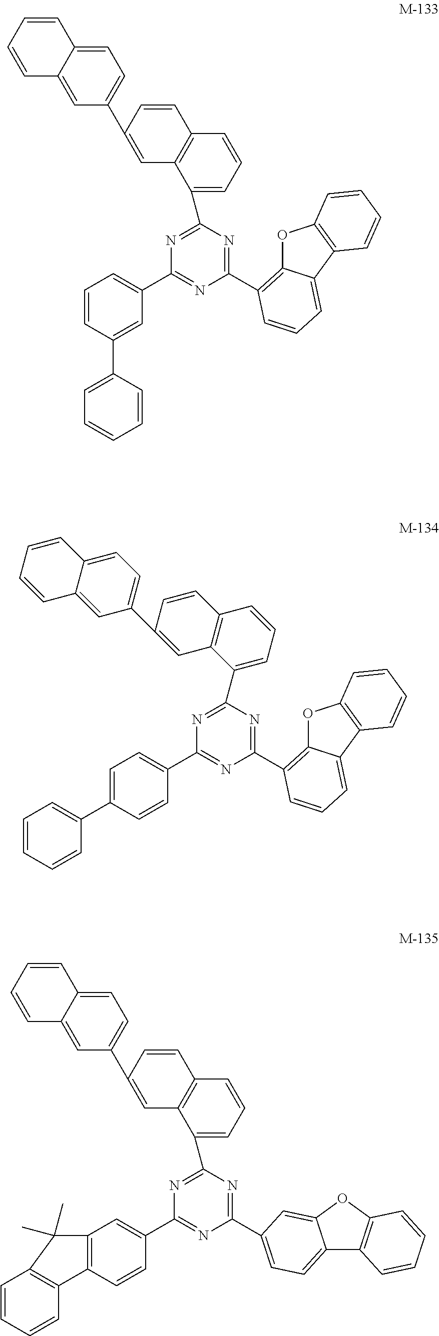 [SMILES: c1ccc(-c2cccc(-c3nc(-c4cccc5ccc(-c6ccc7ccccc7c6)cc45)nc(-c4cccc5c4oc4ccccc45)n3)c2)cc1 ; c1ccc(-c2ccc(-c3nc(-c4cccc5ccc(-c6ccc7ccccc7c6)cc45)nc(-c4cccc5c4oc4ccccc45)n3)cc2)cc1 ; CC1(C)c2ccccc2-c2ccc(-c3nc(-c4ccc5c(c4)oc4ccccc45)nc(-c4cccc5ccc(-c6ccc7ccccc7c6)cc45)n3)cc21]

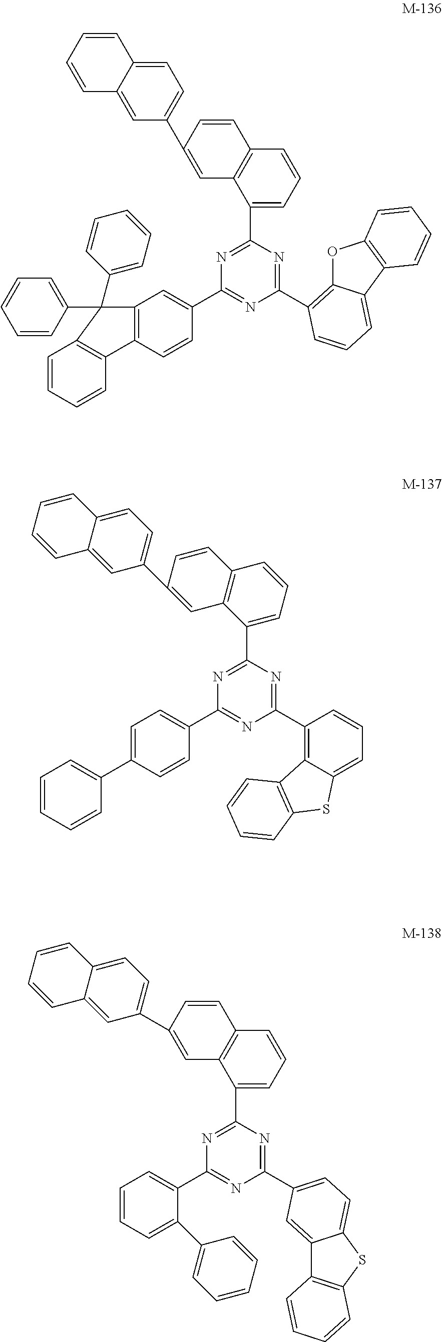 [SMILES: c1ccc(C2(c3ccccc3)c3ccccc3-c3ccc(-c4nc(-c5cccc6ccc(-c7ccc8ccccc8c7)cc56)nc(-c5cccc6c5oc5ccccc56)n4)cc32)cc1 ; c1ccc(-c2ccc(-c3nc(-c4cccc5ccc(-c6ccc7ccccc7c6)cc45)nc(-c4cccc5sc6ccccc6c45)n3)cc2)cc1 ; c1ccc(-c2ccccc2-c2nc(-c3ccc4sc5ccccc5c4c3)nc(-c3cccc4ccc(-c5ccc6ccccc6c5)cc34)n2)cc1]

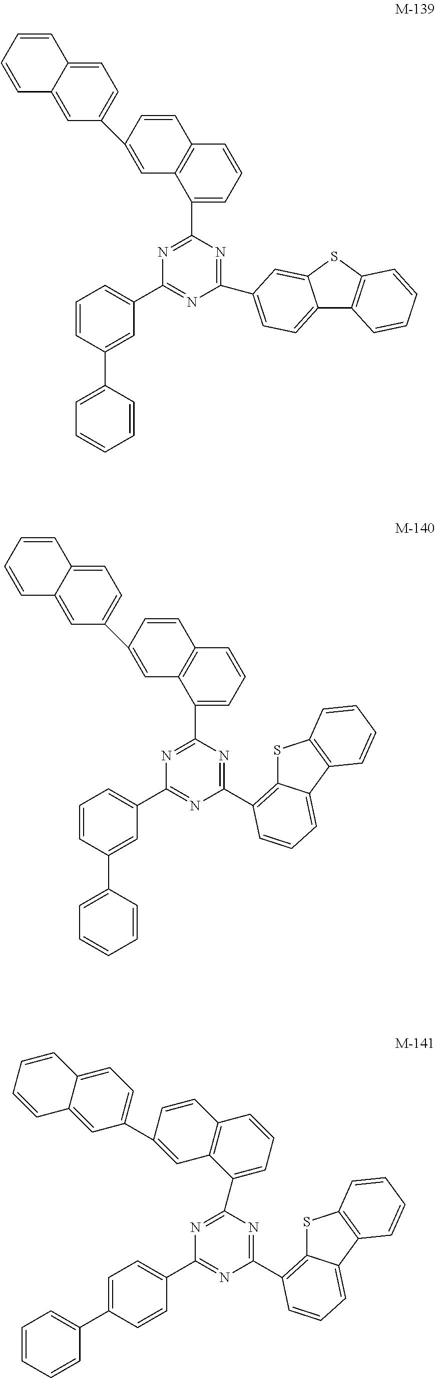 [SMILES: c1ccc(-c2cccc(-c3nc(-c4ccc5c(c4)sc4ccccc45)nc(-c4cccc5ccc(-c6ccc7ccccc7c6)cc45)n3)c2)cc1 ; c1ccc(-c2cccc(-c3nc(-c4cccc5ccc(-c6ccc7ccccc7c6)cc45)nc(-c4cccc5c4sc4ccccc45)n3)c2)cc1 ; c1ccc(-c2ccc(-c3nc(-c4cccc5ccc(-c6ccc7ccccc7c6)cc45)nc(-c4cccc5c4sc4ccccc45)n3)cc2)cc1]

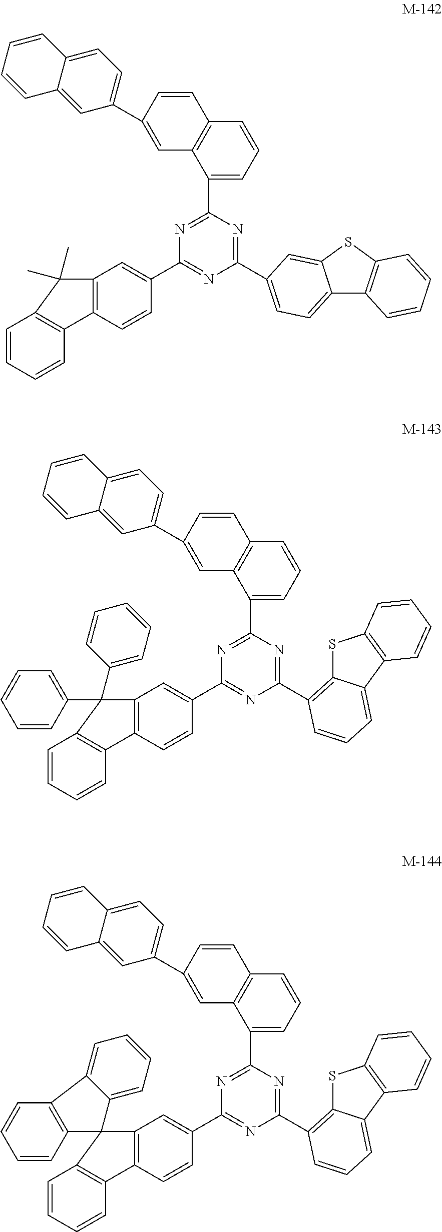 [SMILES: CC1(C)c2ccccc2-c2ccc(-c3nc(-c4ccc5c(c4)sc4ccccc45)nc(-c4cccc5ccc(-c6ccc7ccccc7c6)cc45)n3)cc21 ; c1ccc(C2(c3ccccc3)c3ccccc3-c3ccc(-c4nc(-c5cccc6ccc(-c7ccc8ccccc8c7)cc56)nc(-c5cccc6c5sc5ccccc56)n4)cc32)cc1 ; c1ccc2c(c1)-c1ccccc1C21c2ccccc2-c2ccc(-c3nc(-c4cccc5ccc(-c6ccc7ccccc7c6)cc45)nc(-c4cccc5c4sc4ccccc45)n3)cc21]

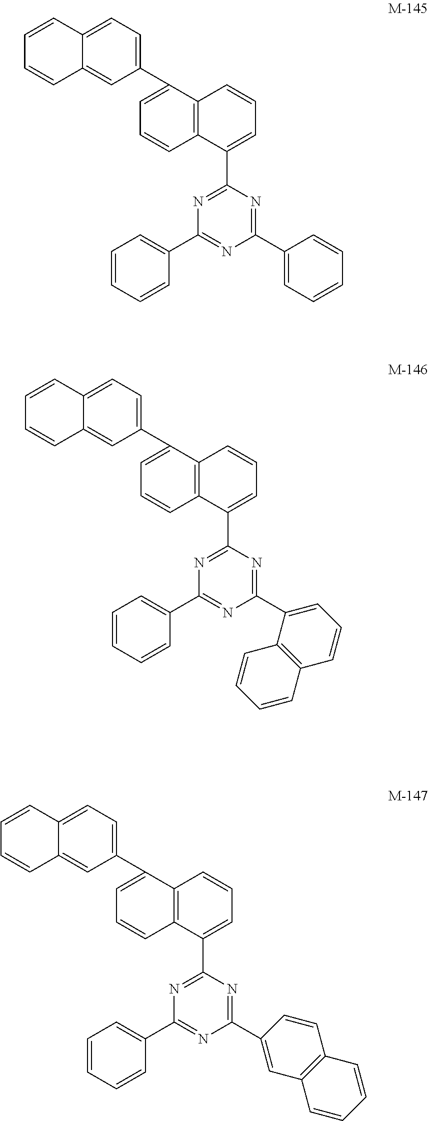 [SMILES: c1ccc(-c2nc(-c3ccccc3)nc(-c3cccc4c(-c5ccc6ccccc6c5)cccc34)n2)cc1 ; c1ccc(-c2nc(-c3cccc4ccccc34)nc(-c3cccc4c(-c5ccc6ccccc6c5)cccc34)n2)cc1 ; c1ccc(-c2nc(-c3ccc4ccccc4c3)nc(-c3cccc4c(-c5ccc6ccccc6c5)cccc34)n2)cc1]

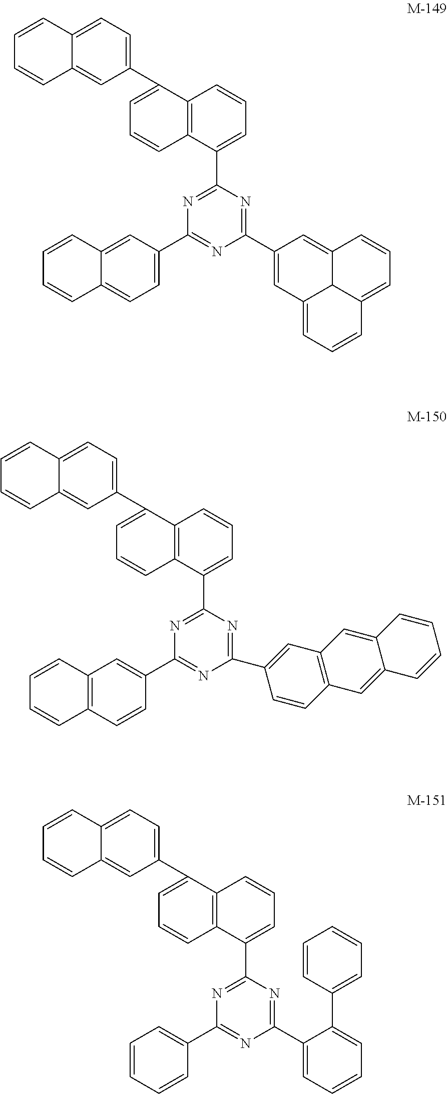 [SMILES: C1=CC2=CC=CC3=CC(c4nc(-c5ccc6ccccc6c5)nc(-c5cccc6c(-c7ccc8ccccc8c7)cccc56)n4)=CC(=C1)C23 ; c1ccc2cc(-c3nc(-c4ccc5cc6ccccc6cc5c4)nc(-c4cccc5c(-c6ccc7ccccc7c6)cccc45)n3)ccc2c1 ; c1ccc(-c2nc(-c3ccccc3-c3ccccc3)nc(-c3cccc4c(-c5ccc6ccccc6c5)cccc34)n2)cc1]

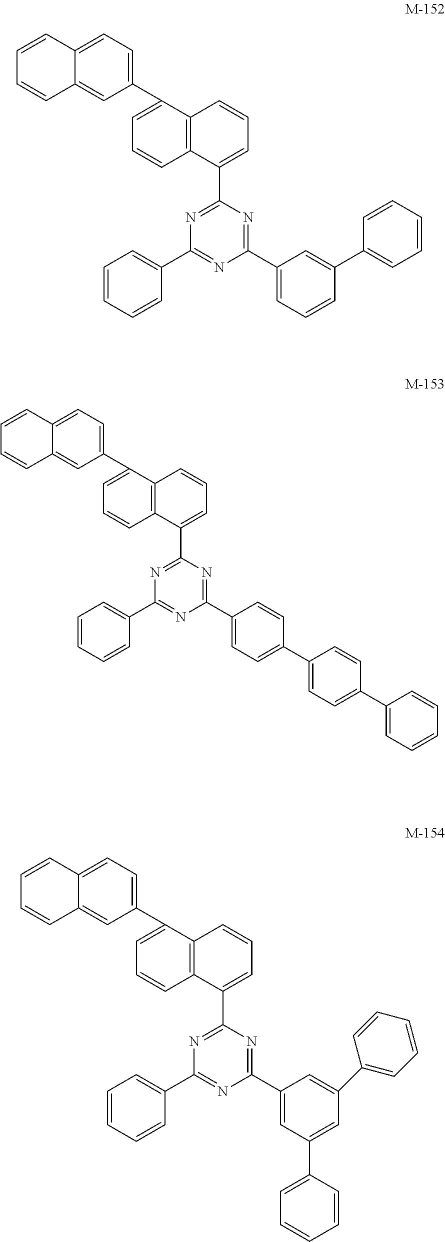 [SMILES: c1ccc(-c2cccc(-c3nc(-c4ccccc4)nc(-c4cccc5c(-c6ccc7ccccc7c6)cccc45)n3)c2)cc1 ; c1ccc(-c2ccc(-c3ccc(-c4nc(-c5ccccc5)nc(-c5cccc6c(-c7ccc8ccccc8c7)cccc56)n4)cc3)cc2)cc1 ; c1ccc(-c2cc(-c3ccccc3)cc(-c3nc(-c4ccccc4)nc(-c4cccc5c(-c6ccc7ccccc7c6)cccc45)n3)c2)cc1]

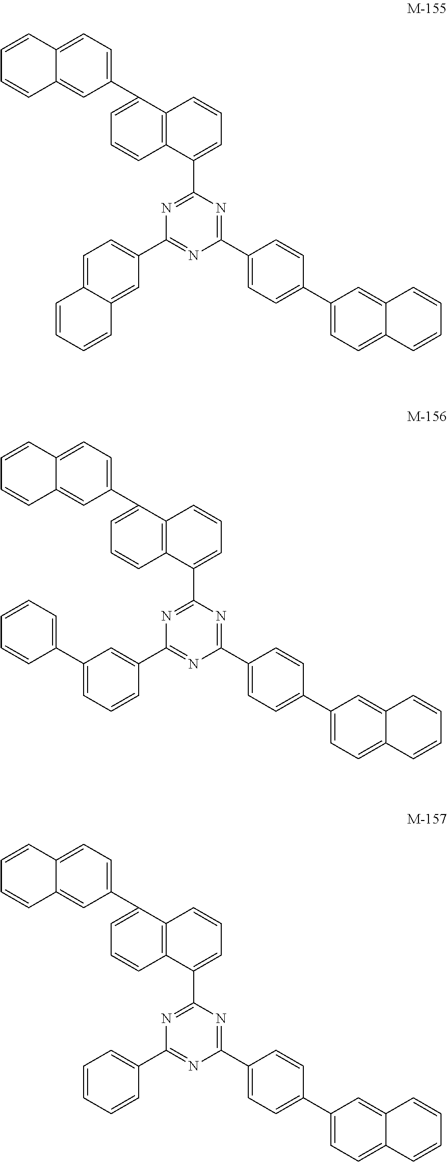 [SMILES: c1ccc2cc(-c3ccc(-c4nc(-c5ccc6ccccc6c5)nc(-c5cccc6c(-c7ccc8ccccc8c7)cccc56)n4)cc3)ccc2c1 ; c1ccc(-c2cccc(-c3nc(-c4ccc(-c5ccc6ccccc6c5)cc4)nc(-c4cccc5c(-c6ccc7ccccc7c6)cccc45)n3)c2)cc1 ; c1ccc(-c2nc(-c3ccc(-c4ccc5ccccc5c4)cc3)nc(-c3cccc4c(-c5ccc6ccccc6c5)cccc34)n2)cc1]

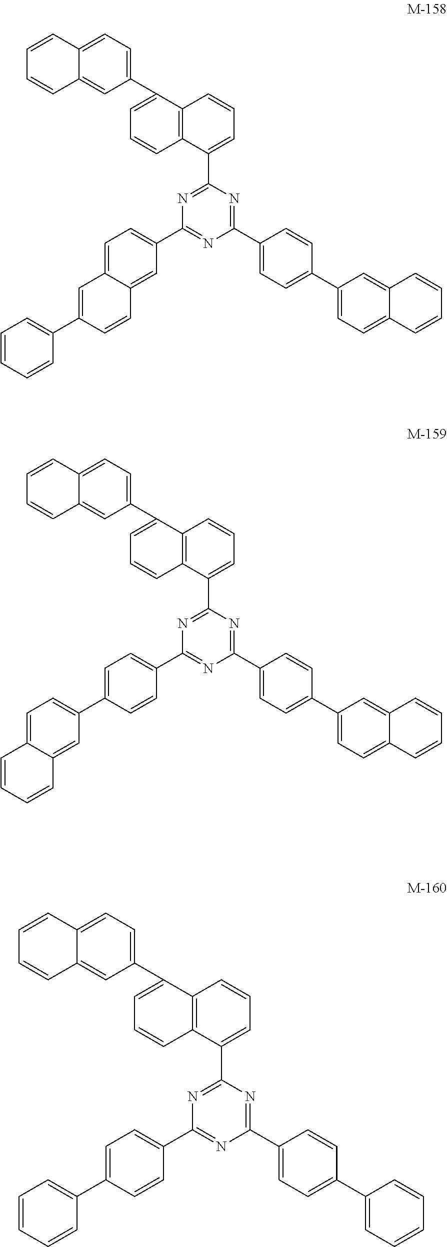 [SMILES: c1ccc(-c2ccc3cc(-c4nc(-c5ccc(-c6ccc7ccccc7c6)cc5)nc(-c5cccc6c(-c7ccc8ccccc8c7)cccc56)n4)ccc3c2)cc1 ; c1ccc2cc(-c3ccc(-c4nc(-c5ccc(-c6ccc7ccccc7c6)cc5)nc(-c5cccc6c(-c7ccc8ccccc8c7)cccc56)n4)cc3)ccc2c1 ; c1ccc(-c2ccc(-c3nc(-c4ccc(-c5ccccc5)cc4)nc(-c4cccc5c(-c6ccc7ccccc7c6)cccc45)n3)cc2)cc1]

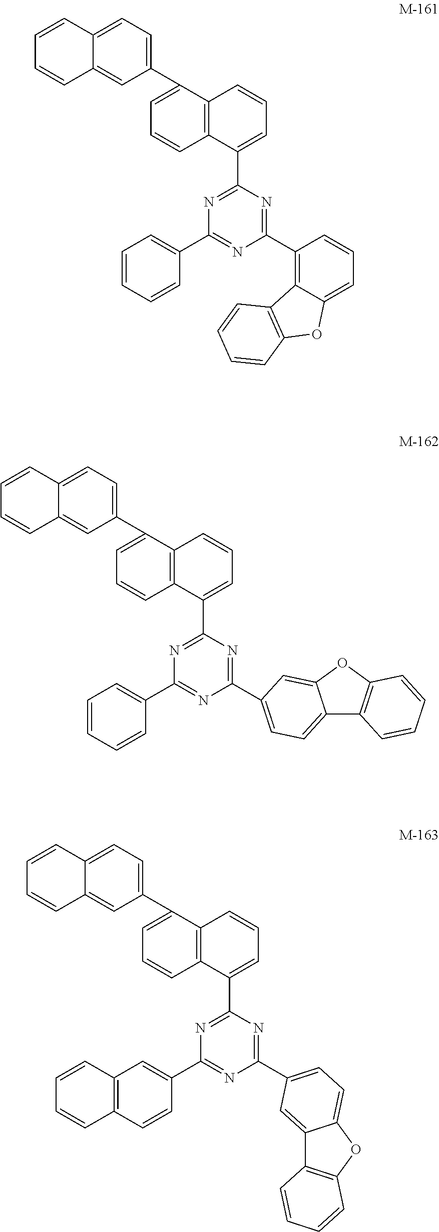 [SMILES: c1ccc(-c2nc(-c3cccc4c(-c5ccc6ccccc6c5)cccc34)nc(-c3cccc4oc5ccccc5c34)n2)cc1 ; c1ccc(-c2nc(-c3ccc4c(c3)oc3ccccc34)nc(-c3cccc4c(-c5ccc6ccccc6c5)cccc34)n2)cc1 ; c1ccc2cc(-c3nc(-c4ccc5oc6ccccc6c5c4)nc(-c4cccc5c(-c6ccc7ccccc7c6)cccc45)n3)ccc2c1]

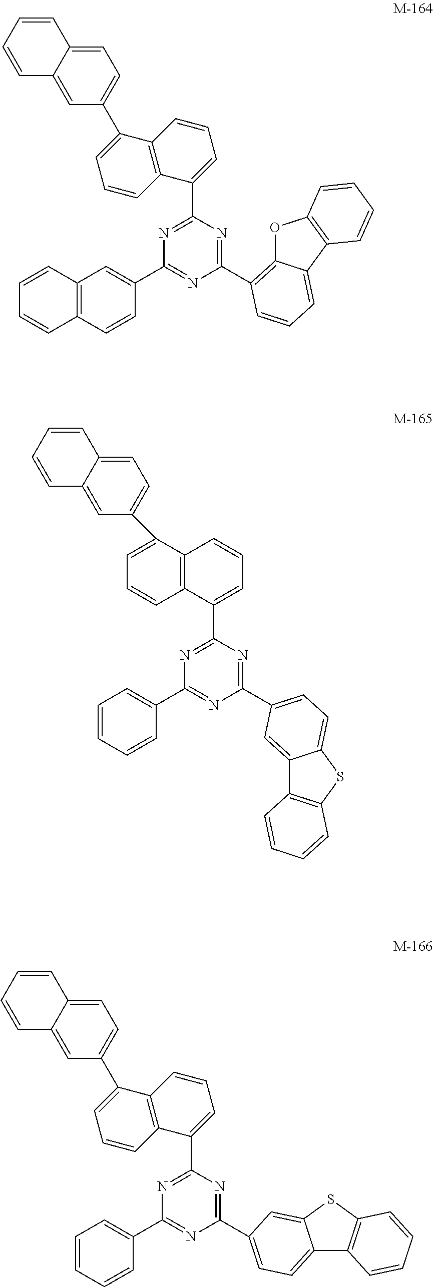 [SMILES: c1ccc2cc(-c3nc(-c4cccc5c(-c6ccc7ccccc7c6)cccc45)nc(-c4cccc5c4oc4ccccc45)n3)ccc2c1 ; c1ccc(-c2nc(-c3ccc4sc5ccccc5c4c3)nc(-c3cccc4c(-c5ccc6ccccc6c5)cccc34)n2)cc1 ; c1ccc(-c2nc(-c3ccc4c(c3)sc3ccccc34)nc(-c3cccc4c(-c5ccc6ccccc6c5)cccc34)n2)cc1]

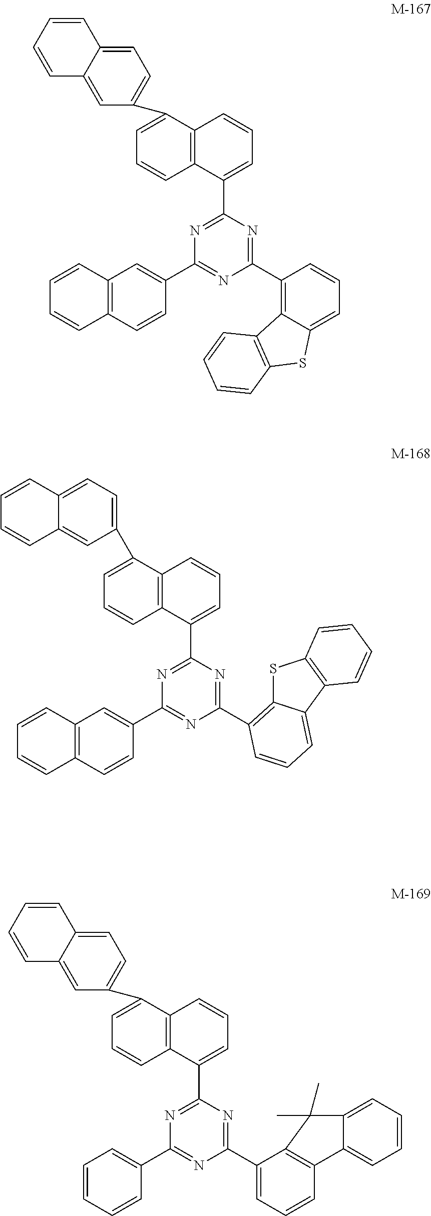 [SMILES: c1ccc2cc(-c3nc(-c4cccc5c(-c6ccc7ccccc7c6)cccc45)nc(-c4cccc5sc6ccccc6c45)n3)ccc2c1 ; c1ccc2cc(-c3nc(-c4cccc5c(-c6ccc7ccccc7c6)cccc45)nc(-c4cccc5c4sc4ccccc45)n3)ccc2c1 ; CC1(C)c2ccccc2-c2cccc(-c3nc(-c4ccccc4)nc(-c4cccc5c(-c6ccc7ccccc7c6)cccc45)n3)c21]

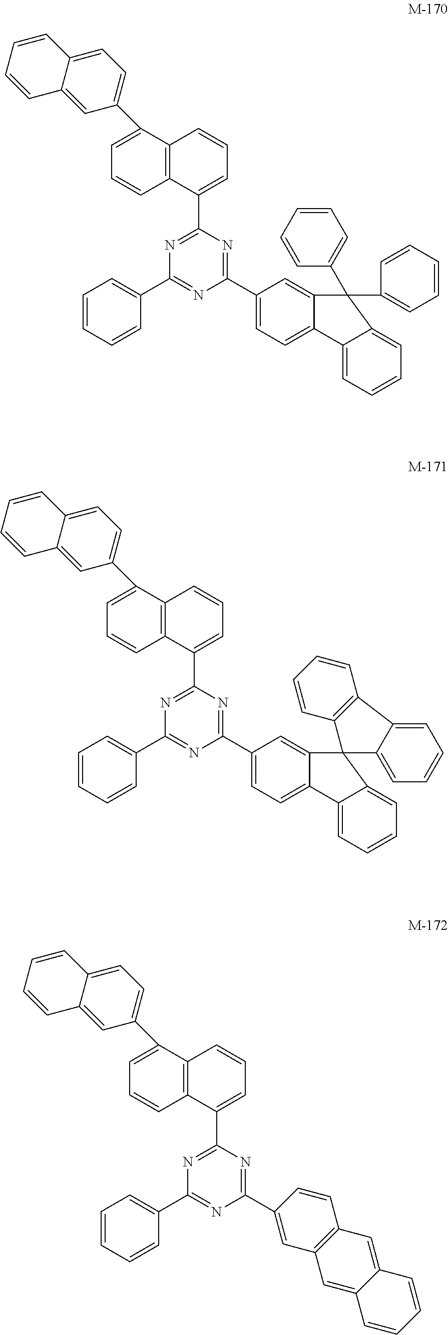 [SMILES: c1ccc(-c2nc(-c3ccc4c(c3)C(c3ccccc3)(c3ccccc3)c3ccccc3-4)nc(-c3cccc4c(-c5ccc6ccccc6c5)cccc34)n2)cc1 ; c1ccc(-c2nc(-c3ccc4c(c3)C3(c5ccccc5-c5ccccc53)c3ccccc3-4)nc(-c3cccc4c(-c5ccc6ccccc6c5)cccc34)n2)cc1 ; c1ccc(-c2nc(-c3ccc4cc5ccccc5cc4c3)nc(-c3cccc4c(-c5ccc6ccccc6c5)cccc34)n2)cc1]

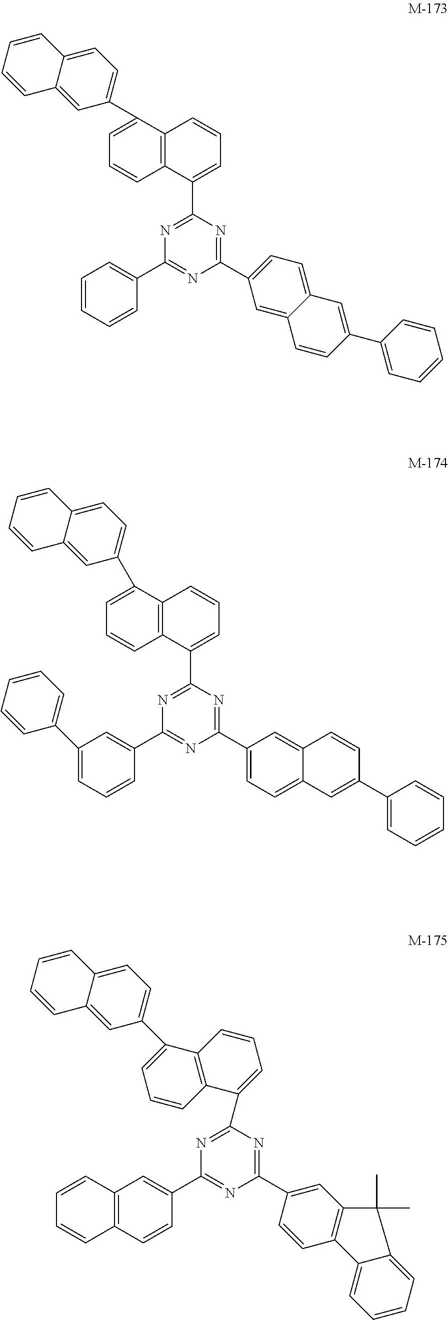 [SMILES: c1ccc(-c2ccc3cc(-c4nc(-c5ccccc5)nc(-c5cccc6c(-c7ccc8ccccc8c7)cccc56)n4)ccc3c2)cc1 ; c1ccc(-c2cccc(-c3nc(-c4ccc5cc(-c6ccccc6)ccc5c4)nc(-c4cccc5c(-c6ccc7ccccc7c6)cccc45)n3)c2)cc1 ; CC1(C)c2ccccc2-c2ccc(-c3nc(-c4ccc5ccccc5c4)nc(-c4cccc5c(-c6ccc7ccccc7c6)cccc45)n3)cc21]

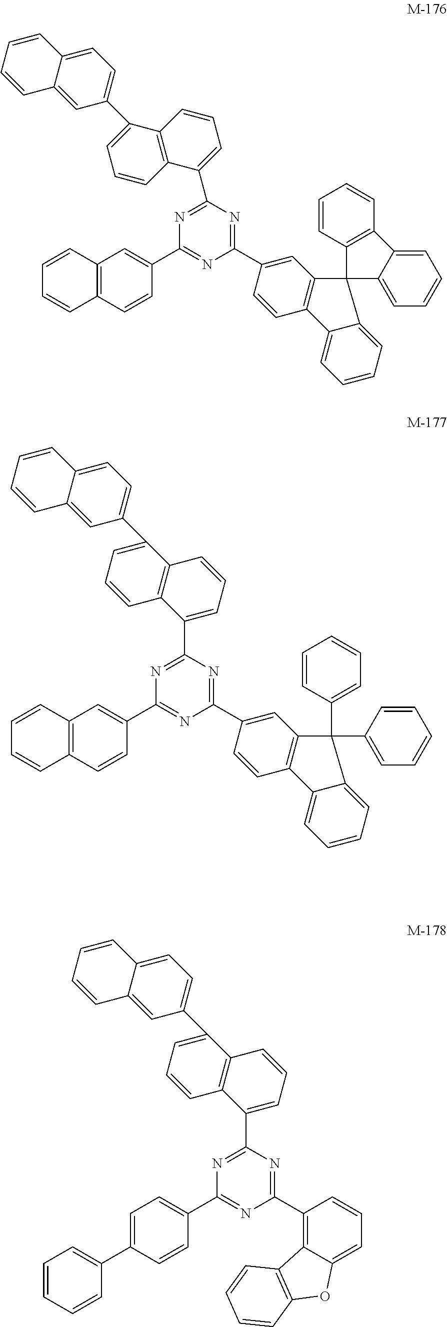 [SMILES: c1ccc2c(c1)-c1ccccc1C21c2ccccc2-c2ccc(-c3nc(-c4ccc5ccccc5c4)nc(-c4cccc5c(-c6ccc7ccccc7c6)cccc45)n3)cc21 ; c1ccc(C2(c3ccccc3)c3ccccc3-c3ccc(-c4nc(-c5ccc6ccccc6c5)nc(-c5cccc6c(-c7ccc8ccccc8c7)cccc56)n4)cc32)cc1 ; c1ccc(-c2ccc(-c3nc(-c4cccc5c(-c6ccc7ccccc7c6)cccc45)nc(-c4cccc5oc6ccccc6c45)n3)cc2)cc1]

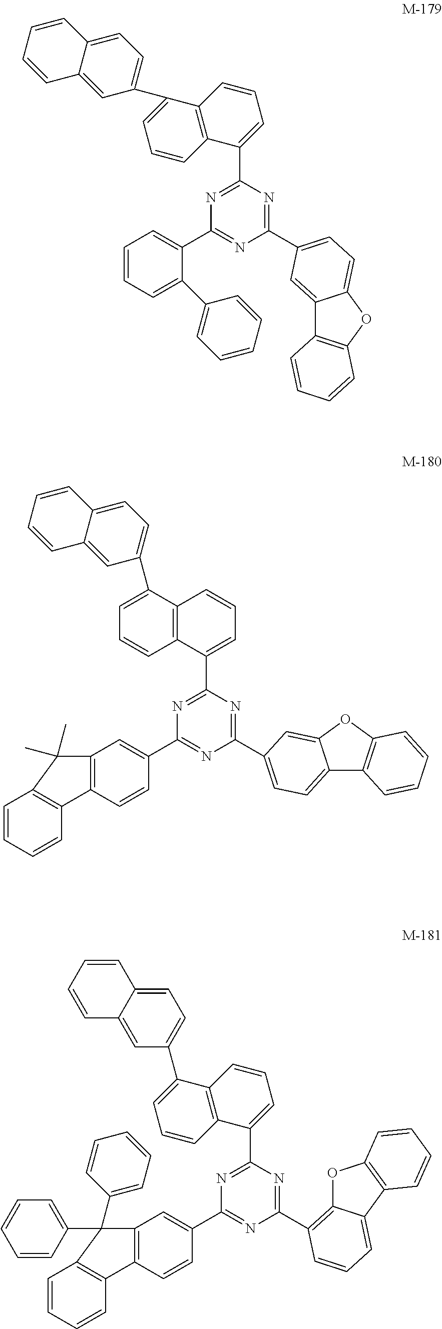 [SMILES: c1ccc(-c2ccccc2-c2nc(-c3ccc4oc5ccccc5c4c3)nc(-c3cccc4c(-c5ccc6ccccc6c5)cccc34)n2)cc1 ; CC1(C)c2ccccc2-c2ccc(-c3nc(-c4ccc5c(c4)oc4ccccc45)nc(-c4cccc5c(-c6ccc7ccccc7c6)cccc45)n3)cc21 ; c1ccc(C2(c3ccccc3)c3ccccc3-c3ccc(-c4nc(-c5cccc6c(-c7ccc8ccccc8c7)cccc56)nc(-c5cccc6c5oc5ccccc56)n4)cc32)cc1]

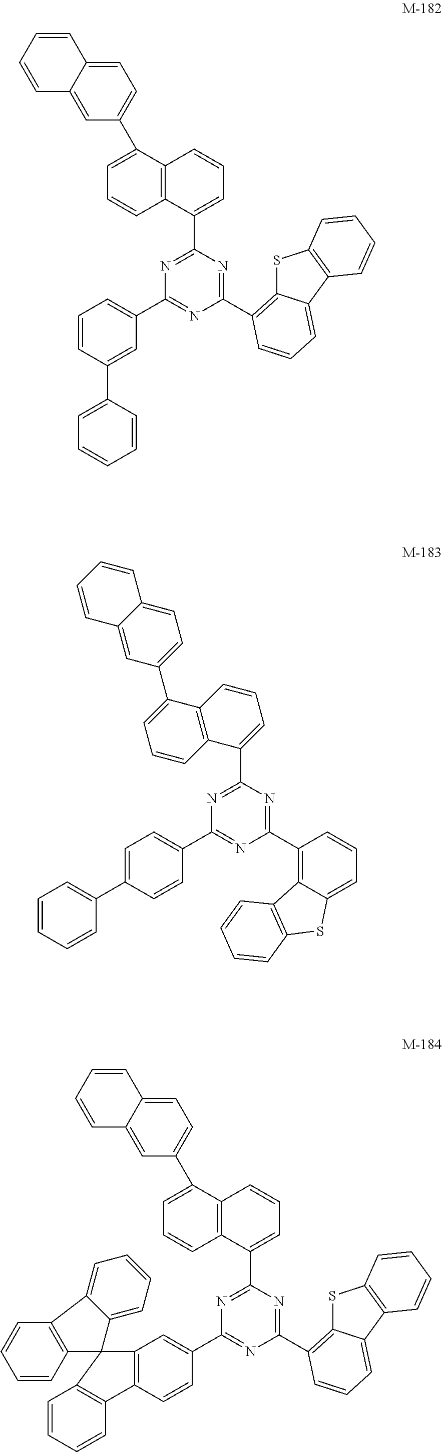 [SMILES: c1ccc(-c2cccc(-c3nc(-c4cccc5c(-c6ccc7ccccc7c6)cccc45)nc(-c4cccc5c4sc4ccccc45)n3)c2)cc1 ; c1ccc(-c2ccc(-c3nc(-c4cccc5c(-c6ccc7ccccc7c6)cccc45)nc(-c4cccc5sc6ccccc6c45)n3)cc2)cc1 ; c1ccc2c(c1)-c1ccccc1C21c2ccccc2-c2ccc(-c3nc(-c4cccc5c(-c6ccc7ccccc7c6)cccc45)nc(-c4cccc5c4sc4ccccc45)n3)cc21]

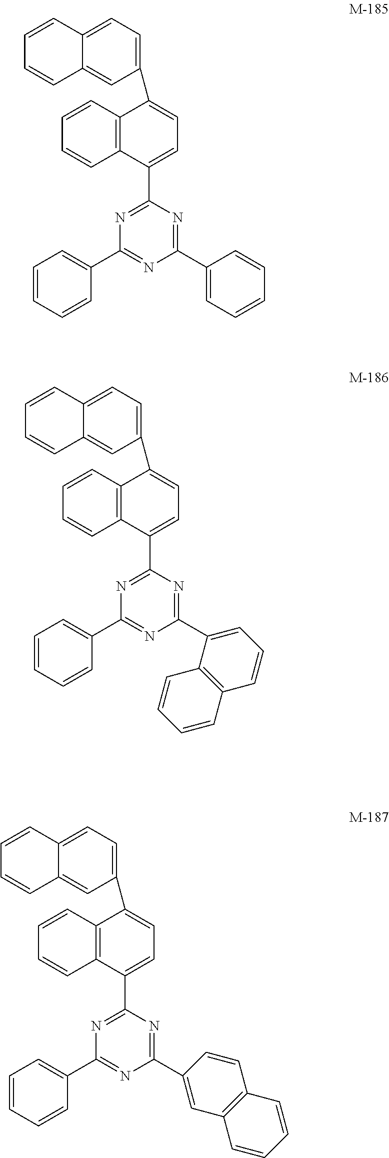 [SMILES: c1ccc(-c2nc(-c3ccccc3)nc(-c3ccc(-c4ccc5ccccc5c4)c4ccccc34)n2)cc1 ; c1ccc(-c2nc(-c3cccc4ccccc34)nc(-c3ccc(-c4ccc5ccccc5c4)c4ccccc34)n2)cc1 ; c1ccc(-c2nc(-c3ccc4ccccc4c3)nc(-c3ccc(-c4ccc5ccccc5c4)c4ccccc34)n2)cc1]

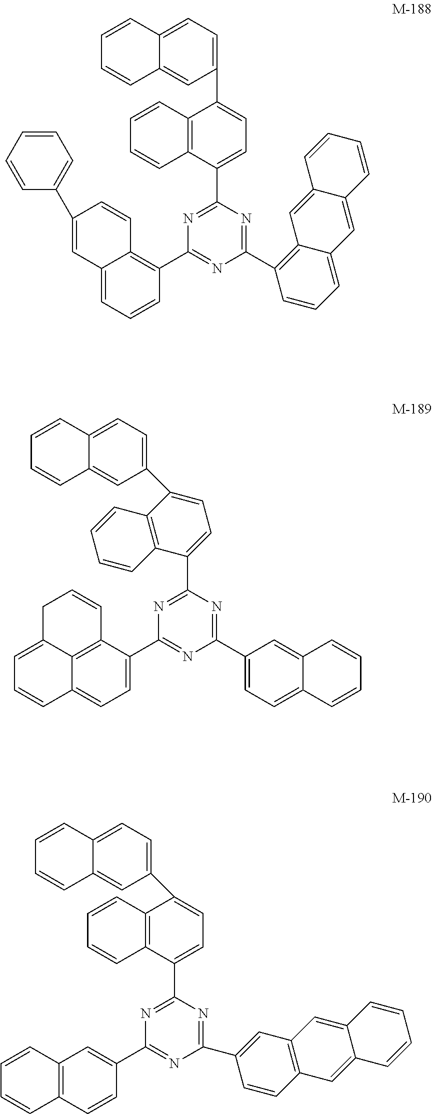 [SMILES: c1ccc(-c2ccc3c(-c4nc(-c5cccc6cc7ccccc7cc56)nc(-c5ccc(-c6ccc7ccccc7c6)c6ccccc56)n4)cccc3c2)cc1 ; C1=Cc2c(-c3nc(-c4ccc5ccccc5c4)nc(-c4ccc(-c5ccc6ccccc6c5)c5ccccc45)n3)ccc3cccc(c23)C1 ; c1ccc2cc(-c3nc(-c4ccc5cc6ccccc6cc5c4)nc(-c4ccc(-c5ccc6ccccc6c5)c5ccccc45)n3)ccc2c1]

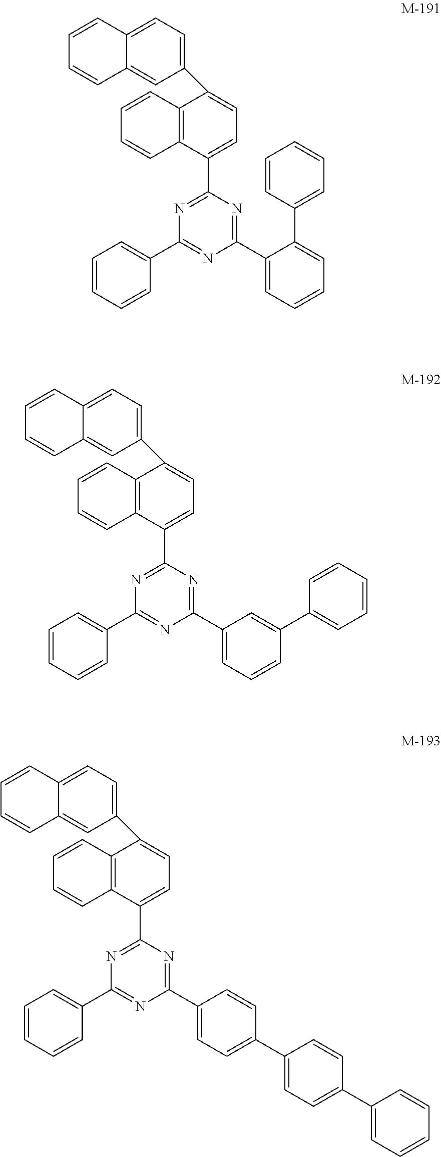 [SMILES: c1ccc(-c2nc(-c3ccccc3-c3ccccc3)nc(-c3ccc(-c4ccc5ccccc5c4)c4ccccc34)n2)cc1 ; c1ccc(-c2cccc(-c3nc(-c4ccccc4)nc(-c4ccc(-c5ccc6ccccc6c5)c5ccccc45)n3)c2)cc1 ; c1ccc(-c2ccc(-c3ccc(-c4nc(-c5ccccc5)nc(-c5ccc(-c6ccc7ccccc7c6)c6ccccc56)n4)cc3)cc2)cc1]

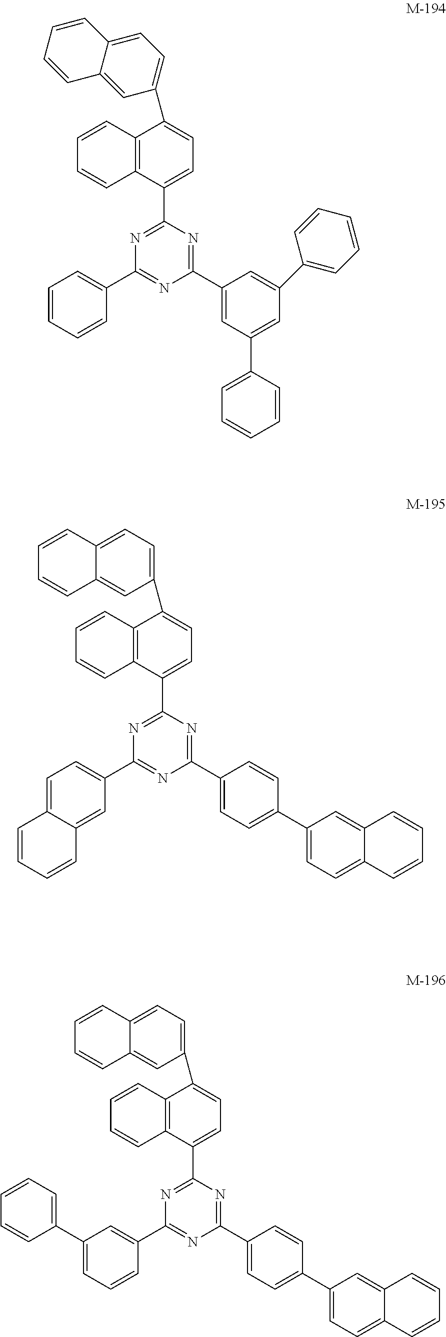 [SMILES: c1ccc(-c2cc(-c3ccccc3)cc(-c3nc(-c4ccccc4)nc(-c4ccc(-c5ccc6ccccc6c5)c5ccccc45)n3)c2)cc1 ; c1ccc2cc(-c3ccc(-c4nc(-c5ccc6ccccc6c5)nc(-c5ccc(-c6ccc7ccccc7c6)c6ccccc56)n4)cc3)ccc2c1 ; c1ccc(-c2cccc(-c3nc(-c4ccc(-c5ccc6ccccc6c5)cc4)nc(-c4ccc(-c5ccc6ccccc6c5)c5ccccc45)n3)c2)cc1]

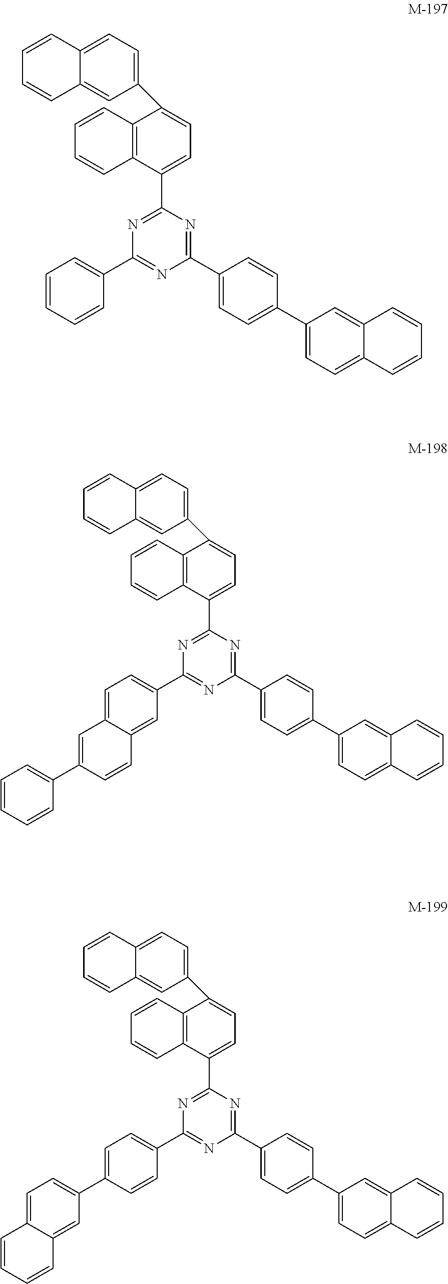 [SMILES: c1ccc(-c2nc(-c3ccc(-c4ccc5ccccc5c4)cc3)nc(-c3ccc(-c4ccc5ccccc5c4)c4ccccc34)n2)cc1 ; c1ccc(-c2ccc3cc(-c4nc(-c5ccc(-c6ccc7ccccc7c6)cc5)nc(-c5ccc(-c6ccc7ccccc7c6)c6ccccc56)n4)ccc3c2)cc1 ; c1ccc2cc(-c3ccc(-c4nc(-c5ccc(-c6ccc7ccccc7c6)cc5)nc(-c5ccc(-c6ccc7ccccc7c6)c6ccccc56)n4)cc3)ccc2c1]

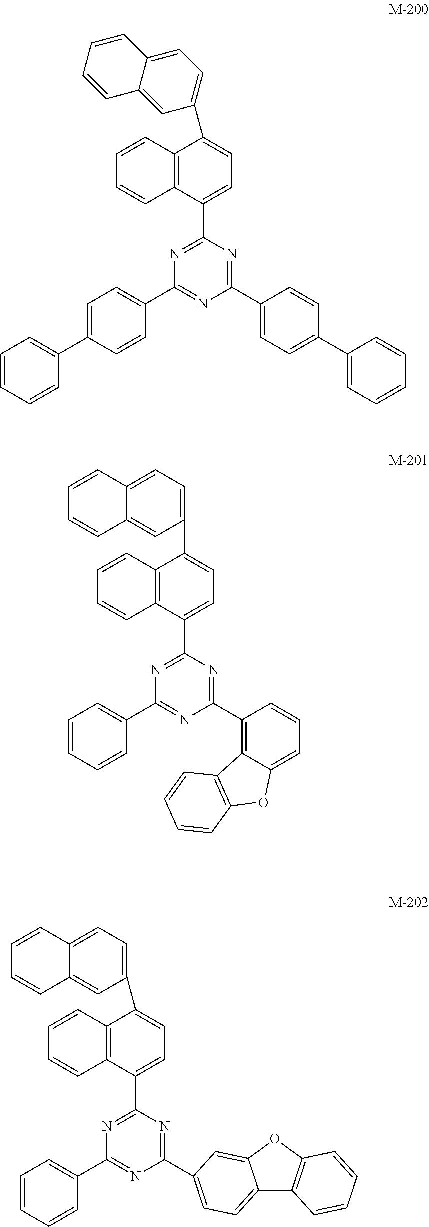 [SMILES: c1ccc(-c2ccc(-c3nc(-c4ccc(-c5ccccc5)cc4)nc(-c4ccc(-c5ccc6ccccc6c5)c5ccccc45)n3)cc2)cc1 ; c1ccc(-c2nc(-c3ccc(-c4ccc5ccccc5c4)c4ccccc34)nc(-c3cccc4oc5ccccc5c34)n2)cc1 ; c1ccc(-c2nc(-c3ccc4c(c3)oc3ccccc34)nc(-c3ccc(-c4ccc5ccccc5c4)c4ccccc34)n2)cc1]

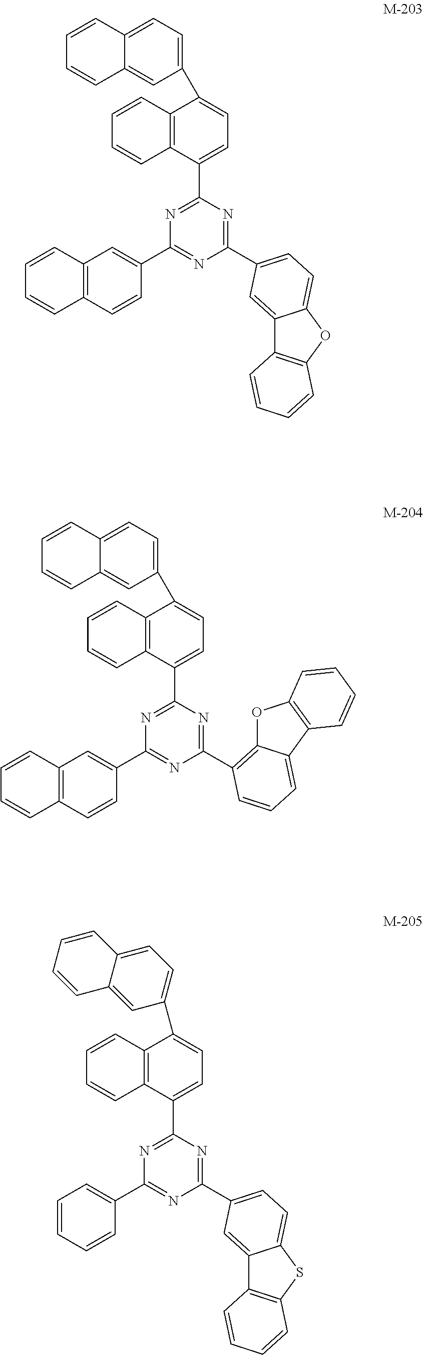 [SMILES: c1ccc2cc(-c3nc(-c4ccc5oc6ccccc6c5c4)nc(-c4ccc(-c5ccc6ccccc6c5)c5ccccc45)n3)ccc2c1 ; c1ccc2cc(-c3nc(-c4ccc(-c5ccc6ccccc6c5)c5ccccc45)nc(-c4cccc5c4oc4ccccc45)n3)ccc2c1 ; c1ccc(-c2nc(-c3ccc4sc5ccccc5c4c3)nc(-c3ccc(-c4ccc5ccccc5c4)c4ccccc34)n2)cc1]

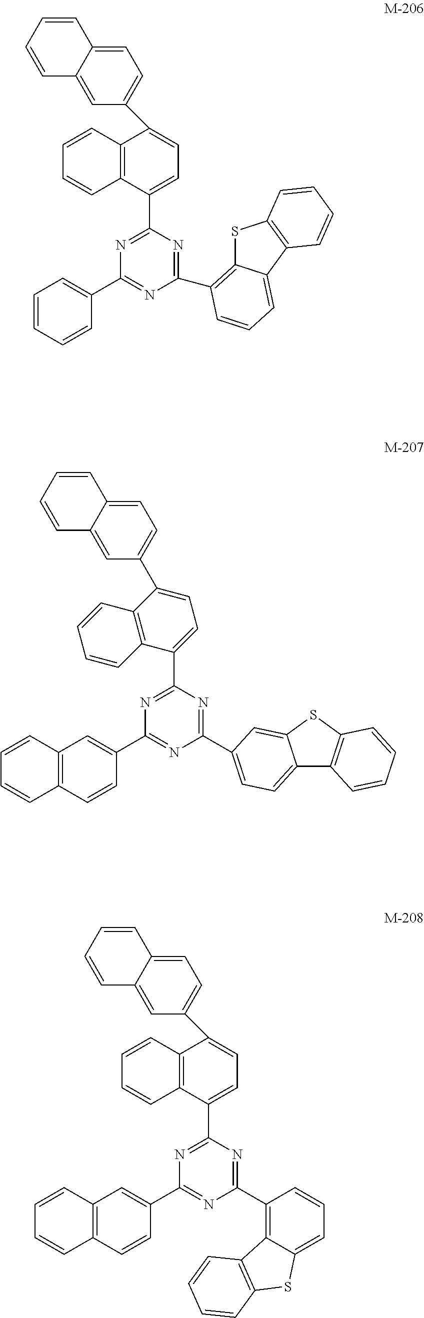 [SMILES: c1ccc(-c2nc(-c3ccc(-c4ccc5ccccc5c4)c4ccccc34)nc(-c3cccc4c3sc3ccccc34)n2)cc1 ; c1ccc2cc(-c3nc(-c4ccc5c(c4)sc4ccccc45)nc(-c4ccc(-c5ccc6ccccc6c5)c5ccccc45)n3)ccc2c1 ; c1ccc2cc(-c3nc(-c4ccc(-c5ccc6ccccc6c5)c5ccccc45)nc(-c4cccc5sc6ccccc6c45)n3)ccc2c1]

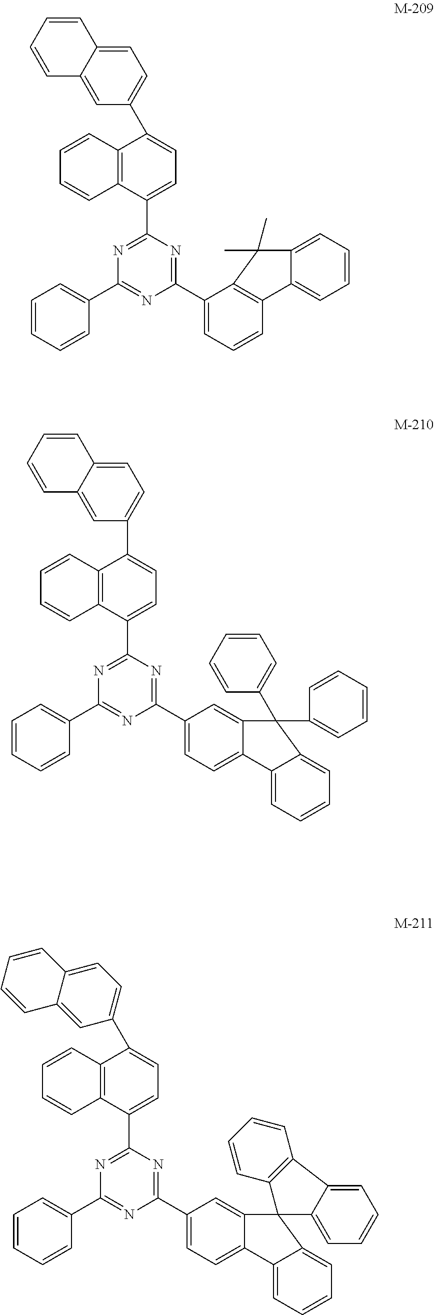 [SMILES: CC1(C)c2ccccc2-c2cccc(-c3nc(-c4ccccc4)nc(-c4ccc(-c5ccc6ccccc6c5)c5ccccc45)n3)c21 ; c1ccc(-c2nc(-c3ccc4c(c3)C(c3ccccc3)(c3ccccc3)c3ccccc3-4)nc(-c3ccc(-c4ccc5ccccc5c4)c4ccccc34)n2)cc1 ; c1ccc(-c2nc(-c3ccc4c(c3)C3(c5ccccc5-c5ccccc53)c3ccccc3-4)nc(-c3ccc(-c4ccc5ccccc5c4)c4ccccc34)n2)cc1]

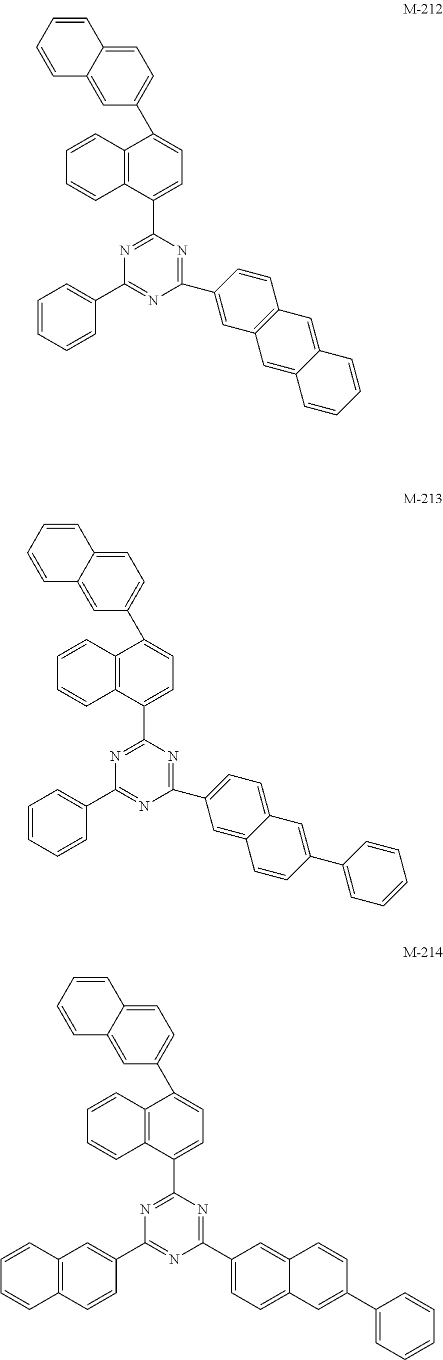 [SMILES: c1ccc(-c2nc(-c3ccc4cc5ccccc5cc4c3)nc(-c3ccc(-c4ccc5ccccc5c4)c4ccccc34)n2)cc1 ; c1ccc(-c2ccc3cc(-c4nc(-c5ccccc5)nc(-c5ccc(-c6ccc7ccccc7c6)c6ccccc56)n4)ccc3c2)cc1 ; c1ccc(-c2ccc3cc(-c4nc(-c5ccc6ccccc6c5)nc(-c5ccc(-c6ccc7ccccc7c6)c6ccccc56)n4)ccc3c2)cc1]

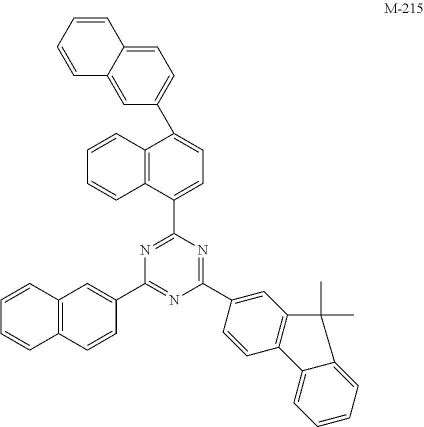 [SMILES: CC1(C)c2ccccc2-c2ccc(-c3nc(-c4ccc5ccccc5c4)nc(-c4ccc(-c5ccc6ccccc6c5)c5ccccc45)n3)cc21]

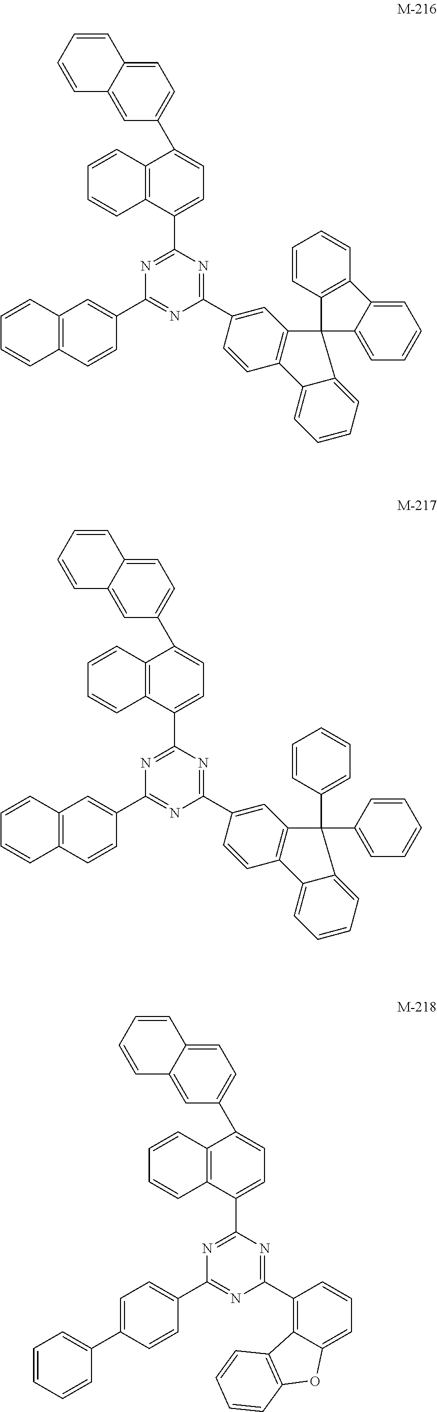 [SMILES: c1ccc2c(c1)-c1ccccc1C21c2ccccc2-c2ccc(-c3nc(-c4ccc5ccccc5c4)nc(-c4ccc(-c5ccc6ccccc6c5)c5ccccc45)n3)cc21 ; c1ccc(C2(c3ccccc3)c3ccccc3-c3ccc(-c4nc(-c5ccc6ccccc6c5)nc(-c5ccc(-c6ccc7ccccc7c6)c6ccccc56)n4)cc32)cc1 ; c1ccc(-c2ccc(-c3nc(-c4ccc(-c5ccc6ccccc6c5)c5ccccc45)nc(-c4cccc5oc6ccccc6c45)n3)cc2)cc1]

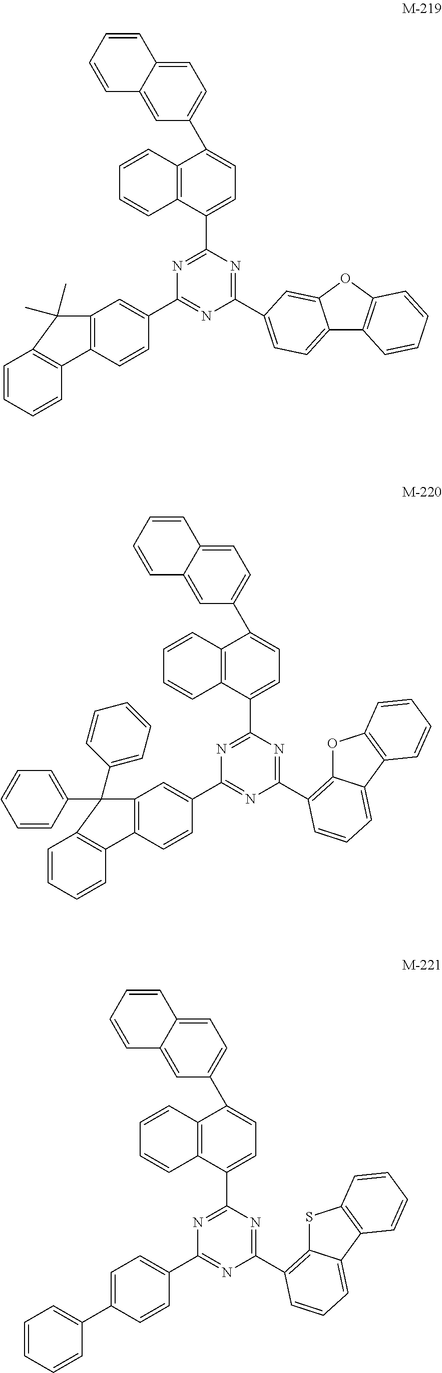 [SMILES: CC1(C)c2ccccc2-c2ccc(-c3nc(-c4ccc5c(c4)oc4ccccc45)nc(-c4ccc(-c5ccc6ccccc6c5)c5ccccc45)n3)cc21 ; c1ccc(C2(c3ccccc3)c3ccccc3-c3ccc(-c4nc(-c5ccc(-c6ccc7ccccc7c6)c6ccccc56)nc(-c5cccc6c5oc5ccccc56)n4)cc32)cc1 ; c1ccc(-c2ccc(-c3nc(-c4ccc(-c5ccc6ccccc6c5)c5ccccc45)nc(-c4cccc5c4sc4ccccc45)n3)cc2)cc1]

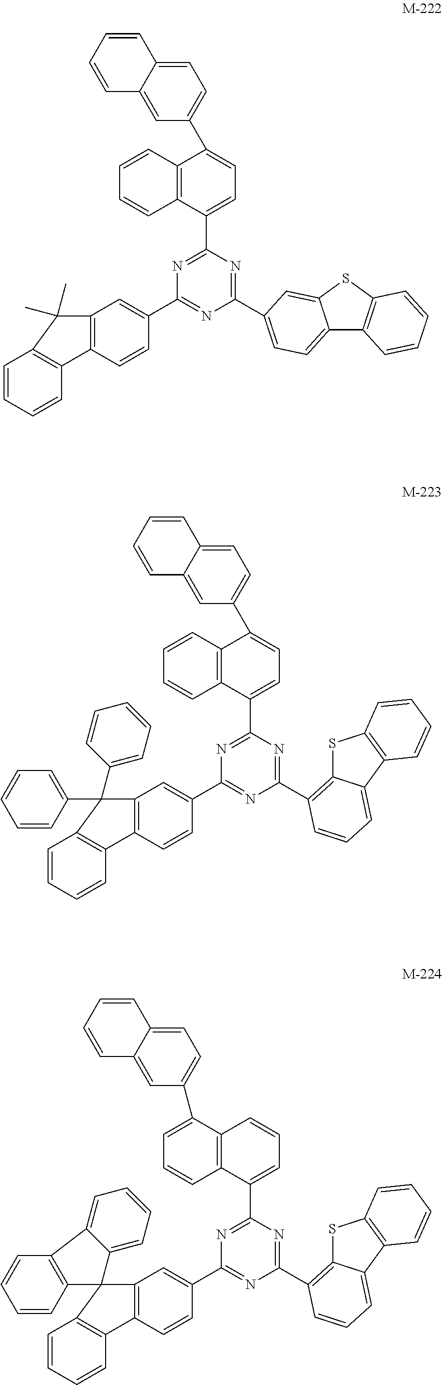 [SMILES: CC1(C)c2ccccc2-c2ccc(-c3nc(-c4ccc5c(c4)sc4ccccc45)nc(-c4ccc(-c5ccc6ccccc6c5)c5ccccc45)n3)cc21 ; c1ccc(C2(c3ccccc3)c3ccccc3-c3ccc(-c4nc(-c5ccc(-c6ccc7ccccc7c6)c6ccccc56)nc(-c5cccc6c5sc5ccccc56)n4)cc32)cc1 ; c1ccc2c(c1)-c1ccccc1C21c2ccccc2-c2ccc(-c3nc(-c4cccc5c(-c6ccc7ccccc7c6)cccc45)nc(-c4cccc5c4sc4ccccc45)n3)cc21]

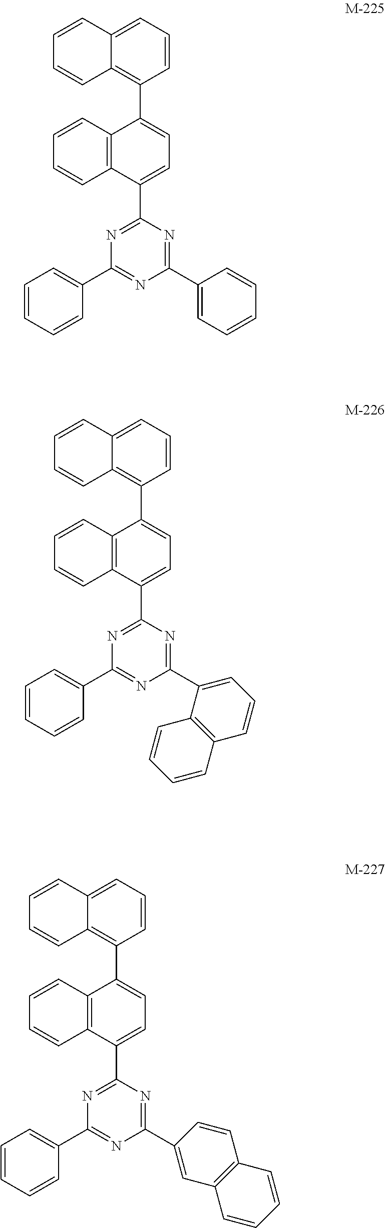 [SMILES: c1ccc(-c2nc(-c3ccccc3)nc(-c3ccc(-c4cccc5ccccc45)c4ccccc34)n2)cc1 ; c1ccc(-c2nc(-c3cccc4ccccc34)nc(-c3ccc(-c4cccc5ccccc45)c4ccccc34)n2)cc1 ; c1ccc(-c2nc(-c3ccc4ccccc4c3)nc(-c3ccc(-c4cccc5ccccc45)c4ccccc34)n2)cc1]

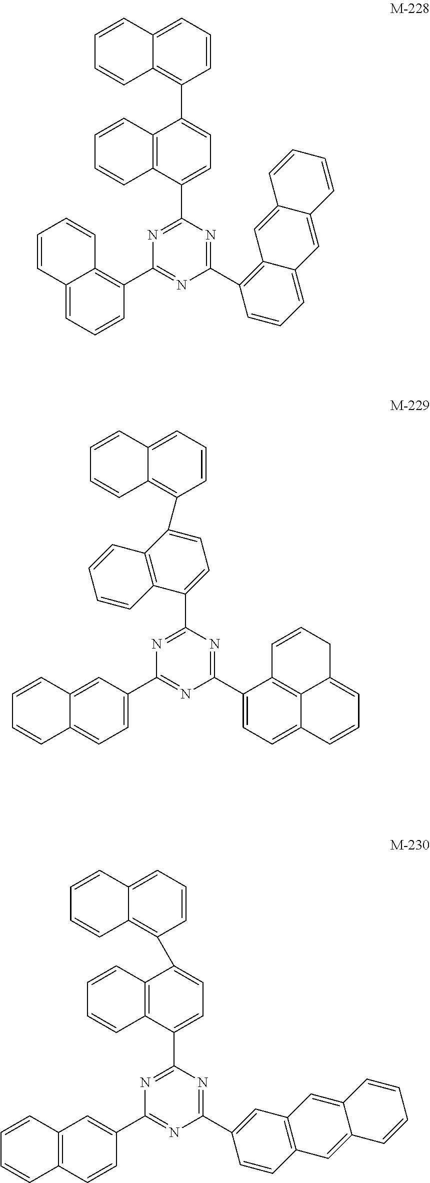 [SMILES: c1ccc2cc3c(-c4nc(-c5cccc6ccccc56)nc(-c5ccc(-c6cccc7ccccc67)c6ccccc56)n4)cccc3cc2c1 ; C1=Cc2c(-c3nc(-c4ccc5ccccc5c4)nc(-c4ccc(-c5cccc6ccccc56)c5ccccc45)n3)ccc3cccc(c23)C1 ; c1ccc2cc(-c3nc(-c4ccc5cc6ccccc6cc5c4)nc(-c4ccc(-c5cccc6ccccc56)c5ccccc45)n3)ccc2c1]

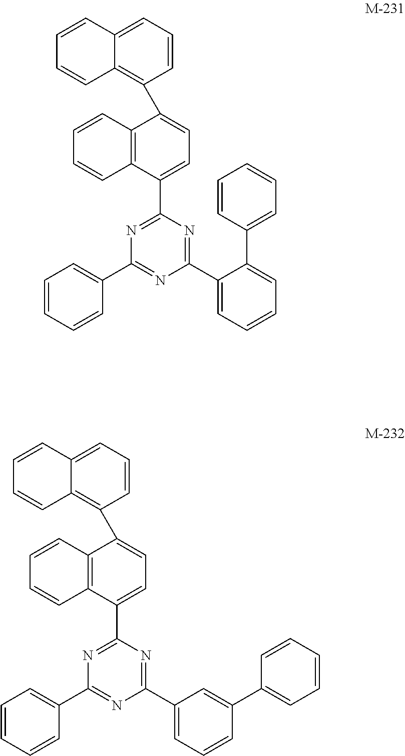 [SMILES: c1ccc(-c2nc(-c3ccccc3-c3ccccc3)nc(-c3ccc(-c4cccc5ccccc45)c4ccccc34)n2)cc1 ; c1ccc(-c2cccc(-c3nc(-c4ccccc4)nc(-c4ccc(-c5cccc6ccccc56)c5ccccc45)n3)c2)cc1]

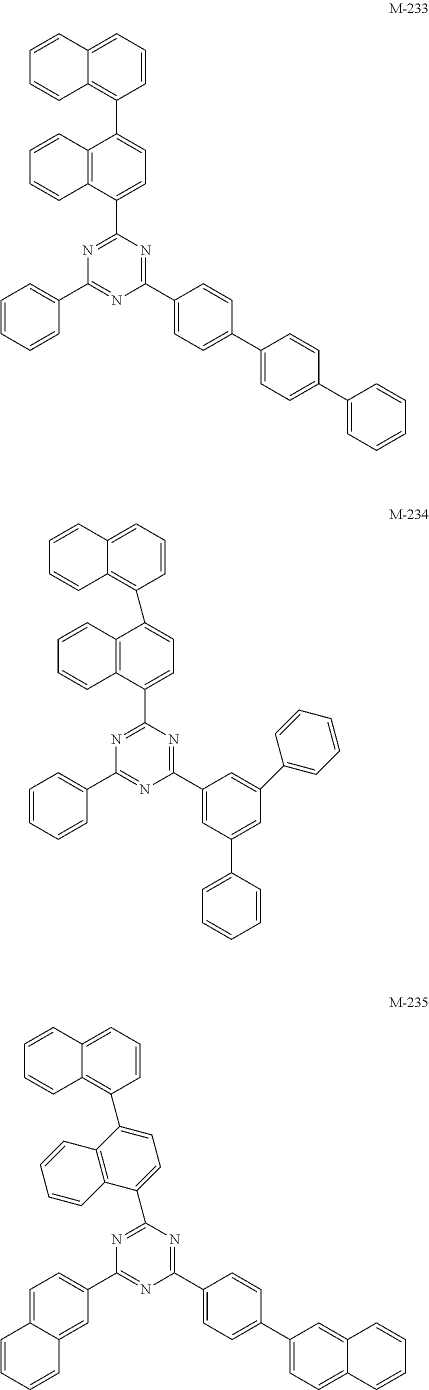 [SMILES: c1ccc(-c2ccc(-c3ccc(-c4nc(-c5ccccc5)nc(-c5ccc(-c6cccc7ccccc67)c6ccccc56)n4)cc3)cc2)cc1 ; c1ccc(-c2cc(-c3ccccc3)cc(-c3nc(-c4ccccc4)nc(-c4ccc(-c5cccc6ccccc56)c5ccccc45)n3)c2)cc1 ; c1ccc2cc(-c3ccc(-c4nc(-c5ccc6ccccc6c5)nc(-c5ccc(-c6cccc7ccccc67)c6ccccc56)n4)cc3)ccc2c1]

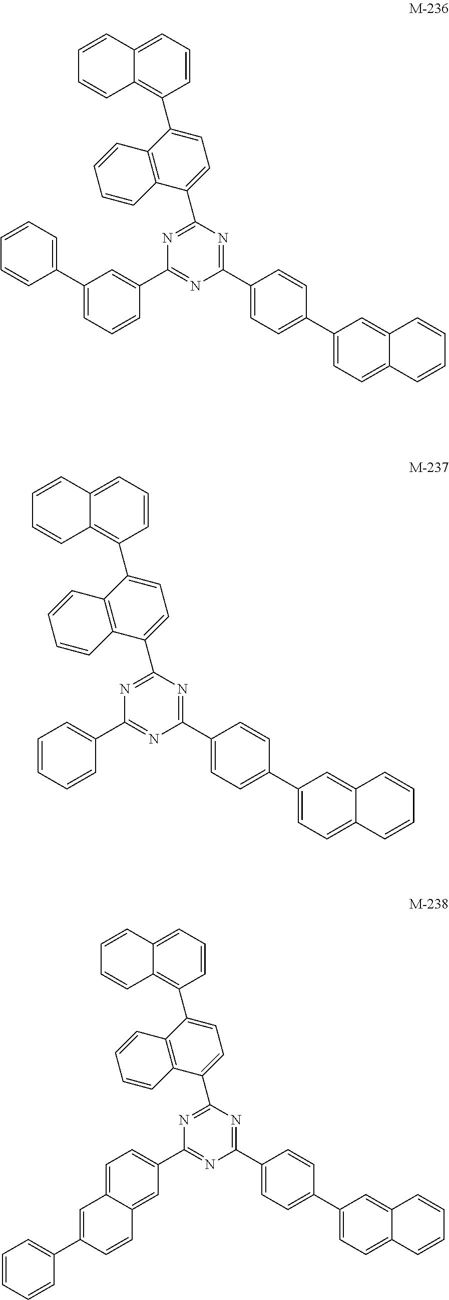 [SMILES: c1ccc(-c2cccc(-c3nc(-c4ccc(-c5ccc6ccccc6c5)cc4)nc(-c4ccc(-c5cccc6ccccc56)c5ccccc45)n3)c2)cc1 ; c1ccc(-c2nc(-c3ccc(-c4ccc5ccccc5c4)cc3)nc(-c3ccc(-c4cccc5ccccc45)c4ccccc34)n2)cc1 ; c1ccc(-c2ccc3cc(-c4nc(-c5ccc(-c6ccc7ccccc7c6)cc5)nc(-c5ccc(-c6cccc7ccccc67)c6ccccc56)n4)ccc3c2)cc1]

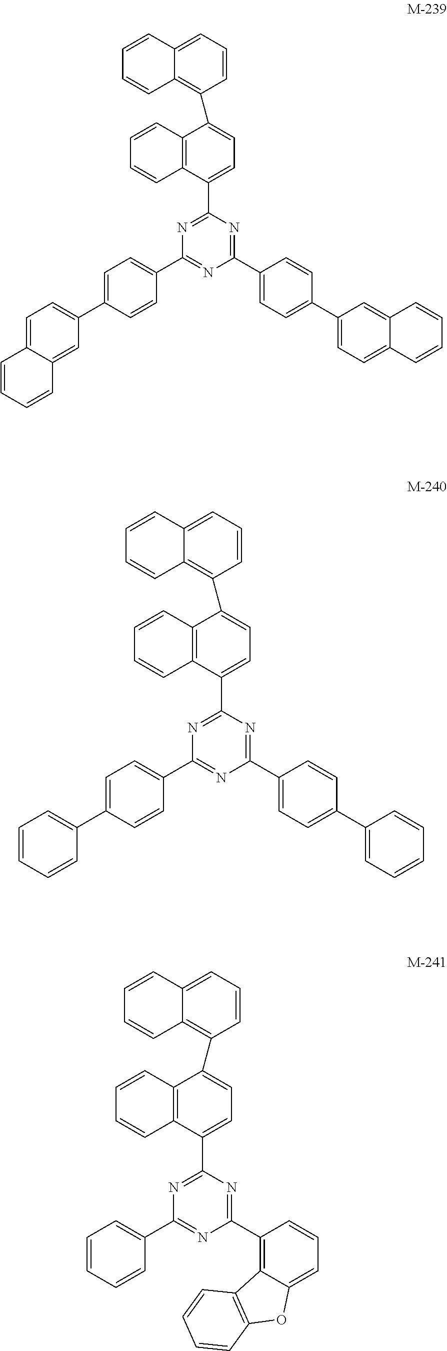 [SMILES: c1ccc2cc(-c3ccc(-c4nc(-c5ccc(-c6ccc7ccccc7c6)cc5)nc(-c5ccc(-c6cccc7ccccc67)c6ccccc56)n4)cc3)ccc2c1 ; c1ccc(-c2ccc(-c3nc(-c4ccc(-c5ccccc5)cc4)nc(-c4ccc(-c5cccc6ccccc56)c5ccccc45)n3)cc2)cc1 ; c1ccc(-c2nc(-c3ccc(-c4cccc5ccccc45)c4ccccc34)nc(-c3cccc4oc5ccccc5c34)n2)cc1]

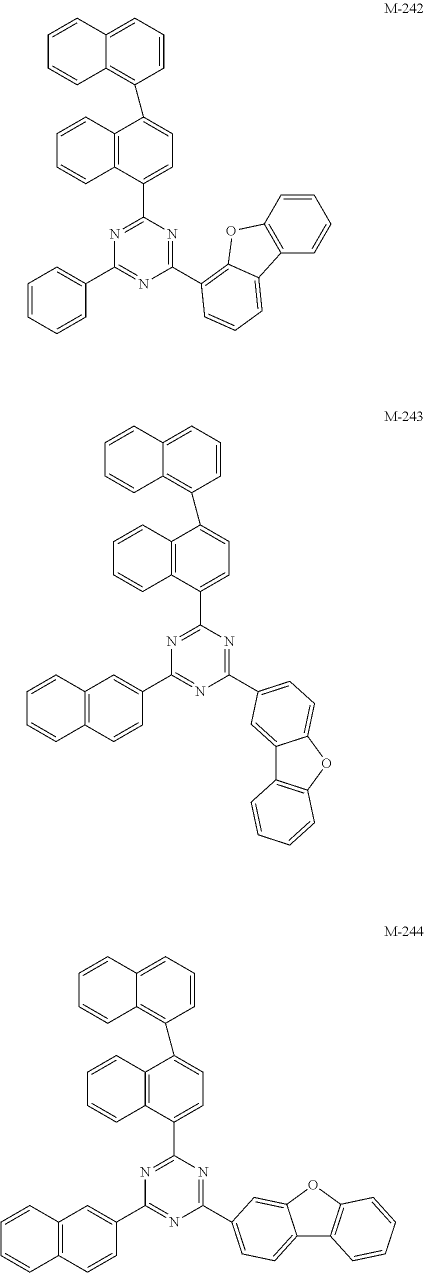 [SMILES: c1ccc(-c2nc(-c3ccc(-c4cccc5ccccc45)c4ccccc34)nc(-c3cccc4c3oc3ccccc34)n2)cc1 ; c1ccc2cc(-c3nc(-c4ccc5oc6ccccc6c5c4)nc(-c4ccc(-c5cccc6ccccc56)c5ccccc45)n3)ccc2c1 ; c1ccc2cc(-c3nc(-c4ccc5c(c4)oc4ccccc45)nc(-c4ccc(-c5cccc6ccccc56)c5ccccc45)n3)ccc2c1]

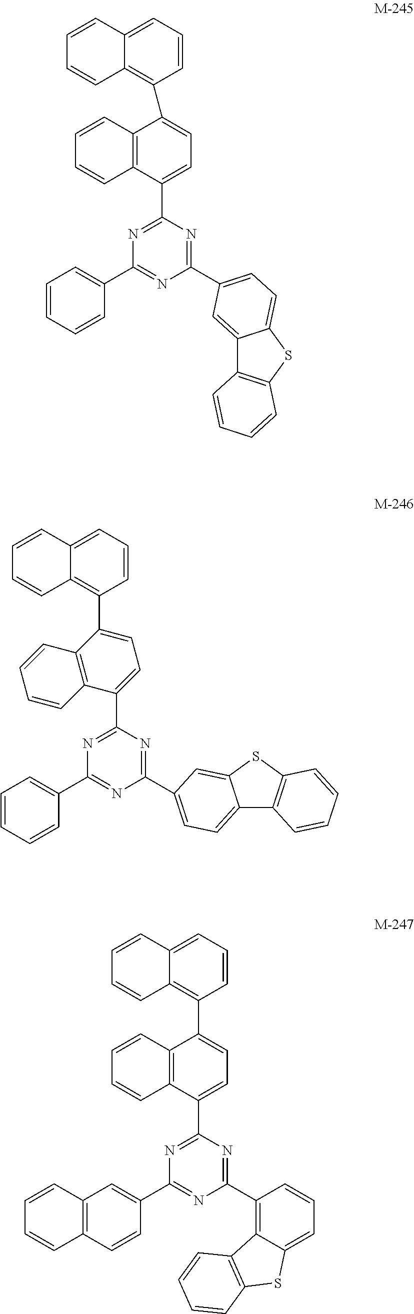 [SMILES: c1ccc(-c2nc(-c3ccc4sc5ccccc5c4c3)nc(-c3ccc(-c4cccc5ccccc45)c4ccccc34)n2)cc1 ; c1ccc(-c2nc(-c3ccc4c(c3)sc3ccccc34)nc(-c3ccc(-c4cccc5ccccc45)c4ccccc34)n2)cc1 ; c1ccc2cc(-c3nc(-c4ccc(-c5cccc6ccccc56)c5ccccc45)nc(-c4cccc5sc6ccccc6c45)n3)ccc2c1]

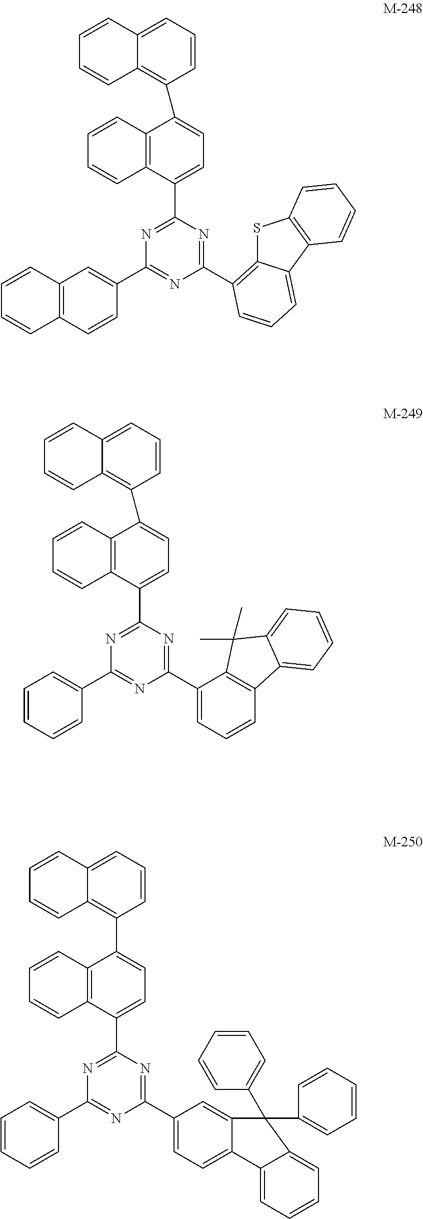 [SMILES: c1ccc2cc(-c3nc(-c4ccc(-c5cccc6ccccc56)c5ccccc45)nc(-c4cccc5c4sc4ccccc45)n3)ccc2c1 ; CC1(C)c2ccccc2-c2cccc(-c3nc(-c4ccccc4)nc(-c4ccc(-c5cccc6ccccc56)c5ccccc45)n3)c21 ; c1ccc(-c2nc(-c3ccc4c(c3)C(c3ccccc3)(c3ccccc3)c3ccccc3-4)nc(-c3ccc(-c4cccc5ccccc45)c4ccccc34)n2)cc1]

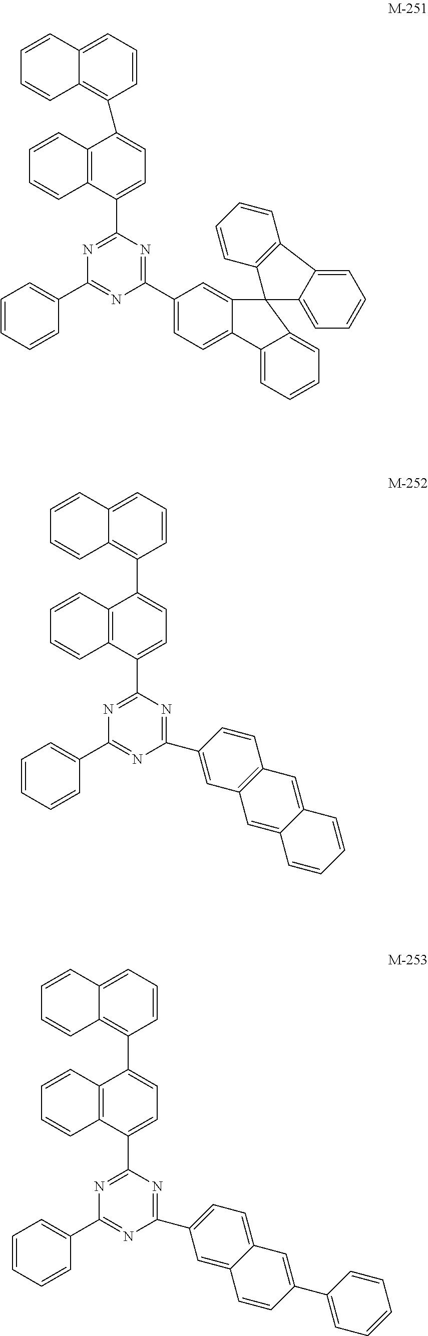 [SMILES: c1ccc(-c2nc(-c3ccc4c(c3)C3(c5ccccc5-c5ccccc53)c3ccccc3-4)nc(-c3ccc(-c4cccc5ccccc45)c4ccccc34)n2)cc1 ; c1ccc(-c2nc(-c3ccc4cc5ccccc5cc4c3)nc(-c3ccc(-c4cccc5ccccc45)c4ccccc34)n2)cc1 ; c1ccc(-c2ccc3cc(-c4nc(-c5ccccc5)nc(-c5ccc(-c6cccc7ccccc67)c6ccccc56)n4)ccc3c2)cc1]

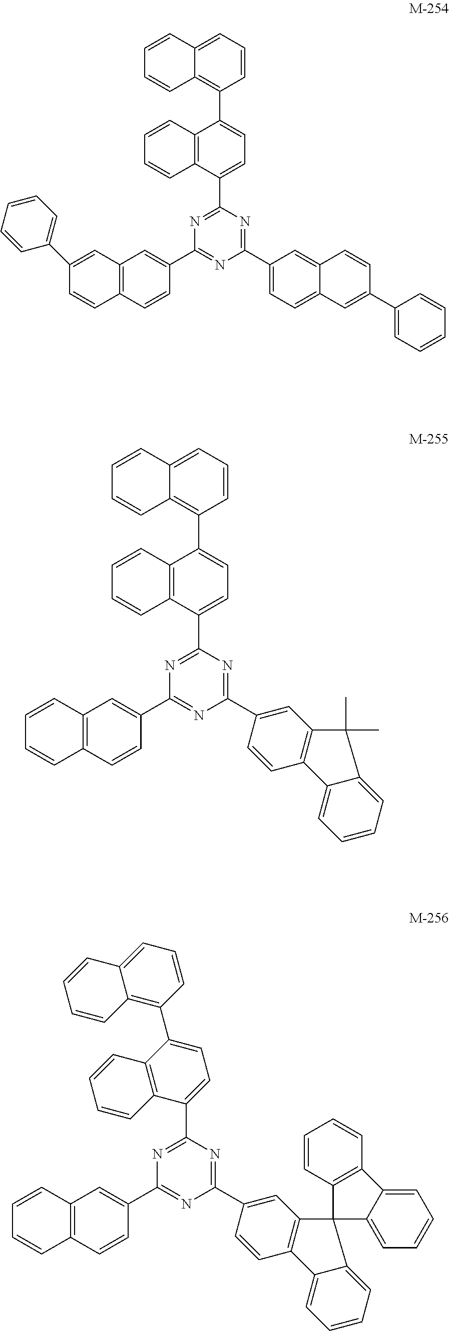 [SMILES: c1ccc(-c2ccc3cc(-c4nc(-c5ccc6ccc(-c7ccccc7)cc6c5)nc(-c5ccc(-c6cccc7ccccc67)c6ccccc56)n4)ccc3c2)cc1 ; CC1(C)c2ccccc2-c2ccc(-c3nc(-c4ccc5ccccc5c4)nc(-c4ccc(-c5cccc6ccccc56)c5ccccc45)n3)cc21 ; c1ccc2c(c1)-c1ccccc1C21c2ccccc2-c2ccc(-c3nc(-c4ccc5ccccc5c4)nc(-c4ccc(-c5cccc6ccccc56)c5ccccc45)n3)cc21]

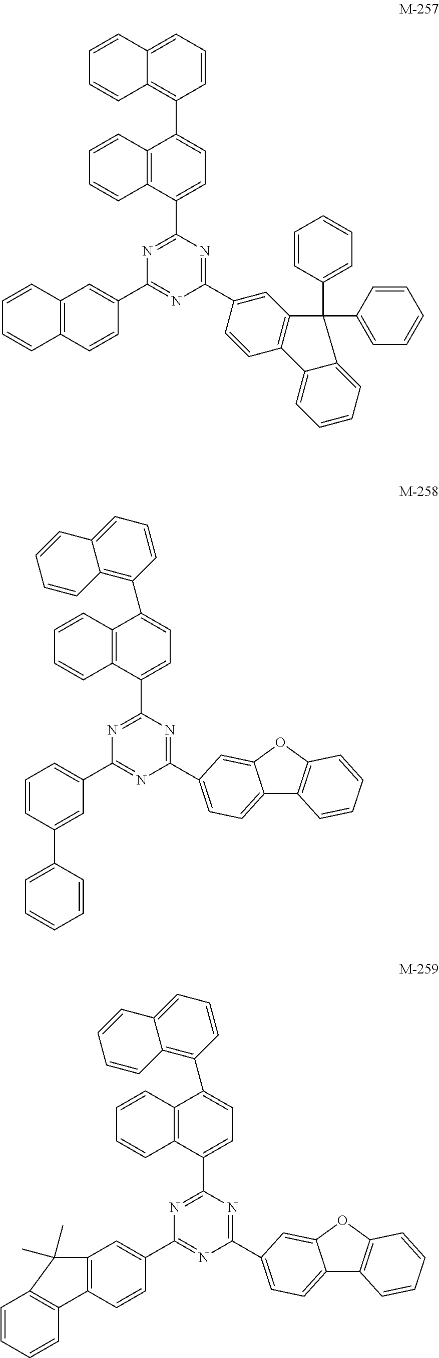 [SMILES: c1ccc(C2(c3ccccc3)c3ccccc3-c3ccc(-c4nc(-c5ccc6ccccc6c5)nc(-c5ccc(-c6cccc7ccccc67)c6ccccc56)n4)cc32)cc1 ; c1ccc(-c2cccc(-c3nc(-c4ccc5c(c4)oc4ccccc45)nc(-c4ccc(-c5cccc6ccccc56)c5ccccc45)n3)c2)cc1 ; CC1(C)c2ccccc2-c2ccc(-c3nc(-c4ccc5c(c4)oc4ccccc45)nc(-c4ccc(-c5cccc6ccccc56)c5ccccc45)n3)cc21]

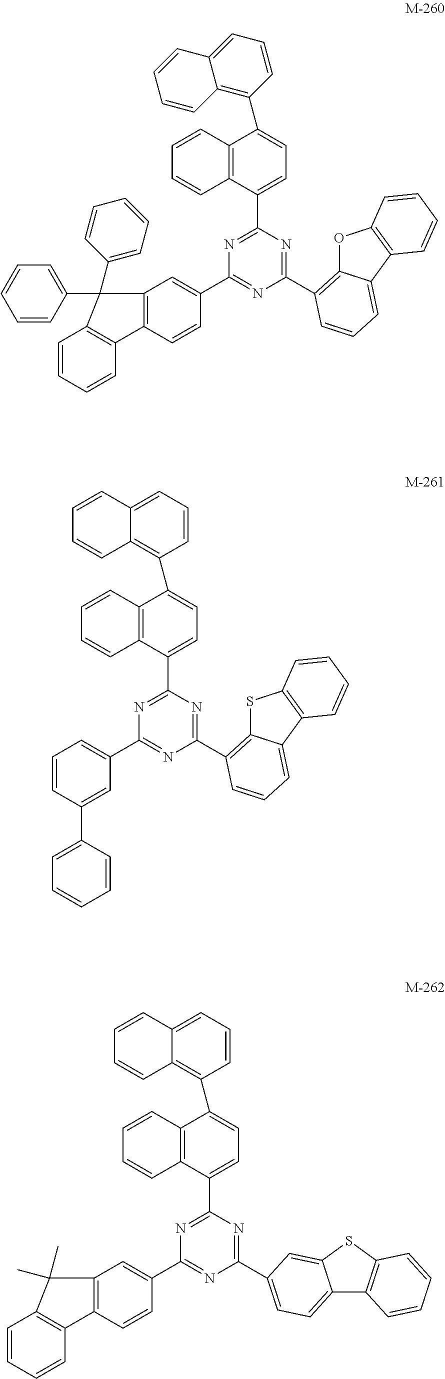 [SMILES: c1ccc(C2(c3ccccc3)c3ccccc3-c3ccc(-c4nc(-c5ccc(-c6cccc7ccccc67)c6ccccc56)nc(-c5cccc6c5oc5ccccc56)n4)cc32)cc1 ; c1ccc(-c2cccc(-c3nc(-c4ccc(-c5cccc6ccccc56)c5ccccc45)nc(-c4cccc5c4sc4ccccc45)n3)c2)cc1 ; CC1(C)c2ccccc2-c2ccc(-c3nc(-c4ccc5c(c4)sc4ccccc45)nc(-c4ccc(-c5cccc6ccccc56)c5ccccc45)n3)cc21]

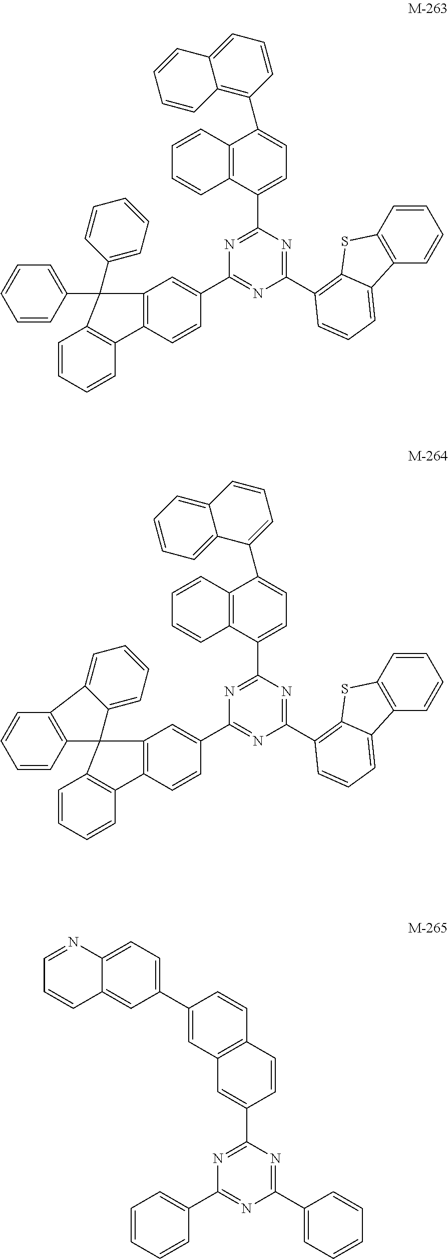 [SMILES: c1ccc(C2(c3ccccc3)c3ccccc3-c3ccc(-c4nc(-c5ccc(-c6cccc7ccccc67)c6ccccc56)nc(-c5cccc6c5sc5ccccc56)n4)cc32)cc1 ; c1ccc2c(c1)-c1ccccc1C21c2ccccc2-c2ccc(-c3nc(-c4ccc(-c5cccc6ccccc56)c5ccccc45)nc(-c4cccc5c4sc4ccccc45)n3)cc21 ; c1ccc(-c2nc(-c3ccccc3)nc(-c3ccc4ccc(-c5ccc6ncccc6c5)cc4c3)n2)cc1]

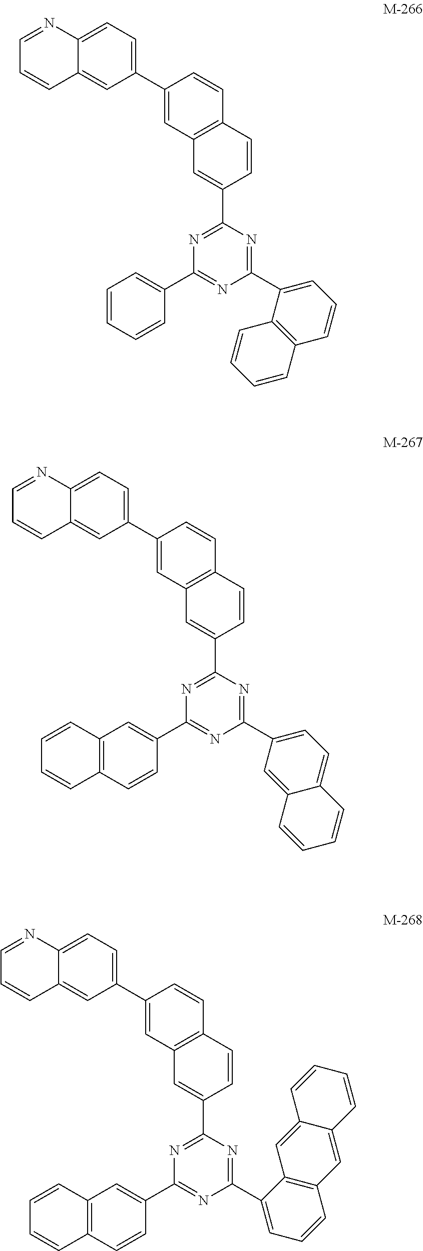 [SMILES: c1ccc(-c2nc(-c3ccc4ccc(-c5ccc6ncccc6c5)cc4c3)nc(-c3cccc4ccccc34)n2)cc1 ; c1ccc2cc(-c3nc(-c4ccc5ccccc5c4)nc(-c4ccc5ccc(-c6ccc7ncccc7c6)cc5c4)n3)ccc2c1 ; c1ccc2cc(-c3nc(-c4ccc5ccc(-c6ccc7ncccc7c6)cc5c4)nc(-c4cccc5cc6ccccc6cc45)n3)ccc2c1]

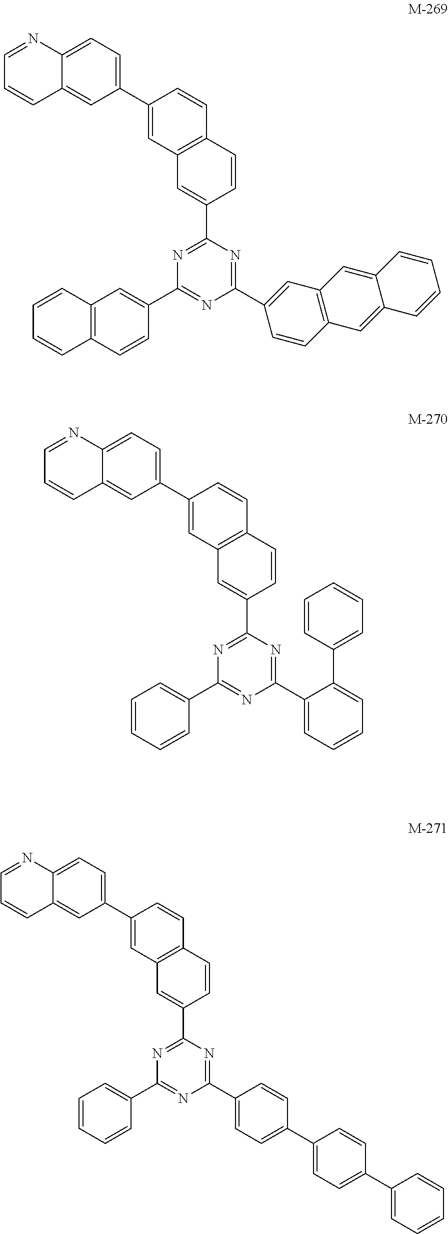 [SMILES: c1ccc2cc(-c3nc(-c4ccc5ccc(-c6ccc7ncccc7c6)cc5c4)nc(-c4ccc5cc6ccccc6cc5c4)n3)ccc2c1 ; c1ccc(-c2nc(-c3ccc4ccc(-c5ccc6ncccc6c5)cc4c3)nc(-c3ccccc3-c3ccccc3)n2)cc1 ; c1ccc(-c2ccc(-c3ccc(-c4nc(-c5ccccc5)nc(-c5ccc6ccc(-c7ccc8ncccc8c7)cc6c5)n4)cc3)cc2)cc1]

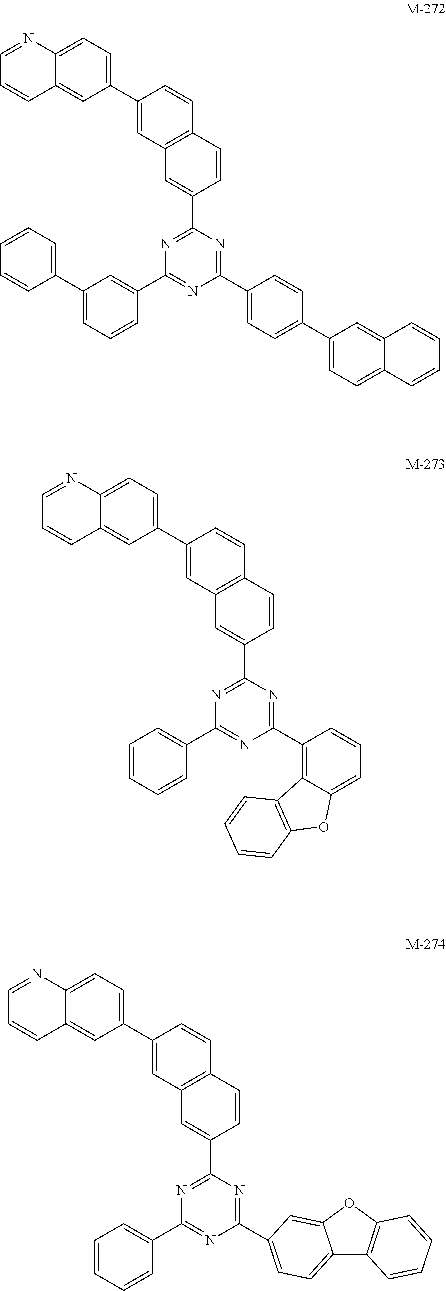 [SMILES: c1ccc(-c2cccc(-c3nc(-c4ccc(-c5ccc6ccccc6c5)cc4)nc(-c4ccc5ccc(-c6ccc7ncccc7c6)cc5c4)n3)c2)cc1 ; c1ccc(-c2nc(-c3ccc4ccc(-c5ccc6ncccc6c5)cc4c3)nc(-c3cccc4oc5ccccc5c34)n2)cc1 ; c1ccc(-c2nc(-c3ccc4ccc(-c5ccc6ncccc6c5)cc4c3)nc(-c3ccc4c(c3)oc3ccccc34)n2)cc1]

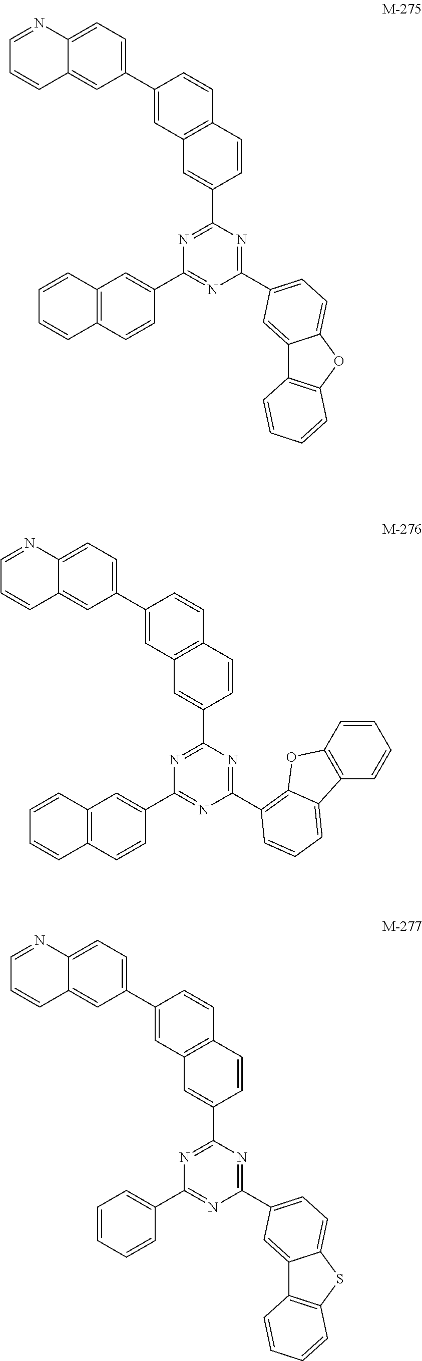 [SMILES: c1ccc2cc(-c3nc(-c4ccc5ccc(-c6ccc7ncccc7c6)cc5c4)nc(-c4ccc5oc6ccccc6c5c4)n3)ccc2c1 ; c1ccc2cc(-c3nc(-c4ccc5ccc(-c6ccc7ncccc7c6)cc5c4)nc(-c4cccc5c4oc4ccccc45)n3)ccc2c1 ; c1ccc(-c2nc(-c3ccc4ccc(-c5ccc6ncccc6c5)cc4c3)nc(-c3ccc4sc5ccccc5c4c3)n2)cc1]

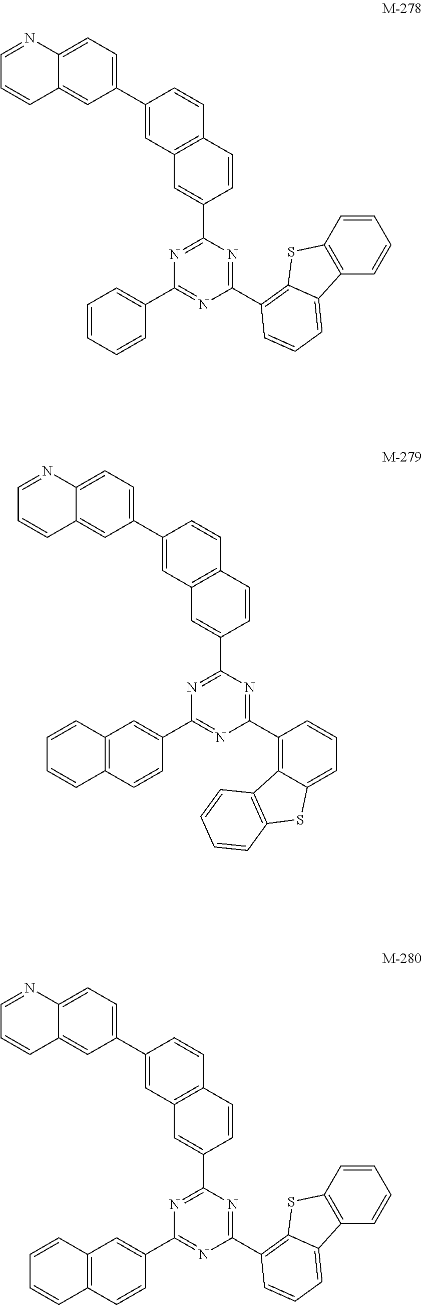 [SMILES: c1ccc(-c2nc(-c3ccc4ccc(-c5ccc6ncccc6c5)cc4c3)nc(-c3cccc4c3sc3ccccc34)n2)cc1 ; c1ccc2cc(-c3nc(-c4ccc5ccc(-c6ccc7ncccc7c6)cc5c4)nc(-c4cccc5sc6ccccc6c45)n3)ccc2c1 ; c1ccc2cc(-c3nc(-c4ccc5ccc(-c6ccc7ncccc7c6)cc5c4)nc(-c4cccc5c4sc4ccccc45)n3)ccc2c1]

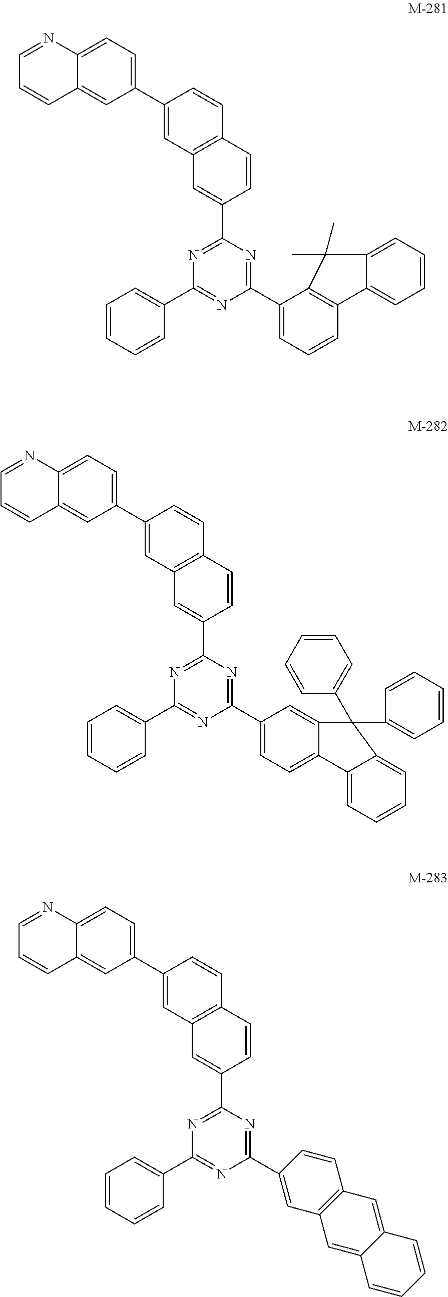 [SMILES: CC1(C)c2ccccc2-c2cccc(-c3nc(-c4ccccc4)nc(-c4ccc5ccc(-c6ccc7ncccc7c6)cc5c4)n3)c21 ; c1ccc(-c2nc(-c3ccc4c(c3)C(c3ccccc3)(c3ccccc3)c3ccccc3-4)nc(-c3ccc4ccc(-c5ccc6ncccc6c5)cc4c3)n2)cc1 ; c1ccc(-c2nc(-c3ccc4ccc(-c5ccc6ncccc6c5)cc4c3)nc(-c3ccc4cc5ccccc5cc4c3)n2)cc1]

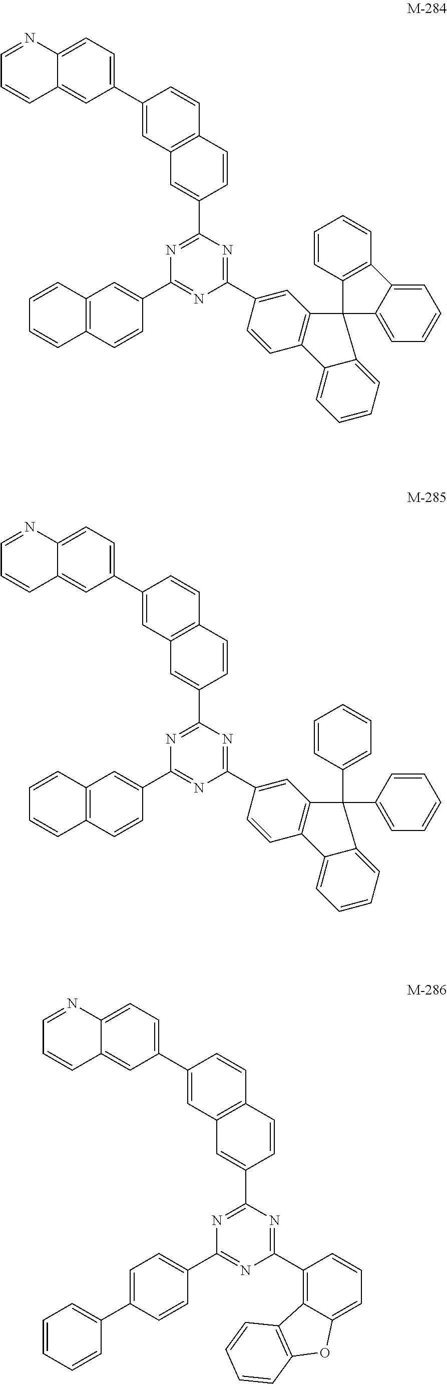

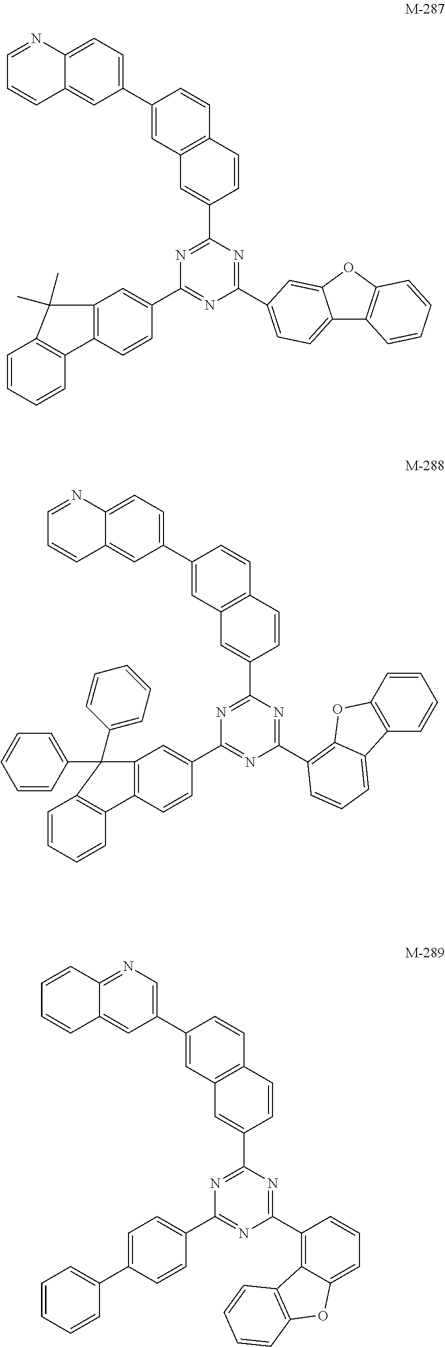 [SMILES: CC1(C)c2ccccc2-c2ccc(-c3nc(-c4ccc5ccc(-c6ccc7ncccc7c6)cc5c4)nc(-c4ccc5c(c4)oc4ccccc45)n3)cc21 ; c1ccc(C2(c3ccccc3)c3ccccc3-c3ccc(-c4nc(-c5ccc6ccc(-c7ccc8ncccc8c7)cc6c5)nc(-c5cccc6c5oc5ccccc56)n4)cc32)cc1 ; c1ccc(-c2ccc(-c3nc(-c4ccc5ccc(-c6cnc7ccccc7c6)cc5c4)nc(-c4cccc5oc6ccccc6c45)n3)cc2)cc1]

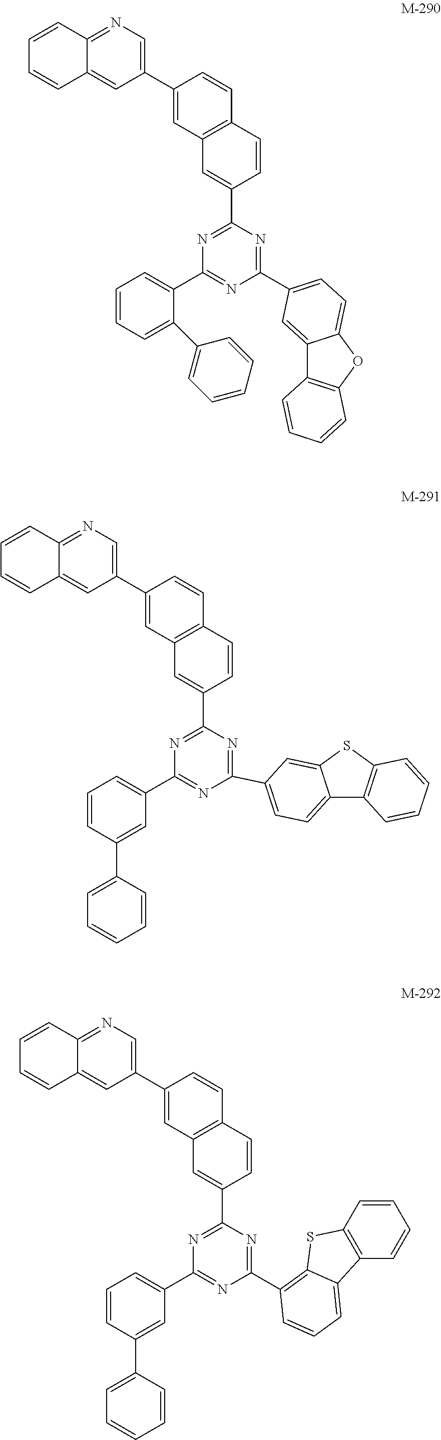 [SMILES: c1ccc(-c2ccccc2-c2nc(-c3ccc4ccc(-c5cnc6ccccc6c5)cc4c3)nc(-c3ccc4oc5ccccc5c4c3)n2)cc1 ; c1ccc(-c2cccc(-c3nc(-c4ccc5ccc(-c6cnc7ccccc7c6)cc5c4)nc(-c4ccc5c(c4)sc4ccccc45)n3)c2)cc1 ; c1ccc(-c2cccc(-c3nc(-c4ccc5ccc(-c6cnc7ccccc7c6)cc5c4)nc(-c4cccc5c4sc4ccccc45)n3)c2)cc1]

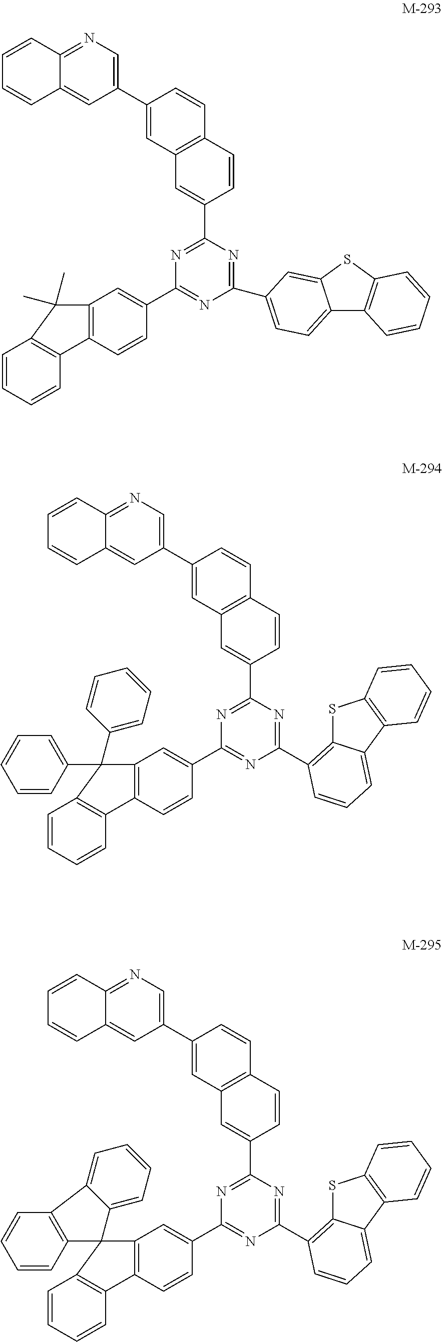 [SMILES: CC1(C)c2ccccc2-c2ccc(-c3nc(-c4ccc5ccc(-c6cnc7ccccc7c6)cc5c4)nc(-c4ccc5c(c4)sc4ccccc45)n3)cc21 ; c1ccc(C2(c3ccccc3)c3ccccc3-c3ccc(-c4nc(-c5ccc6ccc(-c7cnc8ccccc8c7)cc6c5)nc(-c5cccc6c5sc5ccccc56)n4)cc32)cc1 ; c1ccc2c(c1)-c1ccccc1C21c2ccccc2-c2ccc(-c3nc(-c4ccc5ccc(-c6cnc7ccccc7c6)cc5c4)nc(-c4cccc5c4sc4ccccc45)n3)cc21]

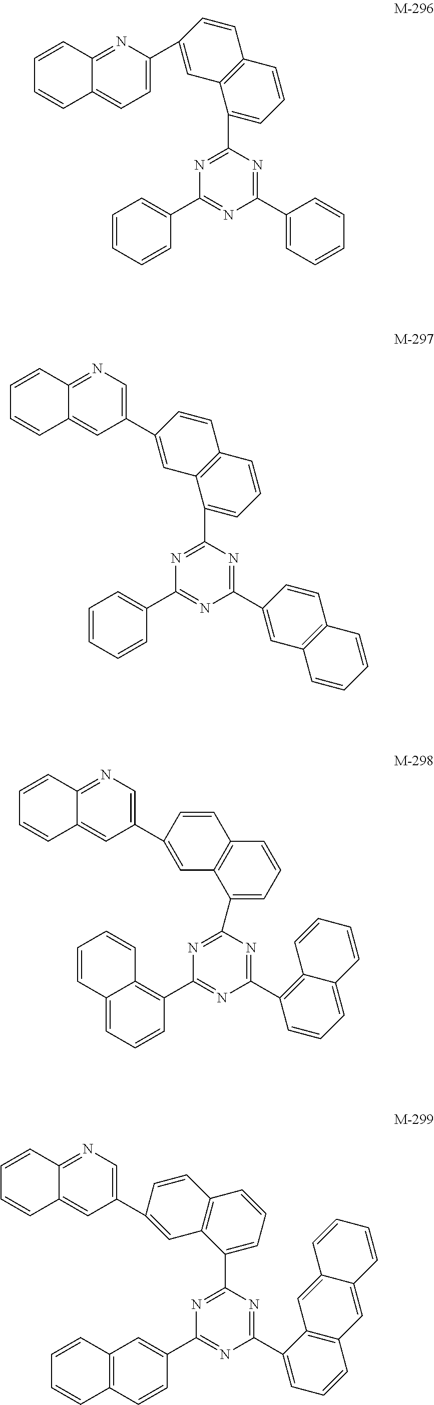 [SMILES: c1ccc(-c2nc(-c3ccccc3)nc(-c3cccc4ccc(-c5ccc6ccccc6n5)cc34)n2)cc1 ; c1ccc(-c2nc(-c3ccc4ccccc4c3)nc(-c3cccc4ccc(-c5cnc6ccccc6c5)cc34)n2)cc1 ; c1ccc2ncc(-c3ccc4cccc(-c5nc(-c6cccc7ccccc67)nc(-c6cccc7ccccc67)n5)c4c3)cc2c1 ; c1ccc2cc(-c3nc(-c4cccc5ccc(-c6cnc7ccccc7c6)cc45)nc(-c4cccc5cc6ccccc6cc45)n3)ccc2c1]

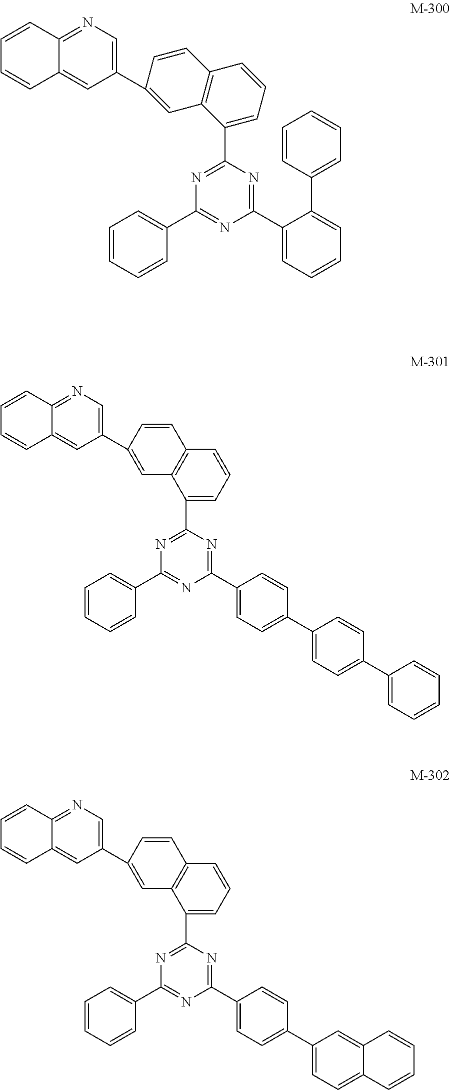 [SMILES: c1ccc(-c2nc(-c3ccccc3-c3ccccc3)nc(-c3cccc4ccc(-c5cnc6ccccc6c5)cc34)n2)cc1 ; c1ccc(-c2ccc(-c3ccc(-c4nc(-c5ccccc5)nc(-c5cccc6ccc(-c7cnc8ccccc8c7)cc56)n4)cc3)cc2)cc1 ; c1ccc(-c2nc(-c3ccc(-c4ccc5ccccc5c4)cc3)nc(-c3cccc4ccc(-c5cnc6ccccc6c5)cc34)n2)cc1]

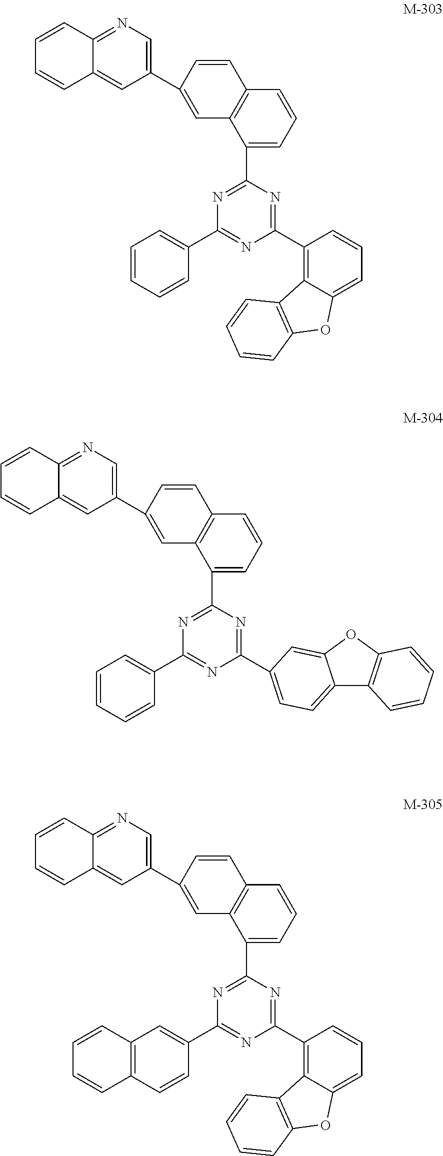 [SMILES: c1ccc(-c2nc(-c3cccc4ccc(-c5cnc6ccccc6c5)cc34)nc(-c3cccc4oc5ccccc5c34)n2)cc1 ; c1ccc(-c2nc(-c3ccc4c(c3)oc3ccccc34)nc(-c3cccc4ccc(-c5cnc6ccccc6c5)cc34)n2)cc1 ; c1ccc2cc(-c3nc(-c4cccc5ccc(-c6cnc7ccccc7c6)cc45)nc(-c4cccc5oc6ccccc6c45)n3)ccc2c1]

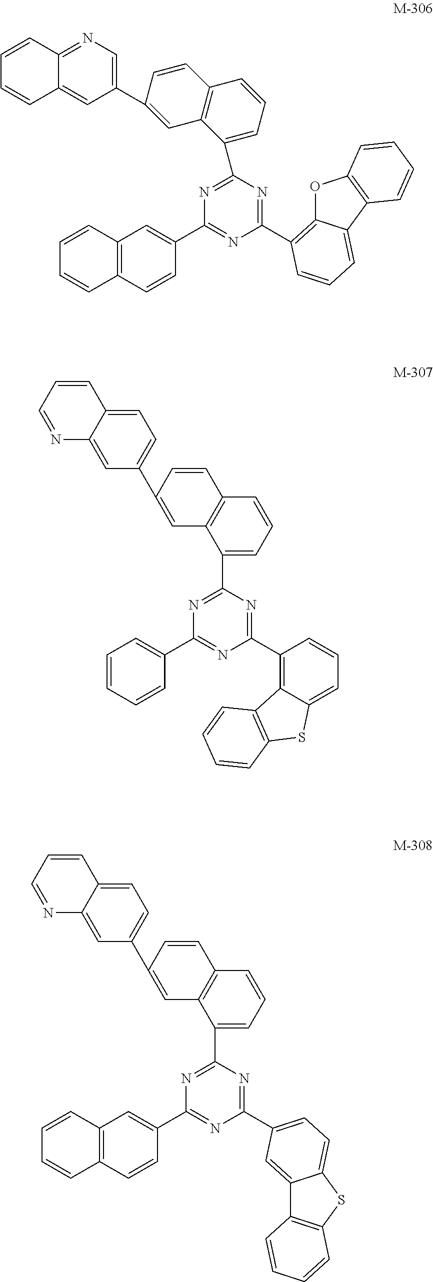 [SMILES: c1ccc2cc(-c3nc(-c4cccc5ccc(-c6cnc7ccccc7c6)cc45)nc(-c4cccc5c4oc4ccccc45)n3)ccc2c1 ; c1ccc(-c2nc(-c3cccc4ccc(-c5ccc6cccnc6c5)cc34)nc(-c3cccc4sc5ccccc5c34)n2)cc1 ; c1ccc2cc(-c3nc(-c4ccc5sc6ccccc6c5c4)nc(-c4cccc5ccc(-c6ccc7cccnc7c6)cc45)n3)ccc2c1]

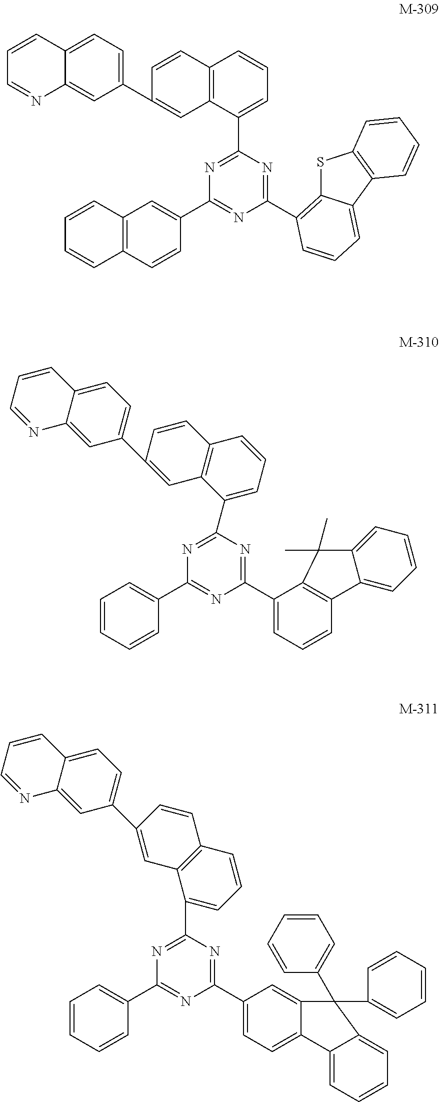 [SMILES: c1ccc2cc(-c3nc(-c4cccc5ccc(-c6ccc7cccnc7c6)cc45)nc(-c4cccc5c4sc4ccccc45)n3)ccc2c1 ; CC1(C)c2ccccc2-c2cccc(-c3nc(-c4ccccc4)nc(-c4cccc5ccc(-c6ccc7cccnc7c6)cc45)n3)c21 ; c1ccc(-c2nc(-c3ccc4c(c3)C(c3ccccc3)(c3ccccc3)c3ccccc3-4)nc(-c3cccc4ccc(-c5ccc6cccnc6c5)cc34)n2)cc1]

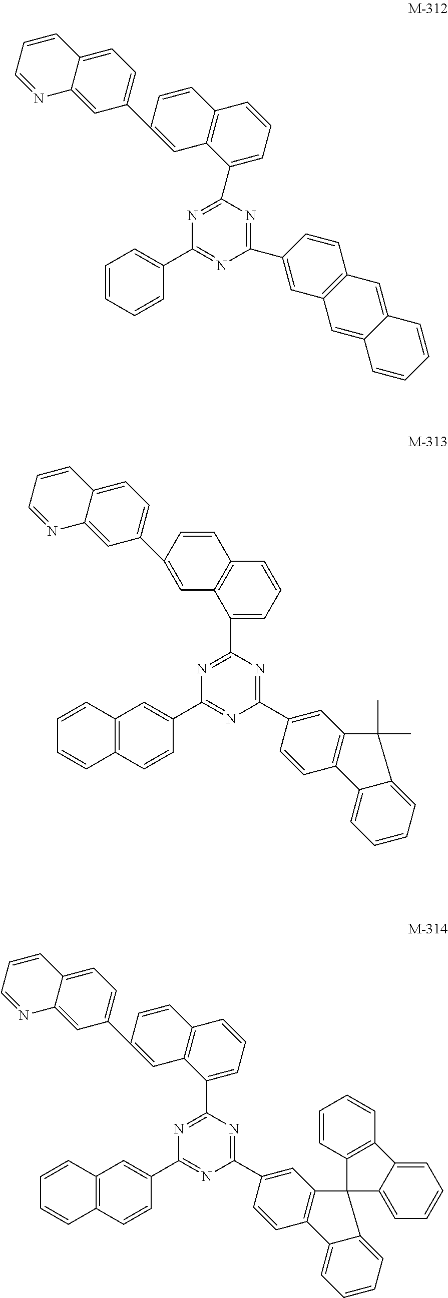 [SMILES: c1ccc(-c2nc(-c3ccc4cc5ccccc5cc4c3)nc(-c3cccc4ccc(-c5ccc6cccnc6c5)cc34)n2)cc1 ; CC1(C)c2ccccc2-c2ccc(-c3nc(-c4ccc5ccccc5c4)nc(-c4cccc5ccc(-c6ccc7cccnc7c6)cc45)n3)cc21 ; c1ccc2c(c1)-c1ccccc1C21c2ccccc2-c2ccc(-c3nc(-c4ccc5ccccc5c4)nc(-c4cccc5ccc(-c6ccc7cccnc7c6)cc45)n3)cc21]

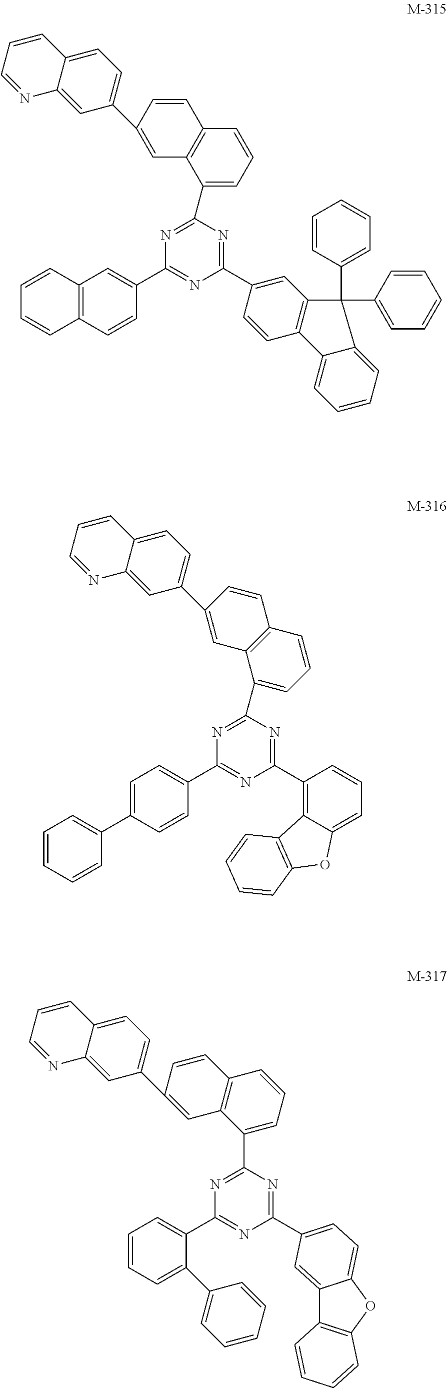 [SMILES: c1ccc(C2(c3ccccc3)c3ccccc3-c3ccc(-c4nc(-c5ccc6ccccc6c5)nc(-c5cccc6ccc(-c7ccc8cccnc8c7)cc56)n4)cc32)cc1 ; c1ccc(-c2ccc(-c3nc(-c4cccc5ccc(-c6ccc7cccnc7c6)cc45)nc(-c4cccc5oc6ccccc6c45)n3)cc2)cc1 ; c1ccc(-c2ccccc2-c2nc(-c3ccc4oc5ccccc5c4c3)nc(-c3cccc4ccc(-c5ccc6cccnc6c5)cc34)n2)cc1]

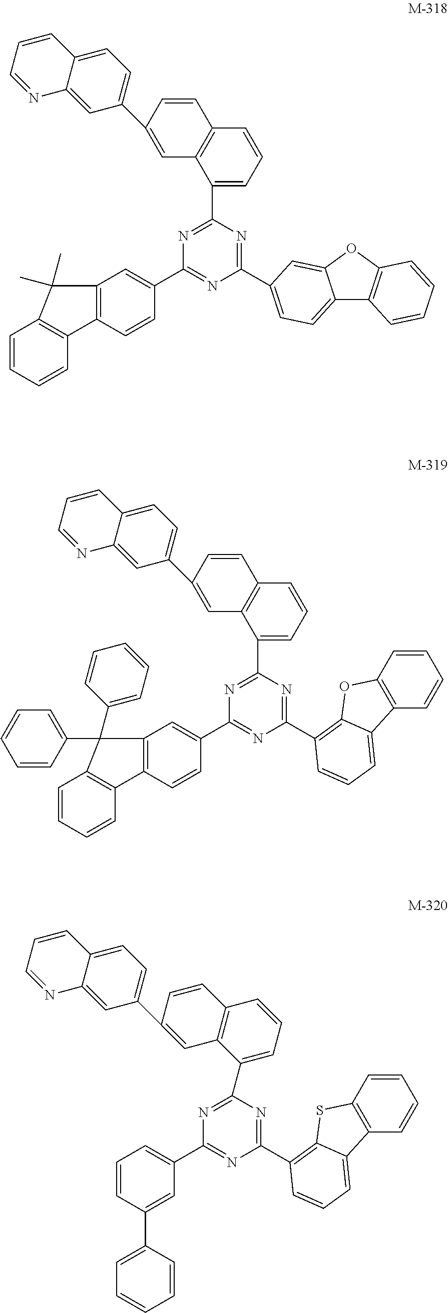 [SMILES: CC1(C)c2ccccc2-c2ccc(-c3nc(-c4ccc5c(c4)oc4ccccc45)nc(-c4cccc5ccc(-c6ccc7cccnc7c6)cc45)n3)cc21 ; c1ccc(C2(c3ccccc3)c3ccccc3-c3ccc(-c4nc(-c5cccc6ccc(-c7ccc8cccnc8c7)cc56)nc(-c5cccc6c5oc5ccccc56)n4)cc32)cc1 ; c1ccc(-c2cccc(-c3nc(-c4cccc5ccc(-c6ccc7cccnc7c6)cc45)nc(-c4cccc5c4sc4ccccc45)n3)c2)cc1]

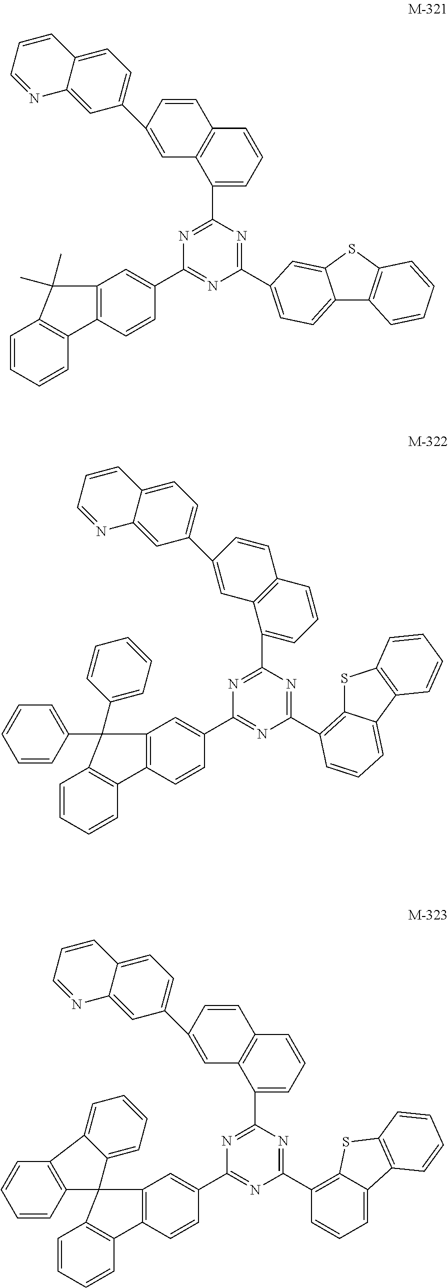 [SMILES: CC1(C)c2ccccc2-c2ccc(-c3nc(-c4ccc5c(c4)sc4ccccc45)nc(-c4cccc5ccc(-c6ccc7cccnc7c6)cc45)n3)cc21 ; c1ccc(C2(c3ccccc3)c3ccccc3-c3ccc(-c4nc(-c5cccc6ccc(-c7ccc8cccnc8c7)cc56)nc(-c5cccc6c5sc5ccccc56)n4)cc32)cc1 ; c1ccc2c(c1)-c1ccccc1C21c2ccccc2-c2ccc(-c3nc(-c4cccc5ccc(-c6ccc7cccnc7c6)cc45)nc(-c4cccc5c4sc4ccccc45)n3)cc21]

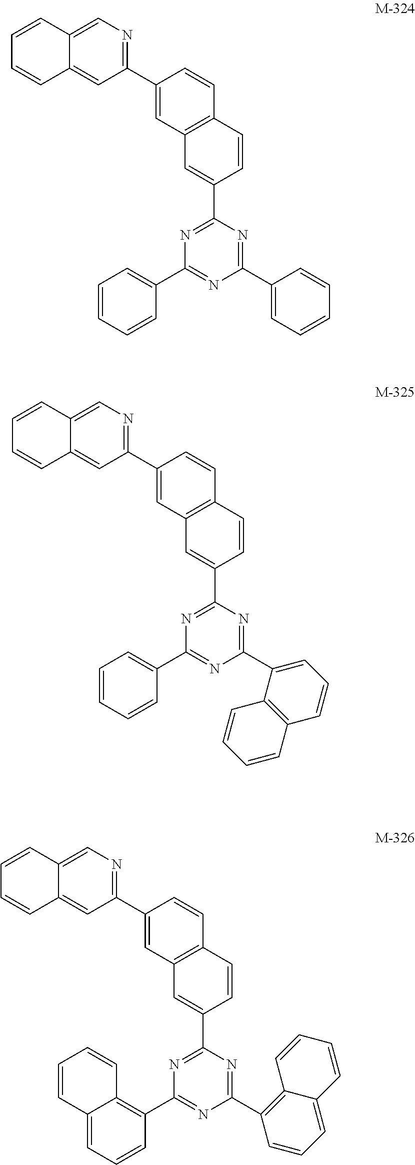 [SMILES: c1ccc(-c2nc(-c3ccccc3)nc(-c3ccc4ccc(-c5cc6ccccc6cn5)cc4c3)n2)cc1 ; c1ccc(-c2nc(-c3ccc4ccc(-c5cc6ccccc6cn5)cc4c3)nc(-c3cccc4ccccc34)n2)cc1 ; c1ccc2cc(-c3ccc4ccc(-c5nc(-c6cccc7ccccc67)nc(-c6cccc7ccccc67)n5)cc4c3)ncc2c1]

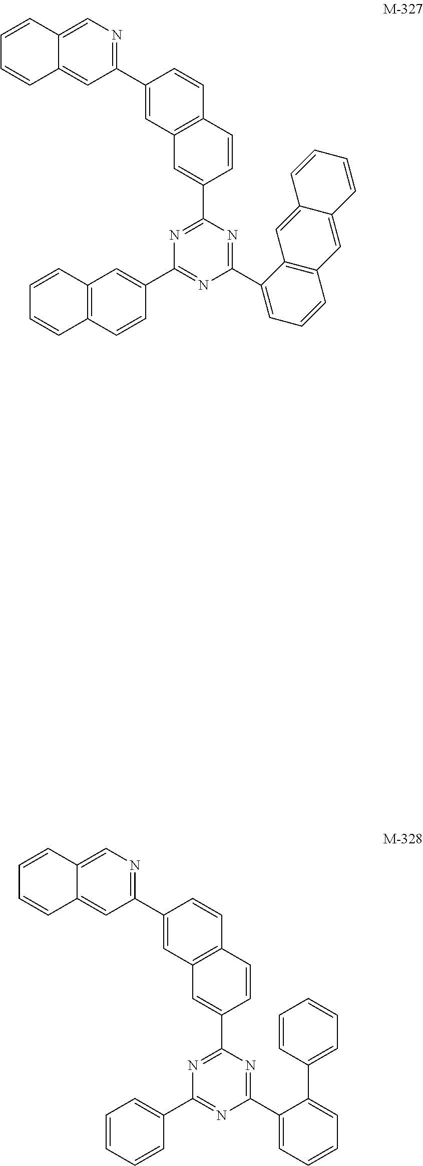 [SMILES: c1ccc2cc(-c3nc(-c4ccc5ccc(-c6cc7ccccc7cn6)cc5c4)nc(-c4cccc5cc6ccccc6cc45)n3)ccc2c1 ; c1ccc(-c2nc(-c3ccc4ccc(-c5cc6ccccc6cn5)cc4c3)nc(-c3ccccc3-c3ccccc3)n2)cc1]

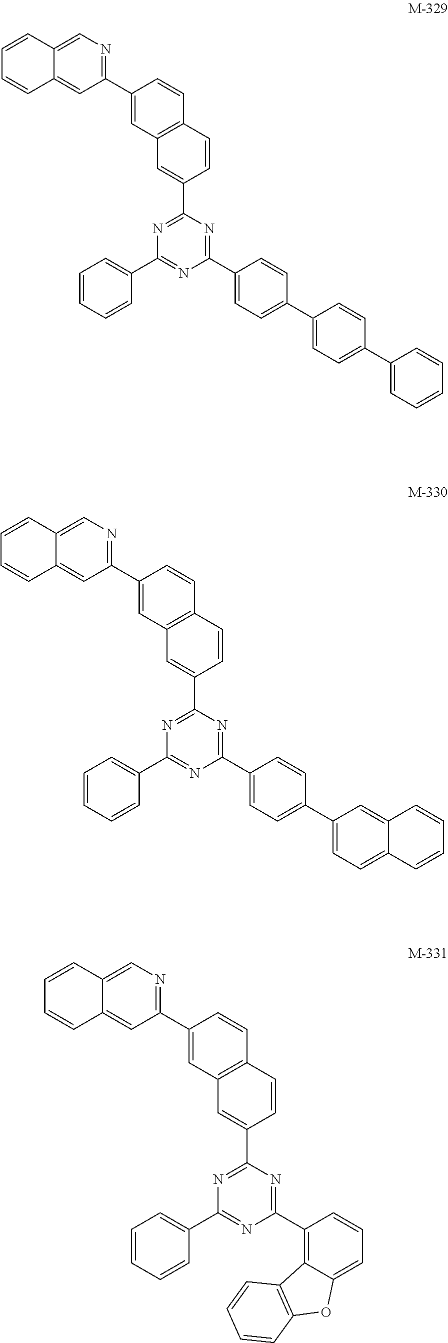 [SMILES: c1ccc(-c2ccc(-c3ccc(-c4nc(-c5ccccc5)nc(-c5ccc6ccc(-c7cc8ccccc8cn7)cc6c5)n4)cc3)cc2)cc1 ; c1ccc(-c2nc(-c3ccc(-c4ccc5ccccc5c4)cc3)nc(-c3ccc4ccc(-c5cc6ccccc6cn5)cc4c3)n2)cc1 ; c1ccc(-c2nc(-c3ccc4ccc(-c5cc6ccccc6cn5)cc4c3)nc(-c3cccc4oc5ccccc5c34)n2)cc1]

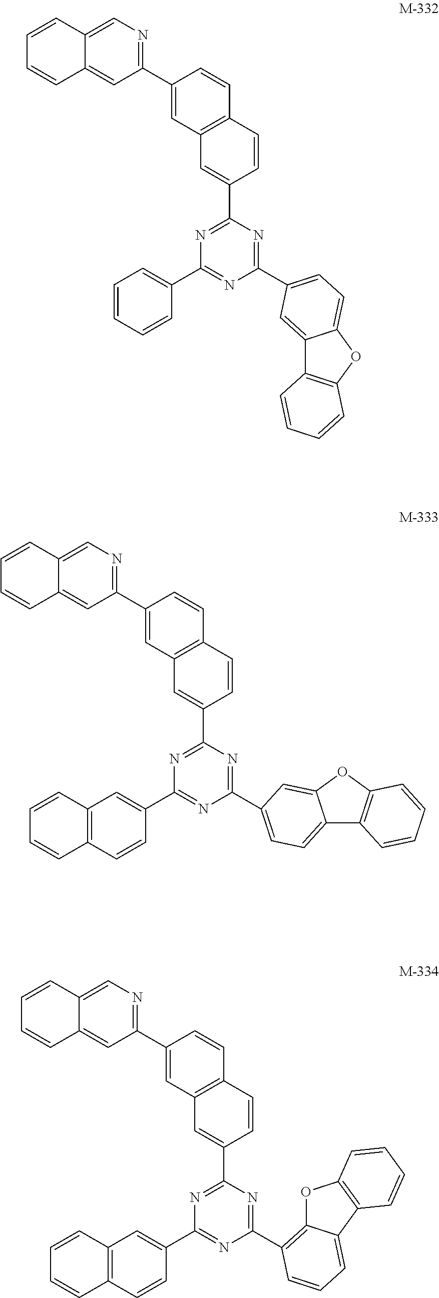 [SMILES: c1ccc(-c2nc(-c3ccc4ccc(-c5cc6ccccc6cn5)cc4c3)nc(-c3ccc4oc5ccccc5c4c3)n2)cc1 ; c1ccc2cc(-c3nc(-c4ccc5ccc(-c6cc7ccccc7cn6)cc5c4)nc(-c4ccc5c(c4)oc4ccccc45)n3)ccc2c1 ; c1ccc2cc(-c3nc(-c4ccc5ccc(-c6cc7ccccc7cn6)cc5c4)nc(-c4cccc5c4oc4ccccc45)n3)ccc2c1]

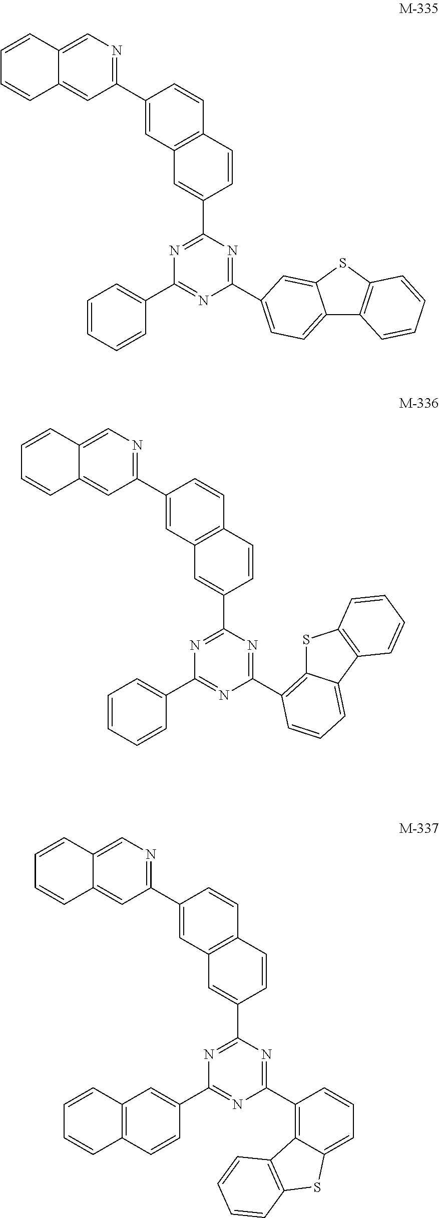 [SMILES: c1ccc(-c2nc(-c3ccc4ccc(-c5cc6ccccc6cn5)cc4c3)nc(-c3ccc4c(c3)sc3ccccc34)n2)cc1 ; c1ccc(-c2nc(-c3ccc4ccc(-c5cc6ccccc6cn5)cc4c3)nc(-c3cccc4c3sc3ccccc34)n2)cc1 ; c1ccc2cc(-c3nc(-c4ccc5ccc(-c6cc7ccccc7cn6)cc5c4)nc(-c4cccc5sc6ccccc6c45)n3)ccc2c1]

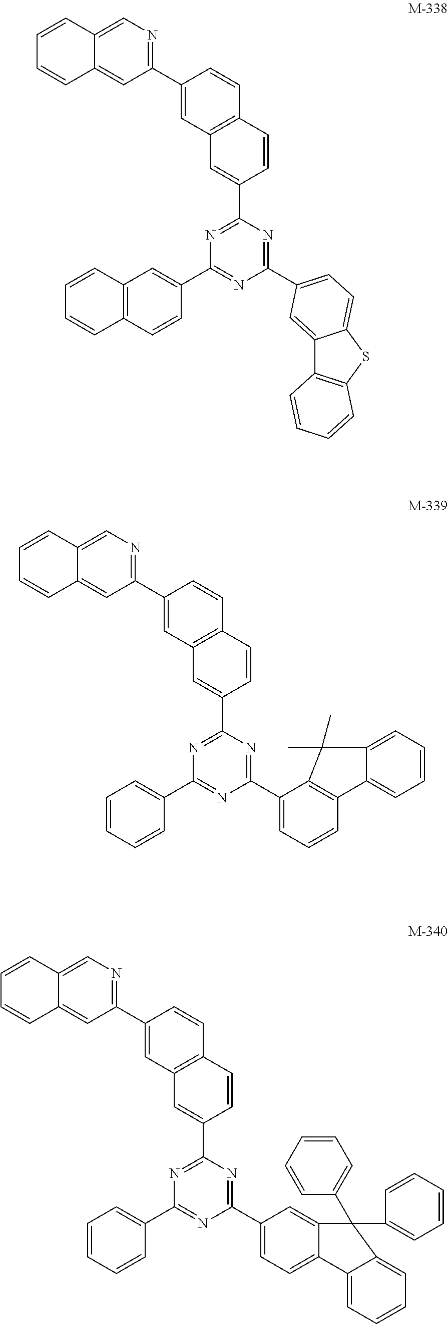 [SMILES: c1ccc2cc(-c3nc(-c4ccc5ccc(-c6cc7ccccc7cn6)cc5c4)nc(-c4ccc5sc6ccccc6c5c4)n3)ccc2c1 ; CC1(C)c2ccccc2-c2cccc(-c3nc(-c4ccccc4)nc(-c4ccc5ccc(-c6cc7ccccc7cn6)cc5c4)n3)c21 ; c1ccc(-c2nc(-c3ccc4c(c3)C(c3ccccc3)(c3ccccc3)c3ccccc3-4)nc(-c3ccc4ccc(-c5cc6ccccc6cn5)cc4c3)n2)cc1]

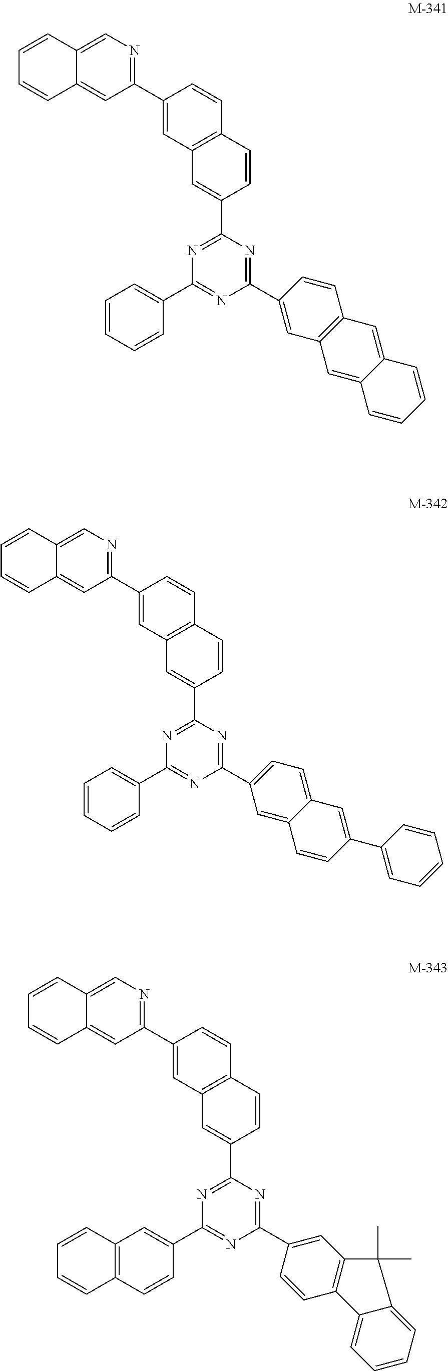 [SMILES: c1ccc(-c2nc(-c3ccc4ccc(-c5cc6ccccc6cn5)cc4c3)nc(-c3ccc4cc5ccccc5cc4c3)n2)cc1 ; c1ccc(-c2ccc3cc(-c4nc(-c5ccccc5)nc(-c5ccc6ccc(-c7cc8ccccc8cn7)cc6c5)n4)ccc3c2)cc1 ; CC1(C)c2ccccc2-c2ccc(-c3nc(-c4ccc5ccccc5c4)nc(-c4ccc5ccc(-c6cc7ccccc7cn6)cc5c4)n3)cc21]

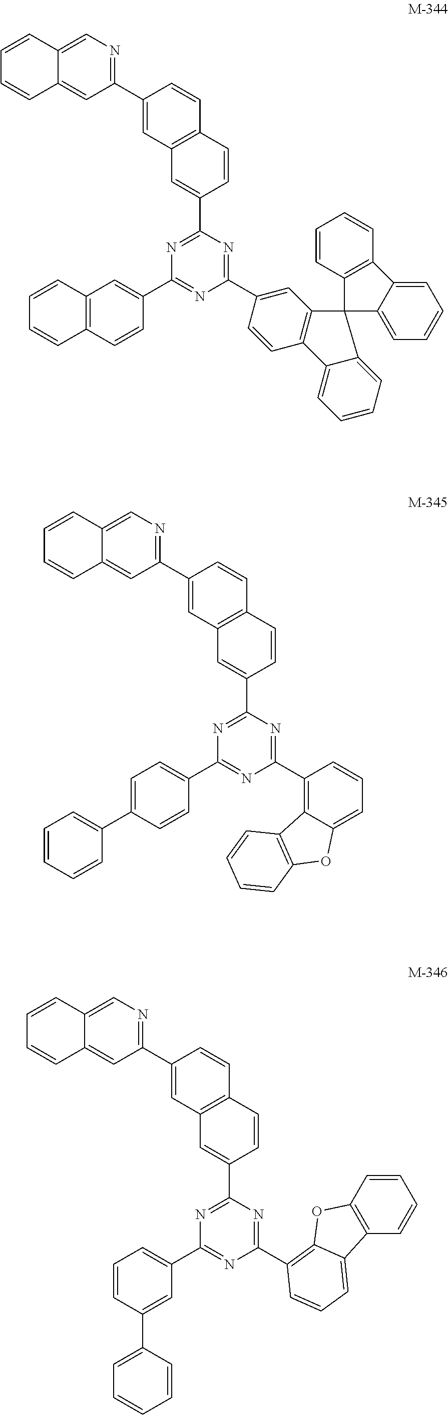 [SMILES: c1ccc2c(c1)-c1ccccc1C21c2ccccc2-c2ccc(-c3nc(-c4ccc5ccccc5c4)nc(-c4ccc5ccc(-c6cc7ccccc7cn6)cc5c4)n3)cc21 ; c1ccc(-c2ccc(-c3nc(-c4ccc5ccc(-c6cc7ccccc7cn6)cc5c4)nc(-c4cccc5oc6ccccc6c45)n3)cc2)cc1 ; c1ccc(-c2cccc(-c3nc(-c4ccc5ccc(-c6cc7ccccc7cn6)cc5c4)nc(-c4cccc5c4oc4ccccc45)n3)c2)cc1]

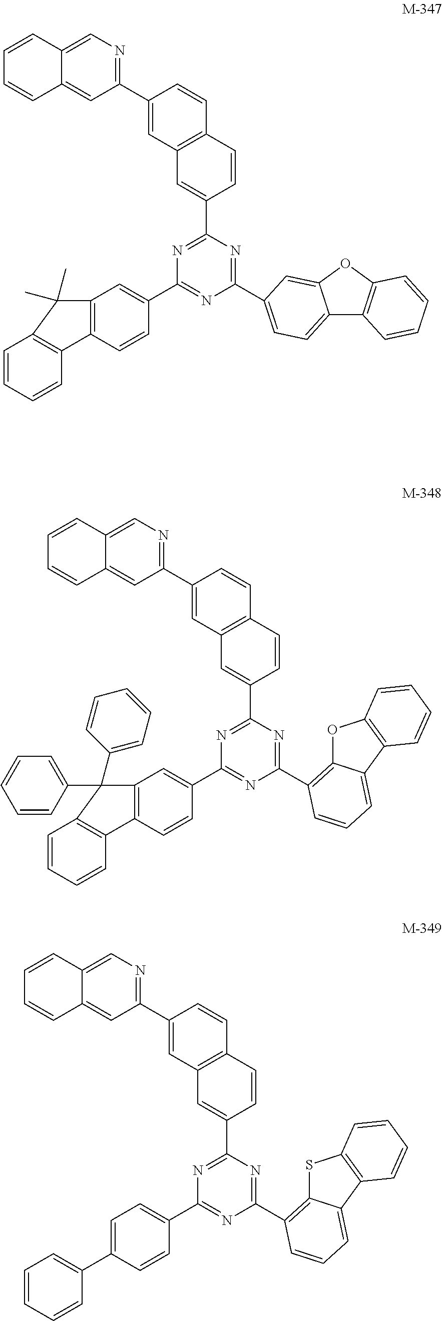 [SMILES: CC1(C)c2ccccc2-c2ccc(-c3nc(-c4ccc5ccc(-c6cc7ccccc7cn6)cc5c4)nc(-c4ccc5c(c4)oc4ccccc45)n3)cc21 ; c1ccc(C2(c3ccccc3)c3ccccc3-c3ccc(-c4nc(-c5ccc6ccc(-c7cc8ccccc8cn7)cc6c5)nc(-c5cccc6c5oc5ccccc56)n4)cc32)cc1 ; c1ccc(-c2ccc(-c3nc(-c4ccc5ccc(-c6cc7ccccc7cn6)cc5c4)nc(-c4cccc5c4sc4ccccc45)n3)cc2)cc1]

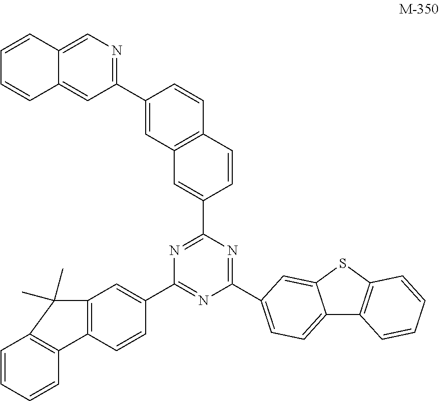 [SMILES: CC1(C)c2ccccc2-c2ccc(-c3nc(-c4ccc5ccc(-c6cc7ccccc7cn6)cc5c4)nc(-c4ccc5c(c4)sc4ccccc45)n3)cc21]

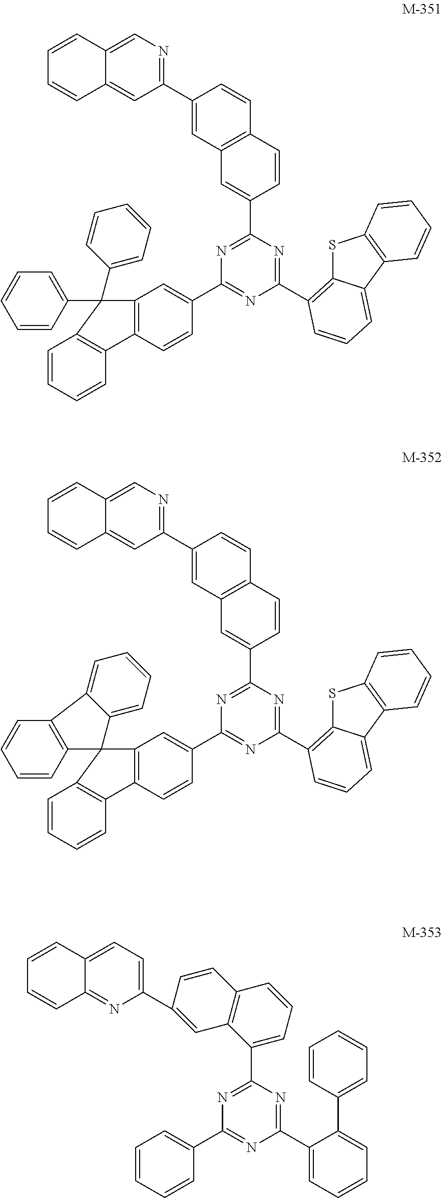 [SMILES: c1ccc(C2(c3ccccc3)c3ccccc3-c3ccc(-c4nc(-c5ccc6ccc(-c7cc8ccccc8cn7)cc6c5)nc(-c5cccc6c5sc5ccccc56)n4)cc32)cc1 ; c1ccc2c(c1)-c1ccccc1C21c2ccccc2-c2ccc(-c3nc(-c4ccc5ccc(-c6cc7ccccc7cn6)cc5c4)nc(-c4cccc5c4sc4ccccc45)n3)cc21 ; c1ccc(-c2nc(-c3ccccc3-c3ccccc3)nc(-c3cccc4ccc(-c5ccc6ccccc6n5)cc34)n2)cc1]

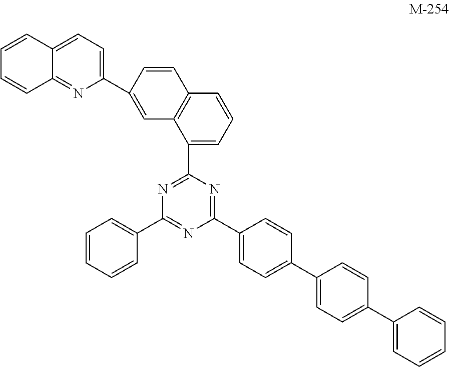 [SMILES: c1ccc(-c2ccc(-c3ccc(-c4nc(-c5ccccc5)nc(-c5cccc6ccc(-c7ccc8ccccc8n7)cc56)n4)cc3)cc2)cc1]

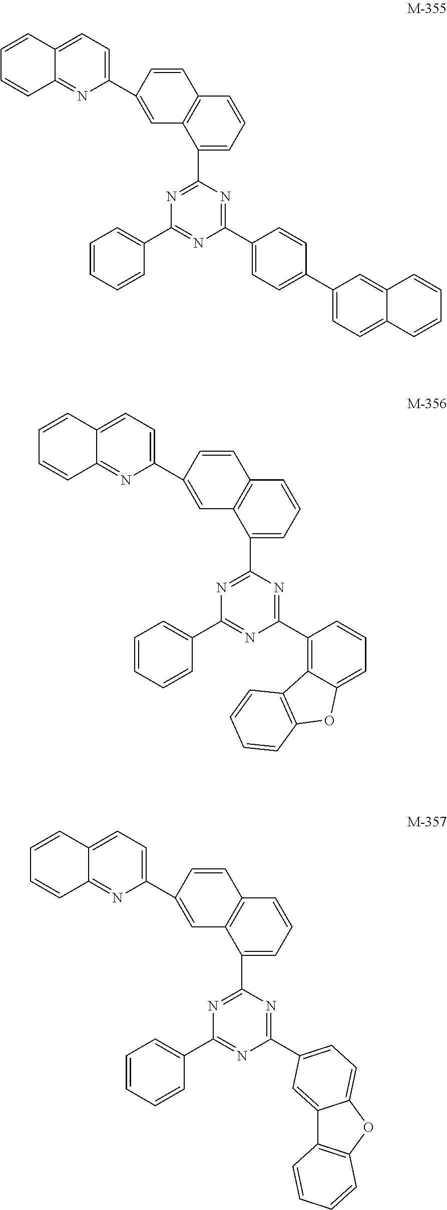 [SMILES: c1ccc(-c2nc(-c3ccc(-c4ccc5ccccc5c4)cc3)nc(-c3cccc4ccc(-c5ccc6ccccc6n5)cc34)n2)cc1 ; c1ccc(-c2nc(-c3cccc4ccc(-c5ccc6ccccc6n5)cc34)nc(-c3cccc4oc5ccccc5c34)n2)cc1 ; c1ccc(-c2nc(-c3ccc4oc5ccccc5c4c3)nc(-c3cccc4ccc(-c5ccc6ccccc6n5)cc34)n2)cc1]

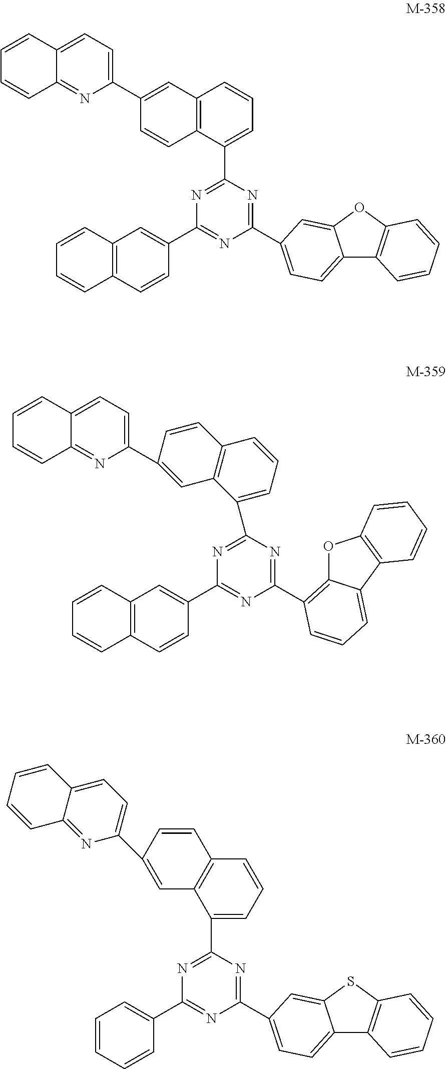 [SMILES: c1ccc2cc(-c3nc(-c4ccc5c(c4)oc4ccccc45)nc(-c4cccc5cc(-c6ccc7ccccc7n6)ccc45)n3)ccc2c1 ; c1ccc2cc(-c3nc(-c4cccc5ccc(-c6ccc7ccccc7n6)cc45)nc(-c4cccc5c4oc4ccccc45)n3)ccc2c1 ; c1ccc(-c2nc(-c3ccc4c(c3)sc3ccccc34)nc(-c3cccc4ccc(-c5ccc6ccccc6n5)cc34)n2)cc1]

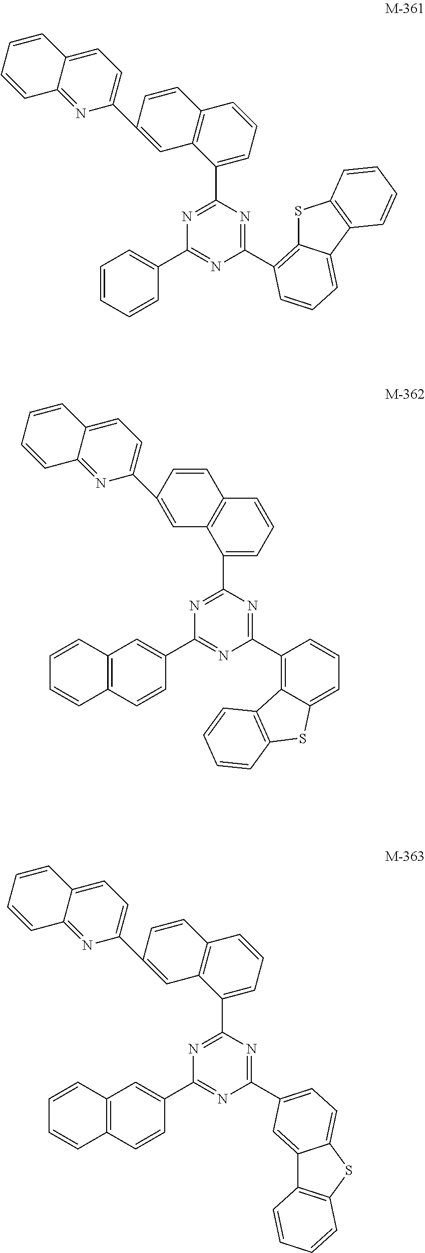 [SMILES: c1ccc(-c2nc(-c3cccc4ccc(-c5ccc6ccccc6n5)cc34)nc(-c3cccc4c3sc3ccccc34)n2)cc1 ; c1ccc2cc(-c3nc(-c4cccc5ccc(-c6ccc7ccccc7n6)cc45)nc(-c4cccc5sc6ccccc6c45)n3)ccc2c1 ; c1ccc2cc(-c3nc(-c4ccc5sc6ccccc6c5c4)nc(-c4cccc5ccc(-c6ccc7ccccc7n6)cc45)n3)ccc2c1]

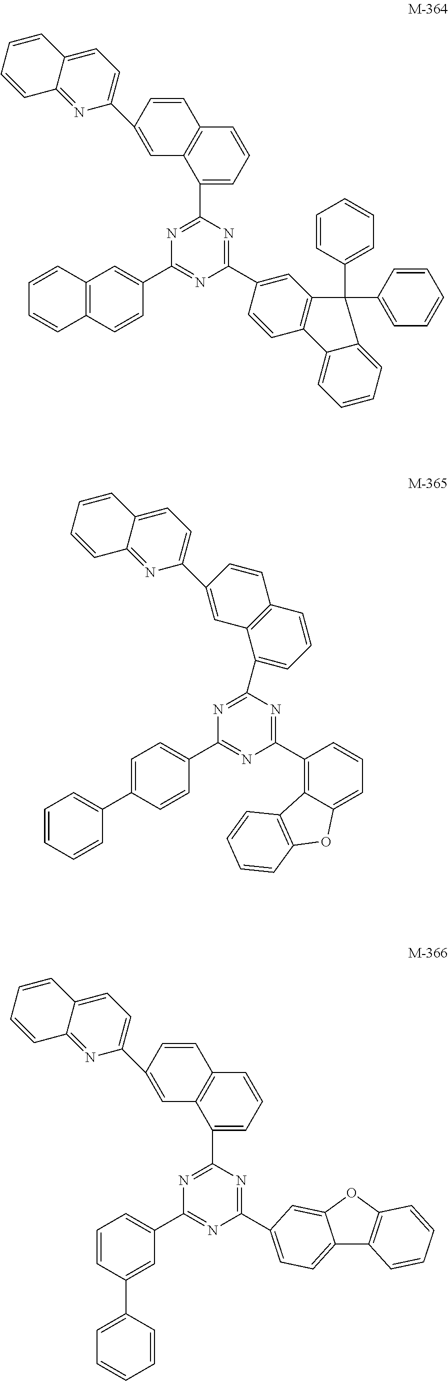 [SMILES: c1ccc(C2(c3ccccc3)c3ccccc3-c3ccc(-c4nc(-c5ccc6ccccc6c5)nc(-c5cccc6ccc(-c7ccc8ccccc8n7)cc56)n4)cc32)cc1 ; c1ccc(-c2ccc(-c3nc(-c4cccc5ccc(-c6ccc7ccccc7n6)cc45)nc(-c4cccc5oc6ccccc6c45)n3)cc2)cc1 ; c1ccc(-c2cccc(-c3nc(-c4ccc5c(c4)oc4ccccc45)nc(-c4cccc5ccc(-c6ccc7ccccc7n6)cc45)n3)c2)cc1]

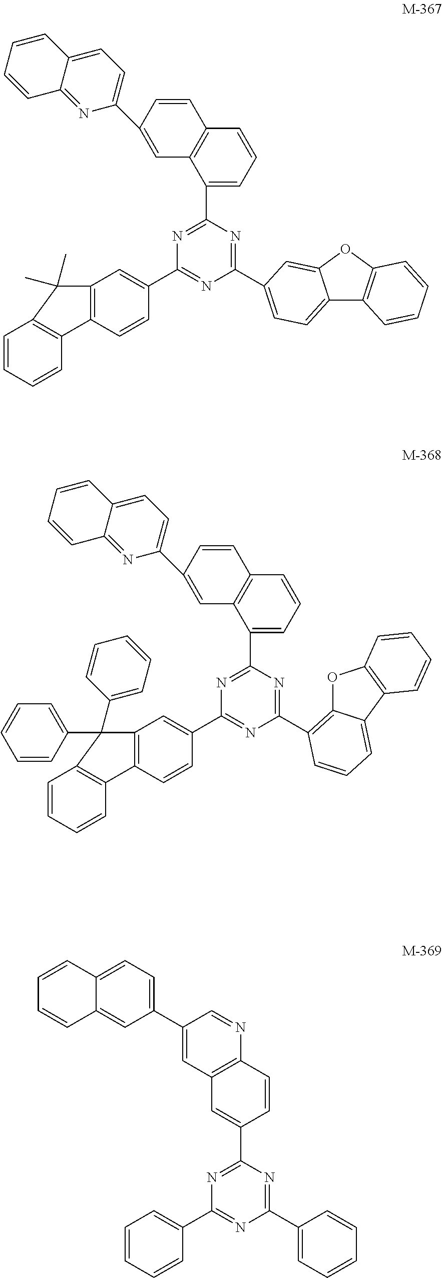 [SMILES: CC1(C)c2ccccc2-c2ccc(-c3nc(-c4ccc5c(c4)oc4ccccc45)nc(-c4cccc5ccc(-c6ccc7ccccc7n6)cc45)n3)cc21 ; c1ccc(C2(c3ccccc3)c3ccccc3-c3ccc(-c4nc(-c5cccc6ccc(-c7ccc8ccccc8n7)cc56)nc(-c5cccc6c5oc5ccccc56)n4)cc32)cc1 ; c1ccc(-c2nc(-c3ccccc3)nc(-c3ccc4ncc(-c5ccc6ccccc6c5)cc4c3)n2)cc1]

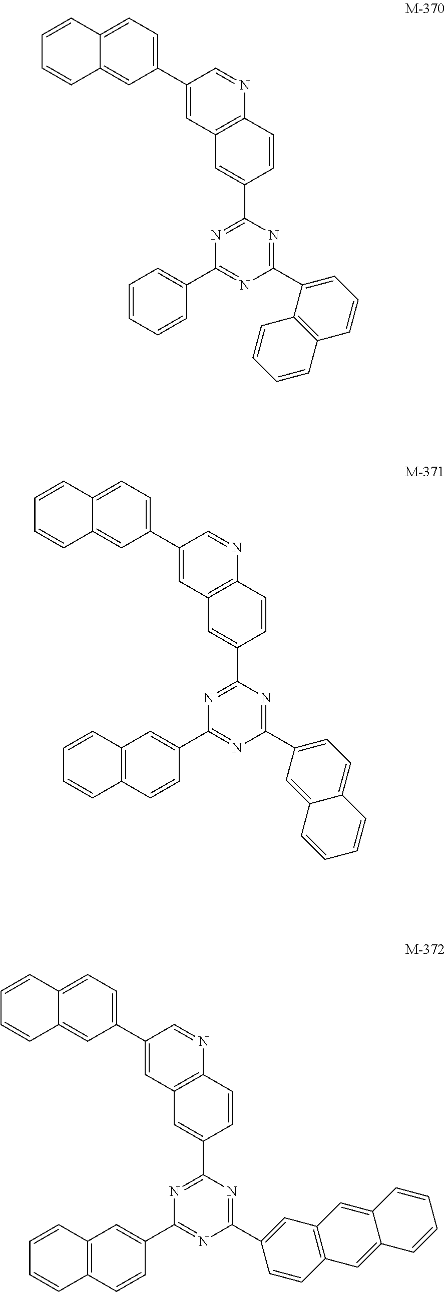 [SMILES: c1ccc(-c2nc(-c3ccc4ncc(-c5ccc6ccccc6c5)cc4c3)nc(-c3cccc4ccccc34)n2)cc1 ; c1ccc2cc(-c3cnc4ccc(-c5nc(-c6ccc7ccccc7c6)nc(-c6ccc7ccccc7c6)n5)cc4c3)ccc2c1 ; c1ccc2cc(-c3cnc4ccc(-c5nc(-c6ccc7ccccc7c6)nc(-c6ccc7cc8ccccc8cc7c6)n5)cc4c3)ccc2c1]

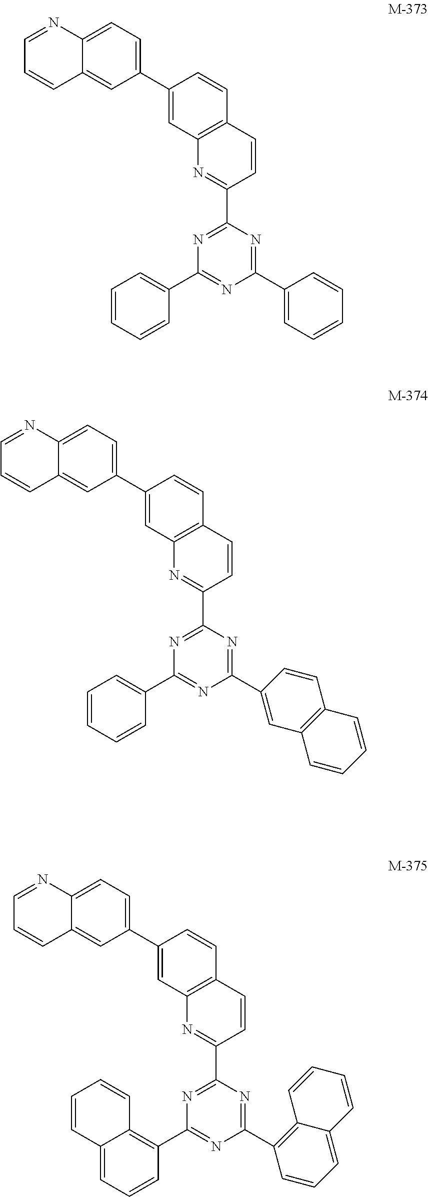 [SMILES: c1ccc(-c2nc(-c3ccccc3)nc(-c3ccc4ccc(-c5ccc6ncccc6c5)cc4n3)n2)cc1 ; c1ccc(-c2nc(-c3ccc4ccccc4c3)nc(-c3ccc4ccc(-c5ccc6ncccc6c5)cc4n3)n2)cc1 ; c1cnc2ccc(-c3ccc4ccc(-c5nc(-c6cccc7ccccc67)nc(-c6cccc7ccccc67)n5)nc4c3)cc2c1]

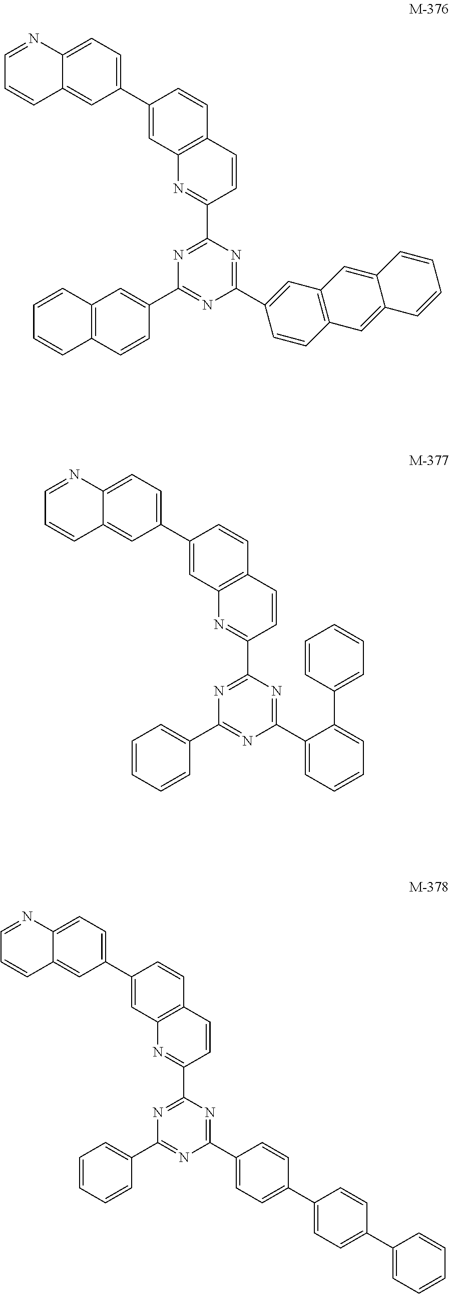 [SMILES: c1ccc2cc(-c3nc(-c4ccc5cc6ccccc6cc5c4)nc(-c4ccc5ccc(-c6ccc7ncccc7c6)cc5n4)n3)ccc2c1 ; c1ccc(-c2nc(-c3ccc4ccc(-c5ccc6ncccc6c5)cc4n3)nc(-c3ccccc3-c3ccccc3)n2)cc1 ; c1ccc(-c2ccc(-c3ccc(-c4nc(-c5ccccc5)nc(-c5ccc6ccc(-c7ccc8ncccc8c7)cc6n5)n4)cc3)cc2)cc1]

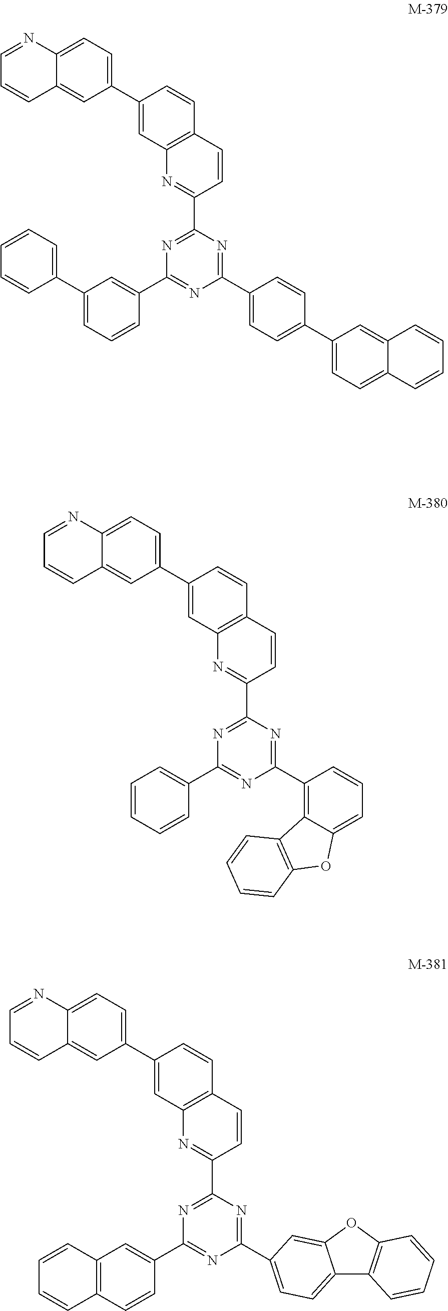 [SMILES: c1ccc(-c2cccc(-c3nc(-c4ccc(-c5ccc6ccccc6c5)cc4)nc(-c4ccc5ccc(-c6ccc7ncccc7c6)cc5n4)n3)c2)cc1 ; c1ccc(-c2nc(-c3ccc4ccc(-c5ccc6ncccc6c5)cc4n3)nc(-c3cccc4oc5ccccc5c34)n2)cc1 ; c1ccc2cc(-c3nc(-c4ccc5c(c4)oc4ccccc45)nc(-c4ccc5ccc(-c6ccc7ncccc7c6)cc5n4)n3)ccc2c1]

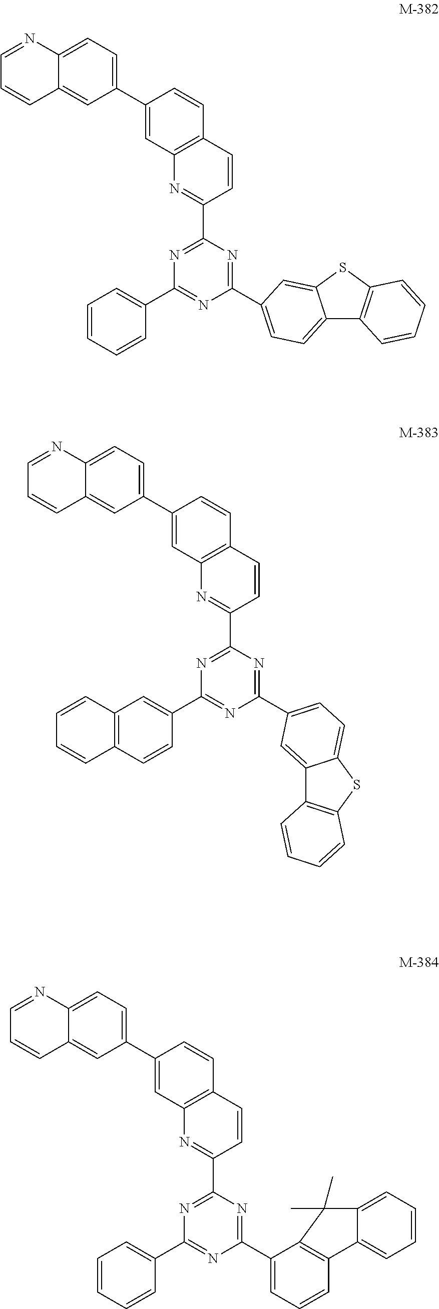 [SMILES: c1ccc(-c2nc(-c3ccc4c(c3)sc3ccccc34)nc(-c3ccc4ccc(-c5ccc6ncccc6c5)cc4n3)n2)cc1 ; c1ccc2cc(-c3nc(-c4ccc5sc6ccccc6c5c4)nc(-c4ccc5ccc(-c6ccc7ncccc7c6)cc5n4)n3)ccc2c1 ; CC1(C)c2ccccc2-c2cccc(-c3nc(-c4ccccc4)nc(-c4ccc5ccc(-c6ccc7ncccc7c6)cc5n4)n3)c21]

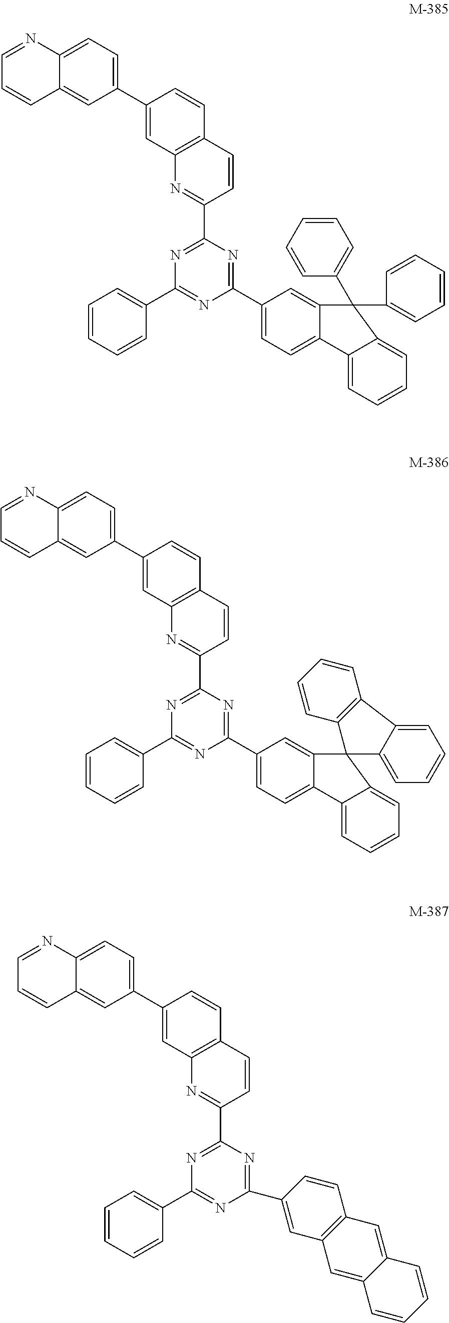 [SMILES: c1ccc(-c2nc(-c3ccc4c(c3)C(c3ccccc3)(c3ccccc3)c3ccccc3-4)nc(-c3ccc4ccc(-c5ccc6ncccc6c5)cc4n3)n2)cc1 ; c1ccc(-c2nc(-c3ccc4c(c3)C3(c5ccccc5-c5ccccc53)c3ccccc3-4)nc(-c3ccc4ccc(-c5ccc6ncccc6c5)cc4n3)n2)cc1 ; c1ccc(-c2nc(-c3ccc4cc5ccccc5cc4c3)nc(-c3ccc4ccc(-c5ccc6ncccc6c5)cc4n3)n2)cc1]

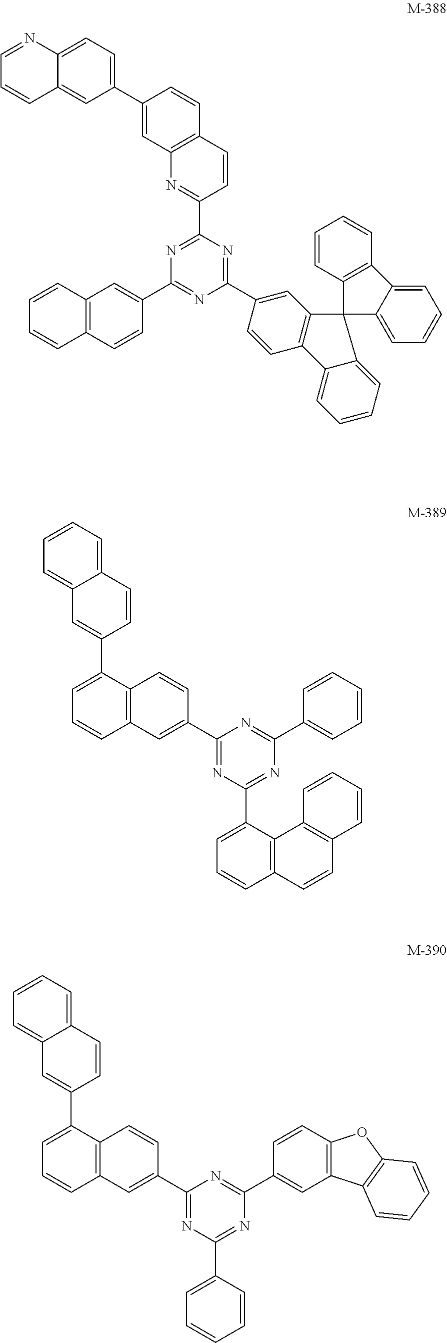 [SMILES: c1ccc2c(c1)-c1ccccc1C21c2ccccc2-c2ccc(-c3nc(-c4ccc5ccccc5c4)nc(-c4ccc5ccc(-c6ccc7ncccc7c6)cc5n4)n3)cc21 ; c1ccc(-c2nc(-c3ccc4c(-c5ccc6ccccc6c5)cccc4c3)nc(-c3cccc4ccc5ccccc5c34)n2)cc1 ; c1ccc(-c2nc(-c3ccc4c(-c5ccc6ccccc6c5)cccc4c3)nc(-c3ccc4oc5ccccc5c4c3)n2)cc1]

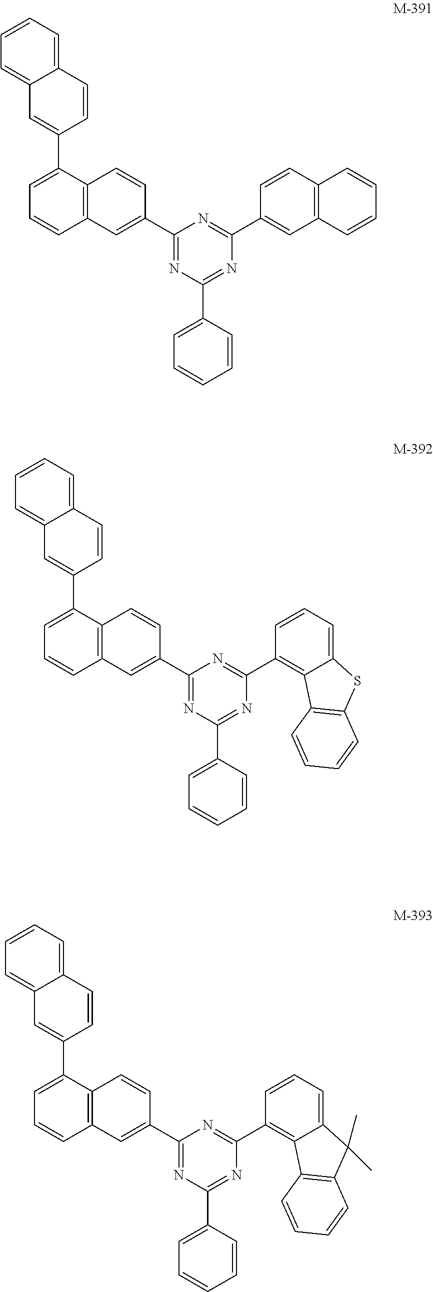 [SMILES: c1ccc(-c2nc(-c3ccc4ccccc4c3)nc(-c3ccc4c(-c5ccc6ccccc6c5)cccc4c3)n2)cc1 ; c1ccc(-c2nc(-c3ccc4c(-c5ccc6ccccc6c5)cccc4c3)nc(-c3cccc4sc5ccccc5c34)n2)cc1 ; CC1(C)c2ccccc2-c2c(-c3nc(-c4ccccc4)nc(-c4ccc5c(-c6ccc7ccccc7c6)cccc5c4)n3)cccc21]

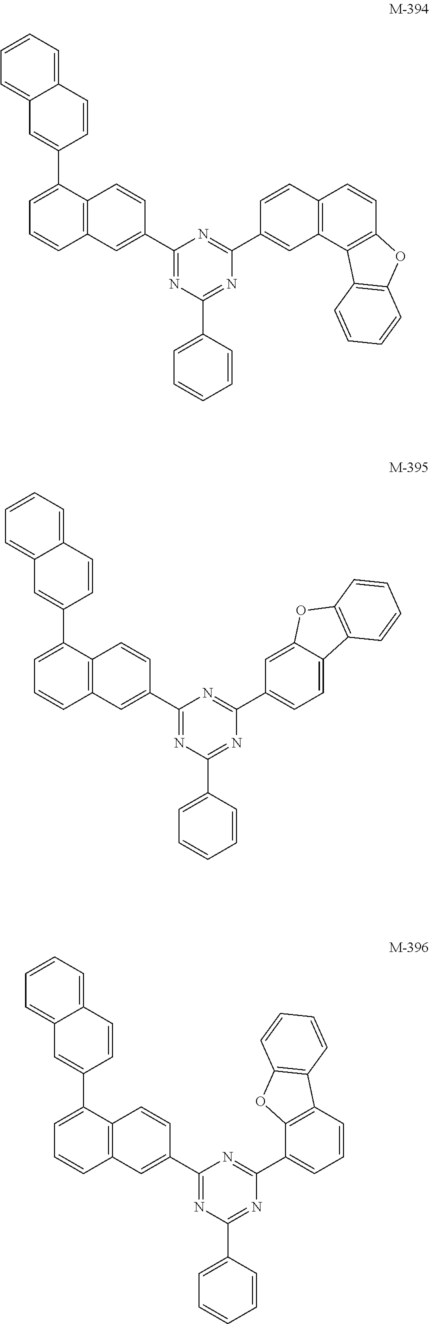 [SMILES: c1ccc(-c2nc(-c3ccc4c(-c5ccc6ccccc6c5)cccc4c3)nc(-c3ccc4ccc5oc6ccccc6c5c4c3)n2)cc1 ; c1ccc(-c2nc(-c3ccc4c(-c5ccc6ccccc6c5)cccc4c3)nc(-c3ccc4c(c3)oc3ccccc34)n2)cc1 ; c1ccc(-c2nc(-c3ccc4c(-c5ccc6ccccc6c5)cccc4c3)nc(-c3cccc4c3oc3ccccc34)n2)cc1]

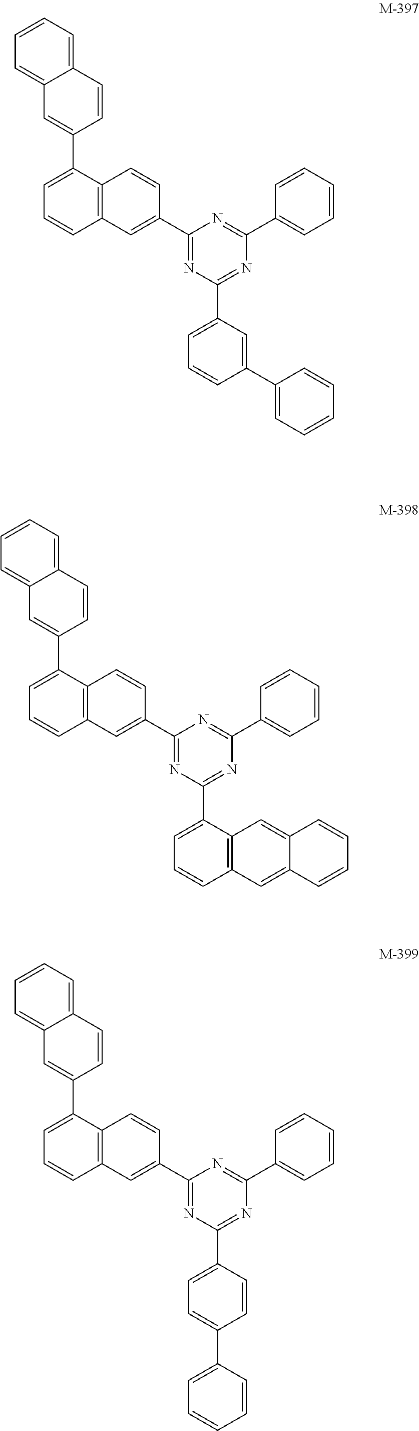 [SMILES: c1ccc(-c2cccc(-c3nc(-c4ccccc4)nc(-c4ccc5c(-c6ccc7ccccc7c6)cccc5c4)n3)c2)cc1 ; c1ccc(-c2nc(-c3ccc4c(-c5ccc6ccccc6c5)cccc4c3)nc(-c3cccc4cc5ccccc5cc34)n2)cc1 ; c1ccc(-c2ccc(-c3nc(-c4ccccc4)nc(-c4ccc5c(-c6ccc7ccccc7c6)cccc5c4)n3)cc2)cc1]

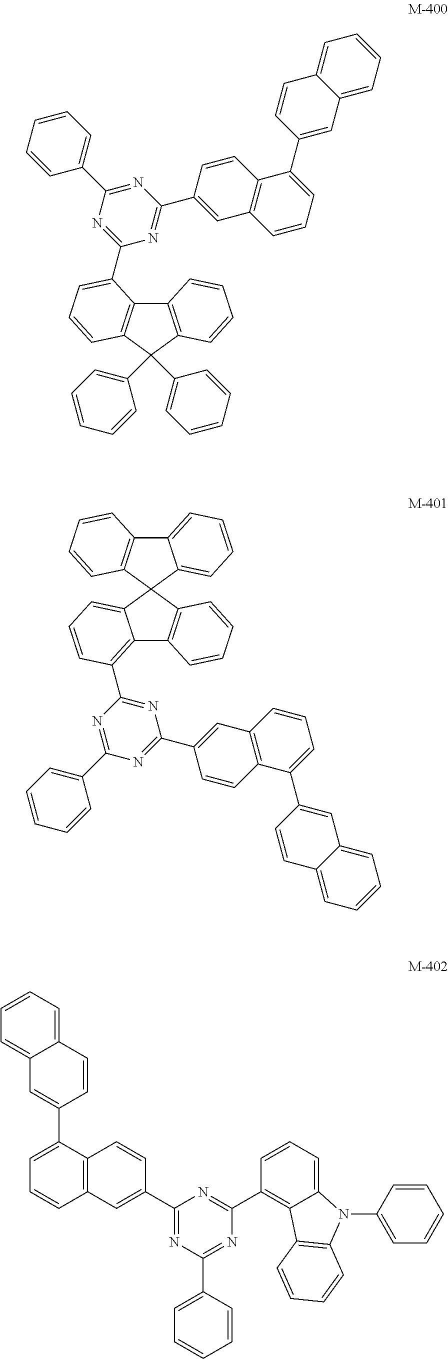 [SMILES: c1ccc(-c2nc(-c3ccc4c(-c5ccc6ccccc6c5)cccc4c3)nc(-c3cccc4c3-c3ccccc3C4(c3ccccc3)c3ccccc3)n2)cc1 ; c1ccc(-c2nc(-c3ccc4c(-c5ccc6ccccc6c5)cccc4c3)nc(-c3cccc4c3-c3ccccc3C43c4ccccc4-c4ccccc43)n2)cc1 ; c1ccc(-c2nc(-c3ccc4c(-c5ccc6ccccc6c5)cccc4c3)nc(-c3cccc4c3c3ccccc3n4-c3ccccc3)n2)cc1]

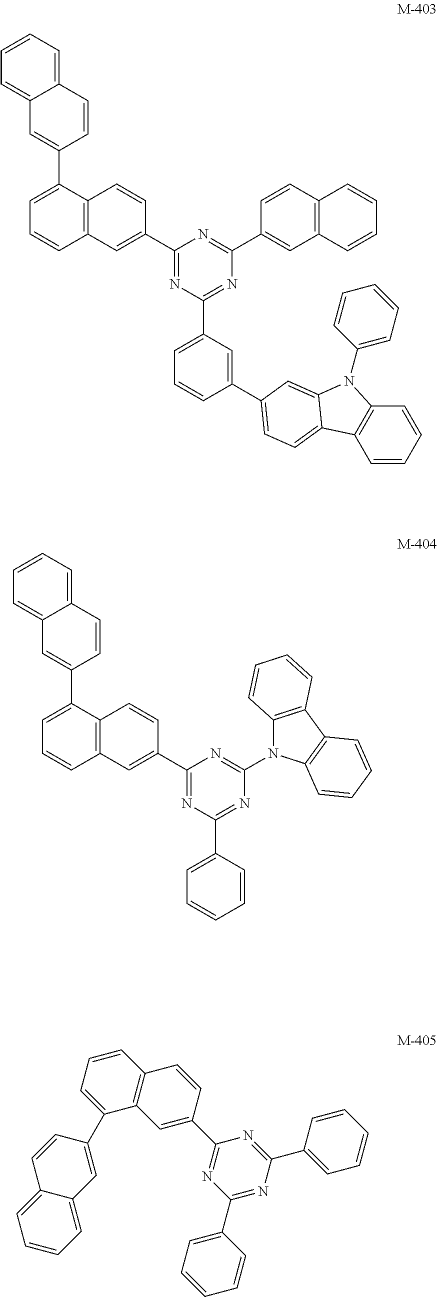 [SMILES: c1ccc(-n2c3ccccc3c3ccc(-c4cccc(-c5nc(-c6ccc7ccccc7c6)nc(-c6ccc7c(-c8ccc9ccccc9c8)cccc7c6)n5)c4)cc32)cc1 ; c1ccc(-c2nc(-c3ccc4c(-c5ccc6ccccc6c5)cccc4c3)nc(-n3c4ccccc4c4ccccc43)n2)cc1 ; c1ccc(-c2nc(-c3ccccc3)nc(-c3ccc4cccc(-c5ccc6ccccc6c5)c4c3)n2)cc1]

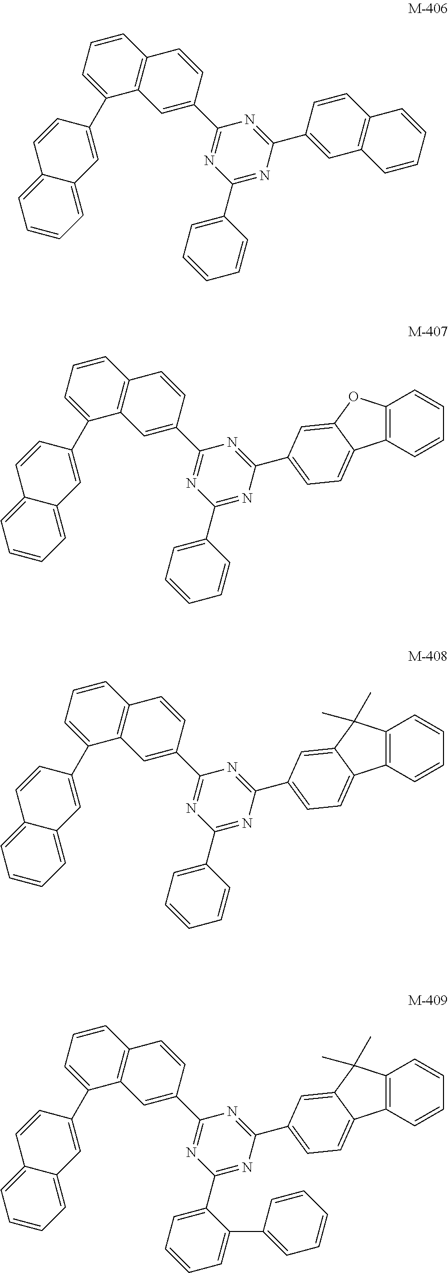 [SMILES: c1ccc(-c2nc(-c3ccc4ccccc4c3)nc(-c3ccc4cccc(-c5ccc6ccccc6c5)c4c3)n2)cc1 ; c1ccc(-c2nc(-c3ccc4c(c3)oc3ccccc34)nc(-c3ccc4cccc(-c5ccc6ccccc6c5)c4c3)n2)cc1 ; CC1(C)c2ccccc2-c2ccc(-c3nc(-c4ccccc4)nc(-c4ccc5cccc(-c6ccc7ccccc7c6)c5c4)n3)cc21 ; CC1(C)c2ccccc2-c2ccc(-c3nc(-c4ccc5cccc(-c6ccc7ccccc7c6)c5c4)nc(-c4ccccc4-c4ccccc4)n3)cc21]

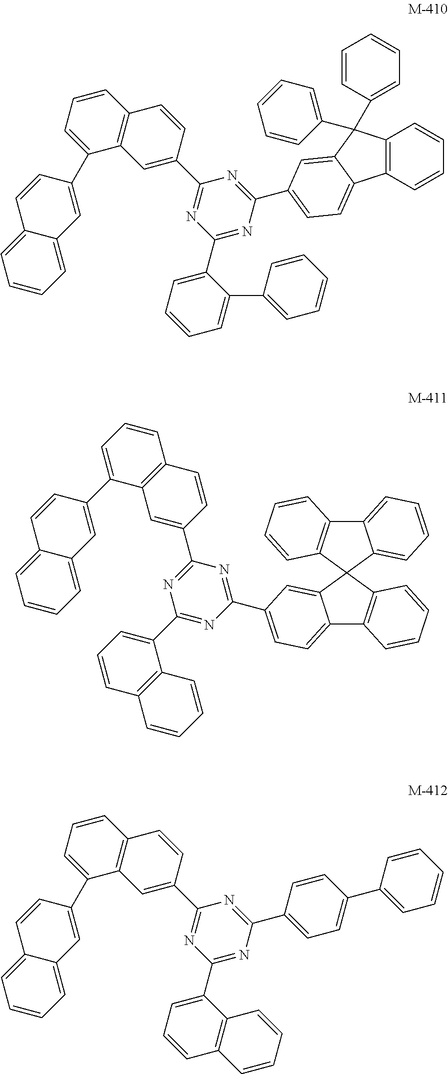 [SMILES: c1ccc(-c2ccccc2-c2nc(-c3ccc4c(c3)C(c3ccccc3)(c3ccccc3)c3ccccc3-4)nc(-c3ccc4cccc(-c5ccc6ccccc6c5)c4c3)n2)cc1 ; c1ccc2c(c1)-c1ccccc1C21c2ccccc2-c2ccc(-c3nc(-c4ccc5cccc(-c6ccc7ccccc7c6)c5c4)nc(-c4cccc5ccccc45)n3)cc21 ; c1ccc(-c2ccc(-c3nc(-c4ccc5cccc(-c6ccc7ccccc7c6)c5c4)nc(-c4cccc5ccccc45)n3)cc2)cc1]

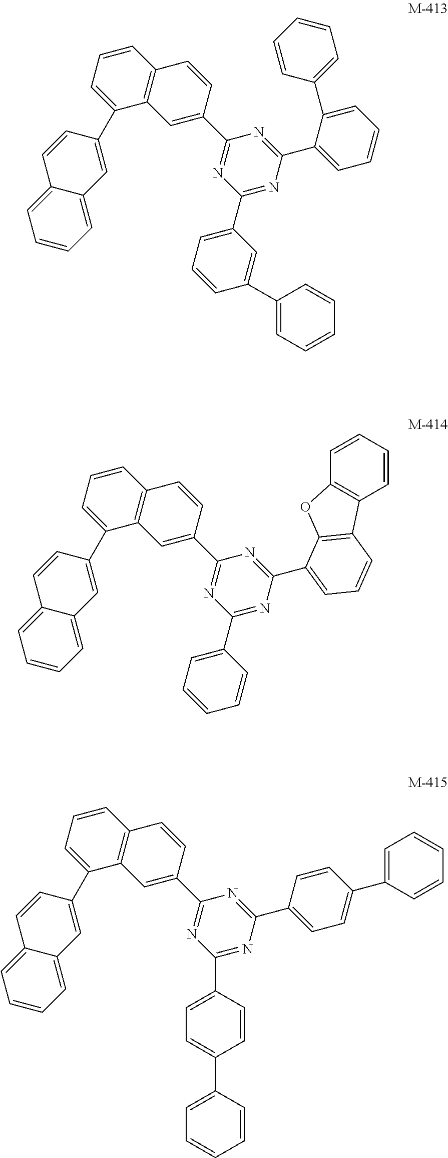 [SMILES: c1ccc(-c2cccc(-c3nc(-c4ccc5cccc(-c6ccc7ccccc7c6)c5c4)nc(-c4ccccc4-c4ccccc4)n3)c2)cc1 ; c1ccc(-c2nc(-c3ccc4cccc(-c5ccc6ccccc6c5)c4c3)nc(-c3cccc4c3oc3ccccc34)n2)cc1 ; c1ccc(-c2ccc(-c3nc(-c4ccc(-c5ccccc5)cc4)nc(-c4ccc5cccc(-c6ccc7ccccc7c6)c5c4)n3)cc2)cc1]

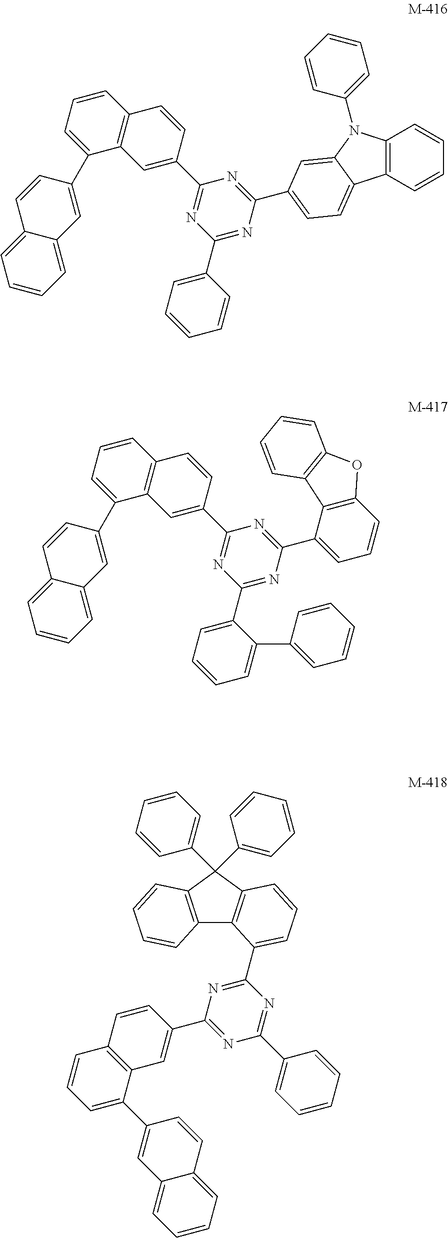 [SMILES: c1ccc(-c2nc(-c3ccc4cccc(-c5ccc6ccccc6c5)c4c3)nc(-c3ccc4c5ccccc5n(-c5ccccc5)c4c3)n2)cc1 ; c1ccc(-c2ccccc2-c2nc(-c3ccc4cccc(-c5ccc6ccccc6c5)c4c3)nc(-c3cccc4oc5ccccc5c34)n2)cc1 ; c1ccc(-c2nc(-c3ccc4cccc(-c5ccc6ccccc6c5)c4c3)nc(-c3cccc4c3-c3ccccc3C4(c3ccccc3)c3ccccc3)n2)cc1]

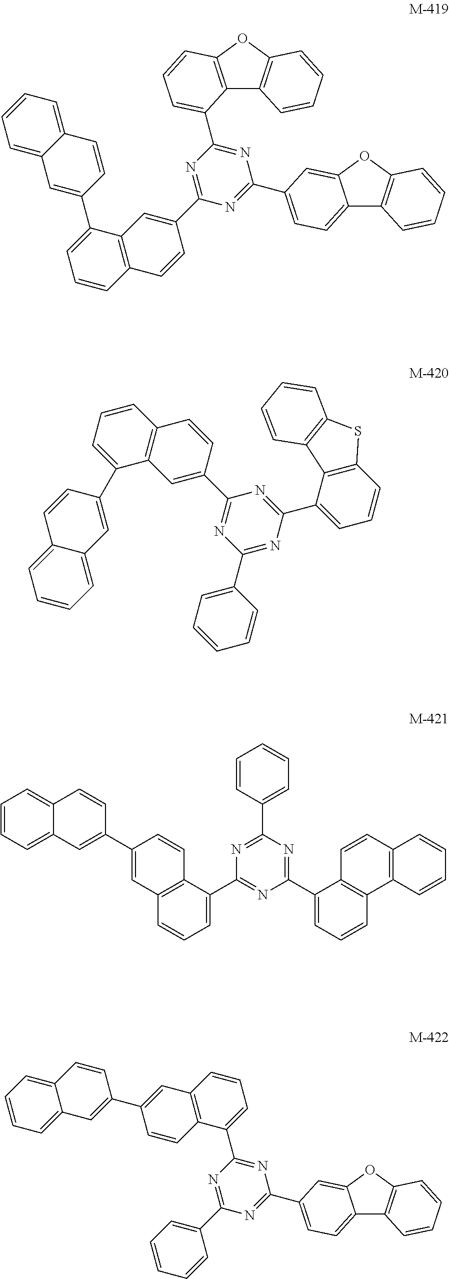 [SMILES: c1ccc2cc(-c3cccc4ccc(-c5nc(-c6ccc7c(c6)oc6ccccc67)nc(-c6cccc7oc8ccccc8c67)n5)cc34)ccc2c1 ; c1ccc(-c2nc(-c3ccc4cccc(-c5ccc6ccccc6c5)c4c3)nc(-c3cccc4sc5ccccc5c34)n2)cc1 ; c1ccc(-c2nc(-c3cccc4cc(-c5ccc6ccccc6c5)ccc34)nc(-c3cccc4c3ccc3ccccc34)n2)cc1 ; c1ccc(-c2nc(-c3ccc4c(c3)oc3ccccc34)nc(-c3cccc4cc(-c5ccc6ccccc6c5)ccc34)n2)cc1]

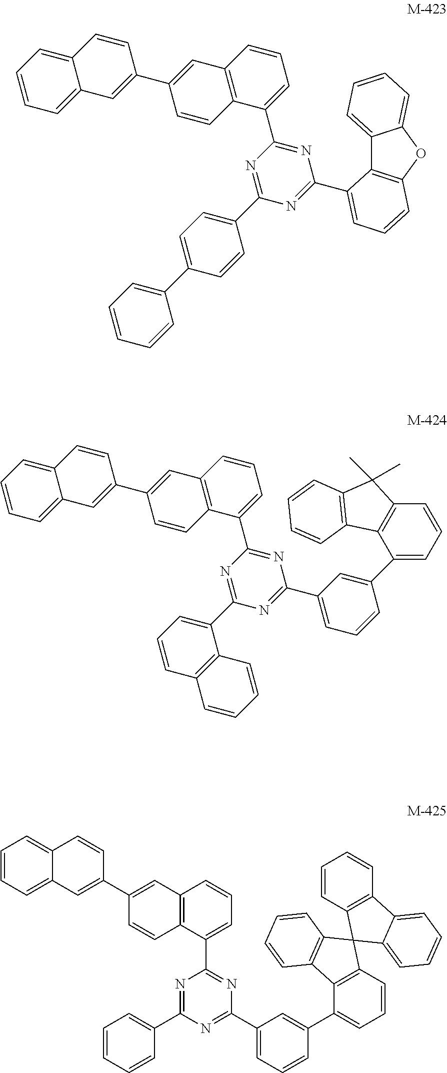 [SMILES: c1ccc(-c2ccc(-c3nc(-c4cccc5cc(-c6ccc7ccccc7c6)ccc45)nc(-c4cccc5oc6ccccc6c45)n3)cc2)cc1 ; CC1(C)c2ccccc2-c2c(-c3cccc(-c4nc(-c5cccc6ccccc56)nc(-c5cccc6cc(-c7ccc8ccccc8c7)ccc56)n4)c3)cccc21 ; c1ccc(-c2nc(-c3cccc(-c4cccc5c4-c4ccccc4C54c5ccccc5-c5ccccc54)c3)nc(-c3cccc4cc(-c5ccc6ccccc6c5)ccc34)n2)cc1]

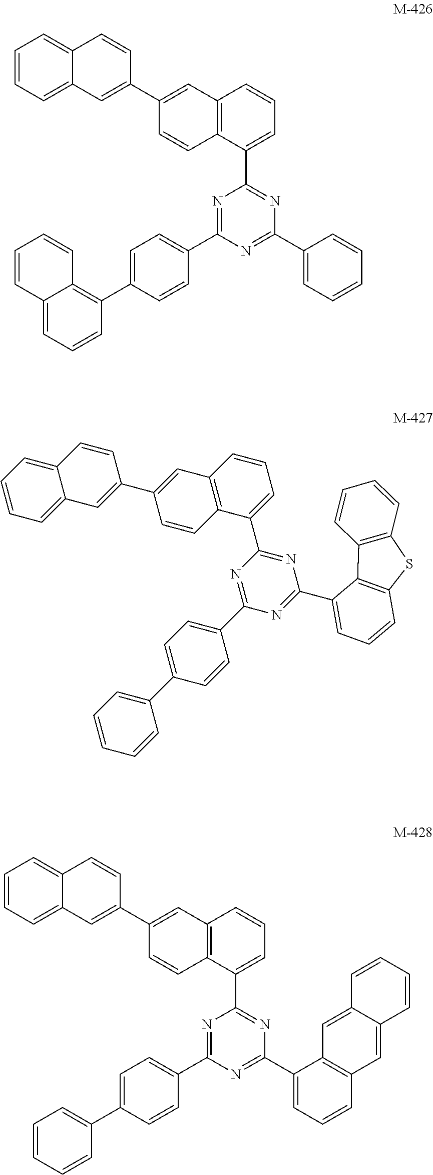 [SMILES: c1ccc(-c2nc(-c3ccc(-c4cccc5ccccc45)cc3)nc(-c3cccc4cc(-c5ccc6ccccc6c5)ccc34)n2)cc1 ; c1ccc(-c2ccc(-c3nc(-c4cccc5cc(-c6ccc7ccccc7c6)ccc45)nc(-c4cccc5sc6ccccc6c45)n3)cc2)cc1 ; c1ccc(-c2ccc(-c3nc(-c4cccc5cc(-c6ccc7ccccc7c6)ccc45)nc(-c4cccc5cc6ccccc6cc45)n3)cc2)cc1]

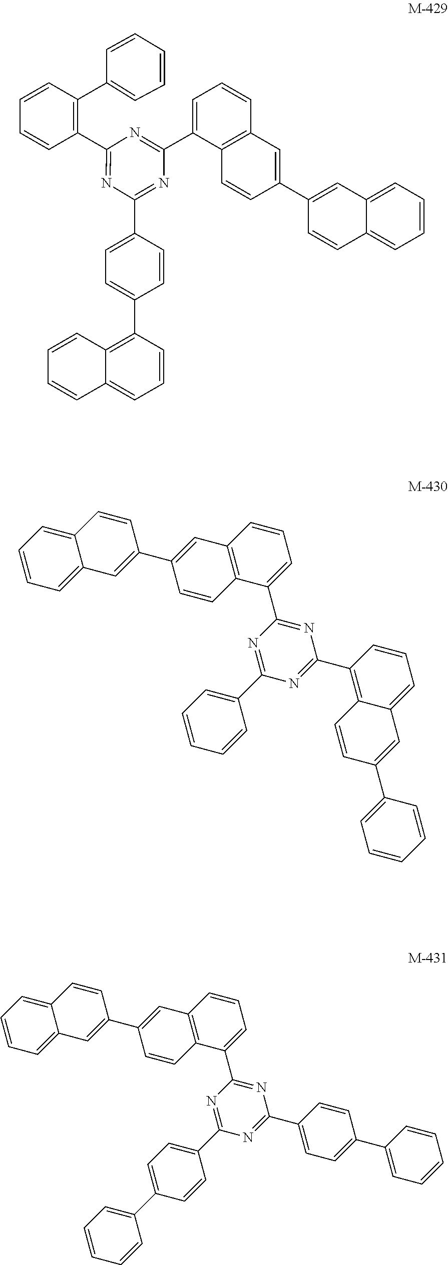 [SMILES: c1ccc(-c2ccccc2-c2nc(-c3ccc(-c4cccc5ccccc45)cc3)nc(-c3cccc4cc(-c5ccc6ccccc6c5)ccc34)n2)cc1 ; c1ccc(-c2ccc3c(-c4nc(-c5ccccc5)nc(-c5cccc6cc(-c7ccc8ccccc8c7)ccc56)n4)cccc3c2)cc1 ; c1ccc(-c2ccc(-c3nc(-c4ccc(-c5ccccc5)cc4)nc(-c4cccc5cc(-c6ccc7ccccc7c6)ccc45)n3)cc2)cc1]

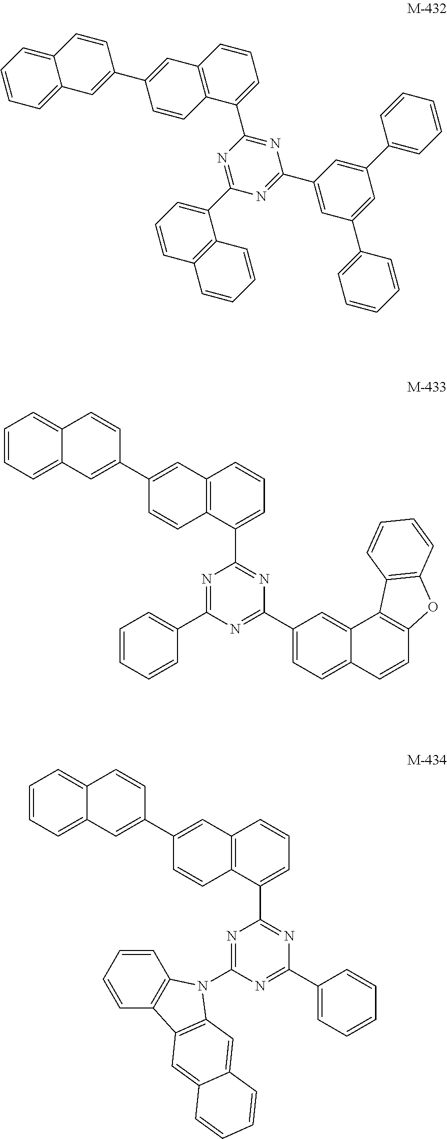 [SMILES: c1ccc(-c2cc(-c3ccccc3)cc(-c3nc(-c4cccc5ccccc45)nc(-c4cccc5cc(-c6ccc7ccccc7c6)ccc45)n3)c2)cc1 ; c1ccc(-c2nc(-c3ccc4ccc5oc6ccccc6c5c4c3)nc(-c3cccc4cc(-c5ccc6ccccc6c5)ccc34)n2)cc1 ; c1ccc(-c2nc(-c3cccc4cc(-c5ccc6ccccc6c5)ccc34)nc(-n3c4ccccc4c4cc5ccccc5cc43)n2)cc1]

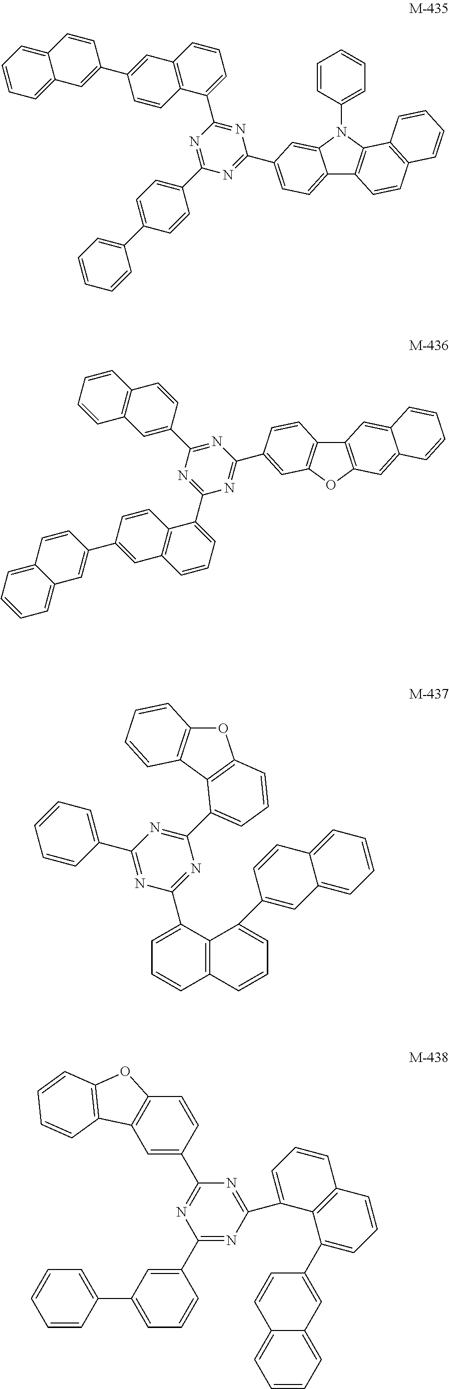 [SMILES: c1ccc(-c2ccc(-c3nc(-c4ccc5c6ccc7ccccc7c6n(-c6ccccc6)c5c4)nc(-c4cccc5cc(-c6ccc7ccccc7c6)ccc45)n3)cc2)cc1 ; c1ccc2cc(-c3ccc4c(-c5nc(-c6ccc7ccccc7c6)nc(-c6ccc7c(c6)oc6cc8ccccc8cc67)n5)cccc4c3)ccc2c1 ; c1ccc(-c2nc(-c3cccc4cccc(-c5ccc6ccccc6c5)c34)nc(-c3cccc4oc5ccccc5c34)n2)cc1 ; c1ccc(-c2cccc(-c3nc(-c4ccc5oc6ccccc6c5c4)nc(-c4cccc5cccc(-c6ccc7ccccc7c6)c45)n3)c2)cc1]

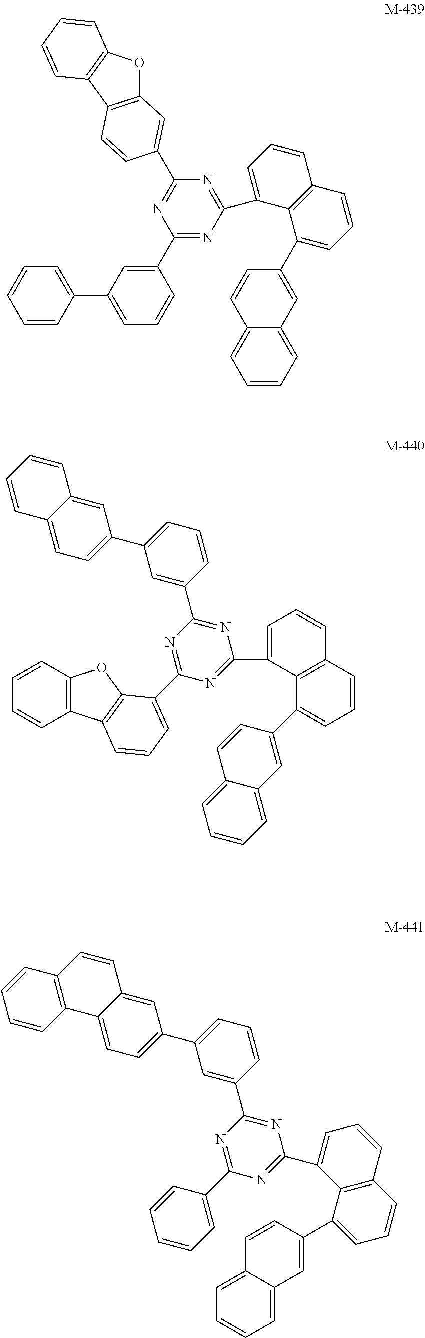 [SMILES: c1ccc(-c2cccc(-c3nc(-c4ccc5c(c4)oc4ccccc45)nc(-c4cccc5cccc(-c6ccc7ccccc7c6)c45)n3)c2)cc1 ; c1cc(-c2ccc3ccccc3c2)cc(-c2nc(-c3cccc4c3oc3ccccc34)nc(-c3cccc4cccc(-c5ccc6ccccc6c5)c34)n2)c1 ; c1ccc(-c2nc(-c3cccc(-c4ccc5c(ccc6ccccc65)c4)c3)nc(-c3cccc4cccc(-c5ccc6ccccc6c5)c34)n2)cc1]

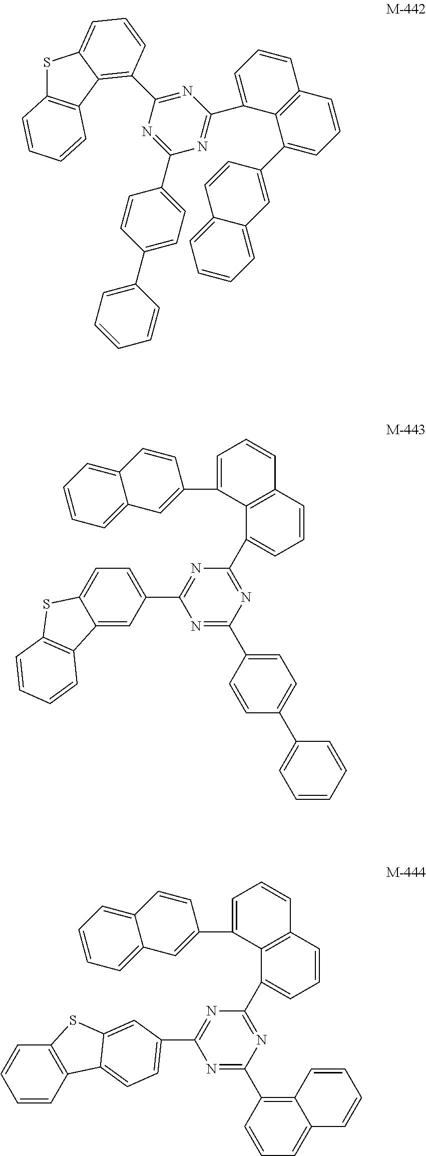 [SMILES: c1ccc(-c2ccc(-c3nc(-c4cccc5cccc(-c6ccc7ccccc7c6)c45)nc(-c4cccc5sc6ccccc6c45)n3)cc2)cc1 ; c1ccc(-c2ccc(-c3nc(-c4ccc5sc6ccccc6c5c4)nc(-c4cccc5cccc(-c6ccc7ccccc7c6)c45)n3)cc2)cc1 ; c1ccc2cc(-c3cccc4cccc(-c5nc(-c6ccc7c(c6)sc6ccccc67)nc(-c6cccc7ccccc67)n5)c34)ccc2c1]

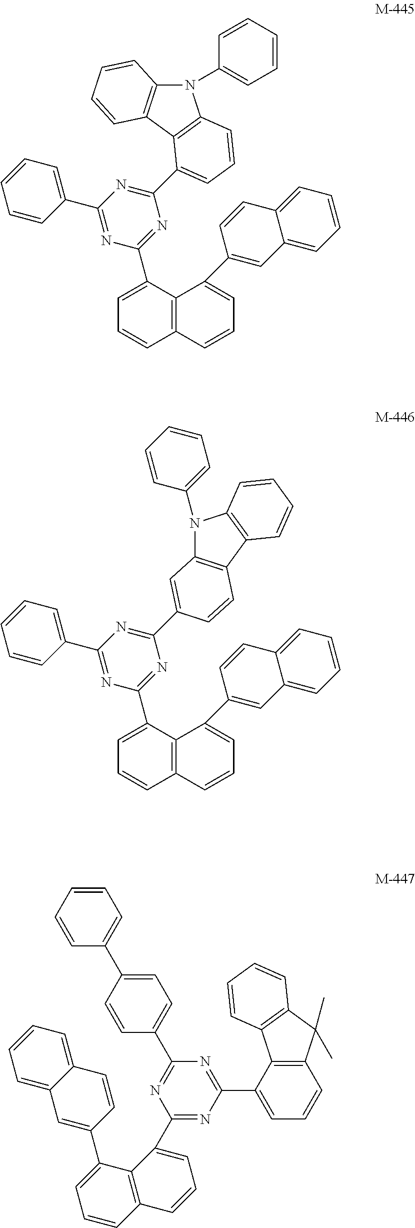 [SMILES: c1ccc(-c2nc(-c3cccc4cccc(-c5ccc6ccccc6c5)c34)nc(-c3cccc4c3c3ccccc3n4-c3ccccc3)n2)cc1 ; c1ccc(-c2nc(-c3ccc4c5ccccc5n(-c5ccccc5)c4c3)nc(-c3cccc4cccc(-c5ccc6ccccc6c5)c34)n2)cc1 ; CC1(C)c2ccccc2-c2c(-c3nc(-c4ccc(-c5ccccc5)cc4)nc(-c4cccc5cccc(-c6ccc7ccccc7c6)c45)n3)cccc21]

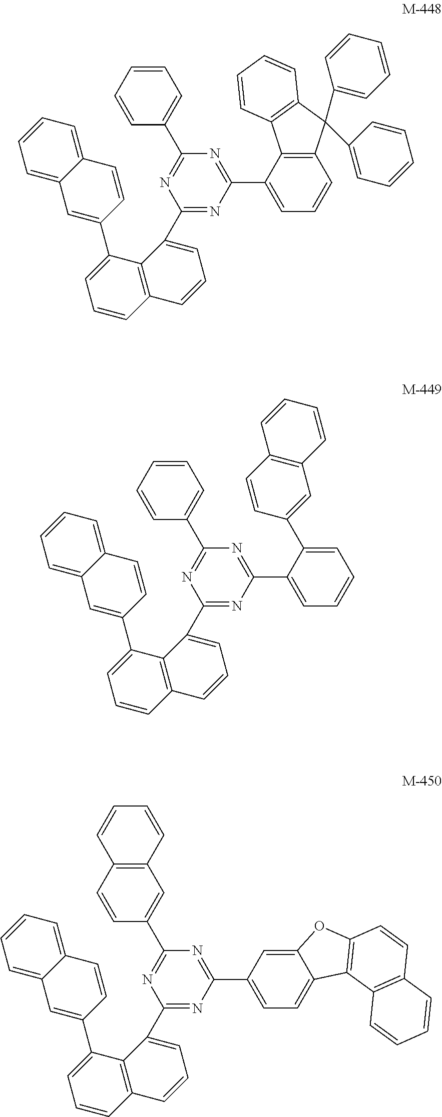 [SMILES: c1ccc(-c2nc(-c3cccc4c3-c3ccccc3C4(c3ccccc3)c3ccccc3)nc(-c3cccc4cccc(-c5ccc6ccccc6c5)c34)n2)cc1 ; c1ccc(-c2nc(-c3ccccc3-c3ccc4ccccc4c3)nc(-c3cccc4cccc(-c5ccc6ccccc6c5)c34)n2)cc1 ; c1ccc2cc(-c3nc(-c4ccc5c(c4)oc4ccc6ccccc6c45)nc(-c4cccc5cccc(-c6ccc7ccccc7c6)c45)n3)ccc2c1]

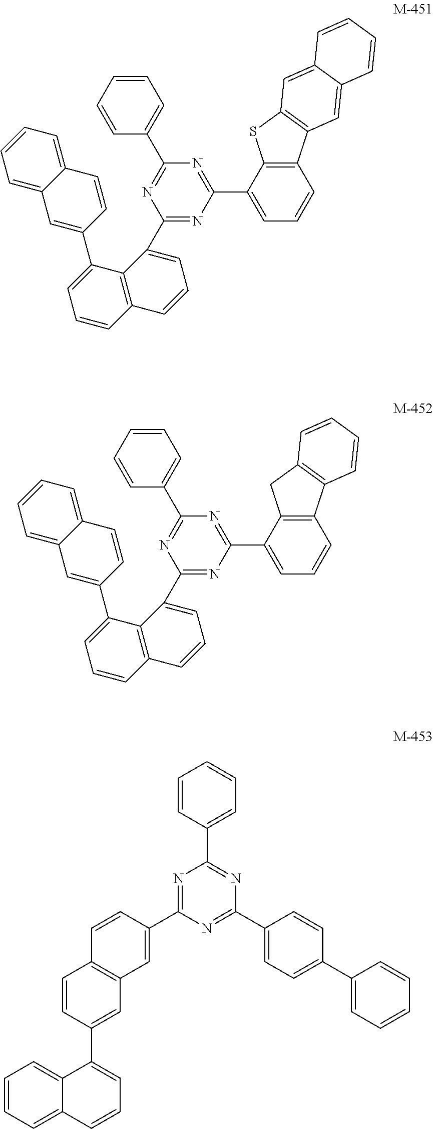 [SMILES: c1ccc(-c2nc(-c3cccc4c3sc3cc5ccccc5cc34)nc(-c3cccc4cccc(-c5ccc6ccccc6c5)c34)n2)cc1 ; c1ccc(-c2nc(-c3cccc4c3Cc3ccccc3-4)nc(-c3cccc4cccc(-c5ccc6ccccc6c5)c34)n2)cc1 ; c1ccc(-c2ccc(-c3nc(-c4ccccc4)nc(-c4ccc5ccc(-c6cccc7ccccc67)cc5c4)n3)cc2)cc1]

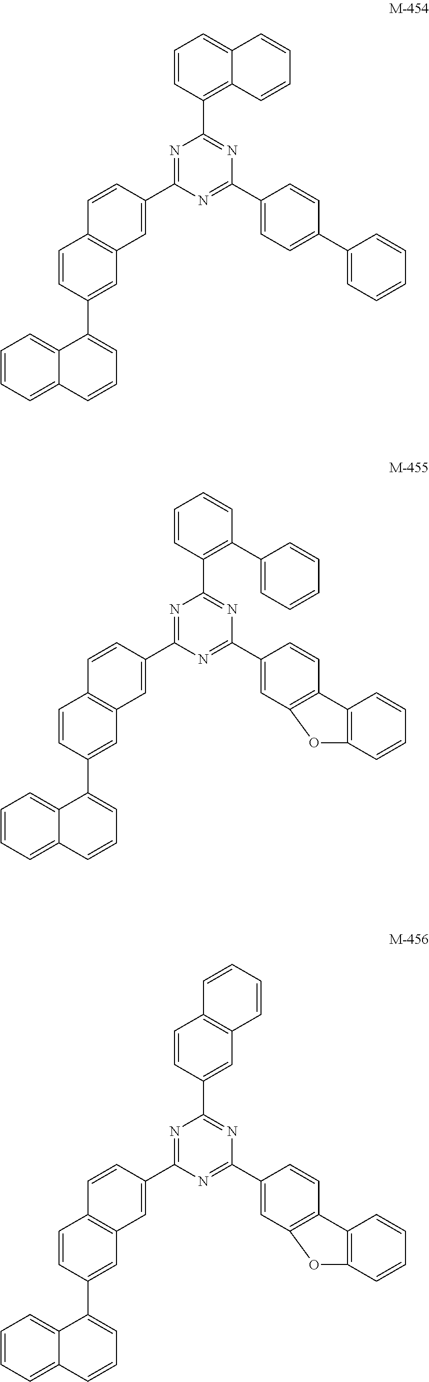 [SMILES: c1ccc(-c2ccc(-c3nc(-c4ccc5ccc(-c6cccc7ccccc67)cc5c4)nc(-c4cccc5ccccc45)n3)cc2)cc1 ; c1ccc(-c2ccccc2-c2nc(-c3ccc4ccc(-c5cccc6ccccc56)cc4c3)nc(-c3ccc4c(c3)oc3ccccc34)n2)cc1 ; c1ccc2cc(-c3nc(-c4ccc5ccc(-c6cccc7ccccc67)cc5c4)nc(-c4ccc5c(c4)oc4ccccc45)n3)ccc2c1]

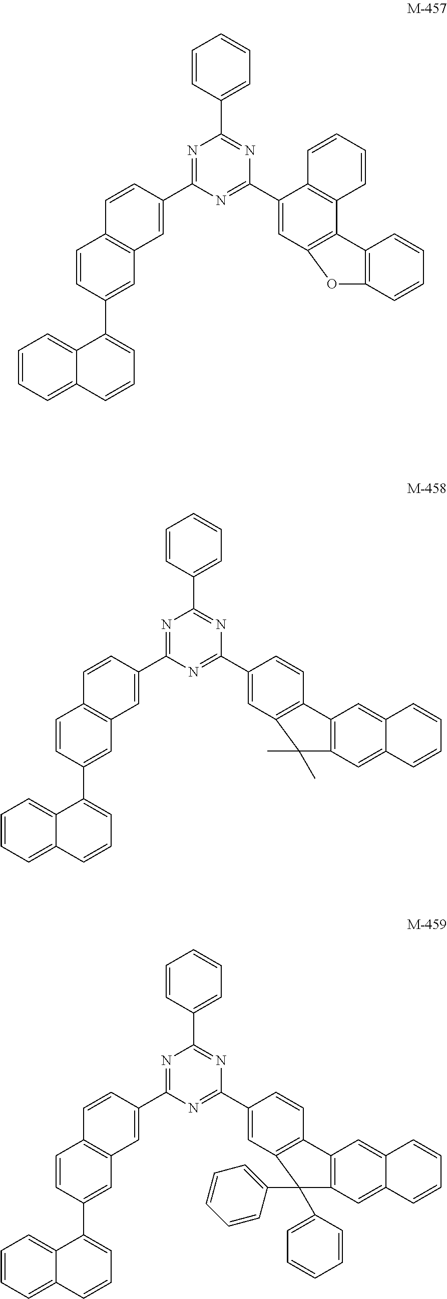 [SMILES: c1ccc(-c2nc(-c3ccc4ccc(-c5cccc6ccccc56)cc4c3)nc(-c3cc4oc5ccccc5c4c4ccccc34)n2)cc1 ; CC1(C)c2cc(-c3nc(-c4ccccc4)nc(-c4ccc5ccc(-c6cccc7ccccc67)cc5c4)n3)ccc2-c2cc3ccccc3cc21 ; c1ccc(-c2nc(-c3ccc4c(c3)C(c3ccccc3)(c3ccccc3)c3cc5ccccc5cc3-4)nc(-c3ccc4ccc(-c5cccc6ccccc56)cc4c3)n2)cc1]

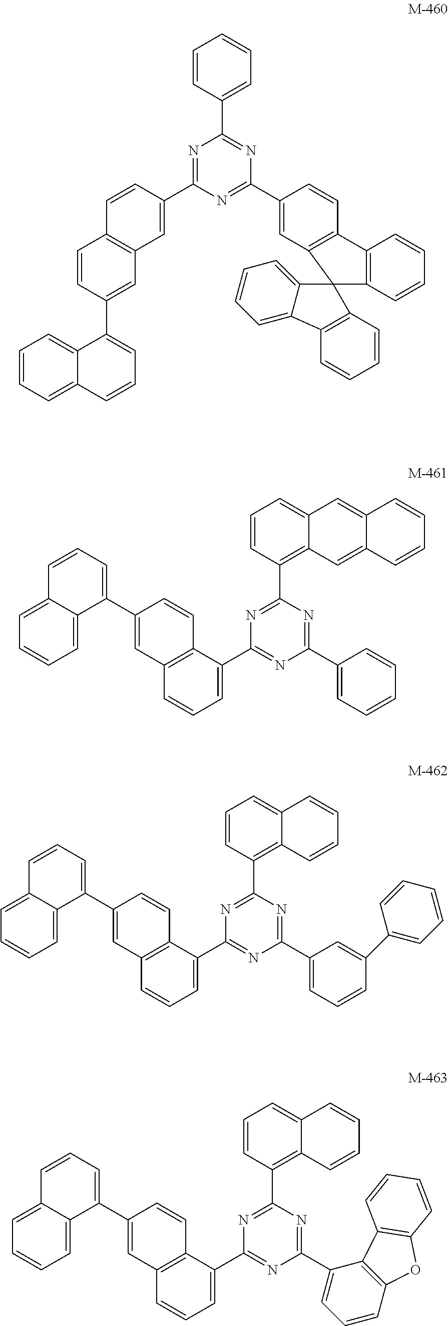 [SMILES: c1ccc(-c2nc(-c3ccc4c(c3)C3(c5ccccc5-c5ccccc53)c3ccccc3-4)nc(-c3ccc4ccc(-c5cccc6ccccc56)cc4c3)n2)cc1 ; c1ccc(-c2nc(-c3cccc4cc(-c5cccc6ccccc56)ccc34)nc(-c3cccc4cc5ccccc5cc34)n2)cc1 ; c1ccc(-c2cccc(-c3nc(-c4cccc5ccccc45)nc(-c4cccc5cc(-c6cccc7ccccc67)ccc45)n3)c2)cc1 ; c1ccc2c(-c3ccc4c(-c5nc(-c6cccc7ccccc67)nc(-c6cccc7oc8ccccc8c67)n5)cccc4c3)cccc2c1]

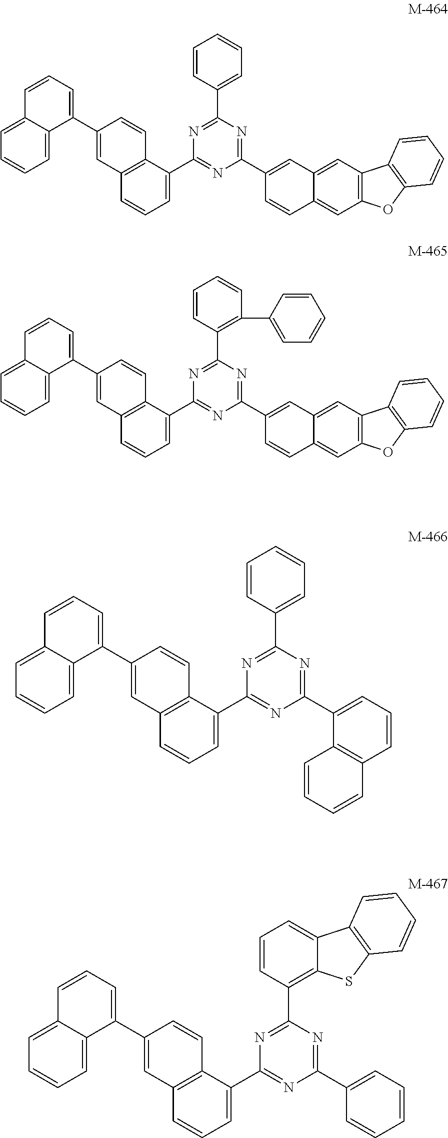 [SMILES: c1ccc(-c2nc(-c3ccc4cc5oc6ccccc6c5cc4c3)nc(-c3cccc4cc(-c5cccc6ccccc56)ccc34)n2)cc1 ; c1ccc(-c2ccccc2-c2nc(-c3ccc4cc5oc6ccccc6c5cc4c3)nc(-c3cccc4cc(-c5cccc6ccccc56)ccc34)n2)cc1 ; c1ccc(-c2nc(-c3cccc4ccccc34)nc(-c3cccc4cc(-c5cccc6ccccc56)ccc34)n2)cc1 ; c1ccc(-c2nc(-c3cccc4cc(-c5cccc6ccccc56)ccc34)nc(-c3cccc4c3sc3ccccc34)n2)cc1]

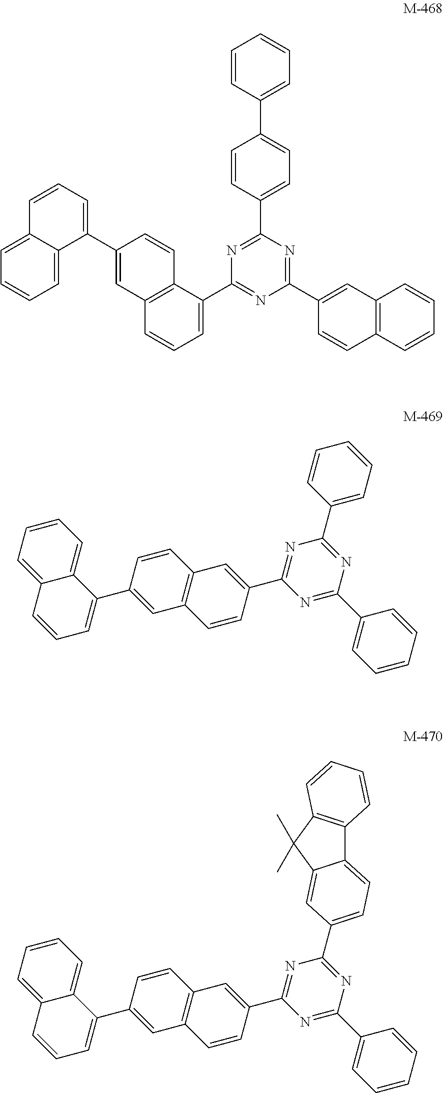 [SMILES: c1ccc(-c2ccc(-c3nc(-c4ccc5ccccc5c4)nc(-c4cccc5cc(-c6cccc7ccccc67)ccc45)n3)cc2)cc1 ; c1ccc(-c2nc(-c3ccccc3)nc(-c3ccc4cc(-c5cccc6ccccc56)ccc4c3)n2)cc1 ; CC1(C)c2ccccc2-c2ccc(-c3nc(-c4ccccc4)nc(-c4ccc5cc(-c6cccc7ccccc67)ccc5c4)n3)cc21]

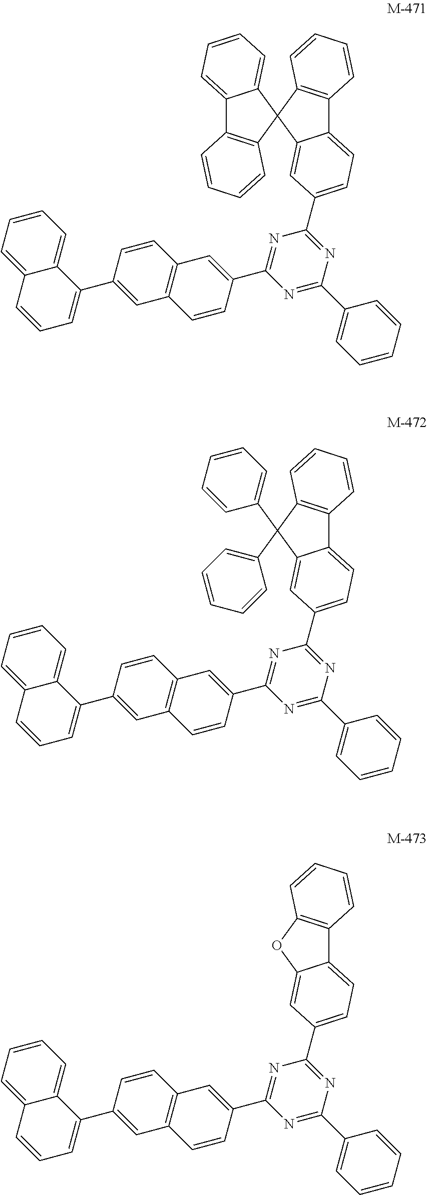 [SMILES: c1ccc(-c2nc(-c3ccc4c(c3)C3(c5ccccc5-c5ccccc53)c3ccccc3-4)nc(-c3ccc4cc(-c5cccc6ccccc56)ccc4c3)n2)cc1 ; c1ccc(-c2nc(-c3ccc4c(c3)C(c3ccccc3)(c3ccccc3)c3ccccc3-4)nc(-c3ccc4cc(-c5cccc6ccccc56)ccc4c3)n2)cc1 ; c1ccc(-c2nc(-c3ccc4cc(-c5cccc6ccccc56)ccc4c3)nc(-c3ccc4c(c3)oc3ccccc34)n2)cc1]

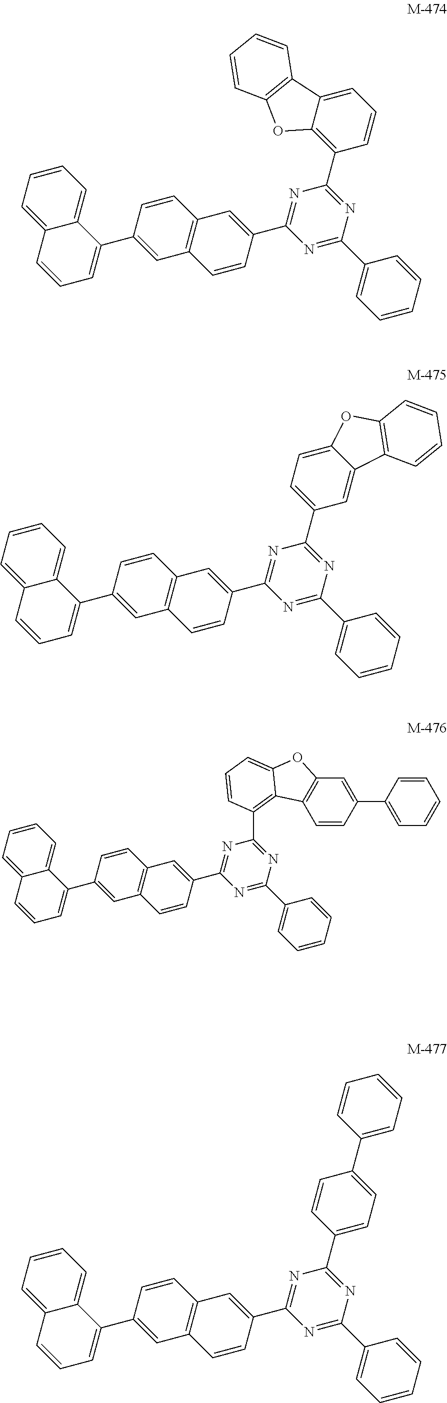 [SMILES: c1ccc(-c2nc(-c3ccc4cc(-c5cccc6ccccc56)ccc4c3)nc(-c3cccc4c3oc3ccccc34)n2)cc1 ; c1ccc(-c2nc(-c3ccc4cc(-c5cccc6ccccc56)ccc4c3)nc(-c3ccc4oc5ccccc5c4c3)n2)cc1 ; c1ccc(-c2ccc3c(c2)oc2cccc(-c4nc(-c5ccccc5)nc(-c5ccc6cc(-c7cccc8ccccc78)ccc6c5)n4)c23)cc1 ; c1ccc(-c2ccc(-c3nc(-c4ccccc4)nc(-c4ccc5cc(-c6cccc7ccccc67)ccc5c4)n3)cc2)cc1]

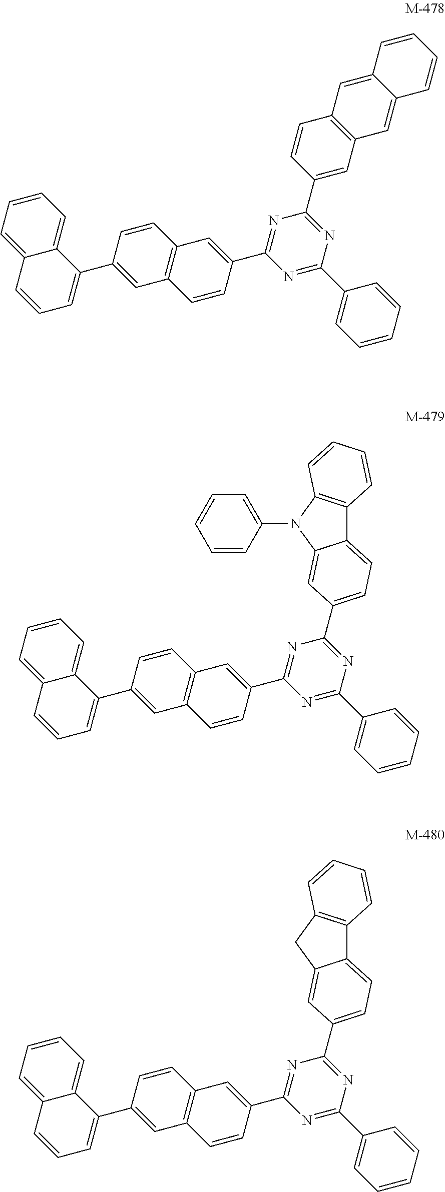 [SMILES: c1ccc(-c2nc(-c3ccc4cc(-c5cccc6ccccc56)ccc4c3)nc(-c3ccc4cc5ccccc5cc4c3)n2)cc1 ; c1ccc(-c2nc(-c3ccc4cc(-c5cccc6ccccc56)ccc4c3)nc(-c3ccc4c5ccccc5n(-c5ccccc5)c4c3)n2)cc1 ; c1ccc(-c2nc(-c3ccc4c(c3)Cc3ccccc3-4)nc(-c3ccc4cc(-c5cccc6ccccc56)ccc4c3)n2)cc1]

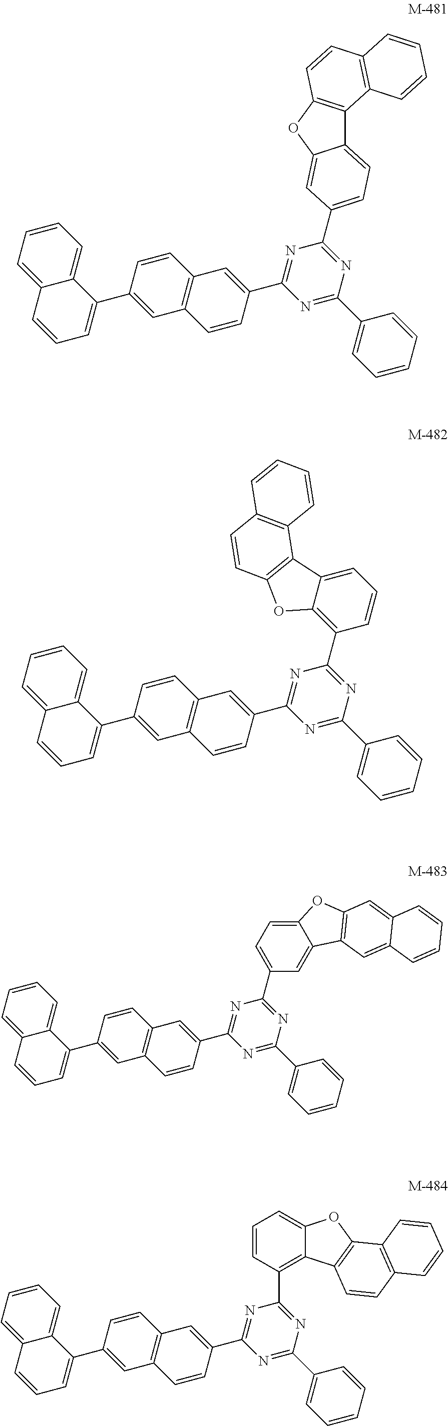 [SMILES: c1ccc(-c2nc(-c3ccc4cc(-c5cccc6ccccc56)ccc4c3)nc(-c3ccc4c(c3)oc3ccc5ccccc5c34)n2)cc1 ; c1ccc(-c2nc(-c3ccc4cc(-c5cccc6ccccc56)ccc4c3)nc(-c3cccc4c3oc3ccc5ccccc5c34)n2)cc1 ; c1ccc(-c2nc(-c3ccc4cc(-c5cccc6ccccc56)ccc4c3)nc(-c3ccc4oc5cc6ccccc6cc5c4c3)n2)cc1 ; c1ccc(-c2nc(-c3ccc4cc(-c5cccc6ccccc56)ccc4c3)nc(-c3cccc4oc5c6ccccc6ccc5c34)n2)cc1]

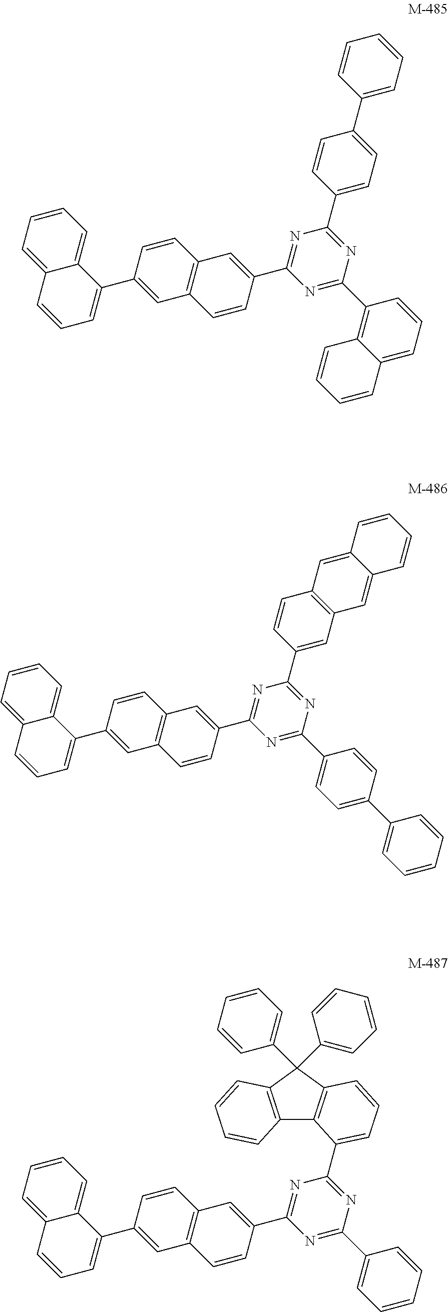 [SMILES: c1ccc(-c2ccc(-c3nc(-c4ccc5cc(-c6cccc7ccccc67)ccc5c4)nc(-c4cccc5ccccc45)n3)cc2)cc1 ; c1ccc(-c2ccc(-c3nc(-c4ccc5cc(-c6cccc7ccccc67)ccc5c4)nc(-c4ccc5cc6ccccc6cc5c4)n3)cc2)cc1 ; c1ccc(-c2nc(-c3ccc4cc(-c5cccc6ccccc56)ccc4c3)nc(-c3cccc4c3-c3ccccc3C4(c3ccccc3)c3ccccc3)n2)cc1]

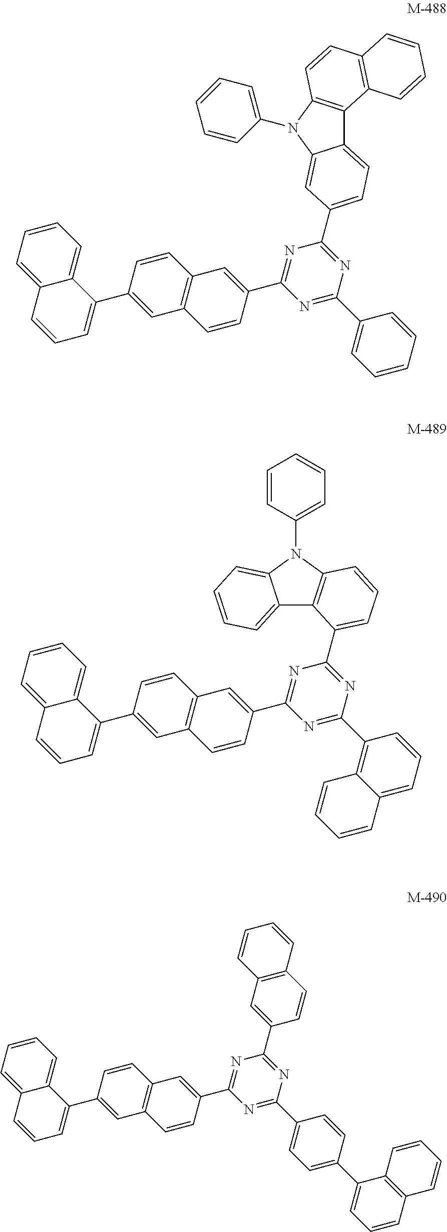 [SMILES: c1ccc(-c2nc(-c3ccc4cc(-c5cccc6ccccc56)ccc4c3)nc(-c3ccc4c5c6ccccc6ccc5n(-c5ccccc5)c4c3)n2)cc1 ; c1ccc(-n2c3ccccc3c3c(-c4nc(-c5ccc6cc(-c7cccc8ccccc78)ccc6c5)nc(-c5cccc6ccccc56)n4)cccc32)cc1 ; c1ccc2cc(-c3nc(-c4ccc(-c5cccc6ccccc56)cc4)nc(-c4ccc5cc(-c6cccc7ccccc67)ccc5c4)n3)ccc2c1]

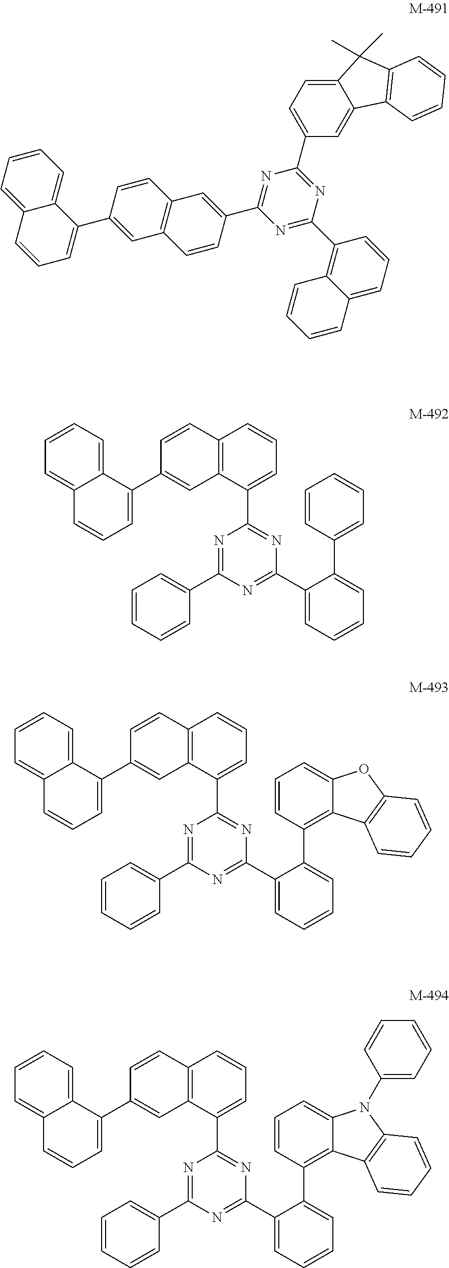 [SMILES: CC1(C)c2ccccc2-c2cc(-c3nc(-c4ccc5cc(-c6cccc7ccccc67)ccc5c4)nc(-c4cccc5ccccc45)n3)ccc21 ; c1ccc(-c2nc(-c3ccccc3-c3ccccc3)nc(-c3cccc4ccc(-c5cccc6ccccc56)cc34)n2)cc1 ; c1ccc(-c2nc(-c3ccccc3-c3cccc4oc5ccccc5c34)nc(-c3cccc4ccc(-c5cccc6ccccc56)cc34)n2)cc1 ; c1ccc(-c2nc(-c3ccccc3-c3cccc4c3c3ccccc3n4-c3ccccc3)nc(-c3cccc4ccc(-c5cccc6ccccc56)cc34)n2)cc1]

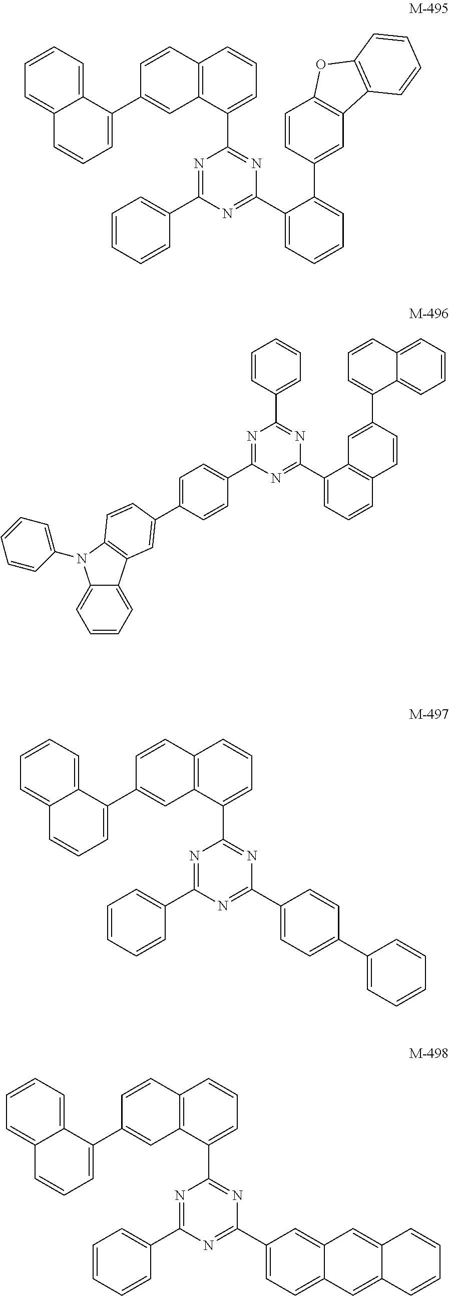 [SMILES: c1ccc(-c2nc(-c3ccccc3-c3ccc4oc5ccccc5c4c3)nc(-c3cccc4ccc(-c5cccc6ccccc56)cc34)n2)cc1 ; c1ccc(-c2nc(-c3ccc(-c4ccc5c(c4)c4ccccc4n5-c4ccccc4)cc3)nc(-c3cccc4ccc(-c5cccc6ccccc56)cc34)n2)cc1 ; c1ccc(-c2ccc(-c3nc(-c4ccccc4)nc(-c4cccc5ccc(-c6cccc7ccccc67)cc45)n3)cc2)cc1 ; c1ccc(-c2nc(-c3ccc4cc5ccccc5cc4c3)nc(-c3cccc4ccc(-c5cccc6ccccc56)cc34)n2)cc1]

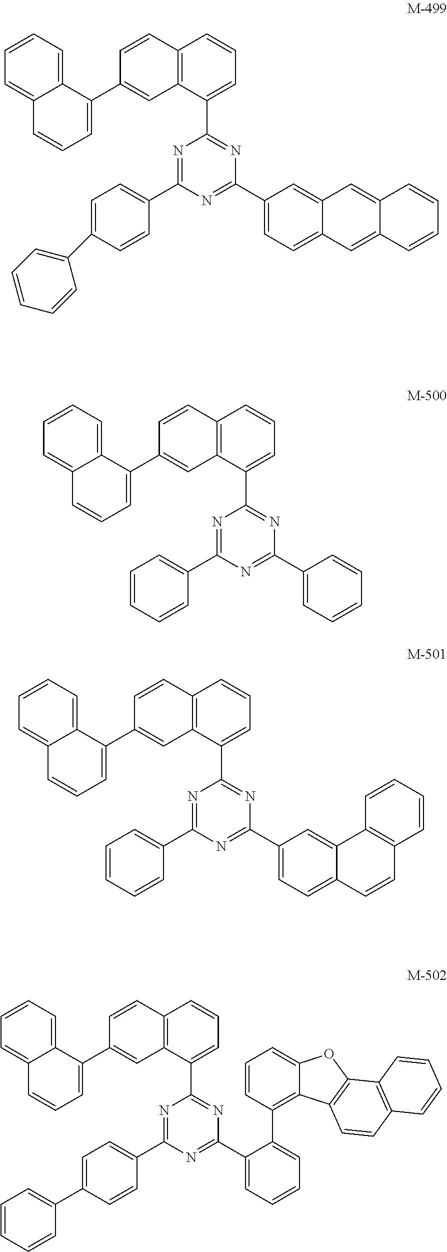 [SMILES: c1ccc(-c2ccc(-c3nc(-c4ccc5cc6ccccc6cc5c4)nc(-c4cccc5ccc(-c6cccc7ccccc67)cc45)n3)cc2)cc1 ; c1ccc(-c2nc(-c3ccccc3)nc(-c3cccc4ccc(-c5cccc6ccccc56)cc34)n2)cc1 ; c1ccc(-c2nc(-c3ccc4ccc5ccccc5c4c3)nc(-c3cccc4ccc(-c5cccc6ccccc56)cc34)n2)cc1 ; c1ccc(-c2ccc(-c3nc(-c4ccccc4-c4cccc5oc6c7ccccc7ccc6c45)nc(-c4cccc5ccc(-c6cccc7ccccc67)cc45)n3)cc2)cc1]

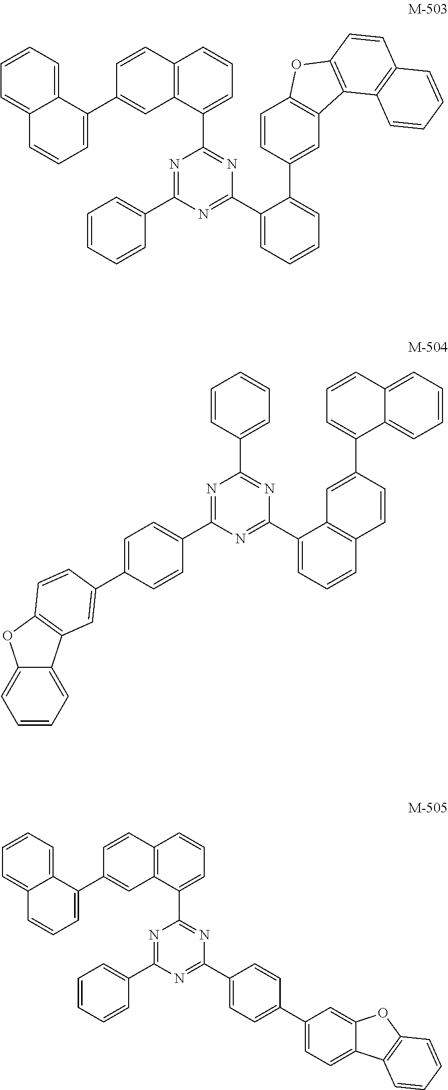 [SMILES: c1ccc(-c2nc(-c3ccccc3-c3ccc4oc5ccc6ccccc6c5c4c3)nc(-c3cccc4ccc(-c5cccc6ccccc56)cc34)n2)cc1 ; c1ccc(-c2nc(-c3ccc(-c4ccc5oc6ccccc6c5c4)cc3)nc(-c3cccc4ccc(-c5cccc6ccccc56)cc34)n2)cc1 ; c1ccc(-c2nc(-c3ccc(-c4ccc5c(c4)oc4ccccc45)cc3)nc(-c3cccc4ccc(-c5cccc6ccccc56)cc34)n2)cc1]

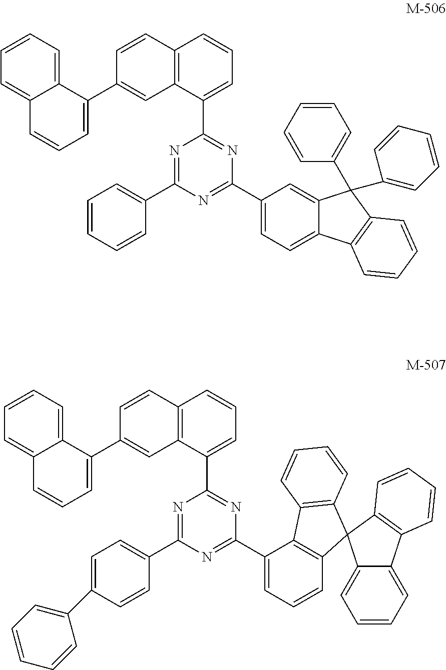 [SMILES: c1ccc(-c2nc(-c3ccc4c(c3)C(c3ccccc3)(c3ccccc3)c3ccccc3-4)nc(-c3cccc4ccc(-c5cccc6ccccc56)cc34)n2)cc1 ; c1ccc(-c2ccc(-c3nc(-c4cccc5c4-c4ccccc4C54c5ccccc5-c5ccccc54)nc(-c4cccc5ccc(-c6cccc7ccccc67)cc45)n3)cc2)cc1]

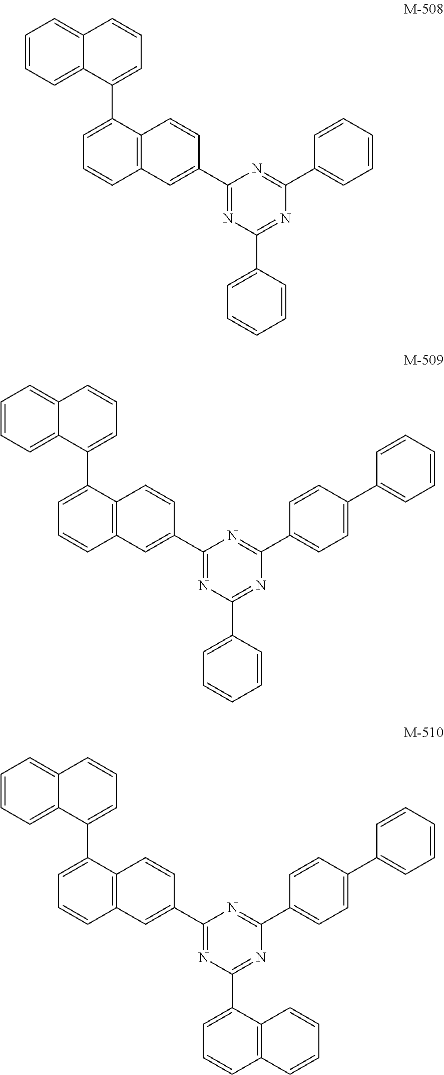 [SMILES: c1ccc(-c2nc(-c3ccccc3)nc(-c3ccc4c(-c5cccc6ccccc56)cccc4c3)n2)cc1 ; c1ccc(-c2ccc(-c3nc(-c4ccccc4)nc(-c4ccc5c(-c6cccc7ccccc67)cccc5c4)n3)cc2)cc1 ; c1ccc(-c2ccc(-c3nc(-c4ccc5c(-c6cccc7ccccc67)cccc5c4)nc(-c4cccc5ccccc45)n3)cc2)cc1]

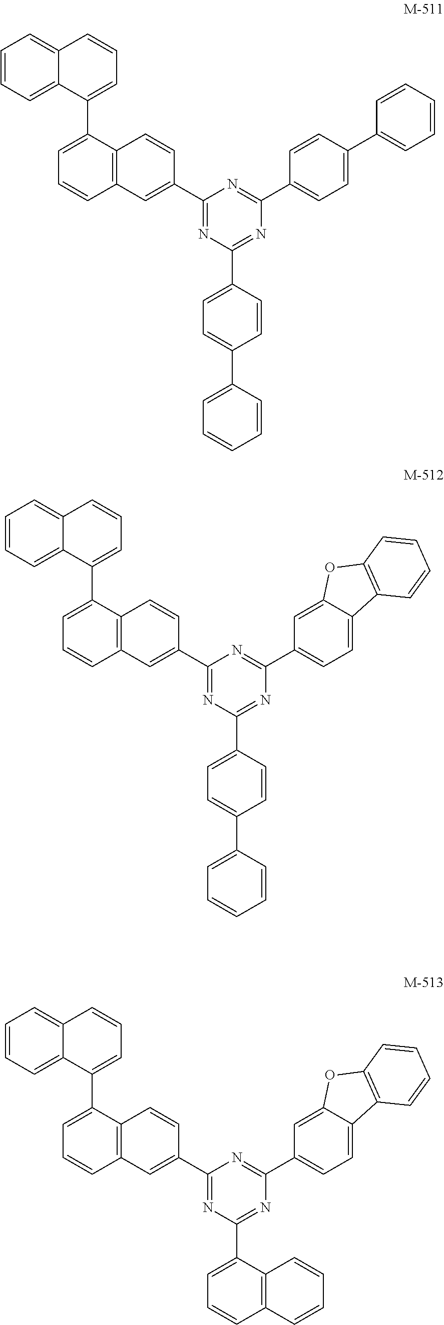 [SMILES: c1ccc(-c2ccc(-c3nc(-c4ccc(-c5ccccc5)cc4)nc(-c4ccc5c(-c6cccc7ccccc67)cccc5c4)n3)cc2)cc1 ; c1ccc(-c2ccc(-c3nc(-c4ccc5c(-c6cccc7ccccc67)cccc5c4)nc(-c4ccc5c(c4)oc4ccccc45)n3)cc2)cc1 ; c1ccc2c(-c3nc(-c4ccc5c(-c6cccc7ccccc67)cccc5c4)nc(-c4ccc5c(c4)oc4ccccc45)n3)cccc2c1]

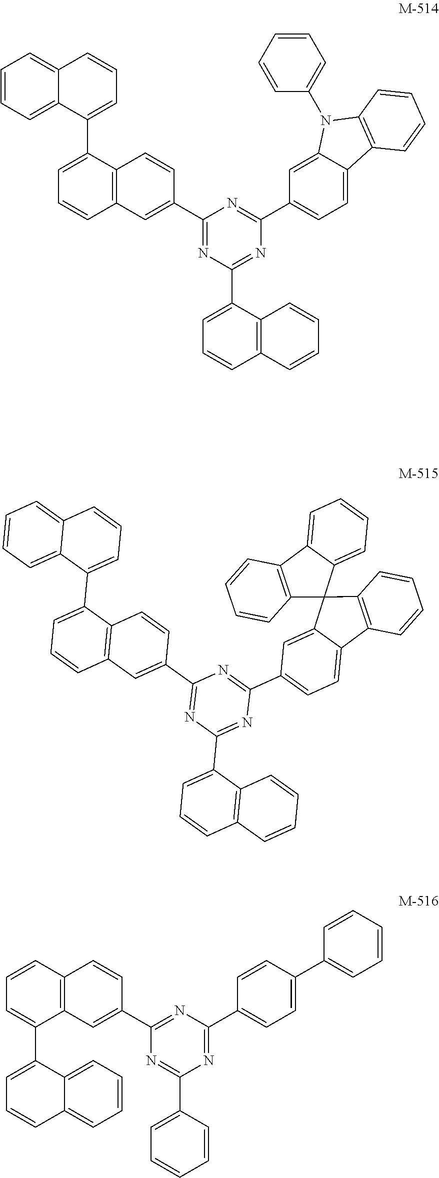 [SMILES: c1ccc(-n2c3ccccc3c3ccc(-c4nc(-c5ccc6c(-c7cccc8ccccc78)cccc6c5)nc(-c5cccc6ccccc56)n4)cc32)cc1 ; c1ccc2c(c1)-c1ccccc1C21c2ccccc2-c2ccc(-c3nc(-c4ccc5c(-c6cccc7ccccc67)cccc5c4)nc(-c4cccc5ccccc45)n3)cc21 ; c1ccc(-c2ccc(-c3nc(-c4ccccc4)nc(-c4ccc5cccc(-c6cccc7ccccc67)c5c4)n3)cc2)cc1]

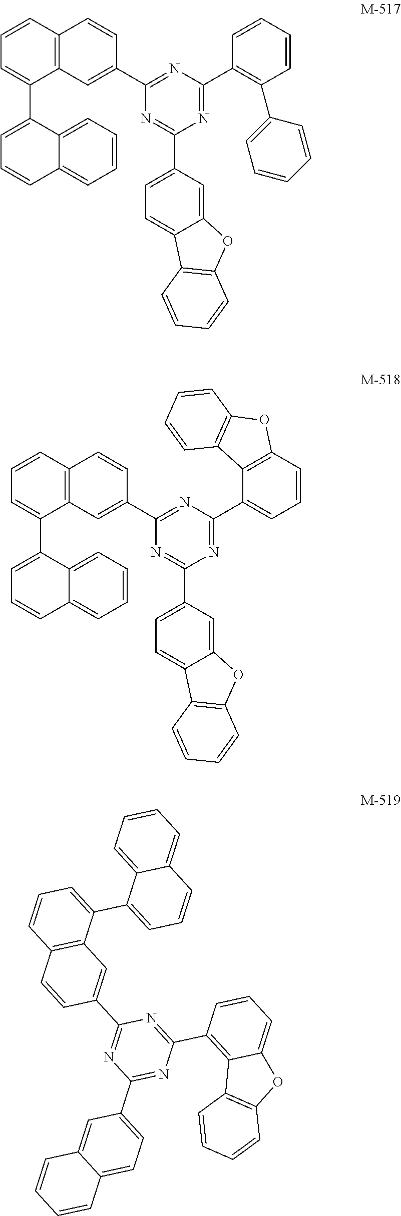 [SMILES: c1ccc(-c2ccccc2-c2nc(-c3ccc4c(c3)oc3ccccc34)nc(-c3ccc4cccc(-c5cccc6ccccc56)c4c3)n2)cc1 ; c1ccc2c(-c3cccc4ccc(-c5nc(-c6ccc7c(c6)oc6ccccc67)nc(-c6cccc7oc8ccccc8c67)n5)cc34)cccc2c1 ; c1ccc2cc(-c3nc(-c4ccc5cccc(-c6cccc7ccccc67)c5c4)nc(-c4cccc5oc6ccccc6c45)n3)ccc2c1]

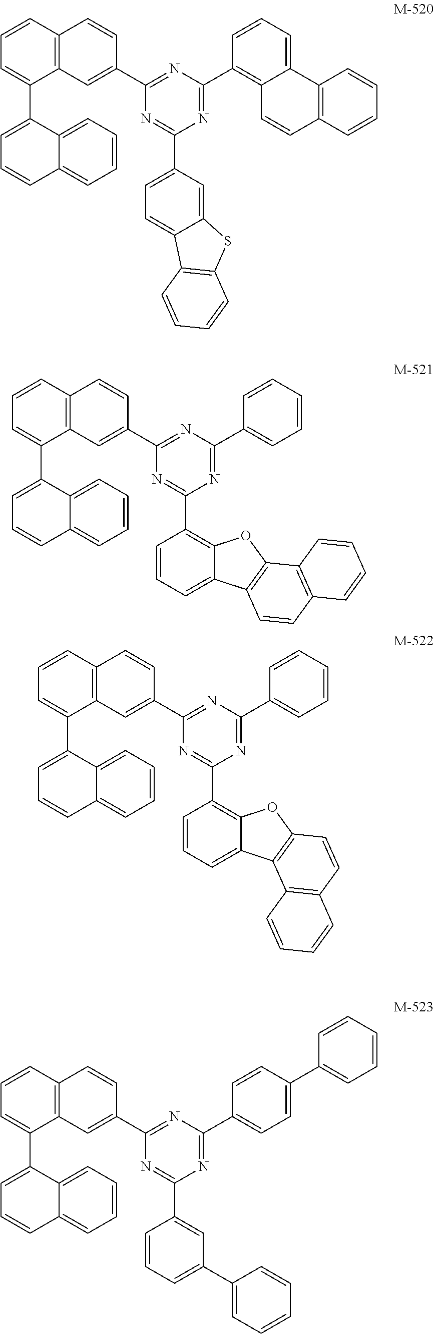

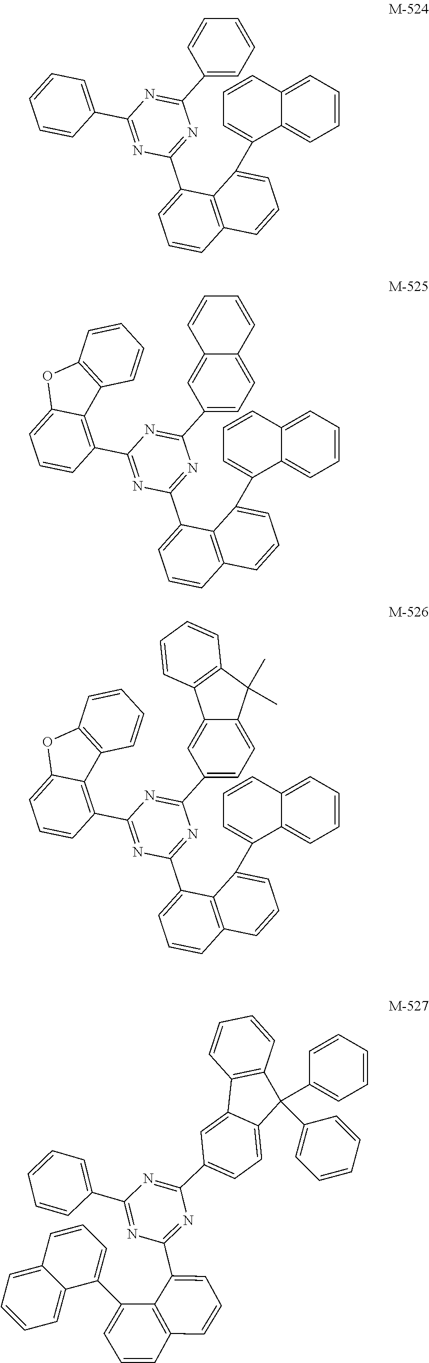

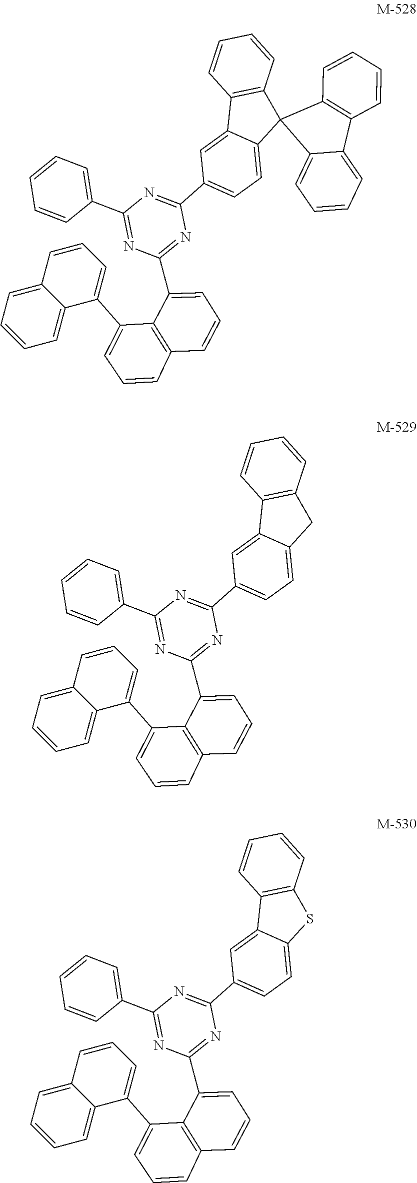 [SMILES: c1ccc(-c2nc(-c3ccc4c(c3)-c3ccccc3C43c4ccccc4-c4ccccc43)nc(-c3cccc4cccc(-c5cccc6ccccc56)c34)n2)cc1 ; c1ccc(-c2nc(-c3ccc4c(c3)-c3ccccc3C4)nc(-c3cccc4cccc(-c5cccc6ccccc56)c34)n2)cc1 ; c1ccc(-c2nc(-c3ccc4sc5ccccc5c4c3)nc(-c3cccc4cccc(-c5cccc6ccccc56)c34)n2)cc1]

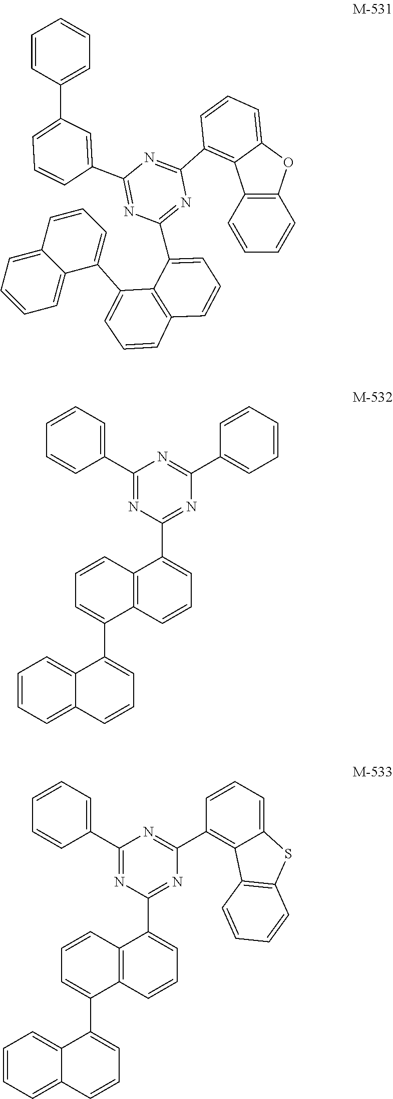 [SMILES: c1ccc(-c2cccc(-c3nc(-c4cccc5cccc(-c6cccc7ccccc67)c45)nc(-c4cccc5oc6ccccc6c45)n3)c2)cc1 ; c1ccc(-c2nc(-c3ccccc3)nc(-c3cccc4c(-c5cccc6ccccc56)cccc34)n2)cc1 ; c1ccc(-c2nc(-c3cccc4c(-c5cccc6ccccc56)cccc34)nc(-c3cccc4sc5ccccc5c34)n2)cc1]

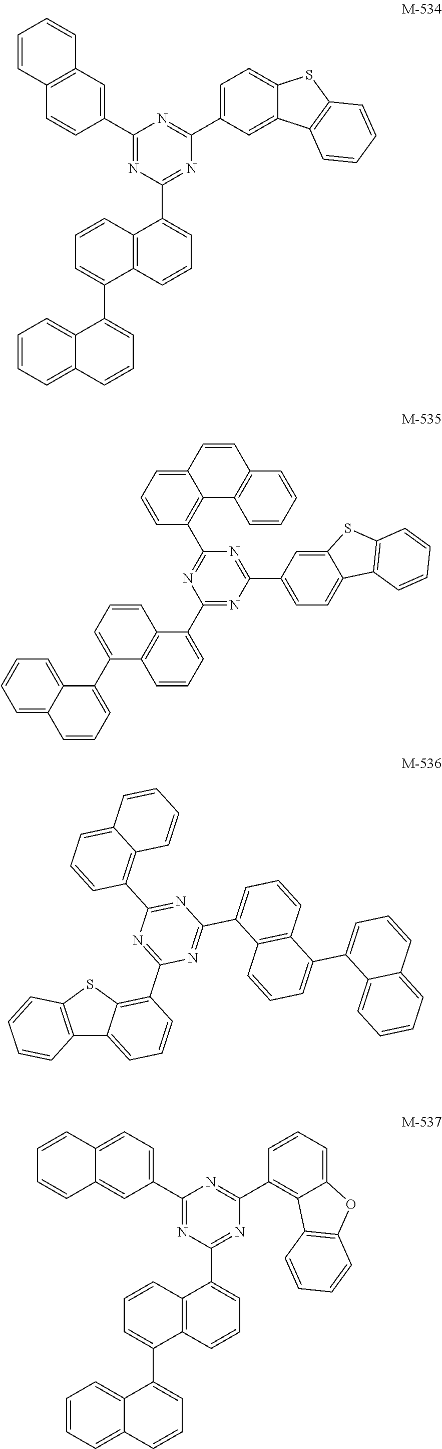 [SMILES: c1ccc2cc(-c3nc(-c4ccc5sc6ccccc6c5c4)nc(-c4cccc5c(-c6cccc7ccccc67)cccc45)n3)ccc2c1 ; c1ccc2c(-c3cccc4c(-c5nc(-c6ccc7c(c6)sc6ccccc67)nc(-c6cccc7ccc8ccccc8c67)n5)cccc34)cccc2c1 ; c1ccc2c(-c3nc(-c4cccc5c(-c6cccc7ccccc67)cccc45)nc(-c4cccc5c4sc4ccccc45)n3)cccc2c1 ; c1ccc2cc(-c3nc(-c4cccc5c(-c6cccc7ccccc67)cccc45)nc(-c4cccc5oc6ccccc6c45)n3)ccc2c1]

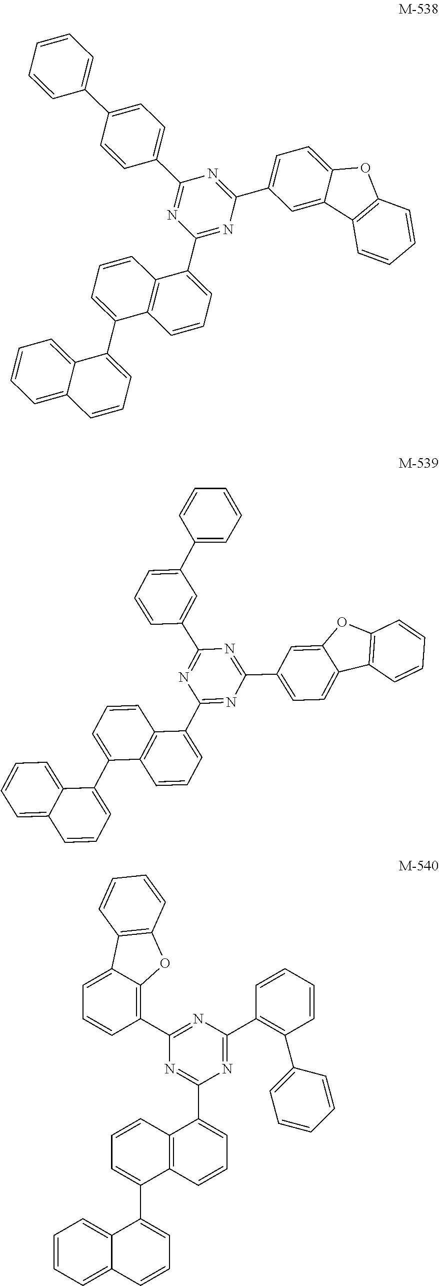

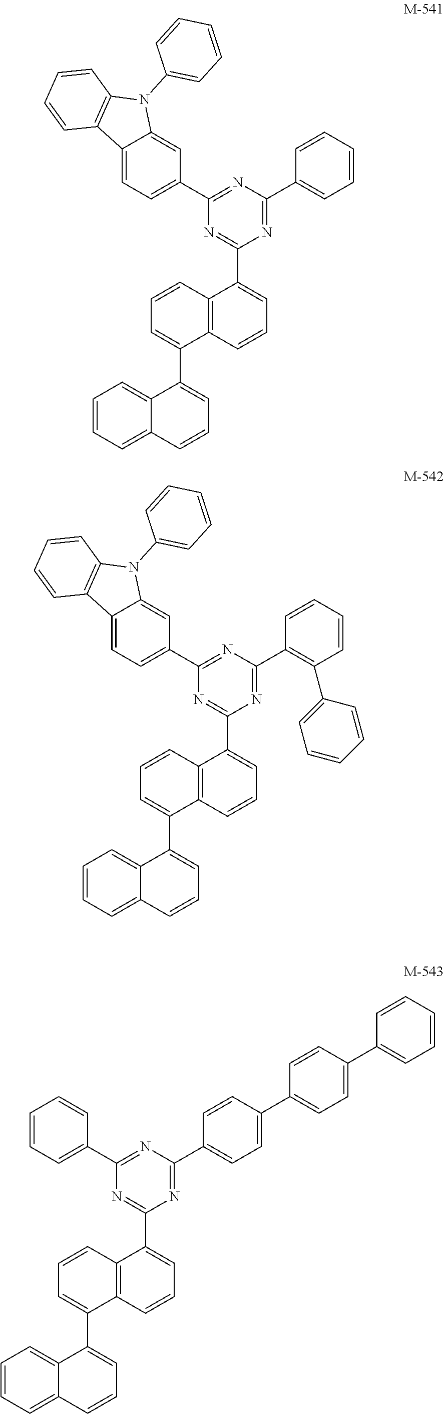

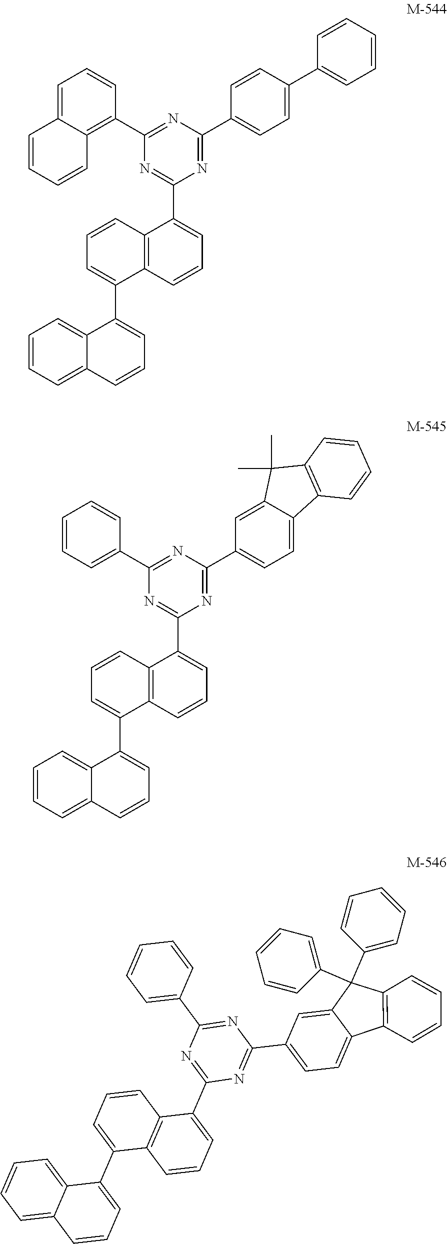 [SMILES: c1ccc(-c2ccc(-c3nc(-c4cccc5ccccc45)nc(-c4cccc5c(-c6cccc7ccccc67)cccc45)n3)cc2)cc1 ; CC1(C)c2ccccc2-c2ccc(-c3nc(-c4ccccc4)nc(-c4cccc5c(-c6cccc7ccccc67)cccc45)n3)cc21 ; c1ccc(-c2nc(-c3ccc4c(c3)C(c3ccccc3)(c3ccccc3)c3ccccc3-4)nc(-c3cccc4c(-c5cccc6ccccc56)cccc34)n2)cc1]

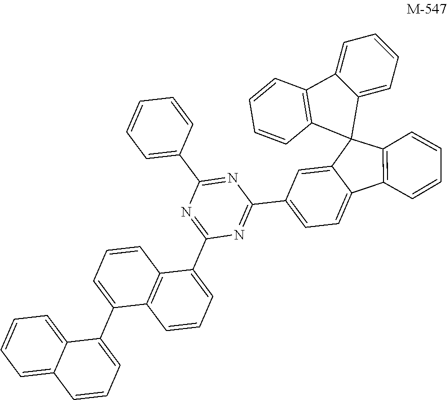 [SMILES: c1ccc(-c2nc(-c3ccc4c(c3)C3(c5ccccc5-c5ccccc53)c3ccccc3-4)nc(-c3cccc4c(-c5cccc6ccccc56)cccc34)n2)cc1]

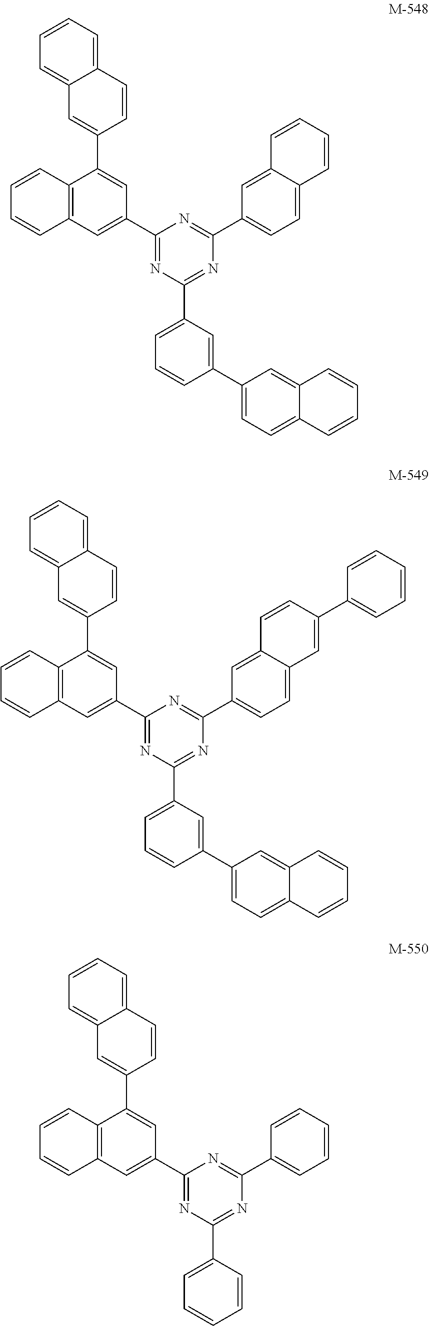 [SMILES: c1cc(-c2ccc3ccccc3c2)cc(-c2nc(-c3ccc4ccccc4c3)nc(-c3cc(-c4ccc5ccccc5c4)c4ccccc4c3)n2)c1 ; c1ccc(-c2ccc3cc(-c4nc(-c5cccc(-c6ccc7ccccc7c6)c5)nc(-c5cc(-c6ccc7ccccc7c6)c6ccccc6c5)n4)ccc3c2)cc1 ; c1ccc(-c2nc(-c3ccccc3)nc(-c3cc(-c4ccc5ccccc5c4)c4ccccc4c3)n2)cc1]

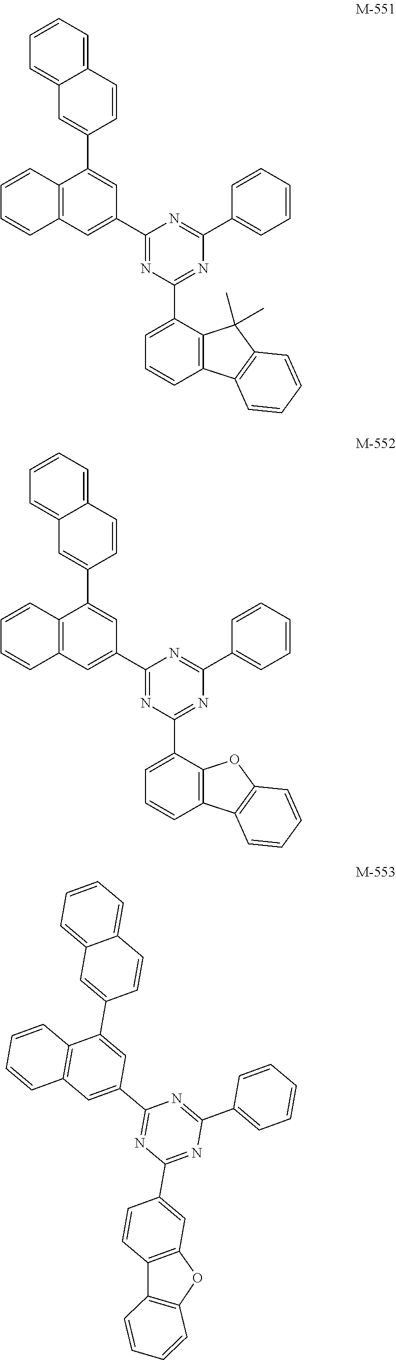 [SMILES: CC1(C)c2ccccc2-c2cccc(-c3nc(-c4ccccc4)nc(-c4cc(-c5ccc6ccccc6c5)c5ccccc5c4)n3)c21 ; c1ccc(-c2nc(-c3cc(-c4ccc5ccccc5c4)c4ccccc4c3)nc(-c3cccc4c3oc3ccccc34)n2)cc1 ; c1ccc(-c2nc(-c3cc(-c4ccc5ccccc5c4)c4ccccc4c3)nc(-c3ccc4c(c3)oc3ccccc34)n2)cc1]

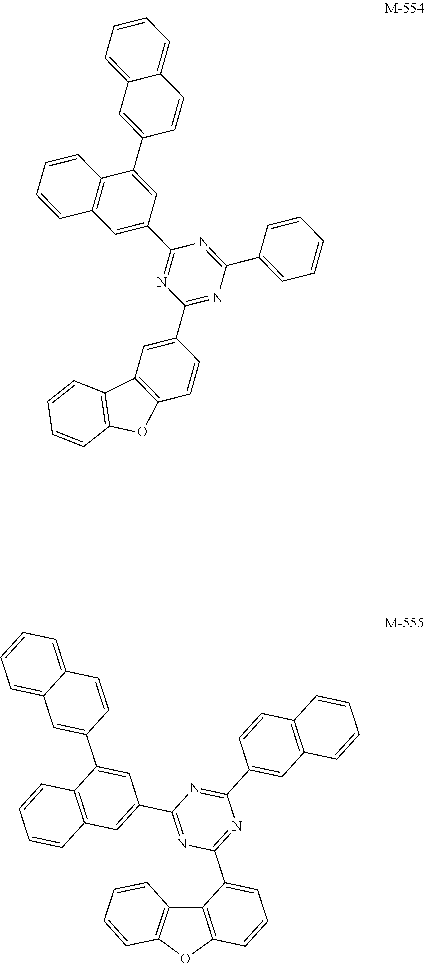 [SMILES: c1ccc(-c2nc(-c3cc(-c4ccc5ccccc5c4)c4ccccc4c3)nc(-c3ccc4oc5ccccc5c4c3)n2)cc1 ; c1ccc2cc(-c3nc(-c4cc(-c5ccc6ccccc6c5)c5ccccc5c4)nc(-c4cccc5oc6ccccc6c45)n3)ccc2c1]

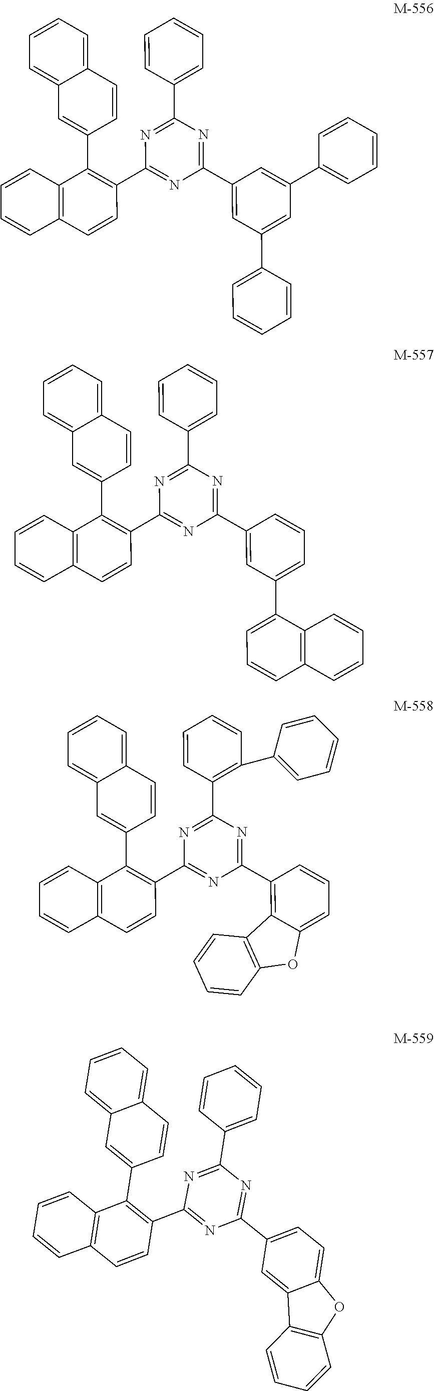

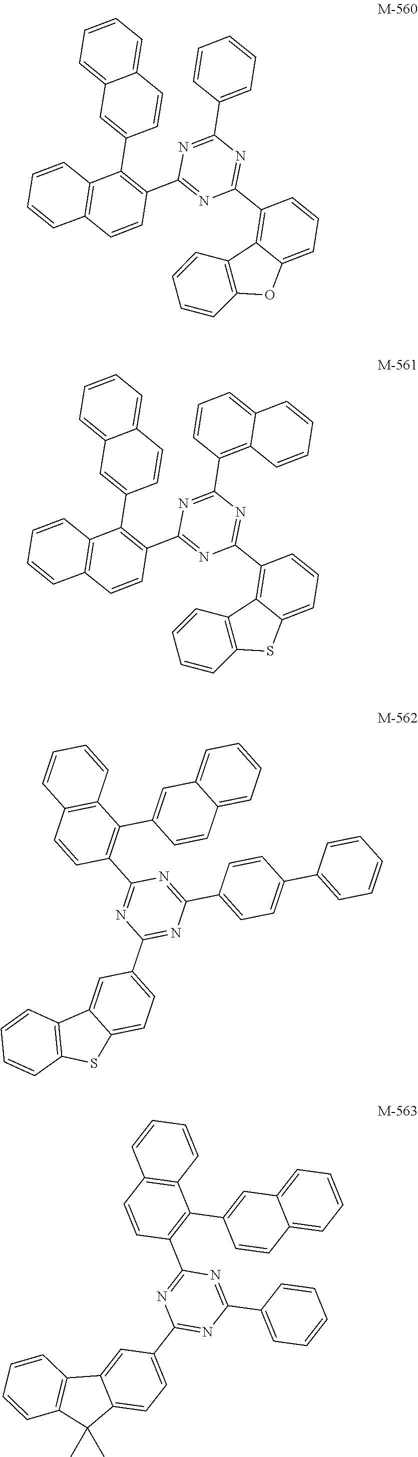 [SMILES: c1ccc(-c2nc(-c3ccc4ccccc4c3-c3ccc4ccccc4c3)nc(-c3cccc4oc5ccccc5c34)n2)cc1 ; c1ccc2cc(-c3c(-c4nc(-c5cccc6ccccc56)nc(-c5cccc6sc7ccccc7c56)n4)ccc4ccccc34)ccc2c1 ; c1ccc(-c2ccc(-c3nc(-c4ccc5sc6ccccc6c5c4)nc(-c4ccc5ccccc5c4-c4ccc5ccccc5c4)n3)cc2)cc1 ; CC1(C)c2ccccc2-c2cc(-c3nc(-c4ccccc4)nc(-c4ccc5ccccc5c4-c4ccc5ccccc5c4)n3)ccc21]

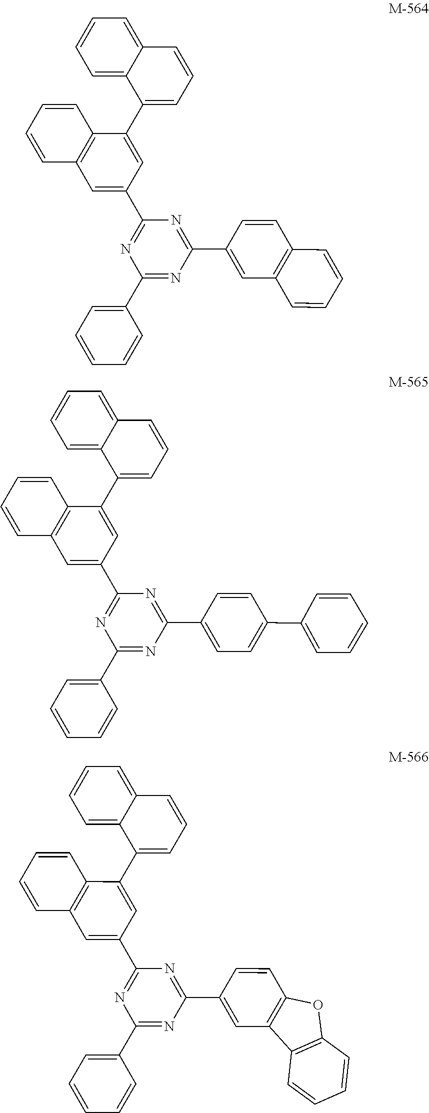

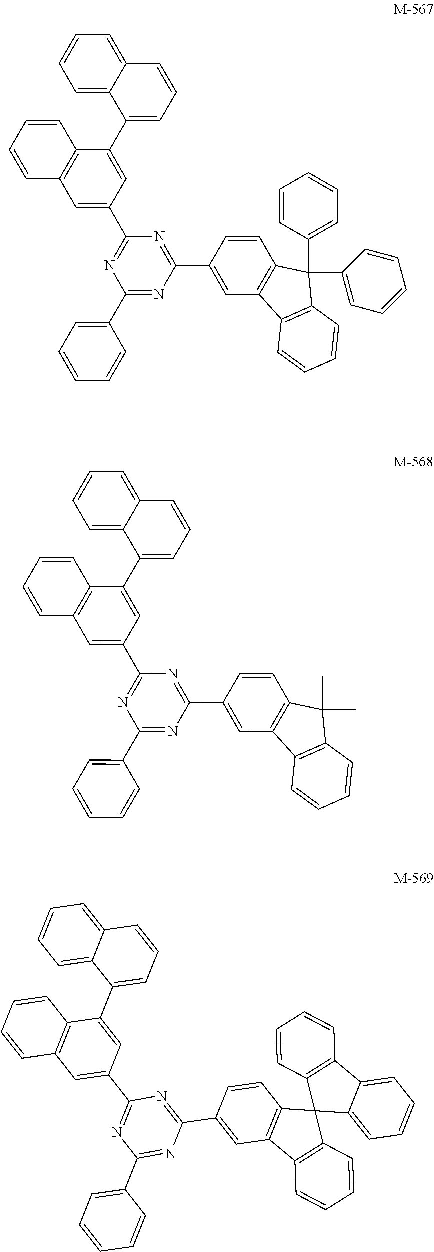 [SMILES: c1ccc(-c2nc(-c3ccc4c(c3)-c3ccccc3C4(c3ccccc3)c3ccccc3)nc(-c3cc(-c4cccc5ccccc45)c4ccccc4c3)n2)cc1 ; CC1(C)c2ccccc2-c2cc(-c3nc(-c4ccccc4)nc(-c4cc(-c5cccc6ccccc56)c5ccccc5c4)n3)ccc21 ; c1ccc(-c2nc(-c3ccc4c(c3)-c3ccccc3C43c4ccccc4-c4ccccc43)nc(-c3cc(-c4cccc5ccccc45)c4ccccc4c3)n2)cc1]

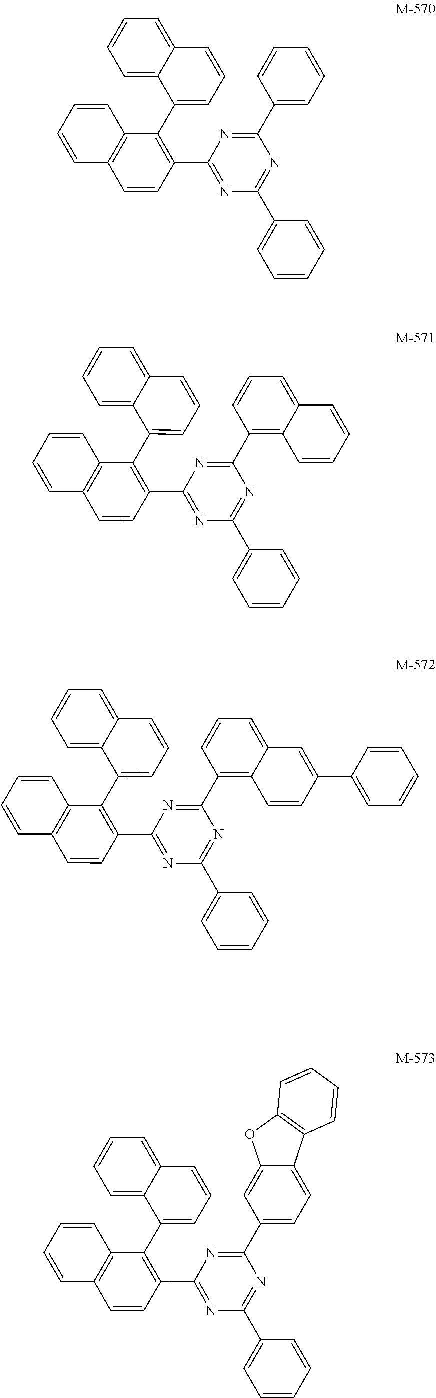 [SMILES: c1ccc(-c2nc(-c3ccccc3)nc(-c3ccc4ccccc4c3-c3cccc4ccccc34)n2)cc1 ; c1ccc(-c2nc(-c3ccc4ccccc4c3-c3cccc4ccccc34)nc(-c3cccc4ccccc34)n2)cc1 ; c1ccc(-c2ccc3c(-c4nc(-c5ccccc5)nc(-c5ccc6ccccc6c5-c5cccc6ccccc56)n4)cccc3c2)cc1 ; c1ccc(-c2nc(-c3ccc4c(c3)oc3ccccc34)nc(-c3ccc4ccccc4c3-c3cccc4ccccc34)n2)cc1]

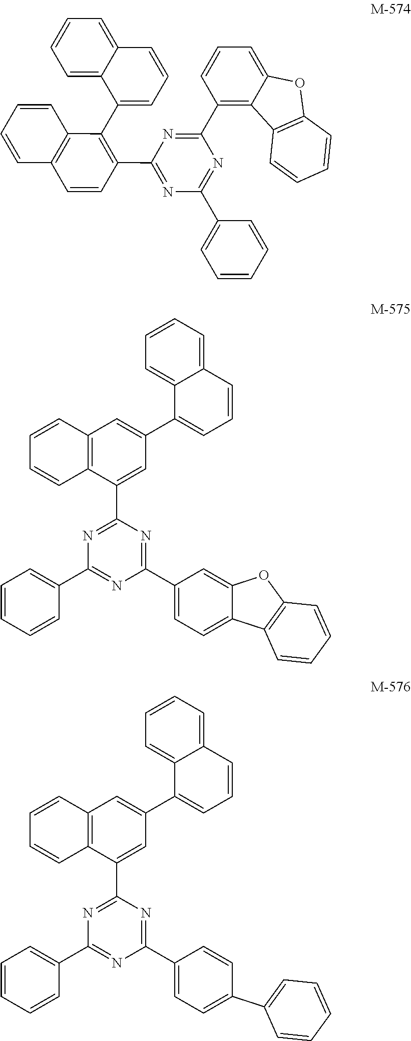 [SMILES: c1ccc(-c2nc(-c3ccc4ccccc4c3-c3cccc4ccccc34)nc(-c3cccc4oc5ccccc5c34)n2)cc1 ; c1ccc(-c2nc(-c3ccc4c(c3)oc3ccccc34)nc(-c3cc(-c4cccc5ccccc45)cc4ccccc34)n2)cc1 ; c1ccc(-c2ccc(-c3nc(-c4ccccc4)nc(-c4cc(-c5cccc6ccccc56)cc5ccccc45)n3)cc2)cc1]

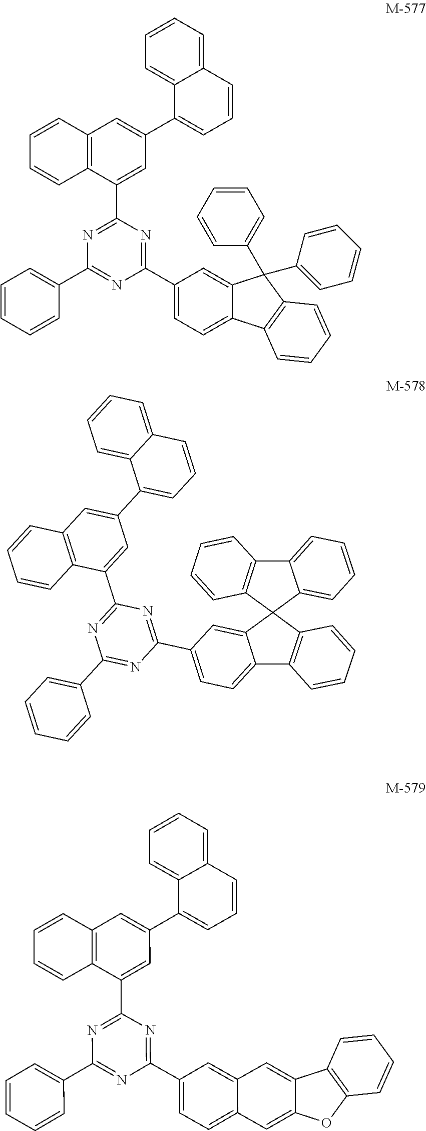 [SMILES: c1ccc(-c2nc(-c3ccc4c(c3)C(c3ccccc3)(c3ccccc3)c3ccccc3-4)nc(-c3cc(-c4cccc5ccccc45)cc4ccccc34)n2)cc1 ; c1ccc(-c2nc(-c3ccc4c(c3)C3(c5ccccc5-c5ccccc53)c3ccccc3-4)nc(-c3cc(-c4cccc5ccccc45)cc4ccccc34)n2)cc1 ; c1ccc(-c2nc(-c3ccc4cc5oc6ccccc6c5cc4c3)nc(-c3cc(-c4cccc5ccccc45)cc4ccccc34)n2)cc1]

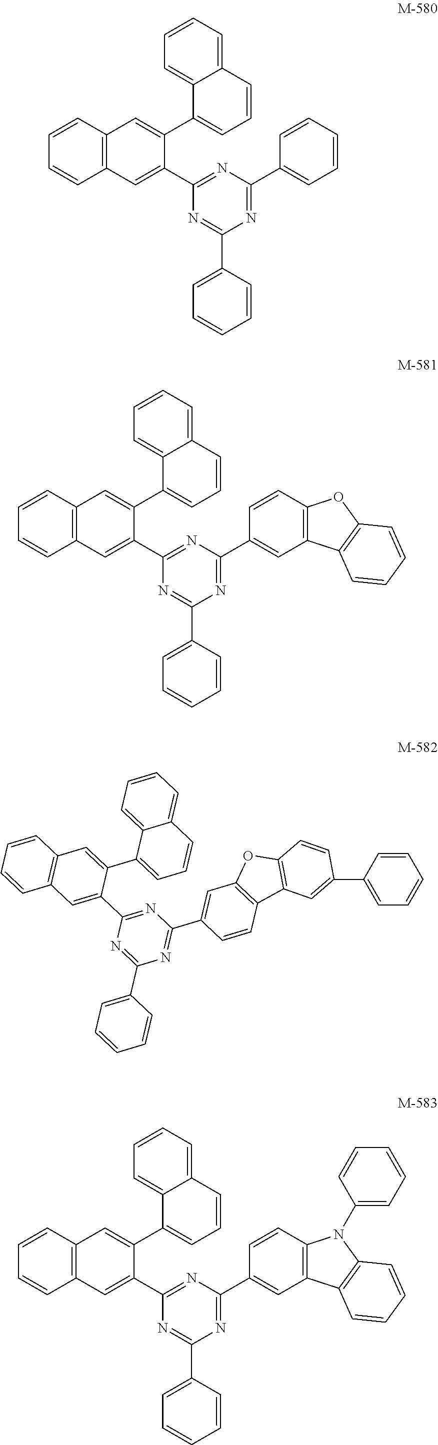 [SMILES: c1ccc(-c2nc(-c3ccccc3)nc(-c3cc4ccccc4cc3-c3cccc4ccccc34)n2)cc1 ; c1ccc(-c2nc(-c3ccc4oc5ccccc5c4c3)nc(-c3cc4ccccc4cc3-c3cccc4ccccc34)n2)cc1 ; c1ccc(-c2ccc3oc4cc(-c5nc(-c6ccccc6)nc(-c6cc7ccccc7cc6-c6cccc7ccccc67)n5)ccc4c3c2)cc1 ; c1ccc(-c2nc(-c3ccc4c(c3)c3ccccc3n4-c3ccccc3)nc(-c3cc4ccccc4cc3-c3cccc4ccccc34)n2)cc1]

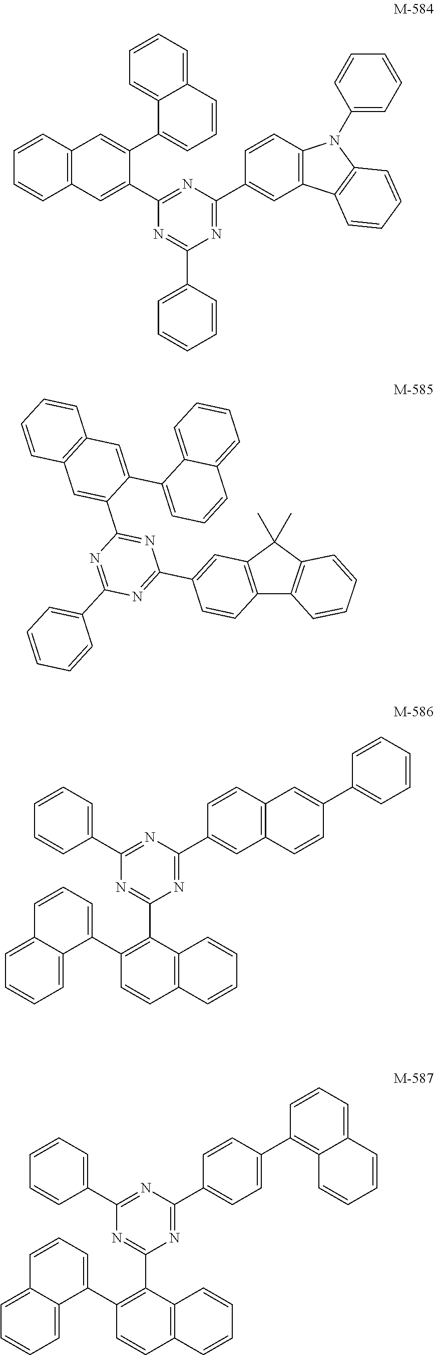 [SMILES: c1ccc(-c2nc(-c3ccc4c(c3)c3ccccc3n4-c3ccccc3)nc(-c3cc4ccccc4cc3-c3cccc4ccccc34)n2)cc1 ; CC1(C)c2ccccc2-c2ccc(-c3nc(-c4ccccc4)nc(-c4cc5ccccc5cc4-c4cccc5ccccc45)n3)cc21 ; c1ccc(-c2ccc3cc(-c4nc(-c5ccccc5)nc(-c5c(-c6cccc7ccccc67)ccc6ccccc56)n4)ccc3c2)cc1 ; c1ccc(-c2nc(-c3ccc(-c4cccc5ccccc45)cc3)nc(-c3c(-c4cccc5ccccc45)ccc4ccccc34)n2)cc1]

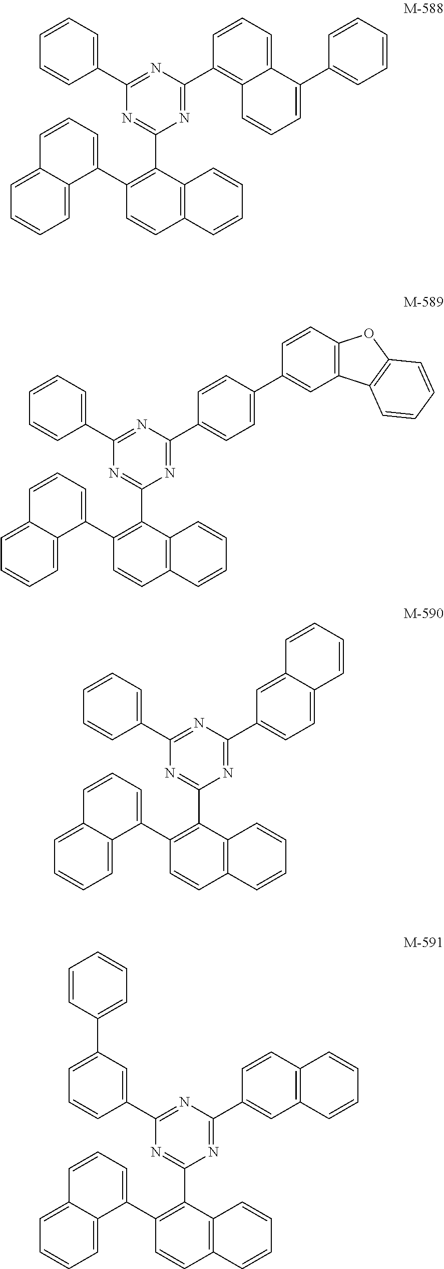 [SMILES: c1ccc(-c2nc(-c3c(-c4cccc5ccccc45)ccc4ccccc34)nc(-c3cccc4c(-c5ccccc5)cccc34)n2)cc1 ; c1ccc(-c2nc(-c3ccc(-c4ccc5oc6ccccc6c5c4)cc3)nc(-c3c(-c4cccc5ccccc45)ccc4ccccc34)n2)cc1 ; c1ccc(-c2nc(-c3ccc4ccccc4c3)nc(-c3c(-c4cccc5ccccc45)ccc4ccccc34)n2)cc1 ; c1ccc(-c2cccc(-c3nc(-c4ccc5ccccc5c4)nc(-c4c(-c5cccc6ccccc56)ccc5ccccc45)n3)c2)cc1]

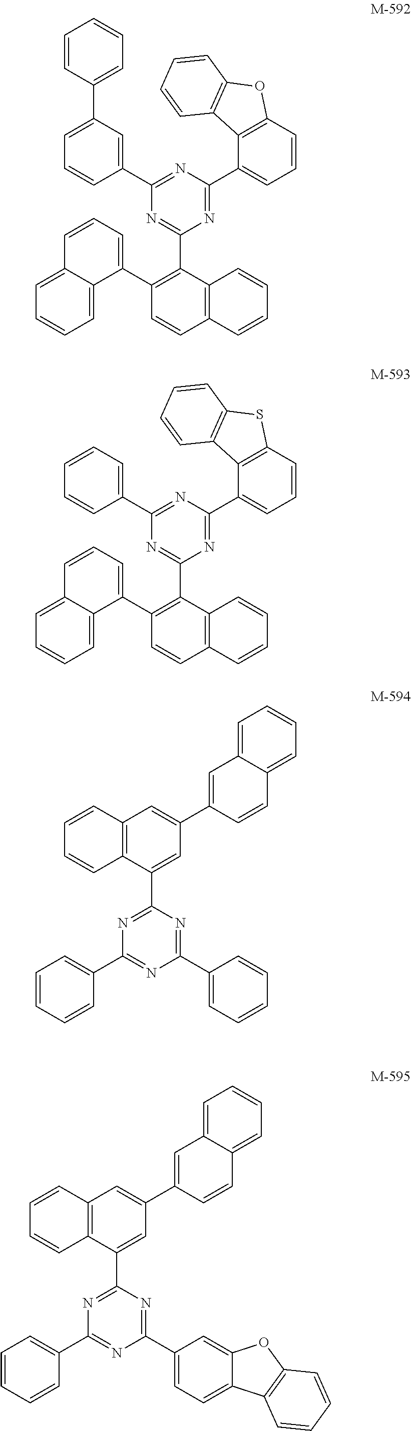 [SMILES: c1ccc(-c2cccc(-c3nc(-c4c(-c5cccc6ccccc56)ccc5ccccc45)nc(-c4cccc5oc6ccccc6c45)n3)c2)cc1 ; c1ccc(-c2nc(-c3c(-c4cccc5ccccc45)ccc4ccccc34)nc(-c3cccc4sc5ccccc5c34)n2)cc1 ; c1ccc(-c2nc(-c3ccccc3)nc(-c3cc(-c4ccc5ccccc5c4)cc4ccccc34)n2)cc1 ; c1ccc(-c2nc(-c3ccc4c(c3)oc3ccccc34)nc(-c3cc(-c4ccc5ccccc5c4)cc4ccccc34)n2)cc1]

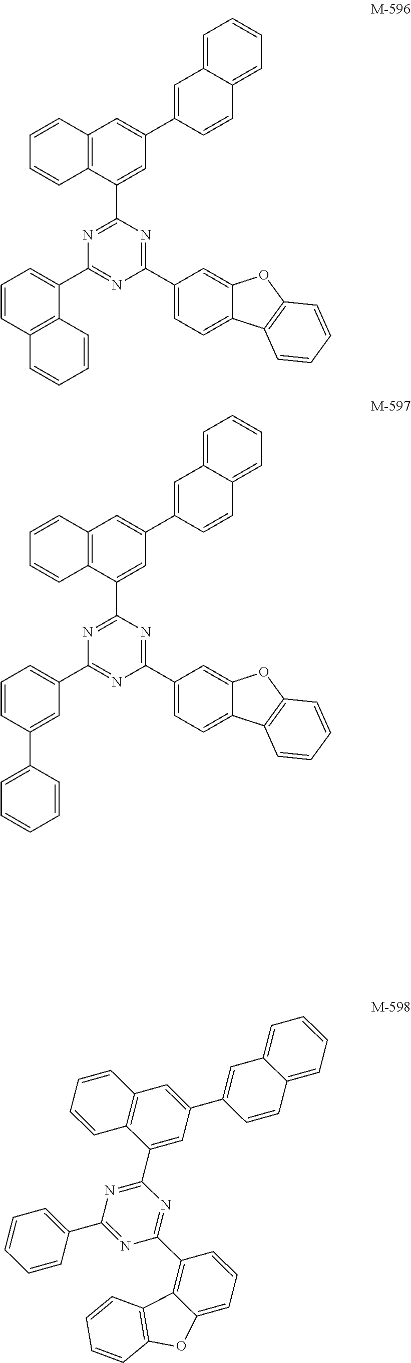 [SMILES: c1ccc2cc(-c3cc(-c4nc(-c5ccc6c(c5)oc5ccccc56)nc(-c5cccc6ccccc56)n4)c4ccccc4c3)ccc2c1 ; c1ccc(-c2cccc(-c3nc(-c4ccc5c(c4)oc4ccccc45)nc(-c4cc(-c5ccc6ccccc6c5)cc5ccccc45)n3)c2)cc1 ; c1ccc(-c2nc(-c3cc(-c4ccc5ccccc5c4)cc4ccccc34)nc(-c3cccc4oc5ccccc5c34)n2)cc1]

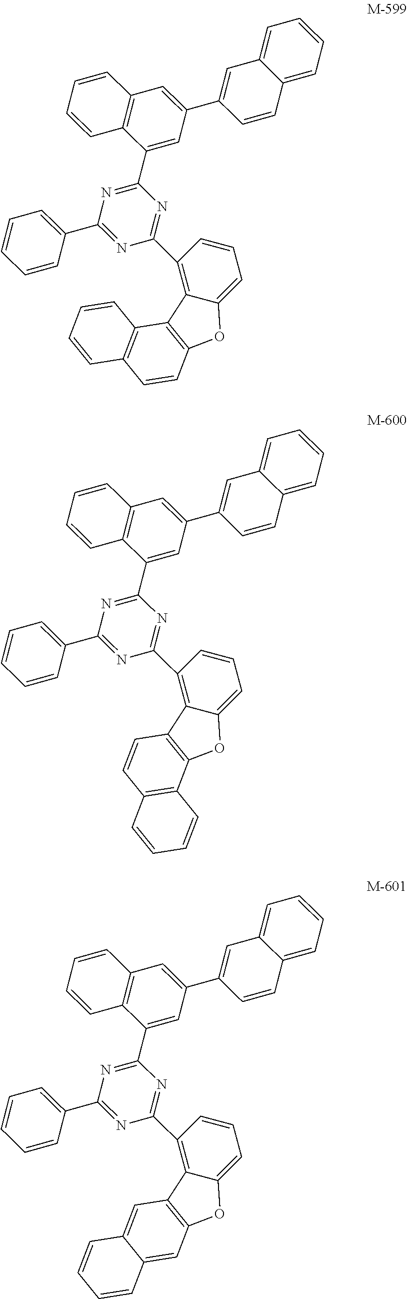 [SMILES: c1ccc(-c2nc(-c3cc(-c4ccc5ccccc5c4)cc4ccccc34)nc(-c3cccc4oc5ccc6ccccc6c5c34)n2)cc1 ; c1ccc(-c2nc(-c3cc(-c4ccc5ccccc5c4)cc4ccccc34)nc(-c3cccc4oc5c6ccccc6ccc5c34)n2)cc1 ; c1ccc(-c2nc(-c3cc(-c4ccc5ccccc5c4)cc4ccccc34)nc(-c3cccc4oc5cc6ccccc6cc5c34)n2)cc1]

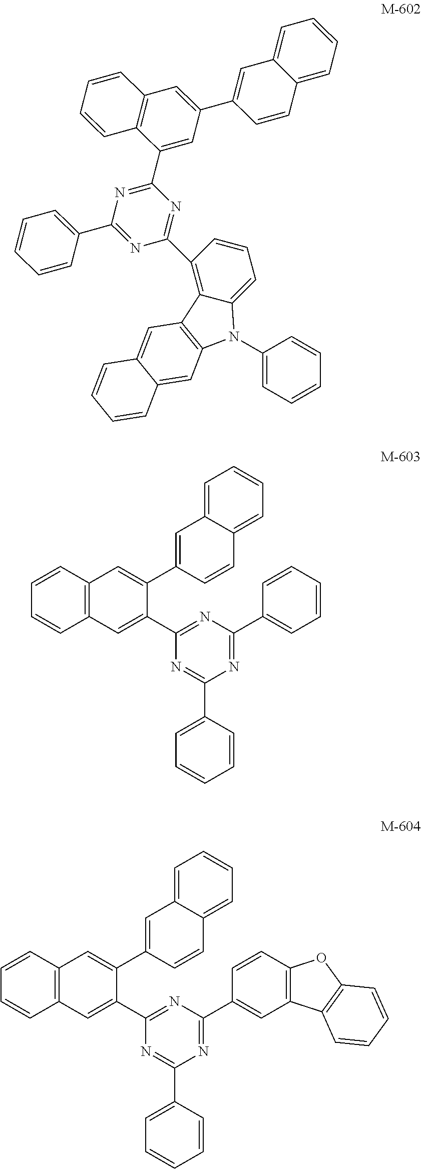 [SMILES: c1ccc(-c2nc(-c3cc(-c4ccc5ccccc5c4)cc4ccccc34)nc(-c3cccc4c3c3cc5ccccc5cc3n4-c3ccccc3)n2)cc1 ; c1ccc(-c2nc(-c3ccccc3)nc(-c3cc4ccccc4cc3-c3ccc4ccccc4c3)n2)cc1 ; c1ccc(-c2nc(-c3ccc4oc5ccccc5c4c3)nc(-c3cc4ccccc4cc3-c3ccc4ccccc4c3)n2)cc1]

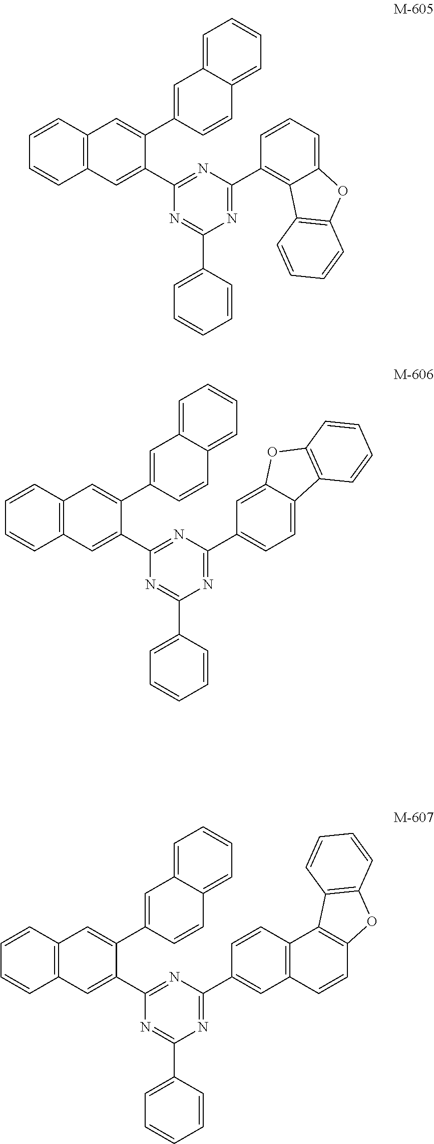 [SMILES: c1ccc(-c2nc(-c3cc4ccccc4cc3-c3ccc4ccccc4c3)nc(-c3cccc4oc5ccccc5c34)n2)cc1 ; c1ccc(-c2nc(-c3ccc4c(c3)oc3ccccc34)nc(-c3cc4ccccc4cc3-c3ccc4ccccc4c3)n2)cc1 ; c1ccc(-c2nc(-c3ccc4c(ccc5oc6ccccc6c54)c3)nc(-c3cc4ccccc4cc3-c3ccc4ccccc4c3)n2)cc1]

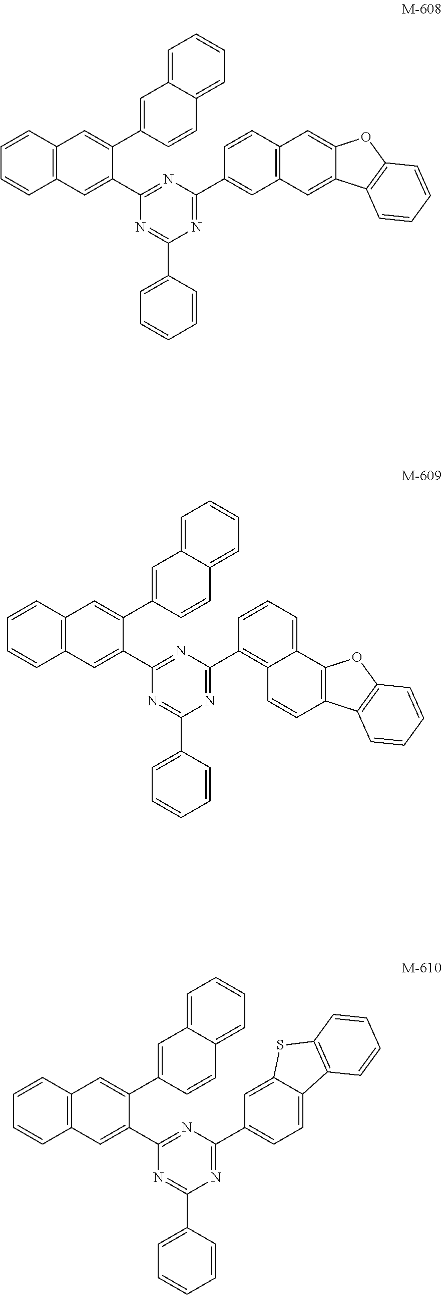 [SMILES: c1ccc(-c2nc(-c3ccc4cc5oc6ccccc6c5cc4c3)nc(-c3cc4ccccc4cc3-c3ccc4ccccc4c3)n2)cc1 ; c1ccc(-c2nc(-c3cc4ccccc4cc3-c3ccc4ccccc4c3)nc(-c3cccc4c3ccc3c5ccccc5oc43)n2)cc1 ; c1ccc(-c2nc(-c3ccc4c(c3)sc3ccccc34)nc(-c3cc4ccccc4cc3-c3ccc4ccccc4c3)n2)cc1]

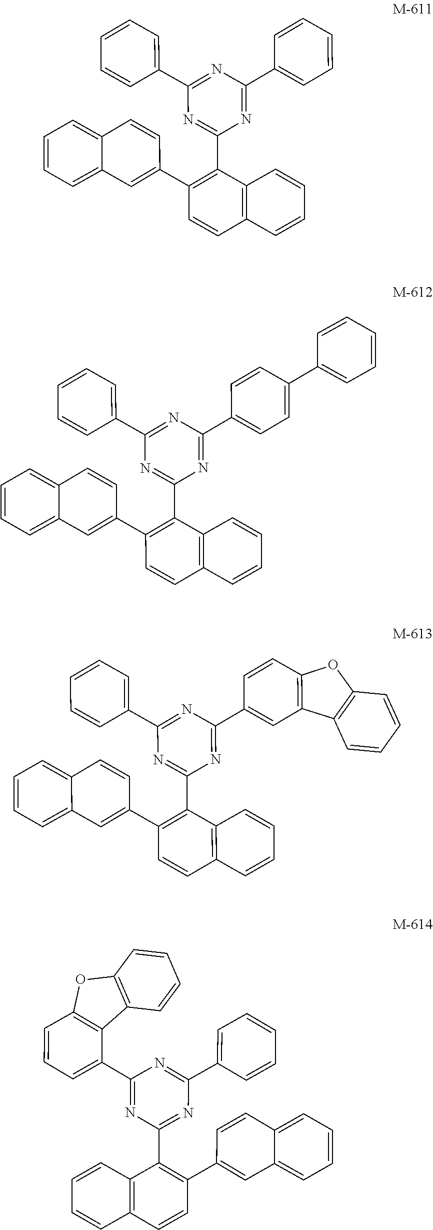 [SMILES: c1ccc(-c2nc(-c3ccccc3)nc(-c3c(-c4ccc5ccccc5c4)ccc4ccccc34)n2)cc1 ; c1ccc(-c2ccc(-c3nc(-c4ccccc4)nc(-c4c(-c5ccc6ccccc6c5)ccc5ccccc45)n3)cc2)cc1 ; c1ccc(-c2nc(-c3ccc4oc5ccccc5c4c3)nc(-c3c(-c4ccc5ccccc5c4)ccc4ccccc34)n2)cc1 ; c1ccc(-c2nc(-c3c(-c4ccc5ccccc5c4)ccc4ccccc34)nc(-c3cccc4oc5ccccc5c34)n2)cc1]

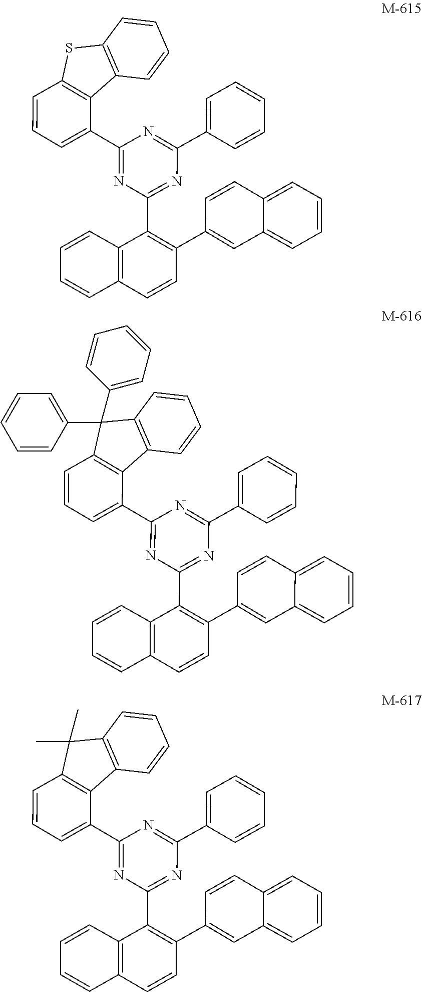

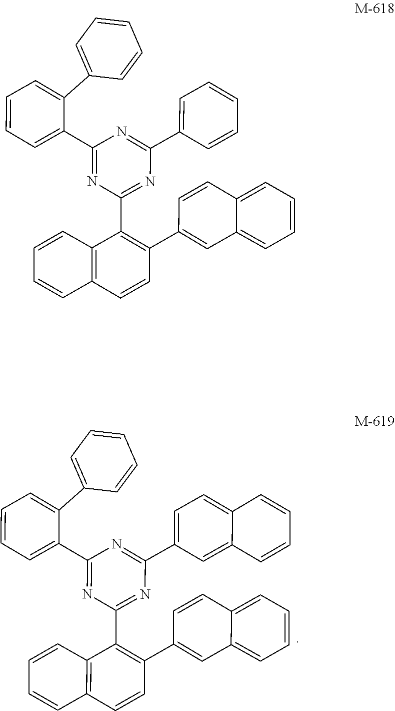 [SMILES: c1ccc(-c2nc(-c3ccccc3-c3ccccc3)nc(-c3c(-c4ccc5ccccc5c4)ccc4ccccc34)n2)cc1 ; c1ccc(-c2ccccc2-c2nc(-c3ccc4ccccc4c3)nc(-c3c(-c4ccc5ccccc5c4)ccc4ccccc34)n2)cc1]

Preferably, the mass ratio of compound N to compound M is from 1:9 to 9:1;
preferably, the mass ratio of compound N to compound M is from 2:8 to 8:2;
more preferably, the mass ratio of compound N to compound M is from 3:7 to 7:3;
further preferably, the mass ratio of compound N to compound M is from 4:6 to 6:4.

The present application also provides an application of the organic electroluminescent material composition described above in the preparation of optical devices.

Preferably, the optical devices comprise any one of organic electroluminescent devices, organic field-effect transistors, organic thin-film transistors, organic light emitting transistors, organic integrated circuits, organic solar cells, organic field quenching devices, luminescent electrochemical cells, organic laser diodes, and organic photoreceptors.

The present application also provides an organic electroluminescent device, the organic electroluminescent device comprises an anode, a cathode, and an organic layer arranged between the anode and the cathode; the organic layer comprises the organic electroluminescent material composition described above, preferably, an light emitting layer of the organic layer the comprises the organic electroluminescent material composition described above.

Preferably, the organic layer comprises a hole injection layer, a hole transport layer, an electron barrier layer, a light emitting layer, a hole barrier layer, an electron transport layer, and an electron injection layer sequentially arranged from the anode side to the cathode side;
preferably, the material of the light emitting layer comprises a host material and a guest material; the host material comprises the organic electroluminescent material composition above.

Preferably, the guest material comprises a phosphorescent dopant, and the phosphorescent dopant comprises a complex containing transition metals.

The present application also provides an organic electroluminescent equipment, the organic electroluminescent equipment comprises the organic electroluminescent device above.

The beneficial effects of the present application:

The organic electroluminescent material composition of the present application, based on Formula (1), compound N and compound M cooperate with each other to facilitate the matching of HOMO and LUMO energy levels with adjacent energy levels, resulting in relatively high stability and balanced carrier mobility of the organic electroluminescent compound, thereby enabling the organic electroluminescent device containing the material to have a better lifespan, lower driving voltage and higher efficiency at the same time.

### BRIEF DESCRIPTION OF THE DRAWINGS

In order to illustrate the technical solutions in the specific embodiments of the present application or in the prior art more clearly, the drawings to be used in the description of the specific embodiments or the prior art will be briefly introduced below. Obviously, the drawings in the following description show some of the embodiments of the present application, and those of ordinary skill in the art may still obtain other drawings from these drawings without creative efforts.

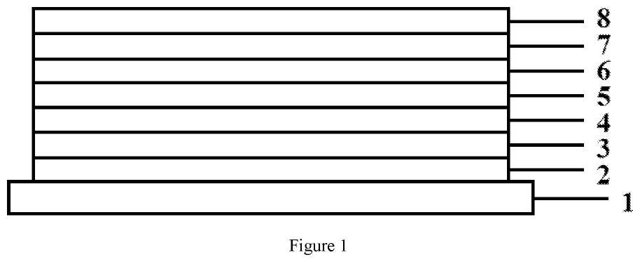

FIG. 1 is a structural diagram of an organic electroluminescent device in an embodiment of the present application;
wherein, 1. substrate; 2—anode; 3—hole injection layer; 4—hole transport layer; 5—light emitting layer; 6—electron transport layer; 7—electron injection layer; 8—cathode.

### DETAILED DESCRIPTION

The following examples are provided for a better further understanding of the present application and are not limited to the best embodiments, not limiting the content and scope of protection of the present application, and any product that is the same as or similar to that of the present application obtained by anyone under the inspiration of the present application or by combining the features of the present application with that of other prior art falls within the scope of protection of the present application.

If specific experimental steps or conditions are not specified in the examples, the operation or conditions of conventional experimental steps described in the literature in this field can be carried out. The adopted reagents or instruments which are not specified with the manufacturer are conventional commercially-available reagent products.

### Example 1

The present example provides a method for preparing a compound with M-17 structure in an organic electroluminescent material composition, comprising the following steps:

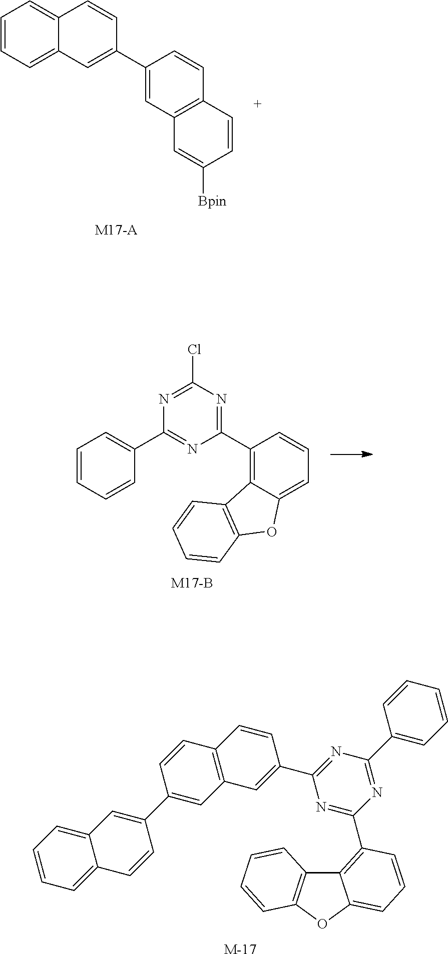

A 50 mL double-neck round-bottom flask was taken, a stirrer and an upwards-connected return pipe were placed in the flask, the flask was filled with nitrogen after being dried, compounds M17-A (19.8 mmol, CAS: 1884145-03-2), M17-B (20.75 mmol, CAS: 1883265-32-4), tetrakis(triphenylphosphine)palladium (0.396 mmol), potassium carbonate (39.6 mmol), 35 mL of toluene, 15 mL of ethanol and 15 mL of distilled water were added respectively, and the mixture was stirred at 90 degrees Celsius for 8 hours. After the reaction was completed, the mixture was added into methanol dropwise, and the obtained solid was filtered. The obtained solid was purified through column chromatography to obtain compound M-17 (8.5 g, yield: 75%).

Elemental analysis: C₄₁H₂₅N₃O; theoretical value: C, 85.54; H, 4.38; N, 7.30; 0, 2.78; measured value: C, 85.52; H, 4.38; N, 7.32; HRMS (ESI) m/z (M+): theoretical value: 575.20; measured value: 576.34.

### Example 2

The present example provides a method for preparing a compound with M-296 structure in an organic electroluminescent material composition, comprising the following steps:

(I) Synthesis of an intermediate M296-A, with a synthetic route being as follows:

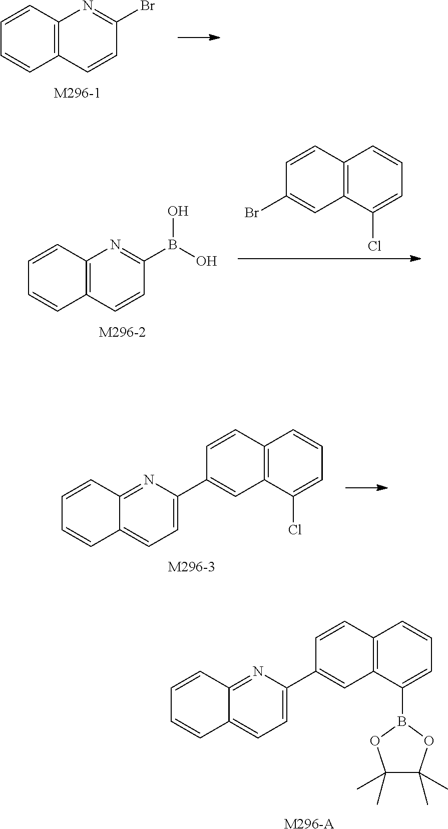

An intermediate M296-1 (2-bromoquinoline, CAS: 2005-43-8, 20 g) and 200 mL of anhydrous tetrahydrofuran were added into a 250 mL three-necked flask equipped with a thermometer and a magnetic stirrer, the temperature was reduced to −78° C. under a nitrogen protection condition, n-butyl lithium (1.6 M, 45.2 mL) was added dropwise with the temperature controlled, stirring was conducted for 1 h after dropwise adding, triisopropyl borate (19.52 g) was added dropwise with the temperature controlled at −78° C., the mixture was transferred to the room temperature after dropwise adding to react for 12 h, a hydrochloric acid solution (6.5 mL of 36% hydrochloric acid+24 mL of water) was added dropwise, 50 mL of ethyl acetate and 25 mL of water were added into the reaction liquid for extraction and liquid separation, the organic phase was spin-dried and then 50 mL of n-hexane was added, reflux was conducted for 1 h to produce a slurry, filtering was conducted at the room temperature, and 15 g of an intermediate M296-2 was obtained after drying.

The intermediate M296-2 (15 g), an intermediate 7-bromo-1-chloronaphthalene (21.9 g), potassium carbonate (16.6 g) and tetrakis(triphenylphosphine)palladium (2.0 g) were added into a 250 mL three-necked flask equipped with a thermometer and a magnetic stirrer, toluene (80 mL), ethanol (35 mL) and water (35 mL) were added, under a nitrogen protection condition, the temperature was raised to 85° C. to react for 6 h, 50 mL of ethyl acetate and 25 mL of water were added into the reaction liquid for extraction and liquid separation, the organic phase was prepared into sample and subjected column chromatography, and 15 g of an intermediate M296-3 was obtained.

The intermediate M296-3 (15 g), bis(pinacolato)diboron (15.8 g), potassium acetate (10 g) and Pd(dppf)Cl₂ (0.64 g) were added into a 250 mL three-necked flask equipped with a thermometer and a magnetic stirrer, 1,4-dioxane (150 mL) was added, under a nitrogen protection condition, the temperature was raised to 110° C. to react for 4 h, 100 mL of toluene and 100 mL of water were added into the reaction liquid for extraction and liquid separation, the organic phase was prepared into sample and subjected column chromatography, and 16 g of the intermediate M296-A was obtained.

(II) Synthesis of the compound M-296, with a synthetic route being as follows:

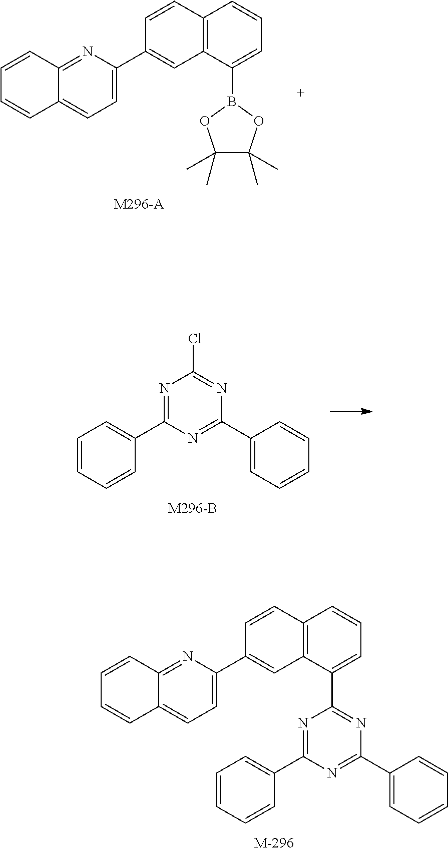

The intermediate M296-A (16 g), an intermediate M296-B (2-chloro-4,6-diphenyl-1,3,5-triazine, CAS: 3842-55-5, 11.2 g), potassium carbonate (11.6 g) and tetrakis(triphenylphosphine)palladium (1.3 g) were added into a 250 mL three-necked flask equipped with a thermometer and a magnetic stirrer, toluene (110 mL), ethanol (50 mL) and water (50 mL) were added, under a nitrogen protection condition, the temperature was raised to 85° C. to react for 6 h, water and ethanol were added into the reaction liquid at the room temperature for filtration, and 16 g of the product M-296 was obtained after drying (yield 78%).

Elemental analysis: C₃₄H₂₂N₄; theoretical value: C, 83.93; H, 4.56; N, 11.51; measured value: C, 83.95; H, 4.56; N, 11.49; HRMS (ESI) m/z (M+): theoretical value: 486.18; measured value: 487.12.

### Example 3

The present example provides a method for preparing a compound with M-381 structure in an organic electroluminescent material composition, comprising the following steps:

(I) Synthesis of an intermediate M381-B, with a synthetic route being as follows:

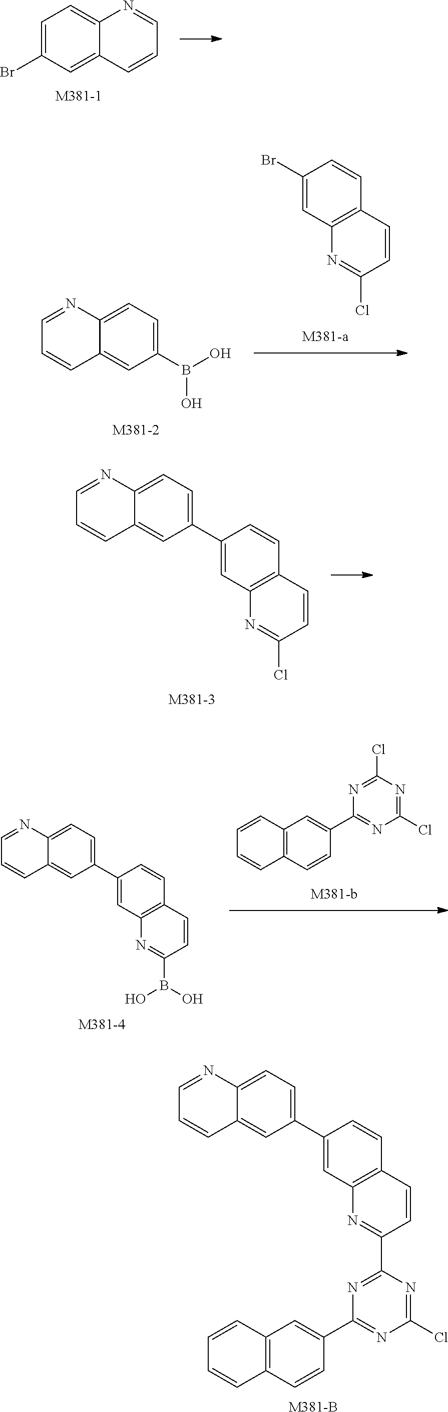

An intermediate M381-1 (CAS: 5332-25-2, 20 g) and 200 mL of anhydrous tetrahydrofuran were added into a 250 mL three-necked flask equipped with a thermometer and a magnetic stirrer, the temperature was reduced to −78° C. under a nitrogen protection condition, n-butyl lithium (1.6 M, 45.2 mL) was added dropwise with the temperature controlled, stirring was conducted for 1 h after dropwise adding, triisopropyl borate (19.52 g) was added dropwise with the temperature controlled at −78° C., the mixture was transferred to the room temperature after dropwise adding to react for 12 h, a hydrochloric acid solution (6.5 mL of 36% hydrochloric acid+24 mL of water) was added dropwise, 50 mL of ethyl acetate and 25 mL of water were added into the reaction liquid for extraction and liquid separation, the organic phase was spin-dried and then 50 mL of n-hexane was added, reflux was conducted for 1 h to produce a slurry, filtering was conducted at the room temperature, and 15 g of an intermediate M381-2 was obtained after drying.

The intermediate M381-2 (15 g), a raw material M367-a (CAS: 99455-15-9, 21 g), potassium carbonate (16.6 g) and tetrakis(triphenylphosphine)palladium (2.0 g) were added into a 250 mL three-necked flask equipped with a thermometer and a magnetic stirrer, toluene (80 mL), ethanol (35 mL) and water (35 mL) were added, under a nitrogen protection condition, the temperature was raised to 85° C. to react for 6 h, 50 mL of ethyl acetate and 25 mL of water were added into the reaction liquid for extraction and liquid separation, the organic phase was prepared into sample and subjected column chromatography, and 13 g of an intermediate M381-3 was obtained.

The intermediate M381-3 (13 g) and 200 mL of anhydrous tetrahydrofuran were added into a 250 mL three-necked flask equipped with a thermometer and a magnetic stirrer, the temperature was reduced to −78° C. under a nitrogen protection condition, n-butyl lithium (1.6 M, 40 mL) was added dropwise with the temperature controlled, stirring was conducted for 1 h after dropwise adding, triisopropyl borate (17 g) was added dropwise with the temperature controlled at −78° C., the mixture was transferred to the room temperature after dropwise adding to react for 12 h, a hydrochloric acid solution (6.5 mL of 36% hydrochloric acid+24 mL of water) was added dropwise, 50 mL of ethyl acetate and 25 mL of water were added into the reaction liquid for extraction and liquid separation, the organic phase was spin-dried and 50 mL of n-hexane was added, reflux was conducted for 1 h to produce a slurry, filtering was conducted at the room temperature, and 12 g of an intermediate M381-4 was obtained after drying.

The intermediate M381-4 (12 g), a raw material M381-b (CAS: 112719-97-8, 11 g), potassium carbonate (11 g) and tetrakis(triphenylphosphine)palladium (1.2 g) were added into a 250 mL three-necked flask equipped with a thermometer and a magnetic stirrer, toluene (80 mL), ethanol (35 mL) and water (35 mL) were added, under a nitrogen protection condition, the temperature was raised to 85° C. to react for 6 h, 50 mL of ethyl acetate and 25 mL of water were added into the reaction liquid for extraction and liquid separation, the organic phase was prepared into sample and subjected column chromatography, and 16 g of the intermediate M381-B was obtained.

(II) Synthesis of the compound M-381, with a synthetic route being as follows:

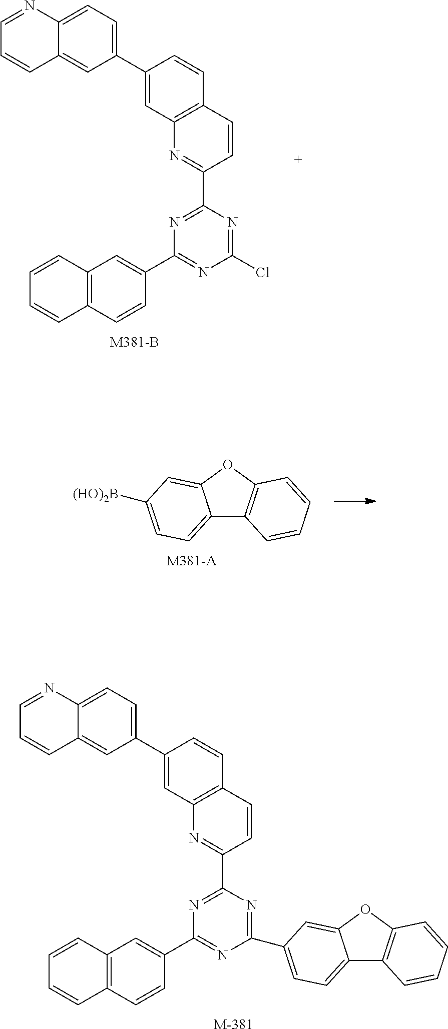

The intermediate M381-B (16 g), a raw material M381-A (6.85 g, CAS: 395087-89-5), potassium carbonate (9 g) and tetrakis(triphenylphosphine)palladium (1.0 g) were added into a 250 mL three-necked flask equipped with a thermometer and a magnetic stirrer, toluene (80 mL), ethanol (35 mL) and water (35 mL) were added, under a nitrogen protection condition, the temperature was raised to 85° C. to react for 6 h, 50 mL of ethyl acetate and 25 mL of water were added into the reaction liquid for extraction and liquid separation, the organic phase was prepared into sample and subjected column chromatography, and 15 g of the final product M-381 was obtained (yield 74%).

Elemental analysis: C₄₃H₂₅N₅₀; theoretical value: C, 82.28; H, 4.01; N, 11.16; O, 2.55; measured value: C, 82.30; H, 4.01; N, 11.14; HRMS (ESI) m/z (M+): theoretical value: 627.21; measured value: 628.13.

### Examples 4-31

Examples 4-31 provides the method for preparing Compounds M-76, M-108, M-145, M-253, M-394, M-412, M-423, M-442, M-450, M-460, M-461, M-480, M-502, M-520, M-526, M-537, M-548, M-562, M-572, M-579, M-584, M-589, M-599, M-610, M-611, M-308, M-365 or M-371. The specific preparation method is as follows:
toluene, ethanol and water were added into a raw material Mn-B, a raw material Mn-A, potassium carbonate and tetrakis(triphenylphosphine)palladium, under a nitrogen protection condition, the temperature was raised for reaction, after the reaction was completed, the material was purified to obtain the final product. The dosage of the materials and experimental parameters are the same as those in Example 1.

The structures of the raw material Mn-B, the raw material Mn-A and the product as well as the yields were shown in Table 1 below. The elemental analysis results of the prepared compounds were shown in Table 2. The dosage of the materials and experimental parameters are the same as those in Example 1.

TABLE 1

| | Raw material | | | Yield |
|---|---|---|---|---|
| | Mn-A | Raw material Mn-B | Product M-n | % |
| Ex- am- ple 4 | 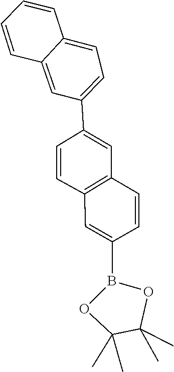 [SMILES: CC1(C)OB(c2ccc3cc(-c4ccc5ccccc5c4)ccc3c2)OC1(C)C] M76-A | 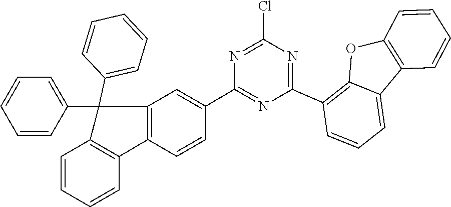 [SMILES: Clc1nc(-c2ccc3c(c2)C(c2ccccc2)(c2ccccc2)c2ccccc2-3)nc(-c2cccc3c2oc2ccccc23)n1] M76-B | 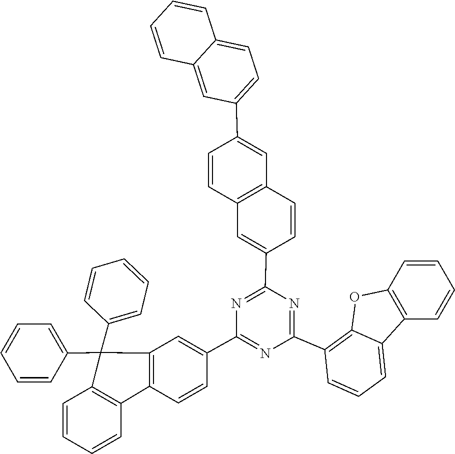 [SMILES: c1ccc(C2(c3ccccc3)c3ccccc3-c3ccc(-c4nc(-c5ccc6cc(-c7ccc8ccccc8c7)ccc6c5)nc(-c5cccc6c5oc5ccccc56)n4)cc32)cc1] M-76 | 76 |
| Ex- am- ple 5 | 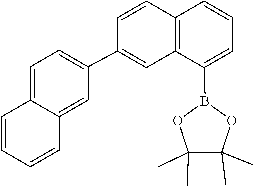 [SMILES: CC1(C)OB(c2cccc3ccc(-c4ccc5ccccc5c4)cc23)OC1(C)C] M108-A | 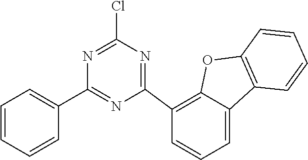 [SMILES: Clc1nc(-c2ccccc2)nc(-c2cccc3c2oc2ccccc23)n1] M108-B | 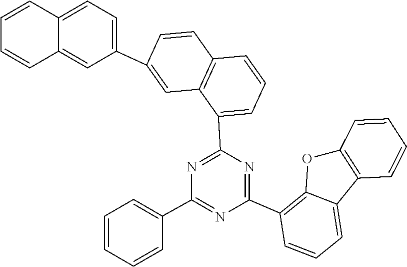 [SMILES: c1ccc(-c2nc(-c3cccc4ccc(-c5ccc6ccccc6c5)cc34)nc(-c3cccc4c3oc3ccccc34)n2)cc1] M-108 | 83 |
| Ex- am- ple 6 | 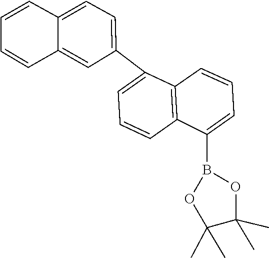 [SMILES: CC1(C)OB(c2cccc3c(-c4ccc5ccccc5c4)cccc23)OC1(C)C] M145-A | 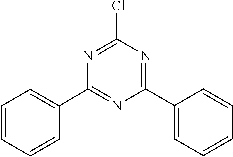 [SMILES: Clc1nc(-c2ccccc2)nc(-c2ccccc2)n1] M145-B | 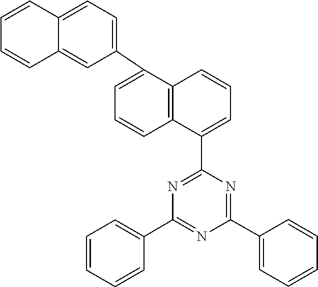 [SMILES: c1ccc(-c2nc(-c3ccccc3)nc(-c3cccc4c(-c5ccc6ccccc6c5)cccc34)n2)cc1] M-145 | 80 |
| Ex- am- ple 7 | 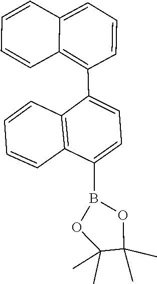 [SMILES: CC1(C)OB(c2ccc(-c3cccc4ccccc34)c3ccccc23)OC1(C)C] M253-A | 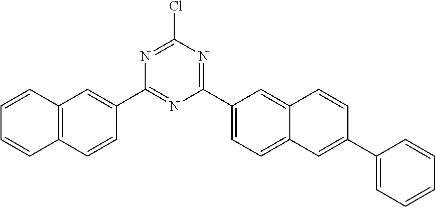 [SMILES: Clc1nc(-c2ccc3ccccc3c2)nc(-c2ccc3cc(-c4ccccc4)ccc3c2)n1] M253-B | 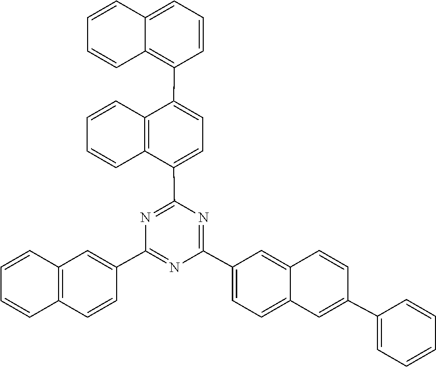 [SMILES: c1ccc(-c2ccc3cc(-c4nc(-c5ccc6ccccc6c5)nc(-c5ccc(-c6cccc7ccccc67)c6ccccc56)n4)ccc3c2)cc1] M-253 | 77 |
| Ex- am- ple 8 | 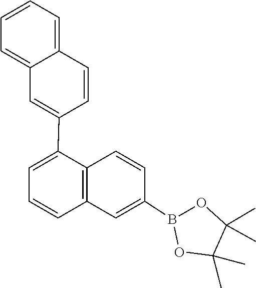 [SMILES: CC1(C)OB(c2ccc3c(-c4ccc5ccccc5c4)cccc3c2)OC1(C)C] M394-A | 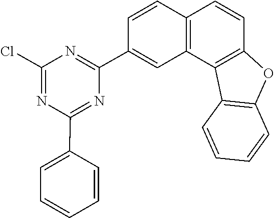 [SMILES: Clc1nc(-c2ccccc2)nc(-c2ccc3ccc4oc5ccccc5c4c3c2)n1] M394-B | 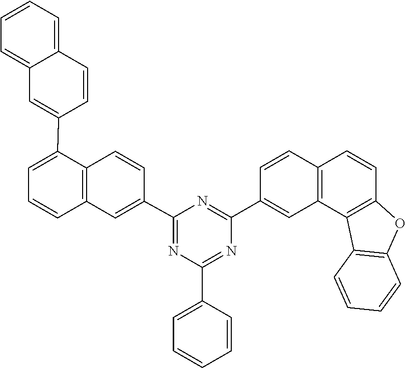 [SMILES: c1ccc(-c2nc(-c3ccc4c(-c5ccc6ccccc6c5)cccc4c3)nc(-c3ccc4ccc5oc6ccccc6c5c4c3)n2)cc1] M-394 | 79 |
| Ex- am- ple 9 | 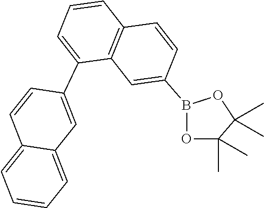 M412-A | 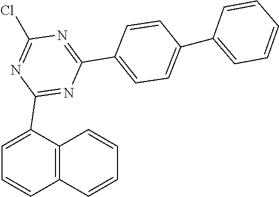 [SMILES: Clc1nc(-c2ccc(-c3ccccc3)cc2)nc(-c2cccc3ccccc23)n1] M412-B | 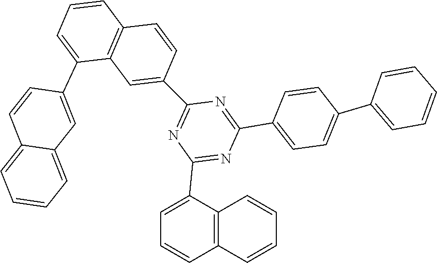 [SMILES: c1ccc(-c2ccc(-c3nc(-c4ccc5cccc(-c6ccc7ccccc7c6)c5c4)nc(-c4cccc5ccccc45)n3)cc2)cc1] M-412 | 74 |
| Ex- am- ple 10 | 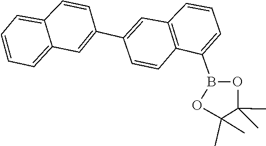 [SMILES: CC1(C)OB(c2cccc3cc(-c4ccc5ccccc5c4)ccc23)OC1(C)C] M423-A | 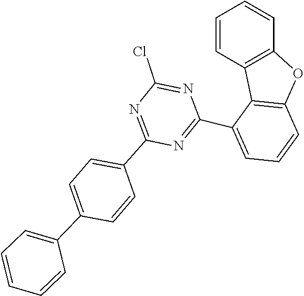 [SMILES: Clc1nc(-c2ccc(-c3ccccc3)cc2)nc(-c2cccc3oc4ccccc4c23)n1] M423-B | 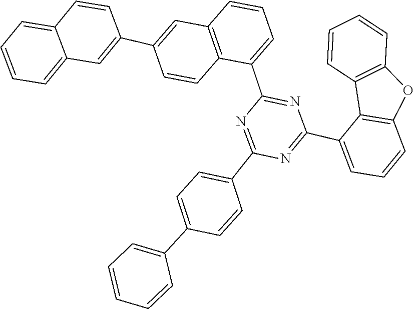 [SMILES: c1ccc(-c2ccc(-c3nc(-c4cccc5cc(-c6ccc7ccccc7c6)ccc45)nc(-c4cccc5oc6ccccc6c45)n3)cc2)cc1] M-423 | 68 |
| Ex- am- ple 11 | 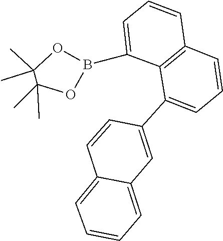 [SMILES: CC1(C)OB(c2cccc3cccc(-c4ccc5ccccc5c4)c23)OC1(C)C] M442-A | 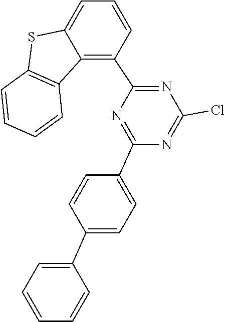 [SMILES: Clc1nc(-c2ccc(-c3ccccc3)cc2)nc(-c2cccc3sc4ccccc4c23)n1] M442-B | 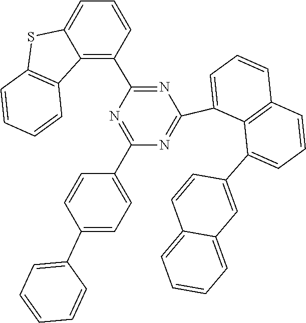 [SMILES: c1ccc(-c2ccc(-c3nc(-c4cccc5cccc(-c6ccc7ccccc7c6)c45)nc(-c4cccc5sc6ccccc6c45)n3)cc2)cc1] M-442 | 72 |
| Ex- am- ple 12 | 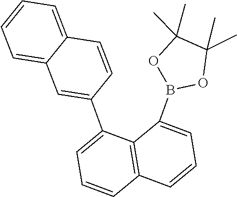 [SMILES: CC1(C)OB(c2cccc3cccc(-c4ccc5ccccc5c4)c23)OC1(C)C] M450-A | 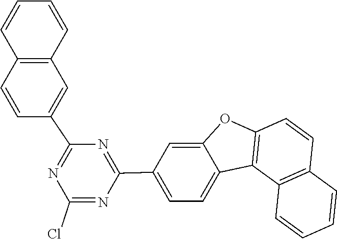 [SMILES: Clc1nc(-c2ccc3ccccc3c2)nc(-c2ccc3c(c2)oc2ccc4ccccc4c23)n1] M450-B | 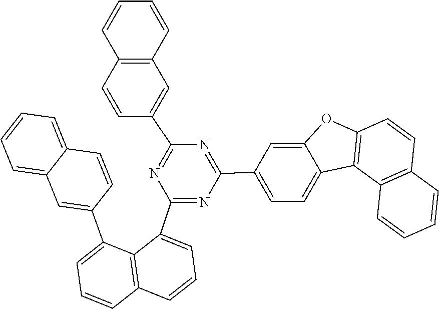 [SMILES: c1ccc2cc(-c3nc(-c4ccc5c(c4)oc4ccc6ccccc6c45)nc(-c4cccc5cccc(-c6ccc7ccccc7c6)c45)n3)ccc2c1] M-450 | 71 |
| Ex- am- ple 13 | 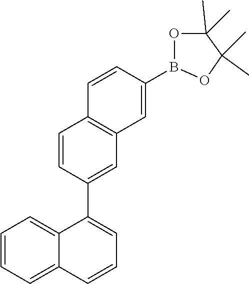 [SMILES: CC1(C)OB(c2ccc3ccc(-c4cccc5ccccc45)cc3c2)OC1(C)C] M460-A | 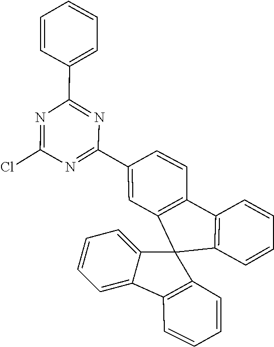 [SMILES: Clc1nc(-c2ccccc2)nc(-c2ccc3c(c2)C2(c4ccccc4-c4ccccc42)c2ccccc2-3)n1] M460-B | 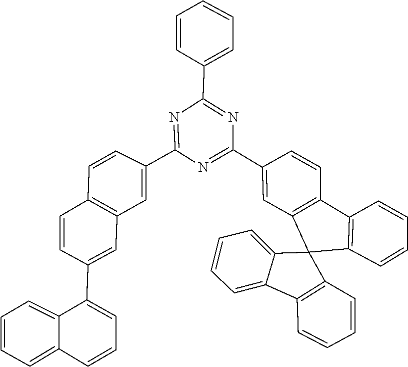 [SMILES: c1ccc(-c2nc(-c3ccc4c(c3)C3(c5ccccc5-c5ccccc53)c3ccccc3-4)nc(-c3ccc4ccc(-c5cccc6ccccc56)cc4c3)n2)cc1] M-460 | 68 |
| Ex- am- ple 14 | 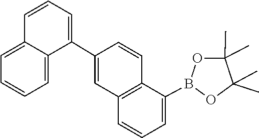 [SMILES: CC1(C)OB(c2cccc3cc(-c4cccc5ccccc45)ccc23)OC1(C)C] M461-A | 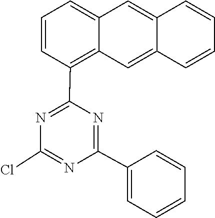 [SMILES: Clc1nc(-c2ccccc2)nc(-c2cccc3cc4ccccc4cc23)n1] M461-B | 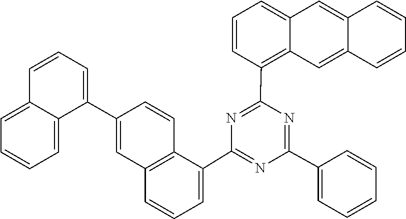 [SMILES: c1ccc(-c2nc(-c3cccc4cc(-c5cccc6ccccc56)ccc34)nc(-c3cccc4cc5ccccc5cc34)n2)cc1] M-461 | 65 |
| Ex- am- ple 15 | 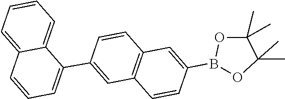 [SMILES: CC1(C)OB(c2ccc3cc(-c4cccc5ccccc45)ccc3c2)OC1(C)C] M480-A | 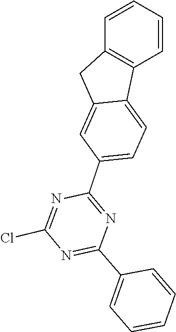 [SMILES: Clc1nc(-c2ccccc2)nc(-c2ccc3c(c2)Cc2ccccc2-3)n1] M480-B | 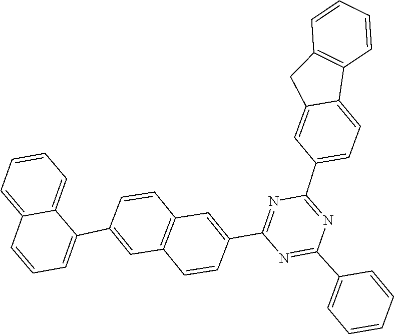 [SMILES: c1ccc(-c2nc(-c3ccc4c(c3)Cc3ccccc3-4)nc(-c3ccc4cc(-c5cccc6ccccc56)ccc4c3)n2)cc1] M-480 | 72 |
| Ex- am- ple 16 | 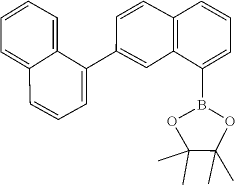 [SMILES: CC1(C)OB(c2cccc3ccc(-c4cccc5ccccc45)cc23)OC1(C)C] M502-A | 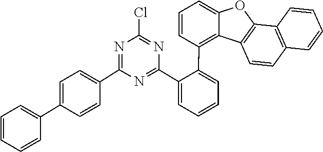 [SMILES: Clc1nc(-c2ccc(-c3ccccc3)cc2)nc(-c2ccccc2-c2cccc3oc4c5ccccc5ccc4c23)n1] M502-B | 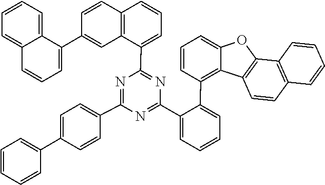 [SMILES: c1ccc(-c2ccc(-c3nc(-c4ccccc4-c4cccc5oc6c7ccccc7ccc6c45)nc(-c4cccc5ccc(-c6cccc7ccccc67)cc45)n3)cc2)cc1] M-502 | 68 |
| Ex- am- ple 17 | 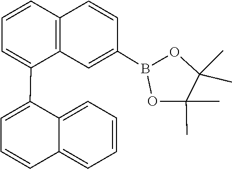 [SMILES: CC1(C)OB(c2ccc3cccc(-c4cccc5ccccc45)c3c2)OC1(C)C] M520-A | 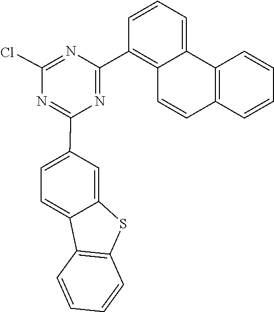 [SMILES: Clc1nc(-c2ccc3c(c2)sc2ccccc23)nc(-c2cccc3c2ccc2ccccc23)n1] M520-B | 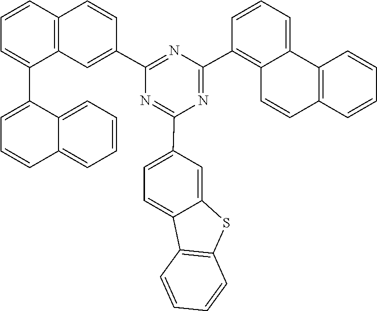 [SMILES: c1ccc2c(-c3cccc4ccc(-c5nc(-c6ccc7c(c6)sc6ccccc67)nc(-c6cccc7c6ccc6ccccc67)n5)cc34)cccc2c1] M-520 | 75 |
| Ex- am- ple 18 | 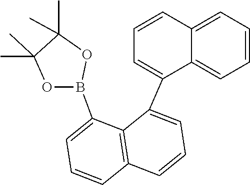 [SMILES: CC1(C)OB(c2cccc3cccc(-c4cccc5ccccc45)c23)OC1(C)C] M526-A | 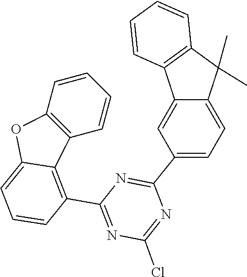 [SMILES: CC1(C)c2ccccc2-c2cc(-c3nc(Cl)nc(-c4cccc5oc6ccccc6c45)n3)ccc21] M526-B | 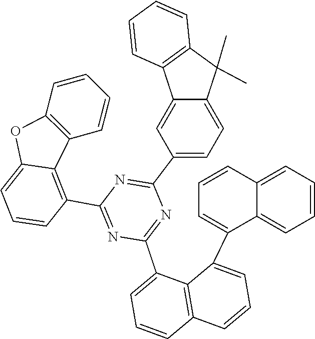 [SMILES: CC1(C)c2ccccc2-c2cc(-c3nc(-c4cccc5cccc(-c6cccc7ccccc67)c45)nc(-c4cccc5oc6ccccc6c45)n3)ccc21] M-526 | 79 |
| Ex- am- ple 19 | 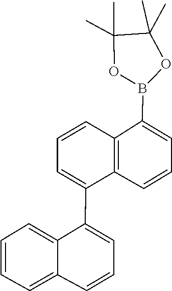 [SMILES: CC1(C)OB(c2cccc3c(-c4cccc5ccccc45)cccc23)OC1(C)C] M537-A | 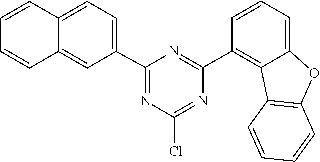 [SMILES: Clc1nc(-c2ccc3ccccc3c2)nc(-c2cccc3oc4ccccc4c23)n1] M537-B | 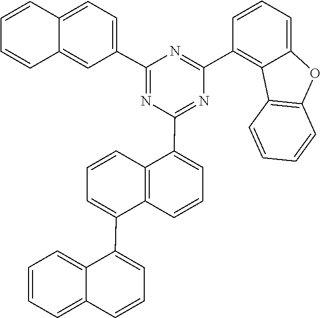 [SMILES: c1ccc2cc(-c3nc(-c4cccc5c(-c6cccc7ccccc67)cccc45)nc(-c4cccc5oc6ccccc6c45)n3)ccc2c1] M-537 | 74 |
| Ex- am- ple 20 | 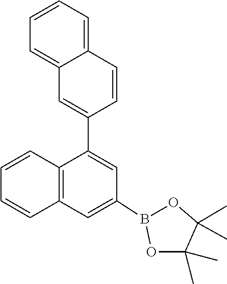 [SMILES: CC1(C)OB(c2cc(-c3ccc4ccccc4c3)c3ccccc3c2)OC1(C)C] M548-A | 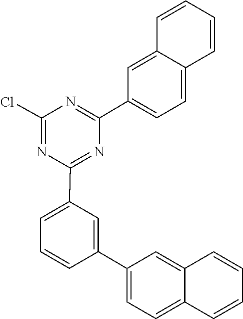 [SMILES: Clc1nc(-c2cccc(-c3ccc4ccccc4c3)c2)nc(-c2ccc3ccccc3c2)n1] M548-B | 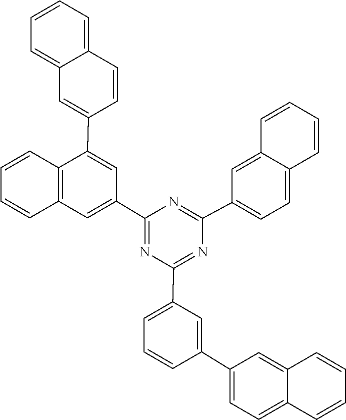 [SMILES: c1cc(-c2ccc3ccccc3c2)cc(-c2nc(-c3ccc4ccccc4c3)nc(-c3cc(-c4ccc5ccccc5c4)c4ccccc4c3)n2)c1] M-548 | 63 |
| Ex- am- ple 21 | 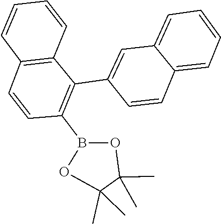 [SMILES: CC1(C)OB(c2ccc3ccccc3c2-c2ccc3ccccc3c2)OC1(C)C] M562-A | 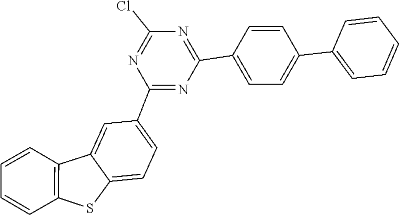 [SMILES: Clc1nc(-c2ccc(-c3ccccc3)cc2)nc(-c2ccc3sc4ccccc4c3c2)n1] M562-B | 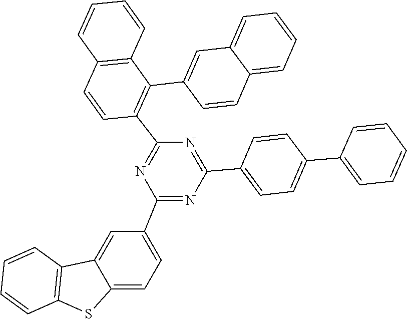 [SMILES: c1ccc(-c2ccc(-c3nc(-c4ccc5sc6ccccc6c5c4)nc(-c4ccc5ccccc5c4-c4ccc5ccccc5c4)n3)cc2)cc1] M-562 | 77 |
| Ex- am- ple 22 | 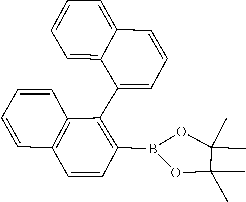 [SMILES: CC1(C)OB(c2ccc3ccccc3c2-c2cccc3ccccc23)OC1(C)C] M572-A | 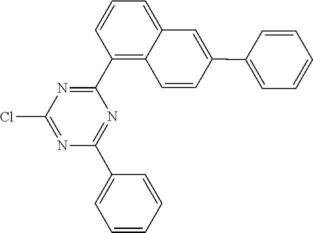 [SMILES: Clc1nc(-c2ccccc2)nc(-c2cccc3cc(-c4ccccc4)ccc23)n1] M572-B | 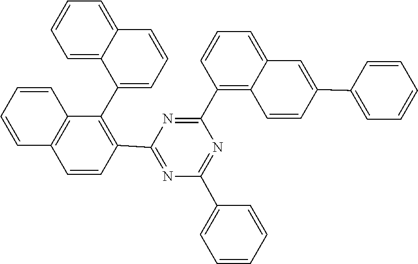 [SMILES: c1ccc(-c2ccc3c(-c4nc(-c5ccccc5)nc(-c5ccc6ccccc6c5-c5cccc6ccccc56)n4)cccc3c2)cc1] M-572 | 70 |
| Ex- am- ple 23 | 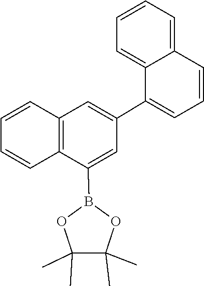 [SMILES: CC1(C)OB(c2cc(-c3cccc4ccccc34)cc3ccccc23)OC1(C)C] M579-A | 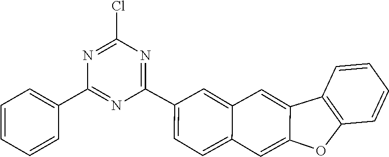 [SMILES: Clc1nc(-c2ccccc2)nc(-c2ccc3cc4oc5ccccc5c4cc3c2)n1] M579-B | 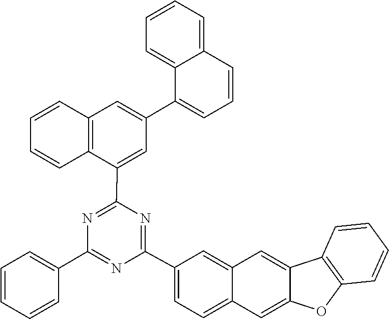 [SMILES: c1ccc(-c2nc(-c3ccc4cc5oc6ccccc6c5cc4c3)nc(-c3cc(-c4cccc5ccccc45)cc4ccccc34)n2)cc1] M-579 | 75 |
| Ex- am- ple 24 | 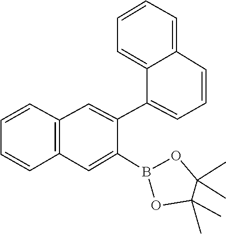 [SMILES: CC1(C)OB(c2cc3ccccc3cc2-c2cccc3ccccc23)OC1(C)C] M584-A | 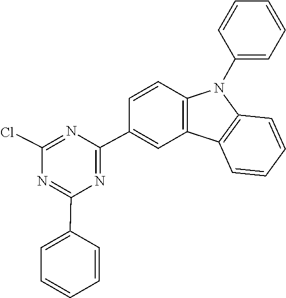 [SMILES: Clc1nc(-c2ccccc2)nc(-c2ccc3c(c2)c2ccccc2n3-c2ccccc2)n1] M584-B | 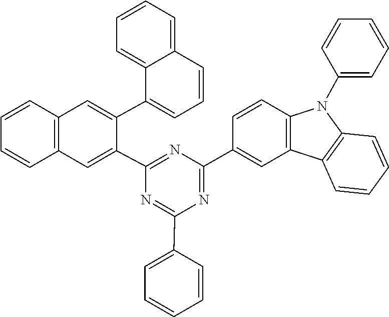 [SMILES: c1ccc(-c2nc(-c3ccc4c(c3)c3ccccc3n4-c3ccccc3)nc(-c3cc4ccccc4cc3-c3cccc4ccccc34)n2)cc1] M-584 | 65 |
| Ex- am- ple 25 | 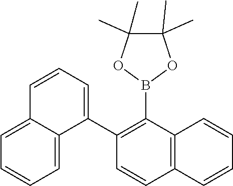 [SMILES: CC1(C)OB(c2c(-c3cccc4ccccc34)ccc3ccccc23)OC1(C)C] M589-A | 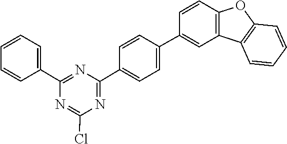 [SMILES: Clc1nc(-c2ccccc2)nc(-c2ccc(-c3ccc4oc5ccccc5c4c3)cc2)n1] M589-B | 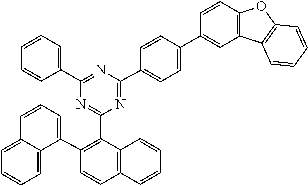 [SMILES: c1ccc(-c2nc(-c3ccc(-c4ccc5oc6ccccc6c5c4)cc3)nc(-c3c(-c4cccc5ccccc45)ccc4ccccc34)n2)cc1] M-589 | 76 |
| Ex- am- ple 26 | 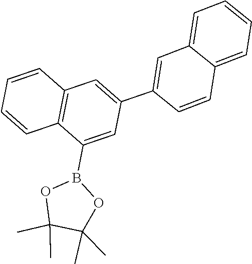 [SMILES: CC1(C)OB(c2cc(-c3ccc4ccccc4c3)cc3ccccc23)OC1(C)C] M599-A | 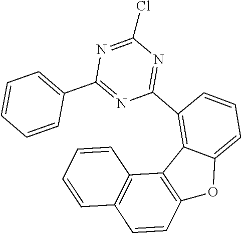 [SMILES: Clc1nc(-c2ccccc2)nc(-c2cccc3oc4ccc5ccccc5c4c23)n1] M599-B | 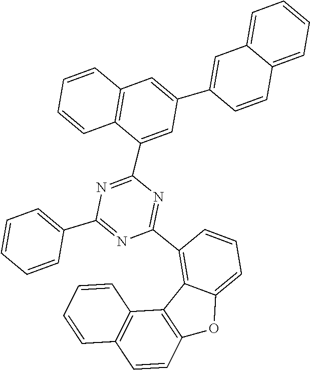 [SMILES: c1ccc(-c2nc(-c3cc(-c4ccc5ccccc5c4)cc4ccccc34)nc(-c3cccc4oc5ccc6ccccc6c5c34)n2)cc1] M-599 | 78 |
| Ex- am- ple 27 | 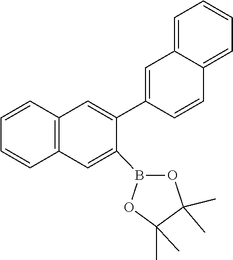 [SMILES: CC1(C)OB(c2cc3ccccc3cc2-c2ccc3ccccc3c2)OC1(C)C] M610-A | 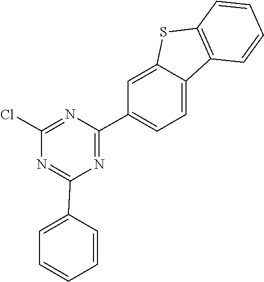 [SMILES: Clc1nc(-c2ccccc2)nc(-c2ccc3c(c2)sc2ccccc23)n1] M610-B | 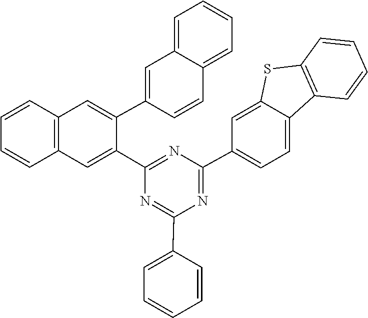 [SMILES: c1ccc(-c2nc(-c3ccc4c(c3)sc3ccccc34)nc(-c3cc4ccccc4cc3-c3ccc4ccccc4c3)n2)cc1] M-610 | 71 |
| Ex- am- ple 28 | 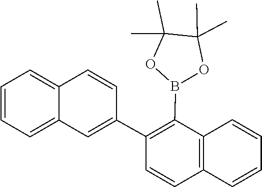 [SMILES: CC1(C)OB(c2c(-c3ccc4ccccc4c3)ccc3ccccc23)OC1(C)C] M611-A | 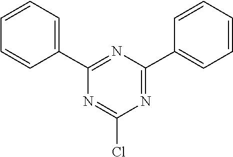 [SMILES: Clc1nc(-c2ccccc2)nc(-c2ccccc2)n1] M611-B | 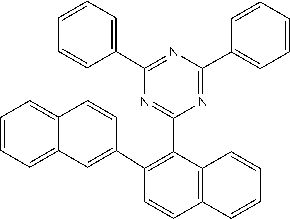 [SMILES: c1ccc(-c2nc(-c3ccccc3)nc(-c3c(-c4ccc5ccccc5c4)ccc4ccccc34)n2)cc1] M-611 | 82 |
| Ex- am- ple 29 | 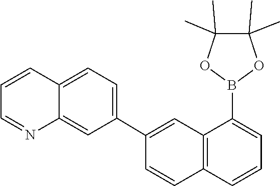 [SMILES: CC1(C)OB(c2cccc3ccc(-c4ccc5cccnc5c4)cc23)OC1(C)C] M308-A | 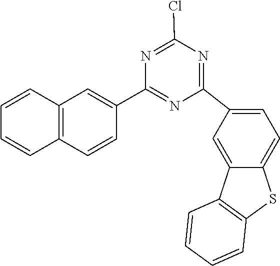 [SMILES: Clc1nc(-c2ccc3ccccc3c2)nc(-c2ccc3sc4ccccc4c3c2)n1] M308-B CAS:875916-80-6 | 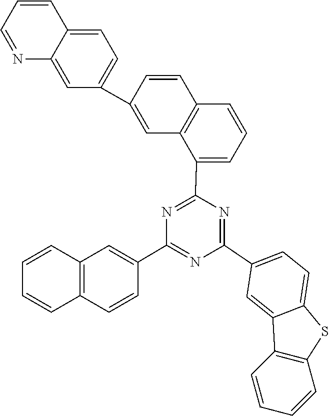 [SMILES: c1ccc2cc(-c3nc(-c4ccc5sc6ccccc6c5c4)nc(-c4cccc5ccc(-c6ccc7cccnc7c6)cc45)n3)ccc2c1] M-308 | 88 |
| Ex- am- ple 30 | 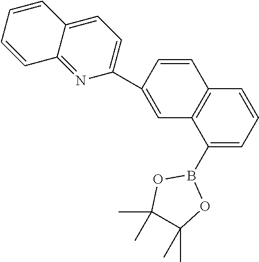 [SMILES: CC1(C)OB(c2cccc3ccc(-c4ccc5ccccc5n4)cc23)OC1(C)C] M365-A | 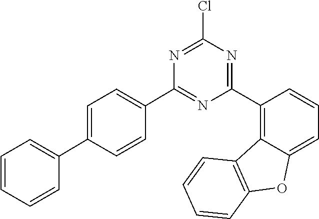 [SMILES: Clc1nc(-c2ccc(-c3ccccc3)cc2)nc(-c2cccc3oc4ccccc4c23)n1] M365-B | 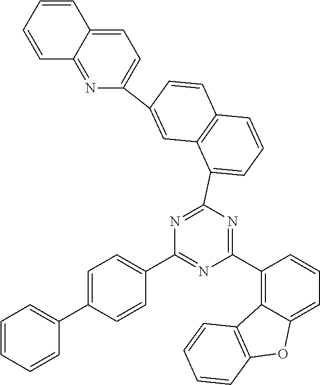 [SMILES: c1ccc(-c2ccc(-c3nc(-c4cccc5ccc(-c6ccc7ccccc7n6)cc45)nc(-c4cccc5oc6ccccc6c45)n3)cc2)cc1] M-365 | 80 |
| Ex- am- ple 31 | 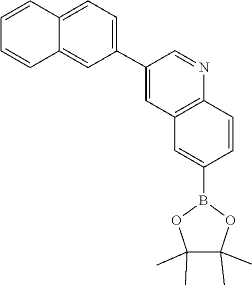 [SMILES: CC1(C)OB(c2ccc3ncc(-c4ccc5ccccc5c4)cc3c2)OC1(C)C] M371-A | 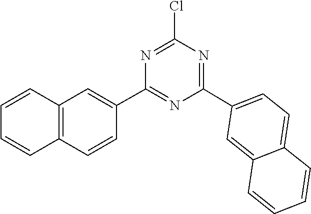 [SMILES: Clc1nc(-c2ccc3ccccc3c2)nc(-c2ccc3ccccc3c2)n1] M371-B | 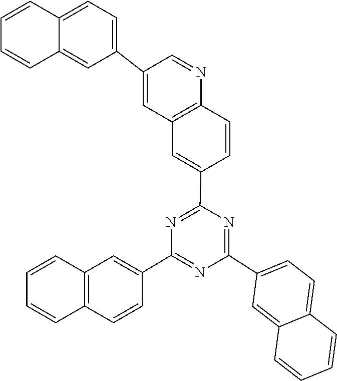 [SMILES: c1ccc2cc(-c3cnc4ccc(-c5nc(-c6ccc7ccccc7c6)nc(-c6ccc7ccccc7c6)n5)cc4c3)ccc2c1] M-371 | 80 |

The product characterization data is shown in Table 2:

TABLE 2

| | | | HRMS (ESI) | |
|---|---|---|---|---|
| | Elemental analysis | | m/z [M + H]+ | |
| Compound | Theoretical | Measured | Theoretical | Measured |
| M-76 | C, 88.32; H, 4.57; N, | C, 88.30; H, 4.57; N, | 815.29 | 816.32 |
| | 5.15; O, 1.96; | 5.17; | | |
| M-108 | C, 85.54; H, 4.38; N, | C, 85.53; H, 4.37; N, | 575.20 | 576.47 |
| | 7.30; O, 2.78; | 7.32; | | |
| M-145 | C, 86.57; H, 4.77; N, | C, 86.56; H, 4.77; N, | 485.19 | 486.33 |
| | 8.65; | 8.67; | | |
| M-253 | C, 88.93; H, 4.72; N, | C, 88.91; H, 4.73; N, | 661.25 | 662.40 |
| | 6.35; | 6.36; | | |
| M-394 | C, 86.38; H, 4.35; N, | C, 86.42; H, 4.34; N, | 625.22 | 626.42 |
| | 6.72; O, 2.56 | 6.68; | | |
| M-412 | C, 88.35; H, 4.78; N, | C, 88.39; H, 4.79; N, | 611.24 | 612.38 |
| | 6.87 | 6.82; | | |
| M-423 | C, 86.61; H, 4.49; N, | C, 86.64; H, 4.52; N, | 651.23 | 656.37 |
| | 6.45; O, 2.45 | 6.39; | | |
| M-442 | C, 84.53; H, 4.38; N, | C, 84.56; H, 4.40; N, | 667.21 | 668.64 |
| | 6.29; S, 4.80 | 6.23; S, 4.81; | | |
| M-450 | C, 87.09; H, 4.33; N, | C, 87.12; H, 4.34; N, | 675.23 | 676.19 |
| | 6.22; O, 2.37 | 6.19; | | |
| M-460 | C, 89.60; H, 4.60; N, | C, 89.64; H, 4.61; N, | 723.27 | 724.57 |
| | 5.80 | 5.75; | | |
| M-461 | C, 88.18; H, 4.65; N, | C, 88.22; H, 4.66; N, | 585.22 | 586.39 |
| | 7.17 | 7.12; | | |
| M-480 | C, 87.93; H, 4.74; N, | C, 87.96; H, 4.77; N, | 573.22 | 574.68 |
| | 7.32 | 7.27; | | |
| M-502 | C, 88.01; H, 4.54; N, | C, 88.06; H, 4.55; N, | 777.28 | 778.45 |
| | 5.40; O, 2.06 | 5.34; | | |
| M-520 | C, 85.07; H, 4.23; N, | C, 85.11; H, 4.24; N, | 691.21 | 692.75 |
| | 6.07; S, 4.63 | 6.02; S, 4.63; | | |
| M-526 | C, 86.81; H, 4.81; N, | C, 86.84; H, 4.83; N, | 691.26 | 692.28 |
| | 6.07; O, 2.31 | 6.02; | | |
| M-537 | C, 86.38; H, 4.35; N, | C, 86.40; H, 4.36; N, | 625.22 | 626.37 |
| | 6.72; O, 2.56 | 6.69; | | |
| M-548 | C, 88.93; H, 4.72; N, | C, 88.96; H, 4.74; N, | 661.25 | 662.48 |
| | 6.35 | 6.30; | | |
| M-562 | C, 84.53; H, 4.38; N, | C, 84.57; H, 4.40; N, | 667.21 | 668.44 |
| | 6.29; S, 4.80 | 6.22; S, 4.81; | | |
| M-572 | C, 88.35; H, 4.78; N, | C, 88.39; H, 4.79; N, | 611.24 | 612.31 |
| | 6.87 | 6.82; | | |
| M-579 | C, 86.38; H, 4.35; N, | C, 86.41; H, 4.36; N, | 625.22 | 626.52 |
| | 6.72; O, 2.56 | 6.68; | | |
| M-584 | C, 86.74; H, 4.65; N, | C, 86.77; H, 4.67; N, | 650.25 | 651.38 |
| | 8.61 | 8.56; | | |
| M-589 | C, 86.61; H, 4.49; N, | C, 86.64; H, 4.51; N, | 651.23 | 652.18 |
| | 6.45; O, 2.45 | 6.40; | | |
| M-599 | C, 86.38; H, 4.35; N, | C, 86.40; H, 4.37; N, | 625.22 | 626.47 |
| | 6.72; O, 2.56 | 6.67; | | |
| M-610 | C, 83.22; H, 4.26; N, | C, 83.25; H, 4.27; N, | 591.18 | 592.04 |
| | 7.10; S, 5.42 | 7.04; S, 5.44; | | |
| M-611 | C, 86.57; H, 4.77; N, | C, 86.60; H, 4.79; N, | 485.19 | 486.66 |
| | 8.65 | 8.61; | | |
| M-308 | C, 82.22; H, 4.08; N, | C, 82.23; H, 4.07; N, | 642.19 | 643.02 |
| | 8.72; S, 4.99; | 8.72; S, 4.98; | | |
| M-365 | C, 84.64; H, 4.32; N, | C, 84.66; H, 4.32; N, | 652.23 | 653.31 |
| | 8.58; O, 2.45; | 8.57; | | |
| M-371 | C, 85.98; H, 4.47; N, | C, 85.99; H, 4.48; N, | 586.22 | 587.77 |
| | 9.55; | 9.53; | | |

### Example 32

The present example provides a method for preparing a compound with N-531 structure in an organic electroluminescent material composition, comprising the following steps:

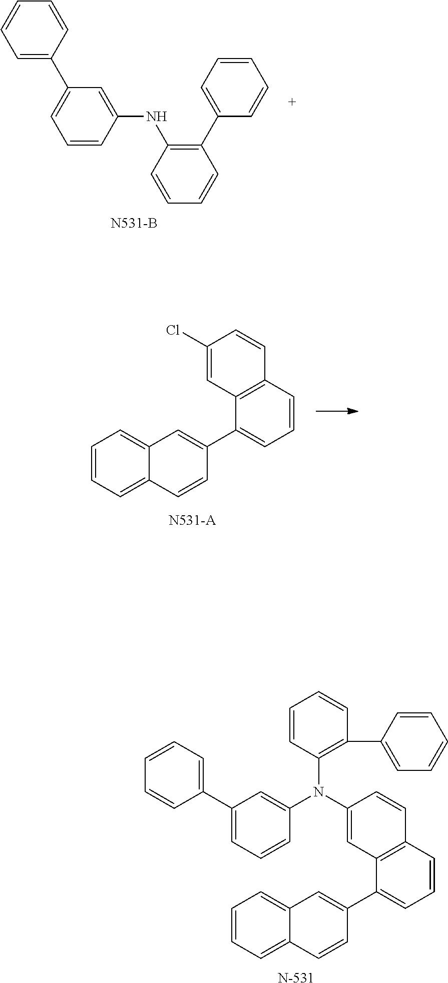

After replacing the air in a three port reaction bottle equipped with mechanical stirrer, thermometer, and condenser tube with nitrogen, intermediate N531-B (10 mmol), intermediate N531-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 20 ml of petroleum ether was added under stirring, the temperature was reduced to 0° C. to 5° C., the material was filtered to obtain compound N-531 with a yield of 78%.

Elemental analysis: C₄₄H₃₁N; theoretical value: C, 92.11; H, 5.45; N, 2.44; measured value: C, 92.10; H, 5.45; N, 2.42; IRMS (ESI) m/z (M+): theoretical value: 573.25; measured value: 574.16.

### Example 33

The present example provides a method for preparing a compound with N-532 structure in an organic material composition, comprising the following steps:

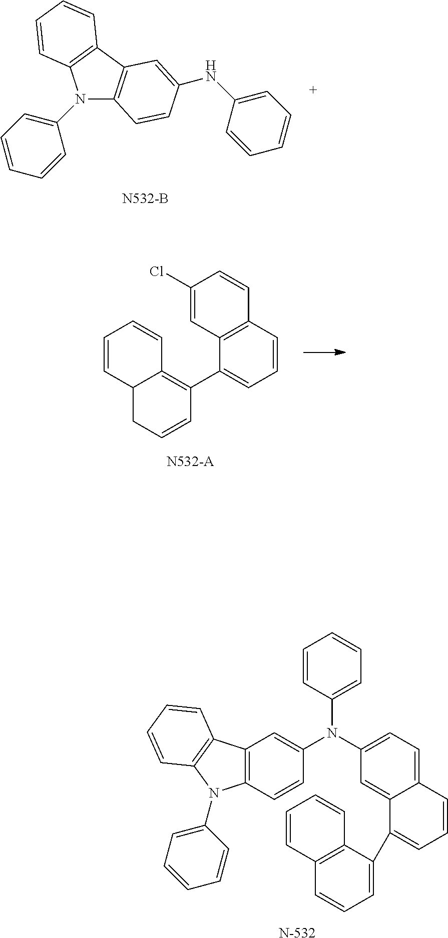

After replacing the air in a three port reaction bottle equipped with mechanical stirrer, thermometer, and condenser tube with nitrogen, intermediate N532-B (10 mmol), intermediate N532-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain compound N-532 with a yield of 71%. m/z=587.1[M+H]⁺.

Elemental analysis: C₄₄H₃₀N₂; theoretical value: C, 90.07; H, 5.15; N, 4.77; measured value: C, 90.10; H, 5.12; N, 4.75; HRMS (ESI) m/z (M+): theoretical value: 586.24; measured value: 587.10.

### Example 34

The present example provides a method for preparing a compound with N-533 structure in an organic electroluminescent material composition, comprising the following steps:

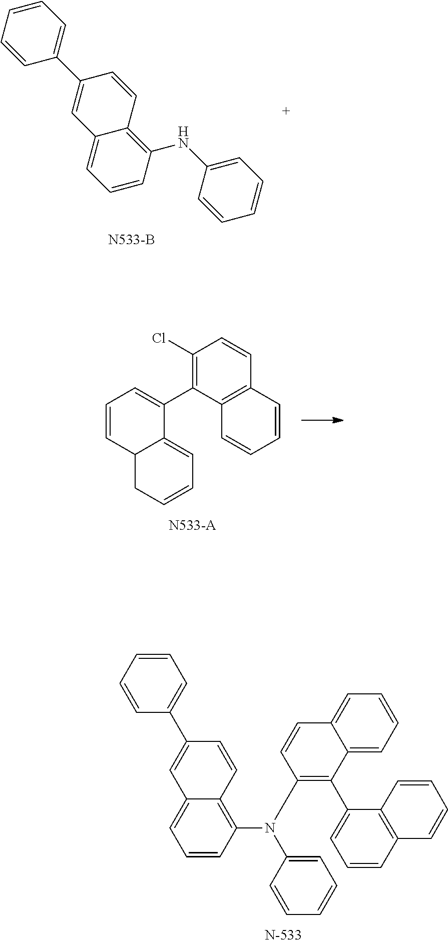

After replacing the air in a three port reaction bottle equipped with mechanical stirrer, thermometer, and condenser tube with nitrogen, intermediate N533-B (10 mmol), intermediate N533-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain compound N-533 with a yield of 73%.

Elemental analysis: C₄₂H₂₉N; theoretical value: C, 92.11; H, 5.34; N, 2.56; measured value: C, 92.10; H, 5.35; N, 2.55; HRMS (ESI) m/z (M+): theoretical value: 547.23; measured value: 548.21.

### Example 35

The present example provides a method for preparing a compound with N-534 structure in an organic electroluminescent material composition, comprising the following steps:

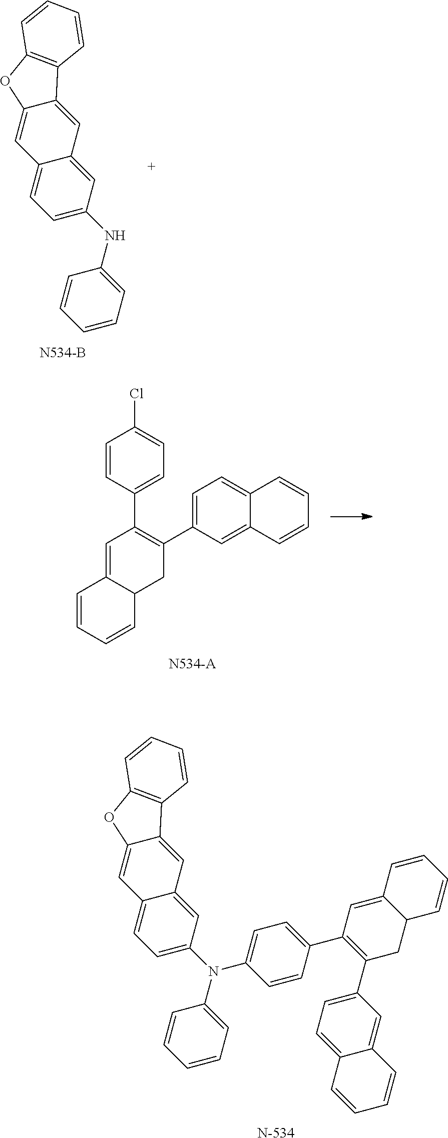

After replacing the air in a three port reaction bottle equipped with mechanical stirrer, thermometer, and condenser tube with nitrogen, intermediate N534-B (10 mmol), intermediate N534-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain compound N-534 with a yield of 58%.

Elemental analysis: C₄₂H₂₉NO; theoretical value: C, 89.49; H, 5.19; N, 2.48; O, 2.84; measured value: C, 89.47; H, 5.18; N, 2.51; HRMS (ESI) m/z (M+): theoretical value: 563.22; measured value: 564.21.

### Example 36

The present example provides a method for preparing a compound with N-535 structure in an organic electroluminescent material composition, comprising the following steps:

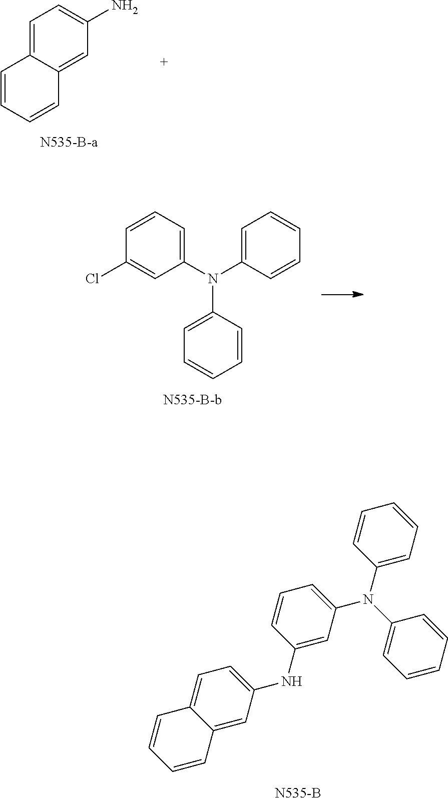

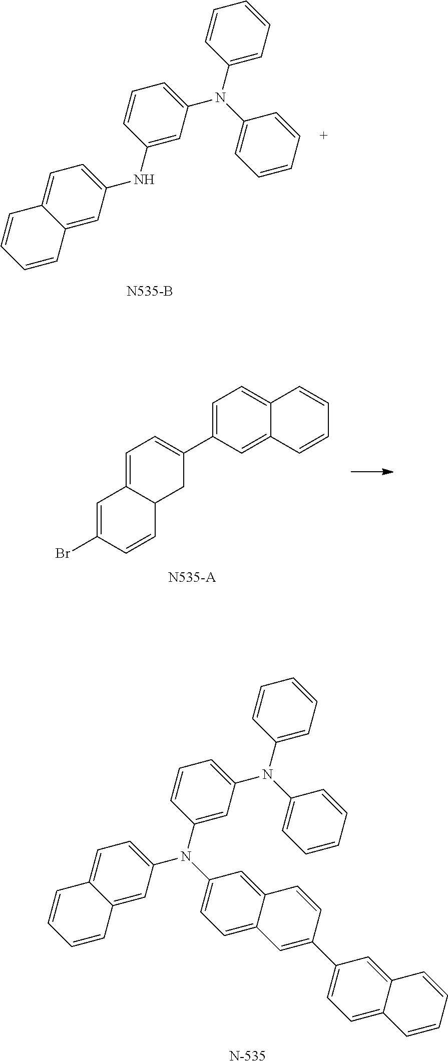 [SMILES: c1ccc(N(c2ccccc2)c2cccc(Nc3ccc4ccccc4c3)c2)cc1 ; "N535-B" ; BrC1=CC2=CC=C(c3ccc4ccccc4c3)CC2C=C1 ; "N535-A" ; c1ccc(N(c2ccccc2)c2cccc(N(c3ccc4ccccc4c3)c3ccc4cc(-c5ccc6ccccc6c5)ccc4c3)c2)cc1 ; "N-535"]

After replacing the air in a three port reaction bottle equipped with mechanical stirrer, thermometer, and condenser tube with nitrogen, the raw material N535-B-a (10.5 mmol), the raw material N535-B-b (10 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain intermediate N535-B with a yield of 74%.

After replacing the air in a three port reaction bottle equipped with mechanical stirrer, thermometer, and condenser tube with nitrogen, intermediate N535-B (10 mmol), intermediate N535-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain compound N-535 with a yield of 65%. m/z=639.28[M+H]⁺.

Elemental analysis: C₄₈H₃₄N₂; theoretical value: C, 90.25; H, 5.36; N, 4.39; measured value: C, 90.26; H, 5.33; N, 4.40; IRMS (ESI) m/z (M+): theoretical value: 638.28; measured value: 639.28.

### Example 37

The present example provides a method for preparing a compound with N-536 structure in an organic electroluminescent material composition, comprising the following steps:

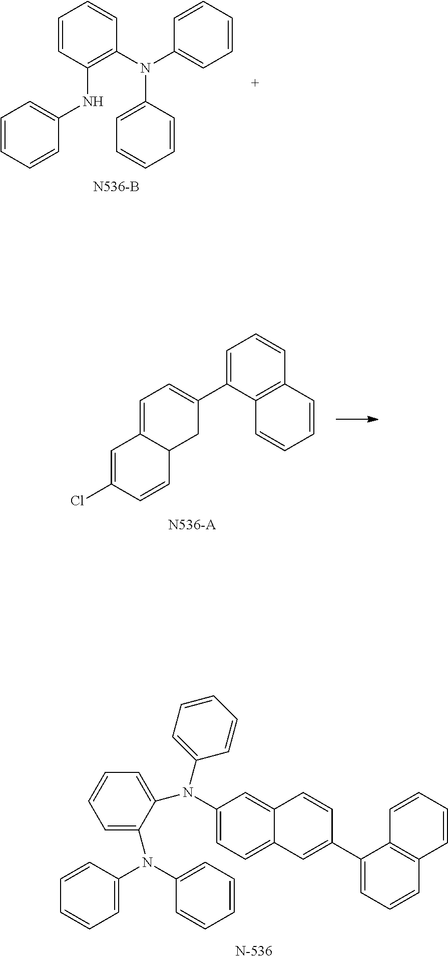

After replacing the air in a three port reaction bottle equipped with mechanical stirrer, thermometer, and condenser tube with nitrogen, intermediate N536-B (10 mmol), intermediate N536-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain compound N-536 with a yield of 34%.

Elemental analysis: C₄₄H₃₂N₂; theoretical value: C, 89.76; H, 5.48; N, 4.76; measured value: C, 89.78; H, 5.46; N, 4.77; IRMS (ESI) m/z (M+): theoretical value: 588.26; measured value: 589.46.

### Example 38

The present example provides a method for preparing a compound with N-537 structure in an organic electroluminescent material composition, comprising the following steps:

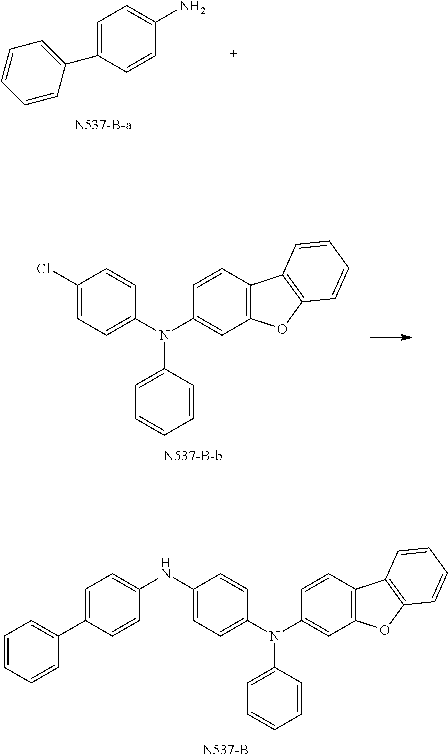

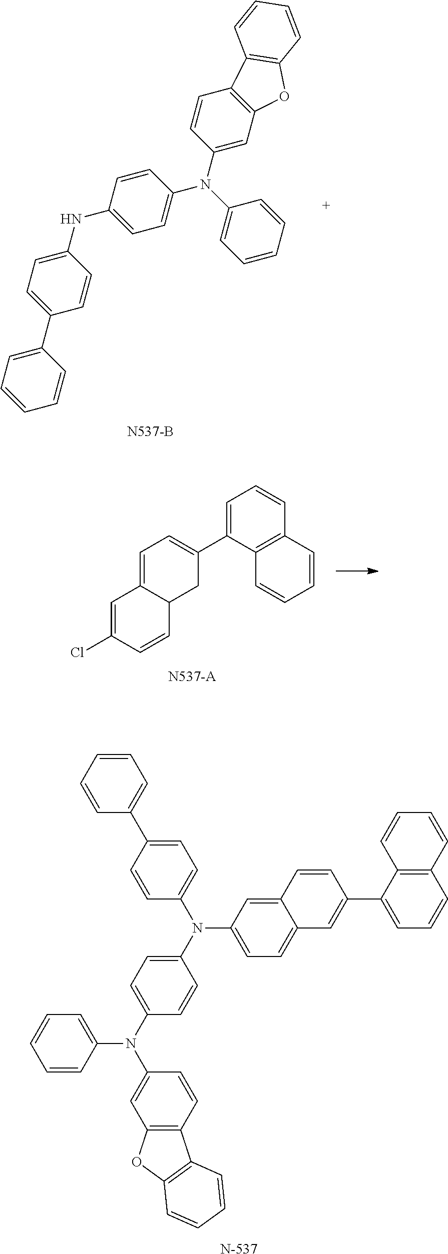

After replacing the air in a three port reaction bottle equipped with mechanical stirrer, thermometer, and condenser tube with nitrogen, raw material N537-B-a (10.5 mmol), intermediate N537-B-b (10 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of toluene was added under stirring, the material was filtered at room temperature and the crystallization process was repeated twice to obtain intermediate N537-B with a yield of 46%.

After replacing the air in a three port reaction bottle equipped with mechanical stirrer, thermometer, and condenser tube with nitrogen, intermediate N537-B (10 mmol), intermediate N537-A (11 mmol), and toluene (100 ml) were added sequentially, then heated and refluxed to separate water for 0.5 hours, the temperature was reduced to 70° C. to 80° C., sodium tert butanol (15 mmol), Pd₂(dba)₃ (0.05 mmol), and s-phos (0.1 mmol) were added slowly, and waited for the system to stabilize before heating to 100° C. to 110° C. and reacted for 3 hours. The temperature was reduced to 25° C. to 30° C., 100 ml of water and 100 ml of toluene were added, stirred to separate the liquid, the aqueous phase was extracted once with 100 ml of toluene, the liquid was separated, and the organic phase was merged, 7 g of anhydrous sodium sulfate was added into the organic phase, stirred, dried and filtered. The organic phase was concentrated (−0.08 MPa to 0.09 MPa, 55° C. to 60° C.) until no liquid flows out. 40 ml of n-hexane was added under stirring, the material was filtered at room temperature to obtain compound N-537 with a yield of 46%. m/z=755.30 [M+H]⁺.

Elemental analysis: C₅₆H₃₈N₂O; theoretical value: C, 89.10; H, 5.07; N, 3.71; 0, 2.12; measured value: C, 89.12; H, 5.08; N, 3.70; HRMS (ESI) m/z (M+): theoretical value: 754.30; measured value: 755.41.

The synthesis conditions of the compounds in the following examples were the same as those of N-531 or N-532, and the differences were that the raw material N-nA, the raw material N-nB and the structures and yields of products were different, which are specifically shown in Table 3 below; and the elemental analysis results of the prepared compounds were shown in Table 4.

TABLE 3

| Ex- | | | | |
|---|---|---|---|---|
| am- | Raw material | | | Yield |
| ple | Nn-B | Raw material Nn-A | Products | % |
| 39 | 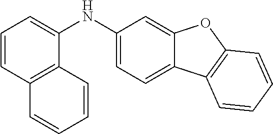 [SMILES: c1ccc2c(Nc3ccc4c(c3)oc3ccccc34)cccc2c1] N4-B | 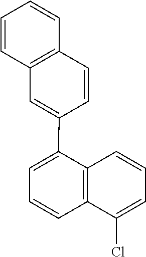 [SMILES: Clc1cccc2c(-c3ccc4ccccc4c3)cccc12] N4-A | 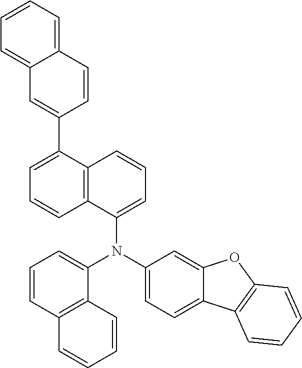 [SMILES: c1ccc2cc(-c3cccc4c(N(c5ccc6c(c5)oc5ccccc56)c5cccc6ccccc56)cccc34)ccc2c1] N-4 | 72 |
| 40 | 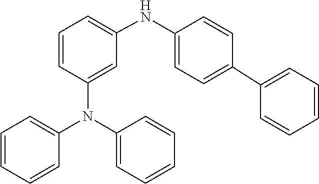 [SMILES: c1ccc(-c2ccc(Nc3cccc(N(c4ccccc4)c4ccccc4)c3)cc2)cc1] N11-B | 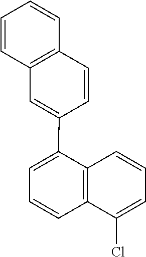 [SMILES: Clc1cccc2c(-c3ccc4ccccc4c3)cccc12] N4-A | 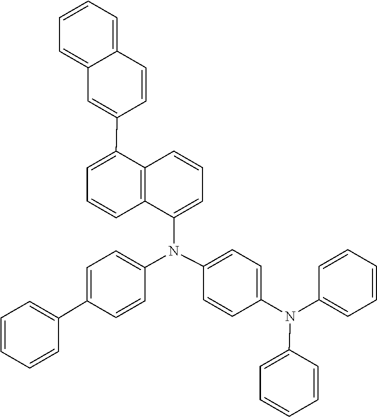 [SMILES: c1ccc(-c2ccc(N(c3ccc(N(c4ccccc4)c4ccccc4)cc3)c3cccc4c(-c5ccc6ccccc6c5)cccc34)cc2)cc1] N-11 | 78 |
| 41 | 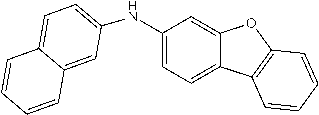 [SMILES: c1ccc2cc(Nc3ccc4c(c3)oc3ccccc34)ccc2c1] N17-B | 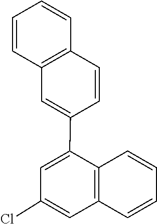 [SMILES: Clc1cc(-c2ccc3ccccc3c2)c2ccccc2c1] N17-A | 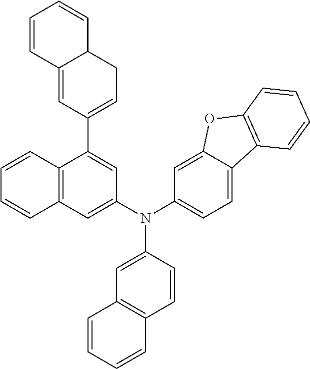 [SMILES: C1=CC2=CC(c3cc(N(c4ccc5ccccc5c4)c4ccc5c(c4)oc4ccccc45)cc4ccccc34)=CCC2C=C1] N-17 | 75 |
| 42 | 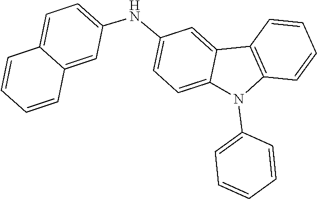 [SMILES: c1ccc(-n2c3ccccc3c3cc(Nc4ccc5ccccc5c4)ccc32)cc1] N21-B | 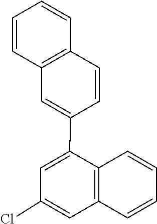 [SMILES: Clc1cc(-c2ccc3ccccc3c2)c2ccccc2c1] N17-A | 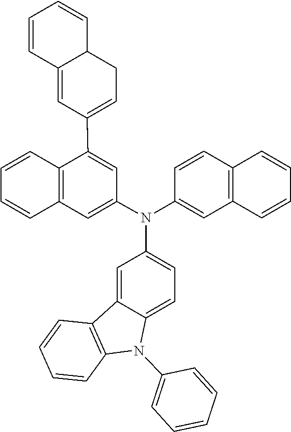 [SMILES: C1=CC2=CC(c3cc(N(c4ccc5ccccc5c4)c4ccc5c(c4)c4ccccc4n5-c4ccccc4)cc4ccccc34)=CCC2C=C1] N-21 | 66 |
| 43 | 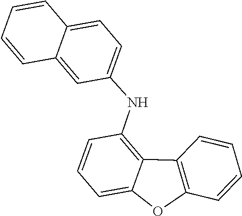 [SMILES: c1ccc2cc(Nc3cccc4oc5ccccc5c34)ccc2c1] N25-B | 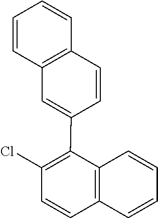 [SMILES: Clc1ccc2ccccc2c1-c1ccc2ccccc2c1] N25-A | 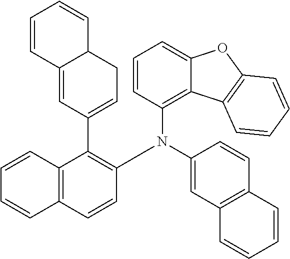 [SMILES: C1=CC2=CC(c3c(N(c4ccc5ccccc5c4)c4cccc5oc6ccccc6c45)ccc4ccccc34)=CCC2C=C1] N-25 | 42 |
| 44 | 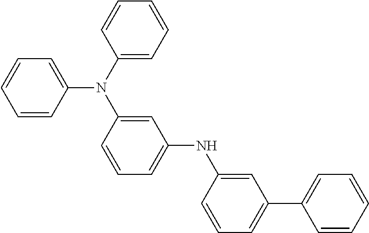 [SMILES: c1ccc(-c2cccc(Nc3cccc(N(c4ccccc4)c4ccccc4)c3)c2)cc1] N28-B | 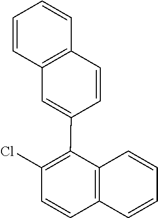 [SMILES: Clc1ccc2ccccc2c1-c1ccc2ccccc2c1] N25-A | 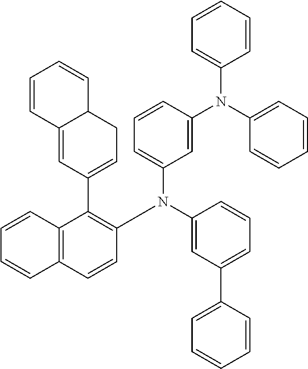 [SMILES: C1=CC2=CC(c3c(N(c4cccc(-c5ccccc5)c4)c4cccc(N(c5ccccc5)c5ccccc5)c4)ccc4ccccc34)=CCC2C=C1] N-28 | 46 |
| 45 | 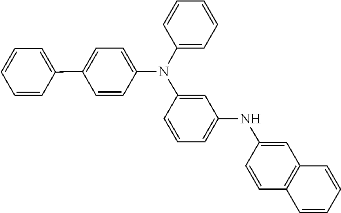 [SMILES: c1ccc(-c2ccc(N(c3ccccc3)c3cccc(Nc4ccc5ccccc5c4)c3)cc2)cc1] N33-B | 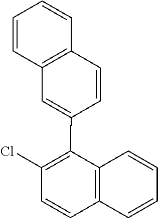 [SMILES: Clc1ccc2ccccc2c1-c1ccc2ccccc2c1] N25-A | 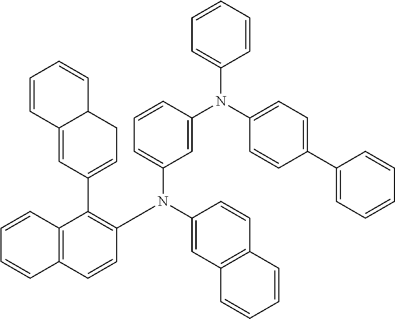 [SMILES: C1=CC2=CC(c3c(N(c4cccc(N(c5ccccc5)c5ccc(-c6ccccc6)cc5)c4)c4ccc5ccccc5c4)ccc4ccccc34)=CCC2C=C1] N-33 | 44 |
| 46 | 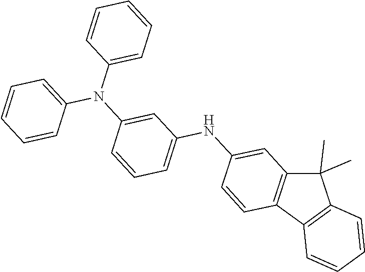 [SMILES: CC1(C)c2ccccc2-c2ccc(Nc3cccc(N(c4ccccc4)c4ccccc4)c3)cc21] N36-B | 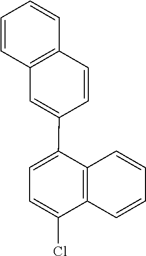 [SMILES: Clc1ccc(-c2ccc3ccccc3c2)c2ccccc12] N36-A | 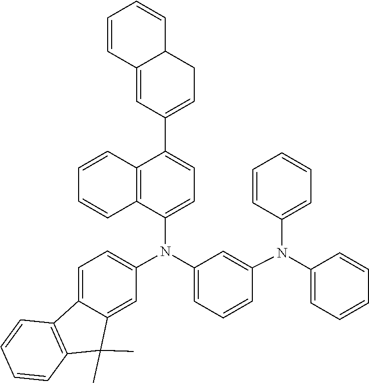 [SMILES: CC1(C)c2ccccc2-c2ccc(N(c3cccc(N(c4ccccc4)c4ccccc4)c3)c3ccc(C4=CCC5C=CC=CC5=C4)c4ccccc34)cc21] N-36 | 68 |
| 47 | 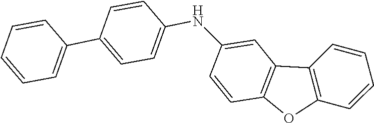 [SMILES: c1ccc(-c2ccc(Nc3ccc4oc5ccccc5c4c3)cc2)cc1] N45-B | 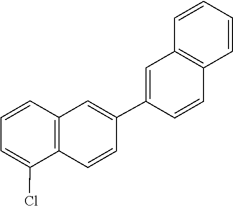 [SMILES: Clc1cccc2cc(-c3ccc4ccccc4c3)ccc12] N45-A | 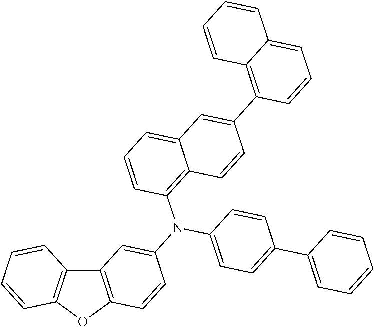 [SMILES: c1ccc(-c2ccc(N(c3ccc4oc5ccccc5c4c3)c3cccc4cc(-c5cccc6ccccc56)ccc34)cc2)cc1] N-45 | 76 |
| 48 | 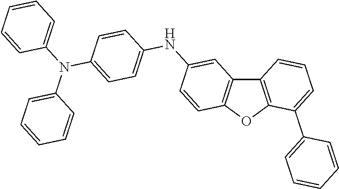 [SMILES: c1ccc(-c2cccc3c2oc2ccc(Nc4ccc(N(c5ccccc5)c5ccccc5)cc4)cc23)cc1] N48-B | 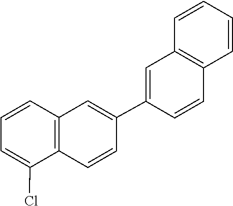 [SMILES: Clc1cccc2cc(-c3ccc4ccccc4c3)ccc12] N45-A | 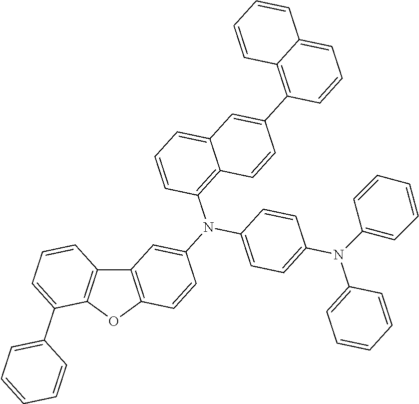 [SMILES: c1ccc(-c2cccc3c2oc2ccc(N(c4ccc(N(c5ccccc5)c5ccccc5)cc4)c4cccc5cc(-c6cccc7ccccc67)ccc45)cc23)cc1] N-48 | 55 |
| 49 | 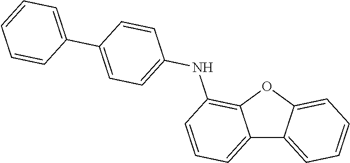 [SMILES: c1ccc(-c2ccc(Nc3cccc4c3oc3ccccc34)cc2)cc1] N55-B | 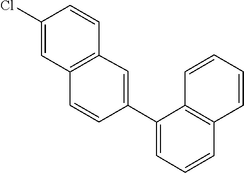 [SMILES: Clc1ccc2cc(-c3cccc4ccccc34)ccc2c1] N55-A | 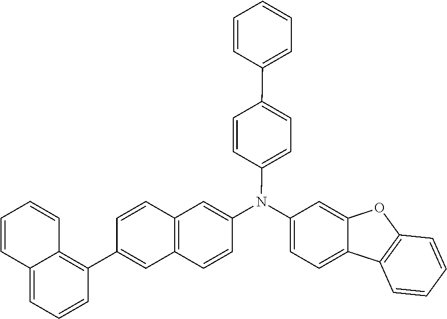 [SMILES: c1ccc(-c2ccc(N(c3ccc4cc(-c5cccc6ccccc56)ccc4c3)c3ccc4c(c3)oc3ccccc34)cc2)cc1] N-55 | 70 |
| 50 | 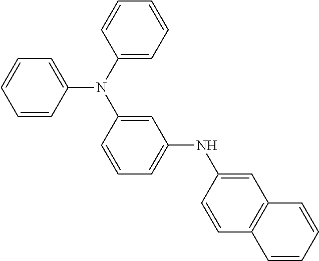 [SMILES: c1ccc(N(c2ccccc2)c2cccc(Nc3ccc4ccccc4c3)c2)cc1] N63-B | 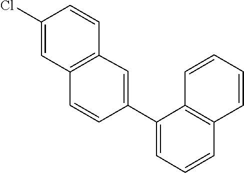 [SMILES: Clc1ccc2cc(-c3cccc4ccccc34)ccc2c1] N55-A | 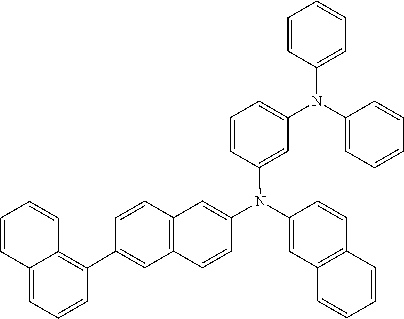 [SMILES: c1ccc(N(c2ccccc2)c2cccc(N(c3ccc4ccccc4c3)c3ccc4cc(-c5cccc6ccccc56)ccc4c3)c2)cc1] N-63 | 58 |
| 51 | 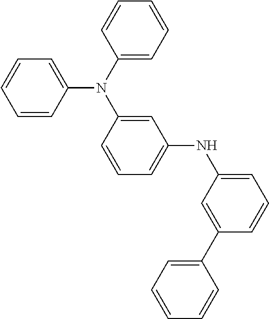 [SMILES: c1ccc(-c2cccc(Nc3cccc(N(c4ccccc4)c4ccccc4)c3)c2)cc1] N65-B | 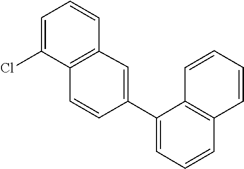 [SMILES: Clc1cccc2cc(-c3cccc4ccccc34)ccc12] N65-A | 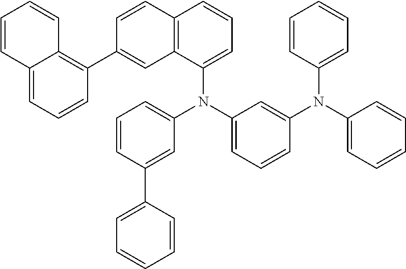 [SMILES: c1ccc(-c2cccc(N(c3cccc(N(c4ccccc4)c4ccccc4)c3)c3cccc4ccc(-c5cccc6ccccc56)cc34)c2)cc1] N-65 | 64 |
| 52 | 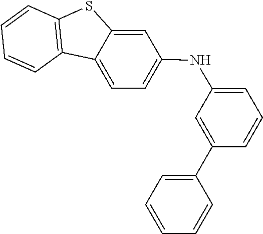 [SMILES: c1ccc(-c2cccc(Nc3ccc4c(c3)sc3ccccc34)c2)cc1] N67-B | 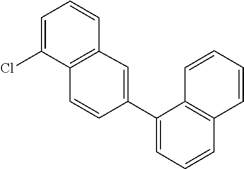 [SMILES: Clc1cccc2cc(-c3cccc4ccccc34)ccc12] N65-A | 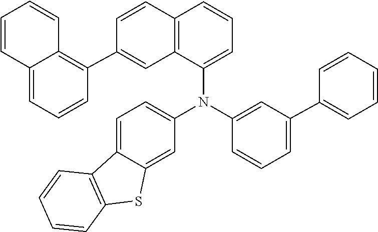 [SMILES: c1ccc(-c2cccc(N(c3ccc4c(c3)sc3ccccc34)c3cccc4ccc(-c5cccc6ccccc56)cc34)c2)cc1] N-67 | 68 |
| 53 | 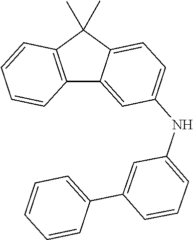 [SMILES: CC1(C)c2ccccc2-c2cc(Nc3cccc(-c4ccccc4)c3)ccc21] N71-B | 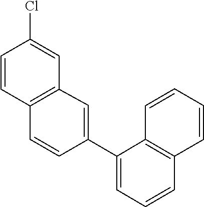 [SMILES: Clc1ccc2ccc(-c3cccc4ccccc34)cc2c1] N71-A | 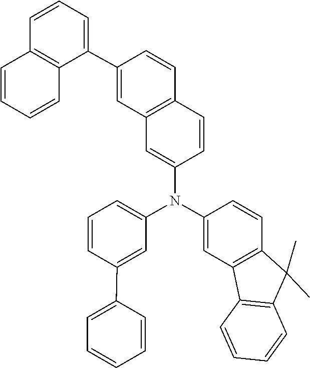 [SMILES: CC1(C)c2ccccc2-c2cc(N(c3cccc(-c4ccccc4)c3)c3ccc4ccc(-c5cccc6ccccc56)cc4c3)ccc21] N-71 | 72 |
| 54 | 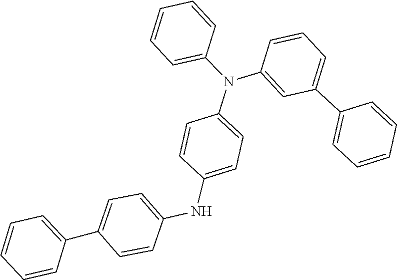 [SMILES: c1ccc(-c2ccc(Nc3ccc(N(c4ccccc4)c4cccc(-c5ccccc5)c4)cc3)cc2)cc1] N77-B | 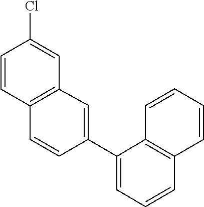 [SMILES: Clc1ccc2ccc(-c3cccc4ccccc34)cc2c1] N71-A | 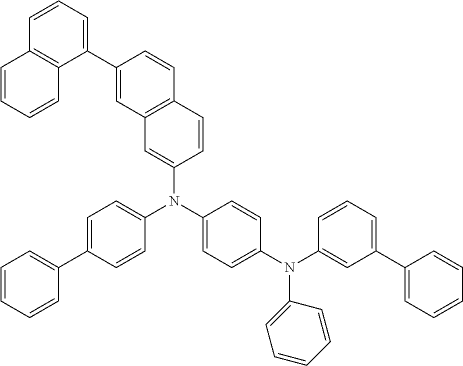 [SMILES: c1ccc(-c2ccc(N(c3ccc(N(c4ccccc4)c4cccc(-c5ccccc5)c4)cc3)c3ccc4ccc(-c5cccc6ccccc56)cc4c3)cc2)cc1] N-77 | 67 |
| 55 | 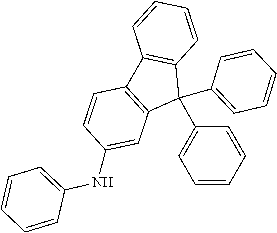 [SMILES: c1ccc(Nc2ccc3c(c2)C(c2ccccc2)(c2ccccc2)c2ccccc2-3)cc1] N85-B | 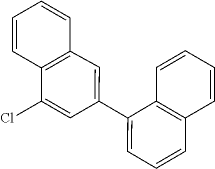 [SMILES: Clc1cc(-c2cccc3ccccc23)cc2ccccc12] N85-A | 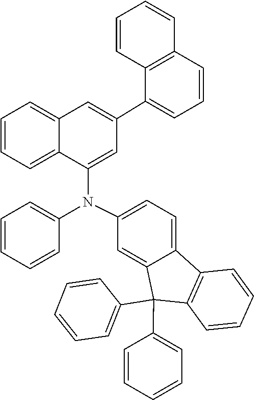 [SMILES: c1ccc(N(c2ccc3c(c2)C(c2ccccc2)(c2ccccc2)c2ccccc2-3)c2cc(-c3cccc4ccccc34)cc3ccccc23)cc1] N-85 | 55 |
| 56 | 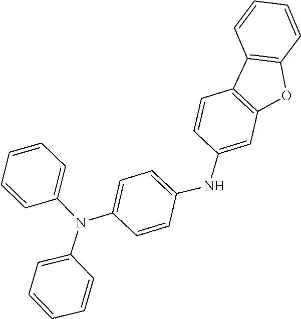 [SMILES: c1ccc(N(c2ccccc2)c2ccc(Nc3ccc4c(c3)oc3ccccc34)cc2)cc1] N87-B | 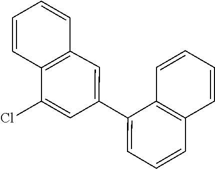 [SMILES: Clc1cc(-c2cccc3ccccc23)cc2ccccc12] N85-A | 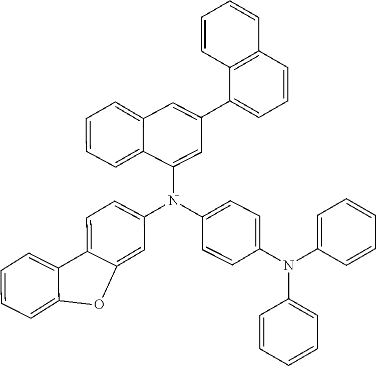 [SMILES: c1ccc(N(c2ccccc2)c2ccc(N(c3ccc4c(c3)oc3ccccc34)c3cc(-c4cccc5ccccc45)cc4ccccc34)cc2)cc1] N-87 | 53 |
| 57 | 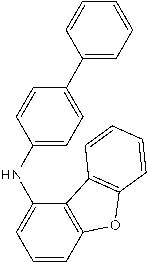 [SMILES: c1ccc(-c2ccc(Nc3cccc4oc5ccccc5c34)cc2)cc1] N91-B | 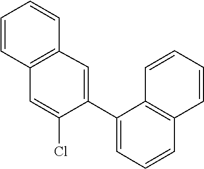 [SMILES: Clc1cc2ccccc2cc1-c1cccc2ccccc12] N91-A | 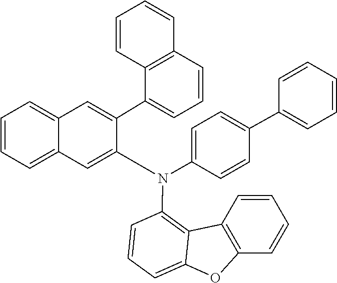 [SMILES: c1ccc(-c2ccc(N(c3cc4ccccc4cc3-c3cccc4ccccc34)c3cccc4oc5ccccc5c34)cc2)cc1] N-91 | 43 |
| 58 | 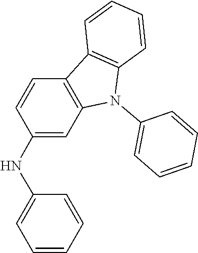 [SMILES: c1ccc(Nc2ccc3c4ccccc4n(-c4ccccc4)c3c2)cc1] N92-B | 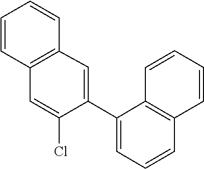 [SMILES: Clc1cc2ccccc2cc1-c1cccc2ccccc12] N92-A | 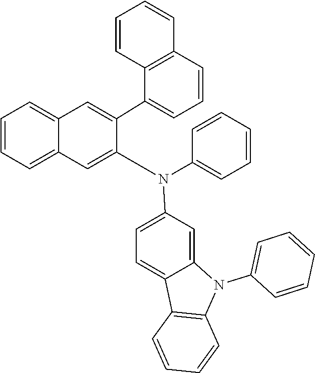 [SMILES: c1ccc(N(c2ccc3c4ccccc4n(-c4ccccc4)c3c2)c2cc3ccccc3cc2-c2cccc3ccccc23)cc1] N-92 | 56 |
| 59 | 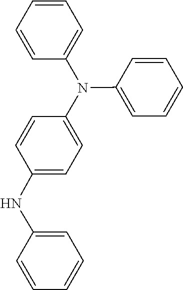 [SMILES: c1ccc(Nc2ccc(N(c3ccccc3)c3ccccc3)cc2)cc1] N99-B | 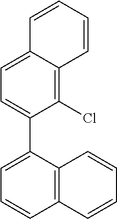 [SMILES: Clc1c(-c2cccc3ccccc23)ccc2ccccc12] N99-A | 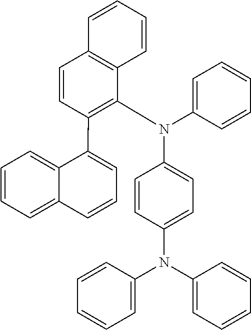 [SMILES: c1ccc(N(c2ccccc2)c2ccc(N(c3ccccc3)c3c(-c4cccc5ccccc45)ccc4ccccc34)cc2)cc1] N-99 | 48 |
| 60 | 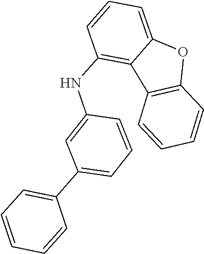 [SMILES: c1ccc(-c2cccc(Nc3cccc4oc5ccccc5c34)c2)cc1] N109-B | 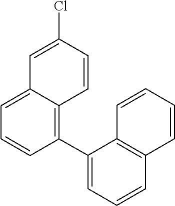 [SMILES: Clc1ccc2c(-c3cccc4ccccc34)cccc2c1] N109-A | 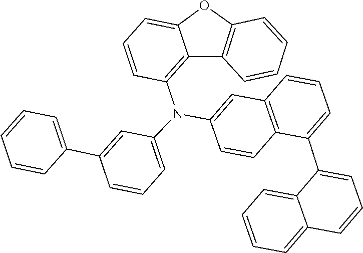 [SMILES: c1ccc(-c2cccc(N(c3ccc4c(-c5cccc6ccccc56)cccc4c3)c3cccc4oc5ccccc5c34)c2)cc1] N-109 | 71 |
| 61 | 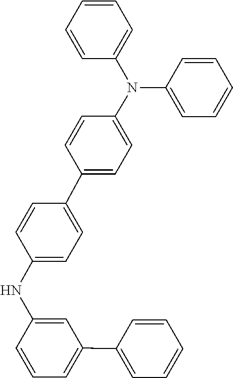 [SMILES: c1ccc(-c2cccc(Nc3ccc(-c4ccc(N(c5ccccc5)c5ccccc5)cc4)cc3)c2)cc1] N112-B | 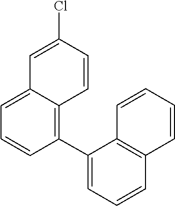 [SMILES: Clc1ccc2c(-c3cccc4ccccc34)cccc2c1] N109-A | 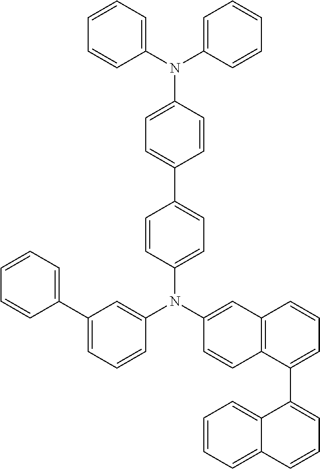 [SMILES: c1ccc(-c2cccc(N(c3ccc(-c4ccc(N(c5ccccc5)c5ccccc5)cc4)cc3)c3ccc4c(-c5cccc6ccccc56)cccc4c3)c2)cc1] N-112 | 69 |
| 62 | 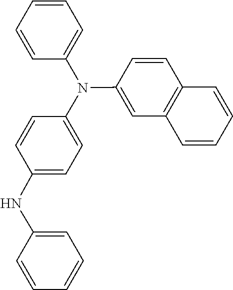 [SMILES: c1ccc(Nc2ccc(N(c3ccccc3)c3ccc4ccccc4c3)cc2)cc1] N119-B | 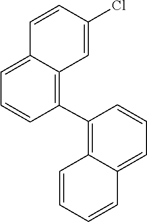 [SMILES: Clc1ccc2cccc(-c3cccc4ccccc34)c2c1] N119-A | 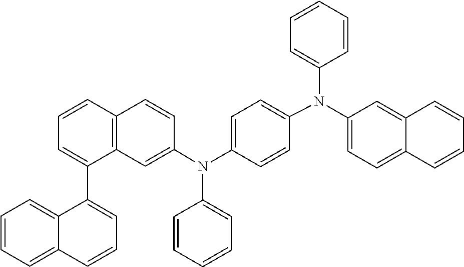 [SMILES: c1ccc(N(c2ccc(N(c3ccccc3)c3ccc4cccc(-c5cccc6ccccc56)c4c3)cc2)c2ccc3ccccc3c2)cc1] N-119 | 66 |
| 63 | 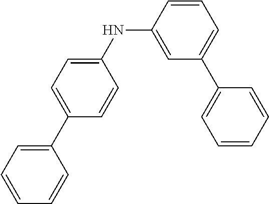 [SMILES: c1ccc(-c2ccc(Nc3cccc(-c4ccccc4)c3)cc2)cc1] N123-B | 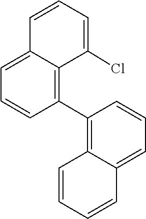 [SMILES: Clc1cccc2cccc(-c3cccc4ccccc34)c12] N123-A | 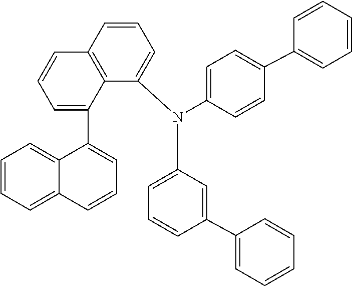 [SMILES: c1ccc(-c2ccc(N(c3cccc(-c4ccccc4)c3)c3cccc4cccc(-c5cccc6ccccc56)c34)cc2)cc1] N-123 | 32 |
| 64 | 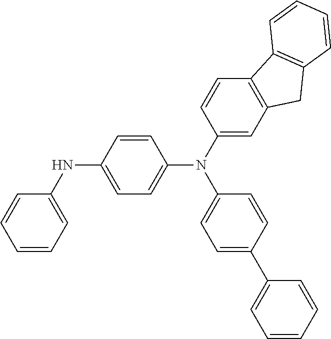 [SMILES: c1ccc(Nc2ccc(N(c3ccc(-c4ccccc4)cc3)c3ccc4c(c3)Cc3ccccc3-4)cc2)cc1] N128-B | 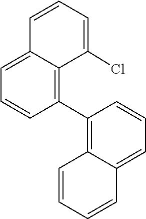 [SMILES: Clc1cccc2cccc(-c3cccc4ccccc34)c12] N123-A | 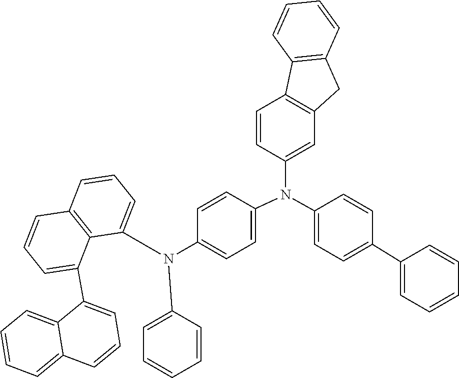 [SMILES: c1ccc(-c2ccc(N(c3ccc(N(c4ccccc4)c4cccc5cccc(-c6cccc7ccccc67)c45)cc3)c3ccc4c(c3)Cc3ccccc3-4)cc2)cc1] N-128 | 28 |
| 65 | 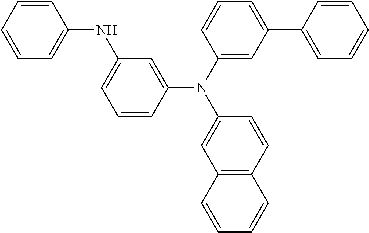 [SMILES: c1ccc(Nc2cccc(N(c3cccc(-c4ccccc4)c3)c3ccc4ccccc4c3)c2)cc1] N134-B | 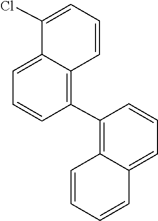 [SMILES: Clc1cccc2c(-c3cccc4ccccc34)cccc12] N134-A | 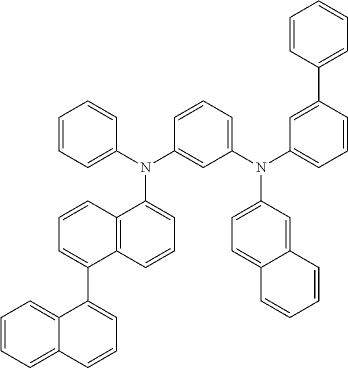 [SMILES: c1ccc(-c2cccc(N(c3cccc(N(c4ccccc4)c4cccc5c(-c6cccc7ccccc67)cccc45)c3)c3ccc4ccccc4c3)c2)cc1] N-134 | 65 |
| 66 | 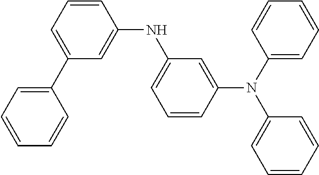 [SMILES: c1ccc(-c2cccc(Nc3cccc(N(c4ccccc4)c4ccccc4)c3)c2)cc1] N139-B | 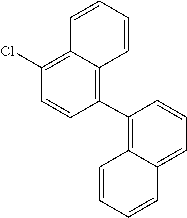 [SMILES: Clc1ccc(-c2cccc3ccccc23)c2ccccc12] N139-A | 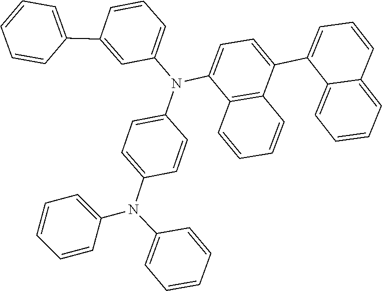 [SMILES: c1ccc(-c2cccc(N(c3ccc(N(c4ccccc4)c4ccccc4)cc3)c3ccc(-c4cccc5ccccc45)c4ccccc34)c2)cc1] N-139 | 67 |
| 67 | 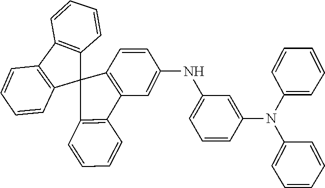 [SMILES: c1ccc(N(c2ccccc2)c2cccc(Nc3ccc4c(c3)-c3ccccc3C43c4ccccc4-c4ccccc43)c2)cc1] N145-B | 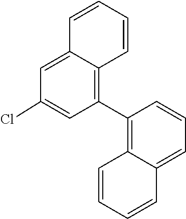 [SMILES: Clc1cc(-c2cccc3ccccc23)c2ccccc2c1] N145-A | 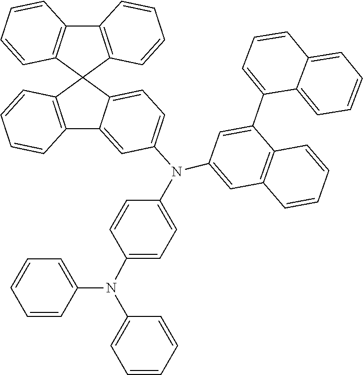 [SMILES: c1ccc(N(c2ccccc2)c2ccc(N(c3ccc4c(c3)-c3ccccc3C43c4ccccc4-c4ccccc43)c3cc(-c4cccc5ccccc45)c4ccccc4c3)cc2)cc1] N-145 | 60 |
| 68 | 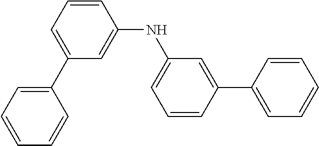 [SMILES: c1ccc(-c2cccc(Nc3cccc(-c4ccccc4)c3)c2)cc1] N151-B | 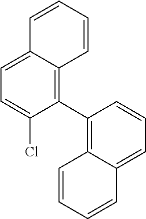 [SMILES: Clc1ccc2ccccc2c1-c1cccc2ccccc12] N151-A | 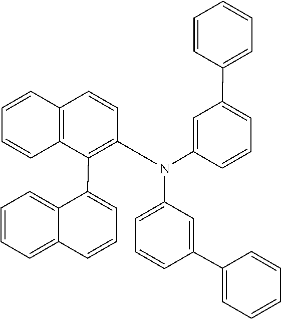 [SMILES: c1ccc(-c2cccc(N(c3cccc(-c4ccccc4)c3)c3ccc4ccccc4c3-c3cccc4ccccc34)c2)cc1] N-151 | 65 |
| 69 | 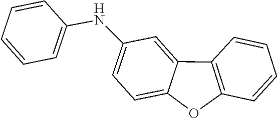 [SMILES: c1ccc(Nc2ccc3oc4ccccc4c3c2)cc1] N175-B | 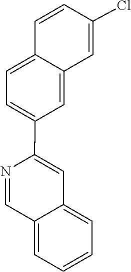 [SMILES: Clc1ccc2ccc(-c3cc4ccccc4cn3)cc2c1] N175-A | 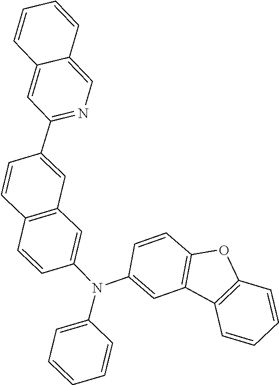 [SMILES: c1ccc(N(c2ccc3ccc(-c4cc5ccccc5cn4)cc3c2)c2ccc3oc4ccccc4c3c2)cc1] N-175 | 58 |
| 70 | 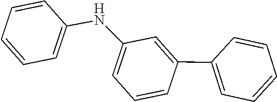 [SMILES: c1ccc(Nc2cccc(-c3ccccc3)c2)cc1] N229-B | 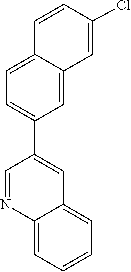 [SMILES: Clc1ccc2ccc(-c3cnc4ccccc4c3)cc2c1] N229-A | 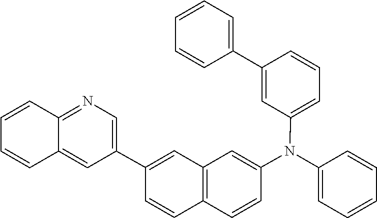 [SMILES: c1ccc(-c2cccc(N(c3ccccc3)c3ccc4ccc(-c5cnc6ccccc6c5)cc4c3)c2)cc1] N-229 | 60 |
| 71 | 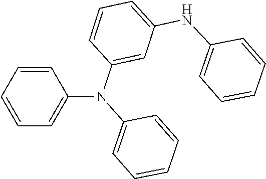 [SMILES: c1ccc(Nc2cccc(N(c3ccccc3)c3ccccc3)c2)cc1] N233-B | 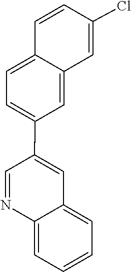 [SMILES: Clc1ccc2ccc(-c3cnc4ccccc4c3)cc2c1] N229-A | 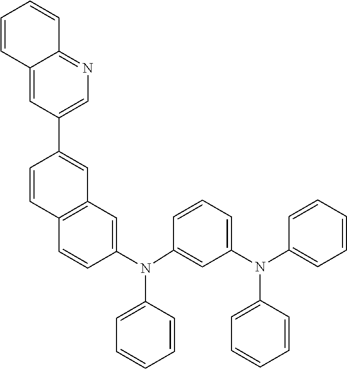 [SMILES: c1ccc(N(c2ccccc2)c2cccc(N(c3ccccc3)c3ccc4ccc(-c5cnc6ccccc6c5)cc4c3)c2)cc1] N-233 | 64 |
| 72 | 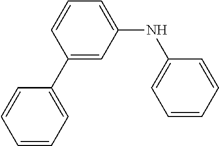 [SMILES: c1ccc(Nc2cccc(-c3ccccc3)c2)cc1] N253-B | 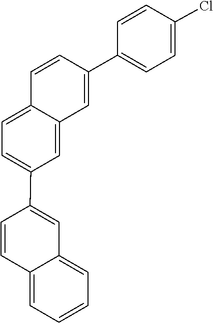 [SMILES: Clc1ccc(-c2ccc3ccc(-c4ccc5ccccc5c4)cc3c2)cc1] N253-A | 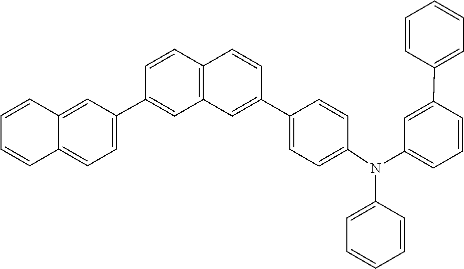 [SMILES: c1ccc(-c2cccc(N(c3ccccc3)c3ccc(-c4ccc5ccc(-c6ccc7ccccc7c6)cc5c4)cc3)c2)cc1] N-253 | 69 |
| 73 | 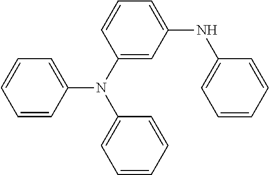 [SMILES: c1ccc(Nc2cccc(N(c3ccccc3)c3ccccc3)c2)cc1] N257-B | 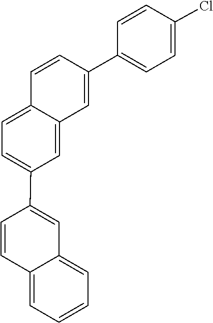 [SMILES: Clc1ccc(-c2ccc3ccc(-c4ccc5ccccc5c4)cc3c2)cc1] N253-A | 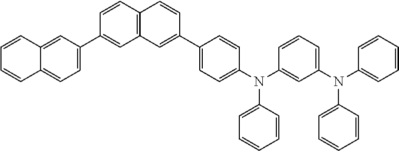 [SMILES: c1ccc(N(c2ccccc2)c2cccc(N(c3ccccc3)c3ccc(-c4ccc5ccc(-c6ccc7ccccc7c6)cc5c4)cc3)c2)cc1] N-257 | 68 |
| 74 | 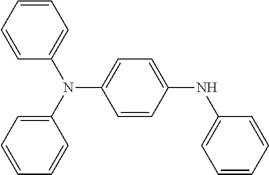 [SMILES: c1ccc(Nc2ccc(N(c3ccccc3)c3ccccc3)cc2)cc1] N269-B | 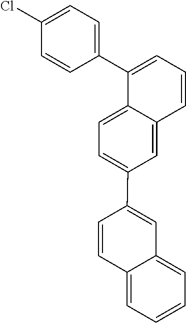 [SMILES: Clc1ccc(-c2cccc3cc(-c4ccc5ccccc5c4)ccc23)cc1] N269-A | 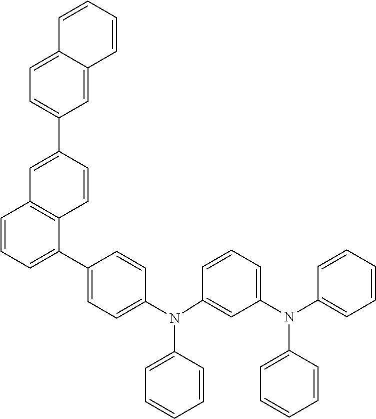 [SMILES: c1ccc(N(c2ccccc2)c2cccc(N(c3ccccc3)c3ccc(-c4cccc5cc(-c6ccc7ccccc7c6)ccc45)cc3)c2)cc1] N-269 | 69 |
| 75 | 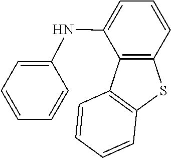 [SMILES: c1ccc(Nc2cccc3sc4ccccc4c23)cc1] N290-B | 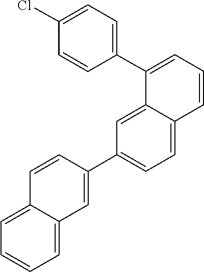 [SMILES: Clc1ccc(-c2cccc3ccc(-c4ccc5ccccc5c4)cc23)cc1] N290-A | 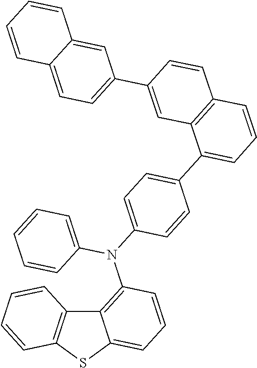 [SMILES: c1ccc(N(c2ccc(-c3cccc4ccc(-c5ccc6ccccc6c5)cc34)cc2)c2cccc3sc4ccccc4c23)cc1] N-290 | 74 |
| 76 | 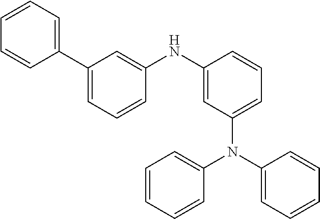 [SMILES: c1ccc(-c2cccc(Nc3cccc(N(c4ccccc4)c4ccccc4)c3)c2)cc1] N313-A | 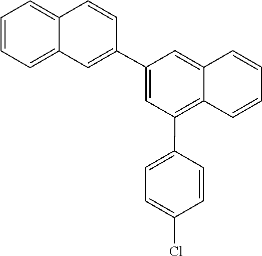 [SMILES: Clc1ccc(-c2cc(-c3ccc4ccccc4c3)cc3ccccc23)cc1] N313-B | 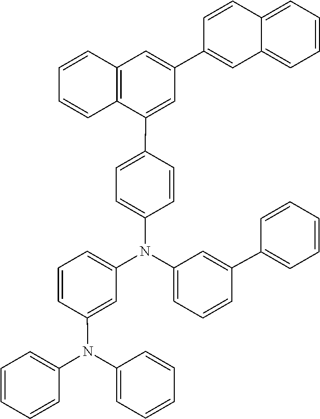 [SMILES: c1ccc(-c2cccc(N(c3ccc(-c4cc(-c5ccc6ccccc6c5)cc5ccccc45)cc3)c3cccc(N(c4ccccc4)c4ccccc4)c3)c2)cc1] N-313 | 70 |
| 77 | 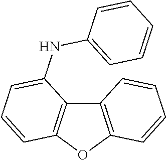 [SMILES: c1ccc(Nc2cccc3oc4ccccc4c23)cc1] N432-B | 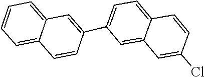 [SMILES: Clc1ccc2ccc(-c3ccc4ccccc4c3)cc2c1] N432-A | 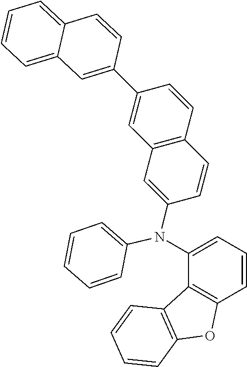 [SMILES: c1ccc(N(c2ccc3ccc(-c4ccc5ccccc5c4)cc3c2)c2cccc3oc4ccccc4c23)cc1] N-432 | 78 |
| 78 | 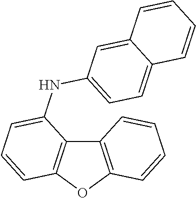 [SMILES: c1ccc2cc(Nc3cccc4oc5ccccc5c34)ccc2c1] N464-B | 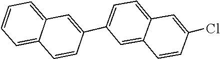 [SMILES: Clc1ccc2cc(-c3ccc4ccccc4c3)ccc2c1] N432-A | 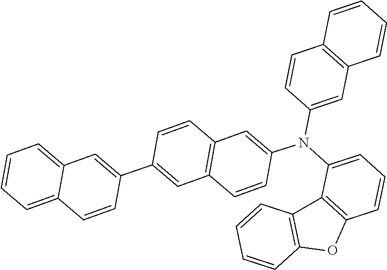 [SMILES: c1ccc2cc(-c3ccc4cc(N(c5ccc6ccccc6c5)c5cccc6oc7ccccc7c56)ccc4c3)ccc2c1] N-464 | 76 |
| 79 | 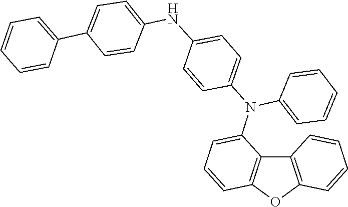 [SMILES: c1ccc(-c2ccc(Nc3ccc(N(c4ccccc4)c4cccc5oc6ccccc6c45)cc3)cc2)cc1] N537-B | 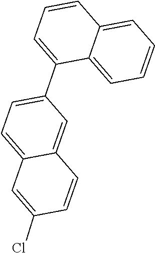 [SMILES: Clc1ccc2cc(-c3cccc4ccccc34)ccc2c1] N537-A | 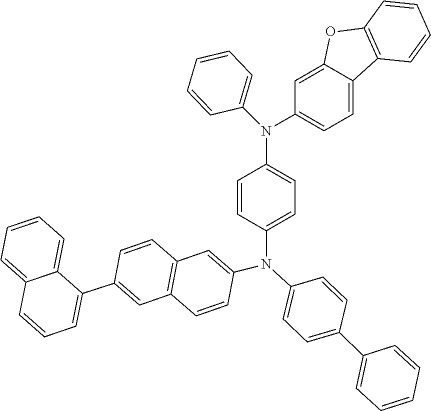 [SMILES: c1ccc(-c2ccc(N(c3ccc(N(c4ccccc4)c4ccc5c(c4)oc4ccccc45)cc3)c3ccc4cc(-c5cccc6ccccc56)ccc4c3)cc2)cc1] N-537 | 76 |
| 80 | 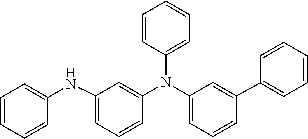 [SMILES: c1ccc(Nc2cccc(N(c3ccccc3)c3cccc(-c4ccccc4)c3)c2)cc1] N545-B | 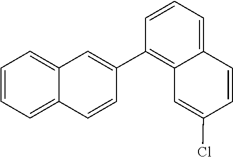 [SMILES: Clc1ccc2cccc(-c3ccc4ccccc4c3)c2c1] N545-A | 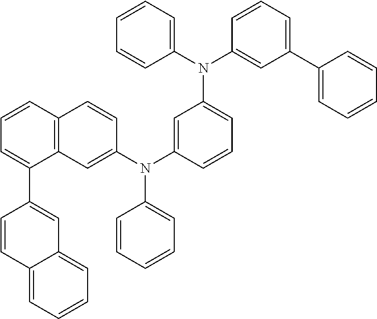 [SMILES: c1ccc(-c2cccc(N(c3ccccc3)c3cccc(N(c4ccccc4)c4ccc5cccc(-c6ccc7ccccc7c6)c5c4)c3)c2)cc1] N-545 | 65 |
| 81 | 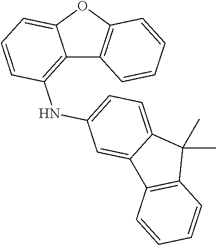 [SMILES: CC1(C)c2ccccc2-c2cc(Nc3cccc4oc5ccccc5c34)ccc21] N-i-37-B | 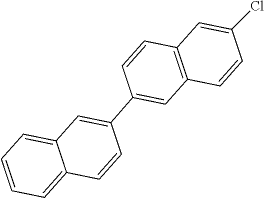 [SMILES: Clc1ccc2cc(-c3ccc4ccccc4c3)ccc2c1] N432-A | 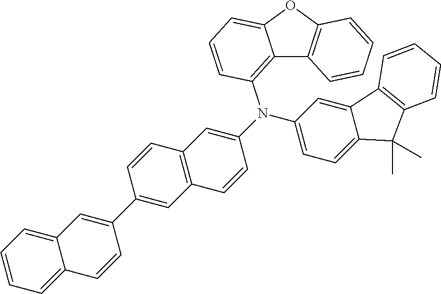 [SMILES: CC1(C)c2ccccc2-c2cc(N(c3ccc4cc(-c5ccc6ccccc6c5)ccc4c3)c3cccc4oc5ccccc5c34)ccc21] N-i-37 | 82 |
| 82 | 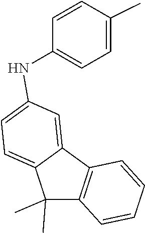 [SMILES: Cc1ccc(Nc2ccc3c(c2)-c2ccccc2C3(C)C)cc1] N-i-38-B | 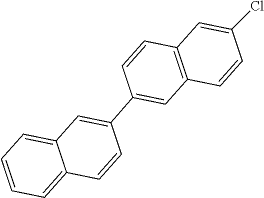 [SMILES: Clc1ccc2cc(-c3ccc4ccccc4c3)ccc2c1] N432-A | 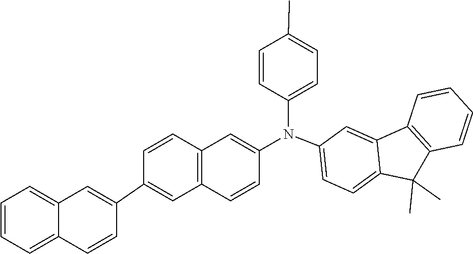 [SMILES: Cc1ccc(N(c2ccc3c(c2)-c2ccccc2C3(C)C)c2ccc3cc(-c4ccc5ccccc5c4)ccc3c2)cc1] N-i-38 | 75 |
| 83 | 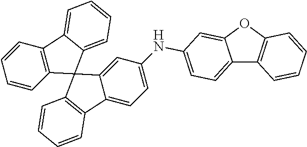 [SMILES: c1ccc2c(c1)-c1ccccc1C21c2ccccc2-c2ccc(Nc3ccc4c(c3)oc3ccccc34)cc21] N-i-9-B | 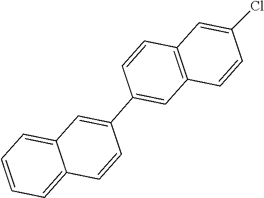 [SMILES: Clc1ccc2cc(-c3ccc4ccccc4c3)ccc2c1] N432-A | 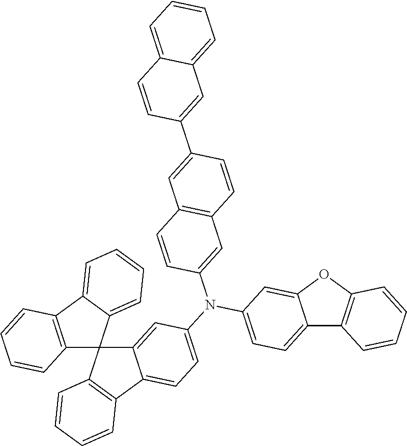 [SMILES: c1ccc2c(c1)-c1ccccc1C21c2ccccc2-c2ccc(N(c3ccc4cc(-c5ccc6ccccc6c5)ccc4c3)c3ccc4c(c3)oc3ccccc34)cc21] N-i-9 | 73 |
| 84 | 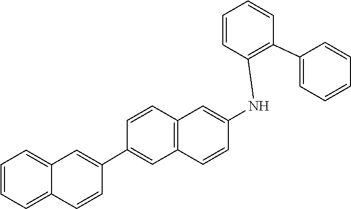 [SMILES: c1ccc(-c2ccccc2Nc2ccc3cc(-c4ccc5ccccc5c4)ccc3c2)cc1] N-i-17-B | 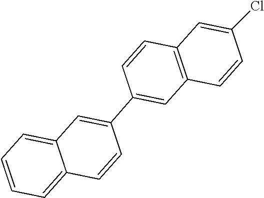 [SMILES: Clc1ccc2cc(-c3ccc4ccccc4c3)ccc2c1] N432-A | 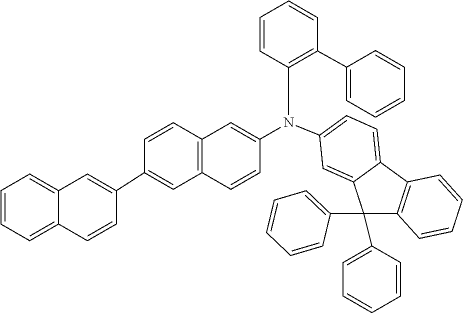 [SMILES: c1ccc(-c2ccccc2N(c2ccc3c(c2)C(c2ccccc2)(c2ccccc2)c2ccccc2-3)c2ccc3cc(-c4ccc5ccccc5c4)ccc3c2)cc1] N-i-17 | 70 |
| 85 | 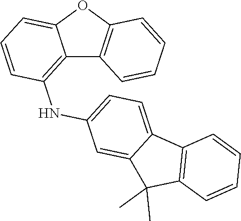 [SMILES: CC1(C)c2ccccc2-c2ccc(Nc3cccc4oc5ccccc5c34)cc21] N-i-1-B | 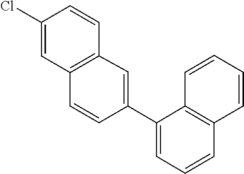 [SMILES: Clc1ccc2cc(-c3cccc4ccccc34)ccc2c1] N55-A | 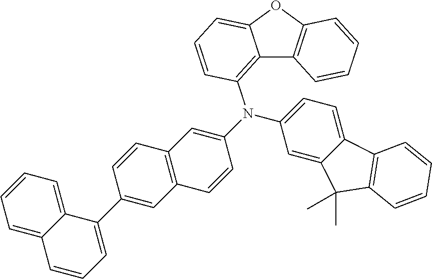 [SMILES: CC1(C)c2ccccc2-c2ccc(N(c3ccc4cc(-c5cccc6ccccc56)ccc4c3)c3cccc4oc5ccccc5c34)cc21] N-i-19 | 78 |
| 86 | 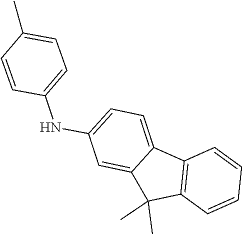 [SMILES: Cc1ccc(Nc2ccc3c(c2)C(C)(C)c2ccccc2-3)cc1] N-i-2-B | 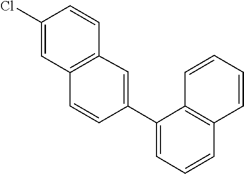 [SMILES: Clc1ccc2cc(-c3cccc4ccccc34)ccc2c1] N55-A | 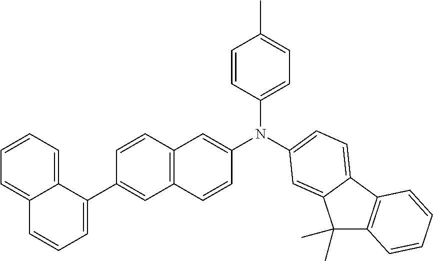 [SMILES: Cc1ccc(N(c2ccc3c(c2)C(C)(C)c2ccccc2-3)c2ccc3cc(-c4cccc5ccccc45)ccc3c2)cc1] N-i-20 | 74 |
| 87 | 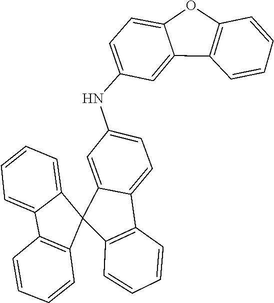 [SMILES: c1ccc2c(c1)-c1ccccc1C21c2ccccc2-c2ccc(Nc3ccc4oc5ccccc5c4c3)cc21] N-i-28-B | 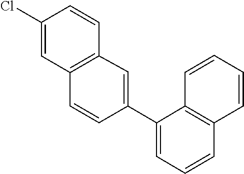 [SMILES: Clc1ccc2cc(-c3cccc4ccccc34)ccc2c1] N55-A | 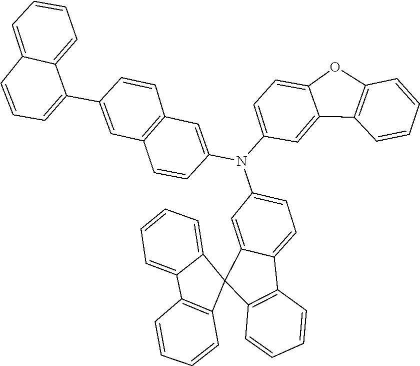 [SMILES: c1ccc2c(c1)-c1ccccc1C21c2ccccc2-c2ccc(N(c3ccc4cc(-c5cccc6ccccc56)ccc4c3)c3ccc4oc5ccccc5c4c3)cc21] N-i-28 | 68 |
| 88 | 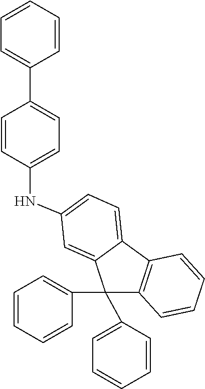 [SMILES: c1ccc(-c2ccc(Nc3ccc4c(c3)C(c3ccccc3)(c3ccccc3)c3ccccc3-4)cc2)cc1] N-i-36-B | 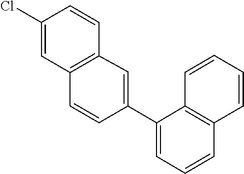 [SMILES: Clc1ccc2cc(-c3cccc4ccccc34)ccc2c1] N55-A | 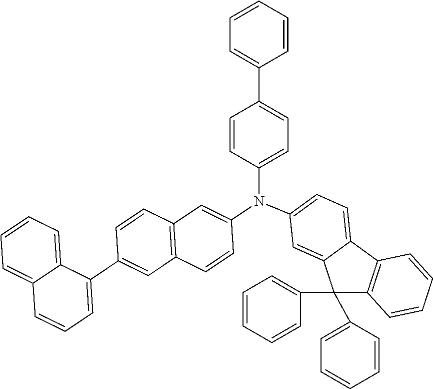 [SMILES: c1ccc(-c2ccc(N(c3ccc4c(c3)C(c3ccccc3)(c3ccccc3)c3ccccc3-4)c3ccc4cc(-c5cccc6ccccc56)ccc4c3)cc2)cc1] N-i-36 | 71 |

TABLE 4

| | | | HRMS (ESI) | |
|---|---|---|---|---|
| | Elemental analysis | | m/z [M + H]+ | |
| Compounds | Theoretical | Measured | Theoretical | Measured |
| N-4 | C, 89.81; H, 4.85; N, | C, 89.86; H, 4.82; N, | 561.21 | 562.19 |
| | 2.49; O, 2.85 | 2.52 | | |
| N-11 | C, 90.33; H, 5.46; N, | C, 90.34; H, 5.42; N, | 664.29 | 665.29 |
| | 4.21 | 4.23 | | |
| N-17 | 89.81; H, 4.85; N, 2.49; | C, 89.86; H, 4.82; N, | 561.21 | 562.21 |
| | O, 2.85 | 2.51 | | |
| N-21 | C, 90.54; H, 5.07; N, | C, 90.57; H, 5.12; N, | 636.26 | 637.23 |
| | 4.40 | 4.44 | | |
| N-25 | C, 89.81; H, 4.85; N, | C, 89.85; H, 4.83; N, | 561.21 | 562.21 |
| | 2.49; O, 2.85 | 2.49 | | |
| N-28 | C, 90.33; H, 5.46; N, | C, 90.38; H, 5.41; N, | 664.29 | 665.29 |
| | 4.21 | 4.23 | | |
| N-33 | C, 90.72; H, 5.36; N, | C, 90.77; H, 5.32; N, | 714.30 | 715.31 |
| | 3.92 | 3.94 | | |
| N-36 | C, 90.31; H, 5.72; N, | C, 90.33; H, 5.75; N, | 704.32 | 705.32 |
| | 3.97 | 3.92 | | |
| N-45 | C, 89.92; H, 4.97; N, | C, 89.94; H, 4.95; N, | 587.22 | 578.23 |
| | 2.38; O, 2.72 | 2.33 | | |
| N-48 | C, 89.10; H, 5.07; N, | C, 89.12; H, 5.11; N, | 754.30 | 755.31 |
| | 3.71; O, 2.12 | 3.74 | | |
| N-55 | C, 92.11; H, 5.45; N, | C, 92.16; H, 5.46; N, | 573.25 | 574.25 |
| | 2.44 | 2.41 | | |
| N-63 | C, 90.25; H, 5.36; N, | C, 90.22; H, 5.39; N, | 638.27 | 639.28 |
| | 4.39 | 4.33 | | |
| N-65 | C, 90.33; H, 5.46; N, | C, 90.38; H, 5.41; N, | 664.29 | 665.29 |
| | 4.21 | 4.25 | | |
| N-67 | C, 87.53; H, 4.84; N, | C, 87.56; H, 4.81; N, | 603.20 | 604.21 |
| | 2.32; S, 5.31 | 2.35; S, 5.33 | | |
| N-71 | C, 91.97; H, 5.75; N, | C, 91.92; H, 5.71; N, | 613.28 | 614.28 |
| | 2.28 | 2.24 | | |
| N-77 | C, 90.78; H, 5.44; N, | C, 90.81; H, 5.43; N, | 740.32 | 741.32 |
| | 3.78 | 3.75 | | |
| N-85 | C, 92.55; H, 5.33; N, | C, 92.59; H, 5.31; N, | 661.28 | 882.28 |
| | 2.12 | 2.14 | | |
| N-87 | C, 88.47; H, 5.05; N, | C, 88.44; H, 5.09; N, | 678.27 | 679.29 |
| | 4.13; O, 2.36 | 4.11 | | |
| N-91 | C, 89.92; H, 4.97; N, | C, 89.95; H, 4.91; N, | 587.22 | 588.23 |
| | 2.38; O, 2.72 | 2.37 | | |
| N-92 | C, 90.07; H, 5.15; N, | C, 90.04; H, 5.18; N, | 586.24 | 567.25 |
| | 4.77 | 4.72 | | |
| N-99 | C, 89.76; H, 5.48; N, | C, 89.71; H, 5.45; N, | 588.26 | 589.26 |
| | 4.76 | 4.73 | | |
| N-109 | C, 89.92; H, 4.97; N, | C, 89.98; H, 4.91; N, | 587.22 | 588.23 |
| | 2.38; O, 2.72 | 2.32 | | |
| N-112 | C, 90.78; H, 5.44; N, | C, 90.74; H, 5.46; N, | 740.32 | 741.32 |
| | 3.78 | 3.71 | | |
| N-119 | C, 90.25; H, 5.36; N, | C, 90.21; H, 5.35; N, | 638.27 | 639.28 |
| | 4.39 | 4.34 | | |
| N-123 | C, 92.11; H, 5.45; N, | C, 92.14; H, 5.41; N, | 573.25 | 574.25 |
| | 2.44 | 2.47 | | |
| N-128 | C, 90.92; H, 5.35; N, | C, 90.91; H, 5.38; N, | 752.32 | 753.32 |
| | 3.72 | 3.74 | | |
| N-134 | C, 90.72; H, 5.36; N, | C, 90.75; H, 5.32; N, | 714.30 | 715.31 |
| | 3.92 | 3.97 | | |
| N-139 | C, 90.33; H, 5.46; N, | C, 90.34; H, 5.45; N, | 664.29 | 664.29 |
| | 4.21 | 4.21 | | |
| N-145 | C, 91.49; H, 5.12; N, | C, 91.51; H, 5.11; N, | 826.33 | 827.34 |
| | 3.39 | 3.38 | | |
| N-151 | C, 92.11; H, 5.45; N, | C, 92.17; H, 5.45; N, | 573.25 | 574.25 |
| | 2.44 | 2.41 | | |
| N-175 | C, 86.69; H, 4.72; N, | C, 86.72; H, 4.75; N, | 512.19 | 513.19 |
| | 5.46; O, 3.12 | 5.42 | | |
| N-229 | C, 89.13; H, 5.26; N, | C, 89.15; H, 5.23; N, | 498.21 | 499.21 |
| | 5.62 | 5.61 | | |
| N-233 | C, 87.58; H, 5.30; N, | C, 87.61; H, 5.36; N, | 589.25 | 590.26 |
| | 7.13 | 7.15 | | |
| N-253 | C, 92.11; H, 5.45; N, | C, 92.13; H, 5.44; N, | 573.25 | 574.25 |
| | 2.44 | 2.44 | | |
| N-257 | C, 90.34; H, 5.45; N, | C, 90.36; H, 5.43; N, | 664.29 | 665.29 |
| | 4.21 | 4.25 | | |
| N-269 | C, 90.34; H, 5.45; N, | C, 90.37; H, 5.42; N, | 664.29 | 665.29 |
| | 4.21 | 4.26 | | |
| N-290 | C, 87.53; H, 4.84; N, | C, 87.51; H, 4.86; N, | 603.20 | 604.21 |
| | 2.32; S, 5.31 | 2.37; S, 5.29 | | |
| N-313 | C, 90.78; H, 5.44; N, | C, 90.79; H, 5.43; N, | 740.32 | 741.32 |
| | 3.78 | 3.78 | | |
| N-432 | C, 89.21; H, 4.93; N, | C, 89.25; H, 4.9; N, | 511.19 | 512.18 |
| | 2.74; O, 3.13 | 2.71 | | |
| N-464 | C, 89.81; H, 4.85; N, | C, 89.83; H, 4.83; N, | 561.21 | 562.21 |
| | 2.49; O, 2.85 | 2.49 | | |
| N-537 | C, 89.10; H, 5.07; N, | C, 89.12; H, 5.05; N, | 754.30 | 755.31 |
| | 3.71; O, 2.12 | 3.74 | | |
| N-545 | C, 90.33; H, 5.46; N, | C, 90.38; H, 5.41; N, | 664.29 | 665.29 |
| | 4.21 | 4.25 | | |
| N-i-37 | C, 89.92; H, 5.30; N, | C, 89.89; H, 5.28; N, | 627.26 | 628.31 |
| | 2.23; O, 2.55 | 2.27 | | |
| N-i-38 | C, 91.43; H, 6.03; N, | C, 91.40; H, 6.04; N, | 551.26 | 552.69 |
| | 2.54 | 2.56 | | |
| N-i-9 | C, 91.29; H, 4.70; N, | C, 91.26; H, 4.71; N, | 749.27 | 750.15 |
| | 1.87; O, 2.13 | 1.91 | | |
| N-i-17 | C, 92.77; H, 5.33; N, | C, 92.75; H, 5.31; N, | 737.31 | 738.65 |
| | 1.90 | 1.94 | | |
| N-i-19 | C, 89.92; H, 5.30; N, | C, 89.89; H, 5.31; N, | 627.26 | 628.28 |
| | 2.23; O, 2.55 | 2.26 | | |
| N-i-20 | C, 91.43; H, 6.03; N, | C, 91.40; H, 6.02; N, | 551.26 | 552.19 |
| | 2.54 | 2.58 | | |
| N-i-28 | C, 91.29; H, 4.70; N, | C, 91.25; H, 4.69; N, | 749.27 | 750.46 |
| | 1.87; O, 2.13 | 1.91 | | |
| N-i-36 | C, 92.77; H, 5.33; N, | C, 92.73; H, 5.35; N, | 737.31 | 738.61 |
| | 1.90 | 1.92 | | |

### Device Example

The present example provides an organic electroluminescent device, as shown in FIG. 1, comprising anode 2, hole injection layer 3, hole transport layer 4, light emitting layer 5, electron transport layer 6, electron injection layer 7, and cathode 8 sequentially stacked on substrate 1. The device has the following structure: anode (indium tin oxide (ITO) coated glass substrate)/hole injection layer (HIL)/hole transport layer (HTL)/light emitting layer (EMLL)/electron transport layer (ETL)/electron injection layer (EIL)/cathode (Al).

The materials for manufacturing the organic electroluminescent device are as follows:

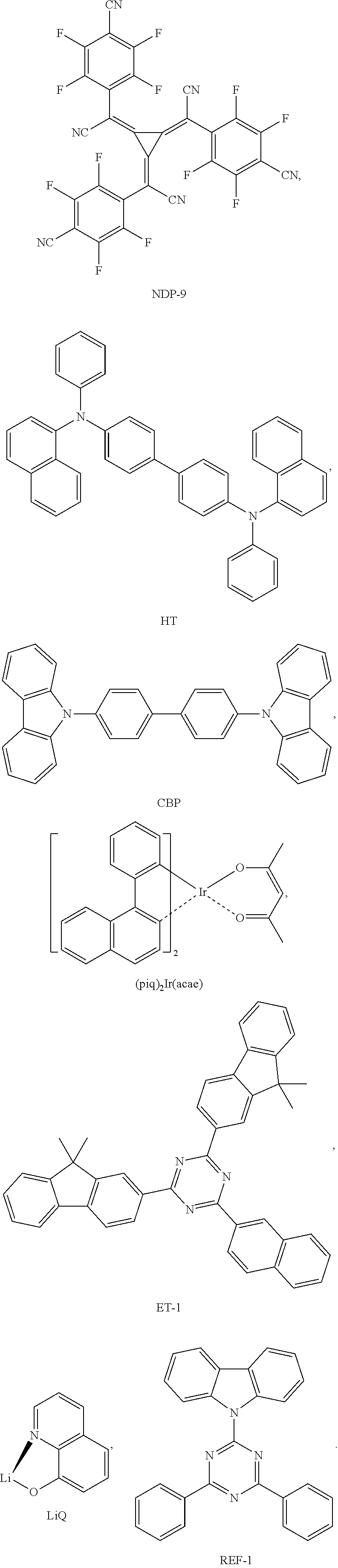

The preparation of the above-mentioned organic electroluminescent device comprises the following steps.

### 1) Substrate Cleaning

The glass substrate coated with transparent ITO is sonicated in a water-based cleaning agent (the composition and concentration of the water-based cleaning agent are: ethylene glycol based solvent ≤10 wt %, triethanolamine ≤1 wt %), then rinsed in deionized water, sonicated in a mixed solvent of acetone and ethanol (volume ratio of acetone and ethanol is 1:1) to remove the oil, baked in a clean environment to completely remove moisture, and then cleaned with ultraviolet light and ozone.

### 2) Organic Layer Preparation

The ITO transparent substrate was transferred into the evaporation coating equipment and vacuumized to 1×10⁻⁶ to 2×10⁻⁴ Pa, a 10 nm hole injection layer (HIL)/80 nm hole transport layer (HTL)/38 nm light emitting layer (EML)/30 nm electron transport layer (ETL)/1 nm electron injection layer (EIL)/80 nm thick cathode (Al) was sequentially evaporated and coated on the anode film.
wherein,
the material of the hole injection layer (HIL) is a mixture of NDP-9 and HT, the mass ratio of NDP-9 to HT is 3:97;
the material of the hole transport layer (HTL) is shown in Table 5;
the material of the light emitting layer (EML) includes a host material and a guest material, and the guest material is (piq)₂Ir(acac); the specific proportions of the host material to the guest material are shown in Table 5;
the material of the electron transport layer (ETL) is shown in Table 5;
the material of the electron injection layer (EIL) is LiQ;
the cathode is aluminum; and
some layers, as well as their materials and thicknesses of the organic electroluminescent device are shown in Table 5.

TABLE 5

| Example | HIL | HTL | EML | ETL | EIL | cathode |
|---|---|---|---|---|---|---|
| No. | thicknesses | thicknesses | thicknesses | thicknesses | thicknesses | thicknesses |
| Example 1 | NDP-9:HT(mass | HT | M-17:N-432:(piq)2I | ET-1:LiQ | LiQ | Al |
| | ratio 3:97) | 80 nm | r(acac) | (mass | 1 nm | 80 nm |
| | 10 nm | | (mass ratio | ratio 1:1) | | |
| | | | 47.5:47.5:5)/38 nm | 30 nm | | |
| Example 2 | NDP-9:HT | HT | M-17:N-464:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/38 nm | 30 nm | | |
| Example 3 | NDP-9:HT | HT | M-17:N-535:(piq)₂I | ET-1:LiQ | LiQ | Al |
| | (mass ratio 3:97) | 80 nm | r(acac)(mass ratio | (mass ratio | 1 nm | 80 nm |
| | 10 nm | | 47.5:47.5:5)/38 nm | 1:1) | | |
| | | | | 30 nm | | |
| Example 4 | NDP-9:HT | HT | M-76:N-531:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/38 nm | 30 nm | | |
| Example 5 | NDP-9:HT | HT | M-76:N-545:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/38 nm | 30 nm | | |
| Example 6 | NDP-9:HT | HT | M-108:N-4:(piq)₂Ir | ET-1:LiQ | LiQ | Al |
| | (mass ratio 3:97) | 80 nm | (acac) | (mass ratio | 1 nm | 80 nm |
| | 10 nm | | (mass | 1:1) | | |
| | | | ratio | 30 nm | | |
| | | | 47.5:47.5:5)/ | | | |
| | | | 38 nm | | | |
| Example 7 | NDP-9:HT | HT | M-108:N-11:(piq)₂I | ET-1:LiQ | LiQ | Al |
| | (mass ratio 3:97) | 80 nm | r(acac)(mass ratio | (mass ratio | 1 nm | 80 nm |
| | 10 nm | | 47.5:47.5:5)/ | 1:1) | | |
| | | | 38 nm | 30 nm | | |
| Example 8 | NDP-9:HT | HT | M-145:N-17:(piq)₂I | ET-1:LiQ | LiQ | Al |
| | (mass ratio 3:97) | 80 nm | r(acac)(mass ratio | mass ratio | 1 nm | 80 nm |
| | 10 nm | | 47.5:47.5:5)/ | 1:1) | | |
| | | | 38 nm | 30 nm | | |
| Example 9 | NDP-9:HT | HT | M-145:N-21:(piq)₂I | ET-1:LiQ | LiQ | Al |
| | (mass ratio 3:97) | 80 nm | r(acac)(mass ratio | (mass ratio | 1 nm | 80 nm |
| | 10 nm | | 47.5:47.5:5)/ | 1:1) | | |
| | | | 38 nm | 30 nm | | |
| Example 10 | NDP-9:HT | HT | M-253:N-25:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 11 | NDP-9:HT | HT | M-253:N-28:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 12 | NDP-9:HT | HT | M-296:N-63:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 13 | NDP-9:HT | HT | M-296:N-55:(piq)₂I | ET-1:LiQ | LiQ | Al |
| | (mass ratio 3:97) | 80 nm | r(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 14 | NDP-9:HT | HT | M-537:N-536:(piq) | ET-1:LiQ | LiQ | Al |
| | (mass ratio 3:97) | 80 nm | ₂Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 15 | NDP-9:HT | HT | M-589:N-537:(piq) | ET-1:LiQ | LiQ | Al |
| | (mass ratio 3:97) | 80 nm | ₂Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 16 | NDP-9:HT | HT | M-308:N-175:(piq) | ET-1:LiQ | LiQ | Al |
| | (mass ratio 3:97) | 80 nm | ₂Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 17 | NDP-9:HT | HT | M-308:N-233:(piq) | ET-1:LiQ | LiQ | Al |
| | (mass ratio 3:97) | 80 nm | ₂Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 18 | NDP-9:HT | HT | M-365:N-179:(piq) | ET-1:LiQ | LiQ | Al |
| | (mass ratio 3:97) | 80 nm | ₂Ir(acac) | (mass | 1 nm | 80 nm |
| | 10 nm | | (mass ratio | ratio | | |
| | | | 47.5:47.5:5)/ | 1:1) | | |
| | | | 38 nm | 30 nm | | |
| Example 19 | NDP-9:HT | HT | M-371:N-92:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 20 | NDP-9:HT | HT | M-381:N-134:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 21 | NDP-9:HT | HT | M-394:N-139:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 22 | NDP-9:HT | HT | M-412:N-145:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 23 | NDP-9:HT | HT | M-423:N-357:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 24 | NDP-9:HT | HT | M-442:N-313:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 25 | NDP-9:HT | HT | M-450:N-533:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 26 | NDP-9:HT | HT | M-460:N-534:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 27 | NDP-9:HT | HT | M-537:N-532:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 28 | NDP-9:HT | HT | M-589:N-269:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 29 | NDP-9:HT | HT | M-461:N-123:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 30 | NDP-9:HT | HT | M-526:N-128:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 31 | NDP-9:HT | HT | M-253:N-549:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 32 | NDP-9:HT | HT | M-253:N-33:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 33 | NDP-9:HT | HT | M-17:N-i-37:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 34 | NDP-9:HT | HT | M-76:N-i-38:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 35 | NDP-9:HT | HT | M-381:N-i-9:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 36 | NDP-9:HT | HT | M-394:N-i-17:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 37 | NDP-9:HT | HT | M-17:N-i-19:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 38 | NDP-9:HT | HT | M-17:N-i-20:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 39 | NDP-9:HT | HT | M-17:N-i-28:(piq)2 | ET-1:LiQ | LiQ | Al |
| | (mass ratio 3:97) | 80 nm | Ir(acac) | (mass | 1 nm | 80 nm |
| | 10 nm | | (mass ratio | ratio | | |
| | | | 47.5:47.5:5)/ | 1:1) | | |
| | | | 38 nm | 30 nm | | |
| Example 40 | NDP-9:HT | HT | M-17:N-i-36:(piq)2 | ET-1:LiQ | LiQ | Al |
| | (mass ratio 3:97) | 80 nm | Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Example 41 | NDP-9:HT | HT | M-253:N-i-37:(piq) | ET-1:LiQ | LiQ | Al |
| | (mass ratio 3:97) | 80 nm | 2Ir(acac) | (mass ratio | 1 nm | 80 nm |
| | 10 nm | | (mass ratio | 1:1) | | |
| | | | 47.5:47.5:5)/ | 30 nm | | |
| | | | 38 nm | | | |
| Comparative | NDP-9:HT | HT80 nm | CBP:(piq)2Ir(acac) | ET-1:LiQ | LiQ | Al |
| Example 1 | (mass ratio 3:97) | | (mass ratio 95:5) | (mass ratio | 1 nm | 80 nm |
| | 10 nm | | 38 nm | 1:1) | | |
| | | | | 30 nm | | |

The Examples in Table 5 refer to device Examples, and the Comparative Example refers to device Comparative Example.

### Test Example

The organic electroluminescent devices obtained by Device Examples 1-41 and Comparative Example 1 in the device examples were tested.

Instrument: the current, voltage, brightness, emission spectrum and other characteristics of the devices were synchronously tested using a PR 650 spectral scanning brightness meter and a Keithley K 2400 digital source meter system;
testing conditions:
testing condition for optical-electrical characteristic: a current density was 10 mA/cm²;
service life testing: a current density was 50 mA/cm², and time was recorded (in hours) when the device brightness was lowered to 95% of the original brightness.

Results of the above device performance testing were shown in Table 6.

TABLE 6

| | Driving | Current | Service life |
|---|---|---|---|
| Item | voltage (V) | efficiency (Cd/A) | T95 (hrs) |
| Example 1 | 3.43 | 22.47 | 278.4 |
| Example 2 | 3.61 | 21.54 | 245.7 |
| Example 3 | 3.33 | 28.45 | 283.3 |
| Example 4 | 3.45 | 23.67 | 289.4 |
| Example 5 | 3.21 | 33.52 | 325.6 |
| Example 6 | 3.68 | 19.41 | 248.7 |
| Example 7 | 3.34 | 25.66 | 296.9 |
| Example 8 | 3.32 | 24.57 | 308.1 |
| Example 9 | 3.25 | 28.86 | 295.2 |
| Example 10 | 3.34 | 23.70 | 288.5 |
| Example 11 | 3.23 | 27.98 | 315.4 |
| Example 12 | 3.54 | 18.36 | 231.5 |
| Example 13 | 3.30 | 27.65 | 312.6 |
| Example 14 | 3.26 | 32.41 | 328.7 |
| Example 15 | 3.22 | 32.66 | 329.8 |
| Example 16 | 3.40 | 20.67 | 283.4 |
| Example 17 | 3.29 | 30.57 | 316.5 |
| Example 18 | 3.42 | 21.09 | 289.4 |
| Example 19 | 3.26 | 28.66 | 313.8 |
| Example 20 | 3.34 | 28.79 | 306.4 |
| Example 21 | 3.31 | 30.65 | 314.7 |
| Example 22 | 3.50 | 26.65 | 297.6 |
| Example 23 | 3.27 | 31.24 | 332.1 |
| Example 24 | 3.31 | 26.51 | 306.3 |
| Example 25 | 3.69 | 18.57 | 220.8 |
| Example 26 | 3.71 | 18.49 | 235.6 |
| Example 27 | 3.56 | 18.35 | 216.8 |
| Example 28 | 3.31 | 29.87 | 326.4 |
| Example 29 | 3.55 | 18.31 | 235.1 |
| Example 30 | 3.47 | 22.32 | 264.5 |
| Example 31 | 3.25 | 30.15 | 321.7 |
| Example 32 | 3.64 | 19.21 | 235.8 |
| Example 33 | 3.20 | 35.27 | 342.1 |
| Example 34 | 3.22 | 34.14 | 332.4 |
| Example 35 | 3.24 | 33.17 | 330.2 |
| Example 36 | 3.24 | 33.67 | 330.7 |
| Example 37 | 3.20 | 35.76 | 352.6 |
| Example 38 | 3.21 | 35.11 | 340.5 |
| Example 39 | 3.24 | 34.28 | 335.9 |
| Example 40 | 3.23 | 33.54 | 325.7 |
| Example 41 | 3.20 | 35.68 | 338.4 |
| Comparative | 4.80 | 5.00 | 5.0 |
| Example 1 | | | |

Obviously, the above examples are only for the purpose of clearly illustrating the instances provided, rather than limiting the embodiments. For those of ordinary skill in the art, other different forms of changes or variations can also be made based on the above explanation. It is not necessary and impossible to exhaustively list all embodiments here. The obvious changes or variations arising from this are still within the scope of protection of the present application.

1. An organic electroluminescent material composition, wherein the organic electroluminescent material composition comprise compound N and compound M, compound N and compound M are compounds represented by Formula (1): 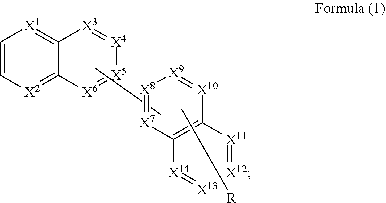
wherein in compound N, R is selected from the following structure: 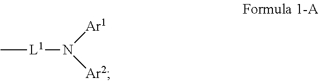
wherein in compound M, R is selected from the following structure: 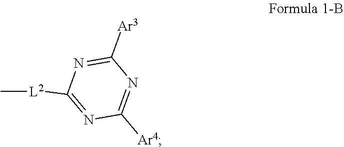
wherein, X¹-X¹⁴ are each independently selected from N or CR⁸, and R⁸ is selected from hydrogen or deuterium;
L¹ and L² are each independently selected from a connecting bond, a substituted or unsubstituted C6-C30 arylenyl, and a substituted or unsubstituted C3-C30 heteroarylenyl;
Ar¹ to Ar⁴ are each independently selected from a substituted or unsubstituted C6-C30 aryl, a substituted or unsubstituted C3-C30 heteroaryl, a substituted or unsubstituted C6-C60 arylamine group, and a substituted or unsubstituted C3-C60 heteroarylamine group;
the substituents in the substituted C6-C30 arylenyl, the substituted C3-C30 heteroarylenyl, the substituted C6-C30 aryl, the substituted C3-C30 heteroaryl, the substituted C6-C60 arylamine group, and the substituted C3-C60 heteroarylamine group are selected from one of or a combination of two of deuterium, halogen, cyano, C1-C6 alkyl, C3-C30 cycloalkyl, C6-C30 aryl, C3-C30 heteroaryl, C6-C60 arylamine group and C3-C60 heteroarylamine group.

2. The organic electroluminescent material composition according to claim 1, wherein in Formula (1), X¹-X¹⁴ are all selected from CR⁸, and R⁸ is selected from hydrogen or deuterium;
preferably, X¹-X¹⁴ are all selected from CR⁸, and R⁸ is hydrogen;
preferably, any one of X¹-X⁶ is selected from N, and the remaining is CR⁸;
preferably, any one of X¹-X⁶ is selected from N, and the remaining is CR⁸; any one of X⁷-X¹⁴ is selected from N, and the remaining is CR⁸;
wherein R⁸ is each present independently, and can be the same or different; and
preferably, Ar¹-Ar⁴ are each independently selected from a substituted or unsubstituted A group;
the A group comprises: phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, benzofuryl, dibenzofuryl, naphthobenzofuryl, dinaphthalofuryl, benzothienyl, dibenzothienyl, naphthobenzothienyl, carbazolyl, phenylcarbazolyl, benzophenylcarbazolyl, dibenzophenylcarbazolyl, biphenylcarbazolyl, phenanthrobenzofuryl, dibenzofuranofuryl, and phenylcarbazolobenzofuryl;
wherein, the substituent of the substituted A group is selected from one of or a combination of two of deuterium, halogen, cyano, C1-C6 alkyl, C3-C30 cycloalkyl, C6-C30 aryl, C3-C30 heteroaryl, C6-C60 arylamine group, and C3-C60 heteroarylamine group.

3. The organic electroluminescent material composition according to claim 1, wherein Ar¹-Ar² are each independently selected from phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, dibenzofuryl, naphthobenzofuryl, dibenzothienyl, naphthobenzothienyl, phenylcarbazolyl, benzophenylcarbazolyl, dibenzophenylcarbazolyl, or a group with the following structure: 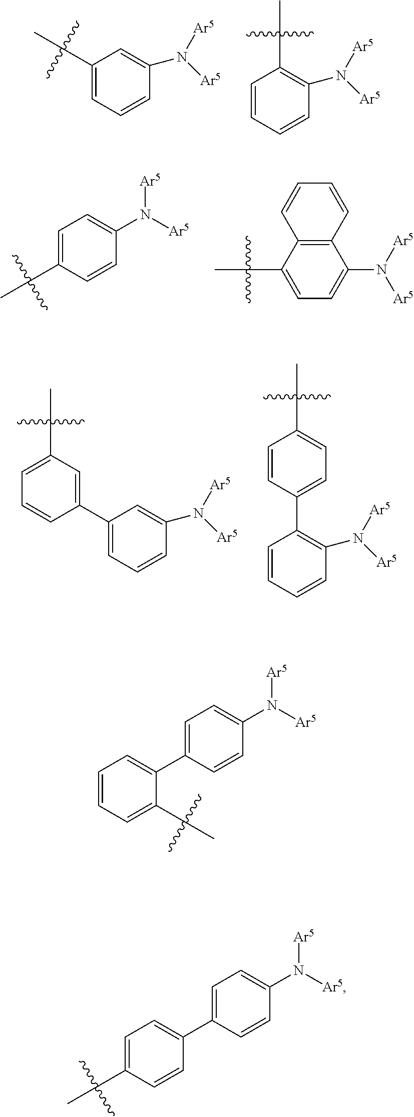
when a plurality of Ar⁵ are each present independently, the plurality of Ar⁵ can be the same or different;
wherein, Ar⁵ is each independently selected from a substituted or unsubstituted B group, wherein the B group comprises: phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, benzofuryl, dibenzofuryl, naphthobenzofuryl, benzothienyl, dibenzothienyl, naphthobenzothienyl, carbazolyl, phenylcarbazolyl, benzophenylcarbazolyl, and dibenzophenylcarbazolyl;
wherein, the substituent of the substituted B group is selected from one of or a combination of two of deuterium, halogen, cyano, C1-C6 alkyl, C3-C30 cycloalkyl, C6-C30 aryl, C3-C30 heteroaryl, C6-C60 arylamine group, and C3-C60 heteroarylamine group;
preferably, Ar³-Ar⁴ is independently selected from phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, dibenzofuryl, naphthobenzofuryl, dibenzothienyl, naphthobenzothienyl, carbazolyl, phenylcarbazolyl, benzocarbazolyl, and dibenzocarbazolyl;
preferably, L¹ and L² are each independently selected from a connecting bond, and a substituted or unsubstituted C6-C18 arylenyl;
preferably, L¹ is selected from a connecting bond, phenylenyl and naphthenyl;
preferably, L² is selected from a connecting bond and phenylenyl.

4. The organic electroluminescent material composition according to claim 1, wherein the structure of the compound N is shown as any one of Formula 1-1 to Formula 1-64: 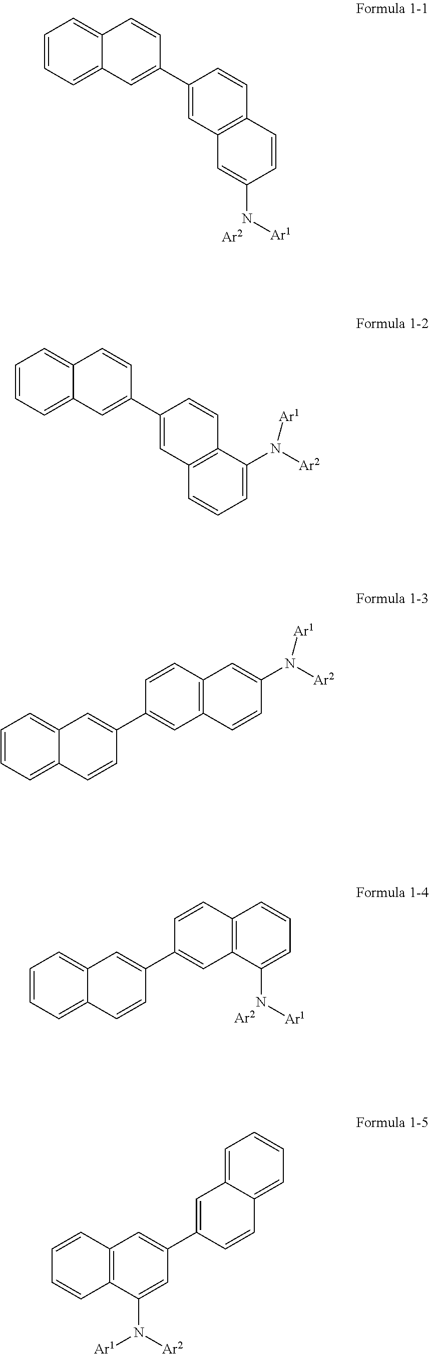 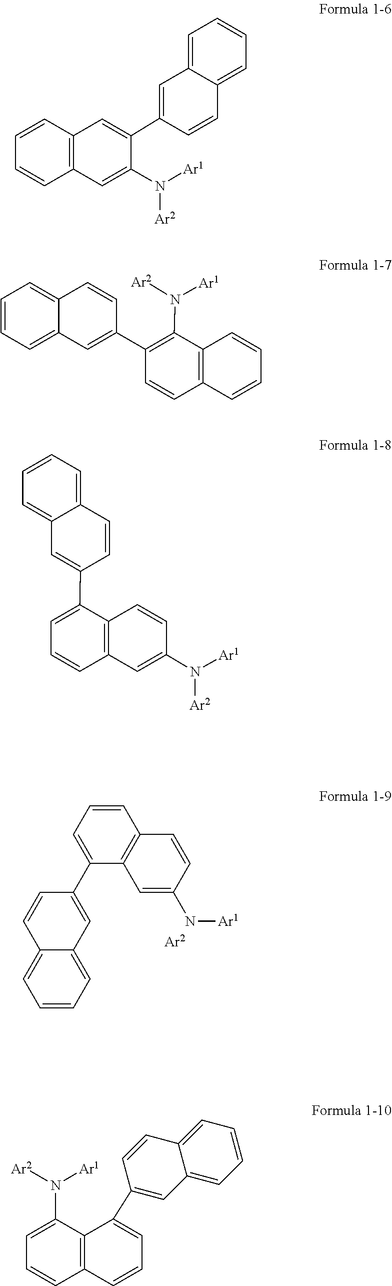 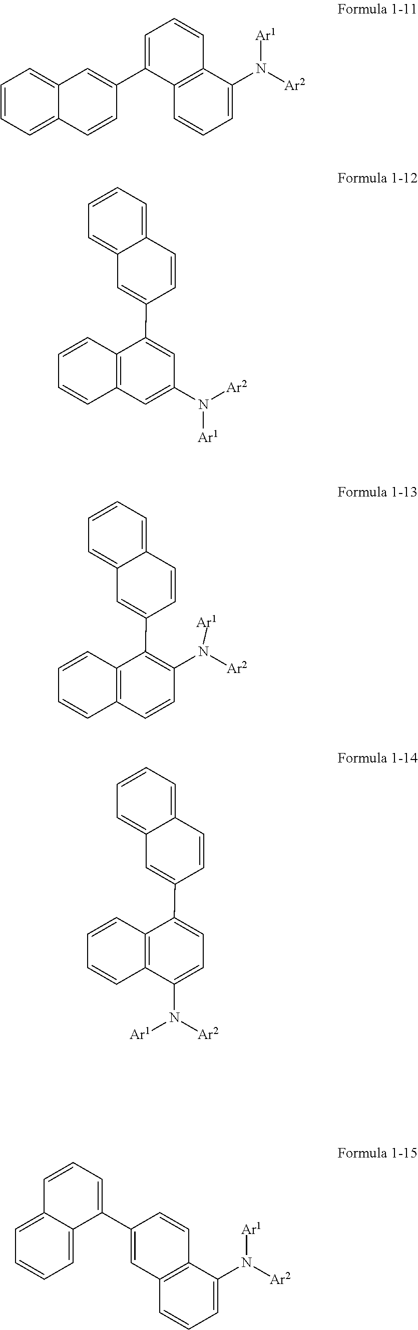 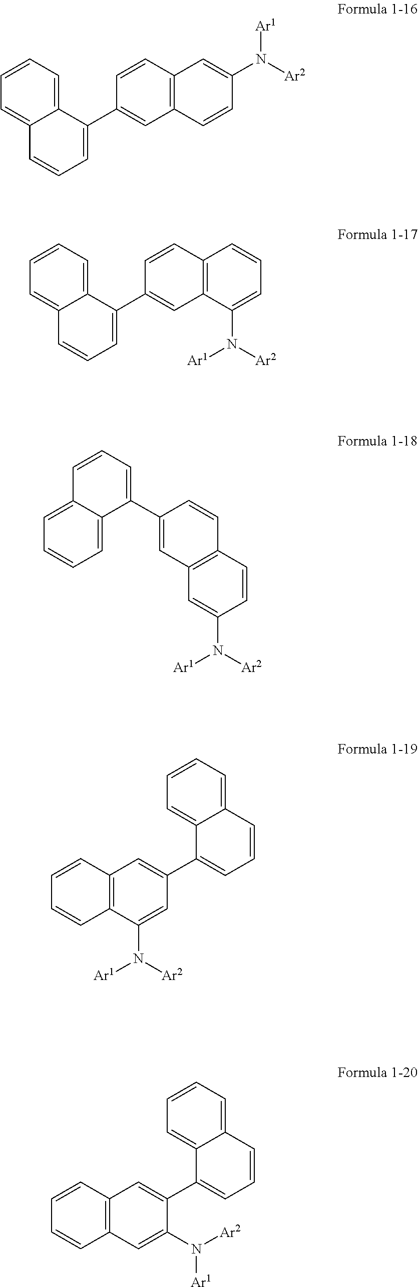 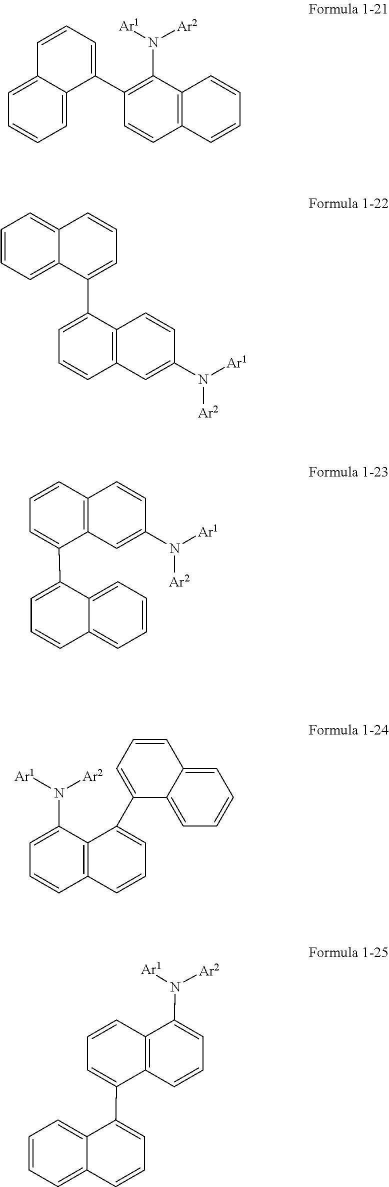 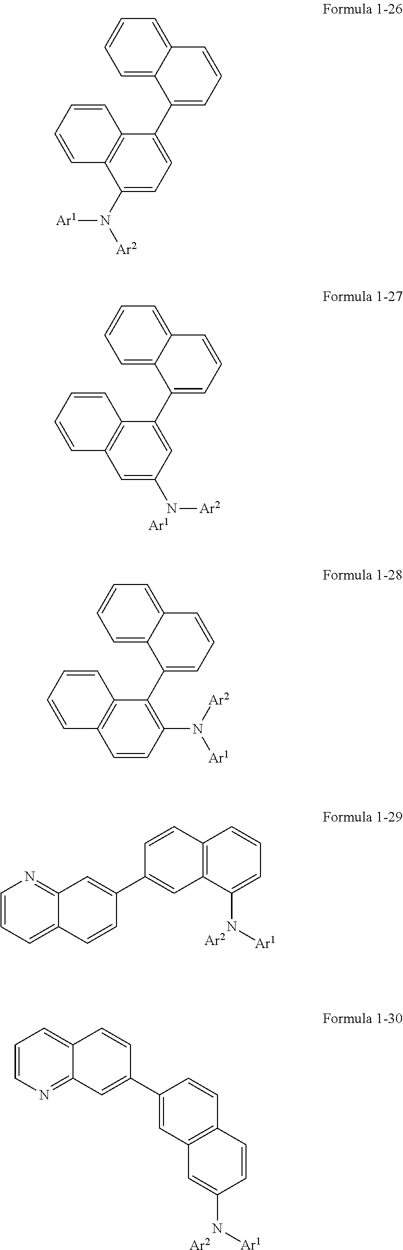 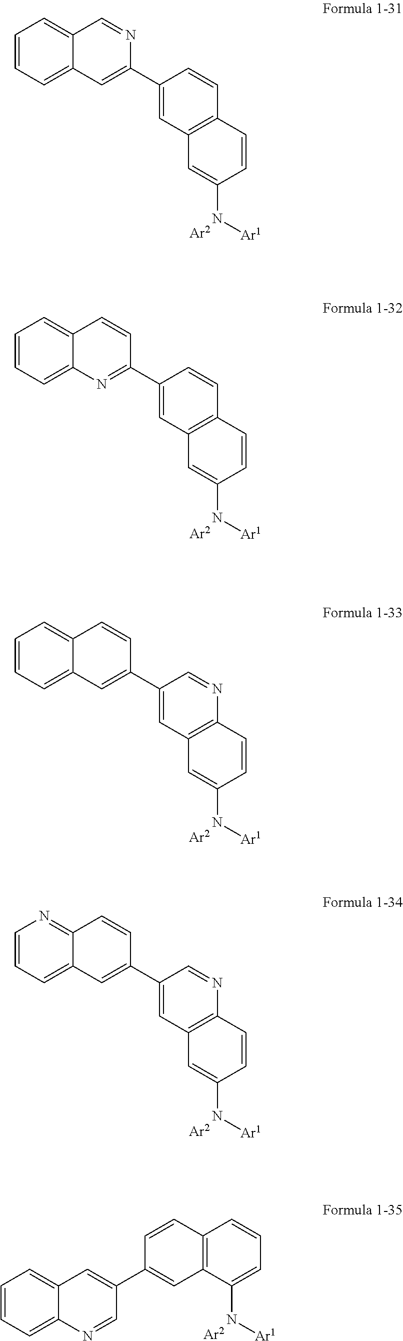 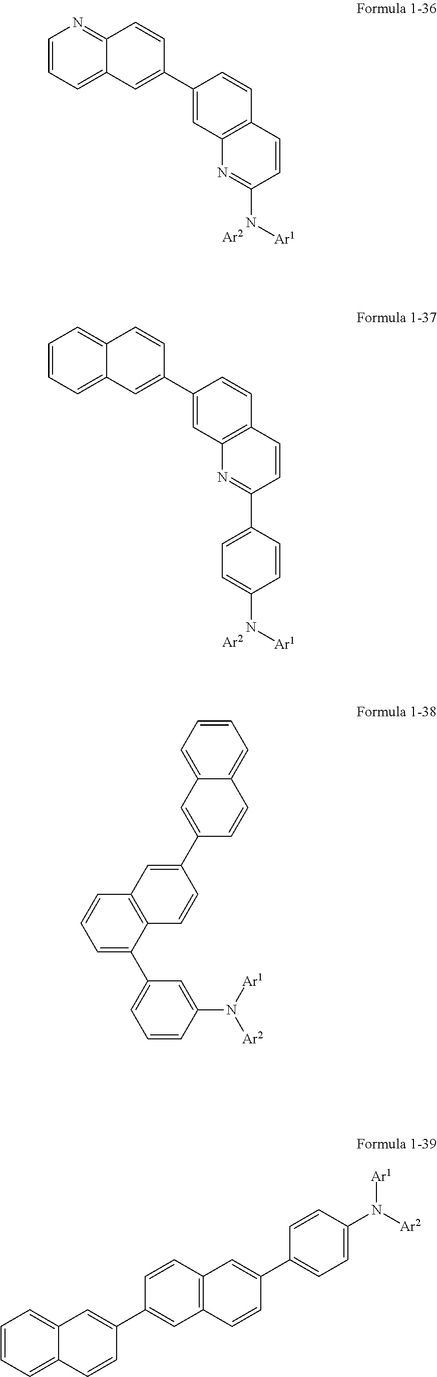 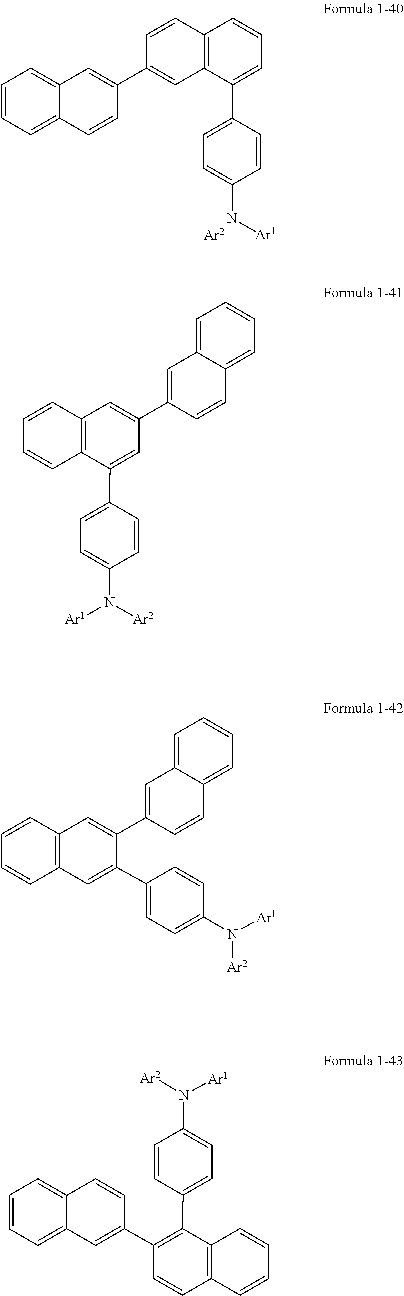 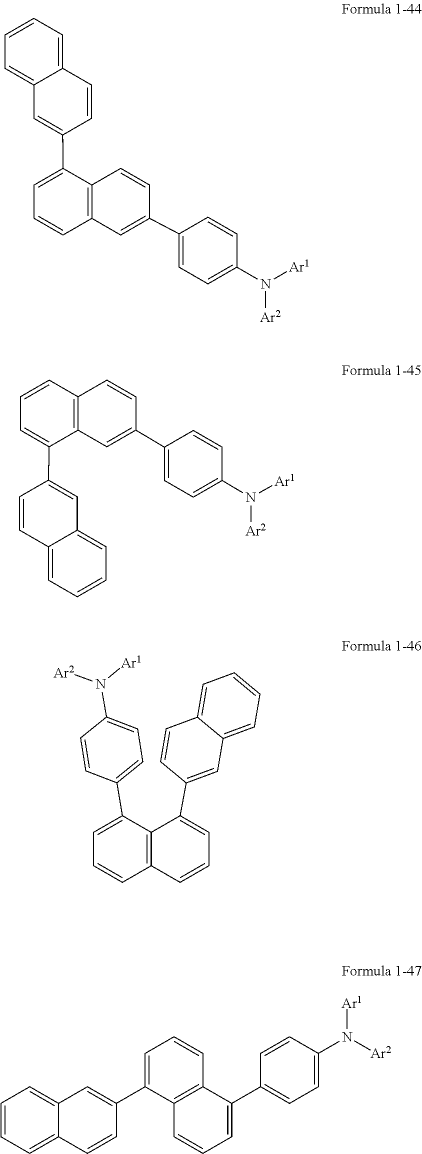 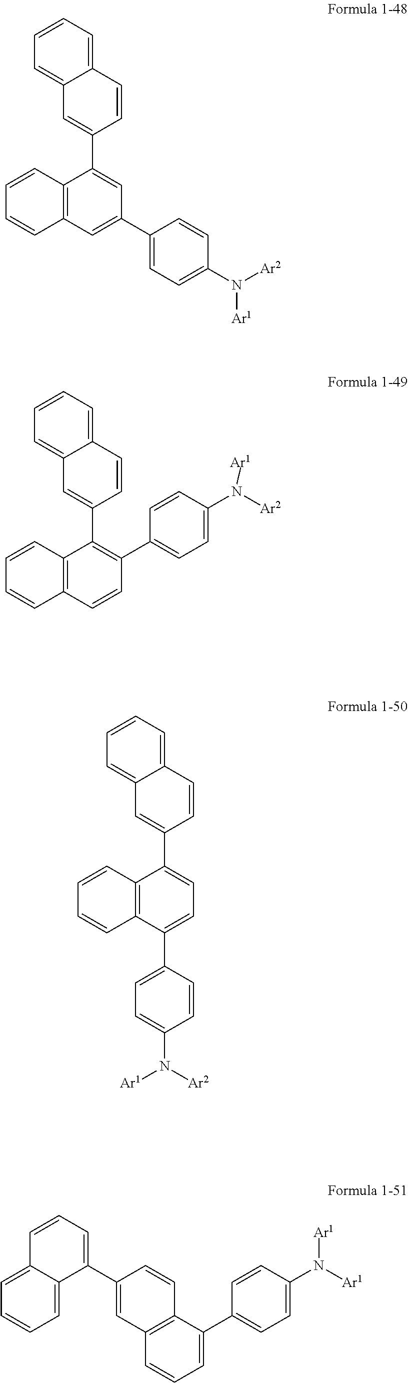 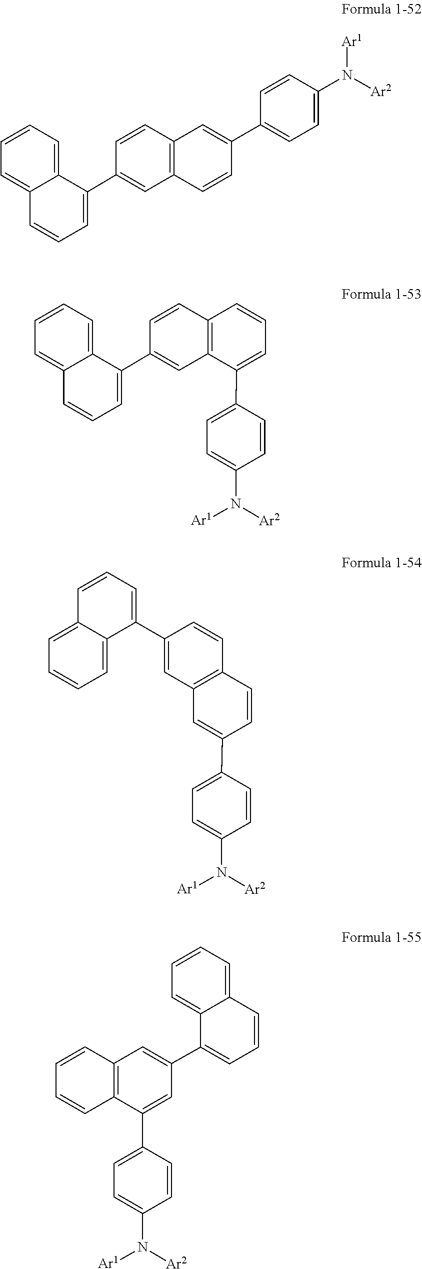 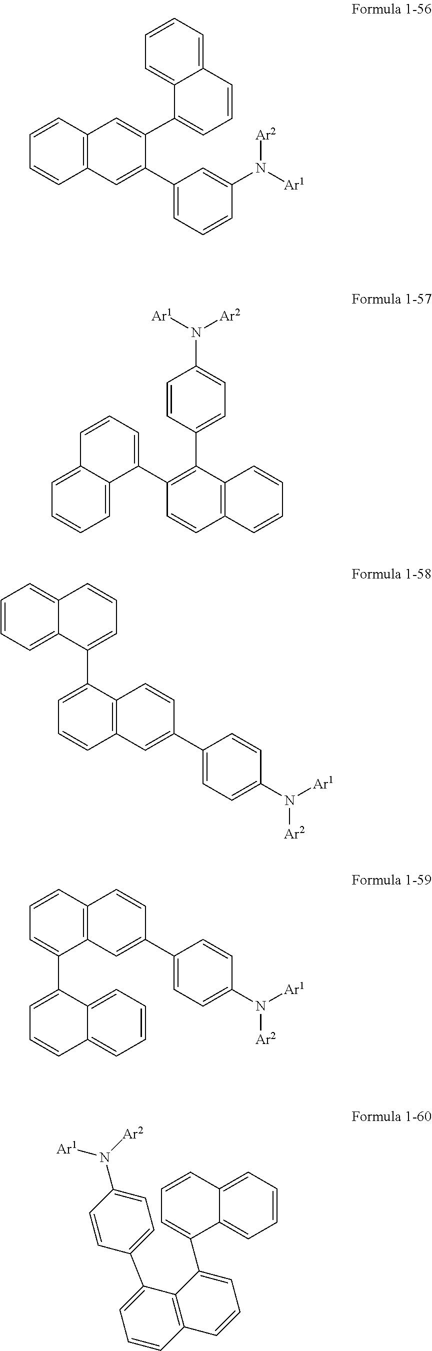 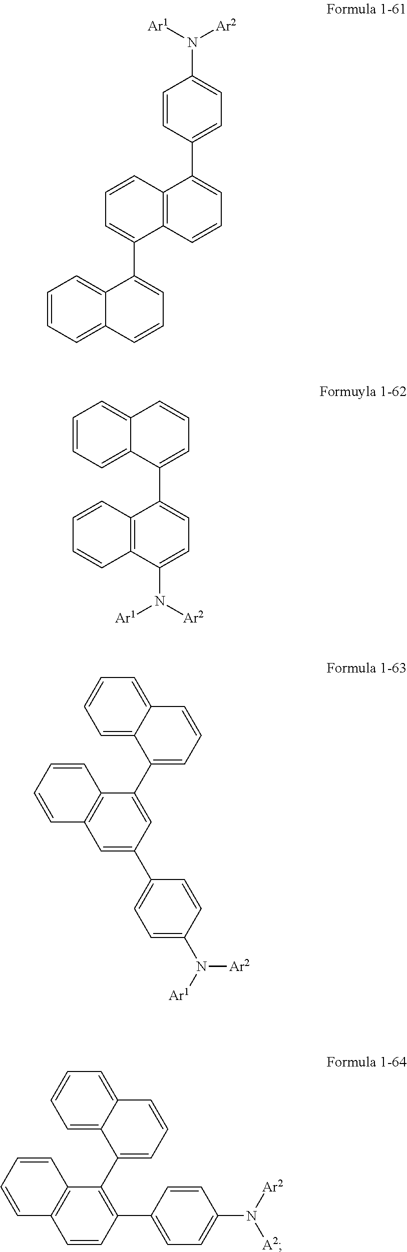
wherein Ar¹-Ar² are defined the same as that in claim 1.

5. The organic electroluminescent material composition according to claim 1, wherein in Formula 1-A, Ar² is selected from the following groups: 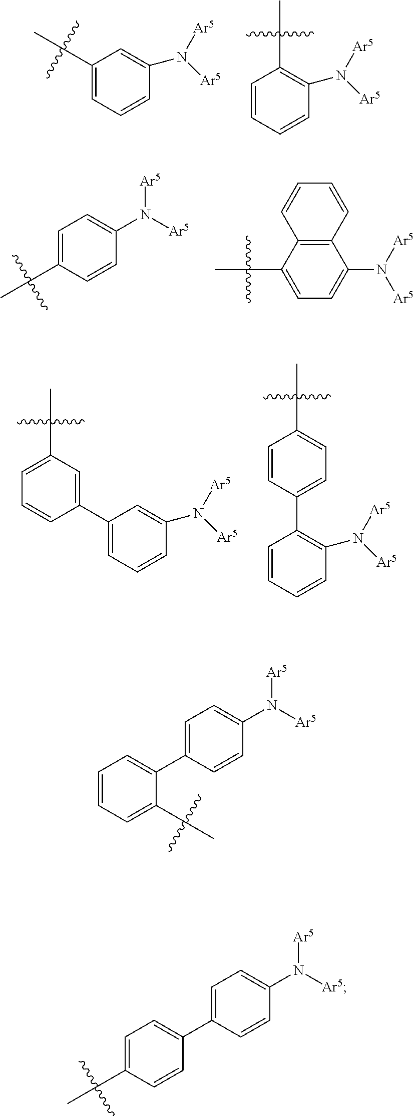
wherein
Ar⁵ is each independently selected from a substituted or unsubstituted B group, wherein the B group comprises: phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, benzofuryl, dibenzofuryl, naphthobenzofuryl, benzothienyl, dibenzothienyl, naphthobenzothienyl, carbazolyl, phenylcarbazolyl, benzophenylcarbazolyl, and dibenzophenylcarbazolyl;
wherein, the substituent of the substituted B group is selected from one of or a combination of two of deuterium, halogen, cyano, C1-C6 alkyl, C3-C30 cycloalkyl, C6-C30 aryl, C3-C30 heteroaryl, C6-C60 arylamine group, and C3-C60 heteroarylamine group.

6. The organic electroluminescent material composition according to claim 1, wherein the compound N has a structure shown as any one of Formula 1-a to Formula 1-h:

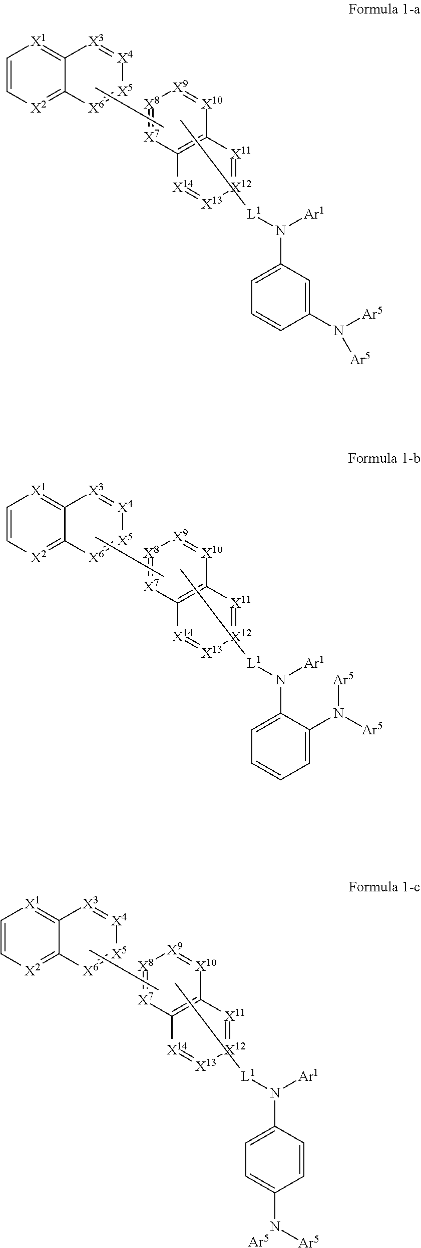

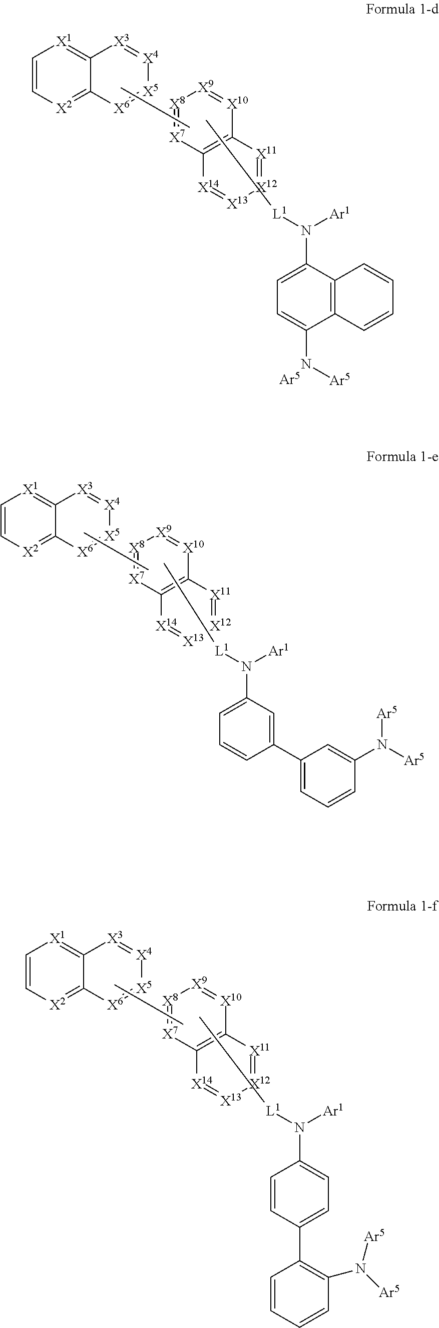

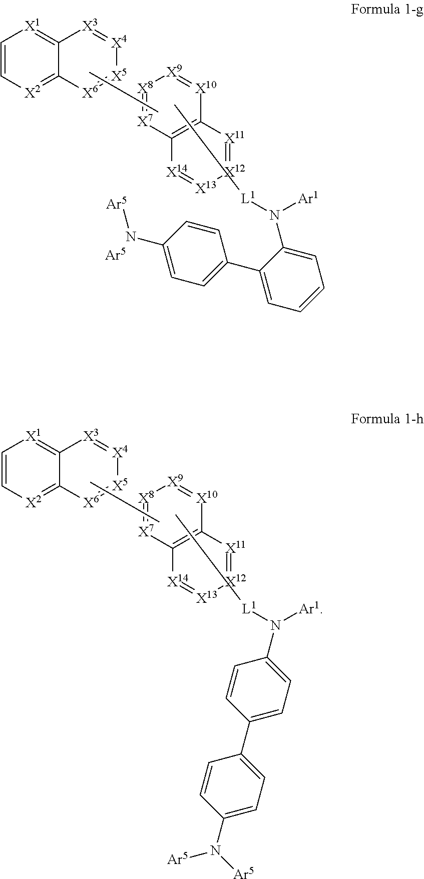

7. The organic electroluminescent material composition according to claim 1, wherein the compound N has a structure shown as any one of Formula 1-i to Formula 1-ii: 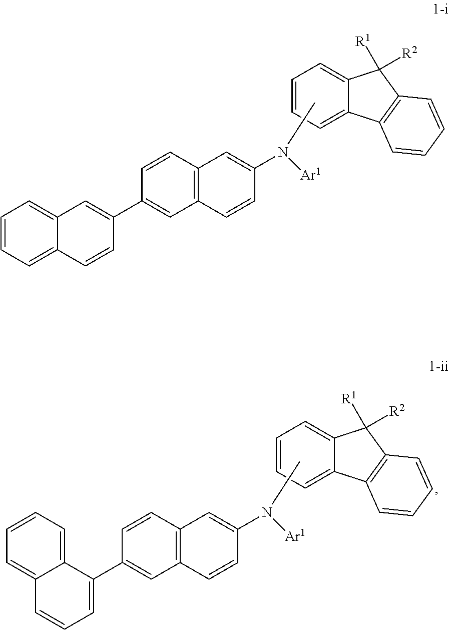
wherein, Ar¹ is defined the same as that in claim 1; R¹-R² are each independently selected from one of or a combination of two of hydrogen, deuterium, a substituted or unsubstituted C1-C6 alkyl, a substituted or unsubstituted C3-C30 cycloalkyl, a substituted or unsubstituted C6-C30 aryl, and a substituted or unsubstituted C3-C30 heteroaryl;
the substituent of the substituted C1-C6 alkyl, the substituted C3-C30 cycloalkyl, the substituted C6-C30 aryl, the substituted C3-C30 heteroaryl is selected from one of or a combination of two of deuterium, halogen, cyano, a C1-C6 alkyl, a C3-C30 cycloalkyl, a C6-C30 aryl, a C3-C30 heteroaryl, a C6-C60 arylamine group, and a C3-C60 heteroarylamine group.

8. The organic electroluminescent material composition according to claim 1, wherein in Formula 1-i or Formula 1-ii, R¹-R² are each independently selected from a C3-C15 cycloalkyl and a C6-C15 aryl;
preferably, R¹ and R² are each independently selected from methyl, phenyl, and fluorenyl;
preferably, Ar¹ is selected from a substituted or unsubstituted C6-C15 aryl and a substituted or unsubstituted C3-C15 heteroaryl; wherein, the substituent of the substituted C6-C15 aryl and the substituted C3-C15 heteroaryl is selected from deuterium, a C1-C3 alkyl, a C3-C10 cycloalkyl, and a C6-C12 aryl;
preferably, Ar¹ is selected from tolyl, phenyl, biphenyl, and dibenzofuryl.

9. The organic electroluminescent material composition according to claim 1, wherein the compound N has a structure shown as any one of the following Formula N-i-1 to Formula N-i-72.

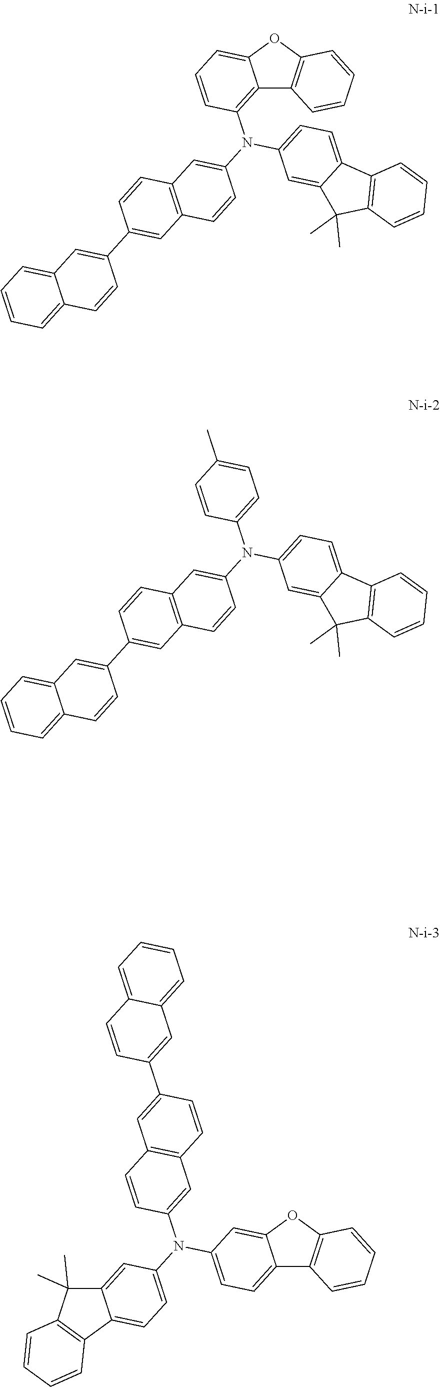 [SMILES: CC1(C)c2ccccc2-c2ccc(N(c3ccc4cc(-c5ccc6ccccc6c5)ccc4c3)c3cccc4oc5ccccc5c34)cc21 ; Cc1ccc(N(c2ccc3c(c2)C(C)(C)c2ccccc2-3)c2ccc3cc(-c4ccc5ccccc5c4)ccc3c2)cc1 ; CC1(C)c2ccccc2-c2ccc(N(c3ccc4cc(-c5ccc6ccccc6c5)ccc4c3)c3ccc4c(c3)oc3ccccc34)cc21]

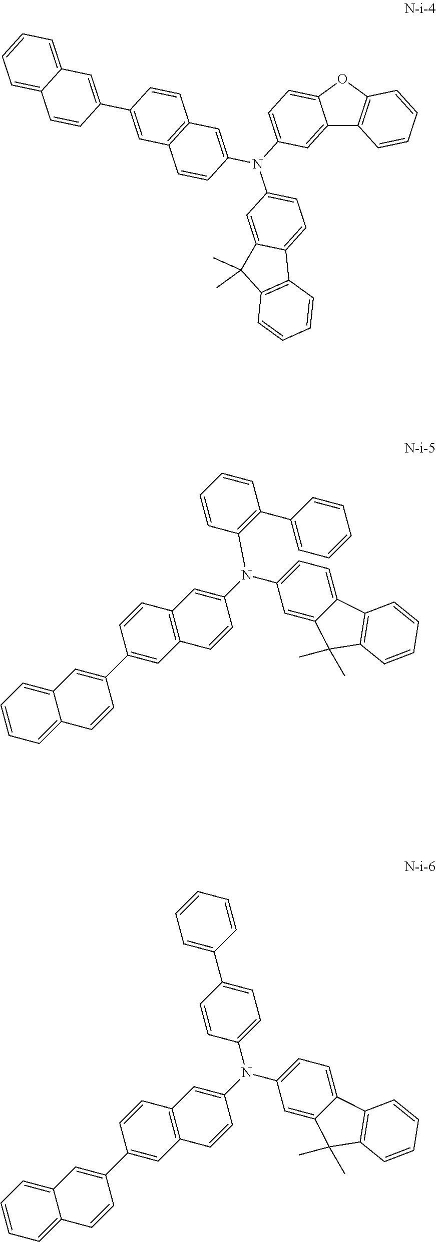 [SMILES: CC1(C)c2ccccc2-c2ccc(N(c3ccc4cc(-c5ccc6ccccc6c5)ccc4c3)c3ccc4oc5ccccc5c4c3)cc21 ; CC1(C)c2ccccc2-c2ccc(N(c3ccc4cc(-c5ccc6ccccc6c5)ccc4c3)c3ccccc3-c3ccccc3)cc21 ; CC1(C)c2ccccc2-c2ccc(N(c3ccc(-c4ccccc4)cc3)c3ccc4cc(-c5ccc6ccccc6c5)ccc4c3)cc21]

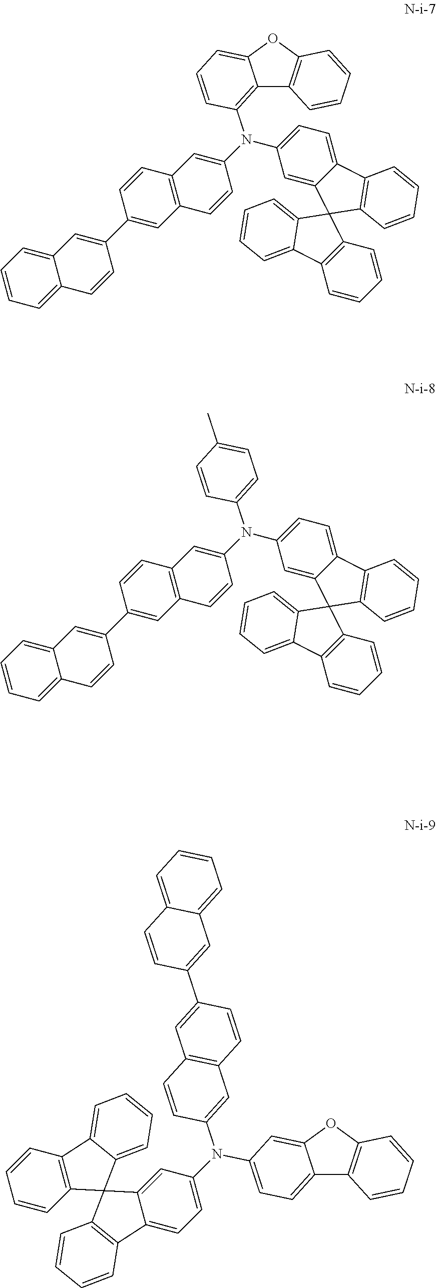 [SMILES: c1ccc2c(c1)-c1ccccc1C21c2ccccc2-c2ccc(N(c3ccc4cc(-c5ccc6ccccc6c5)ccc4c3)c3cccc4oc5ccccc5c34)cc21 ; Cc1ccc(N(c2ccc3c(c2)C2(c4ccccc4-c4ccccc42)c2ccccc2-3)c2ccc3cc(-c4ccc5ccccc5c4)ccc3c2)cc1 ; c1ccc2c(c1)-c1ccccc1C21c2ccccc2-c2ccc(N(c3ccc4cc(-c5ccc6ccccc6c5)ccc4c3)c3ccc4c(c3)oc3ccccc34)cc21]

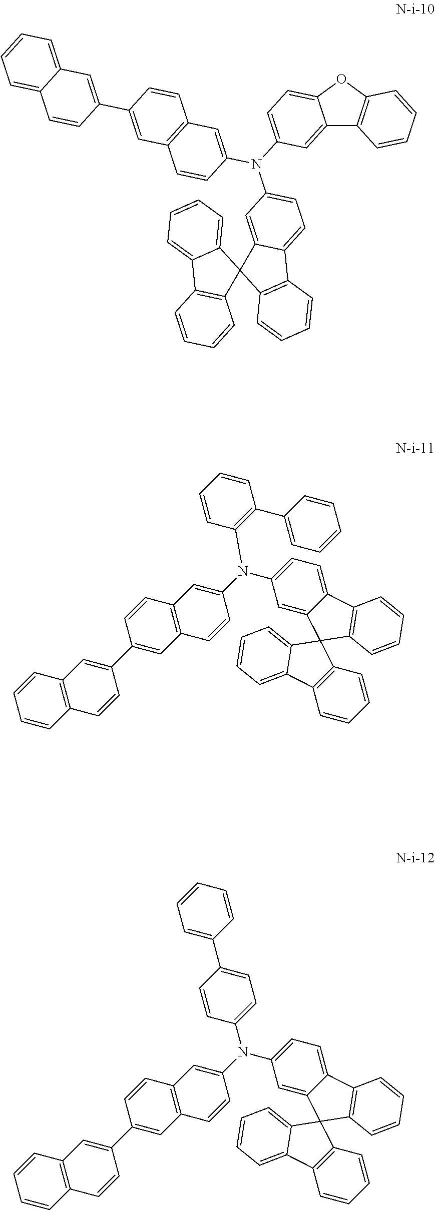 [SMILES: c1ccc2c(c1)-c1ccccc1C21c2ccccc2-c2ccc(N(c3ccc4cc(-c5ccc6ccccc6c5)ccc4c3)c3ccc4oc5ccccc5c4c3)cc21 ; c1ccc(-c2ccccc2N(c2ccc3c(c2)C2(c4ccccc4-c4ccccc42)c2ccccc2-3)c2ccc3cc(-c4ccc5ccccc5c4)ccc3c2)cc1 ; c1ccc(-c2ccc(N(c3ccc4c(c3)C3(c5ccccc5-c5ccccc53)c3ccccc3-4)c3ccc4cc(-c5ccc6ccccc6c5)ccc4c3)cc2)cc1]

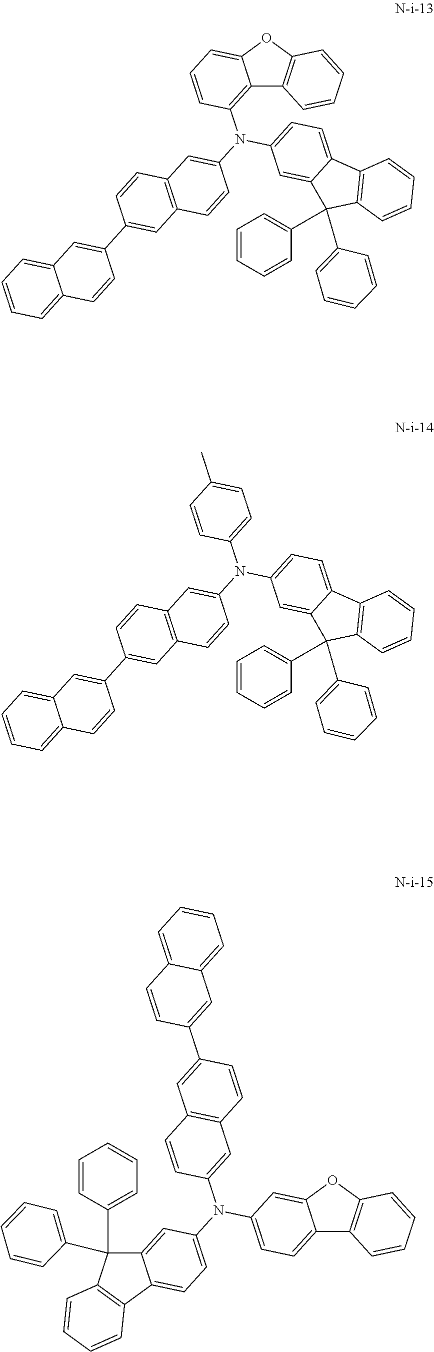 [SMILES: c1ccc(C2(c3ccccc3)c3ccccc3-c3ccc(N(c4ccc5cc(-c6ccc7ccccc7c6)ccc5c4)c4cccc5oc6ccccc6c45)cc32)cc1 ; Cc1ccc(N(c2ccc3c(c2)C(c2ccccc2)(c2ccccc2)c2ccccc2-3)c2ccc3cc(-c4ccc5ccccc5c4)ccc3c2)cc1 ; c1ccc(C2(c3ccccc3)c3ccccc3-c3ccc(N(c4ccc5cc(-c6ccc7ccccc7c6)ccc5c4)c4ccc5c(c4)oc4ccccc45)cc32)cc1]

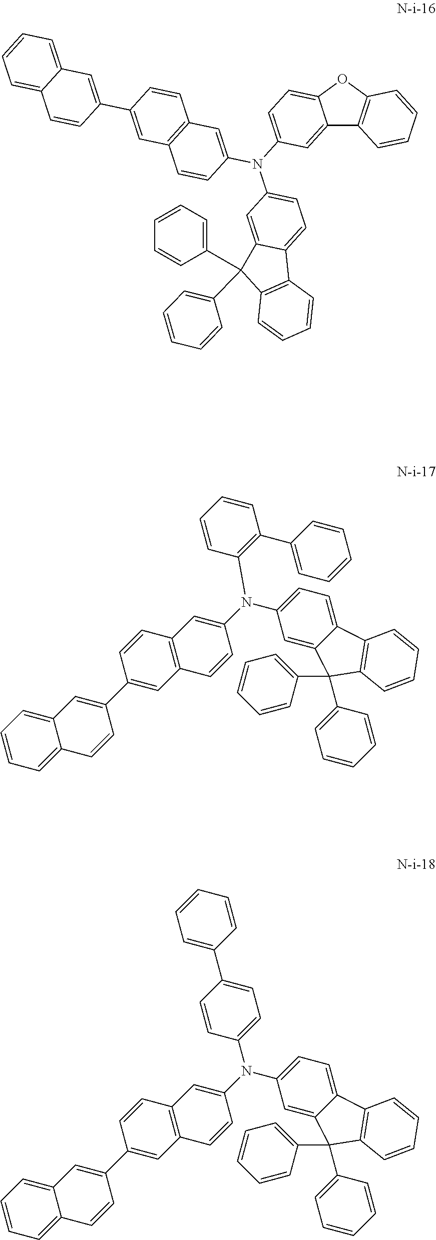 [SMILES: c1ccc(C2(c3ccccc3)c3ccccc3-c3ccc(N(c4ccc5cc(-c6ccc7ccccc7c6)ccc5c4)c4ccc5oc6ccccc6c5c4)cc32)cc1 ; c1ccc(-c2ccccc2N(c2ccc3c(c2)C(c2ccccc2)(c2ccccc2)c2ccccc2-3)c2ccc3cc(-c4ccc5ccccc5c4)ccc3c2)cc1 ; c1ccc(-c2ccc(N(c3ccc4c(c3)C(c3ccccc3)(c3ccccc3)c3ccccc3-4)c3ccc4cc(-c5ccc6ccccc6c5)ccc4c3)cc2)cc1]

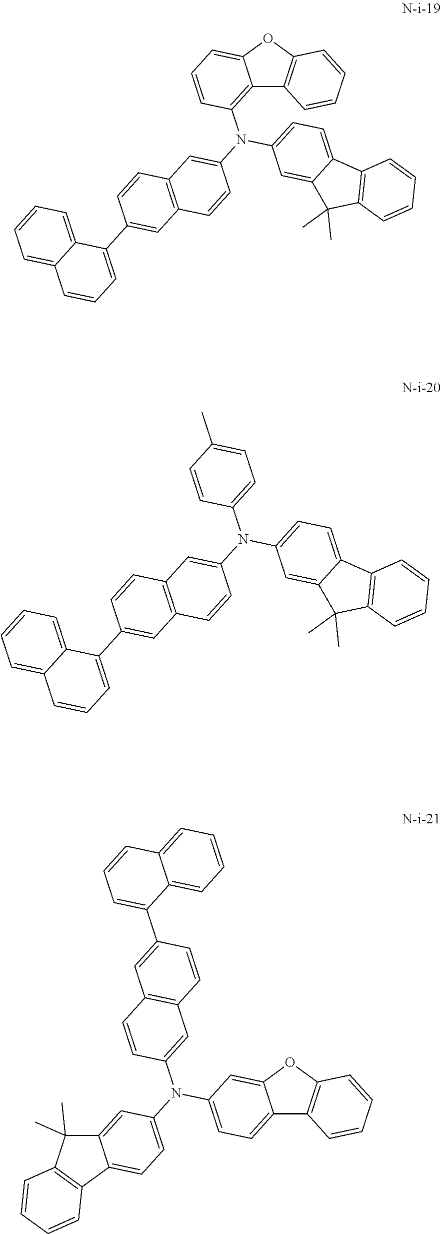 [SMILES: CC1(C)c2ccccc2-c2ccc(N(c3ccc4cc(-c5cccc6ccccc56)ccc4c3)c3cccc4oc5ccccc5c34)cc21 ; Cc1ccc(N(c2ccc3c(c2)C(C)(C)c2ccccc2-3)c2ccc3cc(-c4cccc5ccccc45)ccc3c2)cc1 ; CC1(C)c2ccccc2-c2ccc(N(c3ccc4cc(-c5cccc6ccccc56)ccc4c3)c3ccc4c(c3)oc3ccccc34)cc21]

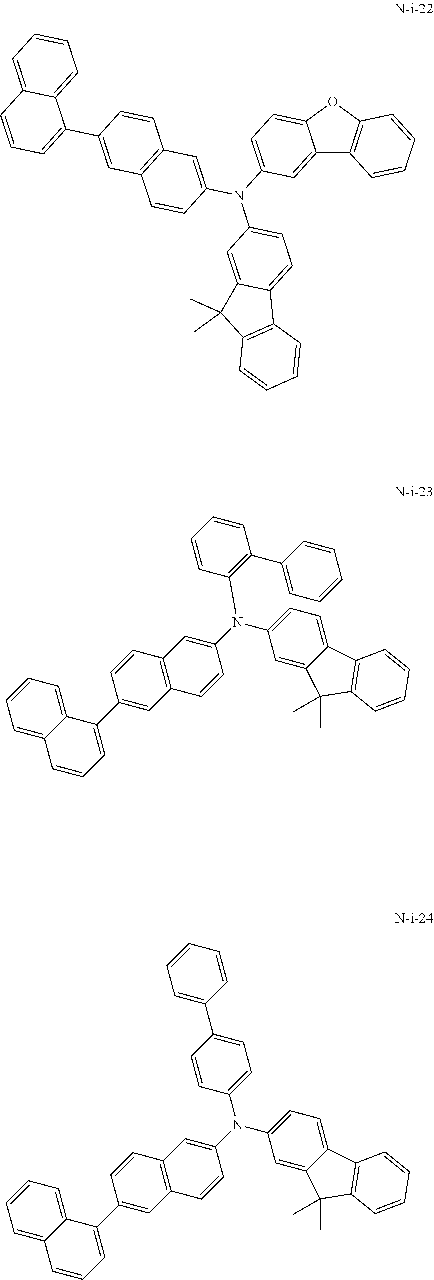 [SMILES: CC1(C)c2ccccc2-c2ccc(N(c3ccc4cc(-c5cccc6ccccc56)ccc4c3)c3ccc4oc5ccccc5c4c3)cc21 ; CC1(C)c2ccccc2-c2ccc(N(c3ccc4cc(-c5cccc6ccccc56)ccc4c3)c3ccccc3-c3ccccc3)cc21 ; CC1(C)c2ccccc2-c2ccc(N(c3ccc(-c4ccccc4)cc3)c3ccc4cc(-c5cccc6ccccc56)ccc4c3)cc21]

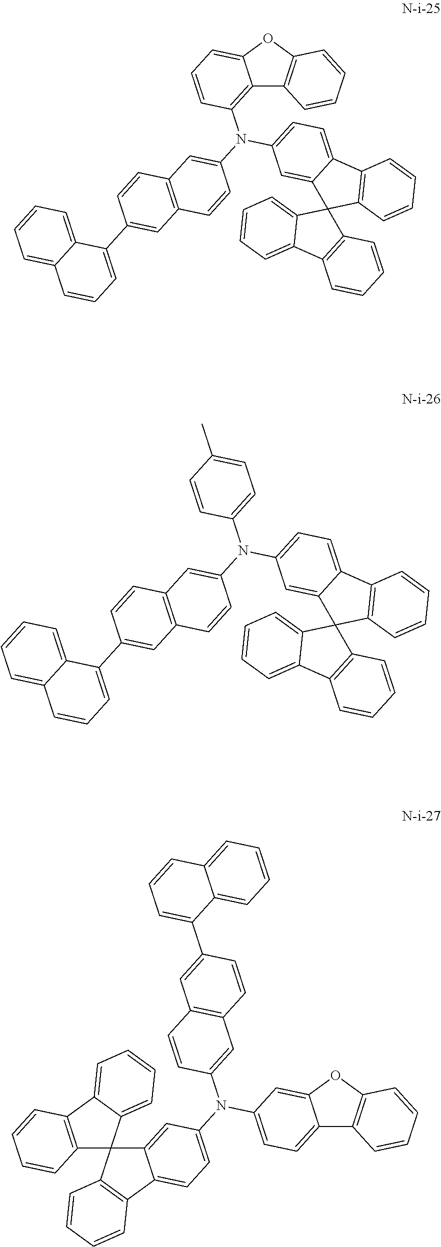 [SMILES: c1ccc2c(c1)-c1ccccc1C21c2ccccc2-c2ccc(N(c3ccc4cc(-c5cccc6ccccc56)ccc4c3)c3cccc4oc5ccccc5c34)cc21 ; Cc1ccc(N(c2ccc3c(c2)C2(c4ccccc4-c4ccccc42)c2ccccc2-3)c2ccc3cc(-c4cccc5ccccc45)ccc3c2)cc1 ; c1ccc2c(c1)-c1ccccc1C21c2ccccc2-c2ccc(N(c3ccc4cc(-c5cccc6ccccc56)ccc4c3)c3ccc4c(c3)oc3ccccc34)cc21]

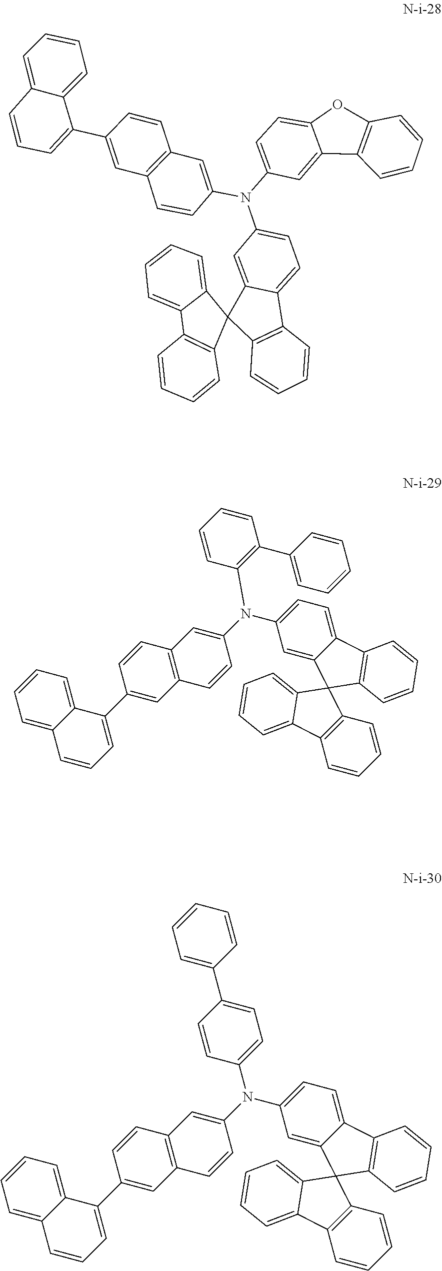 [SMILES: c1ccc2c(c1)-c1ccccc1C21c2ccccc2-c2ccc(N(c3ccc4cc(-c5cccc6ccccc56)ccc4c3)c3ccc4oc5ccccc5c4c3)cc21 ; c1ccc(-c2ccccc2N(c2ccc3c(c2)C2(c4ccccc4-c4ccccc42)c2ccccc2-3)c2ccc3cc(-c4cccc5ccccc45)ccc3c2)cc1 ; c1ccc(-c2ccc(N(c3ccc4c(c3)C3(c5ccccc5-c5ccccc53)c3ccccc3-4)c3ccc4cc(-c5cccc6ccccc56)ccc4c3)cc2)cc1]

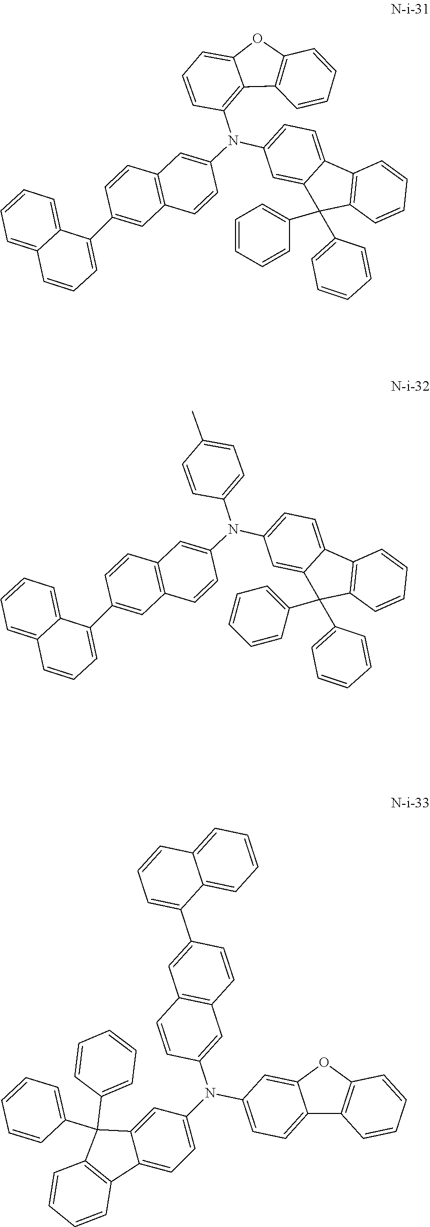 [SMILES: c1ccc(C2(c3ccccc3)c3ccccc3-c3ccc(N(c4ccc5cc(-c6cccc7ccccc67)ccc5c4)c4cccc5oc6ccccc6c45)cc32)cc1 ; Cc1ccc(N(c2ccc3c(c2)C(c2ccccc2)(c2ccccc2)c2ccccc2-3)c2ccc3cc(-c4cccc5ccccc45)ccc3c2)cc1 ; c1ccc(C2(c3ccccc3)c3ccccc3-c3ccc(N(c4ccc5cc(-c6cccc7ccccc67)ccc5c4)c4ccc5c(c4)oc4ccccc45)cc32)cc1]

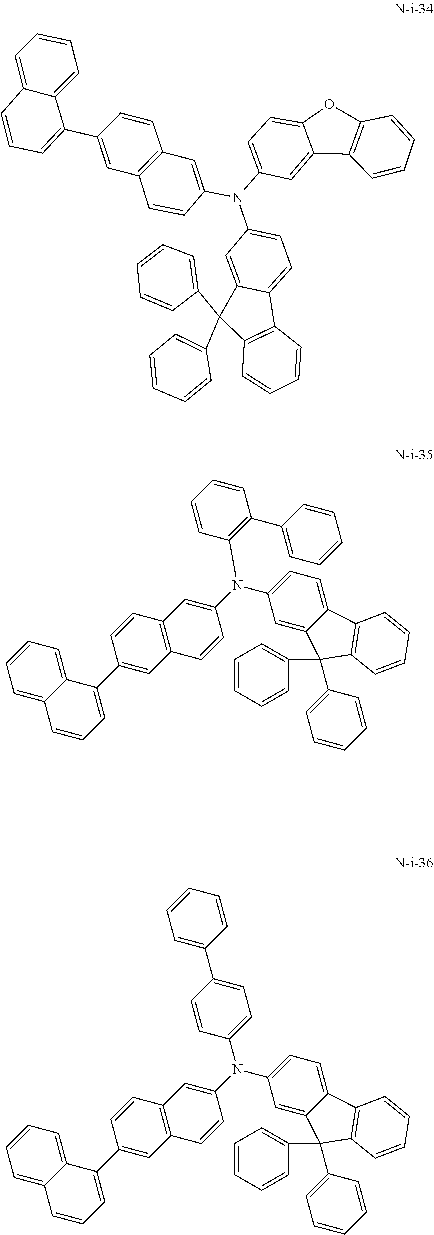 [SMILES: c1ccc(C2(c3ccccc3)c3ccccc3-c3ccc(N(c4ccc5cc(-c6cccc7ccccc67)ccc5c4)c4ccc5oc6ccccc6c5c4)cc32)cc1 ; c1ccc(-c2ccccc2N(c2ccc3c(c2)C(c2ccccc2)(c2ccccc2)c2ccccc2-3)c2ccc3cc(-c4cccc5ccccc45)ccc3c2)cc1 ; c1ccc(-c2ccc(N(c3ccc4c(c3)C(c3ccccc3)(c3ccccc3)c3ccccc3-4)c3ccc4cc(-c5cccc6ccccc56)ccc4c3)cc2)cc1]

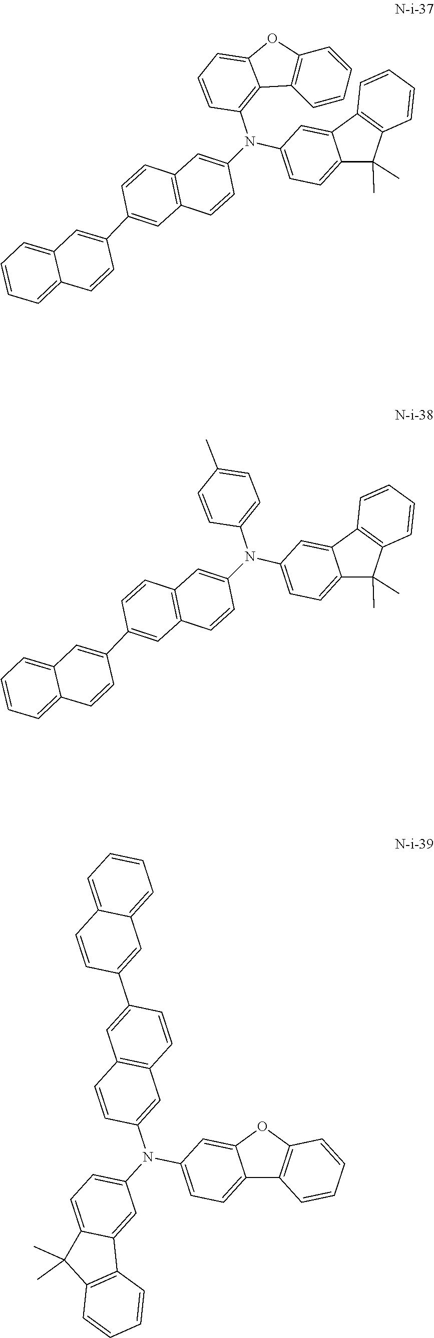 [SMILES: CC1(C)c2ccccc2-c2cc(N(c3ccc4cc(-c5ccc6ccccc6c5)ccc4c3)c3cccc4oc5ccccc5c34)ccc21 ; Cc1ccc(N(c2ccc3c(c2)-c2ccccc2C3(C)C)c2ccc3cc(-c4ccc5ccccc5c4)ccc3c2)cc1 ; CC1(C)c2ccccc2-c2cc(N(c3ccc4cc(-c5ccc6ccccc6c5)ccc4c3)c3ccc4c(c3)oc3ccccc34)ccc21]

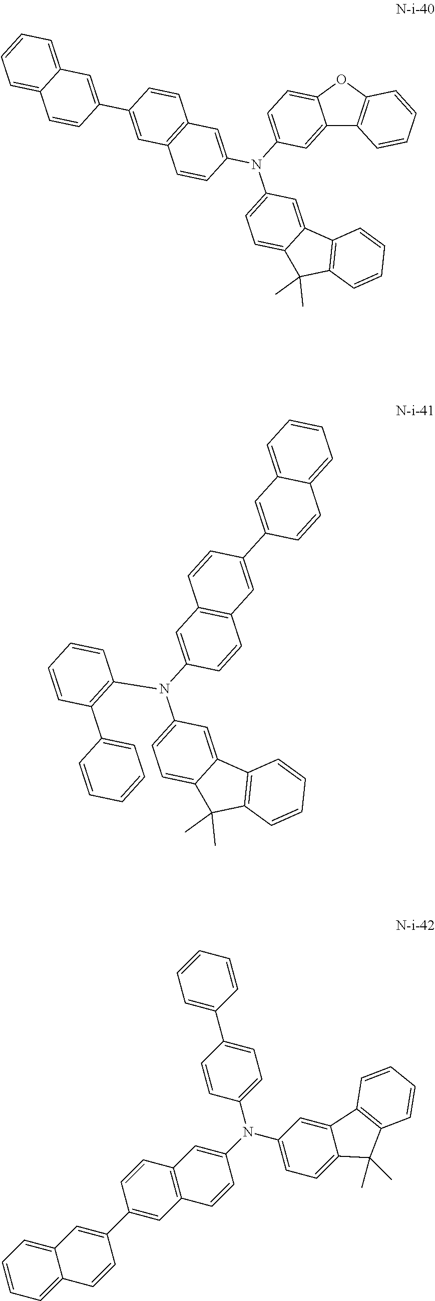 [SMILES: CC1(C)c2ccccc2-c2cc(N(c3ccc4cc(-c5ccc6ccccc6c5)ccc4c3)c3ccc4oc5ccccc5c4c3)ccc21 ; CC1(C)c2ccccc2-c2cc(N(c3ccc4cc(-c5ccc6ccccc6c5)ccc4c3)c3ccccc3-c3ccccc3)ccc21 ; CC1(C)c2ccccc2-c2cc(N(c3ccc(-c4ccccc4)cc3)c3ccc4cc(-c5ccc6ccccc6c5)ccc4c3)ccc21]

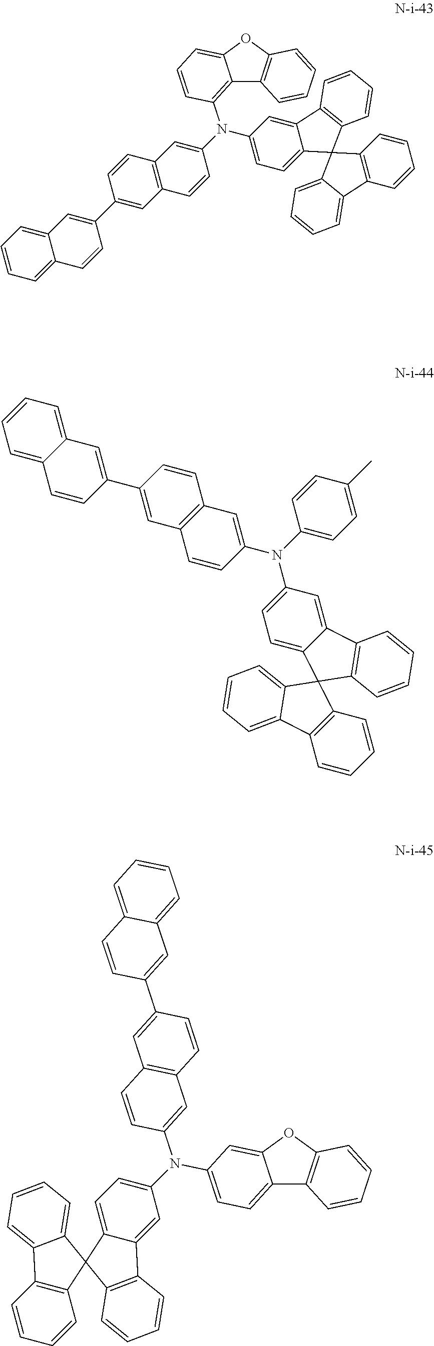 [SMILES: c1ccc2c(c1)-c1ccccc1C21c2ccccc2-c2cc(N(c3ccc4cc(-c5ccc6ccccc6c5)ccc4c3)c3cccc4oc5ccccc5c34)ccc21 ; Cc1ccc(N(c2ccc3c(c2)-c2ccccc2C32c3ccccc3-c3ccccc32)c2ccc3cc(-c4ccc5ccccc5c4)ccc3c2)cc1 ; c1ccc2c(c1)-c1ccccc1C21c2ccccc2-c2cc(N(c3ccc4cc(-c5ccc6ccccc6c5)ccc4c3)c3ccc4c(c3)oc3ccccc34)ccc21]

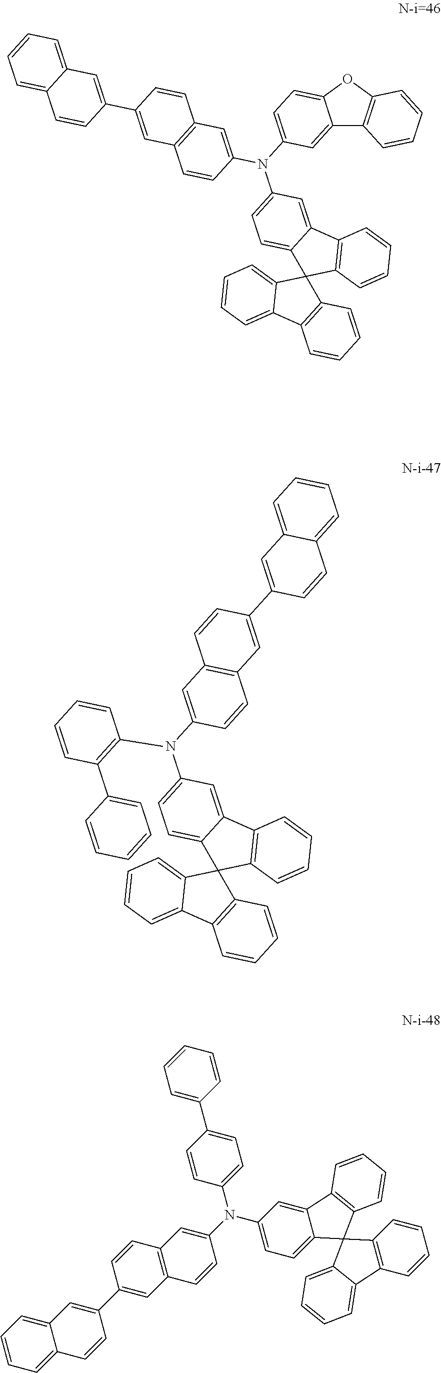 [SMILES: c1ccc2c(c1)-c1ccccc1C21c2ccccc2-c2cc(N(c3ccc4cc(-c5ccc6ccccc6c5)ccc4c3)c3ccc4oc5ccccc5c4c3)ccc21 ; c1ccc(-c2ccccc2N(c2ccc3c(c2)-c2ccccc2C32c3ccccc3-c3ccccc32)c2ccc3cc(-c4ccc5ccccc5c4)ccc3c2)cc1 ; c1ccc(-c2ccc(N(c3ccc4c(c3)-c3ccccc3C43c4ccccc4-c4ccccc43)c3ccc4cc(-c5ccc6ccccc6c5)ccc4c3)cc2)cc1]

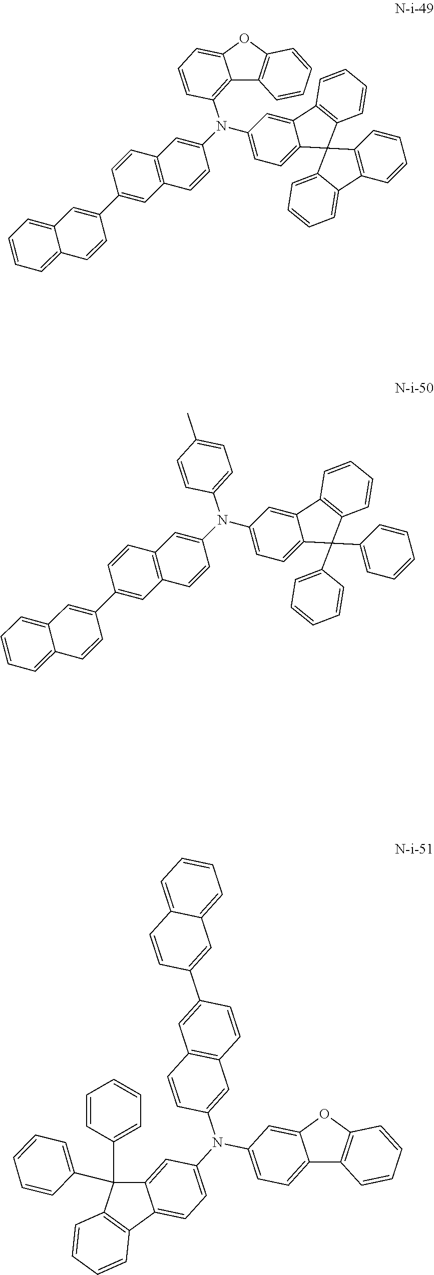 [SMILES: c1ccc2c(c1)-c1ccccc1C21c2ccccc2-c2cc(N(c3ccc4cc(-c5ccc6ccccc6c5)ccc4c3)c3cccc4oc5ccccc5c34)ccc21 ; Cc1ccc(N(c2ccc3c(c2)-c2ccccc2C3(c2ccccc2)c2ccccc2)c2ccc3cc(-c4ccc5ccccc5c4)ccc3c2)cc1 ; c1ccc(C2(c3ccccc3)c3ccccc3-c3ccc(N(c4ccc5cc(-c6ccc7ccccc7c6)ccc5c4)c4ccc5c(c4)oc4ccccc45)cc32)cc1]

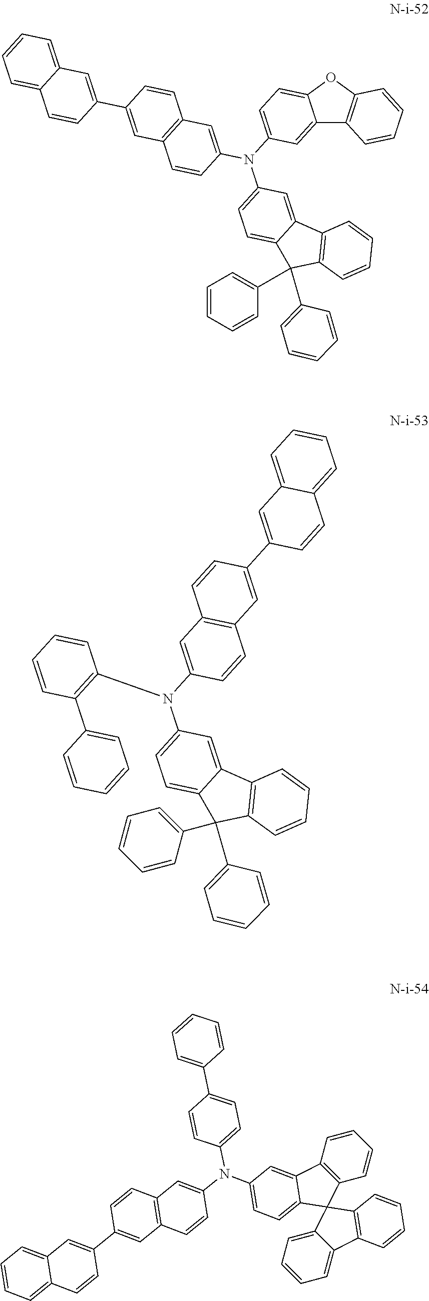 [SMILES: c1ccc(C2(c3ccccc3)c3ccccc3-c3cc(N(c4ccc5cc(-c6ccc7ccccc7c6)ccc5c4)c4ccc5oc6ccccc6c5c4)ccc32)cc1 ; c1ccc(-c2ccccc2N(c2ccc3c(c2)-c2ccccc2C3(c2ccccc2)c2ccccc2)c2ccc3cc(-c4ccc5ccccc5c4)ccc3c2)cc1 ; c1ccc(-c2ccc(N(c3ccc4c(c3)-c3ccccc3C43c4ccccc4-c4ccccc43)c3ccc4cc(-c5ccc6ccccc6c5)ccc4c3)cc2)cc1]

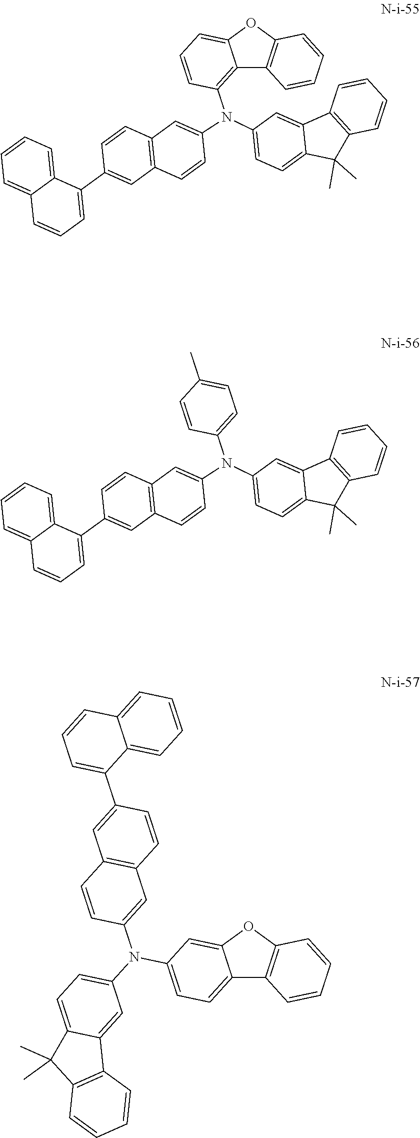 [SMILES: CC1(C)c2ccccc2-c2cc(N(c3ccc4cc(-c5cccc6ccccc56)ccc4c3)c3cccc4oc5ccccc5c34)ccc21 ; Cc1ccc(N(c2ccc3c(c2)-c2ccccc2C3(C)C)c2ccc3cc(-c4cccc5ccccc45)ccc3c2)cc1 ; CC1(C)c2ccccc2-c2cc(N(c3ccc4cc(-c5cccc6ccccc56)ccc4c3)c3ccc4c(c3)oc3ccccc34)ccc21]

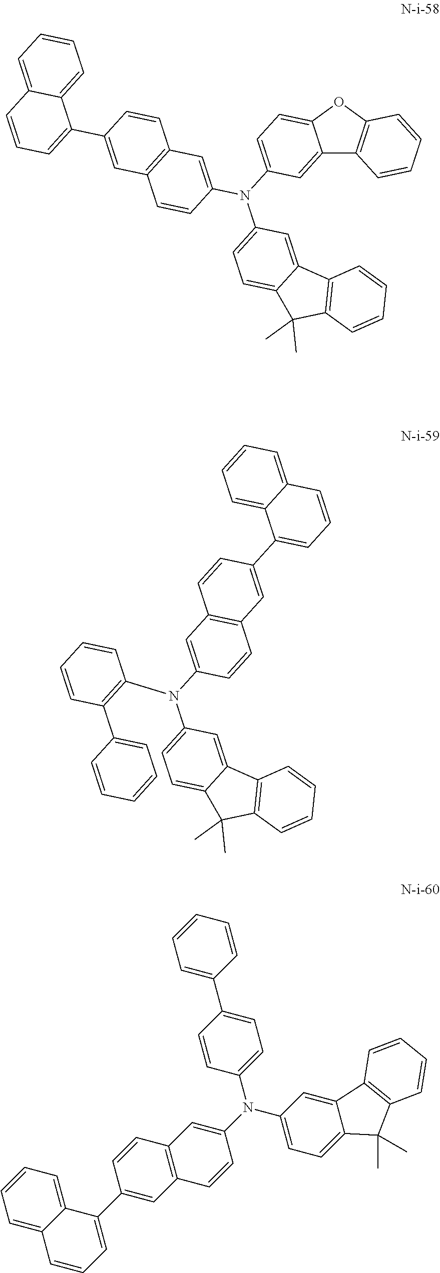 [SMILES: CC1(C)c2ccccc2-c2cc(N(c3ccc4cc(-c5cccc6ccccc56)ccc4c3)c3ccc4oc5ccccc5c4c3)ccc21 ; CC1(C)c2ccccc2-c2cc(N(c3ccc4cc(-c5cccc6ccccc56)ccc4c3)c3ccccc3-c3ccccc3)ccc21 ; CC1(C)c2ccccc2-c2cc(N(c3ccc(-c4ccccc4)cc3)c3ccc4cc(-c5cccc6ccccc56)ccc4c3)ccc21]

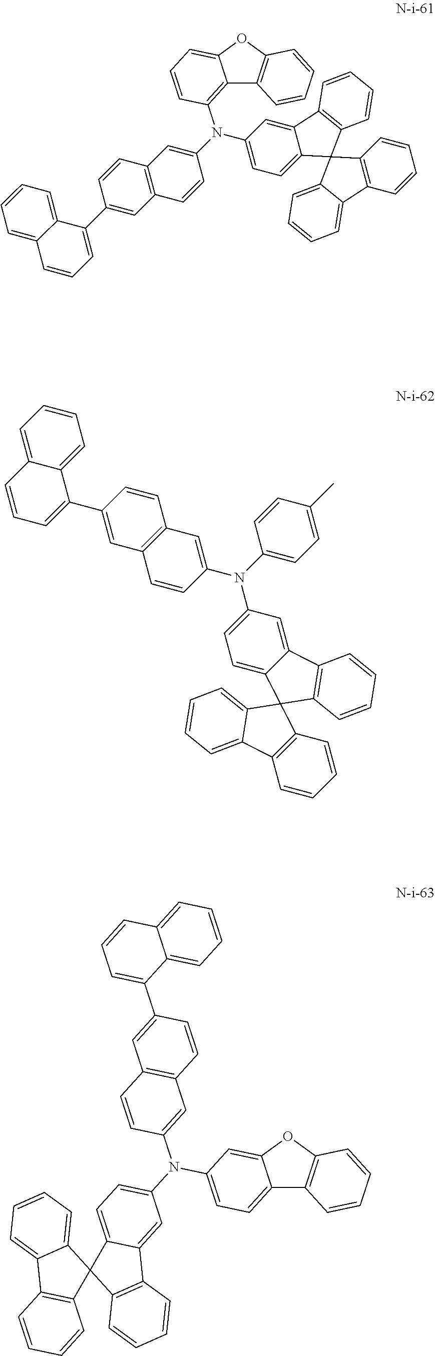 [SMILES: c1ccc2c(c1)-c1ccccc1C21c2ccccc2-c2cc(N(c3ccc4cc(-c5cccc6ccccc56)ccc4c3)c3cccc4oc5ccccc5c34)ccc21 ; Cc1ccc(N(c2ccc3c(c2)-c2ccccc2C32c3ccccc3-c3ccccc32)c2ccc3cc(-c4cccc5ccccc45)ccc3c2)cc1 ; c1ccc2c(c1)-c1ccccc1C21c2ccccc2-c2cc(N(c3ccc4cc(-c5cccc6ccccc56)ccc4c3)c3ccc4c(c3)oc3ccccc34)ccc21]

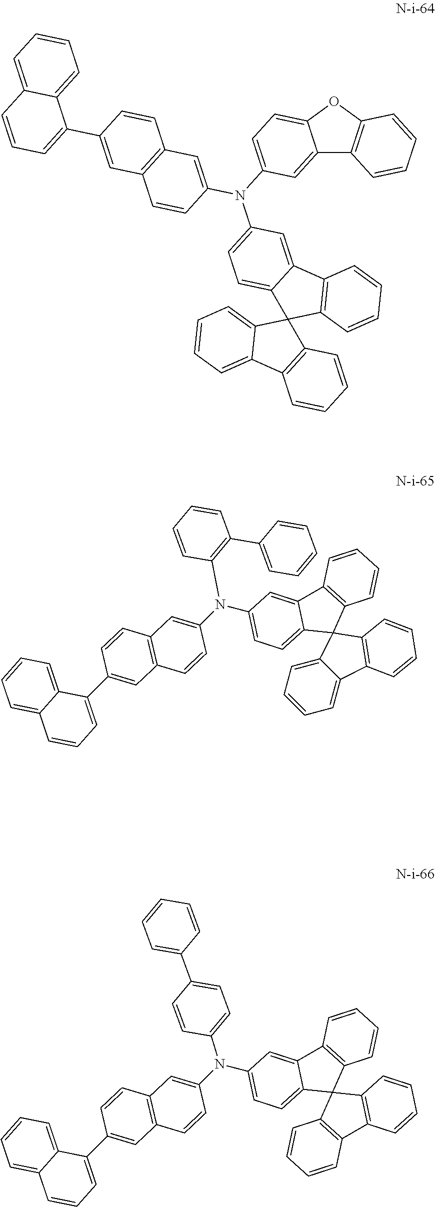 [SMILES: c1ccc2c(c1)-c1ccccc1C21c2ccccc2-c2cc(N(c3ccc4cc(-c5cccc6ccccc56)ccc4c3)c3ccc4oc5ccccc5c4c3)ccc21 ; c1ccc(-c2ccccc2N(c2ccc3c(c2)-c2ccccc2C32c3ccccc3-c3ccccc32)c2ccc3cc(-c4cccc5ccccc45)ccc3c2)cc1 ; c1ccc(-c2ccc(N(c3ccc4c(c3)-c3ccccc3C43c4ccccc4-c4ccccc43)c3ccc4cc(-c5cccc6ccccc56)ccc4c3)cc2)cc1]

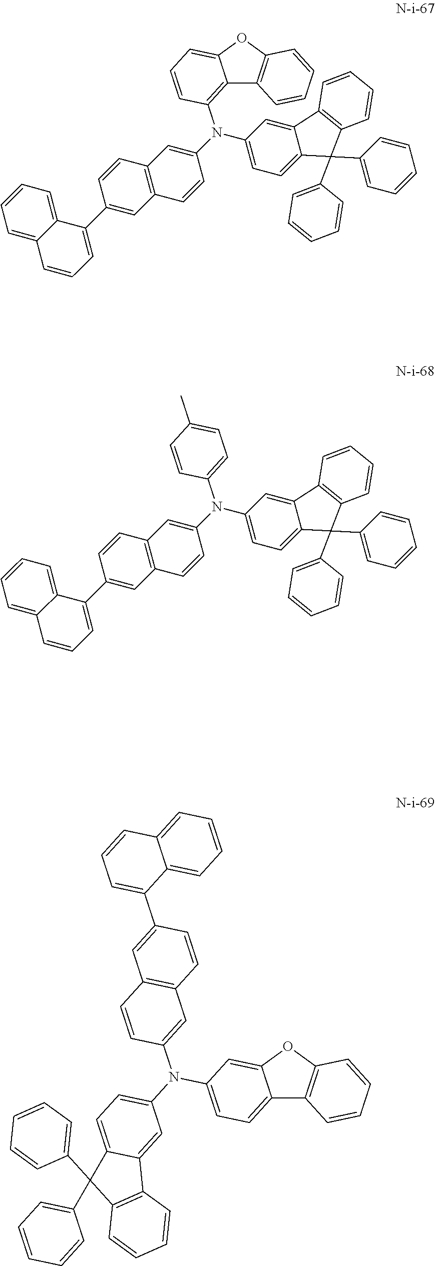 [SMILES: c1ccc(C2(c3ccccc3)c3ccccc3-c3cc(N(c4ccc5cc(-c6cccc7ccccc67)ccc5c4)c4cccc5oc6ccccc6c45)ccc32)cc1 ; Cc1ccc(N(c2ccc3c(c2)-c2ccccc2C3(c2ccccc2)c2ccccc2)c2ccc3cc(-c4cccc5ccccc45)ccc3c2)cc1 ; c1ccc(C2(c3ccccc3)c3ccccc3-c3cc(N(c4ccc5cc(-c6cccc7ccccc67)ccc5c4)c4ccc5c(c4)oc4ccccc45)ccc32)cc1]

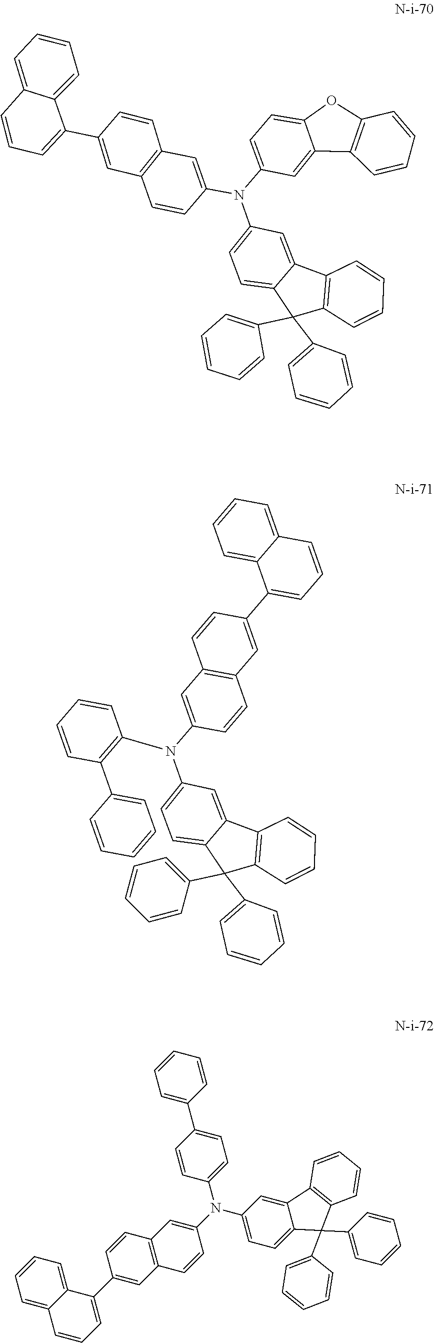 [SMILES: c1ccc(C2(c3ccccc3)c3ccccc3-c3cc(N(c4ccc5cc(-c6cccc7ccccc67)ccc5c4)c4ccc5oc6ccccc6c5c4)ccc32)cc1 ; c1ccc(-c2ccccc2N(c2ccc3c(c2)-c2ccccc2C3(c2ccccc2)c2ccccc2)c2ccc3cc(-c4cccc5ccccc45)ccc3c2)cc1 ; c1ccc(-c2ccc(N(c3ccc4c(c3)-c3ccccc3C4(c3ccccc3)c3ccccc3)c3ccc4cc(-c5cccc6ccccc56)ccc4c3)cc2)cc1]

10. The organic electroluminescent material composition according to claim 1, wherein the compound N has the structure shown in any one of the following N-1 to N-549:

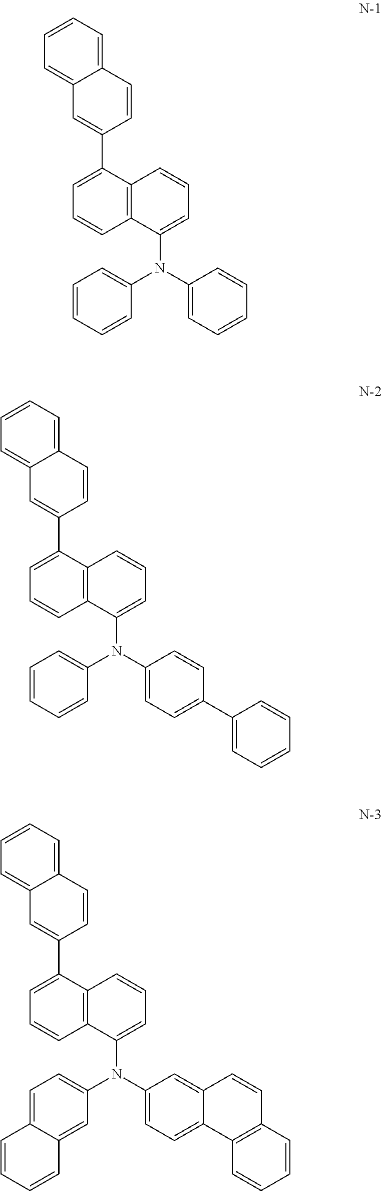 [SMILES: c1ccc(N(c2ccccc2)c2cccc3c(-c4ccc5ccccc5c4)cccc23)cc1 ; c1ccc(-c2ccc(N(c3ccccc3)c3cccc4c(-c5ccc6ccccc6c5)cccc34)cc2)cc1 ; c1ccc2cc(-c3cccc4c(N(c5ccc6ccccc6c5)c5ccc6c(ccc7ccccc76)c5)cccc34)ccc2c1]

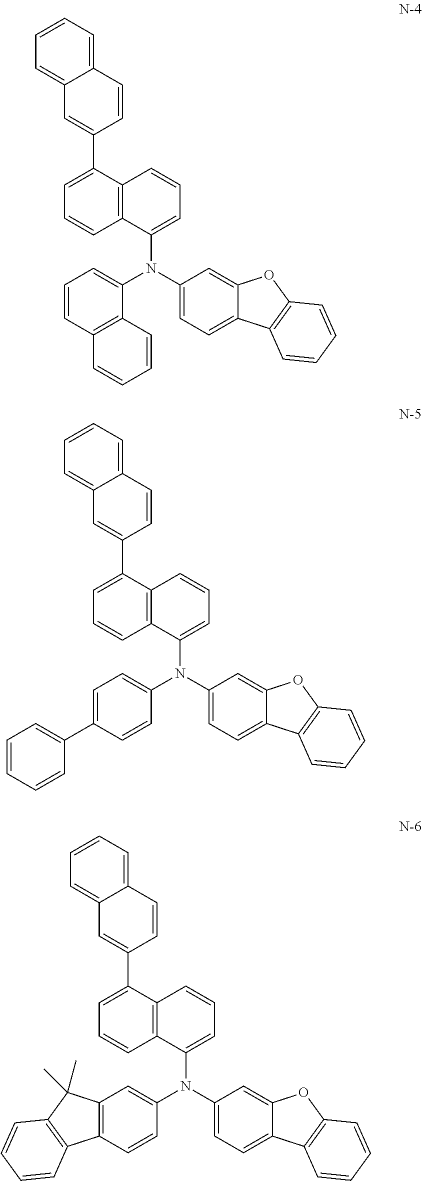 [SMILES: c1ccc2cc(-c3cccc4c(N(c5ccc6c(c5)oc5ccccc56)c5cccc6ccccc56)cccc34)ccc2c1 ; c1ccc(-c2ccc(N(c3ccc4c(c3)oc3ccccc34)c3cccc4c(-c5ccc6ccccc6c5)cccc34)cc2)cc1 ; CC1(C)c2ccccc2-c2ccc(N(c3ccc4c(c3)oc3ccccc34)c3cccc4c(-c5ccc6ccccc6c5)cccc34)cc21]

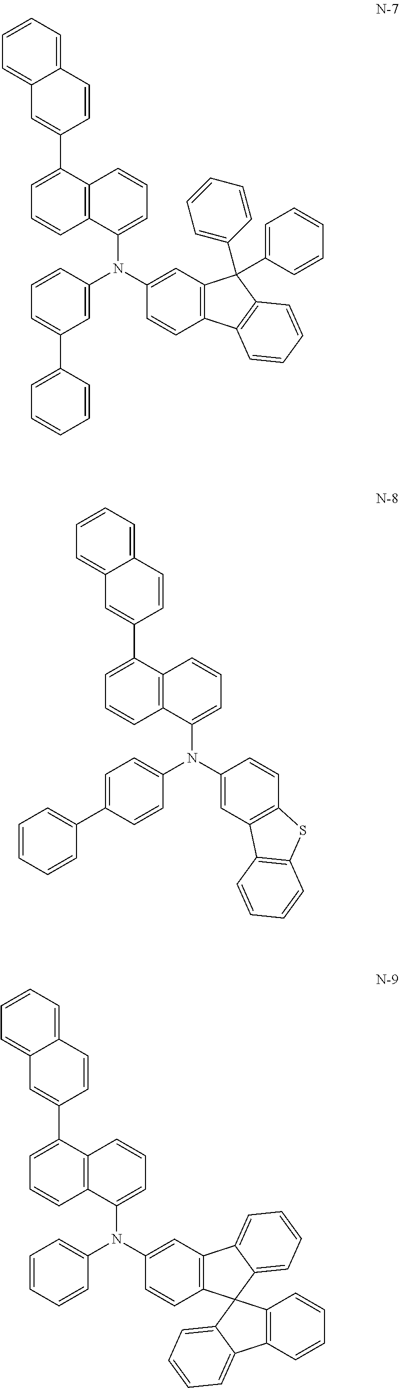 [SMILES: c1ccc(-c2cccc(N(c3ccc4c(c3)C(c3ccccc3)(c3ccccc3)c3ccccc3-4)c3cccc4c(-c5ccc6ccccc6c5)cccc34)c2)cc1 ; c1ccc(-c2ccc(N(c3ccc4sc5ccccc5c4c3)c3cccc4c(-c5ccc6ccccc6c5)cccc34)cc2)cc1 ; c1ccc(N(c2ccc3c(c2)-c2ccccc2C32c3ccccc3-c3ccccc32)c2cccc3c(-c4ccc5ccccc5c4)cccc23)cc1]

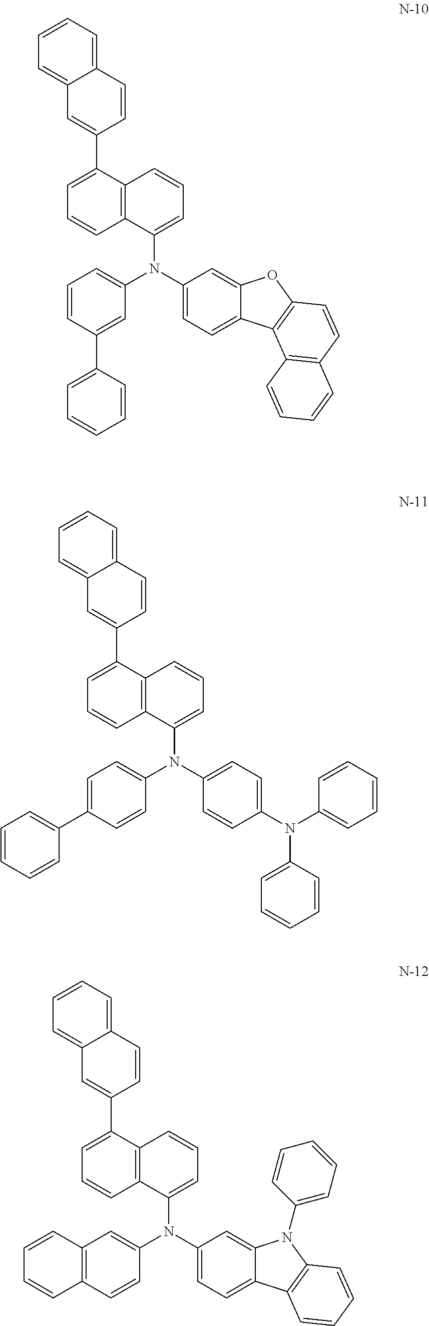 [SMILES: c1ccc(-c2cccc(N(c3ccc4c(c3)oc3ccc5ccccc5c34)c3cccc4c(-c5ccc6ccccc6c5)cccc34)c2)cc1 ; c1ccc(-c2ccc(N(c3ccc(N(c4ccccc4)c4ccccc4)cc3)c3cccc4c(-c5ccc6ccccc6c5)cccc34)cc2)cc1 ; c1ccc(-n2c3ccccc3c3ccc(N(c4ccc5ccccc5c4)c4cccc5c(-c6ccc7ccccc7c6)cccc45)cc32)cc1]

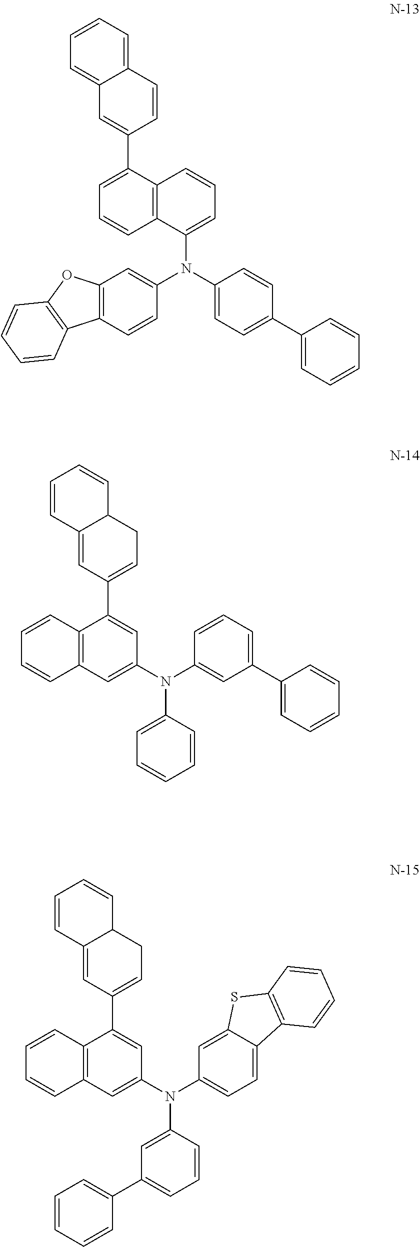 [SMILES: c1ccc(-c2ccc(N(c3ccc4c(c3)oc3ccccc34)c3cccc4c(-c5ccc6ccccc6c5)cccc34)cc2)cc1 ; C1=CC2=CC(c3cc(N(c4ccccc4)c4cccc(-c5ccccc5)c4)cc4ccccc34)=CCC2C=C1 ; C1=CC2=CC(c3cc(N(c4cccc(-c5ccccc5)c4)c4ccc5c(c4)sc4ccccc45)cc4ccccc34)=CCC2C=C1]

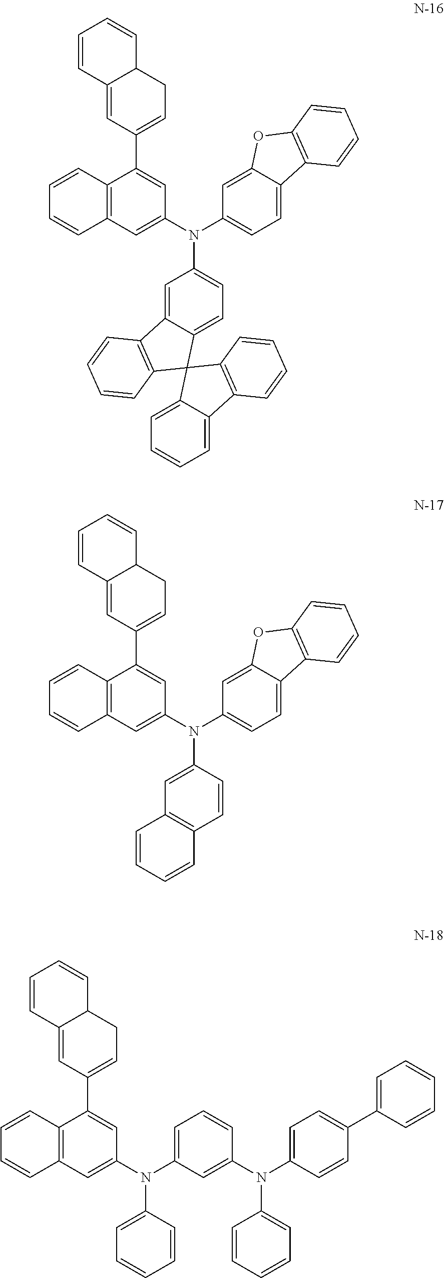 [SMILES: C1=CC2=CC(c3cc(N(c4ccc5c(c4)-c4ccccc4C54c5ccccc5-c5ccccc54)c4ccc5c(c4)oc4ccccc45)cc4ccccc34)=CCC2C=C1 ; C1=CC2=CC(c3cc(N(c4ccc5ccccc5c4)c4ccc5c(c4)oc4ccccc45)cc4ccccc34)=CCC2C=C1 ; C1=CC2=CC(c3cc(N(c4ccccc4)c4cccc(N(c5ccccc5)c5ccc(-c6ccccc6)cc5)c4)cc4ccccc34)=CCC2C=C1]

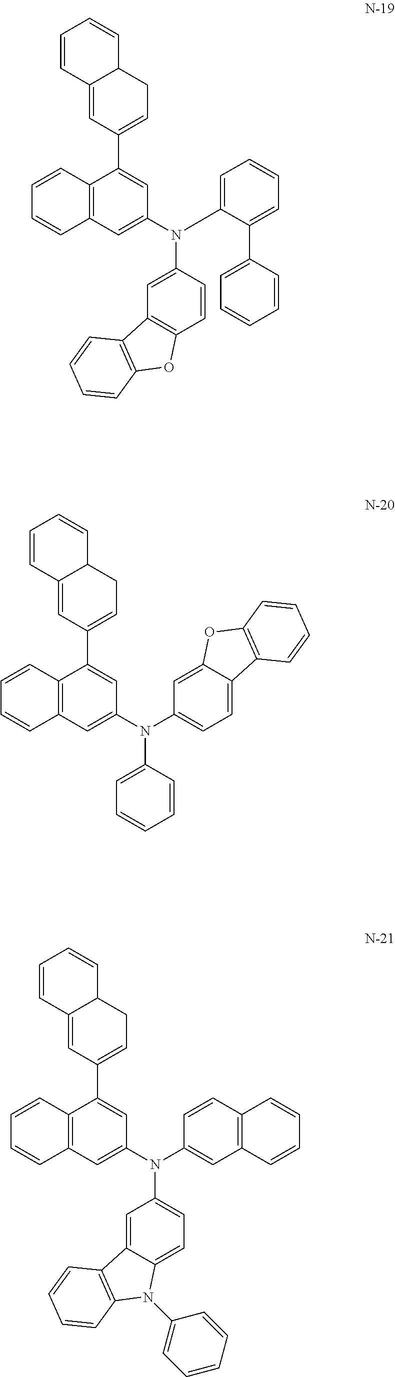 [SMILES: C1=CC2=CC(c3cc(N(c4ccc5oc6ccccc6c5c4)c4ccccc4-c4ccccc4)cc4ccccc34)=CCC2C=C1 ; C1=CC2=CC(c3cc(N(c4ccccc4)c4ccc5c(c4)oc4ccccc45)cc4ccccc34)=CCC2C=C1 ; C1=CC2=CC(c3cc(N(c4ccc5ccccc5c4)c4ccc5c(c4)c4ccccc4n5-c4ccccc4)cc4ccccc34)=CCC2C=C1]

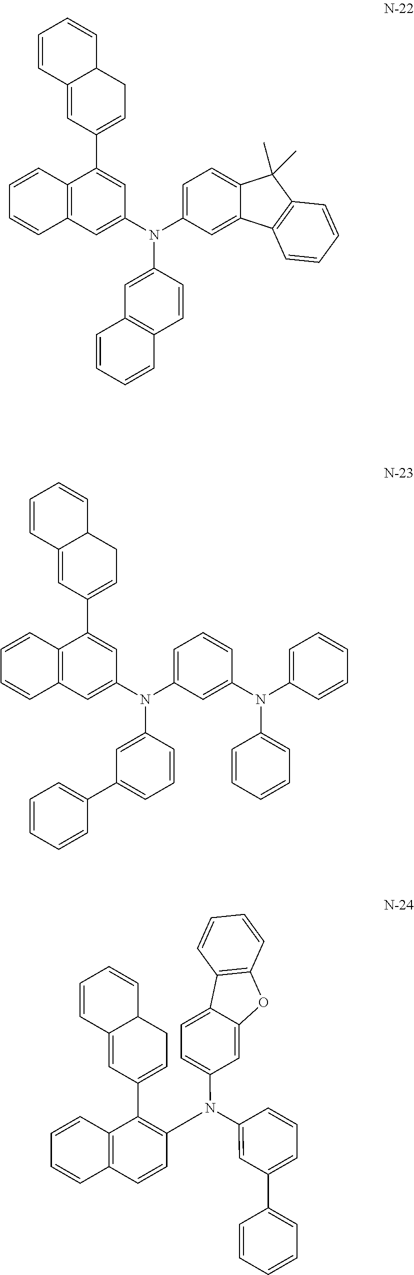 [SMILES: CC1(C)c2ccccc2-c2cc(N(c3ccc4ccccc4c3)c3cc(C4=CCC5C=CC=CC5=C4)c4ccccc4c3)ccc21 ; C1=CC2=CC(c3cc(N(c4cccc(-c5ccccc5)c4)c4cccc(N(c5ccccc5)c5ccccc5)c4)cc4ccccc34)=CCC2C=C1 ; C1=CC2=CC(c3c(N(c4cccc(-c5ccccc5)c4)c4ccc5c(c4)oc4ccccc45)ccc4ccccc34)=CCC2C=C1]

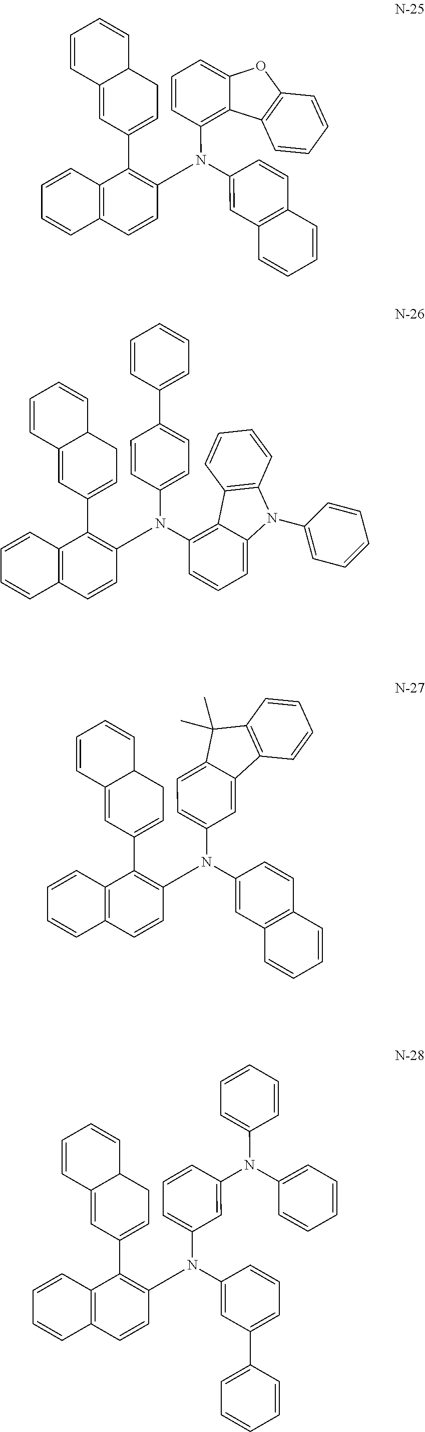 [SMILES: C1=CC2=CC(c3c(N(c4ccc5ccccc5c4)c4cccc5oc6ccccc6c45)ccc4ccccc34)=CCC2C=C1 ; C1=CC2=CC(c3c(N(c4ccc(-c5ccccc5)cc4)c4cccc5c4c4ccccc4n5-c4ccccc4)ccc4ccccc34)=CCC2C=C1 ; CC1(C)c2ccccc2-c2cc(N(c3ccc4ccccc4c3)c3ccc4ccccc4c3C3=CCC4C=CC=CC4=C3)ccc21 ; C1=CC2=CC(c3c(N(c4cccc(-c5ccccc5)c4)c4cccc(N(c5ccccc5)c5ccccc5)c4)ccc4ccccc34)=CCC2C=C1]

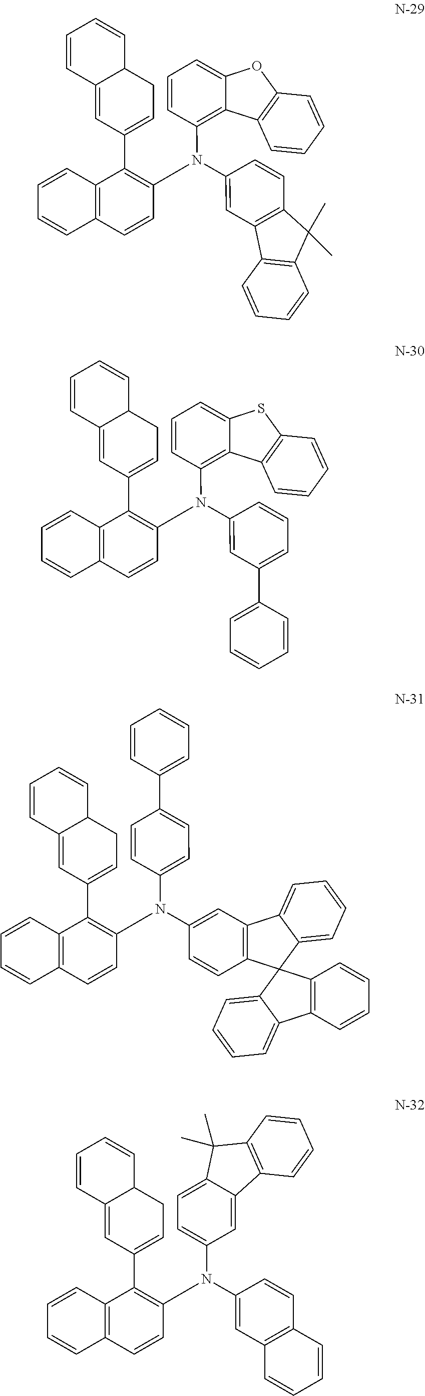 [SMILES: CC1(C)c2ccccc2-c2cc(N(c3ccc4ccccc4c3C3=CCC4C=CC=CC4=C3)c3cccc4oc5ccccc5c34)ccc21 ; C1=CC2=CC(c3c(N(c4cccc(-c5ccccc5)c4)c4cccc5sc6ccccc6c45)ccc4ccccc34)=CCC2C=C1 ; C1=CC2=CC(c3c(N(c4ccc(-c5ccccc5)cc4)c4ccc5c(c4)-c4ccccc4C54c5ccccc5-c5ccccc54)ccc4ccccc34)=CCC2C=C1 ; CC1(C)c2ccccc2-c2cc(N(c3ccc4ccccc4c3)c3ccc4ccccc4c3C3=CCC4C=CC=CC4=C3)ccc21]

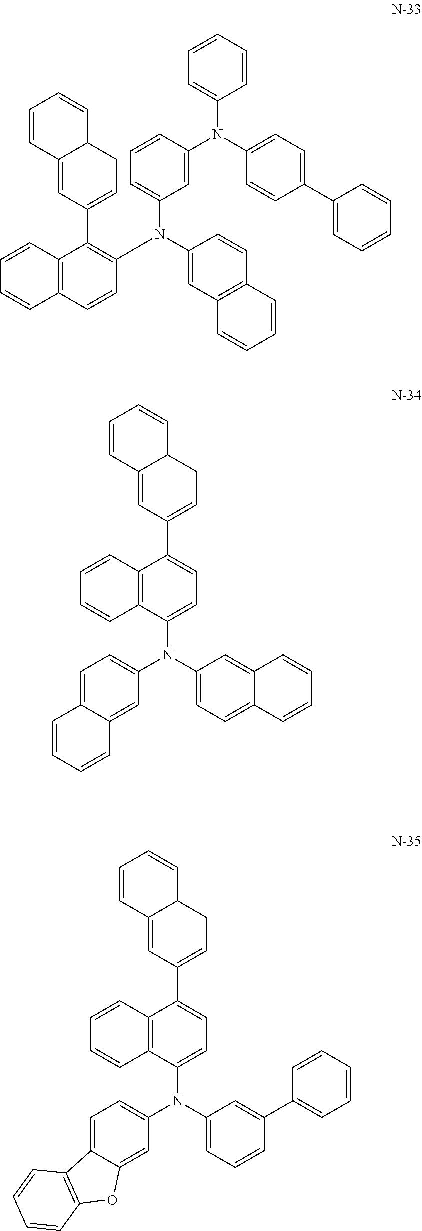 [SMILES: C1=CC2=CC(c3c(N(c4cccc(N(c5ccccc5)c5ccc(-c6ccccc6)cc5)c4)c4ccc5ccccc5c4)ccc4ccccc34)=CCC2C=C1 ; C1=CC2=CC(c3ccc(N(c4ccc5ccccc5c4)c4ccc5ccccc5c4)c4ccccc34)=CCC2C=C1 ; C1=CC2=CC(c3ccc(N(c4cccc(-c5ccccc5)c4)c4ccc5c(c4)oc4ccccc45)c4ccccc34)=CCC2C=C1]

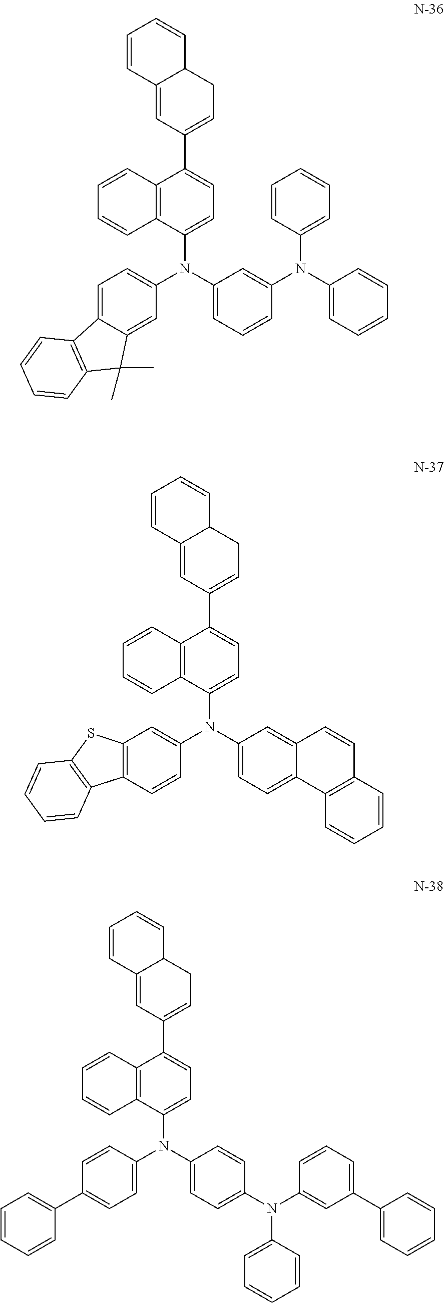 [SMILES: CC1(C)c2ccccc2-c2ccc(N(c3cccc(N(c4ccccc4)c4ccccc4)c3)c3ccc(C4=CCC5C=CC=CC5=C4)c4ccccc34)cc21 ; C1=CC2=CC(c3ccc(N(c4ccc5c(ccc6ccccc65)c4)c4ccc5c(c4)sc4ccccc45)c4ccccc34)=CCC2C=C1 ; C1=CC2=CC(c3ccc(N(c4ccc(-c5ccccc5)cc4)c4ccc(N(c5ccccc5)c5cccc(-c6ccccc6)c5)cc4)c4ccccc34)=CCC2C=C1]

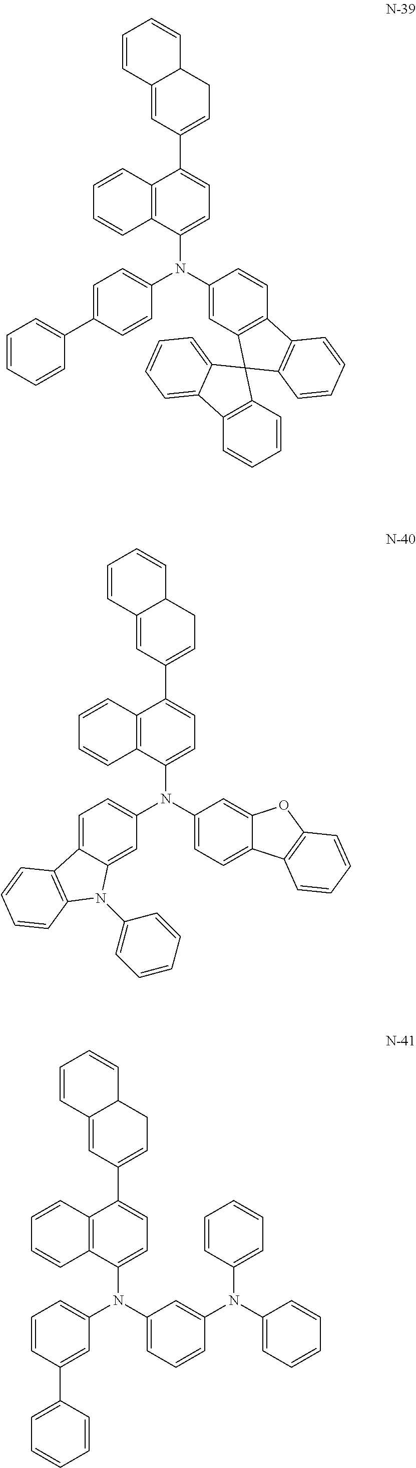 [SMILES: C1=CC2=CC(c3ccc(N(c4ccc(-c5ccccc5)cc4)c4ccc5c(c4)C4(c6ccccc6-c6ccccc64)c4ccccc4-5)c4ccccc34)=CCC2C=C1 ; C1=CC2=CC(c3ccc(N(c4ccc5c(c4)oc4ccccc45)c4ccc5c6ccccc6n(-c6ccccc6)c5c4)c4ccccc34)=CCC2C=C1 ; C1=CC2=CC(c3ccc(N(c4cccc(-c5ccccc5)c4)c4cccc(N(c5ccccc5)c5ccccc5)c4)c4ccccc34)=CCC2C=C1]

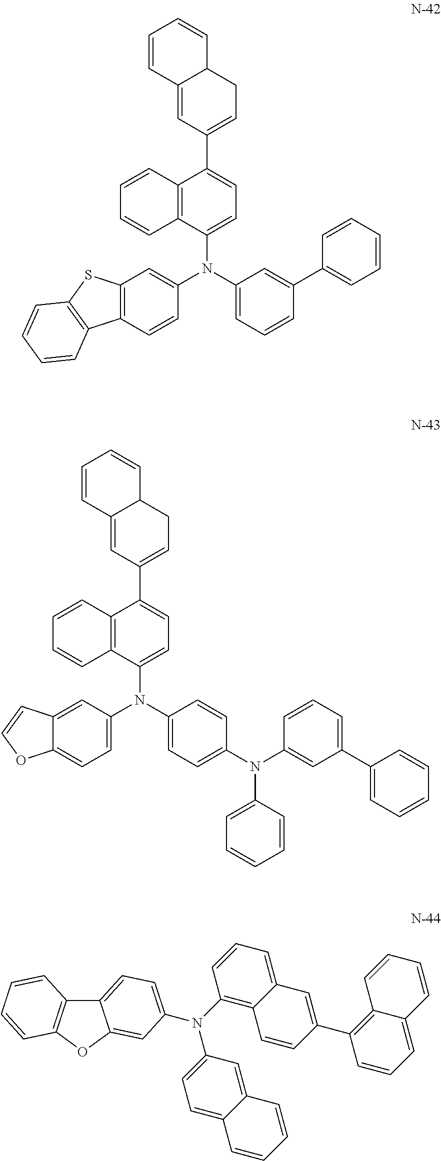 [SMILES: C1=CC2=CC(c3ccc(N(c4cccc(-c5ccccc5)c4)c4ccc5c(c4)sc4ccccc45)c4ccccc34)=CCC2C=C1 ; C1=CC2=CC(c3ccc(N(c4ccc(N(c5ccccc5)c5cccc(-c6ccccc6)c5)cc4)c4ccc5occc5c4)c4ccccc34)=CCC2C=C1 ; c1ccc2cc(N(c3ccc4c(c3)oc3ccccc34)c3cccc4cc(-c5cccc6ccccc56)ccc34)ccc2c1]

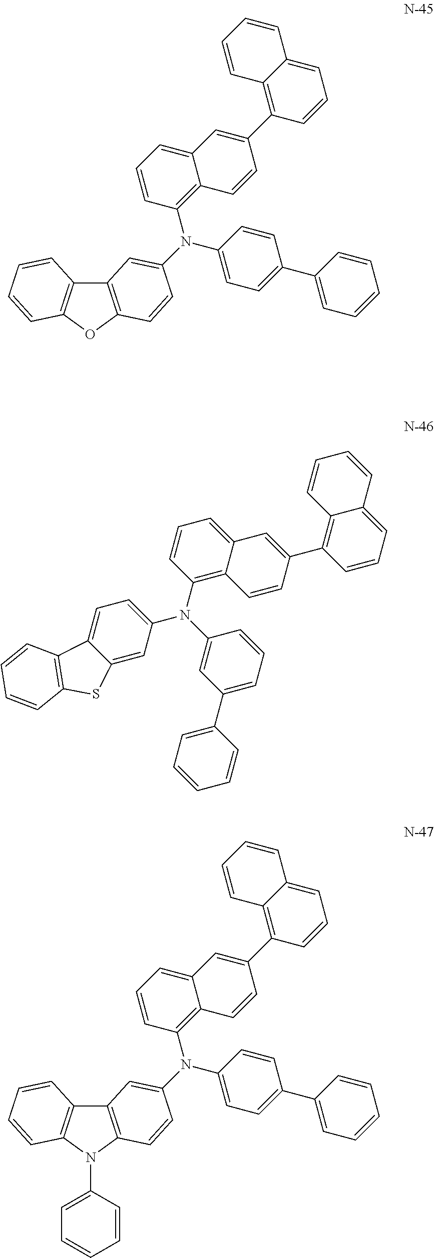 [SMILES: c1ccc(-c2ccc(N(c3ccc4oc5ccccc5c4c3)c3cccc4cc(-c5cccc6ccccc56)ccc34)cc2)cc1 ; c1ccc(-c2cccc(N(c3ccc4c(c3)sc3ccccc34)c3cccc4cc(-c5cccc6ccccc56)ccc34)c2)cc1 ; c1ccc(-c2ccc(N(c3ccc4c(c3)c3ccccc3n4-c3ccccc3)c3cccc4cc(-c5cccc6ccccc56)ccc34)cc2)cc1]

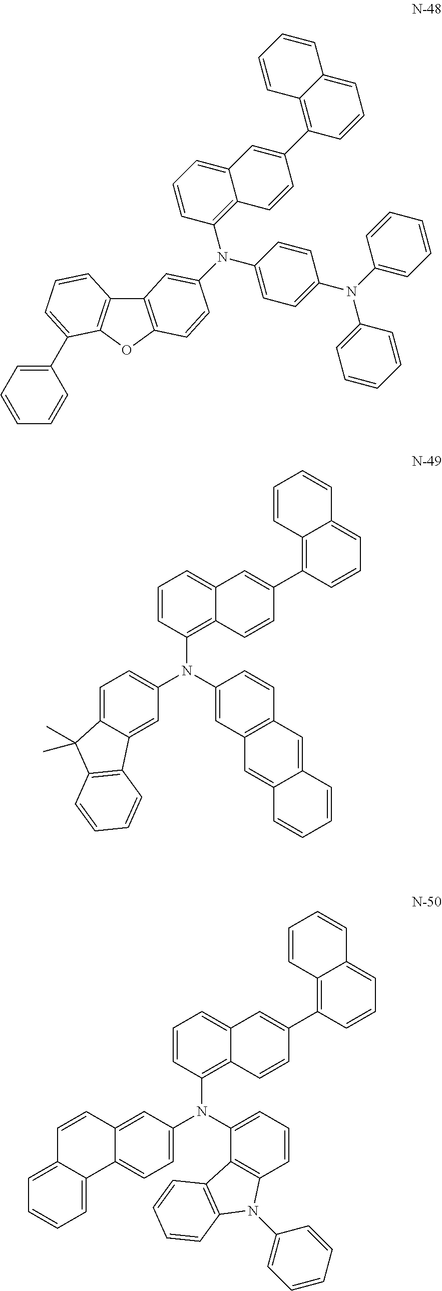 [SMILES: c1ccc(-c2cccc3c2oc2ccc(N(c4ccc(N(c5ccccc5)c5ccccc5)cc4)c4cccc5cc(-c6cccc7ccccc67)ccc45)cc23)cc1 ; CC1(C)c2ccccc2-c2cc(N(c3ccc4cc5ccccc5cc4c3)c3cccc4cc(-c5cccc6ccccc56)ccc34)ccc21 ; c1ccc(-n2c3ccccc3c3c(N(c4ccc5c(ccc6ccccc65)c4)c4cccc5cc(-c6cccc7ccccc67)ccc45)cccc32)cc1]

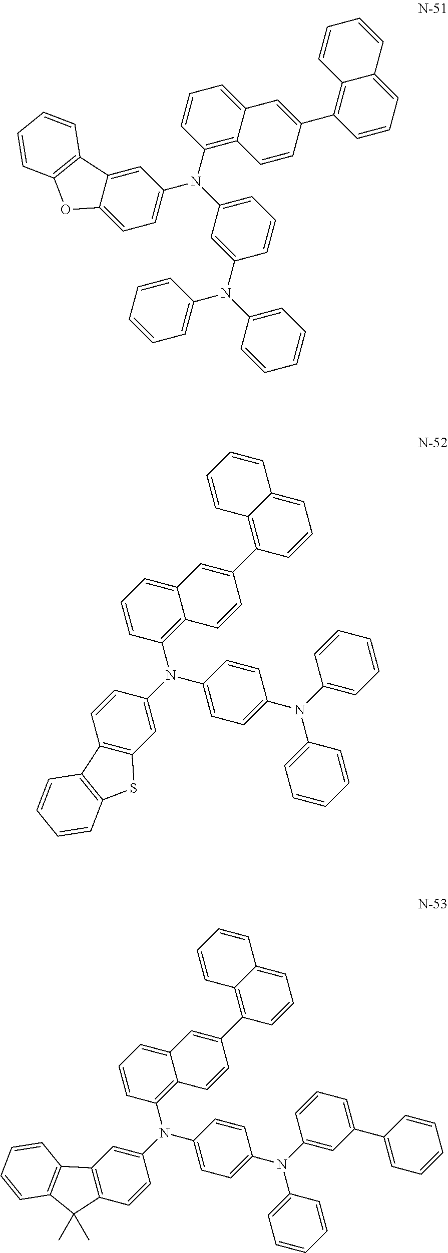 [SMILES: c1ccc(N(c2ccccc2)c2cccc(N(c3ccc4oc5ccccc5c4c3)c3cccc4cc(-c5cccc6ccccc56)ccc34)c2)cc1 ; c1ccc(N(c2ccccc2)c2ccc(N(c3ccc4c(c3)sc3ccccc34)c3cccc4cc(-c5cccc6ccccc56)ccc34)cc2)cc1 ; CC1(C)c2ccccc2-c2cc(N(c3ccc(N(c4ccccc4)c4cccc(-c5ccccc5)c4)cc3)c3cccc4cc(-c5cccc6ccccc56)ccc34)ccc21]

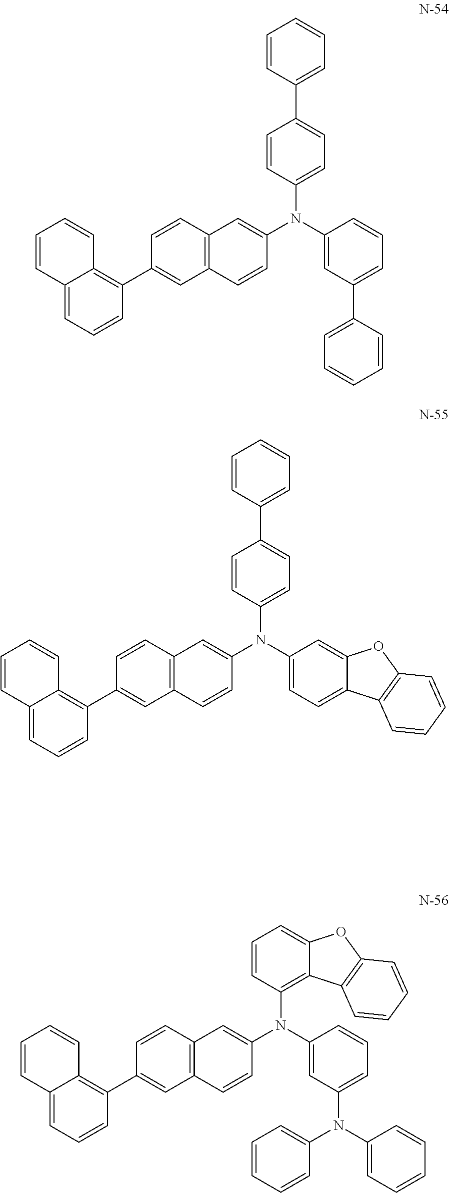 [SMILES: c1ccc(-c2ccc(N(c3cccc(-c4ccccc4)c3)c3ccc4cc(-c5cccc6ccccc56)ccc4c3)cc2)cc1 ; c1ccc(-c2ccc(N(c3ccc4cc(-c5cccc6ccccc56)ccc4c3)c3ccc4c(c3)oc3ccccc34)cc2)cc1 ; c1ccc(N(c2ccccc2)c2cccc(N(c3ccc4cc(-c5cccc6ccccc56)ccc4c3)c3cccc4oc5ccccc5c34)c2)cc1]

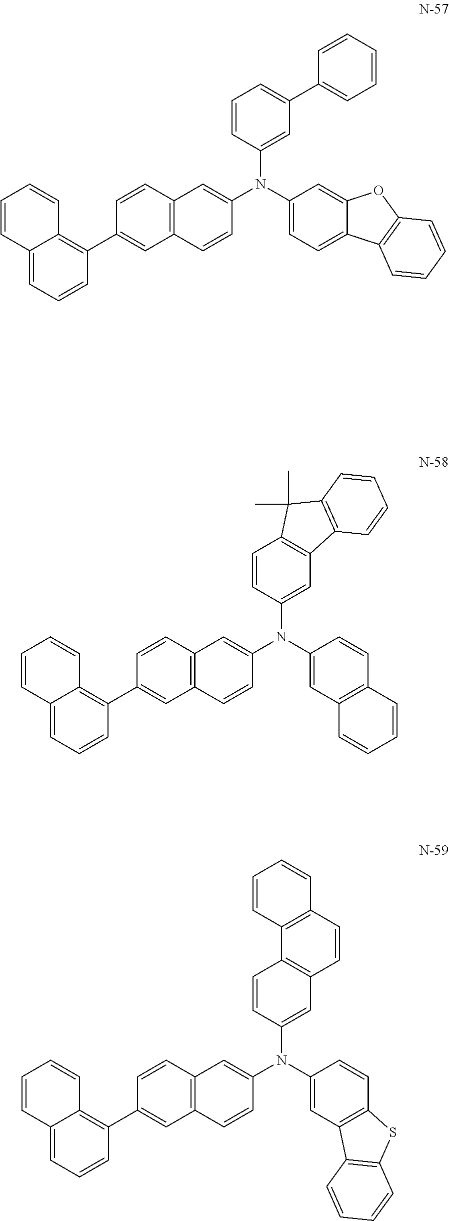 [SMILES: c1ccc(-c2cccc(N(c3ccc4cc(-c5cccc6ccccc56)ccc4c3)c3ccc4c(c3)oc3ccccc34)c2)cc1 ; CC1(C)c2ccccc2-c2cc(N(c3ccc4ccccc4c3)c3ccc4cc(-c5cccc6ccccc56)ccc4c3)ccc21 ; c1ccc2c(-c3ccc4cc(N(c5ccc6c(ccc7ccccc76)c5)c5ccc6sc7ccccc7c6c5)ccc4c3)cccc2c1]

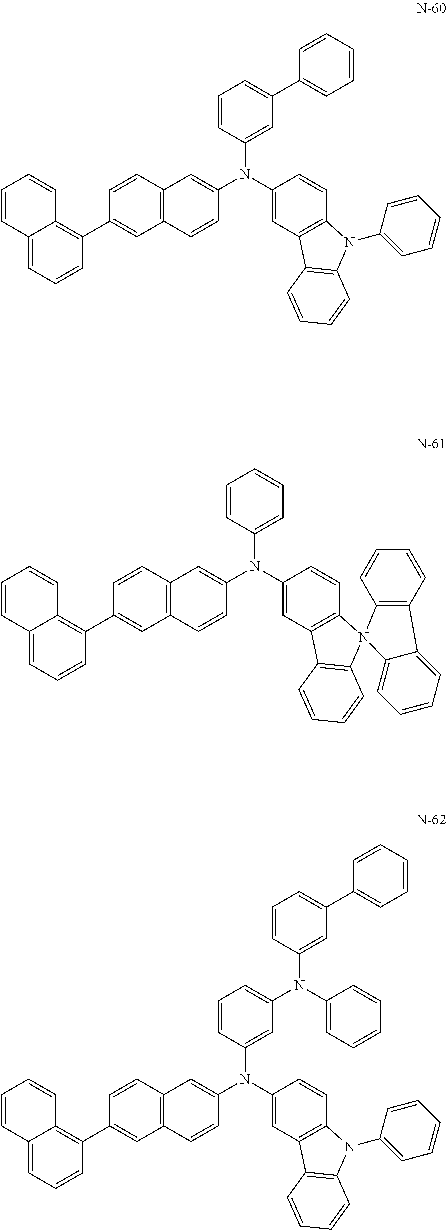

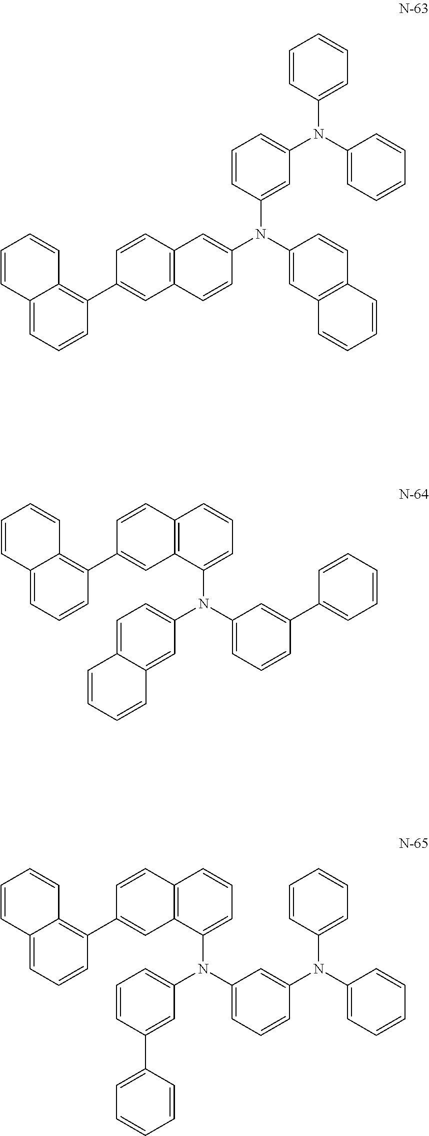 [SMILES: c1ccc(N(c2ccccc2)c2cccc(N(c3ccc4ccccc4c3)c3ccc4cc(-c5cccc6ccccc56)ccc4c3)c2)cc1 ; c1ccc(-c2cccc(N(c3ccc4ccccc4c3)c3cccc4ccc(-c5cccc6ccccc56)cc34)c2)cc1 ; c1ccc(-c2cccc(N(c3cccc(N(c4ccccc4)c4ccccc4)c3)c3cccc4ccc(-c5cccc6ccccc56)cc34)c2)cc1]

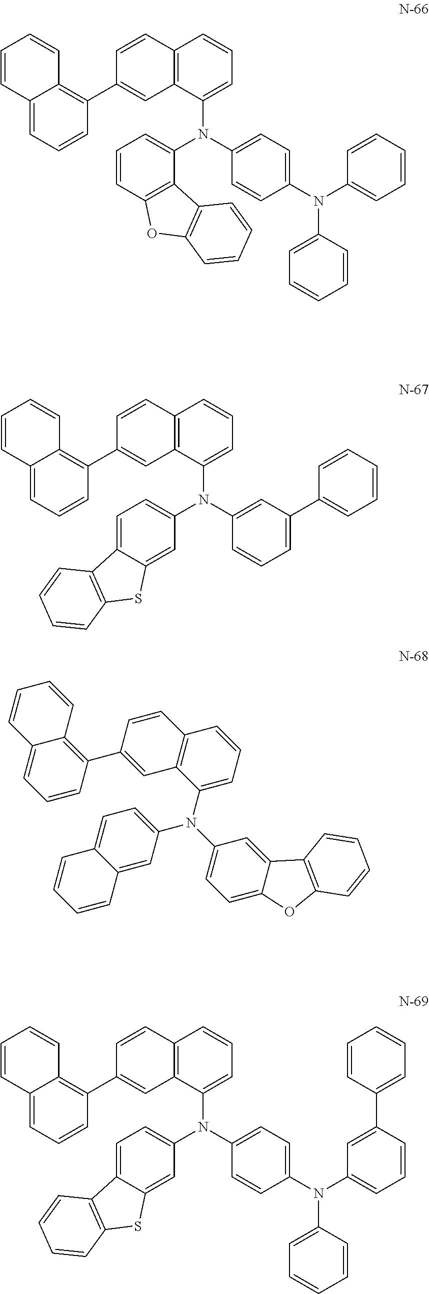 [SMILES: c1ccc(N(c2ccccc2)c2ccc(N(c3cccc4ccc(-c5cccc6ccccc56)cc34)c3cccc4oc5ccccc5c34)cc2)cc1 ; c1ccc(-c2cccc(N(c3ccc4c(c3)sc3ccccc34)c3cccc4ccc(-c5cccc6ccccc56)cc34)c2)cc1 ; c1ccc2cc(N(c3ccc4oc5ccccc5c4c3)c3cccc4ccc(-c5cccc6ccccc56)cc34)ccc2c1 ; c1ccc(-c2cccc(N(c3ccccc3)c3ccc(N(c4ccc5c(c4)sc4ccccc45)c4cccc5ccc(-c6cccc7ccccc67)cc45)cc3)c2)cc1]

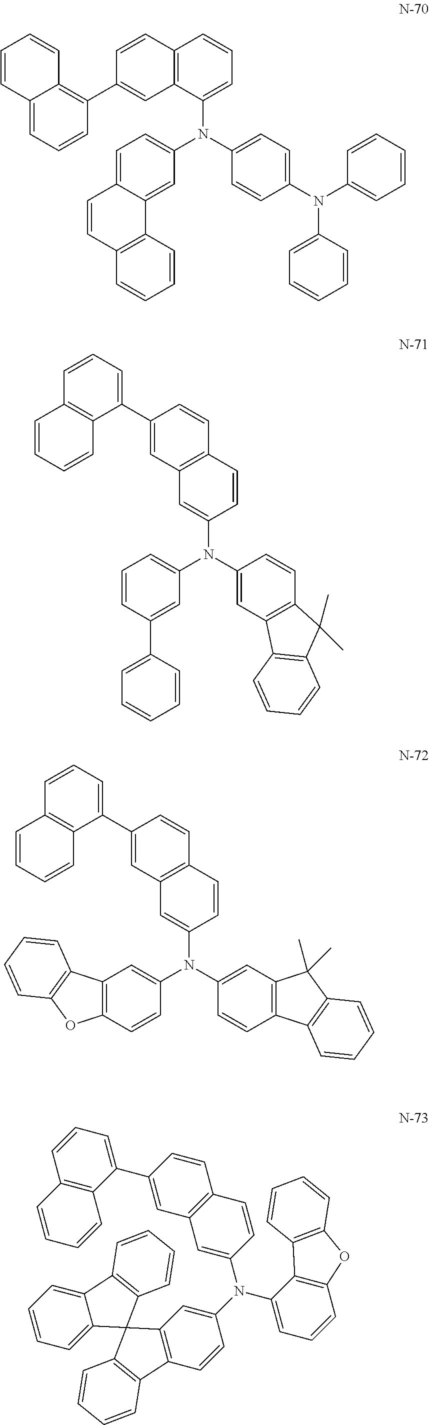 [SMILES: c1ccc(N(c2ccccc2)c2ccc(N(c3ccc4ccc5ccccc5c4c3)c3cccc4ccc(-c5cccc6ccccc56)cc34)cc2)cc1 ; CC1(C)c2ccccc2-c2cc(N(c3cccc(-c4ccccc4)c3)c3ccc4ccc(-c5cccc6ccccc56)cc4c3)ccc21 ; CC1(C)c2ccccc2-c2ccc(N(c3ccc4ccc(-c5cccc6ccccc56)cc4c3)c3ccc4oc5ccccc5c4c3)cc21 ; c1ccc2c(c1)-c1ccccc1C21c2ccccc2-c2ccc(N(c3ccc4ccc(-c5cccc6ccccc56)cc4c3)c3cccc4oc5ccccc5c34)cc21]

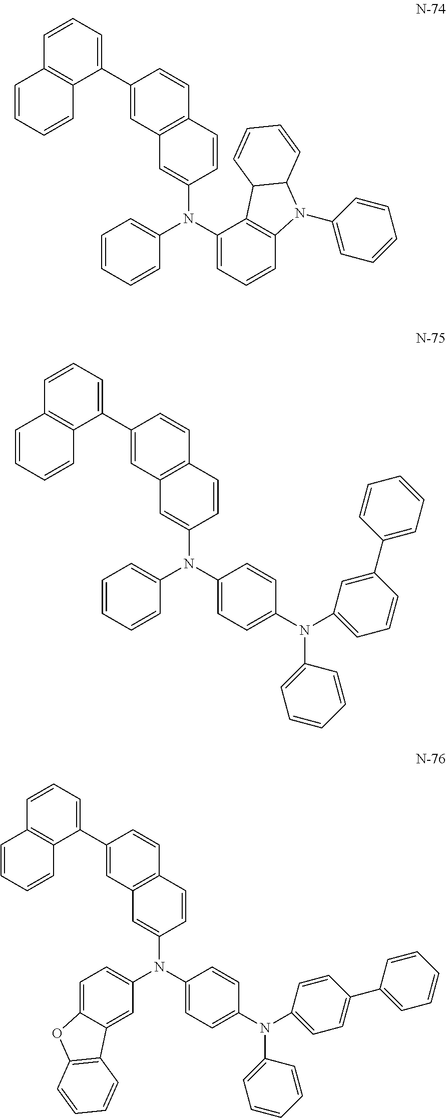 [SMILES: C1=CC2c3c(N(c4ccccc4)c4ccc5ccc(-c6cccc7ccccc67)cc5c4)cccc3N(c3ccccc3)C2C=C1 ; c1ccc(-c2cccc(N(c3ccccc3)c3ccc(N(c4ccccc4)c4ccc5ccc(-c6cccc7ccccc67)cc5c4)cc3)c2)cc1 ; c1ccc(-c2ccc(N(c3ccccc3)c3ccc(N(c4ccc5ccc(-c6cccc7ccccc67)cc5c4)c4ccc5oc6ccccc6c5c4)cc3)cc2)cc1]

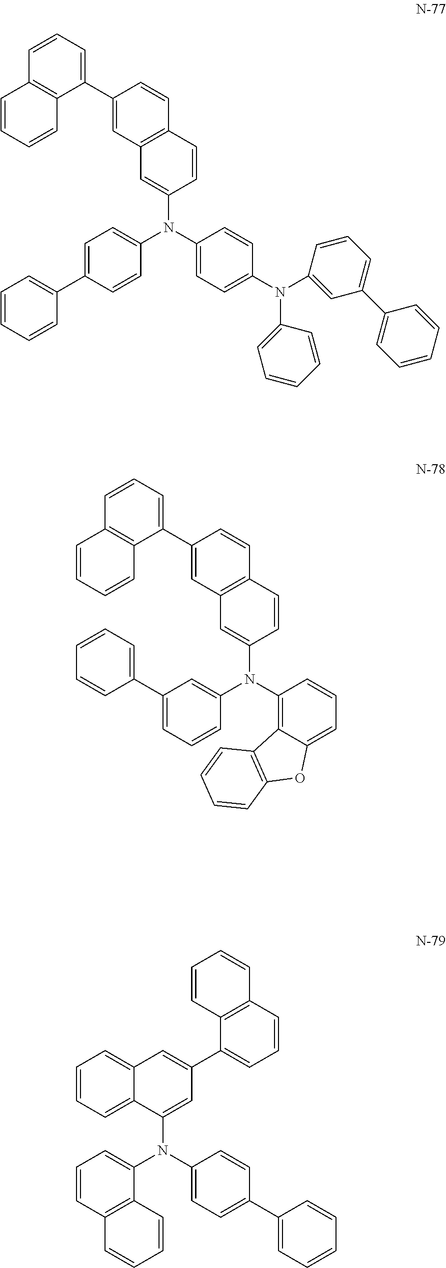 [SMILES: c1ccc(-c2ccc(N(c3ccc(N(c4ccccc4)c4cccc(-c5ccccc5)c4)cc3)c3ccc4ccc(-c5cccc6ccccc56)cc4c3)cc2)cc1 ; c1ccc(-c2cccc(N(c3ccc4ccc(-c5cccc6ccccc56)cc4c3)c3cccc4oc5ccccc5c34)c2)cc1 ; c1ccc(-c2ccc(N(c3cccc4ccccc34)c3cc(-c4cccc5ccccc45)cc4ccccc34)cc2)cc1]

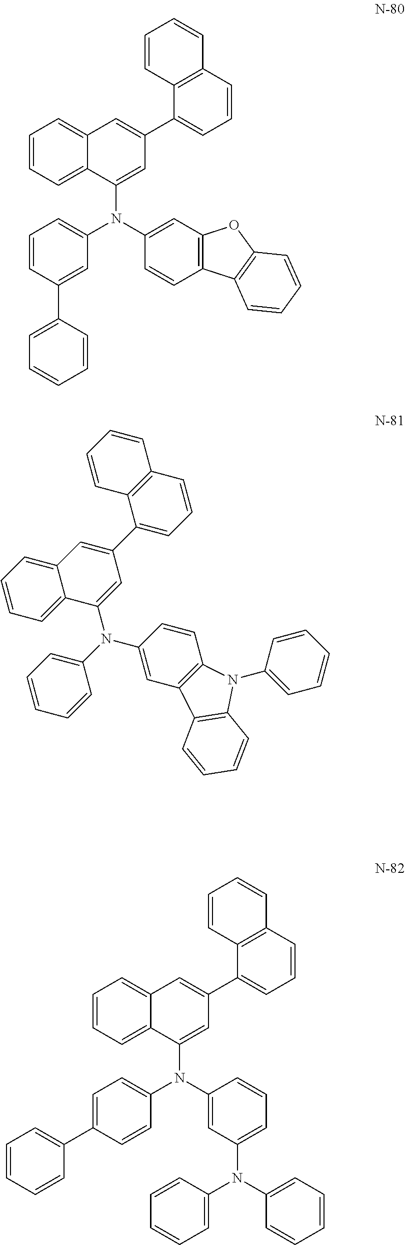 [SMILES: c1ccc(-c2cccc(N(c3ccc4c(c3)oc3ccccc34)c3cc(-c4cccc5ccccc45)cc4ccccc34)c2)cc1 ; c1ccc(N(c2ccc3c(c2)c2ccccc2n3-c2ccccc2)c2cc(-c3cccc4ccccc34)cc3ccccc23)cc1 ; c1ccc(-c2ccc(N(c3cccc(N(c4ccccc4)c4ccccc4)c3)c3cc(-c4cccc5ccccc45)cc4ccccc34)cc2)cc1]

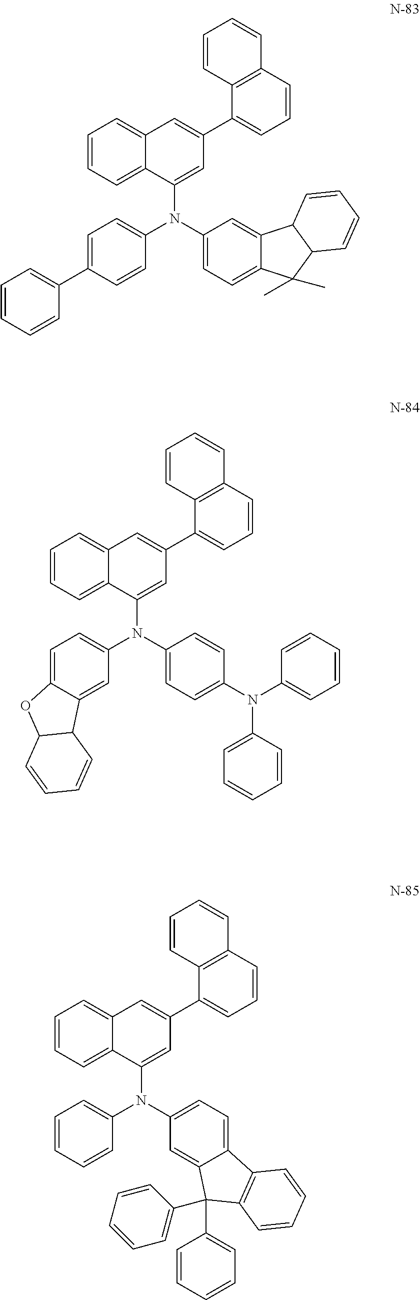 [SMILES: CC1(C)c2ccc(N(c3ccc(-c4ccccc4)cc3)c3cc(-c4cccc5ccccc45)cc4ccccc34)cc2C2C=CC=CC21 ; C1=CC2Oc3ccc(N(c4ccc(N(c5ccccc5)c5ccccc5)cc4)c4cc(-c5cccc6ccccc56)cc5ccccc45)cc3C2C=C1 ; c1ccc(N(c2ccc3c(c2)C(c2ccccc2)(c2ccccc2)c2ccccc2-3)c2cc(-c3cccc4ccccc34)cc3ccccc23)cc1]

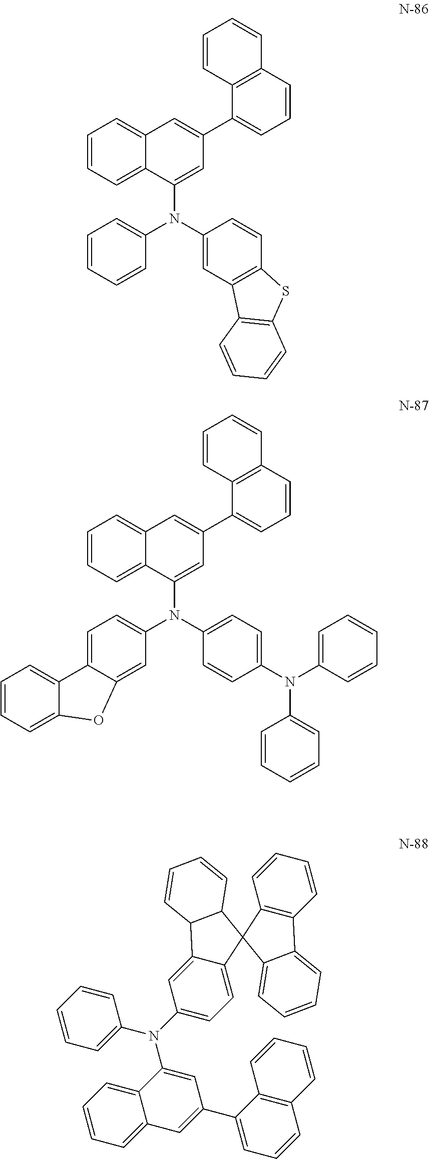

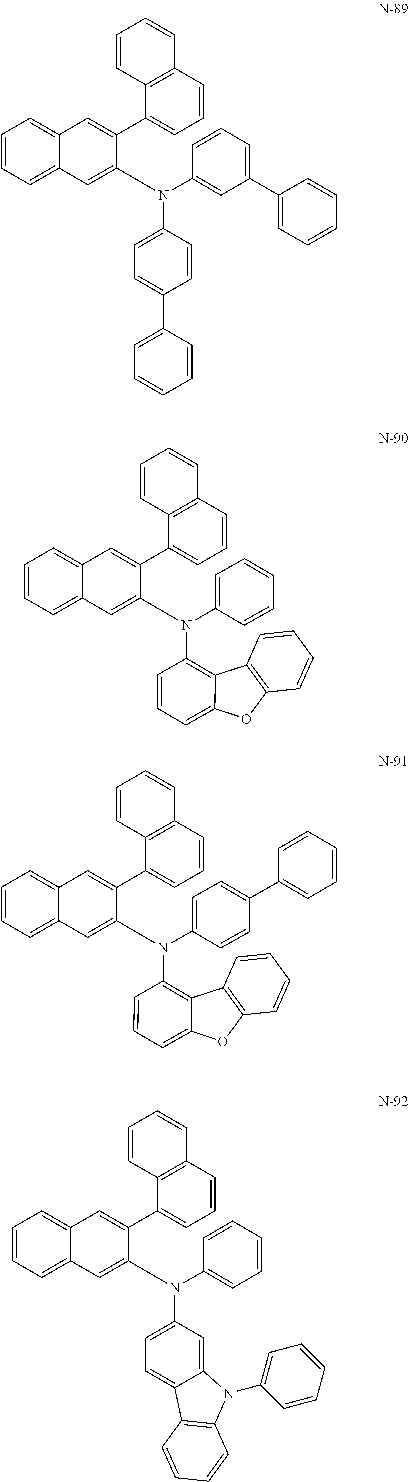 [SMILES: c1ccc(-c2ccc(N(c3cccc(-c4ccccc4)c3)c3cc4ccccc4cc3-c3cccc4ccccc34)cc2)cc1 ; c1ccc(N(c2cc3ccccc3cc2-c2cccc3ccccc23)c2cccc3oc4ccccc4c23)cc1 ; c1ccc(-c2ccc(N(c3cc4ccccc4cc3-c3cccc4ccccc34)c3cccc4oc5ccccc5c34)cc2)cc1 ; c1ccc(N(c2ccc3c4ccccc4n(-c4ccccc4)c3c2)c2cc3ccccc3cc2-c2cccc3ccccc23)cc1]

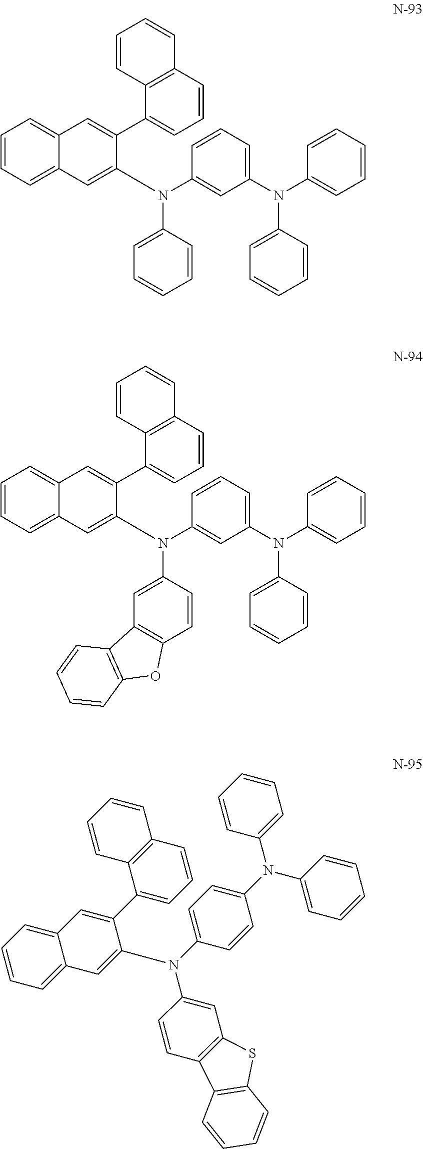 [SMILES: c1ccc(N(c2ccccc2)c2cccc(N(c3ccccc3)c3cc4ccccc4cc3-c3cccc4ccccc34)c2)cc1 ; c1ccc(N(c2ccccc2)c2cccc(N(c3ccc4oc5ccccc5c4c3)c3cc4ccccc4cc3-c3cccc4ccccc34)c2)cc1 ; c1ccc(N(c2ccccc2)c2ccc(N(c3ccc4c(c3)sc3ccccc34)c3cc4ccccc4cc3-c3cccc4ccccc34)cc2)cc1]

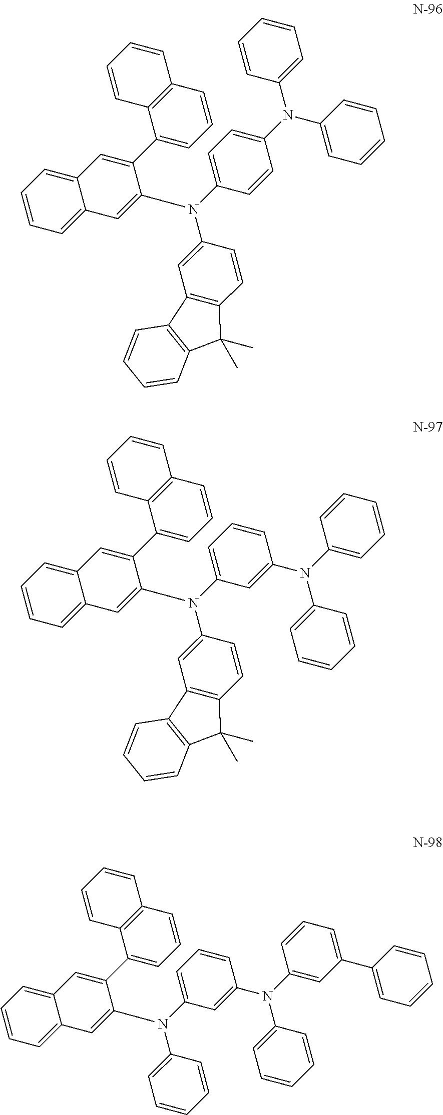 [SMILES: CC1(C)c2ccccc2-c2cc(N(c3ccc(N(c4ccccc4)c4ccccc4)cc3)c3cc4ccccc4cc3-c3cccc4ccccc34)ccc21 ; CC1(C)c2ccccc2-c2cc(N(c3cccc(N(c4ccccc4)c4ccccc4)c3)c3cc4ccccc4cc3-c3cccc4ccccc34)ccc21 ; c1ccc(-c2cccc(N(c3ccccc3)c3cccc(N(c4ccccc4)c4cc5ccccc5cc4-c4cccc5ccccc45)c3)c2)cc1]

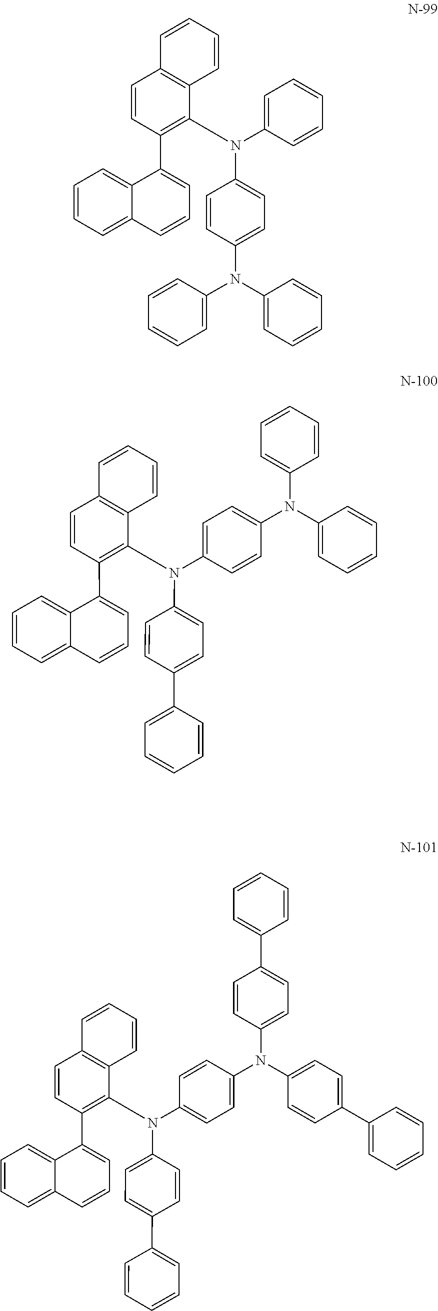 [SMILES: c1ccc(N(c2ccccc2)c2ccc(N(c3ccccc3)c3c(-c4cccc5ccccc45)ccc4ccccc34)cc2)cc1 ; c1ccc(-c2ccc(N(c3ccc(N(c4ccccc4)c4ccccc4)cc3)c3c(-c4cccc5ccccc45)ccc4ccccc34)cc2)cc1 ; c1ccc(-c2ccc(N(c3ccc(-c4ccccc4)cc3)c3ccc(N(c4ccc(-c5ccccc5)cc4)c4c(-c5cccc6ccccc56)ccc5ccccc45)cc3)cc2)cc1]

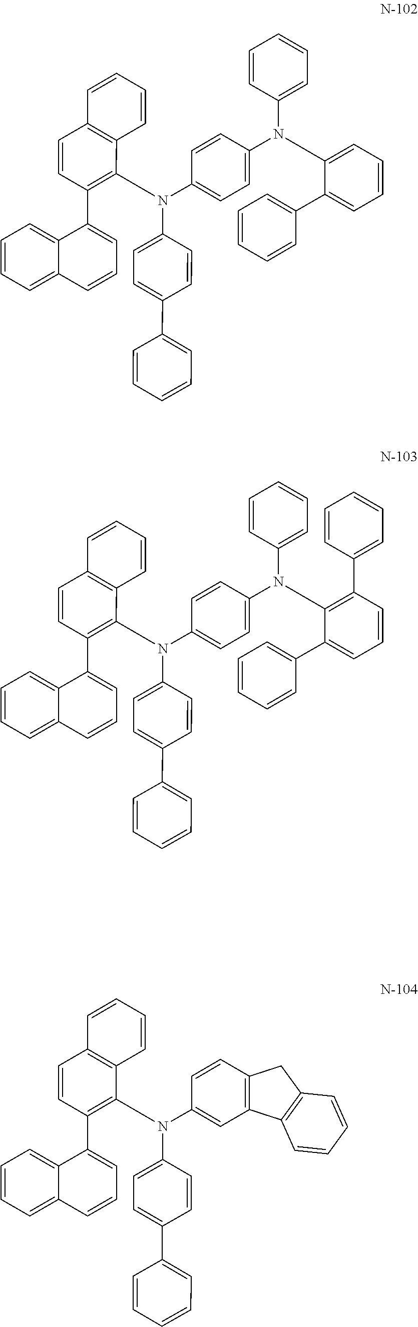 [SMILES: c1ccc(-c2ccc(N(c3ccc(N(c4ccccc4)c4ccccc4-c4ccccc4)cc3)c3c(-c4cccc5ccccc45)ccc4ccccc34)cc2)cc1 ; c1ccc(-c2ccc(N(c3ccc(N(c4ccccc4)c4c(-c5ccccc5)cccc4-c4ccccc4)cc3)c3c(-c4cccc5ccccc45)ccc4ccccc34)cc2)cc1 ; c1ccc(-c2ccc(N(c3ccc4c(c3)-c3ccccc3C4)c3c(-c4cccc5ccccc45)ccc4ccccc34)cc2)cc1]

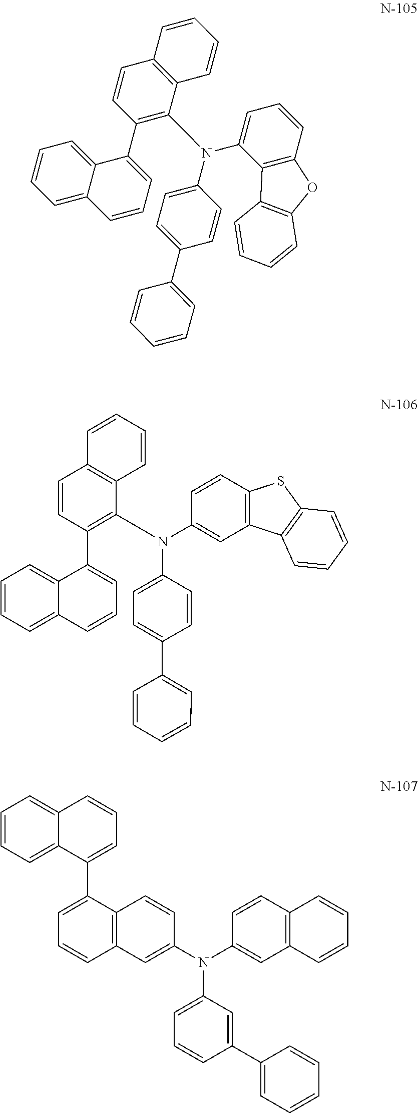 [SMILES: c1ccc(-c2ccc(N(c3c(-c4cccc5ccccc45)ccc4ccccc34)c3cccc4oc5ccccc5c34)cc2)cc1 ; c1ccc(-c2ccc(N(c3ccc4sc5ccccc5c4c3)c3c(-c4cccc5ccccc45)ccc4ccccc34)cc2)cc1 ; c1ccc(-c2cccc(N(c3ccc4ccccc4c3)c3ccc4c(-c5cccc6ccccc56)cccc4c3)c2)cc1]

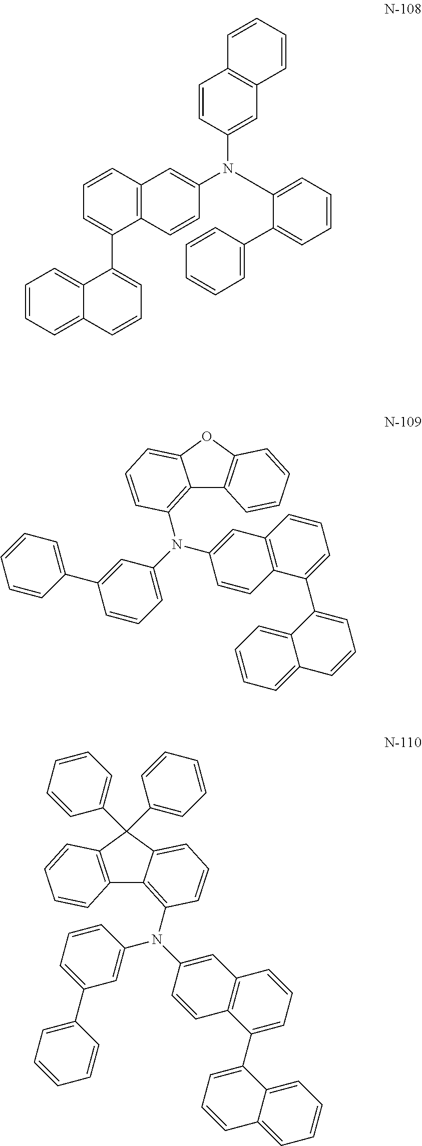 [SMILES: c1ccc(-c2ccccc2N(c2ccc3ccccc3c2)c2ccc3c(-c4cccc5ccccc45)cccc3c2)cc1 ; c1ccc(-c2cccc(N(c3ccc4c(-c5cccc6ccccc56)cccc4c3)c3cccc4oc5ccccc5c34)c2)cc1 ; c1ccc(-c2cccc(N(c3ccc4c(-c5cccc6ccccc56)cccc4c3)c3cccc4c3-c3ccccc3C4(c3ccccc3)c3ccccc3)c2)cc1]

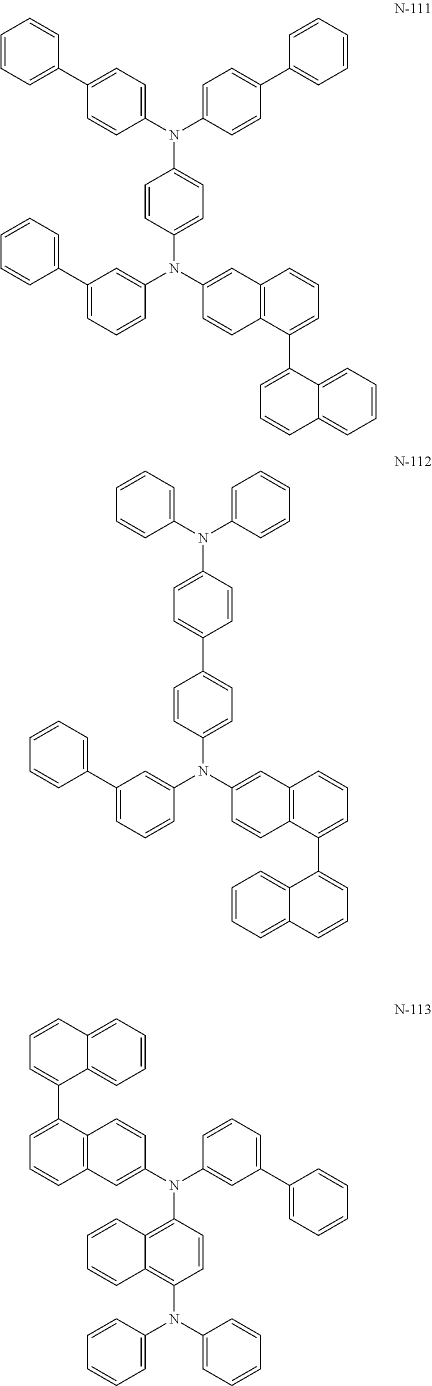

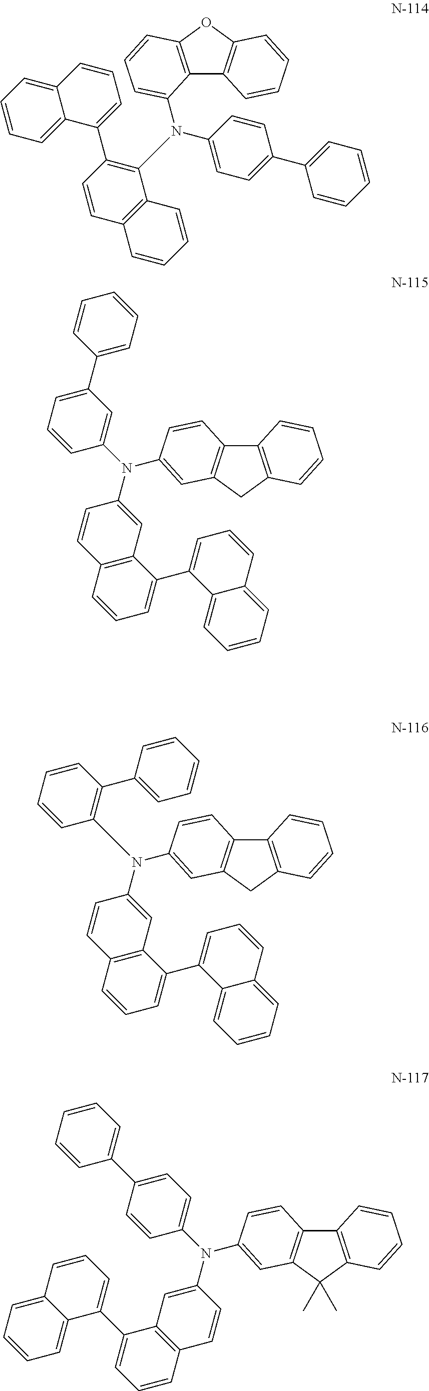

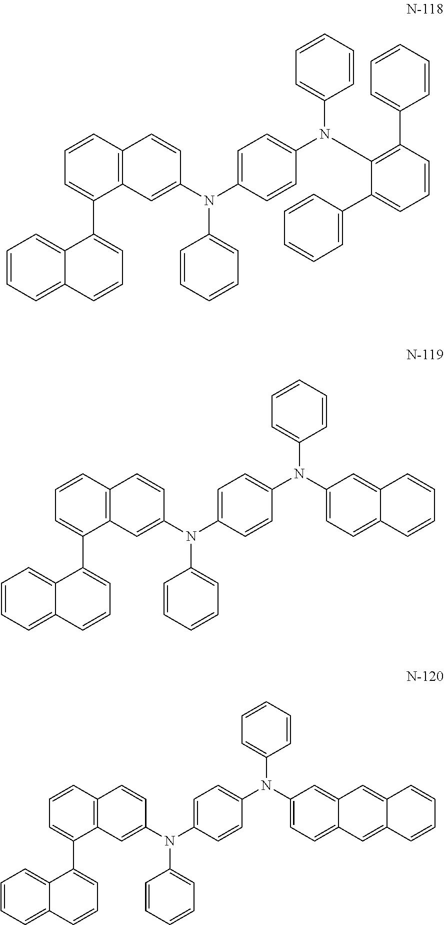 [SMILES: c1ccc(-c2cccc(-c3ccccc3)c2N(c2ccccc2)c2ccc(N(c3ccccc3)c3ccc4cccc(-c5cccc6ccccc56)c4c3)cc2)cc1 ; c1ccc(N(c2ccc(N(c3ccccc3)c3ccc4cccc(-c5cccc6ccccc56)c4c3)cc2)c2ccc3ccccc3c2)cc1 ; c1ccc(N(c2ccc(N(c3ccccc3)c3ccc4cccc(-c5cccc6ccccc56)c4c3)cc2)c2ccc3cc4ccccc4cc3c2)cc1]

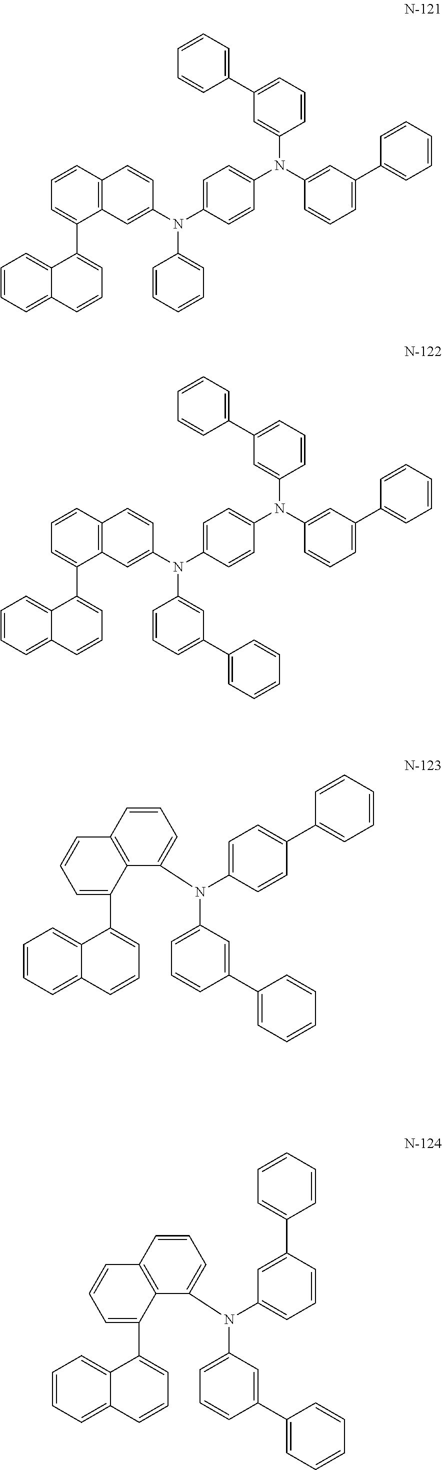 [SMILES: c1ccc(-c2cccc(N(c3ccc(N(c4ccccc4)c4ccc5cccc(-c6cccc7ccccc67)c5c4)cc3)c3cccc(-c4ccccc4)c3)c2)cc1 ; c1ccc(-c2cccc(N(c3ccc(N(c4cccc(-c5ccccc5)c4)c4ccc5cccc(-c6cccc7ccccc67)c5c4)cc3)c3cccc(-c4ccccc4)c3)c2)cc1 ; c1ccc(-c2ccc(N(c3cccc(-c4ccccc4)c3)c3cccc4cccc(-c5cccc6ccccc56)c34)cc2)cc1 ; c1ccc(-c2cccc(N(c3cccc(-c4ccccc4)c3)c3cccc4cccc(-c5cccc6ccccc56)c34)c2)cc1]

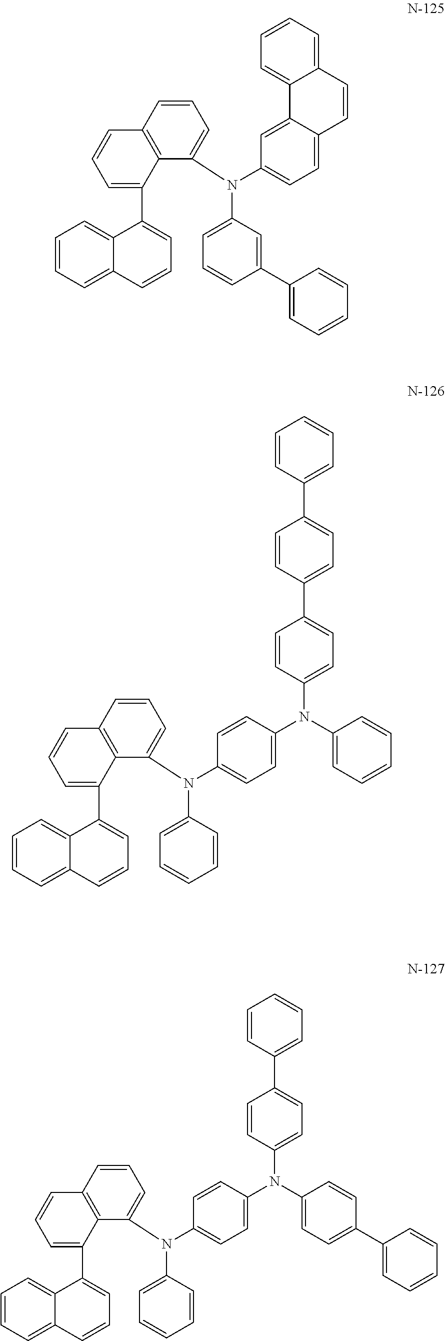 [SMILES: c1ccc(-c2cccc(N(c3ccc4ccc5ccccc5c4c3)c3cccc4cccc(-c5cccc6ccccc56)c34)c2)cc1 ; c1ccc(-c2ccc(-c3ccc(N(c4ccccc4)c4ccc(N(c5ccccc5)c5cccc6cccc(-c7cccc8ccccc78)c56)cc4)cc3)cc2)cc1 ; c1ccc(-c2ccc(N(c3ccc(-c4ccccc4)cc3)c3ccc(N(c4ccccc4)c4cccc5cccc(-c6cccc7ccccc67)c45)cc3)cc2)cc1]

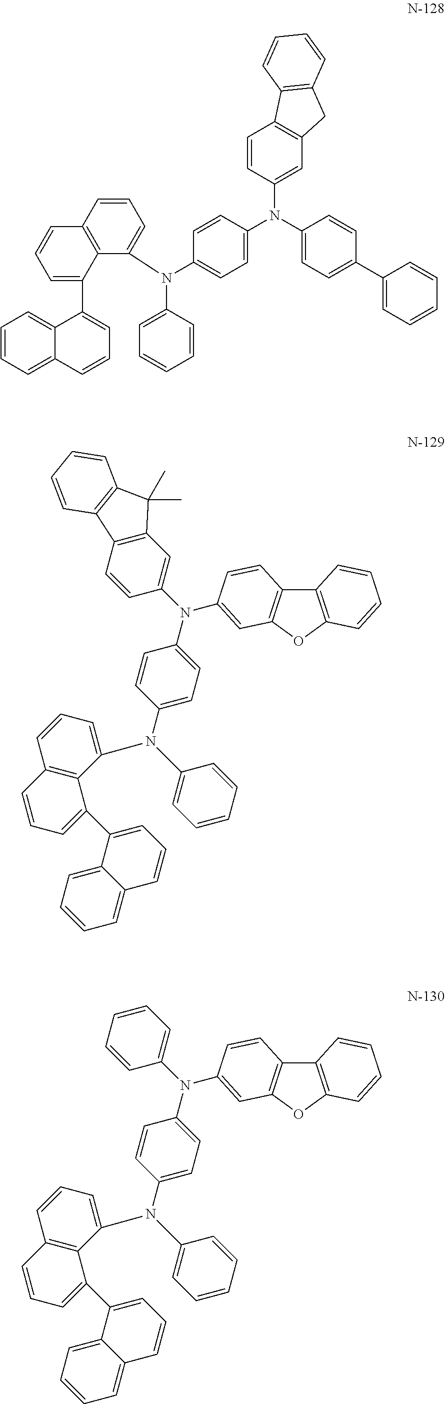 [SMILES: c1ccc(-c2ccc(N(c3ccc(N(c4ccccc4)c4cccc5cccc(-c6cccc7ccccc67)c45)cc3)c3ccc4c(c3)Cc3ccccc3-4)cc2)cc1 ; CC1(C)c2ccccc2-c2ccc(N(c3ccc(N(c4ccccc4)c4cccc5cccc(-c6cccc7ccccc67)c45)cc3)c3ccc4c(c3)oc3ccccc34)cc21 ; c1ccc(N(c2ccc(N(c3ccccc3)c3cccc4cccc(-c5cccc6ccccc56)c34)cc2)c2ccc3c(c2)oc2ccccc23)cc1]

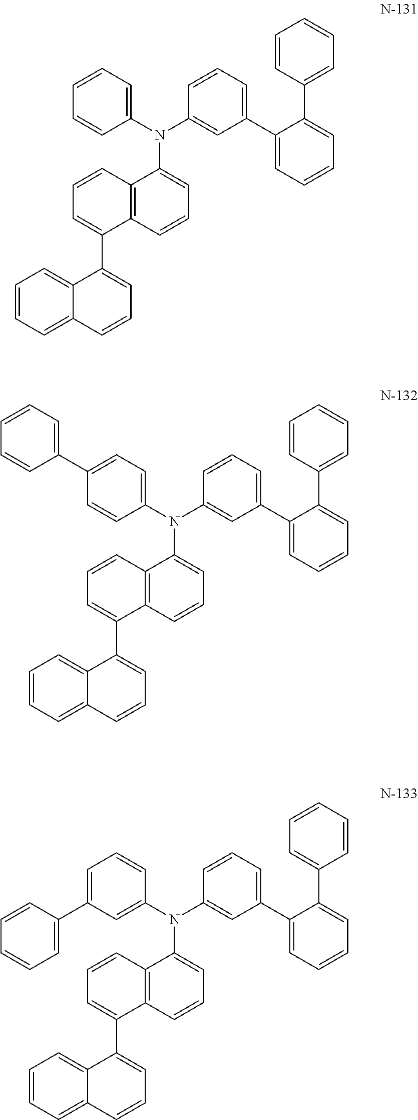 [SMILES: c1ccc(-c2ccccc2-c2cccc(N(c3ccccc3)c3cccc4c(-c5cccc6ccccc56)cccc34)c2)cc1 ; c1ccc(-c2ccc(N(c3cccc(-c4ccccc4-c4ccccc4)c3)c3cccc4c(-c5cccc6ccccc56)cccc34)cc2)cc1 ; c1ccc(-c2cccc(N(c3cccc(-c4ccccc4-c4ccccc4)c3)c3cccc4c(-c5cccc6ccccc56)cccc34)c2)cc1]

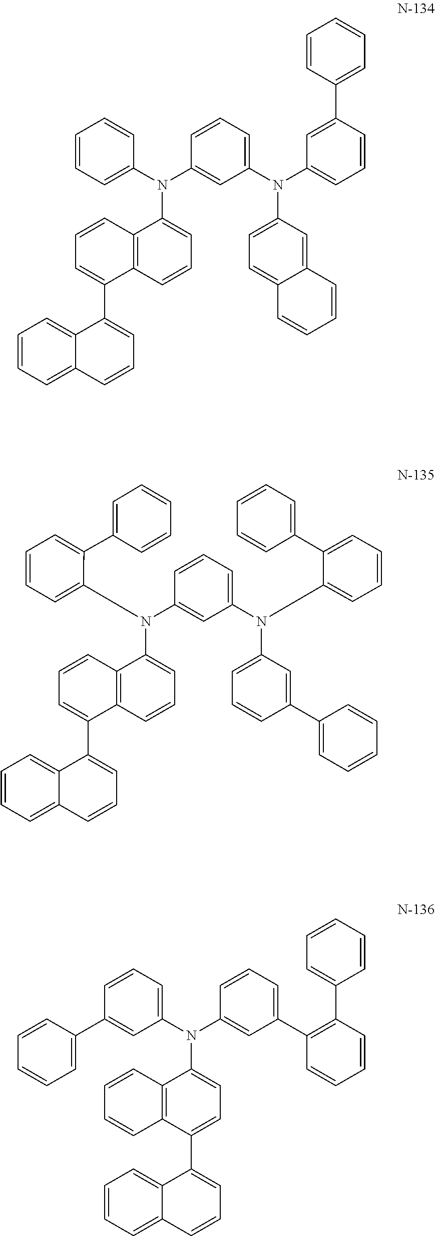 [SMILES: c1ccc(-c2cccc(N(c3cccc(N(c4ccccc4)c4cccc5c(-c6cccc7ccccc67)cccc45)c3)c3ccc4ccccc4c3)c2)cc1 ; c1ccc(-c2cccc(N(c3cccc(N(c4ccccc4-c4ccccc4)c4cccc5c(-c6cccc7ccccc67)cccc45)c3)c3ccccc3-c3ccccc3)c2)cc1 ; c1ccc(-c2cccc(N(c3cccc(-c4ccccc4-c4ccccc4)c3)c3ccc(-c4cccc5ccccc45)c4ccccc34)c2)cc1]

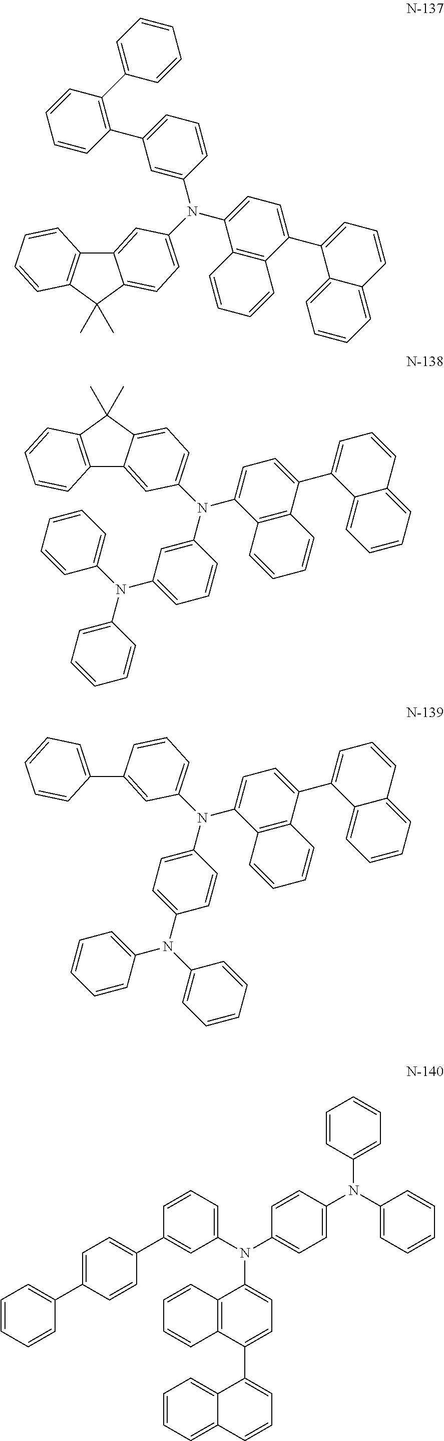 [SMILES: CC1(C)c2ccccc2-c2cc(N(c3cccc(-c4ccccc4-c4ccccc4)c3)c3ccc(-c4cccc5ccccc45)c4ccccc34)ccc21 ; CC1(C)c2ccccc2-c2cc(N(c3cccc(N(c4ccccc4)c4ccccc4)c3)c3ccc(-c4cccc5ccccc45)c4ccccc34)ccc21 ; c1ccc(-c2cccc(N(c3ccc(N(c4ccccc4)c4ccccc4)cc3)c3ccc(-c4cccc5ccccc45)c4ccccc34)c2)cc1 ; c1ccc(-c2ccc(-c3cccc(N(c4ccc(N(c5ccccc5)c5ccccc5)cc4)c4ccc(-c5cccc6ccccc56)c5ccccc45)c3)cc2)cc1]

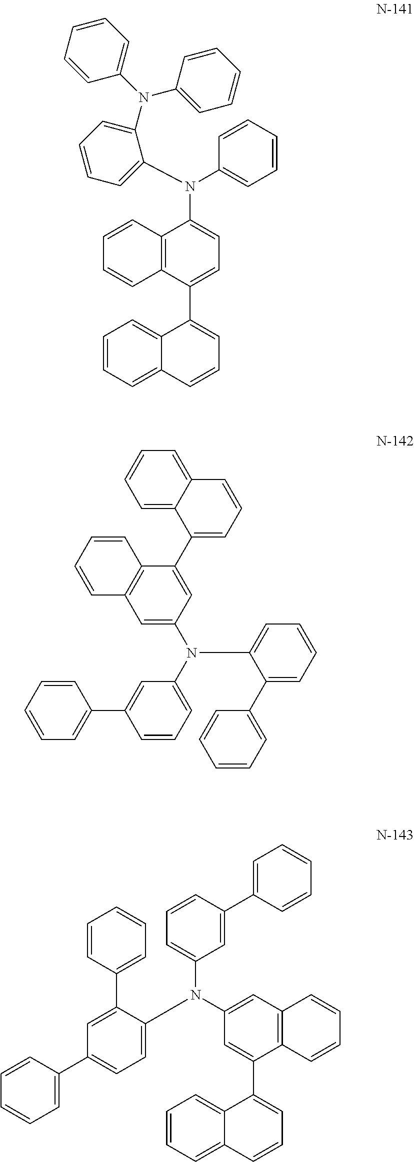 [SMILES: c1ccc(N(c2ccccc2)c2ccccc2N(c2ccccc2)c2ccc(-c3cccc4ccccc34)c3ccccc23)cc1 ; c1ccc(-c2cccc(N(c3cc(-c4cccc5ccccc45)c4ccccc4c3)c3ccccc3-c3ccccc3)c2)cc1 ; c1ccc(-c2cccc(N(c3cc(-c4cccc5ccccc45)c4ccccc4c3)c3ccc(-c4ccccc4)cc3-c3ccccc3)c2)cc1]

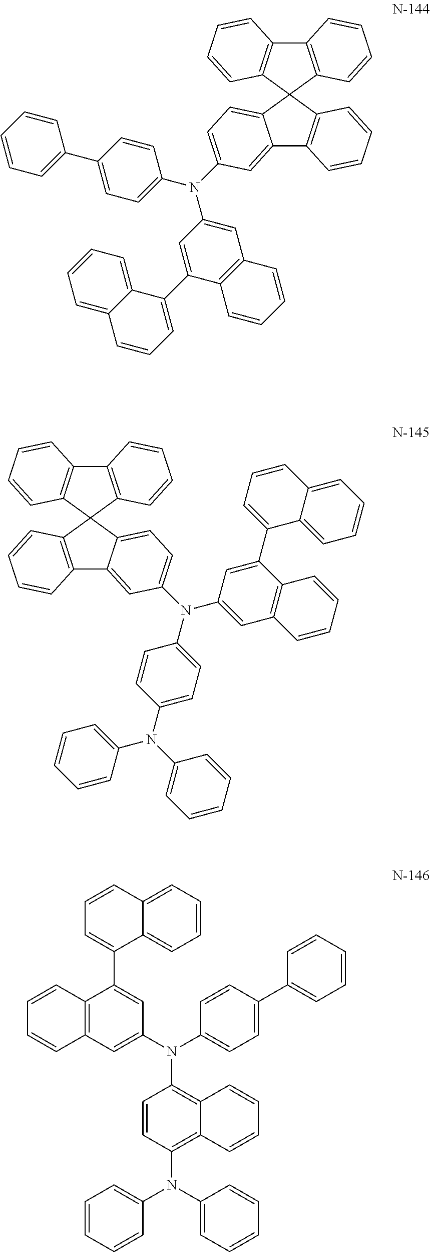 [SMILES: c1ccc(-c2ccc(N(c3ccc4c(c3)-c3ccccc3C43c4ccccc4-c4ccccc43)c3cc(-c4cccc5ccccc45)c4ccccc4c3)cc2)cc1 ; c1ccc(N(c2ccccc2)c2ccc(N(c3ccc4c(c3)-c3ccccc3C43c4ccccc4-c4ccccc43)c3cc(-c4cccc5ccccc45)c4ccccc4c3)cc2)cc1 ; c1ccc(-c2ccc(N(c3cc(-c4cccc5ccccc45)c4ccccc4c3)c3ccc(N(c4ccccc4)c4ccccc4)c4ccccc34)cc2)cc1]

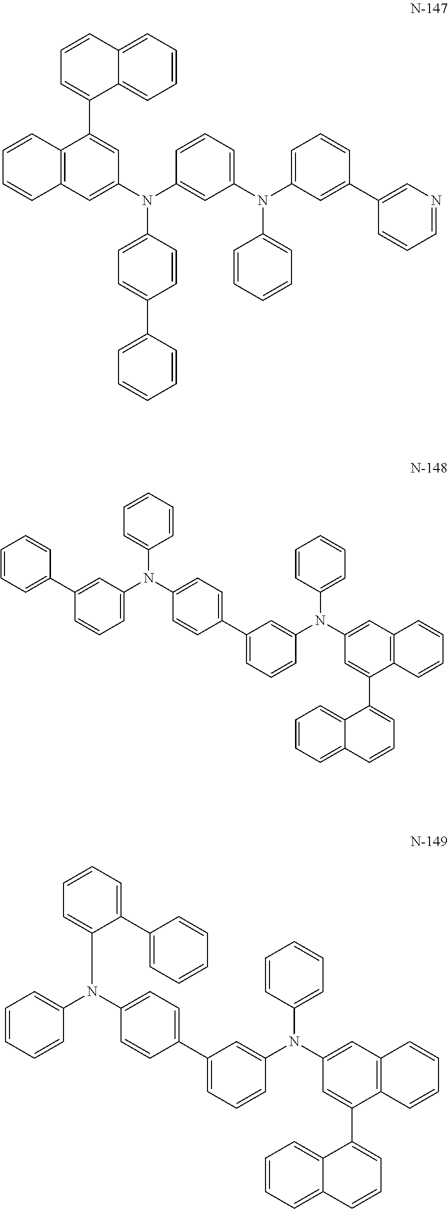 [SMILES: c1ccc(-c2ccc(N(c3cccc(N(c4ccccc4)c4cccc(-c5cccnc5)c4)c3)c3cc(-c4cccc5ccccc45)c4ccccc4c3)cc2)cc1 ; c1ccc(-c2cccc(N(c3ccccc3)c3ccc(-c4cccc(N(c5ccccc5)c5cc(-c6cccc7ccccc67)c6ccccc6c5)c4)cc3)c2)cc1 ; c1ccc(-c2ccccc2N(c2ccccc2)c2ccc(-c3cccc(N(c4ccccc4)c4cc(-c5cccc6ccccc56)c5ccccc5c4)c3)cc2)cc1]

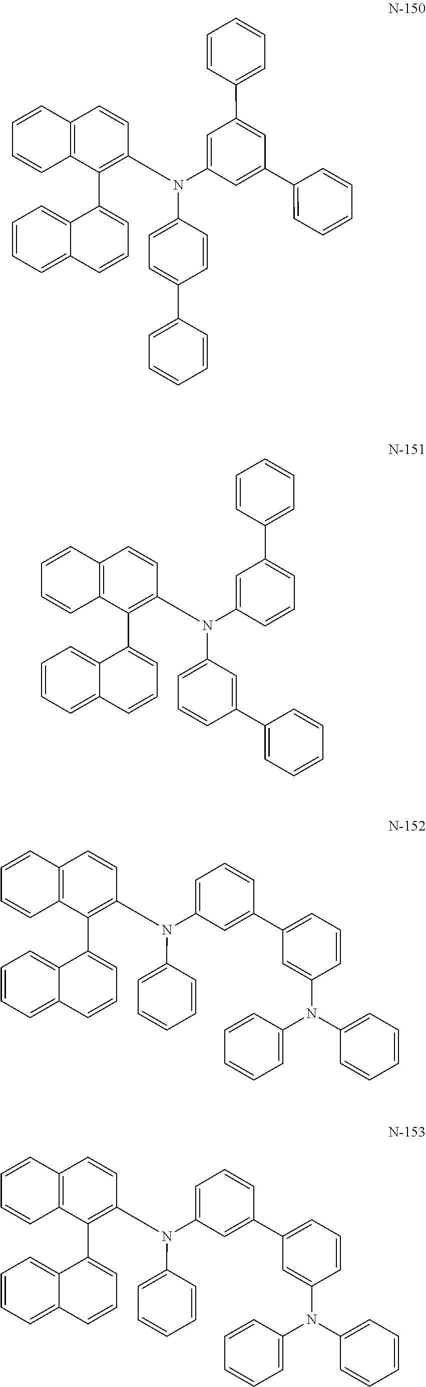 [SMILES: c1ccc(-c2ccc(N(c3cc(-c4ccccc4)cc(-c4ccccc4)c3)c3ccc4ccccc4c3-c3cccc4ccccc34)cc2)cc1 ; c1ccc(-c2cccc(N(c3cccc(-c4ccccc4)c3)c3ccc4ccccc4c3-c3cccc4ccccc34)c2)cc1 ; c1ccc(N(c2ccccc2)c2cccc(-c3cccc(N(c4ccccc4)c4ccc5ccccc5c4-c4cccc5ccccc45)c3)c2)cc1 ; c1ccc(N(c2ccccc2)c2cccc(-c3cccc(N(c4ccccc4)c4ccc5ccccc5c4-c4cccc5ccccc45)c3)c2)cc1]

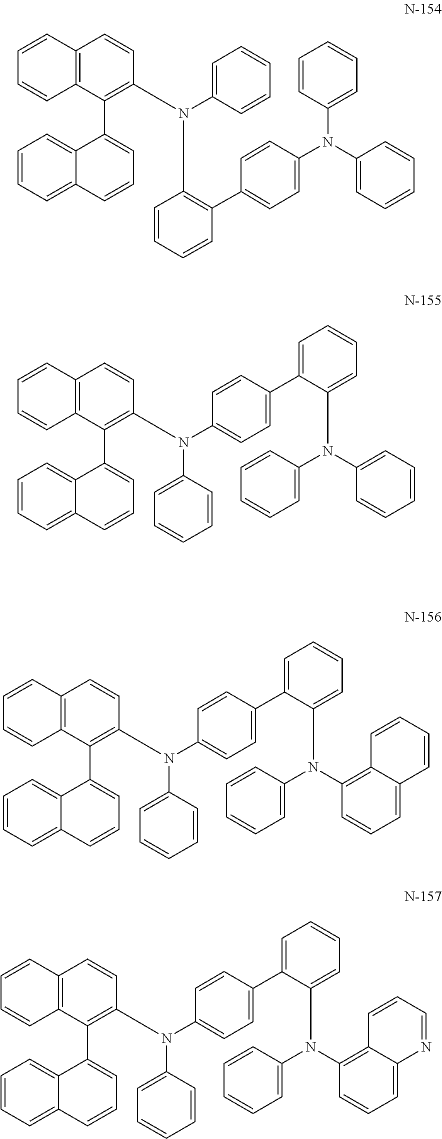 [SMILES: c1ccc(N(c2ccccc2)c2ccc(-c3ccccc3N(c3ccccc3)c3ccc4ccccc4c3-c3cccc4ccccc34)cc2)cc1 ; c1ccc(N(c2ccccc2)c2ccccc2-c2ccc(N(c3ccccc3)c3ccc4ccccc4c3-c3cccc4ccccc34)cc2)cc1 ; c1ccc(N(c2ccc(-c3ccccc3N(c3ccccc3)c3cccc4ccccc34)cc2)c2ccc3ccccc3c2-c2cccc3ccccc23)cc1 ; c1ccc(N(c2ccc(-c3ccccc3N(c3ccccc3)c3cccc4ncccc34)cc2)c2ccc3ccccc3c2-c2cccc3ccccc23)cc1]

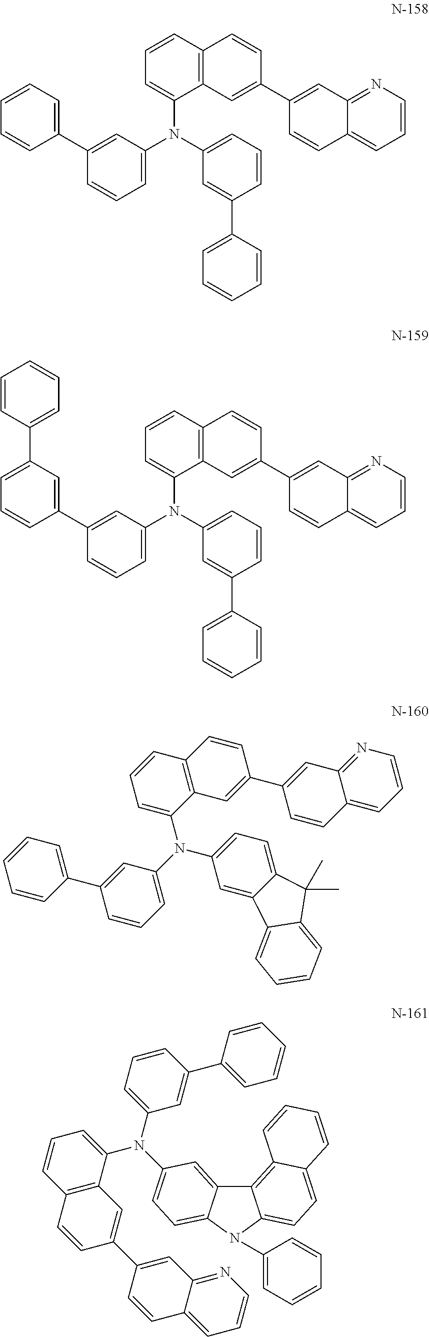

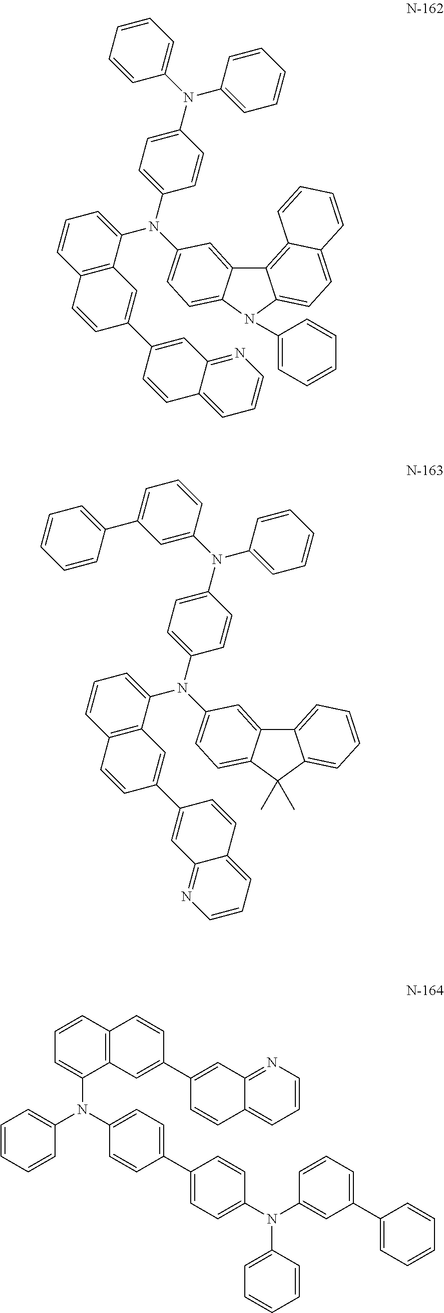 [SMILES: c1ccc(N(c2ccccc2)c2ccc(N(c3ccc4c(c3)c3c5ccccc5ccc3n4-c3ccccc3)c3cccc4ccc(-c5ccc6cccnc6c5)cc34)cc2)cc1 ; CC1(C)c2ccccc2-c2cc(N(c3ccc(N(c4ccccc4)c4cccc(-c5ccccc5)c4)cc3)c3cccc4ccc(-c5ccc6cccnc6c5)cc34)ccc21 ; c1ccc(-c2cccc(N(c3ccccc3)c3ccc(-c4ccc(N(c5ccccc5)c5cccc6ccc(-c7ccc8cccnc8c7)cc56)cc4)cc3)c2)cc1]

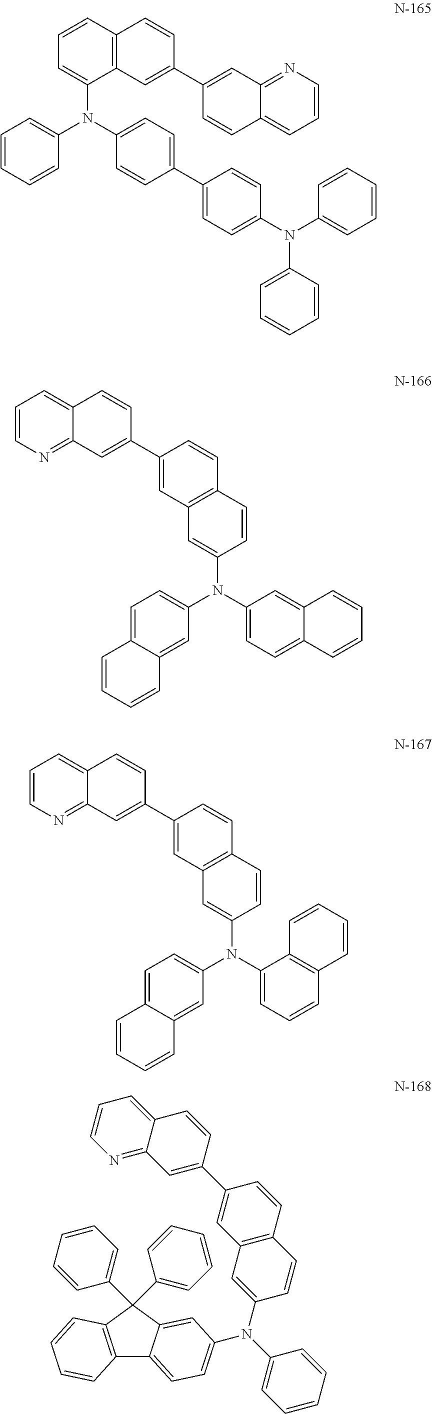

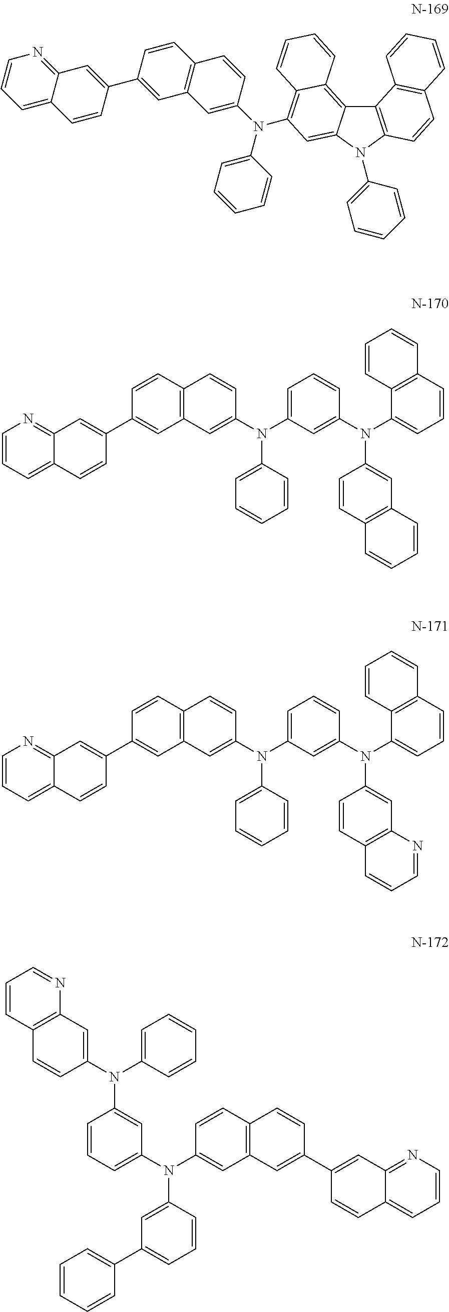 [SMILES: c1ccc(N(c2ccc3ccc(-c4ccc5cccnc5c4)cc3c2)c2cc3c(c4ccccc24)c2c4ccccc4ccc2n3-c2ccccc2)cc1 ; c1ccc(N(c2cccc(N(c3ccc4ccccc4c3)c3cccc4ccccc34)c2)c2ccc3ccc(-c4ccc5cccnc5c4)cc3c2)cc1 ; c1ccc(N(c2cccc(N(c3ccc4cccnc4c3)c3cccc4ccccc34)c2)c2ccc3ccc(-c4ccc5cccnc5c4)cc3c2)cc1 ; c1ccc(-c2cccc(N(c3cccc(N(c4ccccc4)c4ccc5cccnc5c4)c3)c3ccc4ccc(-c5ccc6cccnc6c5)cc4c3)c2)cc1]

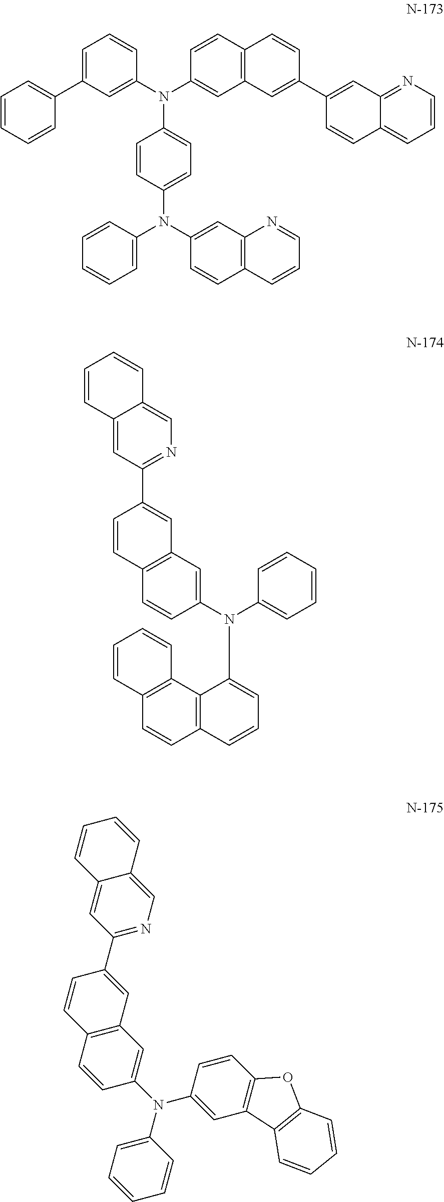 [SMILES: c1ccc(-c2cccc(N(c3ccc(N(c4ccccc4)c4ccc5cccnc5c4)cc3)c3ccc4ccc(-c5ccc6cccnc6c5)cc4c3)c2)cc1 ; c1ccc(N(c2ccc3ccc(-c4cc5ccccc5cn4)cc3c2)c2cccc3ccc4ccccc4c23)cc1 ; c1ccc(N(c2ccc3ccc(-c4cc5ccccc5cn4)cc3c2)c2ccc3oc4ccccc4c3c2)cc1]

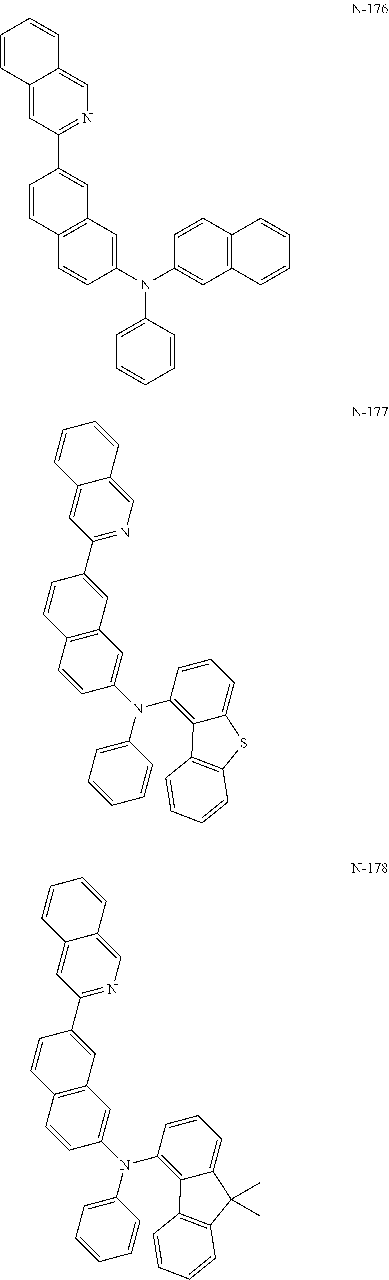 [SMILES: c1ccc(N(c2ccc3ccccc3c2)c2ccc3ccc(-c4cc5ccccc5cn4)cc3c2)cc1 ; c1ccc(N(c2ccc3ccc(-c4cc5ccccc5cn4)cc3c2)c2cccc3sc4ccccc4c23)cc1 ; CC1(C)c2ccccc2-c2c(N(c3ccccc3)c3ccc4ccc(-c5cc6ccccc6cn5)cc4c3)cccc21]

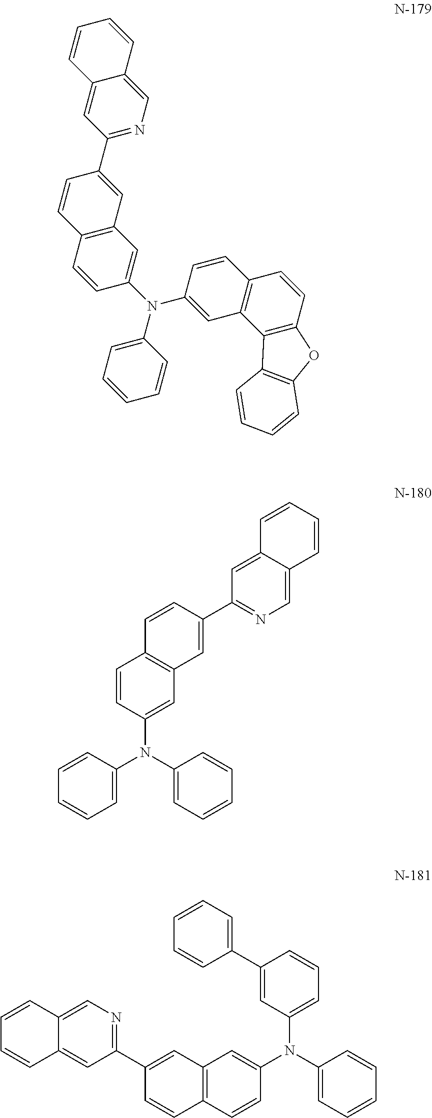 [SMILES: c1ccc(N(c2ccc3ccc(-c4cc5ccccc5cn4)cc3c2)c2ccc3ccc4oc5ccccc5c4c3c2)cc1 ; c1ccc(N(c2ccccc2)c2ccc3ccc(-c4cc5ccccc5cn4)cc3c2)cc1 ; c1ccc(-c2cccc(N(c3ccccc3)c3ccc4ccc(-c5cc6ccccc6cn5)cc4c3)c2)cc1]

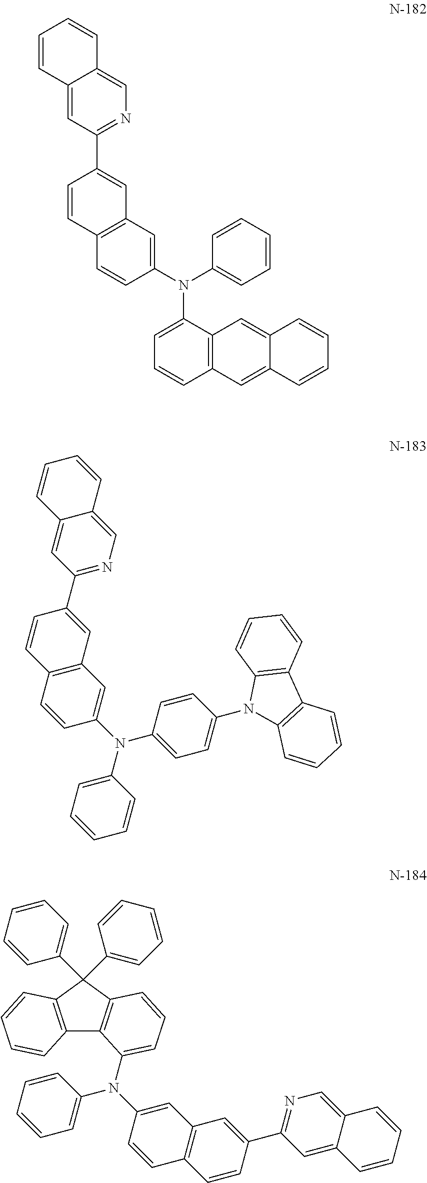 [SMILES: c1ccc(N(c2ccc3ccc(-c4cc5ccccc5cn4)cc3c2)c2cccc3cc4ccccc4cc23)cc1 ; c1ccc(N(c2ccc(-n3c4ccccc4c4ccccc43)cc2)c2ccc3ccc(-c4cc5ccccc5cn4)cc3c2)cc1 ; c1ccc(N(c2ccc3ccc(-c4cc5ccccc5cn4)cc3c2)c2cccc3c2-c2ccccc2C3(c2ccccc2)c2ccccc2)cc1]

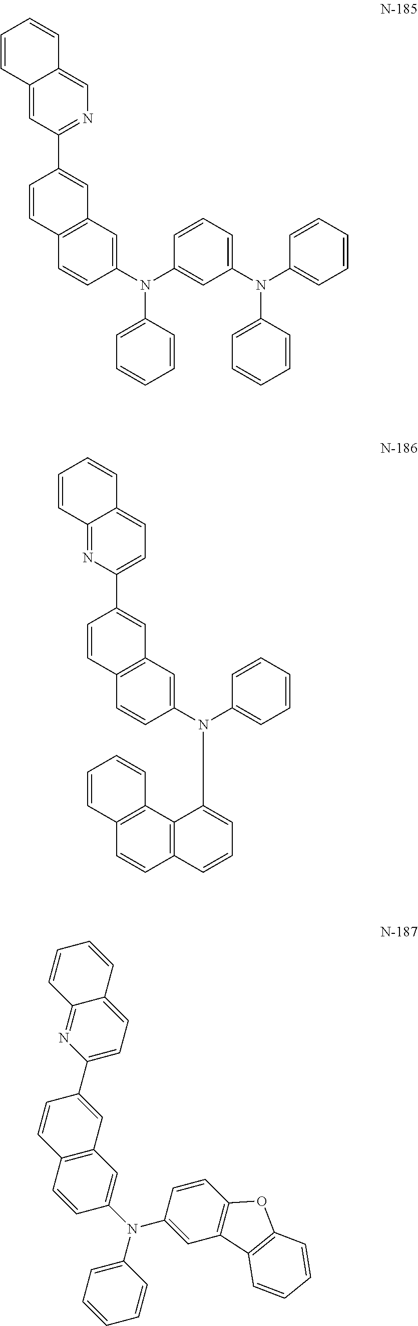 [SMILES: c1ccc(N(c2ccccc2)c2cccc(N(c3ccccc3)c3ccc4ccc(-c5cc6ccccc6cn5)cc4c3)c2)cc1 ; c1ccc(N(c2ccc3ccc(-c4ccc5ccccc5n4)cc3c2)c2cccc3ccc4ccccc4c23)cc1 ; c1ccc(N(c2ccc3ccc(-c4ccc5ccccc5n4)cc3c2)c2ccc3oc4ccccc4c3c2)cc1]

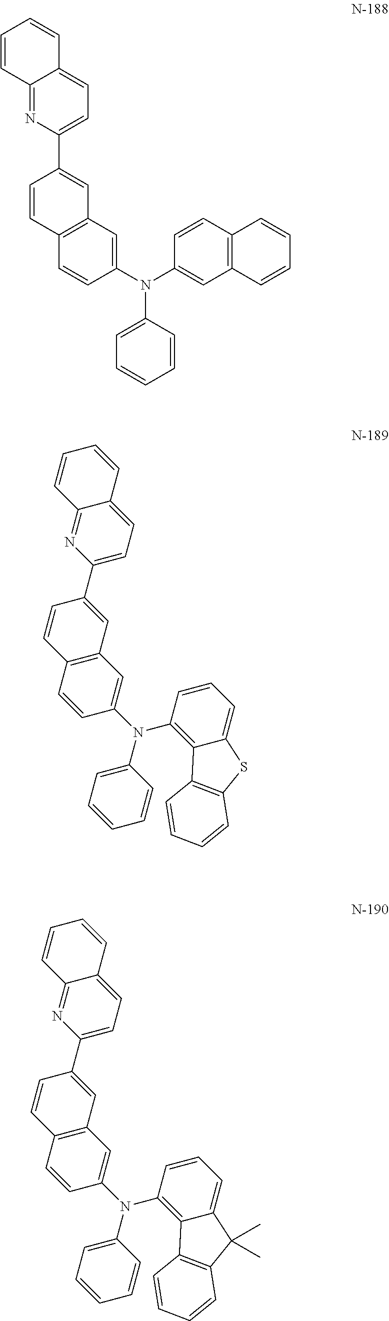 [SMILES: c1ccc(N(c2ccc3ccccc3c2)c2ccc3ccc(-c4ccc5ccccc5n4)cc3c2)cc1 ; c1ccc(N(c2ccc3ccc(-c4ccc5ccccc5n4)cc3c2)c2cccc3sc4ccccc4c23)cc1 ; CC1(C)c2ccccc2-c2c(N(c3ccccc3)c3ccc4ccc(-c5ccc6ccccc6n5)cc4c3)cccc21]

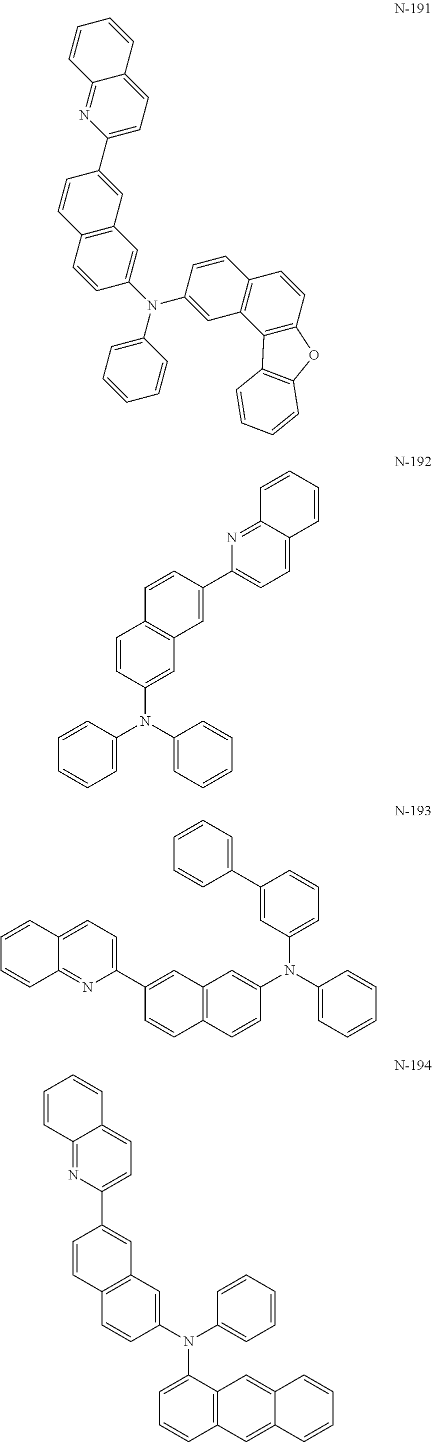

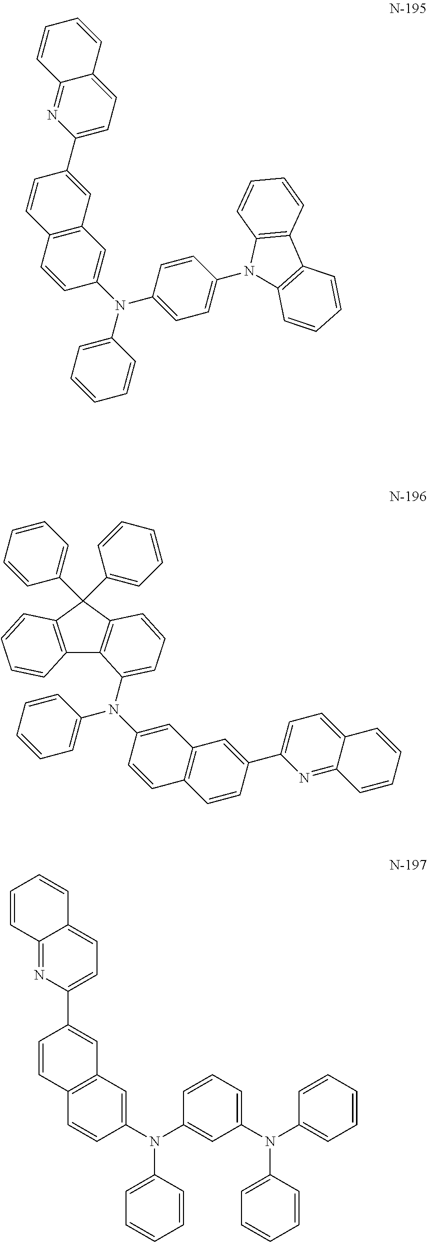 [SMILES: c1ccc(N(c2ccc(-n3c4ccccc4c4ccccc43)cc2)c2ccc3ccc(-c4ccc5ccccc5n4)cc3c2)cc1 ; c1ccc(N(c2ccc3ccc(-c4ccc5ccccc5n4)cc3c2)c2cccc3c2-c2ccccc2C3(c2ccccc2)c2ccccc2)cc1 ; c1ccc(N(c2ccccc2)c2cccc(N(c3ccccc3)c3ccc4ccc(-c5ccc6ccccc6n5)cc4c3)c2)cc1]

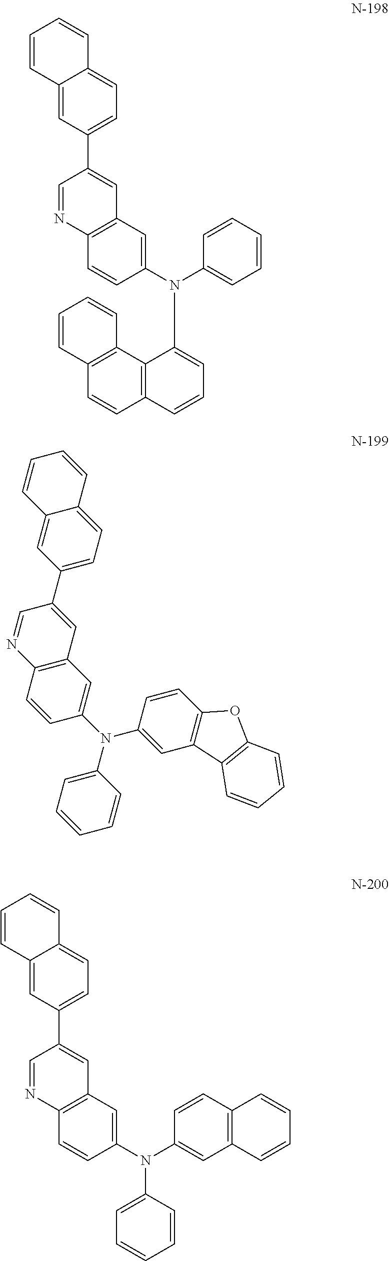 [SMILES: c1ccc(N(c2ccc3ncc(-c4ccc5ccccc5c4)cc3c2)c2cccc3ccc4ccccc4c23)cc1 ; c1ccc(N(c2ccc3ncc(-c4ccc5ccccc5c4)cc3c2)c2ccc3oc4ccccc4c3c2)cc1 ; c1ccc(N(c2ccc3ccccc3c2)c2ccc3ncc(-c4ccc5ccccc5c4)cc3c2)cc1]

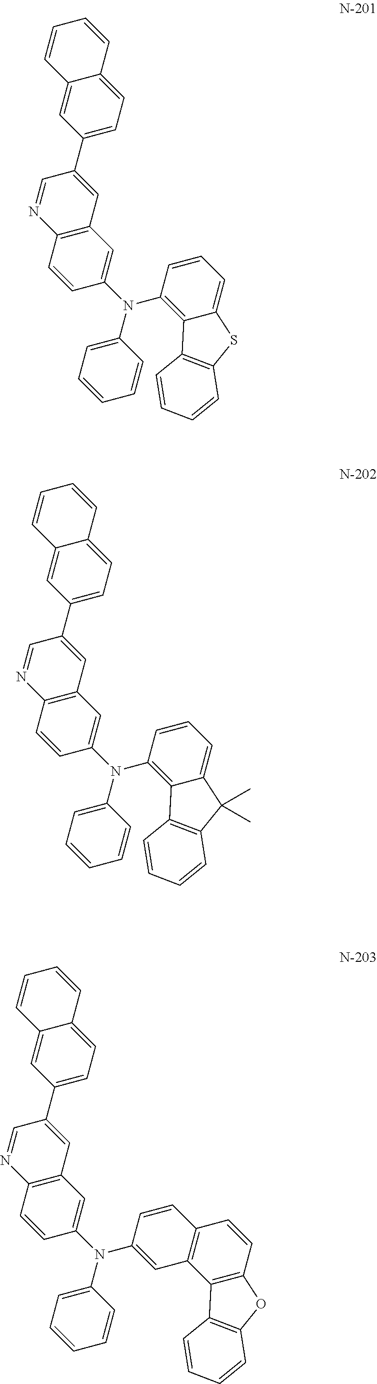 [SMILES: c1ccc(N(c2ccc3ncc(-c4ccc5ccccc5c4)cc3c2)c2cccc3sc4ccccc4c23)cc1 ; CC1(C)c2ccccc2-c2c(N(c3ccccc3)c3ccc4ncc(-c5ccc6ccccc6c5)cc4c3)cccc21 ; c1ccc(N(c2ccc3ncc(-c4ccc5ccccc5c4)cc3c2)c2ccc3ccc4oc5ccccc5c4c3c2)cc1]

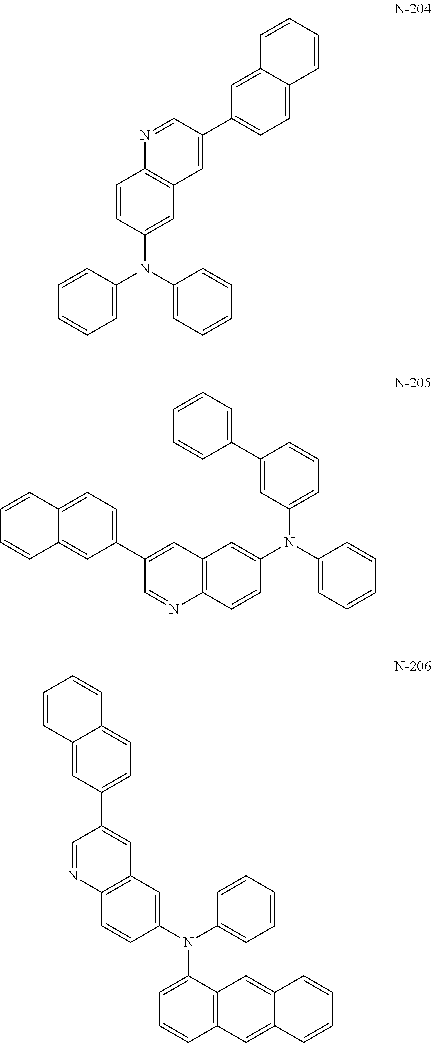 [SMILES: c1ccc(N(c2ccccc2)c2ccc3ncc(-c4ccc5ccccc5c4)cc3c2)cc1 ; c1ccc(-c2cccc(N(c3ccccc3)c3ccc4ncc(-c5ccc6ccccc6c5)cc4c3)c2)cc1 ; c1ccc(N(c2ccc3ncc(-c4ccc5ccccc5c4)cc3c2)c2cccc3cc4ccccc4cc23)cc1]

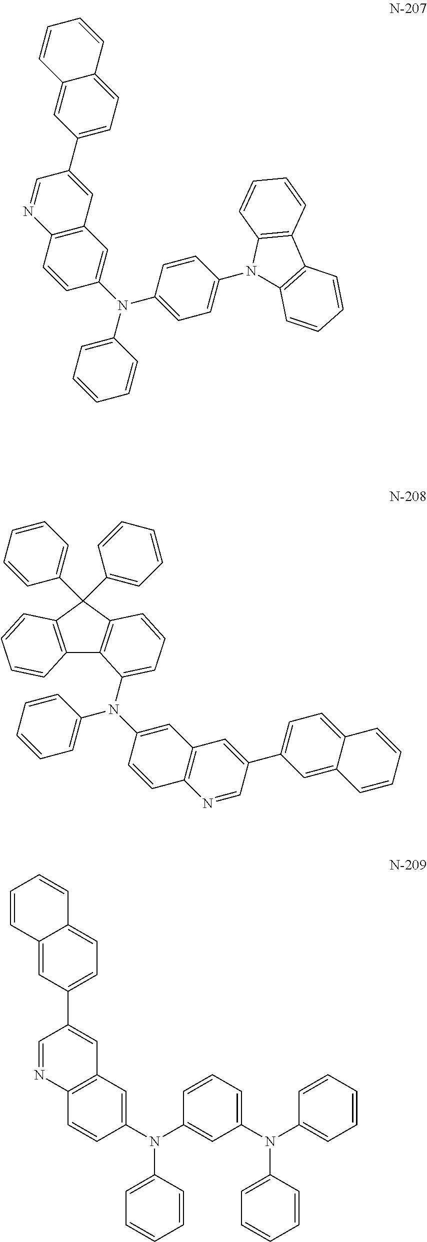 [SMILES: c1ccc(N(c2ccc(-n3c4ccccc4c4ccccc43)cc2)c2ccc3ncc(-c4ccc5ccccc5c4)cc3c2)cc1 ; c1ccc(N(c2ccc3ncc(-c4ccc5ccccc5c4)cc3c2)c2cccc3c2-c2ccccc2C3(c2ccccc2)c2ccccc2)cc1 ; c1ccc(N(c2ccccc2)c2cccc(N(c3ccccc3)c3ccc4ncc(-c5ccc6ccccc6c5)cc4c3)c2)cc1]

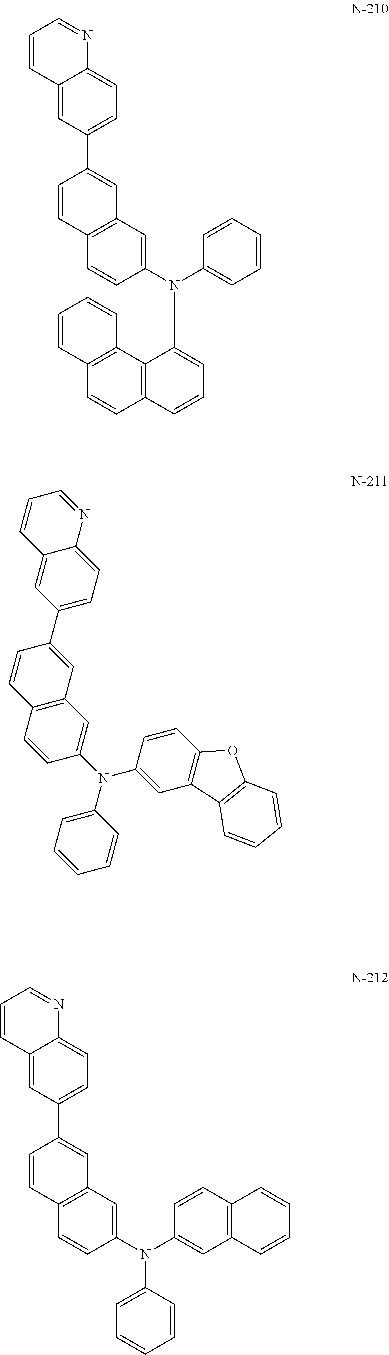 [SMILES: c1ccc(N(c2ccc3ccc(-c4ccc5ncccc5c4)cc3c2)c2cccc3ccc4ccccc4c23)cc1 ; c1ccc(N(c2ccc3ccc(-c4ccc5ncccc5c4)cc3c2)c2ccc3oc4ccccc4c3c2)cc1 ; c1ccc(N(c2ccc3ccccc3c2)c2ccc3ccc(-c4ccc5ncccc5c4)cc3c2)cc1]

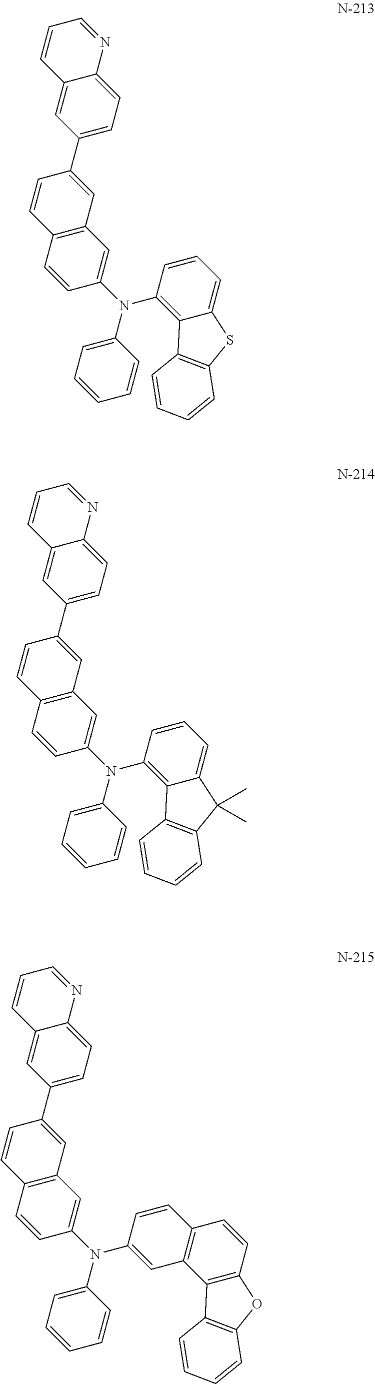 [SMILES: c1ccc(N(c2ccc3ccc(-c4ccc5ncccc5c4)cc3c2)c2cccc3sc4ccccc4c23)cc1 ; CC1(C)c2ccccc2-c2c(N(c3ccccc3)c3ccc4ccc(-c5ccc6ncccc6c5)cc4c3)cccc21 ; c1ccc(N(c2ccc3ccc(-c4ccc5ncccc5c4)cc3c2)c2ccc3ccc4oc5ccccc5c4c3c2)cc1]

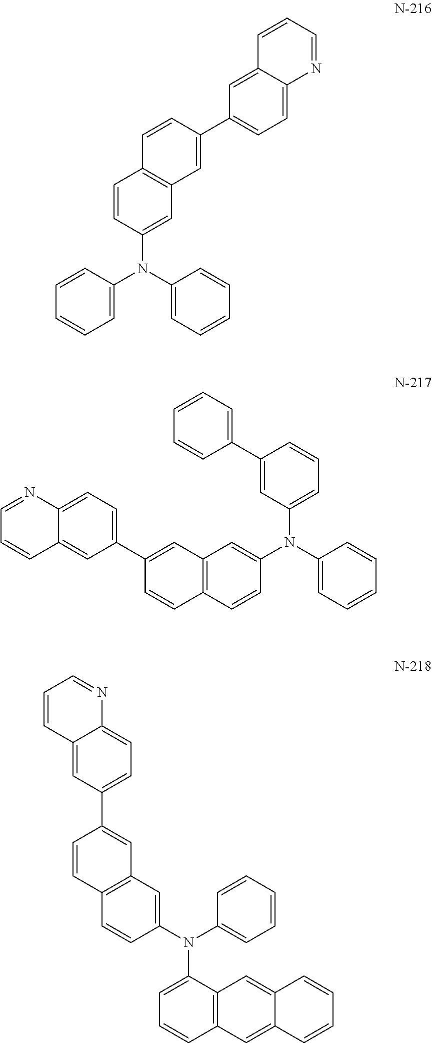 [SMILES: c1ccc(N(c2ccccc2)c2ccc3ccc(-c4ccc5ncccc5c4)cc3c2)cc1 ; c1ccc(-c2cccc(N(c3ccccc3)c3ccc4ccc(-c5ccc6ncccc6c5)cc4c3)c2)cc1 ; c1ccc(N(c2ccc3ccc(-c4ccc5ncccc5c4)cc3c2)c2cccc3cc4ccccc4cc23)cc1]

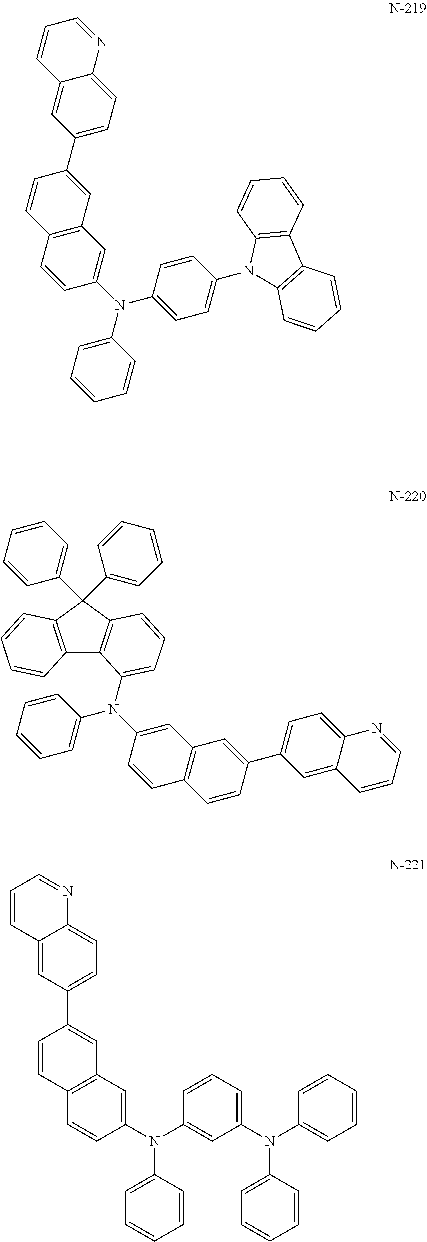 [SMILES: c1ccc(N(c2ccc(-n3c4ccccc4c4ccccc43)cc2)c2ccc3ccc(-c4ccc5ncccc5c4)cc3c2)cc1 ; c1ccc(N(c2ccc3ccc(-c4ccc5ncccc5c4)cc3c2)c2cccc3c2-c2ccccc2C3(c2ccccc2)c2ccccc2)cc1 ; c1ccc(N(c2ccccc2)c2cccc(N(c3ccccc3)c3ccc4ccc(-c5ccc6ncccc6c5)cc4c3)c2)cc1]

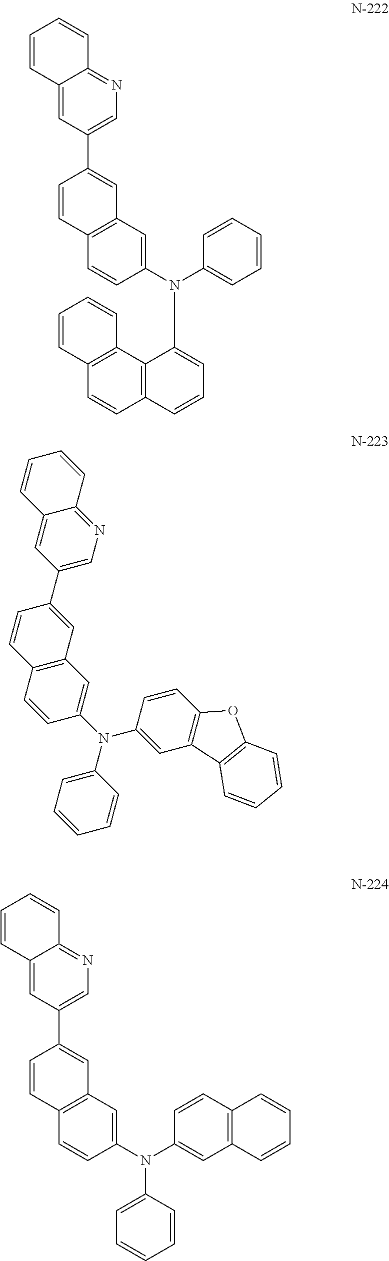 [SMILES: c1ccc(N(c2ccc3ccc(-c4cnc5ccccc5c4)cc3c2)c2cccc3ccc4ccccc4c23)cc1 ; c1ccc(N(c2ccc3ccc(-c4cnc5ccccc5c4)cc3c2)c2ccc3oc4ccccc4c3c2)cc1 ; c1ccc(N(c2ccc3ccccc3c2)c2ccc3ccc(-c4cnc5ccccc5c4)cc3c2)cc1]

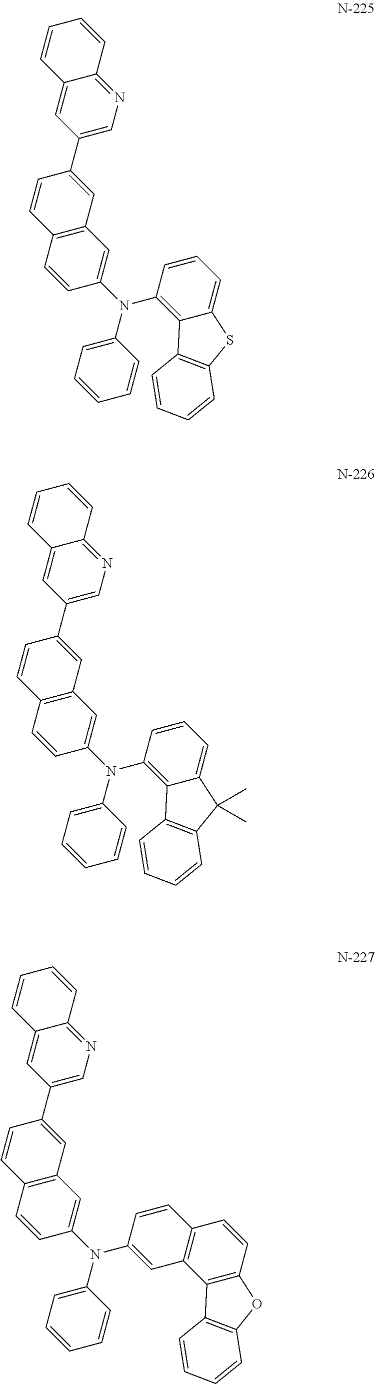 [SMILES: c1ccc(N(c2ccc3ccc(-c4cnc5ccccc5c4)cc3c2)c2cccc3sc4ccccc4c23)cc1 ; CC1(C)c2ccccc2-c2c(N(c3ccccc3)c3ccc4ccc(-c5cnc6ccccc6c5)cc4c3)cccc21 ; c1ccc(N(c2ccc3ccc(-c4cnc5ccccc5c4)cc3c2)c2ccc3ccc4oc5ccccc5c4c3c2)cc1]

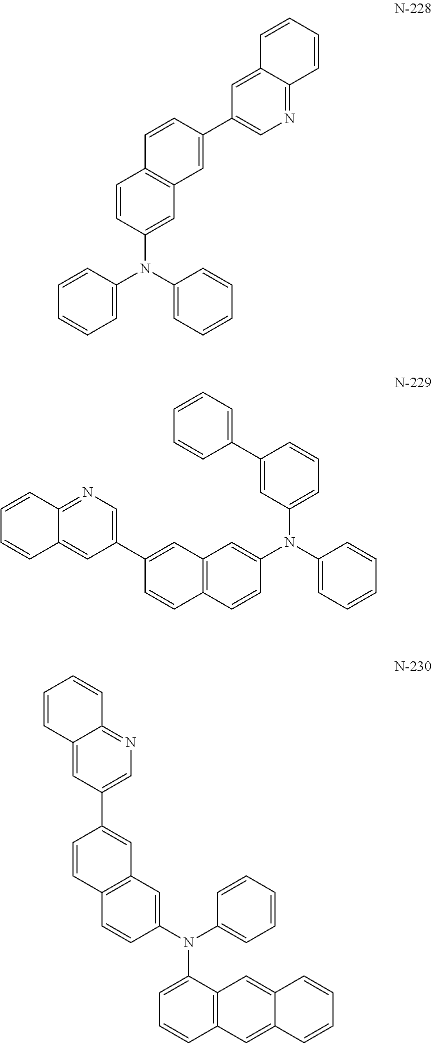 [SMILES: c1ccc(N(c2ccccc2)c2ccc3ccc(-c4cnc5ccccc5c4)cc3c2)cc1 ; c1ccc(-c2cccc(N(c3ccccc3)c3ccc4ccc(-c5cnc6ccccc6c5)cc4c3)c2)cc1 ; c1ccc(N(c2ccc3ccc(-c4cnc5ccccc5c4)cc3c2)c2cccc3cc4ccccc4cc23)cc1]

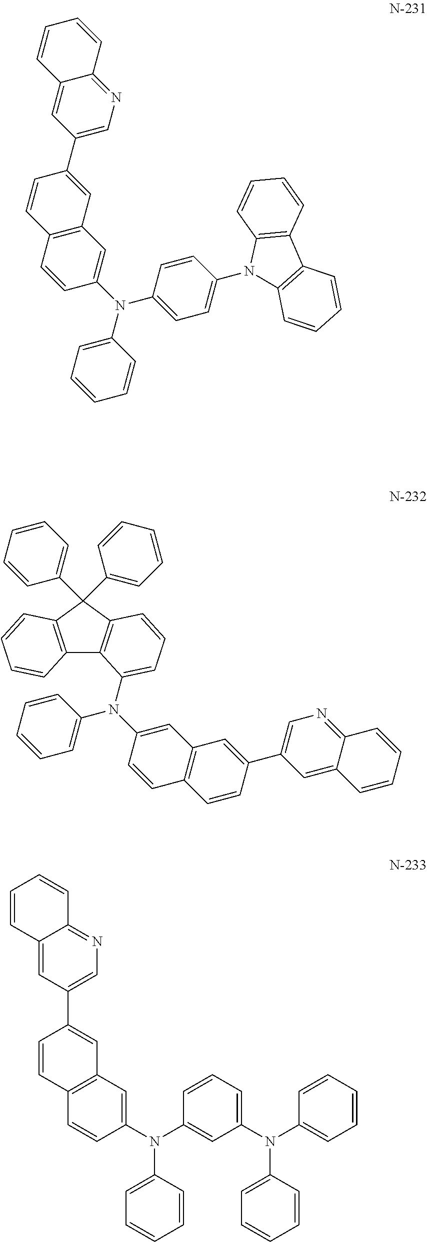 [SMILES: c1ccc(N(c2ccc(-n3c4ccccc4c4ccccc43)cc2)c2ccc3ccc(-c4cnc5ccccc5c4)cc3c2)cc1 ; c1ccc(N(c2ccc3ccc(-c4cnc5ccccc5c4)cc3c2)c2cccc3c2-c2ccccc2C3(c2ccccc2)c2ccccc2)cc1 ; c1ccc(N(c2ccccc2)c2cccc(N(c3ccccc3)c3ccc4ccc(-c5cnc6ccccc6c5)cc4c3)c2)cc1]

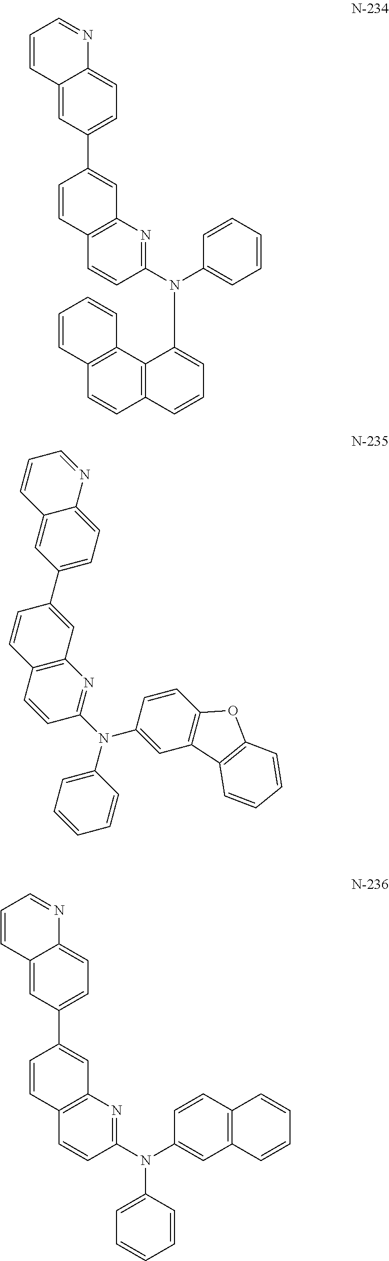 [SMILES: c1ccc(N(c2ccc3ccc(-c4ccc5ncccc5c4)cc3n2)c2cccc3ccc4ccccc4c23)cc1 ; c1ccc(N(c2ccc3oc4ccccc4c3c2)c2ccc3ccc(-c4ccc5ncccc5c4)cc3n2)cc1 ; c1ccc(N(c2ccc3ccccc3c2)c2ccc3ccc(-c4ccc5ncccc5c4)cc3n2)cc1]

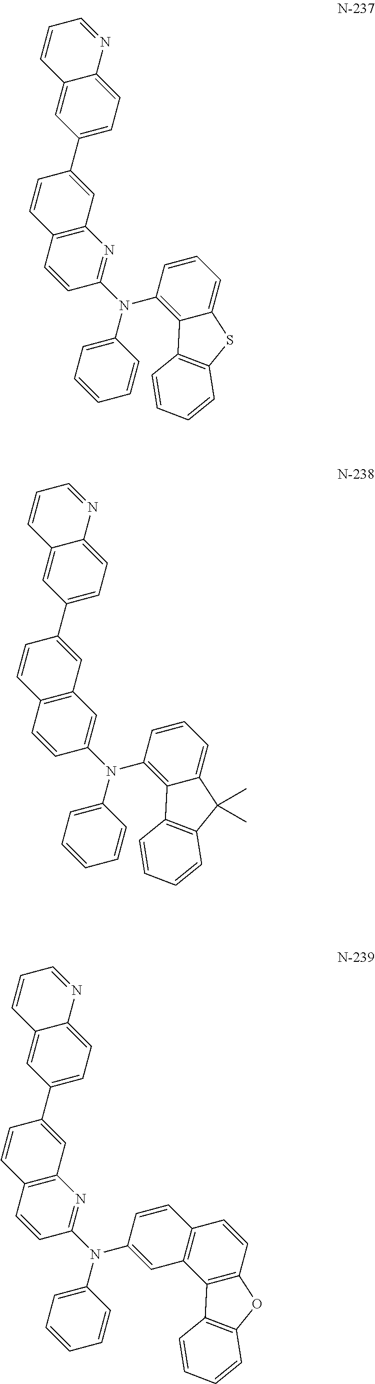 [SMILES: c1ccc(N(c2ccc3ccc(-c4ccc5ncccc5c4)cc3n2)c2cccc3sc4ccccc4c23)cc1 ; CC1(C)c2ccccc2-c2c(N(c3ccccc3)c3ccc4ccc(-c5ccc6ncccc6c5)cc4c3)cccc21 ; c1ccc(N(c2ccc3ccc4oc5ccccc5c4c3c2)c2ccc3ccc(-c4ccc5ncccc5c4)cc3n2)cc1]

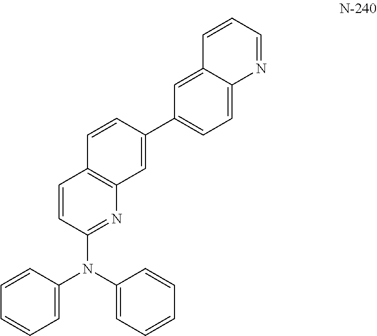 [SMILES: c1ccc(N(c2ccccc2)c2ccc3ccc(-c4ccc5ncccc5c4)cc3n2)cc1]

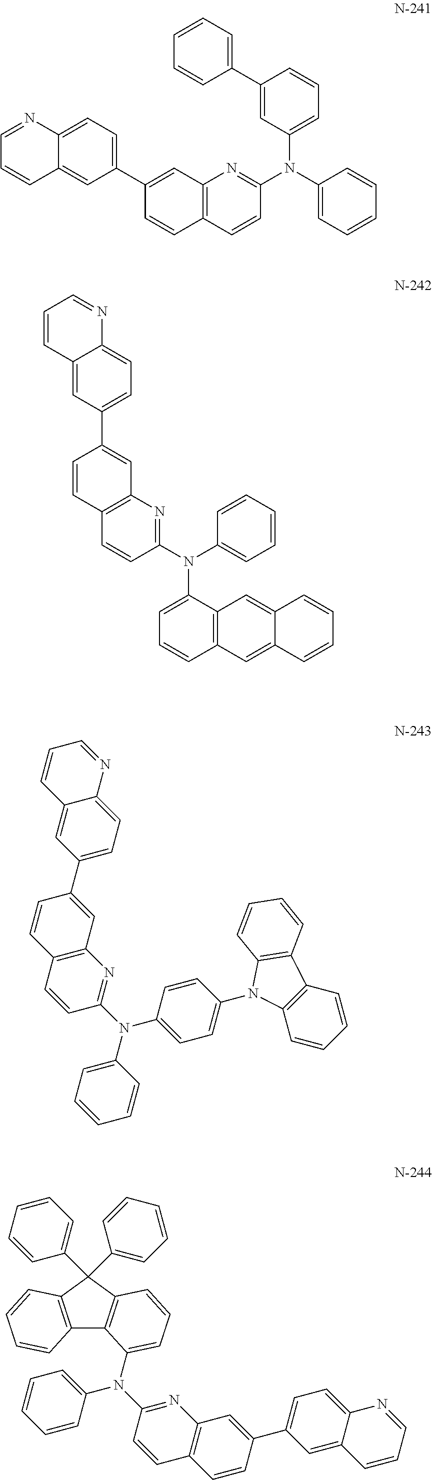 [SMILES: c1ccc(-c2cccc(N(c3ccccc3)c3ccc4ccc(-c5ccc6ncccc6c5)cc4n3)c2)cc1 ; c1ccc(N(c2ccc3ccc(-c4ccc5ncccc5c4)cc3n2)c2cccc3cc4ccccc4cc23)cc1 ; c1ccc(N(c2ccc(-n3c4ccccc4c4ccccc43)cc2)c2ccc3ccc(-c4ccc5ncccc5c4)cc3n2)cc1 ; c1ccc(N(c2ccc3ccc(-c4ccc5ncccc5c4)cc3n2)c2cccc3c2-c2ccccc2C3(c2ccccc2)c2ccccc2)cc1]

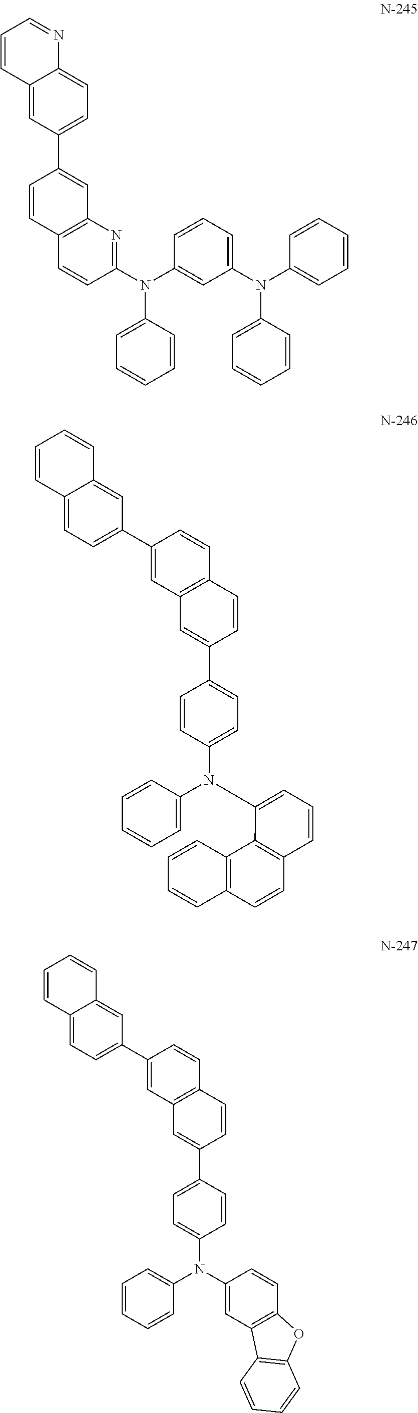 [SMILES: c1ccc(N(c2ccccc2)c2cccc(N(c3ccccc3)c3ccc4ccc(-c5ccc6ncccc6c5)cc4n3)c2)cc1 ; c1ccc(N(c2ccc(-c3ccc4ccc(-c5ccc6ccccc6c5)cc4c3)cc2)c2cccc3ccc4ccccc4c23)cc1 ; c1ccc(N(c2ccc(-c3ccc4ccc(-c5ccc6ccccc6c5)cc4c3)cc2)c2ccc3oc4ccccc4c3c2)cc1]

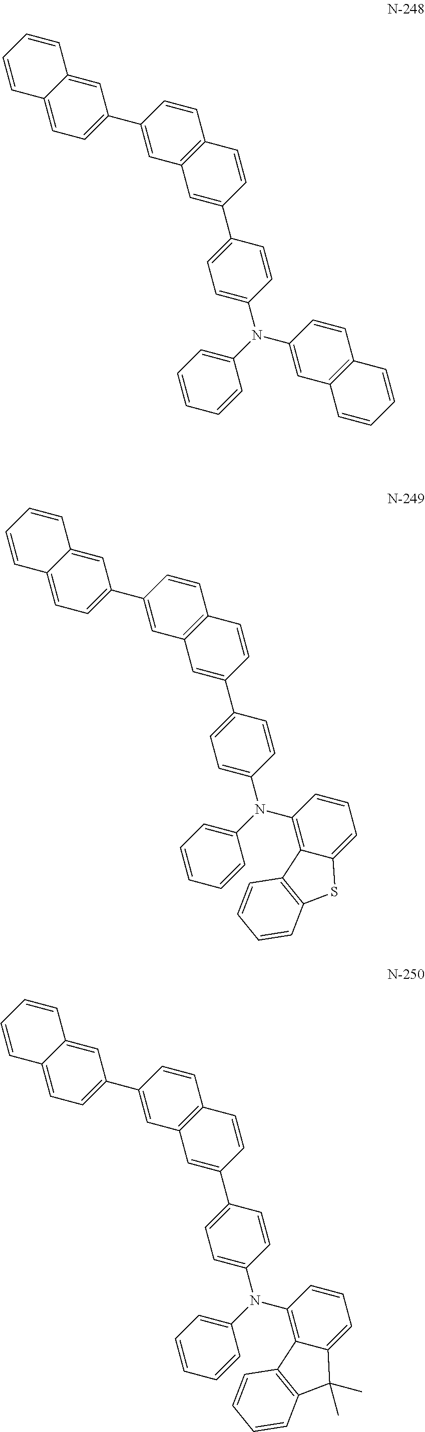 [SMILES: c1ccc(N(c2ccc(-c3ccc4ccc(-c5ccc6ccccc6c5)cc4c3)cc2)c2ccc3ccccc3c2)cc1 ; c1ccc(N(c2ccc(-c3ccc4ccc(-c5ccc6ccccc6c5)cc4c3)cc2)c2cccc3sc4ccccc4c23)cc1 ; CC1(C)c2ccccc2-c2c(N(c3ccccc3)c3ccc(-c4ccc5ccc(-c6ccc7ccccc7c6)cc5c4)cc3)cccc21]

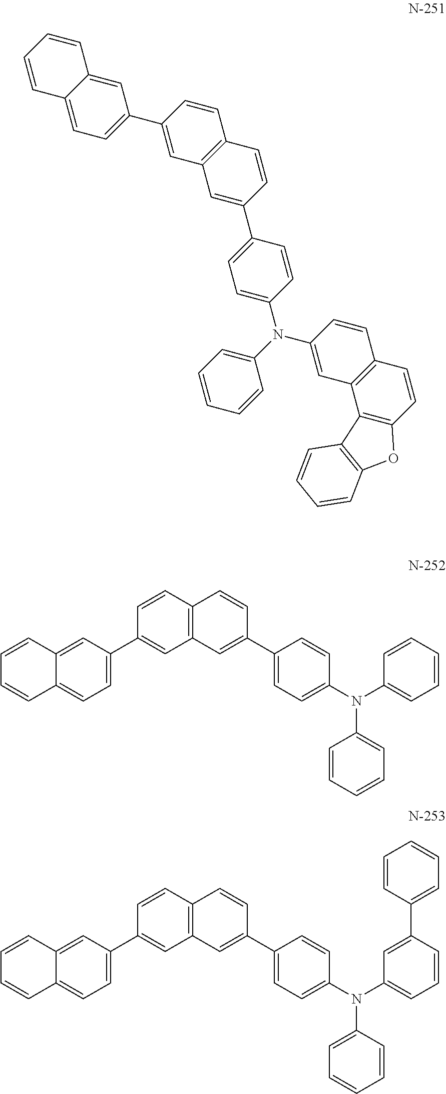 [SMILES: c1ccc(N(c2ccc(-c3ccc4ccc(-c5ccc6ccccc6c5)cc4c3)cc2)c2ccc3ccc4oc5ccccc5c4c3c2)cc1 ; c1ccc(N(c2ccccc2)c2ccc(-c3ccc4ccc(-c5ccc6ccccc6c5)cc4c3)cc2)cc1 ; c1ccc(-c2cccc(N(c3ccccc3)c3ccc(-c4ccc5ccc(-c6ccc7ccccc7c6)cc5c4)cc3)c2)cc1]

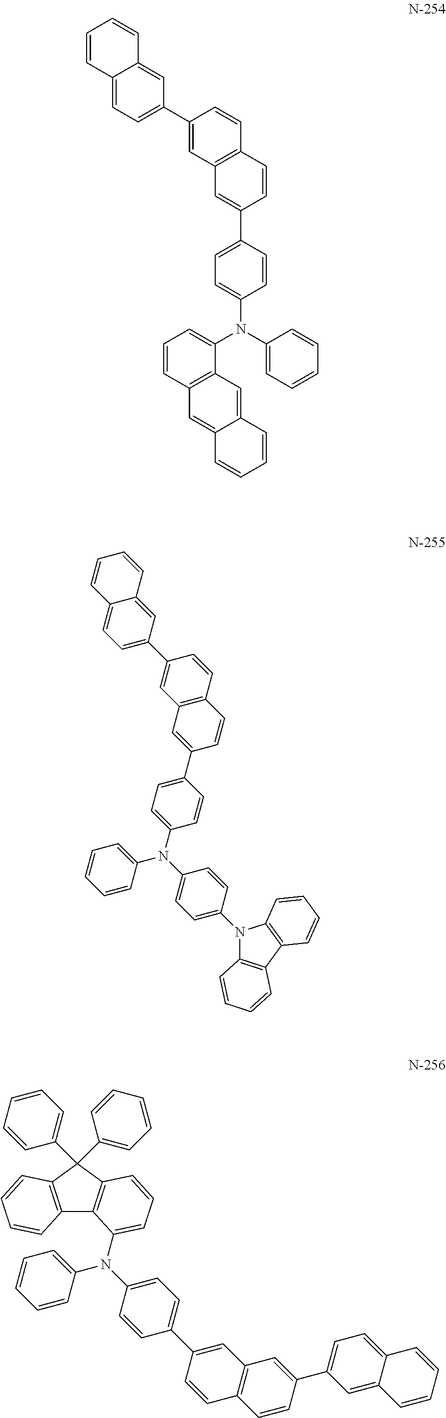 [SMILES: c1ccc(N(c2ccc(-c3ccc4ccc(-c5ccc6ccccc6c5)cc4c3)cc2)c2cccc3cc4ccccc4cc23)cc1 ; c1ccc(N(c2ccc(-c3ccc4ccc(-c5ccc6ccccc6c5)cc4c3)cc2)c2ccc(-n3c4ccccc4c4ccccc43)cc2)cc1 ; c1ccc(N(c2ccc(-c3ccc4ccc(-c5ccc6ccccc6c5)cc4c3)cc2)c2cccc3c2-c2ccccc2C3(c2ccccc2)c2ccccc2)cc1]

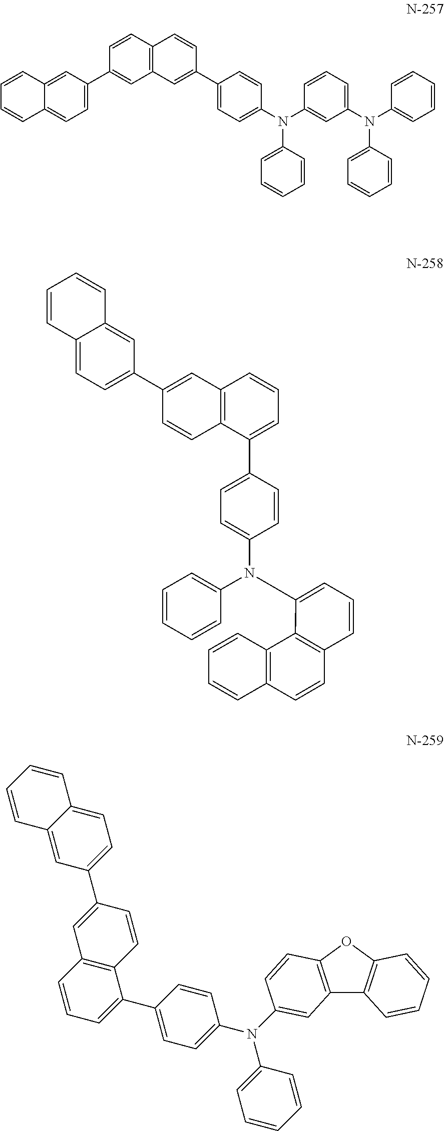 [SMILES: c1ccc(N(c2ccccc2)c2cccc(N(c3ccccc3)c3ccc(-c4ccc5ccc(-c6ccc7ccccc7c6)cc5c4)cc3)c2)cc1 ; c1ccc(N(c2ccc(-c3cccc4cc(-c5ccc6ccccc6c5)ccc34)cc2)c2cccc3ccc4ccccc4c23)cc1 ; c1ccc(N(c2ccc(-c3cccc4cc(-c5ccc6ccccc6c5)ccc34)cc2)c2ccc3oc4ccccc4c3c2)cc1]

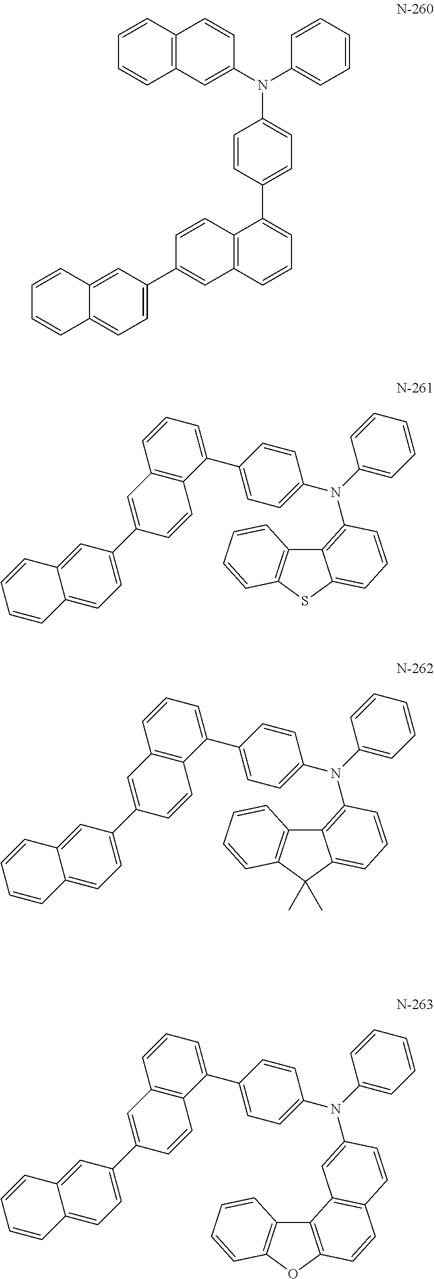 [SMILES: c1ccc(N(c2ccc(-c3cccc4cc(-c5ccc6ccccc6c5)ccc34)cc2)c2ccc3ccccc3c2)cc1 ; c1ccc(N(c2ccc(-c3cccc4cc(-c5ccc6ccccc6c5)ccc34)cc2)c2cccc3sc4ccccc4c23)cc1 ; CC1(C)c2ccccc2-c2c(N(c3ccccc3)c3ccc(-c4cccc5cc(-c6ccc7ccccc7c6)ccc45)cc3)cccc21 ; c1ccc(N(c2ccc(-c3cccc4cc(-c5ccc6ccccc6c5)ccc34)cc2)c2ccc3ccc4oc5ccccc5c4c3c2)cc1]

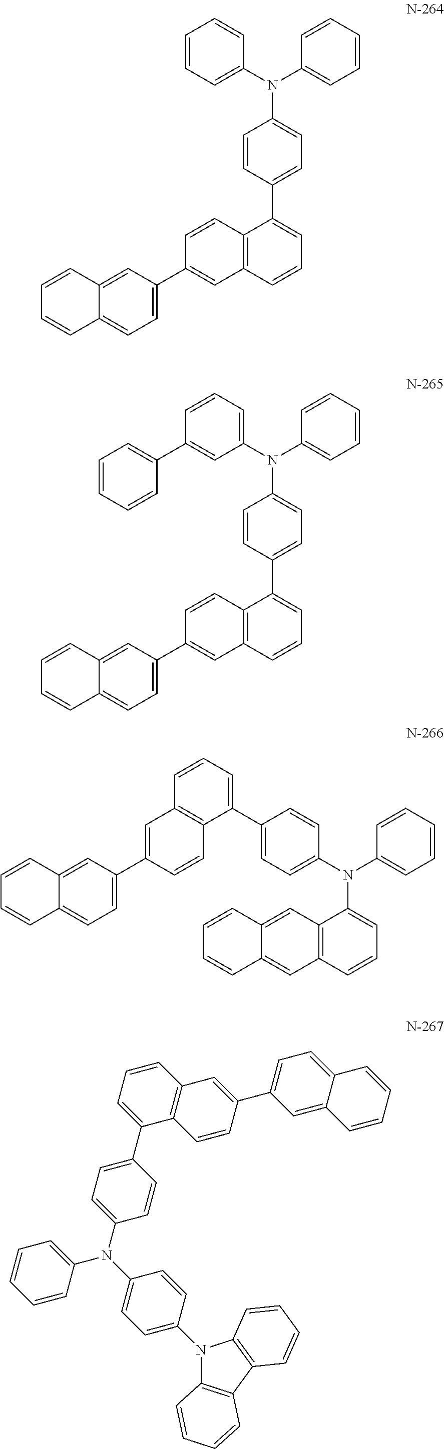 [SMILES: c1ccc(N(c2ccccc2)c2ccc(-c3cccc4cc(-c5ccc6ccccc6c5)ccc34)cc2)cc1 ; c1ccc(-c2cccc(N(c3ccccc3)c3ccc(-c4cccc5cc(-c6ccc7ccccc7c6)ccc45)cc3)c2)cc1 ; c1ccc(N(c2ccc(-c3cccc4cc(-c5ccc6ccccc6c5)ccc34)cc2)c2cccc3cc4ccccc4cc23)cc1 ; c1ccc(N(c2ccc(-c3cccc4cc(-c5ccc6ccccc6c5)ccc34)cc2)c2ccc(-n3c4ccccc4c4ccccc43)cc2)cc1]

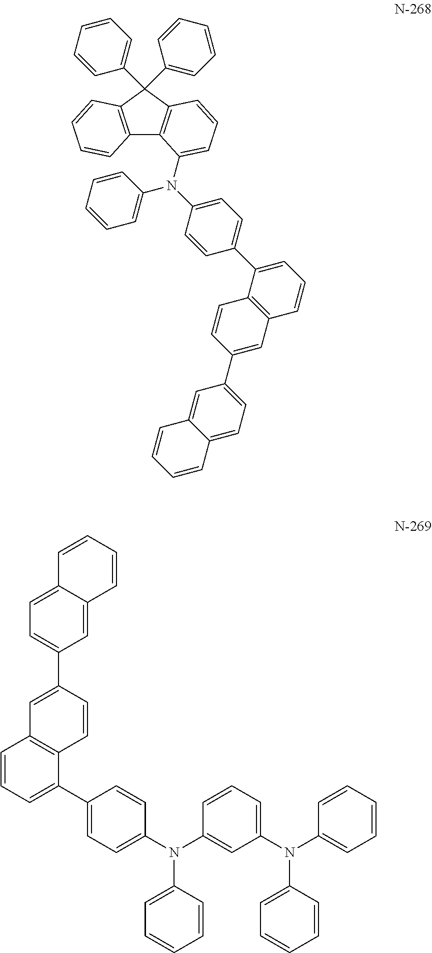 [SMILES: c1ccc(N(c2ccc(-c3cccc4cc(-c5ccc6ccccc6c5)ccc34)cc2)c2cccc3c2-c2ccccc2C3(c2ccccc2)c2ccccc2)cc1 ; c1ccc(N(c2ccccc2)c2cccc(N(c3ccccc3)c3ccc(-c4cccc5cc(-c6ccc7ccccc7c6)ccc45)cc3)c2)cc1]

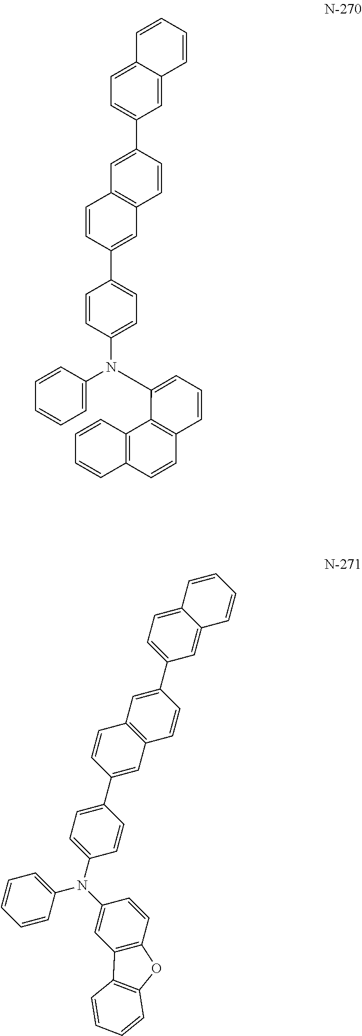 [SMILES: c1ccc(N(c2ccc(-c3ccc4cc(-c5ccc6ccccc6c5)ccc4c3)cc2)c2cccc3ccc4ccccc4c23)cc1 ; c1ccc(N(c2ccc(-c3ccc4cc(-c5ccc6ccccc6c5)ccc4c3)cc2)c2ccc3oc4ccccc4c3c2)cc1]

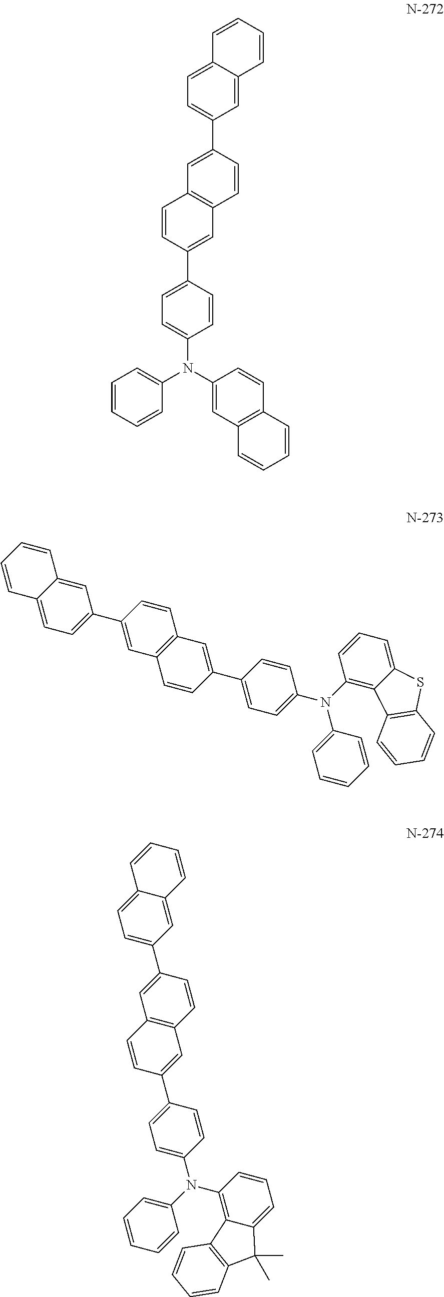 [SMILES: c1ccc(N(c2ccc(-c3ccc4cc(-c5ccc6ccccc6c5)ccc4c3)cc2)c2ccc3ccccc3c2)cc1 ; c1ccc(N(c2ccc(-c3ccc4cc(-c5ccc6ccccc6c5)ccc4c3)cc2)c2cccc3sc4ccccc4c23)cc1 ; CC1(C)c2ccccc2-c2c(N(c3ccccc3)c3ccc(-c4ccc5cc(-c6ccc7ccccc7c6)ccc5c4)cc3)cccc21]

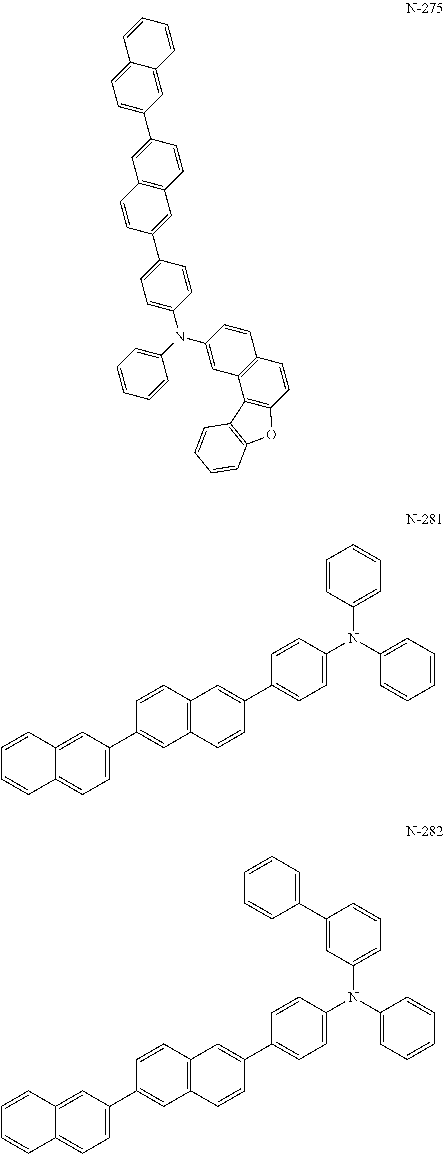 [SMILES: c1ccc(N(c2ccc(-c3ccc4cc(-c5ccc6ccccc6c5)ccc4c3)cc2)c2ccc3ccc4oc5ccccc5c4c3c2)cc1 ; c1ccc(N(c2ccccc2)c2ccc(-c3ccc4cc(-c5ccc6ccccc6c5)ccc4c3)cc2)cc1 ; c1ccc(-c2cccc(N(c3ccccc3)c3ccc(-c4ccc5cc(-c6ccc7ccccc7c6)ccc5c4)cc3)c2)cc1]

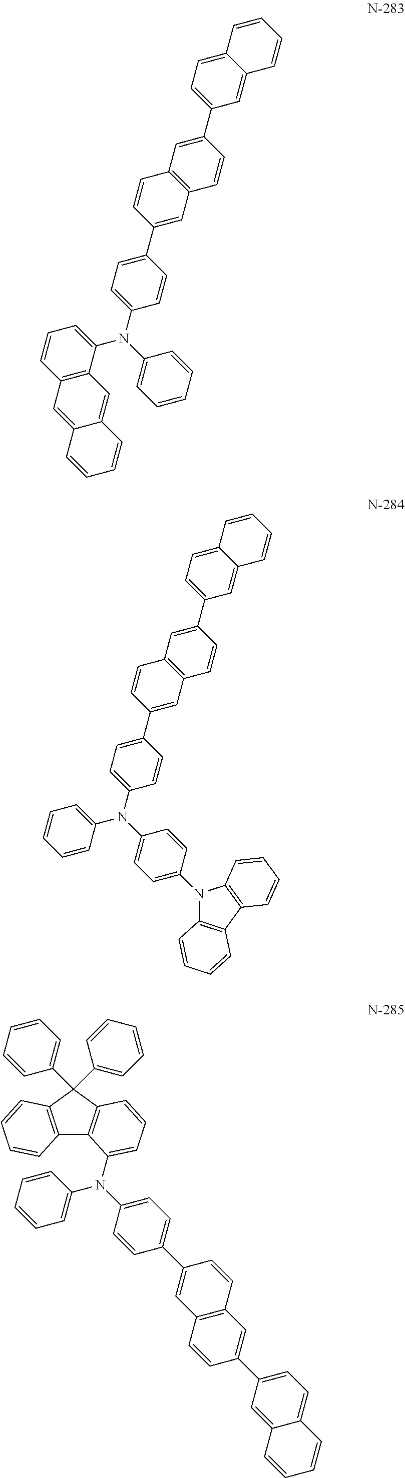 [SMILES: c1ccc(N(c2ccc(-c3ccc4cc(-c5ccc6ccccc6c5)ccc4c3)cc2)c2cccc3cc4ccccc4cc23)cc1 ; c1ccc(N(c2ccc(-c3ccc4cc(-c5ccc6ccccc6c5)ccc4c3)cc2)c2ccc(-n3c4ccccc4c4ccccc43)cc2)cc1 ; c1ccc(N(c2ccc(-c3ccc4cc(-c5ccc6ccccc6c5)ccc4c3)cc2)c2cccc3c2-c2ccccc2C3(c2ccccc2)c2ccccc2)cc1]

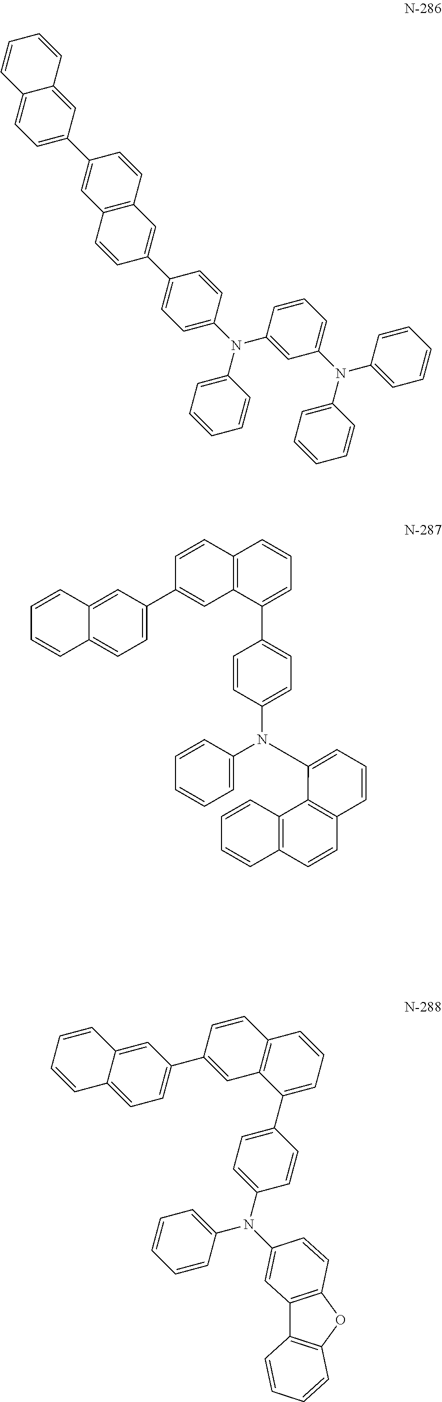 [SMILES: c1ccc(N(c2ccccc2)c2cccc(N(c3ccccc3)c3ccc(-c4ccc5cc(-c6ccc7ccccc7c6)ccc5c4)cc3)c2)cc1 ; c1ccc(N(c2ccc(-c3cccc4ccc(-c5ccc6ccccc6c5)cc34)cc2)c2cccc3ccc4ccccc4c23)cc1 ; c1ccc(N(c2ccc(-c3cccc4ccc(-c5ccc6ccccc6c5)cc34)cc2)c2ccc3oc4ccccc4c3c2)cc1]

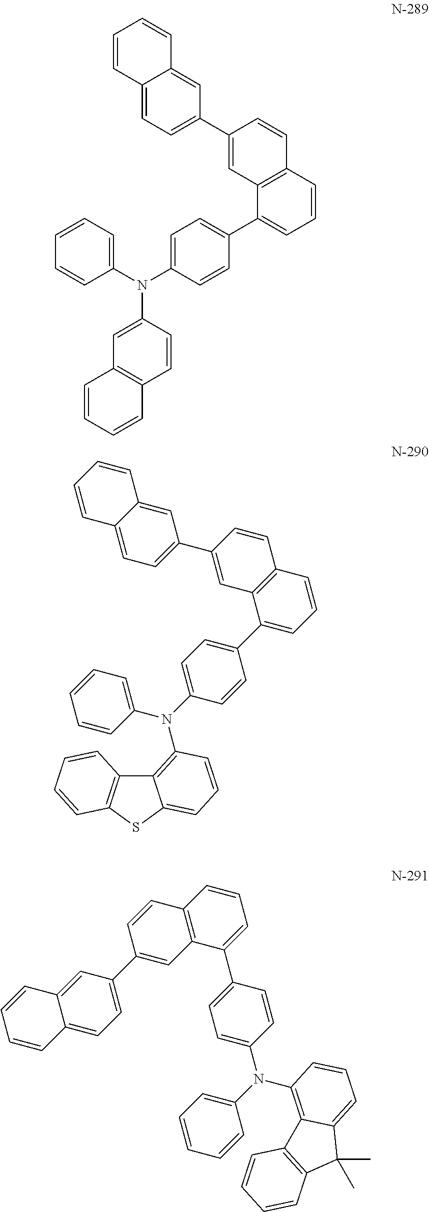

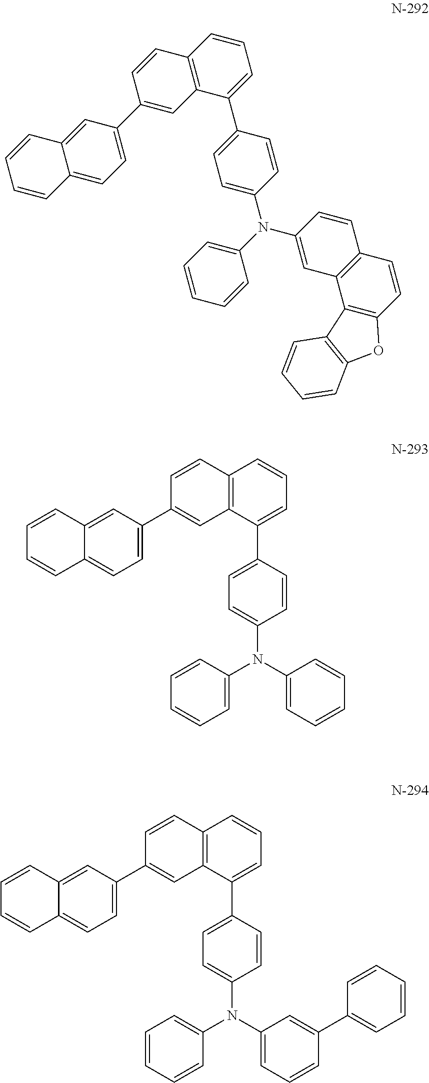 [SMILES: c1ccc(N(c2ccc(-c3cccc4ccc(-c5ccc6ccccc6c5)cc34)cc2)c2ccc3ccc4oc5ccccc5c4c3c2)cc1 ; c1ccc(N(c2ccccc2)c2ccc(-c3cccc4ccc(-c5ccc6ccccc6c5)cc34)cc2)cc1 ; c1ccc(-c2cccc(N(c3ccccc3)c3ccc(-c4cccc5ccc(-c6ccc7ccccc7c6)cc45)cc3)c2)cc1]

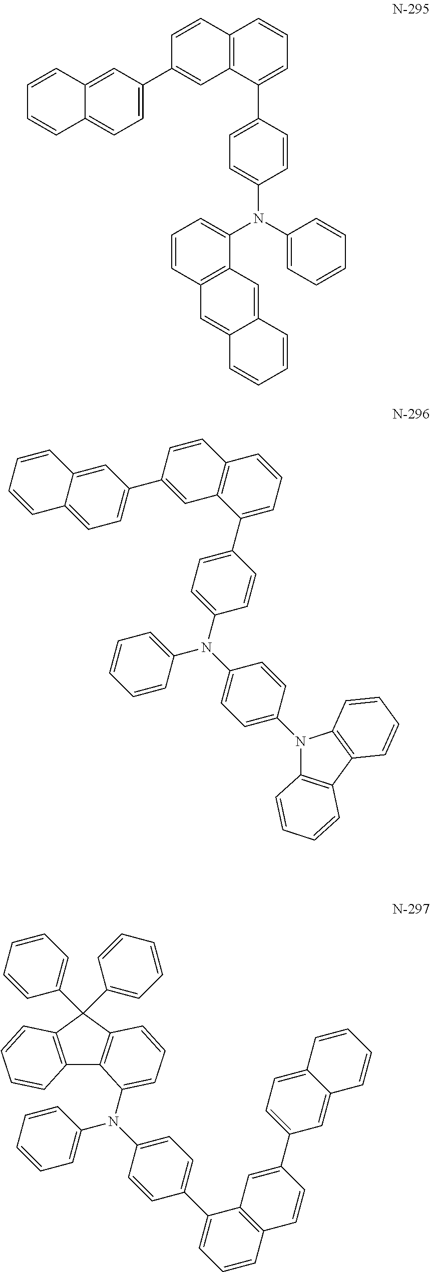 [SMILES: c1ccc(N(c2ccc(-c3cccc4ccc(-c5ccc6ccccc6c5)cc34)cc2)c2cccc3cc4ccccc4cc23)cc1 ; c1ccc(N(c2ccc(-c3cccc4ccc(-c5ccc6ccccc6c5)cc34)cc2)c2ccc(-n3c4ccccc4c4ccccc43)cc2)cc1 ; c1ccc(N(c2ccc(-c3cccc4ccc(-c5ccc6ccccc6c5)cc34)cc2)c2cccc3c2-c2ccccc2C3(c2ccccc2)c2ccccc2)cc1]

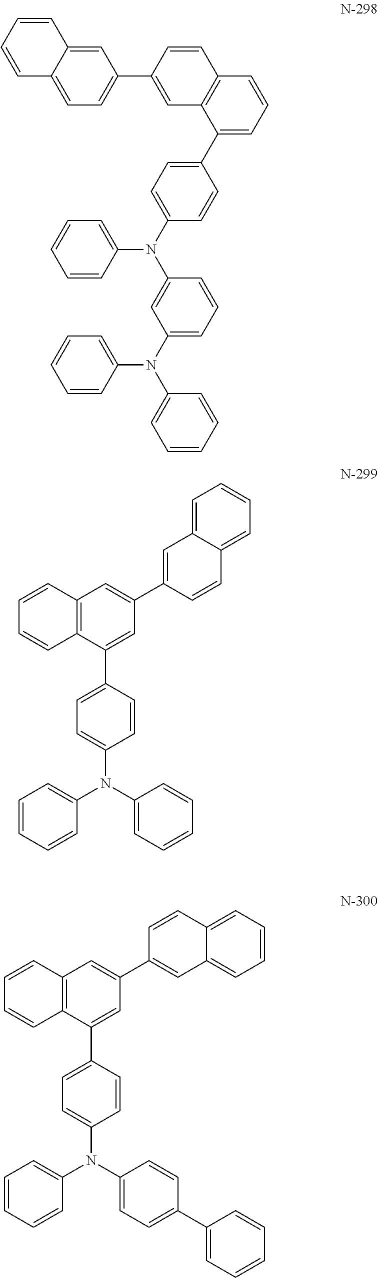

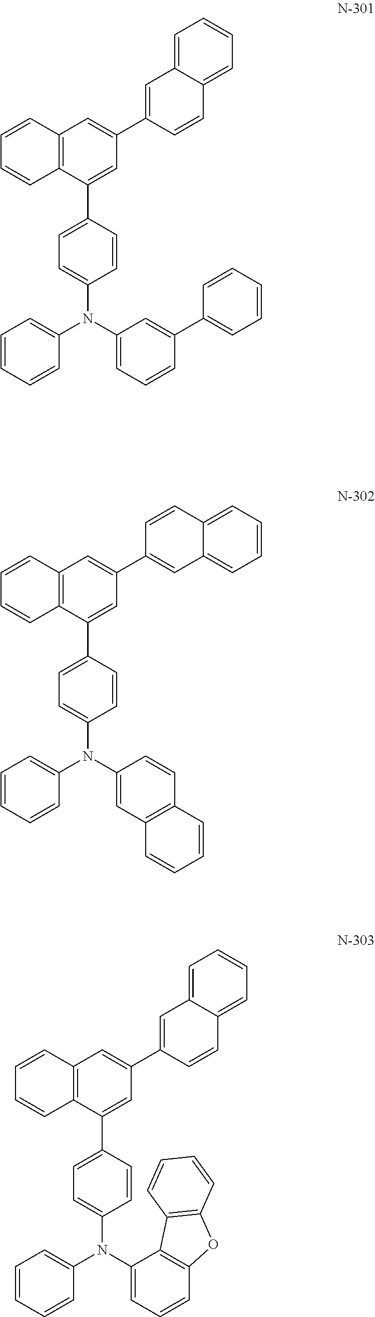 [SMILES: c1ccc(-c2cccc(N(c3ccccc3)c3ccc(-c4cc(-c5ccc6ccccc6c5)cc5ccccc45)cc3)c2)cc1 ; c1ccc(N(c2ccc(-c3cc(-c4ccc5ccccc5c4)cc4ccccc34)cc2)c2ccc3ccccc3c2)cc1 ; c1ccc(N(c2ccc(-c3cc(-c4ccc5ccccc5c4)cc4ccccc34)cc2)c2cccc3oc4ccccc4c23)cc1]

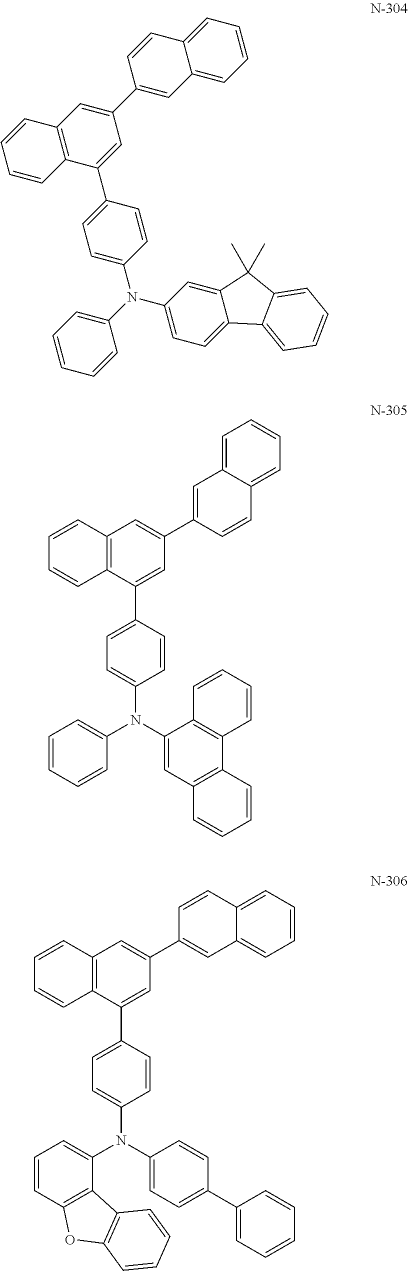 [SMILES: CC1(C)c2ccccc2-c2ccc(N(c3ccccc3)c3ccc(-c4cc(-c5ccc6ccccc6c5)cc5ccccc45)cc3)cc21 ; c1ccc(N(c2ccc(-c3cc(-c4ccc5ccccc5c4)cc4ccccc34)cc2)c2cc3ccccc3c3ccccc23)cc1 ; c1ccc(-c2ccc(N(c3ccc(-c4cc(-c5ccc6ccccc6c5)cc5ccccc45)cc3)c3cccc4oc5ccccc5c34)cc2)cc1]

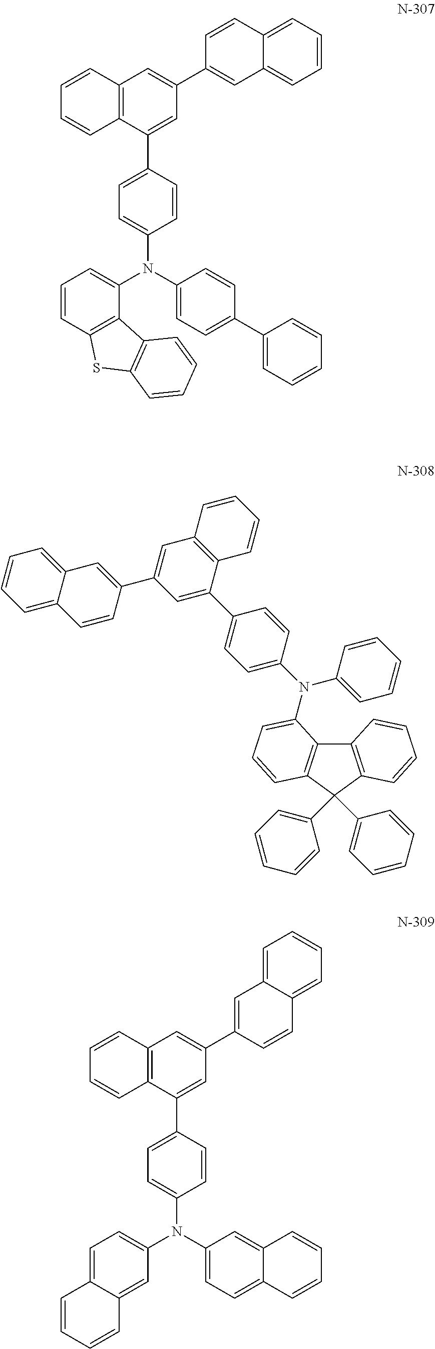 [SMILES: c1ccc(-c2ccc(N(c3ccc(-c4cc(-c5ccc6ccccc6c5)cc5ccccc45)cc3)c3cccc4sc5ccccc5c34)cc2)cc1 ; c1ccc(N(c2ccc(-c3cc(-c4ccc5ccccc5c4)cc4ccccc34)cc2)c2cccc3c2-c2ccccc2C3(c2ccccc2)c2ccccc2)cc1 ; c1ccc2cc(-c3cc(-c4ccc(N(c5ccc6ccccc6c5)c5ccc6ccccc6c5)cc4)c4ccccc4c3)ccc2c1]

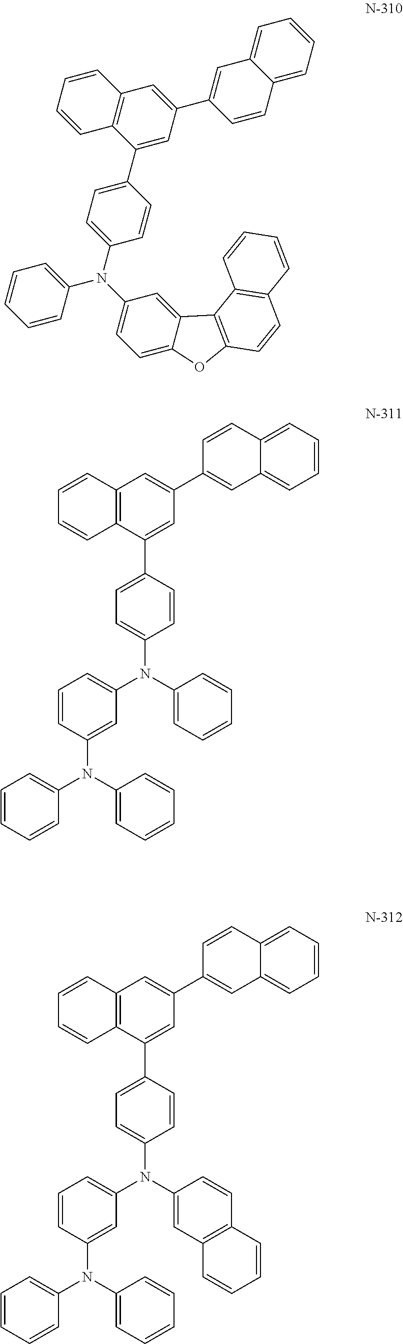 [SMILES: c1ccc(N(c2ccc(-c3cc(-c4ccc5ccccc5c4)cc4ccccc34)cc2)c2ccc3oc4ccc5ccccc5c4c3c2)cc1 ; c1ccc(N(c2ccccc2)c2cccc(N(c3ccccc3)c3ccc(-c4cc(-c5ccc6ccccc6c5)cc5ccccc45)cc3)c2)cc1 ; c1ccc(N(c2ccccc2)c2cccc(N(c3ccc(-c4cc(-c5ccc6ccccc6c5)cc5ccccc45)cc3)c3ccc4ccccc4c3)c2)cc1]

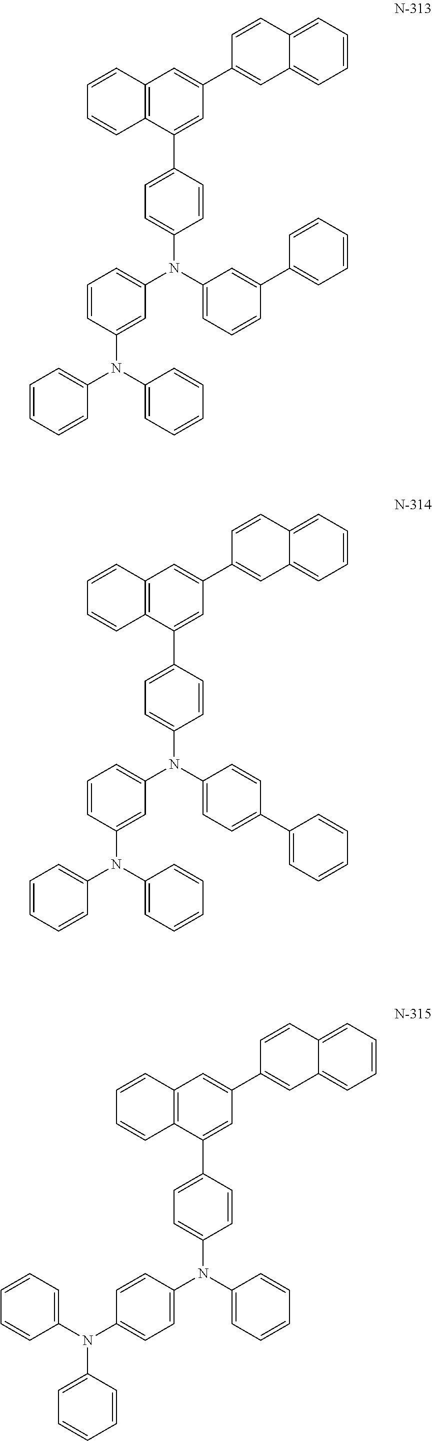 [SMILES: c1ccc(-c2cccc(N(c3ccc(-c4cc(-c5ccc6ccccc6c5)cc5ccccc45)cc3)c3cccc(N(c4ccccc4)c4ccccc4)c3)c2)cc1 ; c1ccc(-c2ccc(N(c3ccc(-c4cc(-c5ccc6ccccc6c5)cc5ccccc45)cc3)c3cccc(N(c4ccccc4)c4ccccc4)c3)cc2)cc1 ; c1ccc(N(c2ccccc2)c2ccc(N(c3ccccc3)c3ccc(-c4cc(-c5ccc6ccccc6c5)cc5ccccc45)cc3)cc2)cc1]

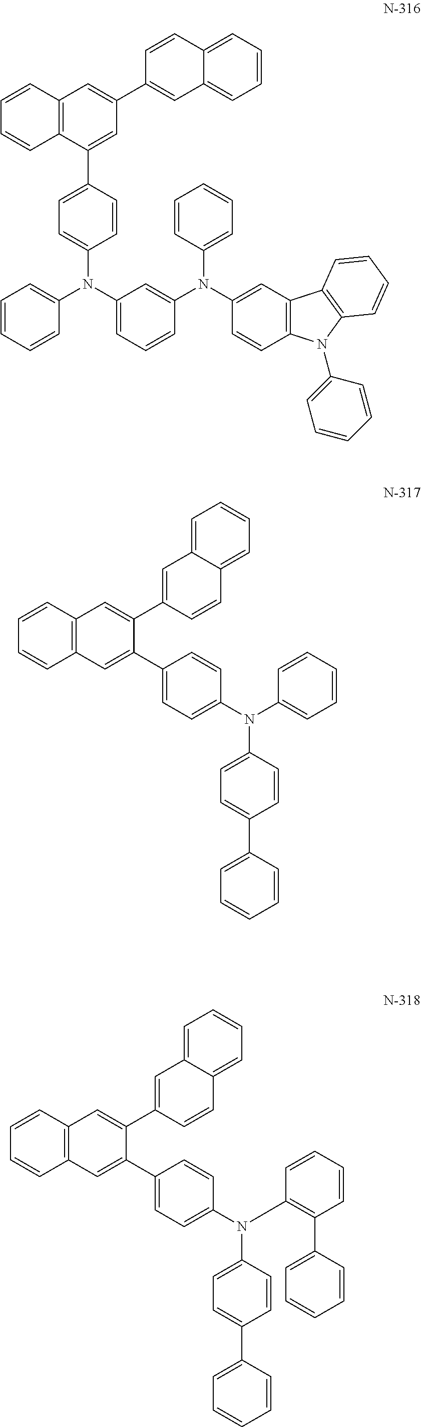 [SMILES: c1ccc(N(c2ccc(-c3cc(-c4ccc5ccccc5c4)cc4ccccc34)cc2)c2cccc(N(c3ccccc3)c3ccc4c(c3)c3ccccc3n4-c3ccccc3)c2)cc1 ; c1ccc(-c2ccc(N(c3ccccc3)c3ccc(-c4cc5ccccc5cc4-c4ccc5ccccc5c4)cc3)cc2)cc1 ; c1ccc(-c2ccc(N(c3ccc(-c4cc5ccccc5cc4-c4ccc5ccccc5c4)cc3)c3ccccc3-c3ccccc3)cc2)cc1]

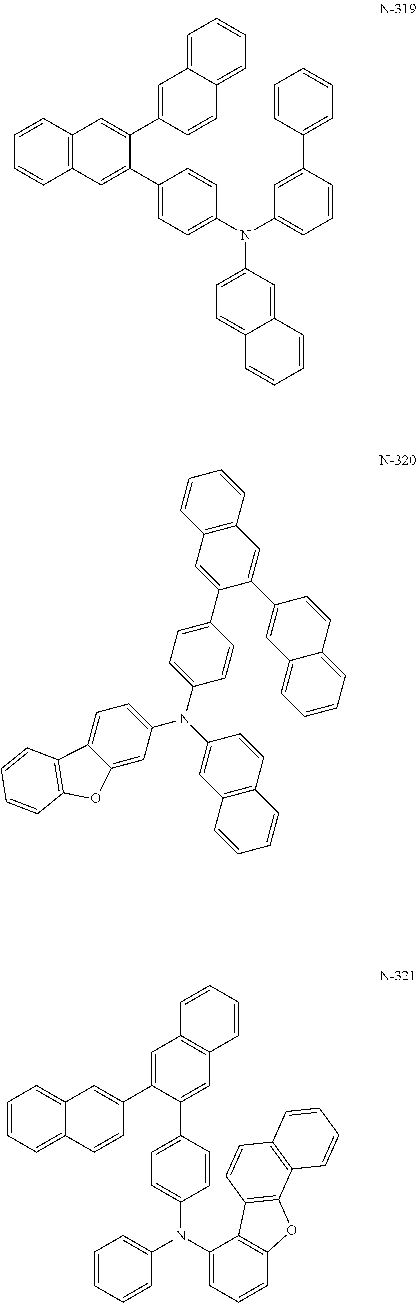 [SMILES: c1ccc(-c2cccc(N(c3ccc(-c4cc5ccccc5cc4-c4ccc5ccccc5c4)cc3)c3ccc4ccccc4c3)c2)cc1 ; c1ccc2cc(-c3cc4ccccc4cc3-c3ccc(N(c4ccc5ccccc5c4)c4ccc5c(c4)oc4ccccc45)cc3)ccc2c1 ; c1ccc(N(c2ccc(-c3cc4ccccc4cc3-c3ccc4ccccc4c3)cc2)c2cccc3oc4c5ccccc5ccc4c23)cc1]

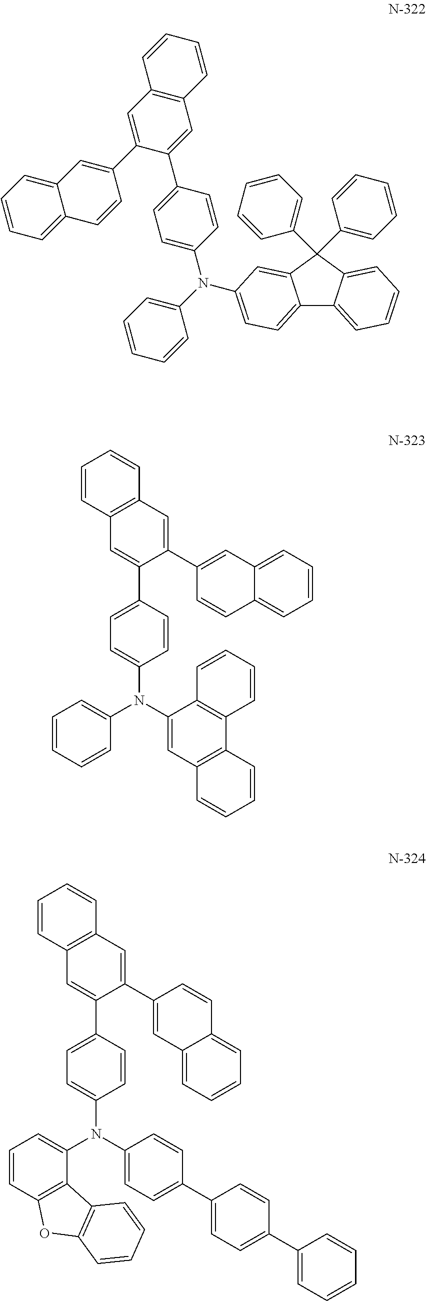 [SMILES: c1ccc(N(c2ccc(-c3cc4ccccc4cc3-c3ccc4ccccc4c3)cc2)c2ccc3c(c2)C(c2ccccc2)(c2ccccc2)c2ccccc2-3)cc1 ; c1ccc(N(c2ccc(-c3cc4ccccc4cc3-c3ccc4ccccc4c3)cc2)c2cc3ccccc3c3ccccc23)cc1 ; c1ccc(-c2ccc(-c3ccc(N(c4ccc(-c5cc6ccccc6cc5-c5ccc6ccccc6c5)cc4)c4cccc5oc6ccccc6c45)cc3)cc2)cc1]

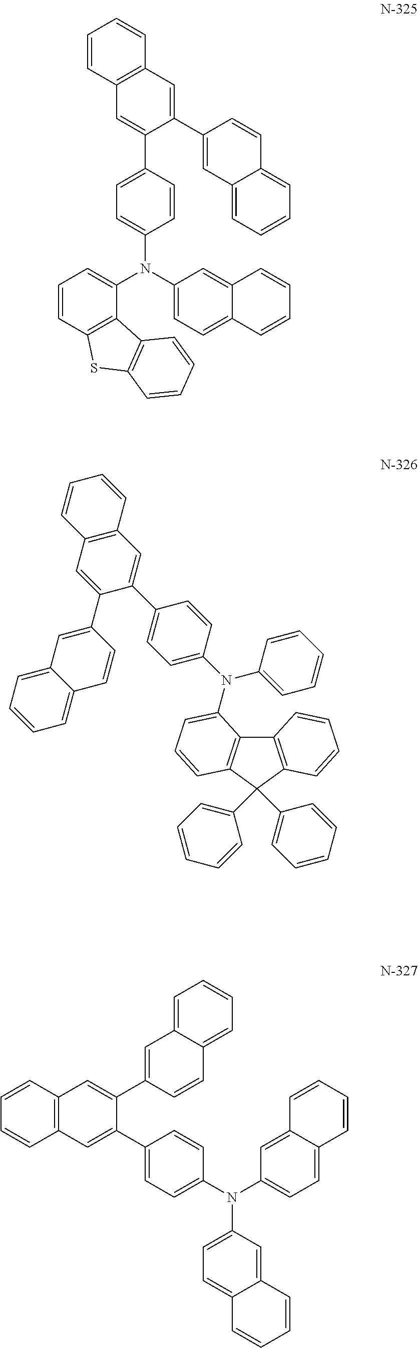 [SMILES: c1ccc2cc(-c3cc4ccccc4cc3-c3ccc(N(c4ccc5ccccc5c4)c4cccc5sc6ccccc6c45)cc3)ccc2c1 ; c1ccc(N(c2ccc(-c3cc4ccccc4cc3-c3ccc4ccccc4c3)cc2)c2cccc3c2-c2ccccc2C3(c2ccccc2)c2ccccc2)cc1 ; c1ccc2cc(-c3cc4ccccc4cc3-c3ccc(N(c4ccc5ccccc5c4)c4ccc5ccccc5c4)cc3)ccc2c1]

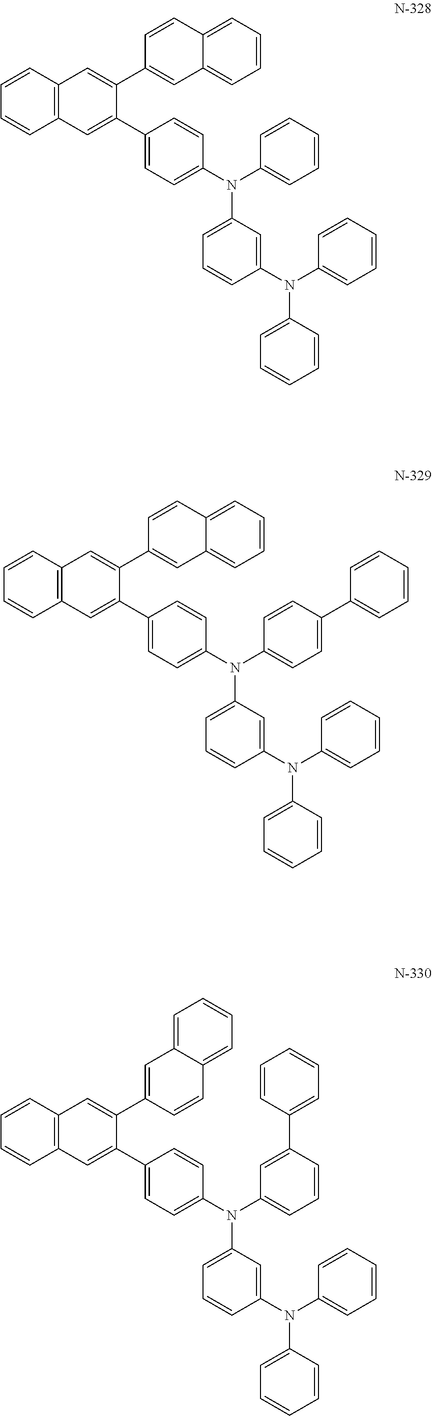 [SMILES: c1ccc(N(c2ccccc2)c2cccc(N(c3ccccc3)c3ccc(-c4cc5ccccc5cc4-c4ccc5ccccc5c4)cc3)c2)cc1 ; c1ccc(-c2ccc(N(c3ccc(-c4cc5ccccc5cc4-c4ccc5ccccc5c4)cc3)c3cccc(N(c4ccccc4)c4ccccc4)c3)cc2)cc1 ; c1ccc(-c2cccc(N(c3ccc(-c4cc5ccccc5cc4-c4ccc5ccccc5c4)cc3)c3cccc(N(c4ccccc4)c4ccccc4)c3)c2)cc1]

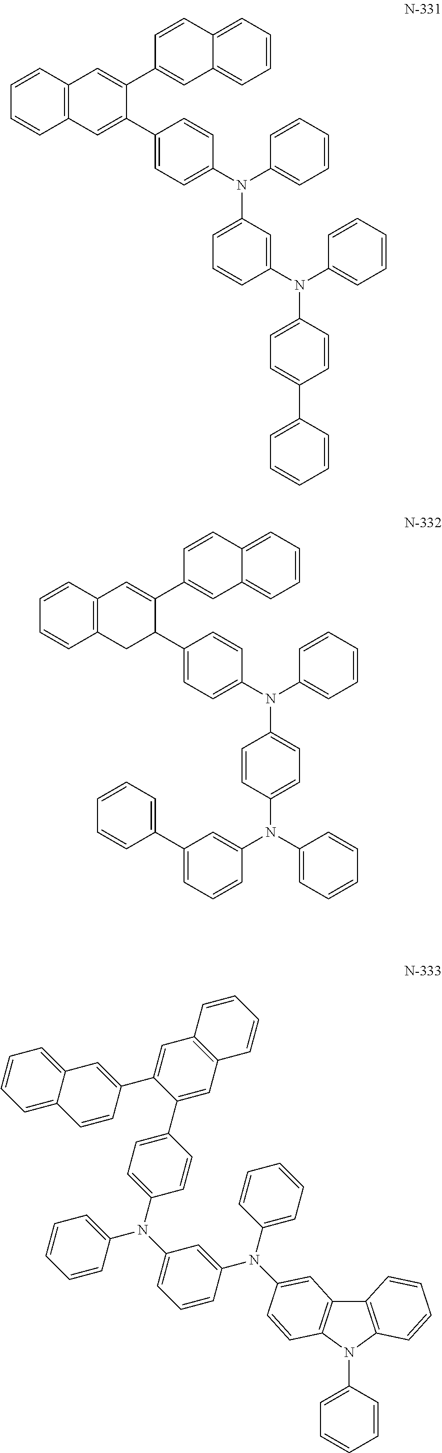 [SMILES: c1ccc(-c2ccc(N(c3ccccc3)c3cccc(N(c4ccccc4)c4ccc(-c5cc6ccccc6cc5-c5ccc6ccccc6c5)cc4)c3)cc2)cc1 ; C1=C(c2ccc3ccccc3c2)C(c2ccc(N(c3ccccc3)c3ccc(N(c4ccccc4)c4cccc(-c5ccccc5)c4)cc3)cc2)Cc2ccccc21 ; c1ccc(N(c2ccc(-c3cc4ccccc4cc3-c3ccc4ccccc4c3)cc2)c2cccc(N(c3ccccc3)c3ccc4c(c3)c3ccccc3n4-c3ccccc3)c2)cc1]

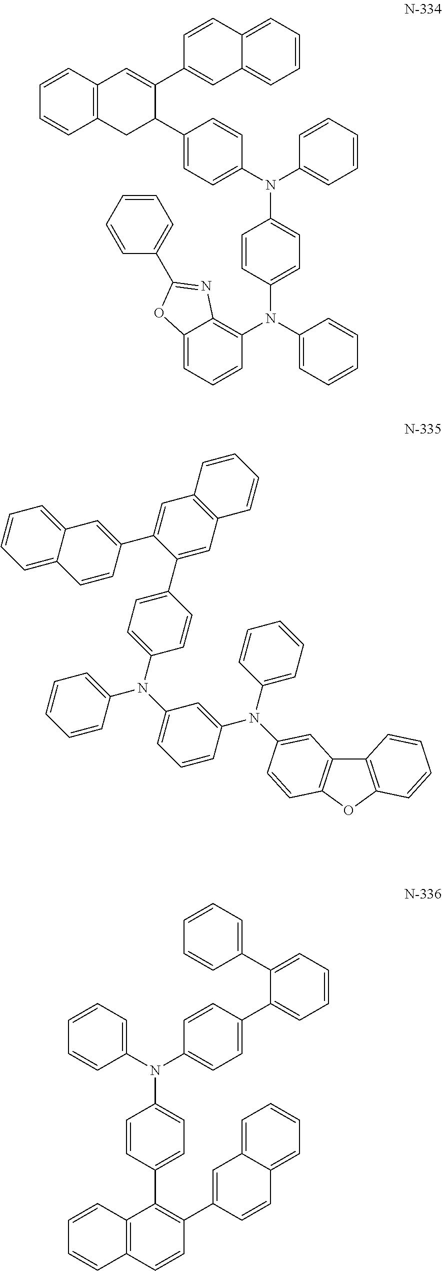 [SMILES: C1=C(c2ccc3ccccc3c2)C(c2ccc(N(c3ccccc3)c3ccc(N(c4ccccc4)c4cccc5oc(-c6ccccc6)nc45)cc3)cc2)Cc2ccccc21 ; c1ccc(N(c2ccc(-c3cc4ccccc4cc3-c3ccc4ccccc4c3)cc2)c2cccc(N(c3ccccc3)c3ccc4oc5ccccc5c4c3)c2)cc1 ; c1ccc(-c2ccccc2-c2ccc(N(c3ccccc3)c3ccc(-c4c(-c5ccc6ccccc6c5)ccc5ccccc45)cc3)cc2)cc1]

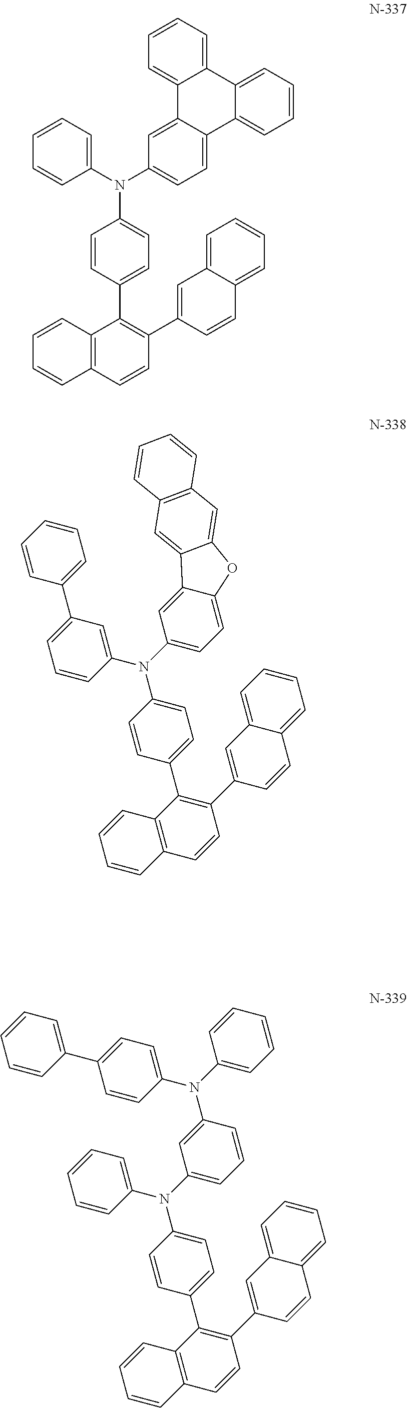 [SMILES: c1ccc(N(c2ccc(-c3c(-c4ccc5ccccc5c4)ccc4ccccc34)cc2)c2ccc3c4ccccc4c4ccccc4c3c2)cc1 ; c1ccc(-c2cccc(N(c3ccc(-c4c(-c5ccc6ccccc6c5)ccc5ccccc45)cc3)c3ccc4oc5cc6ccccc6cc5c4c3)c2)cc1 ; c1ccc(-c2ccc(N(c3ccccc3)c3cccc(N(c4ccccc4)c4ccc(-c5c(-c6ccc7ccccc7c6)ccc6ccccc56)cc4)c3)cc2)cc1]

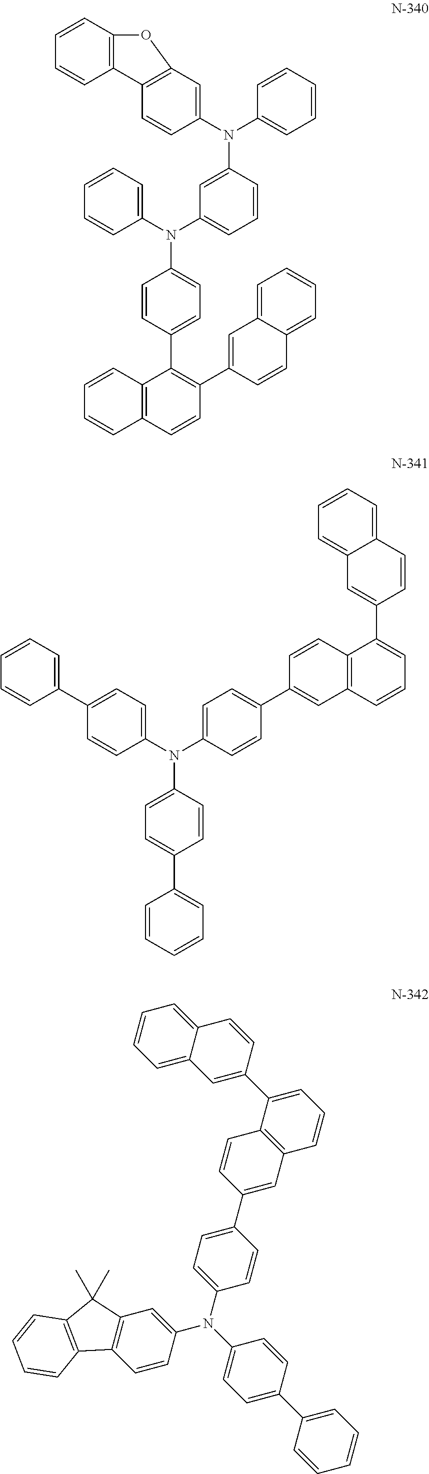 [SMILES: c1ccc(N(c2ccc(-c3c(-c4ccc5ccccc5c4)ccc4ccccc34)cc2)c2cccc(N(c3ccccc3)c3ccc4c(c3)oc3ccccc34)c2)cc1 ; c1ccc(-c2ccc(N(c3ccc(-c4ccccc4)cc3)c3ccc(-c4ccc5c(-c6ccc7ccccc7c6)cccc5c4)cc3)cc2)cc1 ; CC1(C)c2ccccc2-c2ccc(N(c3ccc(-c4ccccc4)cc3)c3ccc(-c4ccc5c(-c6ccc7ccccc7c6)cccc5c4)cc3)cc21]

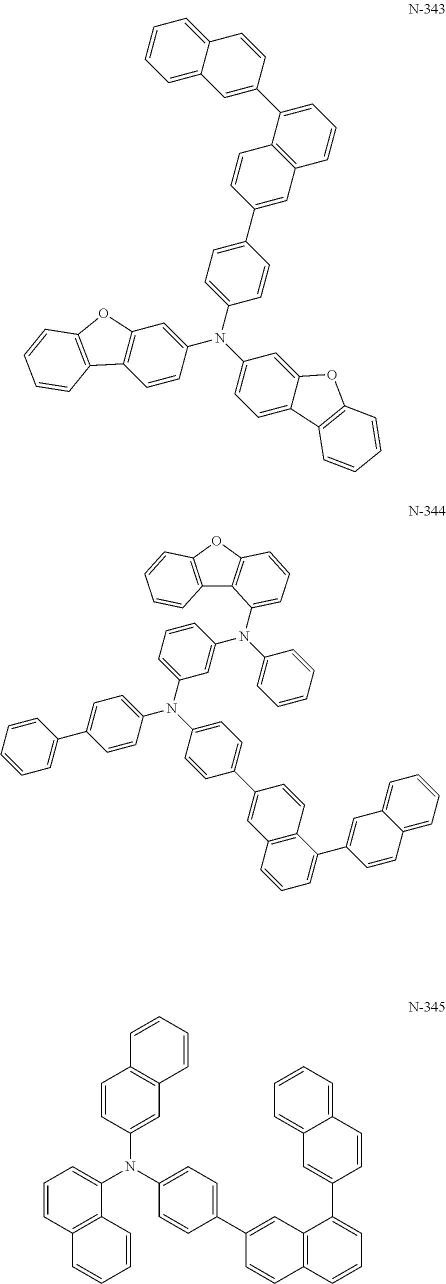 [SMILES: c1ccc2cc(-c3cccc4cc(-c5ccc(N(c6ccc7c(c6)oc6ccccc67)c6ccc7c(c6)oc6ccccc67)cc5)ccc34)ccc2c1 ; c1ccc(-c2ccc(N(c3ccc(-c4ccc5c(-c6ccc7ccccc7c6)cccc5c4)cc3)c3cccc(N(c4ccccc4)c4cccc5oc6ccccc6c45)c3)cc2)cc1 ; c1ccc2cc(-c3cccc4ccc(-c5ccc(N(c6ccc7ccccc7c6)c6cccc7ccccc67)cc5)cc34)ccc2c1]

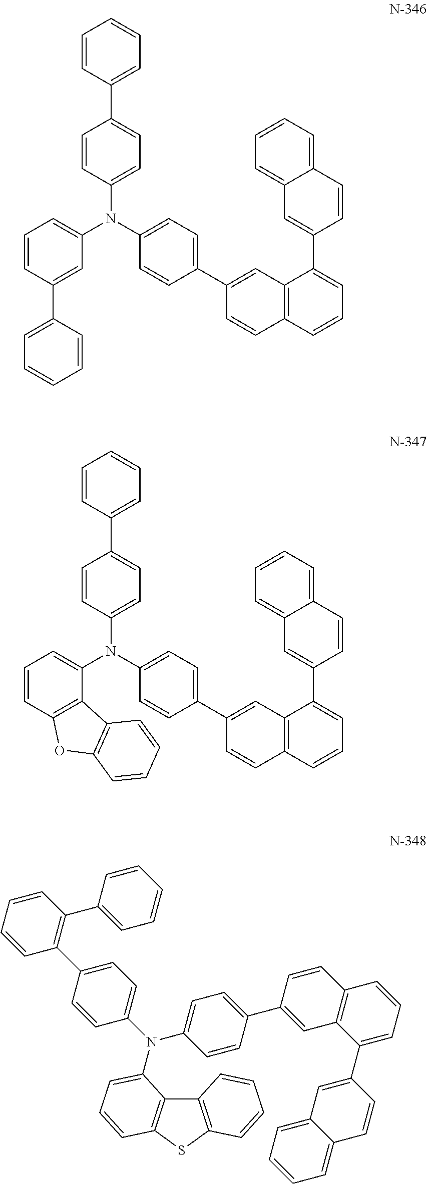 [SMILES: c1ccc(-c2ccc(N(c3ccc(-c4ccc5cccc(-c6ccc7ccccc7c6)c5c4)cc3)c3cccc(-c4ccccc4)c3)cc2)cc1 ; c1ccc(-c2ccc(N(c3ccc(-c4ccc5cccc(-c6ccc7ccccc7c6)c5c4)cc3)c3cccc4oc5ccccc5c34)cc2)cc1 ; c1ccc(-c2ccccc2-c2ccc(N(c3ccc(-c4ccc5cccc(-c6ccc7ccccc7c6)c5c4)cc3)c3cccc4sc5ccccc5c34)cc2)cc1]

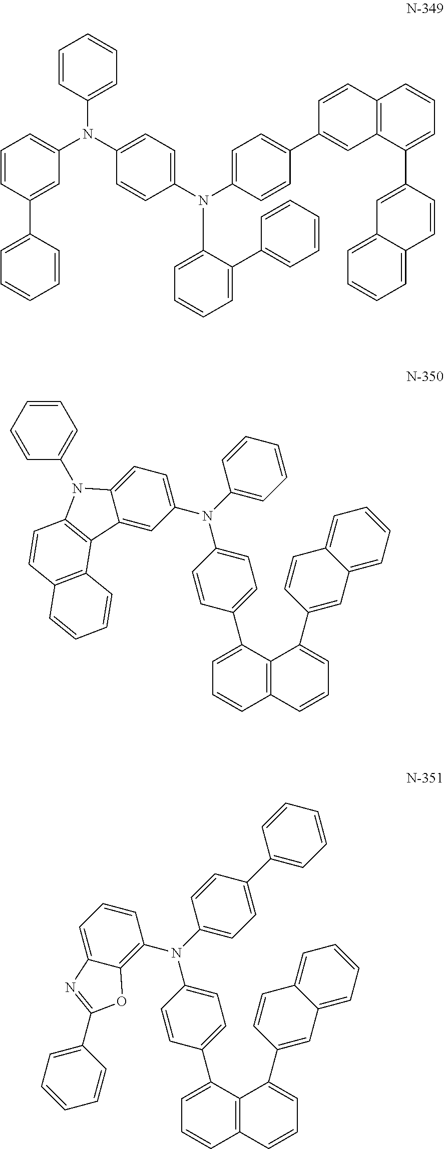 [SMILES: c1ccc(-c2cccc(N(c3ccccc3)c3ccc(N(c4ccc(-c5ccc6cccc(-c7ccc8ccccc8c7)c6c5)cc4)c4ccccc4-c4ccccc4)cc3)c2)cc1 ; c1ccc(N(c2ccc(-c3cccc4cccc(-c5ccc6ccccc6c5)c34)cc2)c2ccc3c(c2)c2c4ccccc4ccc2n3-c2ccccc2)cc1 ; c1ccc(-c2ccc(N(c3ccc(-c4cccc5cccc(-c6ccc7ccccc7c6)c45)cc3)c3cccc4nc(-c5ccccc5)oc34)cc2)cc1]

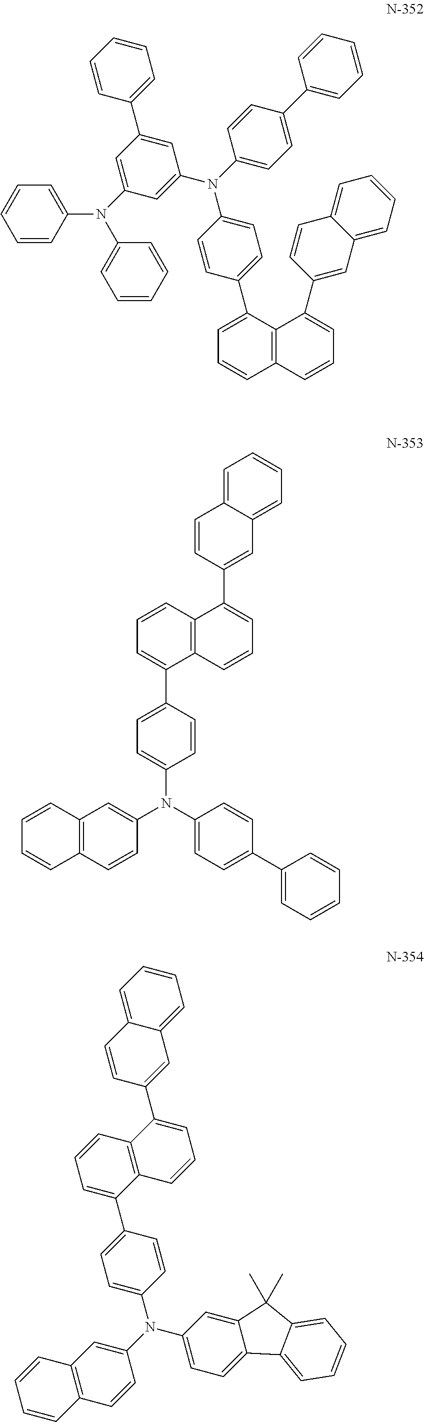 [SMILES: c1ccc(-c2ccc(N(c3ccc(-c4cccc5cccc(-c6ccc7ccccc7c6)c45)cc3)c3cc(-c4ccccc4)cc(N(c4ccccc4)c4ccccc4)c3)cc2)cc1 ; c1ccc(-c2ccc(N(c3ccc(-c4cccc5c(-c6ccc7ccccc7c6)cccc45)cc3)c3ccc4ccccc4c3)cc2)cc1 ; CC1(C)c2ccccc2-c2ccc(N(c3ccc(-c4cccc5c(-c6ccc7ccccc7c6)cccc45)cc3)c3ccc4ccccc4c3)cc21]

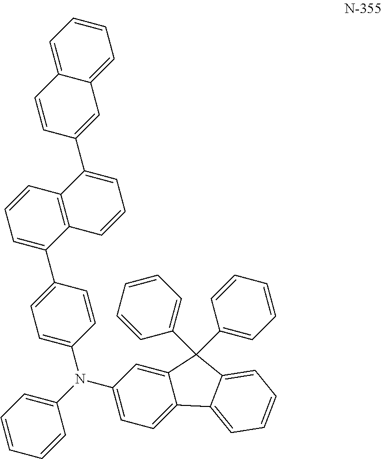 [SMILES: c1ccc(N(c2ccc(-c3cccc4c(-c5ccc6ccccc6c5)cccc34)cc2)c2ccc3c(c2)C(c2ccccc2)(c2ccccc2)c2ccccc2-3)cc1]

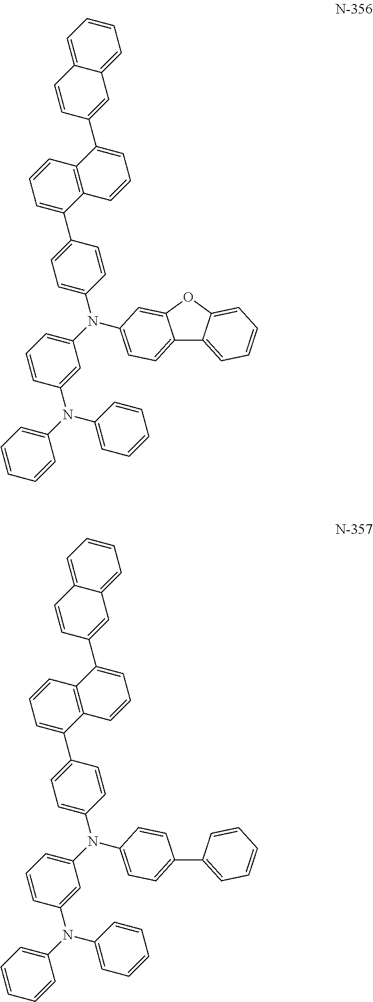 [SMILES: c1ccc(N(c2ccccc2)c2cccc(N(c3ccc(-c4cccc5c(-c6ccc7ccccc7c6)cccc45)cc3)c3ccc4c(c3)oc3ccccc34)c2)cc1 ; c1ccc(-c2ccc(N(c3ccc(-c4cccc5c(-c6ccc7ccccc7c6)cccc45)cc3)c3cccc(N(c4ccccc4)c4ccccc4)c3)cc2)cc1]

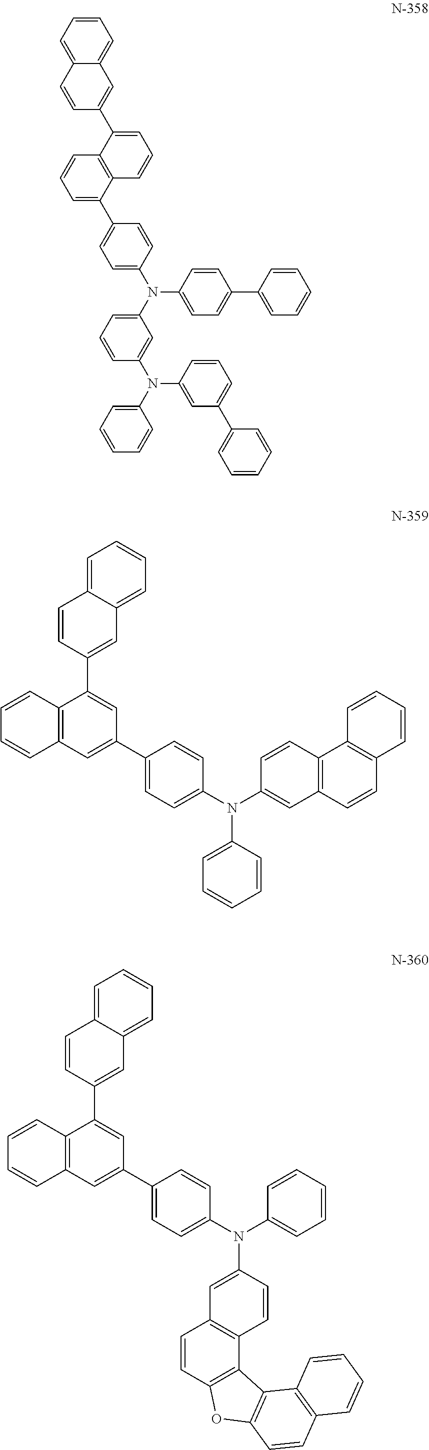 [SMILES: c1ccc(-c2ccc(N(c3ccc(-c4cccc5c(-c6ccc7ccccc7c6)cccc45)cc3)c3cccc(N(c4ccccc4)c4cccc(-c5ccccc5)c4)c3)cc2)cc1 ; c1ccc(N(c2ccc(-c3cc(-c4ccc5ccccc5c4)c4ccccc4c3)cc2)c2ccc3c(ccc4ccccc43)c2)cc1 ; c1ccc(N(c2ccc(-c3cc(-c4ccc5ccccc5c4)c4ccccc4c3)cc2)c2ccc3c(ccc4oc5ccc6ccccc6c5c43)c2)cc1]

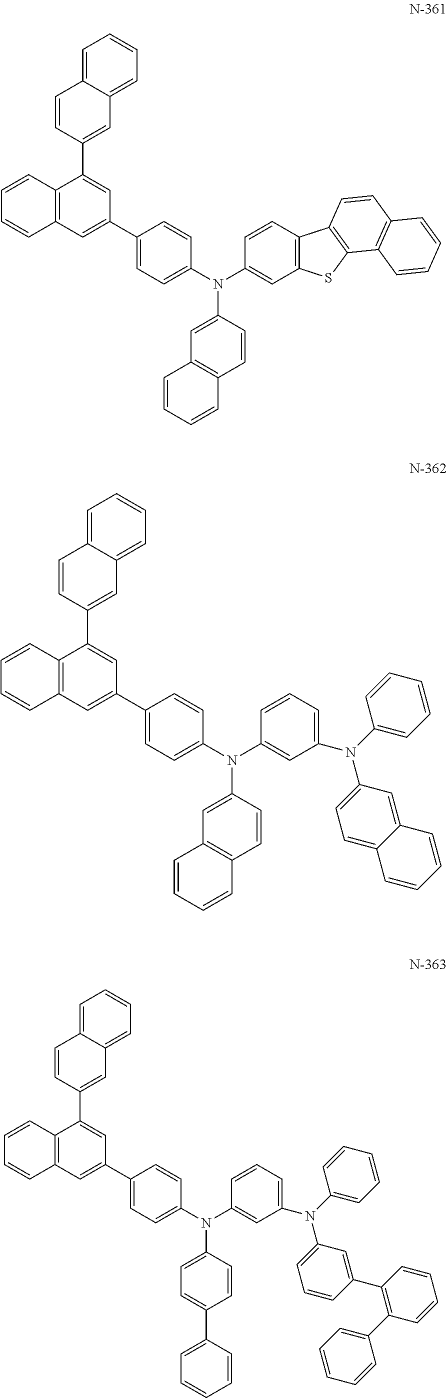 [SMILES: c1ccc2cc(-c3cc(-c4ccc(N(c5ccc6ccccc6c5)c5ccc6c(c5)sc5c7ccccc7ccc65)cc4)cc4ccccc34)ccc2c1 ; c1ccc(N(c2cccc(N(c3ccc(-c4cc(-c5ccc6ccccc6c5)c5ccccc5c4)cc3)c3ccc4ccccc4c3)c2)c2ccc3ccccc3c2)cc1 ; c1ccc(-c2ccc(N(c3ccc(-c4cc(-c5ccc6ccccc6c5)c5ccccc5c4)cc3)c3cccc(N(c4ccccc4)c4cccc(-c5ccccc5-c5ccccc5)c4)c3)cc2)cc1]

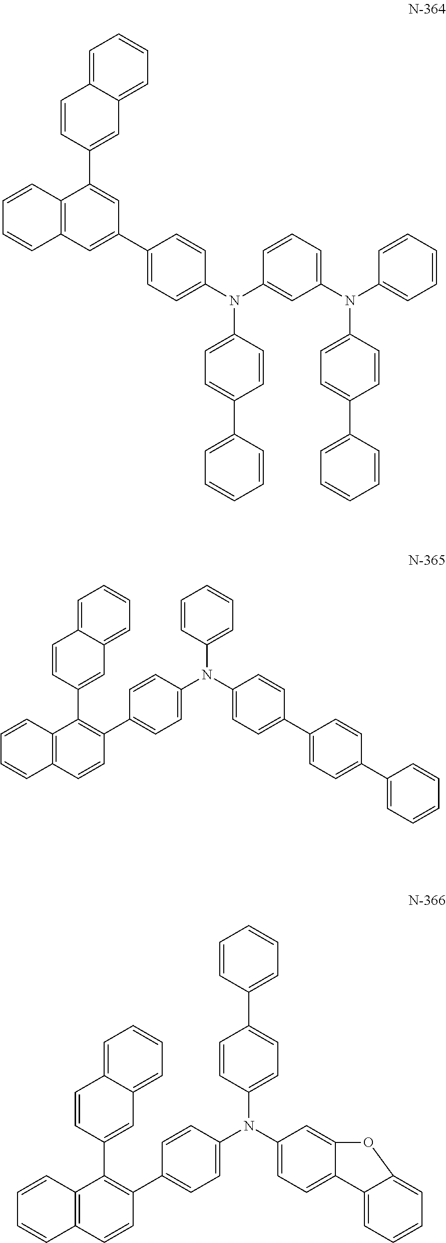 [SMILES: c1ccc(-c2ccc(N(c3ccccc3)c3cccc(N(c4ccc(-c5ccccc5)cc4)c4ccc(-c5cc(-c6ccc7ccccc7c6)c6ccccc6c5)cc4)c3)cc2)cc1 ; c1ccc(-c2ccc(-c3ccc(N(c4ccccc4)c4ccc(-c5ccc6ccccc6c5-c5ccc6ccccc6c5)cc4)cc3)cc2)cc1 ; c1ccc(-c2ccc(N(c3ccc(-c4ccc5ccccc5c4-c4ccc5ccccc5c4)cc3)c3ccc4c(c3)oc3ccccc34)cc2)cc1]

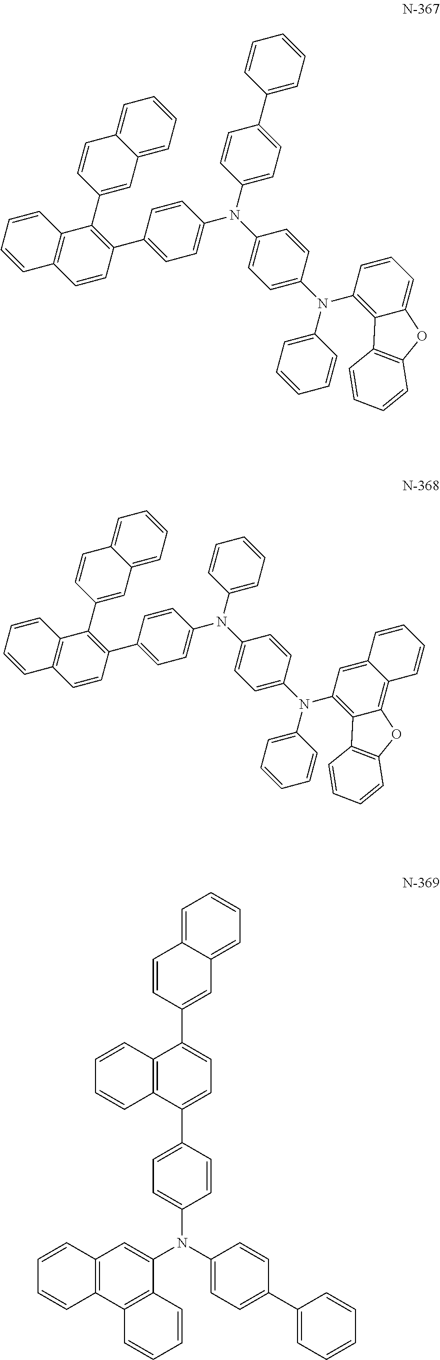 [SMILES: c1ccc(-c2ccc(N(c3ccc(-c4ccc5ccccc5c4-c4ccc5ccccc5c4)cc3)c3ccc(N(c4ccccc4)c4cccc5oc6ccccc6c45)cc3)cc2)cc1 ; c1ccc(N(c2ccc(-c3ccc4ccccc4c3-c3ccc4ccccc4c3)cc2)c2ccc(N(c3ccccc3)c3cc4ccccc4c4oc5ccccc5c34)cc2)cc1 ; c1ccc(-c2ccc(N(c3ccc(-c4ccc(-c5ccc6ccccc6c5)c5ccccc45)cc3)c3cc4ccccc4c4ccccc34)cc2)cc1]

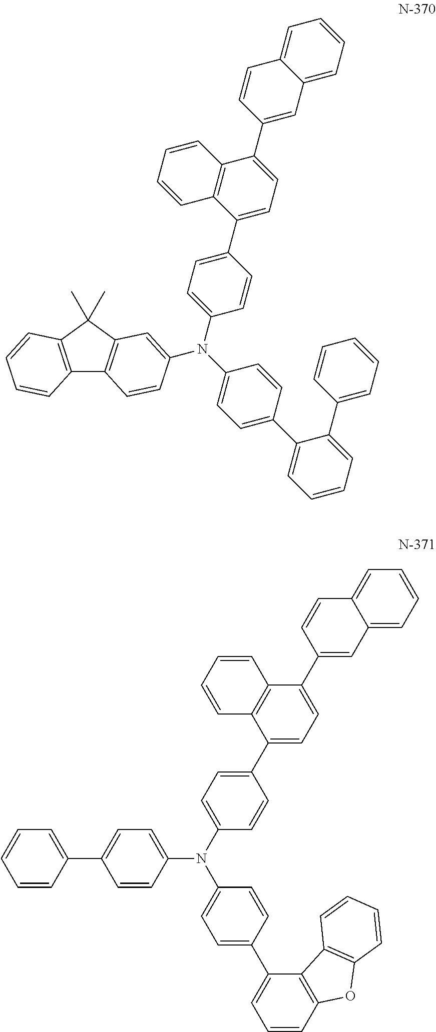 [SMILES: CC1(C)c2ccccc2-c2ccc(N(c3ccc(-c4ccccc4-c4ccccc4)cc3)c3ccc(-c4ccc(-c5ccc6ccccc6c5)c5ccccc45)cc3)cc21 ; c1ccc(-c2ccc(N(c3ccc(-c4ccc(-c5ccc6ccccc6c5)c5ccccc45)cc3)c3ccc(-c4cccc5oc6ccccc6c45)cc3)cc2)cc1]

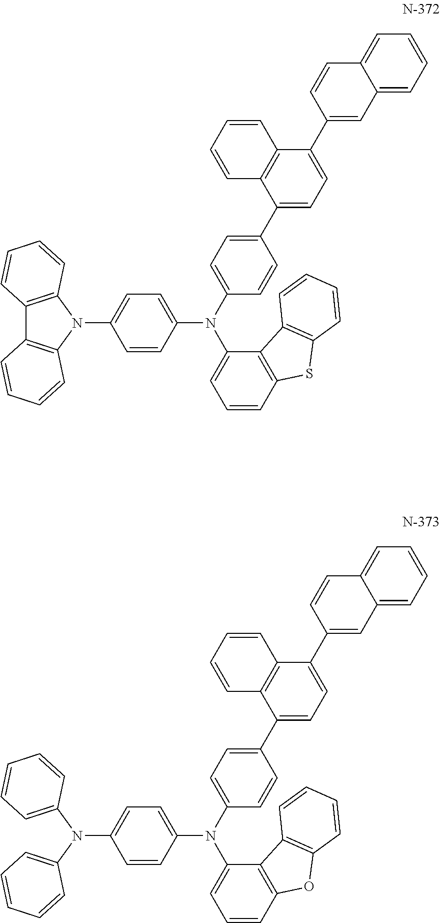 [SMILES: c1ccc2cc(-c3ccc(-c4ccc(N(c5ccc(-n6c7ccccc7c7ccccc76)cc5)c5cccc6sc7ccccc7c56)cc4)c4ccccc34)ccc2c1 ; c1ccc(N(c2ccccc2)c2ccc(N(c3ccc(-c4ccc(-c5ccc6ccccc6c5)c5ccccc45)cc3)c3cccc4oc5ccccc5c34)cc2)cc1]

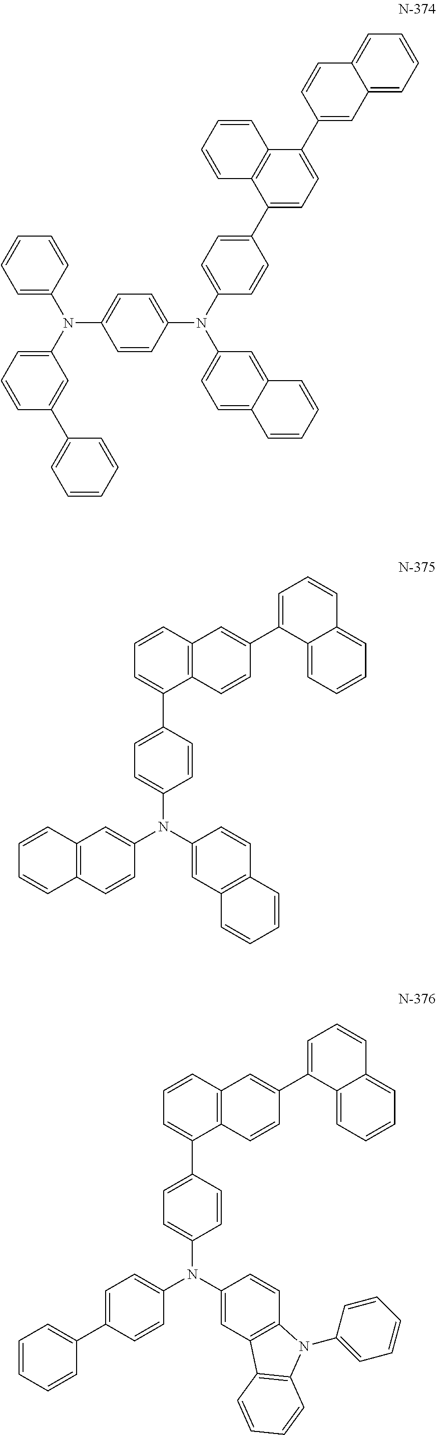 [SMILES: c1ccc(-c2cccc(N(c3ccccc3)c3ccc(N(c4ccc(-c5ccc(-c6ccc7ccccc7c6)c6ccccc56)cc4)c4ccc5ccccc5c4)cc3)c2)cc1 ; c1ccc2cc(N(c3ccc(-c4cccc5cc(-c6cccc7ccccc67)ccc45)cc3)c3ccc4ccccc4c3)ccc2c1 ; c1ccc(-c2ccc(N(c3ccc(-c4cccc5cc(-c6cccc7ccccc67)ccc45)cc3)c3ccc4c(c3)c3ccccc3n4-c3ccccc3)cc2)cc1]

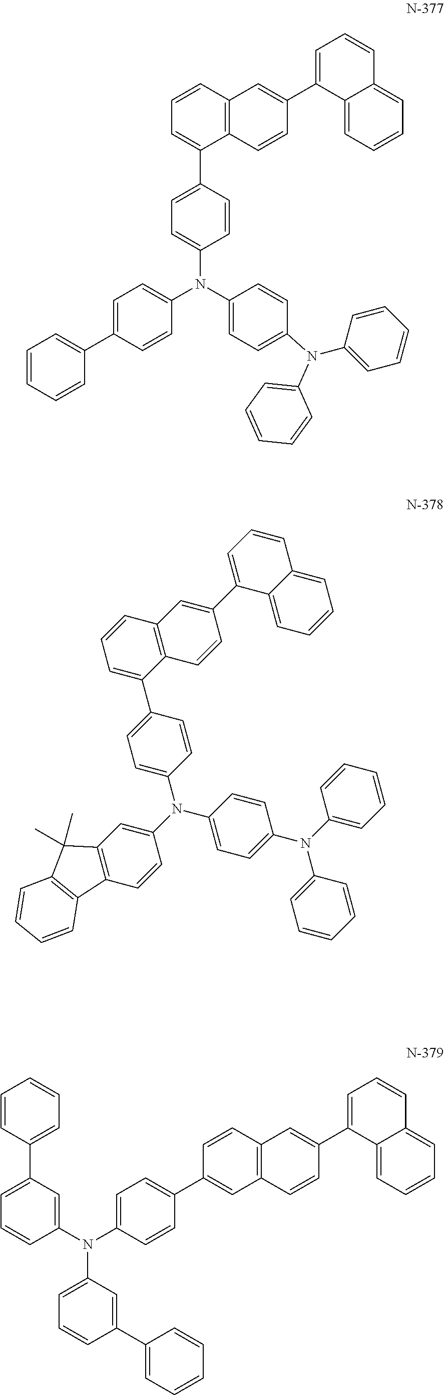 [SMILES: c1ccc(-c2ccc(N(c3ccc(-c4cccc5cc(-c6cccc7ccccc67)ccc45)cc3)c3ccc(N(c4ccccc4)c4ccccc4)cc3)cc2)cc1 ; CC1(C)c2ccccc2-c2ccc(N(c3ccc(-c4cccc5cc(-c6cccc7ccccc67)ccc45)cc3)c3ccc(N(c4ccccc4)c4ccccc4)cc3)cc21 ; c1ccc(-c2cccc(N(c3ccc(-c4ccc5cc(-c6cccc7ccccc67)ccc5c4)cc3)c3cccc(-c4ccccc4)c3)c2)cc1]

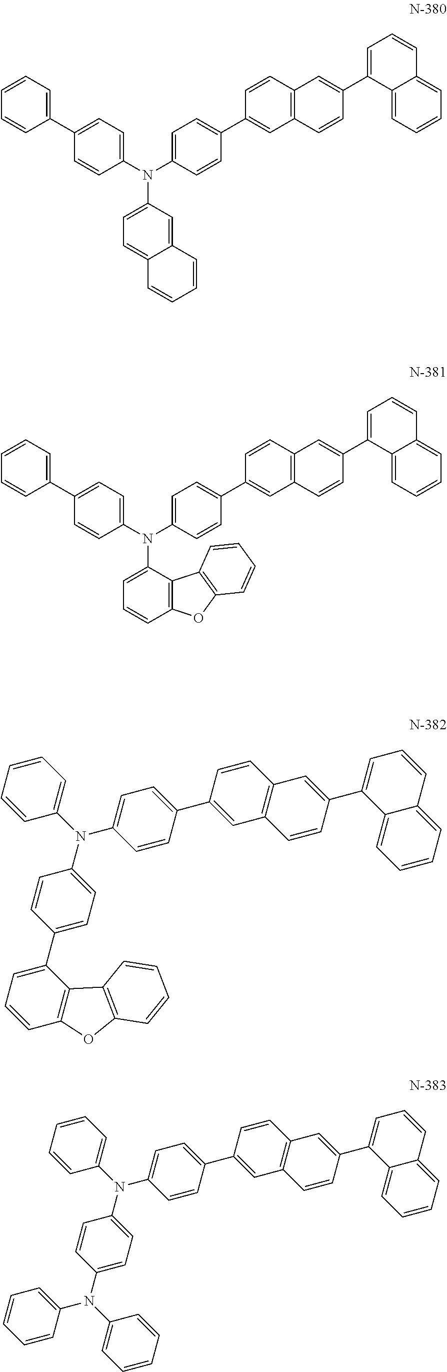 [SMILES: c1ccc(-c2ccc(N(c3ccc(-c4ccc5cc(-c6cccc7ccccc67)ccc5c4)cc3)c3ccc4ccccc4c3)cc2)cc1 ; c1ccc(-c2ccc(N(c3ccc(-c4ccc5cc(-c6cccc7ccccc67)ccc5c4)cc3)c3cccc4oc5ccccc5c34)cc2)cc1 ; c1ccc(N(c2ccc(-c3ccc4cc(-c5cccc6ccccc56)ccc4c3)cc2)c2ccc(-c3cccc4oc5ccccc5c34)cc2)cc1 ; c1ccc(N(c2ccccc2)c2ccc(N(c3ccccc3)c3ccc(-c4ccc5cc(-c6cccc7ccccc67)ccc5c4)cc3)cc2)cc1]

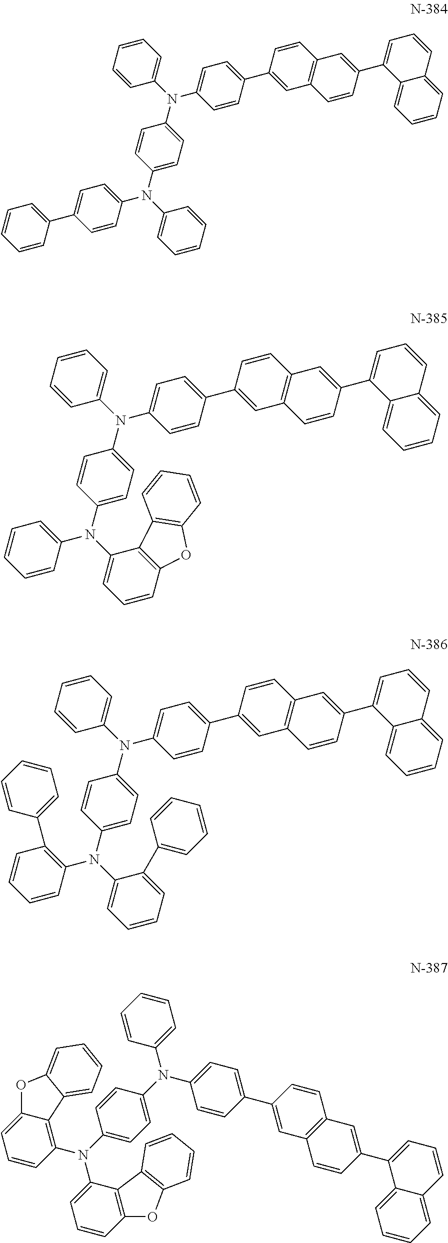 [SMILES: c1ccc(-c2ccc(N(c3ccccc3)c3ccc(N(c4ccccc4)c4ccc(-c5ccc6cc(-c7cccc8ccccc78)ccc6c5)cc4)cc3)cc2)cc1 ; c1ccc(N(c2ccc(-c3ccc4cc(-c5cccc6ccccc56)ccc4c3)cc2)c2ccc(N(c3ccccc3)c3cccc4oc5ccccc5c34)cc2)cc1 ; c1ccc(-c2ccccc2N(c2ccc(N(c3ccccc3)c3ccc(-c4ccc5cc(-c6cccc7ccccc67)ccc5c4)cc3)cc2)c2ccccc2-c2ccccc2)cc1 ; c1ccc(N(c2ccc(-c3ccc4cc(-c5cccc6ccccc56)ccc4c3)cc2)c2ccc(N(c3cccc4oc5ccccc5c34)c3cccc4oc5ccccc5c34)cc2)cc1]

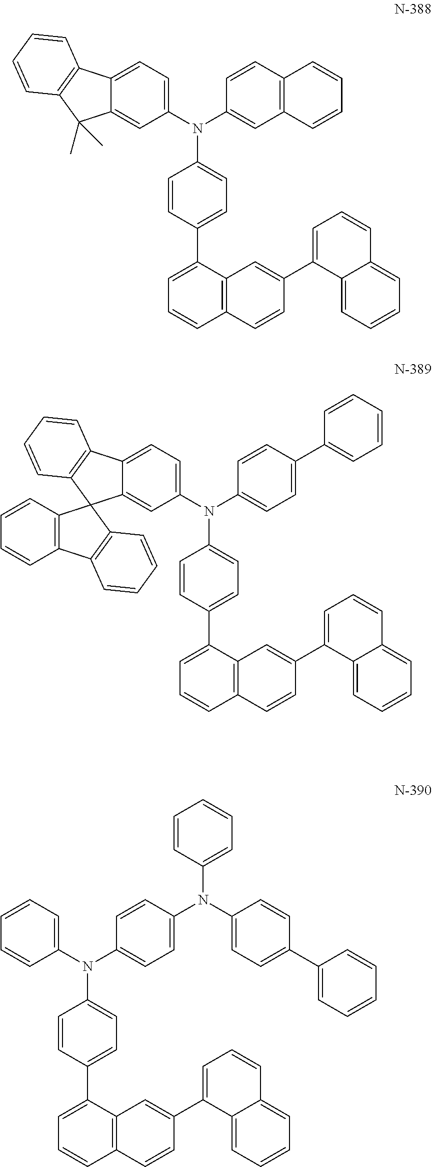 [SMILES: CC1(C)c2ccccc2-c2ccc(N(c3ccc(-c4cccc5ccc(-c6cccc7ccccc67)cc45)cc3)c3ccc4ccccc4c3)cc21 ; c1ccc(-c2ccc(N(c3ccc(-c4cccc5ccc(-c6cccc7ccccc67)cc45)cc3)c3ccc4c(c3)C3(c5ccccc5-c5ccccc53)c3ccccc3-4)cc2)cc1 ; c1ccc(-c2ccc(N(c3ccccc3)c3ccc(N(c4ccccc4)c4ccc(-c5cccc6ccc(-c7cccc8ccccc78)cc56)cc4)cc3)cc2)cc1]

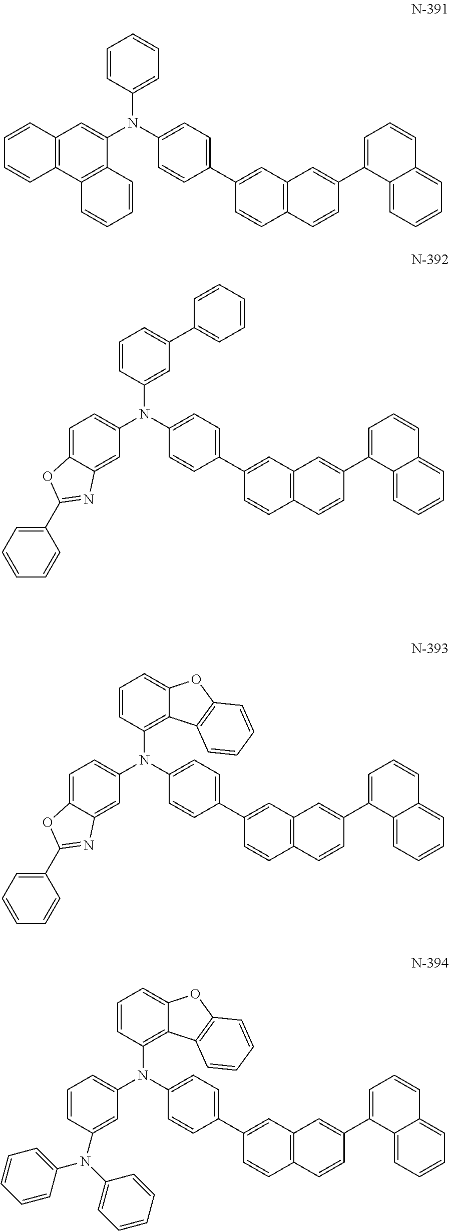 [SMILES: c1ccc(N(c2ccc(-c3ccc4ccc(-c5cccc6ccccc56)cc4c3)cc2)c2cc3ccccc3c3ccccc23)cc1 ; c1ccc(-c2cccc(N(c3ccc(-c4ccc5ccc(-c6cccc7ccccc67)cc5c4)cc3)c3ccc4oc(-c5ccccc5)nc4c3)c2)cc1 ; c1ccc(-c2nc3cc(N(c4ccc(-c5ccc6ccc(-c7cccc8ccccc78)cc6c5)cc4)c4cccc5oc6ccccc6c45)ccc3o2)cc1 ; c1ccc(N(c2ccccc2)c2cccc(N(c3ccc(-c4ccc5ccc(-c6cccc7ccccc67)cc5c4)cc3)c3cccc4oc5ccccc5c34)c2)cc1]

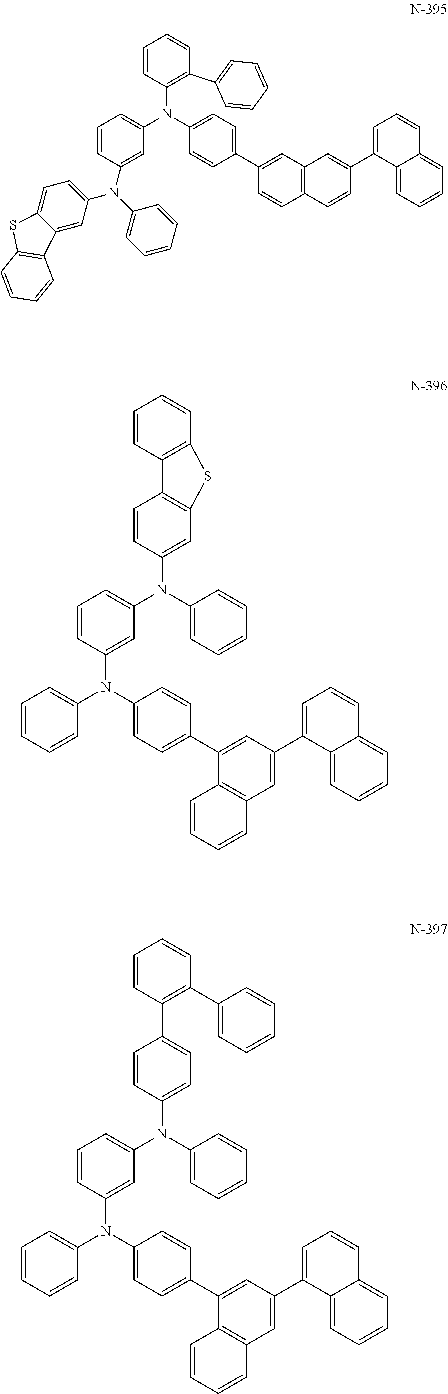 [SMILES: c1ccc(-c2ccccc2N(c2ccc(-c3ccc4ccc(-c5cccc6ccccc56)cc4c3)cc2)c2cccc(N(c3ccccc3)c3ccc4sc5ccccc5c4c3)c2)cc1 ; c1ccc(N(c2ccc(-c3cc(-c4cccc5ccccc45)cc4ccccc34)cc2)c2cccc(N(c3ccccc3)c3ccc4c(c3)sc3ccccc34)c2)cc1 ; c1ccc(-c2ccccc2-c2ccc(N(c3ccccc3)c3cccc(N(c4ccccc4)c4ccc(-c5cc(-c6cccc7ccccc67)cc6ccccc56)cc4)c3)cc2)cc1]

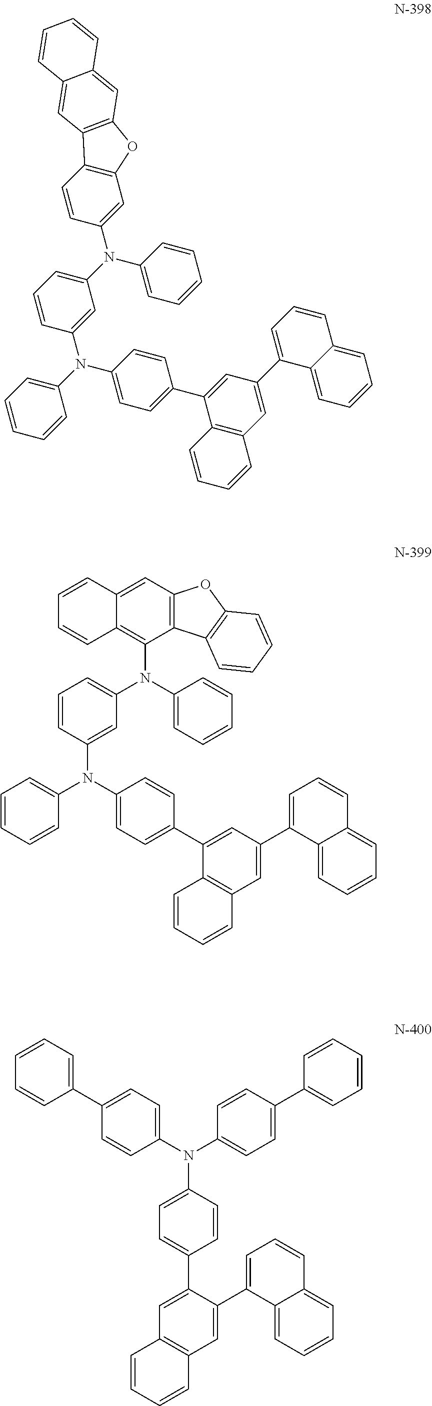 [SMILES: c1ccc(N(c2ccc(-c3cc(-c4cccc5ccccc45)cc4ccccc34)cc2)c2cccc(N(c3ccccc3)c3ccc4c(c3)oc3cc5ccccc5cc34)c2)cc1 ; c1ccc(N(c2ccc(-c3cc(-c4cccc5ccccc45)cc4ccccc34)cc2)c2cccc(N(c3ccccc3)c3c4ccccc4cc4oc5ccccc5c34)c2)cc1 ; c1ccc(-c2ccc(N(c3ccc(-c4ccccc4)cc3)c3ccc(-c4cc5ccccc5cc4-c4cccc5ccccc45)cc3)cc2)cc1]

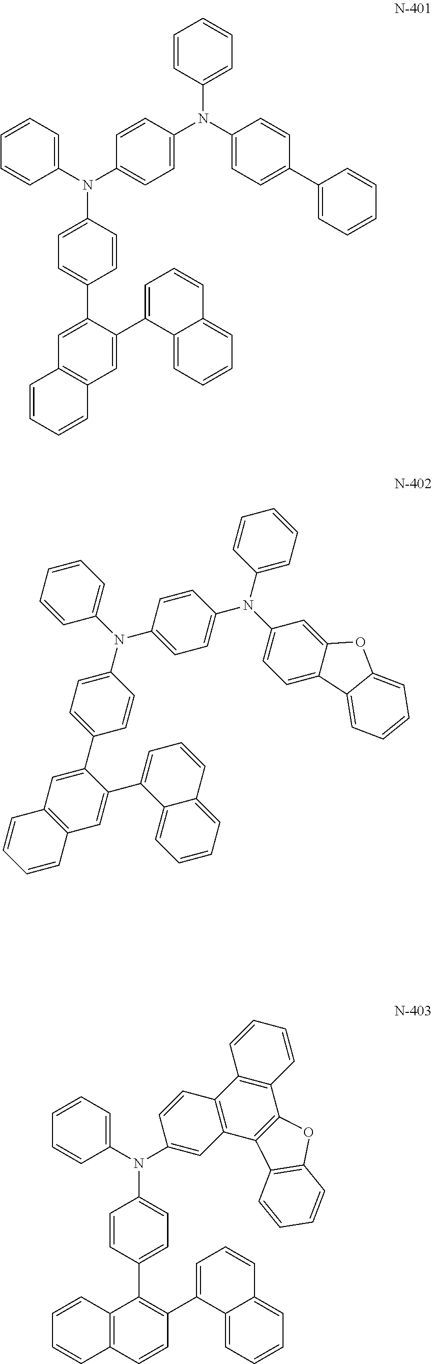 [SMILES: c1ccc(-c2ccc(N(c3ccccc3)c3ccc(N(c4ccccc4)c4ccc(-c5cc6ccccc6cc5-c5cccc6ccccc56)cc4)cc3)cc2)cc1 ; c1ccc(N(c2ccc(-c3cc4ccccc4cc3-c3cccc4ccccc34)cc2)c2ccc(N(c3ccccc3)c3ccc4c(c3)oc3ccccc34)cc2)cc1 ; c1ccc(N(c2ccc(-c3c(-c4cccc5ccccc45)ccc4ccccc34)cc2)c2ccc3c4ccccc4c4oc5ccccc5c4c3c2)cc1]

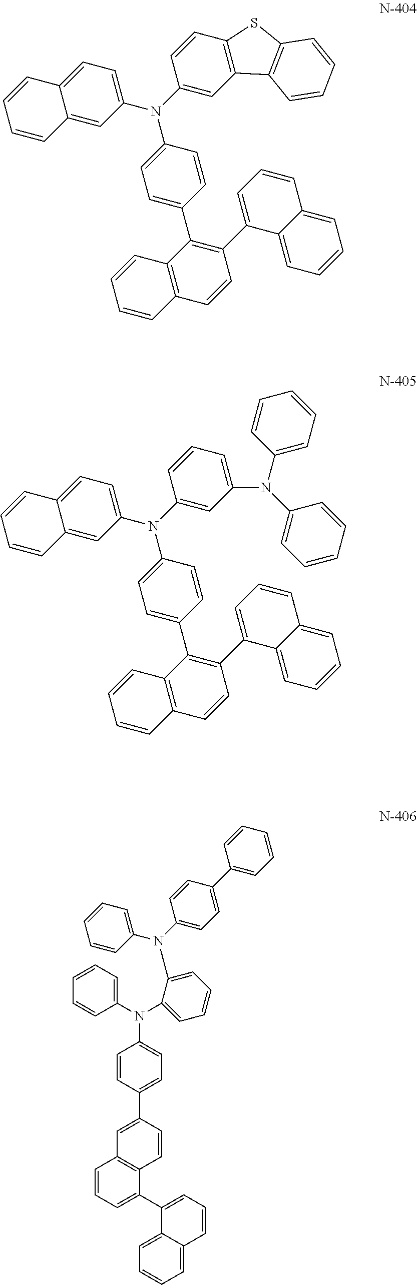 [SMILES: c1ccc2cc(N(c3ccc(-c4c(-c5cccc6ccccc56)ccc5ccccc45)cc3)c3ccc4sc5ccccc5c4c3)ccc2c1 ; c1ccc(N(c2ccccc2)c2cccc(N(c3ccc(-c4c(-c5cccc6ccccc56)ccc5ccccc45)cc3)c3ccc4ccccc4c3)c2)cc1 ; c1ccc(-c2ccc(N(c3ccccc3)c3ccccc3N(c3ccccc3)c3ccc(-c4ccc5c(-c6cccc7ccccc67)cccc5c4)cc3)cc2)cc1]

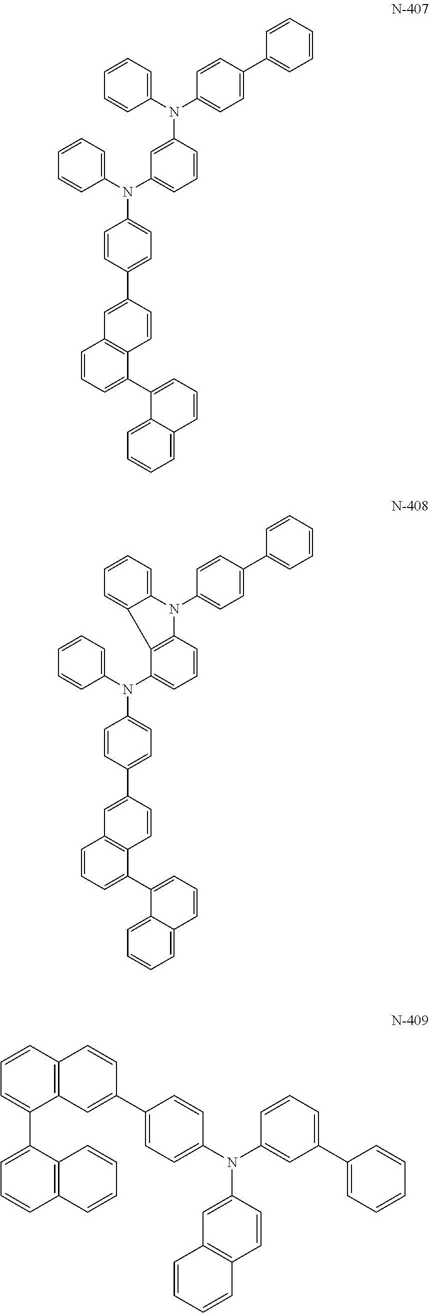 [SMILES: c1ccc(-c2ccc(N(c3ccccc3)c3cccc(N(c4ccccc4)c4ccc(-c5ccc6c(-c7cccc8ccccc78)cccc6c5)cc4)c3)cc2)cc1 ; c1ccc(-c2ccc(-n3c4ccccc4c4c(N(c5ccccc5)c5ccc(-c6ccc7c(-c8cccc9ccccc89)cccc7c6)cc5)cccc43)cc2)cc1 ; c1ccc(-c2cccc(N(c3ccc(-c4ccc5cccc(-c6cccc7ccccc67)c5c4)cc3)c3ccc4ccccc4c3)c2)cc1]

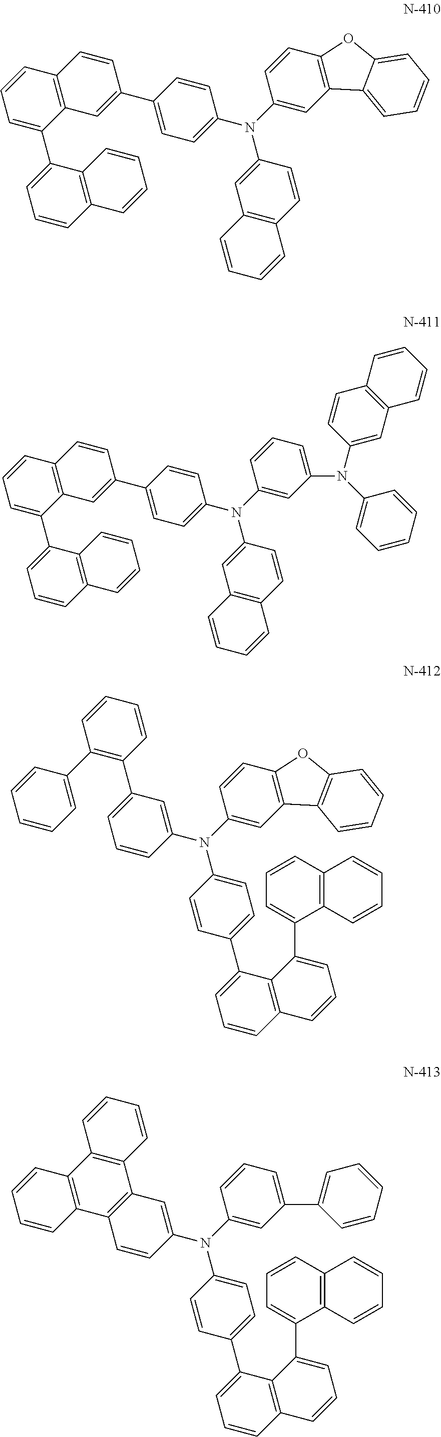 [SMILES: c1ccc2cc(N(c3ccc(-c4ccc5cccc(-c6cccc7ccccc67)c5c4)cc3)c3ccc4oc5ccccc5c4c3)ccc2c1 ; c1ccc(N(c2cccc(N(c3ccc(-c4ccc5cccc(-c6cccc7ccccc67)c5c4)cc3)c3ccc4ccccc4c3)c2)c2ccc3ccccc3c2)cc1 ; c1ccc(-c2ccccc2-c2cccc(N(c3ccc(-c4cccc5cccc(-c6cccc7ccccc67)c45)cc3)c3ccc4oc5ccccc5c4c3)c2)cc1 ; c1ccc(-c2cccc(N(c3ccc(-c4cccc5cccc(-c6cccc7ccccc67)c45)cc3)c3ccc4c5ccccc5c5ccccc5c4c3)c2)cc1]

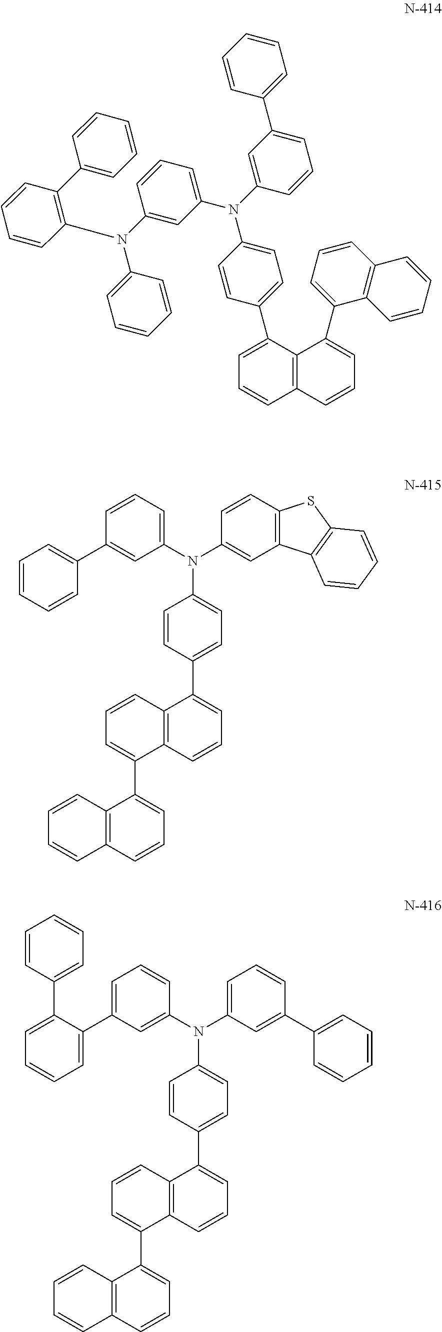 [SMILES: c1ccc(-c2cccc(N(c3ccc(-c4cccc5cccc(-c6cccc7ccccc67)c45)cc3)c3cccc(N(c4ccccc4)c4ccccc4-c4ccccc4)c3)c2)cc1 ; c1ccc(-c2cccc(N(c3ccc(-c4cccc5c(-c6cccc7ccccc67)cccc45)cc3)c3ccc4sc5ccccc5c4c3)c2)cc1 ; c1ccc(-c2cccc(N(c3ccc(-c4cccc5c(-c6cccc7ccccc67)cccc45)cc3)c3cccc(-c4ccccc4-c4ccccc4)c3)c2)cc1]

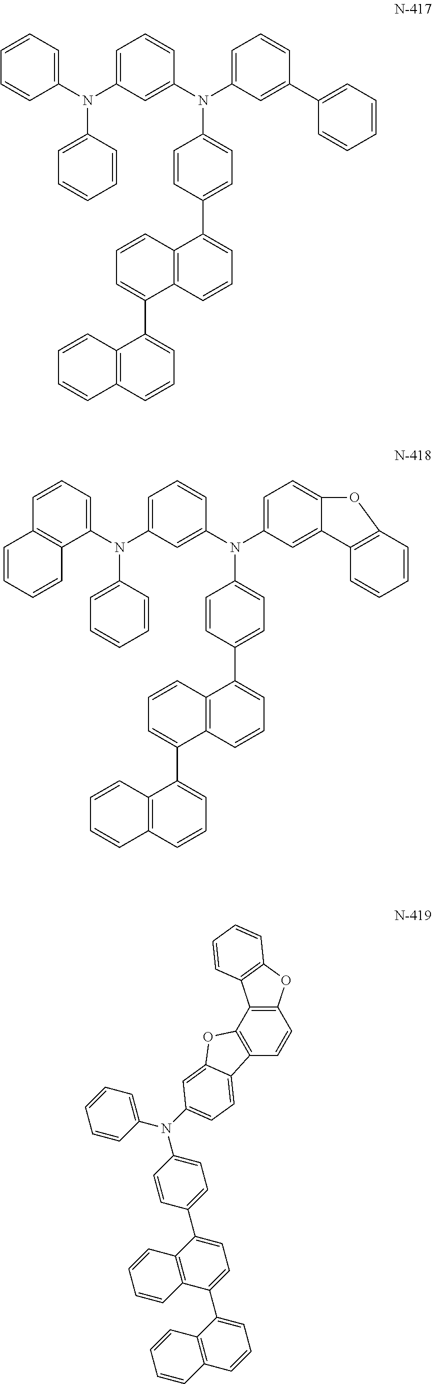 [SMILES: c1ccc(-c2cccc(N(c3ccc(-c4cccc5c(-c6cccc7ccccc67)cccc45)cc3)c3cccc(N(c4ccccc4)c4ccccc4)c3)c2)cc1 ; c1ccc(N(c2cccc(N(c3ccc(-c4cccc5c(-c6cccc7ccccc67)cccc45)cc3)c3ccc4oc5ccccc5c4c3)c2)c2cccc3ccccc23)cc1 ; c1ccc(N(c2ccc(-c3ccc(-c4cccc5ccccc45)c4ccccc34)cc2)c2ccc3c(c2)oc2c3ccc3oc4ccccc4c32)cc1]

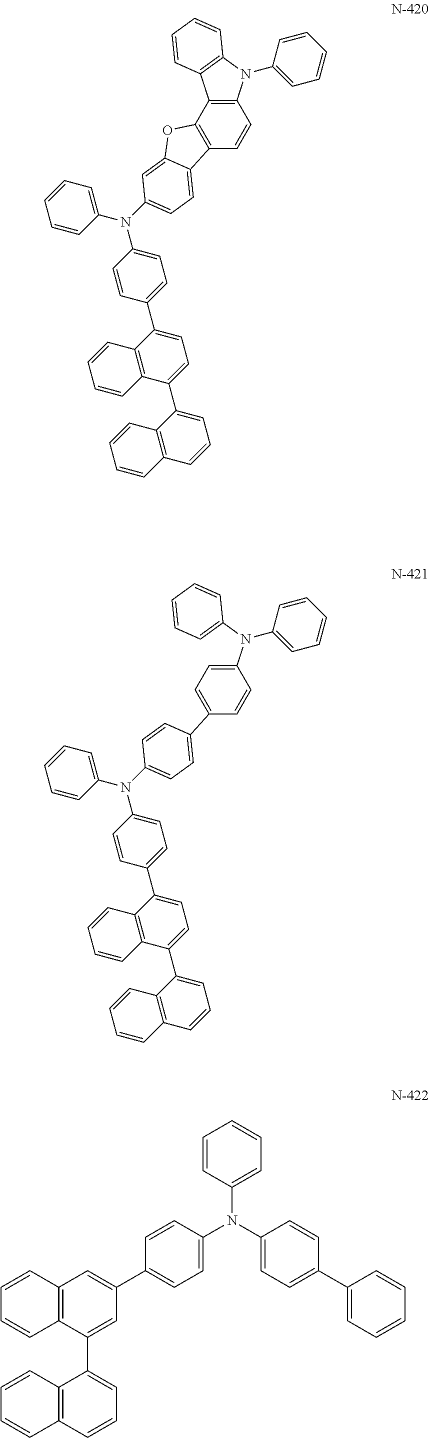 [SMILES: c1ccc(N(c2ccc(-c3ccc(-c4cccc5ccccc45)c4ccccc34)cc2)c2ccc3c(c2)oc2c3ccc3c2c2ccccc2n3-c2ccccc2)cc1 ; c1ccc(N(c2ccccc2)c2ccc(-c3ccc(N(c4ccccc4)c4ccc(-c5ccc(-c6cccc7ccccc67)c6ccccc56)cc4)cc3)cc2)cc1 ; c1ccc(-c2ccc(N(c3ccccc3)c3ccc(-c4cc(-c5cccc6ccccc56)c5ccccc5c4)cc3)cc2)cc1]

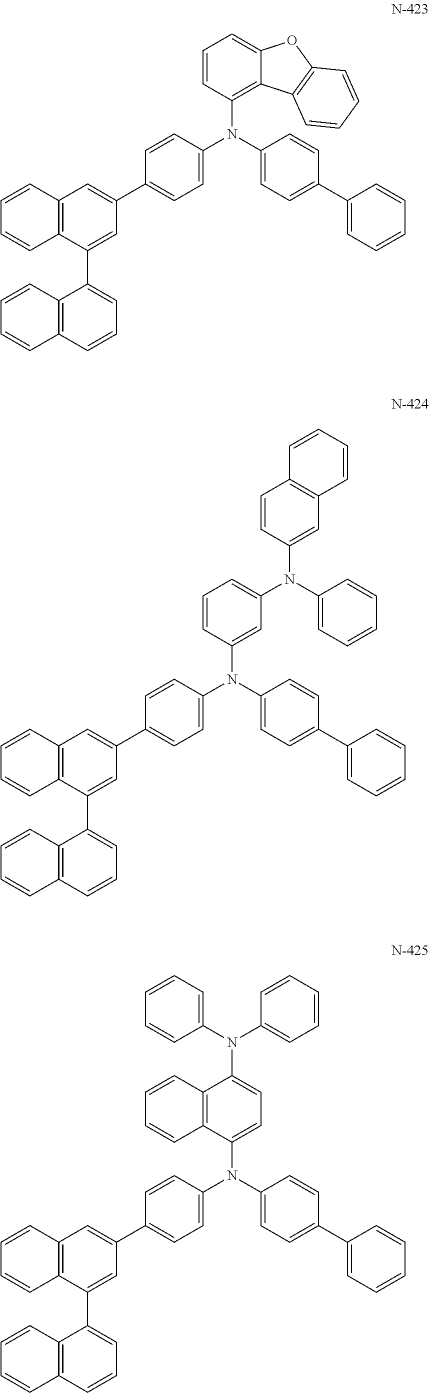 [SMILES: c1ccc(-c2ccc(N(c3ccc(-c4cc(-c5cccc6ccccc56)c5ccccc5c4)cc3)c3cccc4oc5ccccc5c34)cc2)cc1 ; c1ccc(-c2ccc(N(c3ccc(-c4cc(-c5cccc6ccccc56)c5ccccc5c4)cc3)c3cccc(N(c4ccccc4)c4ccc5ccccc5c4)c3)cc2)cc1 ; c1ccc(-c2ccc(N(c3ccc(-c4cc(-c5cccc6ccccc56)c5ccccc5c4)cc3)c3ccc(N(c4ccccc4)c4ccccc4)c4ccccc34)cc2)cc1]

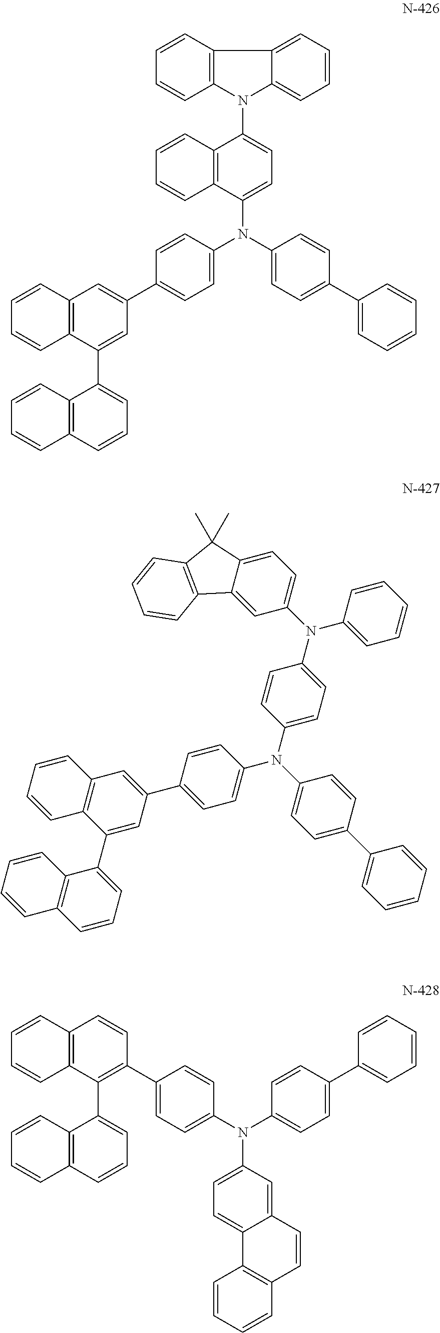 [SMILES: c1ccc(-c2ccc(N(c3ccc(-c4cc(-c5cccc6ccccc56)c5ccccc5c4)cc3)c3ccc(-n4c5ccccc5c5ccccc54)c4ccccc34)cc2)cc1 ; CC1(C)c2ccccc2-c2cc(N(c3ccccc3)c3ccc(N(c4ccc(-c5ccccc5)cc4)c4ccc(-c5cc(-c6cccc7ccccc67)c6ccccc6c5)cc4)cc3)ccc21 ; c1ccc(-c2ccc(N(c3ccc(-c4ccc5ccccc5c4-c4cccc5ccccc45)cc3)c3ccc4c(ccc5ccccc54)c3)cc2)cc1]

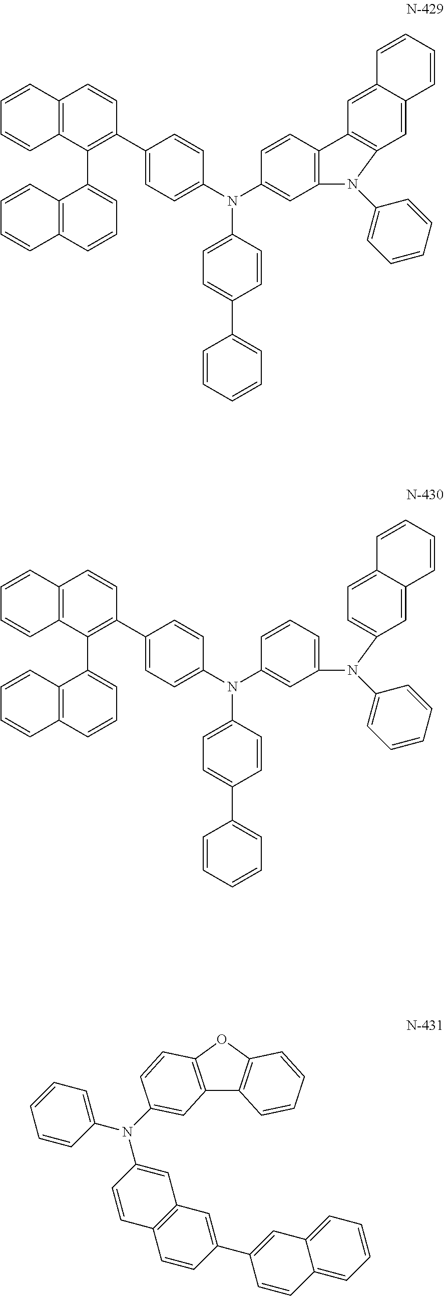 [SMILES: c1ccc(-c2ccc(N(c3ccc(-c4ccc5ccccc5c4-c4cccc5ccccc45)cc3)c3ccc4c5cc6ccccc6cc5n(-c5ccccc5)c4c3)cc2)cc1 ; c1ccc(-c2ccc(N(c3ccc(-c4ccc5ccccc5c4-c4cccc5ccccc45)cc3)c3cccc(N(c4ccccc4)c4ccc5ccccc5c4)c3)cc2)cc1 ; c1ccc(N(c2ccc3ccc(-c4ccc5ccccc5c4)cc3c2)c2ccc3oc4ccccc4c3c2)cc1]

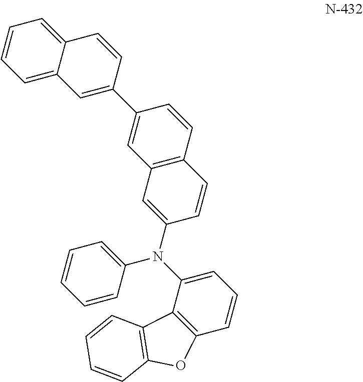 [SMILES: c1ccc(N(c2ccc3ccc(-c4ccc5ccccc5c4)cc3c2)c2cccc3oc4ccccc4c23)cc1]

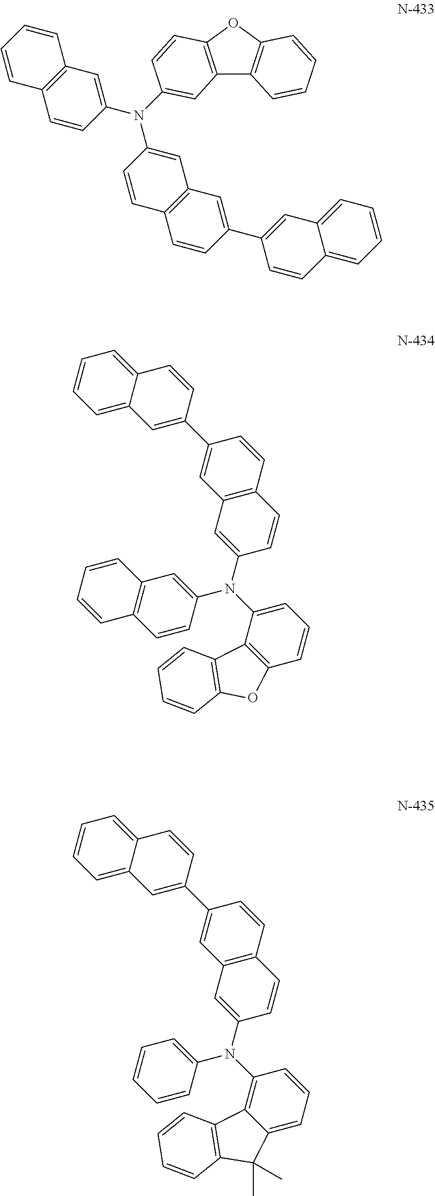 [SMILES: c1ccc2cc(-c3ccc4ccc(N(c5ccc6ccccc6c5)c5ccc6oc7ccccc7c6c5)cc4c3)ccc2c1 ; c1ccc2cc(-c3ccc4ccc(N(c5ccc6ccccc6c5)c5cccc6oc7ccccc7c56)cc4c3)ccc2c1 ; CC1(C)c2ccccc2-c2c(N(c3ccccc3)c3ccc4ccc(-c5ccc6ccccc6c5)cc4c3)cccc21]

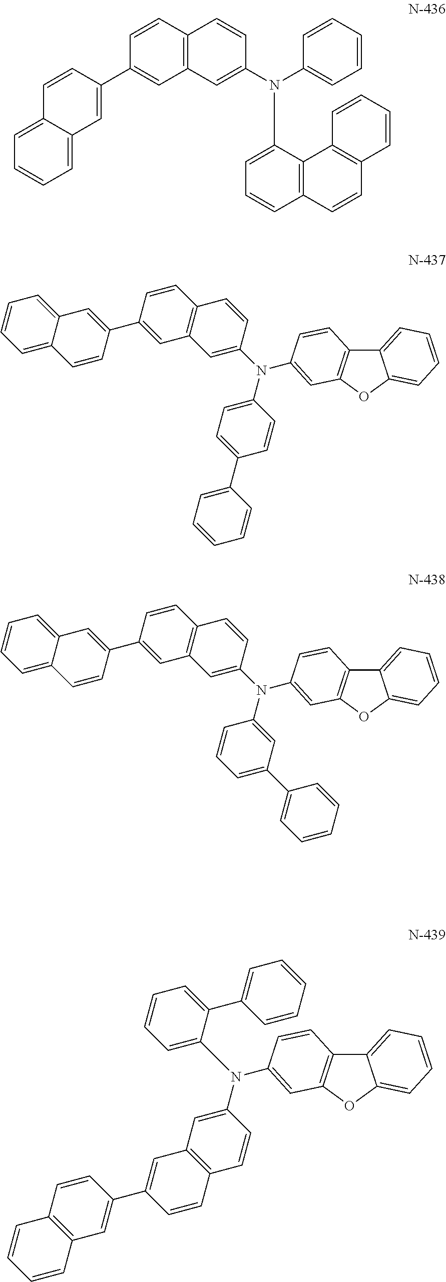 [SMILES: c1ccc(N(c2ccc3ccc(-c4ccc5ccccc5c4)cc3c2)c2cccc3ccc4ccccc4c23)cc1 ; c1ccc(-c2ccc(N(c3ccc4ccc(-c5ccc6ccccc6c5)cc4c3)c3ccc4c(c3)oc3ccccc34)cc2)cc1 ; c1ccc(-c2cccc(N(c3ccc4ccc(-c5ccc6ccccc6c5)cc4c3)c3ccc4c(c3)oc3ccccc34)c2)cc1 ; c1ccc(-c2ccccc2N(c2ccc3ccc(-c4ccc5ccccc5c4)cc3c2)c2ccc3c(c2)oc2ccccc23)cc1]

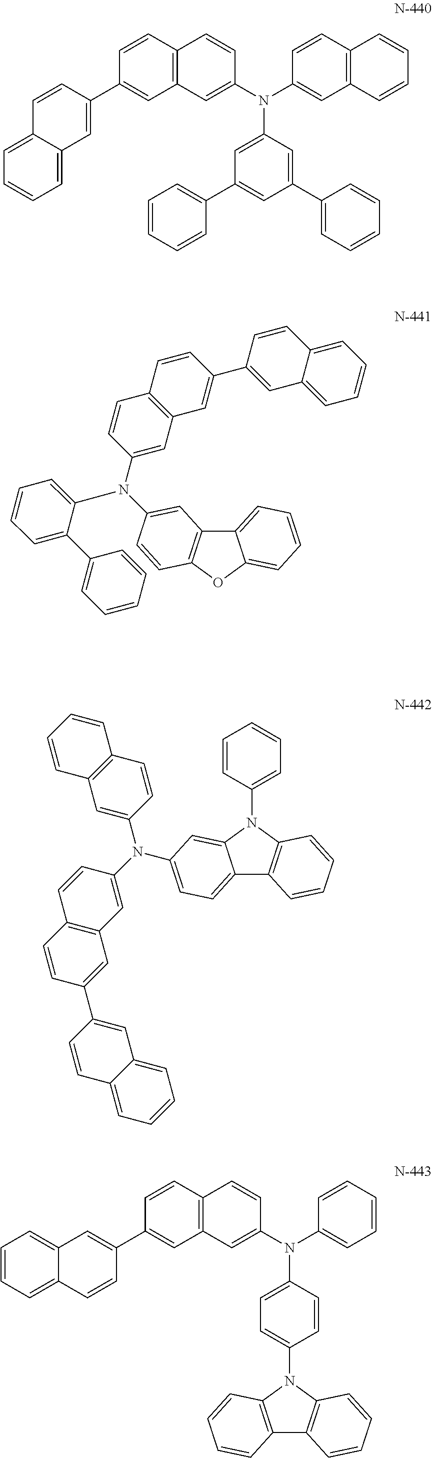 [SMILES: c1ccc(-c2cc(-c3ccccc3)cc(N(c3ccc4ccccc4c3)c3ccc4ccc(-c5ccc6ccccc6c5)cc4c3)c2)cc1 ; c1ccc(-c2ccccc2N(c2ccc3ccc(-c4ccc5ccccc5c4)cc3c2)c2ccc3oc4ccccc4c3c2)cc1 ; c1ccc(-n2c3ccccc3c3ccc(N(c4ccc5ccccc5c4)c4ccc5ccc(-c6ccc7ccccc7c6)cc5c4)cc32)cc1 ; c1ccc(N(c2ccc(-n3c4ccccc4c4ccccc43)cc2)c2ccc3ccc(-c4ccc5ccccc5c4)cc3c2)cc1]

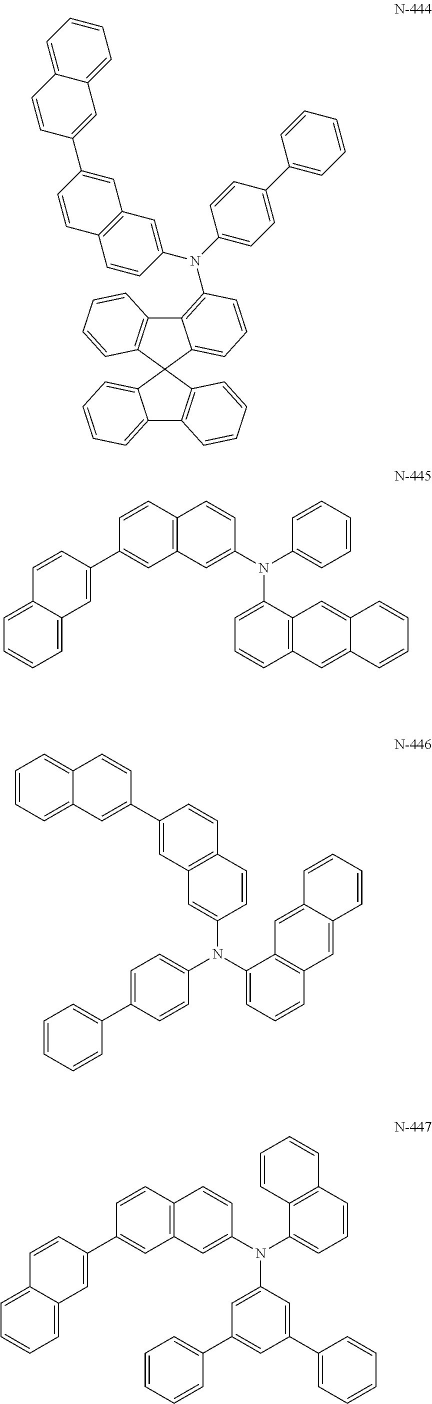 [SMILES: c1ccc(-c2ccc(N(c3ccc4ccc(-c5ccc6ccccc6c5)cc4c3)c3cccc4c3-c3ccccc3C43c4ccccc4-c4ccccc43)cc2)cc1 ; c1ccc(N(c2ccc3ccc(-c4ccc5ccccc5c4)cc3c2)c2cccc3cc4ccccc4cc23)cc1 ; c1ccc(-c2ccc(N(c3ccc4ccc(-c5ccc6ccccc6c5)cc4c3)c3cccc4cc5ccccc5cc34)cc2)cc1 ; c1ccc(-c2cc(-c3ccccc3)cc(N(c3ccc4ccc(-c5ccc6ccccc6c5)cc4c3)c3cccc4ccccc34)c2)cc1]

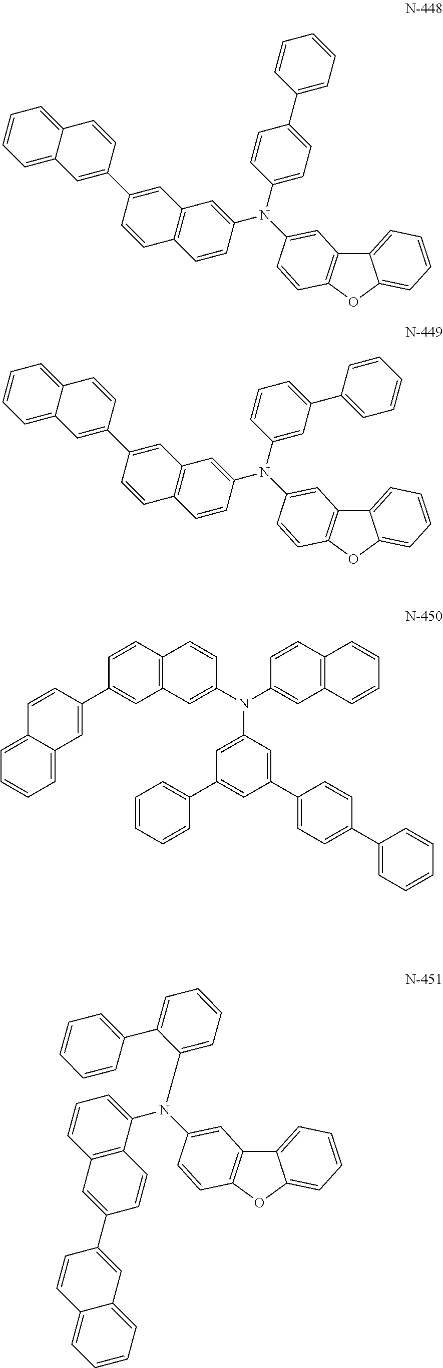 [SMILES: c1ccc(-c2ccc(N(c3ccc4ccc(-c5ccc6ccccc6c5)cc4c3)c3ccc4oc5ccccc5c4c3)cc2)cc1 ; c1ccc(-c2cccc(N(c3ccc4ccc(-c5ccc6ccccc6c5)cc4c3)c3ccc4oc5ccccc5c4c3)c2)cc1 ; c1ccc(-c2ccc(-c3cc(-c4ccccc4)cc(N(c4ccc5ccccc5c4)c4ccc5ccc(-c6ccc7ccccc7c6)cc5c4)c3)cc2)cc1 ; c1ccc(-c2ccccc2N(c2ccc3oc4ccccc4c3c2)c2cccc3cc(-c4ccc5ccccc5c4)ccc23)cc1]

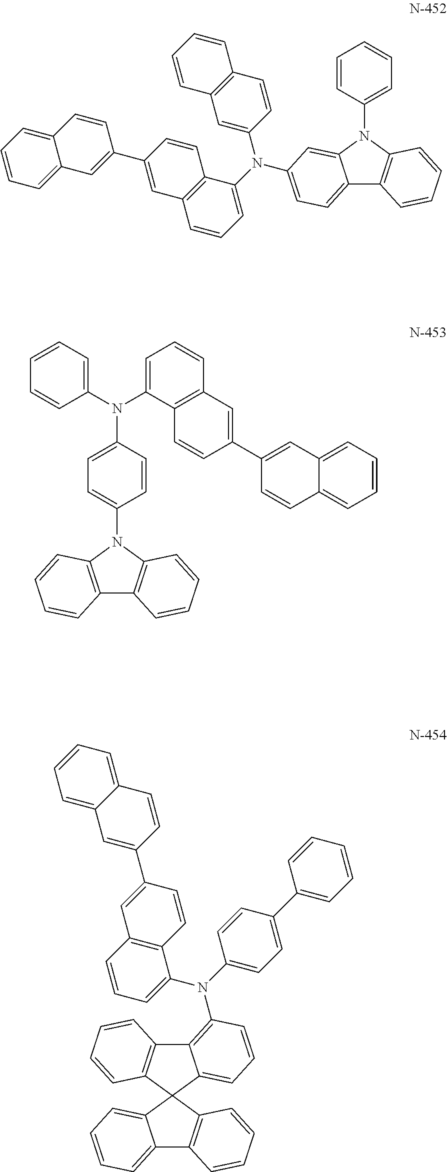 [SMILES: c1ccc(-n2c3ccccc3c3ccc(N(c4ccc5ccccc5c4)c4cccc5cc(-c6ccc7ccccc7c6)ccc45)cc32)cc1 ; c1ccc(N(c2ccc(-n3c4ccccc4c4ccccc43)cc2)c2cccc3cc(-c4ccc5ccccc5c4)ccc23)cc1 ; c1ccc(-c2ccc(N(c3cccc4c3-c3ccccc3C43c4ccccc4-c4ccccc43)c3cccc4cc(-c5ccc6ccccc6c5)ccc34)cc2)cc1]

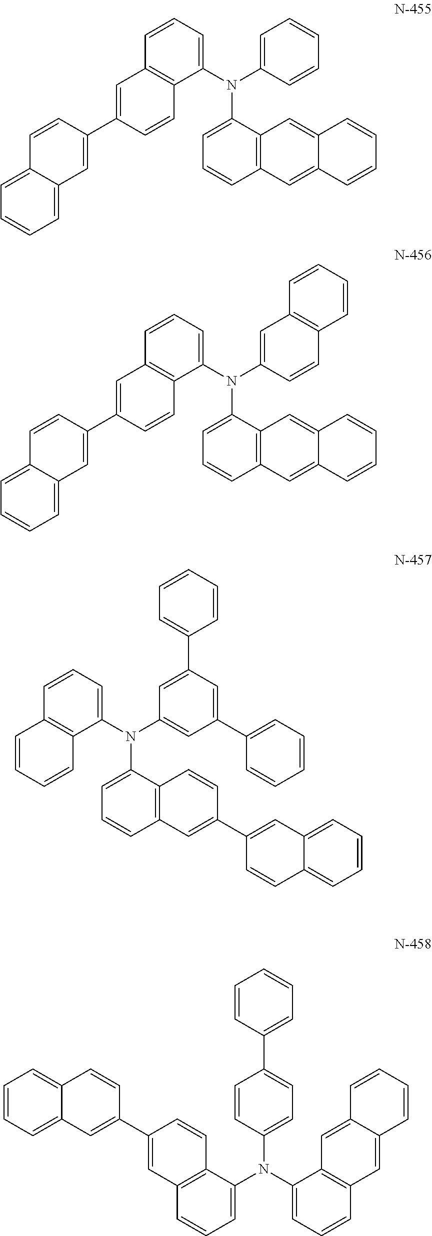 [SMILES: c1ccc(N(c2cccc3cc(-c4ccc5ccccc5c4)ccc23)c2cccc3cc4ccccc4cc23)cc1 ; c1ccc2cc(-c3ccc4c(N(c5ccc6ccccc6c5)c5cccc6cc7ccccc7cc56)cccc4c3)ccc2c1 ; c1ccc(-c2cc(-c3ccccc3)cc(N(c3cccc4ccccc34)c3cccc4cc(-c5ccc6ccccc6c5)ccc34)c2)cc1 ; c1ccc(-c2ccc(N(c3cccc4cc(-c5ccc6ccccc6c5)ccc34)c3cccc4cc5ccccc5cc34)cc2)cc1]

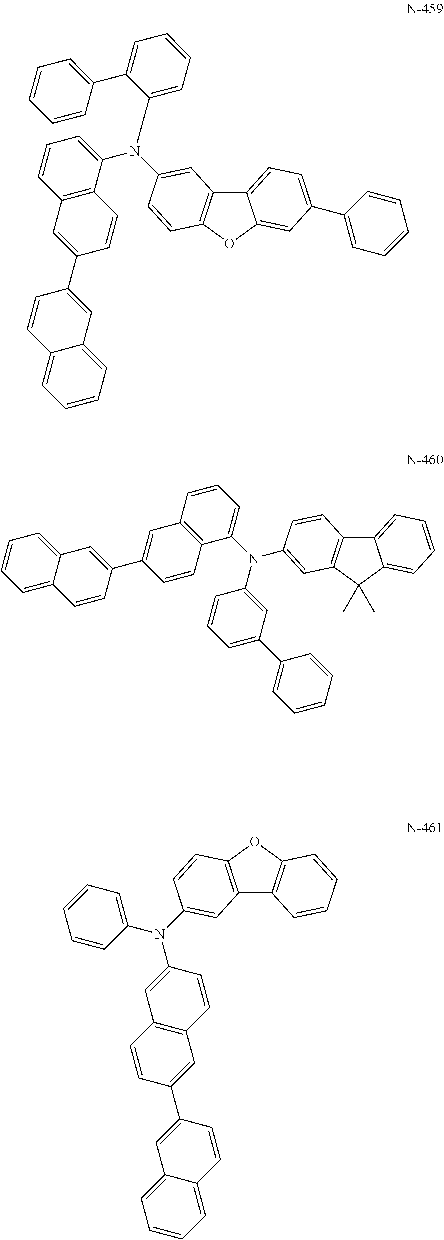 [SMILES: c1ccc(-c2ccc3c(c2)oc2ccc(N(c4ccccc4-c4ccccc4)c4cccc5cc(-c6ccc7ccccc7c6)ccc45)cc23)cc1 ; CC1(C)c2ccccc2-c2ccc(N(c3cccc(-c4ccccc4)c3)c3cccc4cc(-c5ccc6ccccc6c5)ccc34)cc21 ; c1ccc(N(c2ccc3cc(-c4ccc5ccccc5c4)ccc3c2)c2ccc3oc4ccccc4c3c2)cc1]

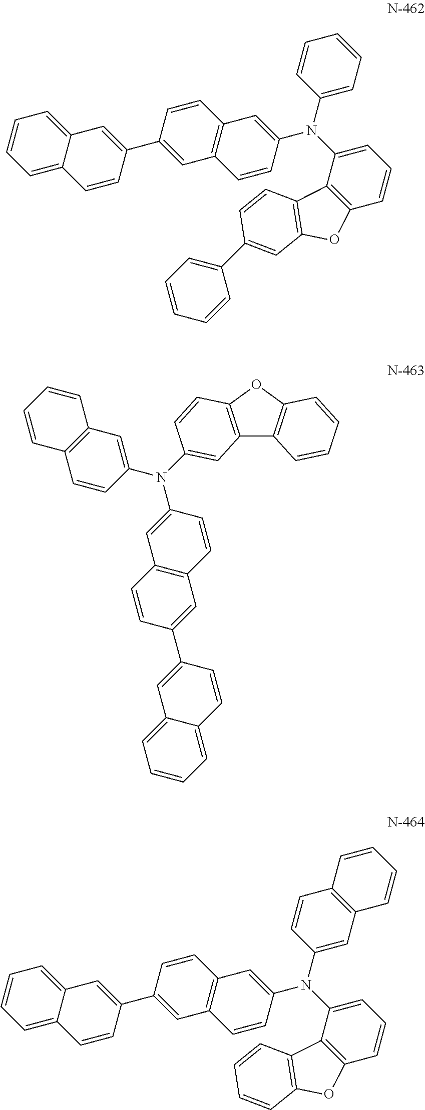 [SMILES: c1ccc(-c2ccc3c(c2)oc2cccc(N(c4ccccc4)c4ccc5cc(-c6ccc7ccccc7c6)ccc5c4)c23)cc1 ; c1ccc2cc(-c3ccc4cc(N(c5ccc6ccccc6c5)c5ccc6oc7ccccc7c6c5)ccc4c3)ccc2c1 ; c1ccc2cc(-c3ccc4cc(N(c5ccc6ccccc6c5)c5cccc6oc7ccccc7c56)ccc4c3)ccc2c1]

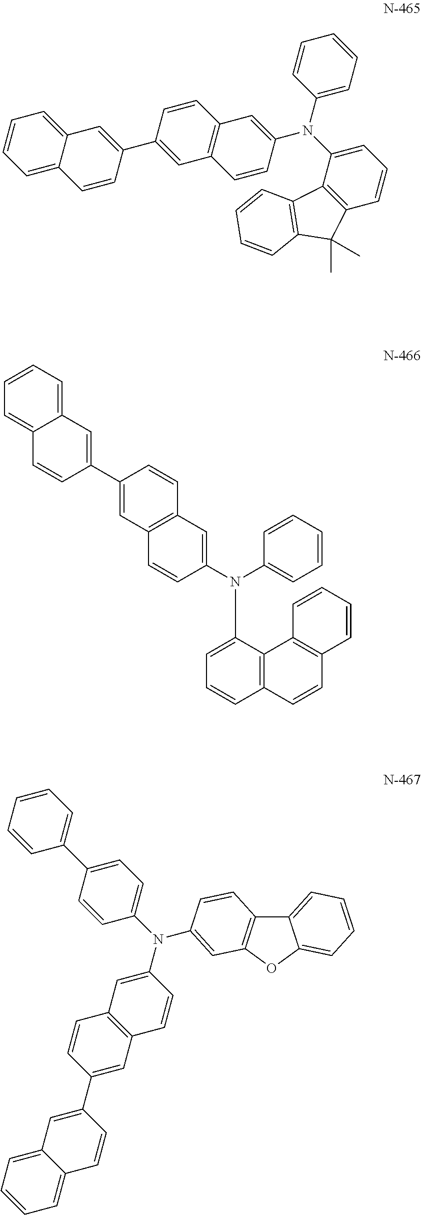 [SMILES: CC1(C)c2ccccc2-c2c(N(c3ccccc3)c3ccc4cc(-c5ccc6ccccc6c5)ccc4c3)cccc21 ; c1ccc(N(c2ccc3cc(-c4ccc5ccccc5c4)ccc3c2)c2cccc3ccc4ccccc4c23)cc1 ; c1ccc(-c2ccc(N(c3ccc4cc(-c5ccc6ccccc6c5)ccc4c3)c3ccc4c(c3)oc3ccccc34)cc2)cc1]

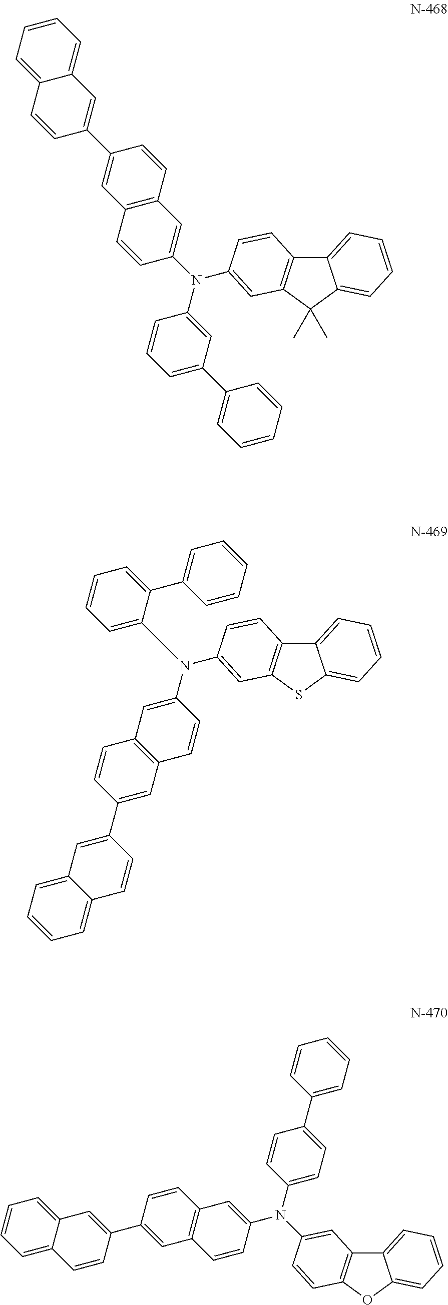 [SMILES: CC1(C)c2ccccc2-c2ccc(N(c3cccc(-c4ccccc4)c3)c3ccc4cc(-c5ccc6ccccc6c5)ccc4c3)cc21 ; c1ccc(-c2ccccc2N(c2ccc3cc(-c4ccc5ccccc5c4)ccc3c2)c2ccc3c(c2)sc2ccccc23)cc1 ; c1ccc(-c2ccc(N(c3ccc4cc(-c5ccc6ccccc6c5)ccc4c3)c3ccc4oc5ccccc5c4c3)cc2)cc1]

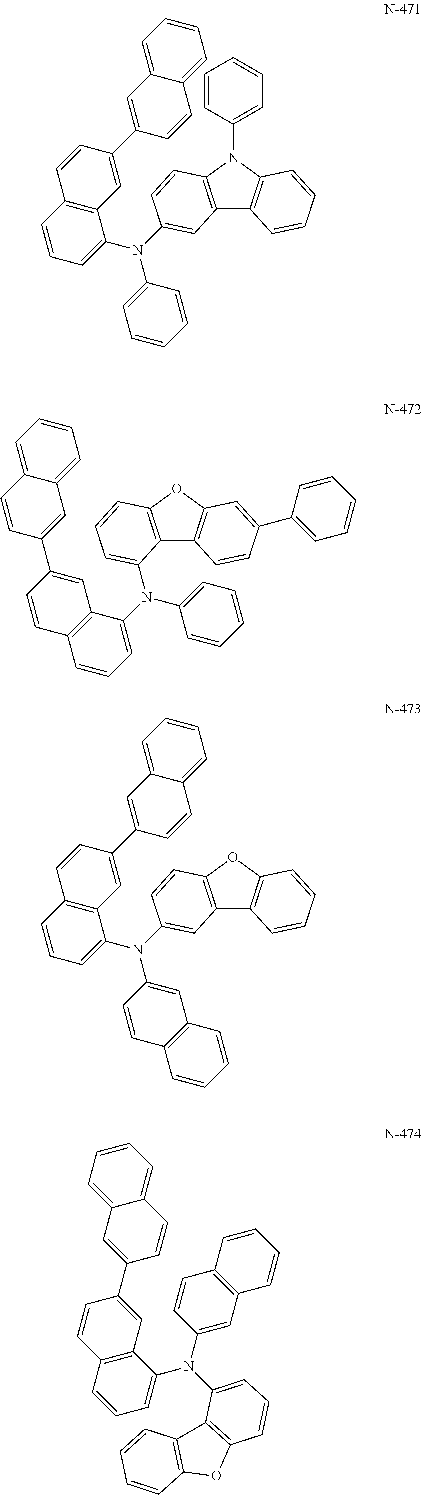 [SMILES: c1ccc(N(c2ccc3c(c2)c2ccccc2n3-c2ccccc2)c2cccc3ccc(-c4ccc5ccccc5c4)cc23)cc1 ; c1ccc(-c2ccc3c(c2)oc2cccc(N(c4ccccc4)c4cccc5ccc(-c6ccc7ccccc7c6)cc45)c23)cc1 ; c1ccc2cc(-c3ccc4cccc(N(c5ccc6ccccc6c5)c5ccc6oc7ccccc7c6c5)c4c3)ccc2c1 ; c1ccc2cc(-c3ccc4cccc(N(c5ccc6ccccc6c5)c5cccc6oc7ccccc7c56)c4c3)ccc2c1]

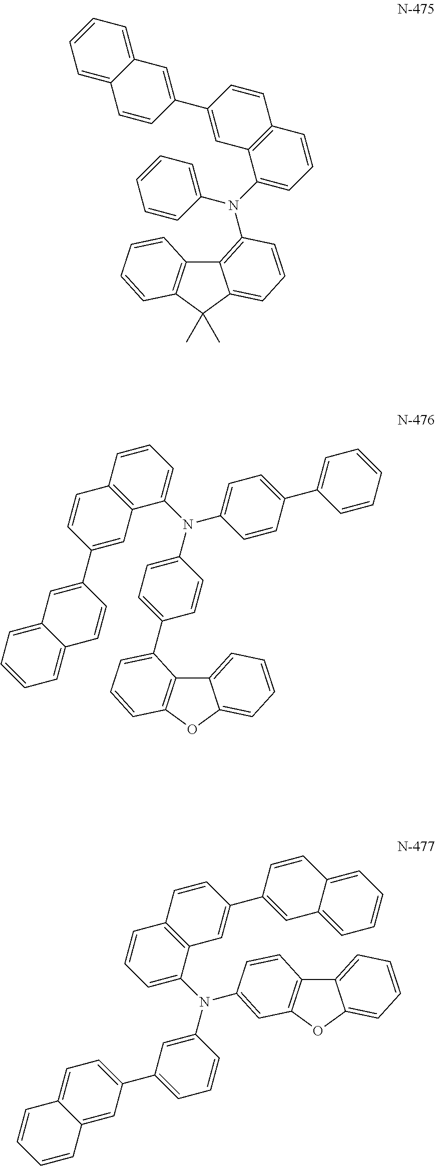 [SMILES: CC1(C)c2ccccc2-c2c(N(c3ccccc3)c3cccc4ccc(-c5ccc6ccccc6c5)cc34)cccc21 ; c1ccc(-c2ccc(N(c3ccc(-c4cccc5oc6ccccc6c45)cc3)c3cccc4ccc(-c5ccc6ccccc6c5)cc34)cc2)cc1 ; c1cc(-c2ccc3ccccc3c2)cc(N(c2ccc3c(c2)oc2ccccc23)c2cccc3ccc(-c4ccc5ccccc5c4)cc23)c1]

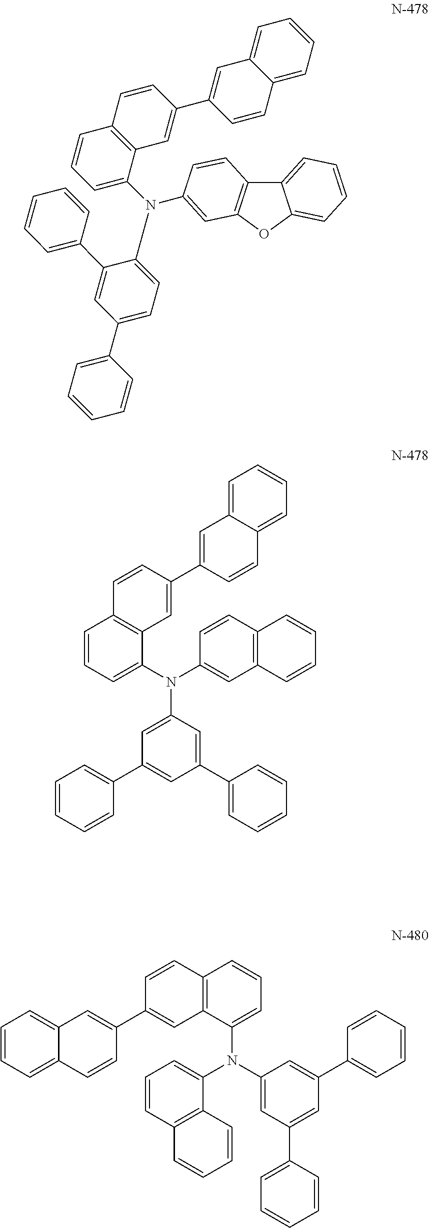 [SMILES: c1ccc(-c2ccc(N(c3ccc4c(c3)oc3ccccc34)c3cccc4ccc(-c5ccc6ccccc6c5)cc34)c(-c3ccccc3)c2)cc1 ; c1ccc(-c2cc(-c3ccccc3)cc(N(c3ccc4ccccc4c3)c3cccc4ccc(-c5ccc6ccccc6c5)cc34)c2)cc1 ; c1ccc(-c2cc(-c3ccccc3)cc(N(c3cccc4ccccc34)c3cccc4ccc(-c5ccc6ccccc6c5)cc34)c2)cc1]

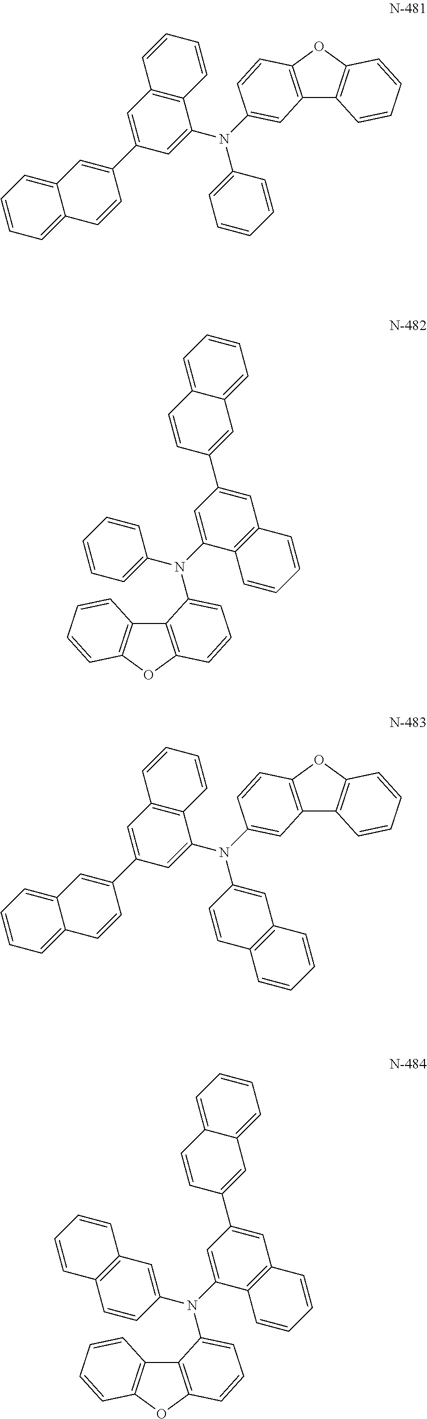 [SMILES: c1ccc(N(c2ccc3oc4ccccc4c3c2)c2cc(-c3ccc4ccccc4c3)cc3ccccc23)cc1 ; c1ccc(N(c2cc(-c3ccc4ccccc4c3)cc3ccccc23)c2cccc3oc4ccccc4c23)cc1 ; c1ccc2cc(-c3cc(N(c4ccc5ccccc5c4)c4ccc5oc6ccccc6c5c4)c4ccccc4c3)ccc2c1 ; c1ccc2cc(-c3cc(N(c4ccc5ccccc5c4)c4cccc5oc6ccccc6c45)c4ccccc4c3)ccc2c1]

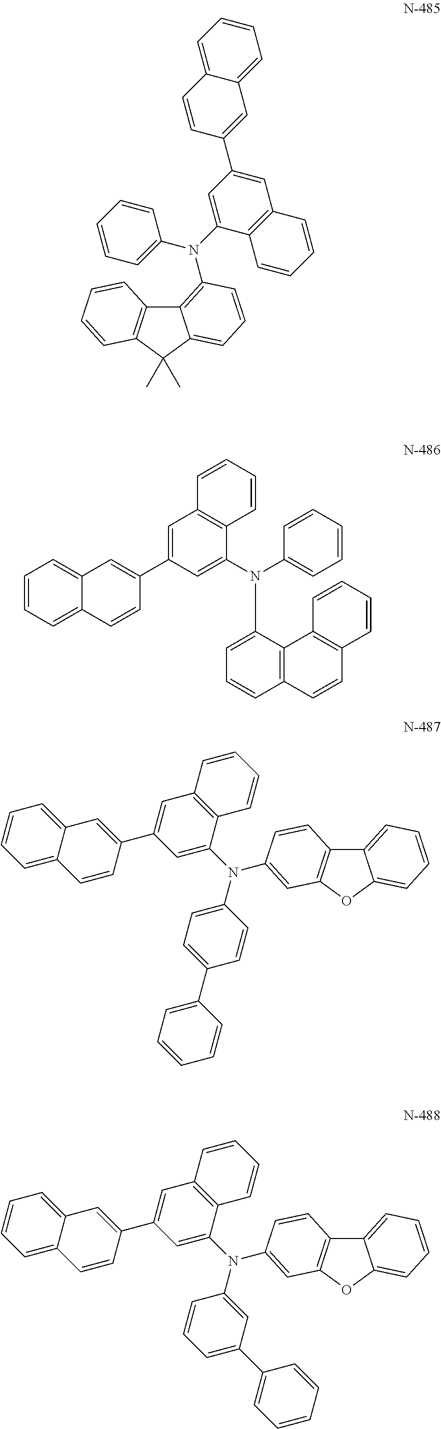 [SMILES: CC1(C)c2ccccc2-c2c(N(c3ccccc3)c3cc(-c4ccc5ccccc5c4)cc4ccccc34)cccc21 ; c1ccc(N(c2cc(-c3ccc4ccccc4c3)cc3ccccc23)c2cccc3ccc4ccccc4c23)cc1 ; c1ccc(-c2ccc(N(c3ccc4c(c3)oc3ccccc34)c3cc(-c4ccc5ccccc5c4)cc4ccccc34)cc2)cc1 ; c1ccc(-c2cccc(N(c3ccc4c(c3)oc3ccccc34)c3cc(-c4ccc5ccccc5c4)cc4ccccc34)c2)cc1]

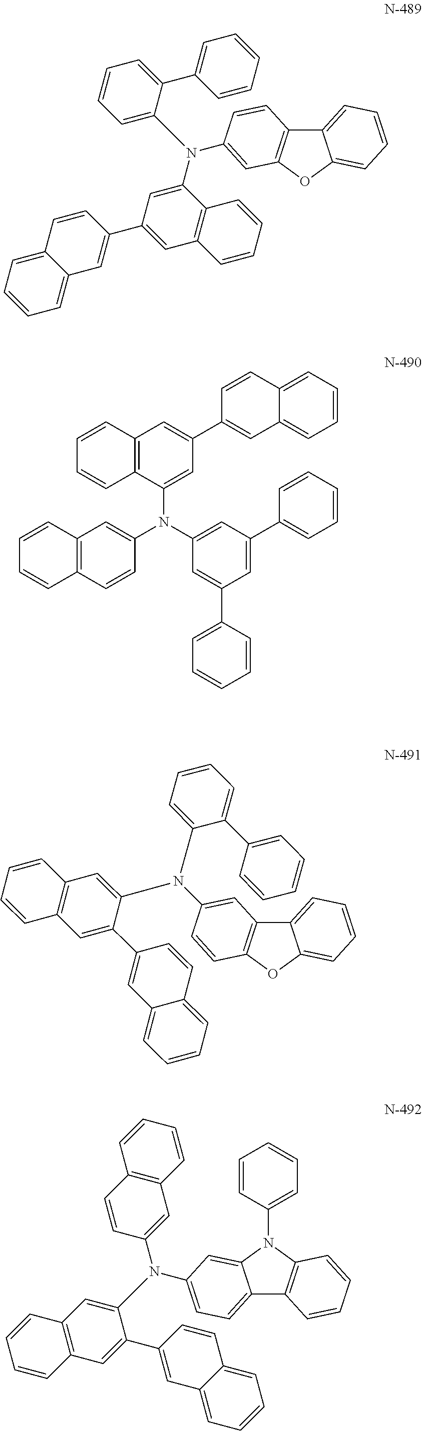 [SMILES: c1ccc(-c2ccccc2N(c2ccc3c(c2)oc2ccccc23)c2cc(-c3ccc4ccccc4c3)cc3ccccc23)cc1 ; c1ccc(-c2cc(-c3ccccc3)cc(N(c3ccc4ccccc4c3)c3cc(-c4ccc5ccccc5c4)cc4ccccc34)c2)cc1 ; c1ccc(-c2ccccc2N(c2ccc3oc4ccccc4c3c2)c2cc3ccccc3cc2-c2ccc3ccccc3c2)cc1 ; c1ccc(-n2c3ccccc3c3ccc(N(c4ccc5ccccc5c4)c4cc5ccccc5cc4-c4ccc5ccccc5c4)cc32)cc1]

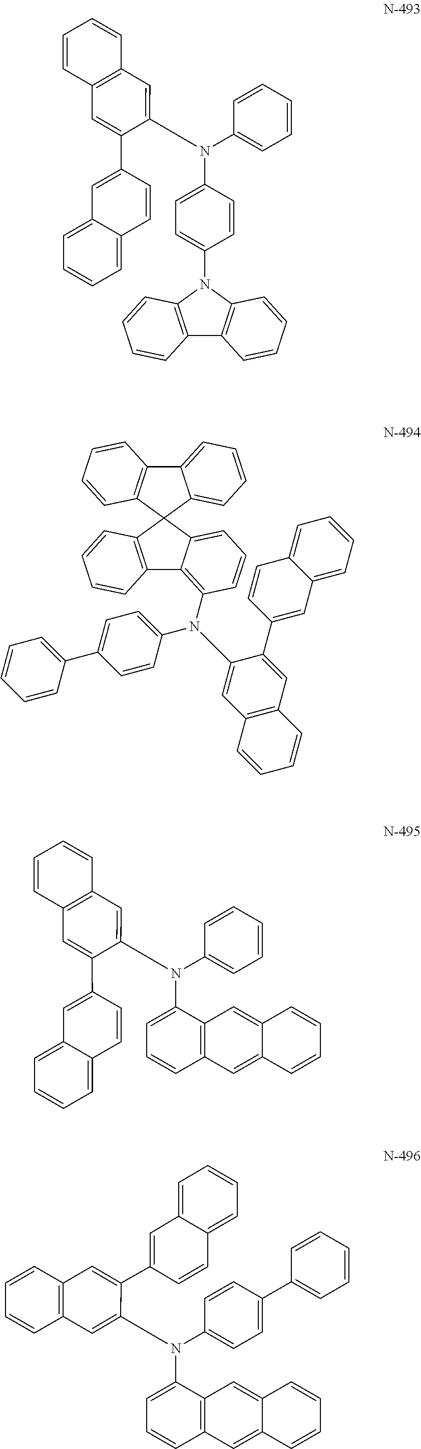 [SMILES: c1ccc(N(c2ccc(-n3c4ccccc4c4ccccc43)cc2)c2cc3ccccc3cc2-c2ccc3ccccc3c2)cc1 ; c1ccc(-c2ccc(N(c3cc4ccccc4cc3-c3ccc4ccccc4c3)c3cccc4c3-c3ccccc3C43c4ccccc4-c4ccccc43)cc2)cc1 ; c1ccc(N(c2cc3ccccc3cc2-c2ccc3ccccc3c2)c2cccc3cc4ccccc4cc23)cc1 ; c1ccc(-c2ccc(N(c3cc4ccccc4cc3-c3ccc4ccccc4c3)c3cccc4cc5ccccc5cc34)cc2)cc1]

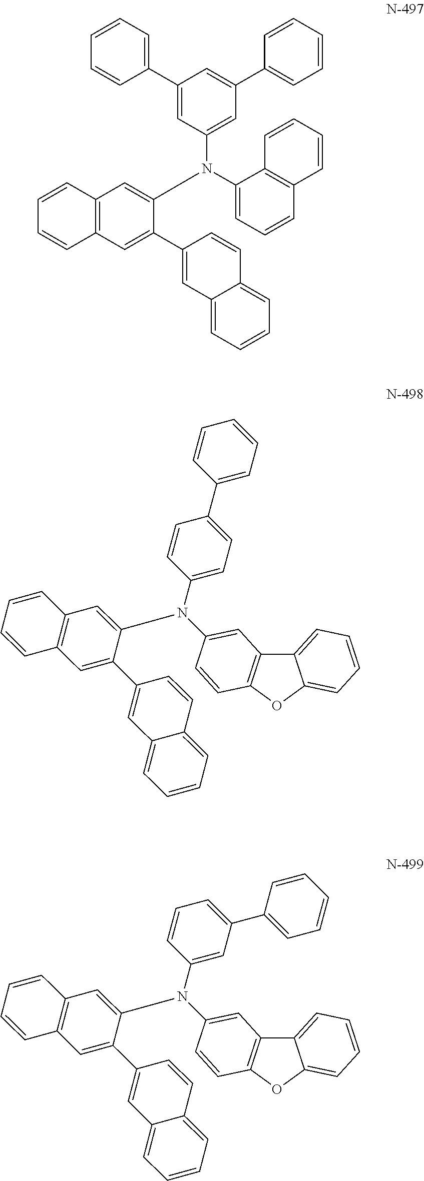 [SMILES: c1ccc(-c2cc(-c3ccccc3)cc(N(c3cc4ccccc4cc3-c3ccc4ccccc4c3)c3cccc4ccccc34)c2)cc1 ; c1ccc(-c2ccc(N(c3ccc4oc5ccccc5c4c3)c3cc4ccccc4cc3-c3ccc4ccccc4c3)cc2)cc1 ; c1ccc(-c2cccc(N(c3ccc4oc5ccccc5c4c3)c3cc4ccccc4cc3-c3ccc4ccccc4c3)c2)cc1]

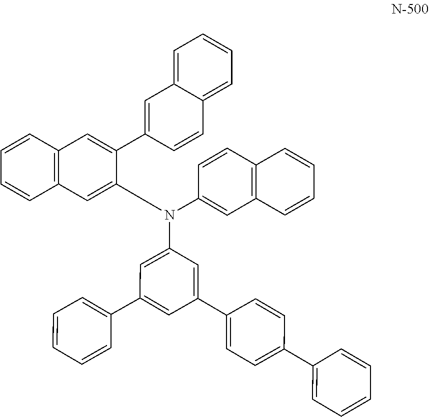 [SMILES: c1ccc(-c2ccc(-c3cc(-c4ccccc4)cc(N(c4ccc5ccccc5c4)c4cc5ccccc5cc4-c4ccc5ccccc5c4)c3)cc2)cc1]

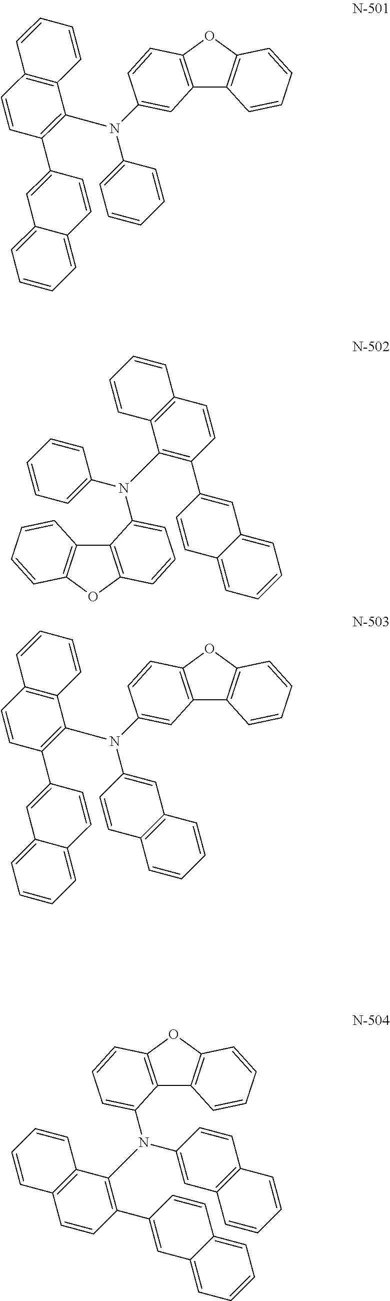 [SMILES: c1ccc(N(c2ccc3oc4ccccc4c3c2)c2c(-c3ccc4ccccc4c3)ccc3ccccc23)cc1 ; c1ccc(N(c2c(-c3ccc4ccccc4c3)ccc3ccccc23)c2cccc3oc4ccccc4c23)cc1 ; c1ccc2cc(-c3ccc4ccccc4c3N(c3ccc4ccccc4c3)c3ccc4oc5ccccc5c4c3)ccc2c1 ; c1ccc2cc(-c3ccc4ccccc4c3N(c3ccc4ccccc4c3)c3cccc4oc5ccccc5c34)ccc2c1]

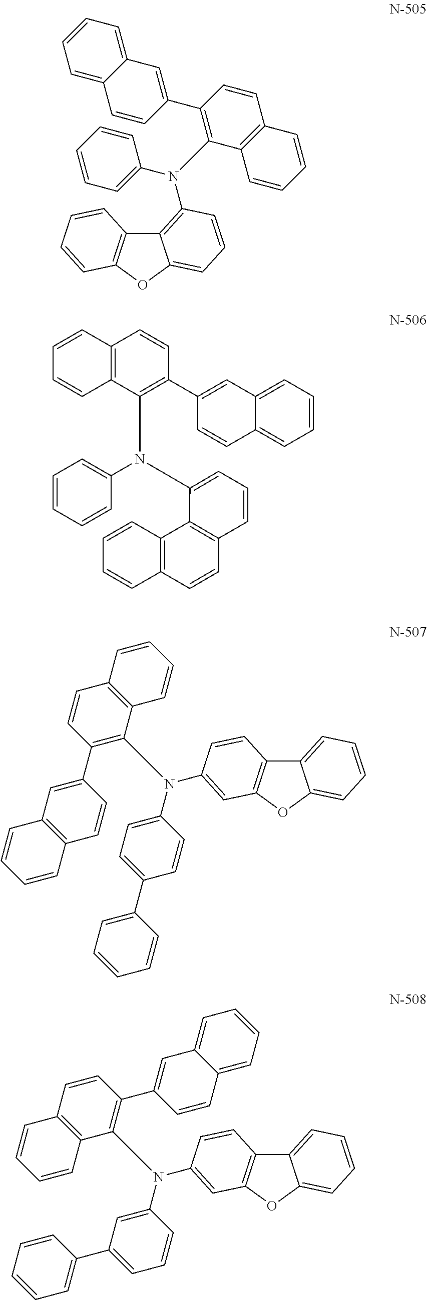

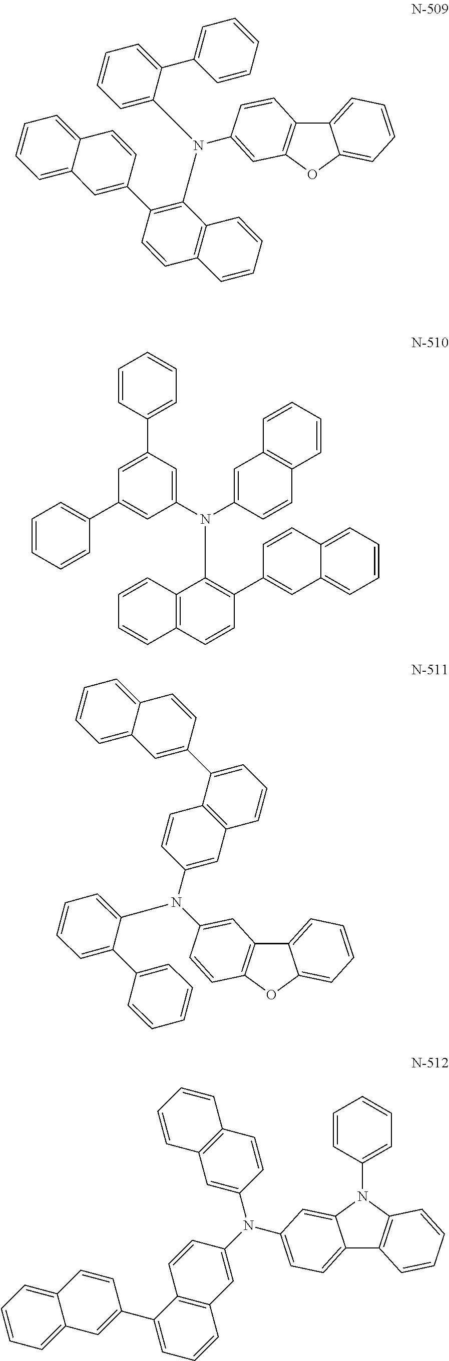

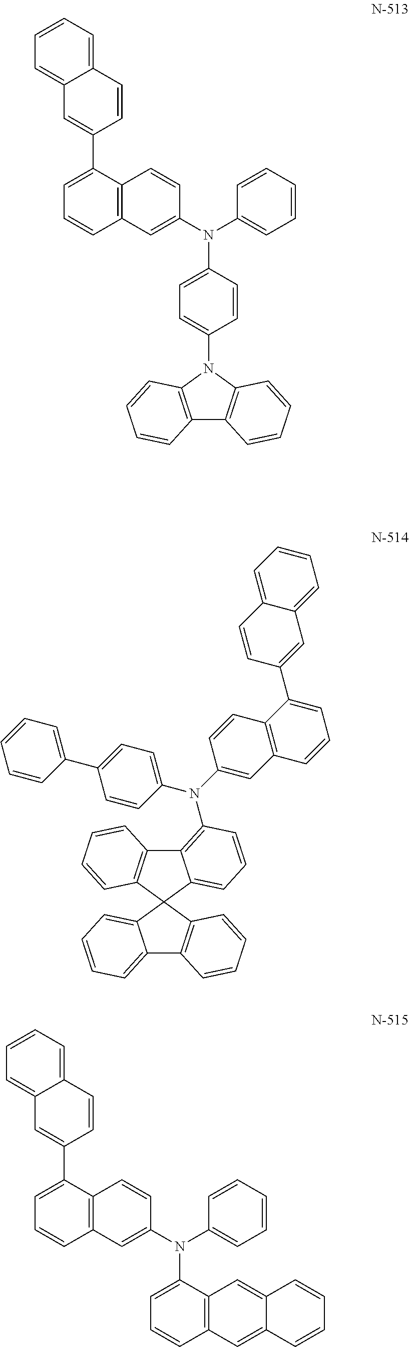 [SMILES: c1ccc(N(c2ccc(-n3c4ccccc4c4ccccc43)cc2)c2ccc3c(-c4ccc5ccccc5c4)cccc3c2)cc1 ; c1ccc(-c2ccc(N(c3ccc4c(-c5ccc6ccccc6c5)cccc4c3)c3cccc4c3-c3ccccc3C43c4ccccc4-c4ccccc43)cc2)cc1 ; c1ccc(N(c2ccc3c(-c4ccc5ccccc5c4)cccc3c2)c2cccc3cc4ccccc4cc23)cc1]

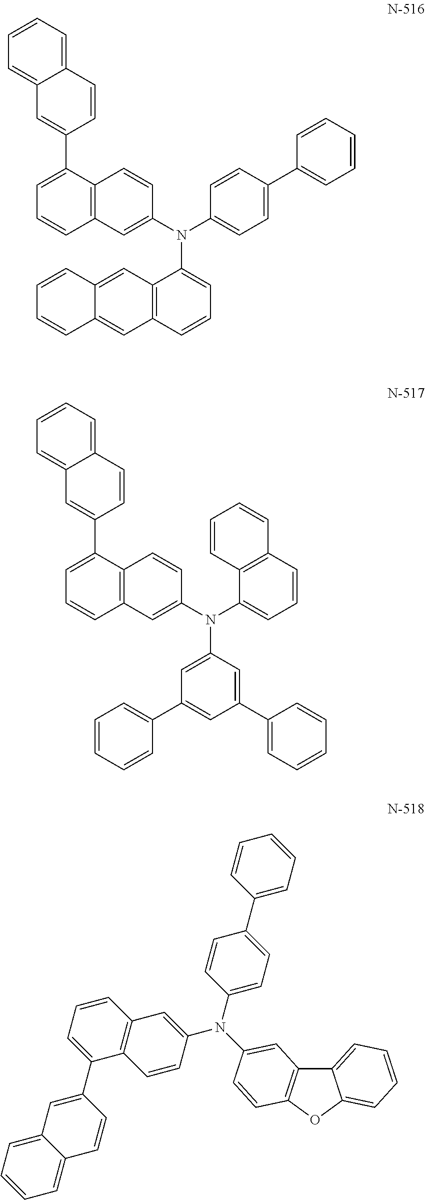 [SMILES: c1ccc(-c2ccc(N(c3ccc4c(-c5ccc6ccccc6c5)cccc4c3)c3cccc4cc5ccccc5cc34)cc2)cc1 ; c1ccc(-c2cc(-c3ccccc3)cc(N(c3ccc4c(-c5ccc6ccccc6c5)cccc4c3)c3cccc4ccccc34)c2)cc1 ; c1ccc(-c2ccc(N(c3ccc4c(-c5ccc6ccccc6c5)cccc4c3)c3ccc4oc5ccccc5c4c3)cc2)cc1]

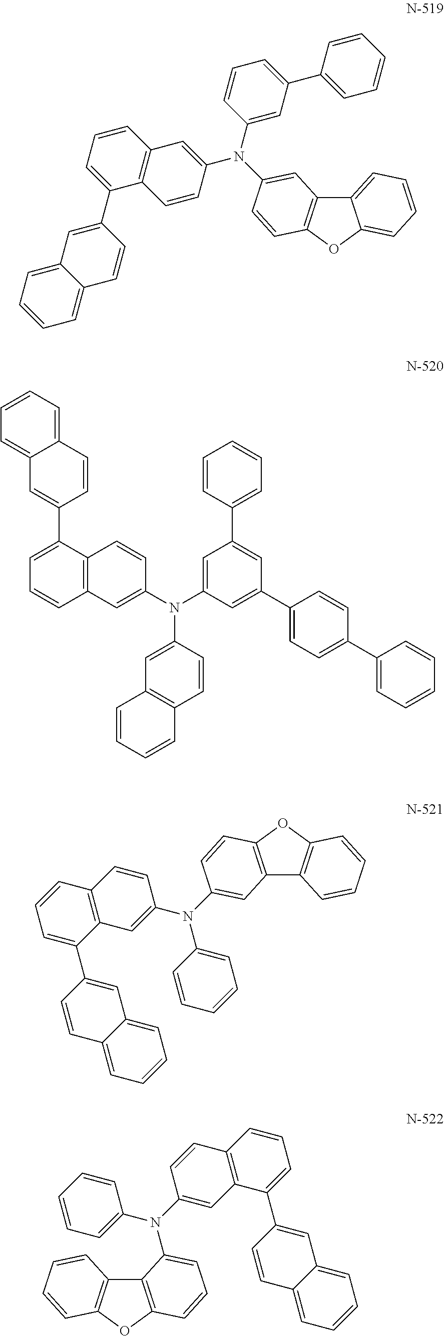 [SMILES: c1ccc(-c2cccc(N(c3ccc4c(-c5ccc6ccccc6c5)cccc4c3)c3ccc4oc5ccccc5c4c3)c2)cc1 ; c1ccc(-c2ccc(-c3cc(-c4ccccc4)cc(N(c4ccc5ccccc5c4)c4ccc5c(-c6ccc7ccccc7c6)cccc5c4)c3)cc2)cc1 ; c1ccc(N(c2ccc3cccc(-c4ccc5ccccc5c4)c3c2)c2ccc3oc4ccccc4c3c2)cc1 ; c1ccc(N(c2ccc3cccc(-c4ccc5ccccc5c4)c3c2)c2cccc3oc4ccccc4c23)cc1]

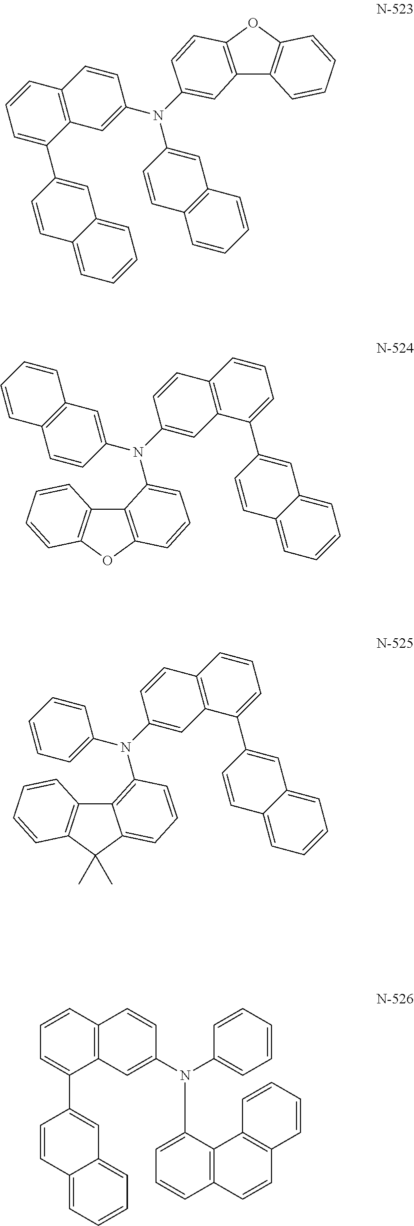 [SMILES: c1ccc2cc(-c3cccc4ccc(N(c5ccc6ccccc6c5)c5ccc6oc7ccccc7c6c5)cc34)ccc2c1 ; c1ccc2cc(-c3cccc4ccc(N(c5ccc6ccccc6c5)c5cccc6oc7ccccc7c56)cc34)ccc2c1 ; CC1(C)c2ccccc2-c2c(N(c3ccccc3)c3ccc4cccc(-c5ccc6ccccc6c5)c4c3)cccc21 ; c1ccc(N(c2ccc3cccc(-c4ccc5ccccc5c4)c3c2)c2cccc3ccc4ccccc4c23)cc1]

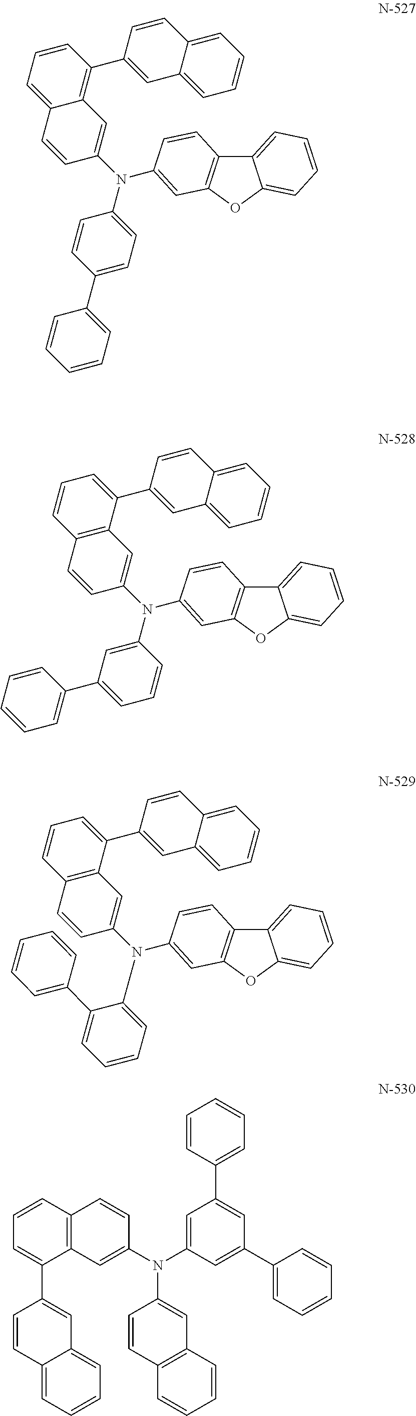 [SMILES: c1ccc(-c2ccc(N(c3ccc4c(c3)oc3ccccc34)c3ccc4cccc(-c5ccc6ccccc6c5)c4c3)cc2)cc1 ; c1ccc(-c2cccc(N(c3ccc4c(c3)oc3ccccc34)c3ccc4cccc(-c5ccc6ccccc6c5)c4c3)c2)cc1 ; c1ccc(-c2ccccc2N(c2ccc3c(c2)oc2ccccc23)c2ccc3cccc(-c4ccc5ccccc5c4)c3c2)cc1 ; c1ccc(-c2cc(-c3ccccc3)cc(N(c3ccc4ccccc4c3)c3ccc4cccc(-c5ccc6ccccc6c5)c4c3)c2)cc1]

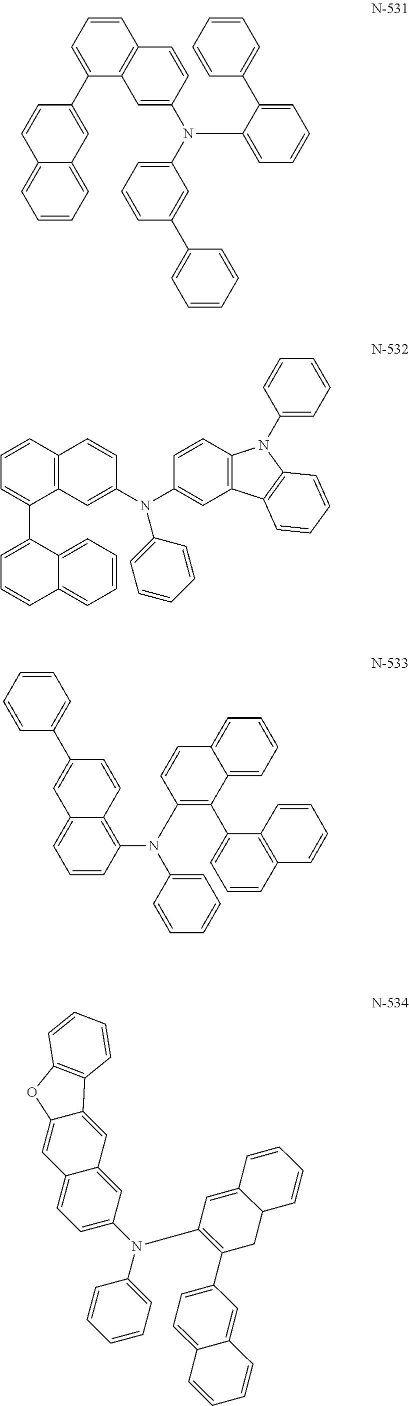 [SMILES: c1ccc(-c2cccc(N(c3ccc4cccc(-c5ccc6ccccc6c5)c4c3)c3ccccc3-c3ccccc3)c2)cc1 ; c1ccc(N(c2ccc3cccc(-c4cccc5ccccc45)c3c2)c2ccc3c(c2)c2ccccc2n3-c2ccccc2)cc1 ; c1ccc(-c2ccc3c(N(c4ccccc4)c4ccc5ccccc5c4-c4cccc5ccccc45)cccc3c2)cc1 ; C1=CC2=CC(N(c3ccccc3)c3ccc4cc5oc6ccccc6c5cc4c3)=C(c3ccc4ccccc4c3)CC2C=C1]

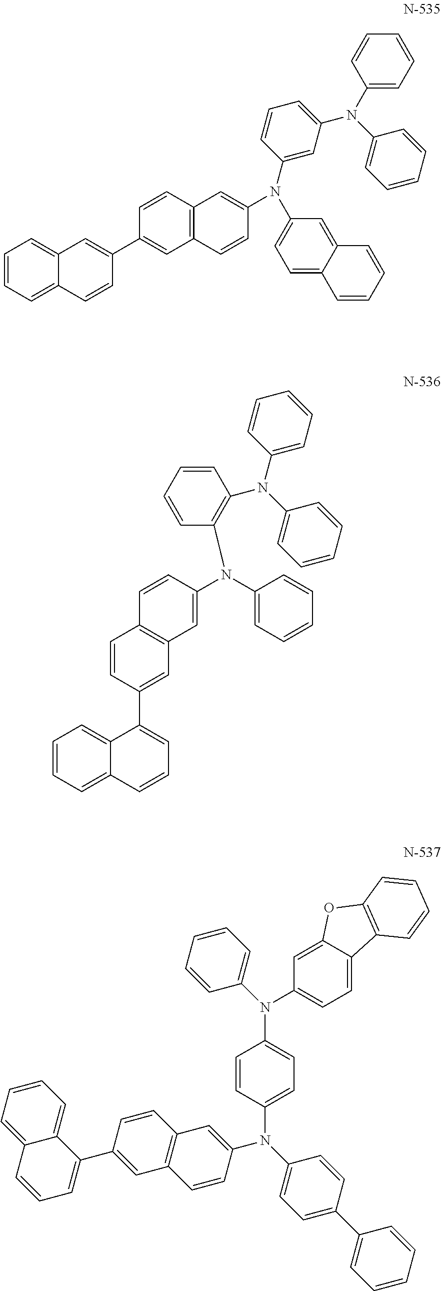 [SMILES: c1ccc(N(c2ccccc2)c2cccc(N(c3ccc4ccccc4c3)c3ccc4cc(-c5ccc6ccccc6c5)ccc4c3)c2)cc1 ; c1ccc(N(c2ccccc2)c2ccccc2N(c2ccccc2)c2ccc3ccc(-c4cccc5ccccc45)cc3c2)cc1 ; c1ccc(-c2ccc(N(c3ccc(N(c4ccccc4)c4ccc5c(c4)oc4ccccc45)cc3)c3ccc4cc(-c5cccc6ccccc56)ccc4c3)cc2)cc1]

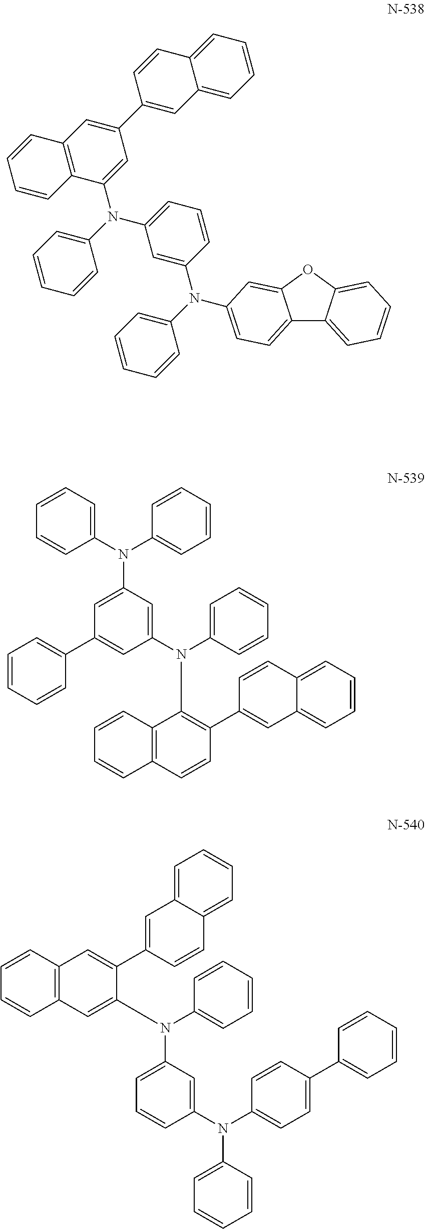 [SMILES: c1ccc(N(c2cccc(N(c3ccccc3)c3cc(-c4ccc5ccccc5c4)cc4ccccc34)c2)c2ccc3c(c2)oc2ccccc23)cc1 ; c1ccc(-c2cc(N(c3ccccc3)c3ccccc3)cc(N(c3ccccc3)c3c(-c4ccc5ccccc5c4)ccc4ccccc34)c2)cc1 ; c1ccc(-c2ccc(N(c3ccccc3)c3cccc(N(c4ccccc4)c4cc5ccccc5cc4-c4ccc5ccccc5c4)c3)cc2)cc1]

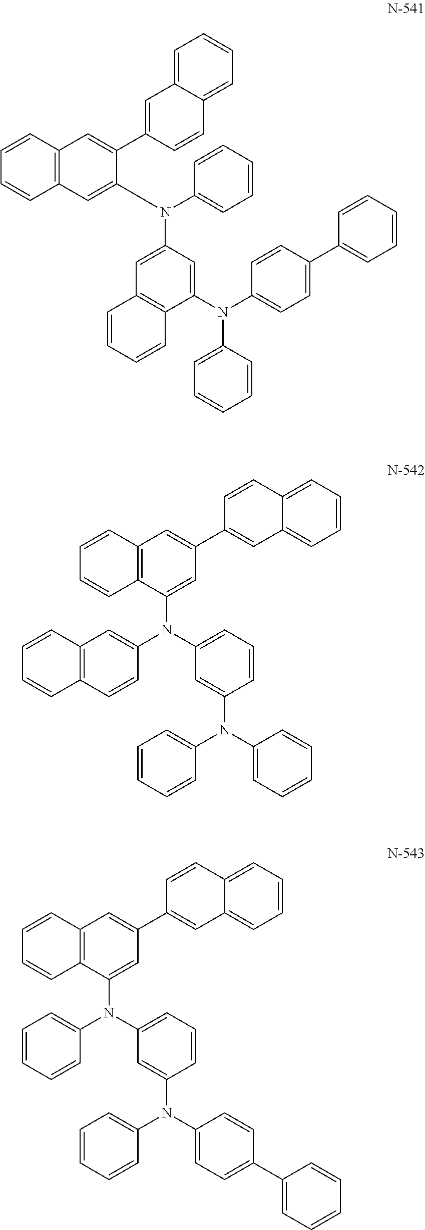 [SMILES: c1ccc(-c2ccc(N(c3ccccc3)c3cc(N(c4ccccc4)c4cc5ccccc5cc4-c4ccc5ccccc5c4)cc4ccccc34)cc2)cc1 ; c1ccc(N(c2ccccc2)c2cccc(N(c3ccc4ccccc4c3)c3cc(-c4ccc5ccccc5c4)cc4ccccc34)c2)cc1 ; c1ccc(-c2ccc(N(c3ccccc3)c3cccc(N(c4ccccc4)c4cc(-c5ccc6ccccc6c5)cc5ccccc45)c3)cc2)cc1]

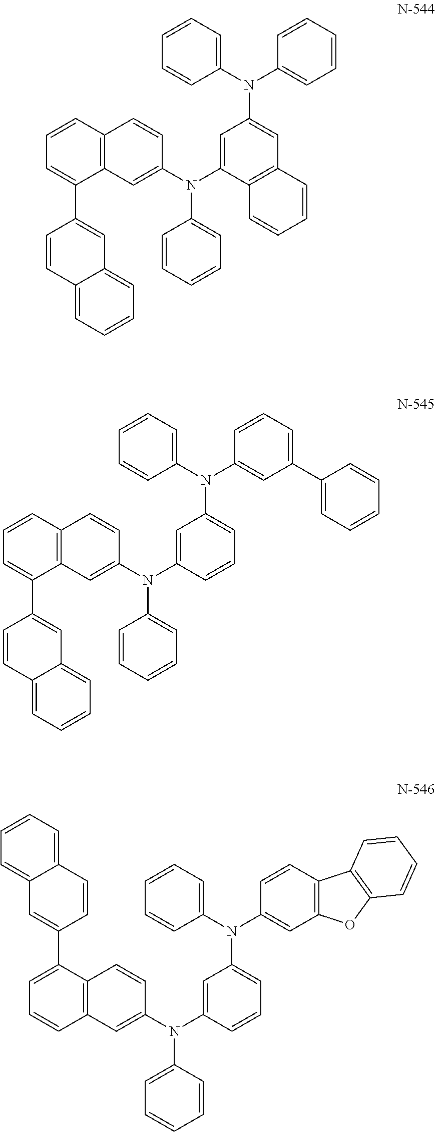 [SMILES: c1ccc(N(c2ccccc2)c2cc(N(c3ccccc3)c3ccc4cccc(-c5ccc6ccccc6c5)c4c3)c3ccccc3c2)cc1 ; c1ccc(-c2cccc(N(c3ccccc3)c3cccc(N(c4ccccc4)c4ccc5cccc(-c6ccc7ccccc7c6)c5c4)c3)c2)cc1 ; c1ccc(N(c2cccc(N(c3ccccc3)c3ccc4c(c3)oc3ccccc34)c2)c2ccc3c(-c4ccc5ccccc5c4)cccc3c2)cc1]

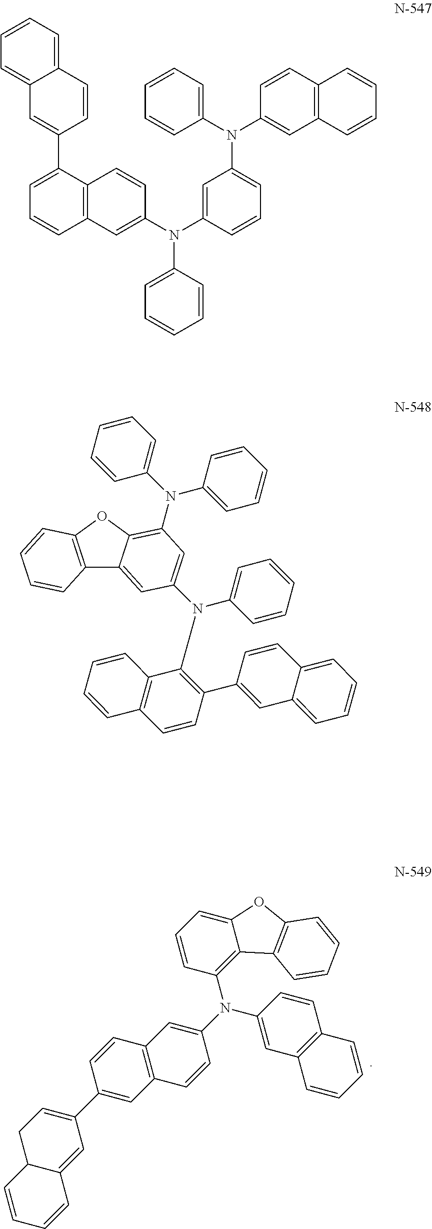 [SMILES: c1ccc(N(c2cccc(N(c3ccccc3)c3ccc4c(-c5ccc6ccccc6c5)cccc4c3)c2)c2ccc3ccccc3c2)cc1 ; c1ccc(N(c2cc(N(c3ccccc3)c3ccccc3)c3oc4ccccc4c3c2)c2c(-c3ccc4ccccc4c3)ccc3ccccc23)cc1 ; C1=CC2=CC(c3ccc4cc(N(c5ccc6ccccc6c5)c5cccc6oc7ccccc7c56)ccc4c3)=CCC2C=C1]

11. The organic electroluminescent material composition according to claim 1, wherein the compound M has the structure shown in any one of Formula 2-1 to Formula 2-28: 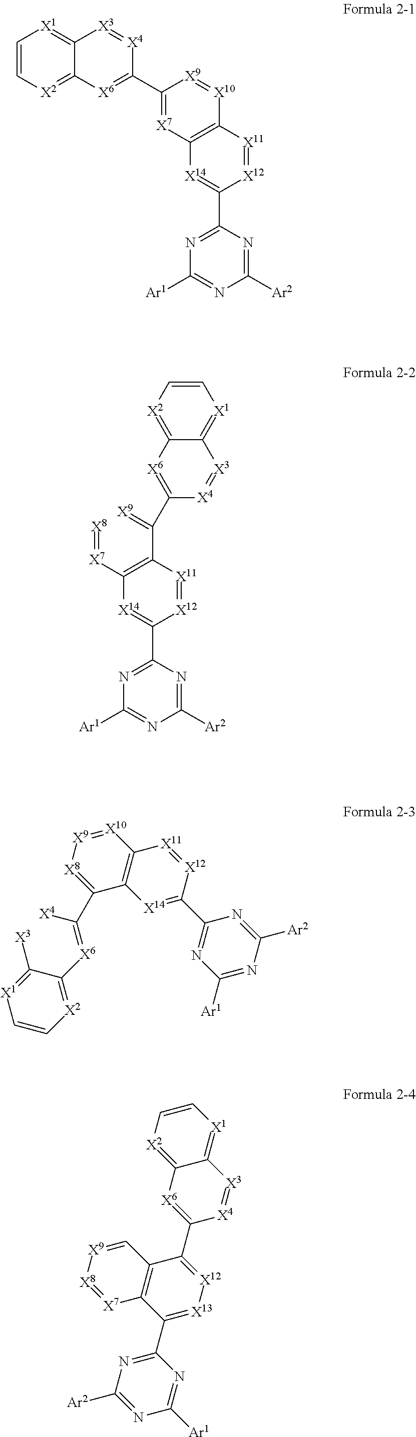 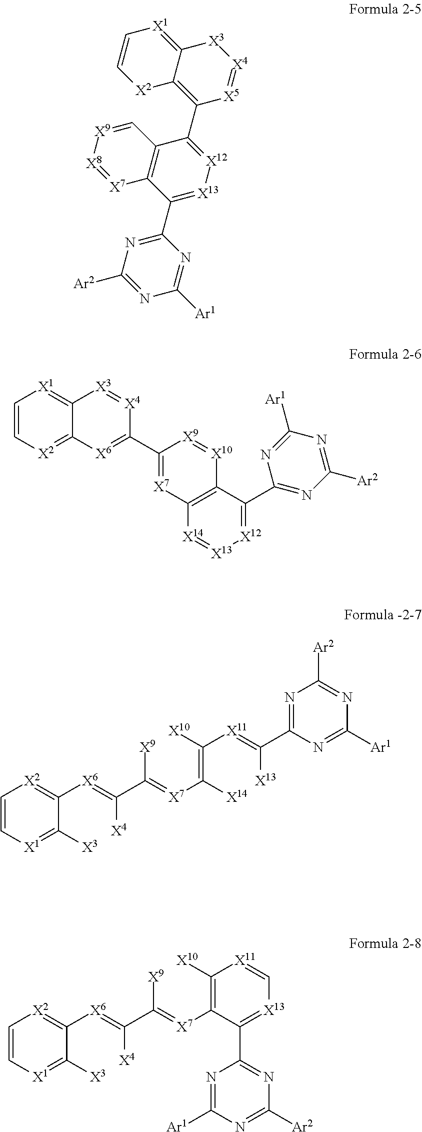 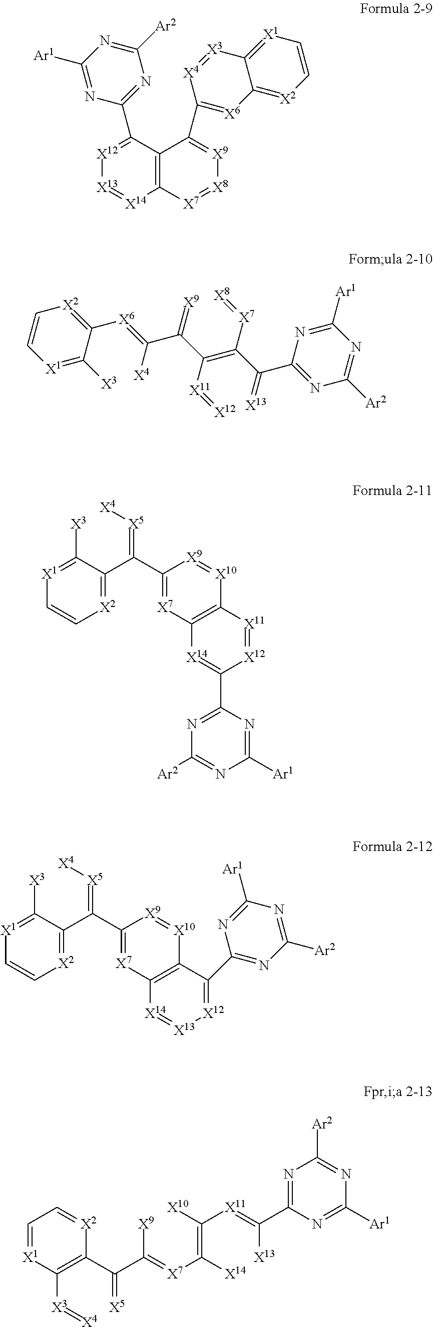 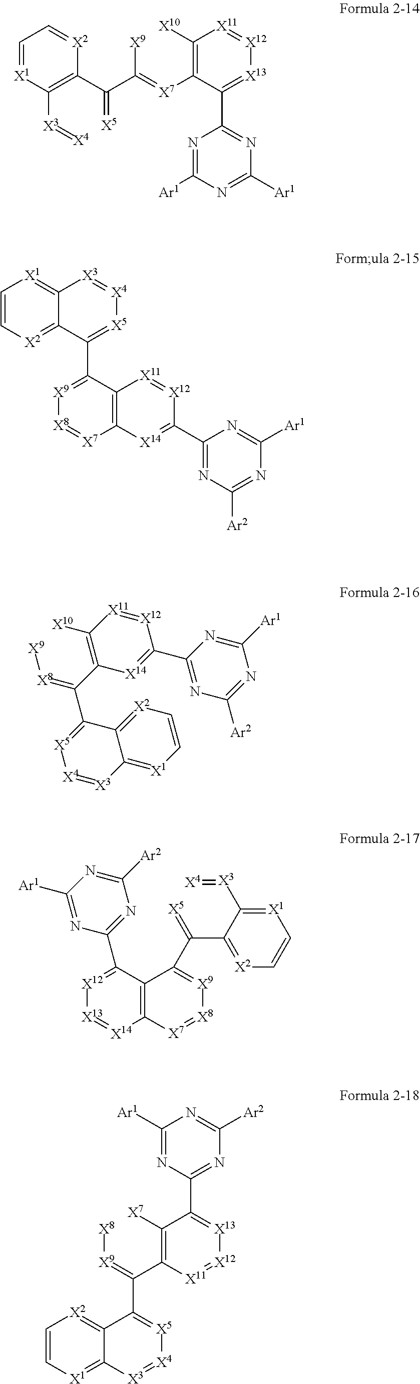 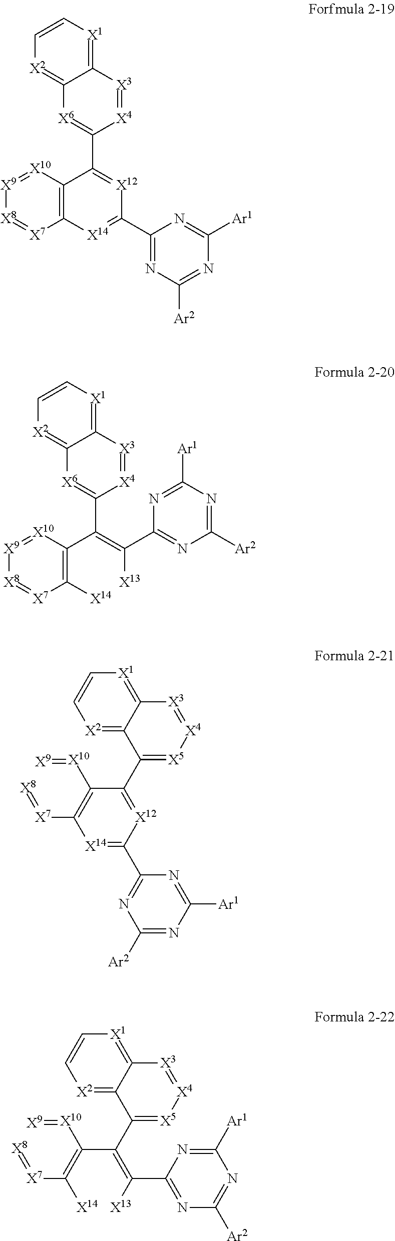 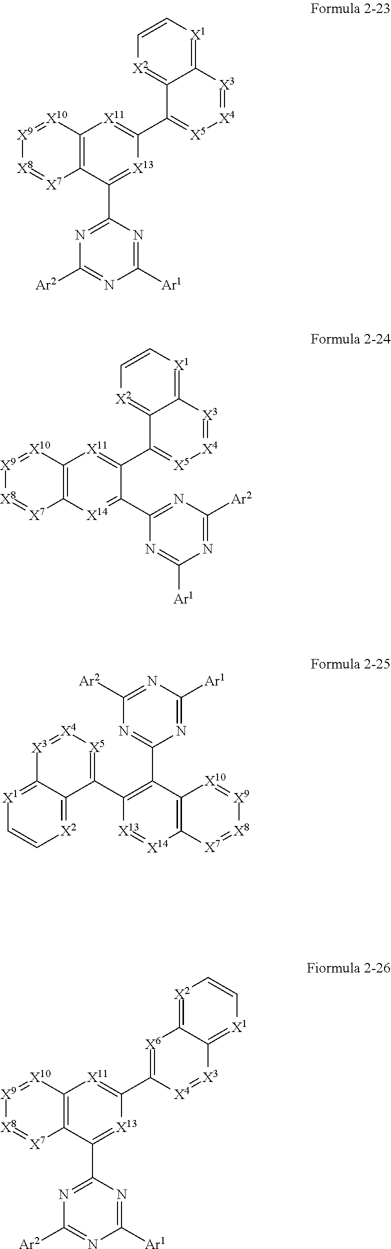 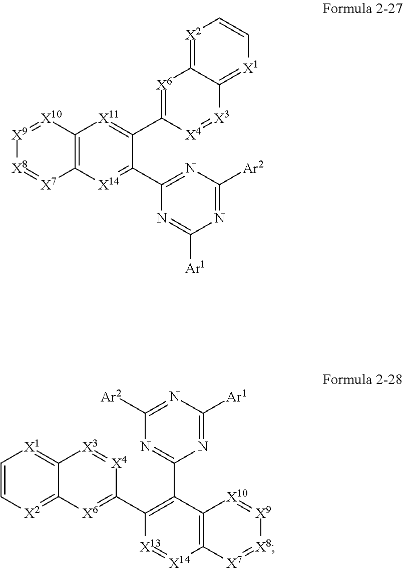
wherein Ar³-Ar⁴ is independently selected from phenyl, naphthyl, biphenyl, triphenyl, phenanthryl, fluoranthenyl, triphenylenyl, fluorenyl, dimethylfluorenyl, diphenylfluorenyl, spirobifluorenyl, benzodimethylfluorenyl, benzodiphenylfluorenyl, benzospirobifluorenyl, dibenzofuryl, naphthobenzofuryl, dibenzothienyl, naphthobenzothienyl, carbazolyl, phenylcarbazolyl, benzocarbazolyl, and dibenzocarbazolyl.

12. The organic electroluminescent material composition according to claim 1, wherein the structure of compound M is shown in any one of M-1 to M-619:

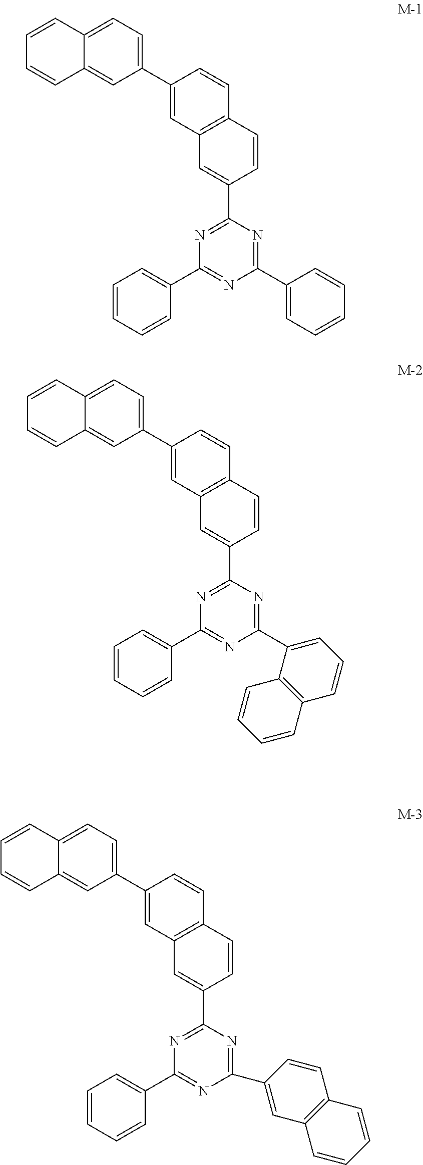 [SMILES: c1ccc(-c2nc(-c3ccccc3)nc(-c3ccc4ccc(-c5ccc6ccccc6c5)cc4c3)n2)cc1 ; c1ccc(-c2nc(-c3ccc4ccc(-c5ccc6ccccc6c5)cc4c3)nc(-c3cccc4ccccc34)n2)cc1 ; c1ccc(-c2nc(-c3ccc4ccccc4c3)nc(-c3ccc4ccc(-c5ccc6ccccc6c5)cc4c3)n2)cc1]

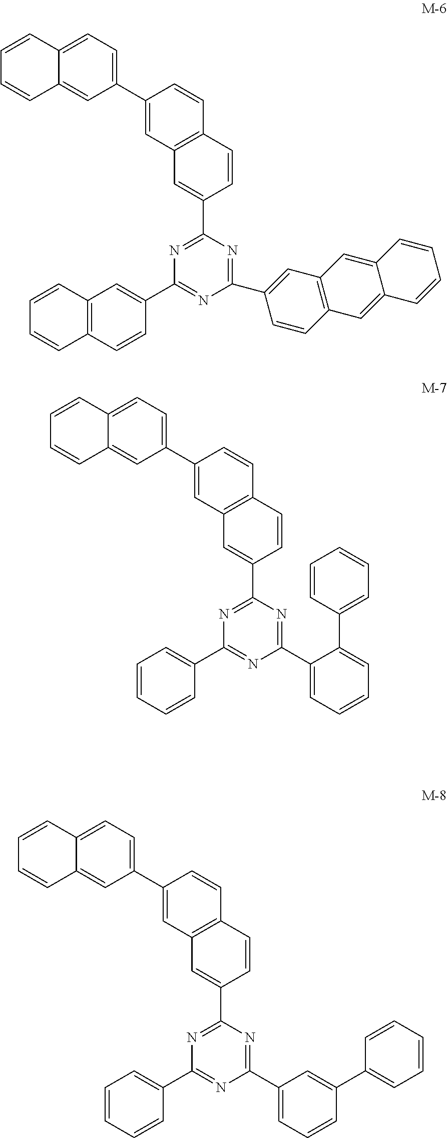 [SMILES: c1ccc2cc(-c3ccc4ccc(-c5nc(-c6ccc7ccccc7c6)nc(-c6ccc7cc8ccccc8cc7c6)n5)cc4c3)ccc2c1 ; c1ccc(-c2nc(-c3ccc4ccc(-c5ccc6ccccc6c5)cc4c3)nc(-c3ccccc3-c3ccccc3)n2)cc1 ; c1ccc(-c2cccc(-c3nc(-c4ccccc4)nc(-c4ccc5ccc(-c6ccc7ccccc7c6)cc5c4)n3)c2)cc1]

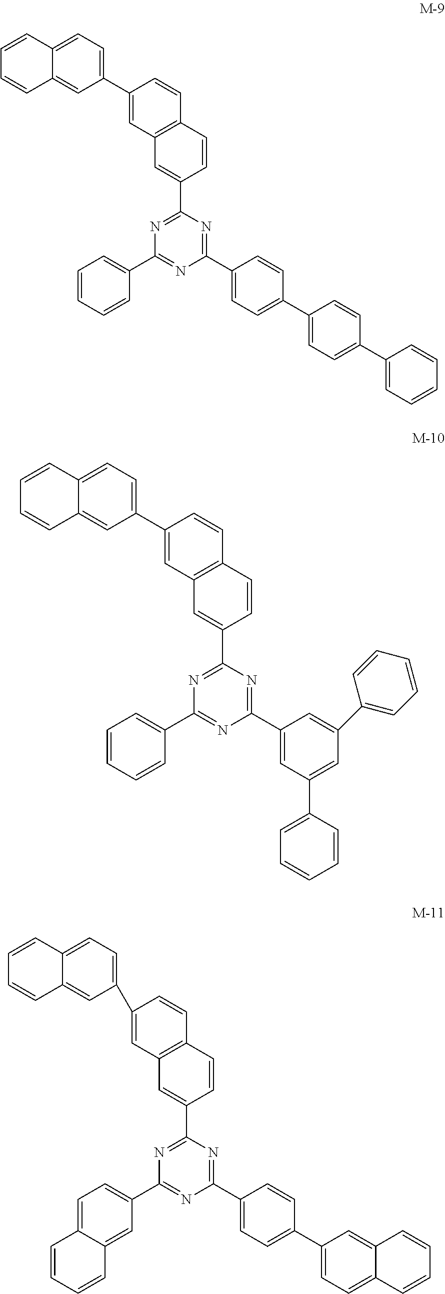 [SMILES: c1ccc(-c2ccc(-c3ccc(-c4nc(-c5ccccc5)nc(-c5ccc6ccc(-c7ccc8ccccc8c7)cc6c5)n4)cc3)cc2)cc1 ; c1ccc(-c2cc(-c3ccccc3)cc(-c3nc(-c4ccccc4)nc(-c4ccc5ccc(-c6ccc7ccccc7c6)cc5c4)n3)c2)cc1 ; c1ccc2cc(-c3ccc(-c4nc(-c5ccc6ccccc6c5)nc(-c5ccc6ccc(-c7ccc8ccccc8c7)cc6c5)n4)cc3)ccc2c1]

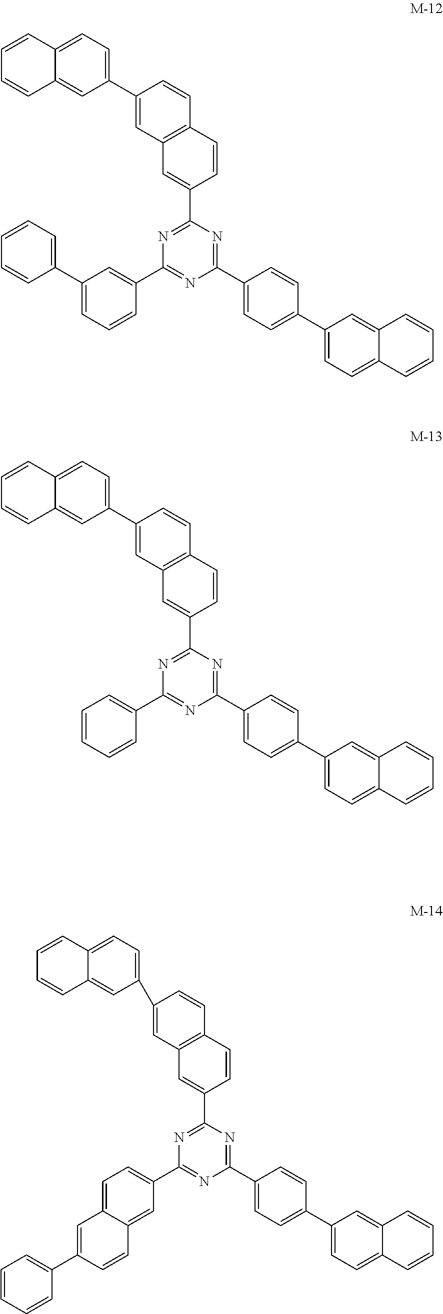 [SMILES: c1ccc(-c2cccc(-c3nc(-c4ccc(-c5ccc6ccccc6c5)cc4)nc(-c4ccc5ccc(-c6ccc7ccccc7c6)cc5c4)n3)c2)cc1 ; c1ccc(-c2nc(-c3ccc(-c4ccc5ccccc5c4)cc3)nc(-c3ccc4ccc(-c5ccc6ccccc6c5)cc4c3)n2)cc1 ; c1ccc(-c2ccc3cc(-c4nc(-c5ccc(-c6ccc7ccccc7c6)cc5)nc(-c5ccc6ccc(-c7ccc8ccccc8c7)cc6c5)n4)ccc3c2)cc1]

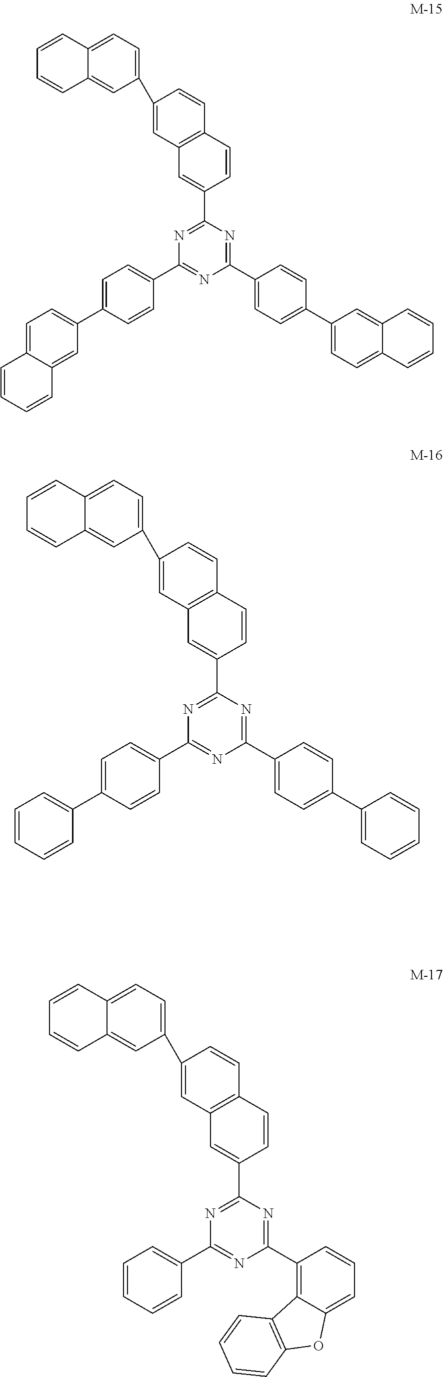 [SMILES: c1ccc2cc(-c3ccc(-c4nc(-c5ccc(-c6ccc7ccccc7c6)cc5)nc(-c5ccc6ccc(-c7ccc8ccccc8c7)cc6c5)n4)cc3)ccc2c1 ; c1ccc(-c2ccc(-c3nc(-c4ccc(-c5ccccc5)cc4)nc(-c4ccc5ccc(-c6ccc7ccccc7c6)cc5c4)n3)cc2)cc1 ; c1ccc(-c2nc(-c3ccc4ccc(-c5ccc6ccccc6c5)cc4c3)nc(-c3cccc4oc5ccccc5c34)n2)cc1]

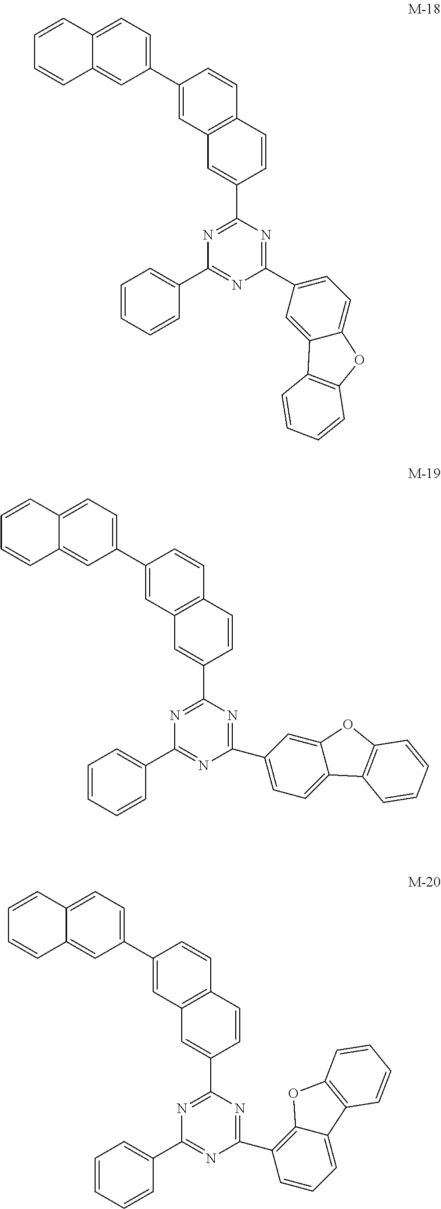 [SMILES: c1ccc(-c2nc(-c3ccc4ccc(-c5ccc6ccccc6c5)cc4c3)nc(-c3ccc4oc5ccccc5c4c3)n2)cc1 ; c1ccc(-c2nc(-c3ccc4ccc(-c5ccc6ccccc6c5)cc4c3)nc(-c3ccc4c(c3)oc3ccccc34)n2)cc1 ; c1ccc(-c2nc(-c3ccc4ccc(-c5ccc6ccccc6c5)cc4c3)nc(-c3cccc4c3oc3ccccc34)n2)cc1]

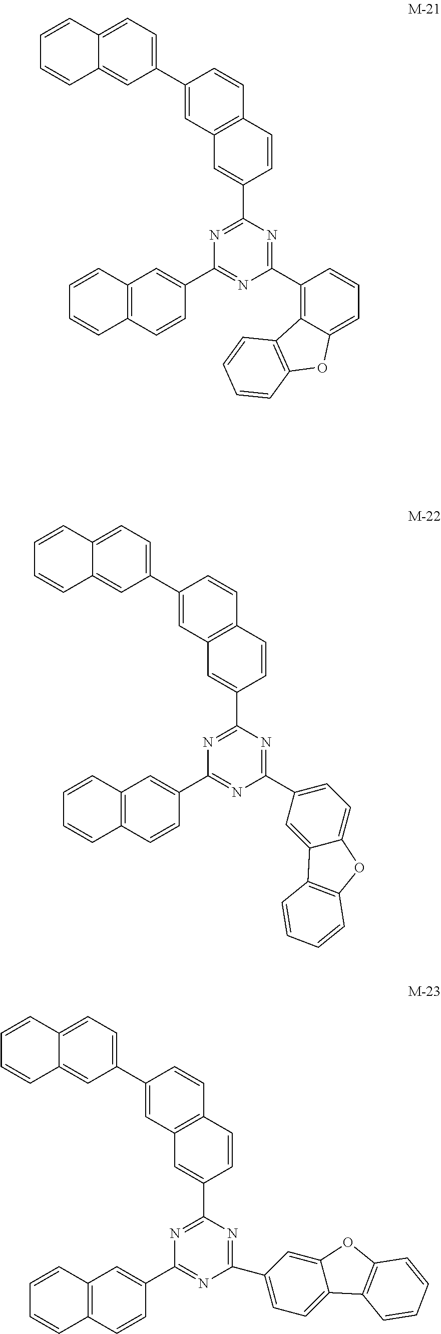 [SMILES: c1ccc2cc(-c3ccc4ccc(-c5nc(-c6ccc7ccccc7c6)nc(-c6cccc7oc8ccccc8c67)n5)cc4c3)ccc2c1 ; c1ccc2cc(-c3ccc4ccc(-c5nc(-c6ccc7ccccc7c6)nc(-c6ccc7oc8ccccc8c7c6)n5)cc4c3)ccc2c1 ; c1ccc2cc(-c3ccc4ccc(-c5nc(-c6ccc7ccccc7c6)nc(-c6ccc7c(c6)oc6ccccc67)n5)cc4c3)ccc2c1]

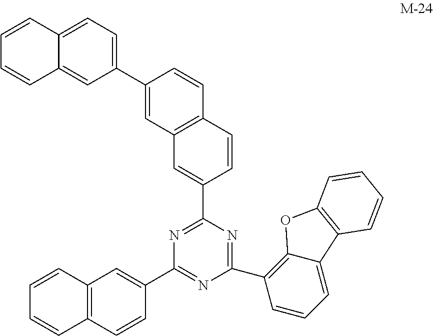 [SMILES: c1ccc2cc(-c3ccc4ccc(-c5nc(-c6ccc7ccccc7c6)nc(-c6cccc7c6oc6ccccc67)n5)cc4c3)ccc2c1]

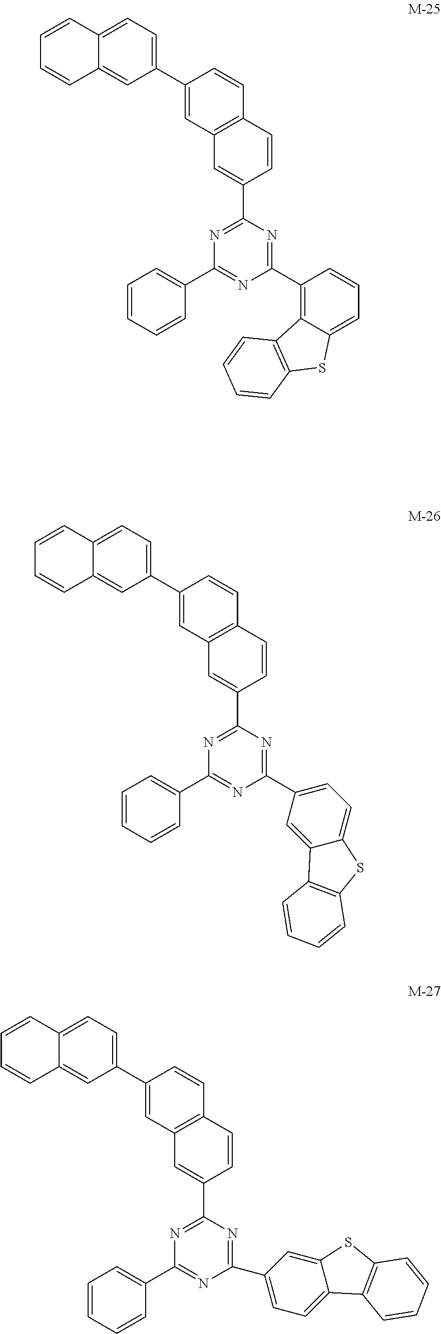 [SMILES: c1ccc(-c2nc(-c3ccc4ccc(-c5ccc6ccccc6c5)cc4c3)nc(-c3cccc4sc5ccccc5c34)n2)cc1 ; c1ccc(-c2nc(-c3ccc4ccc(-c5ccc6ccccc6c5)cc4c3)nc(-c3ccc4sc5ccccc5c4c3)n2)cc1 ; c1ccc(-c2nc(-c3ccc4ccc(-c5ccc6ccccc6c5)cc4c3)nc(-c3ccc4c(c3)sc3ccccc34)n2)cc1]

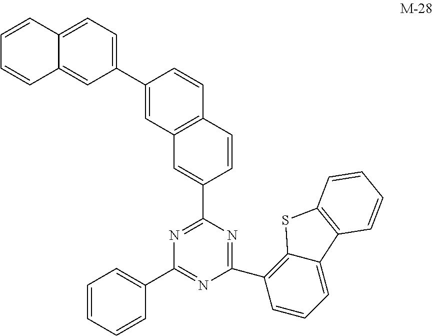 [SMILES: c1ccc(-c2nc(-c3ccc4ccc(-c5ccc6ccccc6c5)cc4c3)nc(-c3cccc4c3sc3ccccc34)n2)cc1]

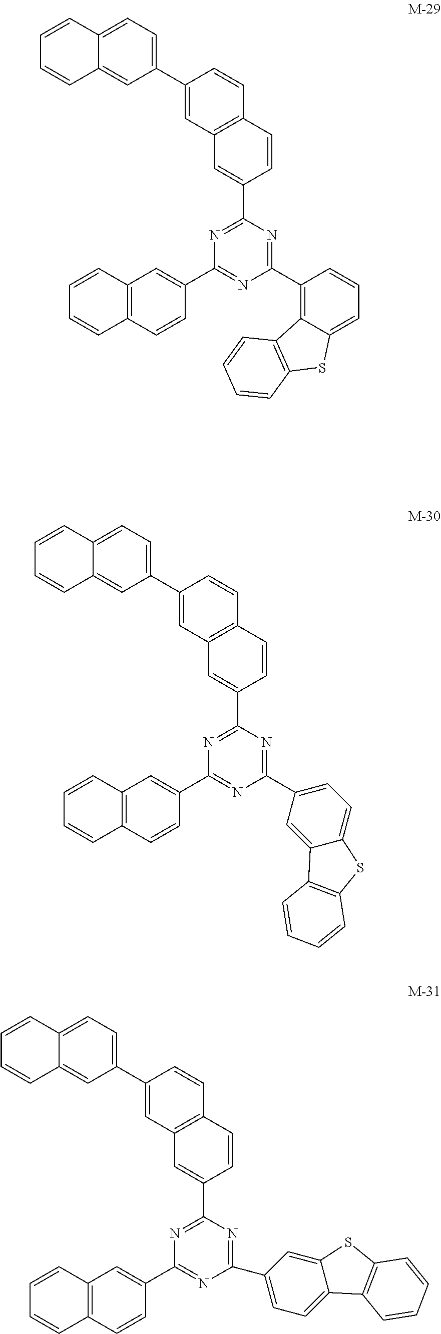 [SMILES: c1ccc2cc(-c3ccc4ccc(-c5nc(-c6ccc7ccccc7c6)nc(-c6cccc7sc8ccccc8c67)n5)cc4c3)ccc2c1 ; c1ccc2cc(-c3ccc4ccc(-c5nc(-c6ccc7ccccc7c6)nc(-c6ccc7sc8ccccc8c7c6)n5)cc4c3)ccc2c1 ; c1ccc2cc(-c3ccc4ccc(-c5nc(-c6ccc7ccccc7c6)nc(-c6ccc7c(c6)sc6ccccc67)n5)cc4c3)ccc2c1]

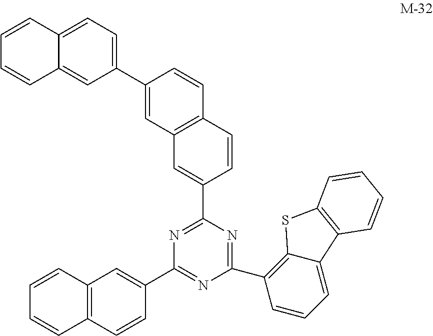 [SMILES: c1ccc2cc(-c3ccc4ccc(-c5nc(-c6ccc7ccccc7c6)nc(-c6cccc7c6sc6ccccc67)n5)cc4c3)ccc2c1]

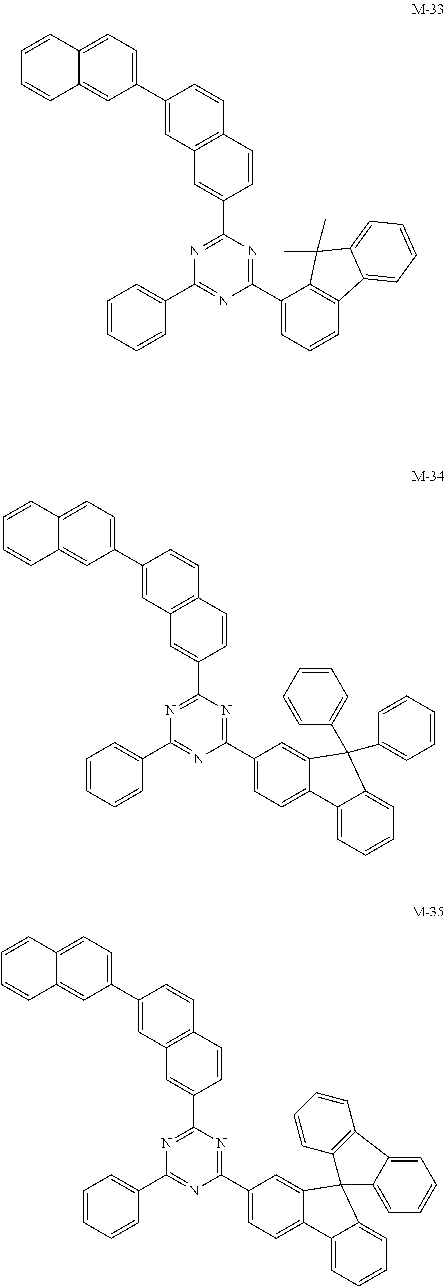 [SMILES: CC1(C)c2ccccc2-c2cccc(-c3nc(-c4ccccc4)nc(-c4ccc5ccc(-c6ccc7ccccc7c6)cc5c4)n3)c21 ; c1ccc(-c2nc(-c3ccc4c(c3)C(c3ccccc3)(c3ccccc3)c3ccccc3-4)nc(-c3ccc4ccc(-c5ccc6ccccc6c5)cc4c3)n2)cc1 ; c1ccc(-c2nc(-c3ccc4c(c3)C3(c5ccccc5-c5ccccc53)c3ccccc3-4)nc(-c3ccc4ccc(-c5ccc6ccccc6c5)cc4c3)n2)cc1]

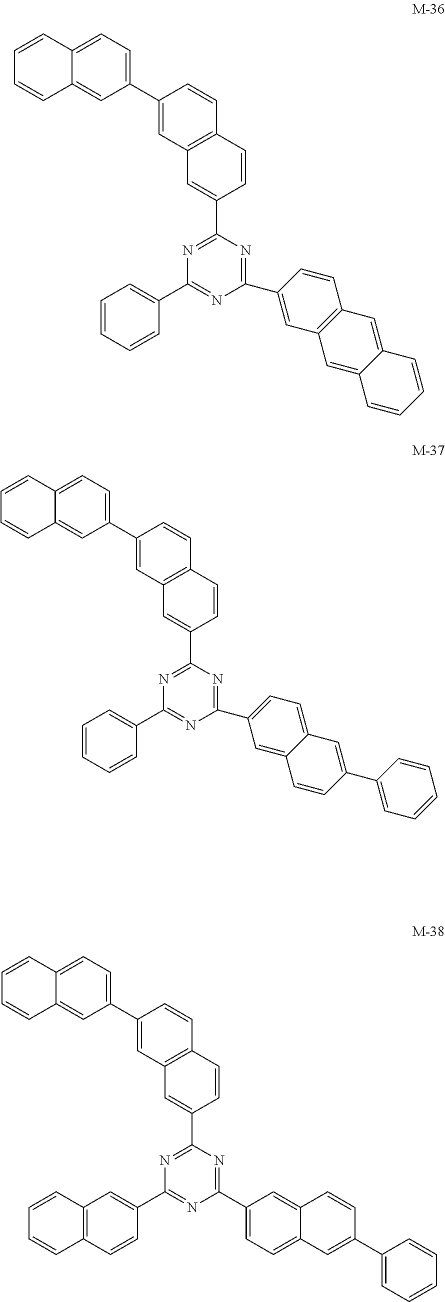 [SMILES: c1ccc(-c2nc(-c3ccc4ccc(-c5ccc6ccccc6c5)cc4c3)nc(-c3ccc4cc5ccccc5cc4c3)n2)cc1 ; c1ccc(-c2ccc3cc(-c4nc(-c5ccccc5)nc(-c5ccc6ccc(-c7ccc8ccccc8c7)cc6c5)n4)ccc3c2)cc1 ; c1ccc(-c2ccc3cc(-c4nc(-c5ccc6ccccc6c5)nc(-c5ccc6ccc(-c7ccc8ccccc8c7)cc6c5)n4)ccc3c2)cc1]

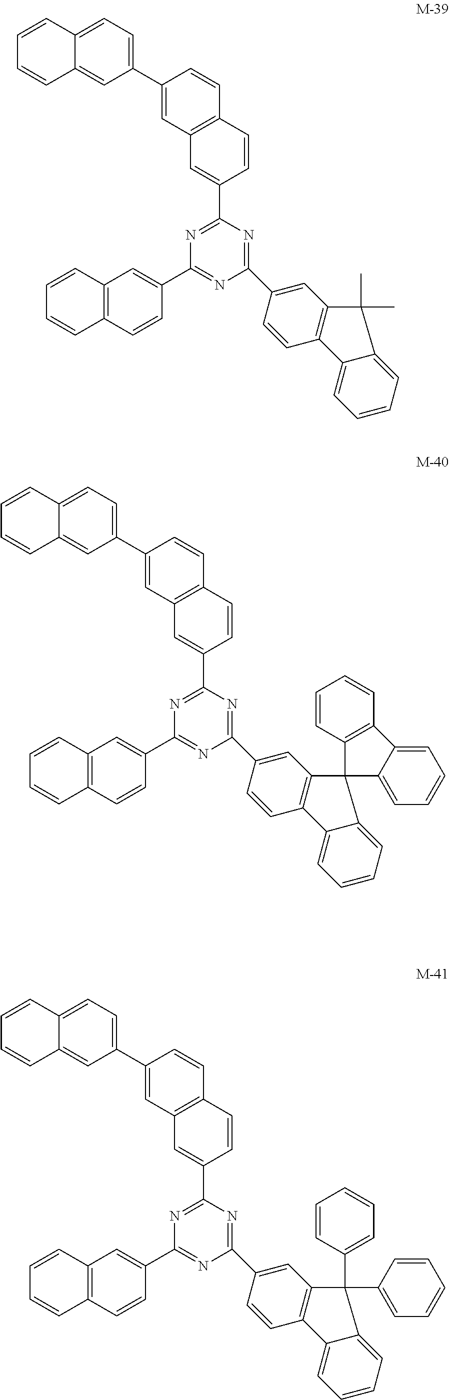 [SMILES: CC1(C)c2ccccc2-c2ccc(-c3nc(-c4ccc5ccccc5c4)nc(-c4ccc5ccc(-c6ccc7ccccc7c6)cc5c4)n3)cc21 ; c1ccc2c(c1)-c1ccccc1C21c2ccccc2-c2ccc(-c3nc(-c4ccc5ccccc5c4)nc(-c4ccc5ccc(-c6ccc7ccccc7c6)cc5c4)n3)cc21 ; c1ccc(C2(c3ccccc3)c3ccccc3-c3ccc(-c4nc(-c5ccc6ccccc6c5)nc(-c5ccc6ccc(-c7ccc8ccccc8c7)cc6c5)n4)cc32)cc1]

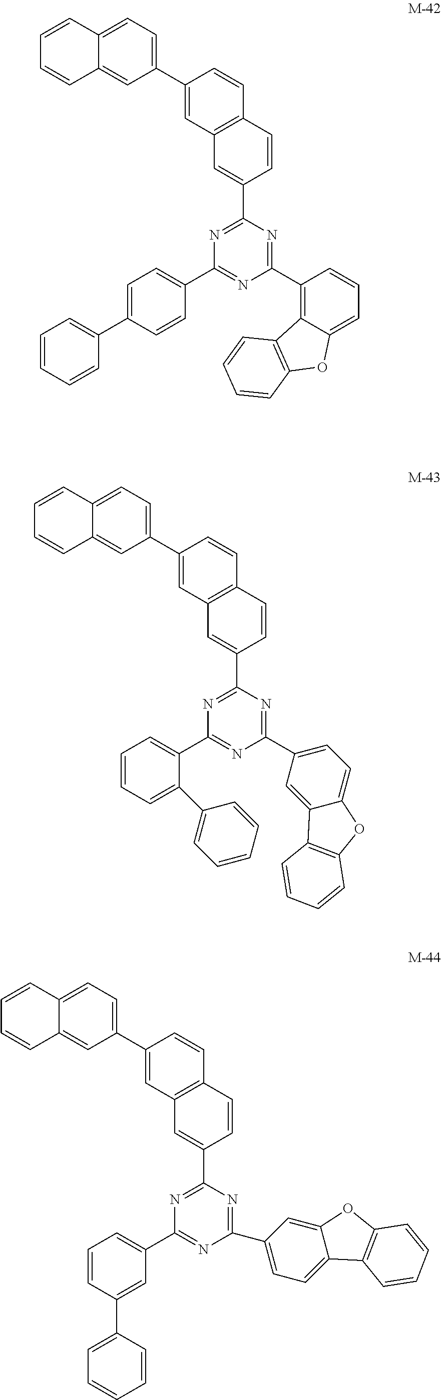 [SMILES: c1ccc(-c2ccc(-c3nc(-c4ccc5ccc(-c6ccc7ccccc7c6)cc5c4)nc(-c4cccc5oc6ccccc6c45)n3)cc2)cc1 ; c1ccc(-c2ccccc2-c2nc(-c3ccc4ccc(-c5ccc6ccccc6c5)cc4c3)nc(-c3ccc4oc5ccccc5c4c3)n2)cc1 ; c1ccc(-c2cccc(-c3nc(-c4ccc5ccc(-c6ccc7ccccc7c6)cc5c4)nc(-c4ccc5c(c4)oc4ccccc45)n3)c2)cc1]

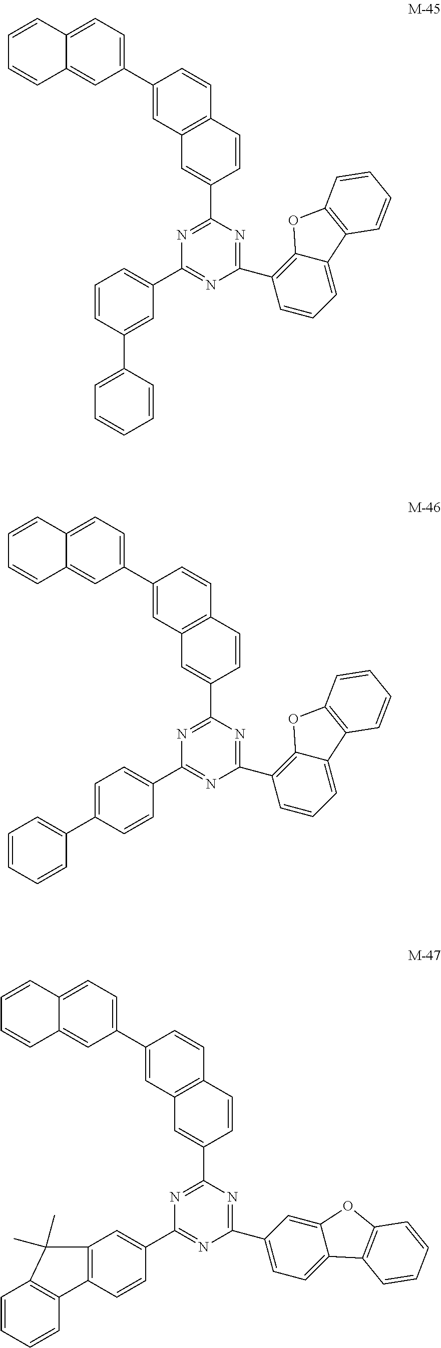 [SMILES: c1ccc(-c2cccc(-c3nc(-c4ccc5ccc(-c6ccc7ccccc7c6)cc5c4)nc(-c4cccc5c4oc4ccccc45)n3)c2)cc1 ; c1ccc(-c2ccc(-c3nc(-c4ccc5ccc(-c6ccc7ccccc7c6)cc5c4)nc(-c4cccc5c4oc4ccccc45)n3)cc2)cc1 ; CC1(C)c2ccccc2-c2ccc(-c3nc(-c4ccc5ccc(-c6ccc7ccccc7c6)cc5c4)nc(-c4ccc5c(c4)oc4ccccc45)n3)cc21]

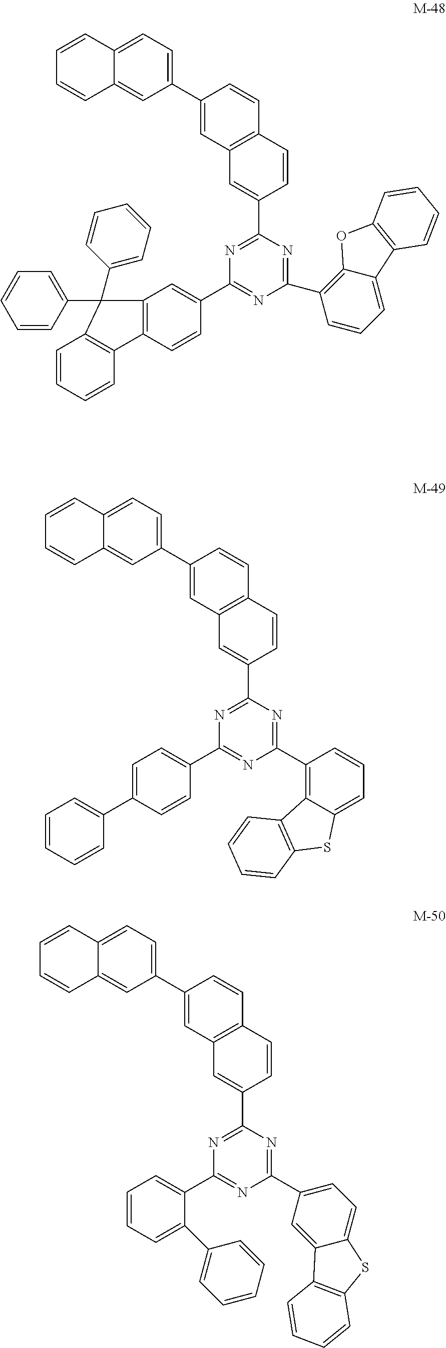 [SMILES: c1ccc(C2(c3ccccc3)c3ccccc3-c3ccc(-c4nc(-c5ccc6ccc(-c7ccc8ccccc8c7)cc6c5)nc(-c5cccc6c5oc5ccccc56)n4)cc32)cc1 ; c1ccc(-c2ccc(-c3nc(-c4ccc5ccc(-c6ccc7ccccc7c6)cc5c4)nc(-c4cccc5sc6ccccc6c45)n3)cc2)cc1 ; c1ccc(-c2ccccc2-c2nc(-c3ccc4ccc(-c5ccc6ccccc6c5)cc4c3)nc(-c3ccc4sc5ccccc5c4c3)n2)cc1]

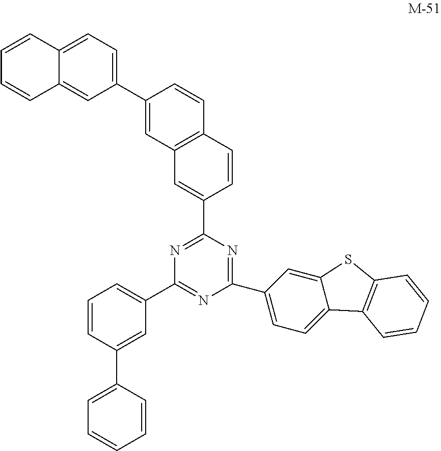 [SMILES: c1ccc(-c2cccc(-c3nc(-c4ccc5ccc(-c6ccc7ccccc7c6)cc5c4)nc(-c4ccc5c(c4)sc4ccccc45)n3)c2)cc1]

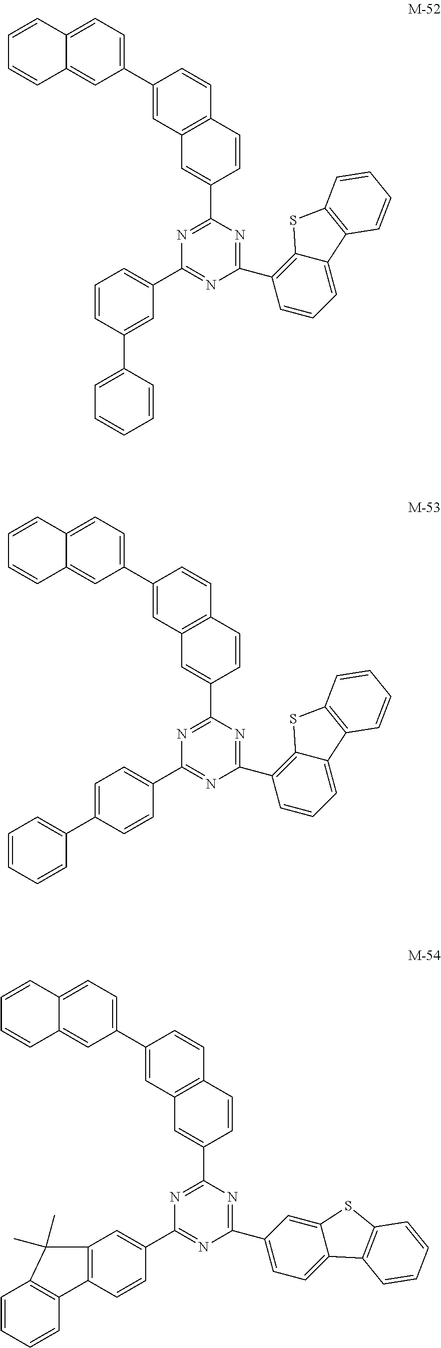 [SMILES: c1ccc(-c2cccc(-c3nc(-c4ccc5ccc(-c6ccc7ccccc7c6)cc5c4)nc(-c4cccc5c4sc4ccccc45)n3)c2)cc1 ; c1ccc(-c2ccc(-c3nc(-c4ccc5ccc(-c6ccc7ccccc7c6)cc5c4)nc(-c4cccc5c4sc4ccccc45)n3)cc2)cc1 ; CC1(C)c2ccccc2-c2ccc(-c3nc(-c4ccc5ccc(-c6ccc7ccccc7c6)cc5c4)nc(-c4ccc5c(c4)sc4ccccc45)n3)cc21]

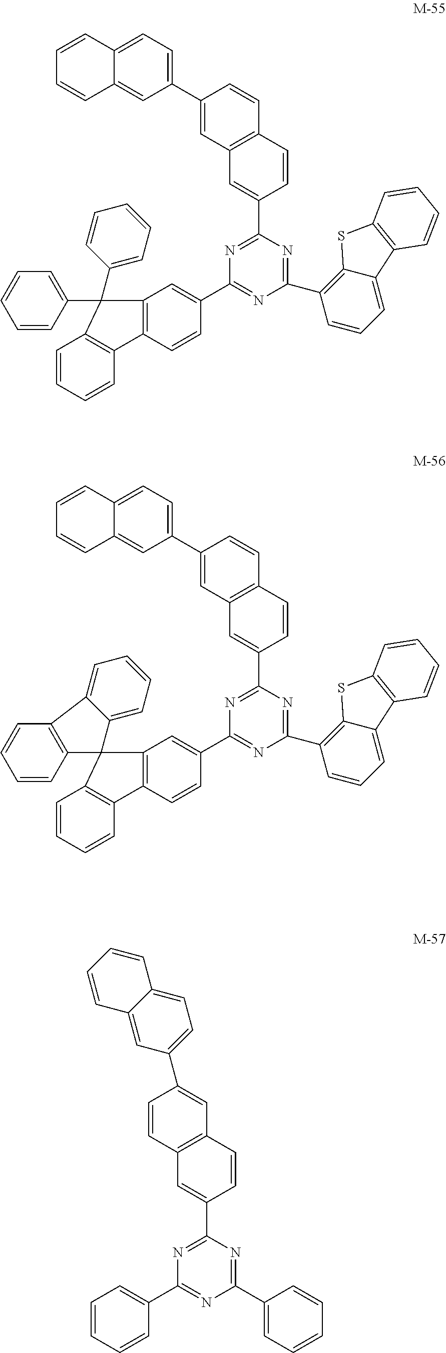 [SMILES: c1ccc(C2(c3ccccc3)c3ccccc3-c3ccc(-c4nc(-c5ccc6ccc(-c7ccc8ccccc8c7)cc6c5)nc(-c5cccc6c5sc5ccccc56)n4)cc32)cc1 ; c1ccc2c(c1)-c1ccccc1C21c2ccccc2-c2ccc(-c3nc(-c4ccc5ccc(-c6ccc7ccccc7c6)cc5c4)nc(-c4cccc5c4sc4ccccc45)n3)cc21 ; c1ccc(-c2nc(-c3ccccc3)nc(-c3ccc4cc(-c5ccc6ccccc6c5)ccc4c3)n2)cc1]

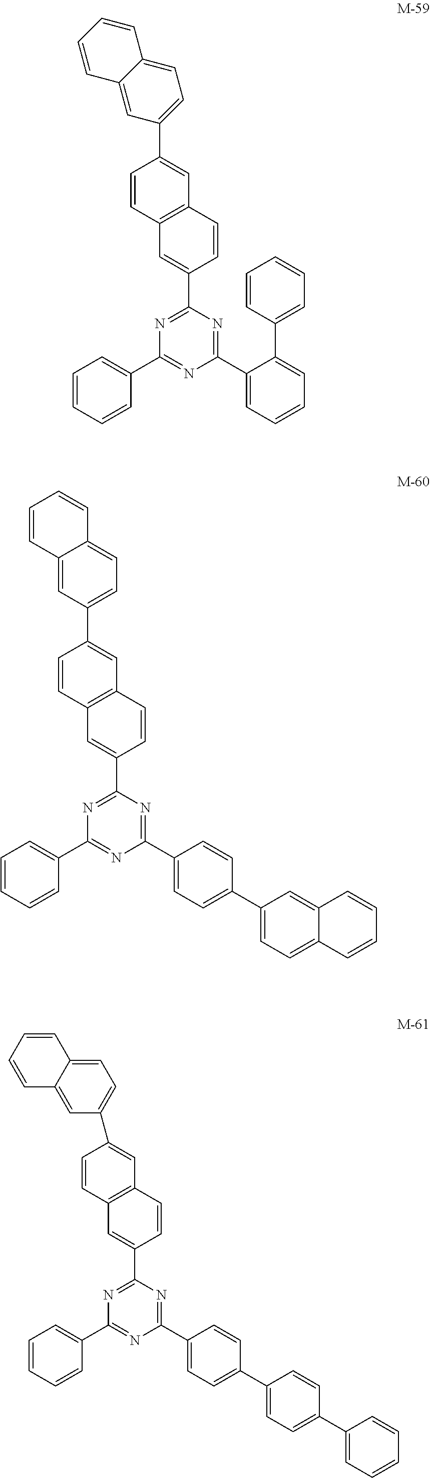 [SMILES: c1ccc(-c2nc(-c3ccc4cc(-c5ccc6ccccc6c5)ccc4c3)nc(-c3ccccc3-c3ccccc3)n2)cc1 ; c1ccc(-c2nc(-c3ccc(-c4ccc5ccccc5c4)cc3)nc(-c3ccc4cc(-c5ccc6ccccc6c5)ccc4c3)n2)cc1 ; c1ccc(-c2ccc(-c3ccc(-c4nc(-c5ccccc5)nc(-c5ccc6cc(-c7ccc8ccccc8c7)ccc6c5)n4)cc3)cc2)cc1]

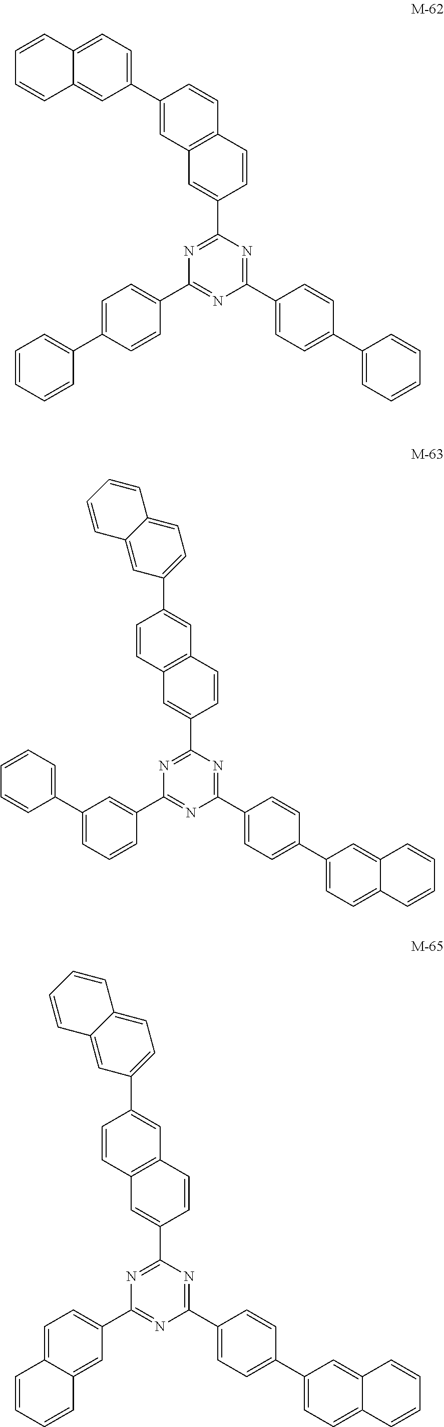 [SMILES: c1ccc(-c2ccc(-c3nc(-c4ccc(-c5ccccc5)cc4)nc(-c4ccc5ccc(-c6ccc7ccccc7c6)cc5c4)n3)cc2)cc1 ; c1ccc(-c2cccc(-c3nc(-c4ccc(-c5ccc6ccccc6c5)cc4)nc(-c4ccc5cc(-c6ccc7ccccc7c6)ccc5c4)n3)c2)cc1 ; c1ccc2cc(-c3ccc(-c4nc(-c5ccc6ccccc6c5)nc(-c5ccc6cc(-c7ccc8ccccc8c7)ccc6c5)n4)cc3)ccc2c1]

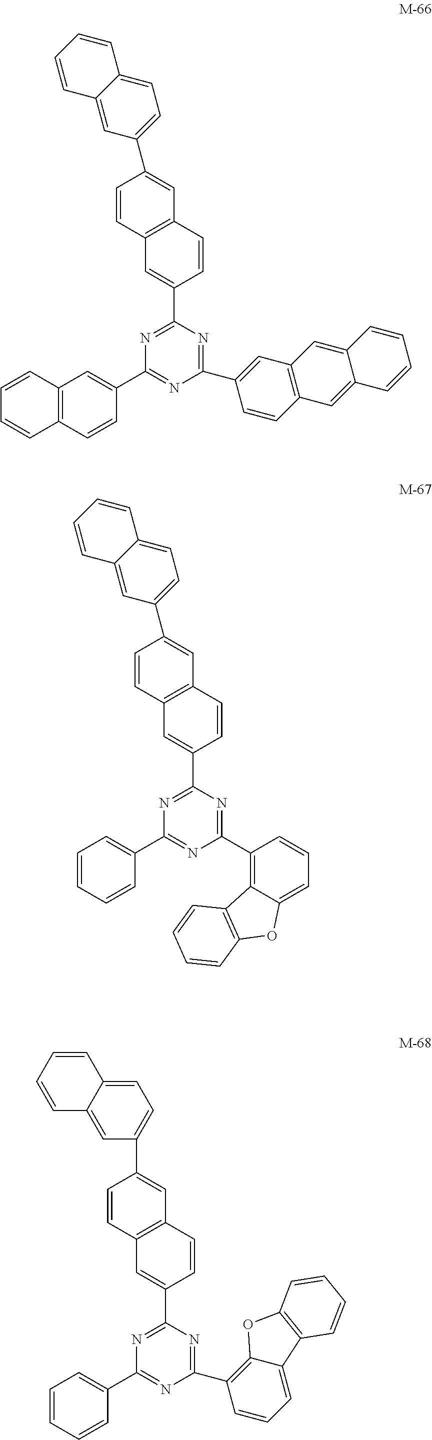 [SMILES: c1ccc2cc(-c3ccc4cc(-c5nc(-c6ccc7ccccc7c6)nc(-c6ccc7cc8ccccc8cc7c6)n5)ccc4c3)ccc2c1 ; c1ccc(-c2nc(-c3ccc4cc(-c5ccc6ccccc6c5)ccc4c3)nc(-c3cccc4oc5ccccc5c34)n2)cc1 ; c1ccc(-c2nc(-c3ccc4cc(-c5ccc6ccccc6c5)ccc4c3)nc(-c3cccc4c3oc3ccccc34)n2)cc1]

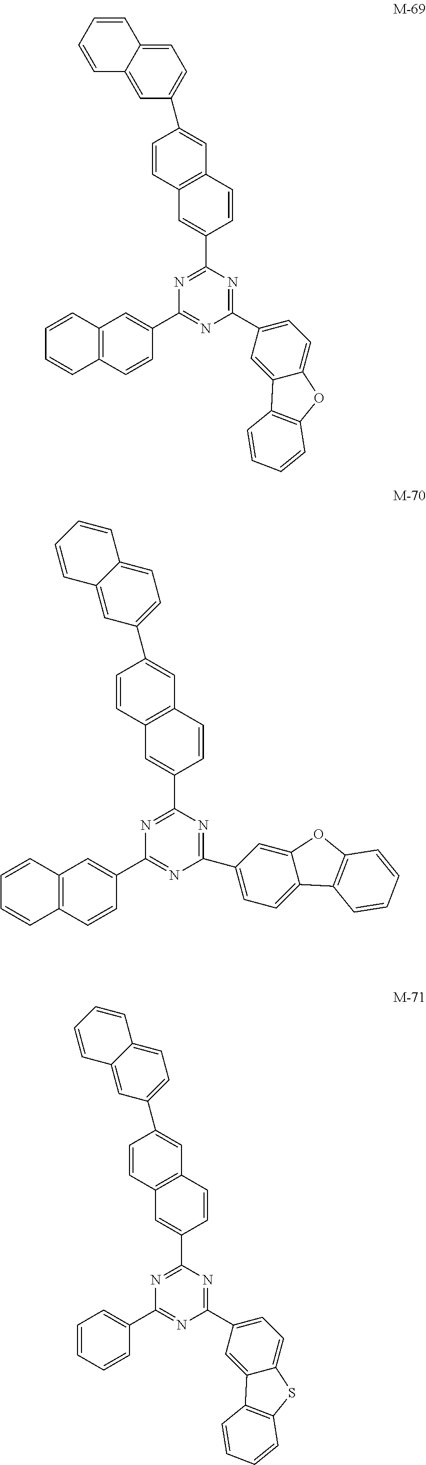 [SMILES: c1ccc2cc(-c3ccc4cc(-c5nc(-c6ccc7ccccc7c6)nc(-c6ccc7oc8ccccc8c7c6)n5)ccc4c3)ccc2c1 ; c1ccc2cc(-c3ccc4cc(-c5nc(-c6ccc7ccccc7c6)nc(-c6ccc7c(c6)oc6ccccc67)n5)ccc4c3)ccc2c1 ; c1ccc(-c2nc(-c3ccc4cc(-c5ccc6ccccc6c5)ccc4c3)nc(-c3ccc4sc5ccccc5c4c3)n2)cc1]

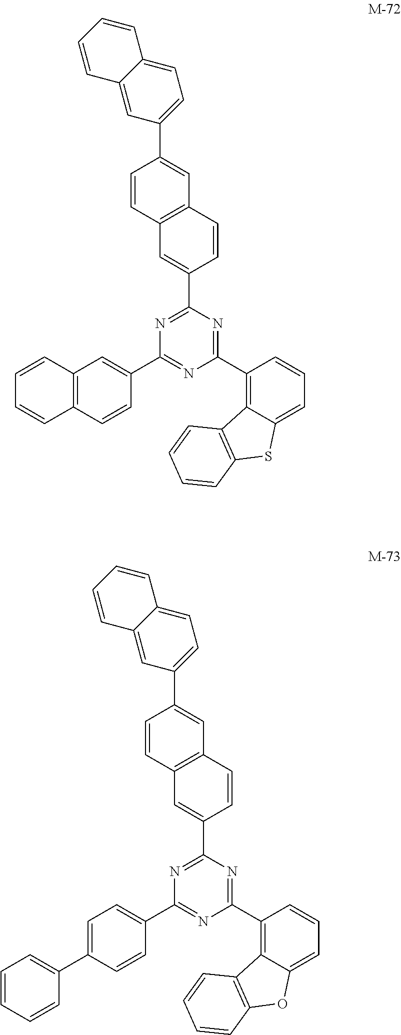 [SMILES: c1ccc2cc(-c3ccc4cc(-c5nc(-c6ccc7ccccc7c6)nc(-c6cccc7sc8ccccc8c67)n5)ccc4c3)ccc2c1 ; c1ccc(-c2ccc(-c3nc(-c4ccc5cc(-c6ccc7ccccc7c6)ccc5c4)nc(-c4cccc5oc6ccccc6c45)n3)cc2)cc1]

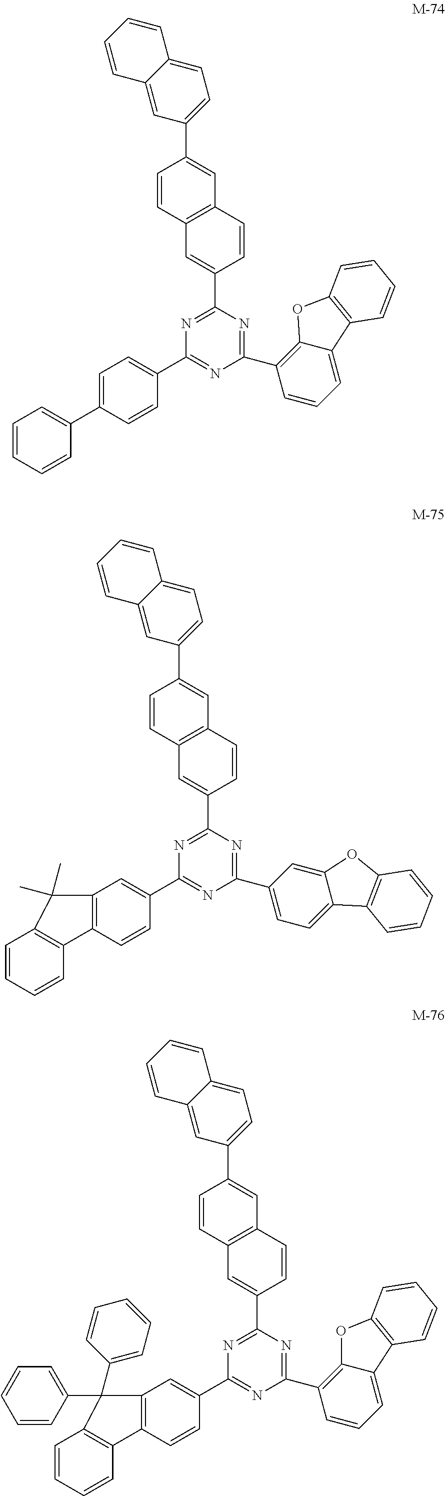 [SMILES: c1ccc(-c2ccc(-c3nc(-c4ccc5cc(-c6ccc7ccccc7c6)ccc5c4)nc(-c4cccc5c4oc4ccccc45)n3)cc2)cc1 ; CC1(C)c2ccccc2-c2ccc(-c3nc(-c4ccc5cc(-c6ccc7ccccc7c6)ccc5c4)nc(-c4ccc5c(c4)oc4ccccc45)n3)cc21 ; c1ccc(C2(c3ccccc3)c3ccccc3-c3ccc(-c4nc(-c5ccc6cc(-c7ccc8ccccc8c7)ccc6c5)nc(-c5cccc6c5oc5ccccc56)n4)cc32)cc1]

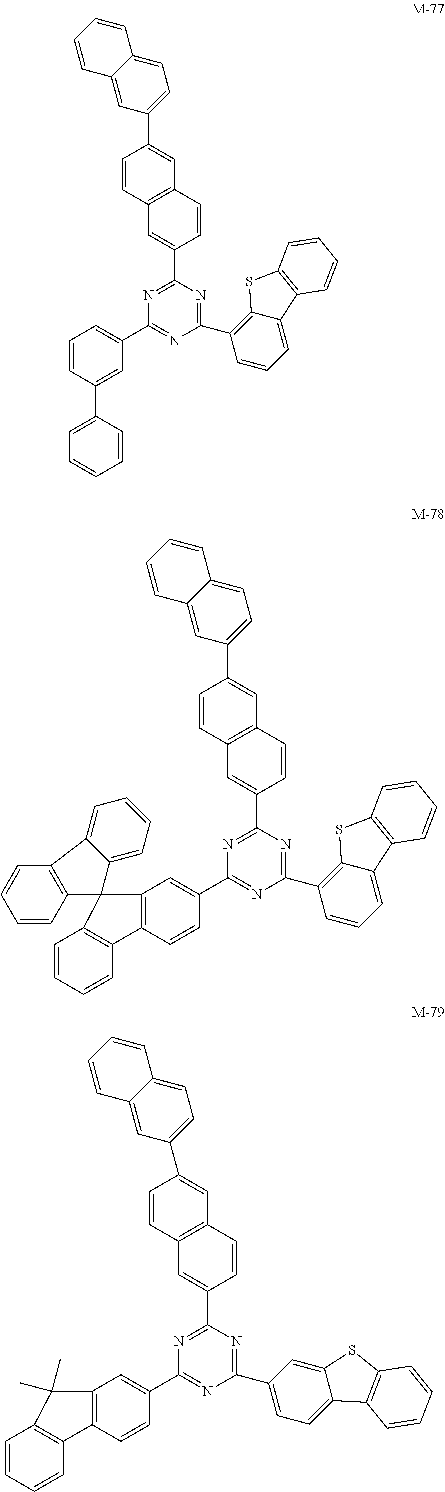 [SMILES: c1ccc(-c2cccc(-c3nc(-c4ccc5cc(-c6ccc7ccccc7c6)ccc5c4)nc(-c4cccc5c4sc4ccccc45)n3)c2)cc1 ; c1ccc2c(c1)-c1ccccc1C21c2ccccc2-c2ccc(-c3nc(-c4ccc5cc(-c6ccc7ccccc7c6)ccc5c4)nc(-c4cccc5c4sc4ccccc45)n3)cc21 ; CC1(C)c2ccccc2-c2ccc(-c3nc(-c4ccc5cc(-c6ccc7ccccc7c6)ccc5c4)nc(-c4ccc5c(c4)sc4ccccc45)n3)cc21]

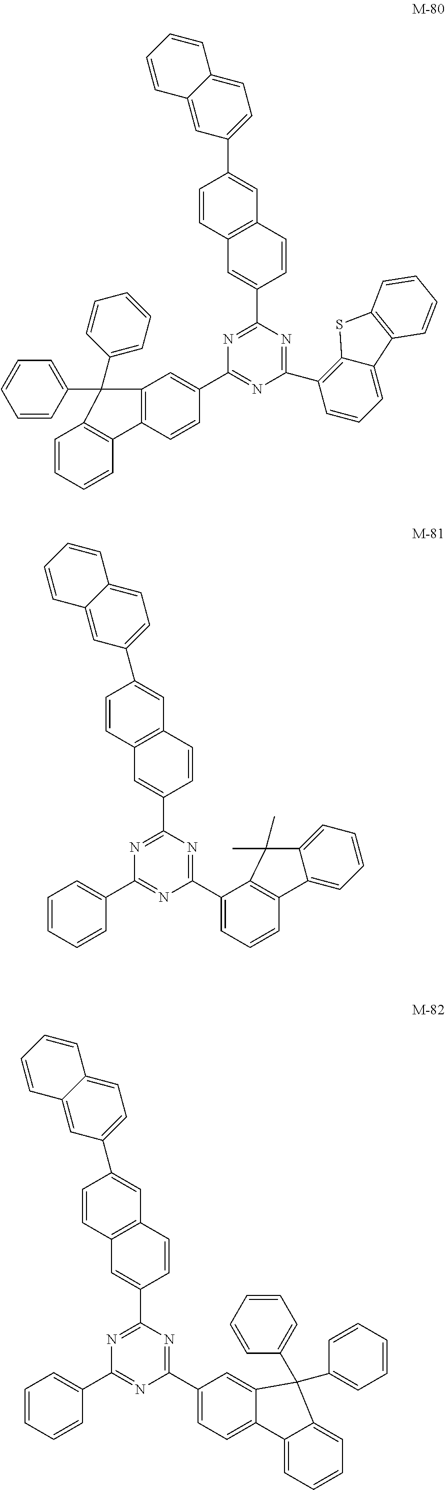 [SMILES: c1ccc(C2(c3ccccc3)c3ccccc3-c3ccc(-c4nc(-c5ccc6cc(-c7ccc8ccccc8c7)ccc6c5)nc(-c5cccc6c5sc5ccccc56)n4)cc32)cc1 ; CC1(C)c2ccccc2-c2cccc(-c3nc(-c4ccccc4)nc(-c4ccc5cc(-c6ccc7ccccc7c6)ccc5c4)n3)c21 ; c1ccc(-c2nc(-c3ccc4c(c3)C(c3ccccc3)(c3ccccc3)c3ccccc3-4)nc(-c3ccc4cc(-c5ccc6ccccc6c5)ccc4c3)n2)cc1]

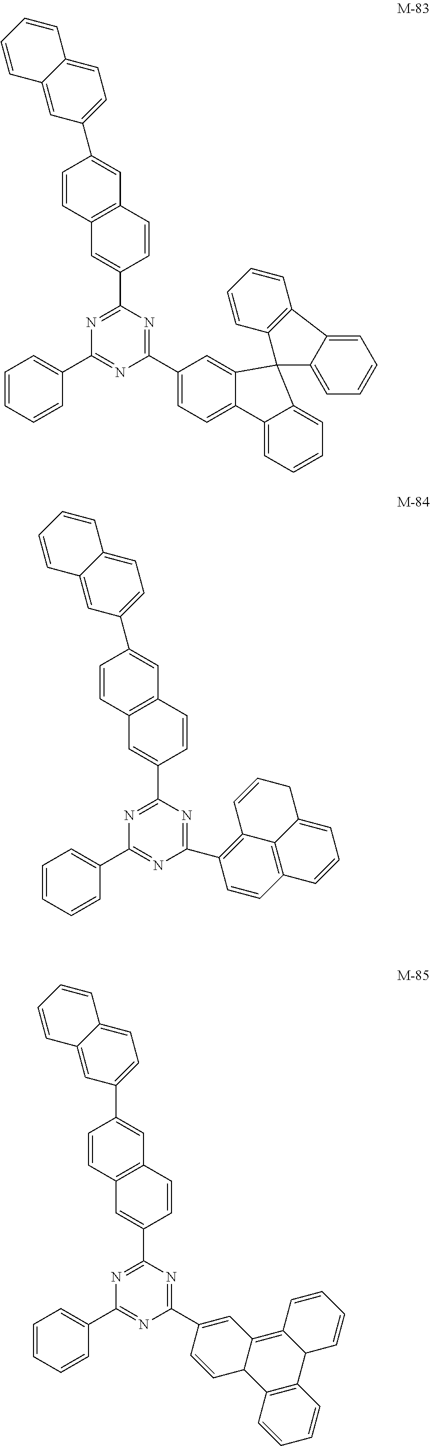 [SMILES: c1ccc(-c2nc(-c3ccc4c(c3)C3(c5ccccc5-c5ccccc53)c3ccccc3-4)nc(-c3ccc4cc(-c5ccc6ccccc6c5)ccc4c3)n2)cc1 ; C1=Cc2c(-c3nc(-c4ccccc4)nc(-c4ccc5cc(-c6ccc7ccccc7c6)ccc5c4)n3)ccc3cccc(c23)C1 ; C1=CC2=C3C=C(c4nc(-c5ccccc5)nc(-c5ccc6cc(-c7ccc8ccccc8c7)ccc6c5)n4)C=CC3c3ccccc3C2C=C1]

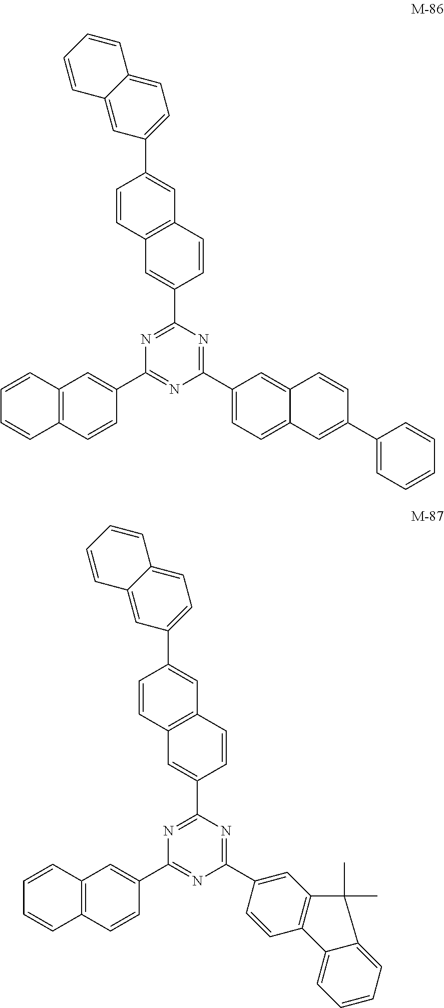 [SMILES: c1ccc(-c2ccc3cc(-c4nc(-c5ccc6ccccc6c5)nc(-c5ccc6cc(-c7ccc8ccccc8c7)ccc6c5)n4)ccc3c2)cc1 ; CC1(C)c2ccccc2-c2ccc(-c3nc(-c4ccc5ccccc5c4)nc(-c4ccc5cc(-c6ccc7ccccc7c6)ccc5c4)n3)cc21]

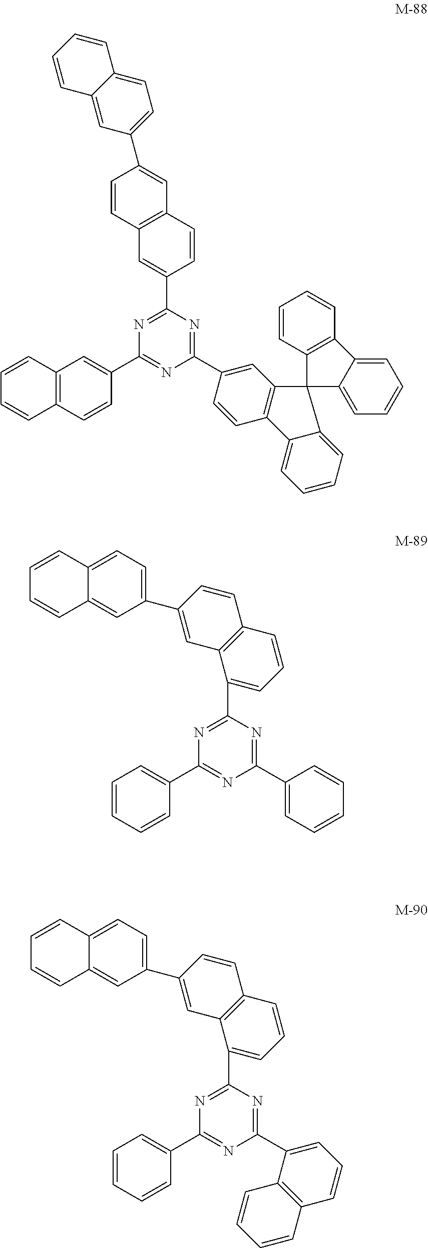 [SMILES: c1ccc2c(c1)-c1ccccc1C21c2ccccc2-c2ccc(-c3nc(-c4ccc5ccccc5c4)nc(-c4ccc5cc(-c6ccc7ccccc7c6)ccc5c4)n3)cc21 ; c1ccc(-c2nc(-c3ccccc3)nc(-c3cccc4ccc(-c5ccc6ccccc6c5)cc34)n2)cc1 ; c1ccc(-c2nc(-c3cccc4ccccc34)nc(-c3cccc4ccc(-c5ccc6ccccc6c5)cc34)n2)cc1]

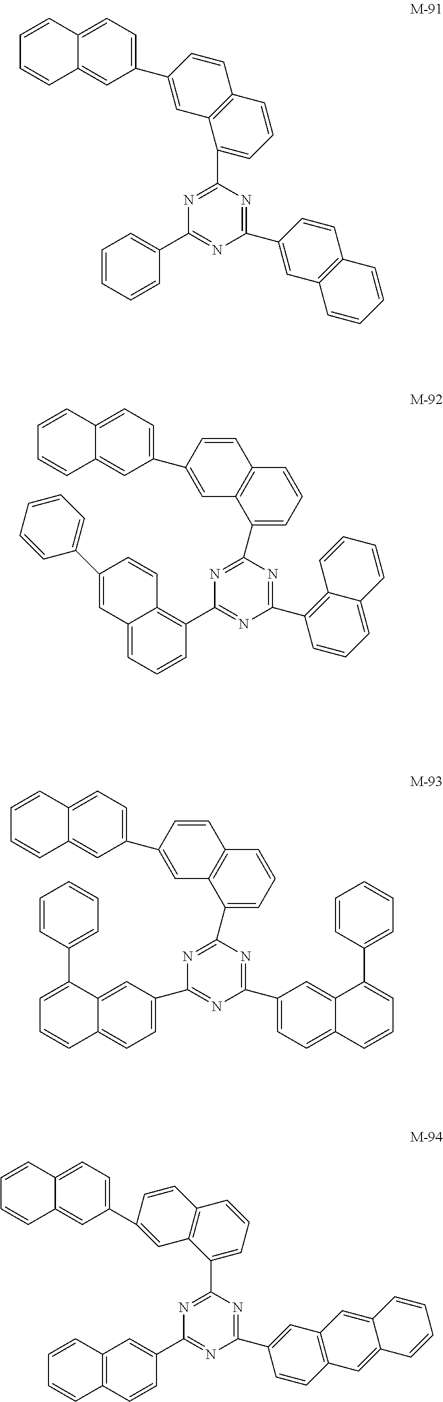 [SMILES: c1ccc(-c2nc(-c3ccc4ccccc4c3)nc(-c3cccc4ccc(-c5ccc6ccccc6c5)cc34)n2)cc1 ; c1ccc(-c2ccc3c(-c4nc(-c5cccc6ccccc56)nc(-c5cccc6ccc(-c7ccc8ccccc8c7)cc56)n4)cccc3c2)cc1 ; c1ccc(-c2cccc3ccc(-c4nc(-c5ccc6cccc(-c7ccccc7)c6c5)nc(-c5cccc6ccc(-c7ccc8ccccc8c7)cc56)n4)cc23)cc1 ; c1ccc2cc(-c3ccc4cccc(-c5nc(-c6ccc7ccccc7c6)nc(-c6ccc7cc8ccccc8cc7c6)n5)c4c3)ccc2c1]

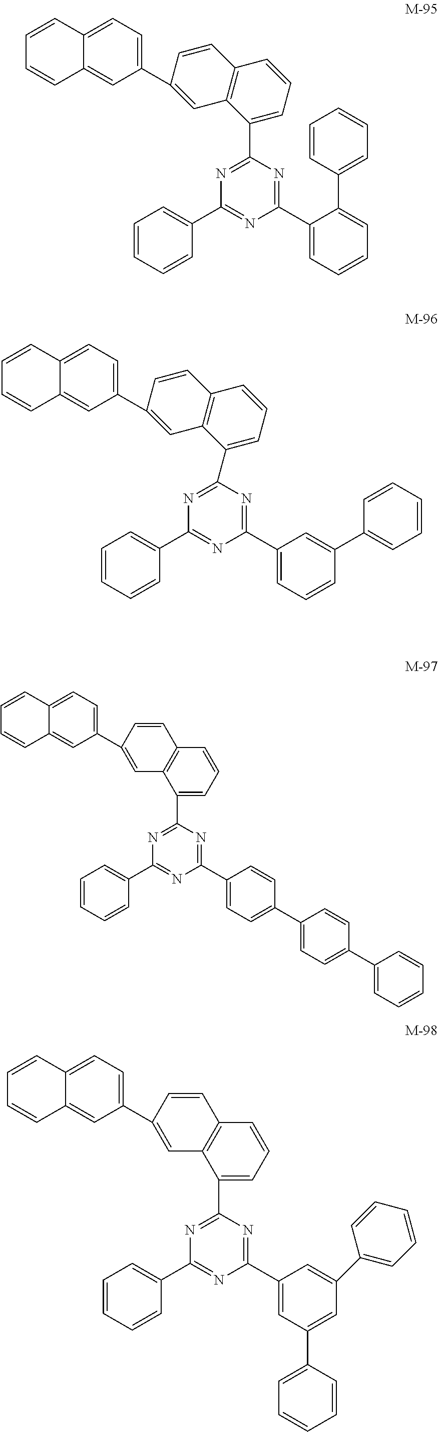 [SMILES: c1ccc(-c2nc(-c3ccccc3-c3ccccc3)nc(-c3cccc4ccc(-c5ccc6ccccc6c5)cc34)n2)cc1 ; c1ccc(-c2cccc(-c3nc(-c4ccccc4)nc(-c4cccc5ccc(-c6ccc7ccccc7c6)cc45)n3)c2)cc1 ; c1ccc(-c2ccc(-c3ccc(-c4nc(-c5ccccc5)nc(-c5cccc6ccc(-c7ccc8ccccc8c7)cc56)n4)cc3)cc2)cc1 ; c1ccc(-c2cc(-c3ccccc3)cc(-c3nc(-c4ccccc4)nc(-c4cccc5ccc(-c6ccc7ccccc7c6)cc45)n3)c2)cc1]

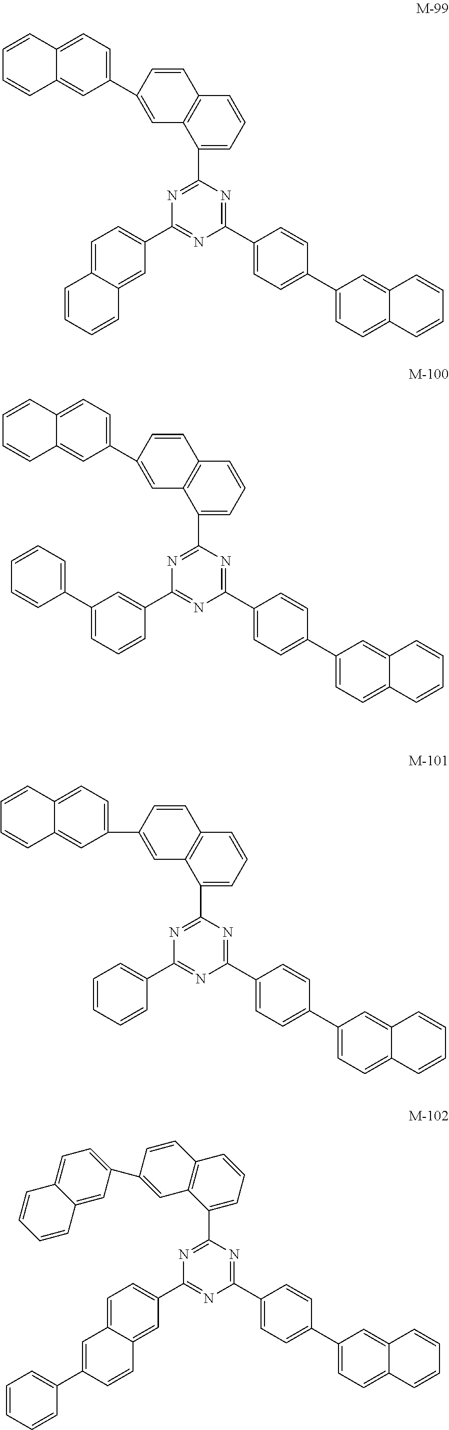 [SMILES: c1ccc2cc(-c3ccc(-c4nc(-c5ccc6ccccc6c5)nc(-c5cccc6ccc(-c7ccc8ccccc8c7)cc56)n4)cc3)ccc2c1 ; c1ccc(-c2cccc(-c3nc(-c4ccc(-c5ccc6ccccc6c5)cc4)nc(-c4cccc5ccc(-c6ccc7ccccc7c6)cc45)n3)c2)cc1 ; c1ccc(-c2nc(-c3ccc(-c4ccc5ccccc5c4)cc3)nc(-c3cccc4ccc(-c5ccc6ccccc6c5)cc34)n2)cc1 ; c1ccc(-c2ccc3cc(-c4nc(-c5ccc(-c6ccc7ccccc7c6)cc5)nc(-c5cccc6ccc(-c7ccc8ccccc8c7)cc56)n4)ccc3c2)cc1]

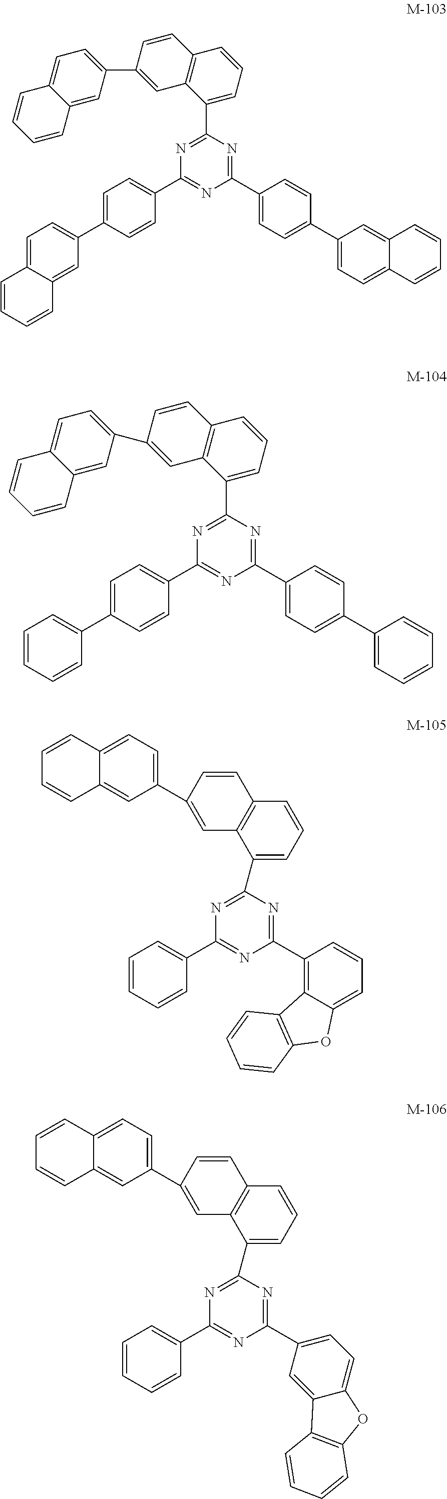 [SMILES: c1ccc2cc(-c3ccc(-c4nc(-c5ccc(-c6ccc7ccccc7c6)cc5)nc(-c5cccc6ccc(-c7ccc8ccccc8c7)cc56)n4)cc3)ccc2c1 ; c1ccc(-c2ccc(-c3nc(-c4ccc(-c5ccccc5)cc4)nc(-c4cccc5ccc(-c6ccc7ccccc7c6)cc45)n3)cc2)cc1 ; c1ccc(-c2nc(-c3cccc4ccc(-c5ccc6ccccc6c5)cc34)nc(-c3cccc4oc5ccccc5c34)n2)cc1 ; c1ccc(-c2nc(-c3ccc4oc5ccccc5c4c3)nc(-c3cccc4ccc(-c5ccc6ccccc6c5)cc34)n2)cc1]

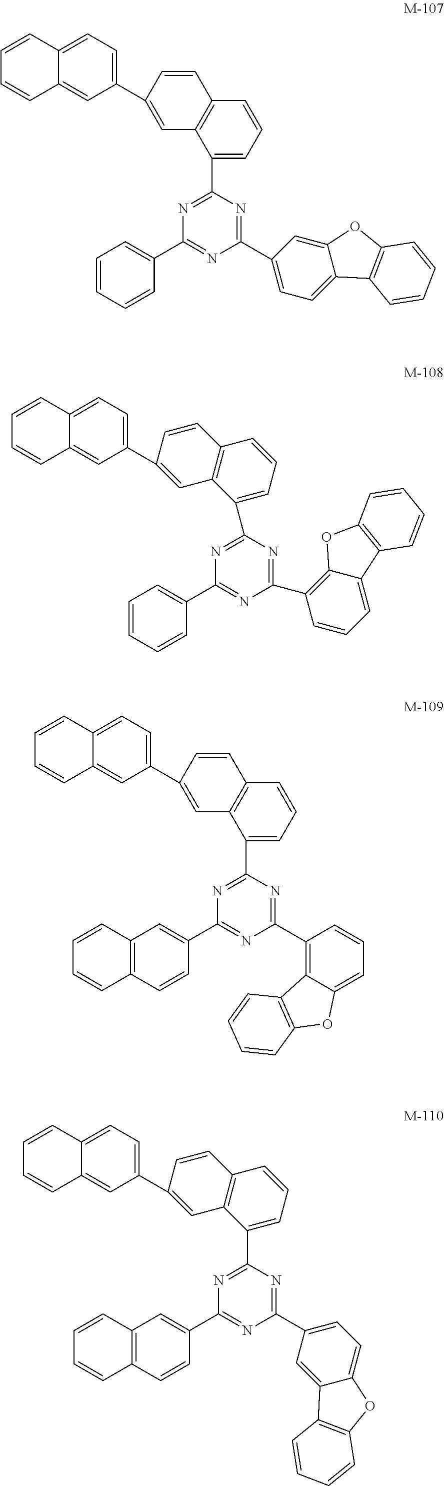 [SMILES: c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3cccc4ccc(-c5ccc6ccccc6c5)cc34)nc(-c3cccc4c3oc3ccccc34)n2)cc1 ; c1ccc2cc(-c3ccc4cccc(-c5nc(-c6ccc7ccccc7c6)nc(-c6cccc7oc8ccccc8c67)n5)c4c3)ccc2c1 ; c1ccc2cc(-c3ccc4cccc(-c5nc(-c6ccc7ccccc7c6)nc(-c6ccc7oc8ccccc8c7c6)n5)c4c3)ccc2c1]

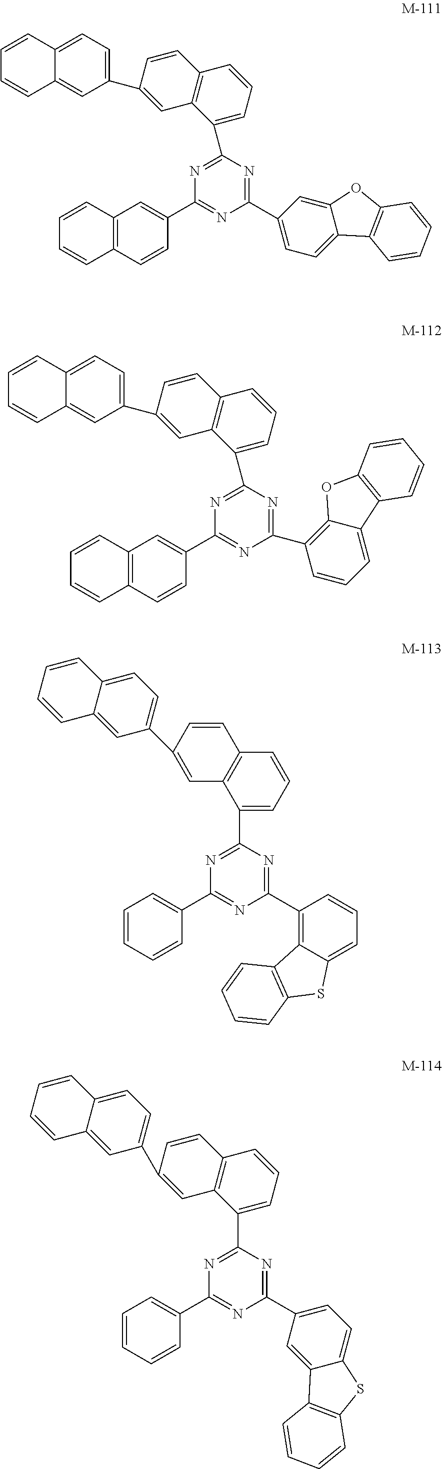 [SMILES: c1ccc2cc(-c3ccc4cccc(-c5nc(-c6ccc7ccccc7c6)nc(-c6ccc7c(c6)oc6ccccc67)n5)c4c3)ccc2c1 ; c1ccc2cc(-c3ccc4cccc(-c5nc(-c6ccc7ccccc7c6)nc(-c6cccc7c6oc6ccccc67)n5)c4c3)ccc2c1 ; c1ccc(-c2nc(-c3cccc4ccc(-c5ccc6ccccc6c5)cc34)nc(-c3cccc4sc5ccccc5c34)n2)cc1 ; c1ccc(-c2nc(-c3ccc4sc5ccccc5c4c3)nc(-c3cccc4ccc(-c5ccc6ccccc6c5)cc34)n2)cc1]

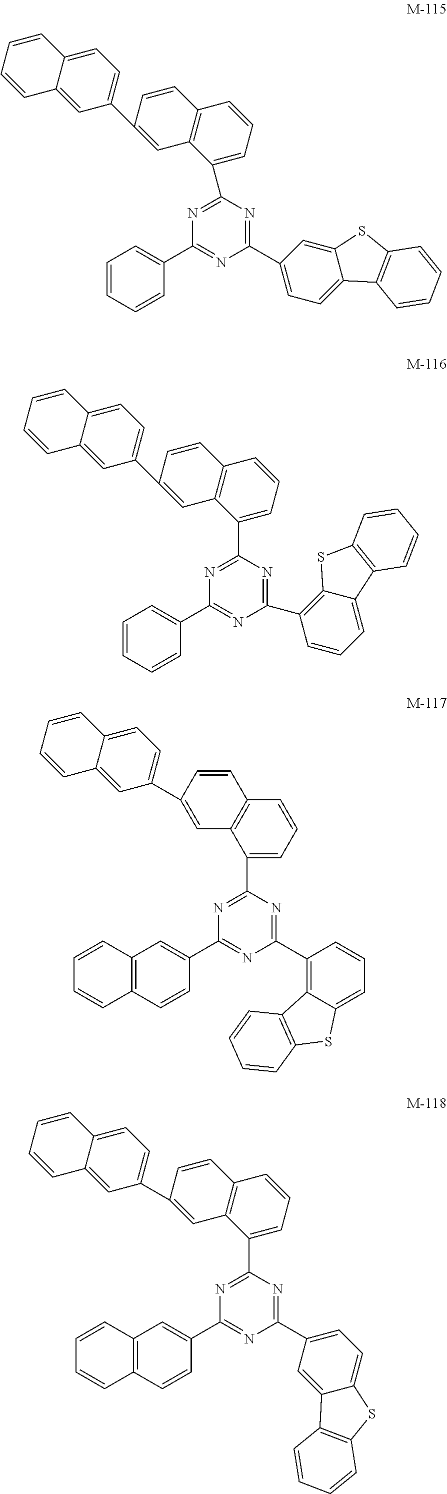 [SMILES: c1ccc(-c2nc(-c3ccc4c(c3)sc3ccccc34)nc(-c3cccc4ccc(-c5ccc6ccccc6c5)cc34)n2)cc1 ; c1ccc(-c2nc(-c3cccc4ccc(-c5ccc6ccccc6c5)cc34)nc(-c3cccc4c3sc3ccccc34)n2)cc1 ; c1ccc2cc(-c3ccc4cccc(-c5nc(-c6ccc7ccccc7c6)nc(-c6cccc7sc8ccccc8c67)n5)c4c3)ccc2c1 ; c1ccc2cc(-c3ccc4cccc(-c5nc(-c6ccc7ccccc7c6)nc(-c6ccc7sc8ccccc8c7c6)n5)c4c3)ccc2c1]

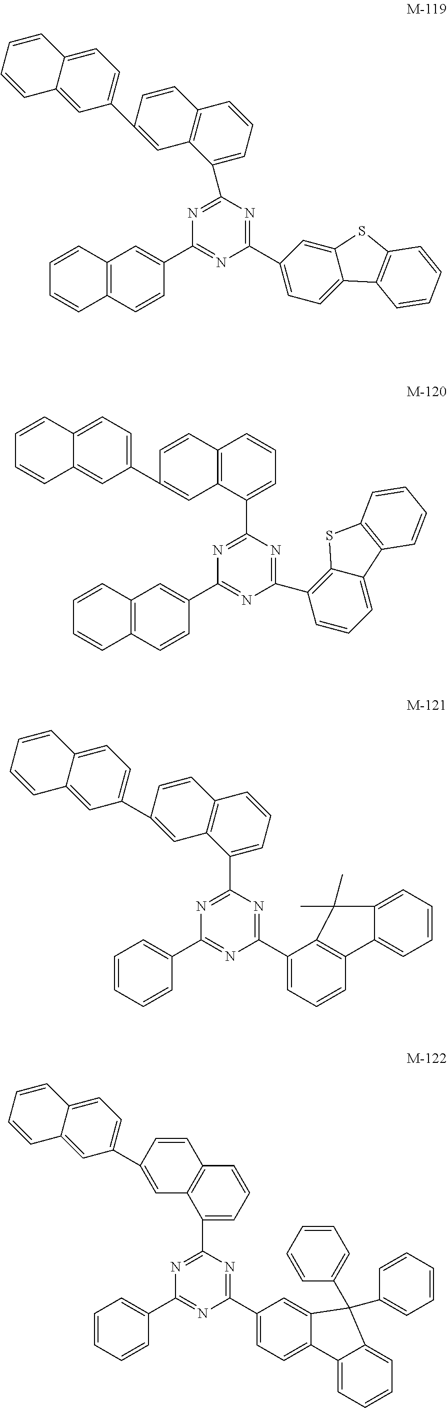 [SMILES: c1ccc2cc(-c3ccc4cccc(-c5nc(-c6ccc7ccccc7c6)nc(-c6ccc7c(c6)sc6ccccc67)n5)c4c3)ccc2c1 ; c1ccc2cc(-c3ccc4cccc(-c5nc(-c6ccc7ccccc7c6)nc(-c6cccc7c6sc6ccccc67)n5)c4c3)ccc2c1 ; CC1(C)c2ccccc2-c2cccc(-c3nc(-c4ccccc4)nc(-c4cccc5ccc(-c6ccc7ccccc7c6)cc45)n3)c21 ; c1ccc(-c2nc(-c3ccc4c(c3)C(c3ccccc3)(c3ccccc3)c3ccccc3-4)nc(-c3cccc4ccc(-c5ccc6ccccc6c5)cc34)n2)cc1]

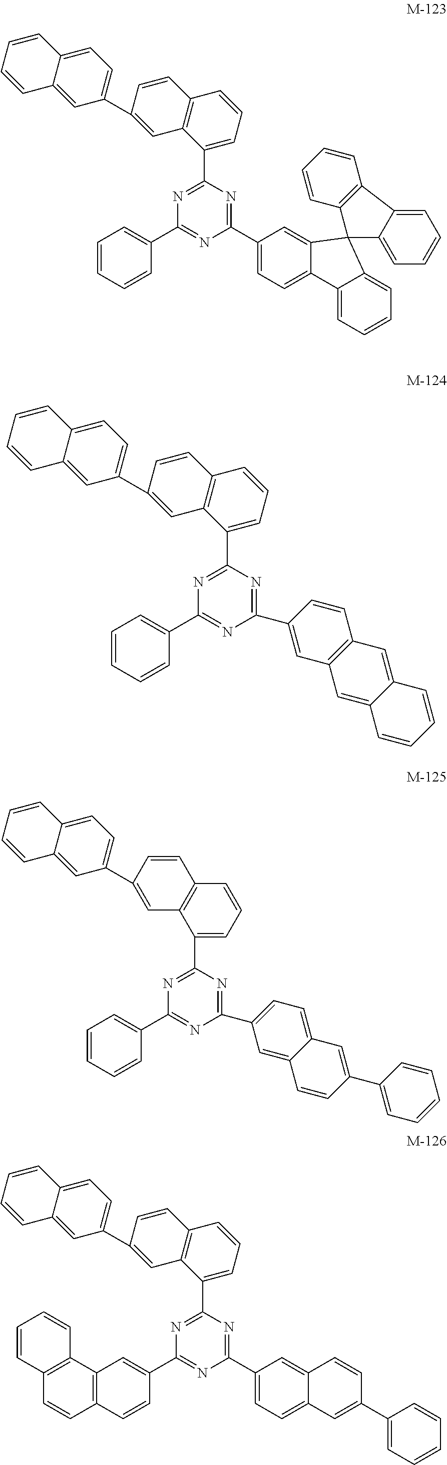 [SMILES: c1ccc(-c2nc(-c3ccc4c(c3)C3(c5ccccc5-c5ccccc53)c3ccccc3-4)nc(-c3cccc4ccc(-c5ccc6ccccc6c5)cc34)n2)cc1 ; c1ccc(-c2nc(-c3ccc4cc5ccccc5cc4c3)nc(-c3cccc4ccc(-c5ccc6ccccc6c5)cc34)n2)cc1 ; c1ccc(-c2ccc3cc(-c4nc(-c5ccccc5)nc(-c5cccc6ccc(-c7ccc8ccccc8c7)cc56)n4)ccc3c2)cc1 ; c1ccc(-c2ccc3cc(-c4nc(-c5ccc6ccc7ccccc7c6c5)nc(-c5cccc6ccc(-c7ccc8ccccc8c7)cc56)n4)ccc3c2)cc1]

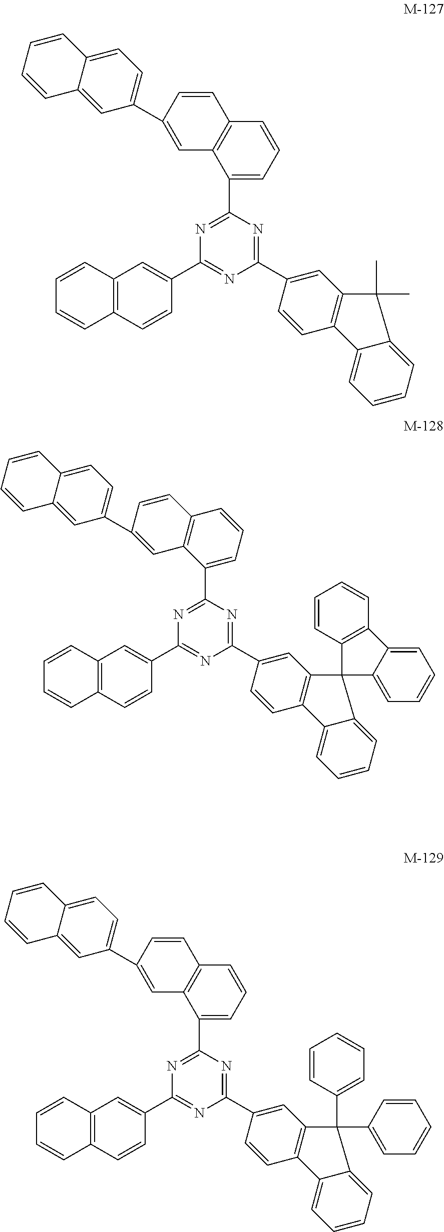 [SMILES: CC1(C)c2ccccc2-c2ccc(-c3nc(-c4ccc5ccccc5c4)nc(-c4cccc5ccc(-c6ccc7ccccc7c6)cc45)n3)cc21 ; c1ccc2c(c1)-c1ccccc1C21c2ccccc2-c2ccc(-c3nc(-c4ccc5ccccc5c4)nc(-c4cccc5ccc(-c6ccc7ccccc7c6)cc45)n3)cc21 ; c1ccc(C2(c3ccccc3)c3ccccc3-c3ccc(-c4nc(-c5ccc6ccccc6c5)nc(-c5cccc6ccc(-c7ccc8ccccc8c7)cc56)n4)cc32)cc1]

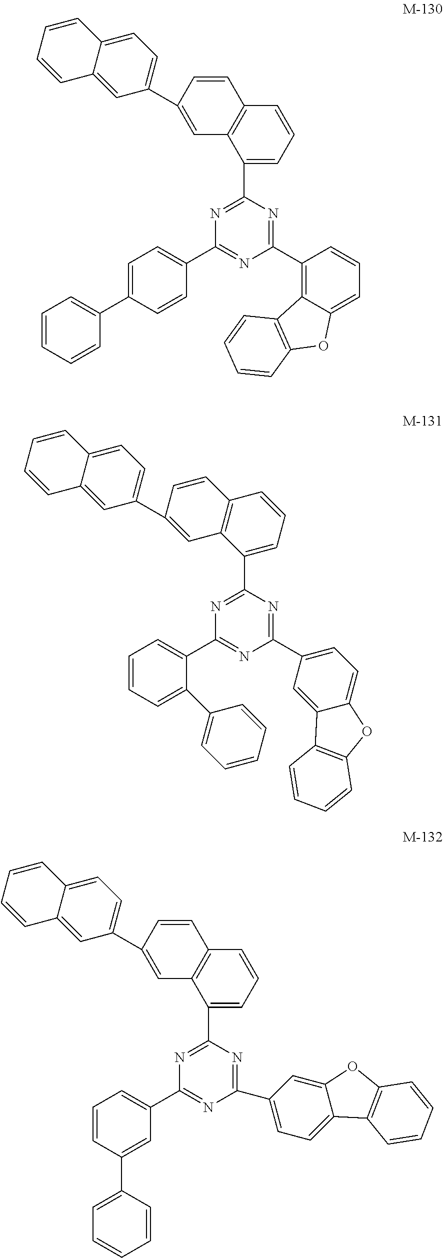 [SMILES: c1ccc(-c2ccc(-c3nc(-c4cccc5ccc(-c6ccc7ccccc7c6)cc45)nc(-c4cccc5oc6ccccc6c45)n3)cc2)cc1 ; c1ccc(-c2ccccc2-c2nc(-c3ccc4oc5ccccc5c4c3)nc(-c3cccc4ccc(-c5ccc6ccccc6c5)cc34)n2)cc1 ; c1ccc(-c2cccc(-c3nc(-c4ccc5c(c4)oc4ccccc45)nc(-c4cccc5ccc(-c6ccc7ccccc7c6)cc45)n3)c2)cc1]

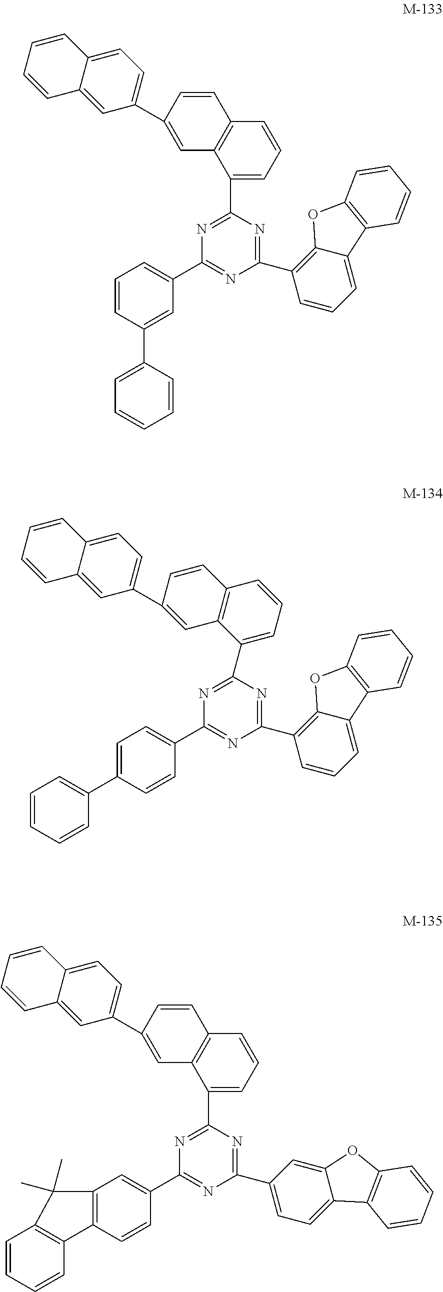 [SMILES: c1ccc(-c2cccc(-c3nc(-c4cccc5ccc(-c6ccc7ccccc7c6)cc45)nc(-c4cccc5c4oc4ccccc45)n3)c2)cc1 ; c1ccc(-c2ccc(-c3nc(-c4cccc5ccc(-c6ccc7ccccc7c6)cc45)nc(-c4cccc5c4oc4ccccc45)n3)cc2)cc1 ; CC1(C)c2ccccc2-c2ccc(-c3nc(-c4ccc5c(c4)oc4ccccc45)nc(-c4cccc5ccc(-c6ccc7ccccc7c6)cc45)n3)cc21]

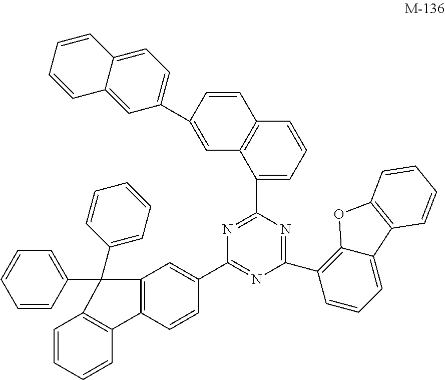 [SMILES: c1ccc(C2(c3ccccc3)c3ccccc3-c3ccc(-c4nc(-c5cccc6ccc(-c7ccc8ccccc8c7)cc56)nc(-c5cccc6c5oc5ccccc56)n4)cc32)cc1]

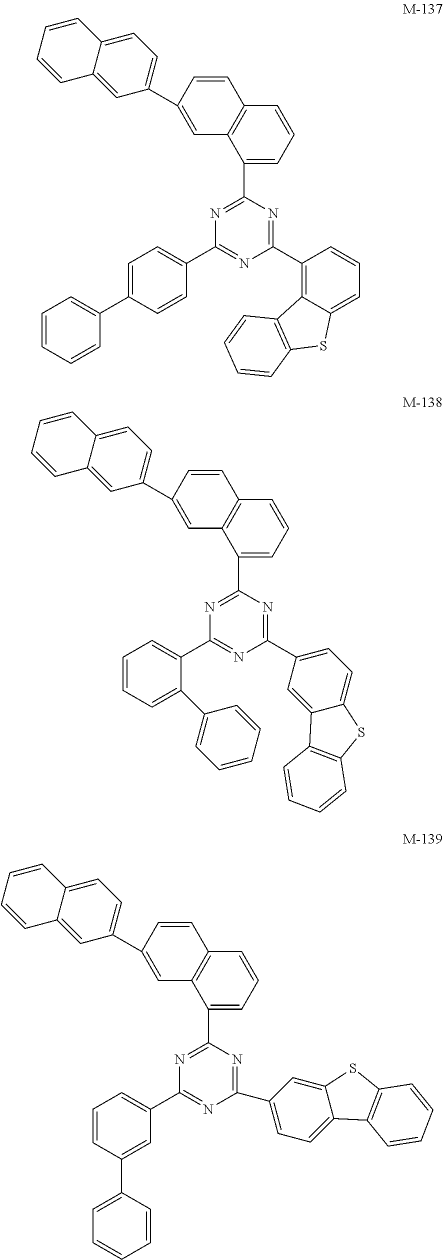 [SMILES: c1ccc(-c2ccc(-c3nc(-c4cccc5ccc(-c6ccc7ccccc7c6)cc45)nc(-c4cccc5sc6ccccc6c45)n3)cc2)cc1 ; c1ccc(-c2ccccc2-c2nc(-c3ccc4sc5ccccc5c4c3)nc(-c3cccc4ccc(-c5ccc6ccccc6c5)cc34)n2)cc1 ; c1ccc(-c2cccc(-c3nc(-c4ccc5c(c4)sc4ccccc45)nc(-c4cccc5ccc(-c6ccc7ccccc7c6)cc45)n3)c2)cc1]

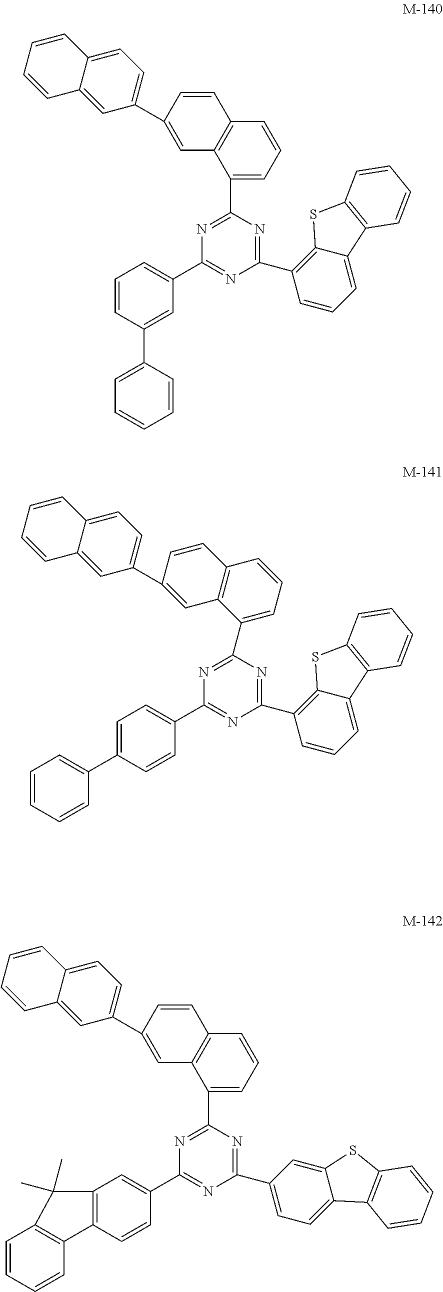 [SMILES: c1ccc(-c2cccc(-c3nc(-c4cccc5ccc(-c6ccc7ccccc7c6)cc45)nc(-c4cccc5c4sc4ccccc45)n3)c2)cc1 ; c1ccc(-c2ccc(-c3nc(-c4cccc5ccc(-c6ccc7ccccc7c6)cc45)nc(-c4cccc5c4sc4ccccc45)n3)cc2)cc1 ; CC1(C)c2ccccc2-c2ccc(-c3nc(-c4ccc5c(c4)sc4ccccc45)nc(-c4cccc5ccc(-c6ccc7ccccc7c6)cc45)n3)cc21]

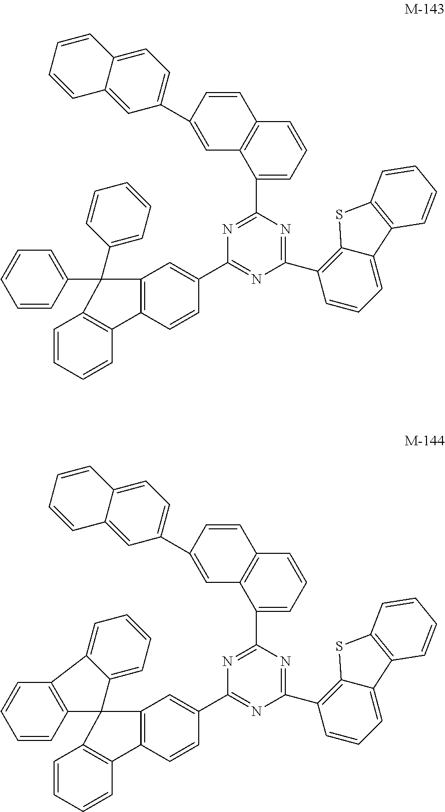 [SMILES: c1ccc(C2(c3ccccc3)c3ccccc3-c3ccc(-c4nc(-c5cccc6ccc(-c7ccc8ccccc8c7)cc56)nc(-c5cccc6c5sc5ccccc56)n4)cc32)cc1 ; c1ccc2c(c1)-c1ccccc1C21c2ccccc2-c2ccc(-c3nc(-c4cccc5ccc(-c6ccc7ccccc7c6)cc45)nc(-c4cccc5c4sc4ccccc45)n3)cc21]

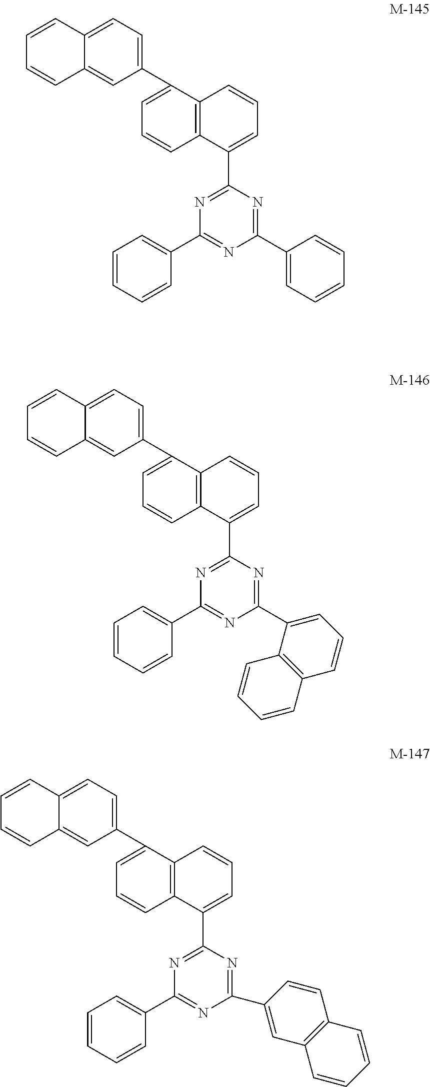 [SMILES: c1ccc(-c2nc(-c3ccccc3)nc(-c3cccc4c(-c5ccc6ccccc6c5)cccc34)n2)cc1 ; c1ccc(-c2nc(-c3cccc4ccccc34)nc(-c3cccc4c(-c5ccc6ccccc6c5)cccc34)n2)cc1 ; c1ccc(-c2nc(-c3ccc4ccccc4c3)nc(-c3cccc4c(-c5ccc6ccccc6c5)cccc34)n2)cc1]

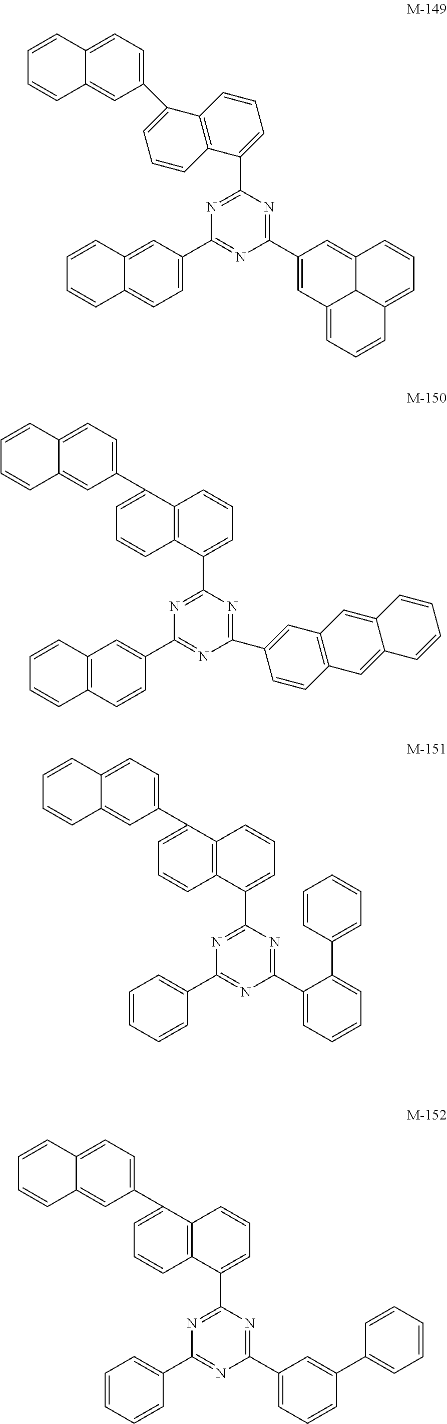 [SMILES: C1=CC2=CC=CC3=CC(c4nc(-c5ccc6ccccc6c5)nc(-c5cccc6c(-c7ccc8ccccc8c7)cccc56)n4)=CC(=C1)C23 ; c1ccc2cc(-c3nc(-c4ccc5cc6ccccc6cc5c4)nc(-c4cccc5c(-c6ccc7ccccc7c6)cccc45)n3)ccc2c1 ; c1ccc(-c2nc(-c3ccccc3-c3ccccc3)nc(-c3cccc4c(-c5ccc6ccccc6c5)cccc34)n2)cc1 ; c1ccc(-c2cccc(-c3nc(-c4ccccc4)nc(-c4cccc5c(-c6ccc7ccccc7c6)cccc45)n3)c2)cc1]

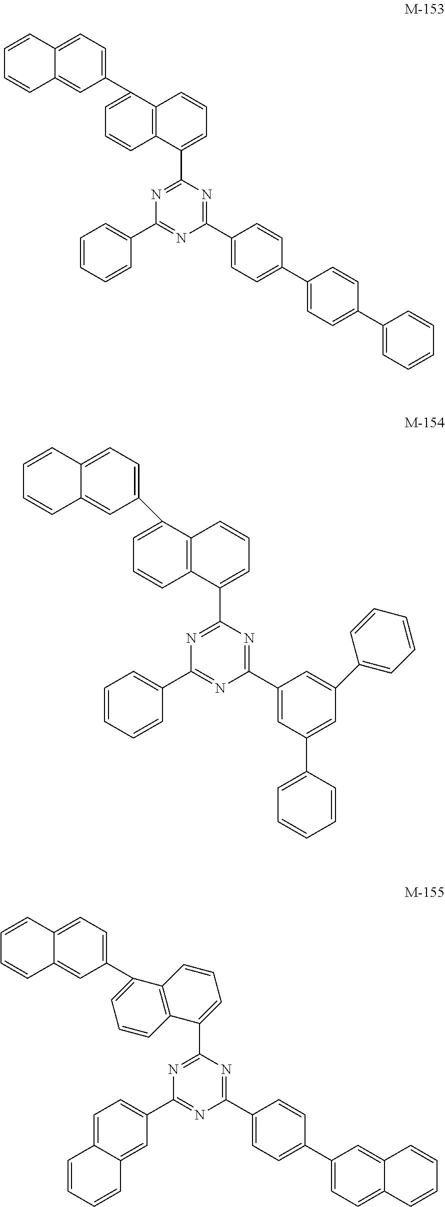 [SMILES: c1ccc(-c2ccc(-c3ccc(-c4nc(-c5ccccc5)nc(-c5cccc6c(-c7ccc8ccccc8c7)cccc56)n4)cc3)cc2)cc1 ; c1ccc(-c2cc(-c3ccccc3)cc(-c3nc(-c4ccccc4)nc(-c4cccc5c(-c6ccc7ccccc7c6)cccc45)n3)c2)cc1 ; c1ccc2cc(-c3ccc(-c4nc(-c5ccc6ccccc6c5)nc(-c5cccc6c(-c7ccc8ccccc8c7)cccc56)n4)cc3)ccc2c1]

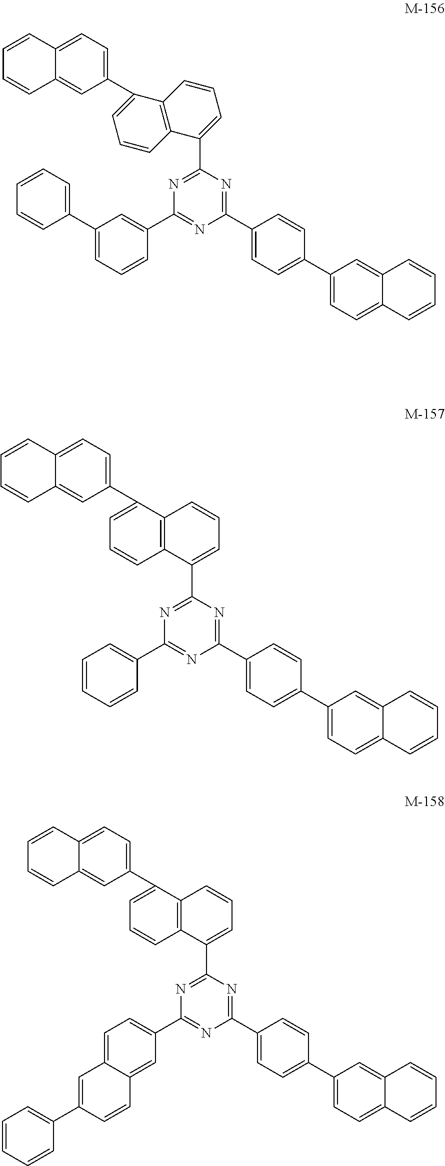 [SMILES: c1ccc(-c2cccc(-c3nc(-c4ccc(-c5ccc6ccccc6c5)cc4)nc(-c4cccc5c(-c6ccc7ccccc7c6)cccc45)n3)c2)cc1 ; c1ccc(-c2nc(-c3ccc(-c4ccc5ccccc5c4)cc3)nc(-c3cccc4c(-c5ccc6ccccc6c5)cccc34)n2)cc1 ; c1ccc(-c2ccc3cc(-c4nc(-c5ccc(-c6ccc7ccccc7c6)cc5)nc(-c5cccc6c(-c7ccc8ccccc8c7)cccc56)n4)ccc3c2)cc1]

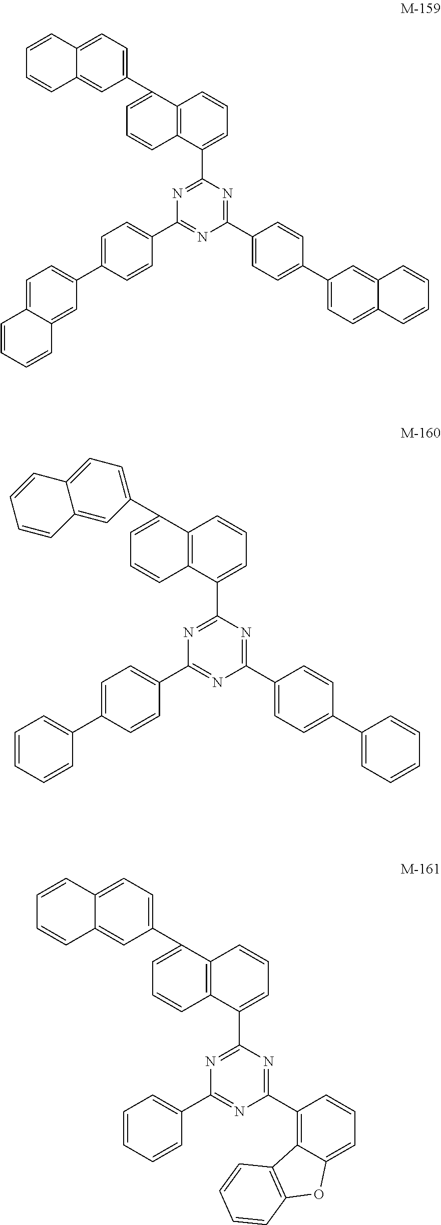 [SMILES: c1ccc2cc(-c3ccc(-c4nc(-c5ccc(-c6ccc7ccccc7c6)cc5)nc(-c5cccc6c(-c7ccc8ccccc8c7)cccc56)n4)cc3)ccc2c1 ; c1ccc(-c2ccc(-c3nc(-c4ccc(-c5ccccc5)cc4)nc(-c4cccc5c(-c6ccc7ccccc7c6)cccc45)n3)cc2)cc1 ; c1ccc(-c2nc(-c3cccc4c(-c5ccc6ccccc6c5)cccc34)nc(-c3cccc4oc5ccccc5c34)n2)cc1]

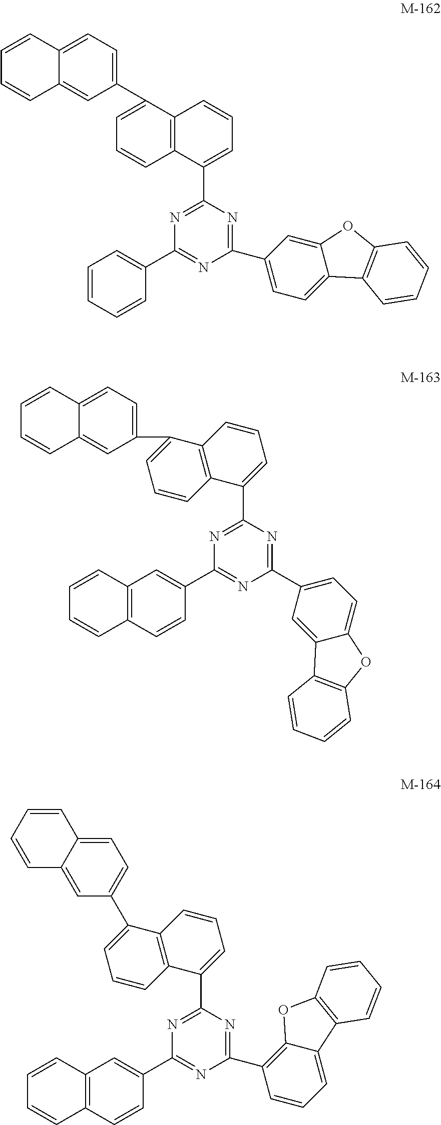 [SMILES: c1ccc(-c2nc(-c3ccc4c(c3)oc3ccccc34)nc(-c3cccc4c(-c5ccc6ccccc6c5)cccc34)n2)cc1 ; c1ccc2cc(-c3nc(-c4ccc5oc6ccccc6c5c4)nc(-c4cccc5c(-c6ccc7ccccc7c6)cccc45)n3)ccc2c1 ; c1ccc2cc(-c3nc(-c4cccc5c(-c6ccc7ccccc7c6)cccc45)nc(-c4cccc5c4oc4ccccc45)n3)ccc2c1]

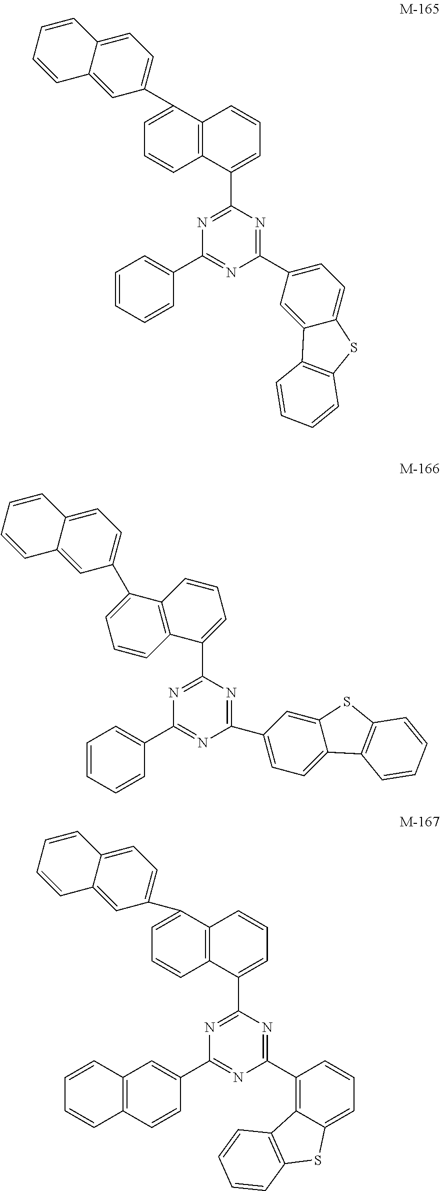 [SMILES: c1ccc(-c2nc(-c3ccc4sc5ccccc5c4c3)nc(-c3cccc4c(-c5ccc6ccccc6c5)cccc34)n2)cc1 ; c1ccc(-c2nc(-c3ccc4c(c3)sc3ccccc34)nc(-c3cccc4c(-c5ccc6ccccc6c5)cccc34)n2)cc1 ; c1ccc2cc(-c3nc(-c4cccc5c(-c6ccc7ccccc7c6)cccc45)nc(-c4cccc5sc6ccccc6c45)n3)ccc2c1]

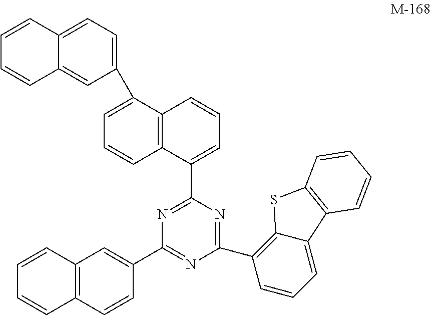 [SMILES: c1ccc2cc(-c3nc(-c4cccc5c(-c6ccc7ccccc7c6)cccc45)nc(-c4cccc5c4sc4ccccc45)n3)ccc2c1]

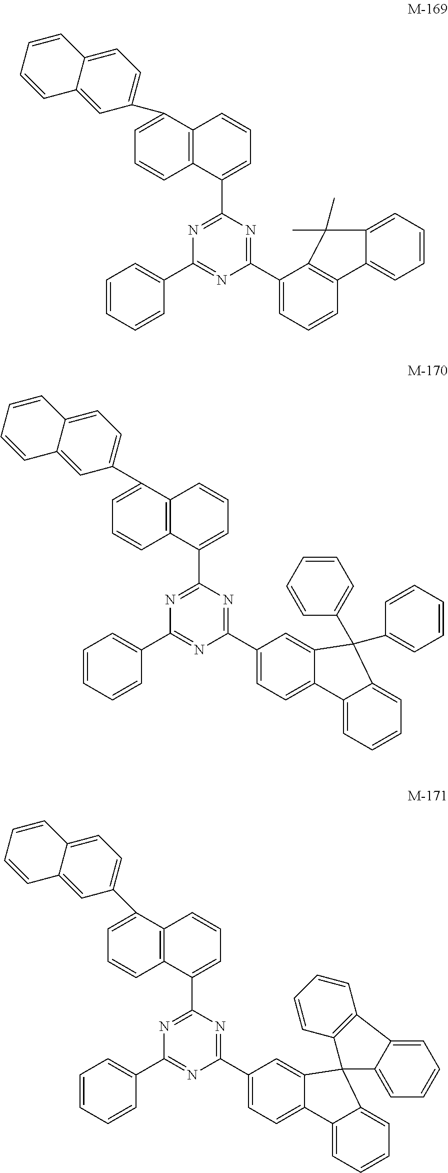 [SMILES: CC1(C)c2ccccc2-c2cccc(-c3nc(-c4ccccc4)nc(-c4cccc5c(-c6ccc7ccccc7c6)cccc45)n3)c21 ; c1ccc(-c2nc(-c3ccc4c(c3)C(c3ccccc3)(c3ccccc3)c3ccccc3-4)nc(-c3cccc4c(-c5ccc6ccccc6c5)cccc34)n2)cc1 ; c1ccc(-c2nc(-c3ccc4c(c3)C3(c5ccccc5-c5ccccc53)c3ccccc3-4)nc(-c3cccc4c(-c5ccc6ccccc6c5)cccc34)n2)cc1]

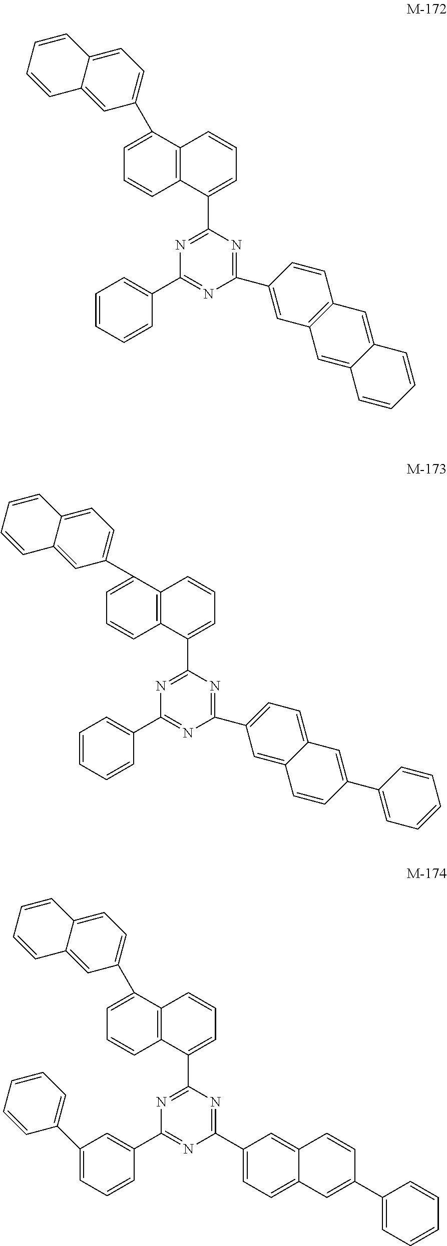 [SMILES: c1ccc(-c2nc(-c3ccc4cc5ccccc5cc4c3)nc(-c3cccc4c(-c5ccc6ccccc6c5)cccc34)n2)cc1 ; c1ccc(-c2ccc3cc(-c4nc(-c5ccccc5)nc(-c5cccc6c(-c7ccc8ccccc8c7)cccc56)n4)ccc3c2)cc1 ; c1ccc(-c2cccc(-c3nc(-c4ccc5cc(-c6ccccc6)ccc5c4)nc(-c4cccc5c(-c6ccc7ccccc7c6)cccc45)n3)c2)cc1]

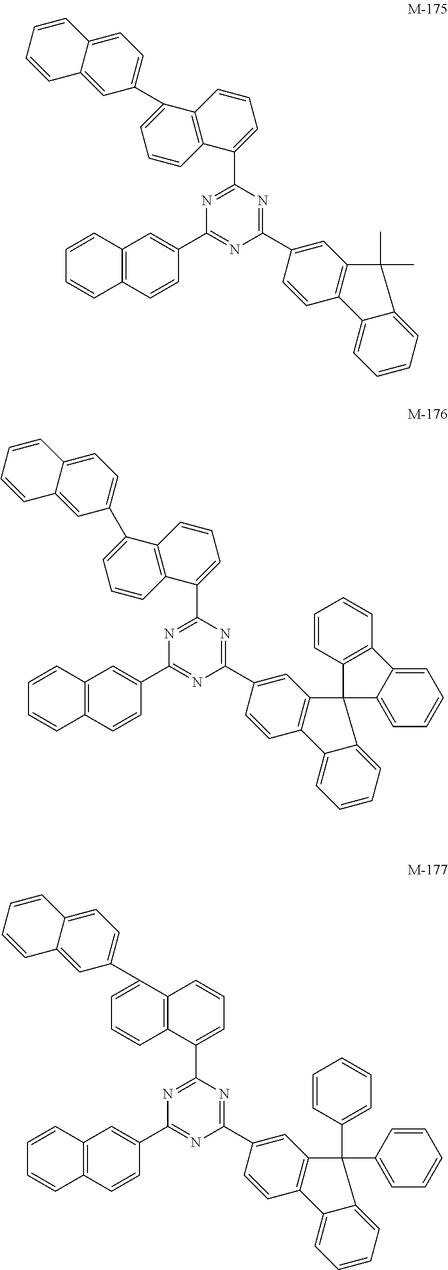 [SMILES: CC1(C)c2ccccc2-c2ccc(-c3nc(-c4ccc5ccccc5c4)nc(-c4cccc5c(-c6ccc7ccccc7c6)cccc45)n3)cc21 ; c1ccc2c(c1)-c1ccccc1C21c2ccccc2-c2ccc(-c3nc(-c4ccc5ccccc5c4)nc(-c4cccc5c(-c6ccc7ccccc7c6)cccc45)n3)cc21 ; c1ccc(C2(c3ccccc3)c3ccccc3-c3ccc(-c4nc(-c5ccc6ccccc6c5)nc(-c5cccc6c(-c7ccc8ccccc8c7)cccc56)n4)cc32)cc1]

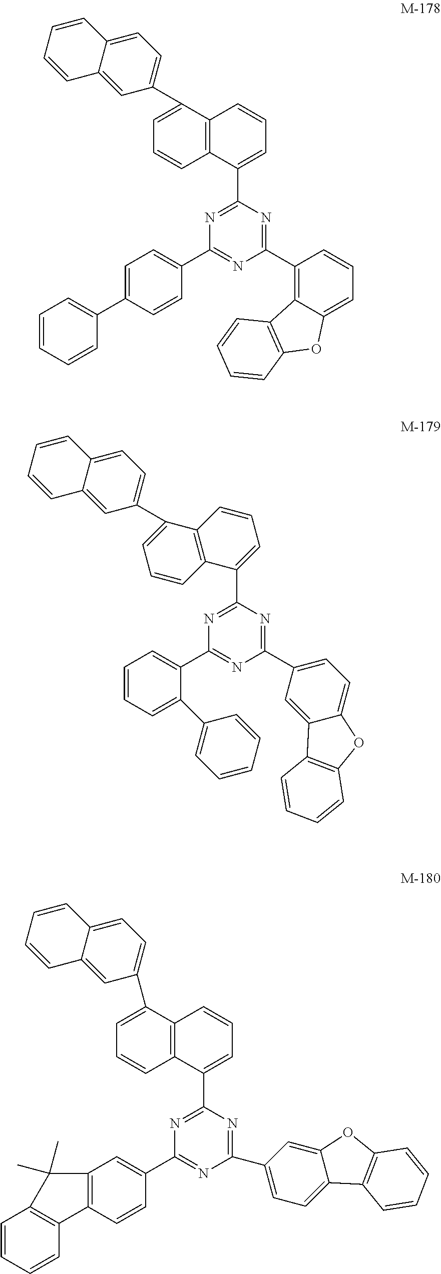 [SMILES: c1ccc(-c2ccc(-c3nc(-c4cccc5c(-c6ccc7ccccc7c6)cccc45)nc(-c4cccc5oc6ccccc6c45)n3)cc2)cc1 ; c1ccc(-c2ccccc2-c2nc(-c3ccc4oc5ccccc5c4c3)nc(-c3cccc4c(-c5ccc6ccccc6c5)cccc34)n2)cc1 ; CC1(C)c2ccccc2-c2ccc(-c3nc(-c4ccc5c(c4)oc4ccccc45)nc(-c4cccc5c(-c6ccc7ccccc7c6)cccc45)n3)cc21]

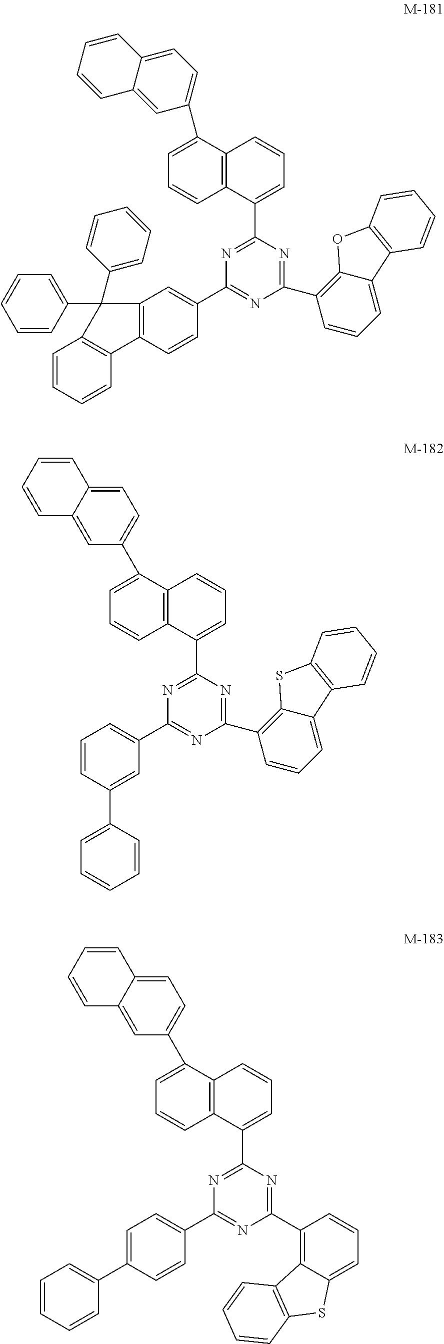 [SMILES: c1ccc(C2(c3ccccc3)c3ccccc3-c3ccc(-c4nc(-c5cccc6c(-c7ccc8ccccc8c7)cccc56)nc(-c5cccc6c5oc5ccccc56)n4)cc32)cc1 ; c1ccc(-c2cccc(-c3nc(-c4cccc5c(-c6ccc7ccccc7c6)cccc45)nc(-c4cccc5c4sc4ccccc45)n3)c2)cc1 ; c1ccc(-c2ccc(-c3nc(-c4cccc5c(-c6ccc7ccccc7c6)cccc45)nc(-c4cccc5sc6ccccc6c45)n3)cc2)cc1]

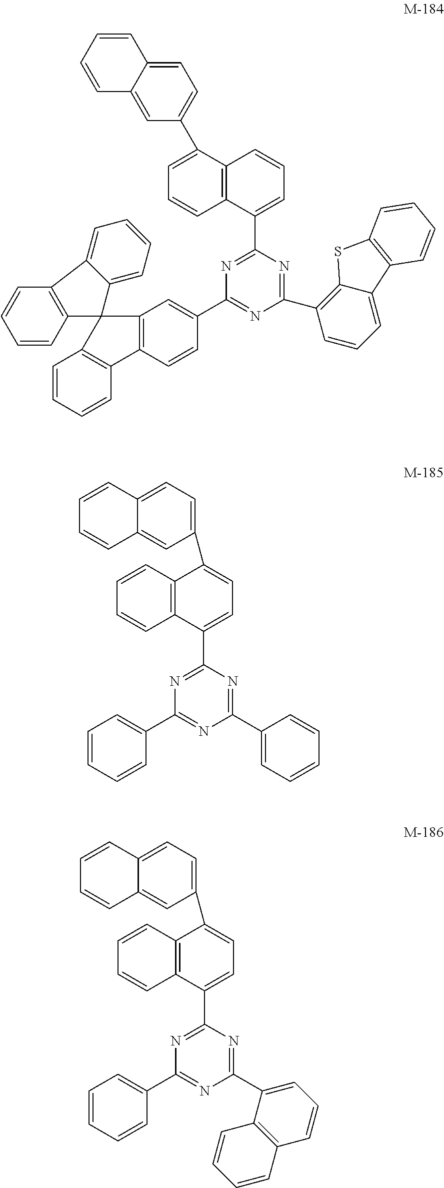 [SMILES: c1ccc2c(c1)-c1ccccc1C21c2ccccc2-c2ccc(-c3nc(-c4cccc5c(-c6ccc7ccccc7c6)cccc45)nc(-c4cccc5c4sc4ccccc45)n3)cc21 ; c1ccc(-c2nc(-c3ccccc3)nc(-c3ccc(-c4ccc5ccccc5c4)c4ccccc34)n2)cc1 ; c1ccc(-c2nc(-c3cccc4ccccc34)nc(-c3ccc(-c4ccc5ccccc5c4)c4ccccc34)n2)cc1]

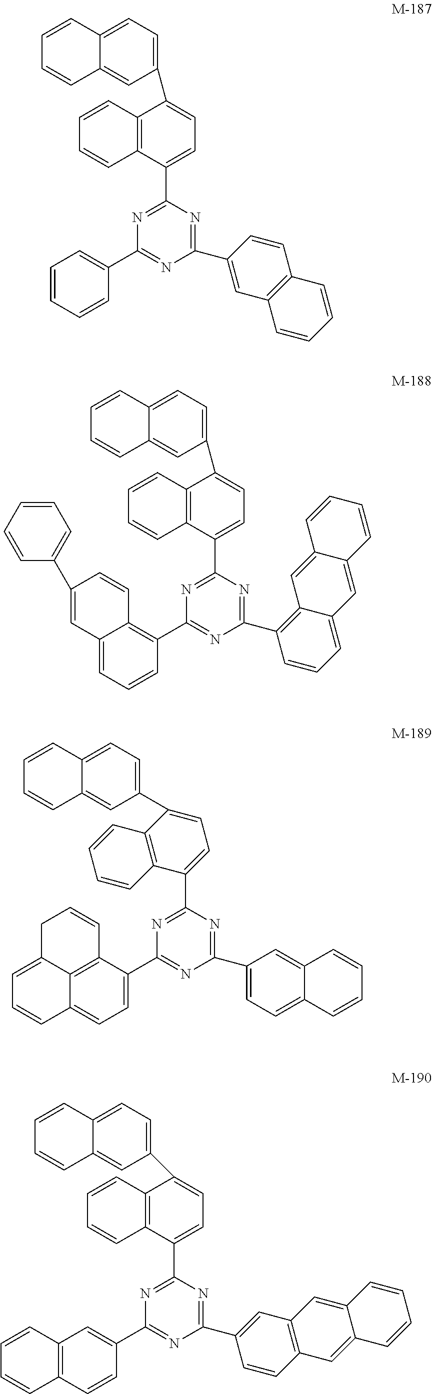 [SMILES: c1ccc(-c2nc(-c3ccc4ccccc4c3)nc(-c3ccc(-c4ccc5ccccc5c4)c4ccccc34)n2)cc1 ; c1ccc(-c2ccc3c(-c4nc(-c5cccc6cc7ccccc7cc56)nc(-c5ccc(-c6ccc7ccccc7c6)c6ccccc56)n4)cccc3c2)cc1 ; C1=Cc2c(-c3nc(-c4ccc5ccccc5c4)nc(-c4ccc(-c5ccc6ccccc6c5)c5ccccc45)n3)ccc3cccc(c23)C1 ; c1ccc2cc(-c3nc(-c4ccc5cc6ccccc6cc5c4)nc(-c4ccc(-c5ccc6ccccc6c5)c5ccccc45)n3)ccc2c1]

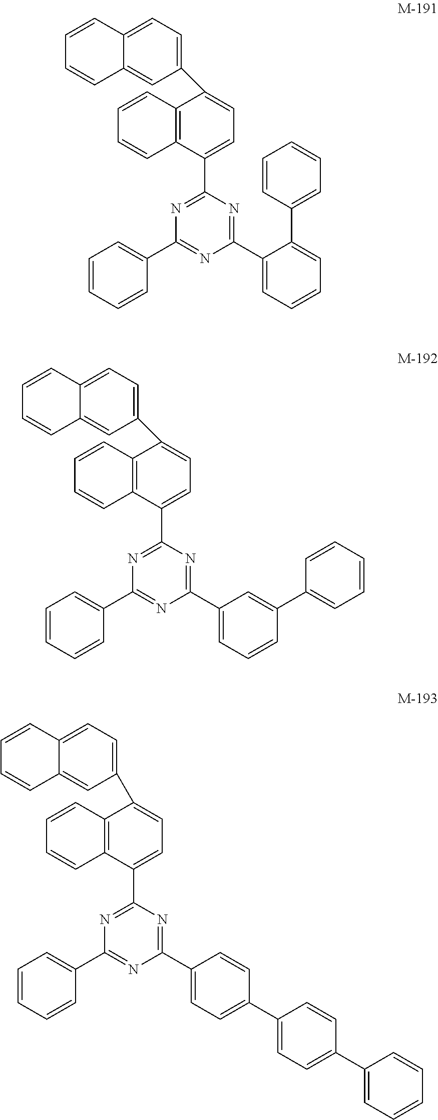 [SMILES: c1ccc(-c2nc(-c3ccccc3-c3ccccc3)nc(-c3ccc(-c4ccc5ccccc5c4)c4ccccc34)n2)cc1 ; c1ccc(-c2cccc(-c3nc(-c4ccccc4)nc(-c4ccc(-c5ccc6ccccc6c5)c5ccccc45)n3)c2)cc1 ; c1ccc(-c2ccc(-c3ccc(-c4nc(-c5ccccc5)nc(-c5ccc(-c6ccc7ccccc7c6)c6ccccc56)n4)cc3)cc2)cc1]

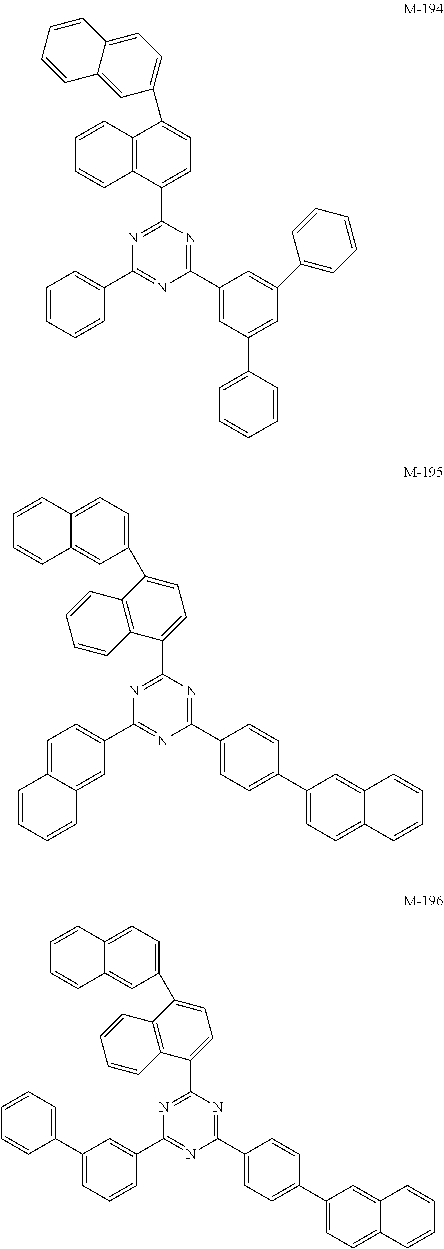 [SMILES: c1ccc(-c2cc(-c3ccccc3)cc(-c3nc(-c4ccccc4)nc(-c4ccc(-c5ccc6ccccc6c5)c5ccccc45)n3)c2)cc1 ; c1ccc2cc(-c3ccc(-c4nc(-c5ccc6ccccc6c5)nc(-c5ccc(-c6ccc7ccccc7c6)c6ccccc56)n4)cc3)ccc2c1 ; c1ccc(-c2cccc(-c3nc(-c4ccc(-c5ccc6ccccc6c5)cc4)nc(-c4ccc(-c5ccc6ccccc6c5)c5ccccc45)n3)c2)cc1]

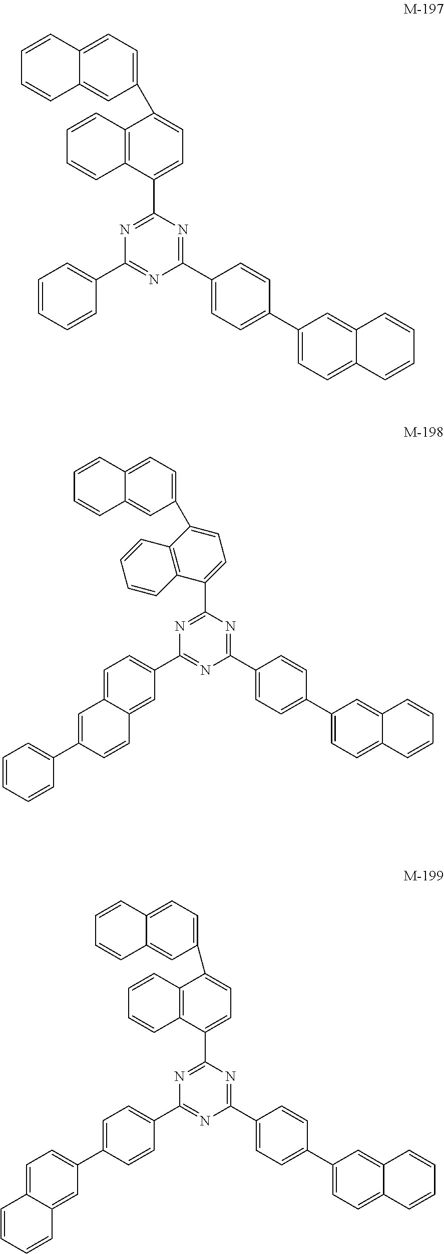 [SMILES: c1ccc(-c2nc(-c3ccc(-c4ccc5ccccc5c4)cc3)nc(-c3ccc(-c4ccc5ccccc5c4)c4ccccc34)n2)cc1 ; c1ccc(-c2ccc3cc(-c4nc(-c5ccc(-c6ccc7ccccc7c6)cc5)nc(-c5ccc(-c6ccc7ccccc7c6)c6ccccc56)n4)ccc3c2)cc1 ; c1ccc2cc(-c3ccc(-c4nc(-c5ccc(-c6ccc7ccccc7c6)cc5)nc(-c5ccc(-c6ccc7ccccc7c6)c6ccccc56)n4)cc3)ccc2c1]

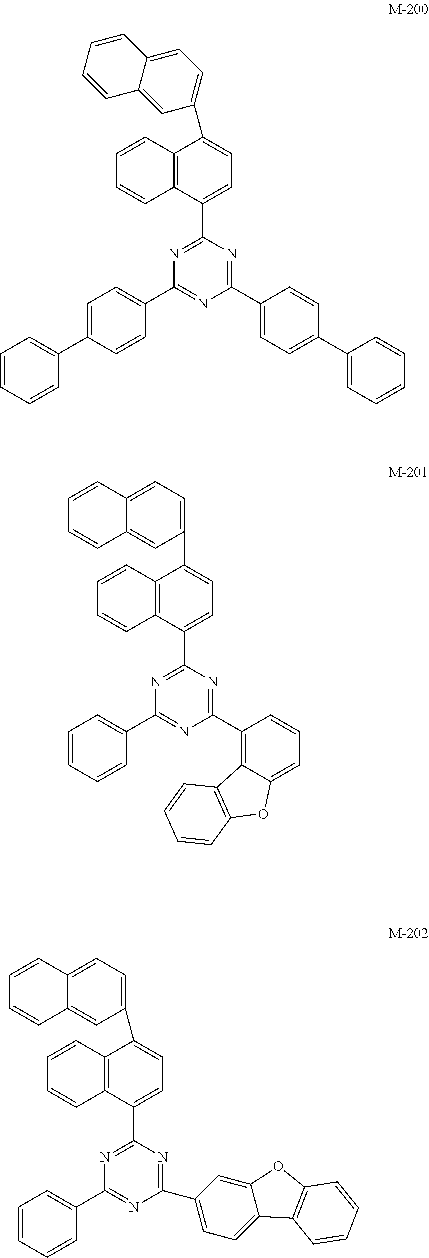 [SMILES: c1ccc(-c2ccc(-c3nc(-c4ccc(-c5ccccc5)cc4)nc(-c4ccc(-c5ccc6ccccc6c5)c5ccccc45)n3)cc2)cc1 ; c1ccc(-c2nc(-c3ccc(-c4ccc5ccccc5c4)c4ccccc34)nc(-c3cccc4oc5ccccc5c34)n2)cc1 ; c1ccc(-c2nc(-c3ccc4c(c3)oc3ccccc34)nc(-c3ccc(-c4ccc5ccccc5c4)c4ccccc34)n2)cc1]

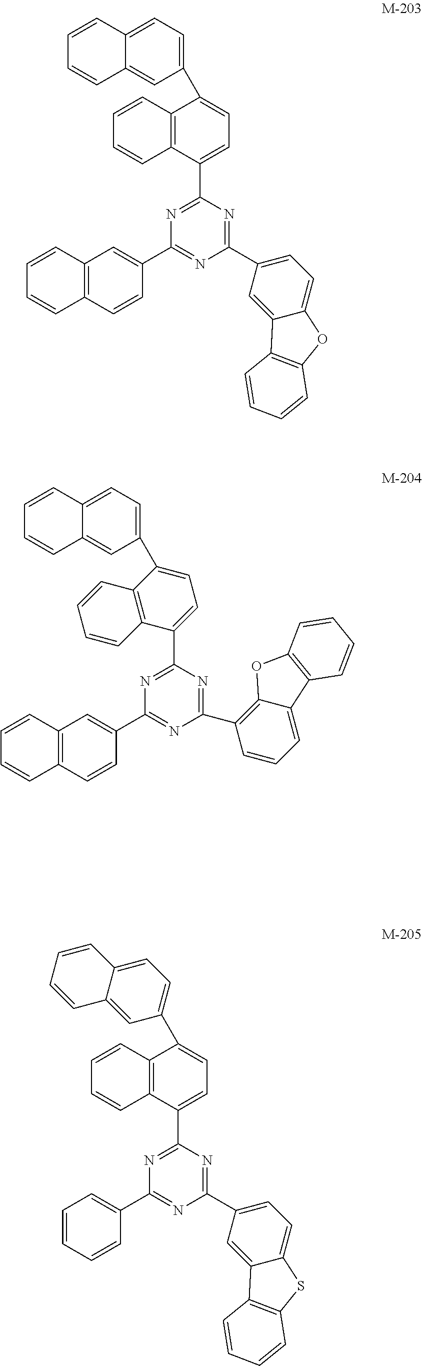 [SMILES: c1ccc2cc(-c3nc(-c4ccc5oc6ccccc6c5c4)nc(-c4ccc(-c5ccc6ccccc6c5)c5ccccc45)n3)ccc2c1 ; c1ccc2cc(-c3nc(-c4ccc(-c5ccc6ccccc6c5)c5ccccc45)nc(-c4cccc5c4oc4ccccc45)n3)ccc2c1 ; c1ccc(-c2nc(-c3ccc4sc5ccccc5c4c3)nc(-c3ccc(-c4ccc5ccccc5c4)c4ccccc34)n2)cc1]

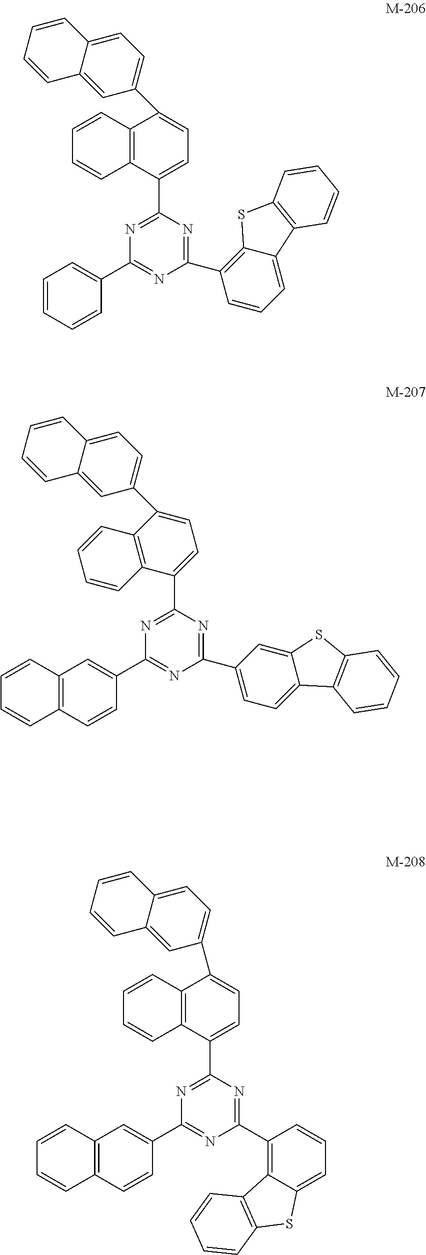 [SMILES: c1ccc(-c2nc(-c3ccc(-c4ccc5ccccc5c4)c4ccccc34)nc(-c3cccc4c3sc3ccccc34)n2)cc1 ; c1ccc2cc(-c3nc(-c4ccc5c(c4)sc4ccccc45)nc(-c4ccc(-c5ccc6ccccc6c5)c5ccccc45)n3)ccc2c1 ; c1ccc2cc(-c3nc(-c4ccc(-c5ccc6ccccc6c5)c5ccccc45)nc(-c4cccc5sc6ccccc6c45)n3)ccc2c1]

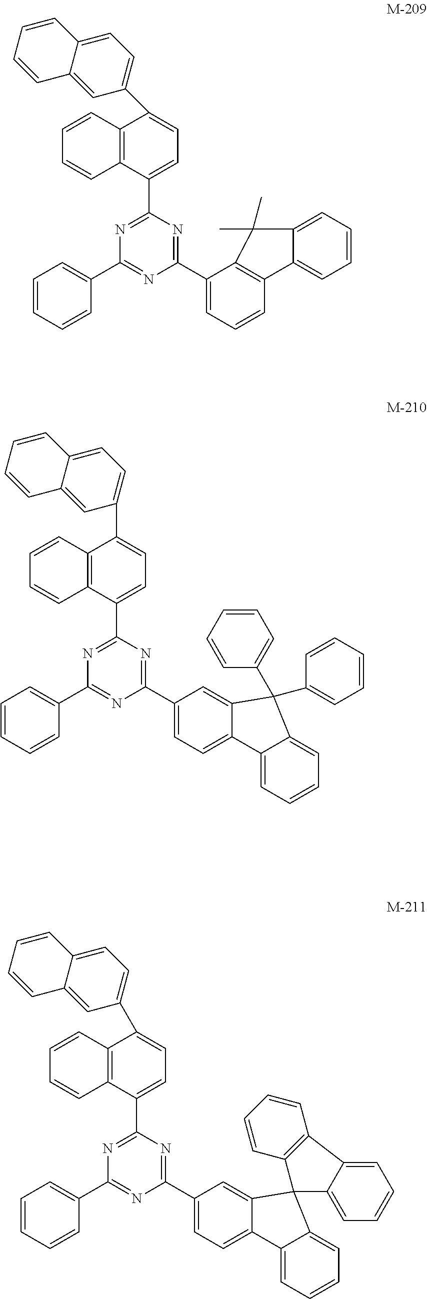 [SMILES: CC1(C)c2ccccc2-c2cccc(-c3nc(-c4ccccc4)nc(-c4ccc(-c5ccc6ccccc6c5)c5ccccc45)n3)c21 ; c1ccc(-c2nc(-c3ccc4c(c3)C(c3ccccc3)(c3ccccc3)c3ccccc3-4)nc(-c3ccc(-c4ccc5ccccc5c4)c4ccccc34)n2)cc1 ; c1ccc(-c2nc(-c3ccc4c(c3)C3(c5ccccc5-c5ccccc53)c3ccccc3-4)nc(-c3ccc(-c4ccc5ccccc5c4)c4ccccc34)n2)cc1]

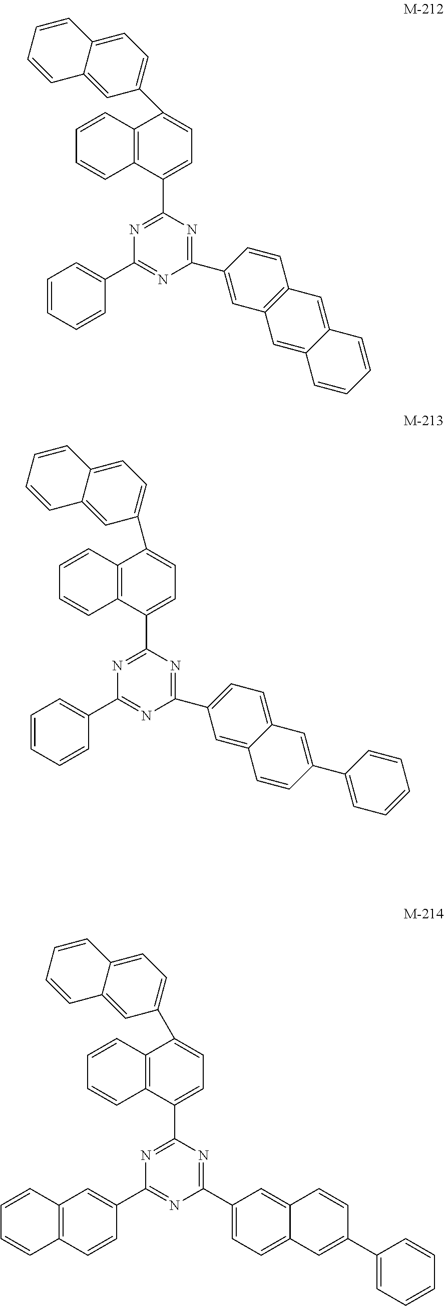 [SMILES: c1ccc(-c2nc(-c3ccc4cc5ccccc5cc4c3)nc(-c3ccc(-c4ccc5ccccc5c4)c4ccccc34)n2)cc1 ; c1ccc(-c2ccc3cc(-c4nc(-c5ccccc5)nc(-c5ccc(-c6ccc7ccccc7c6)c6ccccc56)n4)ccc3c2)cc1 ; c1ccc(-c2ccc3cc(-c4nc(-c5ccc6ccccc6c5)nc(-c5ccc(-c6ccc7ccccc7c6)c6ccccc56)n4)ccc3c2)cc1]

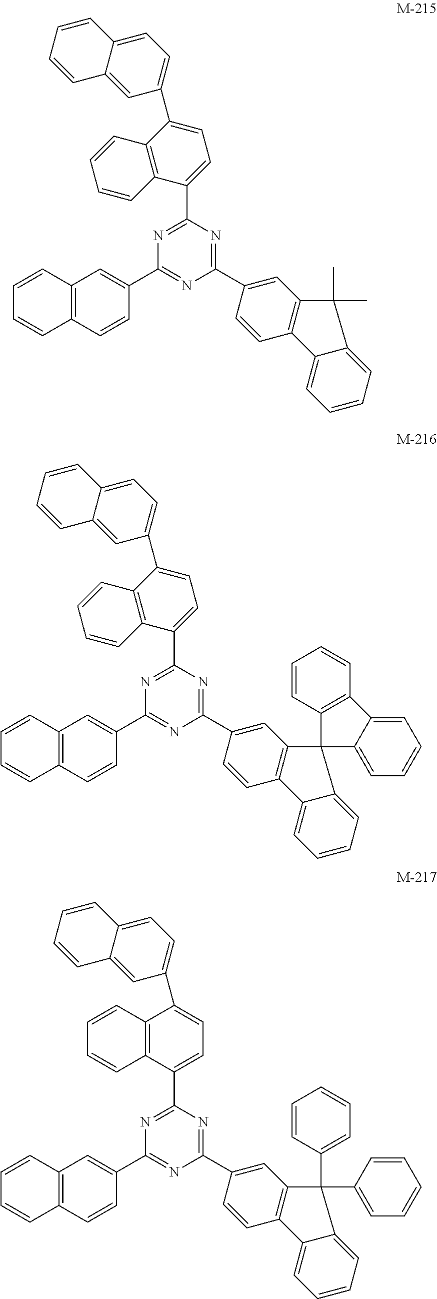 [SMILES: CC1(C)c2ccccc2-c2ccc(-c3nc(-c4ccc5ccccc5c4)nc(-c4ccc(-c5ccc6ccccc6c5)c5ccccc45)n3)cc21 ; c1ccc2c(c1)-c1ccccc1C21c2ccccc2-c2ccc(-c3nc(-c4ccc5ccccc5c4)nc(-c4ccc(-c5ccc6ccccc6c5)c5ccccc45)n3)cc21 ; c1ccc(C2(c3ccccc3)c3ccccc3-c3ccc(-c4nc(-c5ccc6ccccc6c5)nc(-c5ccc(-c6ccc7ccccc7c6)c6ccccc56)n4)cc32)cc1]

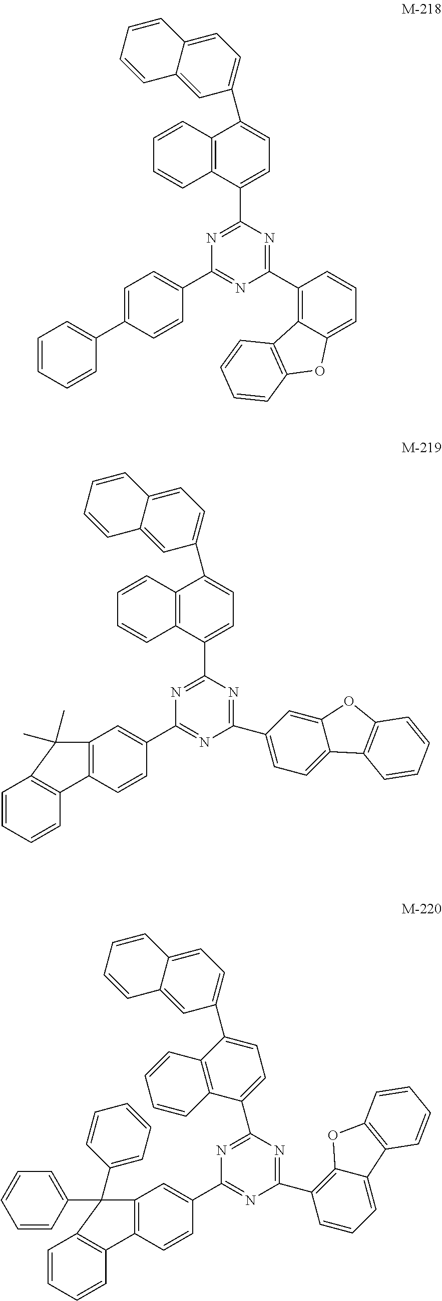 [SMILES: c1ccc(-c2ccc(-c3nc(-c4ccc(-c5ccc6ccccc6c5)c5ccccc45)nc(-c4cccc5oc6ccccc6c45)n3)cc2)cc1 ; CC1(C)c2ccccc2-c2ccc(-c3nc(-c4ccc5c(c4)oc4ccccc45)nc(-c4ccc(-c5ccc6ccccc6c5)c5ccccc45)n3)cc21 ; c1ccc(C2(c3ccccc3)c3ccccc3-c3ccc(-c4nc(-c5ccc(-c6ccc7ccccc7c6)c6ccccc56)nc(-c5cccc6c5oc5ccccc56)n4)cc32)cc1]

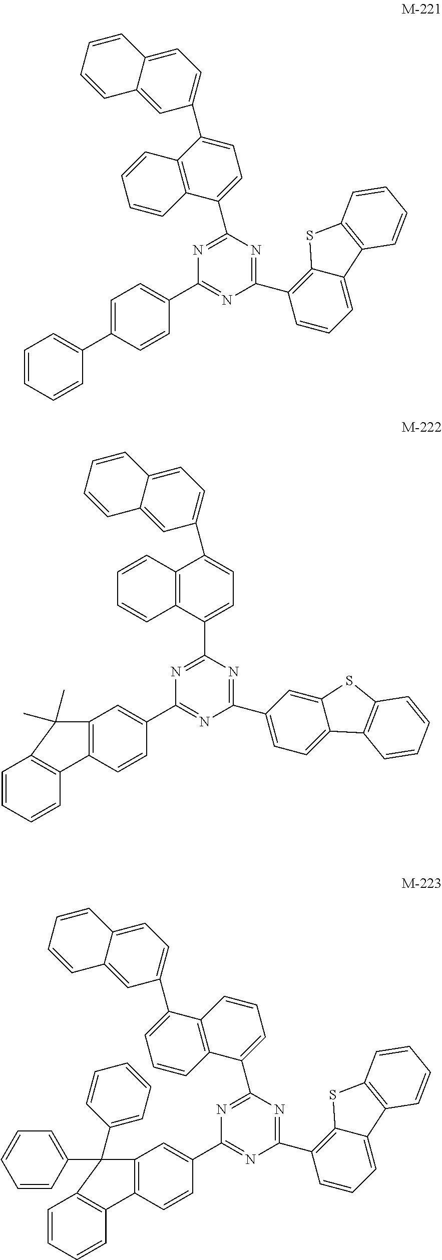 [SMILES: c1ccc(-c2ccc(-c3nc(-c4ccc(-c5ccc6ccccc6c5)c5ccccc45)nc(-c4cccc5c4sc4ccccc45)n3)cc2)cc1 ; CC1(C)c2ccccc2-c2ccc(-c3nc(-c4ccc5c(c4)sc4ccccc45)nc(-c4ccc(-c5ccc6ccccc6c5)c5ccccc45)n3)cc21 ; c1ccc(C2(c3ccccc3)c3ccccc3-c3ccc(-c4nc(-c5cccc6c(-c7ccc8ccccc8c7)cccc56)nc(-c5cccc6c5sc5ccccc56)n4)cc32)cc1]

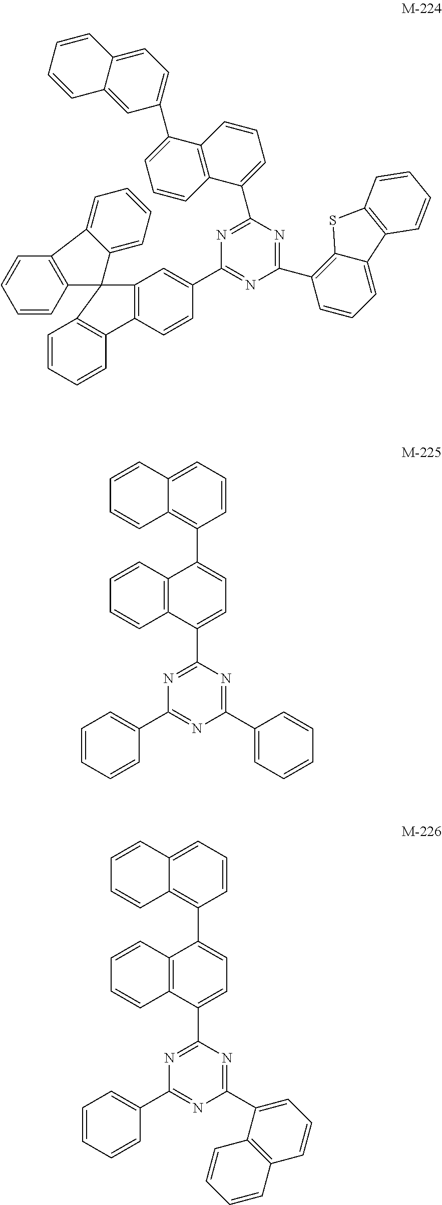 [SMILES: c1ccc2c(c1)-c1ccccc1C21c2ccccc2-c2ccc(-c3nc(-c4cccc5c(-c6ccc7ccccc7c6)cccc45)nc(-c4cccc5c4sc4ccccc45)n3)cc21 ; c1ccc(-c2nc(-c3ccccc3)nc(-c3ccc(-c4cccc5ccccc45)c4ccccc34)n2)cc1 ; c1ccc(-c2nc(-c3cccc4ccccc34)nc(-c3ccc(-c4cccc5ccccc45)c4ccccc34)n2)cc1]

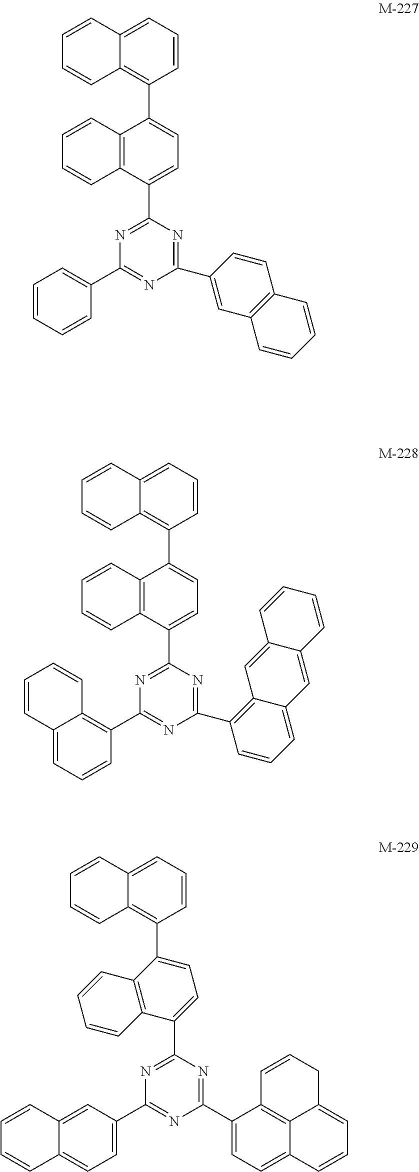 [SMILES: c1ccc(-c2nc(-c3ccc4ccccc4c3)nc(-c3ccc(-c4cccc5ccccc45)c4ccccc34)n2)cc1 ; c1ccc2cc3c(-c4nc(-c5cccc6ccccc56)nc(-c5ccc(-c6cccc7ccccc67)c6ccccc56)n4)cccc3cc2c1 ; C1=Cc2c(-c3nc(-c4ccc5ccccc5c4)nc(-c4ccc(-c5cccc6ccccc56)c5ccccc45)n3)ccc3cccc(c23)C1]

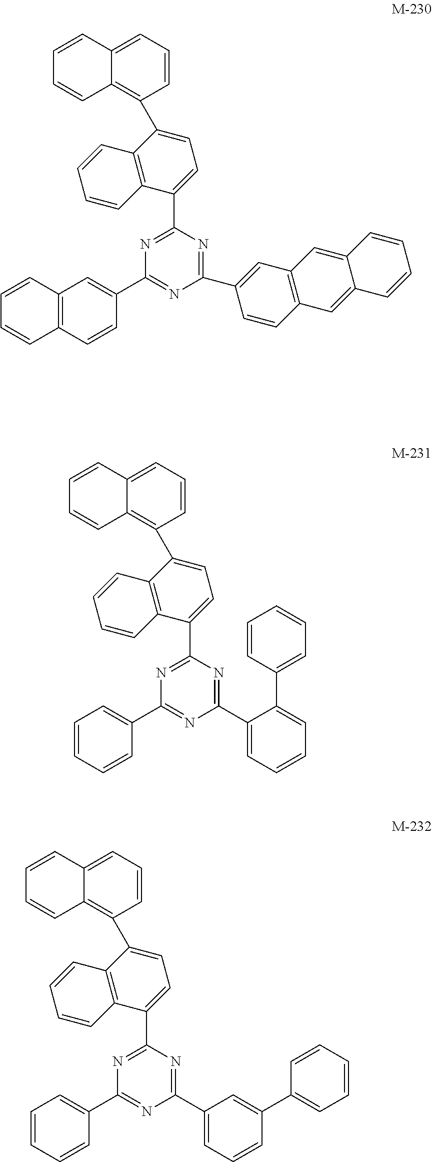 [SMILES: c1ccc2cc(-c3nc(-c4ccc5cc6ccccc6cc5c4)nc(-c4ccc(-c5cccc6ccccc56)c5ccccc45)n3)ccc2c1 ; c1ccc(-c2nc(-c3ccccc3-c3ccccc3)nc(-c3ccc(-c4cccc5ccccc45)c4ccccc34)n2)cc1 ; c1ccc(-c2cccc(-c3nc(-c4ccccc4)nc(-c4ccc(-c5cccc6ccccc56)c5ccccc45)n3)c2)cc1]

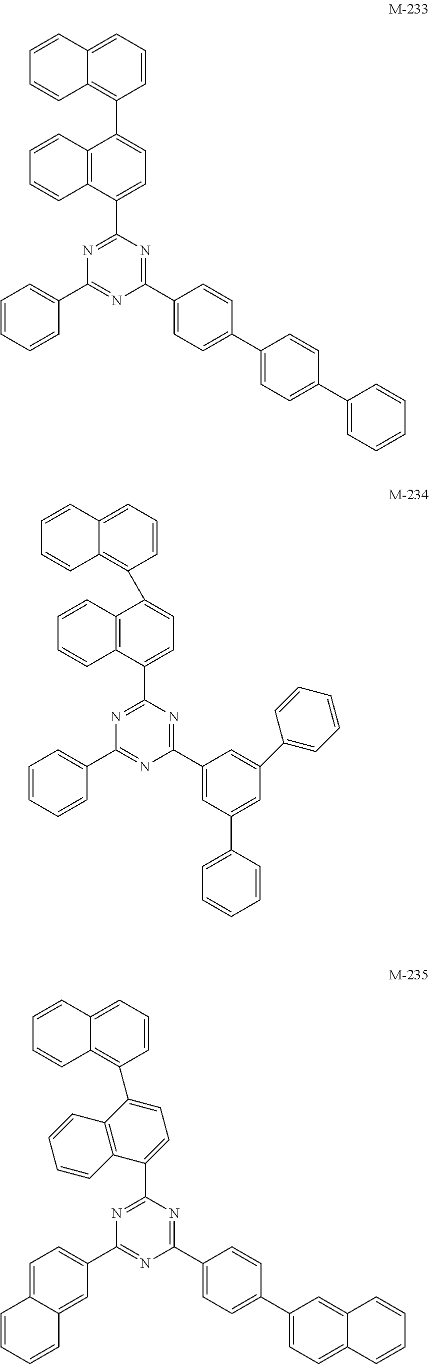 [SMILES: c1ccc(-c2ccc(-c3ccc(-c4nc(-c5ccccc5)nc(-c5ccc(-c6cccc7ccccc67)c6ccccc56)n4)cc3)cc2)cc1 ; c1ccc(-c2cc(-c3ccccc3)cc(-c3nc(-c4ccccc4)nc(-c4ccc(-c5cccc6ccccc56)c5ccccc45)n3)c2)cc1 ; c1ccc2cc(-c3ccc(-c4nc(-c5ccc6ccccc6c5)nc(-c5ccc(-c6cccc7ccccc67)c6ccccc56)n4)cc3)ccc2c1]

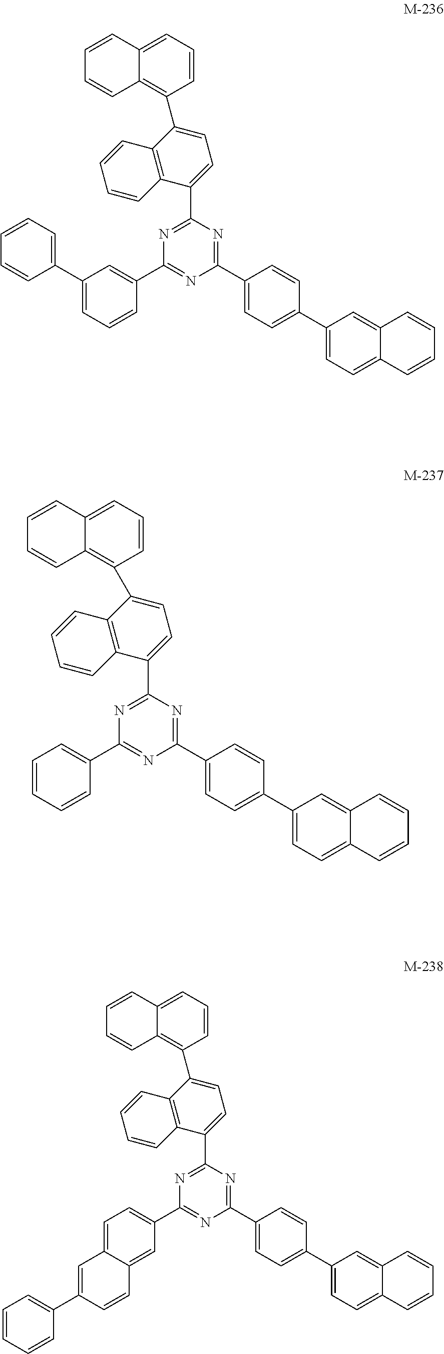 [SMILES: c1ccc(-c2cccc(-c3nc(-c4ccc(-c5ccc6ccccc6c5)cc4)nc(-c4ccc(-c5cccc6ccccc56)c5ccccc45)n3)c2)cc1 ; c1ccc(-c2nc(-c3ccc(-c4ccc5ccccc5c4)cc3)nc(-c3ccc(-c4cccc5ccccc45)c4ccccc34)n2)cc1 ; c1ccc(-c2ccc3cc(-c4nc(-c5ccc(-c6ccc7ccccc7c6)cc5)nc(-c5ccc(-c6cccc7ccccc67)c6ccccc56)n4)ccc3c2)cc1]

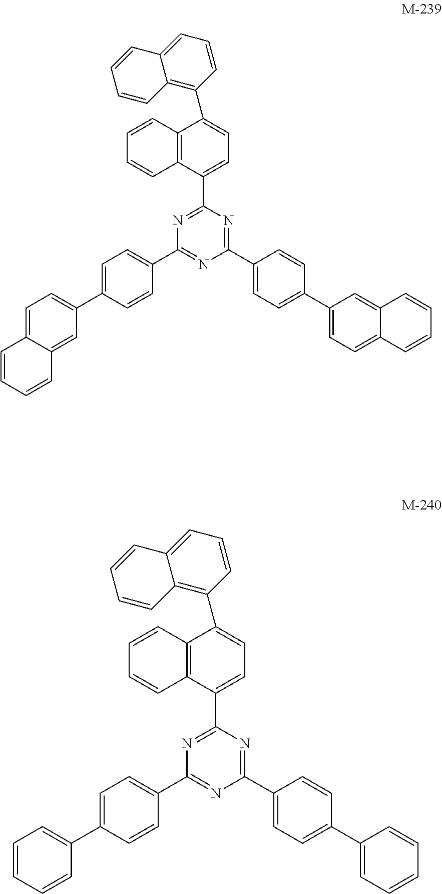 [SMILES: c1ccc2cc(-c3ccc(-c4nc(-c5ccc(-c6ccc7ccccc7c6)cc5)nc(-c5ccc(-c6cccc7ccccc67)c6ccccc56)n4)cc3)ccc2c1 ; c1ccc(-c2ccc(-c3nc(-c4ccc(-c5ccccc5)cc4)nc(-c4ccc(-c5cccc6ccccc56)c5ccccc45)n3)cc2)cc1]

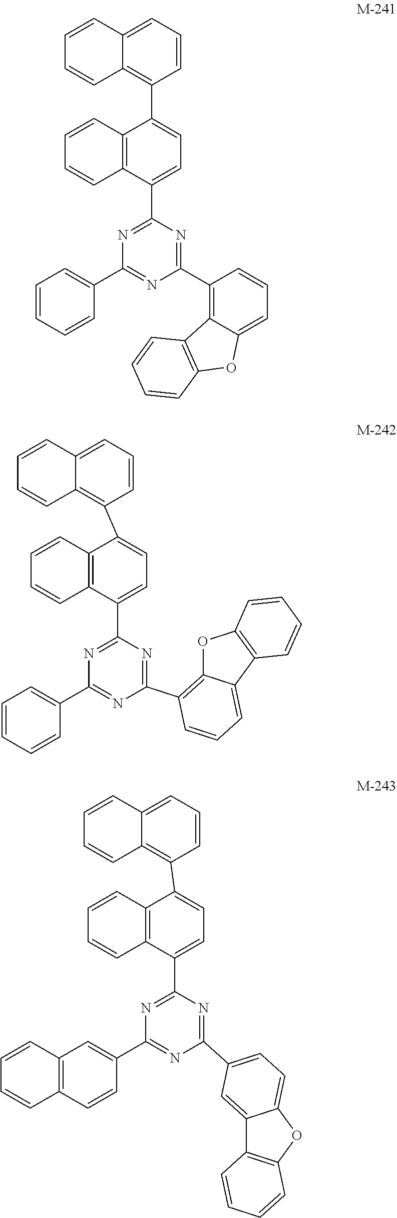 [SMILES: c1ccc(-c2nc(-c3ccc(-c4cccc5ccccc45)c4ccccc34)nc(-c3cccc4oc5ccccc5c34)n2)cc1 ; c1ccc(-c2nc(-c3ccc(-c4cccc5ccccc45)c4ccccc34)nc(-c3cccc4c3oc3ccccc34)n2)cc1 ; c1ccc2cc(-c3nc(-c4ccc5oc6ccccc6c5c4)nc(-c4ccc(-c5cccc6ccccc56)c5ccccc45)n3)ccc2c1]

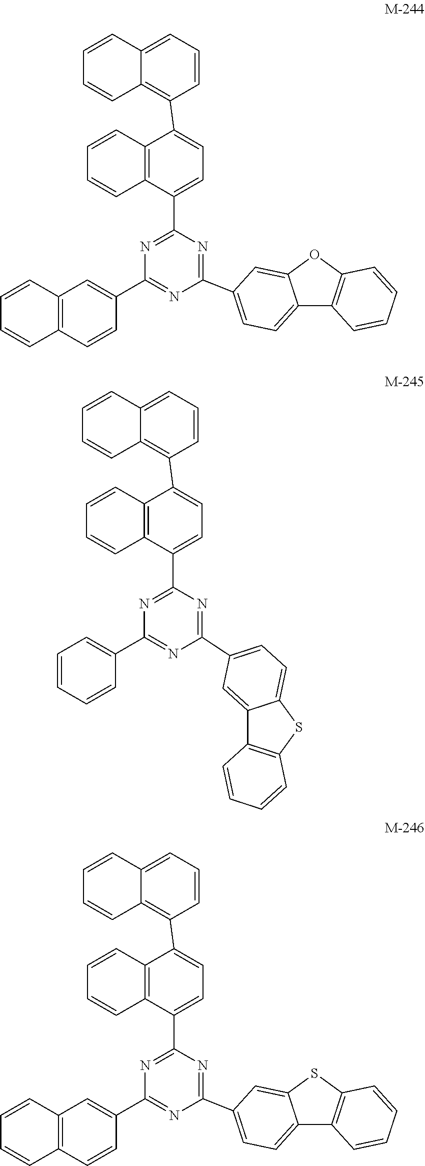 [SMILES: c1ccc2cc(-c3nc(-c4ccc5c(c4)oc4ccccc45)nc(-c4ccc(-c5cccc6ccccc56)c5ccccc45)n3)ccc2c1 ; c1ccc(-c2nc(-c3ccc4sc5ccccc5c4c3)nc(-c3ccc(-c4cccc5ccccc45)c4ccccc34)n2)cc1 ; c1ccc2cc(-c3nc(-c4ccc5c(c4)sc4ccccc45)nc(-c4ccc(-c5cccc6ccccc56)c5ccccc45)n3)ccc2c1]

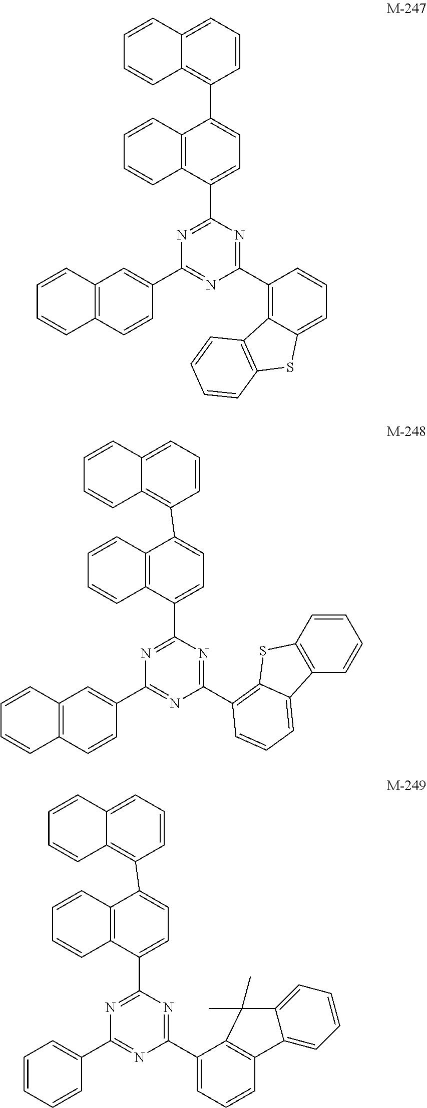

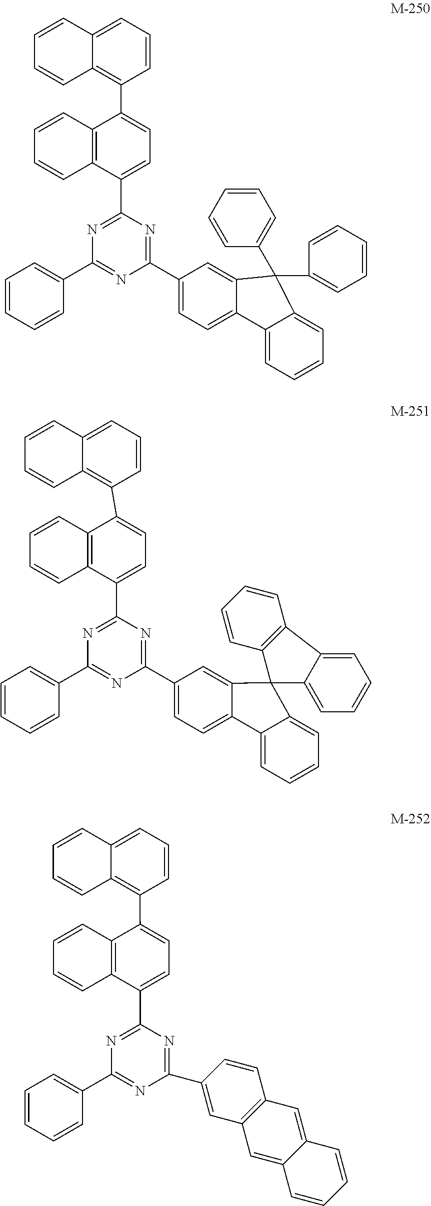 [SMILES: c1ccc(-c2nc(-c3ccc4c(c3)C(c3ccccc3)(c3ccccc3)c3ccccc3-4)nc(-c3ccc(-c4cccc5ccccc45)c4ccccc34)n2)cc1 ; c1ccc(-c2nc(-c3ccc4c(c3)C3(c5ccccc5-c5ccccc53)c3ccccc3-4)nc(-c3ccc(-c4cccc5ccccc45)c4ccccc34)n2)cc1 ; c1ccc(-c2nc(-c3ccc4cc5ccccc5cc4c3)nc(-c3ccc(-c4cccc5ccccc45)c4ccccc34)n2)cc1]

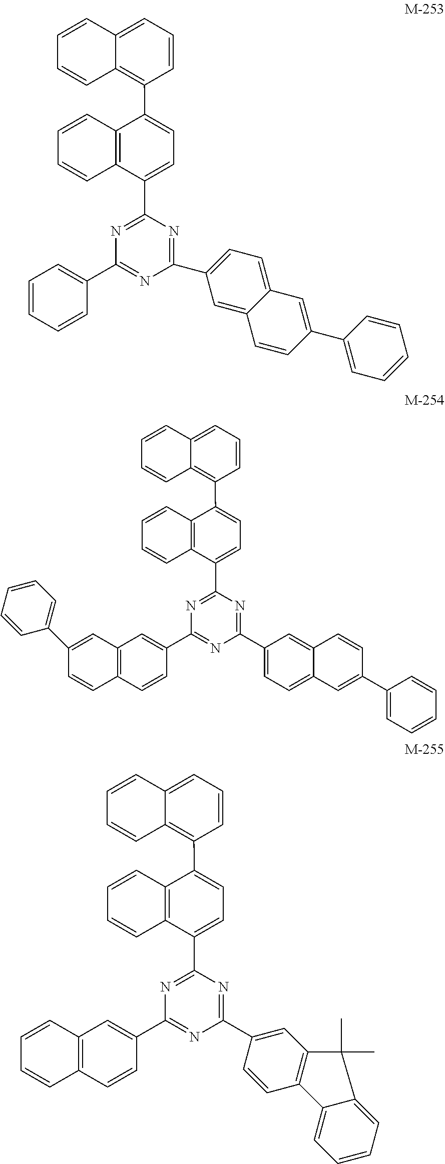 [SMILES: c1ccc(-c2ccc3cc(-c4nc(-c5ccccc5)nc(-c5ccc(-c6cccc7ccccc67)c6ccccc56)n4)ccc3c2)cc1 ; c1ccc(-c2ccc3cc(-c4nc(-c5ccc6ccc(-c7ccccc7)cc6c5)nc(-c5ccc(-c6cccc7ccccc67)c6ccccc56)n4)ccc3c2)cc1 ; CC1(C)c2ccccc2-c2ccc(-c3nc(-c4ccc5ccccc5c4)nc(-c4ccc(-c5cccc6ccccc56)c5ccccc45)n3)cc21]

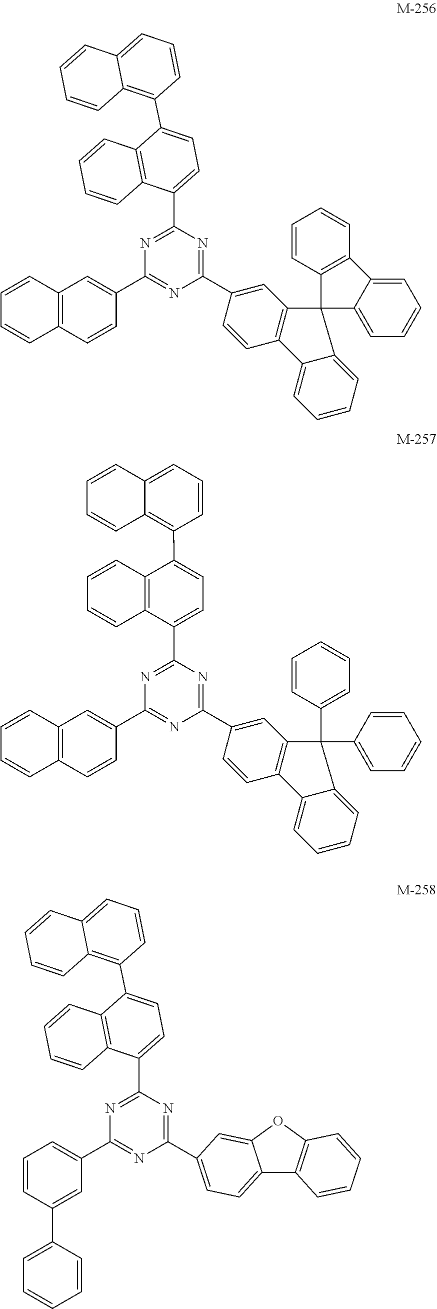 [SMILES: c1ccc2c(c1)-c1ccccc1C21c2ccccc2-c2ccc(-c3nc(-c4ccc5ccccc5c4)nc(-c4ccc(-c5cccc6ccccc56)c5ccccc45)n3)cc21 ; c1ccc(C2(c3ccccc3)c3ccccc3-c3ccc(-c4nc(-c5ccc6ccccc6c5)nc(-c5ccc(-c6cccc7ccccc67)c6ccccc56)n4)cc32)cc1 ; c1ccc(-c2cccc(-c3nc(-c4ccc5c(c4)oc4ccccc45)nc(-c4ccc(-c5cccc6ccccc56)c5ccccc45)n3)c2)cc1]

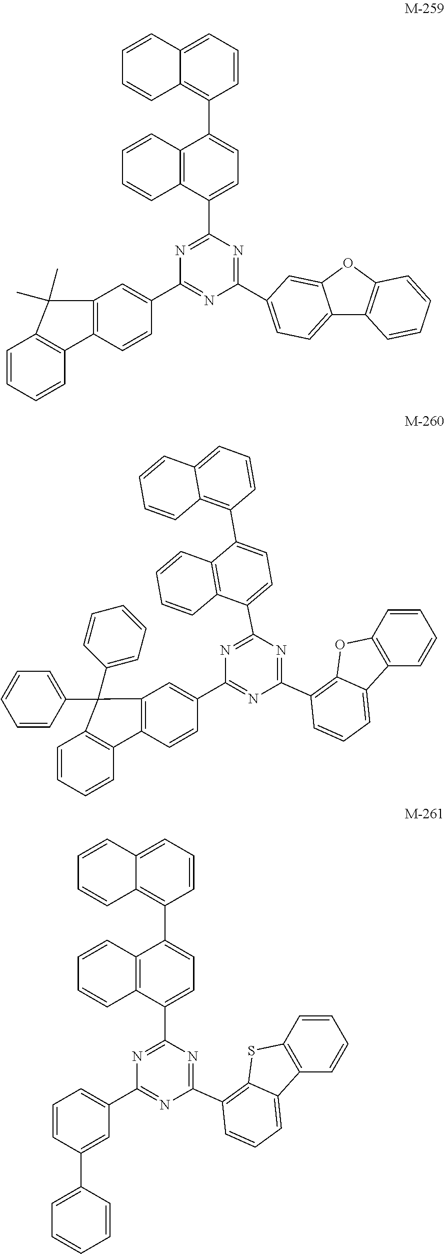 [SMILES: CC1(C)c2ccccc2-c2ccc(-c3nc(-c4ccc5c(c4)oc4ccccc45)nc(-c4ccc(-c5cccc6ccccc56)c5ccccc45)n3)cc21 ; c1ccc(C2(c3ccccc3)c3ccccc3-c3ccc(-c4nc(-c5ccc(-c6cccc7ccccc67)c6ccccc56)nc(-c5cccc6c5oc5ccccc56)n4)cc32)cc1 ; c1ccc(-c2cccc(-c3nc(-c4ccc(-c5cccc6ccccc56)c5ccccc45)nc(-c4cccc5c4sc4ccccc45)n3)c2)cc1]

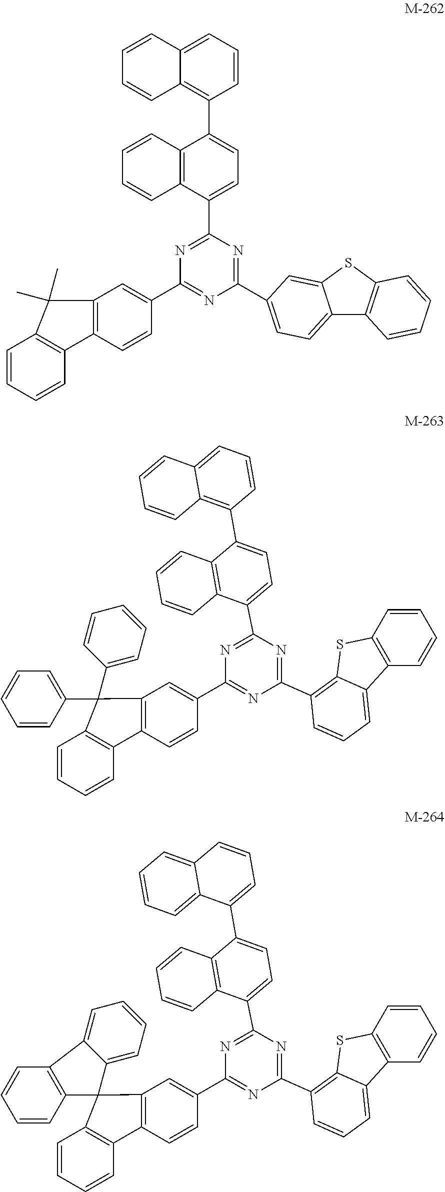 [SMILES: CC1(C)c2ccccc2-c2ccc(-c3nc(-c4ccc5c(c4)sc4ccccc45)nc(-c4ccc(-c5cccc6ccccc56)c5ccccc45)n3)cc21 ; c1ccc(C2(c3ccccc3)c3ccccc3-c3ccc(-c4nc(-c5ccc(-c6cccc7ccccc67)c6ccccc56)nc(-c5cccc6c5sc5ccccc56)n4)cc32)cc1 ; c1ccc2c(c1)-c1ccccc1C21c2ccccc2-c2ccc(-c3nc(-c4ccc(-c5cccc6ccccc56)c5ccccc45)nc(-c4cccc5c4sc4ccccc45)n3)cc21]

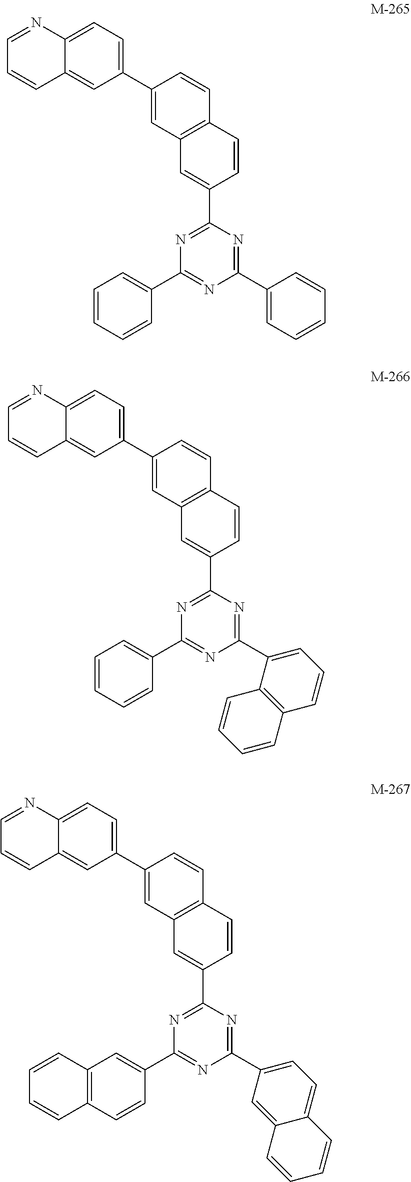 [SMILES: c1ccc(-c2nc(-c3ccccc3)nc(-c3ccc4ccc(-c5ccc6ncccc6c5)cc4c3)n2)cc1 ; c1ccc(-c2nc(-c3ccc4ccc(-c5ccc6ncccc6c5)cc4c3)nc(-c3cccc4ccccc34)n2)cc1 ; c1ccc2cc(-c3nc(-c4ccc5ccccc5c4)nc(-c4ccc5ccc(-c6ccc7ncccc7c6)cc5c4)n3)ccc2c1]

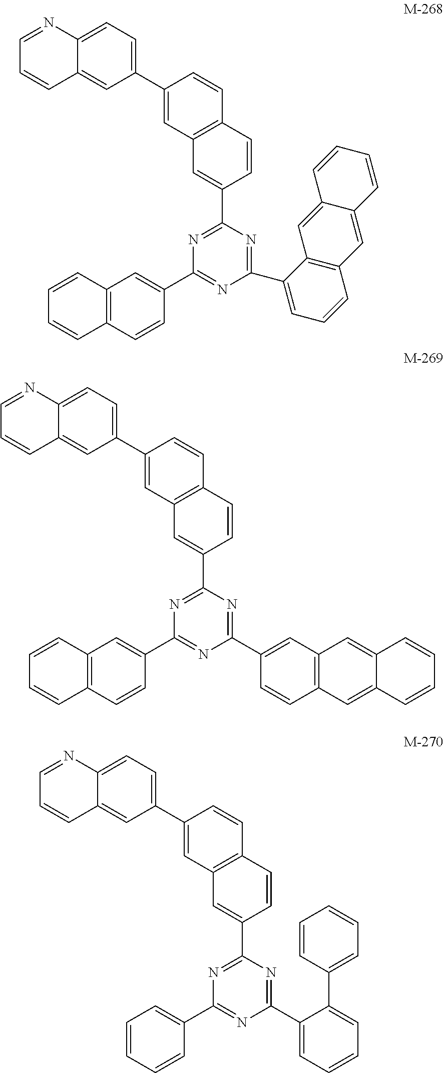 [SMILES: c1ccc2cc(-c3nc(-c4ccc5ccc(-c6ccc7ncccc7c6)cc5c4)nc(-c4cccc5cc6ccccc6cc45)n3)ccc2c1 ; c1ccc2cc(-c3nc(-c4ccc5ccc(-c6ccc7ncccc7c6)cc5c4)nc(-c4ccc5cc6ccccc6cc5c4)n3)ccc2c1 ; c1ccc(-c2nc(-c3ccc4ccc(-c5ccc6ncccc6c5)cc4c3)nc(-c3ccccc3-c3ccccc3)n2)cc1]

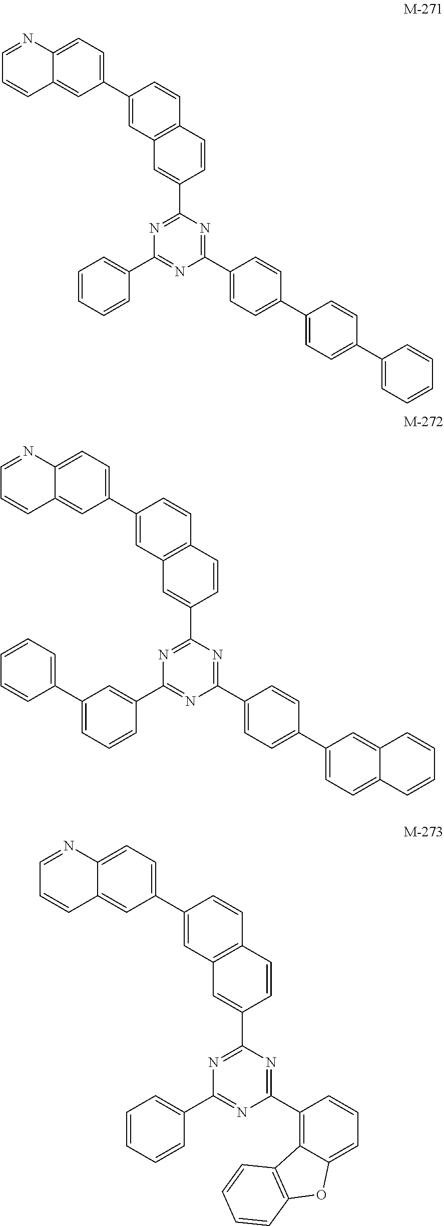 [SMILES: c1ccc(-c2ccc(-c3ccc(-c4nc(-c5ccccc5)nc(-c5ccc6ccc(-c7ccc8ncccc8c7)cc6c5)n4)cc3)cc2)cc1 ; c1ccc(-c2cccc(-c3nc(-c4ccc(-c5ccc6ccccc6c5)cc4)nc(-c4ccc5ccc(-c6ccc7ncccc7c6)cc5c4)n3)c2)cc1 ; c1ccc(-c2nc(-c3ccc4ccc(-c5ccc6ncccc6c5)cc4c3)nc(-c3cccc4oc5ccccc5c34)n2)cc1]

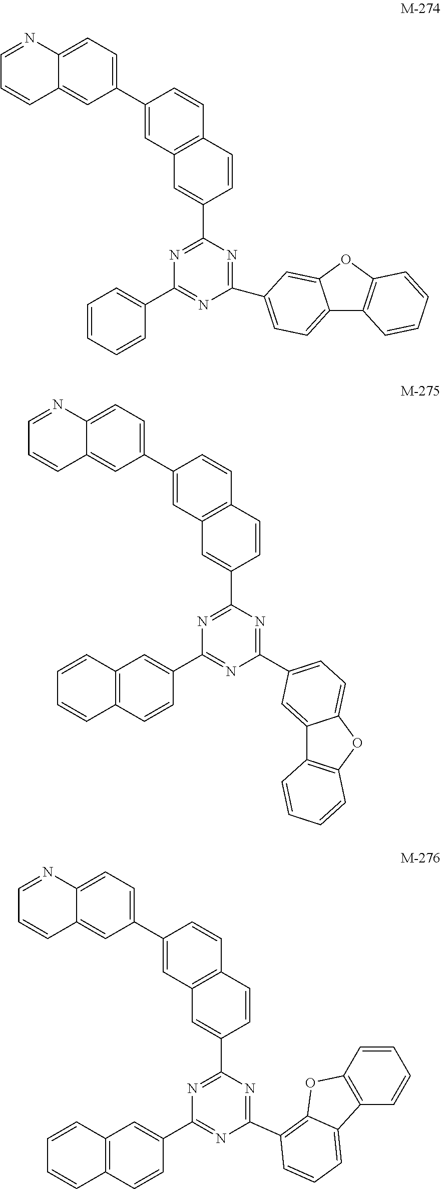 [SMILES: c1ccc(-c2nc(-c3ccc4ccc(-c5ccc6ncccc6c5)cc4c3)nc(-c3ccc4c(c3)oc3ccccc34)n2)cc1 ; c1ccc2cc(-c3nc(-c4ccc5ccc(-c6ccc7ncccc7c6)cc5c4)nc(-c4ccc5oc6ccccc6c5c4)n3)ccc2c1 ; c1ccc2cc(-c3nc(-c4ccc5ccc(-c6ccc7ncccc7c6)cc5c4)nc(-c4cccc5c4oc4ccccc45)n3)ccc2c1]

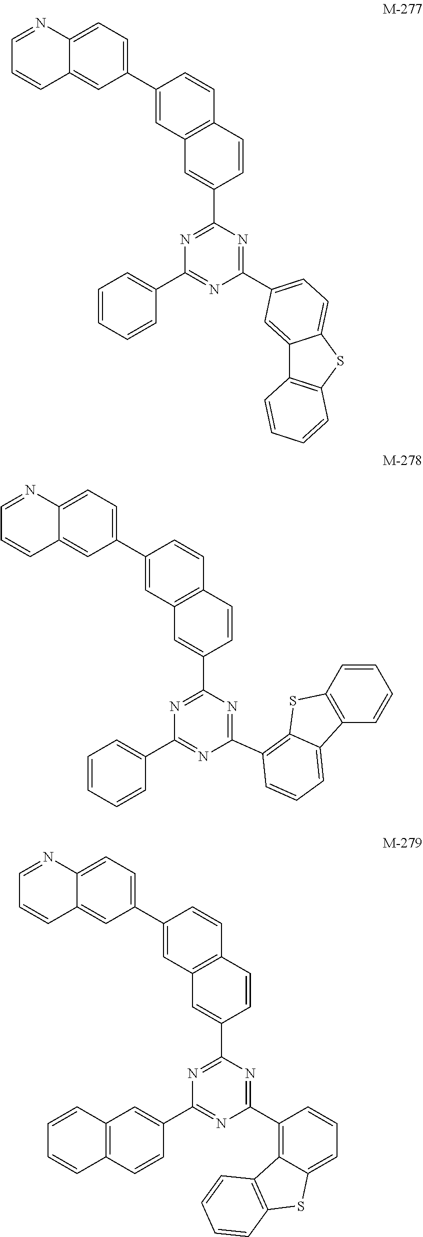 [SMILES: c1ccc(-c2nc(-c3ccc4ccc(-c5ccc6ncccc6c5)cc4c3)nc(-c3ccc4sc5ccccc5c4c3)n2)cc1 ; c1ccc(-c2nc(-c3ccc4ccc(-c5ccc6ncccc6c5)cc4c3)nc(-c3cccc4c3sc3ccccc34)n2)cc1 ; c1ccc2cc(-c3nc(-c4ccc5ccc(-c6ccc7ncccc7c6)cc5c4)nc(-c4cccc5sc6ccccc6c45)n3)ccc2c1]

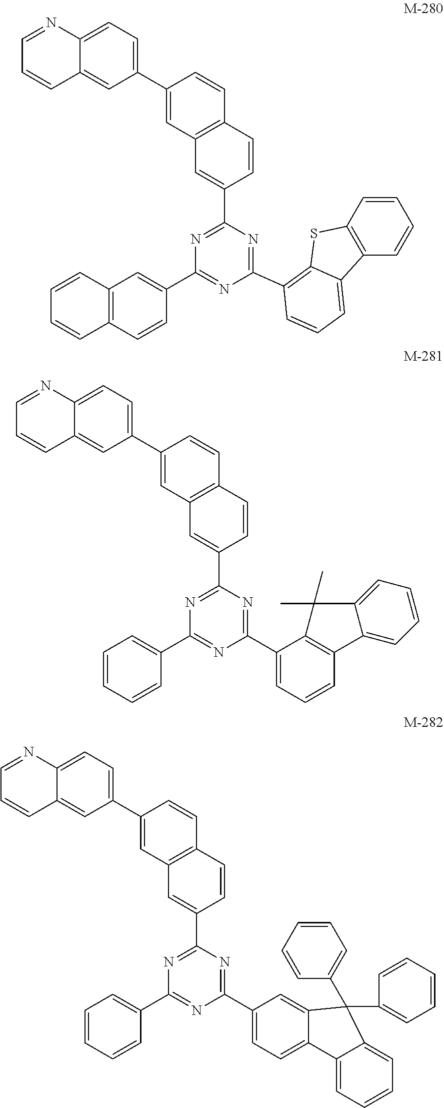 [SMILES: c1ccc2cc(-c3nc(-c4ccc5ccc(-c6ccc7ncccc7c6)cc5c4)nc(-c4cccc5c4sc4ccccc45)n3)ccc2c1 ; CC1(C)c2ccccc2-c2cccc(-c3nc(-c4ccccc4)nc(-c4ccc5ccc(-c6ccc7ncccc7c6)cc5c4)n3)c21 ; c1ccc(-c2nc(-c3ccc4c(c3)C(c3ccccc3)(c3ccccc3)c3ccccc3-4)nc(-c3ccc4ccc(-c5ccc6ncccc6c5)cc4c3)n2)cc1]

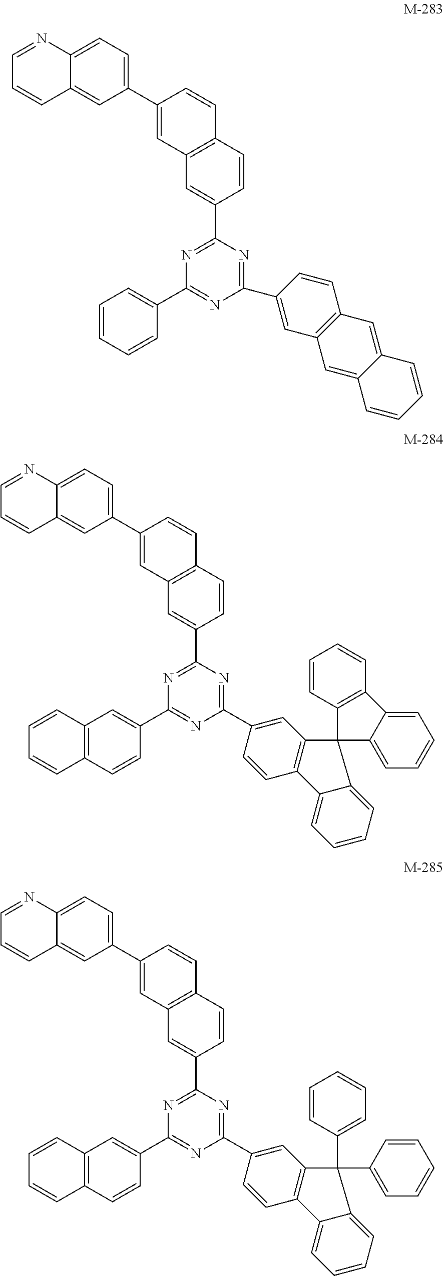 [SMILES: c1ccc(-c2nc(-c3ccc4ccc(-c5ccc6ncccc6c5)cc4c3)nc(-c3ccc4cc5ccccc5cc4c3)n2)cc1 ; c1ccc2c(c1)-c1ccccc1C21c2ccccc2-c2ccc(-c3nc(-c4ccc5ccccc5c4)nc(-c4ccc5ccc(-c6ccc7ncccc7c6)cc5c4)n3)cc21 ; c1ccc(C2(c3ccccc3)c3ccccc3-c3ccc(-c4nc(-c5ccc6ccccc6c5)nc(-c5ccc6ccc(-c7ccc8ncccc8c7)cc6c5)n4)cc32)cc1]

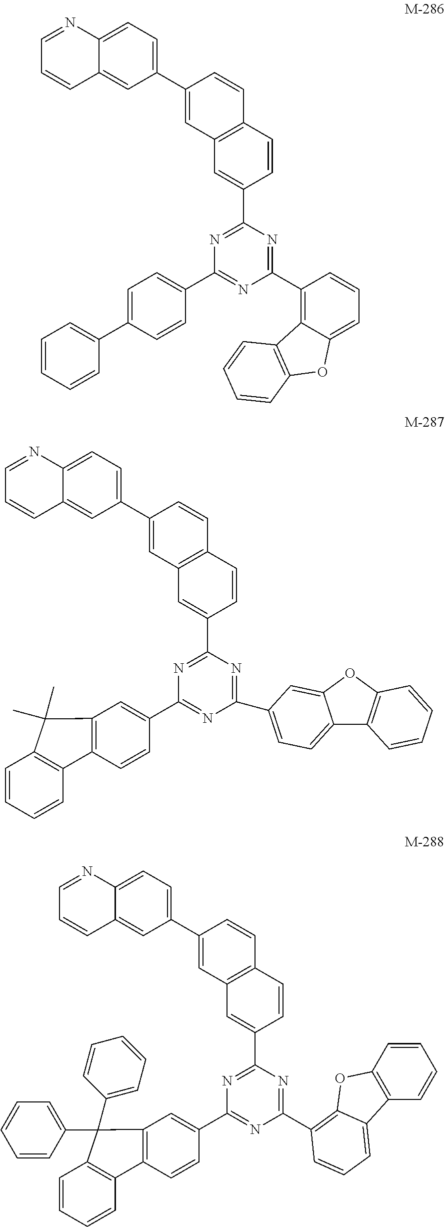 [SMILES: c1ccc(-c2ccc(-c3nc(-c4ccc5ccc(-c6ccc7ncccc7c6)cc5c4)nc(-c4cccc5oc6ccccc6c45)n3)cc2)cc1 ; CC1(C)c2ccccc2-c2ccc(-c3nc(-c4ccc5ccc(-c6ccc7ncccc7c6)cc5c4)nc(-c4ccc5c(c4)oc4ccccc45)n3)cc21 ; c1ccc(C2(c3ccccc3)c3ccccc3-c3ccc(-c4nc(-c5ccc6ccc(-c7ccc8ncccc8c7)cc6c5)nc(-c5cccc6c5oc5ccccc56)n4)cc32)cc1]

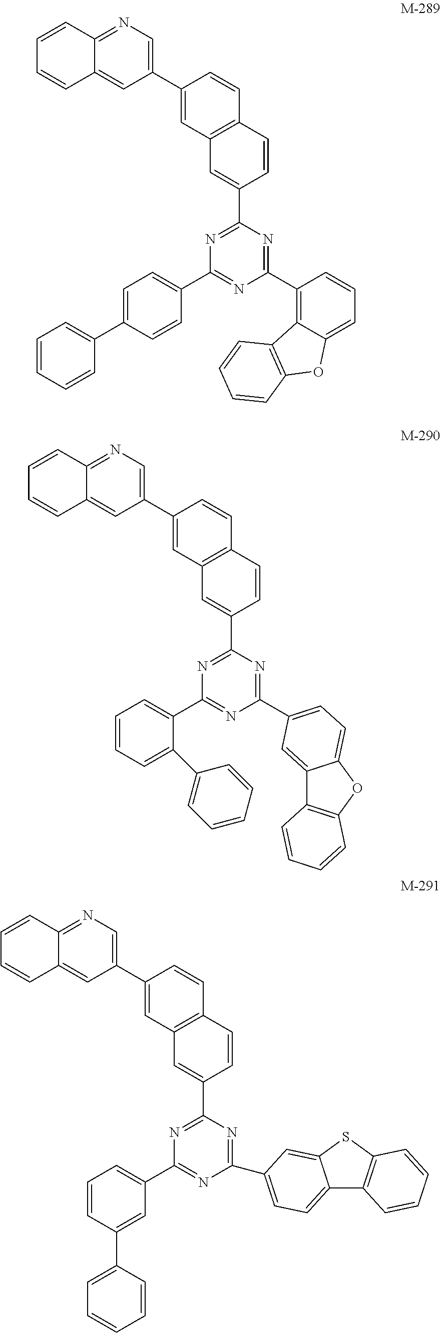 [SMILES: c1ccc(-c2ccc(-c3nc(-c4ccc5ccc(-c6cnc7ccccc7c6)cc5c4)nc(-c4cccc5oc6ccccc6c45)n3)cc2)cc1 ; c1ccc(-c2ccccc2-c2nc(-c3ccc4ccc(-c5cnc6ccccc6c5)cc4c3)nc(-c3ccc4oc5ccccc5c4c3)n2)cc1 ; c1ccc(-c2cccc(-c3nc(-c4ccc5ccc(-c6cnc7ccccc7c6)cc5c4)nc(-c4ccc5c(c4)sc4ccccc45)n3)c2)cc1]

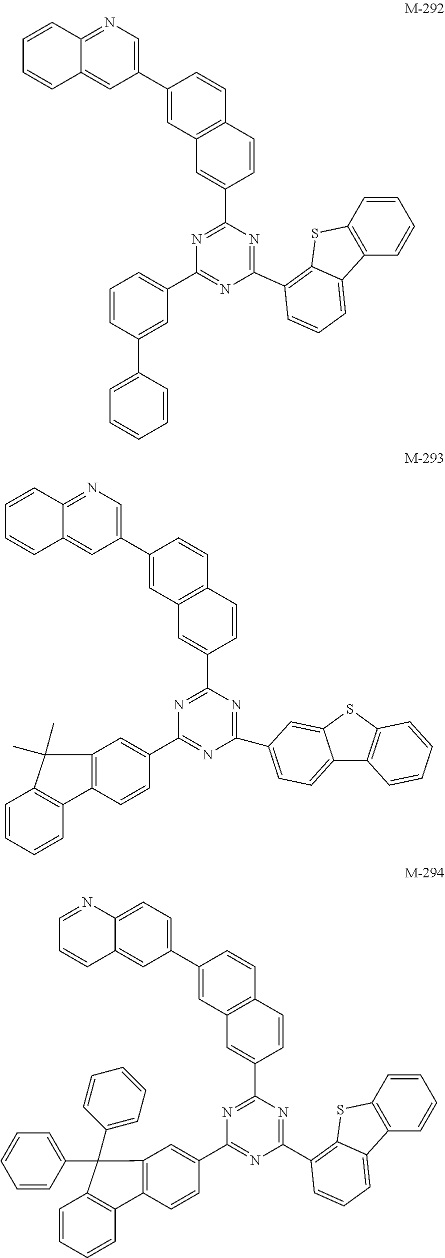 [SMILES: c1ccc(-c2cccc(-c3nc(-c4ccc5ccc(-c6cnc7ccccc7c6)cc5c4)nc(-c4cccc5c4sc4ccccc45)n3)c2)cc1 ; CC1(C)c2ccccc2-c2ccc(-c3nc(-c4ccc5ccc(-c6cnc7ccccc7c6)cc5c4)nc(-c4ccc5c(c4)sc4ccccc45)n3)cc21 ; c1ccc(C2(c3ccccc3)c3ccccc3-c3ccc(-c4nc(-c5ccc6ccc(-c7ccc8ncccc8c7)cc6c5)nc(-c5cccc6c5sc5ccccc56)n4)cc32)cc1]

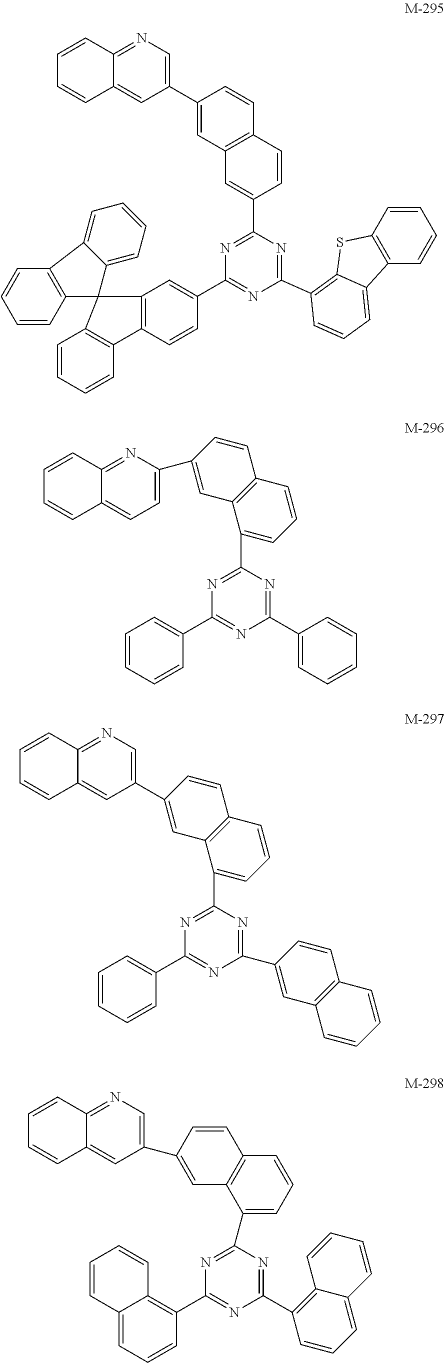 [SMILES: c1ccc2c(c1)-c1ccccc1C21c2ccccc2-c2ccc(-c3nc(-c4ccc5ccc(-c6cnc7ccccc7c6)cc5c4)nc(-c4cccc5c4sc4ccccc45)n3)cc21 ; c1ccc(-c2nc(-c3ccccc3)nc(-c3cccc4ccc(-c5ccc6ccccc6n5)cc34)n2)cc1 ; c1ccc(-c2nc(-c3ccc4ccccc4c3)nc(-c3cccc4ccc(-c5cnc6ccccc6c5)cc34)n2)cc1 ; c1ccc2ncc(-c3ccc4cccc(-c5nc(-c6cccc7ccccc67)nc(-c6cccc7ccccc67)n5)c4c3)cc2c1]

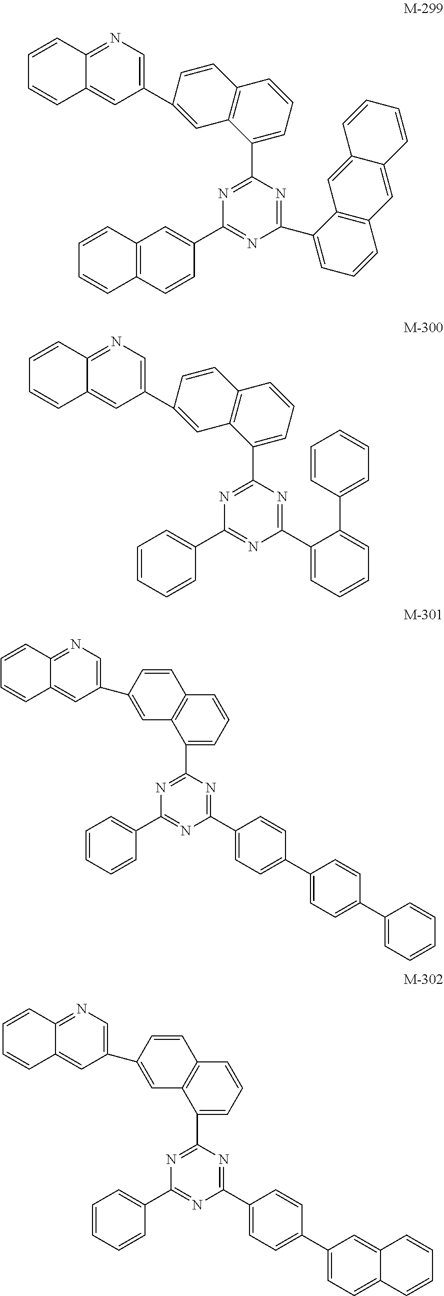 [SMILES: c1ccc2cc(-c3nc(-c4cccc5ccc(-c6cnc7ccccc7c6)cc45)nc(-c4cccc5cc6ccccc6cc45)n3)ccc2c1 ; c1ccc(-c2nc(-c3ccccc3-c3ccccc3)nc(-c3cccc4ccc(-c5cnc6ccccc6c5)cc34)n2)cc1 ; c1ccc(-c2ccc(-c3ccc(-c4nc(-c5ccccc5)nc(-c5cccc6ccc(-c7cnc8ccccc8c7)cc56)n4)cc3)cc2)cc1 ; c1ccc(-c2nc(-c3ccc(-c4ccc5ccccc5c4)cc3)nc(-c3cccc4ccc(-c5cnc6ccccc6c5)cc34)n2)cc1]

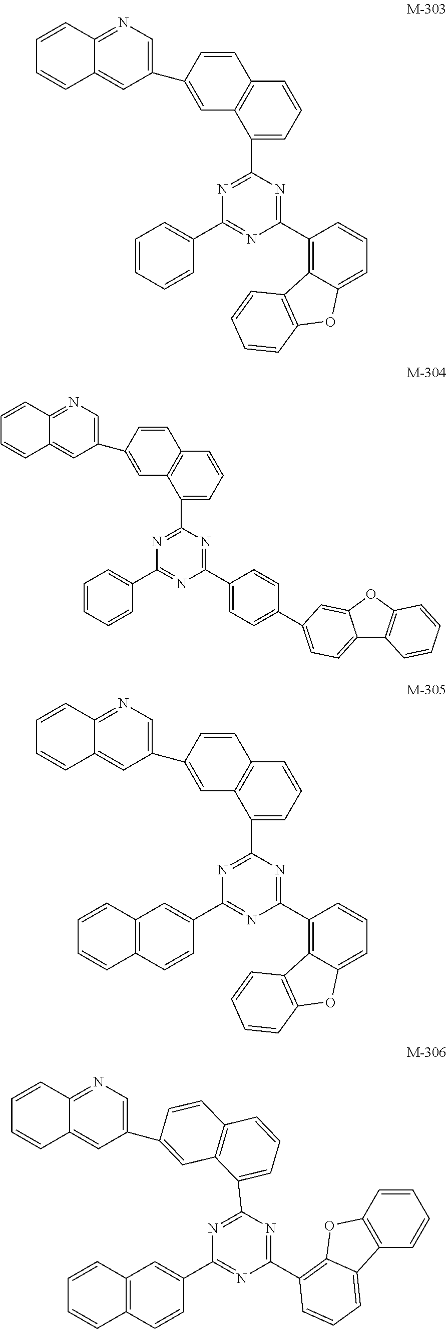 [SMILES: c1ccc(-c2nc(-c3cccc4ccc(-c5cnc6ccccc6c5)cc34)nc(-c3cccc4oc5ccccc5c34)n2)cc1 ; c1ccc(-c2nc(-c3ccc(-c4ccc5c(c4)oc4ccccc45)cc3)nc(-c3cccc4ccc(-c5cnc6ccccc6c5)cc34)n2)cc1 ; c1ccc2cc(-c3nc(-c4cccc5ccc(-c6cnc7ccccc7c6)cc45)nc(-c4cccc5oc6ccccc6c45)n3)ccc2c1 ; c1ccc2cc(-c3nc(-c4cccc5ccc(-c6cnc7ccccc7c6)cc45)nc(-c4cccc5c4oc4ccccc45)n3)ccc2c1]

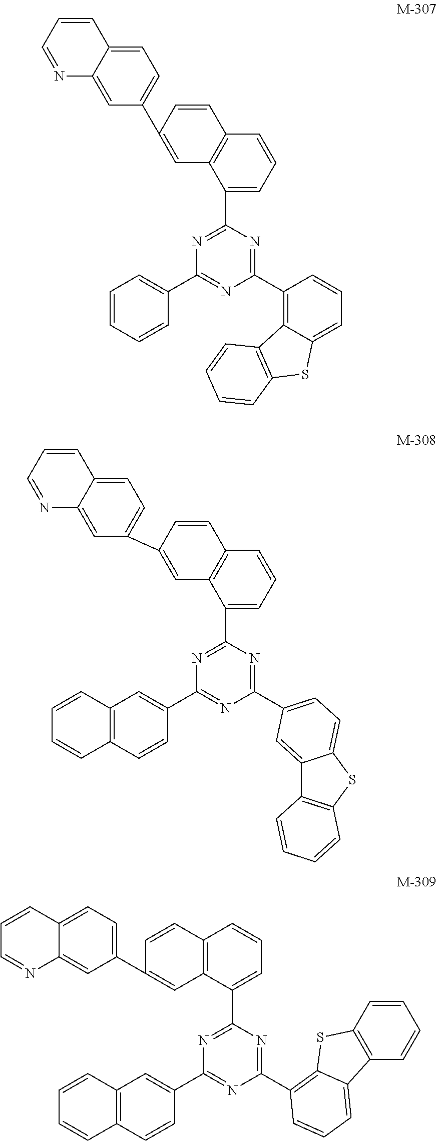 [SMILES: c1ccc(-c2nc(-c3cccc4ccc(-c5ccc6cccnc6c5)cc34)nc(-c3cccc4sc5ccccc5c34)n2)cc1 ; c1ccc2cc(-c3nc(-c4ccc5sc6ccccc6c5c4)nc(-c4cccc5ccc(-c6ccc7cccnc7c6)cc45)n3)ccc2c1 ; c1ccc2cc(-c3nc(-c4cccc5ccc(-c6ccc7cccnc7c6)cc45)nc(-c4cccc5c4sc4ccccc45)n3)ccc2c1]

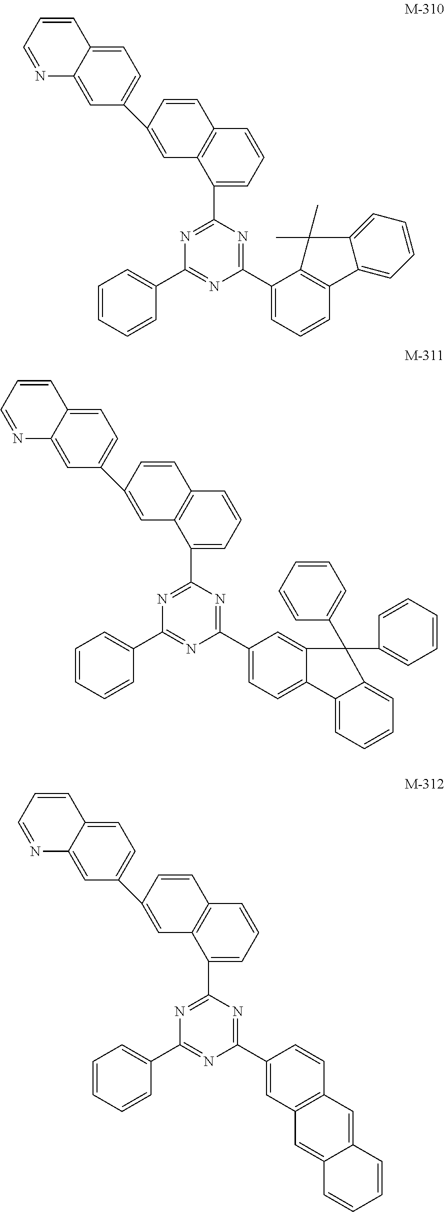 [SMILES: CC1(C)c2ccccc2-c2cccc(-c3nc(-c4ccccc4)nc(-c4cccc5ccc(-c6ccc7cccnc7c6)cc45)n3)c21 ; c1ccc(-c2nc(-c3ccc4c(c3)C(c3ccccc3)(c3ccccc3)c3ccccc3-4)nc(-c3cccc4ccc(-c5ccc6cccnc6c5)cc34)n2)cc1 ; c1ccc(-c2nc(-c3ccc4cc5ccccc5cc4c3)nc(-c3cccc4ccc(-c5ccc6cccnc6c5)cc34)n2)cc1]

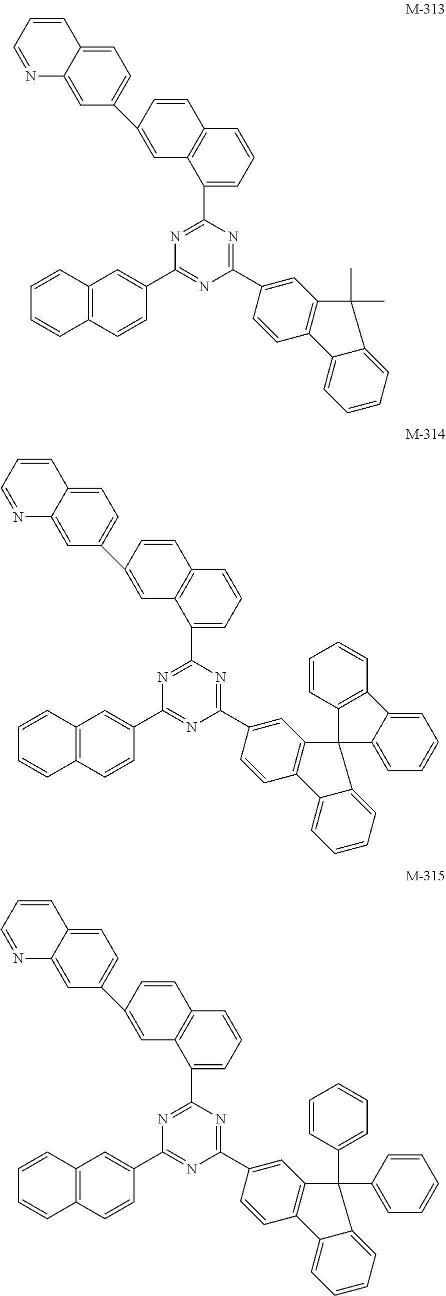 [SMILES: CC1(C)c2ccccc2-c2ccc(-c3nc(-c4ccc5ccccc5c4)nc(-c4cccc5ccc(-c6ccc7cccnc7c6)cc45)n3)cc21 ; c1ccc2c(c1)-c1ccccc1C21c2ccccc2-c2ccc(-c3nc(-c4ccc5ccccc5c4)nc(-c4cccc5ccc(-c6ccc7cccnc7c6)cc45)n3)cc21 ; c1ccc(C2(c3ccccc3)c3ccccc3-c3ccc(-c4nc(-c5ccc6ccccc6c5)nc(-c5cccc6ccc(-c7ccc8cccnc8c7)cc56)n4)cc32)cc1]

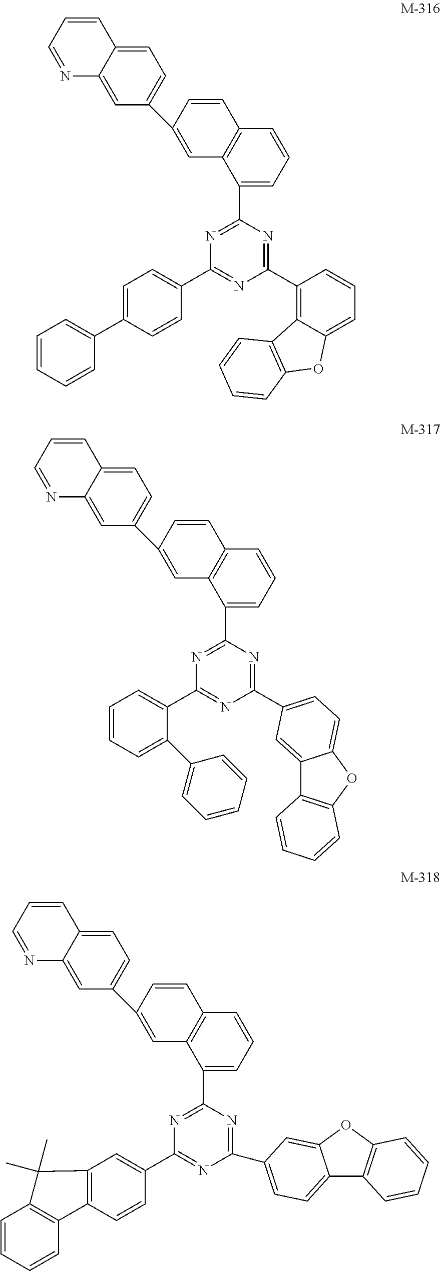 [SMILES: c1ccc(-c2ccc(-c3nc(-c4cccc5ccc(-c6ccc7cccnc7c6)cc45)nc(-c4cccc5oc6ccccc6c45)n3)cc2)cc1 ; c1ccc(-c2ccccc2-c2nc(-c3ccc4oc5ccccc5c4c3)nc(-c3cccc4ccc(-c5ccc6cccnc6c5)cc34)n2)cc1 ; CC1(C)c2ccccc2-c2ccc(-c3nc(-c4ccc5c(c4)oc4ccccc45)nc(-c4cccc5ccc(-c6ccc7cccnc7c6)cc45)n3)cc21]

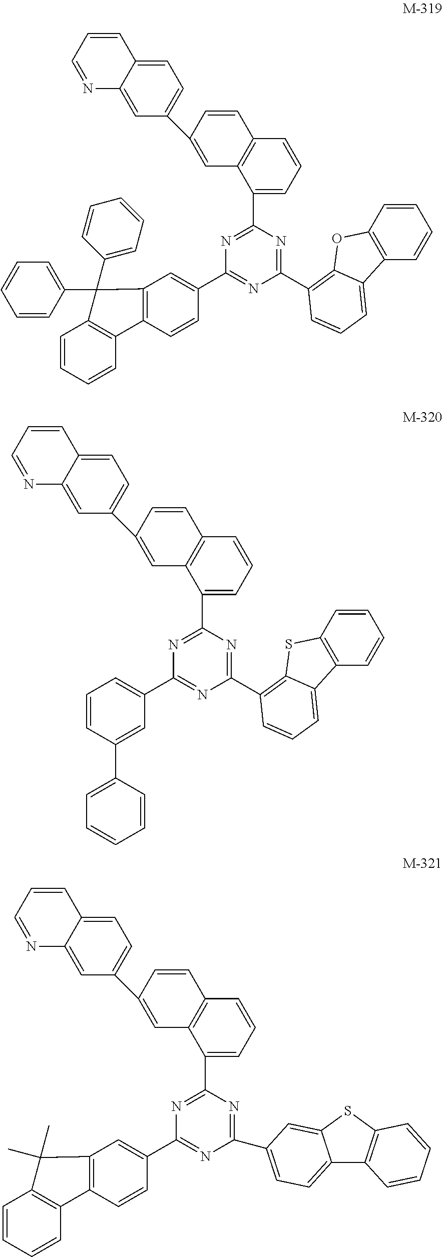 [SMILES: c1ccc(C2(c3ccccc3)c3ccccc3-c3ccc(-c4nc(-c5cccc6ccc(-c7ccc8cccnc8c7)cc56)nc(-c5cccc6c5oc5ccccc56)n4)cc32)cc1 ; c1ccc(-c2cccc(-c3nc(-c4cccc5ccc(-c6ccc7cccnc7c6)cc45)nc(-c4cccc5c4sc4ccccc45)n3)c2)cc1 ; CC1(C)c2ccccc2-c2ccc(-c3nc(-c4ccc5c(c4)sc4ccccc45)nc(-c4cccc5ccc(-c6ccc7cccnc7c6)cc45)n3)cc21]

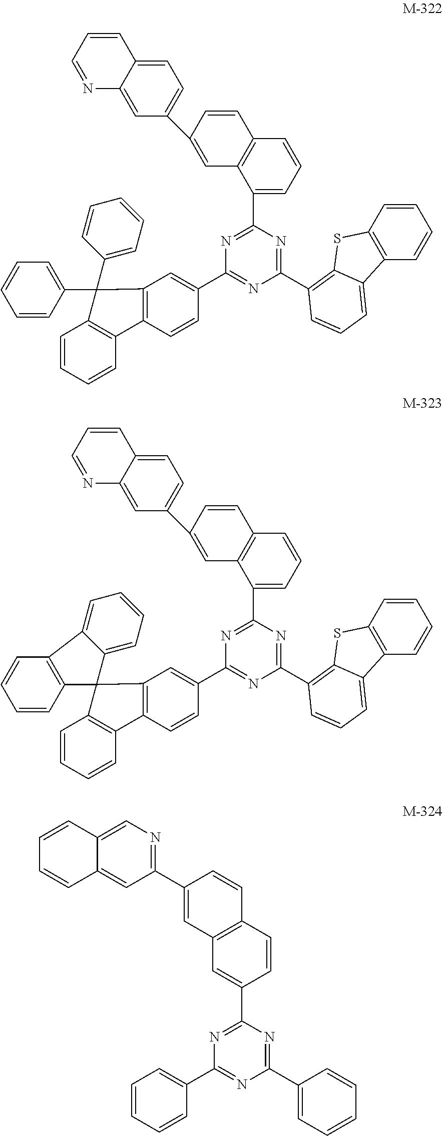

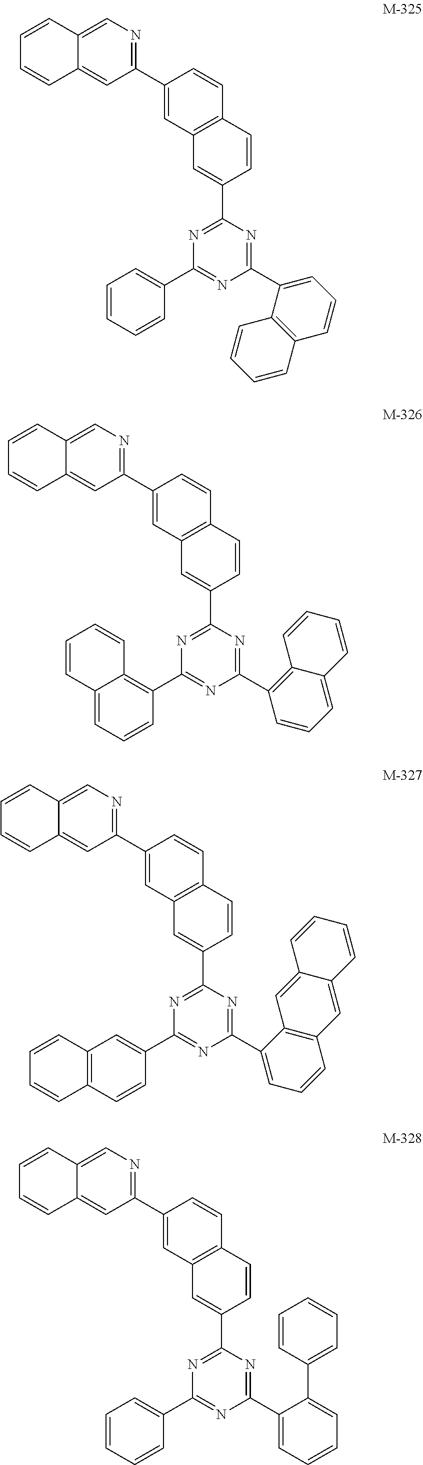 [SMILES: c1ccc(-c2nc(-c3ccc4ccc(-c5cc6ccccc6cn5)cc4c3)nc(-c3cccc4ccccc34)n2)cc1 ; c1ccc2cc(-c3ccc4ccc(-c5nc(-c6cccc7ccccc67)nc(-c6cccc7ccccc67)n5)cc4c3)ncc2c1 ; c1ccc2cc(-c3nc(-c4ccc5ccc(-c6cc7ccccc7cn6)cc5c4)nc(-c4cccc5cc6ccccc6cc45)n3)ccc2c1 ; c1ccc(-c2nc(-c3ccc4ccc(-c5cc6ccccc6cn5)cc4c3)nc(-c3ccccc3-c3ccccc3)n2)cc1]

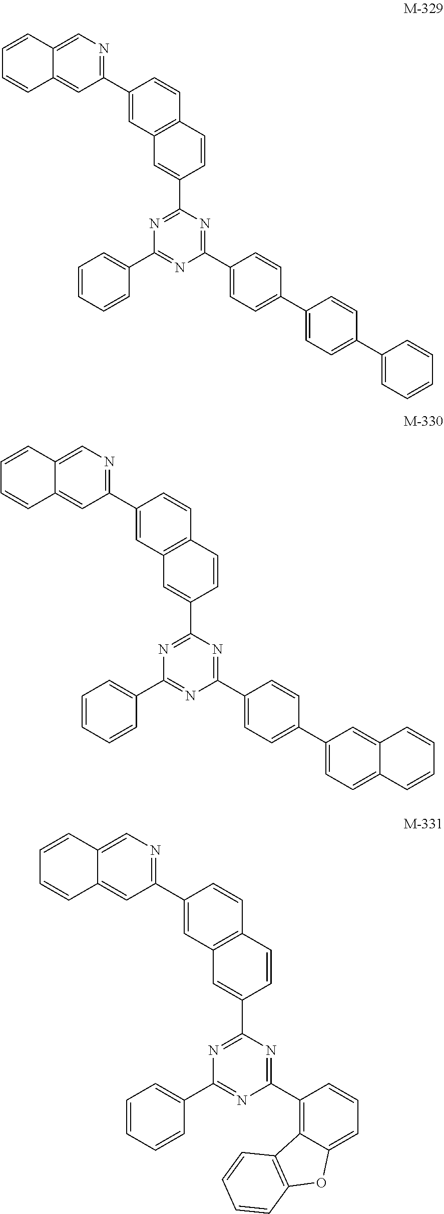 [SMILES: c1ccc(-c2ccc(-c3ccc(-c4nc(-c5ccccc5)nc(-c5ccc6ccc(-c7cc8ccccc8cn7)cc6c5)n4)cc3)cc2)cc1 ; c1ccc(-c2nc(-c3ccc(-c4ccc5ccccc5c4)cc3)nc(-c3ccc4ccc(-c5cc6ccccc6cn5)cc4c3)n2)cc1 ; c1ccc(-c2nc(-c3ccc4ccc(-c5cc6ccccc6cn5)cc4c3)nc(-c3cccc4oc5ccccc5c34)n2)cc1]

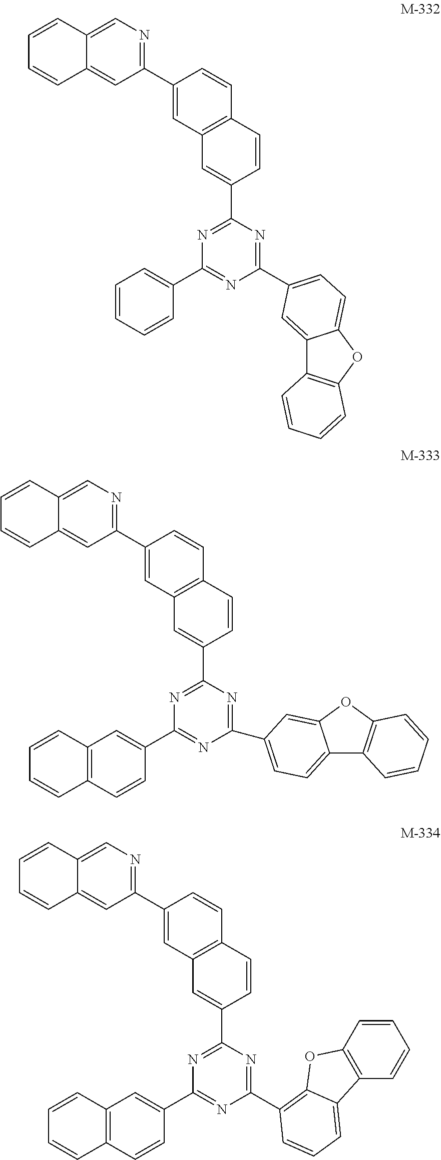

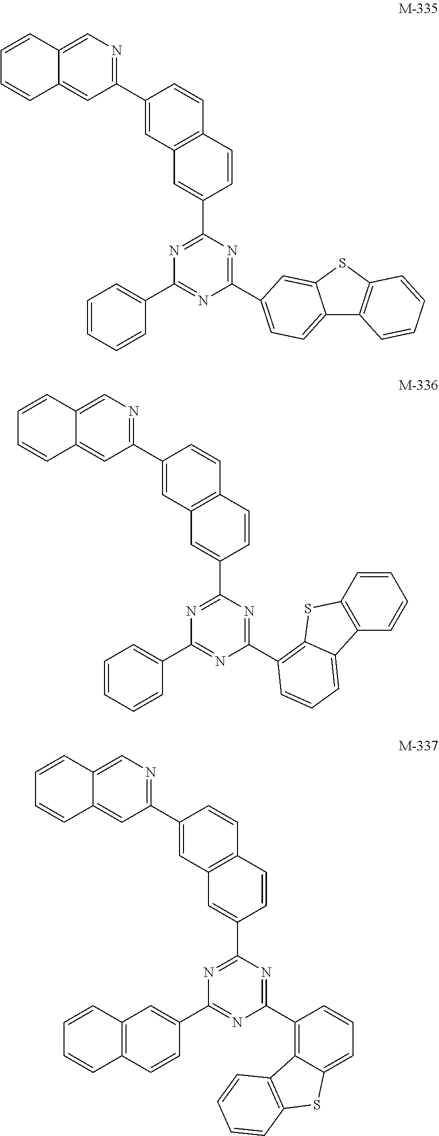

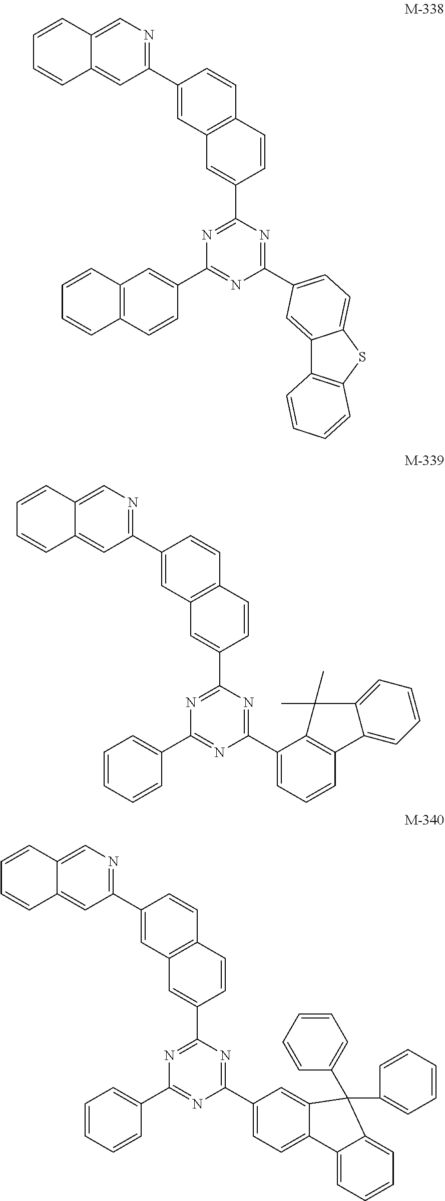 [SMILES: c1ccc2cc(-c3nc(-c4ccc5ccc(-c6cc7ccccc7cn6)cc5c4)nc(-c4ccc5sc6ccccc6c5c4)n3)ccc2c1 ; CC1(C)c2ccccc2-c2cccc(-c3nc(-c4ccccc4)nc(-c4ccc5ccc(-c6cc7ccccc7cn6)cc5c4)n3)c21 ; c1ccc(-c2nc(-c3ccc4c(c3)C(c3ccccc3)(c3ccccc3)c3ccccc3-4)nc(-c3ccc4ccc(-c5cc6ccccc6cn5)cc4c3)n2)cc1]

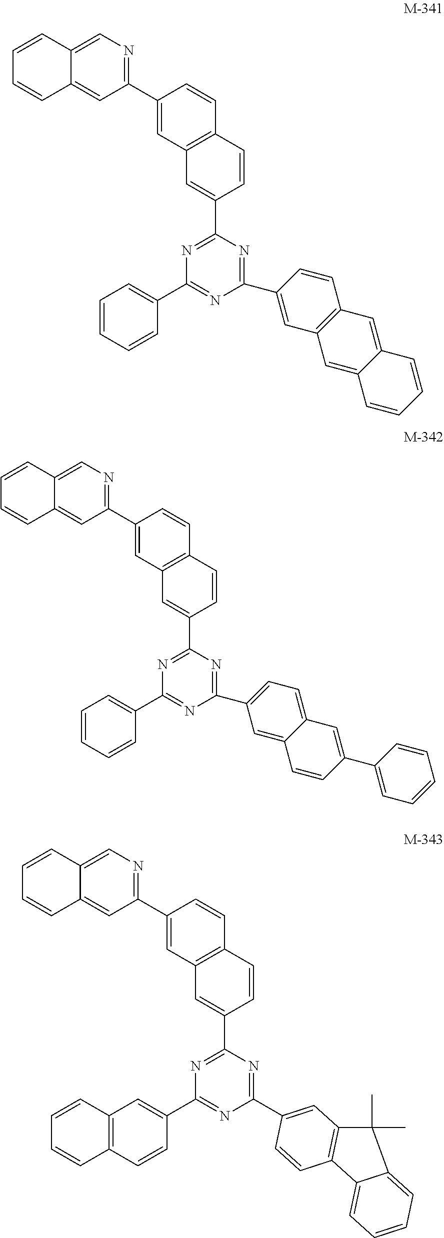 [SMILES: c1ccc(-c2nc(-c3ccc4ccc(-c5cc6ccccc6cn5)cc4c3)nc(-c3ccc4cc5ccccc5cc4c3)n2)cc1 ; c1ccc(-c2ccc3cc(-c4nc(-c5ccccc5)nc(-c5ccc6ccc(-c7cc8ccccc8cn7)cc6c5)n4)ccc3c2)cc1 ; CC1(C)c2ccccc2-c2ccc(-c3nc(-c4ccc5ccccc5c4)nc(-c4ccc5ccc(-c6cc7ccccc7cn6)cc5c4)n3)cc21]

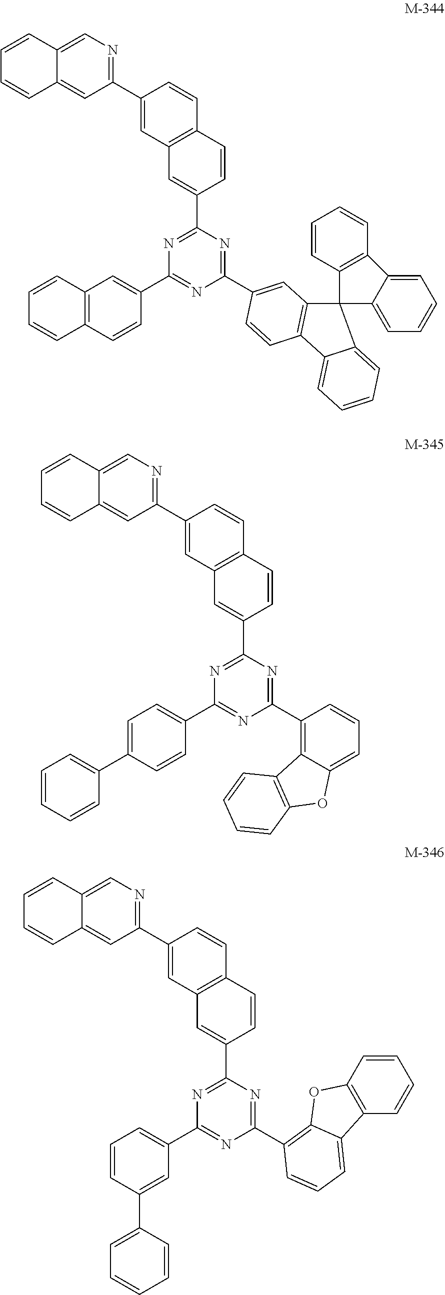 [SMILES: c1ccc2c(c1)-c1ccccc1C21c2ccccc2-c2ccc(-c3nc(-c4ccc5ccccc5c4)nc(-c4ccc5ccc(-c6cc7ccccc7cn6)cc5c4)n3)cc21 ; c1ccc(-c2ccc(-c3nc(-c4ccc5ccc(-c6cc7ccccc7cn6)cc5c4)nc(-c4cccc5oc6ccccc6c45)n3)cc2)cc1 ; c1ccc(-c2cccc(-c3nc(-c4ccc5ccc(-c6cc7ccccc7cn6)cc5c4)nc(-c4cccc5c4oc4ccccc45)n3)c2)cc1]

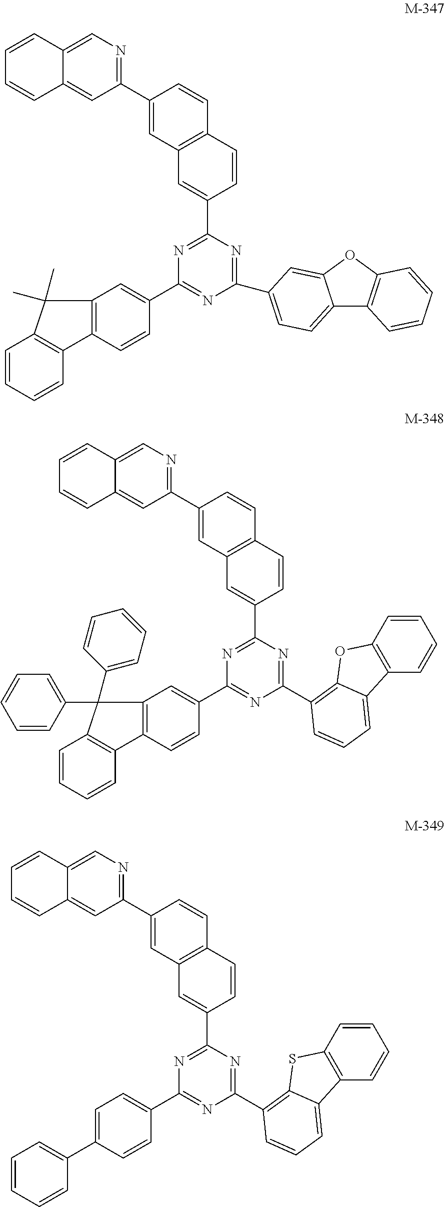 [SMILES: CC1(C)c2ccccc2-c2ccc(-c3nc(-c4ccc5ccc(-c6cc7ccccc7cn6)cc5c4)nc(-c4ccc5c(c4)oc4ccccc45)n3)cc21 ; c1ccc(C2(c3ccccc3)c3ccccc3-c3ccc(-c4nc(-c5ccc6ccc(-c7cc8ccccc8cn7)cc6c5)nc(-c5cccc6c5oc5ccccc56)n4)cc32)cc1 ; c1ccc(-c2ccc(-c3nc(-c4ccc5ccc(-c6cc7ccccc7cn6)cc5c4)nc(-c4cccc5c4sc4ccccc45)n3)cc2)cc1]

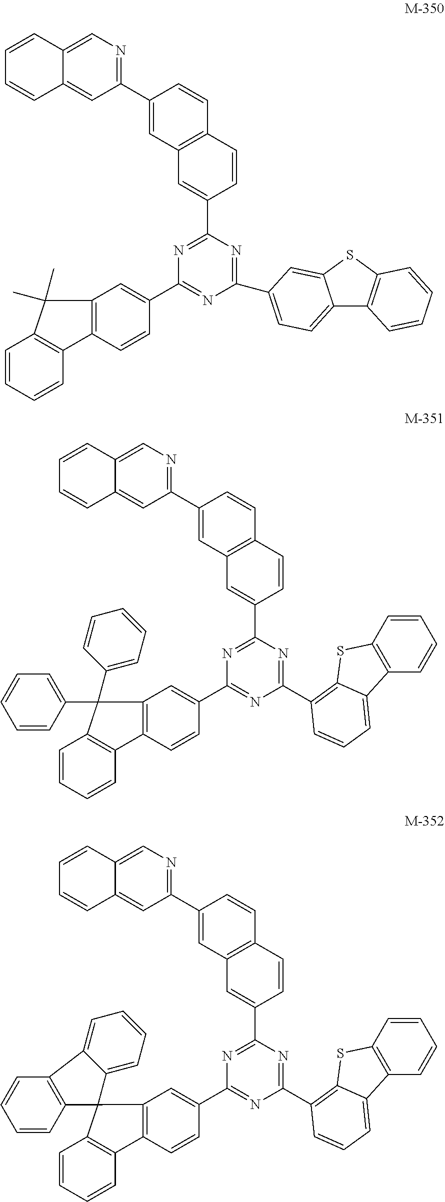 [SMILES: CC1(C)c2ccccc2-c2ccc(-c3nc(-c4ccc5ccc(-c6cc7ccccc7cn6)cc5c4)nc(-c4ccc5c(c4)sc4ccccc45)n3)cc21 ; c1ccc(C2(c3ccccc3)c3ccccc3-c3ccc(-c4nc(-c5ccc6ccc(-c7cc8ccccc8cn7)cc6c5)nc(-c5cccc6c5sc5ccccc56)n4)cc32)cc1 ; c1ccc2c(c1)-c1ccccc1C21c2ccccc2-c2ccc(-c3nc(-c4ccc5ccc(-c6cc7ccccc7cn6)cc5c4)nc(-c4cccc5c4sc4ccccc45)n3)cc21]

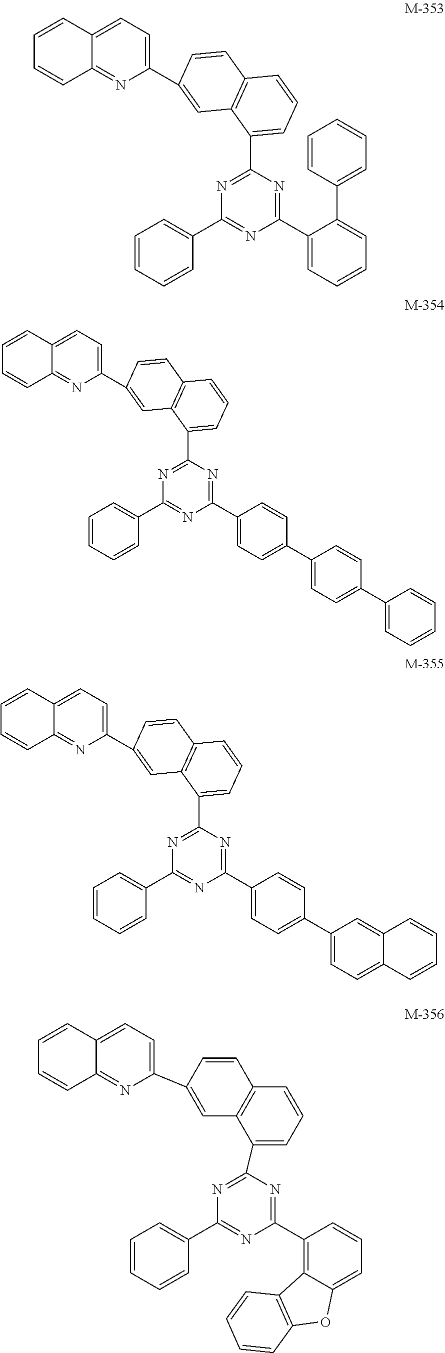 [SMILES: c1ccc(-c2nc(-c3ccccc3-c3ccccc3)nc(-c3cccc4ccc(-c5ccc6ccccc6n5)cc34)n2)cc1 ; c1ccc(-c2ccc(-c3ccc(-c4nc(-c5ccccc5)nc(-c5cccc6ccc(-c7ccc8ccccc8n7)cc56)n4)cc3)cc2)cc1 ; c1ccc(-c2nc(-c3ccc(-c4ccc5ccccc5c4)cc3)nc(-c3cccc4ccc(-c5ccc6ccccc6n5)cc34)n2)cc1 ; c1ccc(-c2nc(-c3cccc4ccc(-c5ccc6ccccc6n5)cc34)nc(-c3cccc4oc5ccccc5c34)n2)cc1]

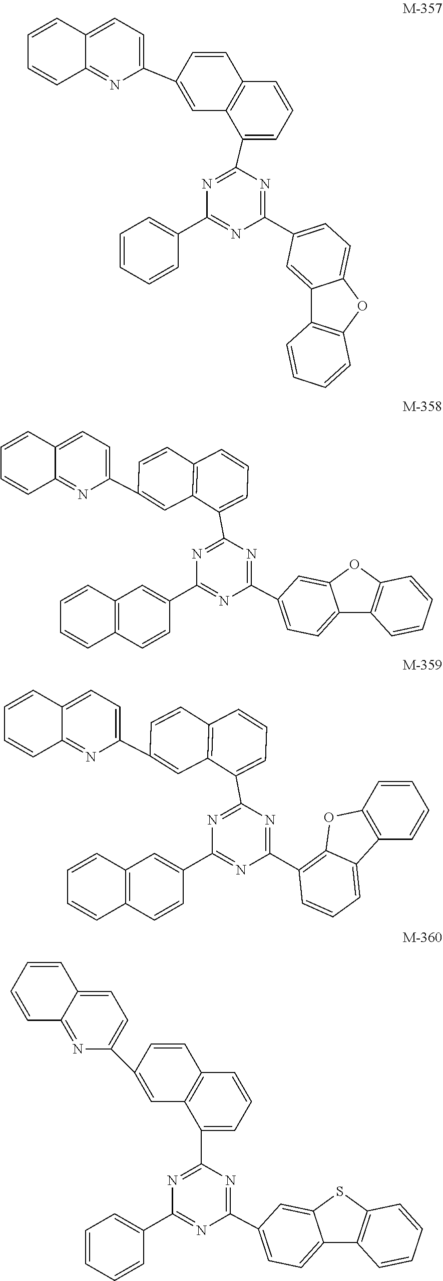

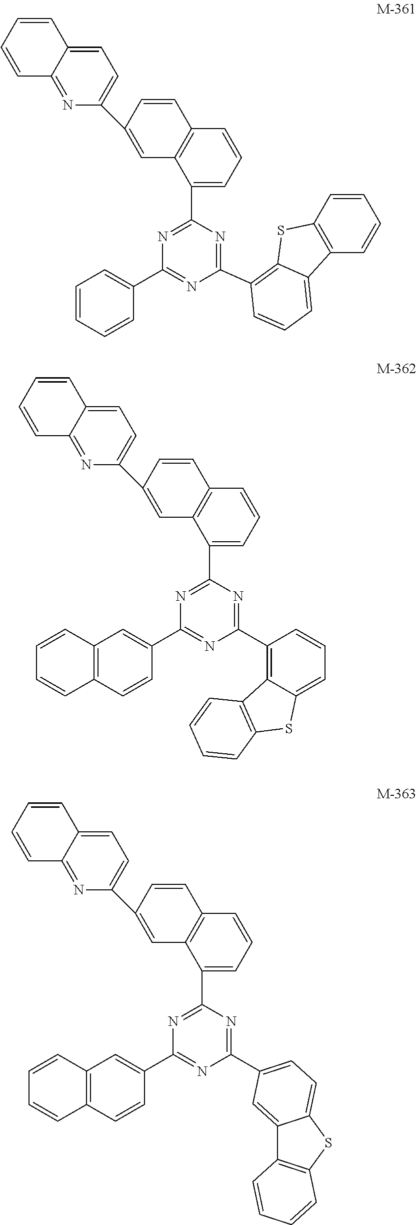 [SMILES: c1ccc(-c2nc(-c3cccc4ccc(-c5ccc6ccccc6n5)cc34)nc(-c3cccc4c3sc3ccccc34)n2)cc1 ; c1ccc2cc(-c3nc(-c4cccc5ccc(-c6ccc7ccccc7n6)cc45)nc(-c4cccc5sc6ccccc6c45)n3)ccc2c1 ; c1ccc2cc(-c3nc(-c4ccc5sc6ccccc6c5c4)nc(-c4cccc5ccc(-c6ccc7ccccc7n6)cc45)n3)ccc2c1]

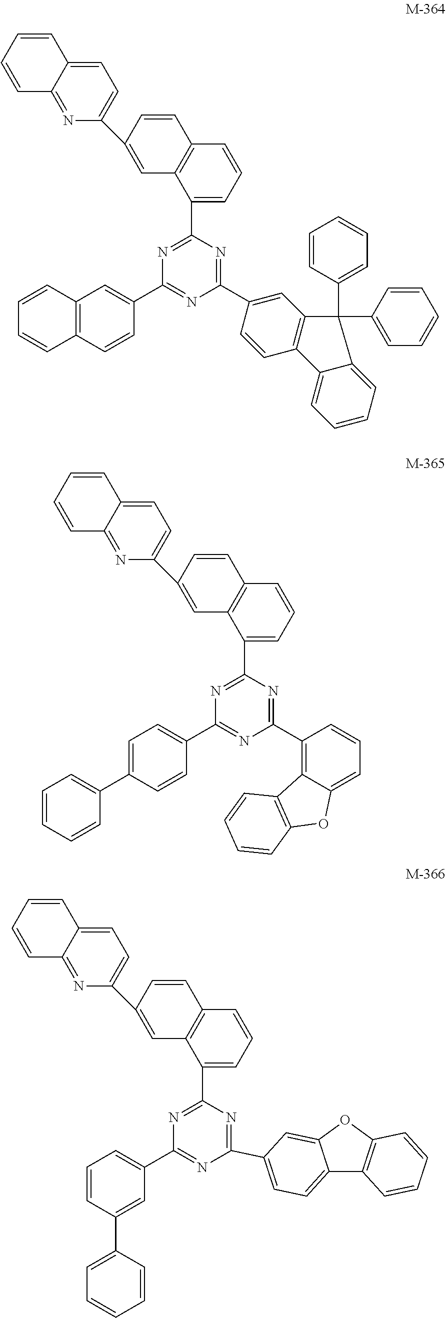 [SMILES: c1ccc(C2(c3ccccc3)c3ccccc3-c3ccc(-c4nc(-c5ccc6ccccc6c5)nc(-c5cccc6ccc(-c7ccc8ccccc8n7)cc56)n4)cc32)cc1 ; c1ccc(-c2ccc(-c3nc(-c4cccc5ccc(-c6ccc7ccccc7n6)cc45)nc(-c4cccc5oc6ccccc6c45)n3)cc2)cc1 ; c1ccc(-c2cccc(-c3nc(-c4ccc5c(c4)oc4ccccc45)nc(-c4cccc5ccc(-c6ccc7ccccc7n6)cc45)n3)c2)cc1]

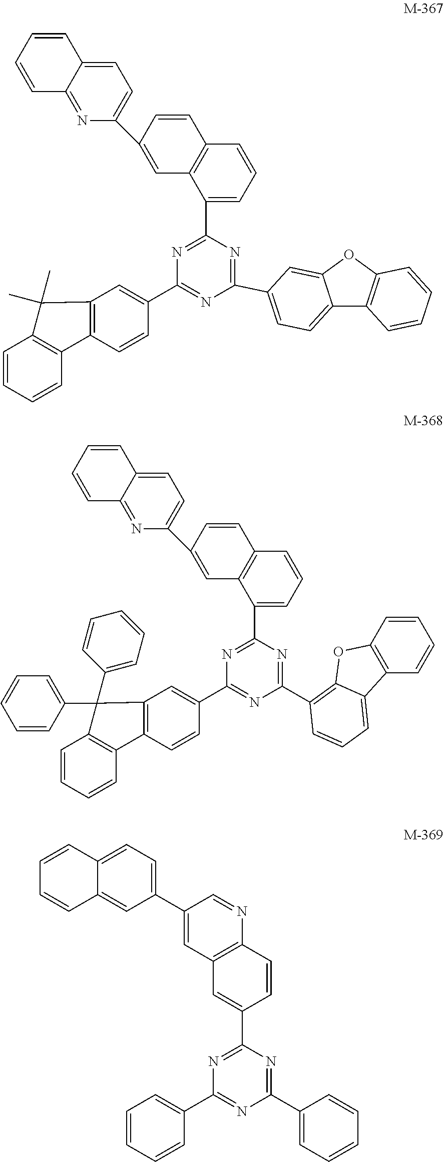 [SMILES: CC1(C)c2ccccc2-c2ccc(-c3nc(-c4ccc5c(c4)oc4ccccc45)nc(-c4cccc5ccc(-c6ccc7ccccc7n6)cc45)n3)cc21 ; c1ccc(C2(c3ccccc3)c3ccccc3-c3ccc(-c4nc(-c5cccc6ccc(-c7ccc8ccccc8n7)cc56)nc(-c5cccc6c5oc5ccccc56)n4)cc32)cc1 ; c1ccc(-c2nc(-c3ccccc3)nc(-c3ccc4ncc(-c5ccc6ccccc6c5)cc4c3)n2)cc1]

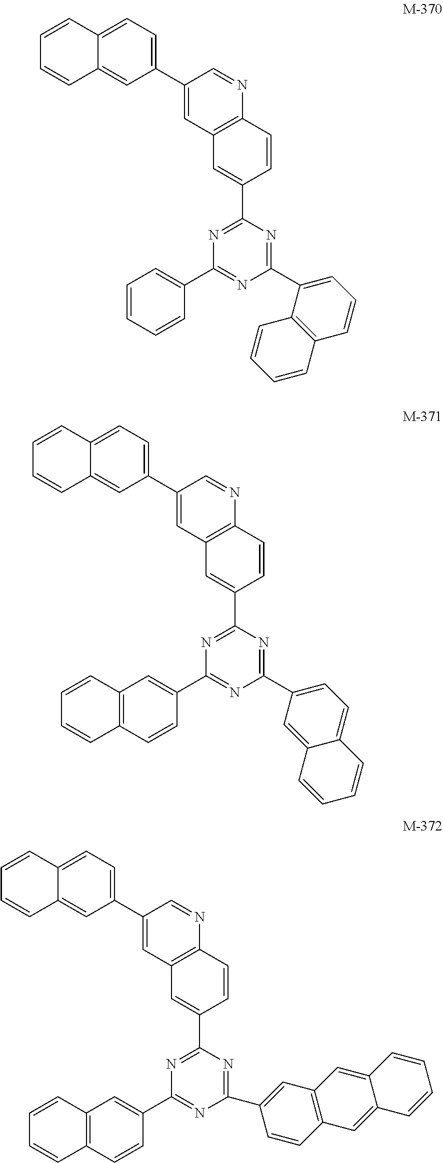 [SMILES: c1ccc(-c2nc(-c3ccc4ncc(-c5ccc6ccccc6c5)cc4c3)nc(-c3cccc4ccccc34)n2)cc1 ; c1ccc2cc(-c3cnc4ccc(-c5nc(-c6ccc7ccccc7c6)nc(-c6ccc7ccccc7c6)n5)cc4c3)ccc2c1 ; c1ccc2cc(-c3cnc4ccc(-c5nc(-c6ccc7ccccc7c6)nc(-c6ccc7cc8ccccc8cc7c6)n5)cc4c3)ccc2c1]

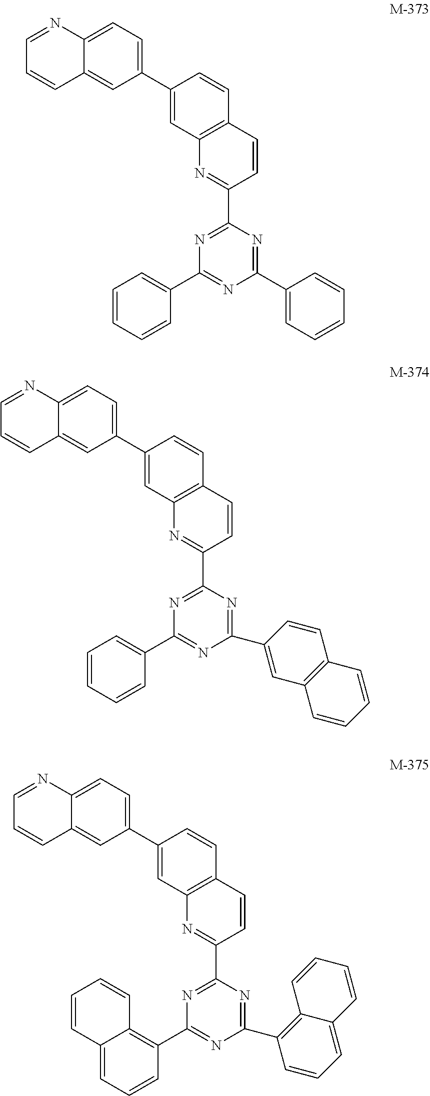 [SMILES: c1ccc(-c2nc(-c3ccccc3)nc(-c3ccc4ccc(-c5ccc6ncccc6c5)cc4n3)n2)cc1 ; c1ccc(-c2nc(-c3ccc4ccccc4c3)nc(-c3ccc4ccc(-c5ccc6ncccc6c5)cc4n3)n2)cc1 ; c1cnc2ccc(-c3ccc4ccc(-c5nc(-c6cccc7ccccc67)nc(-c6cccc7ccccc67)n5)nc4c3)cc2c1]

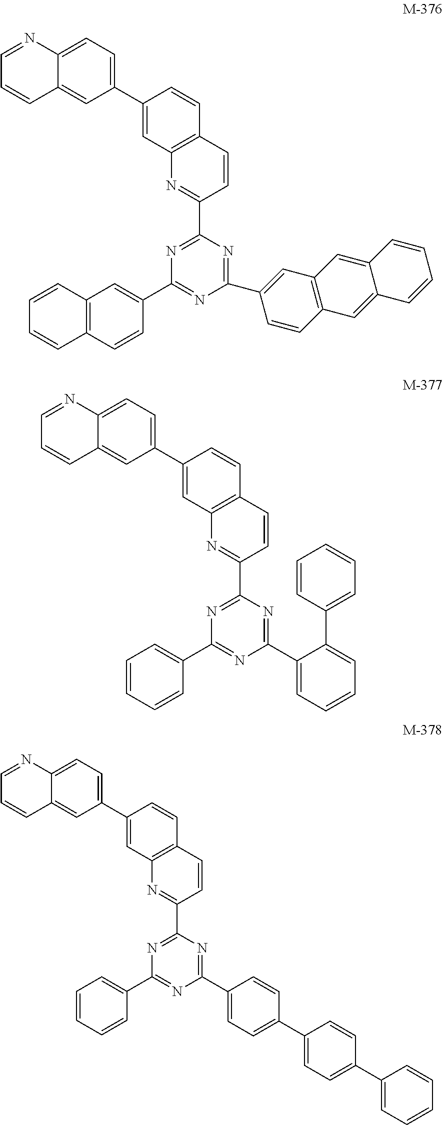 [SMILES: c1ccc2cc(-c3nc(-c4ccc5cc6ccccc6cc5c4)nc(-c4ccc5ccc(-c6ccc7ncccc7c6)cc5n4)n3)ccc2c1 ; c1ccc(-c2nc(-c3ccc4ccc(-c5ccc6ncccc6c5)cc4n3)nc(-c3ccccc3-c3ccccc3)n2)cc1 ; c1ccc(-c2ccc(-c3ccc(-c4nc(-c5ccccc5)nc(-c5ccc6ccc(-c7ccc8ncccc8c7)cc6n5)n4)cc3)cc2)cc1]

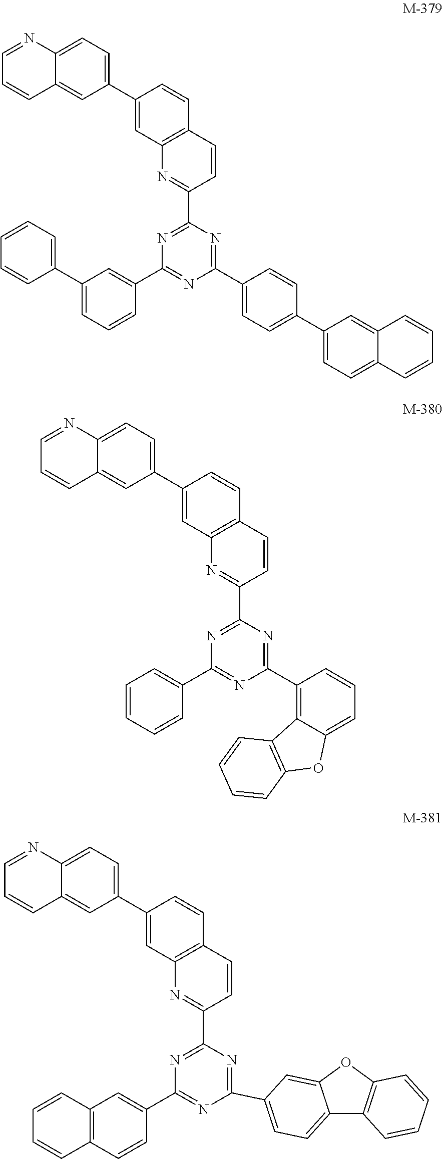 [SMILES: c1ccc(-c2cccc(-c3nc(-c4ccc(-c5ccc6ccccc6c5)cc4)nc(-c4ccc5ccc(-c6ccc7ncccc7c6)cc5n4)n3)c2)cc1 ; c1ccc(-c2nc(-c3ccc4ccc(-c5ccc6ncccc6c5)cc4n3)nc(-c3cccc4oc5ccccc5c34)n2)cc1 ; c1ccc2cc(-c3nc(-c4ccc5c(c4)oc4ccccc45)nc(-c4ccc5ccc(-c6ccc7ncccc7c6)cc5n4)n3)ccc2c1]

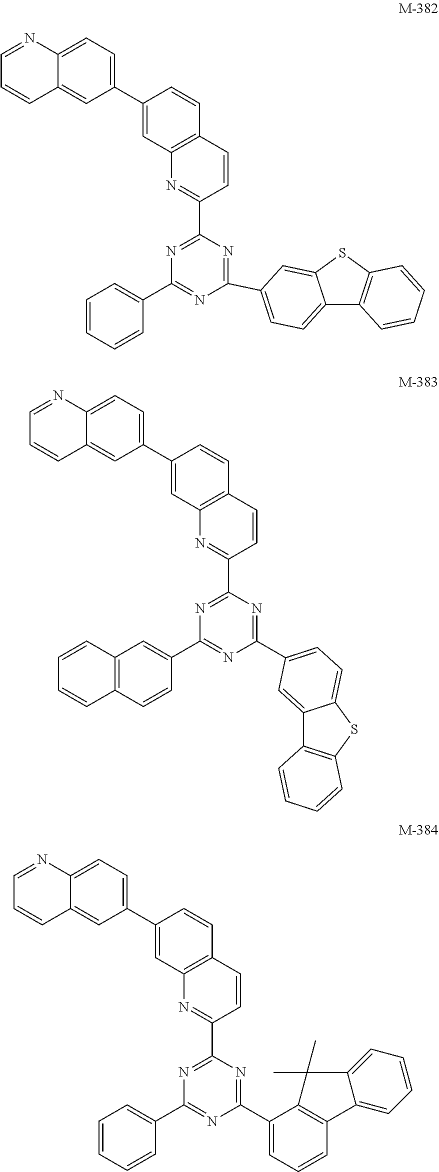 [SMILES: c1ccc(-c2nc(-c3ccc4c(c3)sc3ccccc34)nc(-c3ccc4ccc(-c5ccc6ncccc6c5)cc4n3)n2)cc1 ; c1ccc2cc(-c3nc(-c4ccc5sc6ccccc6c5c4)nc(-c4ccc5ccc(-c6ccc7ncccc7c6)cc5n4)n3)ccc2c1 ; CC1(C)c2ccccc2-c2cccc(-c3nc(-c4ccccc4)nc(-c4ccc5ccc(-c6ccc7ncccc7c6)cc5n4)n3)c21]

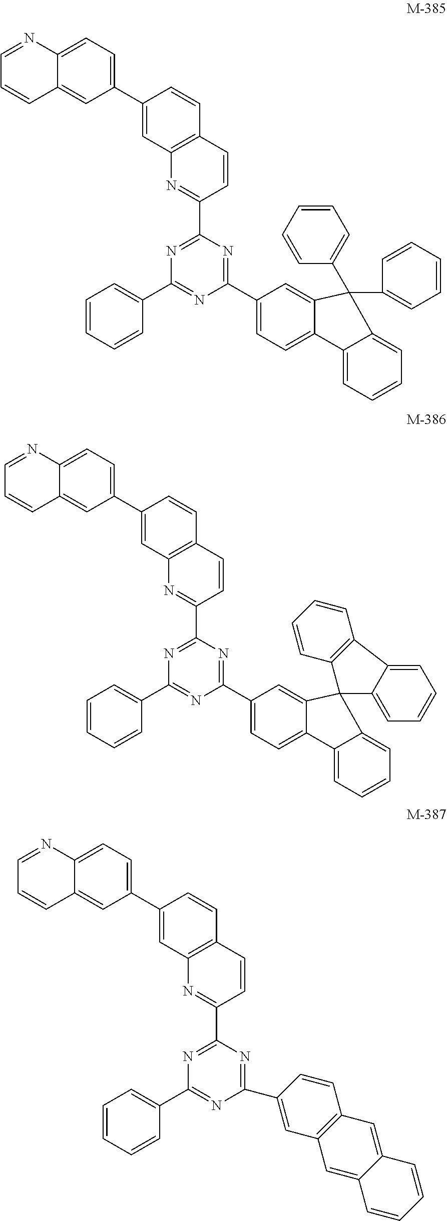 [SMILES: c1ccc(-c2nc(-c3ccc4c(c3)C(c3ccccc3)(c3ccccc3)c3ccccc3-4)nc(-c3ccc4ccc(-c5ccc6ncccc6c5)cc4n3)n2)cc1 ; c1ccc(-c2nc(-c3ccc4c(c3)C3(c5ccccc5-c5ccccc53)c3ccccc3-4)nc(-c3ccc4ccc(-c5ccc6ncccc6c5)cc4n3)n2)cc1 ; c1ccc(-c2nc(-c3ccc4cc5ccccc5cc4c3)nc(-c3ccc4ccc(-c5ccc6ncccc6c5)cc4n3)n2)cc1]

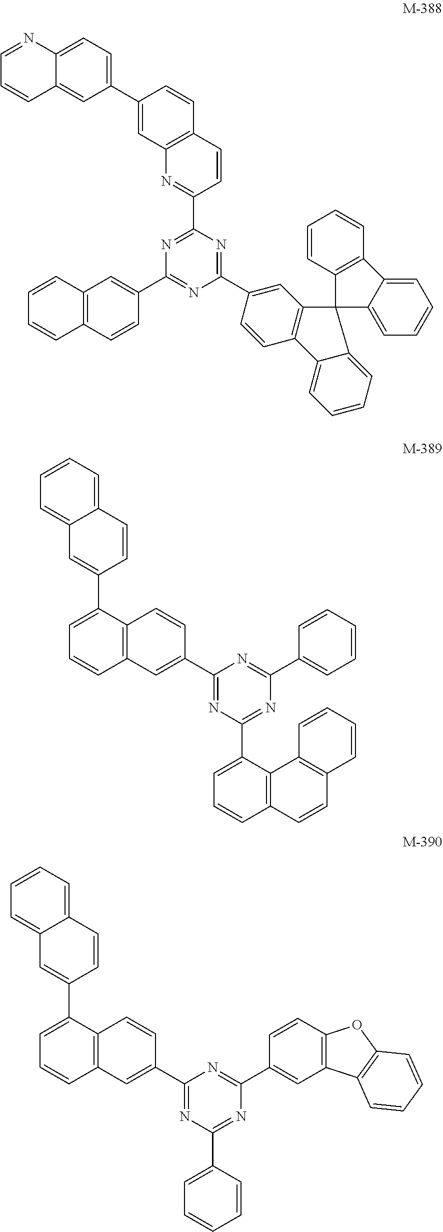 [SMILES: c1ccc2c(c1)-c1ccccc1C21c2ccccc2-c2ccc(-c3nc(-c4ccc5ccccc5c4)nc(-c4ccc5ccc(-c6ccc7ncccc7c6)cc5n4)n3)cc21 ; c1ccc(-c2nc(-c3ccc4c(-c5ccc6ccccc6c5)cccc4c3)nc(-c3cccc4ccc5ccccc5c34)n2)cc1 ; c1ccc(-c2nc(-c3ccc4c(-c5ccc6ccccc6c5)cccc4c3)nc(-c3ccc4oc5ccccc5c4c3)n2)cc1]

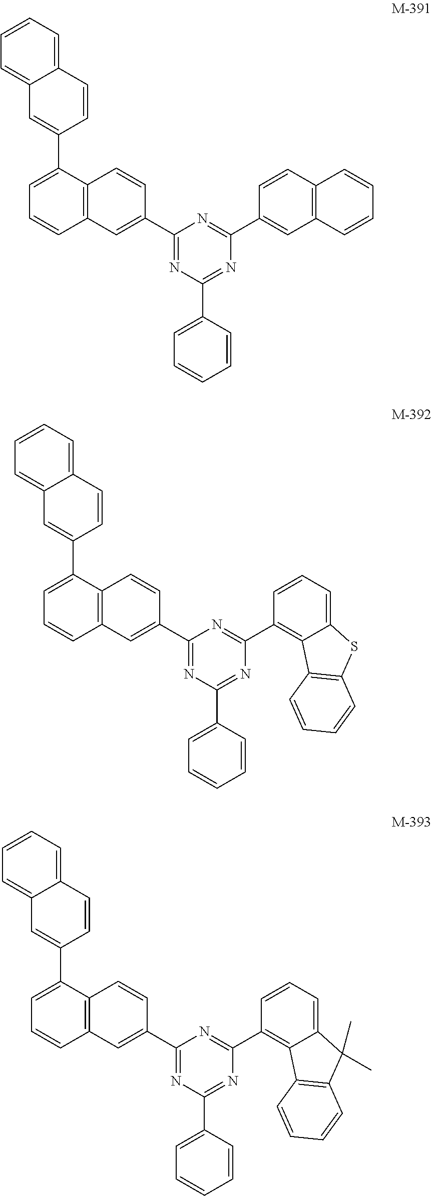 [SMILES: c1ccc(-c2nc(-c3ccc4ccccc4c3)nc(-c3ccc4c(-c5ccc6ccccc6c5)cccc4c3)n2)cc1 ; c1ccc(-c2nc(-c3ccc4c(-c5ccc6ccccc6c5)cccc4c3)nc(-c3cccc4sc5ccccc5c34)n2)cc1 ; CC1(C)c2ccccc2-c2c(-c3nc(-c4ccccc4)nc(-c4ccc5c(-c6ccc7ccccc7c6)cccc5c4)n3)cccc21]

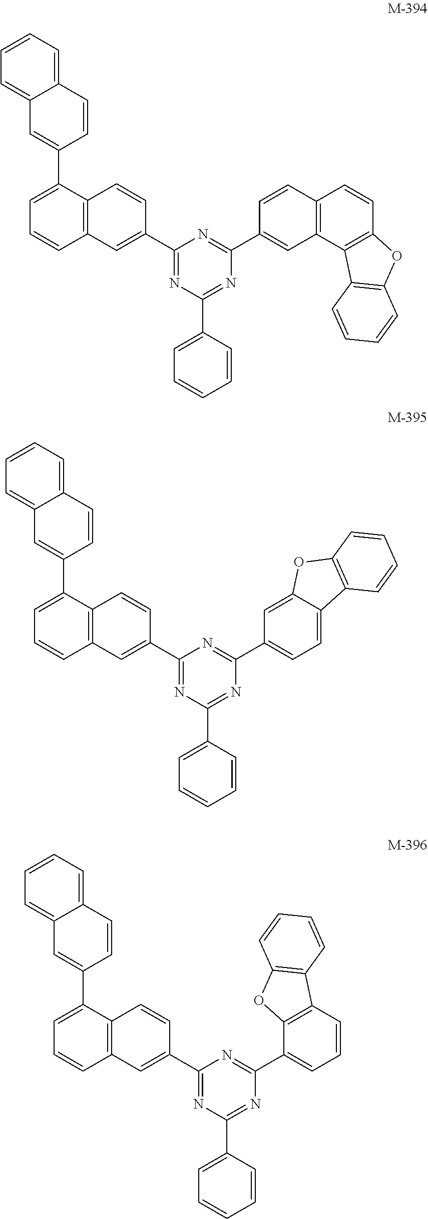 [SMILES: c1ccc(-c2nc(-c3ccc4c(-c5ccc6ccccc6c5)cccc4c3)nc(-c3ccc4ccc5oc6ccccc6c5c4c3)n2)cc1 ; c1ccc(-c2nc(-c3ccc4c(-c5ccc6ccccc6c5)cccc4c3)nc(-c3ccc4c(c3)oc3ccccc34)n2)cc1 ; c1ccc(-c2nc(-c3ccc4c(-c5ccc6ccccc6c5)cccc4c3)nc(-c3cccc4c3oc3ccccc34)n2)cc1]

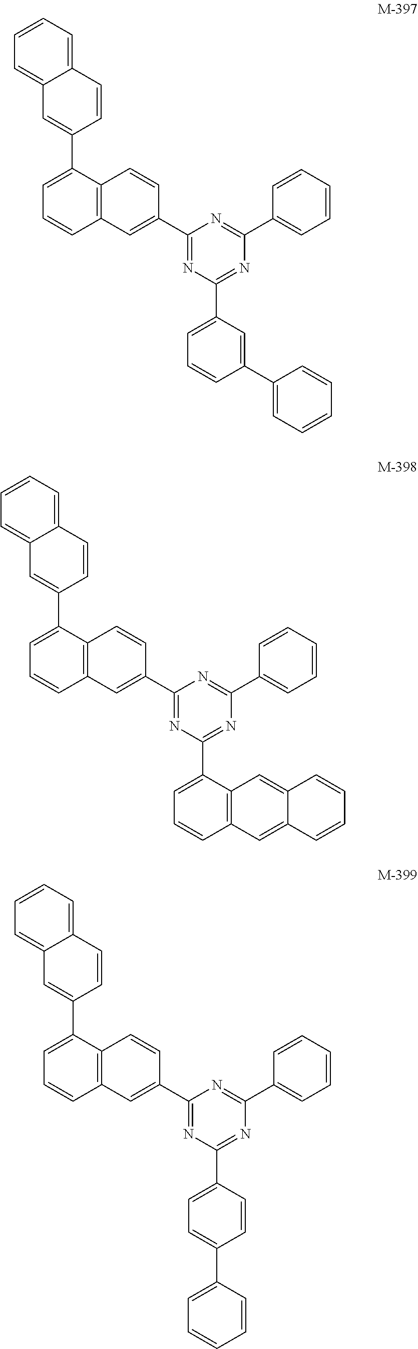 [SMILES: c1ccc(-c2cccc(-c3nc(-c4ccccc4)nc(-c4ccc5c(-c6ccc7ccccc7c6)cccc5c4)n3)c2)cc1 ; c1ccc(-c2nc(-c3ccc4c(-c5ccc6ccccc6c5)cccc4c3)nc(-c3cccc4cc5ccccc5cc34)n2)cc1 ; c1ccc(-c2ccc(-c3nc(-c4ccccc4)nc(-c4ccc5c(-c6ccc7ccccc7c6)cccc5c4)n3)cc2)cc1]

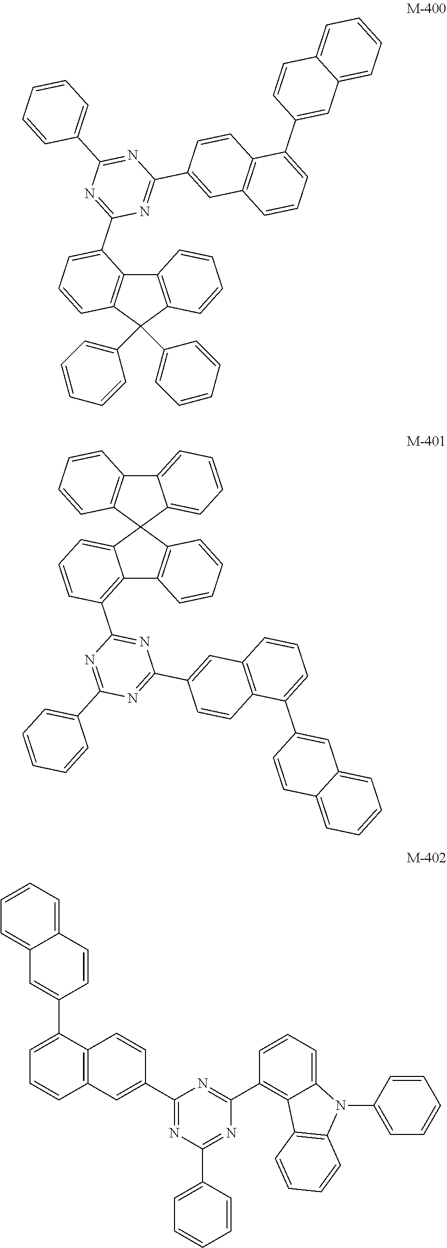

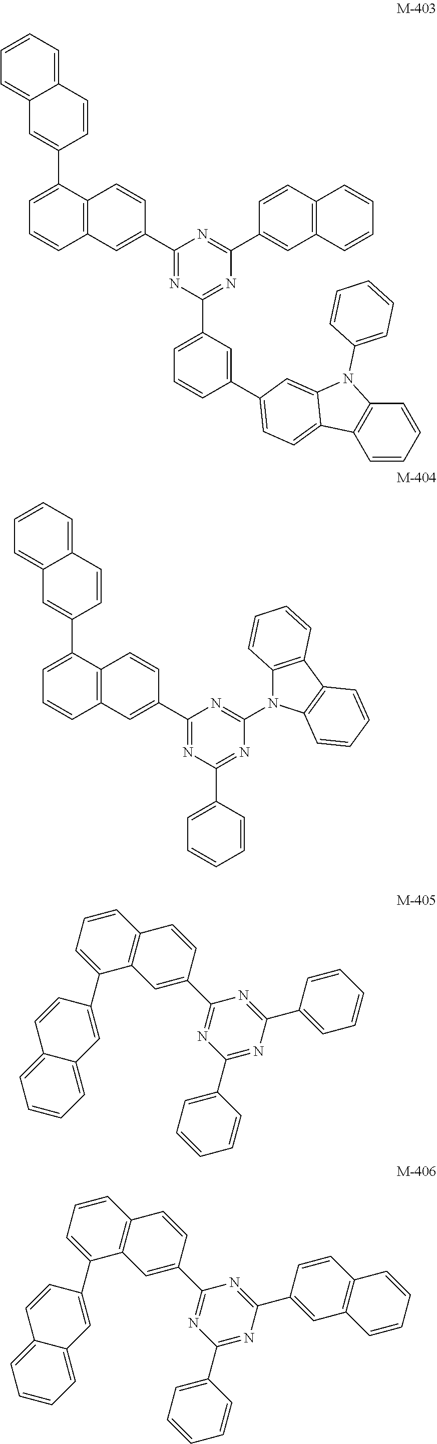 [SMILES: c1ccc(-n2c3ccccc3c3ccc(-c4cccc(-c5nc(-c6ccc7ccccc7c6)nc(-c6ccc7c(-c8ccc9ccccc9c8)cccc7c6)n5)c4)cc32)cc1 ; c1ccc(-c2nc(-c3ccc4c(-c5ccc6ccccc6c5)cccc4c3)nc(-n3c4ccccc4c4ccccc43)n2)cc1 ; c1ccc(-c2nc(-c3ccccc3)nc(-c3ccc4cccc(-c5ccc6ccccc6c5)c4c3)n2)cc1 ; c1ccc(-c2nc(-c3ccc4ccccc4c3)nc(-c3ccc4cccc(-c5ccc6ccccc6c5)c4c3)n2)cc1]

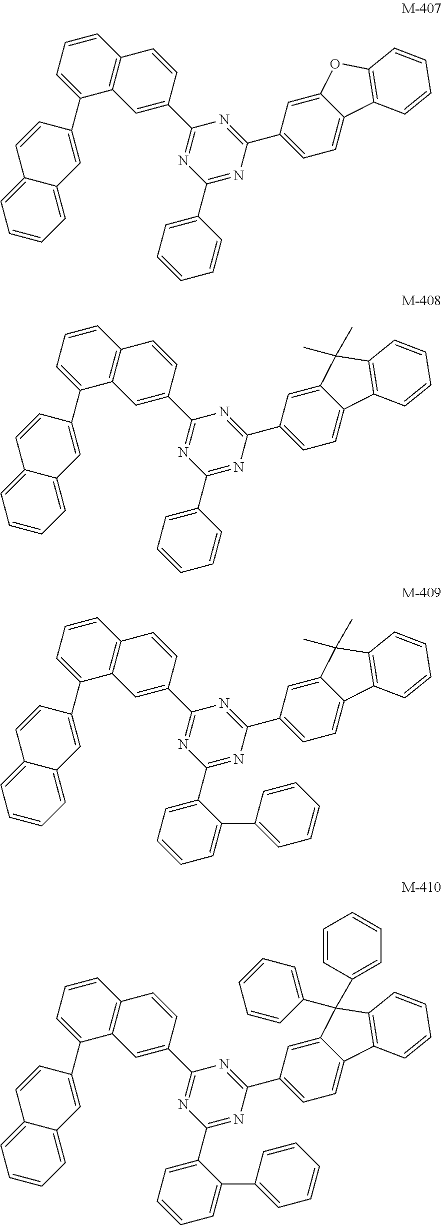 [SMILES: c1ccc(-c2nc(-c3ccc4c(c3)oc3ccccc34)nc(-c3ccc4cccc(-c5ccc6ccccc6c5)c4c3)n2)cc1 ; CC1(C)c2ccccc2-c2ccc(-c3nc(-c4ccccc4)nc(-c4ccc5cccc(-c6ccc7ccccc7c6)c5c4)n3)cc21 ; CC1(C)c2ccccc2-c2ccc(-c3nc(-c4ccc5cccc(-c6ccc7ccccc7c6)c5c4)nc(-c4ccccc4-c4ccccc4)n3)cc21 ; c1ccc(-c2ccccc2-c2nc(-c3ccc4c(c3)C(c3ccccc3)(c3ccccc3)c3ccccc3-4)nc(-c3ccc4cccc(-c5ccc6ccccc6c5)c4c3)n2)cc1]

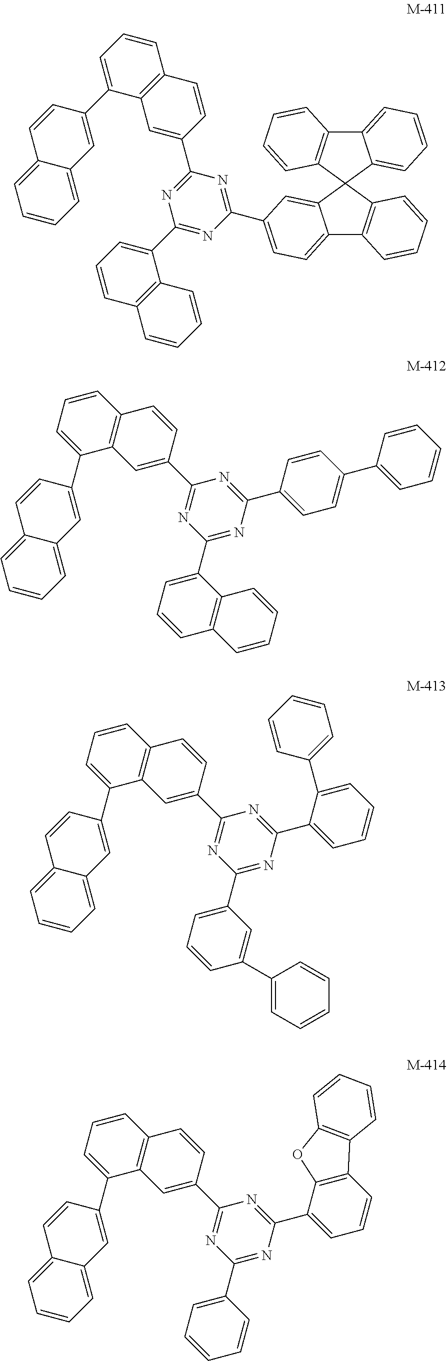 [SMILES: c1ccc2c(c1)-c1ccccc1C21c2ccccc2-c2ccc(-c3nc(-c4ccc5cccc(-c6ccc7ccccc7c6)c5c4)nc(-c4cccc5ccccc45)n3)cc21 ; c1ccc(-c2ccc(-c3nc(-c4ccc5cccc(-c6ccc7ccccc7c6)c5c4)nc(-c4cccc5ccccc45)n3)cc2)cc1 ; c1ccc(-c2cccc(-c3nc(-c4ccc5cccc(-c6ccc7ccccc7c6)c5c4)nc(-c4ccccc4-c4ccccc4)n3)c2)cc1 ; c1ccc(-c2nc(-c3ccc4cccc(-c5ccc6ccccc6c5)c4c3)nc(-c3cccc4c3oc3ccccc34)n2)cc1]

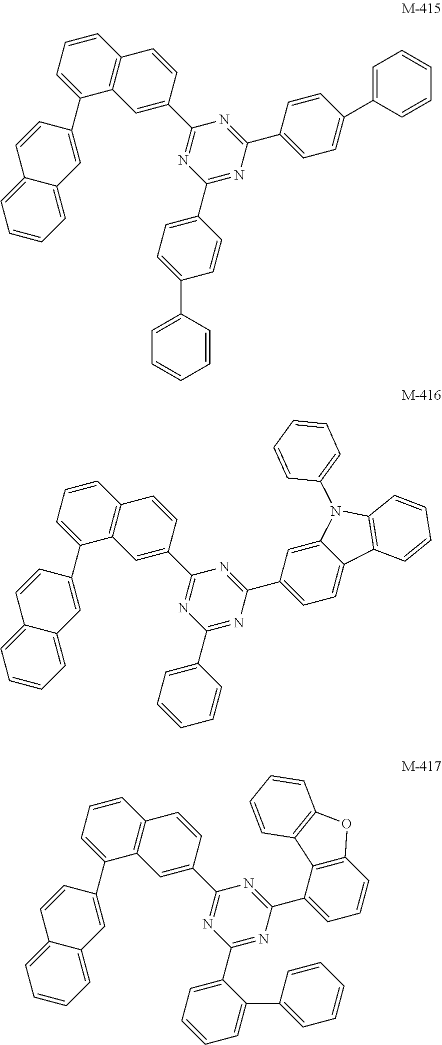 [SMILES: c1ccc(-c2ccc(-c3nc(-c4ccc(-c5ccccc5)cc4)nc(-c4ccc5cccc(-c6ccc7ccccc7c6)c5c4)n3)cc2)cc1 ; c1ccc(-c2nc(-c3ccc4cccc(-c5ccc6ccccc6c5)c4c3)nc(-c3ccc4c5ccccc5n(-c5ccccc5)c4c3)n2)cc1 ; c1ccc(-c2ccccc2-c2nc(-c3ccc4cccc(-c5ccc6ccccc6c5)c4c3)nc(-c3cccc4oc5ccccc5c34)n2)cc1]

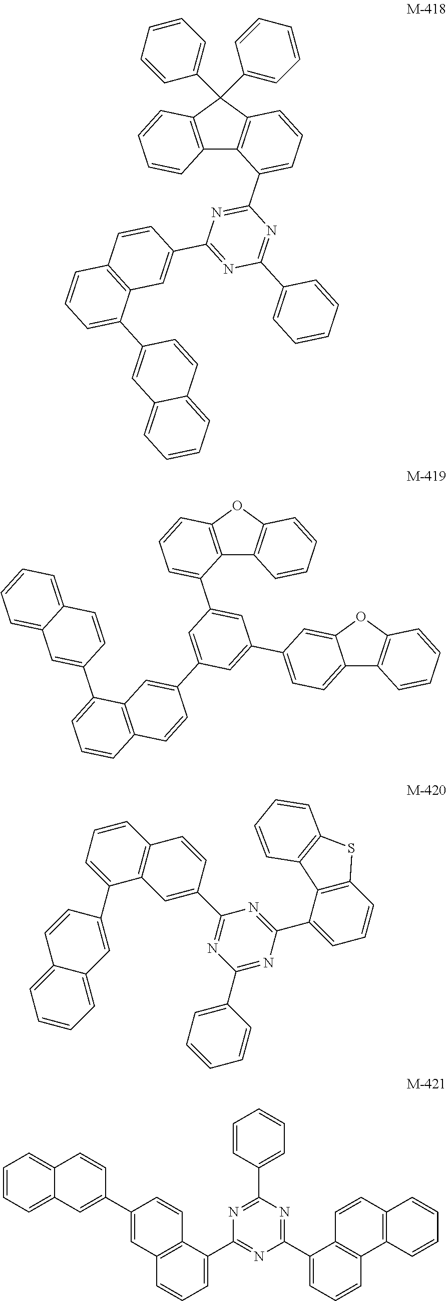 [SMILES: c1ccc(-c2nc(-c3ccc4cccc(-c5ccc6ccccc6c5)c4c3)nc(-c3cccc4c3-c3ccccc3C4(c3ccccc3)c3ccccc3)n2)cc1 ; c1ccc2cc(-c3cccc4ccc(-c5cc(-c6ccc7c(c6)oc6ccccc67)cc(-c6cccc7oc8ccccc8c67)c5)cc34)ccc2c1 ; c1ccc(-c2nc(-c3ccc4cccc(-c5ccc6ccccc6c5)c4c3)nc(-c3cccc4sc5ccccc5c34)n2)cc1 ; c1ccc(-c2nc(-c3cccc4cc(-c5ccc6ccccc6c5)ccc34)nc(-c3cccc4c3ccc3ccccc34)n2)cc1]

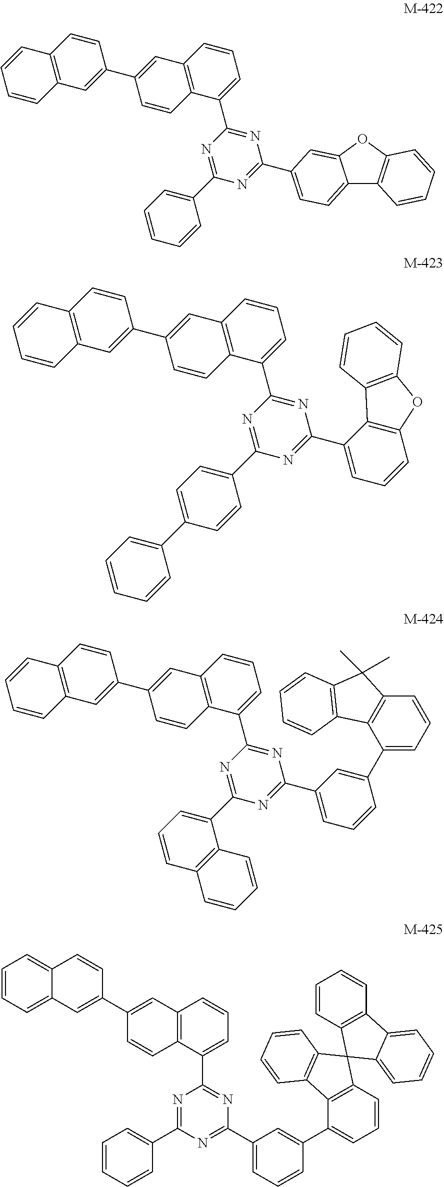 [SMILES: c1ccc(-c2nc(-c3ccc4c(c3)oc3ccccc34)nc(-c3cccc4cc(-c5ccc6ccccc6c5)ccc34)n2)cc1 ; c1ccc(-c2ccc(-c3nc(-c4cccc5cc(-c6ccc7ccccc7c6)ccc45)nc(-c4cccc5oc6ccccc6c45)n3)cc2)cc1 ; CC1(C)c2ccccc2-c2c(-c3cccc(-c4nc(-c5cccc6ccccc56)nc(-c5cccc6cc(-c7ccc8ccccc8c7)ccc56)n4)c3)cccc21 ; c1ccc(-c2nc(-c3cccc(-c4cccc5c4-c4ccccc4C54c5ccccc5-c5ccccc54)c3)nc(-c3cccc4cc(-c5ccc6ccccc6c5)ccc34)n2)cc1]

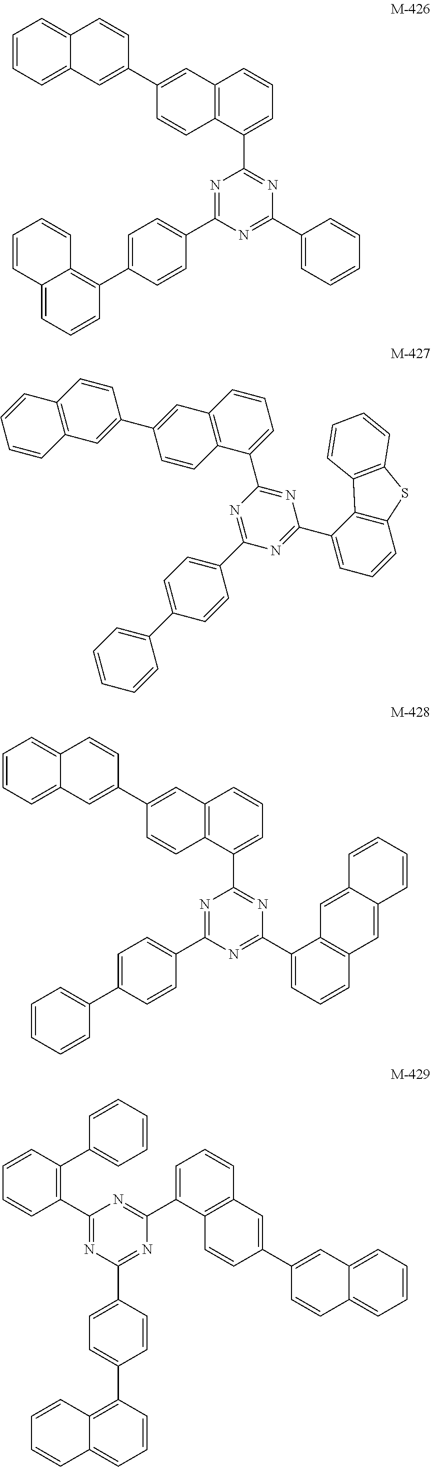

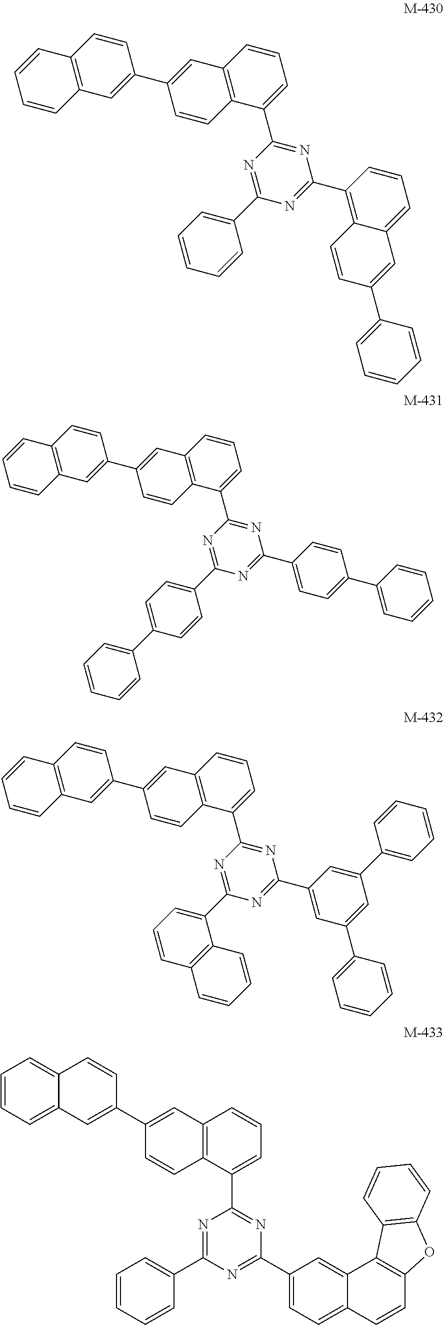 [SMILES: c1ccc(-c2ccc3c(-c4nc(-c5ccccc5)nc(-c5cccc6cc(-c7ccc8ccccc8c7)ccc56)n4)cccc3c2)cc1 ; c1ccc(-c2ccc(-c3nc(-c4ccc(-c5ccccc5)cc4)nc(-c4cccc5cc(-c6ccc7ccccc7c6)ccc45)n3)cc2)cc1 ; c1ccc(-c2cc(-c3ccccc3)cc(-c3nc(-c4cccc5ccccc45)nc(-c4cccc5cc(-c6ccc7ccccc7c6)ccc45)n3)c2)cc1 ; c1ccc(-c2nc(-c3ccc4ccc5oc6ccccc6c5c4c3)nc(-c3cccc4cc(-c5ccc6ccccc6c5)ccc34)n2)cc1]

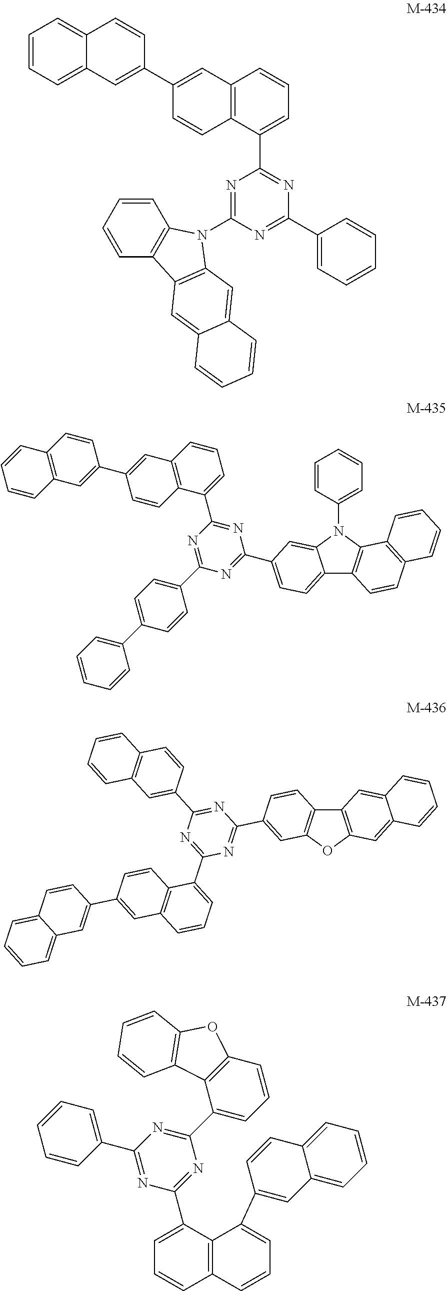 [SMILES: c1ccc(-c2nc(-c3cccc4cc(-c5ccc6ccccc6c5)ccc34)nc(-n3c4ccccc4c4cc5ccccc5cc43)n2)cc1 ; c1ccc(-c2ccc(-c3nc(-c4ccc5c6ccc7ccccc7c6n(-c6ccccc6)c5c4)nc(-c4cccc5cc(-c6ccc7ccccc7c6)ccc45)n3)cc2)cc1 ; c1ccc2cc(-c3ccc4c(-c5nc(-c6ccc7ccccc7c6)nc(-c6ccc7c(c6)oc6cc8ccccc8cc67)n5)cccc4c3)ccc2c1 ; c1ccc(-c2nc(-c3cccc4cccc(-c5ccc6ccccc6c5)c34)nc(-c3cccc4oc5ccccc5c34)n2)cc1]

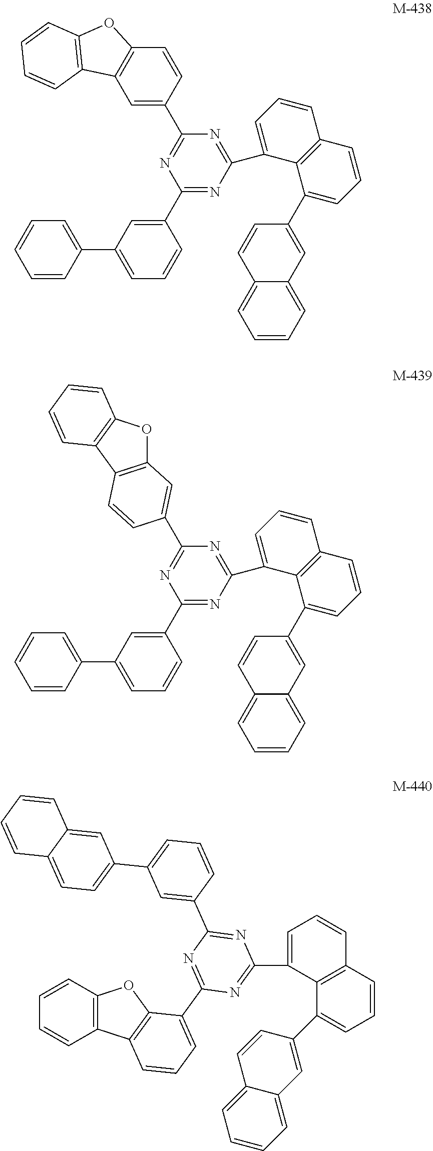 [SMILES: c1ccc(-c2cccc(-c3nc(-c4ccc5oc6ccccc6c5c4)nc(-c4cccc5cccc(-c6ccc7ccccc7c6)c45)n3)c2)cc1 ; c1ccc(-c2cccc(-c3nc(-c4ccc5c(c4)oc4ccccc45)nc(-c4cccc5cccc(-c6ccc7ccccc7c6)c45)n3)c2)cc1 ; c1cc(-c2ccc3ccccc3c2)cc(-c2nc(-c3cccc4c3oc3ccccc34)nc(-c3cccc4cccc(-c5ccc6ccccc6c5)c34)n2)c1]

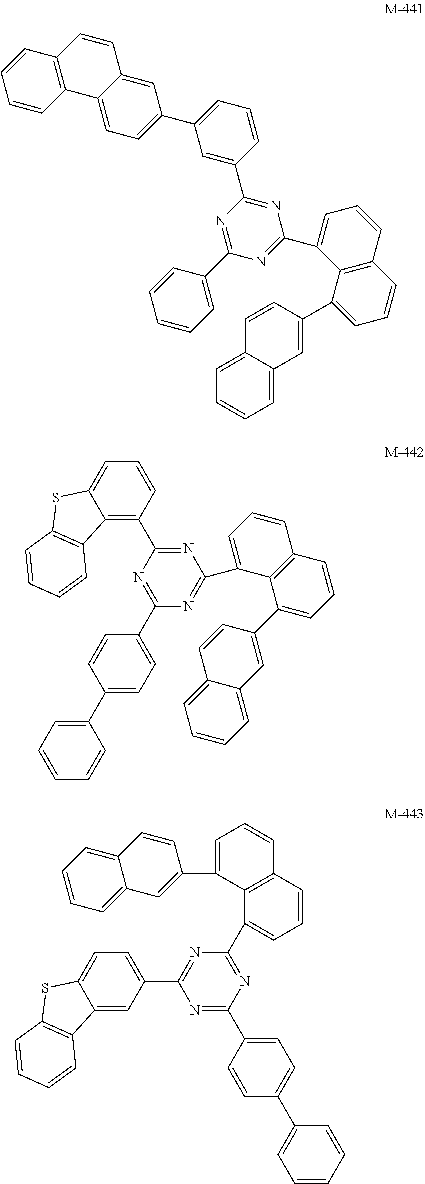 [SMILES: c1ccc(-c2nc(-c3cccc(-c4ccc5c(ccc6ccccc65)c4)c3)nc(-c3cccc4cccc(-c5ccc6ccccc6c5)c34)n2)cc1 ; c1ccc(-c2ccc(-c3nc(-c4cccc5cccc(-c6ccc7ccccc7c6)c45)nc(-c4cccc5sc6ccccc6c45)n3)cc2)cc1 ; c1ccc(-c2ccc(-c3nc(-c4ccc5sc6ccccc6c5c4)nc(-c4cccc5cccc(-c6ccc7ccccc7c6)c45)n3)cc2)cc1]

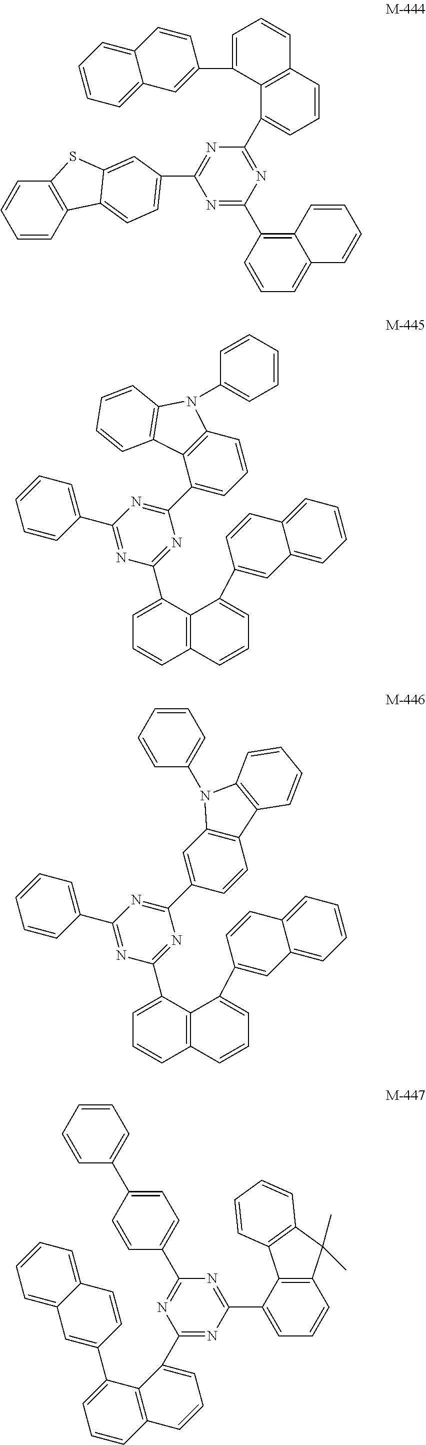

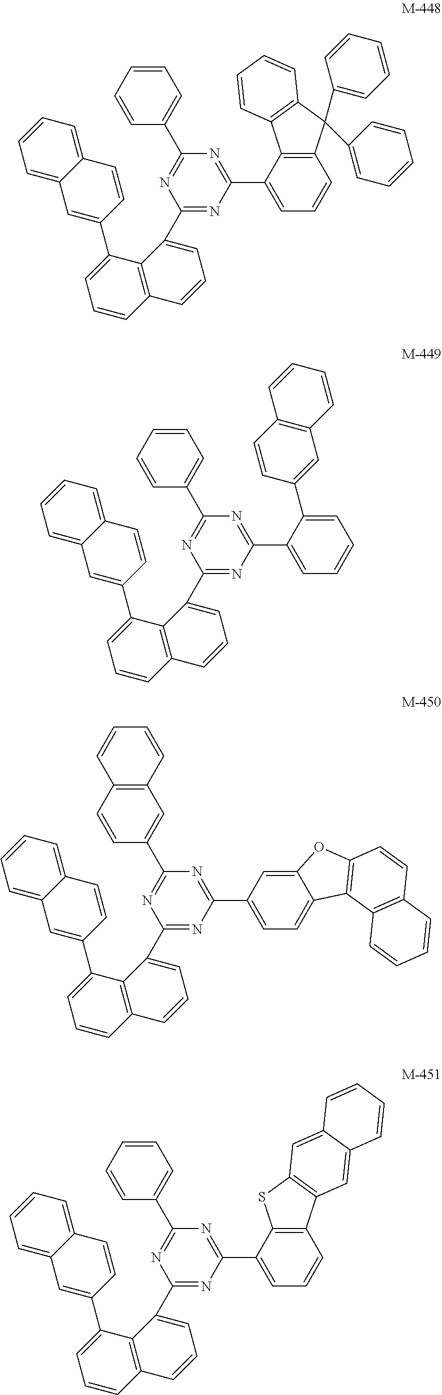

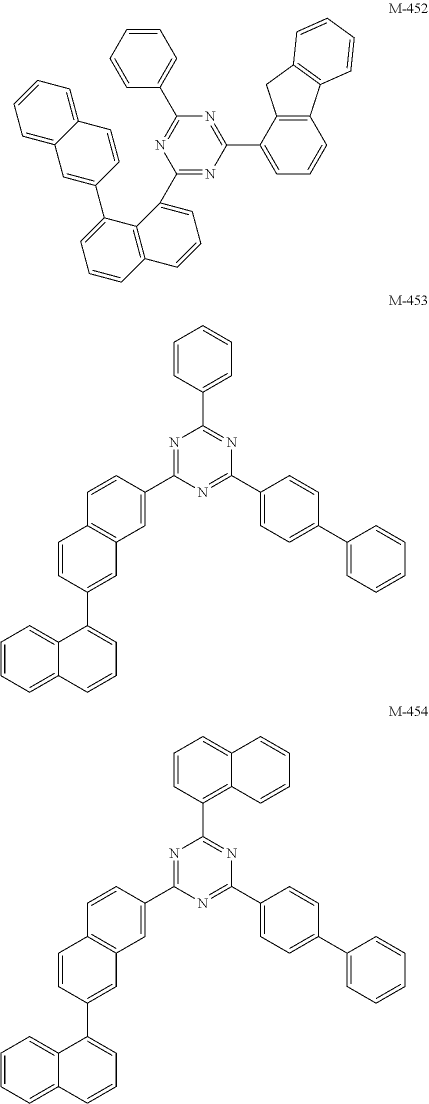 [SMILES: c1ccc(-c2nc(-c3cccc4c3Cc3ccccc3-4)nc(-c3cccc4cccc(-c5ccc6ccccc6c5)c34)n2)cc1 ; c1ccc(-c2ccc(-c3nc(-c4ccccc4)nc(-c4ccc5ccc(-c6cccc7ccccc67)cc5c4)n3)cc2)cc1 ; c1ccc(-c2ccc(-c3nc(-c4ccc5ccc(-c6cccc7ccccc67)cc5c4)nc(-c4cccc5ccccc45)n3)cc2)cc1]

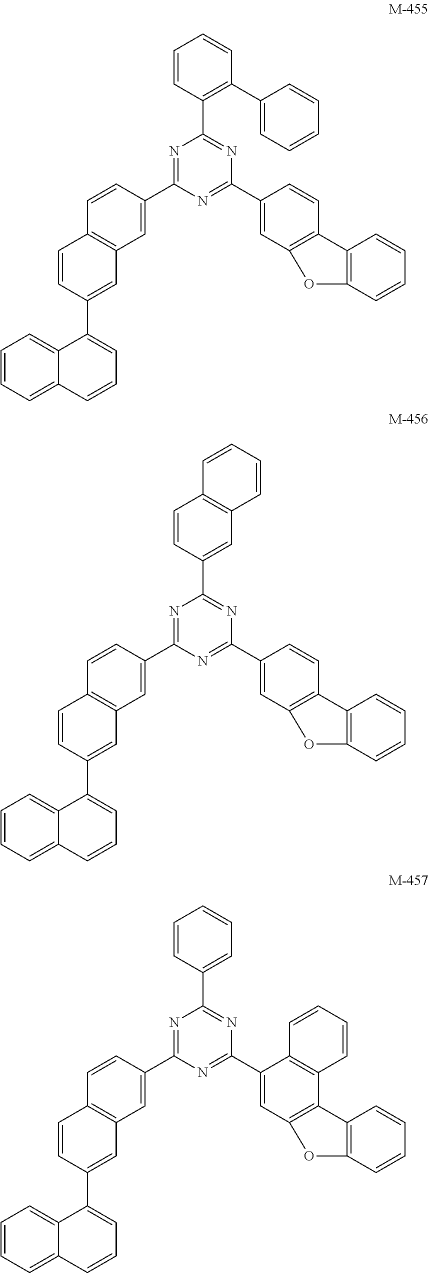 [SMILES: c1ccc(-c2ccccc2-c2nc(-c3ccc4ccc(-c5cccc6ccccc56)cc4c3)nc(-c3ccc4c(c3)oc3ccccc34)n2)cc1 ; c1ccc2cc(-c3nc(-c4ccc5ccc(-c6cccc7ccccc67)cc5c4)nc(-c4ccc5c(c4)oc4ccccc45)n3)ccc2c1 ; c1ccc(-c2nc(-c3ccc4ccc(-c5cccc6ccccc56)cc4c3)nc(-c3cc4oc5ccccc5c4c4ccccc34)n2)cc1]

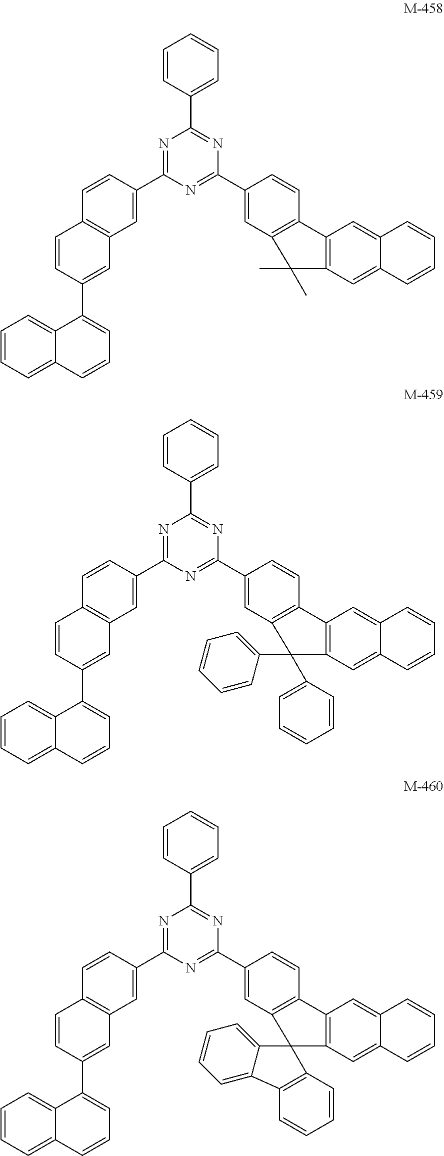 [SMILES: CC1(C)c2cc(-c3nc(-c4ccccc4)nc(-c4ccc5ccc(-c6cccc7ccccc67)cc5c4)n3)ccc2-c2cc3ccccc3cc21 ; c1ccc(-c2nc(-c3ccc4c(c3)C(c3ccccc3)(c3ccccc3)c3cc5ccccc5cc3-4)nc(-c3ccc4ccc(-c5cccc6ccccc56)cc4c3)n2)cc1 ; c1ccc(-c2nc(-c3ccc4c(c3)C3(c5ccccc5-c5ccccc53)c3cc5ccccc5cc3-4)nc(-c3ccc4ccc(-c5cccc6ccccc56)cc4c3)n2)cc1]

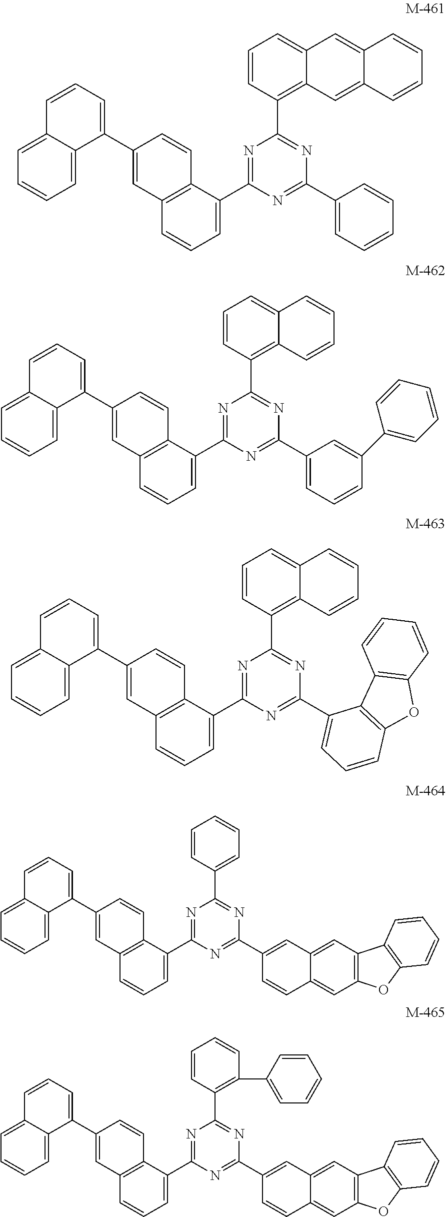 [SMILES: c1ccc(-c2nc(-c3cccc4cc(-c5cccc6ccccc56)ccc34)nc(-c3cccc4cc5ccccc5cc34)n2)cc1 ; c1ccc(-c2cccc(-c3nc(-c4cccc5ccccc45)nc(-c4cccc5cc(-c6cccc7ccccc67)ccc45)n3)c2)cc1 ; c1ccc2c(-c3ccc4c(-c5nc(-c6cccc7ccccc67)nc(-c6cccc7oc8ccccc8c67)n5)cccc4c3)cccc2c1 ; c1ccc(-c2nc(-c3ccc4cc5oc6ccccc6c5cc4c3)nc(-c3cccc4cc(-c5cccc6ccccc56)ccc34)n2)cc1 ; c1ccc(-c2ccccc2-c2nc(-c3ccc4cc5oc6ccccc6c5cc4c3)nc(-c3cccc4cc(-c5cccc6ccccc56)ccc34)n2)cc1]

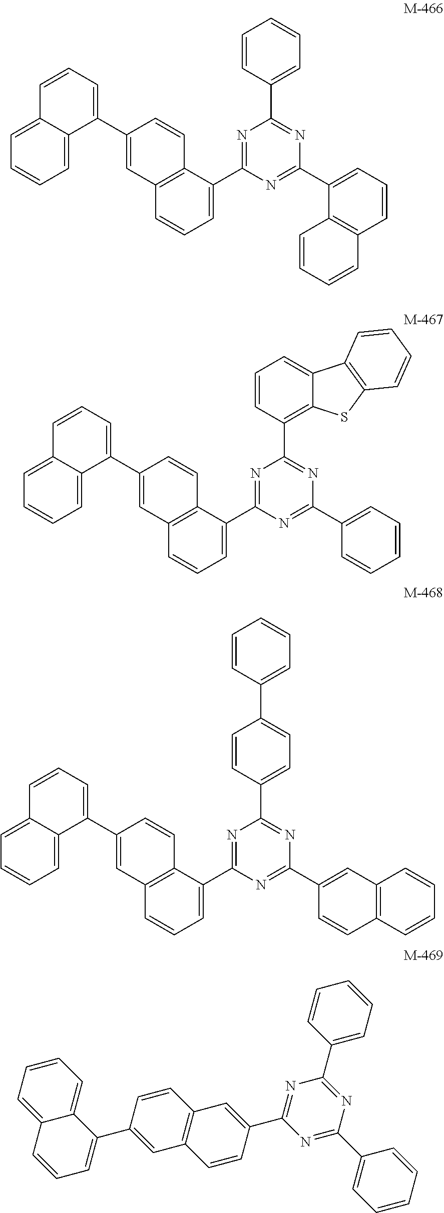

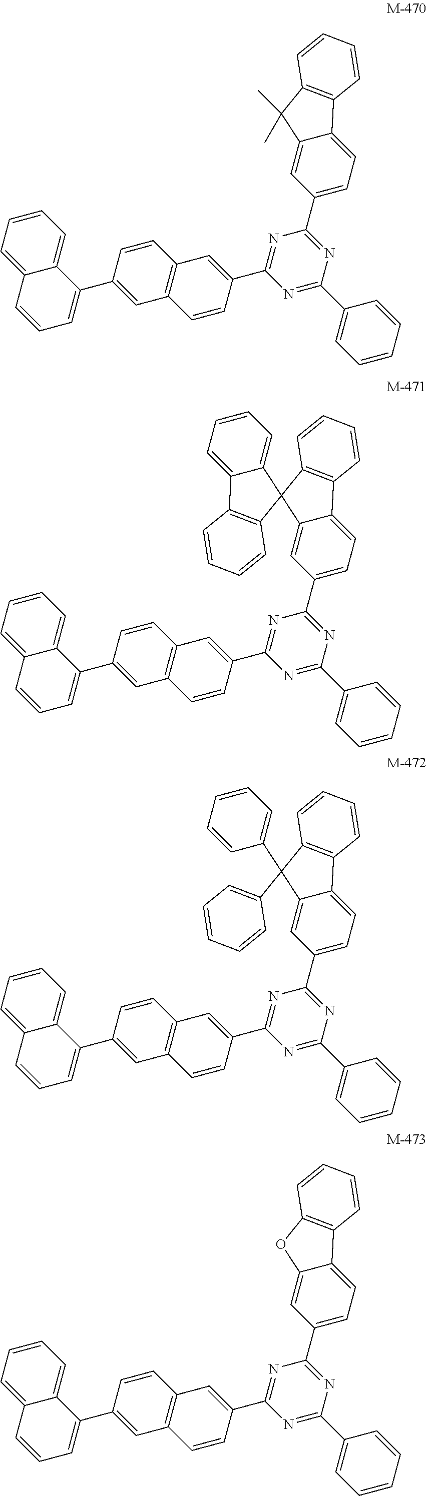 [SMILES: CC1(C)c2ccccc2-c2ccc(-c3nc(-c4ccccc4)nc(-c4ccc5cc(-c6cccc7ccccc67)ccc5c4)n3)cc21 ; c1ccc(-c2nc(-c3ccc4c(c3)C3(c5ccccc5-c5ccccc53)c3ccccc3-4)nc(-c3ccc4cc(-c5cccc6ccccc56)ccc4c3)n2)cc1 ; c1ccc(-c2nc(-c3ccc4c(c3)C(c3ccccc3)(c3ccccc3)c3ccccc3-4)nc(-c3ccc4cc(-c5cccc6ccccc56)ccc4c3)n2)cc1 ; c1ccc(-c2nc(-c3ccc4cc(-c5cccc6ccccc56)ccc4c3)nc(-c3ccc4c(c3)oc3ccccc34)n2)cc1]

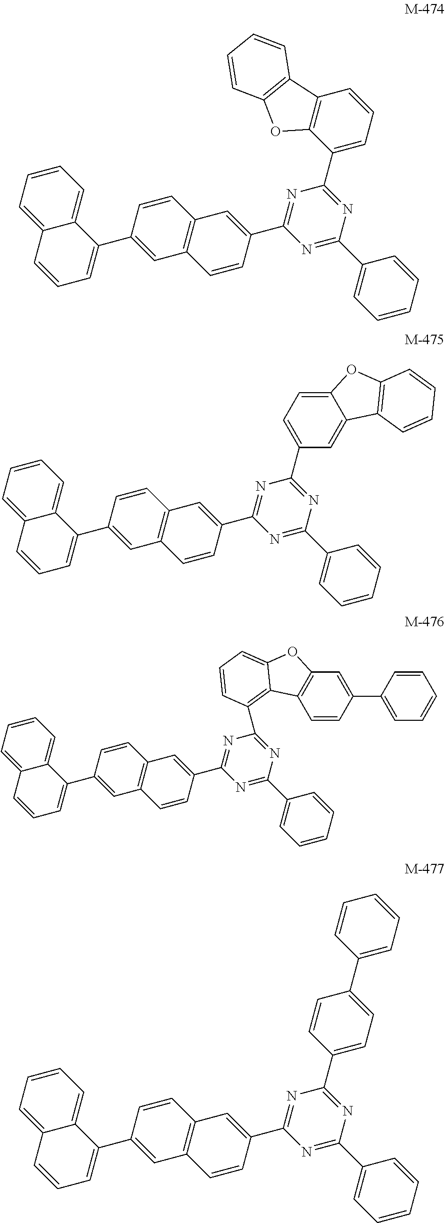 [SMILES: c1ccc(-c2nc(-c3ccc4cc(-c5cccc6ccccc56)ccc4c3)nc(-c3cccc4c3oc3ccccc34)n2)cc1 ; c1ccc(-c2nc(-c3ccc4cc(-c5cccc6ccccc56)ccc4c3)nc(-c3ccc4oc5ccccc5c4c3)n2)cc1 ; c1ccc(-c2ccc3c(c2)oc2cccc(-c4nc(-c5ccccc5)nc(-c5ccc6cc(-c7cccc8ccccc78)ccc6c5)n4)c23)cc1 ; c1ccc(-c2ccc(-c3nc(-c4ccccc4)nc(-c4ccc5cc(-c6cccc7ccccc67)ccc5c4)n3)cc2)cc1]

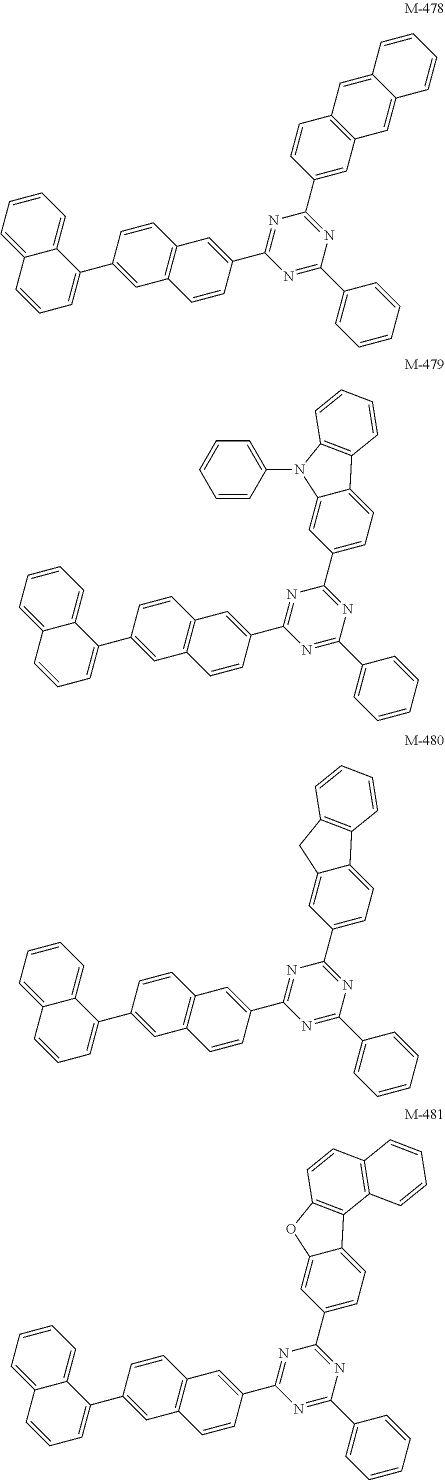

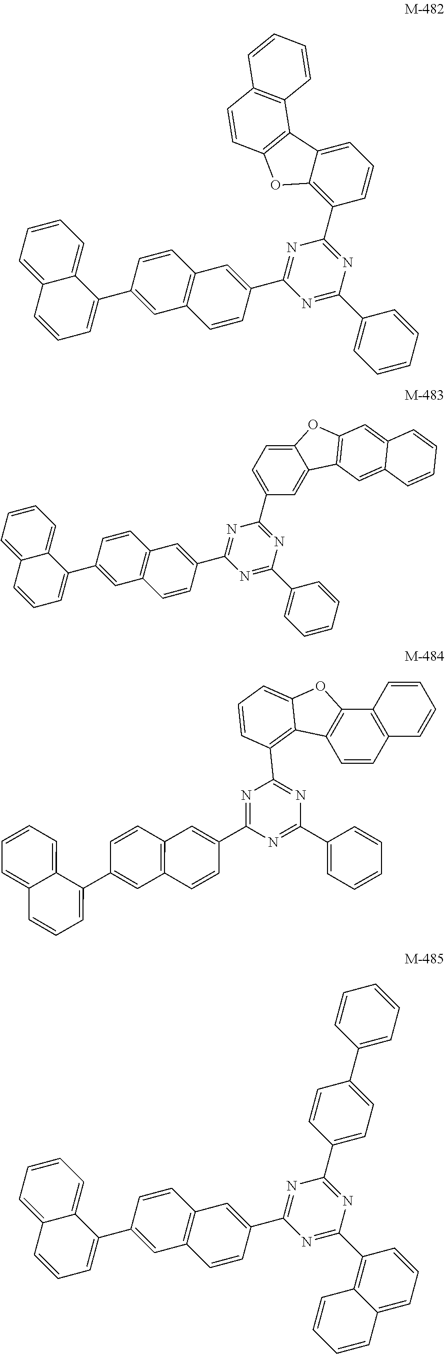 [SMILES: c1ccc(-c2nc(-c3ccc4cc(-c5cccc6ccccc56)ccc4c3)nc(-c3cccc4c3oc3ccc5ccccc5c34)n2)cc1 ; c1ccc(-c2nc(-c3ccc4cc(-c5cccc6ccccc56)ccc4c3)nc(-c3ccc4oc5cc6ccccc6cc5c4c3)n2)cc1 ; c1ccc(-c2nc(-c3ccc4cc(-c5cccc6ccccc56)ccc4c3)nc(-c3cccc4oc5c6ccccc6ccc5c34)n2)cc1 ; c1ccc(-c2ccc(-c3nc(-c4ccc5cc(-c6cccc7ccccc67)ccc5c4)nc(-c4cccc5ccccc45)n3)cc2)cc1]

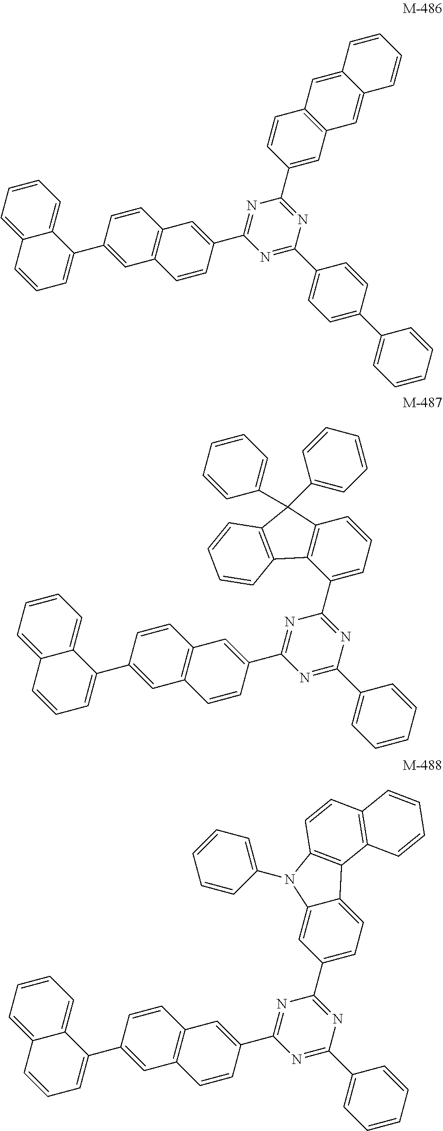

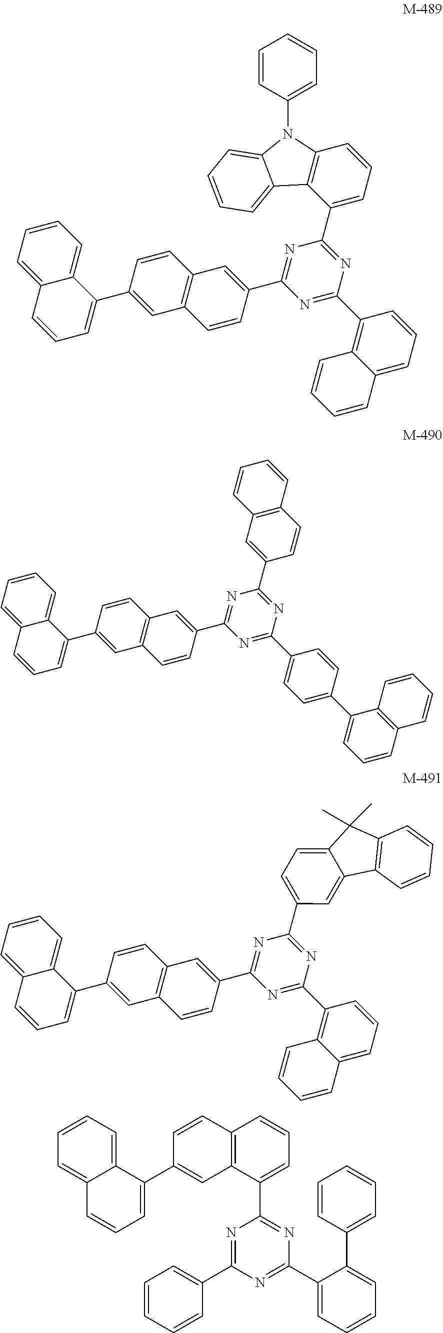

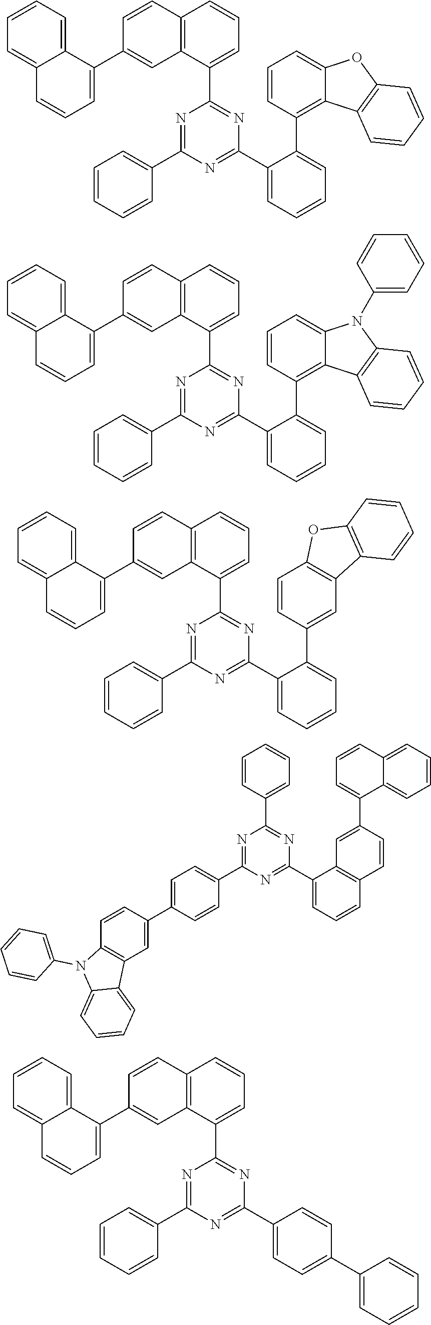

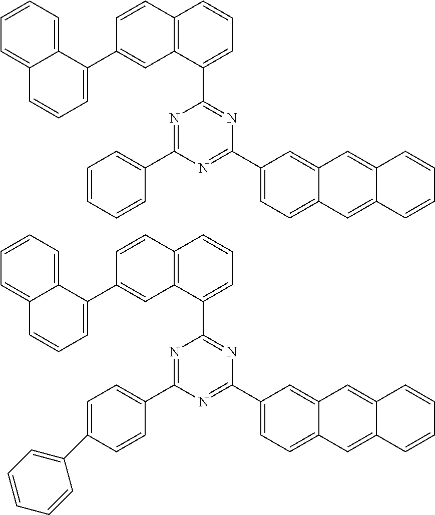

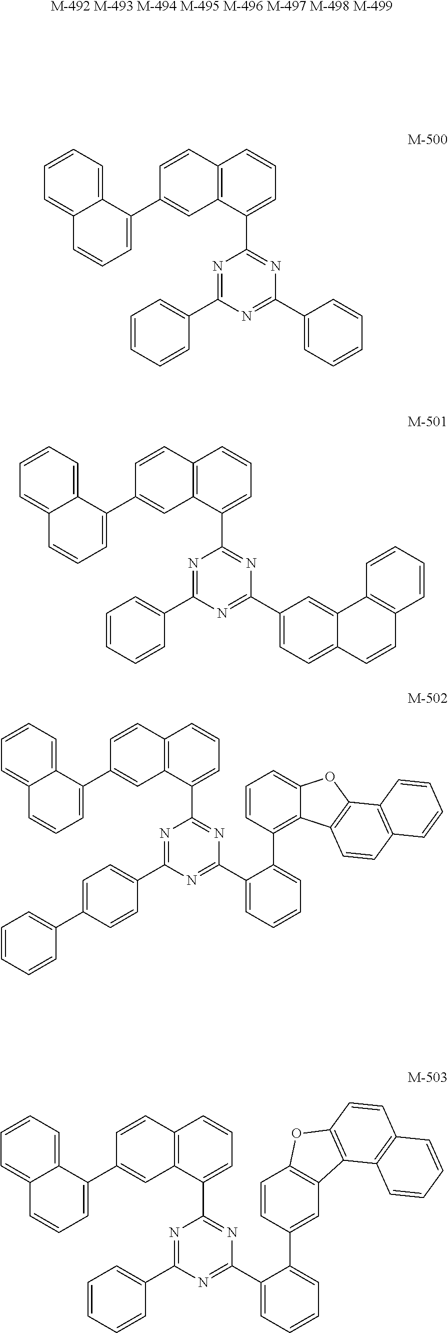 [SMILES: "M-492 M-493 M-494 M-495 M-496 M-497 M-498 M-499" ; c1ccc(-c2nc(-c3ccccc3)nc(-c3cccc4ccc(-c5cccc6ccccc56)cc34)n2)cc1 ; c1ccc(-c2nc(-c3ccc4ccc5ccccc5c4c3)nc(-c3cccc4ccc(-c5cccc6ccccc56)cc34)n2)cc1 ; c1ccc(-c2ccc(-c3nc(-c4ccccc4-c4cccc5oc6c7ccccc7ccc6c45)nc(-c4cccc5ccc(-c6cccc7ccccc67)cc45)n3)cc2)cc1 ; c1ccc(-c2nc(-c3ccccc3-c3ccc4oc5ccc6ccccc6c5c4c3)nc(-c3cccc4ccc(-c5cccc6ccccc56)cc34)n2)cc1]

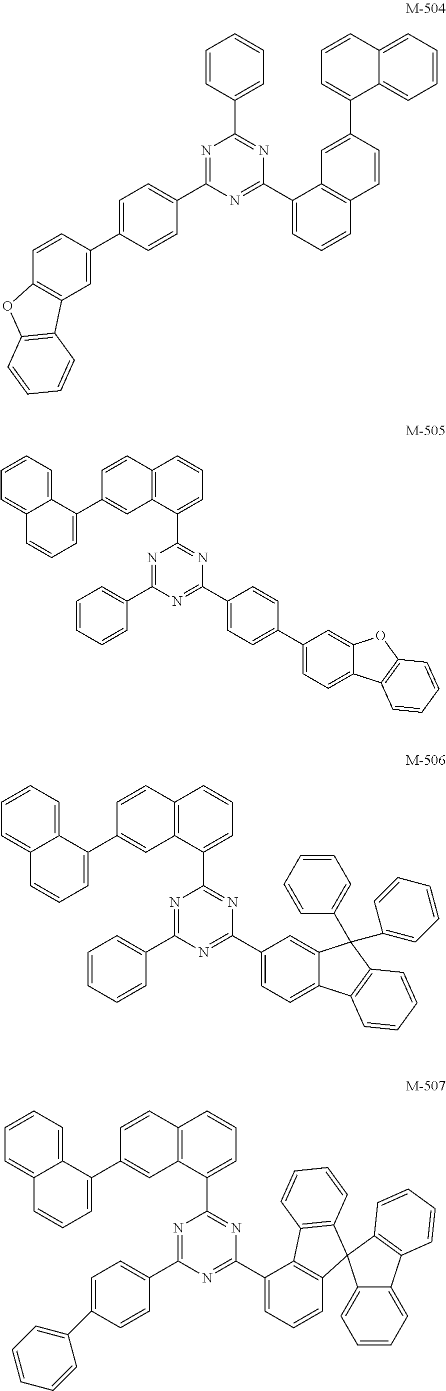 [SMILES: c1ccc(-c2nc(-c3ccc(-c4ccc5oc6ccccc6c5c4)cc3)nc(-c3cccc4ccc(-c5cccc6ccccc56)cc34)n2)cc1 ; c1ccc(-c2nc(-c3ccc(-c4ccc5c(c4)oc4ccccc45)cc3)nc(-c3cccc4ccc(-c5cccc6ccccc56)cc34)n2)cc1 ; c1ccc(-c2nc(-c3ccc4c(c3)C(c3ccccc3)(c3ccccc3)c3ccccc3-4)nc(-c3cccc4ccc(-c5cccc6ccccc56)cc34)n2)cc1 ; c1ccc(-c2ccc(-c3nc(-c4cccc5c4-c4ccccc4C54c5ccccc5-c5ccccc54)nc(-c4cccc5ccc(-c6cccc7ccccc67)cc45)n3)cc2)cc1]

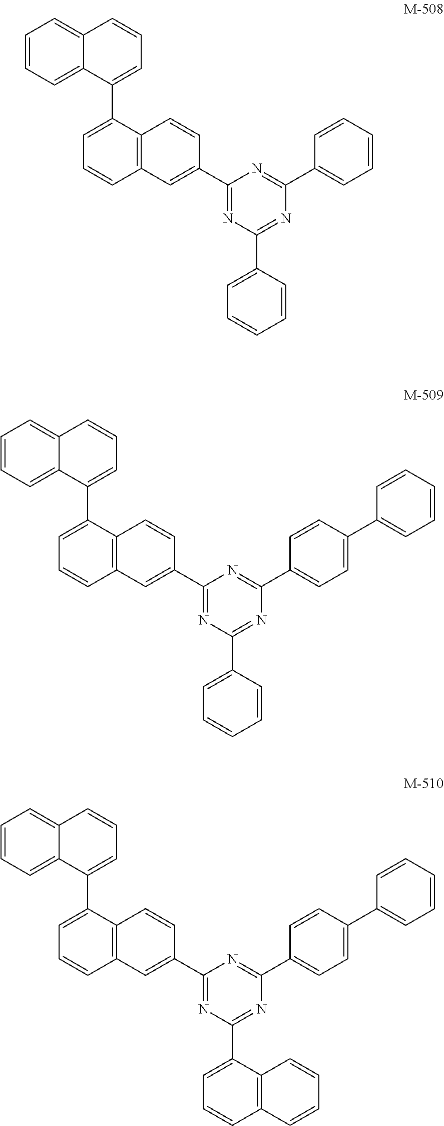 [SMILES: c1ccc(-c2nc(-c3ccccc3)nc(-c3ccc4c(-c5cccc6ccccc56)cccc4c3)n2)cc1 ; c1ccc(-c2ccc(-c3nc(-c4ccccc4)nc(-c4ccc5c(-c6cccc7ccccc67)cccc5c4)n3)cc2)cc1 ; c1ccc(-c2ccc(-c3nc(-c4ccc5c(-c6cccc7ccccc67)cccc5c4)nc(-c4cccc5ccccc45)n3)cc2)cc1]

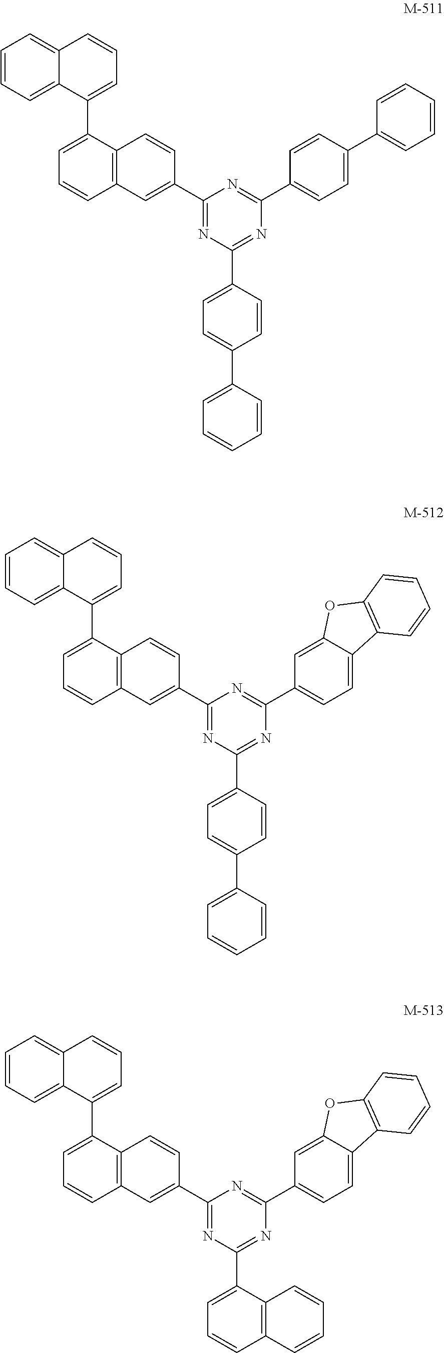 [SMILES: c1ccc(-c2ccc(-c3nc(-c4ccc(-c5ccccc5)cc4)nc(-c4ccc5c(-c6cccc7ccccc67)cccc5c4)n3)cc2)cc1 ; c1ccc(-c2ccc(-c3nc(-c4ccc5c(-c6cccc7ccccc67)cccc5c4)nc(-c4ccc5c(c4)oc4ccccc45)n3)cc2)cc1 ; c1ccc2c(-c3nc(-c4ccc5c(-c6cccc7ccccc67)cccc5c4)nc(-c4ccc5c(c4)oc4ccccc45)n3)cccc2c1]

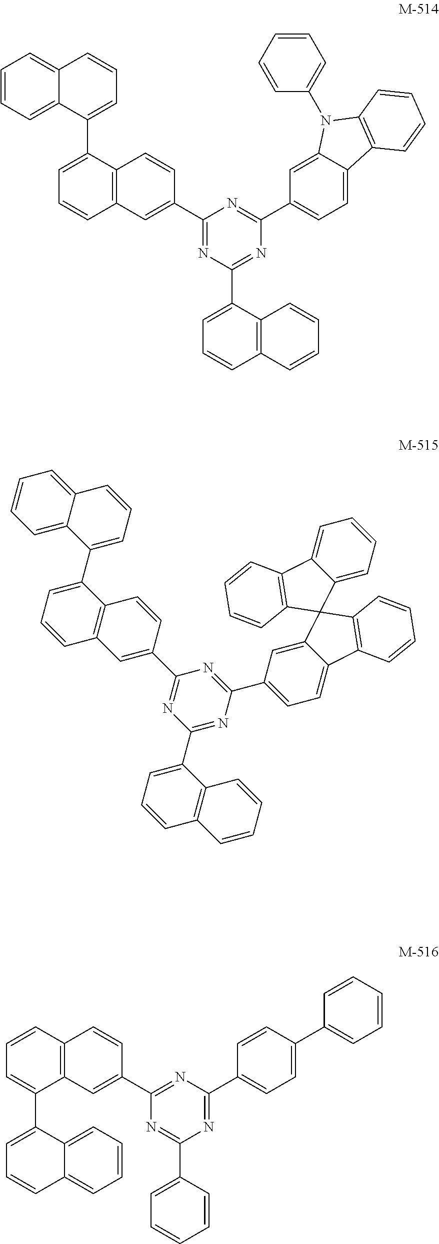 [SMILES: c1ccc(-n2c3ccccc3c3ccc(-c4nc(-c5ccc6c(-c7cccc8ccccc78)cccc6c5)nc(-c5cccc6ccccc56)n4)cc32)cc1 ; c1ccc2c(c1)-c1ccccc1C21c2ccccc2-c2ccc(-c3nc(-c4ccc5c(-c6cccc7ccccc67)cccc5c4)nc(-c4cccc5ccccc45)n3)cc21 ; c1ccc(-c2ccc(-c3nc(-c4ccccc4)nc(-c4ccc5cccc(-c6cccc7ccccc67)c5c4)n3)cc2)cc1]

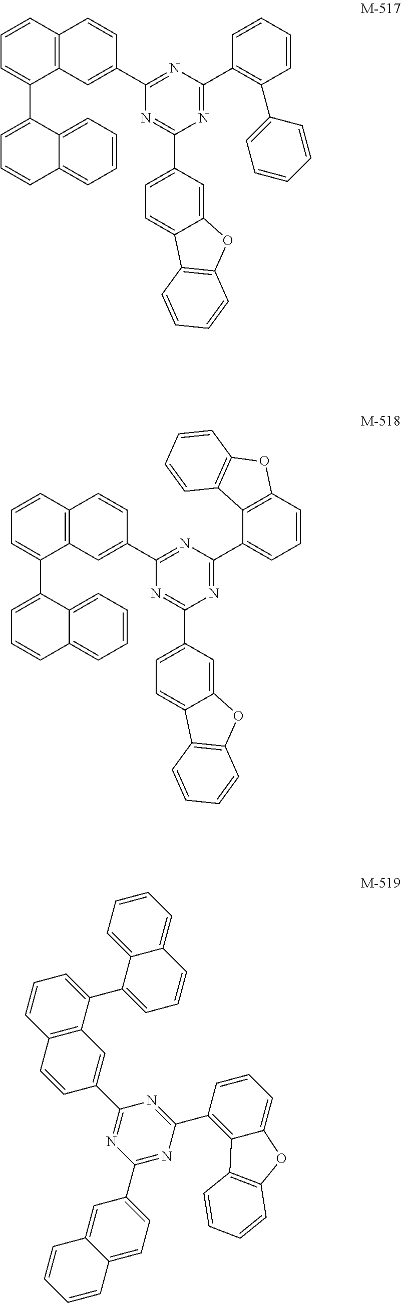 [SMILES: c1ccc(-c2ccccc2-c2nc(-c3ccc4c(c3)oc3ccccc34)nc(-c3ccc4cccc(-c5cccc6ccccc56)c4c3)n2)cc1 ; c1ccc2c(-c3cccc4ccc(-c5nc(-c6ccc7c(c6)oc6ccccc67)nc(-c6cccc7oc8ccccc8c67)n5)cc34)cccc2c1 ; c1ccc2cc(-c3nc(-c4ccc5cccc(-c6cccc7ccccc67)c5c4)nc(-c4cccc5oc6ccccc6c45)n3)ccc2c1]

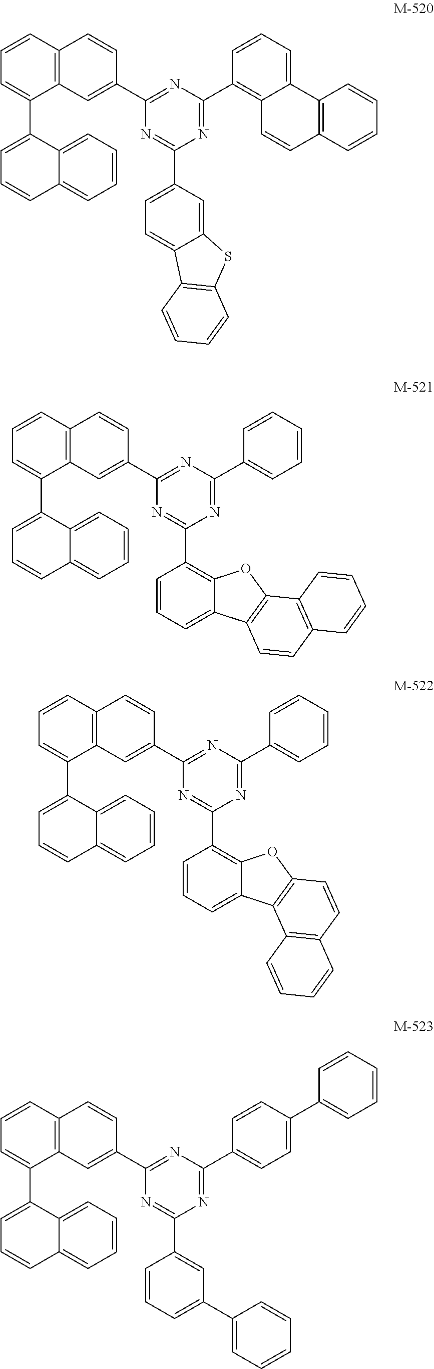

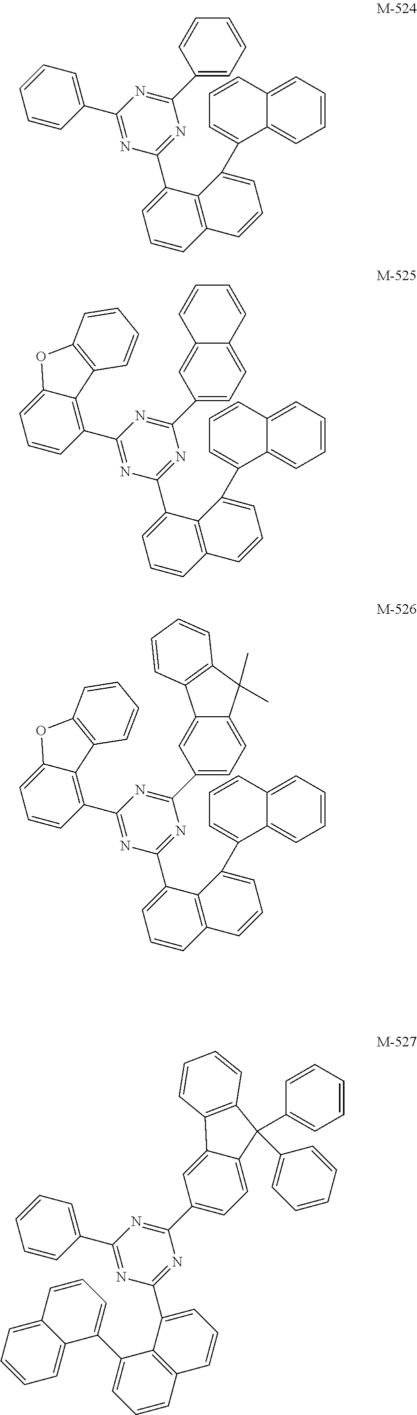

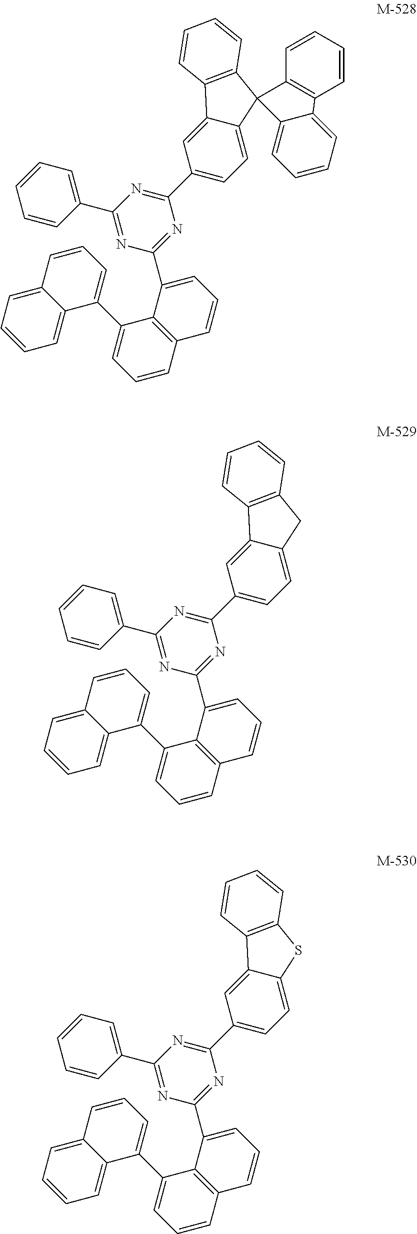 [SMILES: c1ccc(-c2nc(-c3ccc4c(c3)-c3ccccc3C43c4ccccc4-c4ccccc43)nc(-c3cccc4cccc(-c5cccc6ccccc56)c34)n2)cc1 ; c1ccc(-c2nc(-c3ccc4c(c3)-c3ccccc3C4)nc(-c3cccc4cccc(-c5cccc6ccccc56)c34)n2)cc1 ; c1ccc(-c2nc(-c3ccc4sc5ccccc5c4c3)nc(-c3cccc4cccc(-c5cccc6ccccc56)c34)n2)cc1]

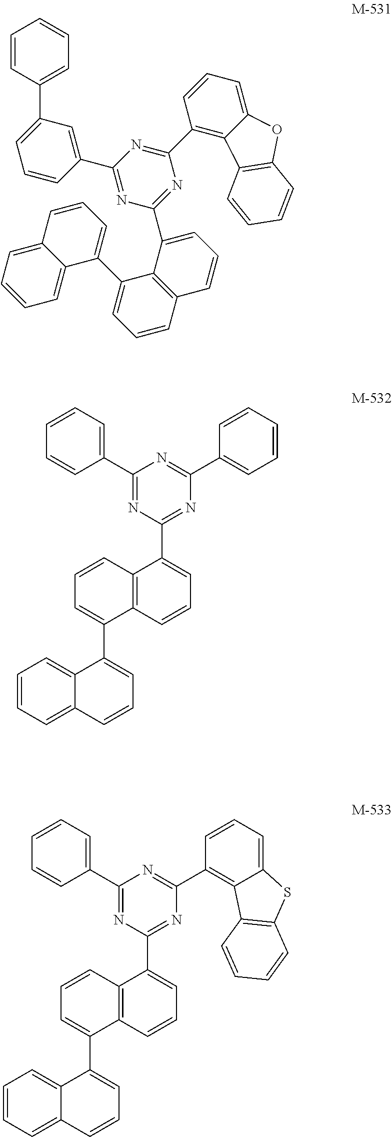 [SMILES: c1ccc(-c2cccc(-c3nc(-c4cccc5cccc(-c6cccc7ccccc67)c45)nc(-c4cccc5oc6ccccc6c45)n3)c2)cc1 ; c1ccc(-c2nc(-c3ccccc3)nc(-c3cccc4c(-c5cccc6ccccc56)cccc34)n2)cc1 ; c1ccc(-c2nc(-c3cccc4c(-c5cccc6ccccc56)cccc34)nc(-c3cccc4sc5ccccc5c34)n2)cc1]

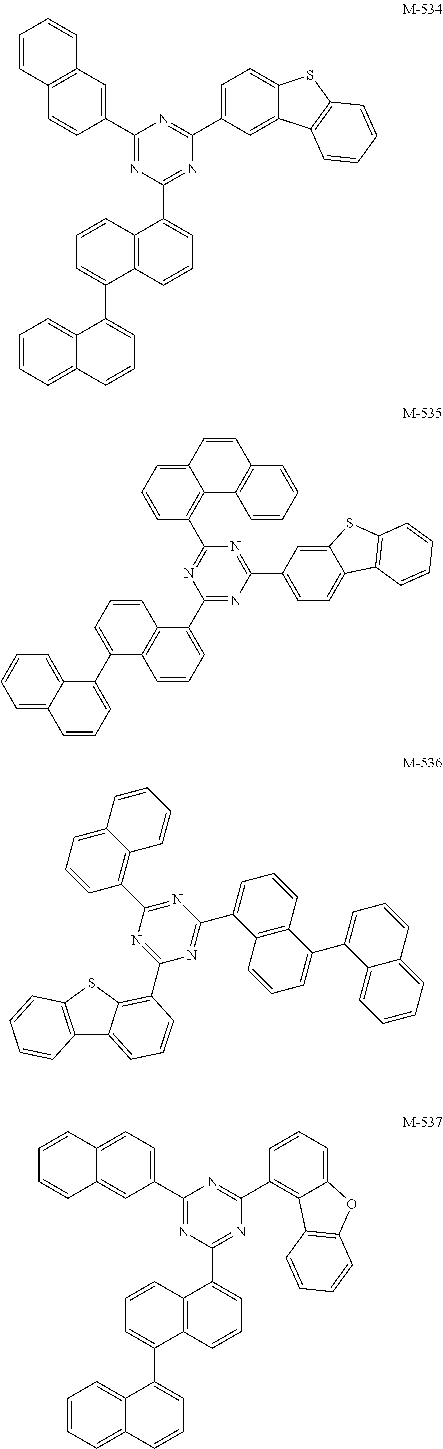 [SMILES: c1ccc2cc(-c3nc(-c4ccc5sc6ccccc6c5c4)nc(-c4cccc5c(-c6cccc7ccccc67)cccc45)n3)ccc2c1 ; c1ccc2c(-c3cccc4c(-c5nc(-c6ccc7c(c6)sc6ccccc67)nc(-c6cccc7ccc8ccccc8c67)n5)cccc34)cccc2c1 ; c1ccc2c(-c3nc(-c4cccc5c(-c6cccc7ccccc67)cccc45)nc(-c4cccc5c4sc4ccccc45)n3)cccc2c1 ; c1ccc2cc(-c3nc(-c4cccc5c(-c6cccc7ccccc67)cccc45)nc(-c4cccc5oc6ccccc6c45)n3)ccc2c1]

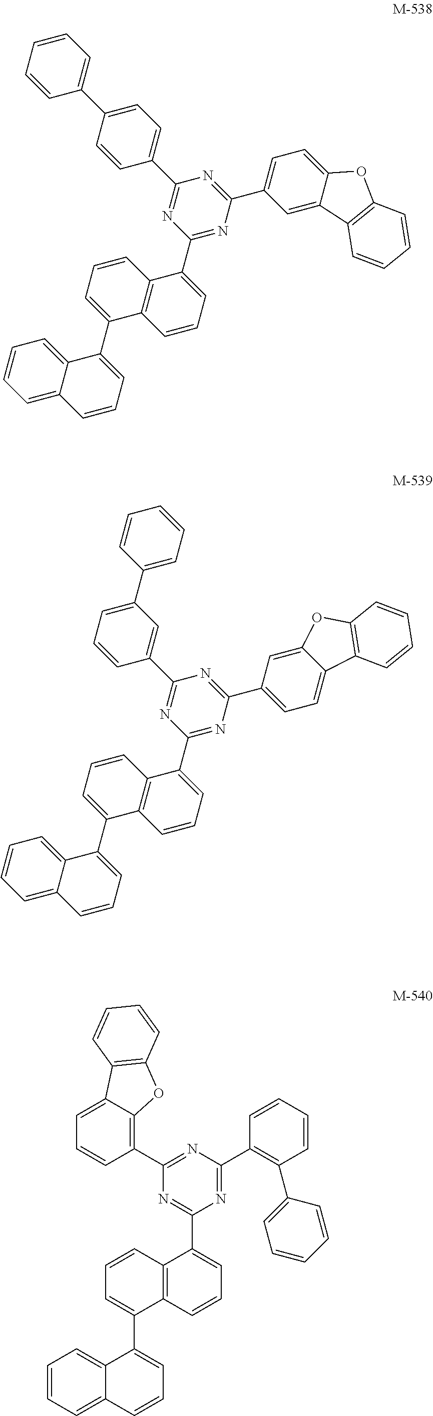 [SMILES: c1ccc(-c2ccc(-c3nc(-c4ccc5oc6ccccc6c5c4)nc(-c4cccc5c(-c6cccc7ccccc67)cccc45)n3)cc2)cc1 ; c1ccc(-c2cccc(-c3nc(-c4ccc5c(c4)oc4ccccc45)nc(-c4cccc5c(-c6cccc7ccccc67)cccc45)n3)c2)cc1 ; c1ccc(-c2ccccc2-c2nc(-c3cccc4c(-c5cccc6ccccc56)cccc34)nc(-c3cccc4c3oc3ccccc34)n2)cc1]

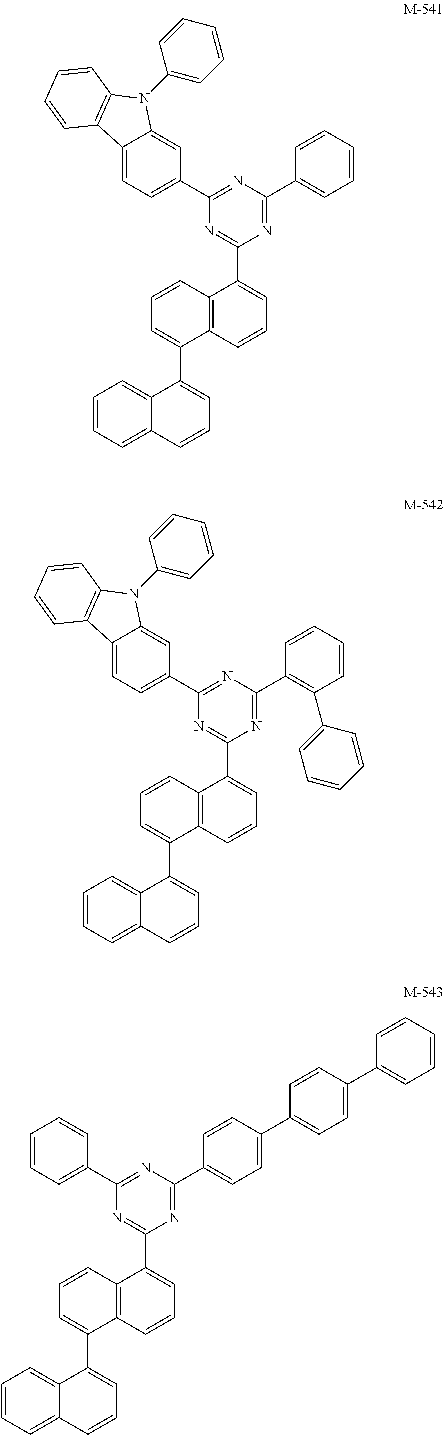 [SMILES: c1ccc(-c2nc(-c3ccc4c5ccccc5n(-c5ccccc5)c4c3)nc(-c3cccc4c(-c5cccc6ccccc56)cccc34)n2)cc1 ; c1ccc(-c2ccccc2-c2nc(-c3ccc4c5ccccc5n(-c5ccccc5)c4c3)nc(-c3cccc4c(-c5cccc6ccccc56)cccc34)n2)cc1 ; c1ccc(-c2ccc(-c3ccc(-c4nc(-c5ccccc5)nc(-c5cccc6c(-c7cccc8ccccc78)cccc56)n4)cc3)cc2)cc1]

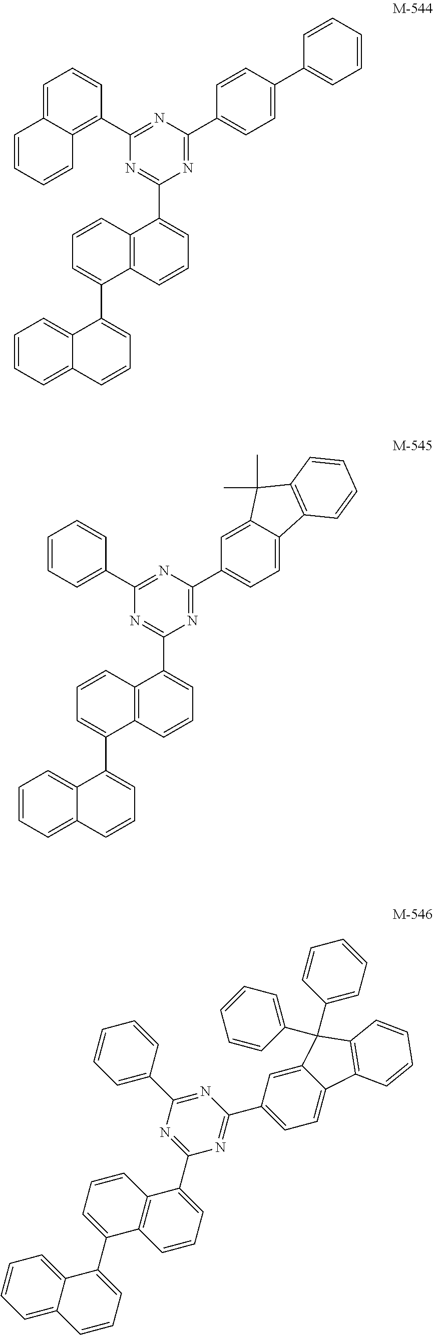 [SMILES: c1ccc(-c2ccc(-c3nc(-c4cccc5ccccc45)nc(-c4cccc5c(-c6cccc7ccccc67)cccc45)n3)cc2)cc1 ; CC1(C)c2ccccc2-c2ccc(-c3nc(-c4ccccc4)nc(-c4cccc5c(-c6cccc7ccccc67)cccc45)n3)cc21 ; c1ccc(-c2nc(-c3ccc4c(c3)C(c3ccccc3)(c3ccccc3)c3ccccc3-4)nc(-c3cccc4c(-c5cccc6ccccc56)cccc34)n2)cc1]

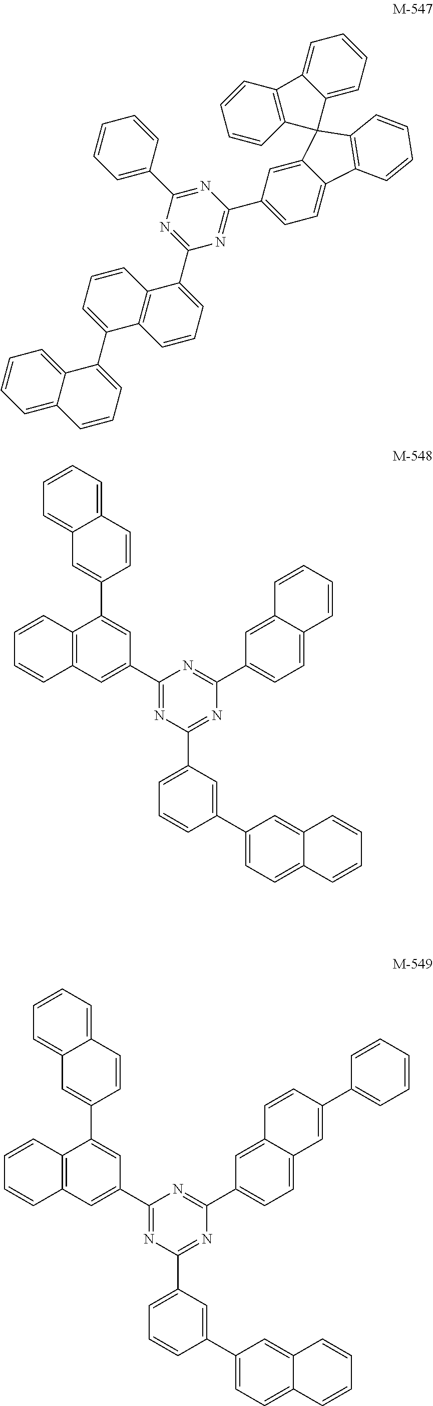

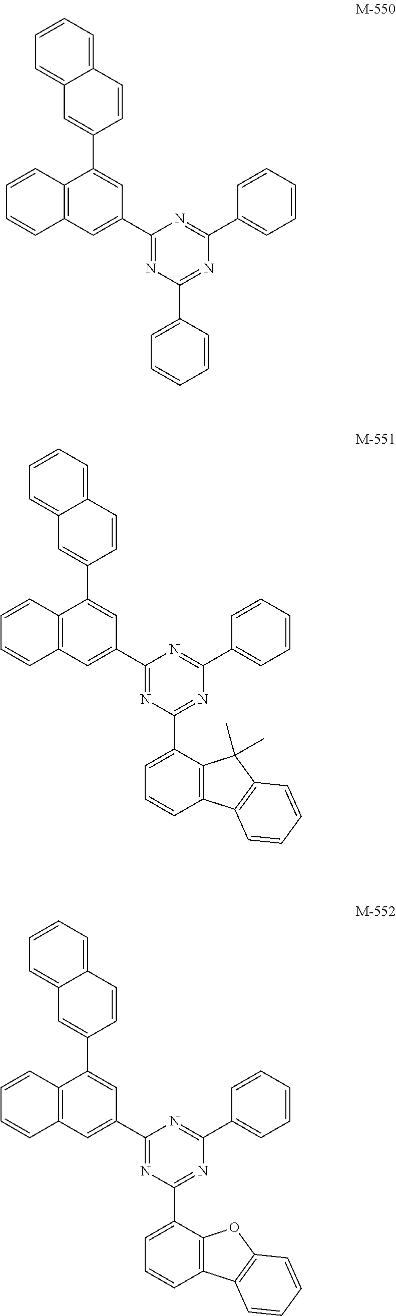 [SMILES: c1ccc(-c2nc(-c3ccccc3)nc(-c3cc(-c4ccc5ccccc5c4)c4ccccc4c3)n2)cc1 ; CC1(C)c2ccccc2-c2cccc(-c3nc(-c4ccccc4)nc(-c4cc(-c5ccc6ccccc6c5)c5ccccc5c4)n3)c21 ; c1ccc(-c2nc(-c3cc(-c4ccc5ccccc5c4)c4ccccc4c3)nc(-c3cccc4c3oc3ccccc34)n2)cc1]

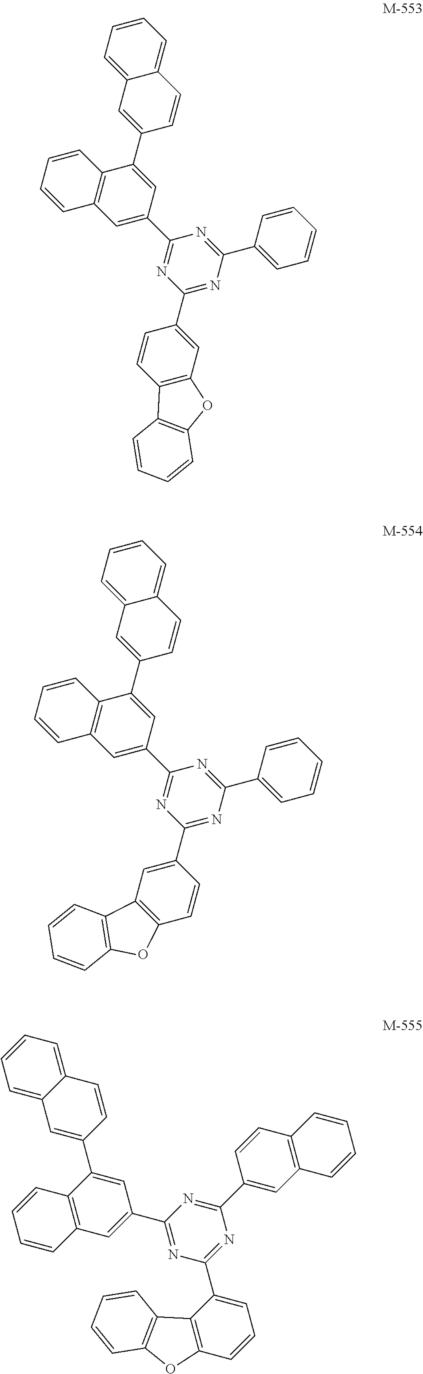 [SMILES: c1ccc(-c2nc(-c3cc(-c4ccc5ccccc5c4)c4ccccc4c3)nc(-c3ccc4c(c3)oc3ccccc34)n2)cc1 ; c1ccc(-c2nc(-c3cc(-c4ccc5ccccc5c4)c4ccccc4c3)nc(-c3ccc4oc5ccccc5c4c3)n2)cc1 ; c1ccc2cc(-c3nc(-c4cc(-c5ccc6ccccc6c5)c5ccccc5c4)nc(-c4cccc5oc6ccccc6c45)n3)ccc2c1]

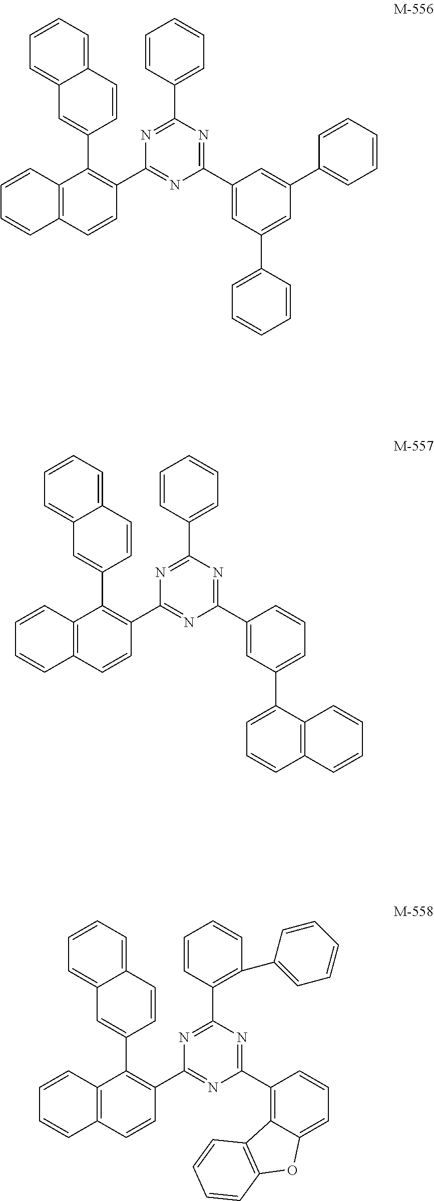 [SMILES: c1ccc(-c2cc(-c3ccccc3)cc(-c3nc(-c4ccccc4)nc(-c4ccc5ccccc5c4-c4ccc5ccccc5c4)n3)c2)cc1 ; c1ccc(-c2nc(-c3cccc(-c4cccc5ccccc45)c3)nc(-c3ccc4ccccc4c3-c3ccc4ccccc4c3)n2)cc1 ; c1ccc(-c2ccccc2-c2nc(-c3ccc4ccccc4c3-c3ccc4ccccc4c3)nc(-c3cccc4oc5ccccc5c34)n2)cc1]

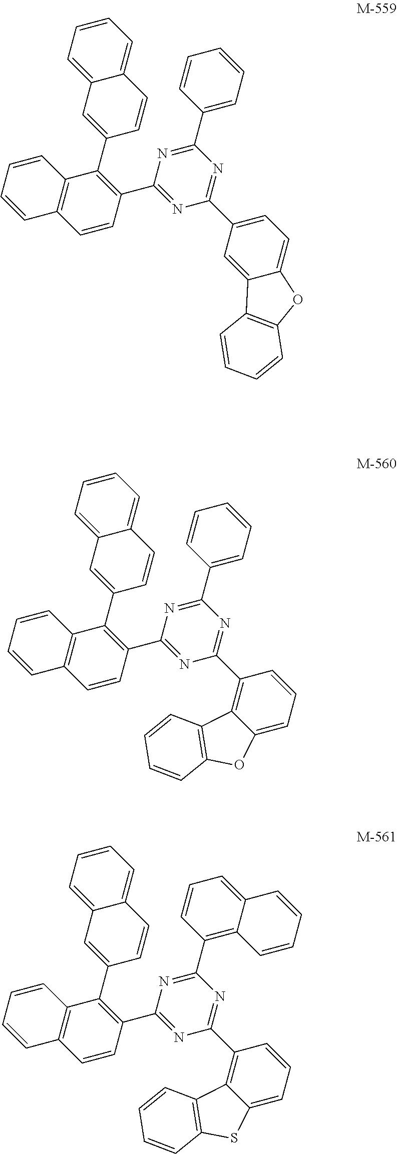 [SMILES: c1ccc(-c2nc(-c3ccc4oc5ccccc5c4c3)nc(-c3ccc4ccccc4c3-c3ccc4ccccc4c3)n2)cc1 ; c1ccc(-c2nc(-c3ccc4ccccc4c3-c3ccc4ccccc4c3)nc(-c3cccc4oc5ccccc5c34)n2)cc1 ; c1ccc2cc(-c3c(-c4nc(-c5cccc6ccccc56)nc(-c5cccc6sc7ccccc7c56)n4)ccc4ccccc34)ccc2c1]

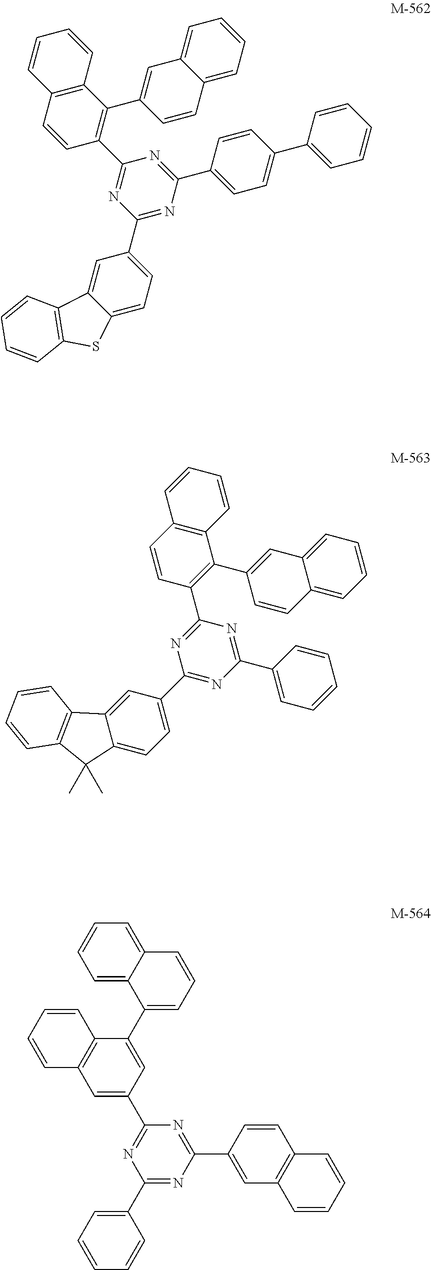 [SMILES: c1ccc(-c2ccc(-c3nc(-c4ccc5sc6ccccc6c5c4)nc(-c4ccc5ccccc5c4-c4ccc5ccccc5c4)n3)cc2)cc1 ; CC1(C)c2ccccc2-c2cc(-c3nc(-c4ccccc4)nc(-c4ccc5ccccc5c4-c4ccc5ccccc5c4)n3)ccc21 ; c1ccc(-c2nc(-c3ccc4ccccc4c3)nc(-c3cc(-c4cccc5ccccc45)c4ccccc4c3)n2)cc1]

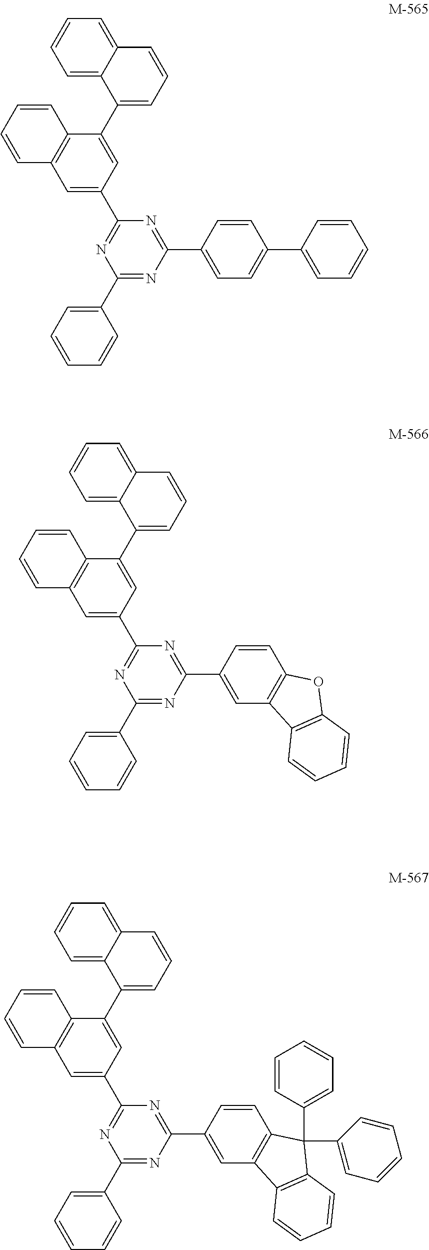 [SMILES: c1ccc(-c2ccc(-c3nc(-c4ccccc4)nc(-c4cc(-c5cccc6ccccc56)c5ccccc5c4)n3)cc2)cc1 ; c1ccc(-c2nc(-c3cc(-c4cccc5ccccc45)c4ccccc4c3)nc(-c3ccc4oc5ccccc5c4c3)n2)cc1 ; c1ccc(-c2nc(-c3ccc4c(c3)-c3ccccc3C4(c3ccccc3)c3ccccc3)nc(-c3cc(-c4cccc5ccccc45)c4ccccc4c3)n2)cc1]

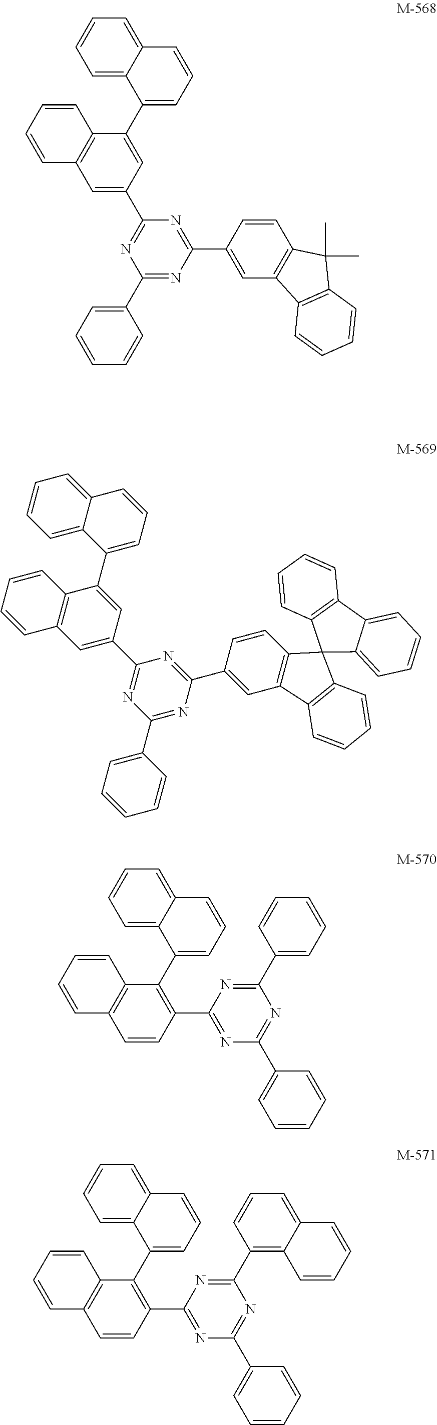 [SMILES: CC1(C)c2ccccc2-c2cc(-c3nc(-c4ccccc4)nc(-c4cc(-c5cccc6ccccc56)c5ccccc5c4)n3)ccc21 ; c1ccc(-c2nc(-c3ccc4c(c3)-c3ccccc3C43c4ccccc4-c4ccccc43)nc(-c3cc(-c4cccc5ccccc45)c4ccccc4c3)n2)cc1 ; c1ccc(-c2nc(-c3ccccc3)nc(-c3ccc4ccccc4c3-c3cccc4ccccc34)n2)cc1 ; c1ccc(-c2nc(-c3ccc4ccccc4c3-c3cccc4ccccc34)nc(-c3cccc4ccccc34)n2)cc1]

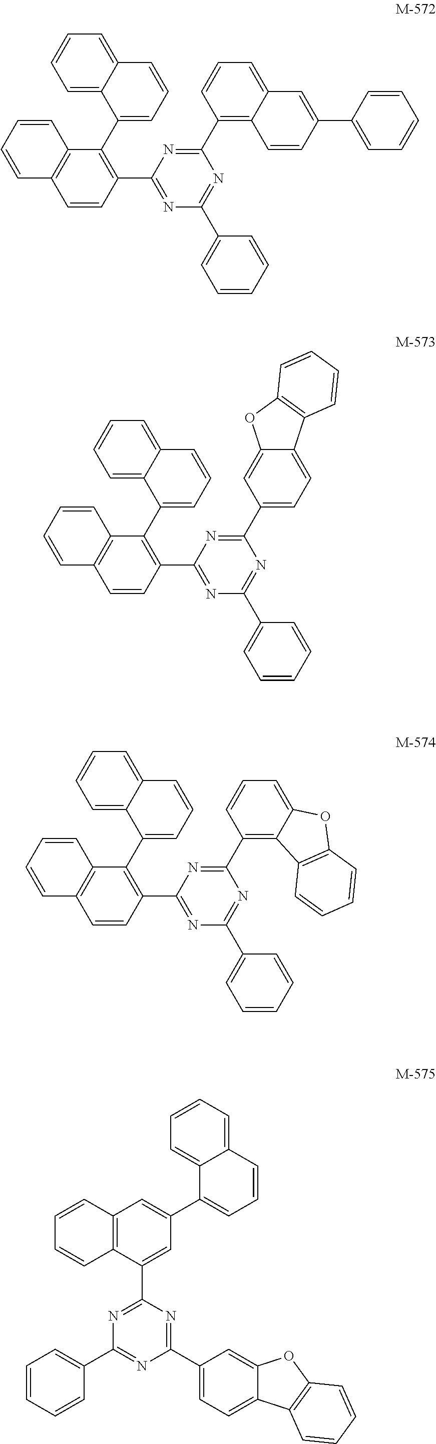 [SMILES: c1ccc(-c2ccc3c(-c4nc(-c5ccccc5)nc(-c5ccc6ccccc6c5-c5cccc6ccccc56)n4)cccc3c2)cc1 ; c1ccc(-c2nc(-c3ccc4c(c3)oc3ccccc34)nc(-c3ccc4ccccc4c3-c3cccc4ccccc34)n2)cc1 ; c1ccc(-c2nc(-c3ccc4ccccc4c3-c3cccc4ccccc34)nc(-c3cccc4oc5ccccc5c34)n2)cc1 ; c1ccc(-c2nc(-c3ccc4c(c3)oc3ccccc34)nc(-c3cc(-c4cccc5ccccc45)cc4ccccc34)n2)cc1]

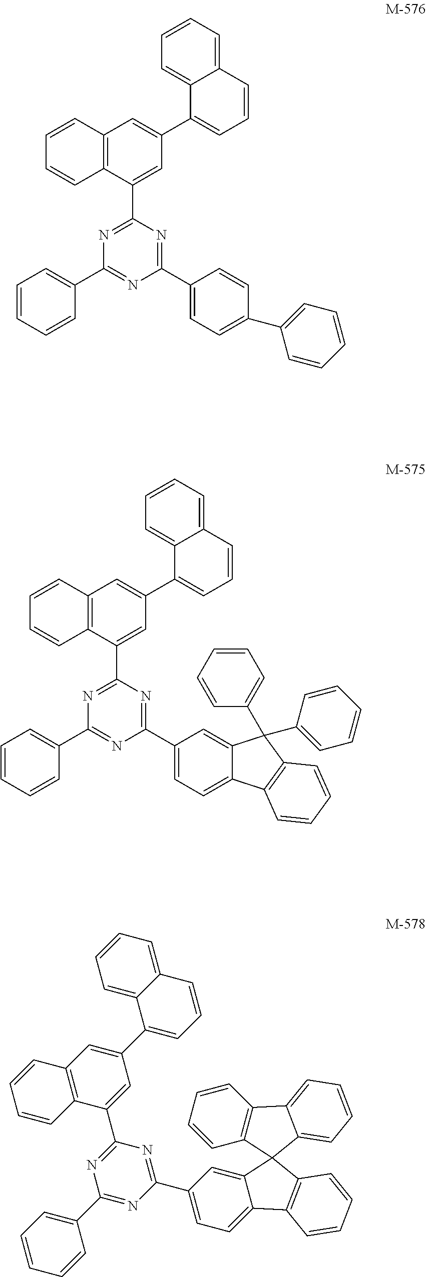 [SMILES: c1ccc(-c2ccc(-c3nc(-c4ccccc4)nc(-c4cc(-c5cccc6ccccc56)cc5ccccc45)n3)cc2)cc1 ; c1ccc(-c2nc(-c3ccc4c(c3)C(c3ccccc3)(c3ccccc3)c3ccccc3-4)nc(-c3cc(-c4cccc5ccccc45)cc4ccccc34)n2)cc1 ; c1ccc(-c2nc(-c3ccc4c(c3)C3(c5ccccc5-c5ccccc53)c3ccccc3-4)nc(-c3cc(-c4cccc5ccccc45)cc4ccccc34)n2)cc1]

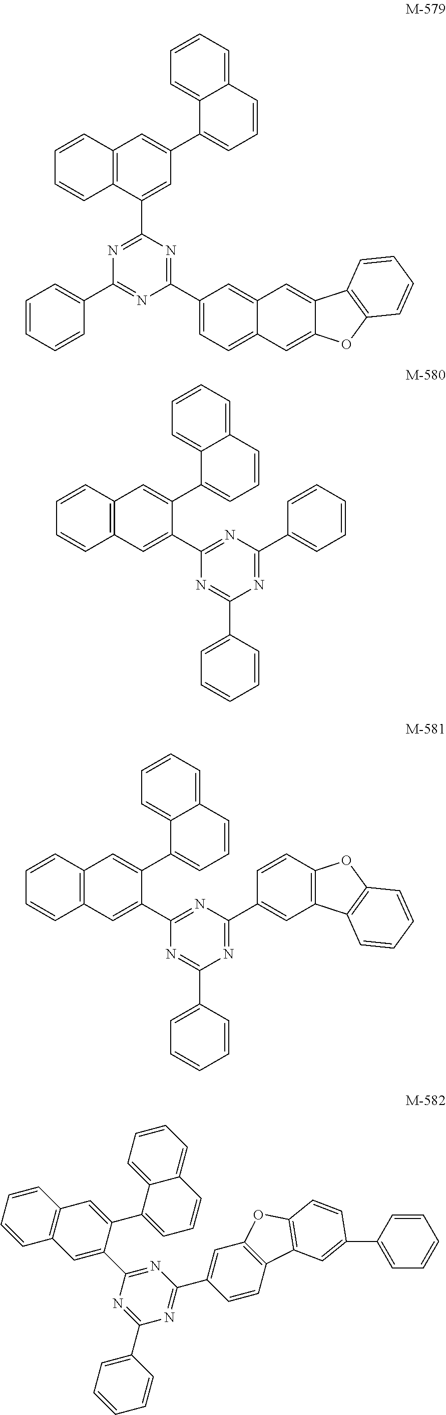

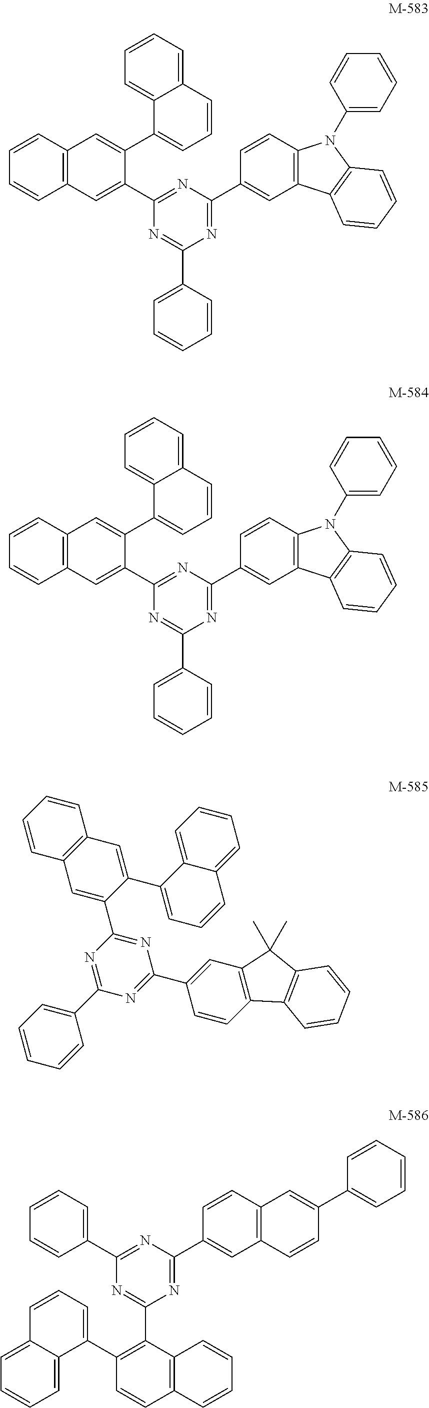 [SMILES: c1ccc(-c2nc(-c3ccc4c(c3)c3ccccc3n4-c3ccccc3)nc(-c3cc4ccccc4cc3-c3cccc4ccccc34)n2)cc1 ; c1ccc(-c2nc(-c3ccc4c(c3)c3ccccc3n4-c3ccccc3)nc(-c3cc4ccccc4cc3-c3cccc4ccccc34)n2)cc1 ; CC1(C)c2ccccc2-c2ccc(-c3nc(-c4ccccc4)nc(-c4cc5ccccc5cc4-c4cccc5ccccc45)n3)cc21 ; c1ccc(-c2ccc3cc(-c4nc(-c5ccccc5)nc(-c5c(-c6cccc7ccccc67)ccc6ccccc56)n4)ccc3c2)cc1]

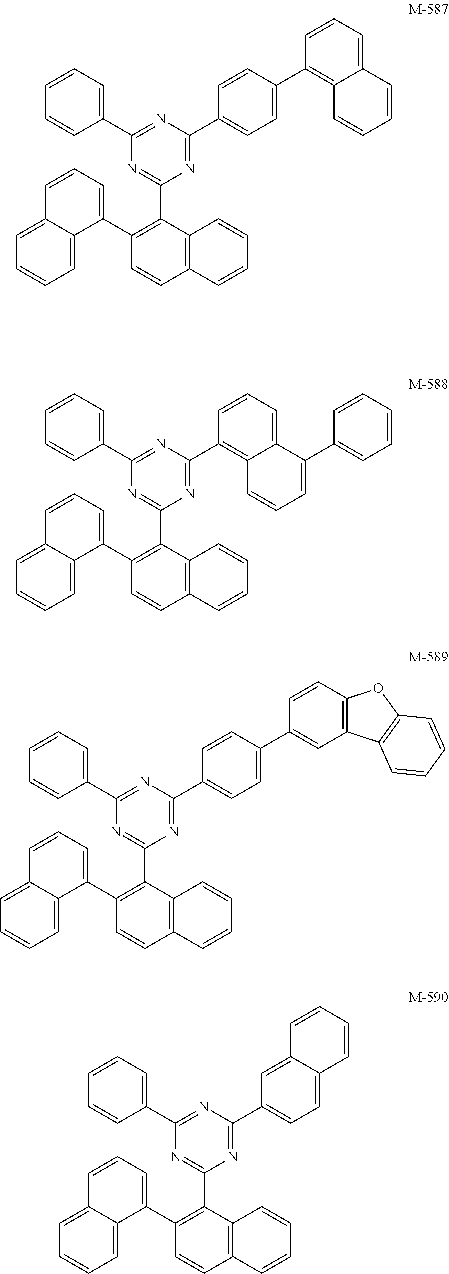 [SMILES: c1ccc(-c2nc(-c3ccc(-c4cccc5ccccc45)cc3)nc(-c3c(-c4cccc5ccccc45)ccc4ccccc34)n2)cc1 ; c1ccc(-c2nc(-c3c(-c4cccc5ccccc45)ccc4ccccc34)nc(-c3cccc4c(-c5ccccc5)cccc34)n2)cc1 ; c1ccc(-c2nc(-c3ccc(-c4ccc5oc6ccccc6c5c4)cc3)nc(-c3c(-c4cccc5ccccc45)ccc4ccccc34)n2)cc1 ; c1ccc(-c2nc(-c3ccc4ccccc4c3)nc(-c3c(-c4cccc5ccccc45)ccc4ccccc34)n2)cc1]

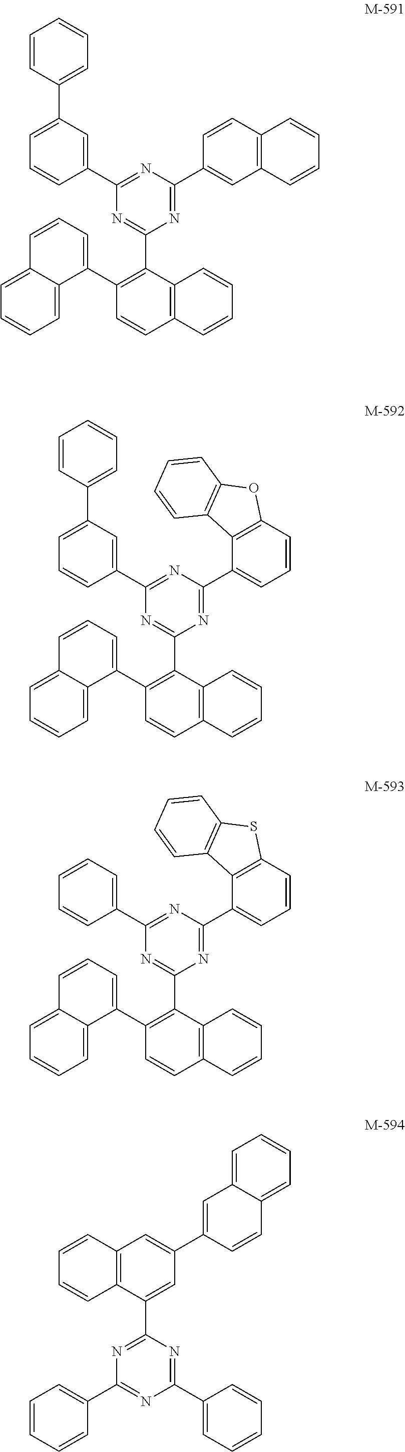 [SMILES: c1ccc(-c2cccc(-c3nc(-c4ccc5ccccc5c4)nc(-c4c(-c5cccc6ccccc56)ccc5ccccc45)n3)c2)cc1 ; c1ccc(-c2cccc(-c3nc(-c4c(-c5cccc6ccccc56)ccc5ccccc45)nc(-c4cccc5oc6ccccc6c45)n3)c2)cc1 ; c1ccc(-c2nc(-c3c(-c4cccc5ccccc45)ccc4ccccc34)nc(-c3cccc4sc5ccccc5c34)n2)cc1 ; c1ccc(-c2nc(-c3ccccc3)nc(-c3cc(-c4ccc5ccccc5c4)cc4ccccc34)n2)cc1]

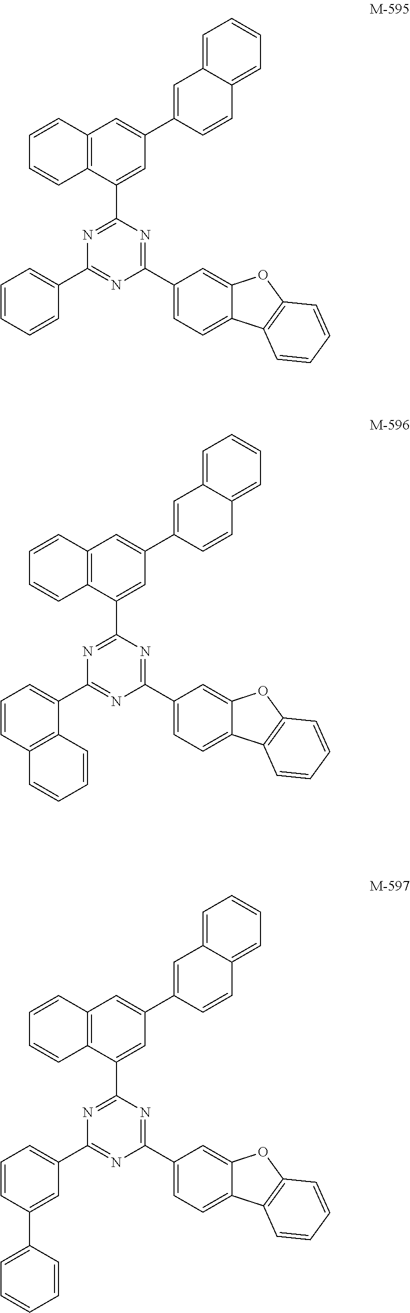 [SMILES: c1ccc(-c2nc(-c3ccc4c(c3)oc3ccccc34)nc(-c3cc(-c4ccc5ccccc5c4)cc4ccccc34)n2)cc1 ; c1ccc2cc(-c3cc(-c4nc(-c5ccc6c(c5)oc5ccccc56)nc(-c5cccc6ccccc56)n4)c4ccccc4c3)ccc2c1 ; c1ccc(-c2cccc(-c3nc(-c4ccc5c(c4)oc4ccccc45)nc(-c4cc(-c5ccc6ccccc6c5)cc5ccccc45)n3)c2)cc1]

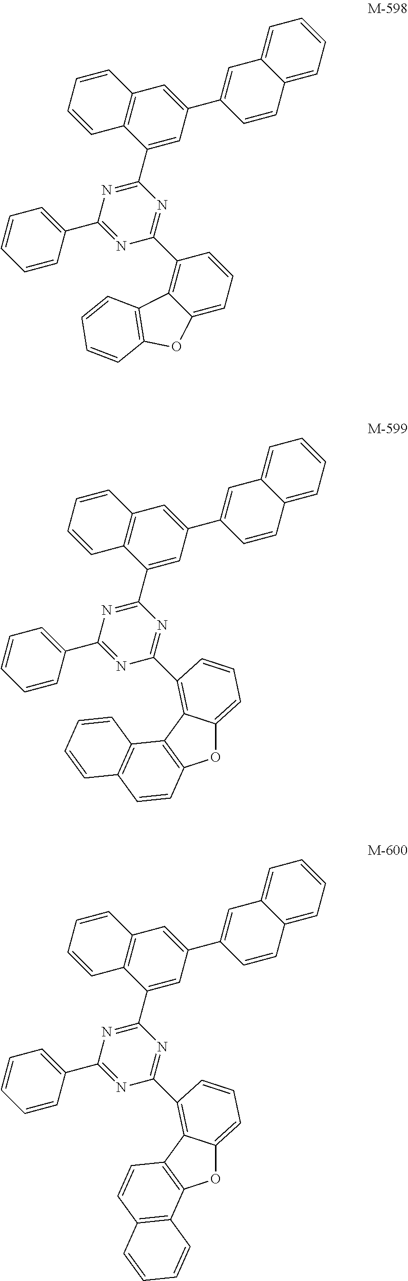 [SMILES: c1ccc(-c2nc(-c3cc(-c4ccc5ccccc5c4)cc4ccccc34)nc(-c3cccc4oc5ccccc5c34)n2)cc1 ; c1ccc(-c2nc(-c3cc(-c4ccc5ccccc5c4)cc4ccccc34)nc(-c3cccc4oc5ccc6ccccc6c5c34)n2)cc1 ; c1ccc(-c2nc(-c3cc(-c4ccc5ccccc5c4)cc4ccccc34)nc(-c3cccc4oc5c6ccccc6ccc5c34)n2)cc1]

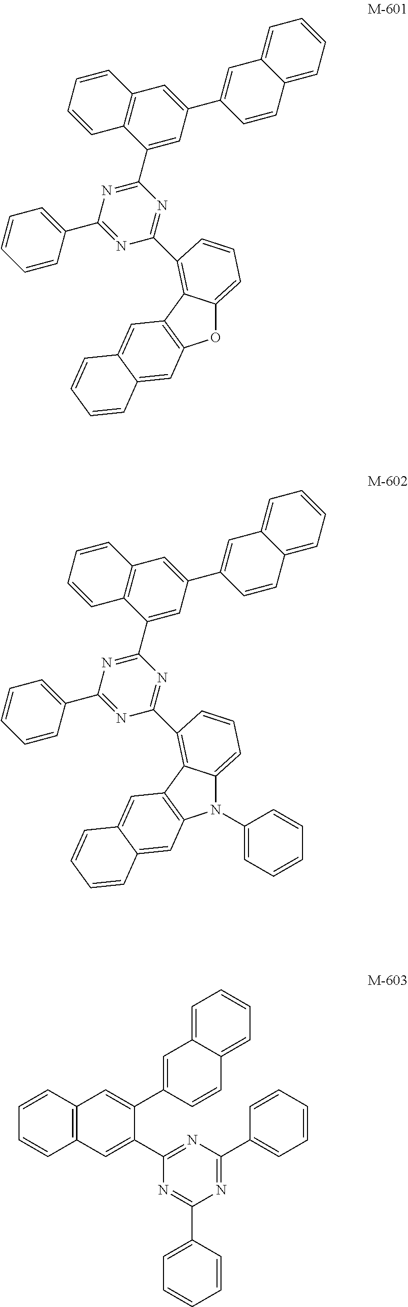 [SMILES: c1ccc(-c2nc(-c3cc(-c4ccc5ccccc5c4)cc4ccccc34)nc(-c3cccc4oc5cc6ccccc6cc5c34)n2)cc1 ; c1ccc(-c2nc(-c3cc(-c4ccc5ccccc5c4)cc4ccccc34)nc(-c3cccc4c3c3cc5ccccc5cc3n4-c3ccccc3)n2)cc1 ; c1ccc(-c2nc(-c3ccccc3)nc(-c3cc4ccccc4cc3-c3ccc4ccccc4c3)n2)cc1]

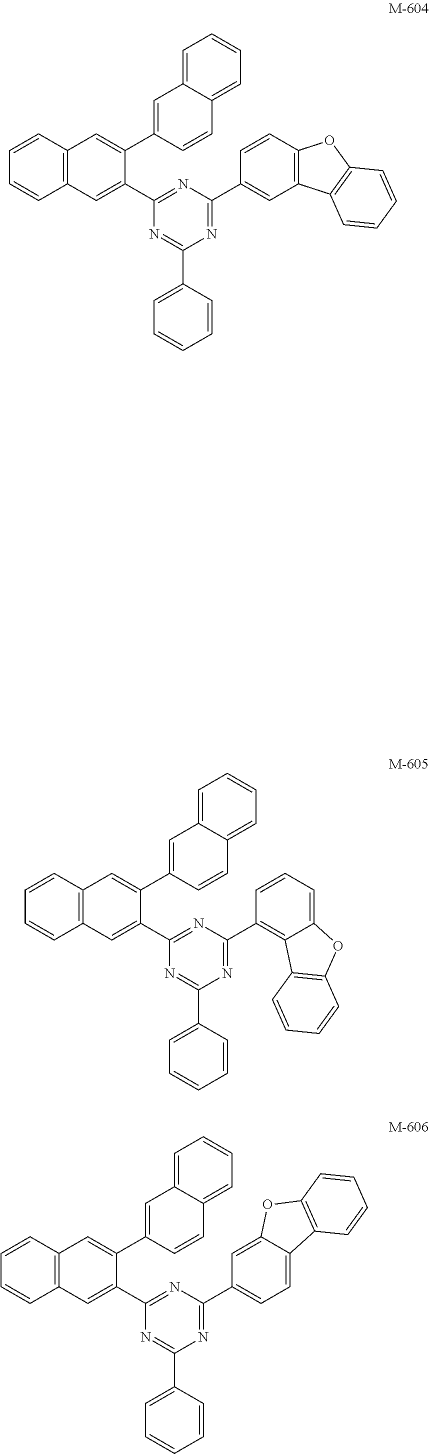 [SMILES: c1ccc(-c2nc(-c3ccc4oc5ccccc5c4c3)nc(-c3cc4ccccc4cc3-c3ccc4ccccc4c3)n2)cc1 ; c1ccc(-c2nc(-c3cc4ccccc4cc3-c3ccc4ccccc4c3)nc(-c3cccc4oc5ccccc5c34)n2)cc1 ; c1ccc(-c2nc(-c3ccc4c(c3)oc3ccccc34)nc(-c3cc4ccccc4cc3-c3ccc4ccccc4c3)n2)cc1]

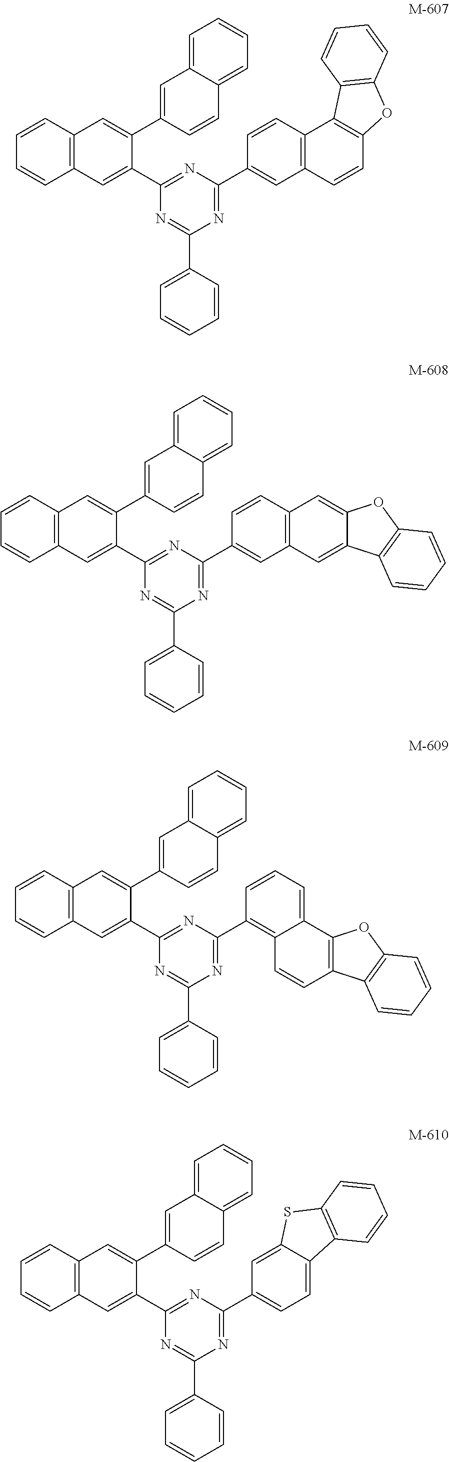 [SMILES: c1ccc(-c2nc(-c3ccc4c(ccc5oc6ccccc6c54)c3)nc(-c3cc4ccccc4cc3-c3ccc4ccccc4c3)n2)cc1 ; c1ccc(-c2nc(-c3ccc4cc5oc6ccccc6c5cc4c3)nc(-c3cc4ccccc4cc3-c3ccc4ccccc4c3)n2)cc1 ; c1ccc(-c2nc(-c3cc4ccccc4cc3-c3ccc4ccccc4c3)nc(-c3cccc4c3ccc3c5ccccc5oc43)n2)cc1 ; c1ccc(-c2nc(-c3ccc4c(c3)sc3ccccc34)nc(-c3cc4ccccc4cc3-c3ccc4ccccc4c3)n2)cc1]

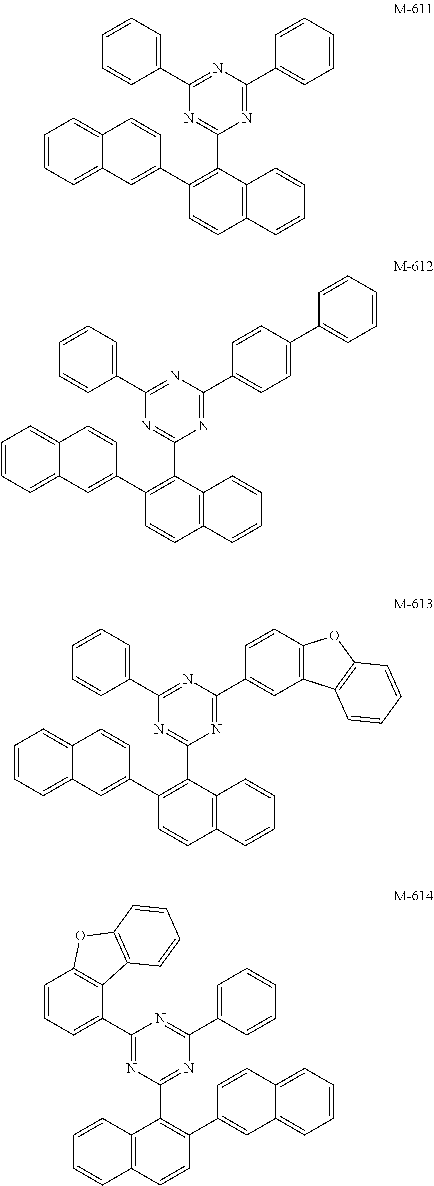 [SMILES: c1ccc(-c2nc(-c3ccccc3)nc(-c3c(-c4ccc5ccccc5c4)ccc4ccccc34)n2)cc1 ; c1ccc(-c2ccc(-c3nc(-c4ccccc4)nc(-c4c(-c5ccc6ccccc6c5)ccc5ccccc45)n3)cc2)cc1 ; c1ccc(-c2nc(-c3ccc4oc5ccccc5c4c3)nc(-c3c(-c4ccc5ccccc5c4)ccc4ccccc34)n2)cc1 ; c1ccc(-c2nc(-c3c(-c4ccc5ccccc5c4)ccc4ccccc34)nc(-c3cccc4oc5ccccc5c34)n2)cc1]

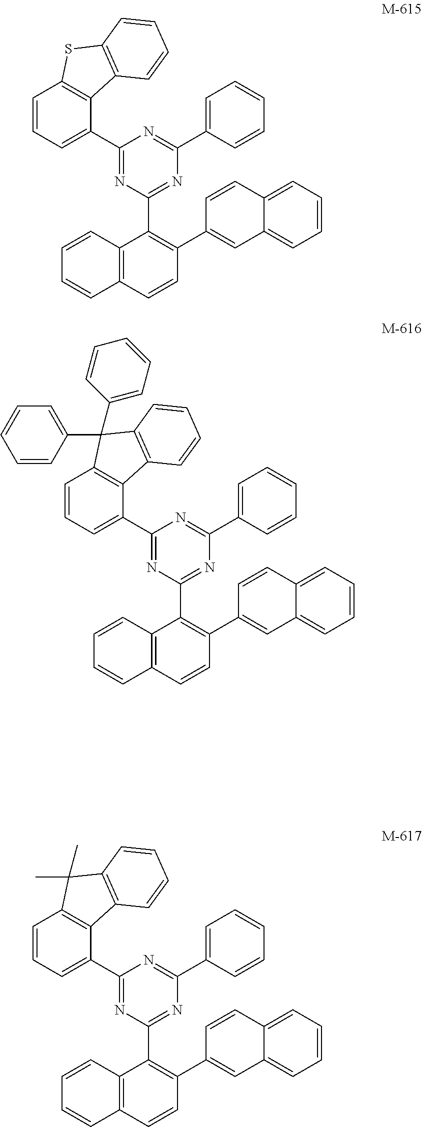

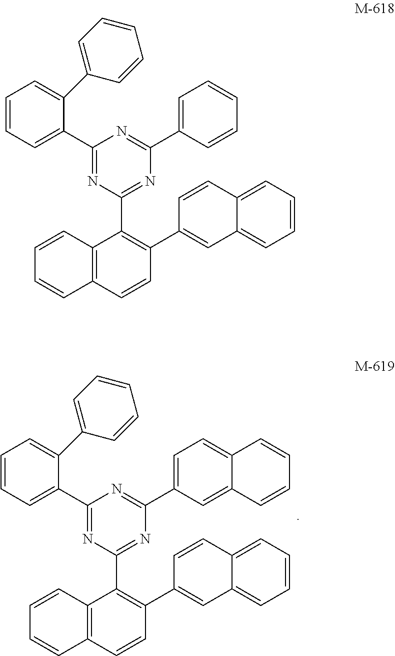 [SMILES: c1ccc(-c2nc(-c3ccccc3-c3ccccc3)nc(-c3c(-c4ccc5ccccc5c4)ccc4ccccc34)n2)cc1 ; c1ccc(-c2ccccc2-c2nc(-c3ccc4ccccc4c3)nc(-c3c(-c4ccc5ccccc5c4)ccc4ccccc34)n2)cc1]

13. The organic electroluminescent material composition according to claim 1, wherein the mass ratio of compound N to compound M is from 1:9 to 9:1.

14. A method for preparing optical devices, comprising using the organic electroluminescent material composition according to claim 1.

15. An organic electroluminescent device, wherein the organic electroluminescent device comprises an anode, a cathode, and an organic layer arranged between the anode and the cathode; wherein the organic layer comprises the organic electroluminescent material composition according to claim 1.

16. An organic electroluminescent equipment, comprising the organic electroluminescent device according to claim 15.

17. The organic electroluminescent material composition according to claim 1, wherein the mass ratio of compound N to compound M is from 2:8 to 8:2.

18. The organic electroluminescent material composition according to claim 1, wherein the mass ratio of compound N to compound M is from 3:7 to 7:3.

19. The organic electroluminescent material composition according to claim 1, wherein the mass ratio of compound N to compound M is from 4:6 to 6:4.

20. An organic electroluminescent device according to claim 15, wherein an light emitting layer in the organic layer comprises the organic electroluminescent material composition according to claim 1.
